(19) United States
(12) Patent Application Publication
(10) Pub. No.: US 2025/0368891 A1
(43) Pub. Date: Dec. 4, 2025

(54) COMPOUND AND ORGANIC LIGHT-EMITTING ELEMENT COMPRISING SAME

(71) Applicants: LG CHEM, LTD., Seoul (KR); SEOUL NATIONAL UNIVERSITY R&DB FOUNDATION, Seoul (KR)

(72) Inventors: Moung Gon KIM, Daejeon (KR); Min Sang KWON, Seongnam-si (KR); Kyunghee KIM, Daejeon (KR); Woochul LEE, Daejeon (KR)

(21) Appl. No.: 18/875,031

(22) PCT Filed: Mar. 21, 2024
(86) PCT No.: PCT/KR2024/003563

§ 371 Date: Dec. 13, 2024

(30) Foreign Application Priority Data
Mar. 21, 2023 (KR) 10-2023-0036948
Mar. 20, 2024 (KR) 10-2024-0038563

(51) Int. Cl. C09K 11/06; H10K 50/12; H10K 85/60

(52) U.S. Cl. CPC C09K 11/06; H10K 50/12; H10K 85/658; C09K 2211/1022

(57) ABSTRACT

A compound of Chemical Formula 1:

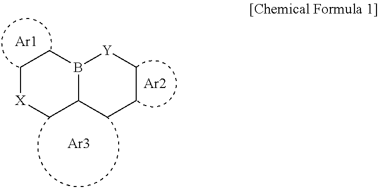

wherein: X is NR, O, or S; Y is O or S; Ar1, Ar2 and Ar3 are each independently a substituted or unsubstituted monocyclic or polycyclic hydrocarbon ring, or a substituted or unsubstituted monocyclic or polycyclic hetero ring, provided that at least one of Ar1, Ar2 and Ar3 includes a hetero ring or a substituted or unsubstituted aliphatic hydrocarbon ring, and when X is NR, at least one of R, Ar1, Ar2 and Ar3 includes a ring in which substituted or unsubstituted aliphatic hydrocarbon rings are fused; when X is NR, at least one of Ar1 and Ar3 is optionally bonded to R to form a ring, and Ar2 and Ar3 are optionally bonded to each other to form a ring; and the other substituents are as defined in the specification; and an organic light-emitting element including the same.

### CROSS-REFERENCE TO RELATED APPLICATION(S)

This application is a National Stage Application of International Application No. PCT/KR2024/003563 filed on Mar. 21, 2024, which claims priority to and the benefit of Korean Patent Application Nos. 10-2023-0036948 and 10-2024-0038563 filed in the Korean Intellectual Property Office on Mar. 21, 2023 and Mar. 20, 2024, respectively, the entire contents of which are incorporated herein by reference.

### TECHNICAL FIELD

The present specification relates to a compound and an organic light emitting device including the same.

### BACKGROUND

An organic light emission phenomenon generally refers to a phenomenon converting electrical energy to light energy using an organic material. An organic light emitting device using an organic light emission phenomenon normally has a structure including a positive electrode, a negative electrode, and an organic material layer therebetween. Here, the organic material layer has in many cases a multi-layered structure composed of different materials in order to improve the efficiency and stability of the organic light emitting device, and for example, may be composed of a hole injection layer, a hole transport layer, a light emitting layer, an electron transport layer, an electron injection layer, and the like. In such a structure of the organic light emitting device, if a voltage is applied between the two electrodes, holes are injected from the positive electrode into the organic material layer and electrons are injected from the negative electrode into the organic material layer, and when the injected holes and electrons meet each other, an exciton is formed, and light is emitted when the exciton falls down again to a ground state.

There is a continuous need for developing a new material for the aforementioned organic light emitting device.

### Citation List

### Patent Document

(Patent Document 1) Korean Patent Application Laid-Open Publication No. 10-2020-129990

### DETAILED DESCRIPTION OF THE INVENTION

### Technical Problem

The present specification provides a compound and an organic light emitting device including the same.

### Technical Solution

An exemplary embodiment of the present specification provides a compound represented by the following Chemical Formula 1.

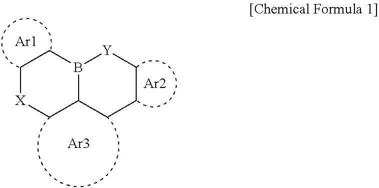

In Chemical Formula 1,
X is NR, O or S,
Y is O or S,
Ar1, Ar2 and Ar3 are the same as or different from each other, and are each independently a substituted or unsubstituted monocyclic or polycyclic hydrocarbon ring; or a substituted or unsubstituted monocyclic or polycyclic hetero ring, provided that at least one of Ar1, Ar2 and Ar3 includes a hetero ring; or a substituted or unsubstituted aliphatic hydrocarbon ring, and further, when X is NR, at least one of R, Ar1, Ar2 and Ar3 includes a ring in which substituted or unsubstituted aliphatic hydrocarbon rings are fused,
when X is NR, at least one of Ar1 and Ar3 may be bonded to R to form a ring, and Ar2 and Ar3 may be bonded to each other to form a ring, and
R is hydrogen; deuterium; a substituted or unsubstituted alkyl group; a substituted or unsubstituted aryl group; or a substituted or unsubstituted heteroaryl group.

Further, an exemplary embodiment of the present specification provides an organic light emitting device including: a positive electrode; a negative electrode; and an organic material layer having one or more layers provided between the positive electrode and the negative electrode, in which one or more layers of the organic material layers include the above-described compound.

### Advantageous Effects

The compound described in the present specification can be used as a material for an organic material layer of an organic light emitting device. The compound according to at least one exemplary embodiment of the present specification can have a narrow full width at half maximum, enhance efficiency, achieve low driving voltage, and/or improve service life characteristics in the organic light emitting device.

### BRIEF DESCRIPTION OF DRAWINGS

FIG. 1 illustrates an example of an organic light emitting device in which a substrate 1, a positive electrode 2, a light emitting layer 6, and a negative electrode 10 are sequentially stacked.

FIG. 2 illustrates an example of an organic light emitting device in which a substrate 1, a positive electrode 2, a hole injection layer 3, a hole transport layer 4, an electron blocking layer 5, a light emitting layer 6, a first electron transport layer 7, a second electron transport layer 8, an electron injection layer 9 and a negative electrode 10 are sequentially stacked.

### DETAILED DESCRIPTION

Hereinafter, the present specification will be described in more detail.

When one part “includes” one constituent element in the present specification, unless otherwise specifically described, this does not mean that another constituent element is excluded, but means that another constituent element may be further included.

When one member is disposed “on” another member in the present specification, this includes not only a case where the one member is brought into contact with another member, but also a case where still another member is present between the two members.

In the present specification, “*” means a position bonded to a formula or a compound.

Examples of the substituents in the present specification will be described below, but are not limited thereto.

The term “substitution” means that a hydrogen atom bonded to a carbon atom of a compound is changed into another substituent, and a position to be substituted is not limited as long as the position is a position at which the hydrogen atom is substituted, that is, a position at which the substituent may be substituted, and when two or more are substituted, the two or more substituents may be the same as or different from each other.

In the present invention, the term “substituted or unsubstituted” means being substituted with one or two or more substituents selected from the group consisting of deuterium; a halogen group; a nitrile group (—CN); a nitro group; a hydroxyl group; an alkyl group; a cycloalkyl group; an alkoxy group; a phosphine oxide group; an aryloxy group; an alkylthioxy group; an arylthioxy group; an alkylsulfoxy group; an arylsulfoxy group; an alkenyl group; a silyl group; a boron group; an amine group; an aryl group; or a heterocyclic group, being substituted with a substituent in which two or more substituents among the exemplified substituents are linked together, or having no substituent. For example, “the substituent in which two or more substituents are linked together” may be a biphenyl group. That is, the biphenyl group may also be an aryl group, and may be interpreted as a substituent in which two phenyl groups are linked together.

In the present specification, the term “substituted or unsubstituted” means being substituted with one or two or more substituents selected from the group consisting of deuterium; a halogen group; a nitrile group; a nitro group; a hydroxyl group; an amino group; an alkoxy group; an aryloxy group; an alkyl group; a cycloalkyl group; an alkenyl group; an alkynyl group; an aryl group; and a heterocyclic group, being substituted with a substituent in which two or more substituents among the exemplified substituents are linked together, or having no substituent.

In the present specification, the term “substituted or unsubstituted” means being substituted with one or two or more substituents selected from the group consisting of deuterium; a halogen group; a nitrile group; alkyl group; an aryl group; and a heterocyclic group, being substituted with a substituent in which two or more substituents among the exemplified substituents are linked together, or having no substituent.

Examples of the substituents will be described below; however, the substituents are not limited thereto.

In the present specification, examples of a halogen group include fluorine (—F), chlorine (—Cl), bromine (—Br) or iodine (—I).

In the present specification, the alkyl group may be straight-chained or branched, and the number of carbon atoms thereof is not particularly limited, but is preferably 1 to 60. According to an exemplary embodiment, the number of carbon atoms of the alkyl group is 1 to 30. According to another exemplary embodiment, the number of carbon atoms of the alkyl group is 1 to 20. According to still another exemplary embodiment, the number of carbon atoms of the alkyl group is 1 to 10. Specific examples of the alkyl group include a methyl group, an ethyl group, a propyl group, an n-propyl group, an isopropyl group, a butyl group, an n-butyl group, an isobutyl group, a tert-butyl group, a pentyl group, an n-pentyl group, a hexyl group, an n-hexyl group, a heptyl group, an n-heptyl group, an octyl group, an n-octyl group, and the like, but are not limited thereto.

In the present specification, the alkoxy group may be straight-chained, branched, or cyclic. The number of carbon atoms of the alkoxy group is not particularly limited, but is preferably 1 to 20. Specific examples thereof include methoxy, ethoxy, n-propoxy, isopropoxy, n-butoxy, isobutoxy, tert-butoxy, sec-butoxy, n-pentyloxy, neopentyloxy, isopentyloxy, n-hexyloxy, 3,3-dimethylbutyloxy, 2-ethylbutyloxy, n-octyloxy, n-nonyloxy, n-decyloxy, and the like, but are not limited thereto.

Substituents including an alkyl group, an alkoxy group, and other alkyl group moieties described in the present specification include both a straight-chained form and a branched form.

In the present specification, an alkenyl group may be straight-chained or branched, and the number of carbon atoms thereof is not particularly limited, but is preferably 2 to 40. According to an exemplary embodiment, the number of carbon atoms of the alkenyl group is 2 to 20. According to another exemplary embodiment, the number of carbon atoms of the alkenyl group is 2 to 10. According to still another exemplary embodiment, the number of carbon atoms of the alkenyl group is 2 to 6. Specific examples thereof include vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, a stilbenyl group, a styrenyl group, and the like, but are not limited thereto.

In the present specification, the alkynyl group may be straight-chained or branched as a substituent including a triple bond between a carbon atom and a carbon atom, and the number of carbon atoms thereof is not particularly limited, but is preferably 2 to 40. According to an exemplary embodiment, the number of carbon atoms of the alkynyl group is 2 to 20. According to another exemplary embodiment, the number of carbon atoms of the alkynyl group is 2 to 10.

In the present specification, a cycloalkyl group is not particularly limited, but has preferably 3 to 60 carbon atoms, and according to an exemplary embodiment, the number of carbon atoms of the cycloalkyl group is 3 to 30. According to another exemplary embodiment, the number of carbon atoms of the cycloalkyl group is 3 to 20. According to another embodiment, the number of carbon atoms of the cycloalkyl group is from 3 to 6. Specific examples thereof may include a cyclopropyl group, a cyclobutyl group, a cyclopentyl group, a cyclohexyl group, a cycloheptyl group, a cyclooctyl group and the like, but are not limited thereto.

In the present specification, an amine group is —NH₂, and the amine group may be substituted with the above-described alkyl group, aryl group, heterocyclic group, alkenyl group, cycloalkyl group, a combination thereof, and the like. The number of carbon atoms of the substituted amine group is not particularly limited, but is preferably 1 to 30. According to an exemplary embodiment, the number of carbon atoms of the amine group is 1 to 20. According to an exemplary embodiment, the number of carbon atoms of the amine group is 1 to 10. Specific examples of the substituted amine group include a methylamine group, a dimethylamine group, an ethylamine group, a diethylamine group, a phenylamine group, a 9,9-dimethylfluorenylphenylamine group, a pyridylphenylamine group, a diphenylamine group, a phenylpyridylamine group, a naphthylamine group, a biphenylamine group, an anthracenylamine group, a dibenzofuranylphenylamine group, a 9-methylanthracenylamine group, a phenylnaphthylamine group, a ditolylamine group, a phenyltolylamine group, and the like, but are not limited thereto.

In the present specification, an aryl group is not particularly limited, but has preferably 6 to 60 carbon atoms, and may be a monocyclic aryl group or a polycyclic aryl group. According to an exemplary embodiment, the number of carbon atoms of the aryl group is from 6 to 30. According to an exemplary embodiment, the number of carbon atoms of the aryl group is from 6 to 20. Examples of the monocyclic aryl group include a phenyl group, a biphenyl group, a terphenyl group, a quaterphenyl group, and the like, but are not limited thereto. Examples of the polycyclic aryl group include a naphthyl group, an anthracenyl group, a phenanthrene group, a pyrenyl group, a perylenyl group, a triphenylene group, a chrysenyl group, a fluorenyl group, and the like, but are not limited thereto. Here, the aryl group includes not only a structure composed only of aromatic hydrocarbon rings but also a structure in which an aromatic hydrocarbon ring is fused with an aliphatic hydrocarbon ring.

In the present specification, a fluorenyl group may be substituted, and two substituents may be bonded to each other to form a spiro structure. In this case, the spiro structure may be an aromatic hydrocarbon ring or an aliphatic hydrocarbon ring.

When the fluorenyl group is substituted, the substituent may be a spirofluorenyl group such as

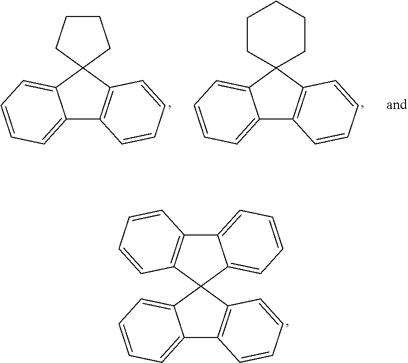

and a substituted fluorenyl group such as

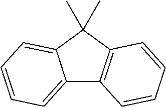

(a 9,9-dimethylfluorenyl group), and

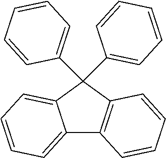 [SMILES: c1ccc(C2(c3ccccc3)c3ccccc3-c3ccccc32)cc1]

(a 9,9-diphenylfluorenyl group). However, the fluorenyl group is not limited thereto.

In the present specification, the above-described description of the aryl group may be applied to an aryl group in an aryloxy group and an arylamine group.

In the present specification, the above-described description of the alkyl group may be applied to an alkyl group in the alkylthioxy group and the alkylsulfoxy group.

In the present specification, the above-described description of the aryl group may be applied to an aryl group in the arylthioxy group and the arylsulfoxy group.

In the present specification, a heterocyclic group is a cyclic group including one or more of N, O, P, S, Si, and Se as a hetero atom, and the number of carbon atoms thereof is not particularly limited, but is preferably 2 to 60. According to an exemplary embodiment, the number of carbon atoms of the heterocyclic group is 2 to 30. According to an exemplary embodiment, the number of carbon atoms of the heterocyclic group is 2 to 20. Examples of the heterocyclic group include a pyridine group, a pyrrole group, a pyrimidine group, a quinoline group, a pyridazinyl group, a furan group, a thiophene group, an imidazole group, a pyrazole group, a dibenzofuran group, a dibenzothiophene group, a carbazole group, a benzocarbazole group, a naphthobenzofuran group, a benzonaphthothiophene group, an indenocarbazole group, a triazinyl group, and the like, but are not limited thereto. Here, the heterocyclic group includes not only a structure composed only of hetero rings, but also a structure in which a hetero ring is fused with an aromatic or aliphatic hydrocarbon ring.

In the present specification, the above-described description of the heterocyclic group may be applied to a heteroaryl group except for an aromatic heteroaryl group.

In the present specification, the description of the aryl group may be applied to an arylene group except for a divalent arylene group.

In the present specification, the description of the heteroaryl group may be applied to a heteroarylene group except for a divalent heteroarylene group.

In the present specification, the hydrocarbon ring includes an aromatic hydrocarbon ring, an aliphatic hydrocarbon ring, or a fused ring thereof.

In the present specification, the hetero ring includes an aromatic hetero ring, an aliphatic hetero ring, or a fused ring thereof. In the case of a ring in which two or more rings are fused, when one or more of the rings are rings including a non-carbon heteroatom as a ring member, the entire ring may be referred to as a hetero ring. In this case, a ring that may be fused with a ring including a heteroatom as a ring member may be a hetero ring or a hydrocarbon ring.

In the present specification, in a substituted or unsubstituted ring formed by being bonded to an adjacent group, the “ring” means a hydrocarbon ring or a hetero ring.

For example, when a group is bonded to an adjacent group to form a ring, it is possible to form a substituted or unsubstituted aliphatic hydrocarbon ring; a substituted or unsubstituted aromatic hydrocarbon ring; a substituted or unsubstituted aliphatic hetero ring; a substituted or unsubstituted aromatic hetero ring; or a fused ring thereof. The hydrocarbon ring means a ring composed only of carbon and hydrogen atoms. The hetero ring means a ring including one or more selected from elements such as N, O, P, S, Si and Se. In the present specification, the aliphatic hydrocarbon ring, the aromatic hydrocarbon ring, the aliphatic hetero ring, and the aromatic hetero ring may be monocyclic or polycyclic.

In the present specification, an aliphatic hydrocarbon ring means a ring composed only of carbon and hydrogen atoms as a ring which is not an aromatic group. Examples of the aliphatic hydrocarbon ring include cyclopropane, cyclobutane, cyclobutene, cyclopentane, cyclopentene, cyclohexane, cyclohexene, 1,4-cyclohexadiene, cycloheptane, cycloheptene, cyclooctane, cyclooctene, and the like, but are not limited thereto.

In the present specification, an aromatic hydrocarbon ring means an aromatic ring composed only of carbon and hydrogen atoms. Examples of the aromatic hydrocarbon ring include benzene, naphthalene, anthracene, phenanthrene, perylene, fluoranthene, triphenylene, phenalene, pyrene, tetracene, chrysene, pentacene, fluorene, indene, acenaphthylene, benzofluorene, spirofluorene, and the like, but are not limited thereto. In the present specification, the aromatic hydrocarbon ring may be interpreted to have the same meaning as the aryl group.

In the present specification, an aliphatic hetero ring means an aliphatic ring including one or more of hetero atoms. Examples of the aliphatic hetero ring include oxirane, tetrahydrofuran, 1,4-dioxane, pyrrolidine, piperidine, morpholine, oxepane, azocane, thiocane, and the like, but are not limited thereto.

In the present specification, an aromatic hetero ring means an aromatic ring including one or more of hetero atoms. Examples of the aromatic hetero ring include pyridine, pyrrole, pyrimidine, pyridazine, furan, thiophene, imidazole, pyrazole, oxazole, isoxazole, thiazole, isothiazole, triazole, oxadiazole, thiadiazole, dithiazole, tetrazole, pyran, thiopyran, diazine, oxazine, thiazine, dioxine, triazine, tetrazine, isoquinoline, quinoline, quinone, quinazoline, quinoxaline, naphthyridine, acridine, phenanthridine, diaza naphthalene, triazaindene, indole, indolizine, benzothiazole, benzoxazole, benzoimidazole, benzothiophene, benzofuran, dibenzothiophene, dibenzofuran, carbazole, benzocarbazole, dibenzocarbazole, phenazine, imidazopyridine, phenoxazine, indolocarbazole, indenocarbazole, and the like, but are not limited thereto.

Hereinafter, preferred exemplary embodiments of the present invention will be described in detail. However, the exemplary embodiments of the present invention may be modified into various other forms, and the scope of the present invention is not limited to the exemplary embodiments which will be described below.

Hereinafter, a compound of the following Chemical Formula 1 will be described in detail.

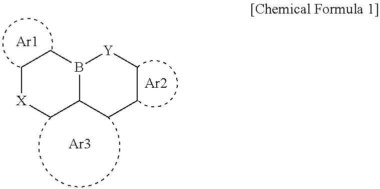

In Chemical Formula 1, the definition of the substituent is the same as that described above.

According to an exemplary embodiment, Ar1, Ar2 and Ar3 are the same as or different from each other, and are each independently a substituted or unsubstituted aromatic hydrocarbon ring; a substituted or unsubstituted fused ring of an aromatic hydrocarbon ring and an aliphatic hydrocarbon ring; a substituted or unsubstituted hetero ring; a substituted or unsubstituted fused ring of a hetero ring and an aromatic hydrocarbon ring; or a substituted or unsubstituted fused ring of a hetero ring, an aromatic hydrocarbon ring and an aliphatic hydrocarbon ring, and at least one of Ar1, Ar2 and Ar3 is a substituted or unsubstituted fused ring of an aromatic hydrocarbon ring and an aliphatic hydrocarbon ring; a substituted or unsubstituted hetero ring; a substituted or unsubstituted fused ring of a hetero ring and an aromatic hydrocarbon ring; or a substituted or unsubstituted fused ring of a hetero ring, an aromatic hydrocarbon ring and an aliphatic hydrocarbon ring.

According to an exemplary embodiment, Ar1, Ar2 and Ar3 are the same as or different from each other, and are each independently a substituted or unsubstituted aromatic hydrocarbon ring; a substituted or unsubstituted fused ring of an aromatic hydrocarbon ring and an aliphatic hydrocarbon ring; a substituted or unsubstituted hetero ring including O or S as a heteroelement; a substituted or unsubstituted fused ring of a hetero ring including O or S as a heteroelement and an aromatic hydrocarbon ring; or a substituted or unsubstituted fused ring of a hetero ring including 0 or S as a heteroelement, an aromatic hydrocarbon ring and an aliphatic hydrocarbon ring, and at least one of Ar1, Ar2 and Ar3 is a substituted or unsubstituted fused ring of an aromatic hydrocarbon ring and an aliphatic hydrocarbon ring; a substituted or unsubstituted hetero ring including O or S as a heteroelement; a substituted or unsubstituted fused ring of a hetero ring including 0 or S as a heteroelement and an aromatic hydrocarbon ring; or a substituted or unsubstituted fused ring of a hetero ring including O or S as a heteroelement, an aromatic hydrocarbon ring and an aliphatic hydrocarbon ring.

According to an exemplary embodiment, Ar1, Ar2 and Ar3 are the same as or different from each other, and are each independently substituted or unsubstituted benzene, substituted or unsubstituted tetrahydronaphthalene, substituted or unsubstituted fluorene, substituted or unsubstituted furan, substituted or unsubstituted benzofuran, substituted or unsubstituted dibenzofuran, substituted or unsubstituted tetrahydronaphthofuran, substituted or unsubstituted tetrahydrobenzonaphthofuran, substituted or unsubstituted thiophene, substituted or unsubstituted benzothiophene, substituted or unsubstituted dibenzothiophene, substituted or unsubstituted tetrahydronaphthothiophene, or substituted or unsubstituted tetrahydrobenzonaphthothiophene, and at least one of Ar1, Ar2 and Ar3 is substituted or unsubstituted tetrahydronaphthalene, substituted or unsubstituted furan, substituted or unsubstituted benzofuran, substituted or unsubstituted dibenzofuran, substituted or unsubstituted tetrahydronaphthofuran, substituted or unsubstituted tetrahydrobenzonaphthofuran, substituted or unsubstituted thiophene, substituted or unsubstituted benzothiophene, substituted or unsubstituted dibenzothiophene, substituted or unsubstituted tetrahydronaphthothiophene, or substituted or unsubstituted tetrahydrobenzonaphthothiophene.

According to an exemplary embodiment, at least one of Ar1, Ar2 and Ar3 includes substituted or unsubstituted tetrahydronaphthalene, or X is NR and R is substituted or unsubstituted tetrahydronaphthalene.

According to an exemplary embodiment, at least one of Ar1 and Ar2 is substituted or unsubstituted tetrahydronaphthalene, or X is NR and R is substituted or unsubstituted tetrahydronaphthalene, or at least one of Ar1 and Ar2 is a hetero ring in which substituted or unsubstituted tetrahydronaphthalene is fused.

According to an exemplary embodiment, Chemical Formula 1 is represented by any one of the following Chemical Formulae 11 to 13:

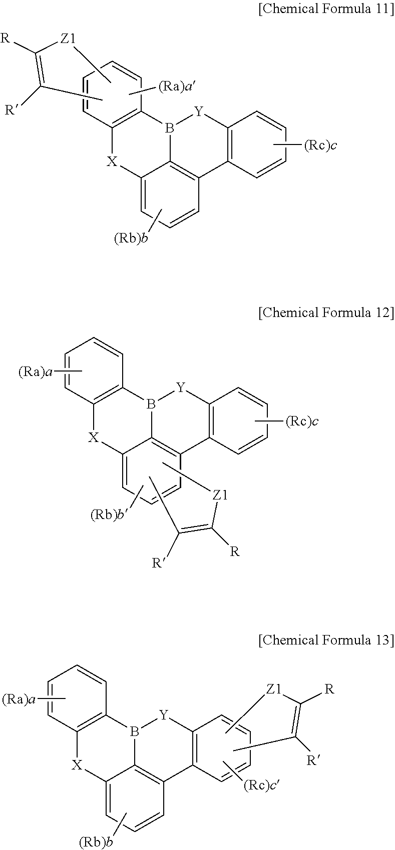

wherein in Chemical Formulae 11 to 13,
X and Y are the same as those defined in Chemical Formula 1,
Z1 is CRxRy, O or S, and
Ra to Rc, Rx, Ry, R and R′ are the same as or different from each other, and are each independently hydrogen; deuterium; a substituted or unsubstituted alkyl group; a substituted or unsubstituted aryl group; or a substituted or unsubstituted heteroaryl group; or are linked to adjacent groups to form a substituted or unsubstituted ring, a and c are each an integer from 0 to 4, b is an integer from 0 to 3, a′ and c′ are each an integer from 0 to 2, and b′ is 0 or 1.

According to an exemplary embodiment, Chemical Formula 1 is represented by any one of the following Chemical Formulae 21 to 23:

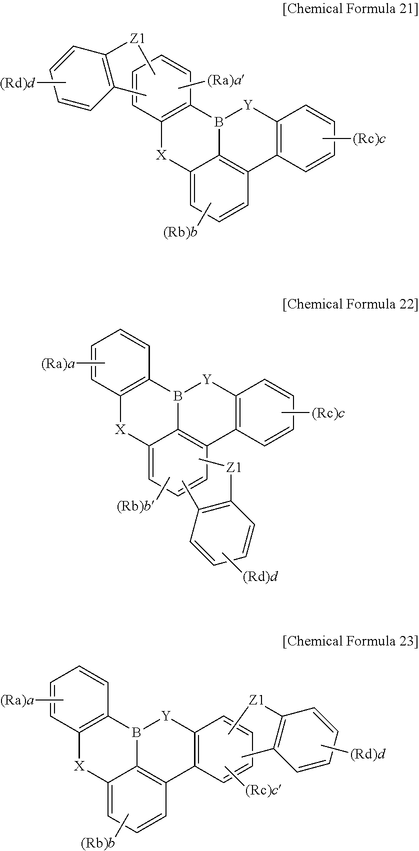

wherein in Chemical Formulae 21 to 23,
X, Y, Z1, Ra to Rc, a, b, c, a′, b′ and c′ are the same as those described above, and
the Rds are the same as or different from each other, and are each independently hydrogen; deuterium; a substituted or unsubstituted alkyl group; a substituted or unsubstituted aryl group; or a substituted or unsubstituted heteroaryl group; or are linked to adjacent groups to form a substituted or unsubstituted ring, and d is an integer from 0 to 4.

According to an exemplary embodiment, Chemical Formula 1 is represented by any one of the following Chemical Formulae 31 to 34:

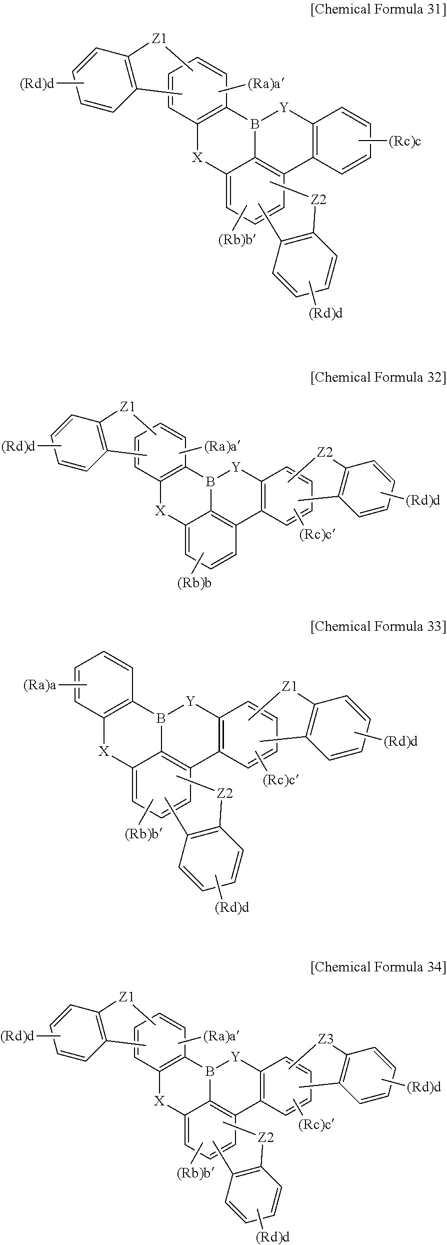

wherein in Chemical Formulae 31 to 34,
X, Y, Z1, Ra to Rd, a, b, c, d, a′, b′ and c′ are the same as those described above, and
Z2 and Z3 are the same as or different from each other, and are each independently CRxRy, O or S, and Rx and Ry are the same as those described above.

According to an exemplary embodiment, Chemical Formula 1 is represented by any one of the following Chemical Formulae 41 to 43.

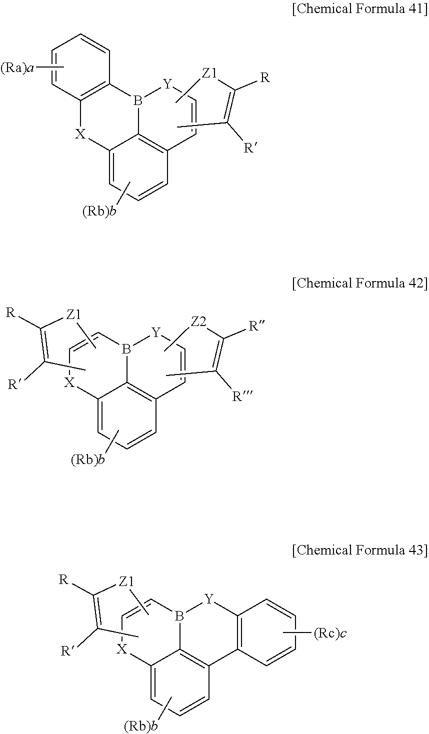

In Chemical Formulae 41 to 43,
X and Y are the same as those defined in Chemical Formula 1,
Z1 and Z2 are each independently CRxRy, O or S, and
Ra to Rc, Rx, Ry, R, R′, R″ and R′″ are the same as or different from each other, and are each independently hydrogen; deuterium; a substituted or unsubstituted alkyl group; a substituted or unsubstituted aryl group; or a substituted or unsubstituted heteroaryl group; or are linked to adjacent groups to form a substituted or unsubstituted ring, a and c are each an integer from 0 to 4, and b is an integer from 0 to 3.

According to an exemplary embodiment, R and R′ of Chemical Formulae 41 to 43 are bonded to each other to form substituted or unsubstituted benzene, or substituted or unsubstituted tetrahydronaphthalene.

According to an exemplary embodiment, R and R′ of Chemical Formulae 41 to 43 are bonded to each other to form benzene unsubstituted or substituted with an alkyl group, or tetrahydronaphthalene unsubstituted or substituted with an alkyl group.

According to an exemplary embodiment, Rb of Chemical Formulae 41 to 43 is hydrogen or deuterium, or forms a substituted or unsubstituted aliphatic ring, a substituted or unsubstituted aromatic ring, or a substituted or unsubstituted hetero ring.

According to an exemplary embodiment, Rb of Chemical Formulae 41 to 43 is hydrogen or deuterium, or forms an aliphatic ring unsubstituted or substituted with deuterium or an alkyl group, an aromatic ring unsubstituted or substituted with deuterium or an alkyl group, or a hetero ring unsubstituted or substituted with deuterium or an alkyl group.

According to an exemplary embodiment, Rc of Chemical Formulae 41 to 43 is hydrogen or deuterium, or forms a substituted or unsubstituted aliphatic ring, a substituted or unsubstituted aromatic ring, or a substituted or unsubstituted hetero ring.

According to an exemplary embodiment, Rc of Chemical Formulae 41 to 43 is hydrogen or deuterium, or forms substituted or unsubstituted hexane, substituted or unsubstituted benzene, substituted or unsubstituted indene, substituted or unsubstituted benzofuran, or substituted or unsubstituted benzothiophene.

According to an exemplary embodiment, Rc of Chemical Formulae 41 to 43 is hydrogen or deuterium, or forms hexane unsubstituted or substituted with deuterium or an alkyl group, benzene unsubstituted or substituted with deuterium or an alkyl group, indene unsubstituted or substituted with deuterium or an alkyl group, benzofuran unsubstituted or substituted with deuterium or an alkyl group, or benzothiophene unsubstituted or substituted with deuterium or an alkyl group.

According to an exemplary embodiment, Chemical Formula 1 includes a C1 to C6 straight-chained or branched alkyl group or cycloalkyl group.

According to an exemplary embodiment, Chemical Formula 1 includes an arylamine group unsubstituted or substituted with an alkyl group; or a heteroarylamine group unsubstituted or substituted with an alkyl group.

According to an exemplary embodiment, Rb is hydrogen, deuterium, a C1 to C6 straight-chained or branched alkyl group, a cycloalkyl group, an arylamine group unsubstituted or substituted with an alkyl group; or a heteroarylamine group unsubstituted or substituted with an alkyl group.

According to an exemplary embodiment, Rc is hydrogen, deuterium, a C1 to C6 straight-chained or branched alkyl group, a cycloalkyl group, an arylamine group unsubstituted or substituted with an alkyl group; or a heteroarylamine group unsubstituted or substituted with an alkyl group.

According to an exemplary embodiment, Rc is hydrogen, deuterium, or an arylamine group unsubstituted or substituted with an alkyl group.

According to an exemplary embodiment, X is NR, and R includes a C1 to C6 straight-chained or branched alkyl group or cycloalkyl group.

According to an exemplary embodiment, X is NR, and R is phenyl substituted with a C1 to C6 straight-chained or branched alkyl group or cycloalkyl group, biphenyl substituted with a C1 to C6 straight-chained or branched alkyl group or cycloalkyl group, a tetrahydronaphthalene group substituted with an alkyl group, dibenzofuran, or dibenzothiophene.

According to an exemplary embodiment, X is NR, and Y is O.

According to an exemplary embodiment, X is NR, and Y is S.

According to an exemplary embodiment, X is O, and Y is O.

According to an exemplary embodiment, X is S, and Y is O.

According to an exemplary embodiment, X is O, and Y is S.

According to an exemplary embodiment, X is S, and Y is S.

According to an exemplary embodiment, the compound of Chemical Formula 1 may be represented by the following compounds:

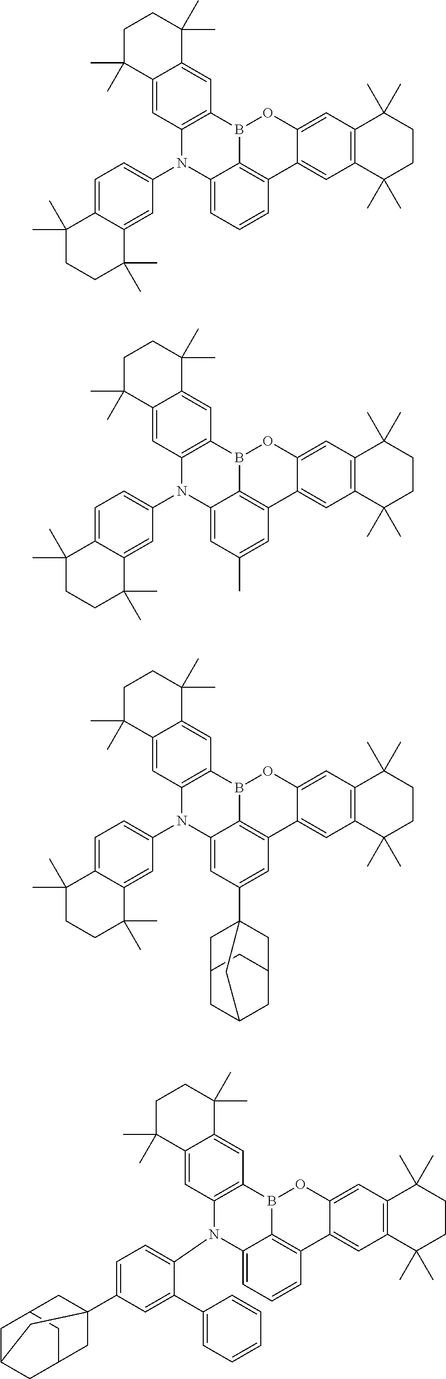 [SMILES: CC1(C)CCC(C)(C)c2cc(N3c4cc5c(cc4B4Oc6cc7c(cc6-c6cccc3c64)C(C)(C)CCC7(C)C)C(C)(C)CCC5(C)C)ccc21 ; Cc1cc2c3c(c1)N(c1ccc4c(c1)C(C)(C)CCC4(C)C)c1cc4c(cc1B3Oc1cc3c(cc1-2)C(C)(C)CCC3(C)C)C(C)(C)CCC4(C)C ; CC1(C)CCC(C)(C)c2cc(N3c4cc5c(cc4B4Oc6cc7c(cc6-c6cc(C89CC%10CC(CC(C%10)C8)C9)cc3c64)C(C)(C)CCC7(C)C)C(C)(C)CCC5(C)C)ccc21 ; CC1(C)CCC(C)(C)c2cc3c(cc21)OB1c2cc4c(cc2N(c2ccc(C56CC7CC(CC(C7)C5)C6)cc2-c2ccccc2)c2cccc-3c21)C(C)(C)CCC4(C)C]

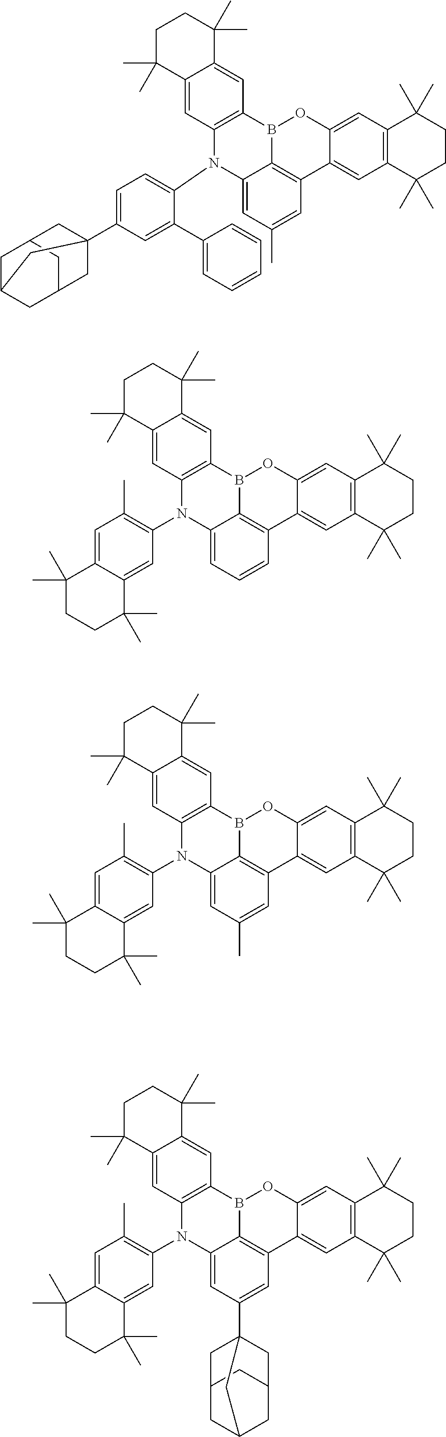 [SMILES: Cc1cc2c3c(c1)N(c1ccc(C45CC6CC(CC(C6)C4)C5)cc1-c1ccccc1)c1cc4c(cc1B3Oc1cc3c(cc1-2)C(C)(C)CCC3(C)C)C(C)(C)CCC4(C)C ; Cc1cc2c(cc1N1c3cc4c(cc3B3Oc5cc6c(cc5-c5cccc1c53)C(C)(C)CCC6(C)C)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Oc1cc3c(cc1-2)C(C)(C)CCC3(C)C)C(C)(C)CCC4(C)C ; Cc1cc2c(cc1N1c3cc4c(cc3B3Oc5cc6c(cc5-c5cc(C78CC9CC(CC(C9)C7)C8)cc1c53)C(C)(C)CCC6(C)C)C(C)(C)CCC4(C)C)C(C)(C)CCC2(C)C]

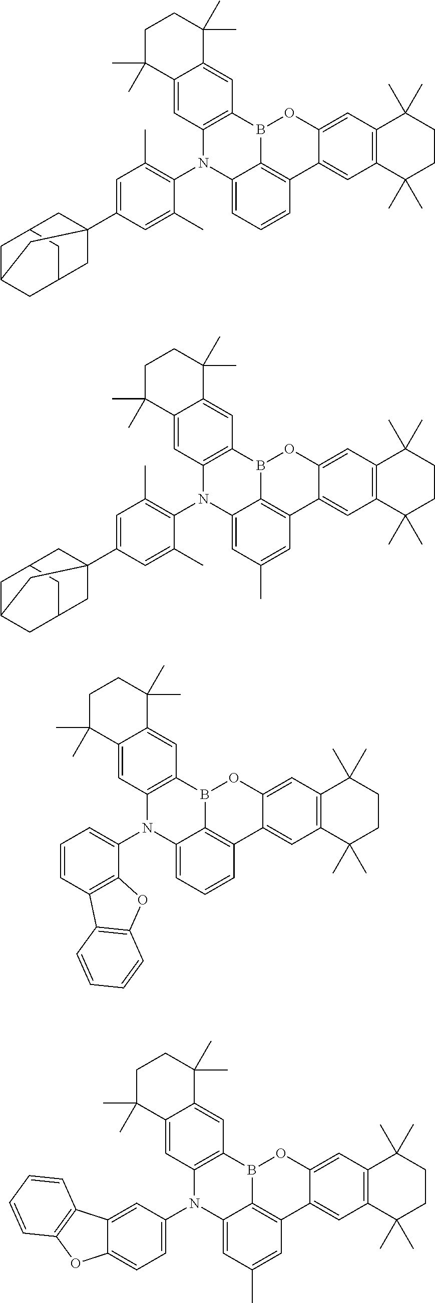 [SMILES: Cc1cc(C23CC4CC(CC(C4)C2)C3)cc(C)c1N1c2cc3c(cc2B2Oc4cc5c(cc4-c4cccc1c42)C(C)(C)CCC5(C)C)C(C)(C)CCC3(C)C ; Cc1cc2c3c(c1)N(c1c(C)cc(C45CC6CC(CC(C6)C4)C5)cc1C)c1cc4c(cc1B3Oc1cc3c(cc1-2)C(C)(C)CCC3(C)C)C(C)(C)CCC4(C)C ; CC1(C)CCC(C)(C)c2cc3c(cc21)OB1c2cc4c(cc2N(c2cccc5c2oc2ccccc25)c2cccc-3c21)C(C)(C)CCC4(C)C ; Cc1cc2c3c(c1)N(c1ccc4oc5ccccc5c4c1)c1cc4c(cc1B3Oc1cc3c(cc1-2)C(C)(C)CCC3(C)C)C(C)(C)CCC4(C)C]

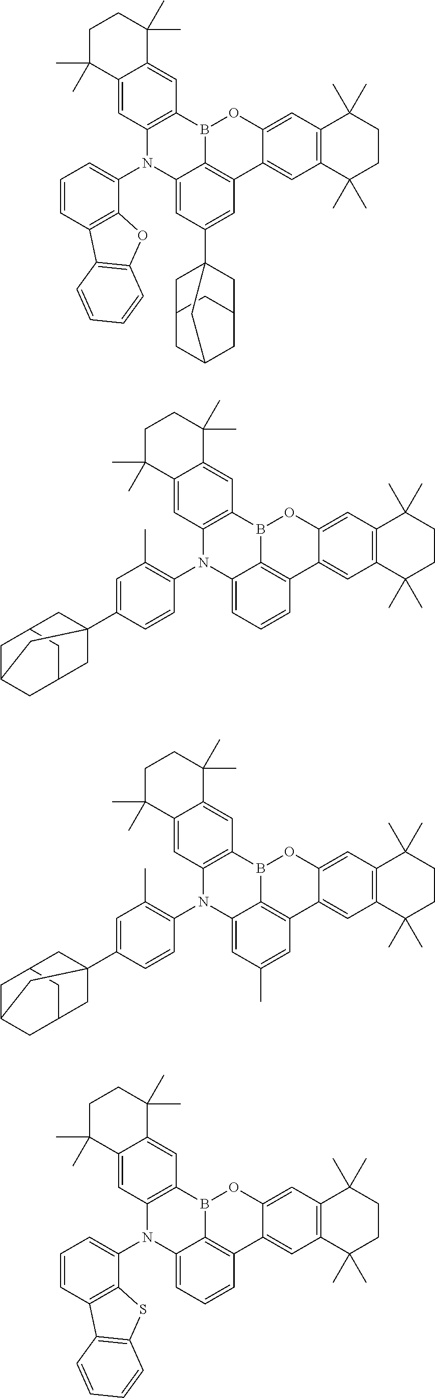

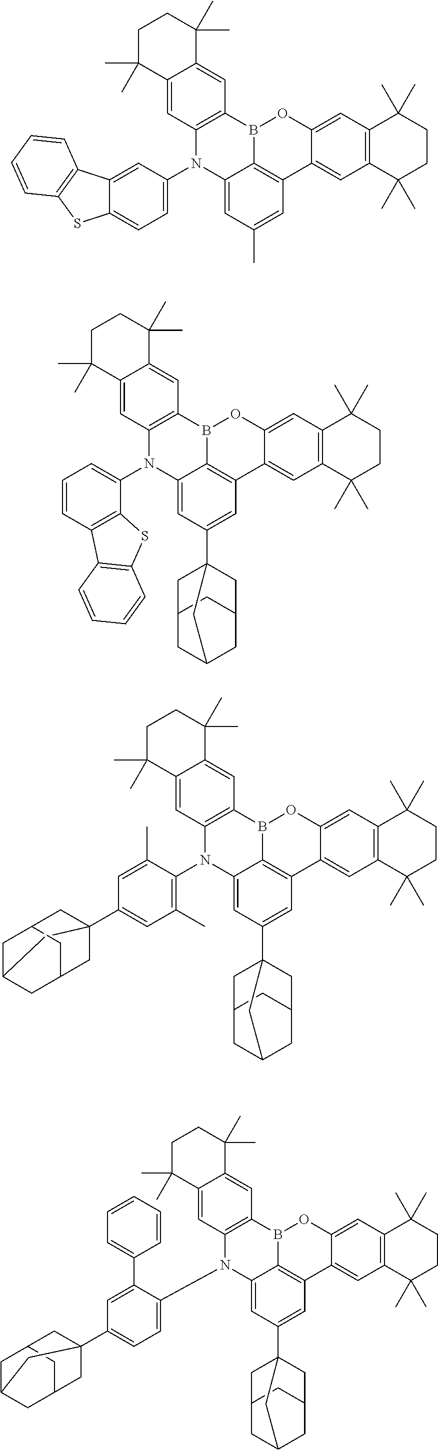

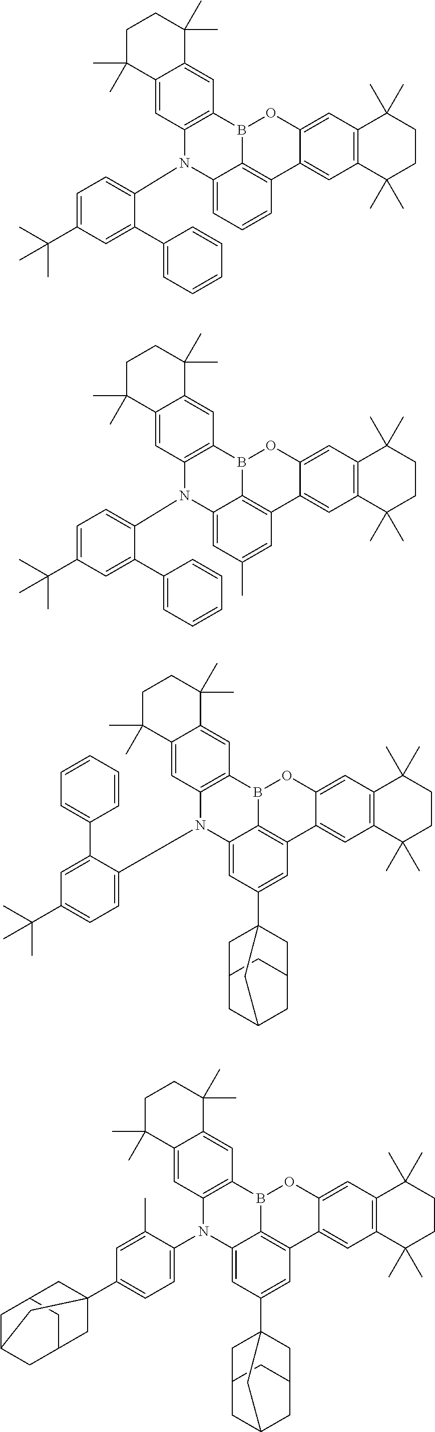

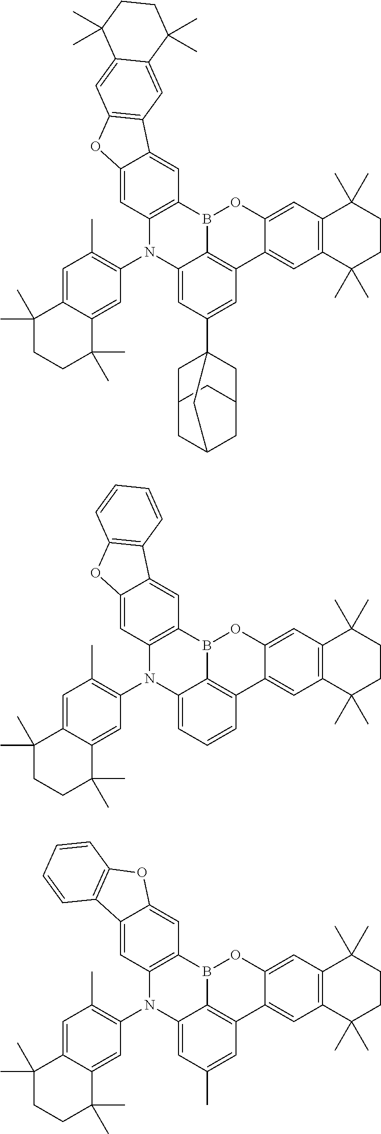

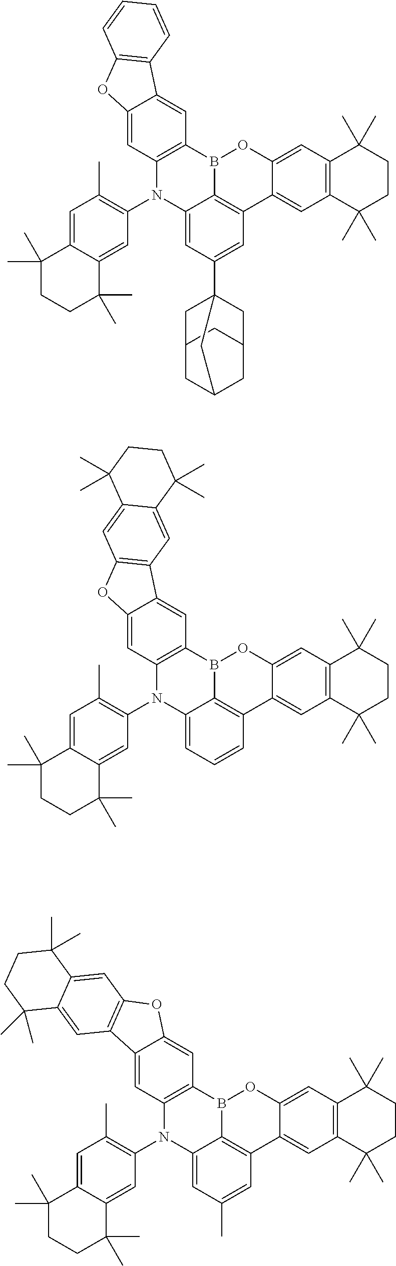 [SMILES: Cc1cc2c(cc1N1c3cc4oc5ccccc5c4cc3B3Oc4cc5c(cc4-c4cc(C67CC8CC(CC(C8)C6)C7)cc1c43)C(C)(C)CCC5(C)C)C(C)(C)CCC2(C)C ; Cc1cc2c(cc1N1c3cc4oc5cc6c(cc5c4cc3B3Oc4cc5c(cc4-c4cccc1c43)C(C)(C)CCC5(C)C)C(C)(C)CCC6(C)C)C(C)(C)CCC2(C)C ; Cc1cc2c3c(c1)N(c1cc4c(cc1C)C(C)(C)CCC4(C)C)c1cc4c(cc1B3Oc1cc3c(cc1-2)C(C)(C)CCC3(C)C)oc1cc2c(cc14)C(C)(C)CCC2(C)C]

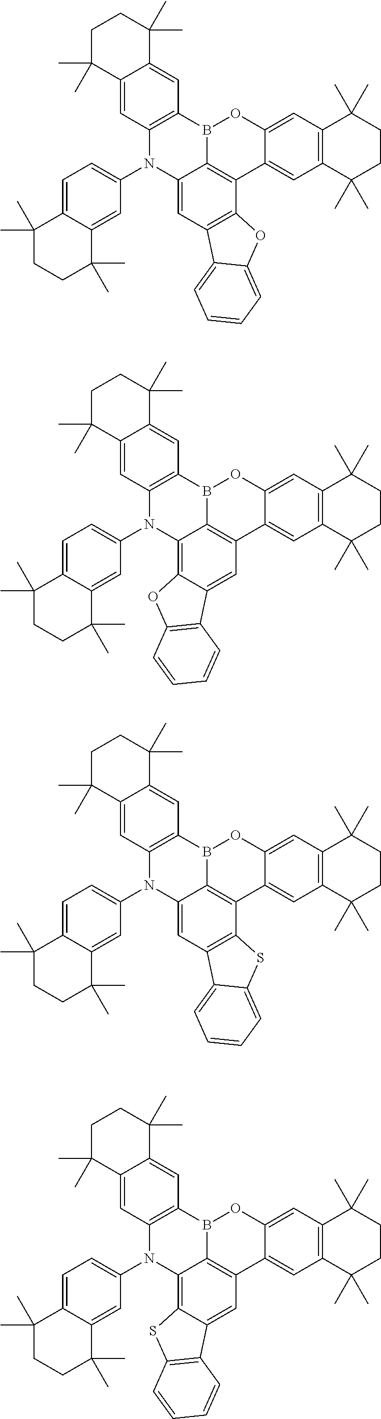

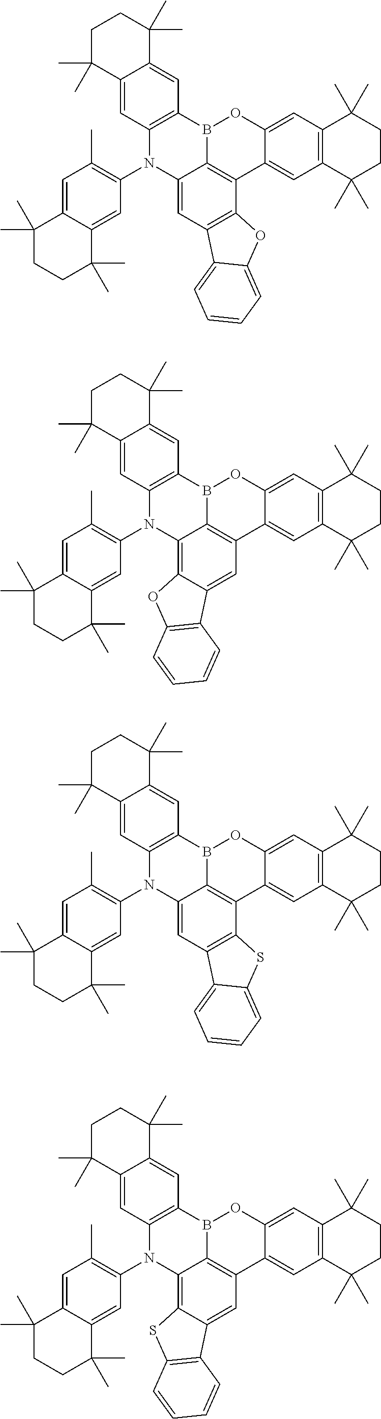

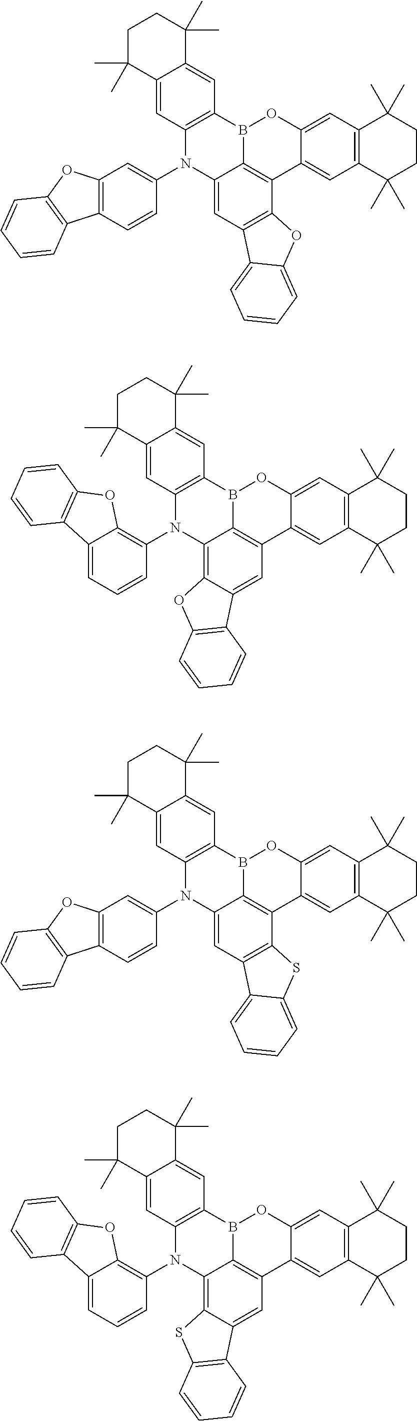

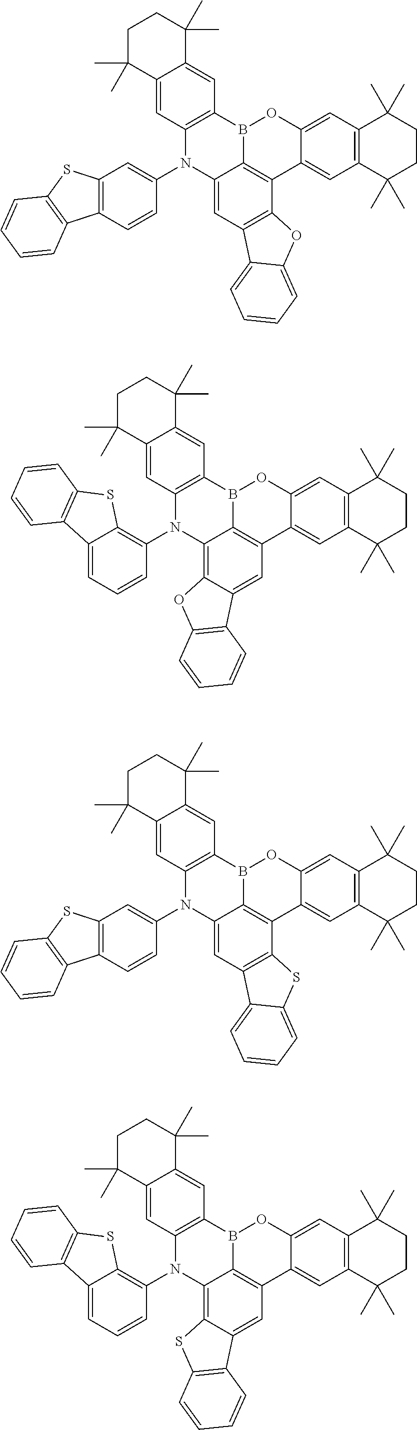 [SMILES: CC1(C)CCC(C)(C)c2cc3c(cc21)OB1c2cc4c(cc2N(c2ccc5c(c2)sc2ccccc25)c2cc5c(oc6ccccc65)c-3c21)C(C)(C)CCC4(C)C ; CC1(C)CCC(C)(C)c2cc3c(cc21)OB1c2cc4c(cc2N(c2cccc5c2sc2ccccc25)c2c1c-3cc1c2oc2ccccc21)C(C)(C)CCC4(C)C ; CC1(C)CCC(C)(C)c2cc3c(cc21)OB1c2cc4c(cc2N(c2ccc5c(c2)sc2ccccc25)c2cc5c(sc6ccccc65)c-3c21)C(C)(C)CCC4(C)C ; CC1(C)CCC(C)(C)c2cc3c(cc21)OB1c2cc4c(cc2N(c2cccc5c2sc2ccccc25)c2c1c-3cc1c2sc2ccccc21)C(C)(C)CCC4(C)C]

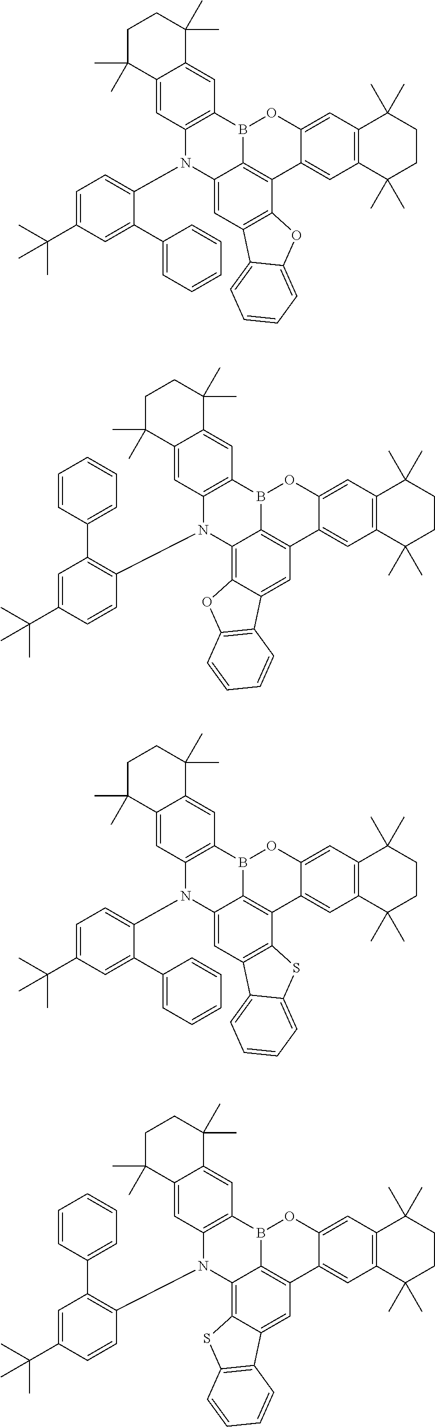 [SMILES: CC(C)(C)c1ccc(N2c3cc4c(cc3B3Oc5cc6c(cc5-c5c3c2cc2c5oc3ccccc32)C(C)(C)CCC6(C)C)C(C)(C)CCC4(C)C)c(-c2ccccc2)c1 ; CC(C)(C)c1ccc(N2c3cc4c(cc3B3Oc5cc6c(cc5-c5cc7c(oc8ccccc87)c2c53)C(C)(C)CCC6(C)C)C(C)(C)CCC4(C)C)c(-c2ccccc2)c1 ; CC(C)(C)c1ccc(N2c3cc4c(cc3B3Oc5cc6c(cc5-c5c3c2cc2c5sc3ccccc32)C(C)(C)CCC6(C)C)C(C)(C)CCC4(C)C)c(-c2ccccc2)c1 ; CC(C)(C)c1ccc(N2c3cc4c(cc3B3Oc5cc6c(cc5-c5cc7c(sc8ccccc87)c2c53)C(C)(C)CCC6(C)C)C(C)(C)CCC4(C)C)c(-c2ccccc2)c1]

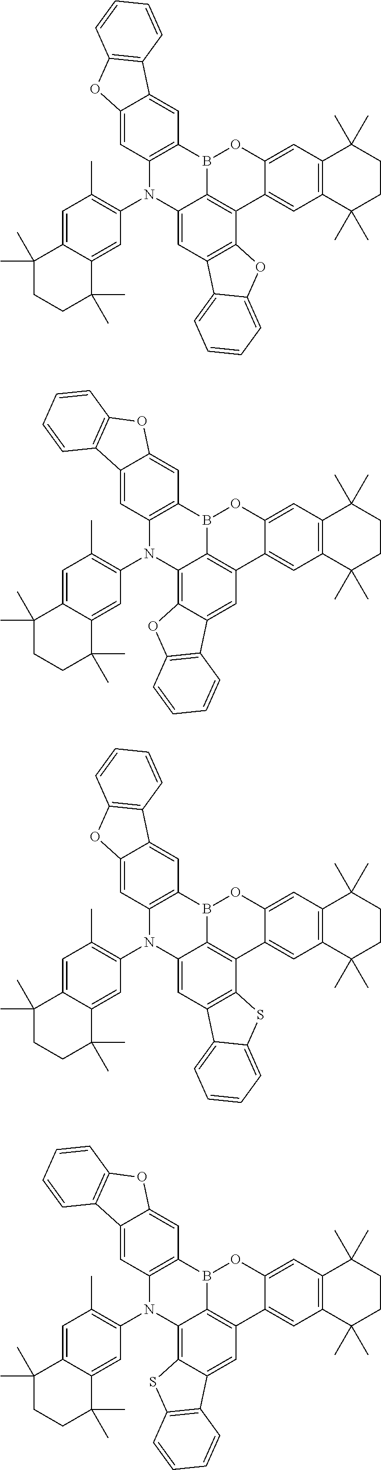

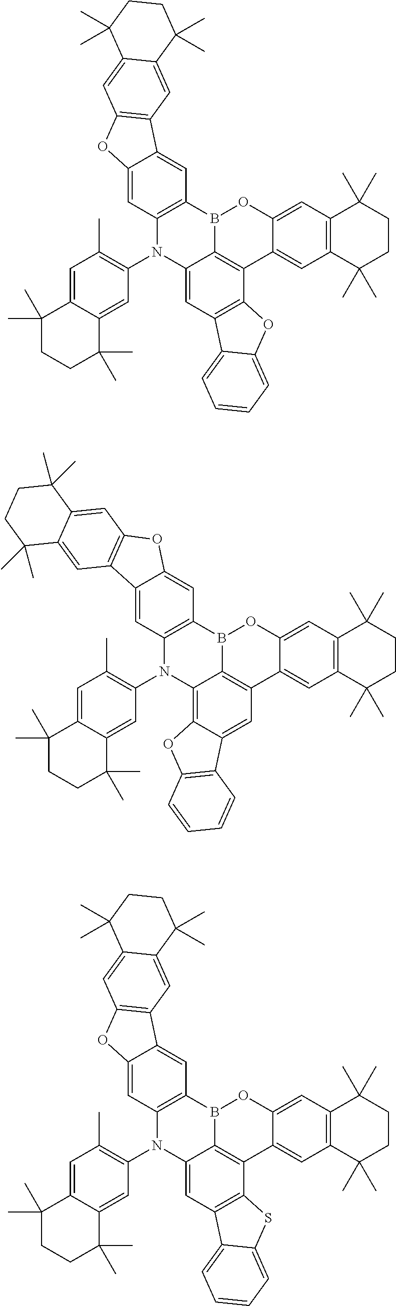 [SMILES: Cc1cc2c(cc1N1c3cc4oc5cc6c(cc5c4cc3B3Oc4cc5c(cc4-c4c3c1cc1c4oc3ccccc31)C(C)(C)CCC5(C)C)C(C)(C)CCC6(C)C)C(C)(C)CCC2(C)C ; Cc1cc2c(cc1N1c3cc4c(cc3B3Oc5cc6c(cc5-c5cc7c(oc8ccccc87)c1c53)C(C)(C)CCC6(C)C)oc1cc3c(cc14)C(C)(C)CCC3(C)C)C(C)(C)CCC2(C)C ; Cc1cc2c(cc1N1c3cc4oc5cc6c(cc5c4cc3B3Oc4cc5c(cc4-c4c3c1cc1c4sc3ccccc31)C(C)(C)CCC5(C)C)C(C)(C)CCC6(C)C)C(C)(C)CCC2(C)C]

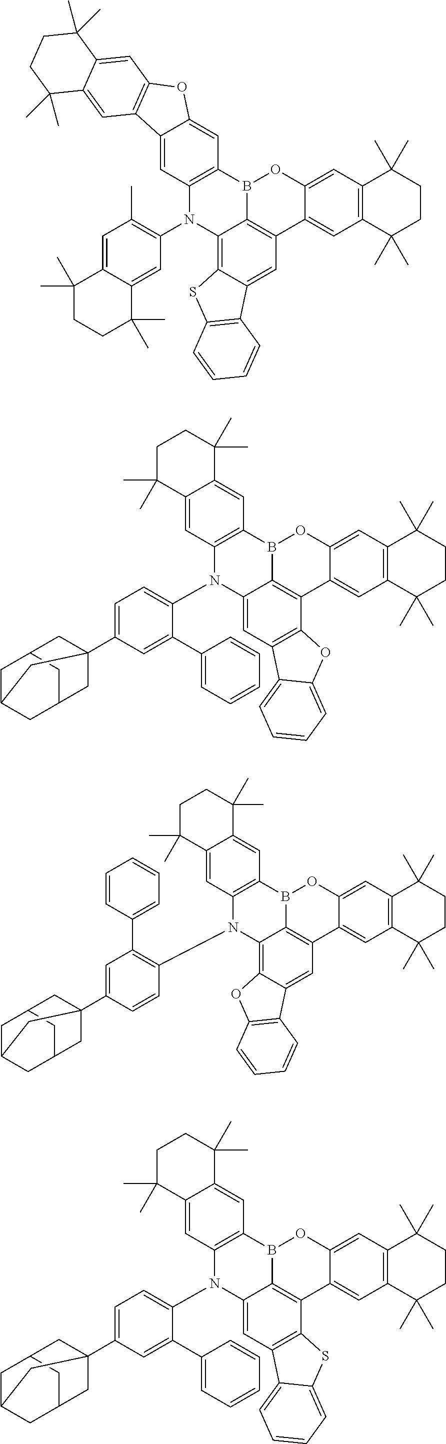

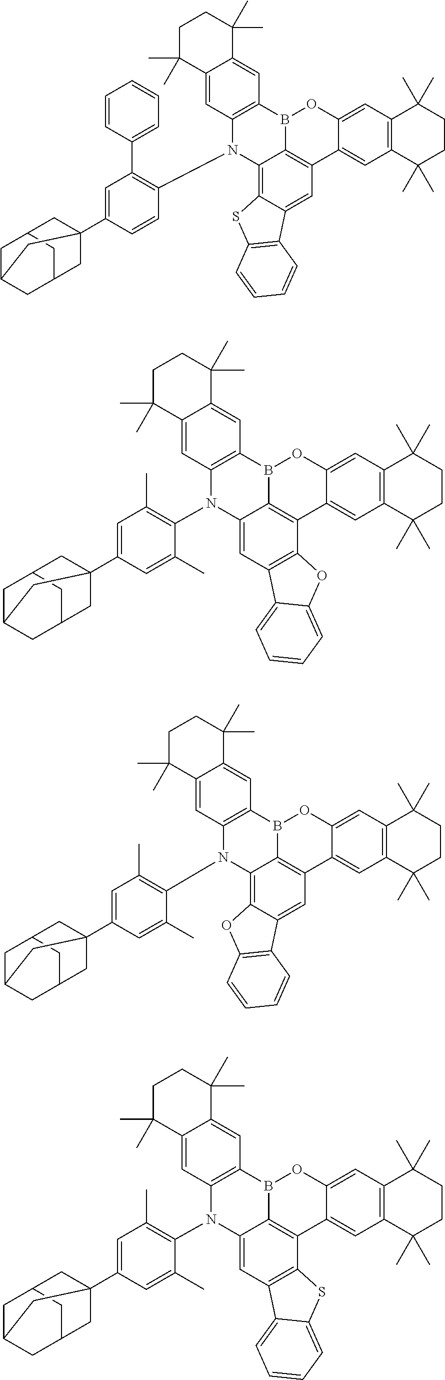 [SMILES: CC1(C)CCC(C)(C)c2cc3c(cc21)OB1c2cc4c(cc2N(c2ccc(C56CC7CC(CC(C7)C5)C6)cc2-c2ccccc2)c2c1c-3cc1c2sc2ccccc21)C(C)(C)CCC4(C)C ; Cc1cc(C23CC4CC(CC(C4)C2)C3)cc(C)c1N1c2cc3c(cc2B2Oc4cc5c(cc4-c4c2c1cc1c4oc2ccccc21)C(C)(C)CCC5(C)C)C(C)(C)CCC3(C)C ; Cc1cc(C23CC4CC(CC(C4)C2)C3)cc(C)c1N1c2cc3c(cc2B2Oc4cc5c(cc4-c4cc6c(oc7ccccc76)c1c42)C(C)(C)CCC5(C)C)C(C)(C)CCC3(C)C ; Cc1cc(C23CC4CC(CC(C4)C2)C3)cc(C)c1N1c2cc3c(cc2B2Oc4cc5c(cc4-c4c2c1cc1c4sc2ccccc21)C(C)(C)CCC5(C)C)C(C)(C)CCC3(C)C]

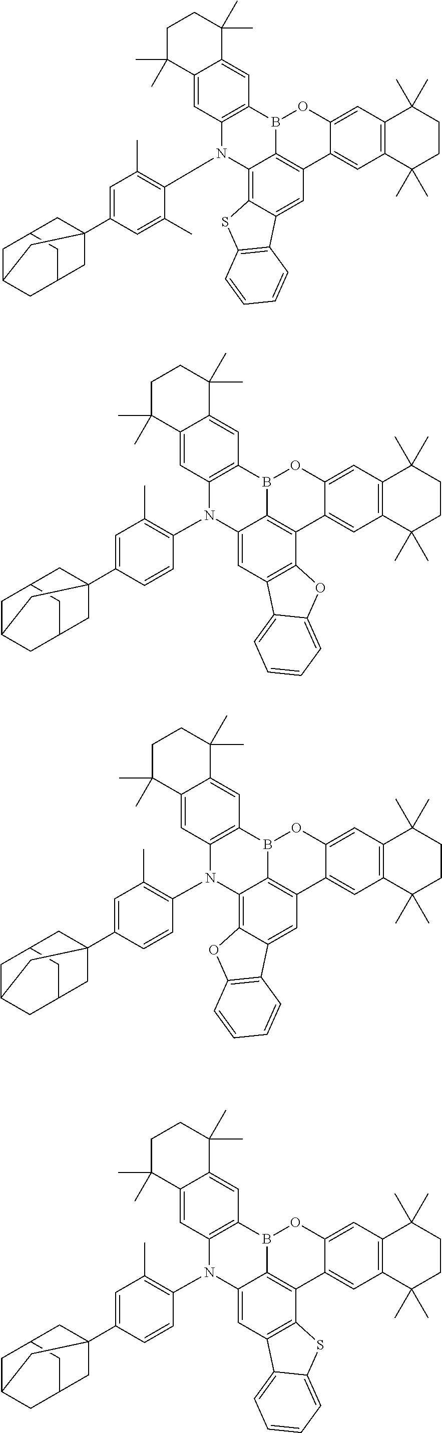 [SMILES: Cc1cc(C23CC4CC(CC(C4)C2)C3)cc(C)c1N1c2cc3c(cc2B2Oc4cc5c(cc4-c4cc6c(sc7ccccc76)c1c42)C(C)(C)CCC5(C)C)C(C)(C)CCC3(C)C ; Cc1cc(C23CC4CC(CC(C4)C2)C3)ccc1N1c2cc3c(cc2B2Oc4cc5c(cc4-c4c2c1cc1c4oc2ccccc21)C(C)(C)CCC5(C)C)C(C)(C)CCC3(C)C ; Cc1cc(C23CC4CC(CC(C4)C2)C3)ccc1N1c2cc3c(cc2B2Oc4cc5c(cc4-c4cc6c(oc7ccccc76)c1c42)C(C)(C)CCC5(C)C)C(C)(C)CCC3(C)C ; Cc1cc(C23CC4CC(CC(C4)C2)C3)ccc1N1c2cc3c(cc2B2Oc4cc5c(cc4-c4c2c1cc1c4sc2ccccc21)C(C)(C)CCC5(C)C)C(C)(C)CCC3(C)C]

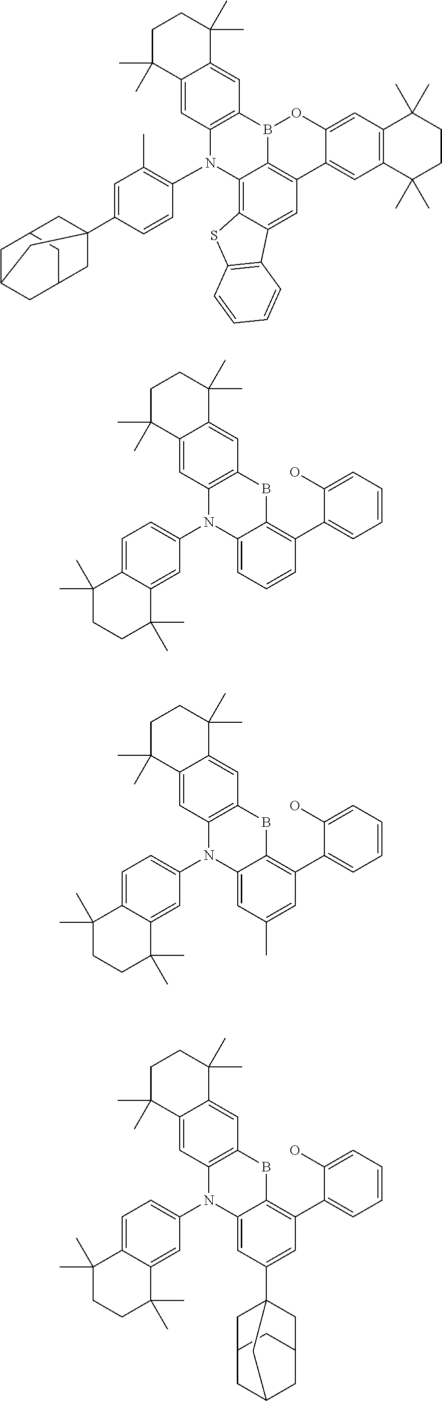

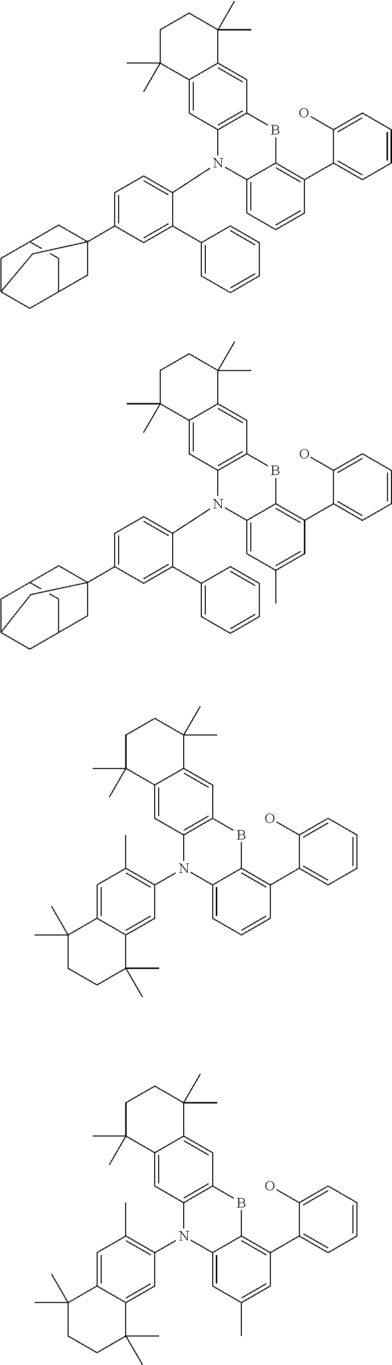

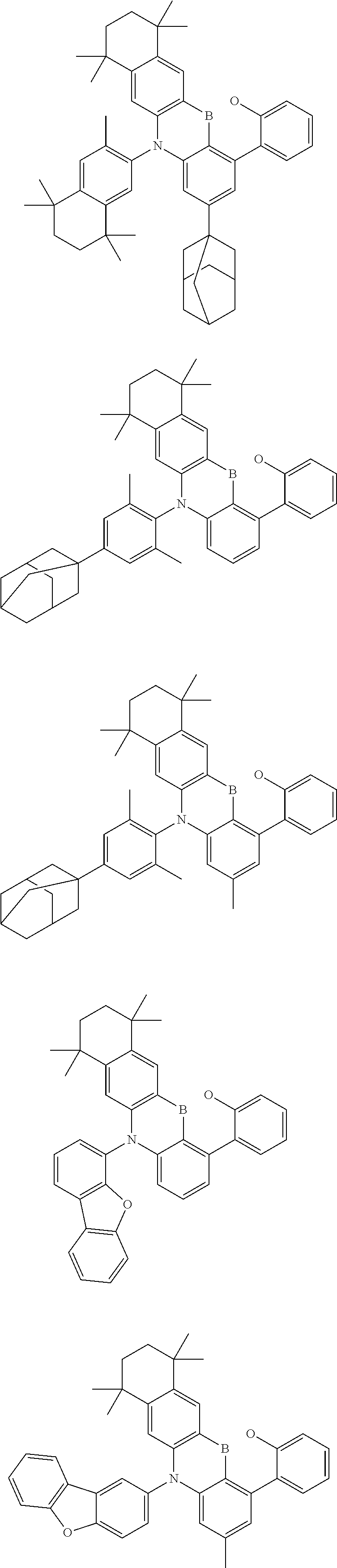

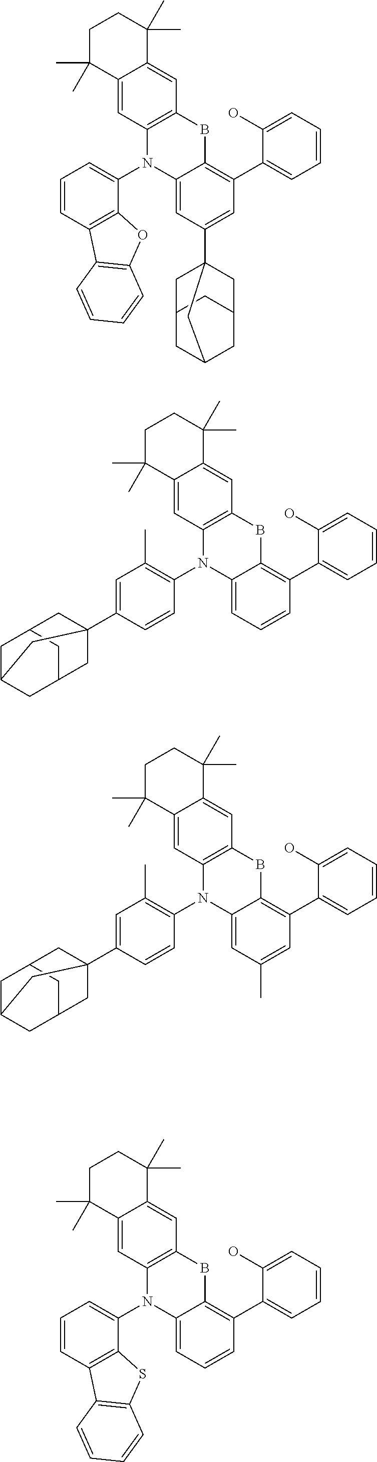

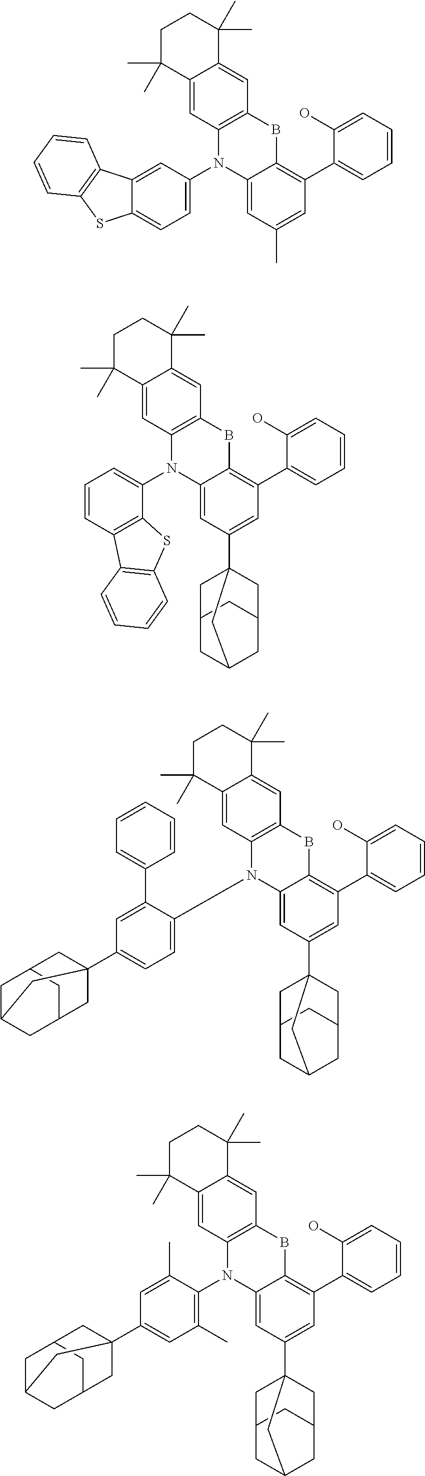

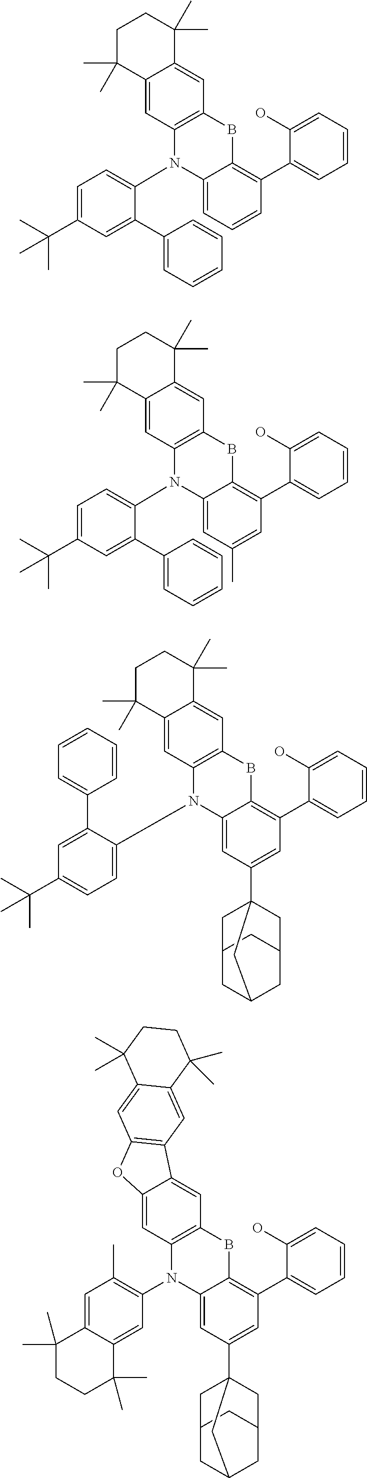

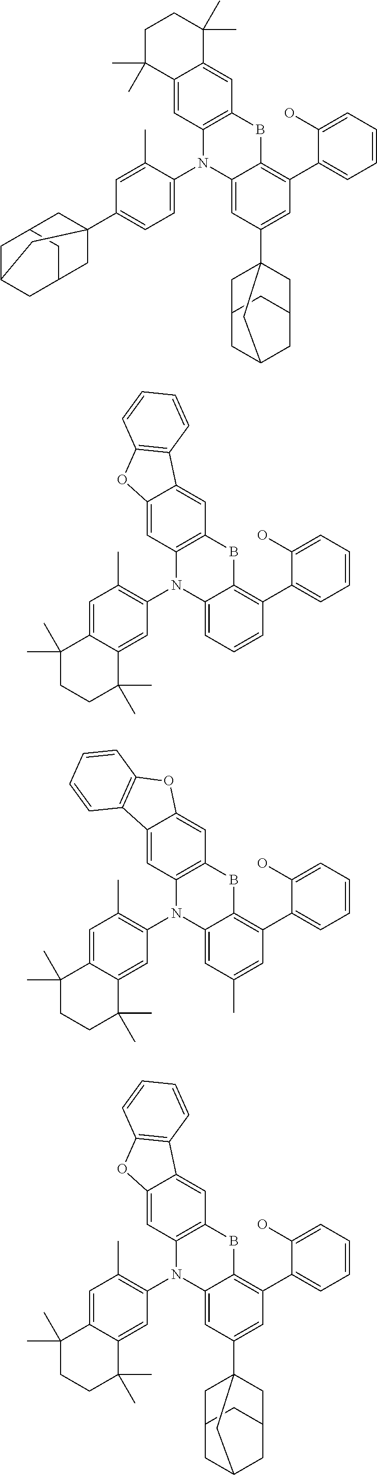

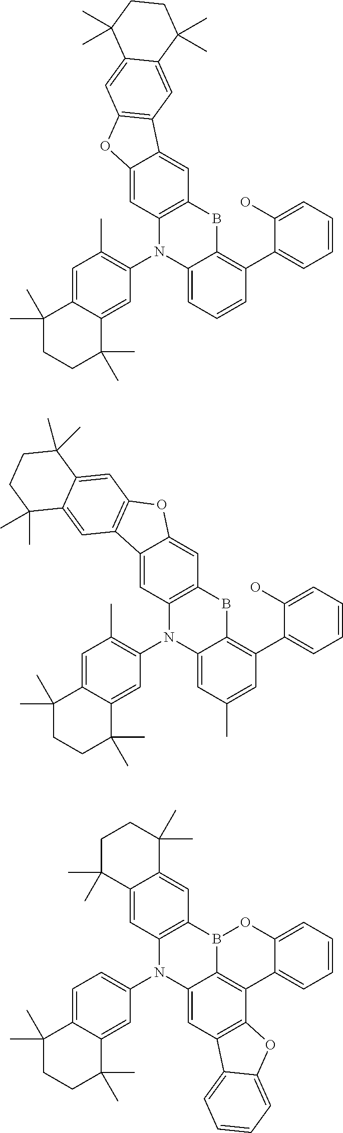

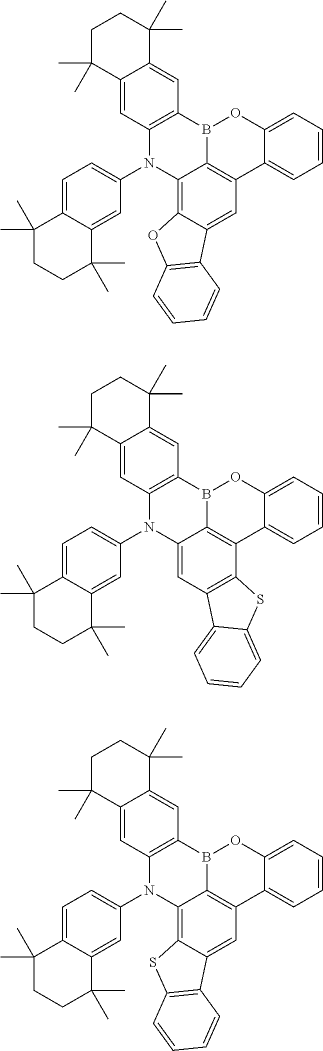

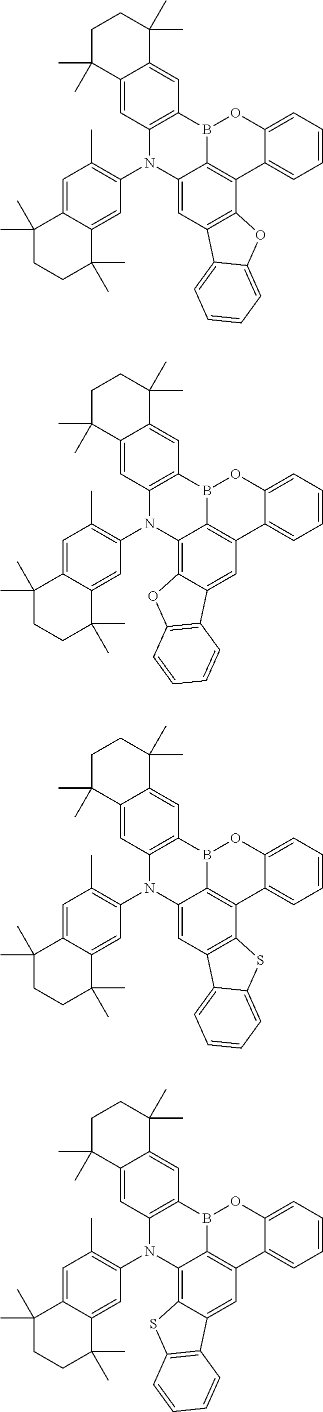

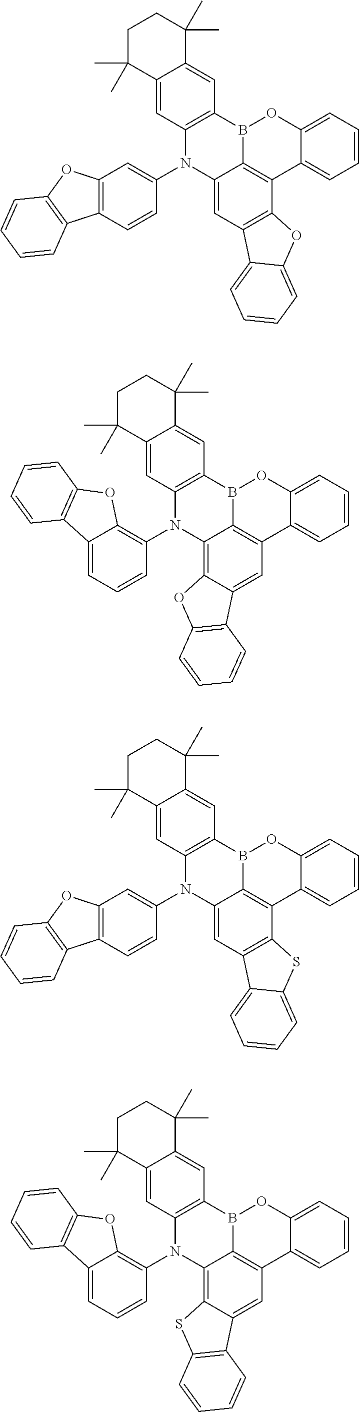

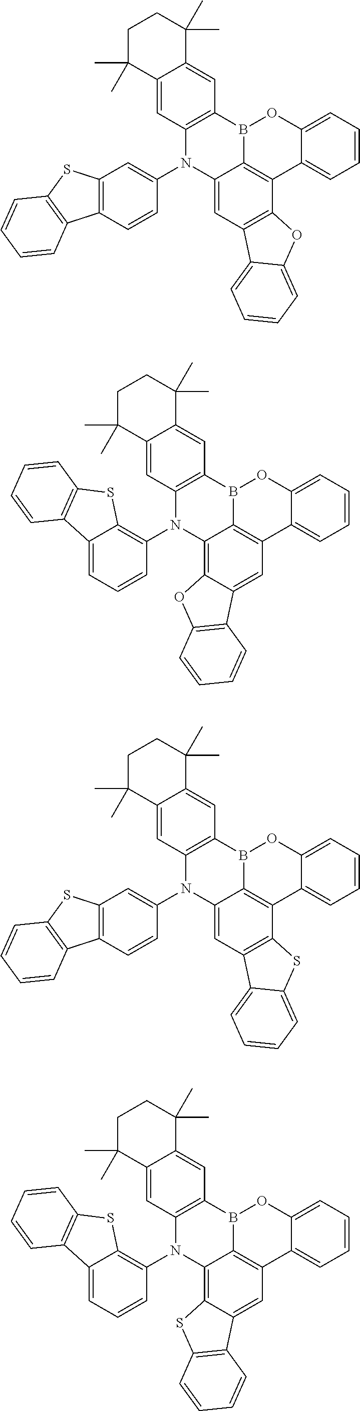

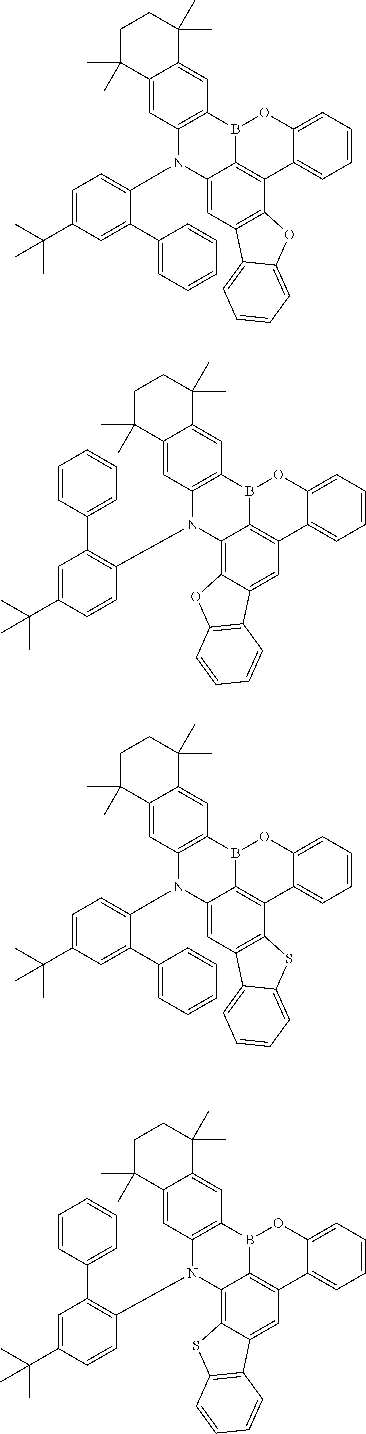

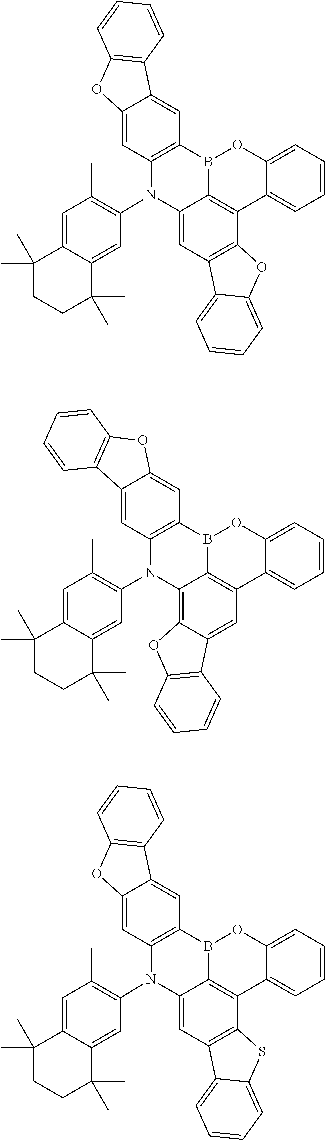 [SMILES: Cc1cc2c(cc1N1c3cc4oc5ccccc5c4cc3B3Oc4ccccc4-c4c3c1cc1c4oc3ccccc31)C(C)(C)CCC2(C)C ; Cc1cc2c(cc1N1c3cc4c(cc3B3Oc5ccccc5-c5cc6c(oc7ccccc76)c1c53)oc1ccccc14)C(C)(C)CCC2(C)C ; Cc1cc2c(cc1N1c3cc4oc5ccccc5c4cc3B3Oc4ccccc4-c4c3c1cc1c4sc3ccccc31)C(C)(C)CCC2(C)C]

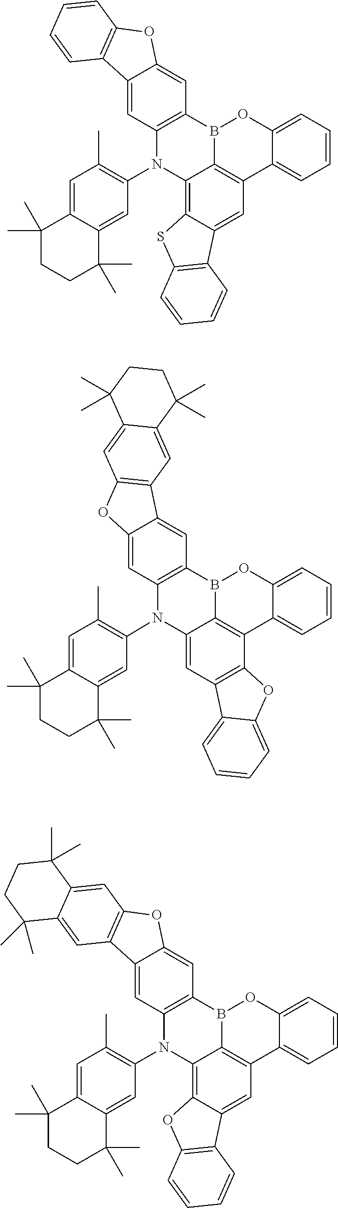 [SMILES: Cc1cc2c(cc1N1c3cc4c(cc3B3Oc5ccccc5-c5cc6c(sc7ccccc76)c1c53)oc1ccccc14)C(C)(C)CCC2(C)C ; Cc1cc2c(cc1N1c3cc4oc5cc6c(cc5c4cc3B3Oc4ccccc4-c4c3c1cc1c4oc3ccccc31)C(C)(C)CCC6(C)C)C(C)(C)CCC2(C)C ; Cc1cc2c(cc1N1c3cc4c(cc3B3Oc5ccccc5-c5cc6c(oc7ccccc76)c1c53)oc1cc3c(cc14)C(C)(C)CCC3(C)C)C(C)(C)CCC2(C)C]

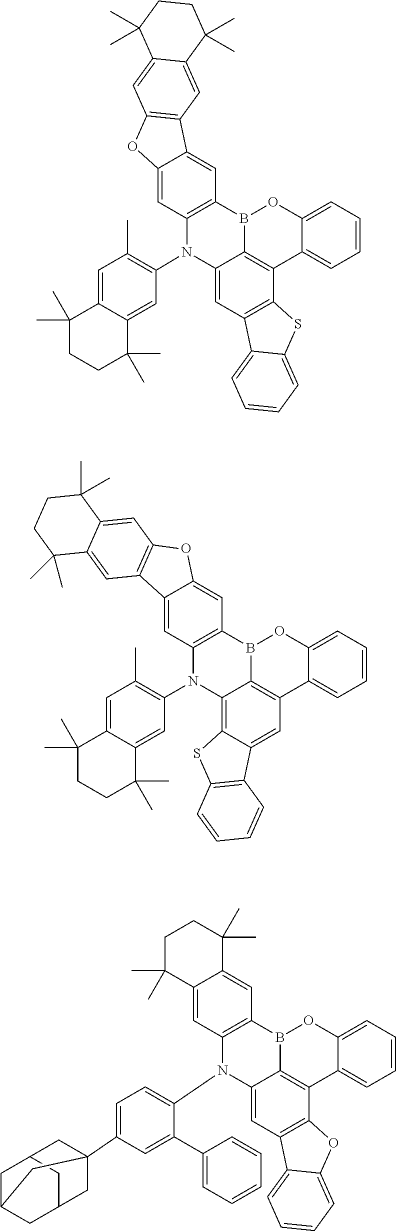 [SMILES: Cc1cc2c(cc1N1c3cc4oc5cc6c(cc5c4cc3B3Oc4ccccc4-c4c3c1cc1c4sc3ccccc31)C(C)(C)CCC6(C)C)C(C)(C)CCC2(C)C ; Cc1cc2c(cc1N1c3cc4c(cc3B3Oc5ccccc5-c5cc6c(sc7ccccc76)c1c53)oc1cc3c(cc14)C(C)(C)CCC3(C)C)C(C)(C)CCC2(C)C ; CC1(C)CCC(C)(C)c2cc3c(cc21)B1Oc2ccccc2-c2c1c(cc1c2oc2ccccc21)N3c1ccc(C23CC4CC(CC(C4)C2)C3)cc1-c1ccccc1]

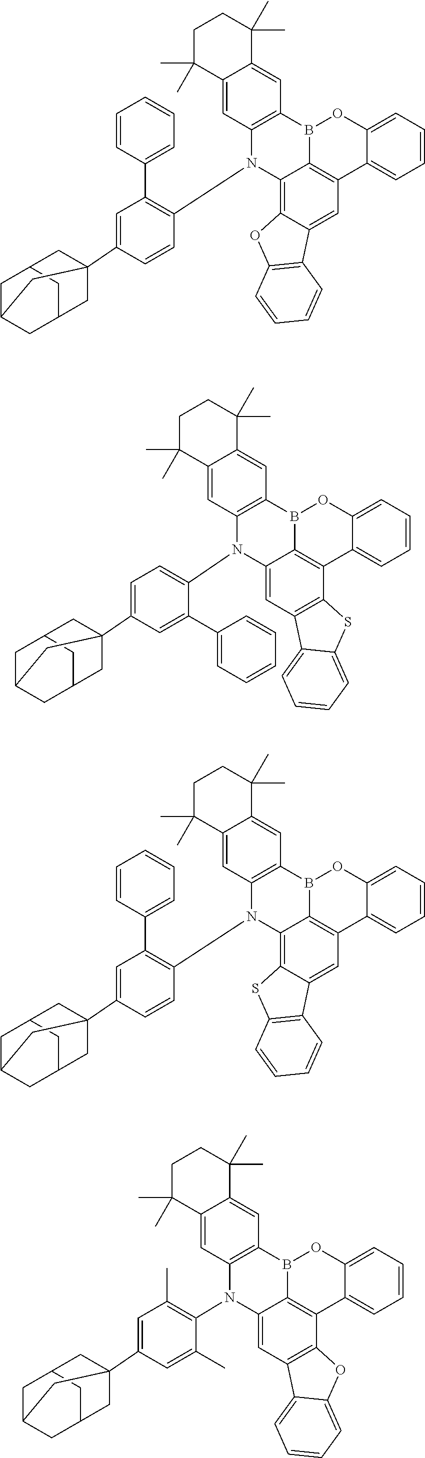 [SMILES: CC1(C)CCC(C)(C)c2cc3c(cc21)B1Oc2ccccc2-c2cc4c(oc5ccccc54)c(c21)N3c1ccc(C23CC4CC(CC(C4)C2)C3)cc1-c1ccccc1 ; CC1(C)CCC(C)(C)c2cc3c(cc21)B1Oc2ccccc2-c2c1c(cc1c2sc2ccccc21)N3c1ccc(C23CC4CC(CC(C4)C2)C3)cc1-c1ccccc1 ; CC1(C)CCC(C)(C)c2cc3c(cc21)B1Oc2ccccc2-c2cc4c(sc5ccccc54)c(c21)N3c1ccc(C23CC4CC(CC(C4)C2)C3)cc1-c1ccccc1 ; Cc1cc(C23CC4CC(CC(C4)C2)C3)cc(C)c1N1c2cc3c(cc2B2Oc4ccccc4-c4c2c1cc1c4oc2ccccc21)C(C)(C)CCC3(C)C]

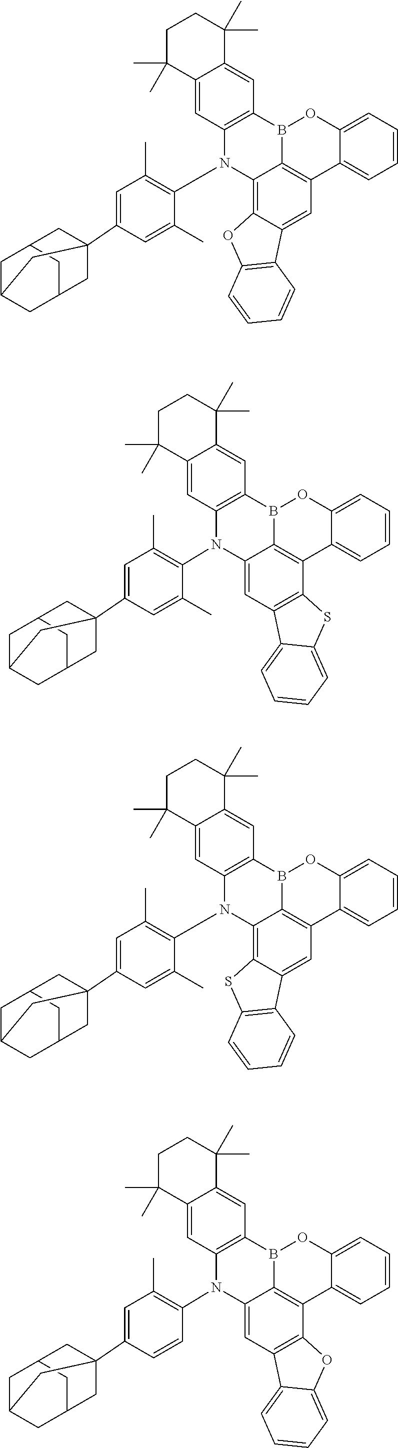 [SMILES: Cc1cc(C23CC4CC(CC(C4)C2)C3)cc(C)c1N1c2cc3c(cc2B2Oc4ccccc4-c4cc5c(oc6ccccc65)c1c42)C(C)(C)CCC3(C)C ; Cc1cc(C23CC4CC(CC(C4)C2)C3)cc(C)c1N1c2cc3c(cc2B2Oc4ccccc4-c4c2c1cc1c4sc2ccccc21)C(C)(C)CCC3(C)C ; Cc1cc(C23CC4CC(CC(C4)C2)C3)cc(C)c1N1c2cc3c(cc2B2Oc4ccccc4-c4cc5c(sc6ccccc65)c1c42)C(C)(C)CCC3(C)C ; Cc1cc(C23CC4CC(CC(C4)C2)C3)ccc1N1c2cc3c(cc2B2Oc4ccccc4-c4c2c1cc1c4oc2ccccc21)C(C)(C)CCC3(C)C]

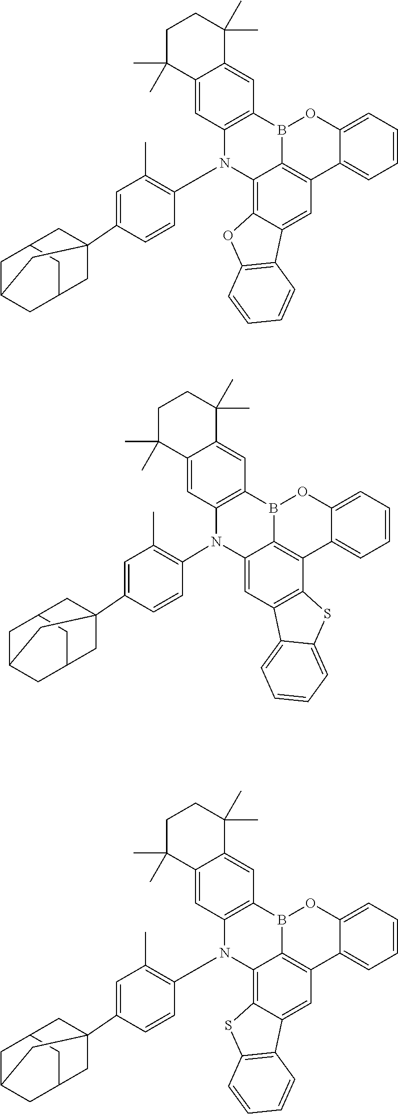 [SMILES: Cc1cc(C23CC4CC(CC(C4)C2)C3)ccc1N1c2cc3c(cc2B2Oc4ccccc4-c4cc5c(oc6ccccc65)c1c42)C(C)(C)CCC3(C)C ; Cc1cc(C23CC4CC(CC(C4)C2)C3)ccc1N1c2cc3c(cc2B2Oc4ccccc4-c4c2c1cc1c4sc2ccccc21)C(C)(C)CCC3(C)C ; Cc1cc(C23CC4CC(CC(C4)C2)C3)ccc1N1c2cc3c(cc2B2Oc4ccccc4-c4cc5c(sc6ccccc65)c1c42)C(C)(C)CCC3(C)C]

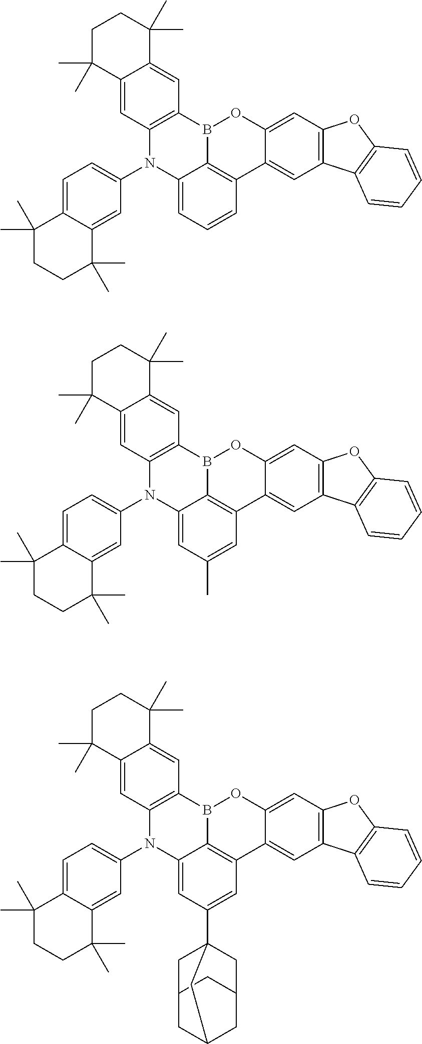 [SMILES: CC1(C)CCC(C)(C)c2cc(N3c4cc5c(cc4B4Oc6cc7oc8ccccc8c7cc6-c6cccc3c64)C(C)(C)CCC5(C)C)ccc21 ; Cc1cc2c3c(c1)N(c1ccc4c(c1)C(C)(C)CCC4(C)C)c1cc4c(cc1B3Oc1cc3oc5ccccc5c3cc1-2)C(C)(C)CCC4(C)C ; CC1(C)CCC(C)(C)c2cc(N3c4cc5c(cc4B4Oc6cc7oc8ccccc8c7cc6-c6cc(C78CC9CC(CC(C9)C7)C8)cc3c64)C(C)(C)CCC5(C)C)ccc21]

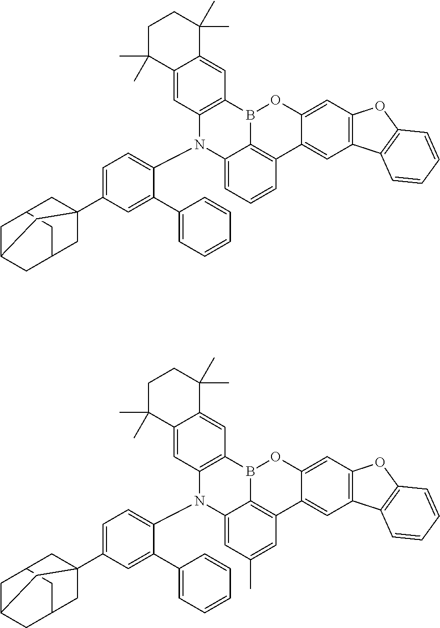 [SMILES: CC1(C)CCC(C)(C)c2cc3c(cc21)B1Oc2cc4oc5ccccc5c4cc2-c2cccc(c21)N3c1ccc(C23CC4CC(CC(C4)C2)C3)cc1-c1ccccc1 ; Cc1cc2c3c(c1)N(c1ccc(C45CC6CC(CC(C6)C4)C5)cc1-c1ccccc1)c1cc4c(cc1B3Oc1cc3oc5ccccc5c3cc1-2)C(C)(C)CCC4(C)C]

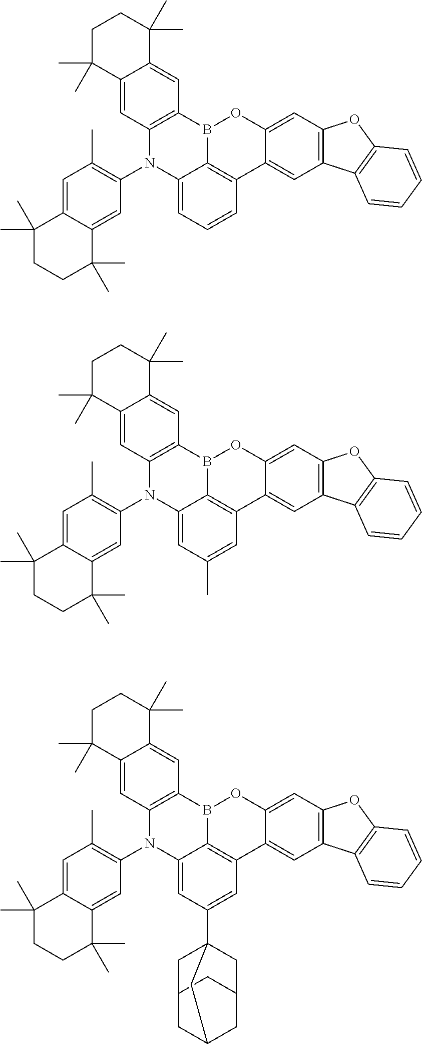 [SMILES: Cc1cc2c(cc1N1c3cc4c(cc3B3Oc5cc6oc7ccccc7c6cc5-c5cccc1c53)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Oc1cc3oc5ccccc5c3cc1-2)C(C)(C)CCC4(C)C ; Cc1cc2c(cc1N1c3cc4c(cc3B3Oc5cc6oc7ccccc7c6cc5-c5cc(C67CC8CC(CC(C8)C6)C7)cc1c53)C(C)(C)CCC4(C)C)C(C)(C)CCC2(C)C]

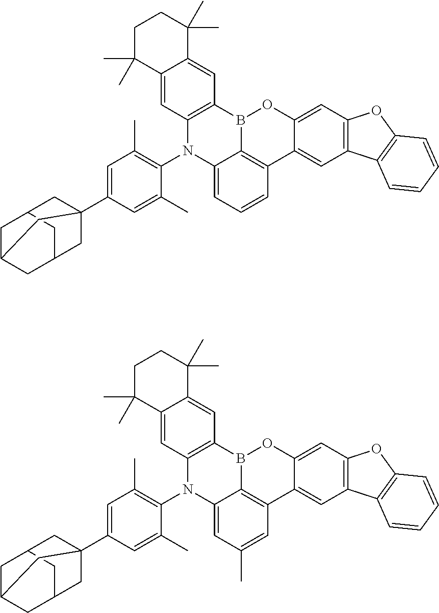 [SMILES: Cc1cc(C23CC4CC(CC(C4)C2)C3)cc(C)c1N1c2cc3c(cc2B2Oc4cc5oc6ccccc6c5cc4-c4cccc1c42)C(C)(C)CCC3(C)C ; Cc1cc2c3c(c1)N(c1c(C)cc(C45CC6CC(CC(C6)C4)C5)cc1C)c1cc4c(cc1B3Oc1cc3oc5ccccc5c3cc1-2)C(C)(C)CCC4(C)C]

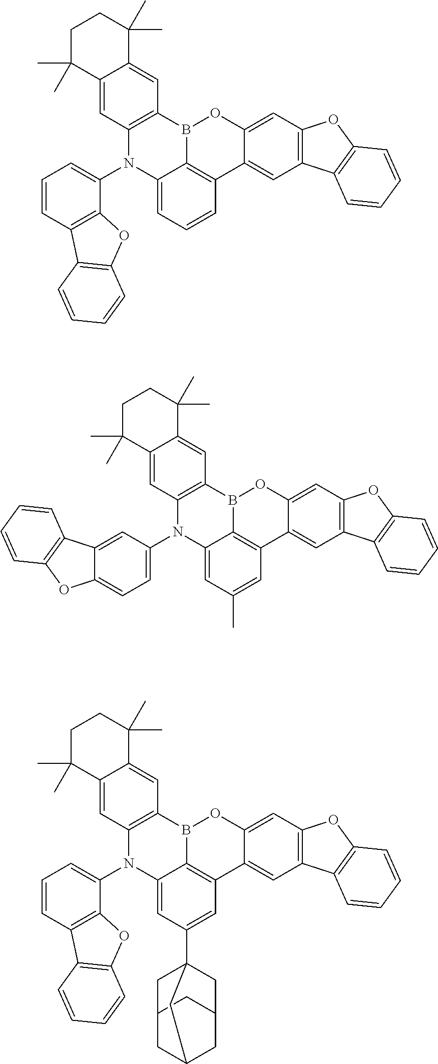 [SMILES: CC1(C)CCC(C)(C)c2cc3c(cc21)B1Oc2cc4oc5ccccc5c4cc2-c2cccc(c21)N3c1cccc2c1oc1ccccc12 ; Cc1cc2c3c(c1)N(c1ccc4oc5ccccc5c4c1)c1cc4c(cc1B3Oc1cc3oc5ccccc5c3cc1-2)C(C)(C)CCC4(C)C ; CC1(C)CCC(C)(C)c2cc3c(cc21)B1Oc2cc4oc5ccccc5c4cc2-c2cc(C45CC6CC(CC(C6)C4)C5)cc(c21)N3c1cccc2c1oc1ccccc12]

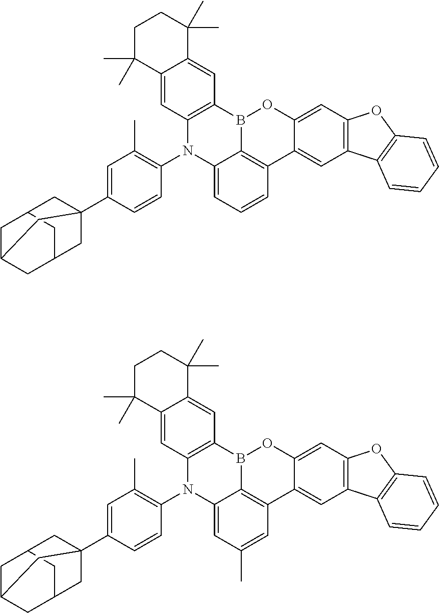 [SMILES: Cc1cc(C23CC4CC(CC(C4)C2)C3)ccc1N1c2cc3c(cc2B2Oc4cc5oc6ccccc6c5cc4-c4cccc1c42)C(C)(C)CCC3(C)C ; Cc1cc2c3c(c1)N(c1ccc(C45CC6CC(CC(C6)C4)C5)cc1C)c1cc4c(cc1B3Oc1cc3oc5ccccc5c3cc1-2)C(C)(C)CCC4(C)C]

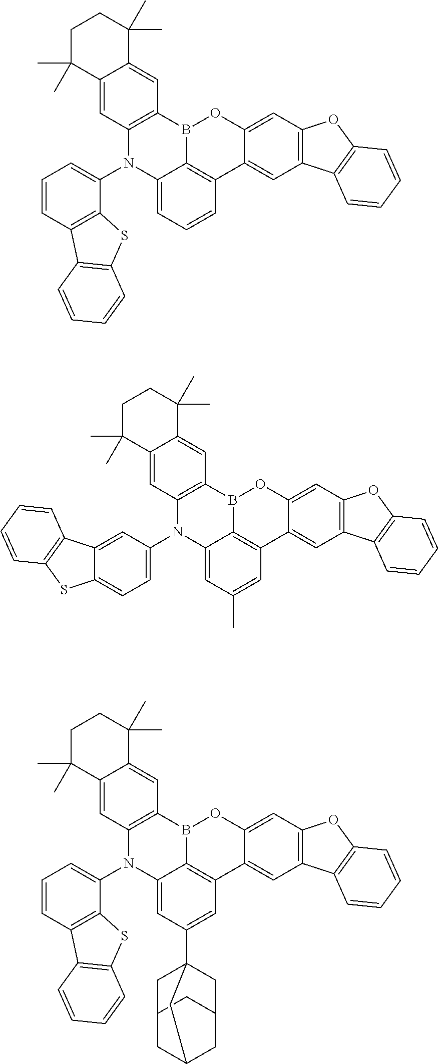 [SMILES: CC1(C)CCC(C)(C)c2cc3c(cc21)B1Oc2cc4oc5ccccc5c4cc2-c2cccc(c21)N3c1cccc2c1sc1ccccc12 ; Cc1cc2c3c(c1)N(c1ccc4sc5ccccc5c4c1)c1cc4c(cc1B3Oc1cc3oc5ccccc5c3cc1-2)C(C)(C)CCC4(C)C ; CC1(C)CCC(C)(C)c2cc3c(cc21)B1Oc2cc4oc5ccccc5c4cc2-c2cc(C45CC6CC(CC(C6)C4)C5)cc(c21)N3c1cccc2c1sc1ccccc12]

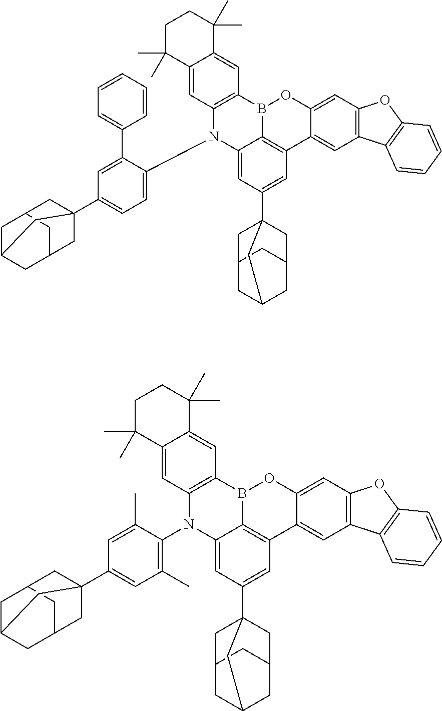 [SMILES: CC1(C)CCC(C)(C)c2cc3c(cc21)B1Oc2cc4oc5ccccc5c4cc2-c2cc(C45CC6CC(CC(C6)C4)C5)cc(c21)N3c1ccc(C23CC4CC(CC(C4)C2)C3)cc1-c1ccccc1 ; Cc1cc(C23CC4CC(CC(C4)C2)C3)cc(C)c1N1c2cc3c(cc2B2Oc4cc5oc6ccccc6c5cc4-c4cc(C56CC7CC(CC(C7)C5)C6)cc1c42)C(C)(C)CCC3(C)C]

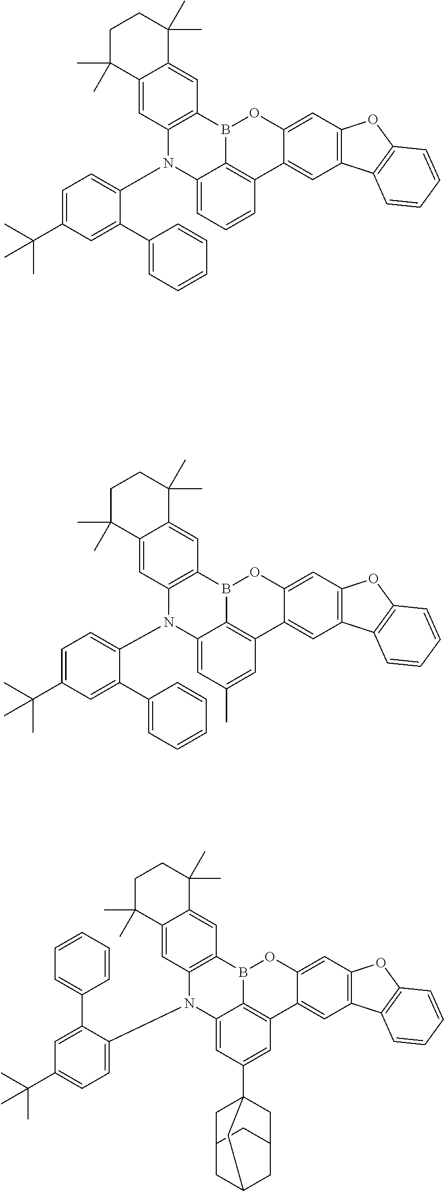 [SMILES: CC(C)(C)c1ccc(N2c3cc4c(cc3B3Oc5cc6oc7ccccc7c6cc5-c5cccc2c53)C(C)(C)CCC4(C)C)c(-c2ccccc2)c1 ; Cc1cc2c3c(c1)N(c1ccc(C(C)(C)C)cc1-c1ccccc1)c1cc4c(cc1B3Oc1cc3oc5ccccc5c3cc1-2)C(C)(C)CCC4(C)C ; CC(C)(C)c1ccc(N2c3cc4c(cc3B3Oc5cc6oc7ccccc7c6cc5-c5cc(C67CC8CC(CC(C8)C6)C7)cc2c53)C(C)(C)CCC4(C)C)c(-c2ccccc2)c1]

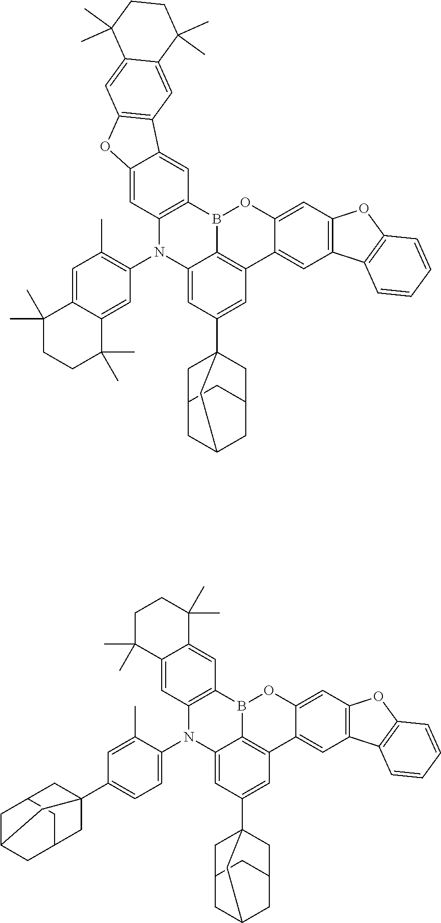 [SMILES: Cc1cc2c(cc1N1c3cc4oc5cc6c(cc5c4cc3B3Oc4cc5oc7ccccc7c5cc4-c4cc(C57CC8CC(CC(C8)C5)C7)cc1c43)C(C)(C)CCC6(C)C)C(C)(C)CCC2(C)C ; Cc1cc(C23CC4CC(CC(C4)C2)C3)ccc1N1c2cc3c(cc2B2Oc4cc5oc6ccccc6c5cc4-c4cc(C56CC7CC(CC(C7)C5)C6)cc1c42)C(C)(C)CCC3(C)C]

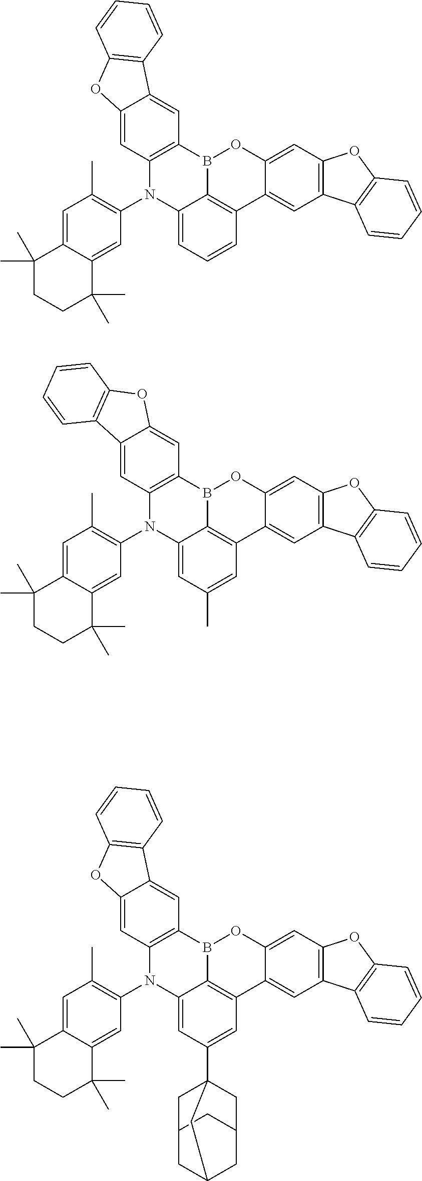

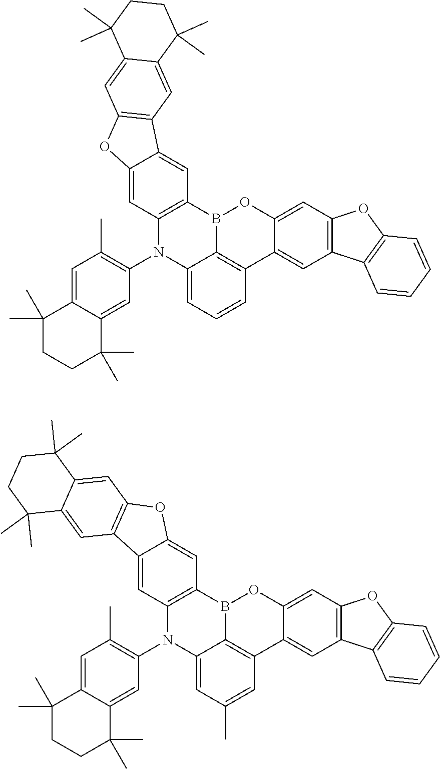 [SMILES: Cc1cc2c(cc1N1c3cc4oc5cc6c(cc5c4cc3B3Oc4cc5oc7ccccc7c5cc4-c4cccc1c43)C(C)(C)CCC6(C)C)C(C)(C)CCC2(C)C ; Cc1cc2c3c(c1)N(c1cc4c(cc1C)C(C)(C)CCC4(C)C)c1cc4c(cc1B3Oc1cc3oc5ccccc5c3cc1-2)oc1cc2c(cc14)C(C)(C)CCC2(C)C]

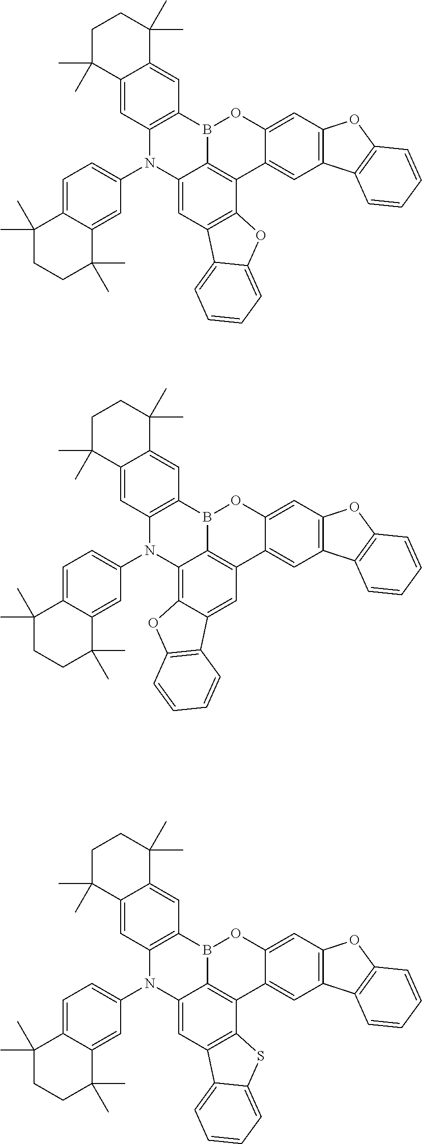 [SMILES: CC1(C)CCC(C)(C)c2cc(N3c4cc5c(cc4B4Oc6cc7oc8ccccc8c7cc6-c6c4c3cc3c6oc4ccccc43)C(C)(C)CCC5(C)C)ccc21 ; CC1(C)CCC(C)(C)c2cc(N3c4cc5c(cc4B4Oc6cc7oc8ccccc8c7cc6-c6cc7c(oc8ccccc87)c3c64)C(C)(C)CCC5(C)C)ccc21 ; CC1(C)CCC(C)(C)c2cc(N3c4cc5c(cc4B4Oc6cc7oc8ccccc8c7cc6-c6c4c3cc3c6sc4ccccc43)C(C)(C)CCC5(C)C)ccc21]

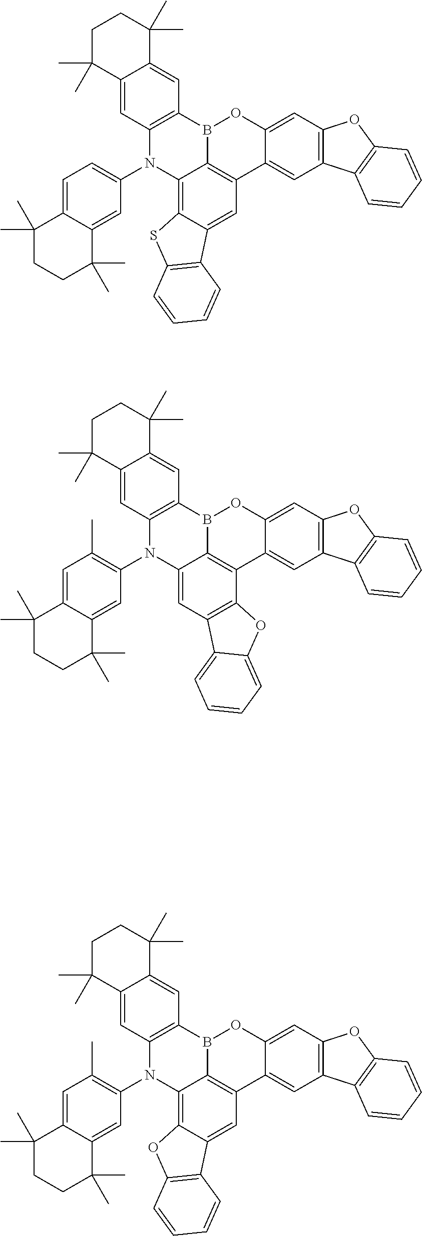 [SMILES: CC1(C)CCC(C)(C)c2cc(N3c4cc5c(cc4B4Oc6cc7oc8ccccc8c7cc6-c6cc7c(sc8ccccc87)c3c64)C(C)(C)CCC5(C)C)ccc21 ; Cc1cc2c(cc1N1c3cc4c(cc3B3Oc5cc6oc7ccccc7c6cc5-c5c3c1cc1c5oc3ccccc31)C(C)(C)CCC4(C)C)C(C)(C)CCC2(C)C ; Cc1cc2c(cc1N1c3cc4c(cc3B3Oc5cc6oc7ccccc7c6cc5-c5cc6c(oc7ccccc76)c1c53)C(C)(C)CCC4(C)C)C(C)(C)CCC2(C)C]

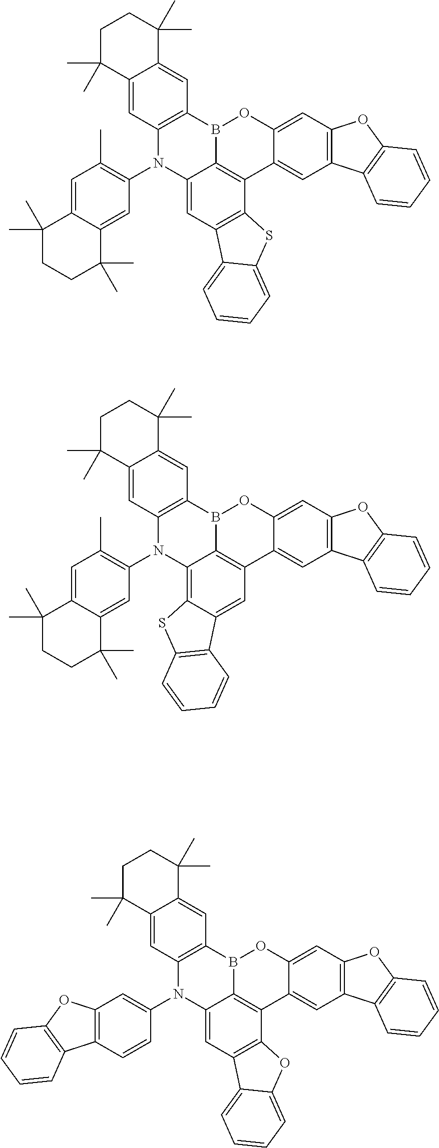 [SMILES: Cc1cc2c(cc1N1c3cc4c(cc3B3Oc5cc6oc7ccccc7c6cc5-c5c3c1cc1c5sc3ccccc31)C(C)(C)CCC4(C)C)C(C)(C)CCC2(C)C ; Cc1cc2c(cc1N1c3cc4c(cc3B3Oc5cc6oc7ccccc7c6cc5-c5cc6c(sc7ccccc76)c1c53)C(C)(C)CCC4(C)C)C(C)(C)CCC2(C)C ; CC1(C)CCC(C)(C)c2cc3c(cc21)B1Oc2cc4oc5ccccc5c4cc2-c2c1c(cc1c2oc2ccccc21)N3c1ccc2c(c1)oc1ccccc12]

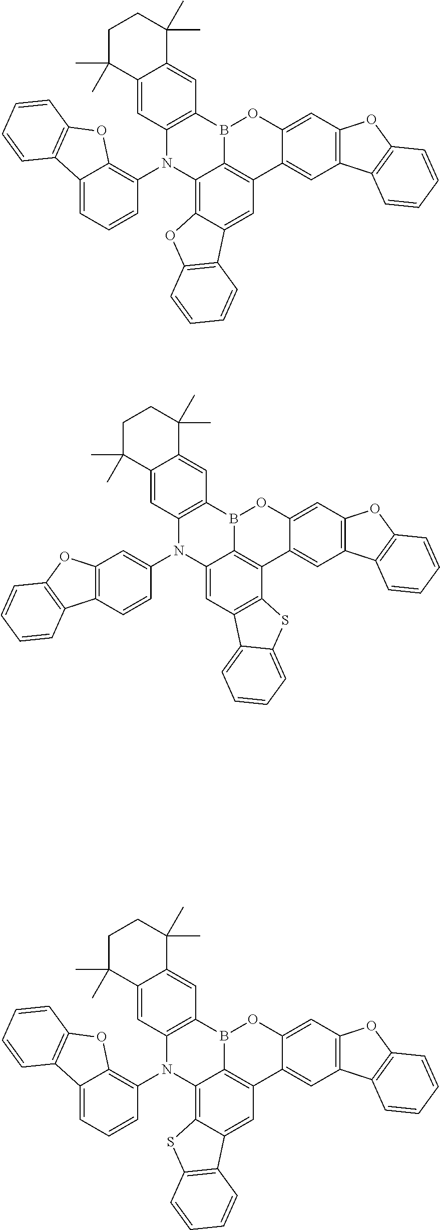 [SMILES: CC1(C)CCC(C)(C)c2cc3c(cc21)B1Oc2cc4oc5ccccc5c4cc2-c2cc4c(oc5ccccc54)c(c21)N3c1cccc2c1oc1ccccc12 ; CC1(C)CCC(C)(C)c2cc3c(cc21)B1Oc2cc4oc5ccccc5c4cc2-c2c1c(cc1c2sc2ccccc21)N3c1ccc2c(c1)oc1ccccc12 ; CC1(C)CCC(C)(C)c2cc3c(cc21)B1Oc2cc4oc5ccccc5c4cc2-c2cc4c(sc5ccccc54)c(c21)N3c1cccc2c1oc1ccccc12]

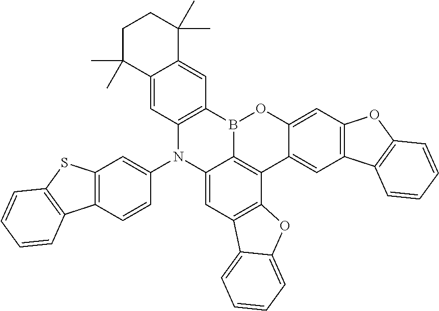 [SMILES: CC1(C)CCC(C)(C)c2cc3c(cc21)B1Oc2cc4oc5ccccc5c4cc2-c2c1c(cc1c2oc2ccccc21)N3c1ccc2c(c1)sc1ccccc12]

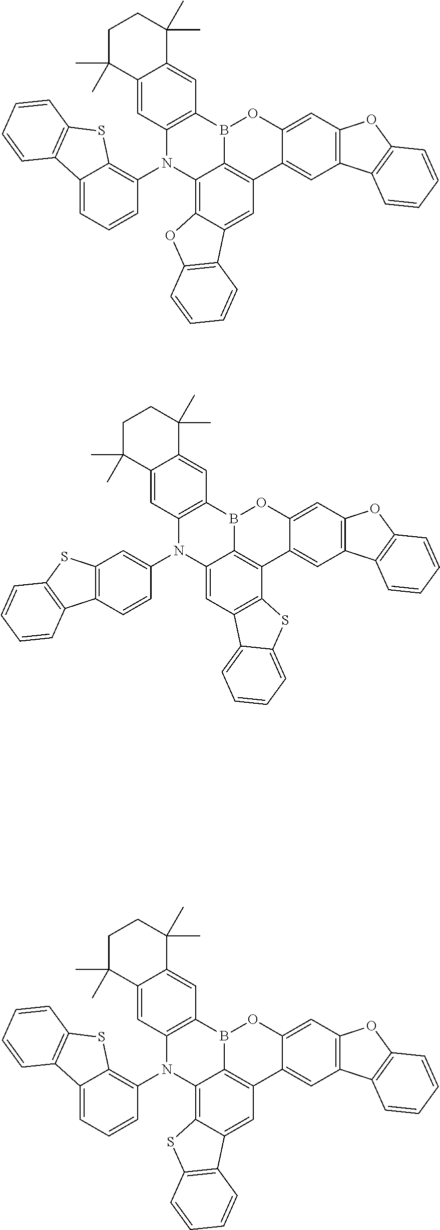 [SMILES: CC1(C)CCC(C)(C)c2cc3c(cc21)B1Oc2cc4oc5ccccc5c4cc2-c2cc4c(oc5ccccc54)c(c21)N3c1cccc2c1sc1ccccc12 ; CC1(C)CCC(C)(C)c2cc3c(cc21)B1Oc2cc4oc5ccccc5c4cc2-c2c1c(cc1c2sc2ccccc21)N3c1ccc2c(c1)sc1ccccc12 ; CC1(C)CCC(C)(C)c2cc3c(cc21)B1Oc2cc4oc5ccccc5c4cc2-c2cc4c(sc5ccccc54)c(c21)N3c1cccc2c1sc1ccccc12]

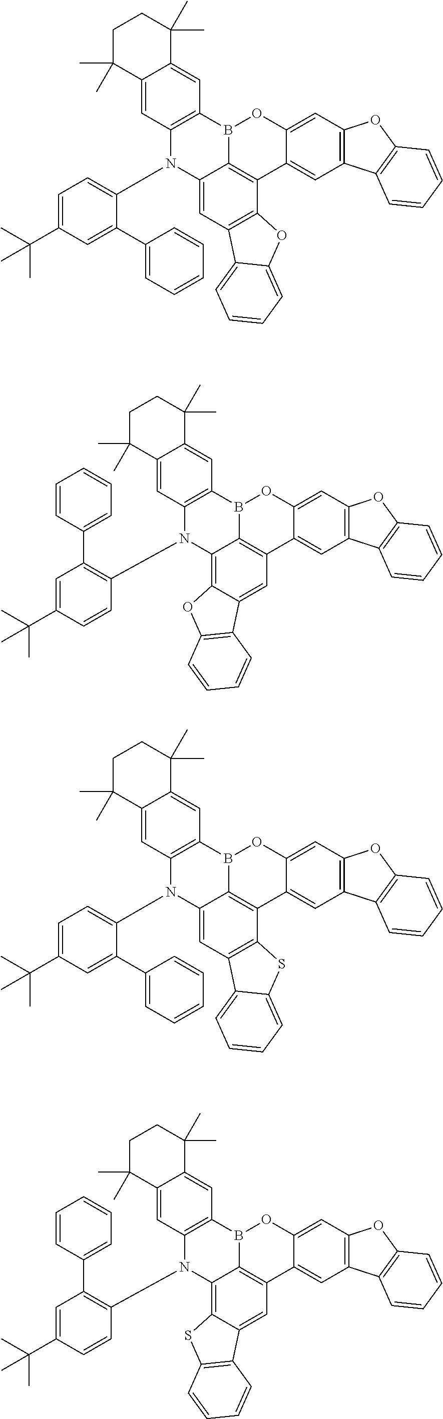

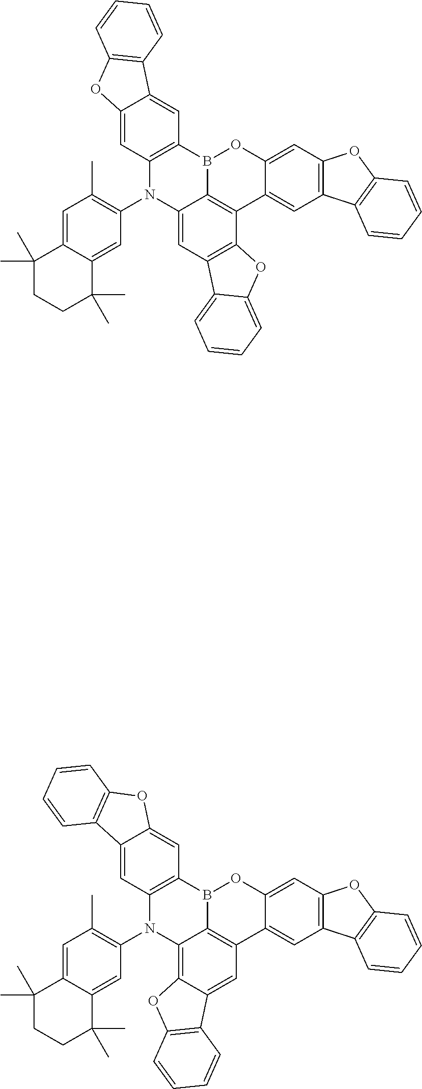 [SMILES: Cc1cc2c(cc1N1c3cc4oc5ccccc5c4cc3B3Oc4cc5oc6ccccc6c5cc4-c4c3c1cc1c4oc3ccccc31)C(C)(C)CCC2(C)C ; Cc1cc2c(cc1N1c3cc4c(cc3B3Oc5cc6oc7ccccc7c6cc5-c5cc6c(oc7ccccc76)c1c53)oc1ccccc14)C(C)(C)CCC2(C)C]

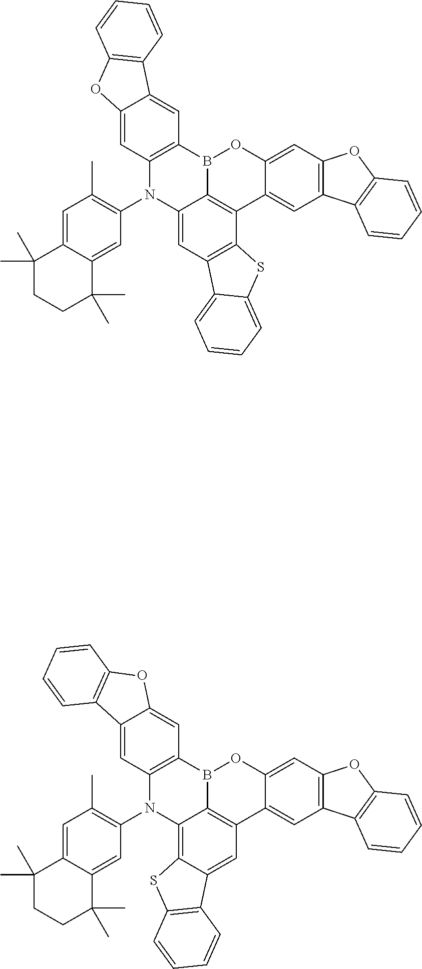 [SMILES: Cc1cc2c(cc1N1c3cc4oc5ccccc5c4cc3B3Oc4cc5oc6ccccc6c5cc4-c4c3c1cc1c4sc3ccccc31)C(C)(C)CCC2(C)C ; Cc1cc2c(cc1N1c3cc4c(cc3B3Oc5cc6oc7ccccc7c6cc5-c5cc6c(sc7ccccc76)c1c53)oc1ccccc14)C(C)(C)CCC2(C)C]

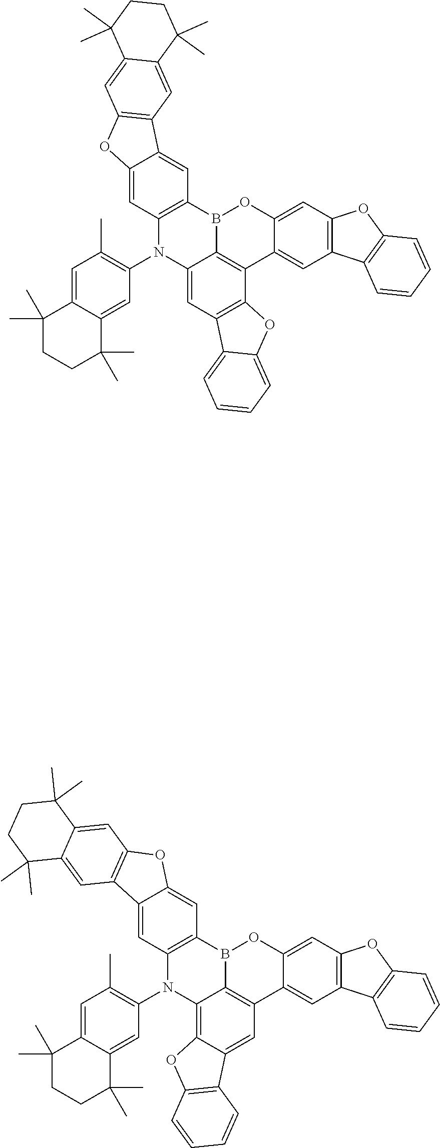 [SMILES: Cc1cc2c(cc1N1c3cc4oc5cc6c(cc5c4cc3B3Oc4cc5oc7ccccc7c5cc4-c4c3c1cc1c4oc3ccccc31)C(C)(C)CCC6(C)C)C(C)(C)CCC2(C)C ; Cc1cc2c(cc1N1c3cc4c(cc3B3Oc5cc6oc7ccccc7c6cc5-c5cc6c(oc7ccccc76)c1c53)oc1cc3c(cc14)C(C)(C)CCC3(C)C)C(C)(C)CCC2(C)C]

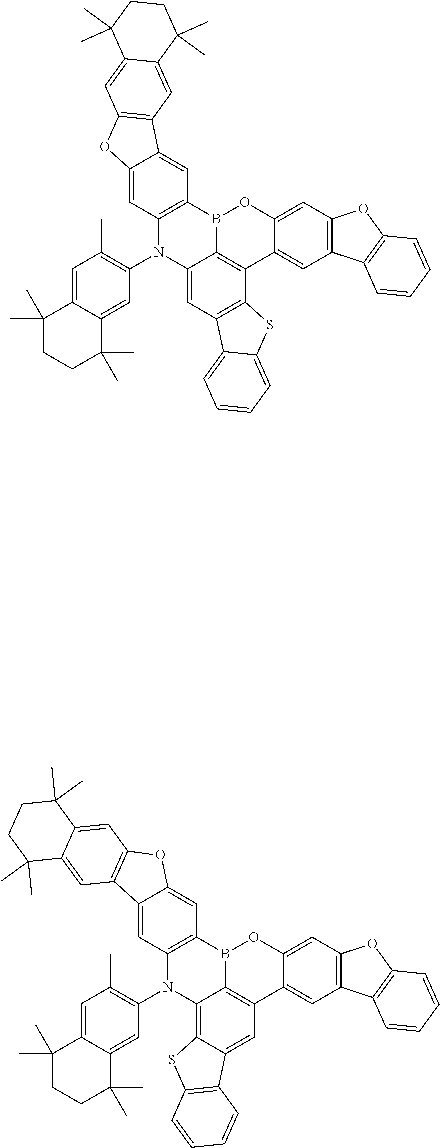 [SMILES: Cc1cc2c(cc1N1c3cc4oc5cc6c(cc5c4cc3B3Oc4cc5oc7ccccc7c5cc4-c4c3c1cc1c4sc3ccccc31)C(C)(C)CCC6(C)C)C(C)(C)CCC2(C)C ; Cc1cc2c(cc1N1c3cc4c(cc3B3Oc5cc6oc7ccccc7c6cc5-c5cc6c(sc7ccccc76)c1c53)oc1cc3c(cc14)C(C)(C)CCC3(C)C)C(C)(C)CCC2(C)C]

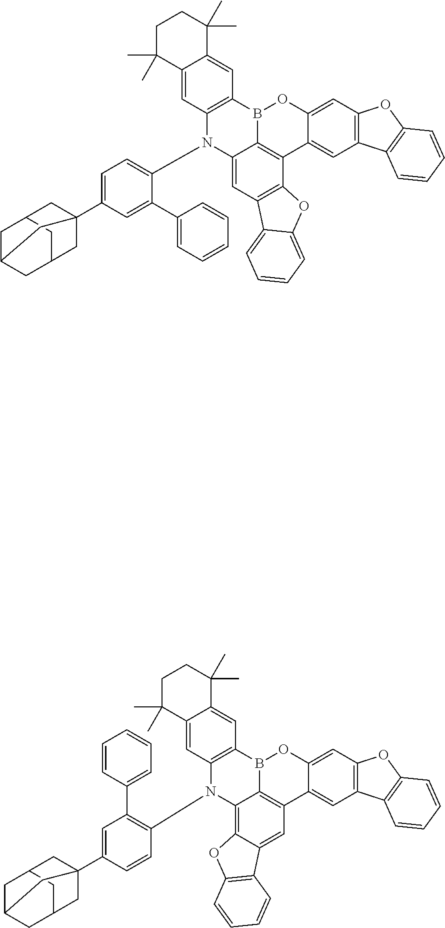 [SMILES: CC1(C)CCC(C)(C)c2cc3c(cc21)B1Oc2cc4oc5ccccc5c4cc2-c2c1c(cc1c2oc2ccccc21)N3c1ccc(C23CC4CC(CC(C4)C2)C3)cc1-c1ccccc1 ; CC1(C)CCC(C)(C)c2cc3c(cc21)B1Oc2cc4oc5ccccc5c4cc2-c2cc4c(oc5ccccc54)c(c21)N3c1ccc(C23CC4CC(CC(C4)C2)C3)cc1-c1ccccc1]

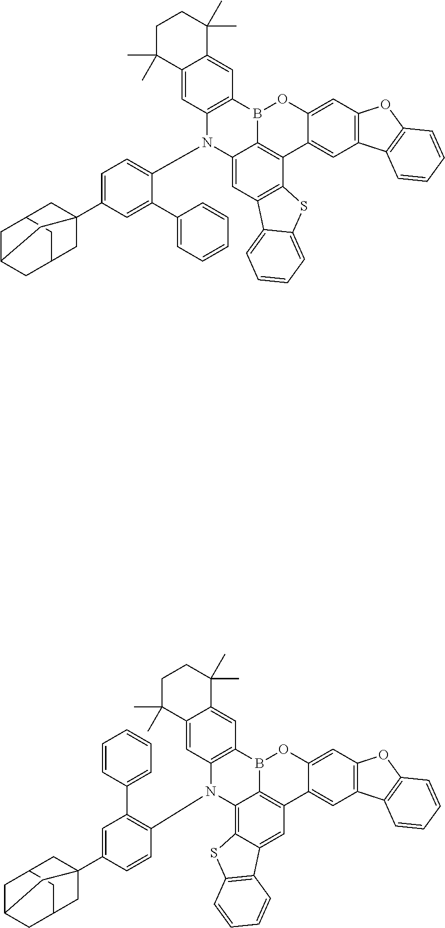 [SMILES: CC1(C)CCC(C)(C)c2cc3c(cc21)B1Oc2cc4oc5ccccc5c4cc2-c2c1c(cc1c2sc2ccccc21)N3c1ccc(C23CC4CC(CC(C4)C2)C3)cc1-c1ccccc1 ; CC1(C)CCC(C)(C)c2cc3c(cc21)B1Oc2cc4oc5ccccc5c4cc2-c2cc4c(sc5ccccc54)c(c21)N3c1ccc(C23CC4CC(CC(C4)C2)C3)cc1-c1ccccc1]

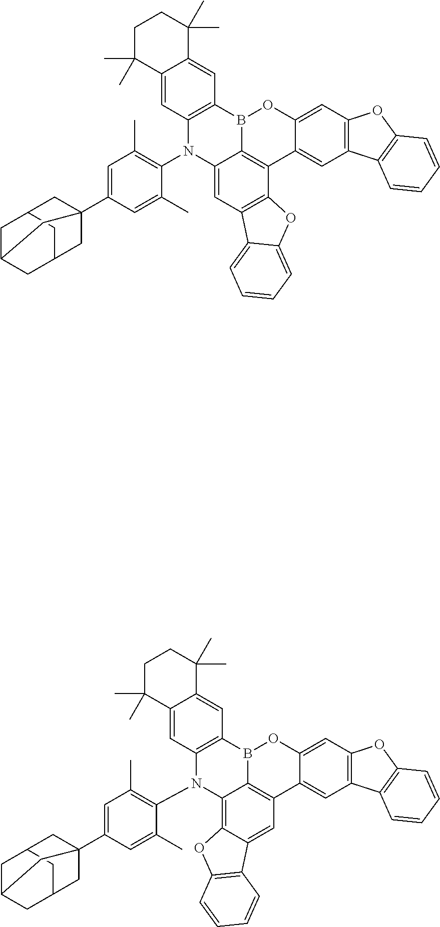 [SMILES: Cc1cc(C23CC4CC(CC(C4)C2)C3)cc(C)c1N1c2cc3c(cc2B2Oc4cc5oc6ccccc6c5cc4-c4c2c1cc1c4oc2ccccc21)C(C)(C)CCC3(C)C ; Cc1cc(C23CC4CC(CC(C4)C2)C3)cc(C)c1N1c2cc3c(cc2B2Oc4cc5oc6ccccc6c5cc4-c4cc5c(oc6ccccc65)c1c42)C(C)(C)CCC3(C)C]

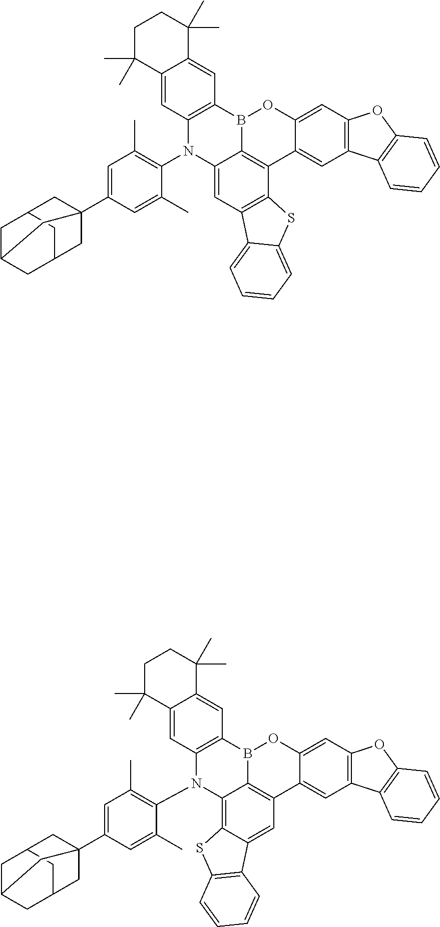 [SMILES: Cc1cc(C23CC4CC(CC(C4)C2)C3)cc(C)c1N1c2cc3c(cc2B2Oc4cc5oc6ccccc6c5cc4-c4c2c1cc1c4sc2ccccc21)C(C)(C)CCC3(C)C ; Cc1cc(C23CC4CC(CC(C4)C2)C3)cc(C)c1N1c2cc3c(cc2B2Oc4cc5oc6ccccc6c5cc4-c4cc5c(sc6ccccc65)c1c42)C(C)(C)CCC3(C)C]

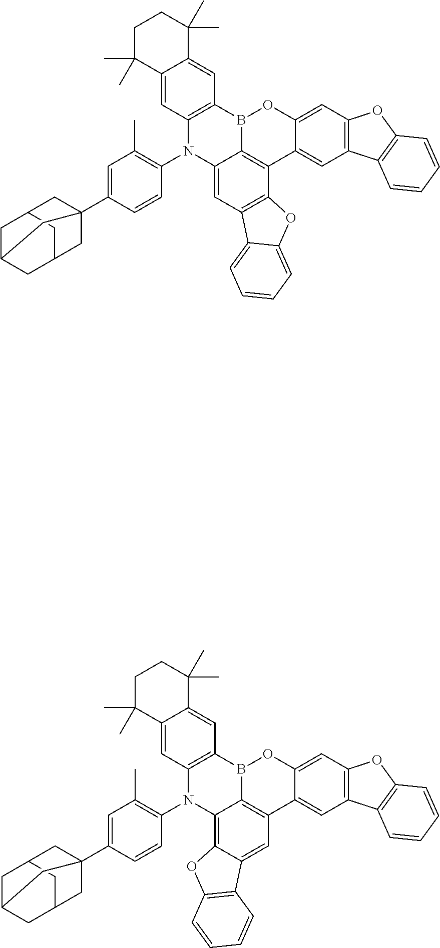 [SMILES: Cc1cc(C23CC4CC(CC(C4)C2)C3)ccc1N1c2cc3c(cc2B2Oc4cc5oc6ccccc6c5cc4-c4c2c1cc1c4oc2ccccc21)C(C)(C)CCC3(C)C ; Cc1cc(C23CC4CC(CC(C4)C2)C3)ccc1N1c2cc3c(cc2B2Oc4cc5oc6ccccc6c5cc4-c4cc5c(oc6ccccc65)c1c42)C(C)(C)CCC3(C)C]

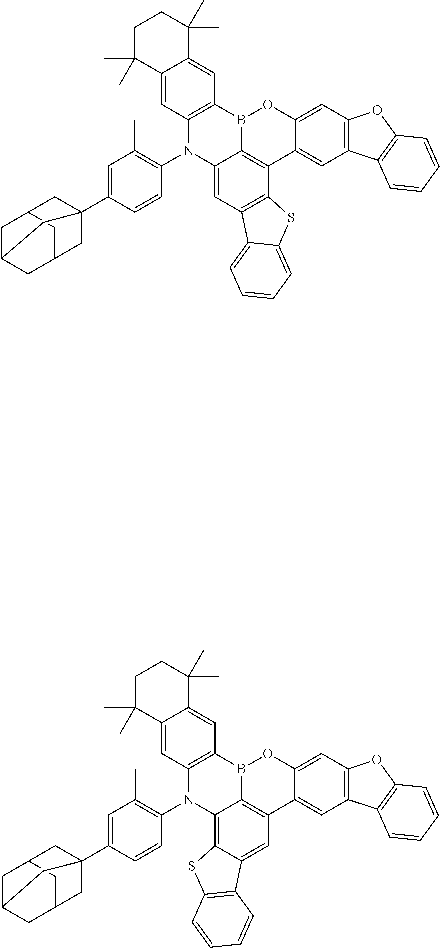 [SMILES: Cc1cc(C23CC4CC(CC(C4)C2)C3)ccc1N1c2cc3c(cc2B2Oc4cc5oc6ccccc6c5cc4-c4c2c1cc1c4sc2ccccc21)C(C)(C)CCC3(C)C ; Cc1cc(C23CC4CC(CC(C4)C2)C3)ccc1N1c2cc3c(cc2B2Oc4cc5oc6ccccc6c5cc4-c4cc5c(sc6ccccc65)c1c42)C(C)(C)CCC3(C)C]

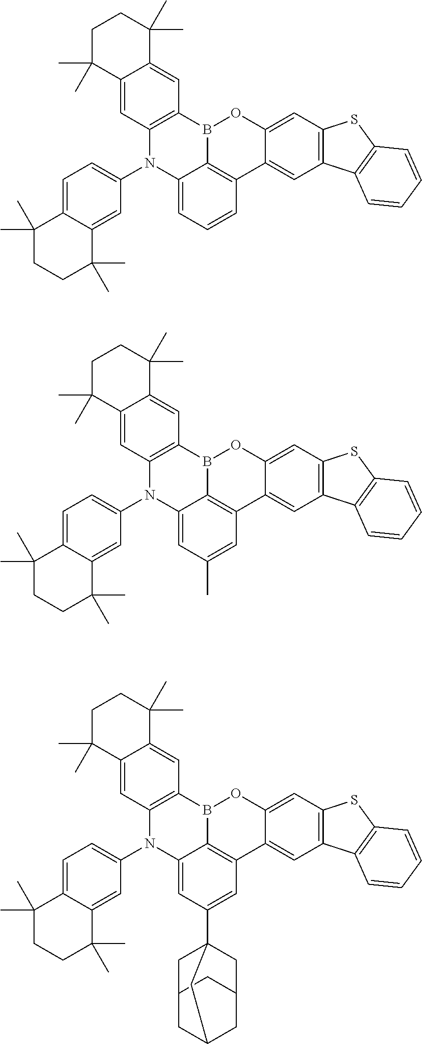 [SMILES: CC1(C)CCC(C)(C)c2cc(N3c4cc5c(cc4B4Oc6cc7sc8ccccc8c7cc6-c6cccc3c64)C(C)(C)CCC5(C)C)ccc21 ; Cc1cc2c3c(c1)N(c1ccc4c(c1)C(C)(C)CCC4(C)C)c1cc4c(cc1B3Oc1cc3sc5ccccc5c3cc1-2)C(C)(C)CCC4(C)C ; CC1(C)CCC(C)(C)c2cc(N3c4cc5c(cc4B4Oc6cc7sc8ccccc8c7cc6-c6cc(C78CC9CC(CC(C9)C7)C8)cc3c64)C(C)(C)CCC5(C)C)ccc21]

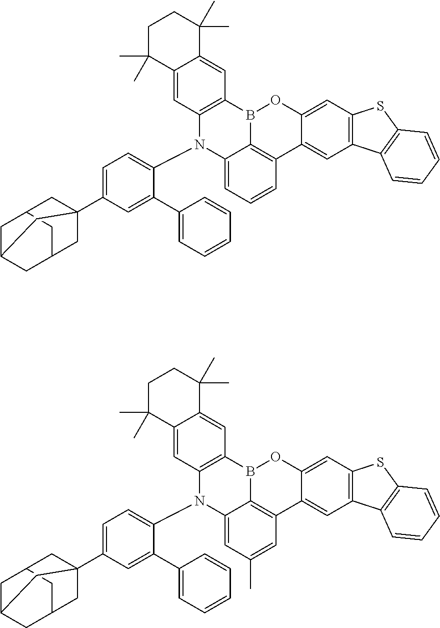 [SMILES: CC1(C)CCC(C)(C)c2cc3c(cc21)B1Oc2cc4sc5ccccc5c4cc2-c2cccc(c21)N3c1ccc(C23CC4CC(CC(C4)C2)C3)cc1-c1ccccc1 ; Cc1cc2c3c(c1)N(c1ccc(C45CC6CC(CC(C6)C4)C5)cc1-c1ccccc1)c1cc4c(cc1B3Oc1cc3sc5ccccc5c3cc1-2)C(C)(C)CCC4(C)C]

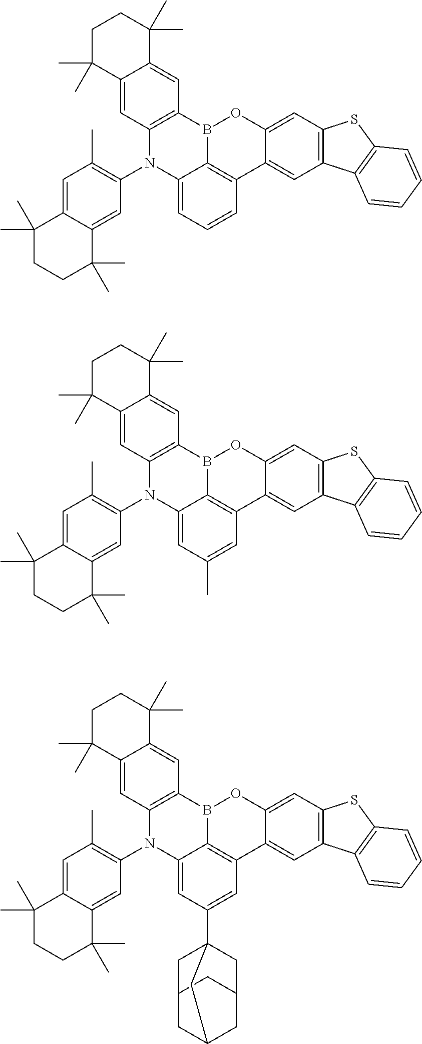 [SMILES: Cc1cc2c(cc1N1c3cc4c(cc3B3Oc5cc6sc7ccccc7c6cc5-c5cccc1c53)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Oc1cc3sc5ccccc5c3cc1-2)C(C)(C)CCC4(C)C ; Cc1cc2c(cc1N1c3cc4c(cc3B3Oc5cc6sc7ccccc7c6cc5-c5cc(C67CC8CC(CC(C8)C6)C7)cc1c53)C(C)(C)CCC4(C)C)C(C)(C)CCC2(C)C]

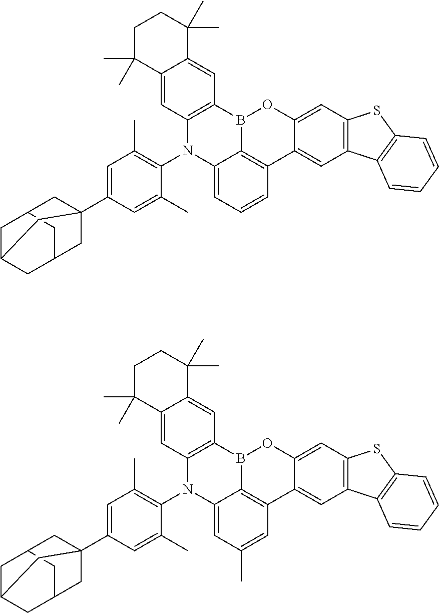 [SMILES: Cc1cc(C23CC4CC(CC(C4)C2)C3)cc(C)c1N1c2cc3c(cc2B2Oc4cc5sc6ccccc6c5cc4-c4cccc1c42)C(C)(C)CCC3(C)C ; Cc1cc2c3c(c1)N(c1c(C)cc(C45CC6CC(CC(C6)C4)C5)cc1C)c1cc4c(cc1B3Oc1cc3sc5ccccc5c3cc1-2)C(C)(C)CCC4(C)C]

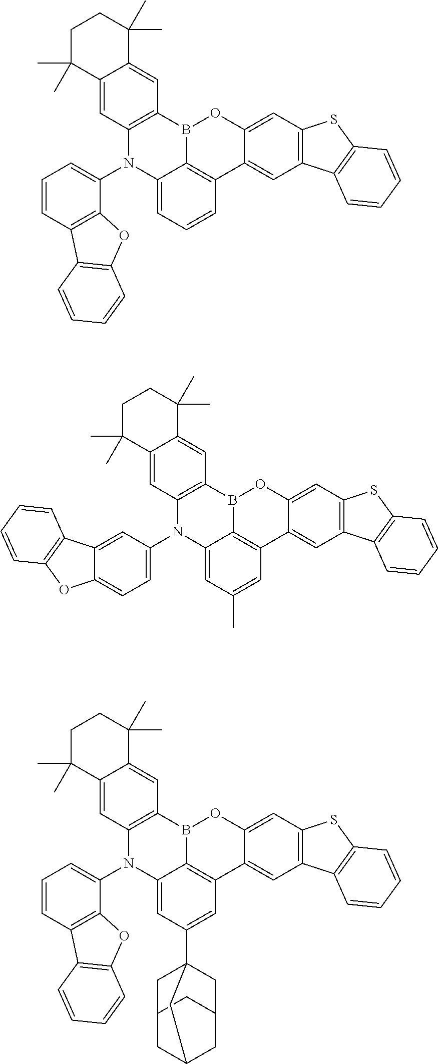 [SMILES: CC1(C)CCC(C)(C)c2cc3c(cc21)B1Oc2cc4sc5ccccc5c4cc2-c2cccc(c21)N3c1cccc2c1oc1ccccc12 ; Cc1cc2c3c(c1)N(c1ccc4oc5ccccc5c4c1)c1cc4c(cc1B3Oc1cc3sc5ccccc5c3cc1-2)C(C)(C)CCC4(C)C ; CC1(C)CCC(C)(C)c2cc3c(cc21)B1Oc2cc4sc5ccccc5c4cc2-c2cc(C45CC6CC(CC(C6)C4)C5)cc(c21)N3c1cccc2c1oc1ccccc12]

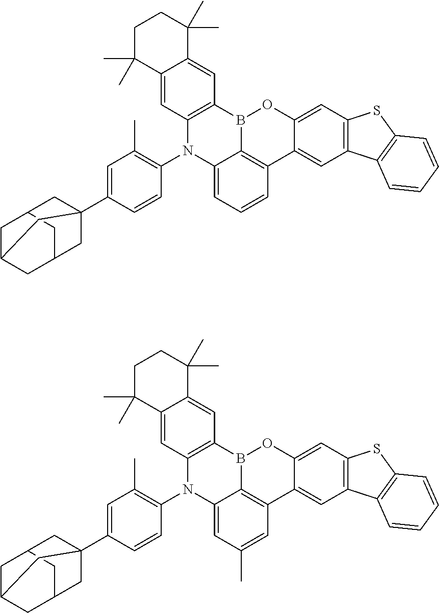 [SMILES: Cc1cc(C23CC4CC(CC(C4)C2)C3)ccc1N1c2cc3c(cc2B2Oc4cc5sc6ccccc6c5cc4-c4cccc1c42)C(C)(C)CCC3(C)C ; Cc1cc2c3c(c1)N(c1ccc(C45CC6CC(CC(C6)C4)C5)cc1C)c1cc4c(cc1B3Oc1cc3sc5ccccc5c3cc1-2)C(C)(C)CCC4(C)C]

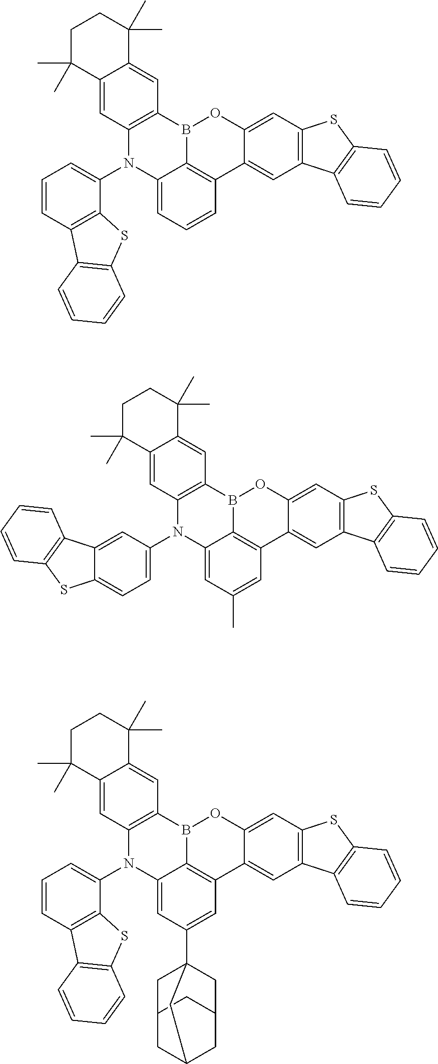 [SMILES: CC1(C)CCC(C)(C)c2cc3c(cc21)B1Oc2cc4sc5ccccc5c4cc2-c2cccc(c21)N3c1cccc2c1sc1ccccc12 ; Cc1cc2c3c(c1)N(c1ccc4sc5ccccc5c4c1)c1cc4c(cc1B3Oc1cc3sc5ccccc5c3cc1-2)C(C)(C)CCC4(C)C ; CC1(C)CCC(C)(C)c2cc3c(cc21)B1Oc2cc4sc5ccccc5c4cc2-c2cc(C45CC6CC(CC(C6)C4)C5)cc(c21)N3c1cccc2c1sc1ccccc12]

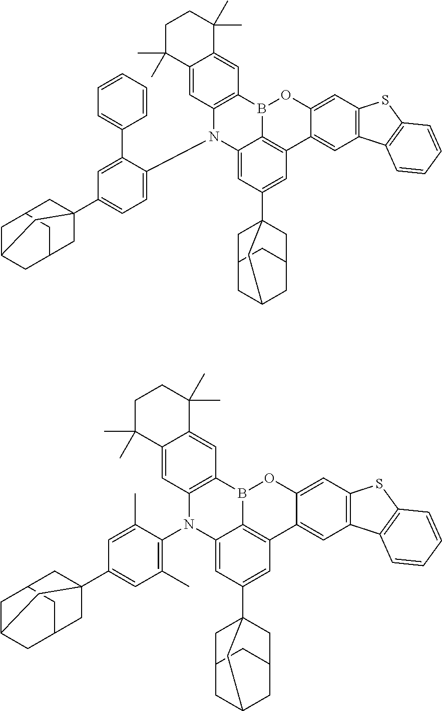 [SMILES: CC1(C)CCC(C)(C)c2cc3c(cc21)B1Oc2cc4sc5ccccc5c4cc2-c2cc(C45CC6CC(CC(C6)C4)C5)cc(c21)N3c1ccc(C23CC4CC(CC(C4)C2)C3)cc1-c1ccccc1 ; Cc1cc(C23CC4CC(CC(C4)C2)C3)cc(C)c1N1c2cc3c(cc2B2Oc4cc5sc6ccccc6c5cc4-c4cc(C56CC7CC(CC(C7)C5)C6)cc1c42)C(C)(C)CCC3(C)C]

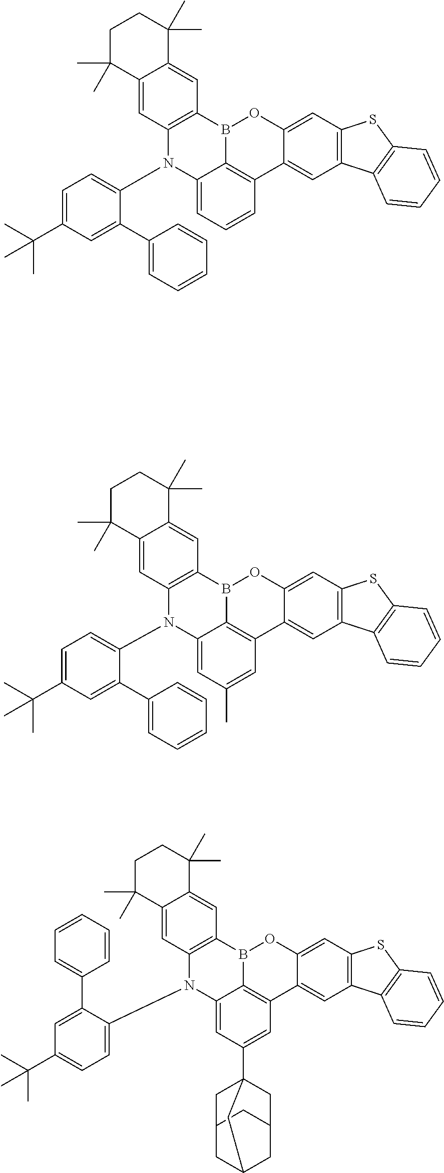 [SMILES: CC(C)(C)c1ccc(N2c3cc4c(cc3B3Oc5cc6sc7ccccc7c6cc5-c5cccc2c53)C(C)(C)CCC4(C)C)c(-c2ccccc2)c1 ; Cc1cc2c3c(c1)N(c1ccc(C(C)(C)C)cc1-c1ccccc1)c1cc4c(cc1B3Oc1cc3sc5ccccc5c3cc1-2)C(C)(C)CCC4(C)C ; CC(C)(C)c1ccc(N2c3cc4c(cc3B3Oc5cc6sc7ccccc7c6cc5-c5cc(C67CC8CC(CC(C8)C6)C7)cc2c53)C(C)(C)CCC4(C)C)c(-c2ccccc2)c1]

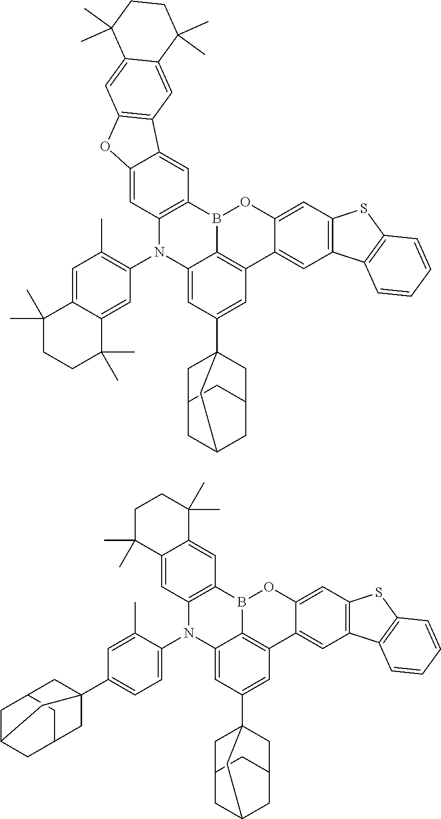

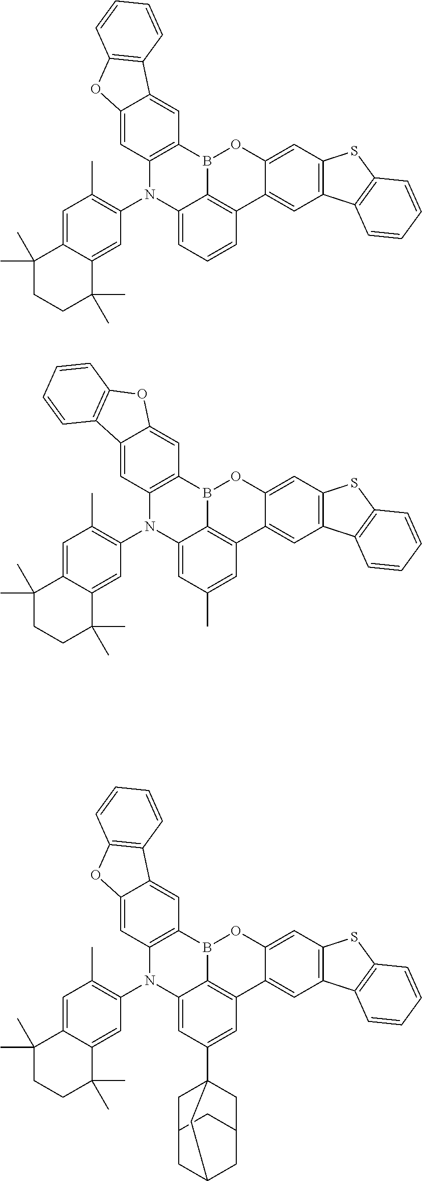

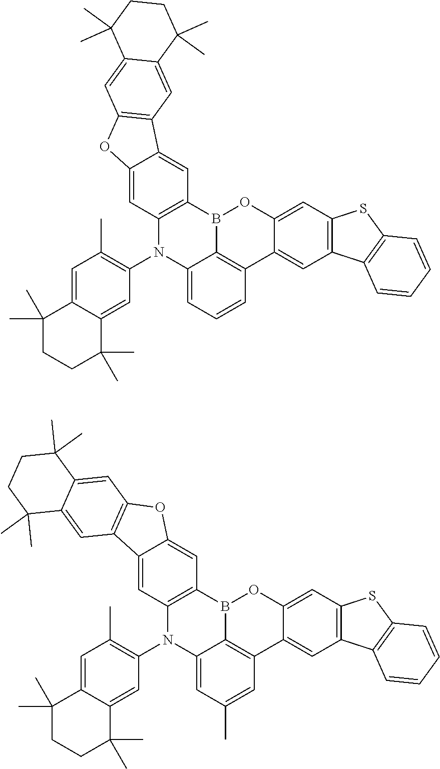 [SMILES: Cc1cc2c(cc1N1c3cc4oc5cc6c(cc5c4cc3B3Oc4cc5sc7ccccc7c5cc4-c4cccc1c43)C(C)(C)CCC6(C)C)C(C)(C)CCC2(C)C ; Cc1cc2c3c(c1)N(c1cc4c(cc1C)C(C)(C)CCC4(C)C)c1cc4c(cc1B3Oc1cc3sc5ccccc5c3cc1-2)oc1cc2c(cc14)C(C)(C)CCC2(C)C]

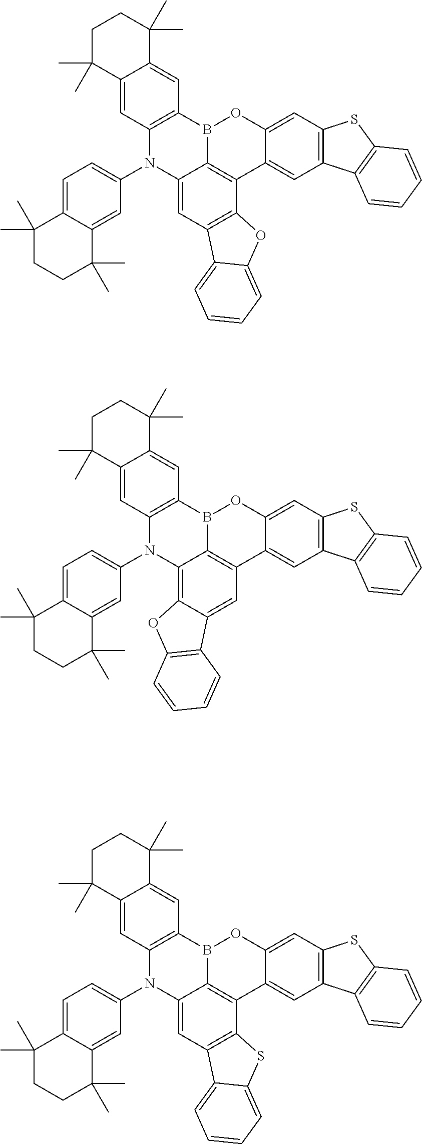 [SMILES: CC1(C)CCC(C)(C)c2cc(N3c4cc5c(cc4B4Oc6cc7sc8ccccc8c7cc6-c6c4c3cc3c6oc4ccccc43)C(C)(C)CCC5(C)C)ccc21 ; CC1(C)CCC(C)(C)c2cc(N3c4cc5c(cc4B4Oc6cc7sc8ccccc8c7cc6-c6cc7c(oc8ccccc87)c3c64)C(C)(C)CCC5(C)C)ccc21 ; CC1(C)CCC(C)(C)c2cc(N3c4cc5c(cc4B4Oc6cc7sc8ccccc8c7cc6-c6c4c3cc3c6sc4ccccc43)C(C)(C)CCC5(C)C)ccc21]

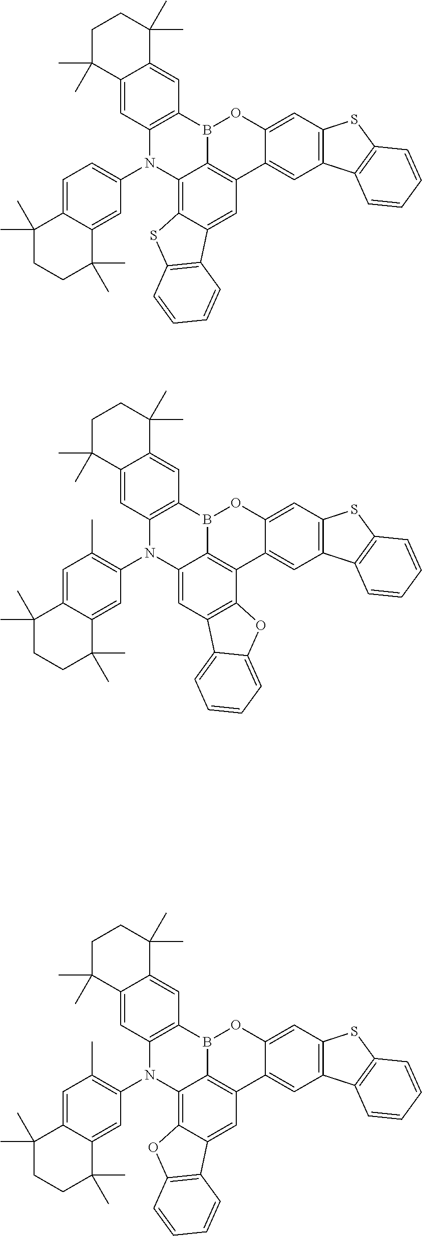 [SMILES: CC1(C)CCC(C)(C)c2cc(N3c4cc5c(cc4B4Oc6cc7sc8ccccc8c7cc6-c6cc7c(sc8ccccc87)c3c64)C(C)(C)CCC5(C)C)ccc21 ; Cc1cc2c(cc1N1c3cc4c(cc3B3Oc5cc6sc7ccccc7c6cc5-c5c3c1cc1c5oc3ccccc31)C(C)(C)CCC4(C)C)C(C)(C)CCC2(C)C ; Cc1cc2c(cc1N1c3cc4c(cc3B3Oc5cc6sc7ccccc7c6cc5-c5cc6c(oc7ccccc76)c1c53)C(C)(C)CCC4(C)C)C(C)(C)CCC2(C)C]

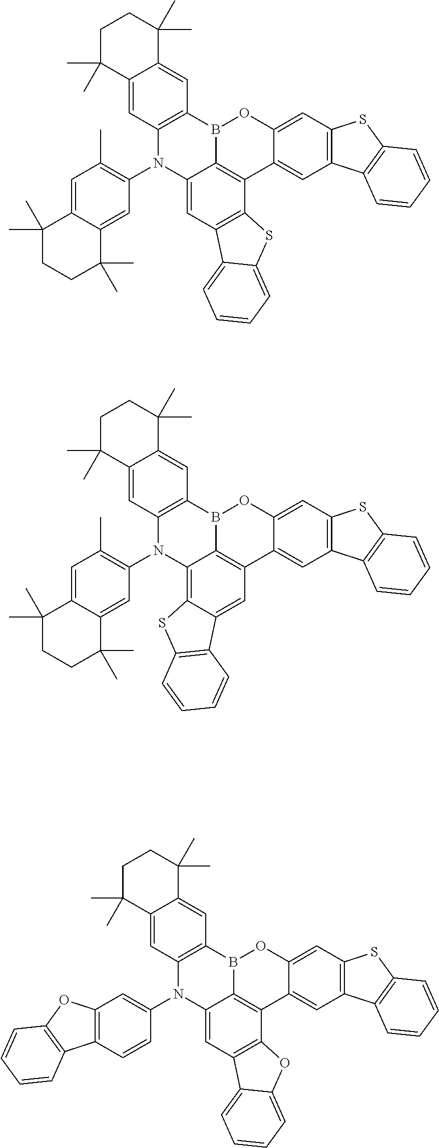 [SMILES: Cc1cc2c(cc1N1c3cc4c(cc3B3Oc5cc6sc7ccccc7c6cc5-c5c3c1cc1c5sc3ccccc31)C(C)(C)CCC4(C)C)C(C)(C)CCC2(C)C ; Cc1cc2c(cc1N1c3cc4c(cc3B3Oc5cc6sc7ccccc7c6cc5-c5cc6c(sc7ccccc76)c1c53)C(C)(C)CCC4(C)C)C(C)(C)CCC2(C)C ; CC1(C)CCC(C)(C)c2cc3c(cc21)B1Oc2cc4sc5ccccc5c4cc2-c2c1c(cc1c2oc2ccccc21)N3c1ccc2c(c1)oc1ccccc12]

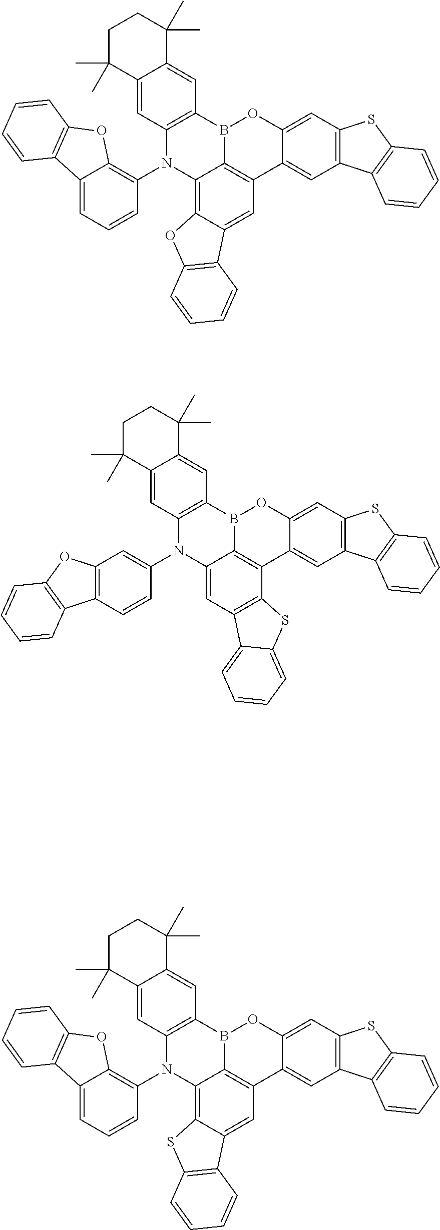 [SMILES: CC1(C)CCC(C)(C)c2cc3c(cc21)B1Oc2cc4sc5ccccc5c4cc2-c2cc4c(oc5ccccc54)c(c21)N3c1cccc2c1oc1ccccc12 ; CC1(C)CCC(C)(C)c2cc3c(cc21)B1Oc2cc4sc5ccccc5c4cc2-c2c1c(cc1c2sc2ccccc21)N3c1ccc2c(c1)oc1ccccc12 ; CC1(C)CCC(C)(C)c2cc3c(cc21)B1Oc2cc4sc5ccccc5c4cc2-c2cc4c(sc5ccccc54)c(c21)N3c1cccc2c1oc1ccccc12]

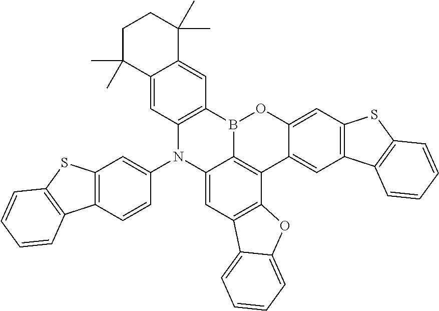 [SMILES: CC1(C)CCC(C)(C)c2cc3c(cc21)B1Oc2cc4sc5ccccc5c4cc2-c2c1c(cc1c2oc2ccccc21)N3c1ccc2c(c1)sc1ccccc12]

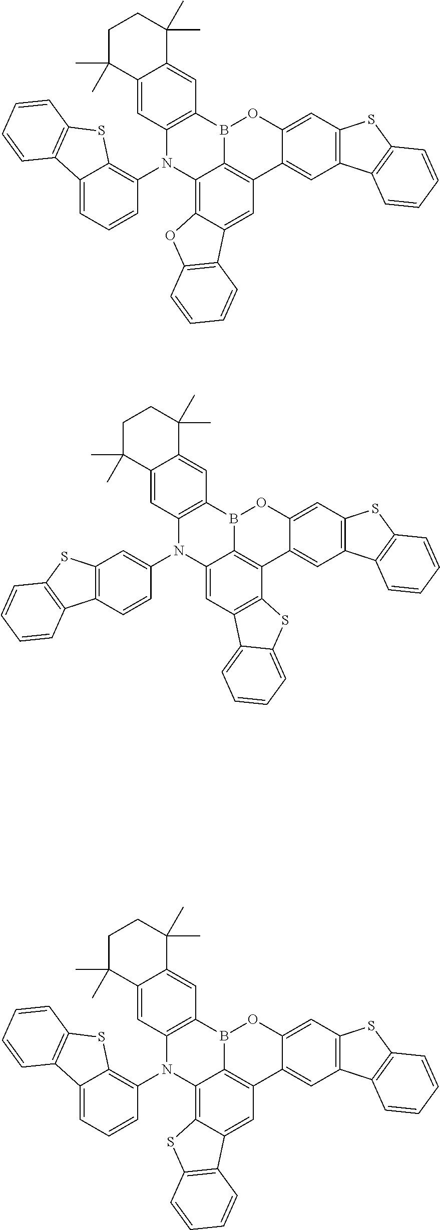 [SMILES: CC1(C)CCC(C)(C)c2cc3c(cc21)B1Oc2cc4sc5ccccc5c4cc2-c2cc4c(oc5ccccc54)c(c21)N3c1cccc2c1sc1ccccc12 ; CC1(C)CCC(C)(C)c2cc3c(cc21)B1Oc2cc4sc5ccccc5c4cc2-c2c1c(cc1c2sc2ccccc21)N3c1ccc2c(c1)sc1ccccc12 ; CC1(C)CCC(C)(C)c2cc3c(cc21)B1Oc2cc4sc5ccccc5c4cc2-c2cc4c(sc5ccccc54)c(c21)N3c1cccc2c1sc1ccccc12]

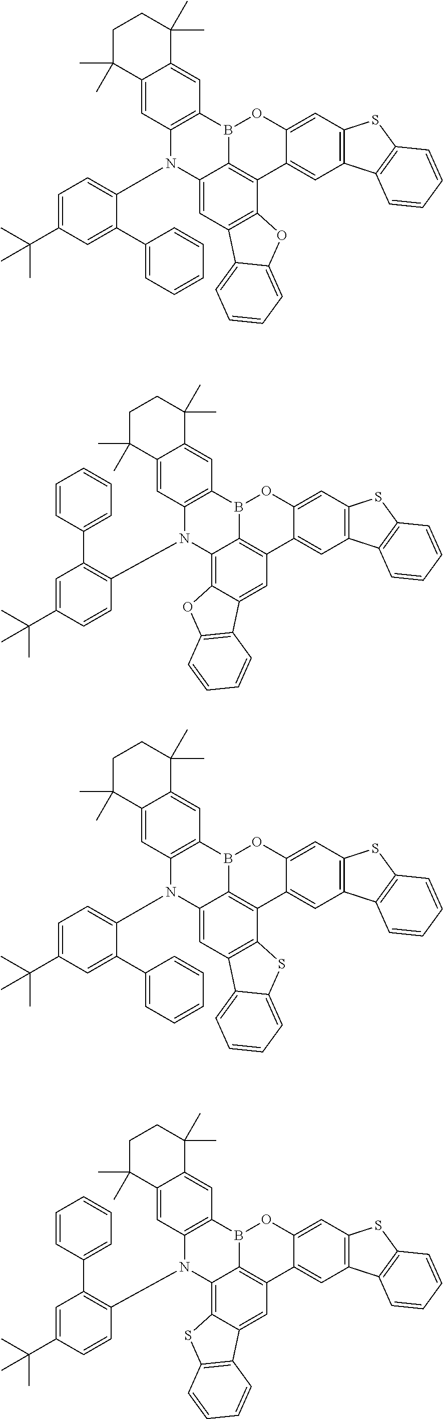

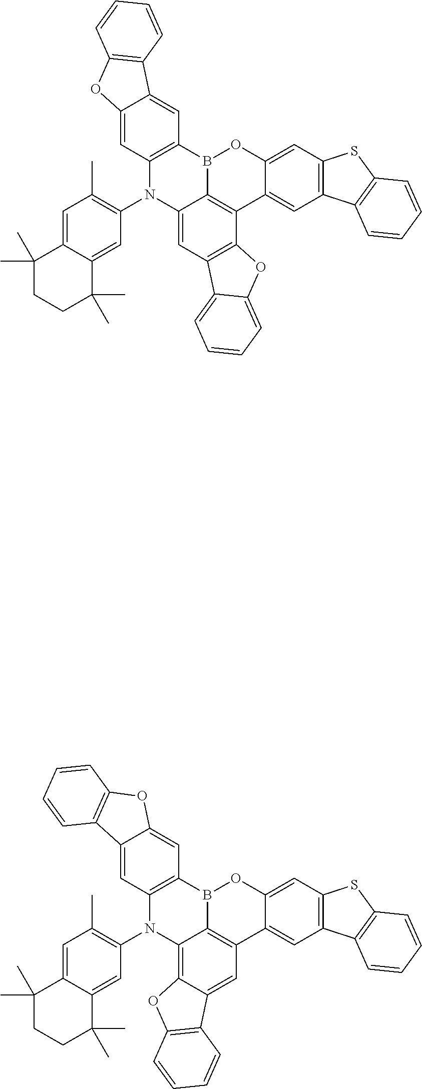 [SMILES: Cc1cc2c(cc1N1c3cc4oc5ccccc5c4cc3B3Oc4cc5sc6ccccc6c5cc4-c4c3c1cc1c4oc3ccccc31)C(C)(C)CCC2(C)C ; Cc1cc2c(cc1N1c3cc4c(cc3B3Oc5cc6sc7ccccc7c6cc5-c5cc6c(oc7ccccc76)c1c53)oc1ccccc14)C(C)(C)CCC2(C)C]

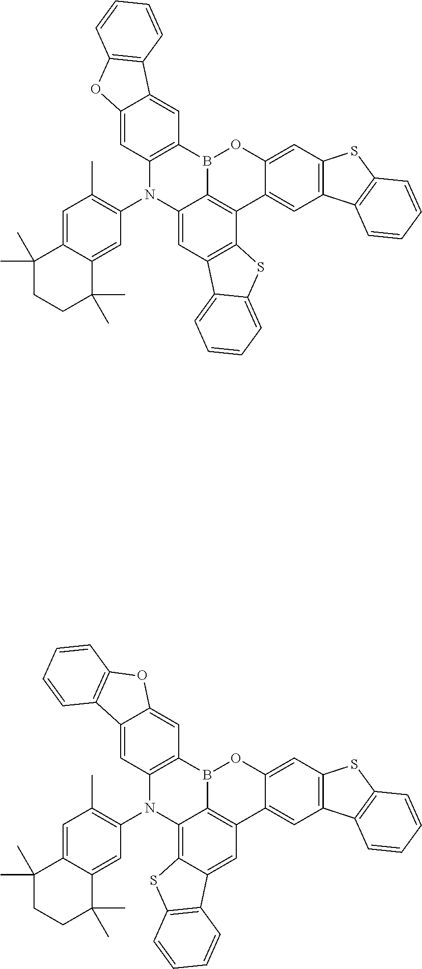 [SMILES: Cc1cc2c(cc1N1c3cc4oc5ccccc5c4cc3B3Oc4cc5sc6ccccc6c5cc4-c4c3c1cc1c4sc3ccccc31)C(C)(C)CCC2(C)C ; Cc1cc2c(cc1N1c3cc4c(cc3B3Oc5cc6sc7ccccc7c6cc5-c5cc6c(sc7ccccc76)c1c53)oc1ccccc14)C(C)(C)CCC2(C)C]

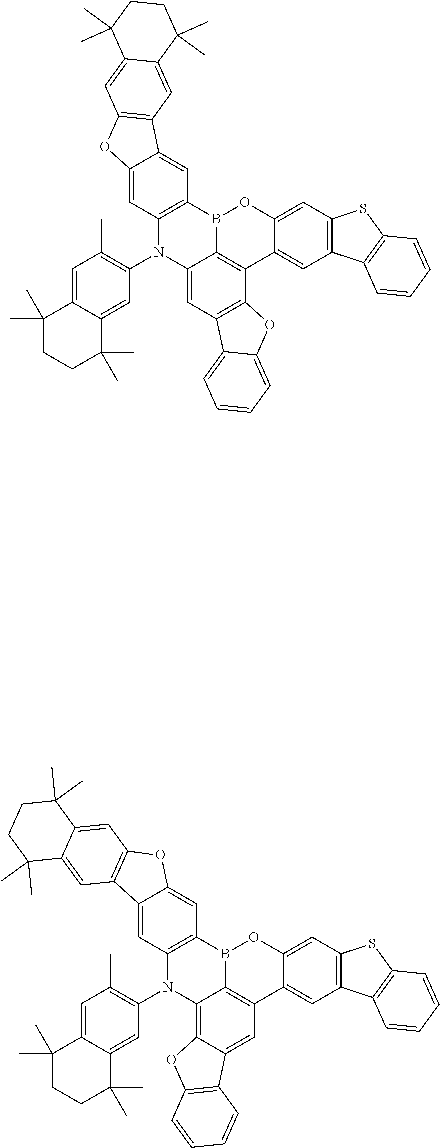 [SMILES: Cc1cc2c(cc1N1c3cc4oc5cc6c(cc5c4cc3B3Oc4cc5sc7ccccc7c5cc4-c4c3c1cc1c4oc3ccccc31)C(C)(C)CCC6(C)C)C(C)(C)CCC2(C)C ; Cc1cc2c(cc1N1c3cc4c(cc3B3Oc5cc6sc7ccccc7c6cc5-c5cc6c(oc7ccccc76)c1c53)oc1cc3c(cc14)C(C)(C)CCC3(C)C)C(C)(C)CCC2(C)C]

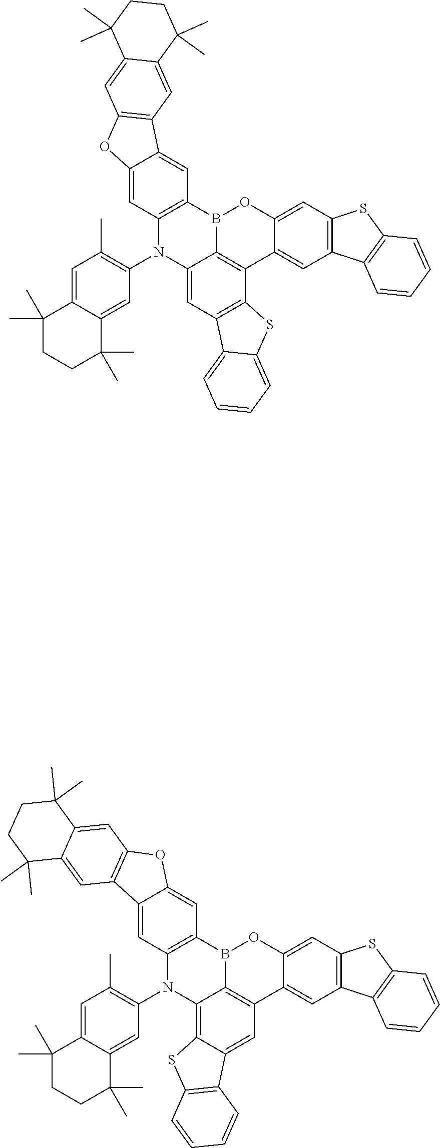 [SMILES: Cc1cc2c(cc1N1c3cc4oc5cc6c(cc5c4cc3B3Oc4cc5sc7ccccc7c5cc4-c4c3c1cc1c4sc3ccccc31)C(C)(C)CCC6(C)C)C(C)(C)CCC2(C)C ; Cc1cc2c(cc1N1c3cc4c(cc3B3Oc5cc6sc7ccccc7c6cc5-c5cc6c(sc7ccccc76)c1c53)oc1cc3c(cc14)C(C)(C)CCC3(C)C)C(C)(C)CCC2(C)C]

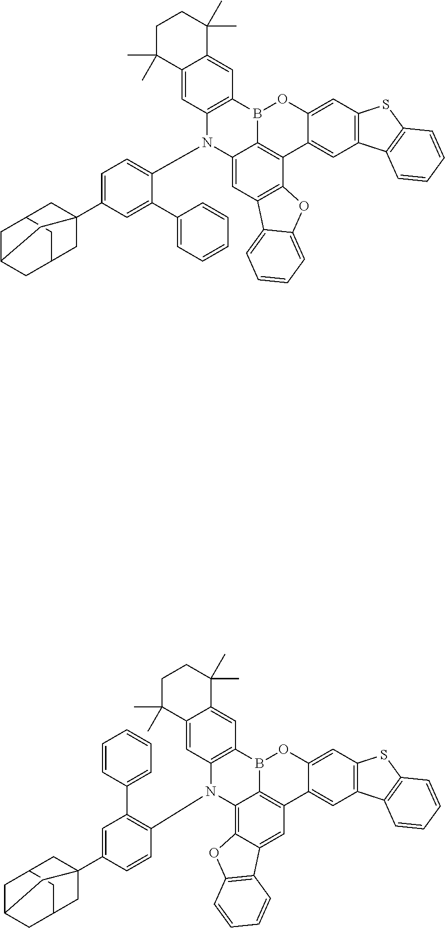 [SMILES: CC1(C)CCC(C)(C)c2cc3c(cc21)B1Oc2cc4sc5ccccc5c4cc2-c2c1c(cc1c2oc2ccccc21)N3c1ccc(C23CC4CC(CC(C4)C2)C3)cc1-c1ccccc1 ; CC1(C)CCC(C)(C)c2cc3c(cc21)B1Oc2cc4sc5ccccc5c4cc2-c2cc4c(oc5ccccc54)c(c21)N3c1ccc(C23CC4CC(CC(C4)C2)C3)cc1-c1ccccc1]

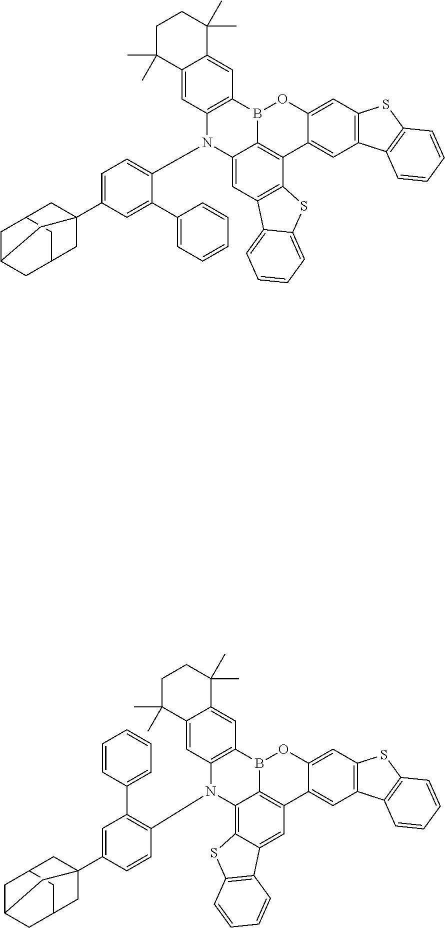 [SMILES: CC1(C)CCC(C)(C)c2cc3c(cc21)B1Oc2cc4sc5ccccc5c4cc2-c2c1c(cc1c2sc2ccccc21)N3c1ccc(C23CC4CC(CC(C4)C2)C3)cc1-c1ccccc1 ; CC1(C)CCC(C)(C)c2cc3c(cc21)B1Oc2cc4sc5ccccc5c4cc2-c2cc4c(sc5ccccc54)c(c21)N3c1ccc(C23CC4CC(CC(C4)C2)C3)cc1-c1ccccc1]

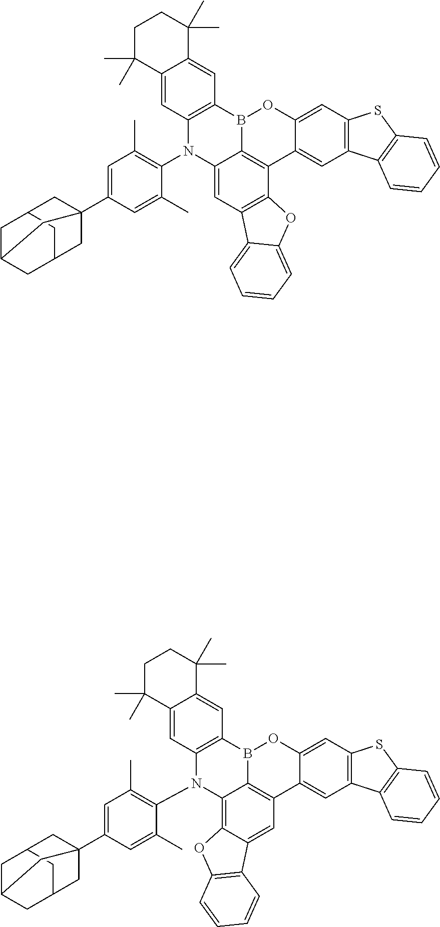 [SMILES: Cc1cc(C23CC4CC(CC(C4)C2)C3)cc(C)c1N1c2cc3c(cc2B2Oc4cc5sc6ccccc6c5cc4-c4c2c1cc1c4oc2ccccc21)C(C)(C)CCC3(C)C ; Cc1cc(C23CC4CC(CC(C4)C2)C3)cc(C)c1N1c2cc3c(cc2B2Oc4cc5sc6ccccc6c5cc4-c4cc5c(oc6ccccc65)c1c42)C(C)(C)CCC3(C)C]

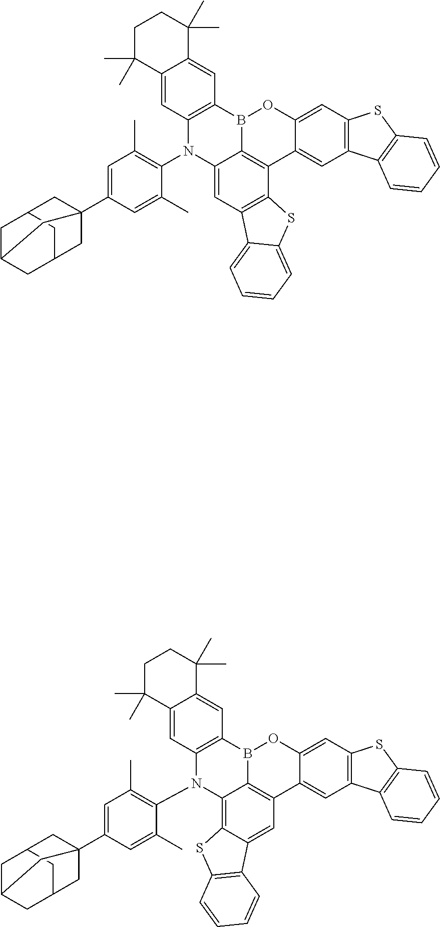 [SMILES: Cc1cc(C23CC4CC(CC(C4)C2)C3)cc(C)c1N1c2cc3c(cc2B2Oc4cc5sc6ccccc6c5cc4-c4c2c1cc1c4sc2ccccc21)C(C)(C)CCC3(C)C ; Cc1cc(C23CC4CC(CC(C4)C2)C3)cc(C)c1N1c2cc3c(cc2B2Oc4cc5sc6ccccc6c5cc4-c4cc5c(sc6ccccc65)c1c42)C(C)(C)CCC3(C)C]

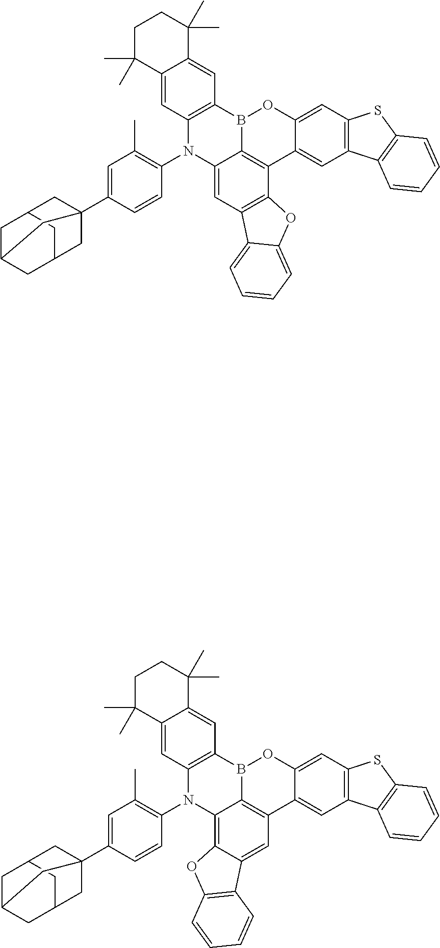 [SMILES: Cc1cc(C23CC4CC(CC(C4)C2)C3)ccc1N1c2cc3c(cc2B2Oc4cc5sc6ccccc6c5cc4-c4c2c1cc1c4oc2ccccc21)C(C)(C)CCC3(C)C ; Cc1cc(C23CC4CC(CC(C4)C2)C3)ccc1N1c2cc3c(cc2B2Oc4cc5sc6ccccc6c5cc4-c4cc5c(oc6ccccc65)c1c42)C(C)(C)CCC3(C)C]

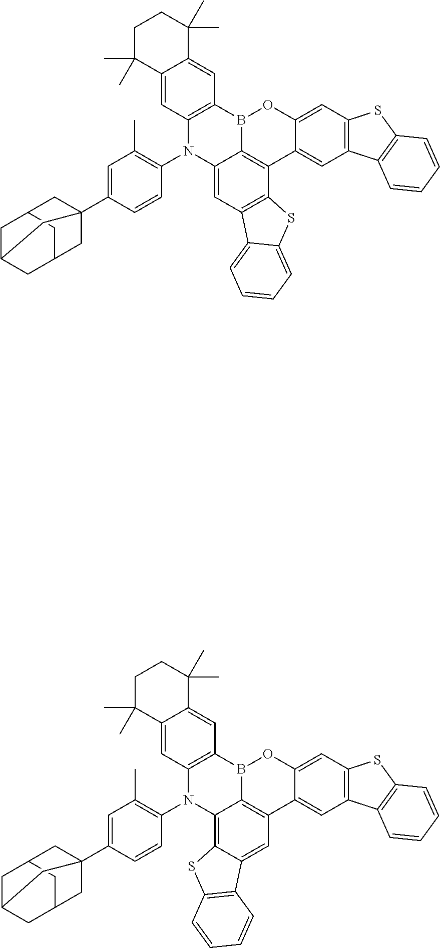 [SMILES: Cc1cc(C23CC4CC(CC(C4)C2)C3)ccc1N1c2cc3c(cc2B2Oc4cc5sc6ccccc6c5cc4-c4c2c1cc1c4sc2ccccc21)C(C)(C)CCC3(C)C ; Cc1cc(C23CC4CC(CC(C4)C2)C3)ccc1N1c2cc3c(cc2B2Oc4cc5sc6ccccc6c5cc4-c4cc5c(sc6ccccc65)c1c42)C(C)(C)CCC3(C)C]

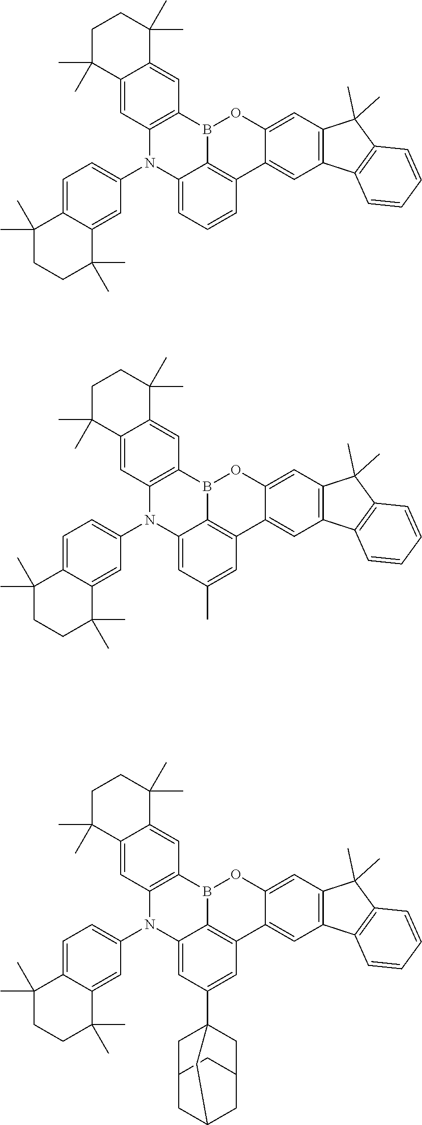 [SMILES: CC1(C)CCC(C)(C)c2cc(N3c4cc5c(cc4B4Oc6cc7c(cc6-c6cccc3c64)-c3ccccc3C7(C)C)C(C)(C)CCC5(C)C)ccc21 ; Cc1cc2c3c(c1)N(c1ccc4c(c1)C(C)(C)CCC4(C)C)c1cc4c(cc1B3Oc1cc3c(cc1-2)-c1ccccc1C3(C)C)C(C)(C)CCC4(C)C ; CC1(C)CCC(C)(C)c2cc(N3c4cc5c(cc4B4Oc6cc7c(cc6-c6cc(C89CC%10CC(CC(C%10)C8)C9)cc3c64)-c3ccccc3C7(C)C)C(C)(C)CCC5(C)C)ccc21]

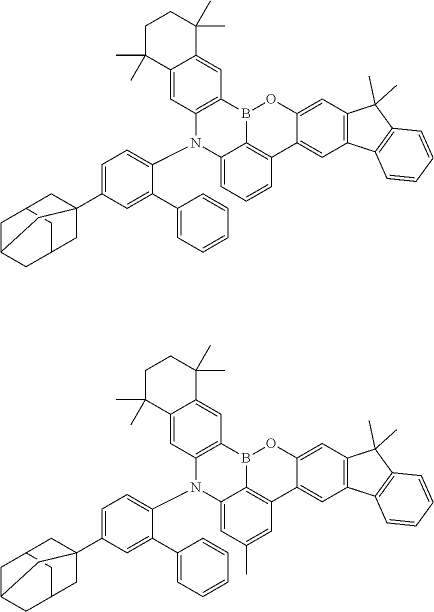 [SMILES: CC1(C)CCC(C)(C)c2cc3c(cc21)B1Oc2cc4c(cc2-c2cccc(c21)N3c1ccc(C23CC5CC(CC(C5)C2)C3)cc1-c1ccccc1)-c1ccccc1C4(C)C ; Cc1cc2c3c(c1)N(c1ccc(C45CC6CC(CC(C6)C4)C5)cc1-c1ccccc1)c1cc4c(cc1B3Oc1cc3c(cc1-2)-c1ccccc1C3(C)C)C(C)(C)CCC4(C)C]

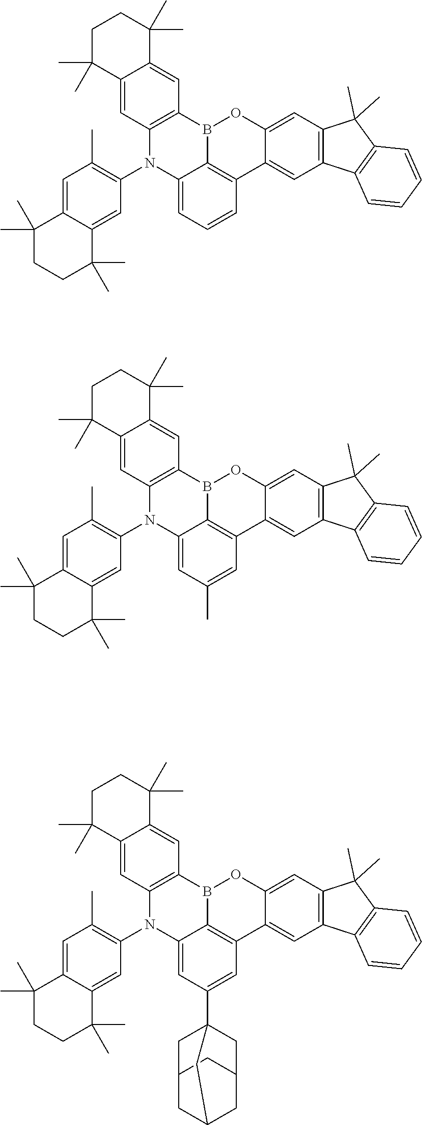 [SMILES: Cc1cc2c(cc1N1c3cc4c(cc3B3Oc5cc6c(cc5-c5cccc1c53)-c1ccccc1C6(C)C)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Oc1cc3c(cc1-2)-c1ccccc1C3(C)C)C(C)(C)CCC4(C)C ; Cc1cc2c(cc1N1c3cc4c(cc3B3Oc5cc6c(cc5-c5cc(C78CC9CC(CC(C9)C7)C8)cc1c53)-c1ccccc1C6(C)C)C(C)(C)CCC4(C)C)C(C)(C)CCC2(C)C]

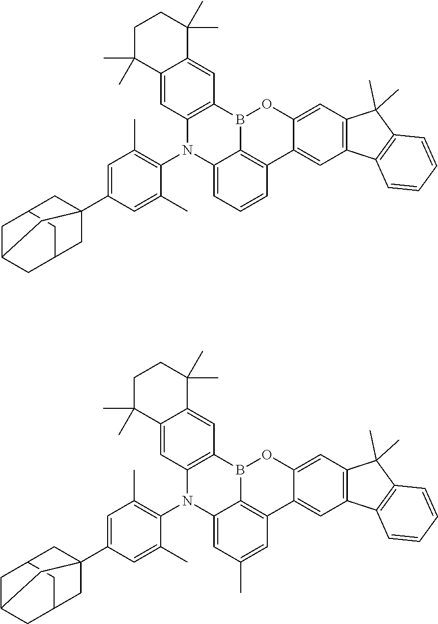 [SMILES: Cc1cc(C23CC4CC(CC(C4)C2)C3)cc(C)c1N1c2cc3c(cc2B2Oc4cc5c(cc4-c4cccc1c42)-c1ccccc1C5(C)C)C(C)(C)CCC3(C)C ; Cc1cc2c3c(c1)N(c1c(C)cc(C45CC6CC(CC(C6)C4)C5)cc1C)c1cc4c(cc1B3Oc1cc3c(cc1-2)-c1ccccc1C3(C)C)C(C)(C)CCC4(C)C]

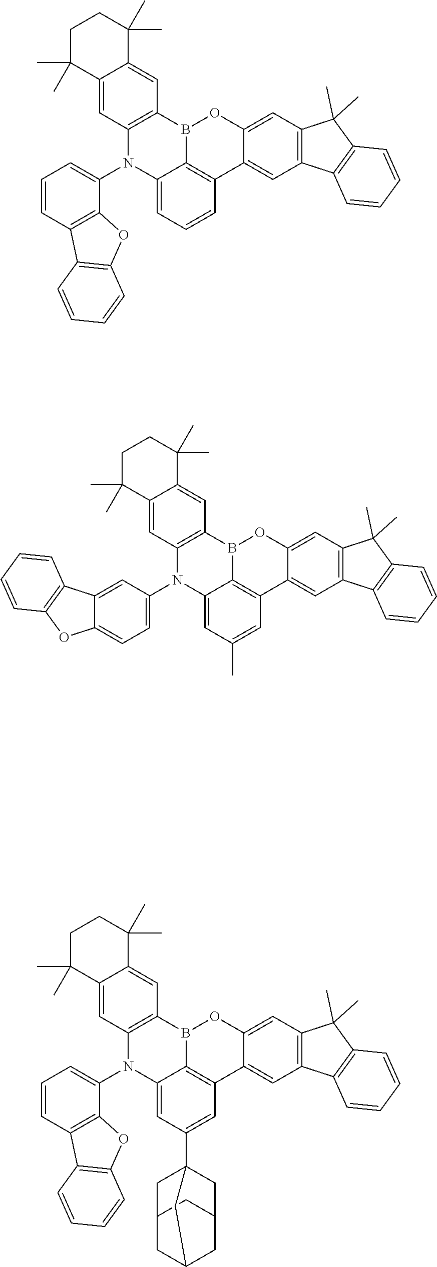 [SMILES: CC1(C)CCC(C)(C)c2cc3c(cc21)B1Oc2cc4c(cc2-c2cccc(c21)N3c1cccc2c1oc1ccccc12)-c1ccccc1C4(C)C ; Cc1cc2c3c(c1)N(c1ccc4oc5ccccc5c4c1)c1cc4c(cc1B3Oc1cc3c(cc1-2)-c1ccccc1C3(C)C)C(C)(C)CCC4(C)C ; CC1(C)CCC(C)(C)c2cc3c(cc21)B1Oc2cc4c(cc2-c2cc(C56CC7CC(CC(C7)C5)C6)cc(c21)N3c1cccc2c1oc1ccccc12)-c1ccccc1C4(C)C]

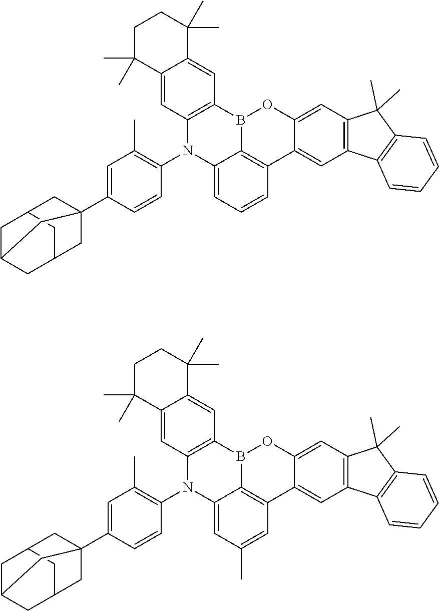 [SMILES: Cc1cc(C23CC4CC(CC(C4)C2)C3)ccc1N1c2cc3c(cc2B2Oc4cc5c(cc4-c4cccc1c42)-c1ccccc1C5(C)C)C(C)(C)CCC3(C)C ; Cc1cc2c3c(c1)N(c1ccc(C45CC6CC(CC(C6)C4)C5)cc1C)c1cc4c(cc1B3Oc1cc3c(cc1-2)-c1ccccc1C3(C)C)C(C)(C)CCC4(C)C]

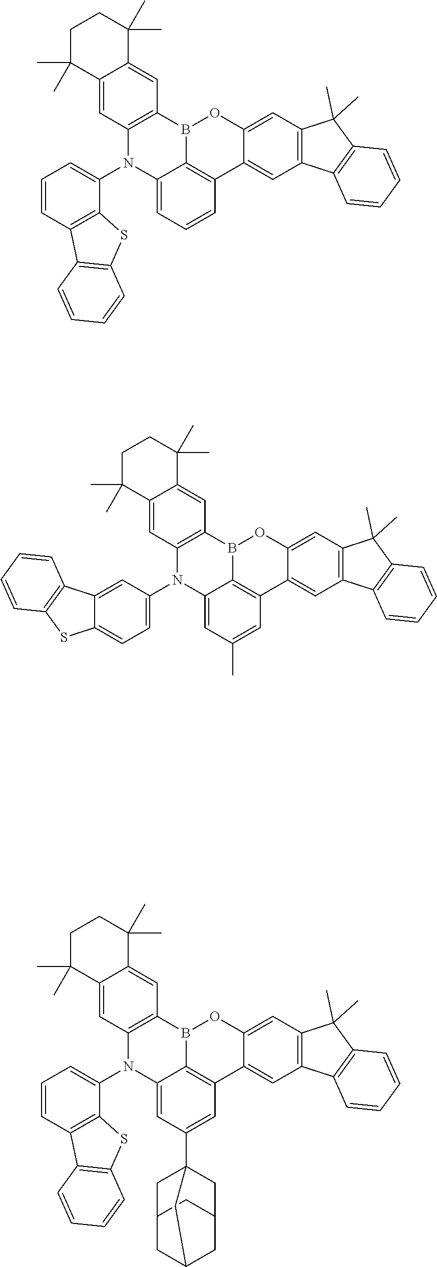 [SMILES: CC1(C)CCC(C)(C)c2cc3c(cc21)B1Oc2cc4c(cc2-c2cccc(c21)N3c1cccc2c1sc1ccccc12)-c1ccccc1C4(C)C ; Cc1cc2c3c(c1)N(c1ccc4sc5ccccc5c4c1)c1cc4c(cc1B3Oc1cc3c(cc1-2)-c1ccccc1C3(C)C)C(C)(C)CCC4(C)C ; CC1(C)CCC(C)(C)c2cc3c(cc21)B1Oc2cc4c(cc2-c2cc(C56CC7CC(CC(C7)C5)C6)cc(c21)N3c1cccc2c1sc1ccccc12)-c1ccccc1C4(C)C]

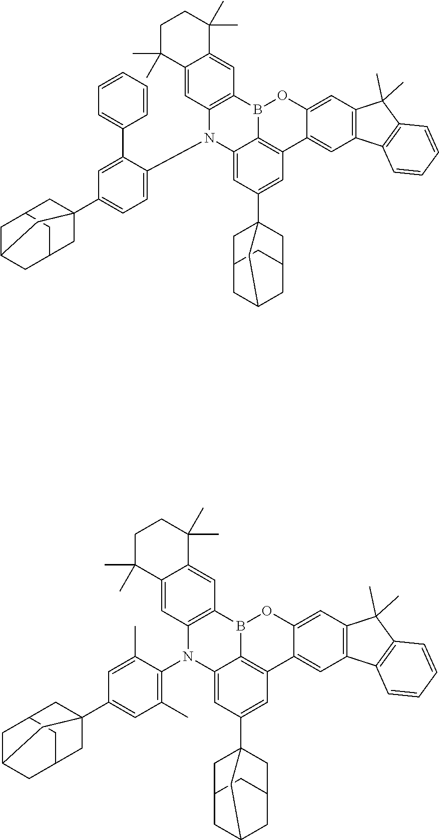 [SMILES: CC1(C)CCC(C)(C)c2cc3c(cc21)B1Oc2cc4c(cc2-c2cc(C56CC7CC(CC(C7)C5)C6)cc(c21)N3c1ccc(C23CC5CC(CC(C5)C2)C3)cc1-c1ccccc1)-c1ccccc1C4(C)C ; Cc1cc(C23CC4CC(CC(C4)C2)C3)cc(C)c1N1c2cc3c(cc2B2Oc4cc5c(cc4-c4cc(C67CC8CC(CC(C8)C6)C7)cc1c42)-c1ccccc1C5(C)C)C(C)(C)CCC3(C)C]

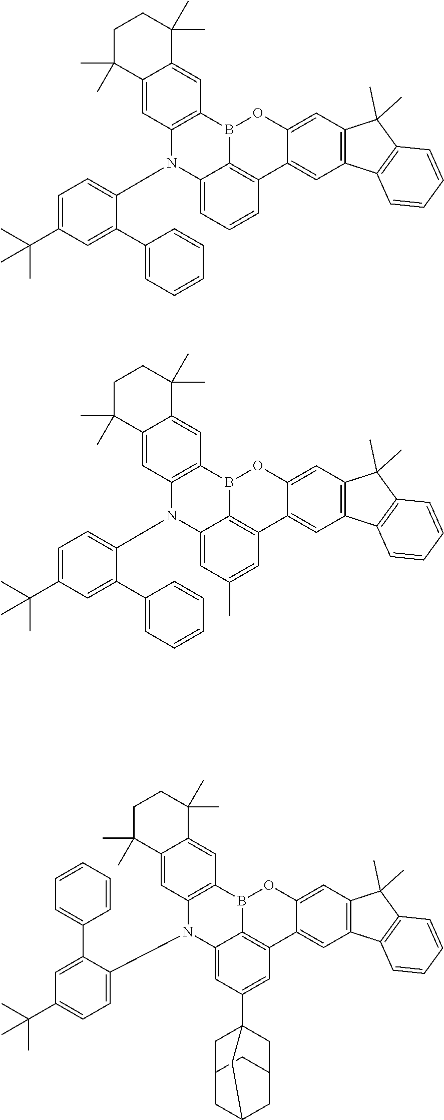 [SMILES: CC(C)(C)c1ccc(N2c3cc4c(cc3B3Oc5cc6c(cc5-c5cccc2c53)-c2ccccc2C6(C)C)C(C)(C)CCC4(C)C)c(-c2ccccc2)c1 ; Cc1cc2c3c(c1)N(c1ccc(C(C)(C)C)cc1-c1ccccc1)c1cc4c(cc1B3Oc1cc3c(cc1-2)-c1ccccc1C3(C)C)C(C)(C)CCC4(C)C ; CC(C)(C)c1ccc(N2c3cc4c(cc3B3Oc5cc6c(cc5-c5cc(C78CC9CC(CC(C9)C7)C8)cc2c53)-c2ccccc2C6(C)C)C(C)(C)CCC4(C)C)c(-c2ccccc2)c1]

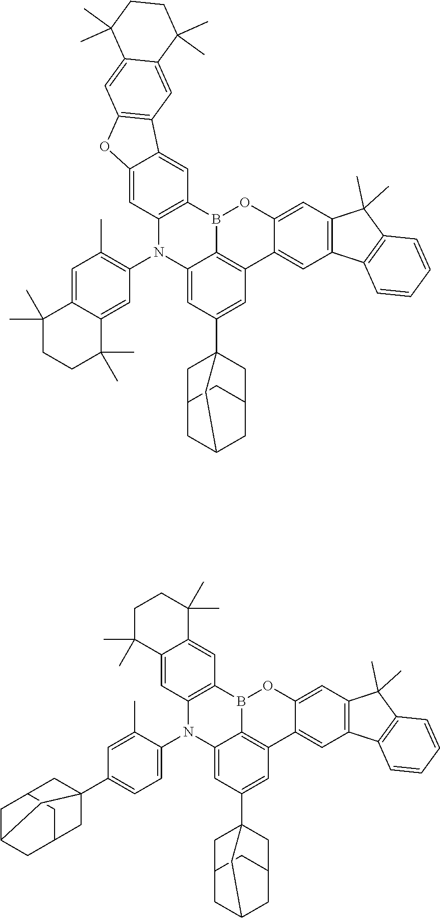 [SMILES: Cc1cc2c(cc1N1c3cc4oc5cc6c(cc5c4cc3B3Oc4cc5c(cc4-c4cc(C78CC9CC(CC(C9)C7)C8)cc1c43)-c1ccccc1C5(C)C)C(C)(C)CCC6(C)C)C(C)(C)CCC2(C)C ; Cc1cc(C23CC4CC(CC(C4)C2)C3)ccc1N1c2cc3c(cc2B2Oc4cc5c(cc4-c4cc(C67CC8CC(CC(C8)C6)C7)cc1c42)-c1ccccc1C5(C)C)C(C)(C)CCC3(C)C]

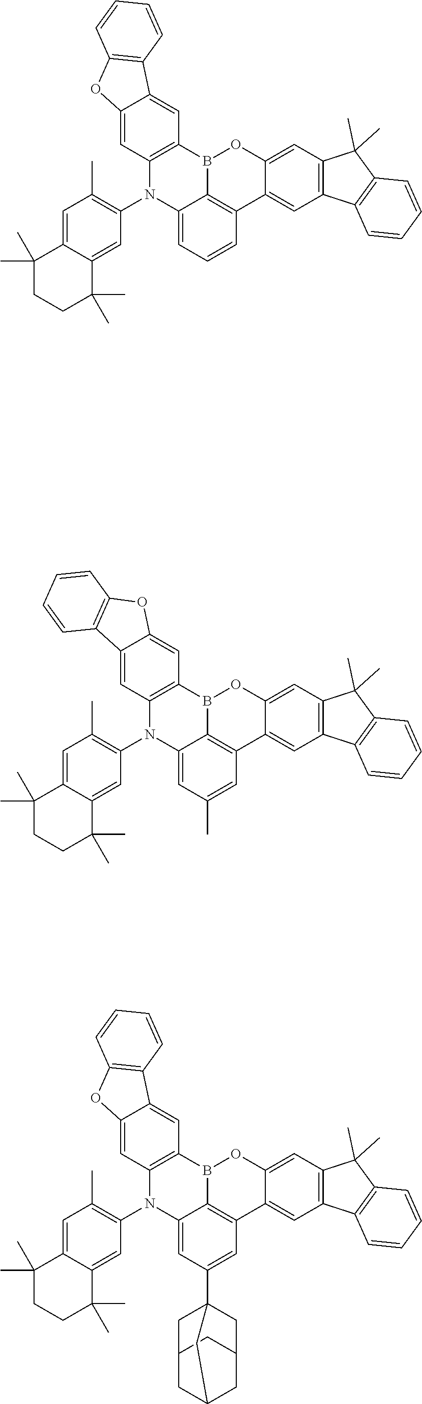 [SMILES: Cc1cc2c(cc1N1c3cc4oc5ccccc5c4cc3B3Oc4cc5c(cc4-c4cccc1c43)-c1ccccc1C5(C)C)C(C)(C)CCC2(C)C ; Cc1cc2c3c(c1)N(c1cc4c(cc1C)C(C)(C)CCC4(C)C)c1cc4c(cc1B3Oc1cc3c(cc1-2)-c1ccccc1C3(C)C)oc1ccccc14 ; Cc1cc2c(cc1N1c3cc4oc5ccccc5c4cc3B3Oc4cc5c(cc4-c4cc(C67CC8CC(CC(C8)C6)C7)cc1c43)-c1ccccc1C5(C)C)C(C)(C)CCC2(C)C]

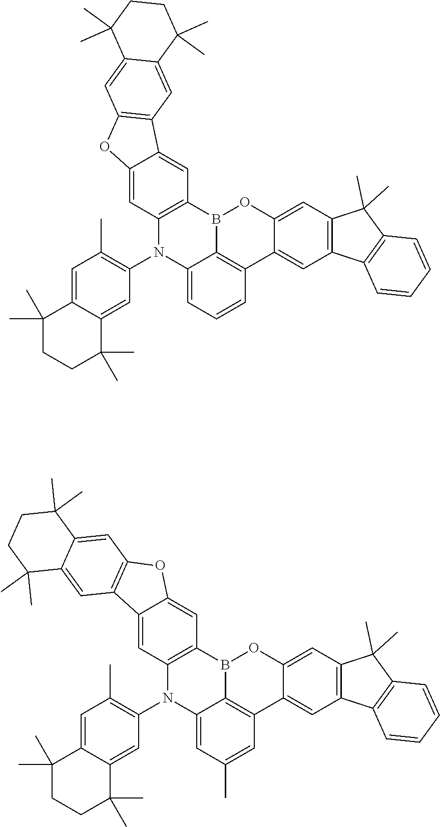 [SMILES: Cc1cc2c(cc1N1c3cc4oc5cc6c(cc5c4cc3B3Oc4cc5c(cc4-c4cccc1c43)-c1ccccc1C5(C)C)C(C)(C)CCC6(C)C)C(C)(C)CCC2(C)C ; Cc1cc2c3c(c1)N(c1cc4c(cc1C)C(C)(C)CCC4(C)C)c1cc4c(cc1B3Oc1cc3c(cc1-2)-c1ccccc1C3(C)C)oc1cc2c(cc14)C(C)(C)CCC2(C)C]

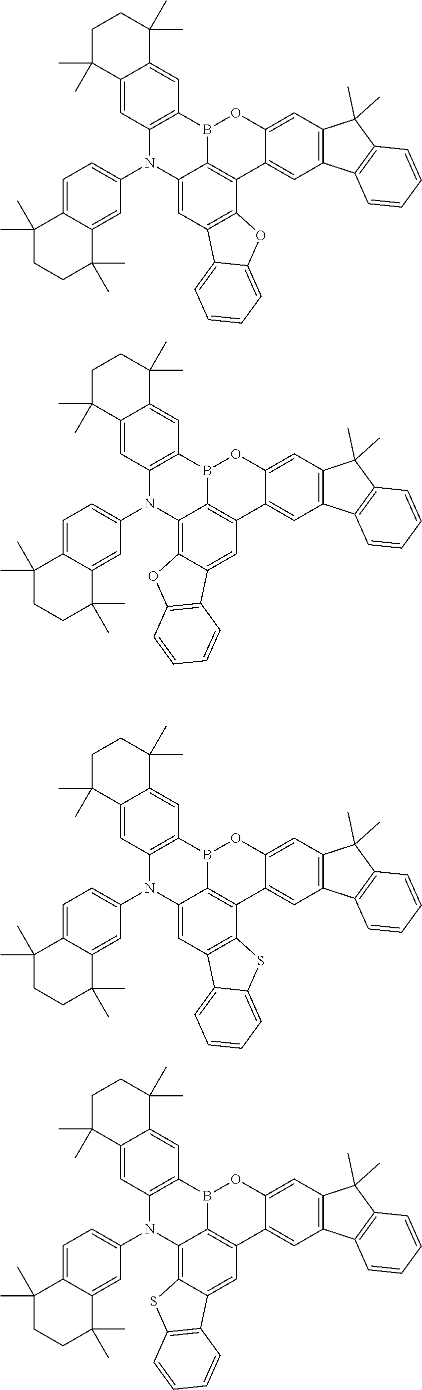 [SMILES: CC1(C)CCC(C)(C)c2cc(N3c4cc5c(cc4B4Oc6cc7c(cc6-c6c4c3cc3c6oc4ccccc43)-c3ccccc3C7(C)C)C(C)(C)CCC5(C)C)ccc21 ; CC1(C)CCC(C)(C)c2cc(N3c4cc5c(cc4B4Oc6cc7c(cc6-c6cc8c(oc9ccccc98)c3c64)-c3ccccc3C7(C)C)C(C)(C)CCC5(C)C)ccc21 ; CC1(C)CCC(C)(C)c2cc(N3c4cc5c(cc4B4Oc6cc7c(cc6-c6c4c3cc3c6sc4ccccc43)-c3ccccc3C7(C)C)C(C)(C)CCC5(C)C)ccc21 ; CC1(C)CCC(C)(C)c2cc(N3c4cc5c(cc4B4Oc6cc7c(cc6-c6cc8c(sc9ccccc98)c3c64)-c3ccccc3C7(C)C)C(C)(C)CCC5(C)C)ccc21]

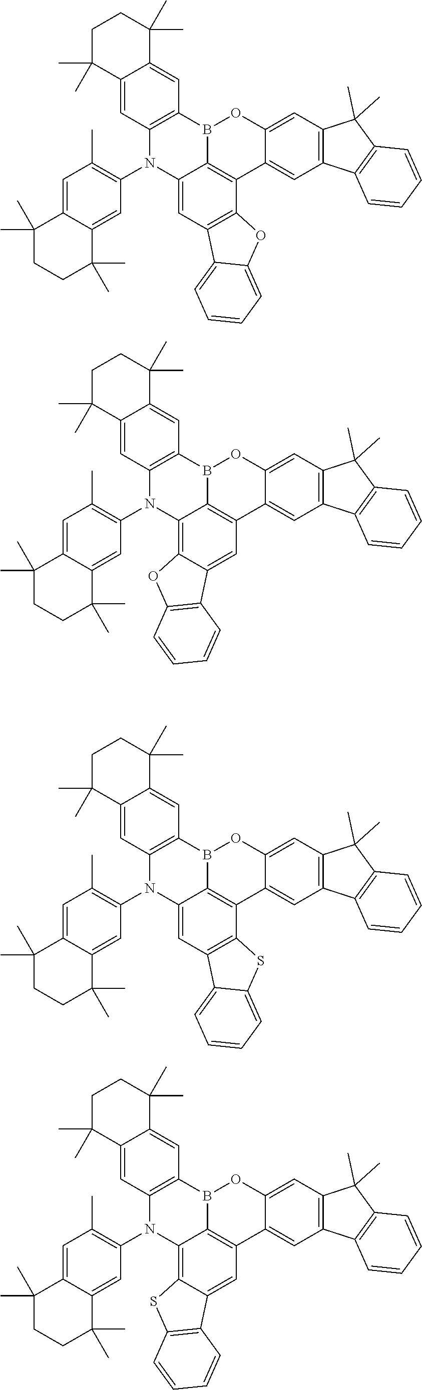 [SMILES: Cc1cc2c(cc1N1c3cc4c(cc3B3Oc5cc6c(cc5-c5c3c1cc1c5oc3ccccc31)-c1ccccc1C6(C)C)C(C)(C)CCC4(C)C)C(C)(C)CCC2(C)C ; Cc1cc2c(cc1N1c3cc4c(cc3B3Oc5cc6c(cc5-c5cc7c(oc8ccccc87)c1c53)-c1ccccc1C6(C)C)C(C)(C)CCC4(C)C)C(C)(C)CCC2(C)C ; Cc1cc2c(cc1N1c3cc4c(cc3B3Oc5cc6c(cc5-c5c3c1cc1c5sc3ccccc31)-c1ccccc1C6(C)C)C(C)(C)CCC4(C)C)C(C)(C)CCC2(C)C ; Cc1cc2c(cc1N1c3cc4c(cc3B3Oc5cc6c(cc5-c5cc7c(sc8ccccc87)c1c53)-c1ccccc1C6(C)C)C(C)(C)CCC4(C)C)C(C)(C)CCC2(C)C]

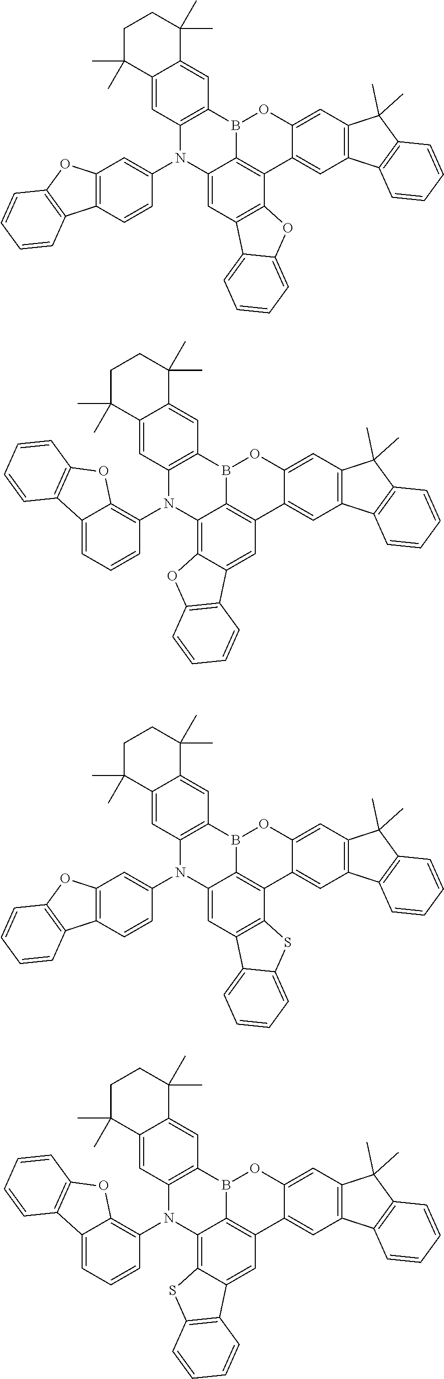 [SMILES: CC1(C)CCC(C)(C)c2cc3c(cc21)B1Oc2cc4c(cc2-c2c1c(cc1c2oc2ccccc21)N3c1ccc2c(c1)oc1ccccc12)-c1ccccc1C4(C)C ; CC1(C)CCC(C)(C)c2cc3c(cc21)B1Oc2cc4c(cc2-c2cc5c(oc6ccccc65)c(c21)N3c1cccc2c1oc1ccccc12)-c1ccccc1C4(C)C ; CC1(C)CCC(C)(C)c2cc3c(cc21)B1Oc2cc4c(cc2-c2c1c(cc1c2sc2ccccc21)N3c1ccc2c(c1)oc1ccccc12)-c1ccccc1C4(C)C ; CC1(C)CCC(C)(C)c2cc3c(cc21)B1Oc2cc4c(cc2-c2cc5c(sc6ccccc65)c(c21)N3c1cccc2c1oc1ccccc12)-c1ccccc1C4(C)C]

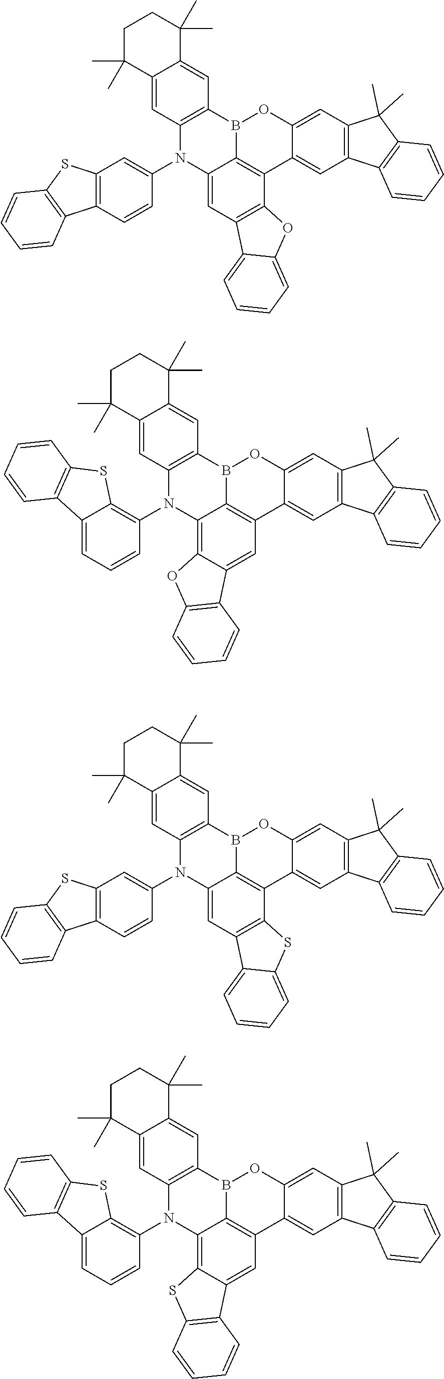 [SMILES: CC1(C)CCC(C)(C)c2cc3c(cc21)B1Oc2cc4c(cc2-c2c1c(cc1c2oc2ccccc21)N3c1ccc2c(c1)sc1ccccc12)-c1ccccc1C4(C)C ; CC1(C)CCC(C)(C)c2cc3c(cc21)B1Oc2cc4c(cc2-c2cc5c(oc6ccccc65)c(c21)N3c1cccc2c1sc1ccccc12)-c1ccccc1C4(C)C ; CC1(C)CCC(C)(C)c2cc3c(cc21)B1Oc2cc4c(cc2-c2c1c(cc1c2sc2ccccc21)N3c1ccc2c(c1)sc1ccccc12)-c1ccccc1C4(C)C ; CC1(C)CCC(C)(C)c2cc3c(cc21)B1Oc2cc4c(cc2-c2cc5c(sc6ccccc65)c(c21)N3c1cccc2c1sc1ccccc12)-c1ccccc1C4(C)C]

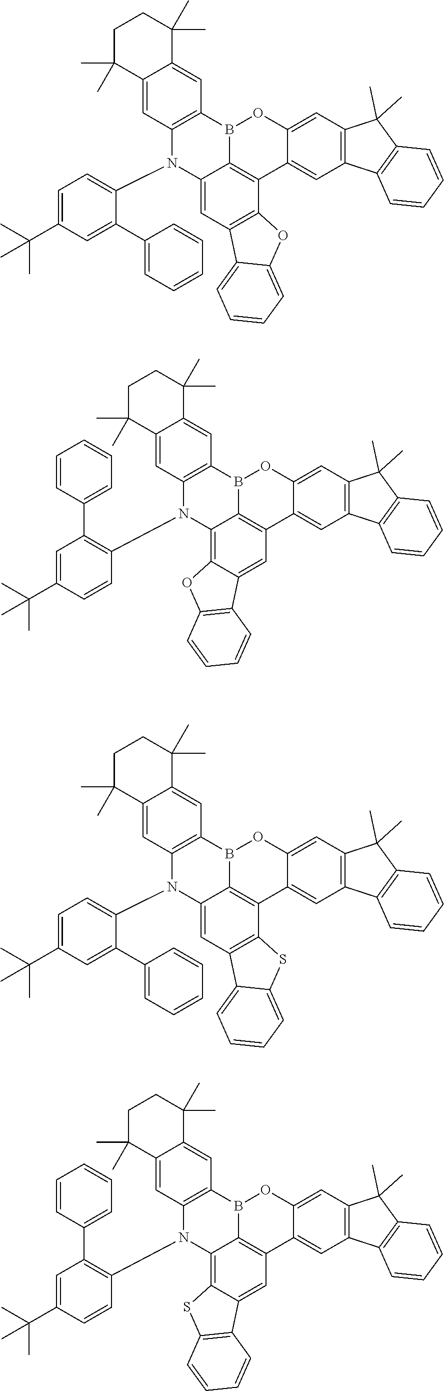 [SMILES: CC(C)(C)c1ccc(N2c3cc4c(cc3B3Oc5cc6c(cc5-c5c3c2cc2c5oc3ccccc32)-c2ccccc2C6(C)C)C(C)(C)CCC4(C)C)c(-c2ccccc2)c1 ; CC(C)(C)c1ccc(N2c3cc4c(cc3B3Oc5cc6c(cc5-c5cc7c(oc8ccccc87)c2c53)-c2ccccc2C6(C)C)C(C)(C)CCC4(C)C)c(-c2ccccc2)c1 ; CC(C)(C)c1ccc(N2c3cc4c(cc3B3Oc5cc6c(cc5-c5c3c2cc2c5sc3ccccc32)-c2ccccc2C6(C)C)C(C)(C)CCC4(C)C)c(-c2ccccc2)c1 ; CC(C)(C)c1ccc(N2c3cc4c(cc3B3Oc5cc6c(cc5-c5cc7c(sc8ccccc87)c2c53)-c2ccccc2C6(C)C)C(C)(C)CCC4(C)C)c(-c2ccccc2)c1]

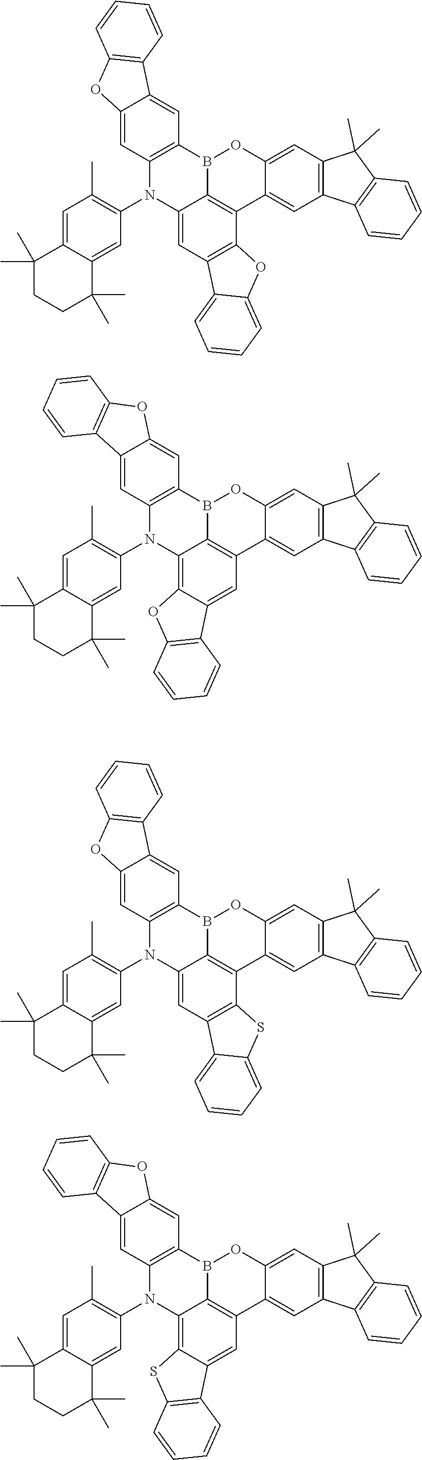 [SMILES: Cc1cc2c(cc1N1c3cc4oc5ccccc5c4cc3B3Oc4cc5c(cc4-c4c3c1cc1c4oc3ccccc31)-c1ccccc1C5(C)C)C(C)(C)CCC2(C)C ; Cc1cc2c(cc1N1c3cc4c(cc3B3Oc5cc6c(cc5-c5cc7c(oc8ccccc87)c1c53)-c1ccccc1C6(C)C)oc1ccccc14)C(C)(C)CCC2(C)C ; Cc1cc2c(cc1N1c3cc4oc5ccccc5c4cc3B3Oc4cc5c(cc4-c4c3c1cc1c4sc3ccccc31)-c1ccccc1C5(C)C)C(C)(C)CCC2(C)C ; Cc1cc2c(cc1N1c3cc4c(cc3B3Oc5cc6c(cc5-c5cc7c(sc8ccccc87)c1c53)-c1ccccc1C6(C)C)oc1ccccc14)C(C)(C)CCC2(C)C]

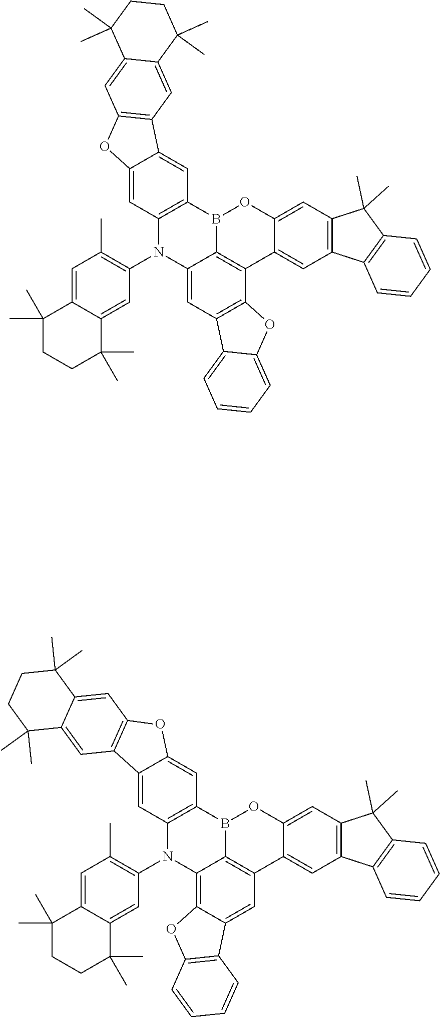 [SMILES: Cc1cc2c(cc1N1c3cc4oc5cc6c(cc5c4cc3B3Oc4cc5c(cc4-c4c3c1cc1c4oc3ccccc31)-c1ccccc1C5(C)C)C(C)(C)CCC6(C)C)C(C)(C)CCC2(C)C ; Cc1cc2c(cc1N1c3cc4c(cc3B3Oc5cc6c(cc5-c5cc7c(oc8ccccc87)c1c53)-c1ccccc1C6(C)C)oc1cc3c(cc14)C(C)(C)CCC3(C)C)C(C)(C)CCC2(C)C]

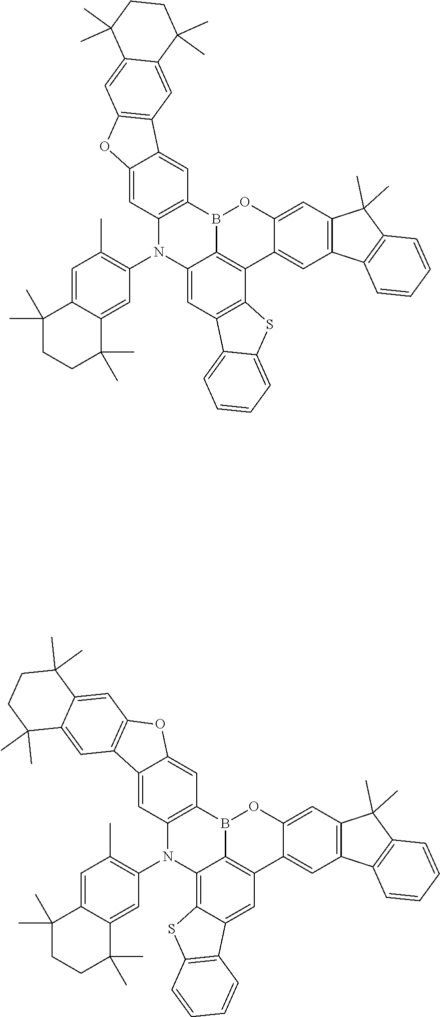 [SMILES: Cc1cc2c(cc1N1c3cc4oc5cc6c(cc5c4cc3B3Oc4cc5c(cc4-c4c3c1cc1c4sc3ccccc31)-c1ccccc1C5(C)C)C(C)(C)CCC6(C)C)C(C)(C)CCC2(C)C ; Cc1cc2c(cc1N1c3cc4c(cc3B3Oc5cc6c(cc5-c5cc7c(sc8ccccc87)c1c53)-c1ccccc1C6(C)C)oc1cc3c(cc14)C(C)(C)CCC3(C)C)C(C)(C)CCC2(C)C]

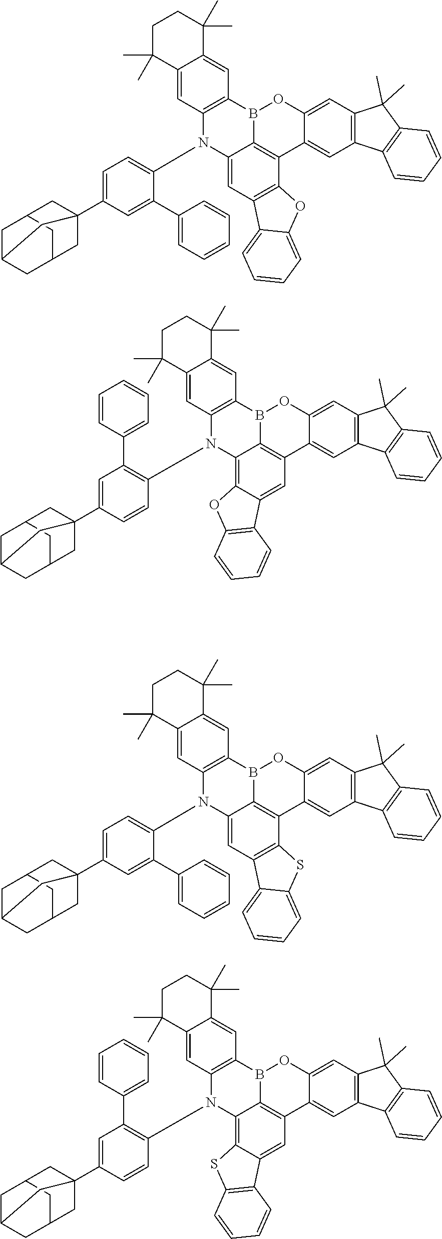

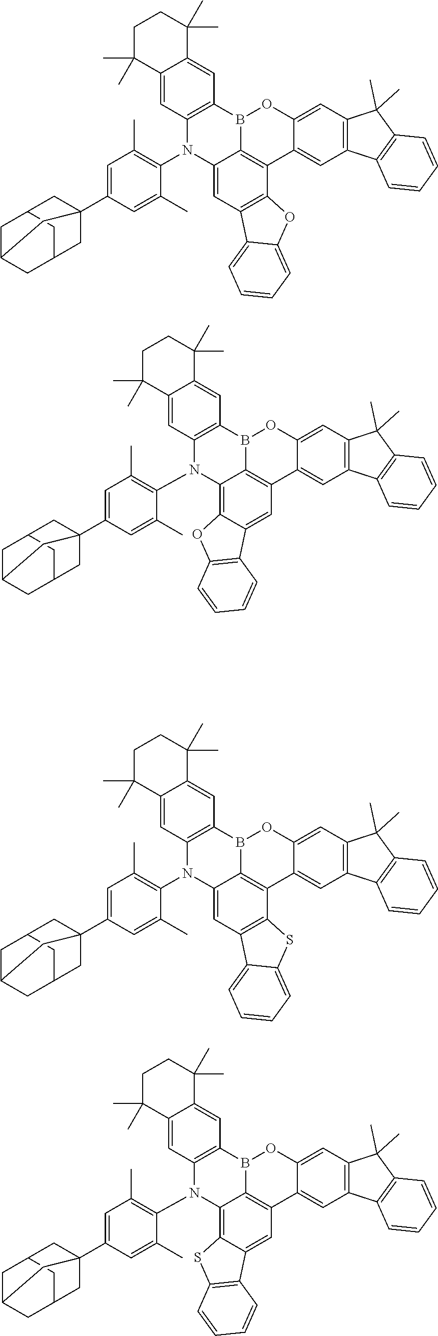 [SMILES: Cc1cc(C23CC4CC(CC(C4)C2)C3)cc(C)c1N1c2cc3c(cc2B2Oc4cc5c(cc4-c4c2c1cc1c4oc2ccccc21)-c1ccccc1C5(C)C)C(C)(C)CCC3(C)C ; Cc1cc(C23CC4CC(CC(C4)C2)C3)cc(C)c1N1c2cc3c(cc2B2Oc4cc5c(cc4-c4cc6c(oc7ccccc76)c1c42)-c1ccccc1C5(C)C)C(C)(C)CCC3(C)C ; Cc1cc(C23CC4CC(CC(C4)C2)C3)cc(C)c1N1c2cc3c(cc2B2Oc4cc5c(cc4-c4c2c1cc1c4sc2ccccc21)-c1ccccc1C5(C)C)C(C)(C)CCC3(C)C ; Cc1cc(C23CC4CC(CC(C4)C2)C3)cc(C)c1N1c2cc3c(cc2B2Oc4cc5c(cc4-c4cc6c(sc7ccccc76)c1c42)-c1ccccc1C5(C)C)C(C)(C)CCC3(C)C]

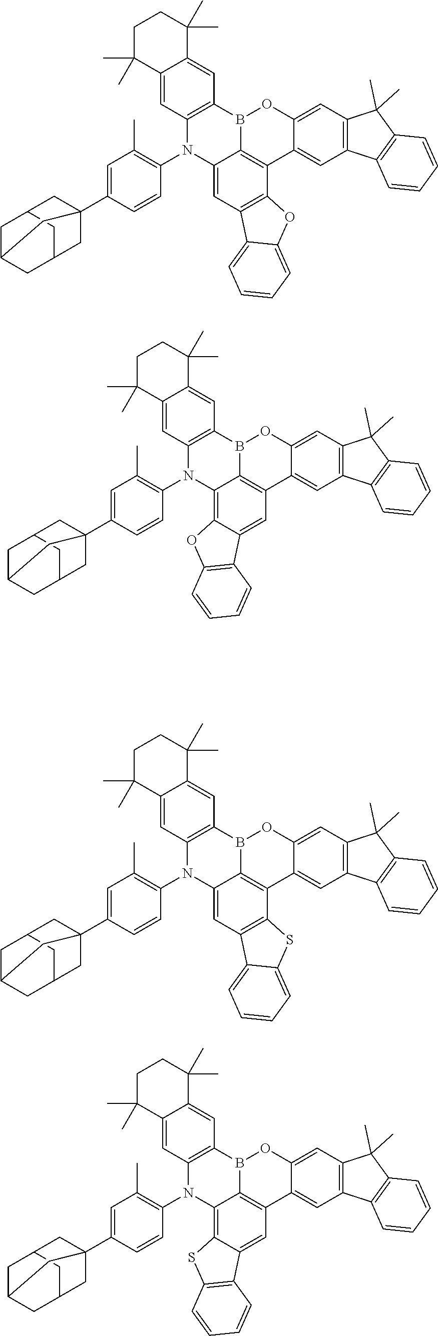 [SMILES: Cc1cc(C23CC4CC(CC(C4)C2)C3)ccc1N1c2cc3c(cc2B2Oc4cc5c(cc4-c4c2c1cc1c4oc2ccccc21)-c1ccccc1C5(C)C)C(C)(C)CCC3(C)C ; Cc1cc(C23CC4CC(CC(C4)C2)C3)ccc1N1c2cc3c(cc2B2Oc4cc5c(cc4-c4cc6c(oc7ccccc76)c1c42)-c1ccccc1C5(C)C)C(C)(C)CCC3(C)C ; Cc1cc(C23CC4CC(CC(C4)C2)C3)ccc1N1c2cc3c(cc2B2Oc4cc5c(cc4-c4c2c1cc1c4sc2ccccc21)-c1ccccc1C5(C)C)C(C)(C)CCC3(C)C ; Cc1cc(C23CC4CC(CC(C4)C2)C3)ccc1N1c2cc3c(cc2B2Oc4cc5c(cc4-c4cc6c(sc7ccccc76)c1c42)-c1ccccc1C5(C)C)C(C)(C)CCC3(C)C]

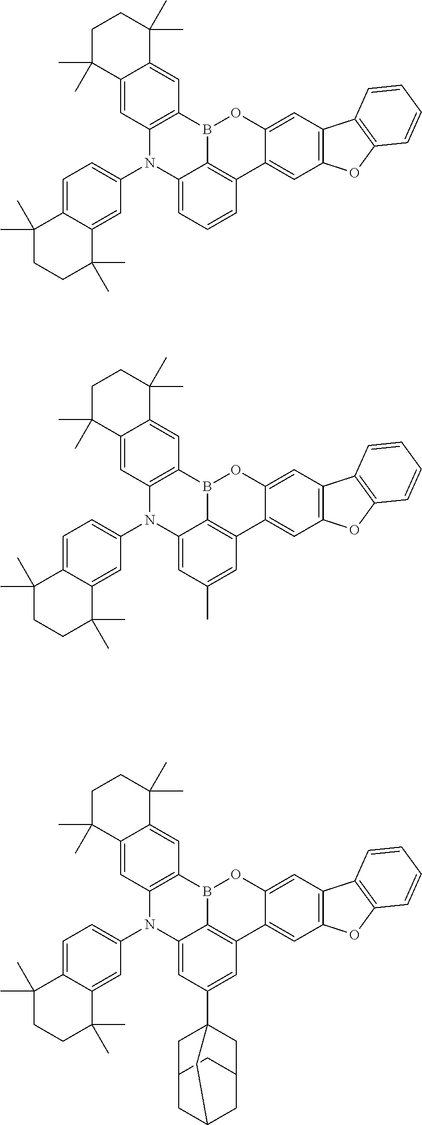 [SMILES: CC1(C)CCC(C)(C)c2cc(N3c4cc5c(cc4B4Oc6cc7c(cc6-c6cccc3c64)oc3ccccc37)C(C)(C)CCC5(C)C)ccc21 ; Cc1cc2c3c(c1)N(c1ccc4c(c1)C(C)(C)CCC4(C)C)c1cc4c(cc1B3Oc1cc3c(cc1-2)oc1ccccc13)C(C)(C)CCC4(C)C ; CC1(C)CCC(C)(C)c2cc(N3c4cc5c(cc4B4Oc6cc7c(cc6-c6cc(C89CC%10CC(CC(C%10)C8)C9)cc3c64)oc3ccccc37)C(C)(C)CCC5(C)C)ccc21]

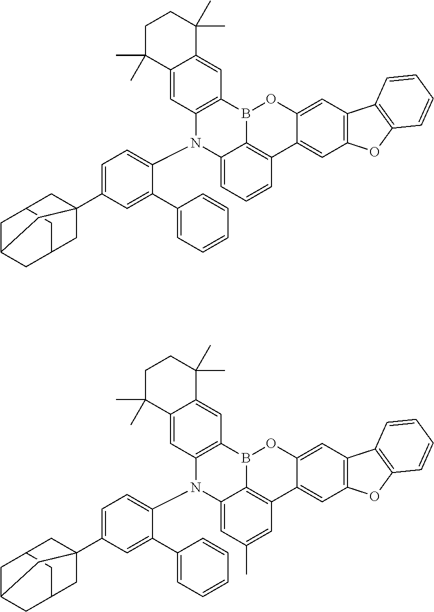 [SMILES: CC1(C)CCC(C)(C)c2cc3c(cc21)B1Oc2cc4c(cc2-c2cccc(c21)N3c1ccc(C23CC5CC(CC(C5)C2)C3)cc1-c1ccccc1)oc1ccccc14 ; Cc1cc2c3c(c1)N(c1ccc(C45CC6CC(CC(C6)C4)C5)cc1-c1ccccc1)c1cc4c(cc1B3Oc1cc3c(cc1-2)oc1ccccc13)C(C)(C)CCC4(C)C]

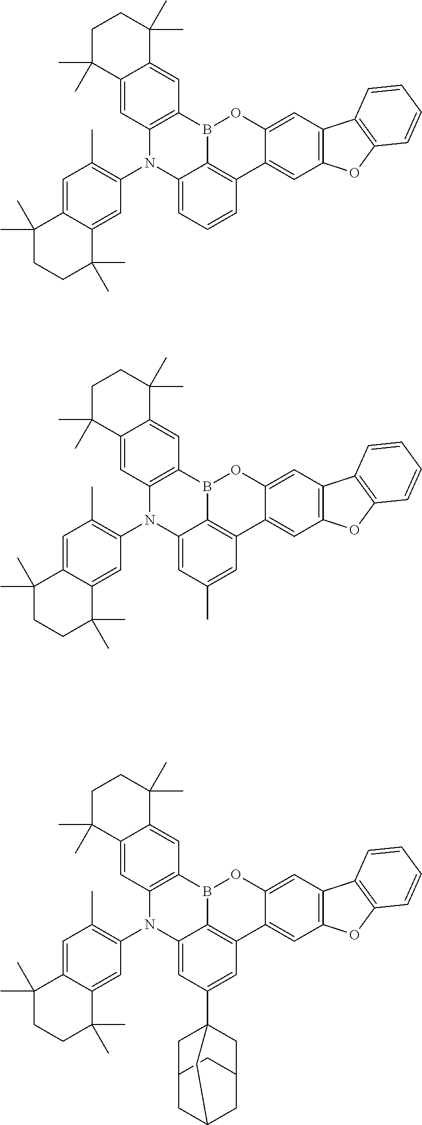 [SMILES: Cc1cc2c(cc1N1c3cc4c(cc3B3Oc5cc6c(cc5-c5cccc1c53)oc1ccccc16)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Oc1cc3c(cc1-2)oc1ccccc13)C(C)(C)CCC4(C)C ; Cc1cc2c(cc1N1c3cc4c(cc3B3Oc5cc6c(cc5-c5cc(C78CC9CC(CC(C9)C7)C8)cc1c53)oc1ccccc16)C(C)(C)CCC4(C)C)C(C)(C)CCC2(C)C]

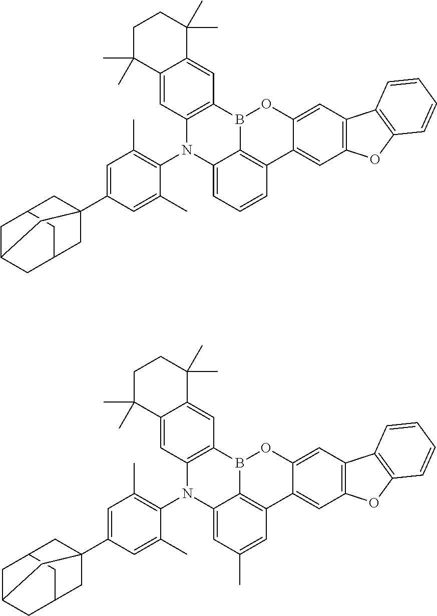 [SMILES: Cc1cc(C23CC4CC(CC(C4)C2)C3)cc(C)c1N1c2cc3c(cc2B2Oc4cc5c(cc4-c4cccc1c42)oc1ccccc15)C(C)(C)CCC3(C)C ; Cc1cc2c3c(c1)N(c1c(C)cc(C45CC6CC(CC(C6)C4)C5)cc1C)c1cc4c(cc1B3Oc1cc3c(cc1-2)oc1ccccc13)C(C)(C)CCC4(C)C]

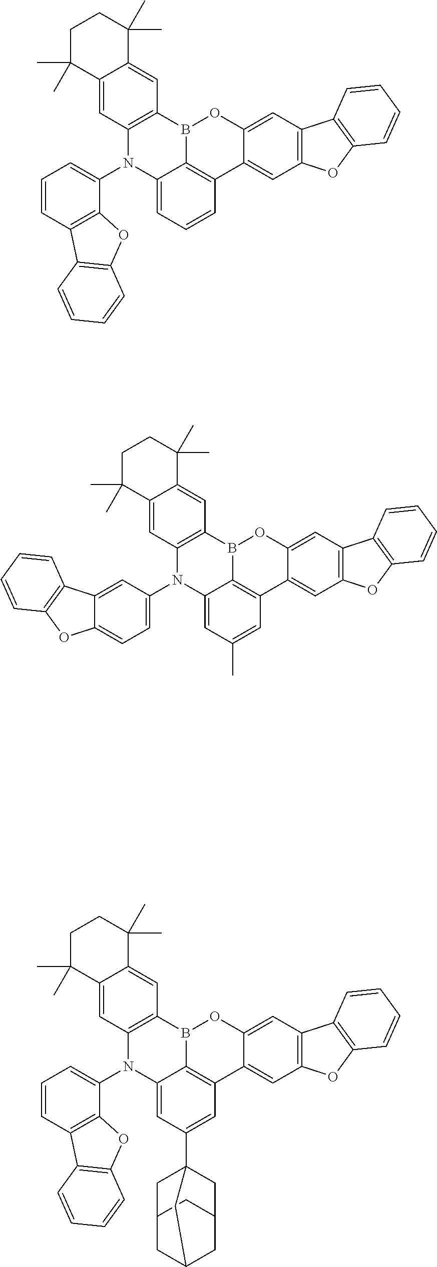 [SMILES: CC1(C)CCC(C)(C)c2cc3c(cc21)B1Oc2cc4c(cc2-c2cccc(c21)N3c1cccc2c1oc1ccccc12)oc1ccccc14 ; Cc1cc2c3c(c1)N(c1ccc4oc5ccccc5c4c1)c1cc4c(cc1B3Oc1cc3c(cc1-2)oc1ccccc13)C(C)(C)CCC4(C)C ; CC1(C)CCC(C)(C)c2cc3c(cc21)B1Oc2cc4c(cc2-c2cc(C56CC7CC(CC(C7)C5)C6)cc(c21)N3c1cccc2c1oc1ccccc12)oc1ccccc14]

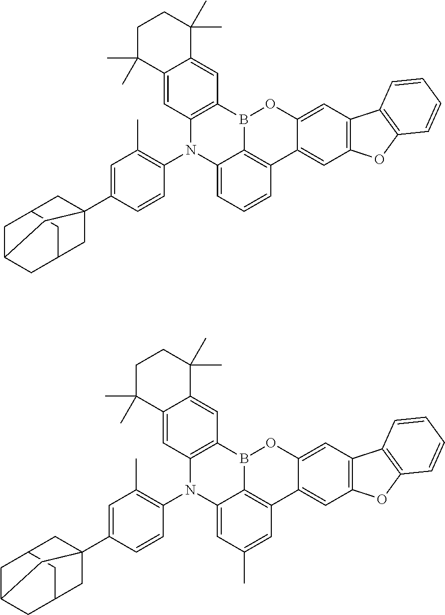 [SMILES: Cc1cc(C23CC4CC(CC(C4)C2)C3)ccc1N1c2cc3c(cc2B2Oc4cc5c(cc4-c4cccc1c42)oc1ccccc15)C(C)(C)CCC3(C)C ; Cc1cc2c3c(c1)N(c1ccc(C45CC6CC(CC(C6)C4)C5)cc1C)c1cc4c(cc1B3Oc1cc3c(cc1-2)oc1ccccc13)C(C)(C)CCC4(C)C]

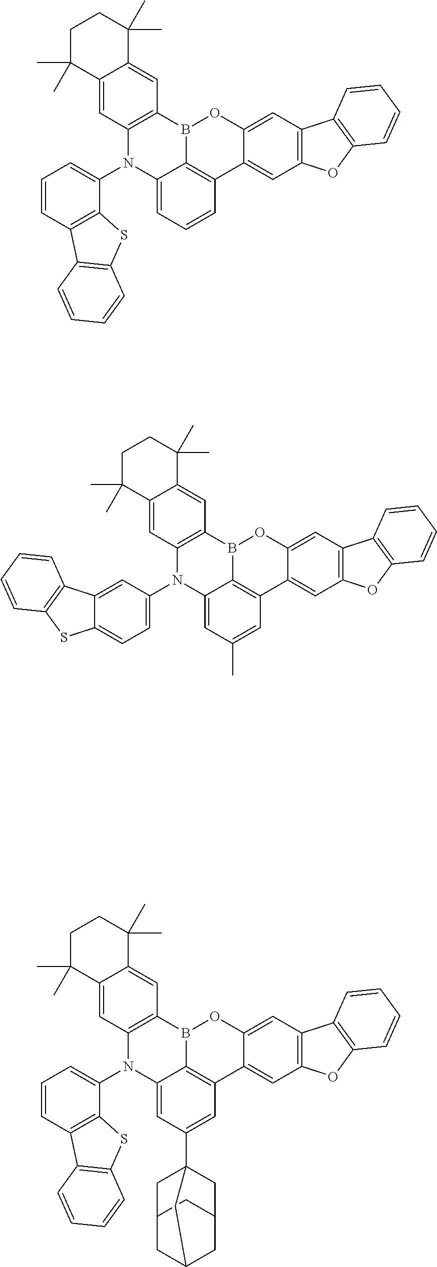 [SMILES: CC1(C)CCC(C)(C)c2cc3c(cc21)B1Oc2cc4c(cc2-c2cccc(c21)N3c1cccc2c1sc1ccccc12)oc1ccccc14 ; Cc1cc2c3c(c1)N(c1ccc4sc5ccccc5c4c1)c1cc4c(cc1B3Oc1cc3c(cc1-2)oc1ccccc13)C(C)(C)CCC4(C)C ; CC1(C)CCC(C)(C)c2cc3c(cc21)B1Oc2cc4c(cc2-c2cc(C56CC7CC(CC(C7)C5)C6)cc(c21)N3c1cccc2c1sc1ccccc12)oc1ccccc14]

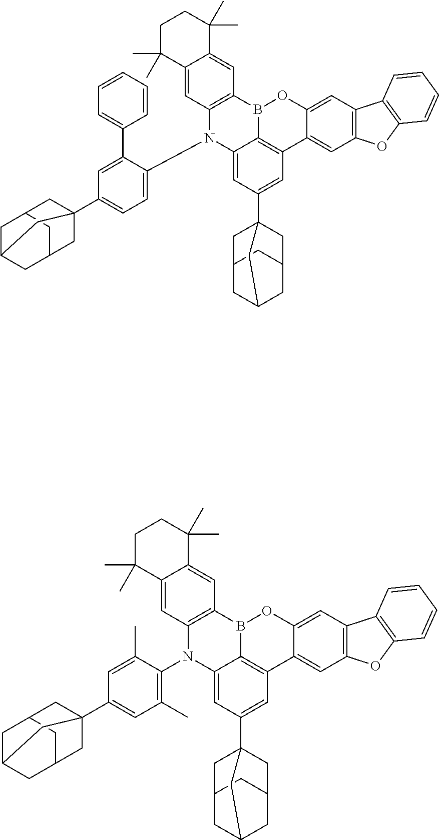 [SMILES: CC1(C)CCC(C)(C)c2cc3c(cc21)B1Oc2cc4c(cc2-c2cc(C56CC7CC(CC(C7)C5)C6)cc(c21)N3c1ccc(C23CC5CC(CC(C5)C2)C3)cc1-c1ccccc1)oc1ccccc14 ; Cc1cc(C23CC4CC(CC(C4)C2)C3)cc(C)c1N1c2cc3c(cc2B2Oc4cc5c(cc4-c4cc(C67CC8CC(CC(C8)C6)C7)cc1c42)oc1ccccc15)C(C)(C)CCC3(C)C]

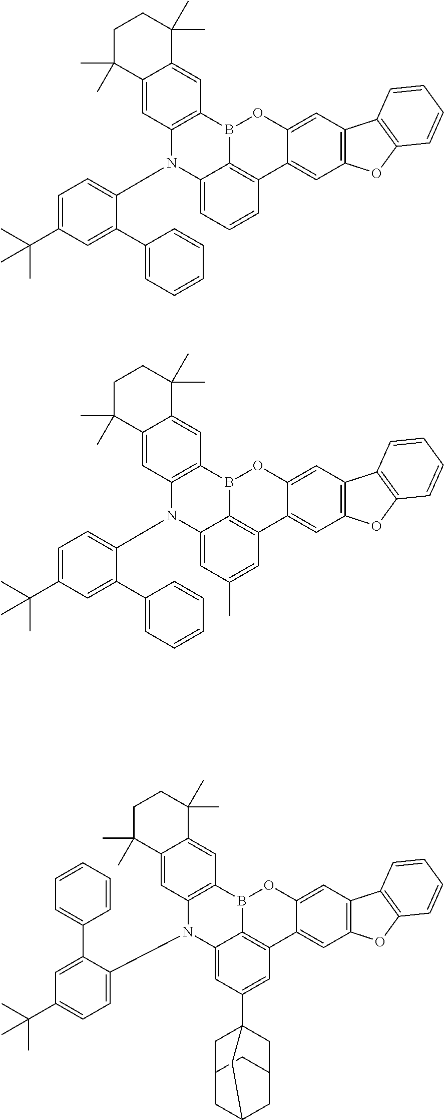 [SMILES: CC(C)(C)c1ccc(N2c3cc4c(cc3B3Oc5cc6c(cc5-c5cccc2c53)oc2ccccc26)C(C)(C)CCC4(C)C)c(-c2ccccc2)c1 ; Cc1cc2c3c(c1)N(c1ccc(C(C)(C)C)cc1-c1ccccc1)c1cc4c(cc1B3Oc1cc3c(cc1-2)oc1ccccc13)C(C)(C)CCC4(C)C ; CC(C)(C)c1ccc(N2c3cc4c(cc3B3Oc5cc6c(cc5-c5cc(C78CC9CC(CC(C9)C7)C8)cc2c53)oc2ccccc26)C(C)(C)CCC4(C)C)c(-c2ccccc2)c1]

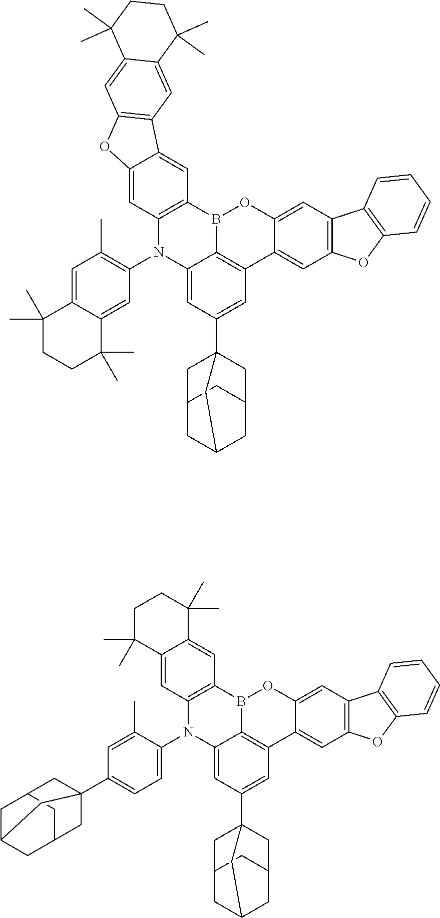 [SMILES: Cc1cc2c(cc1N1c3cc4oc5cc6c(cc5c4cc3B3Oc4cc5c(cc4-c4cc(C78CC9CC(CC(C9)C7)C8)cc1c43)oc1ccccc15)C(C)(C)CCC6(C)C)C(C)(C)CCC2(C)C ; Cc1cc(C23CC4CC(CC(C4)C2)C3)ccc1N1c2cc3c(cc2B2Oc4cc5c(cc4-c4cc(C67CC8CC(CC(C8)C6)C7)cc1c42)oc1ccccc15)C(C)(C)CCC3(C)C]

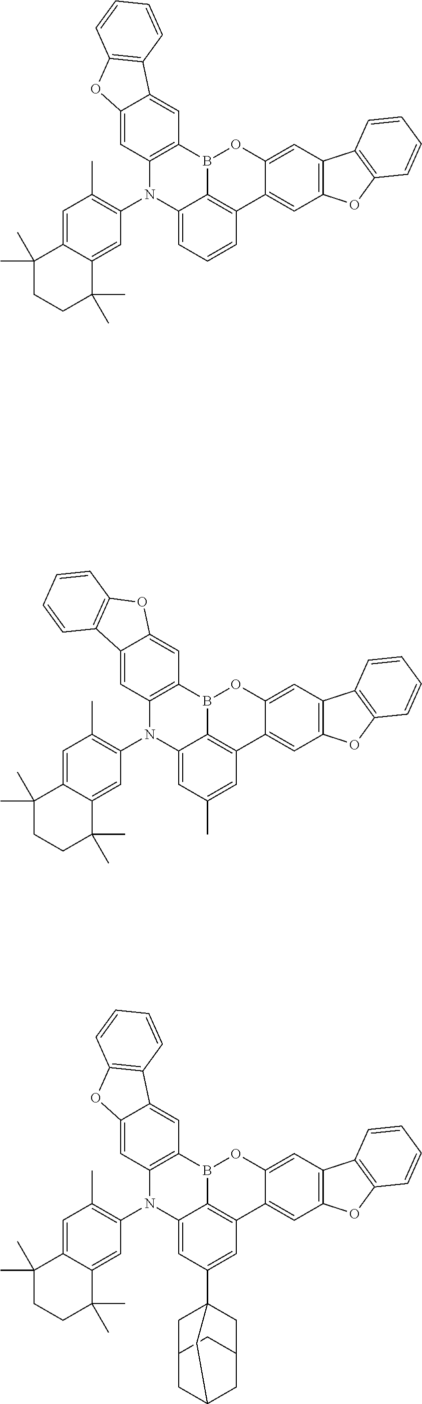 [SMILES: Cc1cc2c(cc1N1c3cc4oc5ccccc5c4cc3B3Oc4cc5c(cc4-c4cccc1c43)oc1ccccc15)C(C)(C)CCC2(C)C ; Cc1cc2c3c(c1)N(c1cc4c(cc1C)C(C)(C)CCC4(C)C)c1cc4c(cc1B3Oc1cc3c(cc1-2)oc1ccccc13)oc1ccccc14 ; Cc1cc2c(cc1N1c3cc4oc5ccccc5c4cc3B3Oc4cc5c(cc4-c4cc(C67CC8CC(CC(C8)C6)C7)cc1c43)oc1ccccc15)C(C)(C)CCC2(C)C]

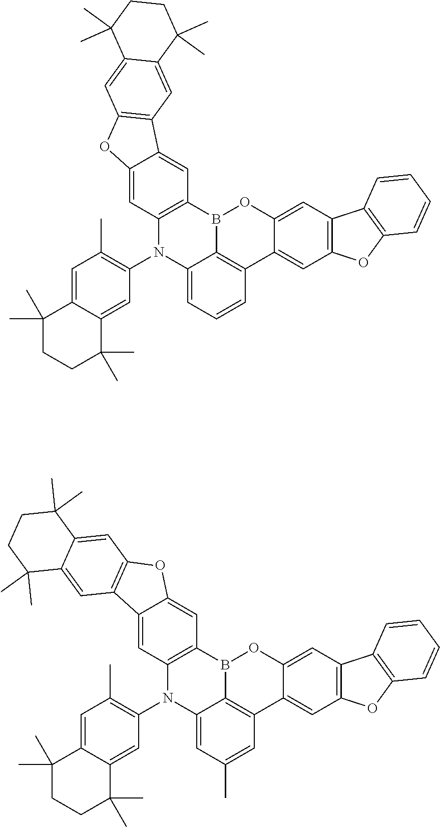 [SMILES: Cc1cc2c(cc1N1c3cc4oc5cc6c(cc5c4cc3B3Oc4cc5c(cc4-c4cccc1c43)oc1ccccc15)C(C)(C)CCC6(C)C)C(C)(C)CCC2(C)C ; Cc1cc2c3c(c1)N(c1cc4c(cc1C)C(C)(C)CCC4(C)C)c1cc4c(cc1B3Oc1cc3c(cc1-2)oc1ccccc13)oc1cc2c(cc14)C(C)(C)CCC2(C)C]

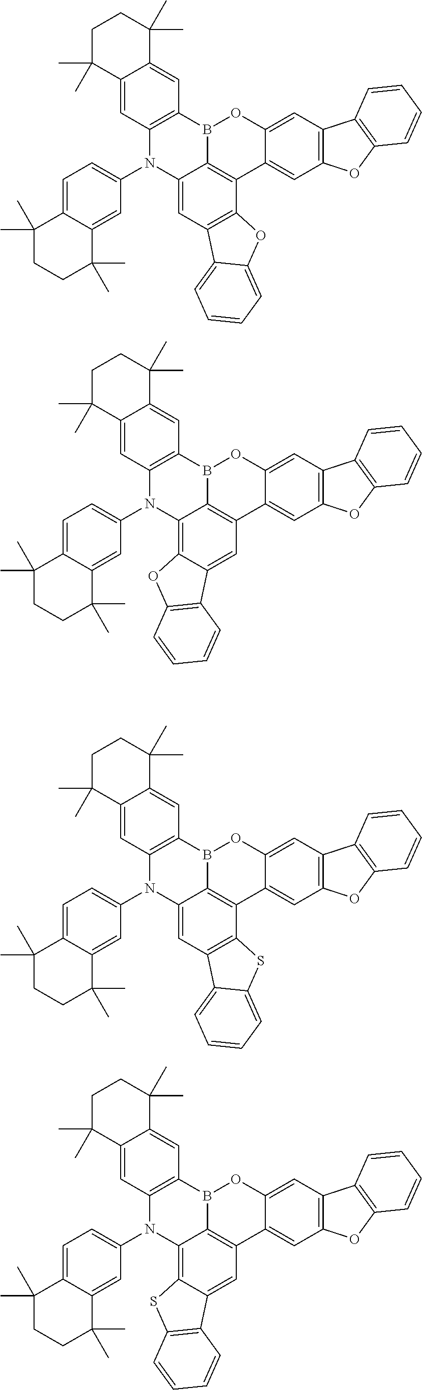 [SMILES: CC1(C)CCC(C)(C)c2cc(N3c4cc5c(cc4B4Oc6cc7c(cc6-c6c4c3cc3c6oc4ccccc43)oc3ccccc37)C(C)(C)CCC5(C)C)ccc21 ; CC1(C)CCC(C)(C)c2cc(N3c4cc5c(cc4B4Oc6cc7c(cc6-c6cc8c(oc9ccccc98)c3c64)oc3ccccc37)C(C)(C)CCC5(C)C)ccc21 ; CC1(C)CCC(C)(C)c2cc(N3c4cc5c(cc4B4Oc6cc7c(cc6-c6c4c3cc3c6sc4ccccc43)oc3ccccc37)C(C)(C)CCC5(C)C)ccc21 ; CC1(C)CCC(C)(C)c2cc(N3c4cc5c(cc4B4Oc6cc7c(cc6-c6cc8c(sc9ccccc98)c3c64)oc3ccccc37)C(C)(C)CCC5(C)C)ccc21]

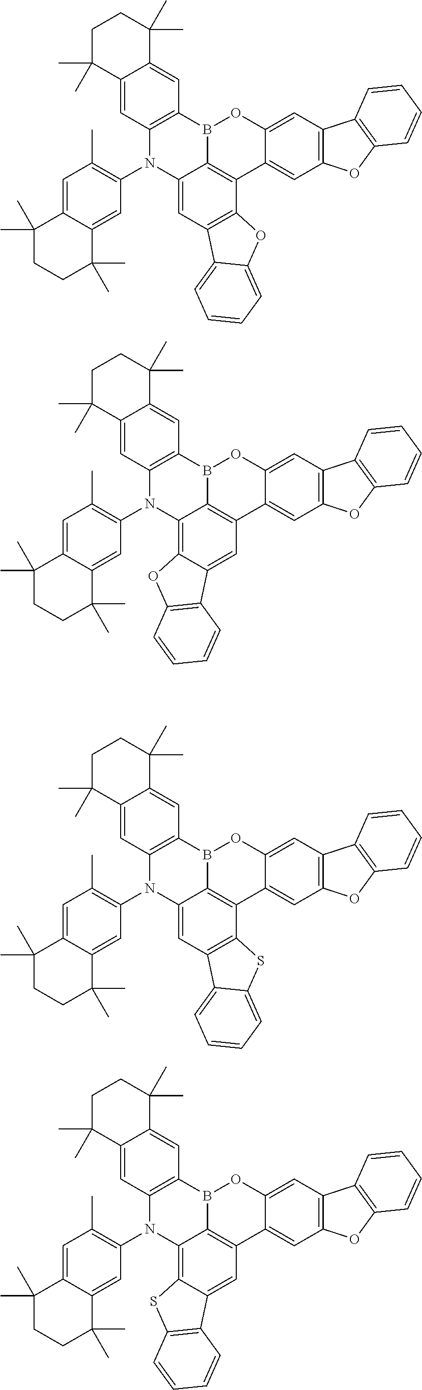 [SMILES: Cc1cc2c(cc1N1c3cc4c(cc3B3Oc5cc6c(cc5-c5c3c1cc1c5oc3ccccc31)oc1ccccc16)C(C)(C)CCC4(C)C)C(C)(C)CCC2(C)C ; Cc1cc2c(cc1N1c3cc4c(cc3B3Oc5cc6c(cc5-c5cc7c(oc8ccccc87)c1c53)oc1ccccc16)C(C)(C)CCC4(C)C)C(C)(C)CCC2(C)C ; Cc1cc2c(cc1N1c3cc4c(cc3B3Oc5cc6c(cc5-c5c3c1cc1c5sc3ccccc31)oc1ccccc16)C(C)(C)CCC4(C)C)C(C)(C)CCC2(C)C ; Cc1cc2c(cc1N1c3cc4c(cc3B3Oc5cc6c(cc5-c5cc7c(sc8ccccc87)c1c53)oc1ccccc16)C(C)(C)CCC4(C)C)C(C)(C)CCC2(C)C]

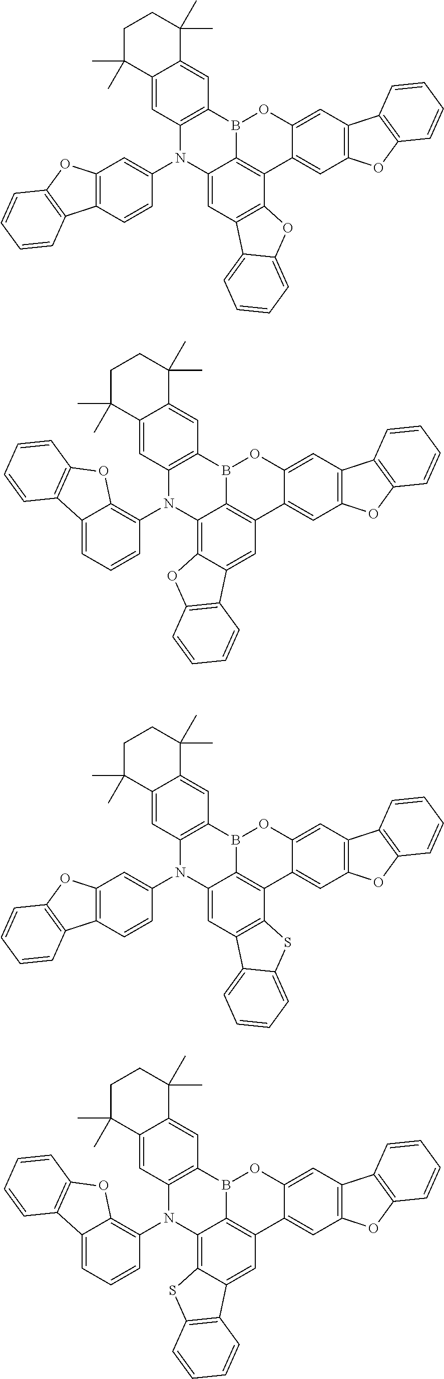 [SMILES: CC1(C)CCC(C)(C)c2cc3c(cc21)B1Oc2cc4c(cc2-c2c1c(cc1c2oc2ccccc21)N3c1ccc2c(c1)oc1ccccc12)oc1ccccc14 ; CC1(C)CCC(C)(C)c2cc3c(cc21)B1Oc2cc4c(cc2-c2cc5c(oc6ccccc65)c(c21)N3c1cccc2c1oc1ccccc12)oc1ccccc14 ; CC1(C)CCC(C)(C)c2cc3c(cc21)B1Oc2cc4c(cc2-c2c1c(cc1c2sc2ccccc21)N3c1ccc2c(c1)oc1ccccc12)oc1ccccc14 ; CC1(C)CCC(C)(C)c2cc3c(cc21)B1Oc2cc4c(cc2-c2cc5c(sc6ccccc65)c(c21)N3c1cccc2c1oc1ccccc12)oc1ccccc14]

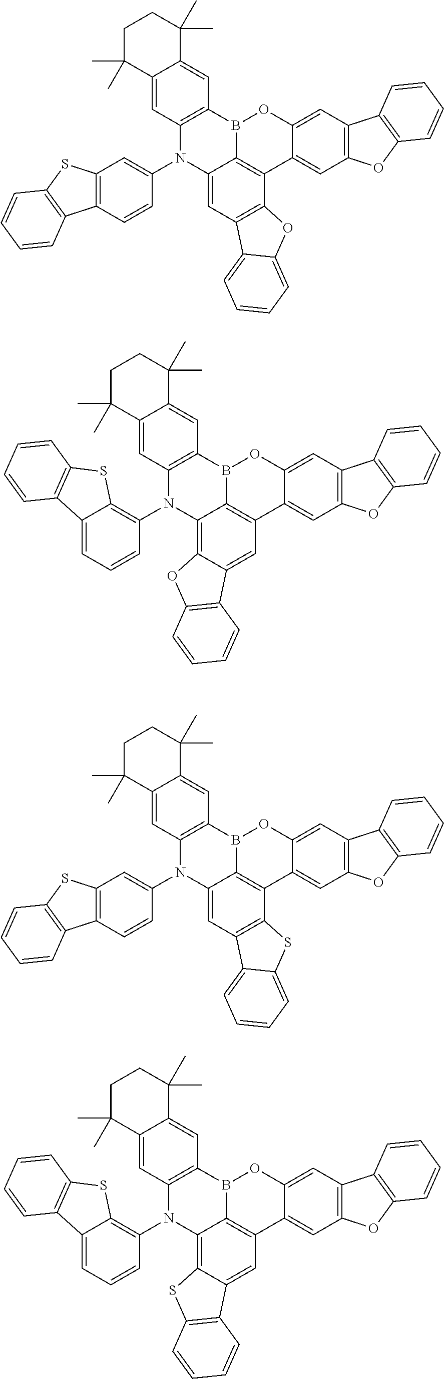 [SMILES: CC1(C)CCC(C)(C)c2cc3c(cc21)B1Oc2cc4c(cc2-c2c1c(cc1c2oc2ccccc21)N3c1ccc2c(c1)sc1ccccc12)oc1ccccc14 ; CC1(C)CCC(C)(C)c2cc3c(cc21)B1Oc2cc4c(cc2-c2cc5c(oc6ccccc65)c(c21)N3c1cccc2c1sc1ccccc12)oc1ccccc14 ; CC1(C)CCC(C)(C)c2cc3c(cc21)B1Oc2cc4c(cc2-c2c1c(cc1c2sc2ccccc21)N3c1ccc2c(c1)sc1ccccc12)oc1ccccc14 ; CC1(C)CCC(C)(C)c2cc3c(cc21)B1Oc2cc4c(cc2-c2cc5c(sc6ccccc65)c(c21)N3c1cccc2c1sc1ccccc12)oc1ccccc14]

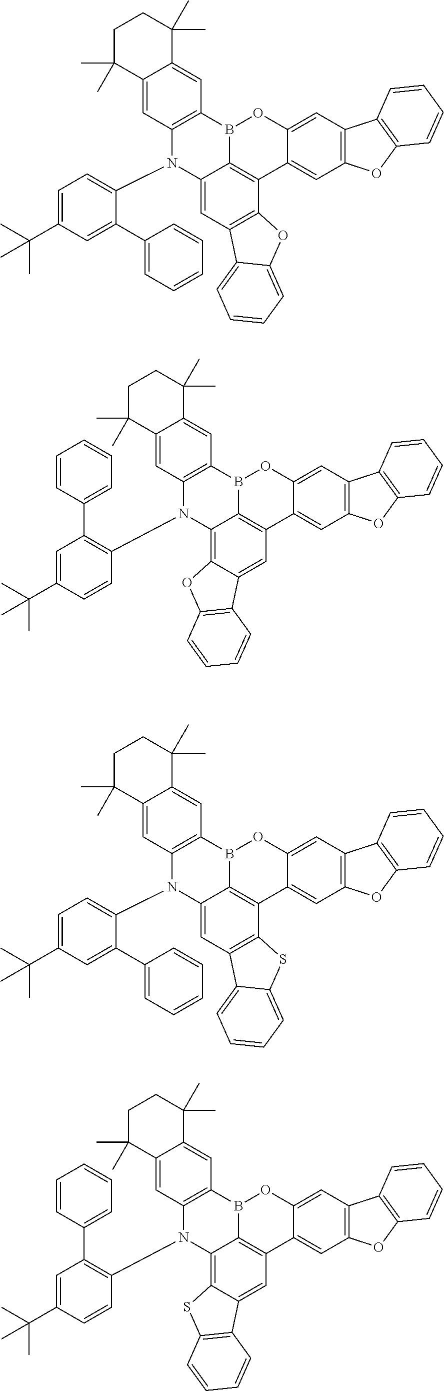 [SMILES: CC(C)(C)c1ccc(N2c3cc4c(cc3B3Oc5cc6c(cc5-c5c3c2cc2c5oc3ccccc32)oc2ccccc26)C(C)(C)CCC4(C)C)c(-c2ccccc2)c1 ; CC(C)(C)c1ccc(N2c3cc4c(cc3B3Oc5cc6c(cc5-c5cc7c(oc8ccccc87)c2c53)oc2ccccc26)C(C)(C)CCC4(C)C)c(-c2ccccc2)c1 ; CC(C)(C)c1ccc(N2c3cc4c(cc3B3Oc5cc6c(cc5-c5c3c2cc2c5sc3ccccc32)oc2ccccc26)C(C)(C)CCC4(C)C)c(-c2ccccc2)c1 ; CC(C)(C)c1ccc(N2c3cc4c(cc3B3Oc5cc6c(cc5-c5cc7c(sc8ccccc87)c2c53)oc2ccccc26)C(C)(C)CCC4(C)C)c(-c2ccccc2)c1]

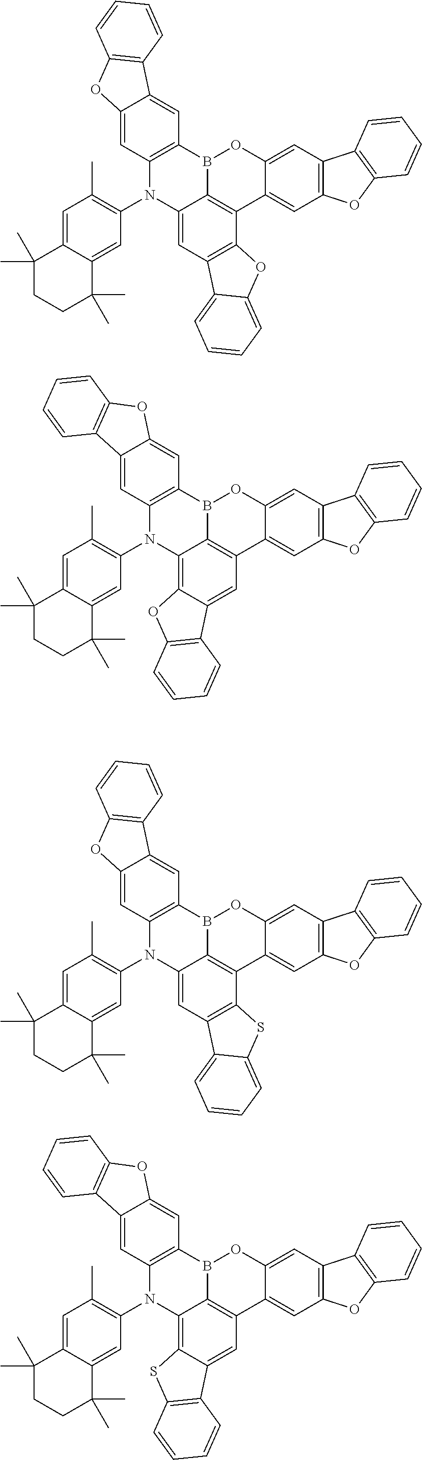 [SMILES: Cc1cc2c(cc1N1c3cc4oc5ccccc5c4cc3B3Oc4cc5c(cc4-c4c3c1cc1c4oc3ccccc31)oc1ccccc15)C(C)(C)CCC2(C)C ; Cc1cc2c(cc1N1c3cc4c(cc3B3Oc5cc6c(cc5-c5cc7c(oc8ccccc87)c1c53)oc1ccccc16)oc1ccccc14)C(C)(C)CCC2(C)C ; Cc1cc2c(cc1N1c3cc4oc5ccccc5c4cc3B3Oc4cc5c(cc4-c4c3c1cc1c4sc3ccccc31)oc1ccccc15)C(C)(C)CCC2(C)C ; Cc1cc2c(cc1N1c3cc4c(cc3B3Oc5cc6c(cc5-c5cc7c(sc8ccccc87)c1c53)oc1ccccc16)oc1ccccc14)C(C)(C)CCC2(C)C]

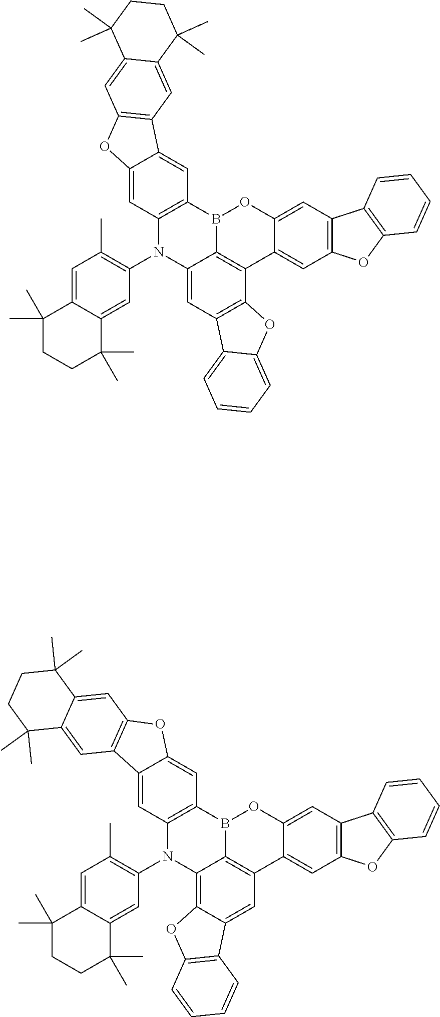 [SMILES: Cc1cc2c(cc1N1c3cc4oc5cc6c(cc5c4cc3B3Oc4cc5c(cc4-c4c3c1cc1c4oc3ccccc31)oc1ccccc15)C(C)(C)CCC6(C)C)C(C)(C)CCC2(C)C ; Cc1cc2c(cc1N1c3cc4c(cc3B3Oc5cc6c(cc5-c5cc7c(oc8ccccc87)c1c53)oc1ccccc16)oc1cc3c(cc14)C(C)(C)CCC3(C)C)C(C)(C)CCC2(C)C]

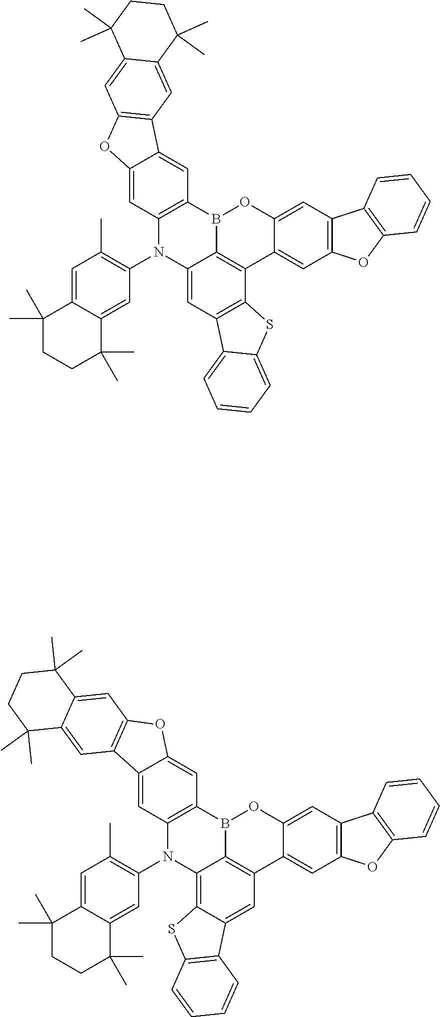 [SMILES: Cc1cc2c(cc1N1c3cc4oc5cc6c(cc5c4cc3B3Oc4cc5c(cc4-c4c3c1cc1c4sc3ccccc31)oc1ccccc15)C(C)(C)CCC6(C)C)C(C)(C)CCC2(C)C ; Cc1cc2c(cc1N1c3cc4c(cc3B3Oc5cc6c(cc5-c5cc7c(sc8ccccc87)c1c53)oc1ccccc16)oc1cc3c(cc14)C(C)(C)CCC3(C)C)C(C)(C)CCC2(C)C]

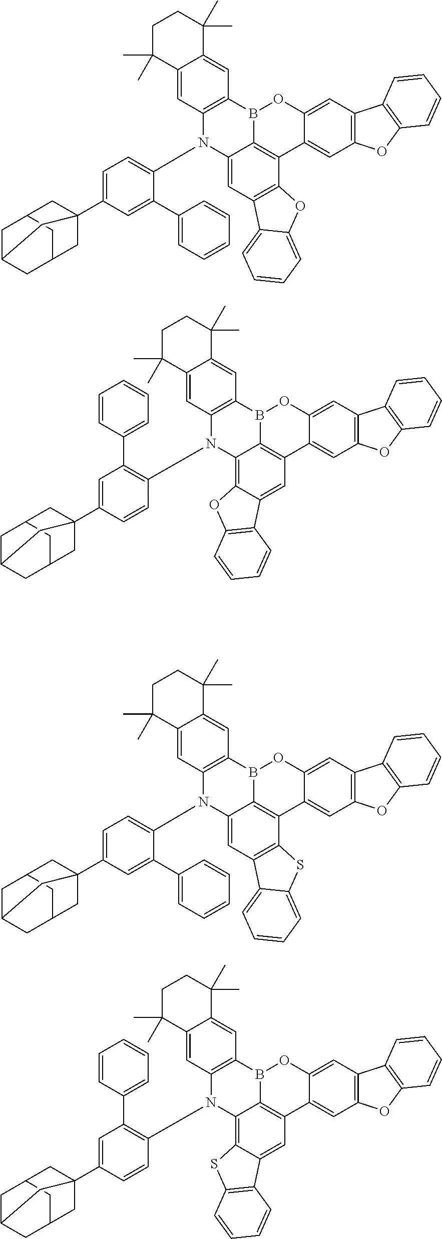

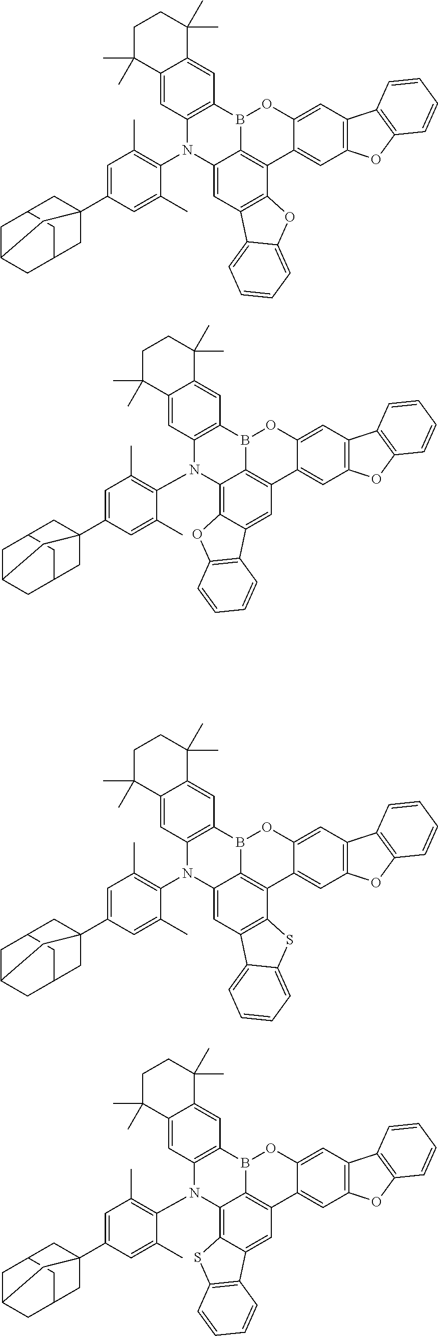 [SMILES: Cc1cc(C23CC4CC(CC(C4)C2)C3)cc(C)c1N1c2cc3c(cc2B2Oc4cc5c(cc4-c4c2c1cc1c4oc2ccccc21)oc1ccccc15)C(C)(C)CCC3(C)C ; Cc1cc(C23CC4CC(CC(C4)C2)C3)cc(C)c1N1c2cc3c(cc2B2Oc4cc5c(cc4-c4cc6c(oc7ccccc76)c1c42)oc1ccccc15)C(C)(C)CCC3(C)C ; Cc1cc(C23CC4CC(CC(C4)C2)C3)cc(C)c1N1c2cc3c(cc2B2Oc4cc5c(cc4-c4c2c1cc1c4sc2ccccc21)oc1ccccc15)C(C)(C)CCC3(C)C ; Cc1cc(C23CC4CC(CC(C4)C2)C3)cc(C)c1N1c2cc3c(cc2B2Oc4cc5c(cc4-c4cc6c(sc7ccccc76)c1c42)oc1ccccc15)C(C)(C)CCC3(C)C]

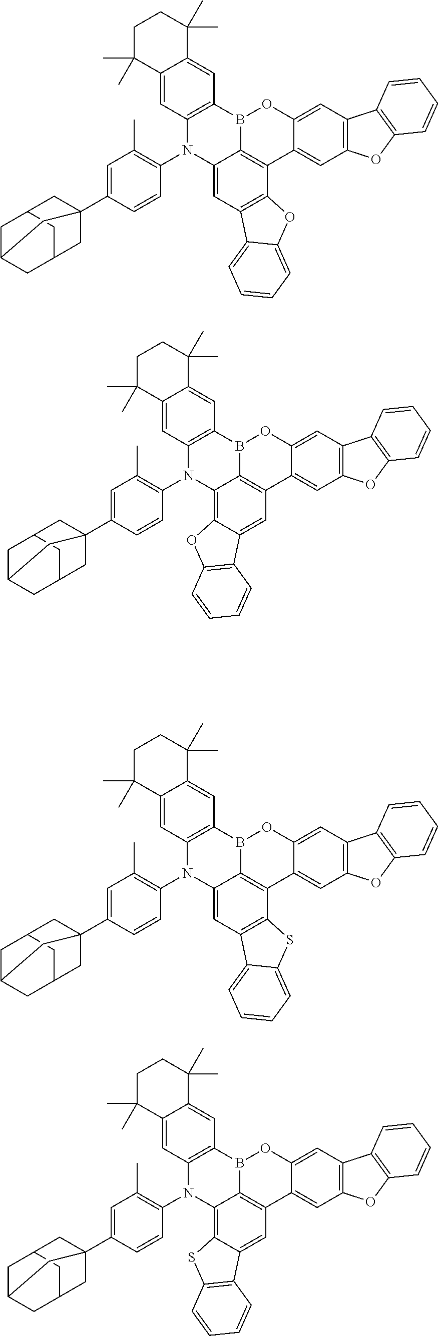 [SMILES: Cc1cc(C23CC4CC(CC(C4)C2)C3)ccc1N1c2cc3c(cc2B2Oc4cc5c(cc4-c4c2c1cc1c4oc2ccccc21)oc1ccccc15)C(C)(C)CCC3(C)C ; Cc1cc(C23CC4CC(CC(C4)C2)C3)ccc1N1c2cc3c(cc2B2Oc4cc5c(cc4-c4cc6c(oc7ccccc76)c1c42)oc1ccccc15)C(C)(C)CCC3(C)C ; Cc1cc(C23CC4CC(CC(C4)C2)C3)ccc1N1c2cc3c(cc2B2Oc4cc5c(cc4-c4c2c1cc1c4sc2ccccc21)oc1ccccc15)C(C)(C)CCC3(C)C ; Cc1cc(C23CC4CC(CC(C4)C2)C3)ccc1N1c2cc3c(cc2B2Oc4cc5c(cc4-c4cc6c(sc7ccccc76)c1c42)oc1ccccc15)C(C)(C)CCC3(C)C]

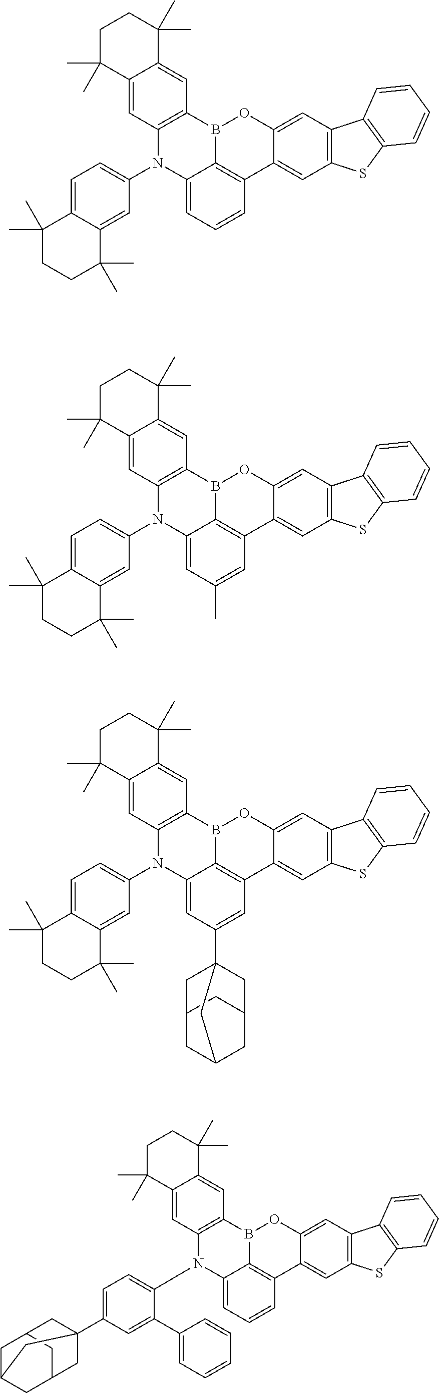 [SMILES: CC1(C)CCC(C)(C)c2cc(N3c4cc5c(cc4B4Oc6cc7c(cc6-c6cccc3c64)sc3ccccc37)C(C)(C)CCC5(C)C)ccc21 ; Cc1cc2c3c(c1)N(c1ccc4c(c1)C(C)(C)CCC4(C)C)c1cc4c(cc1B3Oc1cc3c(cc1-2)sc1ccccc13)C(C)(C)CCC4(C)C ; CC1(C)CCC(C)(C)c2cc(N3c4cc5c(cc4B4Oc6cc7c(cc6-c6cc(C89CC%10CC(CC(C%10)C8)C9)cc3c64)sc3ccccc37)C(C)(C)CCC5(C)C)ccc21 ; CC1(C)CCC(C)(C)c2cc3c(cc21)B1Oc2cc4c(cc2-c2cccc(c21)N3c1ccc(C23CC5CC(CC(C5)C2)C3)cc1-c1ccccc1)sc1ccccc14]

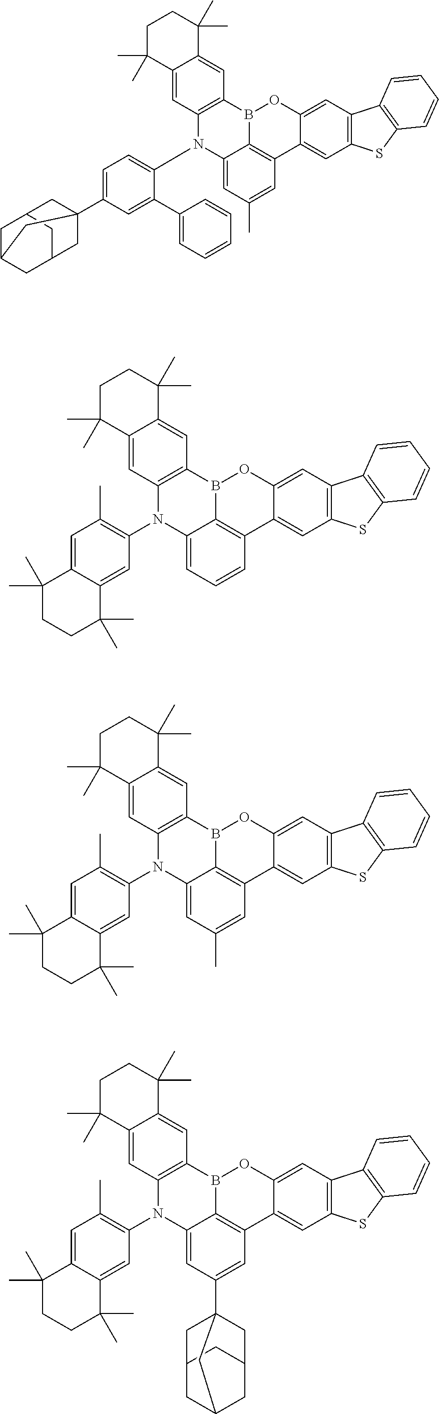 [SMILES: Cc1cc2c3c(c1)N(c1ccc(C45CC6CC(CC(C6)C4)C5)cc1-c1ccccc1)c1cc4c(cc1B3Oc1cc3c(cc1-2)sc1ccccc13)C(C)(C)CCC4(C)C ; Cc1cc2c(cc1N1c3cc4c(cc3B3Oc5cc6c(cc5-c5cccc1c53)sc1ccccc16)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Oc1cc3c(cc1-2)sc1ccccc13)C(C)(C)CCC4(C)C ; Cc1cc2c(cc1N1c3cc4c(cc3B3Oc5cc6c(cc5-c5cc(C78CC9CC(CC(C9)C7)C8)cc1c53)sc1ccccc16)C(C)(C)CCC4(C)C)C(C)(C)CCC2(C)C]

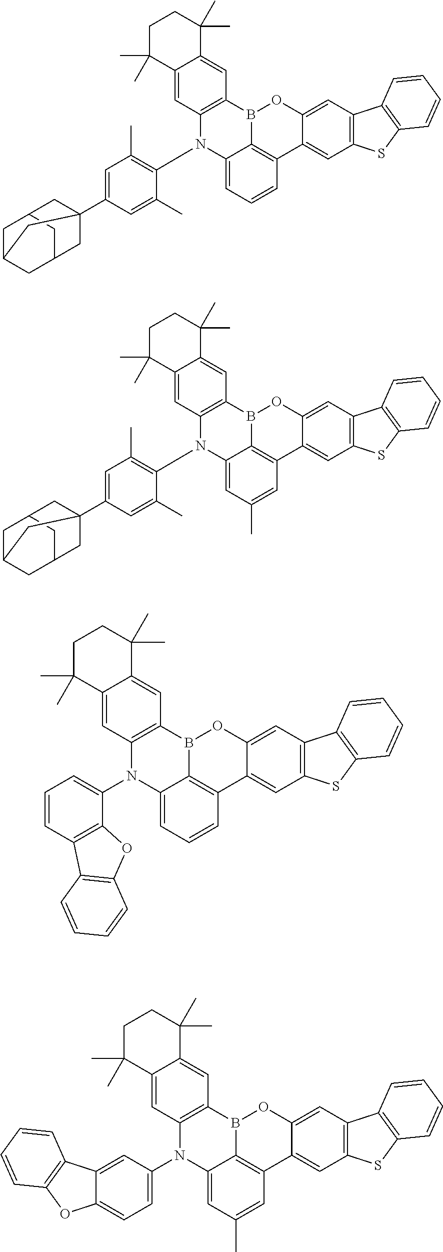 [SMILES: Cc1cc(C23CC4CC(CC(C4)C2)C3)cc(C)c1N1c2cc3c(cc2B2Oc4cc5c(cc4-c4cccc1c42)sc1ccccc15)C(C)(C)CCC3(C)C ; Cc1cc2c3c(c1)N(c1c(C)cc(C45CC6CC(CC(C6)C4)C5)cc1C)c1cc4c(cc1B3Oc1cc3c(cc1-2)sc1ccccc13)C(C)(C)CCC4(C)C ; CC1(C)CCC(C)(C)c2cc3c(cc21)B1Oc2cc4c(cc2-c2cccc(c21)N3c1cccc2c1oc1ccccc12)sc1ccccc14 ; Cc1cc2c3c(c1)N(c1ccc4oc5ccccc5c4c1)c1cc4c(cc1B3Oc1cc3c(cc1-2)sc1ccccc13)C(C)(C)CCC4(C)C]

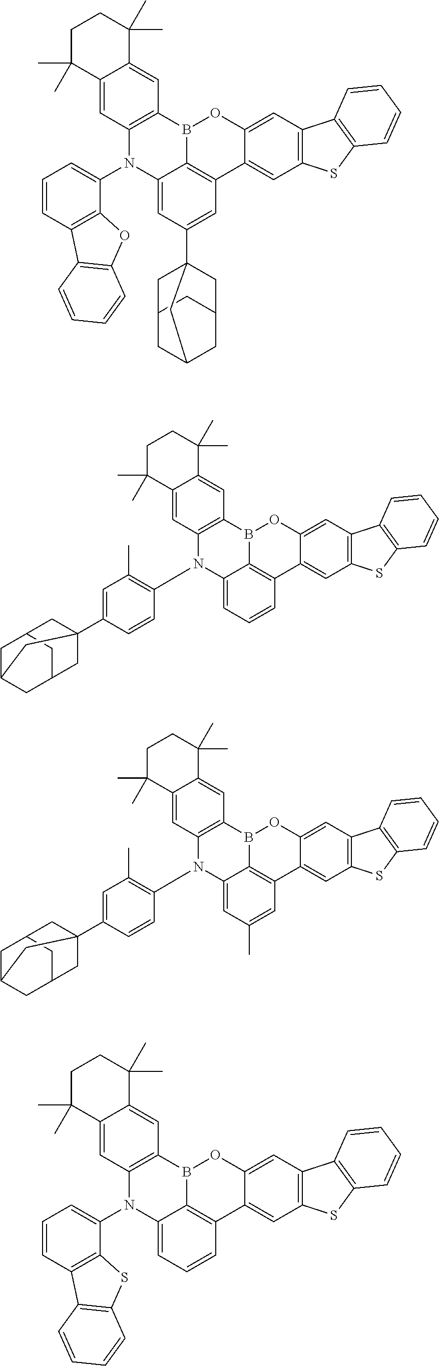 [SMILES: CC1(C)CCC(C)(C)c2cc3c(cc21)B1Oc2cc4c(cc2-c2cc(C56CC7CC(CC(C7)C5)C6)cc(c21)N3c1cccc2c1oc1ccccc12)sc1ccccc14 ; Cc1cc(C23CC4CC(CC(C4)C2)C3)ccc1N1c2cc3c(cc2B2Oc4cc5c(cc4-c4cccc1c42)sc1ccccc15)C(C)(C)CCC3(C)C ; Cc1cc2c3c(c1)N(c1ccc(C45CC6CC(CC(C6)C4)C5)cc1C)c1cc4c(cc1B3Oc1cc3c(cc1-2)sc1ccccc13)C(C)(C)CCC4(C)C ; CC1(C)CCC(C)(C)c2cc3c(cc21)B1Oc2cc4c(cc2-c2cccc(c21)N3c1cccc2c1sc1ccccc12)sc1ccccc14]

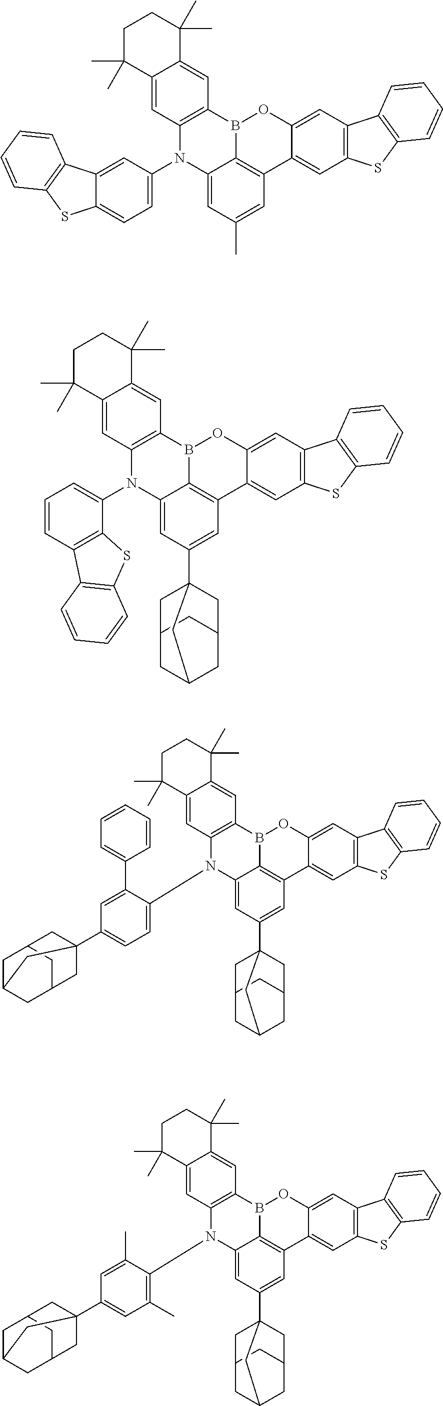 [SMILES: Cc1cc2c3c(c1)N(c1ccc4sc5ccccc5c4c1)c1cc4c(cc1B3Oc1cc3c(cc1-2)sc1ccccc13)C(C)(C)CCC4(C)C ; CC1(C)CCC(C)(C)c2cc3c(cc21)B1Oc2cc4c(cc2-c2cc(C56CC7CC(CC(C7)C5)C6)cc(c21)N3c1cccc2c1sc1ccccc12)sc1ccccc14 ; CC1(C)CCC(C)(C)c2cc3c(cc21)B1Oc2cc4c(cc2-c2cc(C56CC7CC(CC(C7)C5)C6)cc(c21)N3c1ccc(C23CC5CC(CC(C5)C2)C3)cc1-c1ccccc1)sc1ccccc14 ; Cc1cc(C23CC4CC(CC(C4)C2)C3)cc(C)c1N1c2cc3c(cc2B2Oc4cc5c(cc4-c4cc(C67CC8CC(CC(C8)C6)C7)cc1c42)sc1ccccc15)C(C)(C)CCC3(C)C]

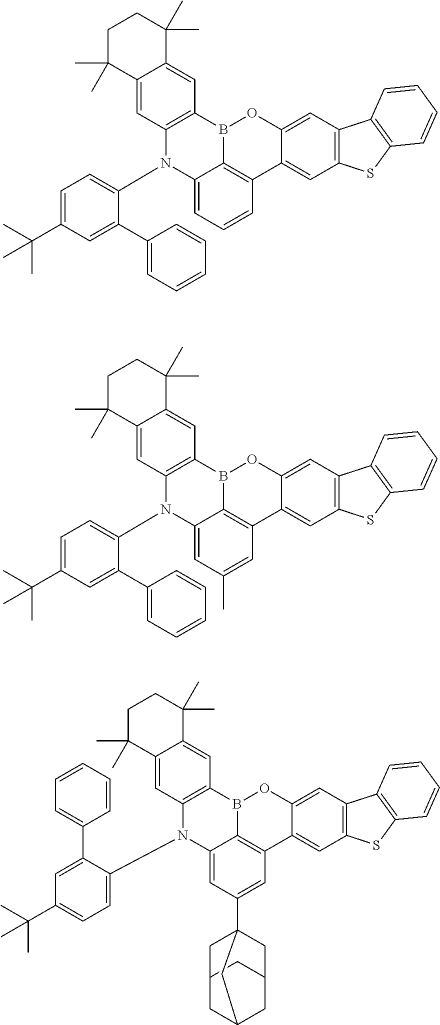 [SMILES: CC(C)(C)c1ccc(N2c3cc4c(cc3B3Oc5cc6c(cc5-c5cccc2c53)sc2ccccc26)C(C)(C)CCC4(C)C)c(-c2ccccc2)c1 ; Cc1cc2c3c(c1)N(c1ccc(C(C)(C)C)cc1-c1ccccc1)c1cc4c(cc1B3Oc1cc3c(cc1-2)sc1ccccc13)C(C)(C)CCC4(C)C ; CC(C)(C)c1ccc(N2c3cc4c(cc3B3Oc5cc6c(cc5-c5cc(C78CC9CC(CC(C9)C7)C8)cc2c53)sc2ccccc26)C(C)(C)CCC4(C)C)c(-c2ccccc2)c1]

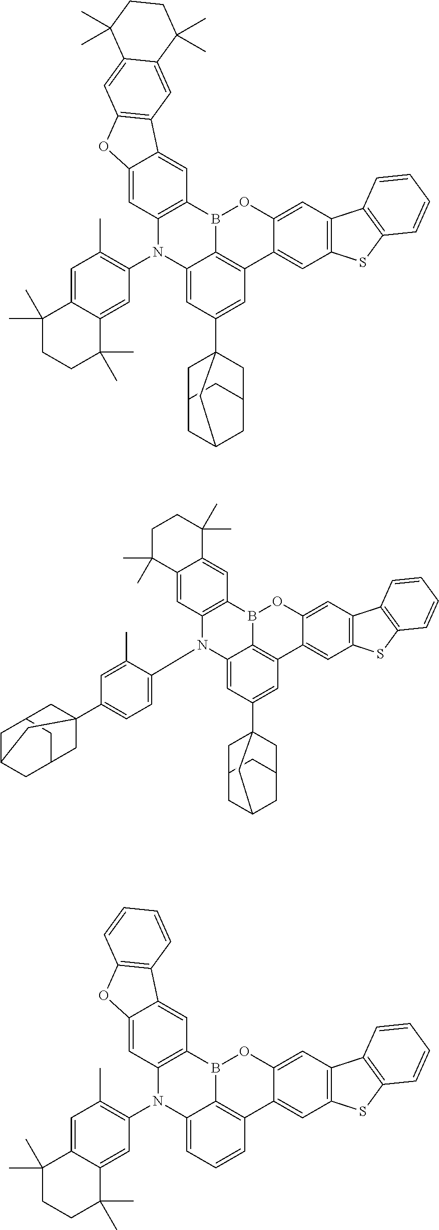 [SMILES: Cc1cc2c(cc1N1c3cc4oc5cc6c(cc5c4cc3B3Oc4cc5c(cc4-c4cc(C78CC9CC(CC(C9)C7)C8)cc1c43)sc1ccccc15)C(C)(C)CCC6(C)C)C(C)(C)CCC2(C)C ; Cc1cc(C23CC4CC(CC(C4)C2)C3)ccc1N1c2cc3c(cc2B2Oc4cc5c(cc4-c4cc(C67CC8CC(CC(C8)C6)C7)cc1c42)sc1ccccc15)C(C)(C)CCC3(C)C ; Cc1cc2c(cc1N1c3cc4oc5ccccc5c4cc3B3Oc4cc5c(cc4-c4cccc1c43)sc1ccccc15)C(C)(C)CCC2(C)C]

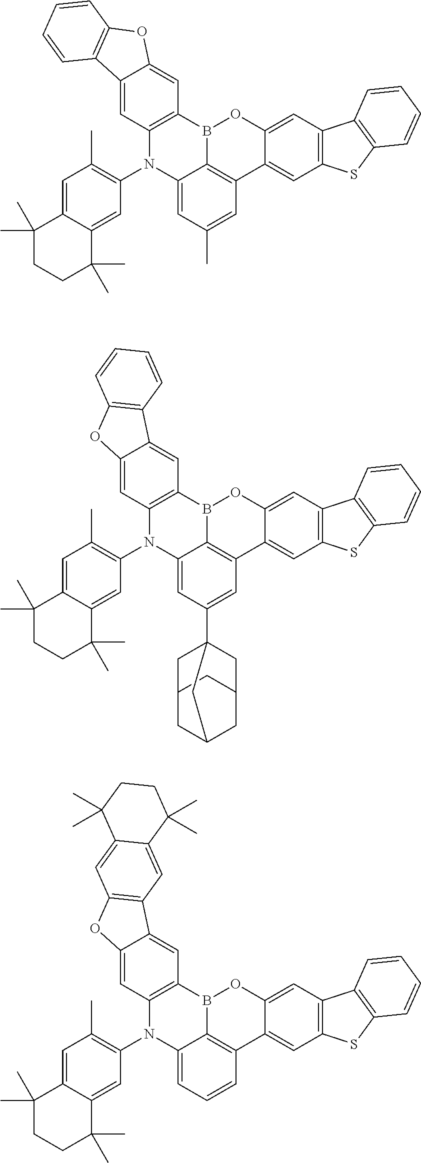 [SMILES: Cc1cc2c3c(c1)N(c1cc4c(cc1C)C(C)(C)CCC4(C)C)c1cc4c(cc1B3Oc1cc3c(cc1-2)sc1ccccc13)oc1ccccc14 ; Cc1cc2c(cc1N1c3cc4oc5ccccc5c4cc3B3Oc4cc5c(cc4-c4cc(C67CC8CC(CC(C8)C6)C7)cc1c43)sc1ccccc15)C(C)(C)CCC2(C)C ; Cc1cc2c(cc1N1c3cc4oc5cc6c(cc5c4cc3B3Oc4cc5c(cc4-c4cccc1c43)sc1ccccc15)C(C)(C)CCC6(C)C)C(C)(C)CCC2(C)C]

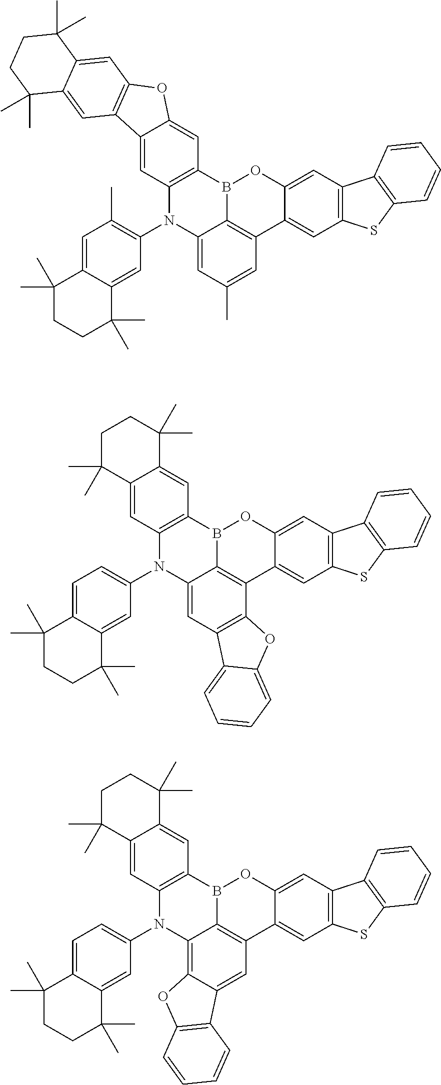 [SMILES: Cc1cc2c3c(c1)N(c1cc4c(cc1C)C(C)(C)CCC4(C)C)c1cc4c(cc1B3Oc1cc3c(cc1-2)sc1ccccc13)oc1cc2c(cc14)C(C)(C)CCC2(C)C ; CC1(C)CCC(C)(C)c2cc(N3c4cc5c(cc4B4Oc6cc7c(cc6-c6c4c3cc3c6oc4ccccc43)sc3ccccc37)C(C)(C)CCC5(C)C)ccc21 ; CC1(C)CCC(C)(C)c2cc(N3c4cc5c(cc4B4Oc6cc7c(cc6-c6cc8c(oc9ccccc98)c3c64)sc3ccccc37)C(C)(C)CCC5(C)C)ccc21]

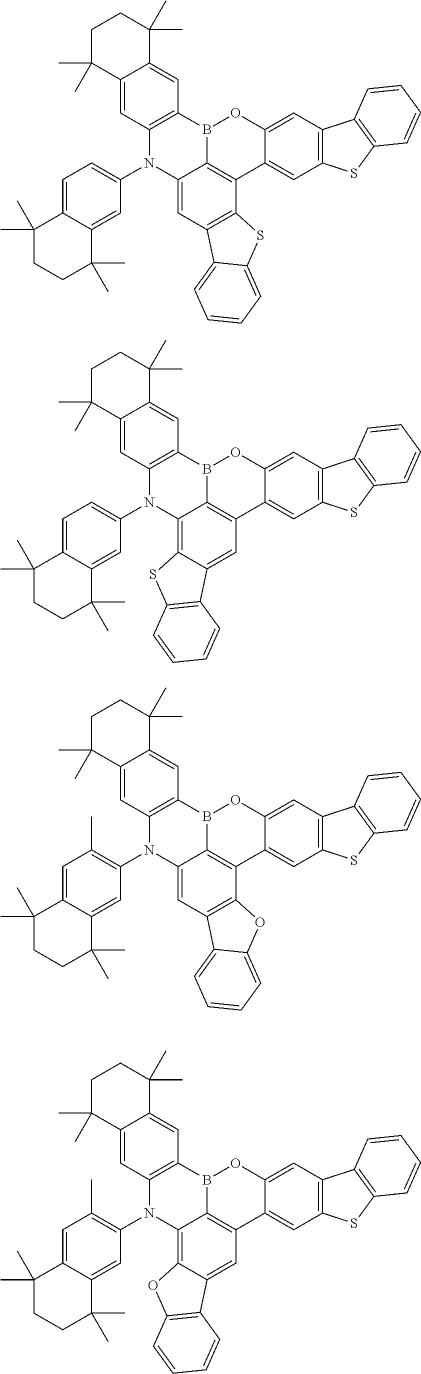

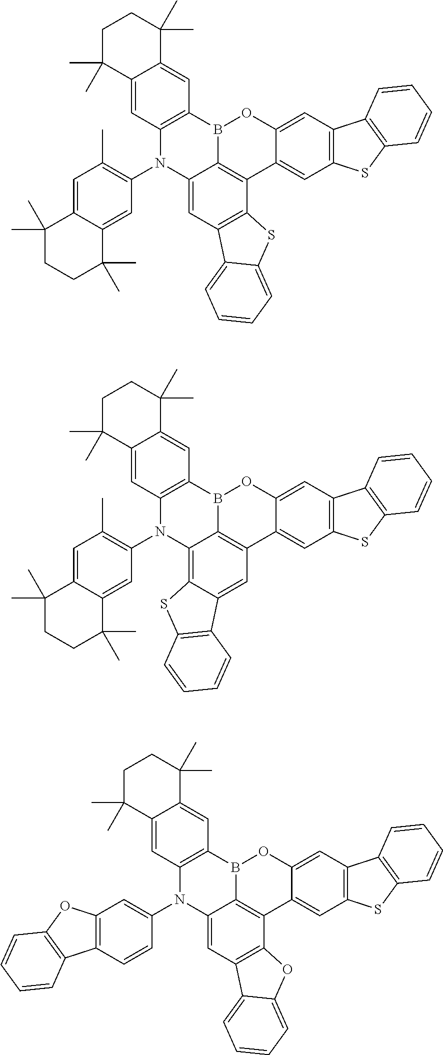 [SMILES: Cc1cc2c(cc1N1c3cc4c(cc3B3Oc5cc6c(cc5-c5c3c1cc1c5sc3ccccc31)sc1ccccc16)C(C)(C)CCC4(C)C)C(C)(C)CCC2(C)C ; Cc1cc2c(cc1N1c3cc4c(cc3B3Oc5cc6c(cc5-c5cc7c(sc8ccccc87)c1c53)sc1ccccc16)C(C)(C)CCC4(C)C)C(C)(C)CCC2(C)C ; CC1(C)CCC(C)(C)c2cc3c(cc21)B1Oc2cc4c(cc2-c2c1c(cc1c2oc2ccccc21)N3c1ccc2c(c1)oc1ccccc12)sc1ccccc14]

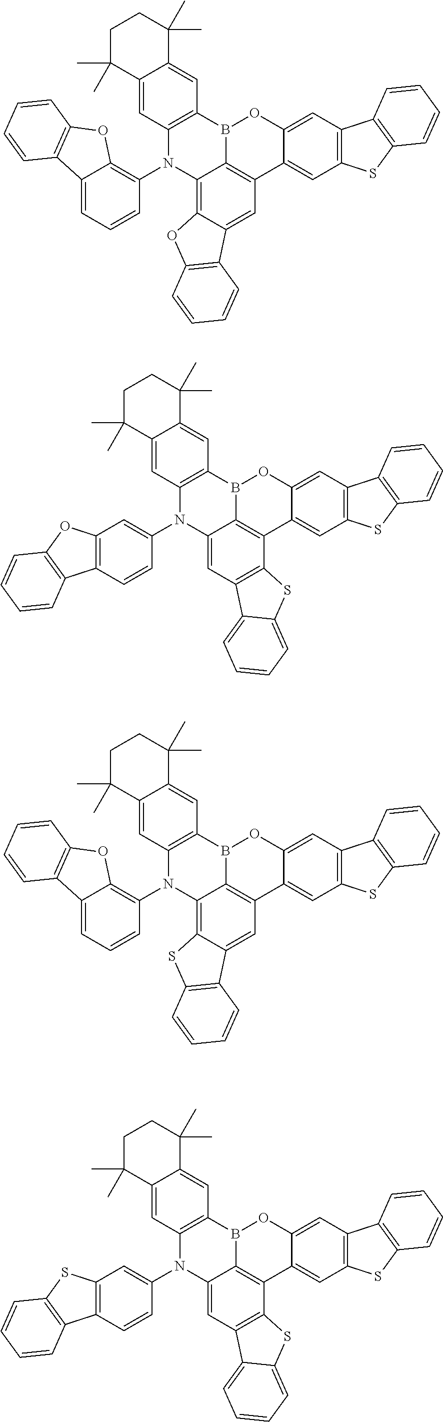

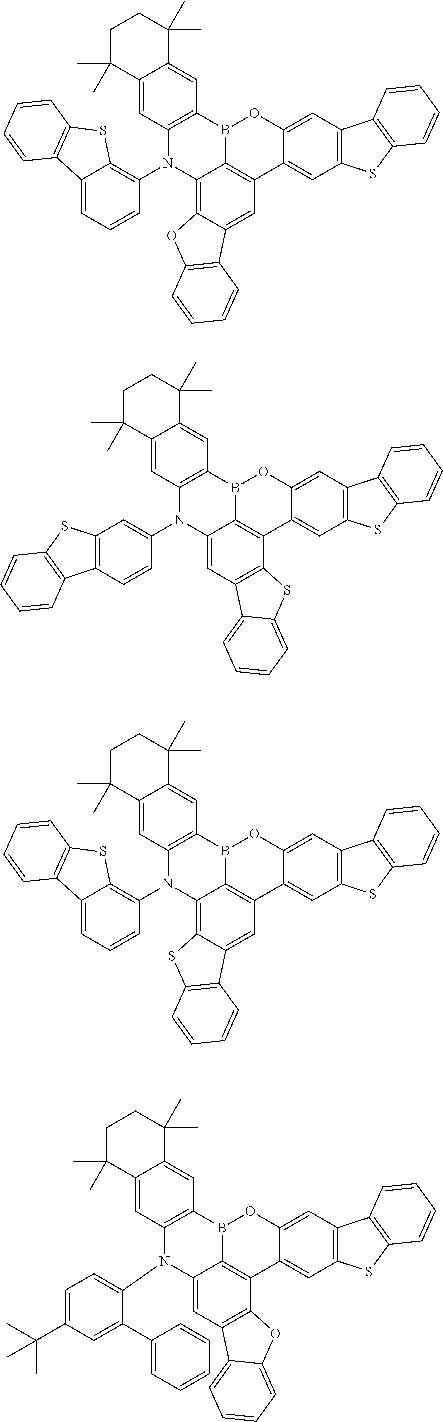

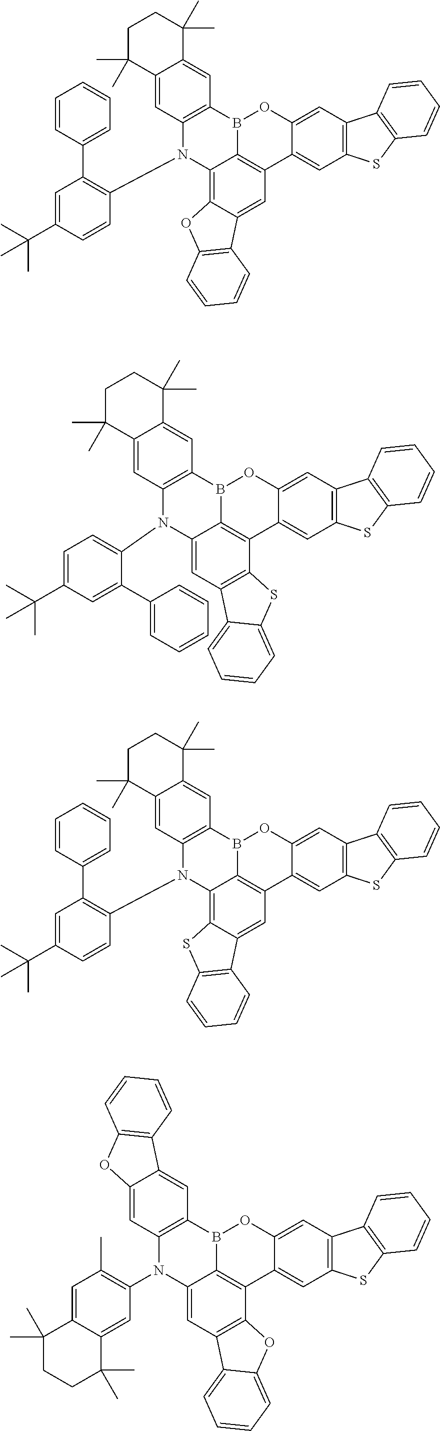 [SMILES: CC(C)(C)c1ccc(N2c3cc4c(cc3B3Oc5cc6c(cc5-c5cc7c(oc8ccccc87)c2c53)sc2ccccc26)C(C)(C)CCC4(C)C)c(-c2ccccc2)c1 ; CC(C)(C)c1ccc(N2c3cc4c(cc3B3Oc5cc6c(cc5-c5c3c2cc2c5sc3ccccc32)sc2ccccc26)C(C)(C)CCC4(C)C)c(-c2ccccc2)c1 ; CC(C)(C)c1ccc(N2c3cc4c(cc3B3Oc5cc6c(cc5-c5cc7c(sc8ccccc87)c2c53)sc2ccccc26)C(C)(C)CCC4(C)C)c(-c2ccccc2)c1 ; Cc1cc2c(cc1N1c3cc4oc5ccccc5c4cc3B3Oc4cc5c(cc4-c4c3c1cc1c4oc3ccccc31)sc1ccccc15)C(C)(C)CCC2(C)C]

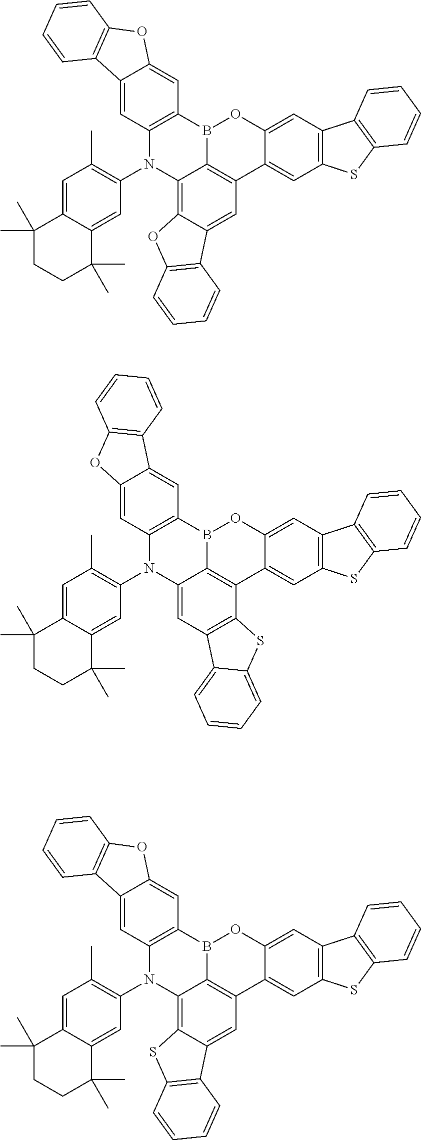 [SMILES: Cc1cc2c(cc1N1c3cc4c(cc3B3Oc5cc6c(cc5-c5cc7c(oc8ccccc87)c1c53)sc1ccccc16)oc1ccccc14)C(C)(C)CCC2(C)C ; Cc1cc2c(cc1N1c3cc4oc5ccccc5c4cc3B3Oc4cc5c(cc4-c4c3c1cc1c4sc3ccccc31)sc1ccccc15)C(C)(C)CCC2(C)C ; Cc1cc2c(cc1N1c3cc4c(cc3B3Oc5cc6c(cc5-c5cc7c(sc8ccccc87)c1c53)sc1ccccc16)oc1ccccc14)C(C)(C)CCC2(C)C]

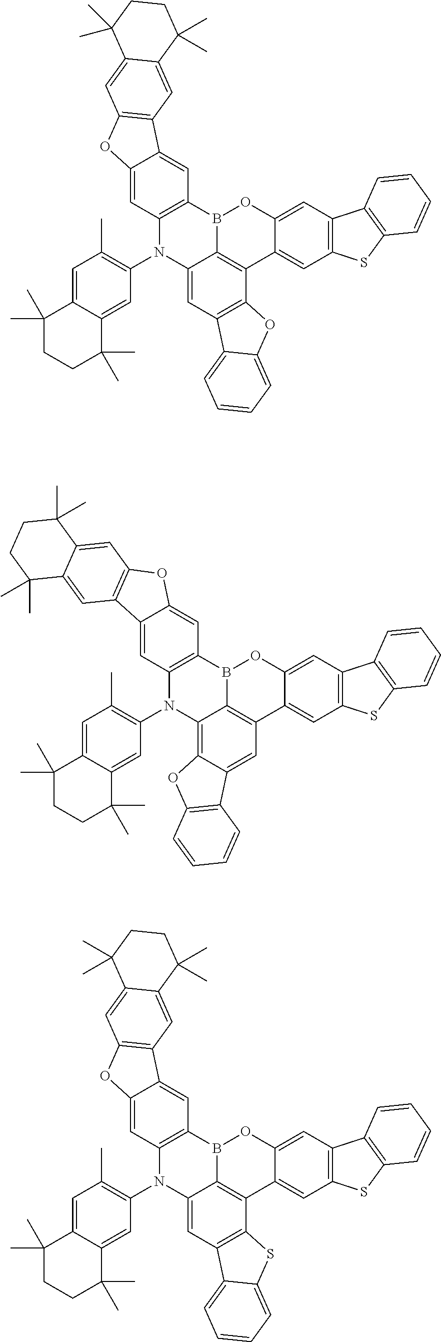 [SMILES: Cc1cc2c(cc1N1c3cc4oc5cc6c(cc5c4cc3B3Oc4cc5c(cc4-c4c3c1cc1c4oc3ccccc31)sc1ccccc15)C(C)(C)CCC6(C)C)C(C)(C)CCC2(C)C ; Cc1cc2c(cc1N1c3cc4c(cc3B3Oc5cc6c(cc5-c5cc7c(oc8ccccc87)c1c53)sc1ccccc16)oc1cc3c(cc14)C(C)(C)CCC3(C)C)C(C)(C)CCC2(C)C ; Cc1cc2c(cc1N1c3cc4oc5cc6c(cc5c4cc3B3Oc4cc5c(cc4-c4c3c1cc1c4sc3ccccc31)sc1ccccc15)C(C)(C)CCC6(C)C)C(C)(C)CCC2(C)C]

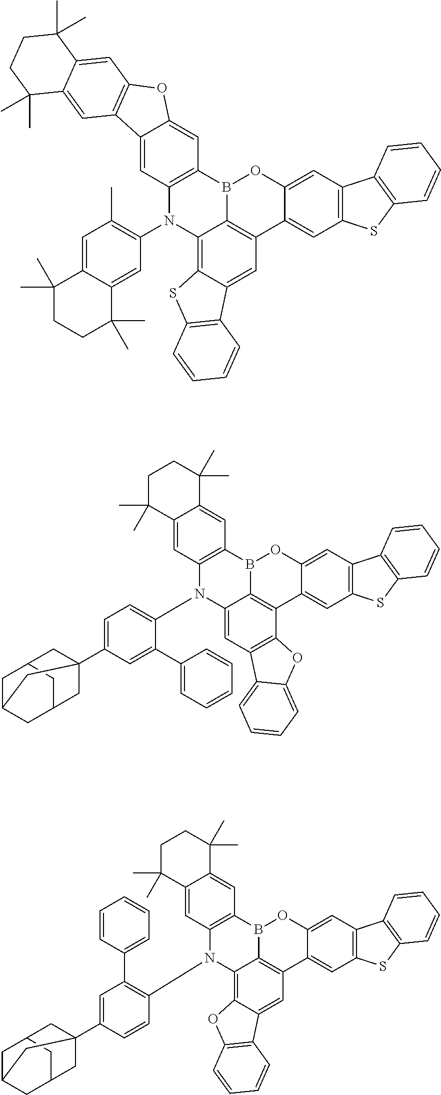 [SMILES: Cc1cc2c(cc1N1c3cc4c(cc3B3Oc5cc6c(cc5-c5cc7c(sc8ccccc87)c1c53)sc1ccccc16)oc1cc3c(cc14)C(C)(C)CCC3(C)C)C(C)(C)CCC2(C)C ; CC1(C)CCC(C)(C)c2cc3c(cc21)B1Oc2cc4c(cc2-c2c1c(cc1c2oc2ccccc21)N3c1ccc(C23CC5CC(CC(C5)C2)C3)cc1-c1ccccc1)sc1ccccc14 ; CC1(C)CCC(C)(C)c2cc3c(cc21)B1Oc2cc4c(cc2-c2cc5c(oc6ccccc65)c(c21)N3c1ccc(C23CC5CC(CC(C5)C2)C3)cc1-c1ccccc1)sc1ccccc14]

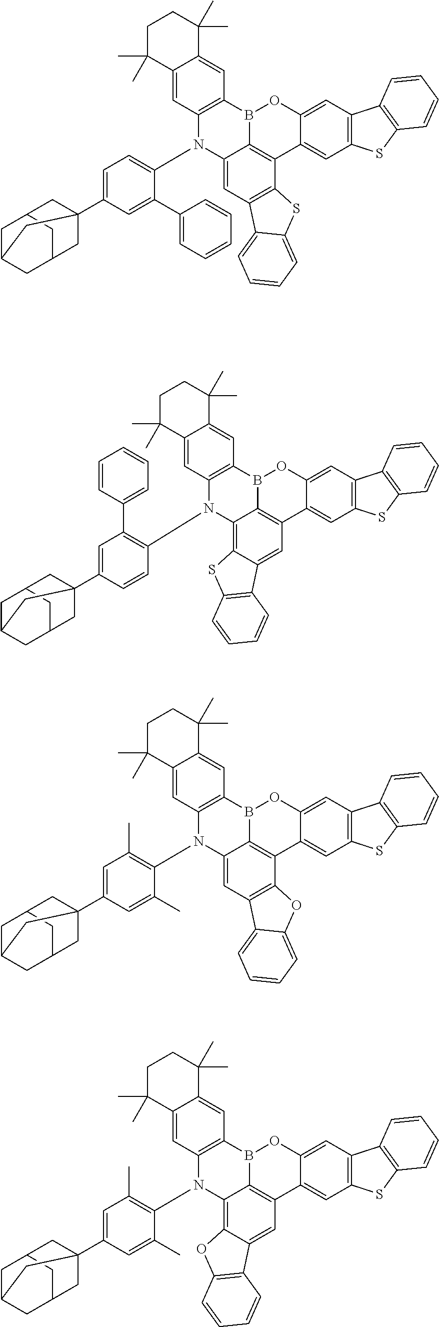 [SMILES: CC1(C)CCC(C)(C)c2cc3c(cc21)B1Oc2cc4c(cc2-c2c1c(cc1c2sc2ccccc21)N3c1ccc(C23CC5CC(CC(C5)C2)C3)cc1-c1ccccc1)sc1ccccc14 ; CC1(C)CCC(C)(C)c2cc3c(cc21)B1Oc2cc4c(cc2-c2cc5c(sc6ccccc65)c(c21)N3c1ccc(C23CC5CC(CC(C5)C2)C3)cc1-c1ccccc1)sc1ccccc14 ; Cc1cc(C23CC4CC(CC(C4)C2)C3)cc(C)c1N1c2cc3c(cc2B2Oc4cc5c(cc4-c4c2c1cc1c4oc2ccccc21)sc1ccccc15)C(C)(C)CCC3(C)C ; Cc1cc(C23CC4CC(CC(C4)C2)C3)cc(C)c1N1c2cc3c(cc2B2Oc4cc5c(cc4-c4cc6c(oc7ccccc76)c1c42)sc1ccccc15)C(C)(C)CCC3(C)C]

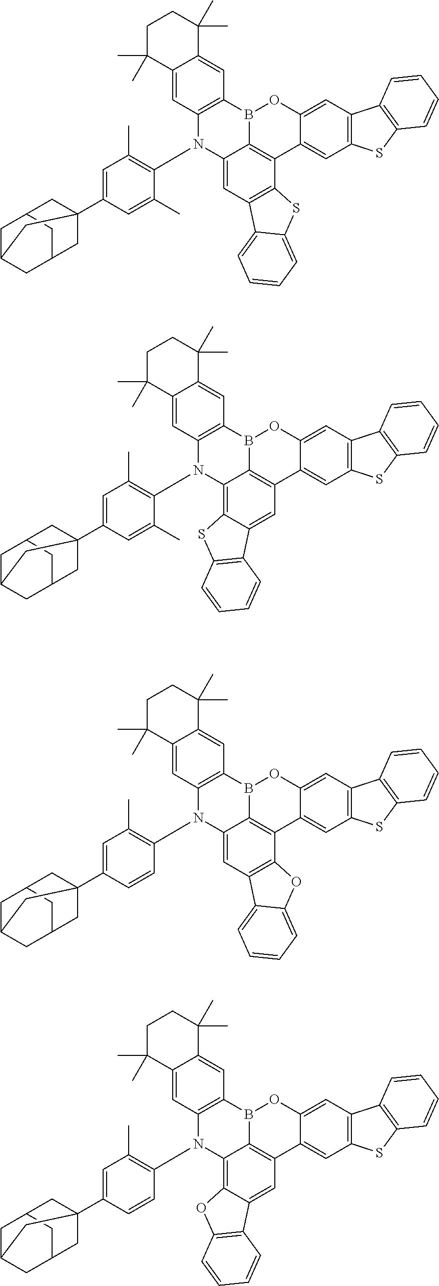 [SMILES: Cc1cc(C23CC4CC(CC(C4)C2)C3)cc(C)c1N1c2cc3c(cc2B2Oc4cc5c(cc4-c4c2c1cc1c4sc2ccccc21)sc1ccccc15)C(C)(C)CCC3(C)C ; Cc1cc(C23CC4CC(CC(C4)C2)C3)cc(C)c1N1c2cc3c(cc2B2Oc4cc5c(cc4-c4cc6c(sc7ccccc76)c1c42)sc1ccccc15)C(C)(C)CCC3(C)C ; Cc1cc(C23CC4CC(CC(C4)C2)C3)ccc1N1c2cc3c(cc2B2Oc4cc5c(cc4-c4c2c1cc1c4oc2ccccc21)sc1ccccc15)C(C)(C)CCC3(C)C ; Cc1cc(C23CC4CC(CC(C4)C2)C3)ccc1N1c2cc3c(cc2B2Oc4cc5c(cc4-c4cc6c(oc7ccccc76)c1c42)sc1ccccc15)C(C)(C)CCC3(C)C]

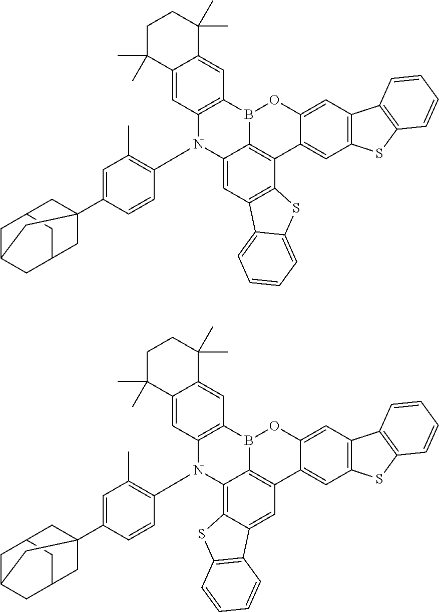 [SMILES: Cc1cc(C23CC4CC(CC(C4)C2)C3)ccc1N1c2cc3c(cc2B2Oc4cc5c(cc4-c4c2c1cc1c4sc2ccccc21)sc1ccccc15)C(C)(C)CCC3(C)C ; Cc1cc(C23CC4CC(CC(C4)C2)C3)ccc1N1c2cc3c(cc2B2Oc4cc5c(cc4-c4cc6c(sc7ccccc76)c1c42)sc1ccccc15)C(C)(C)CCC3(C)C]

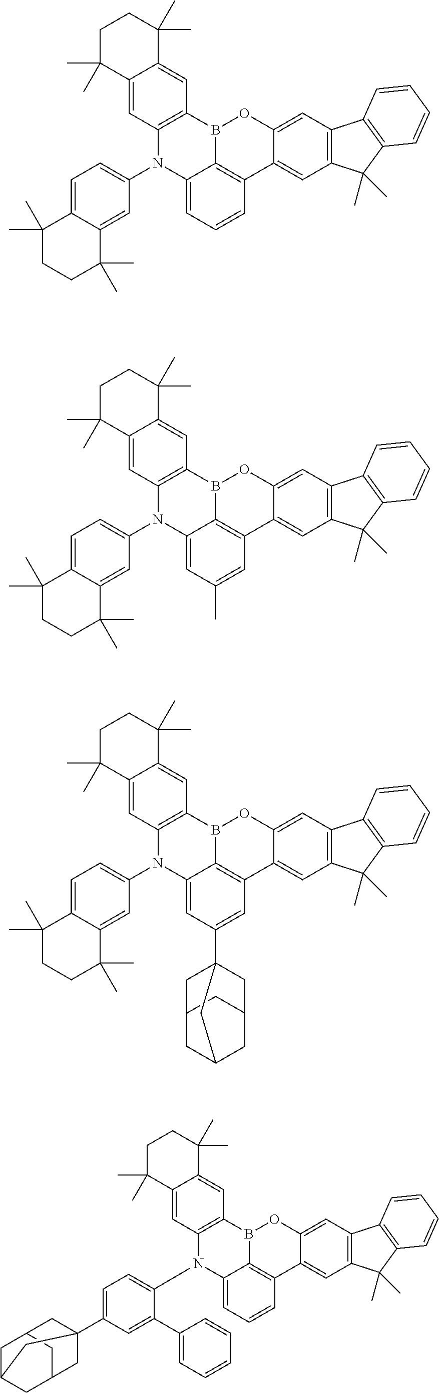 [SMILES: CC1(C)CCC(C)(C)c2cc(N3c4cc5c(cc4B4Oc6cc7c(cc6-c6cccc3c64)C(C)(C)c3ccccc3-7)C(C)(C)CCC5(C)C)ccc21 ; Cc1cc2c3c(c1)N(c1ccc4c(c1)C(C)(C)CCC4(C)C)c1cc4c(cc1B3Oc1cc3c(cc1-2)C(C)(C)c1ccccc1-3)C(C)(C)CCC4(C)C ; CC1(C)CCC(C)(C)c2cc(N3c4cc5c(cc4B4Oc6cc7c(cc6-c6cc(C89CC%10CC(CC(C%10)C8)C9)cc3c64)C(C)(C)c3ccccc3-7)C(C)(C)CCC5(C)C)ccc21 ; CC1(C)CCC(C)(C)c2cc3c(cc21)B1Oc2cc4c(cc2-c2cccc(c21)N3c1ccc(C23CC5CC(CC(C5)C2)C3)cc1-c1ccccc1)C(C)(C)c1ccccc1-4]

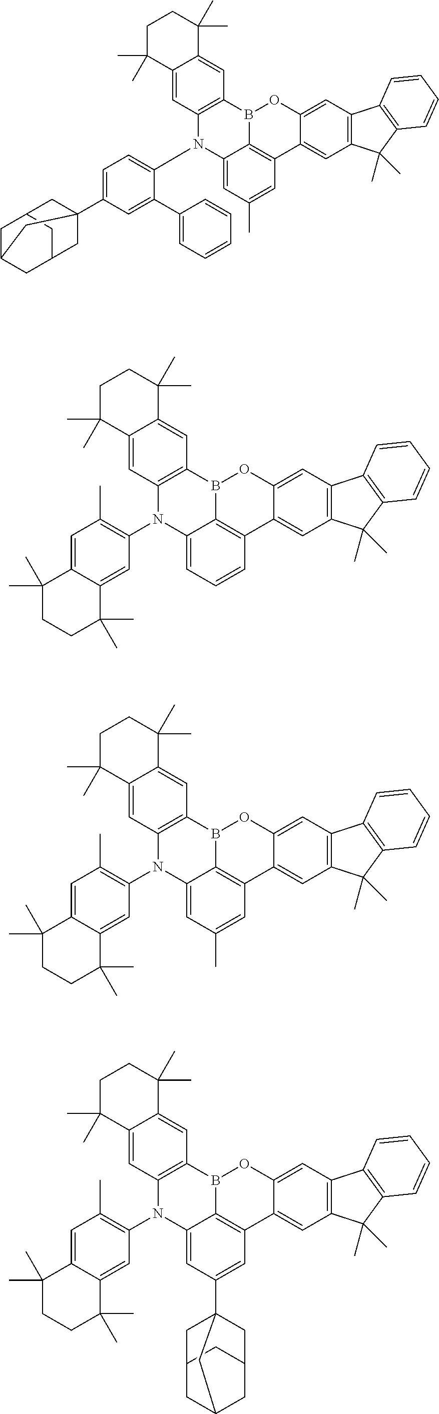 [SMILES: Cc1cc2c3c(c1)N(c1ccc(C45CC6CC(CC(C6)C4)C5)cc1-c1ccccc1)c1cc4c(cc1B3Oc1cc3c(cc1-2)C(C)(C)c1ccccc1-3)C(C)(C)CCC4(C)C ; Cc1cc2c(cc1N1c3cc4c(cc3B3Oc5cc6c(cc5-c5cccc1c53)C(C)(C)c1ccccc1-6)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Oc1cc3c(cc1-2)C(C)(C)c1ccccc1-3)C(C)(C)CCC4(C)C ; Cc1cc2c(cc1N1c3cc4c(cc3B3Oc5cc6c(cc5-c5cc(C78CC9CC(CC(C9)C7)C8)cc1c53)C(C)(C)c1ccccc1-6)C(C)(C)CCC4(C)C)C(C)(C)CCC2(C)C]

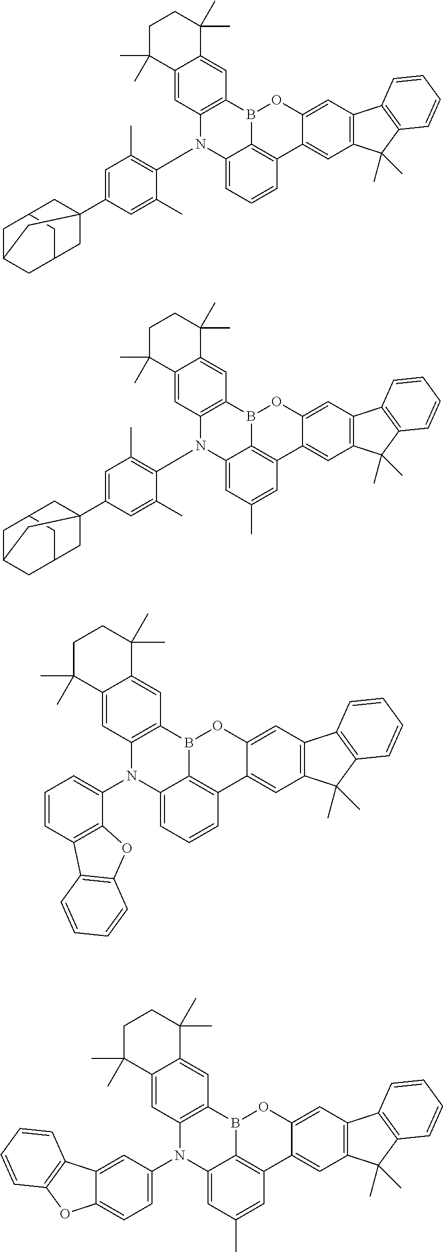 [SMILES: Cc1cc(C23CC4CC(CC(C4)C2)C3)cc(C)c1N1c2cc3c(cc2B2Oc4cc5c(cc4-c4cccc1c42)C(C)(C)c1ccccc1-5)C(C)(C)CCC3(C)C ; Cc1cc2c3c(c1)N(c1c(C)cc(C45CC6CC(CC(C6)C4)C5)cc1C)c1cc4c(cc1B3Oc1cc3c(cc1-2)C(C)(C)c1ccccc1-3)C(C)(C)CCC4(C)C ; CC1(C)CCC(C)(C)c2cc3c(cc21)B1Oc2cc4c(cc2-c2cccc(c21)N3c1cccc2c1oc1ccccc12)C(C)(C)c1ccccc1-4 ; Cc1cc2c3c(c1)N(c1ccc4oc5ccccc5c4c1)c1cc4c(cc1B3Oc1cc3c(cc1-2)C(C)(C)c1ccccc1-3)C(C)(C)CCC4(C)C]

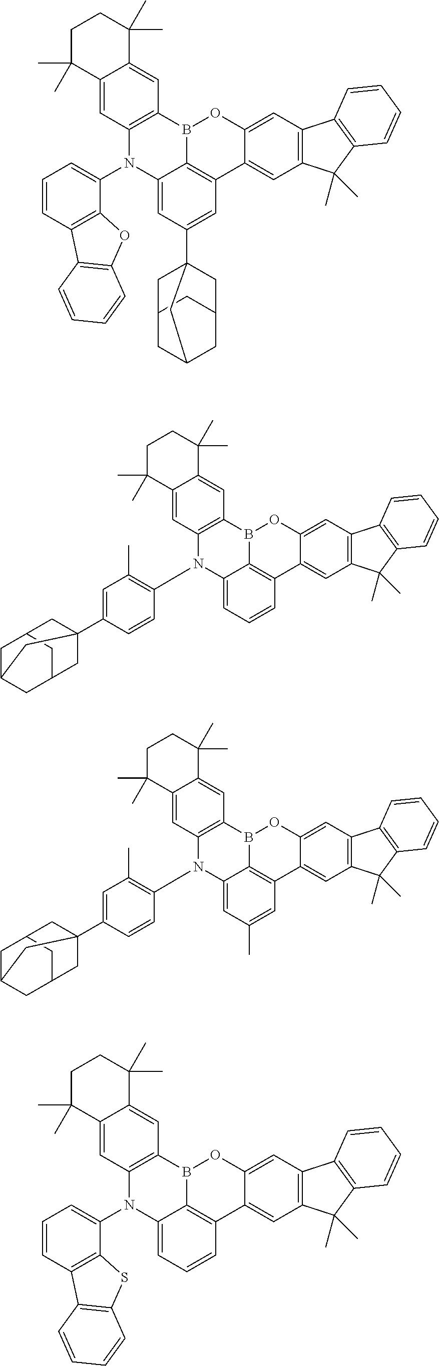 [SMILES: CC1(C)CCC(C)(C)c2cc3c(cc21)B1Oc2cc4c(cc2-c2cc(C56CC7CC(CC(C7)C5)C6)cc(c21)N3c1cccc2c1oc1ccccc12)C(C)(C)c1ccccc1-4 ; Cc1cc(C23CC4CC(CC(C4)C2)C3)ccc1N1c2cc3c(cc2B2Oc4cc5c(cc4-c4cccc1c42)C(C)(C)c1ccccc1-5)C(C)(C)CCC3(C)C ; Cc1cc2c3c(c1)N(c1ccc(C45CC6CC(CC(C6)C4)C5)cc1C)c1cc4c(cc1B3Oc1cc3c(cc1-2)C(C)(C)c1ccccc1-3)C(C)(C)CCC4(C)C ; CC1(C)CCC(C)(C)c2cc3c(cc21)B1Oc2cc4c(cc2-c2cccc(c21)N3c1cccc2c1sc1ccccc12)C(C)(C)c1ccccc1-4]

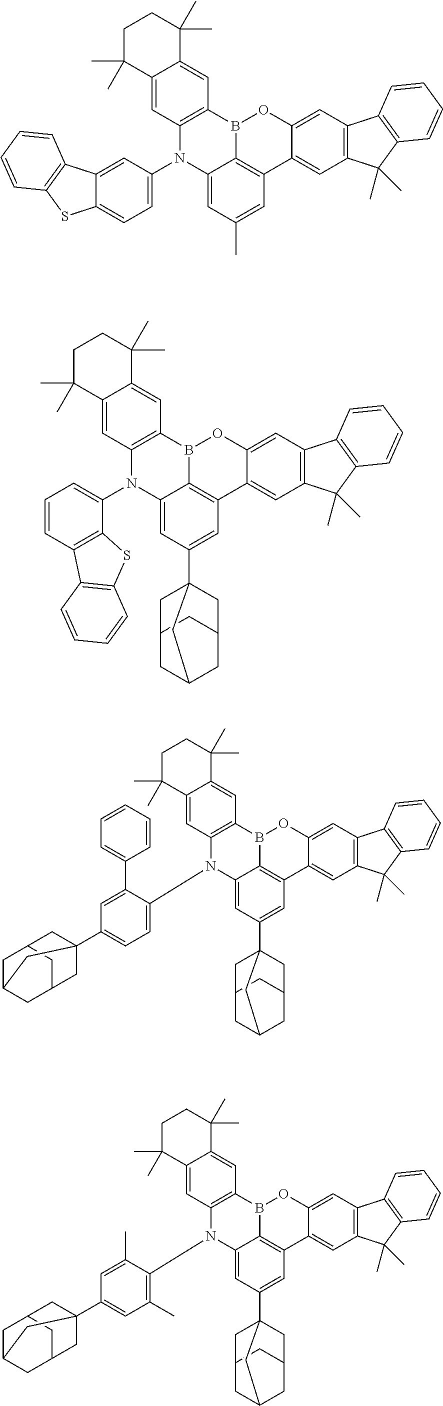 [SMILES: Cc1cc2c3c(c1)N(c1ccc4sc5ccccc5c4c1)c1cc4c(cc1B3Oc1cc3c(cc1-2)C(C)(C)c1ccccc1-3)C(C)(C)CCC4(C)C ; CC1(C)CCC(C)(C)c2cc3c(cc21)B1Oc2cc4c(cc2-c2cc(C56CC7CC(CC(C7)C5)C6)cc(c21)N3c1cccc2c1sc1ccccc12)C(C)(C)c1ccccc1-4 ; CC1(C)CCC(C)(C)c2cc3c(cc21)B1Oc2cc4c(cc2-c2cc(C56CC7CC(CC(C7)C5)C6)cc(c21)N3c1ccc(C23CC5CC(CC(C5)C2)C3)cc1-c1ccccc1)C(C)(C)c1ccccc1-4 ; Cc1cc(C23CC4CC(CC(C4)C2)C3)cc(C)c1N1c2cc3c(cc2B2Oc4cc5c(cc4-c4cc(C67CC8CC(CC(C8)C6)C7)cc1c42)C(C)(C)c1ccccc1-5)C(C)(C)CCC3(C)C]

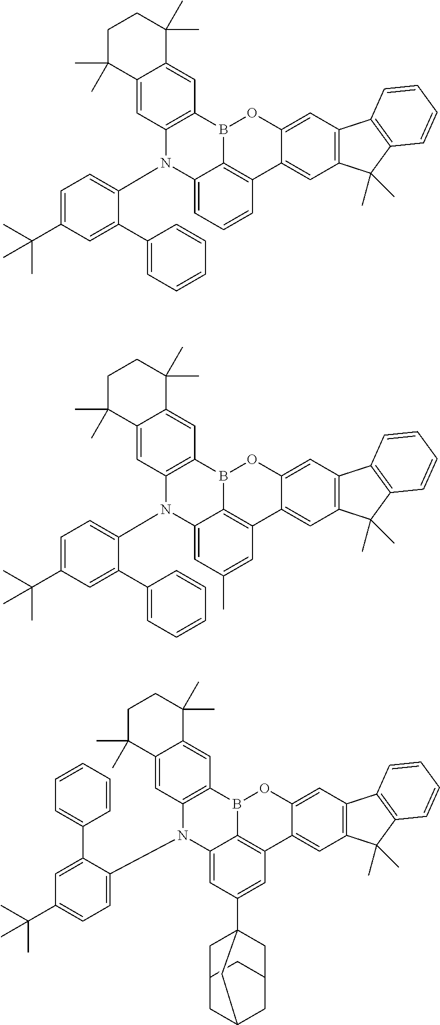 [SMILES: CC(C)(C)c1ccc(N2c3cc4c(cc3B3Oc5cc6c(cc5-c5cccc2c53)C(C)(C)c2ccccc2-6)C(C)(C)CCC4(C)C)c(-c2ccccc2)c1 ; Cc1cc2c3c(c1)N(c1ccc(C(C)(C)C)cc1-c1ccccc1)c1cc4c(cc1B3Oc1cc3c(cc1-2)C(C)(C)c1ccccc1-3)C(C)(C)CCC4(C)C ; CC(C)(C)c1ccc(N2c3cc4c(cc3B3Oc5cc6c(cc5-c5cc(C78CC9CC(CC(C9)C7)C8)cc2c53)C(C)(C)c2ccccc2-6)C(C)(C)CCC4(C)C)c(-c2ccccc2)c1]

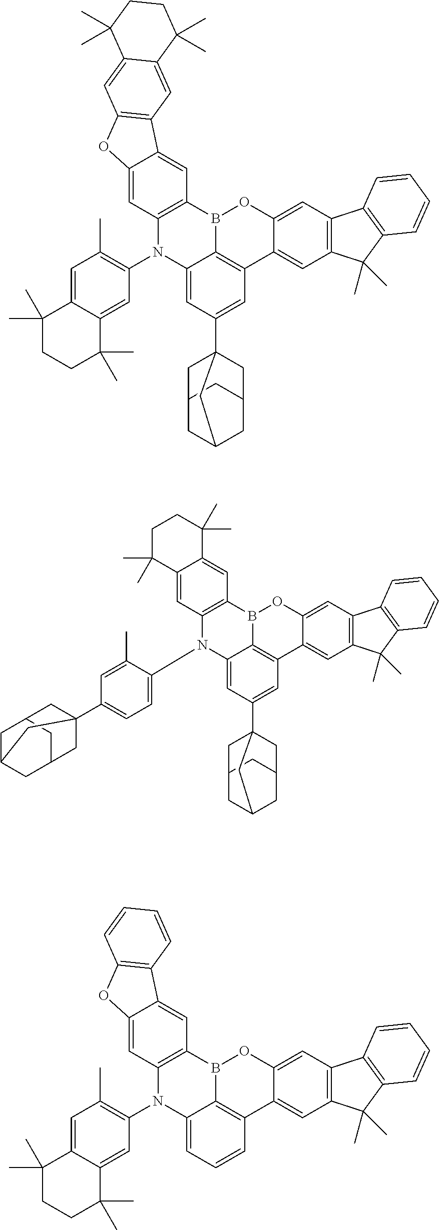 [SMILES: Cc1cc2c(cc1N1c3cc4oc5cc6c(cc5c4cc3B3Oc4cc5c(cc4-c4cc(C78CC9CC(CC(C9)C7)C8)cc1c43)C(C)(C)c1ccccc1-5)C(C)(C)CCC6(C)C)C(C)(C)CCC2(C)C ; Cc1cc(C23CC4CC(CC(C4)C2)C3)ccc1N1c2cc3c(cc2B2Oc4cc5c(cc4-c4cc(C67CC8CC(CC(C8)C6)C7)cc1c42)C(C)(C)c1ccccc1-5)C(C)(C)CCC3(C)C ; Cc1cc2c(cc1N1c3cc4oc5ccccc5c4cc3B3Oc4cc5c(cc4-c4cccc1c43)C(C)(C)c1ccccc1-5)C(C)(C)CCC2(C)C]

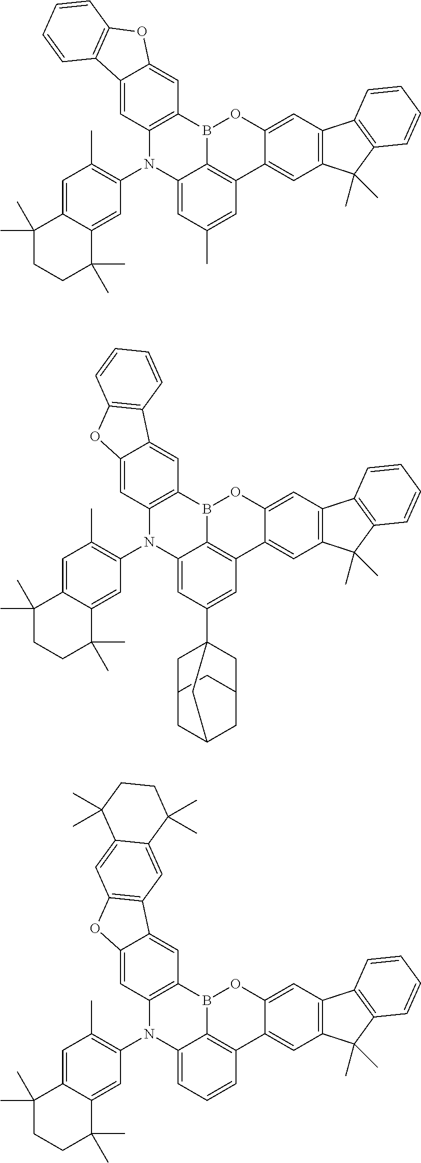 [SMILES: Cc1cc2c3c(c1)N(c1cc4c(cc1C)C(C)(C)CCC4(C)C)c1cc4c(cc1B3Oc1cc3c(cc1-2)C(C)(C)c1ccccc1-3)oc1ccccc14 ; Cc1cc2c(cc1N1c3cc4oc5ccccc5c4cc3B3Oc4cc5c(cc4-c4cc(C67CC8CC(CC(C8)C6)C7)cc1c43)C(C)(C)c1ccccc1-5)C(C)(C)CCC2(C)C ; Cc1cc2c(cc1N1c3cc4oc5cc6c(cc5c4cc3B3Oc4cc5c(cc4-c4cccc1c43)C(C)(C)c1ccccc1-5)C(C)(C)CCC6(C)C)C(C)(C)CCC2(C)C]

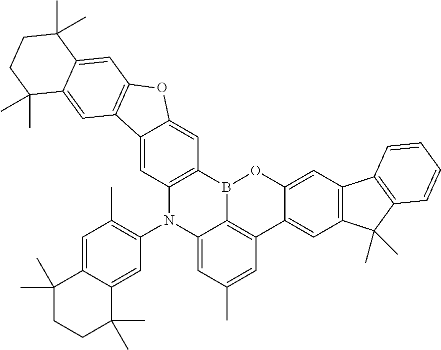 [SMILES: Cc1cc2c3c(c1)N(c1cc4c(cc1C)C(C)(C)CCC4(C)C)c1cc4c(cc1B3Oc1cc3c(cc1-2)C(C)(C)c1ccccc1-3)oc1cc2c(cc14)C(C)(C)CCC2(C)C]

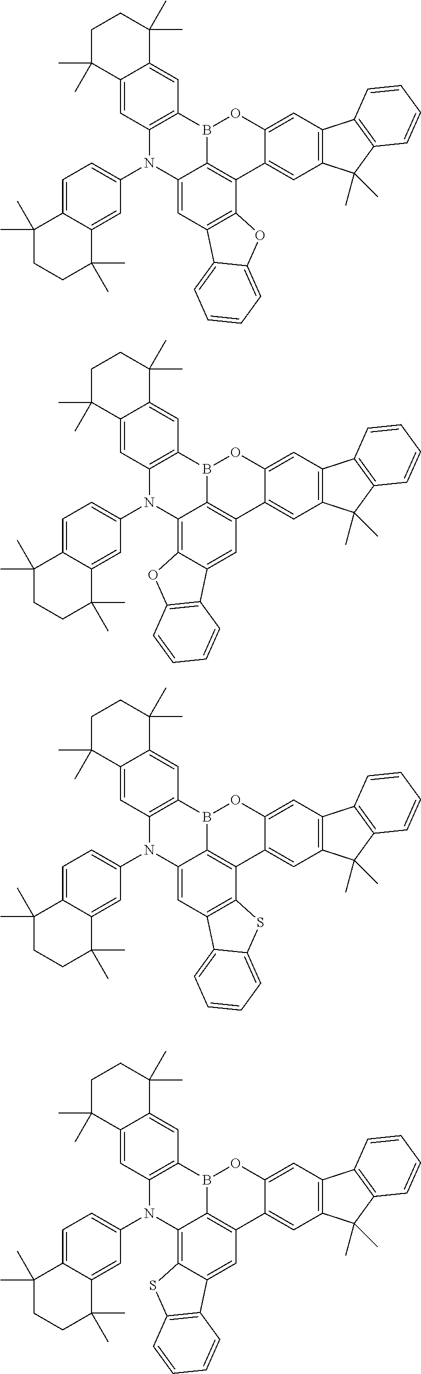

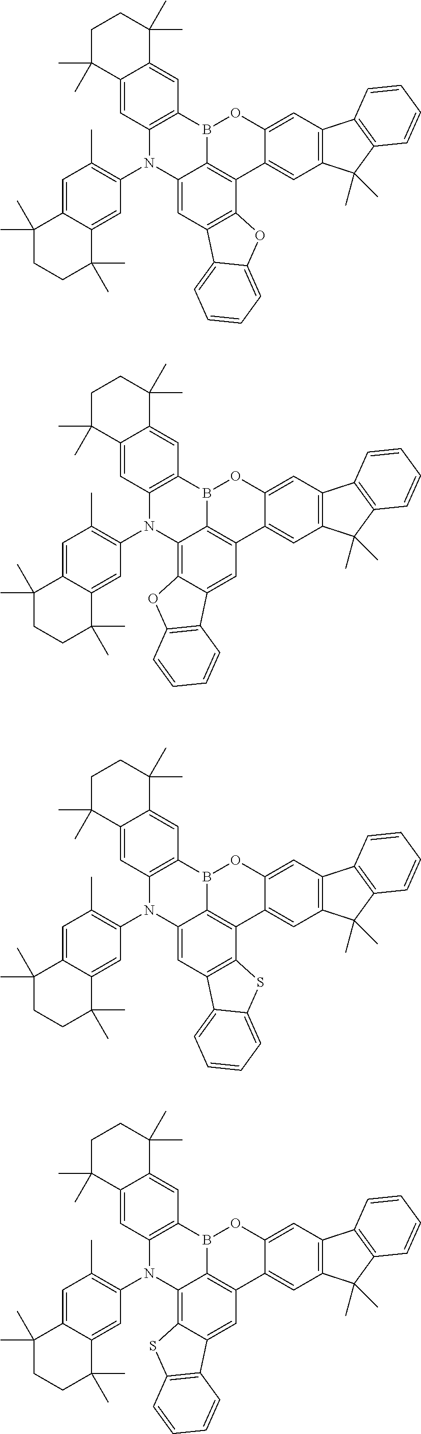 [SMILES: Cc1cc2c(cc1N1c3cc4c(cc3B3Oc5cc6c(cc5-c5c3c1cc1c5oc3ccccc31)C(C)(C)c1ccccc1-6)C(C)(C)CCC4(C)C)C(C)(C)CCC2(C)C ; Cc1cc2c(cc1N1c3cc4c(cc3B3Oc5cc6c(cc5-c5cc7c(oc8ccccc87)c1c53)C(C)(C)c1ccccc1-6)C(C)(C)CCC4(C)C)C(C)(C)CCC2(C)C ; Cc1cc2c(cc1N1c3cc4c(cc3B3Oc5cc6c(cc5-c5c3c1cc1c5sc3ccccc31)C(C)(C)c1ccccc1-6)C(C)(C)CCC4(C)C)C(C)(C)CCC2(C)C ; Cc1cc2c(cc1N1c3cc4c(cc3B3Oc5cc6c(cc5-c5cc7c(sc8ccccc87)c1c53)C(C)(C)c1ccccc1-6)C(C)(C)CCC4(C)C)C(C)(C)CCC2(C)C]

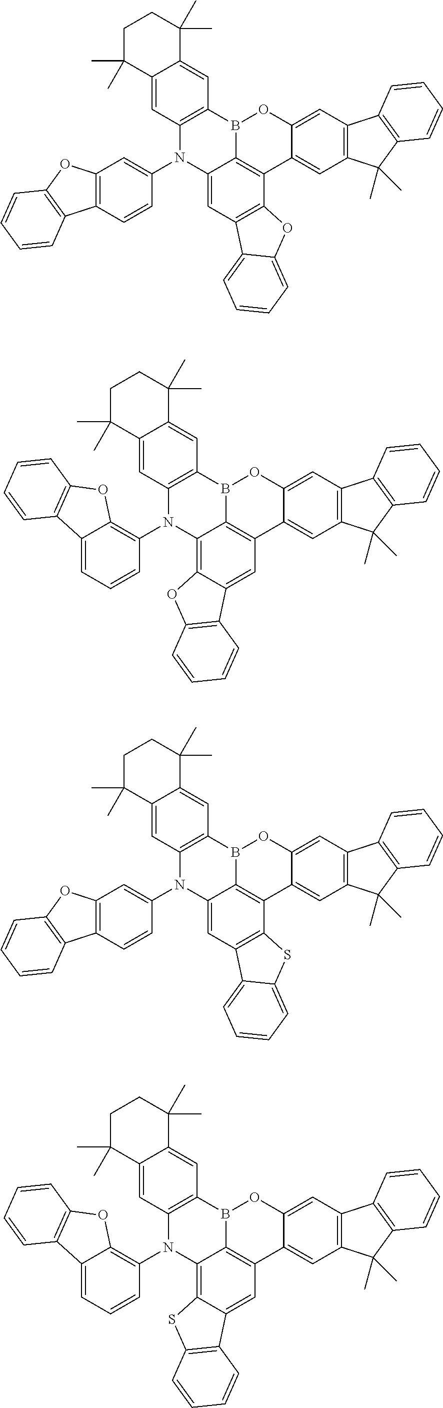

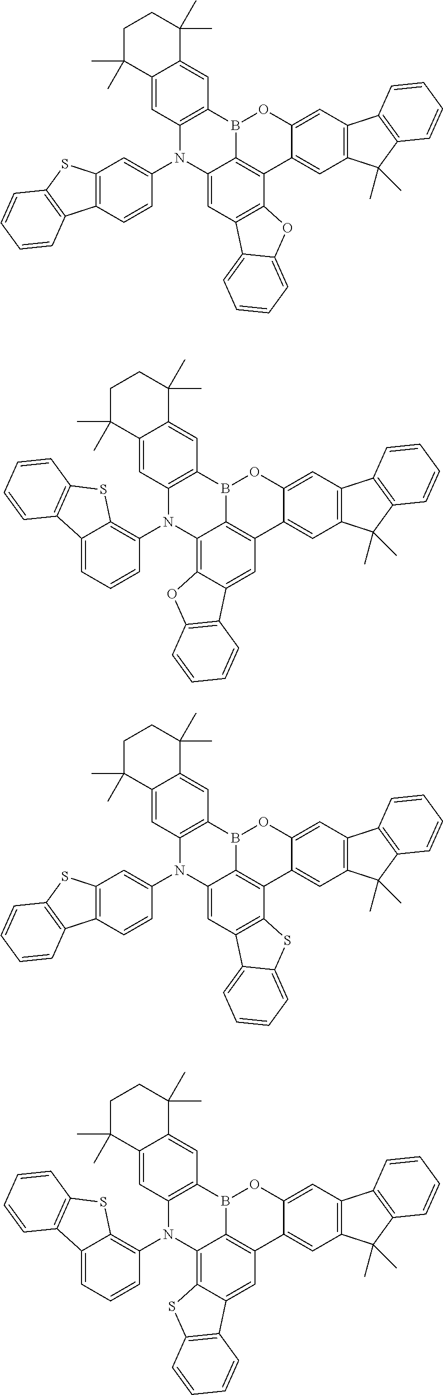

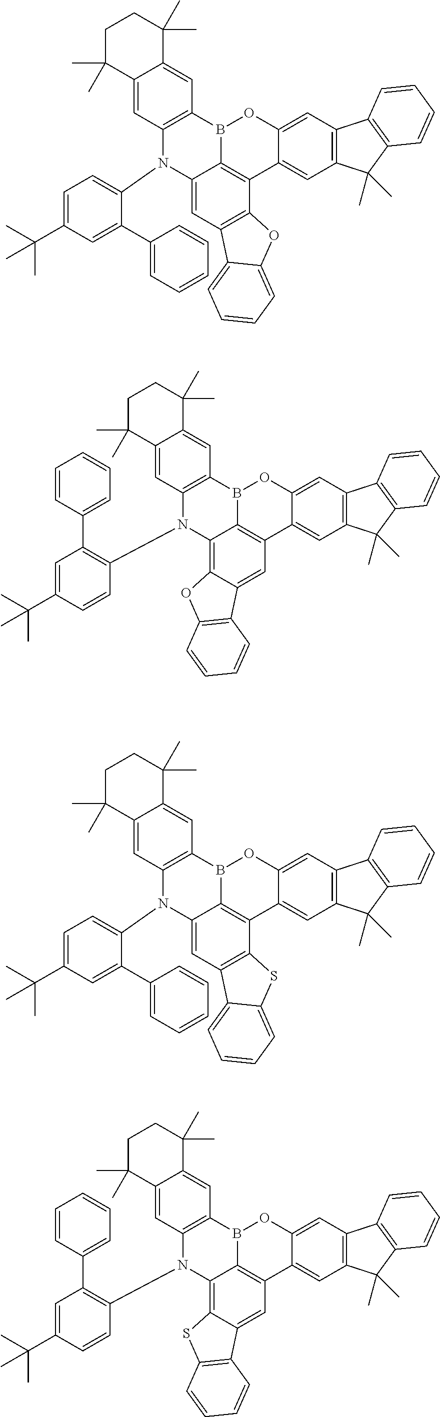 [SMILES: CC(C)(C)c1ccc(N2c3cc4c(cc3B3Oc5cc6c(cc5-c5c3c2cc2c5oc3ccccc32)C(C)(C)c2ccccc2-6)C(C)(C)CCC4(C)C)c(-c2ccccc2)c1 ; CC(C)(C)c1ccc(N2c3cc4c(cc3B3Oc5cc6c(cc5-c5cc7c(oc8ccccc87)c2c53)C(C)(C)c2ccccc2-6)C(C)(C)CCC4(C)C)c(-c2ccccc2)c1 ; CC(C)(C)c1ccc(N2c3cc4c(cc3B3Oc5cc6c(cc5-c5c3c2cc2c5sc3ccccc32)C(C)(C)c2ccccc2-6)C(C)(C)CCC4(C)C)c(-c2ccccc2)c1 ; CC(C)(C)c1ccc(N2c3cc4c(cc3B3Oc5cc6c(cc5-c5cc7c(sc8ccccc87)c2c53)C(C)(C)c2ccccc2-6)C(C)(C)CCC4(C)C)c(-c2ccccc2)c1]

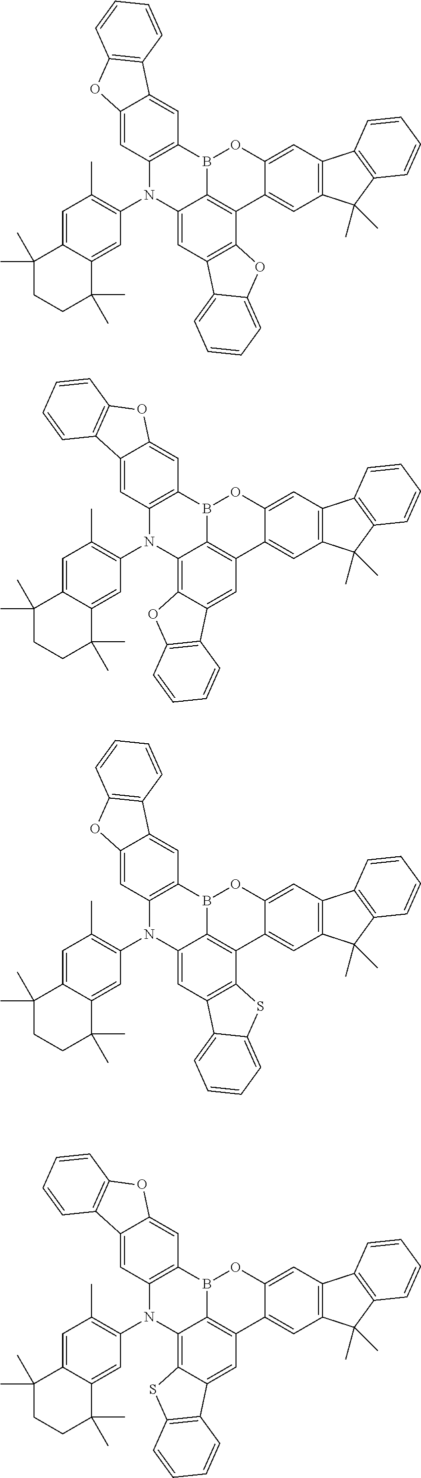 [SMILES: Cc1cc2c(cc1N1c3cc4oc5ccccc5c4cc3B3Oc4cc5c(cc4-c4c3c1cc1c4oc3ccccc31)C(C)(C)c1ccccc1-5)C(C)(C)CCC2(C)C ; Cc1cc2c(cc1N1c3cc4c(cc3B3Oc5cc6c(cc5-c5cc7c(oc8ccccc87)c1c53)C(C)(C)c1ccccc1-6)oc1ccccc14)C(C)(C)CCC2(C)C ; Cc1cc2c(cc1N1c3cc4oc5ccccc5c4cc3B3Oc4cc5c(cc4-c4c3c1cc1c4sc3ccccc31)C(C)(C)c1ccccc1-5)C(C)(C)CCC2(C)C ; Cc1cc2c(cc1N1c3cc4c(cc3B3Oc5cc6c(cc5-c5cc7c(sc8ccccc87)c1c53)C(C)(C)c1ccccc1-6)oc1ccccc14)C(C)(C)CCC2(C)C]

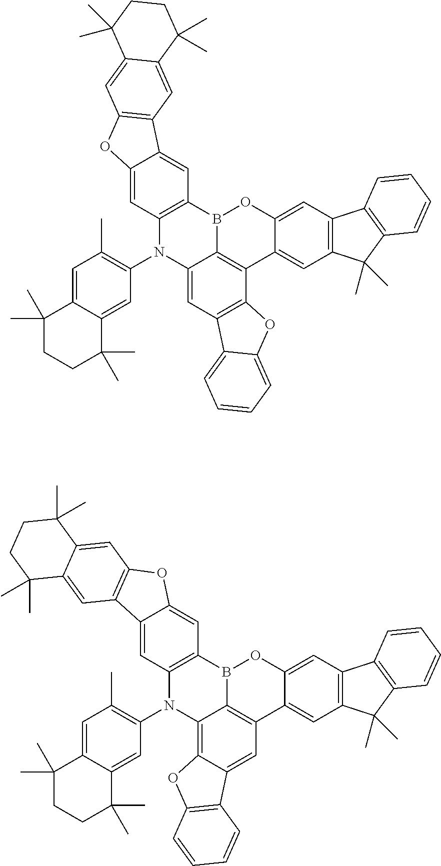 [SMILES: Cc1cc2c(cc1N1c3cc4oc5cc6c(cc5c4cc3B3Oc4cc5c(cc4-c4c3c1cc1c4oc3ccccc31)C(C)(C)c1ccccc1-5)C(C)(C)CCC6(C)C)C(C)(C)CCC2(C)C ; Cc1cc2c(cc1N1c3cc4c(cc3B3Oc5cc6c(cc5-c5cc7c(oc8ccccc87)c1c53)C(C)(C)c1ccccc1-6)oc1cc3c(cc14)C(C)(C)CCC3(C)C)C(C)(C)CCC2(C)C]

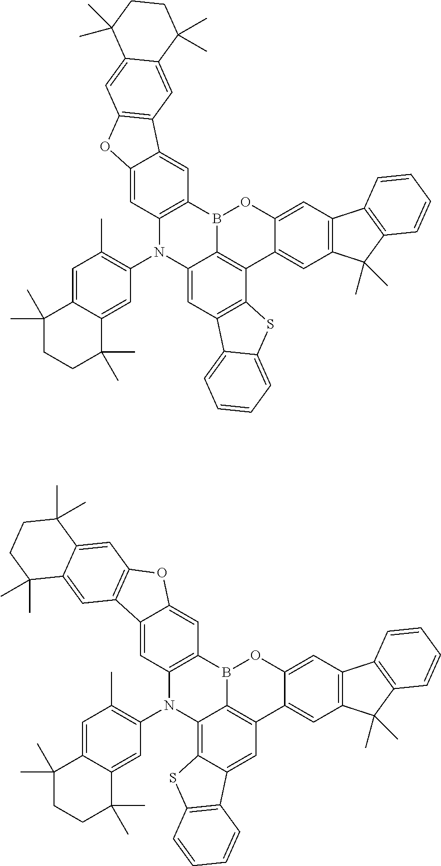 [SMILES: Cc1cc2c(cc1N1c3cc4oc5cc6c(cc5c4cc3B3Oc4cc5c(cc4-c4c3c1cc1c4sc3ccccc31)C(C)(C)c1ccccc1-5)C(C)(C)CCC6(C)C)C(C)(C)CCC2(C)C ; Cc1cc2c(cc1N1c3cc4c(cc3B3Oc5cc6c(cc5-c5cc7c(sc8ccccc87)c1c53)C(C)(C)c1ccccc1-6)oc1cc3c(cc14)C(C)(C)CCC3(C)C)C(C)(C)CCC2(C)C]

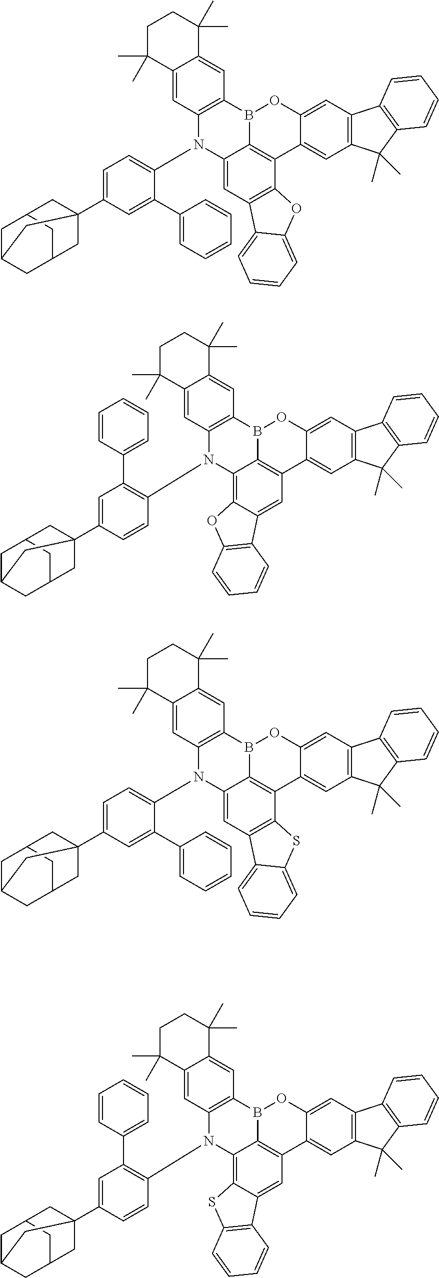

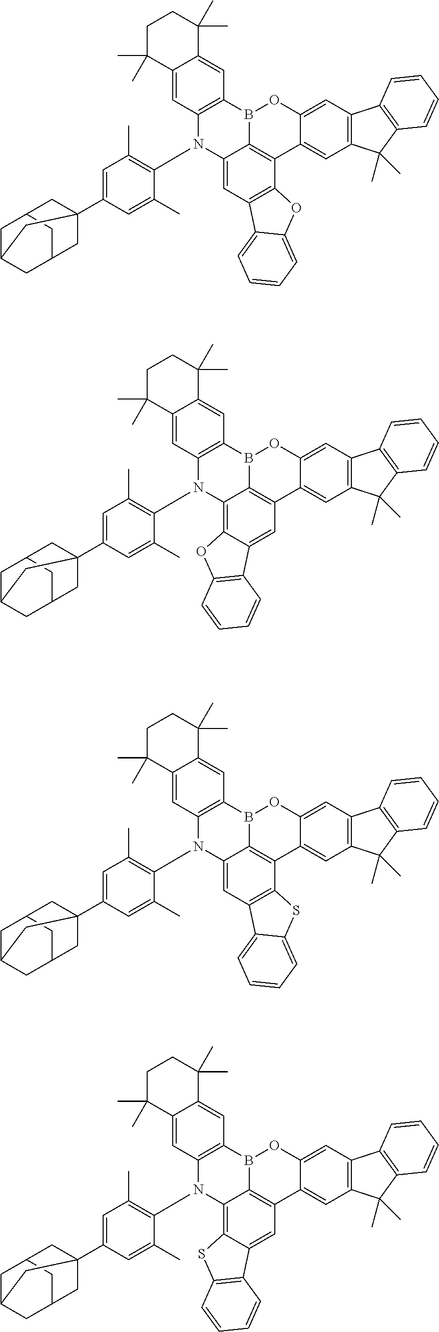 [SMILES: Cc1cc(C23CC4CC(CC(C4)C2)C3)cc(C)c1N1c2cc3c(cc2B2Oc4cc5c(cc4-c4c2c1cc1c4oc2ccccc21)C(C)(C)c1ccccc1-5)C(C)(C)CCC3(C)C ; Cc1cc(C23CC4CC(CC(C4)C2)C3)cc(C)c1N1c2cc3c(cc2B2Oc4cc5c(cc4-c4cc6c(oc7ccccc76)c1c42)C(C)(C)c1ccccc1-5)C(C)(C)CCC3(C)C ; Cc1cc(C23CC4CC(CC(C4)C2)C3)cc(C)c1N1c2cc3c(cc2B2Oc4cc5c(cc4-c4c2c1cc1c4sc2ccccc21)C(C)(C)c1ccccc1-5)C(C)(C)CCC3(C)C ; Cc1cc(C23CC4CC(CC(C4)C2)C3)cc(C)c1N1c2cc3c(cc2B2Oc4cc5c(cc4-c4cc6c(sc7ccccc76)c1c42)C(C)(C)c1ccccc1-5)C(C)(C)CCC3(C)C]

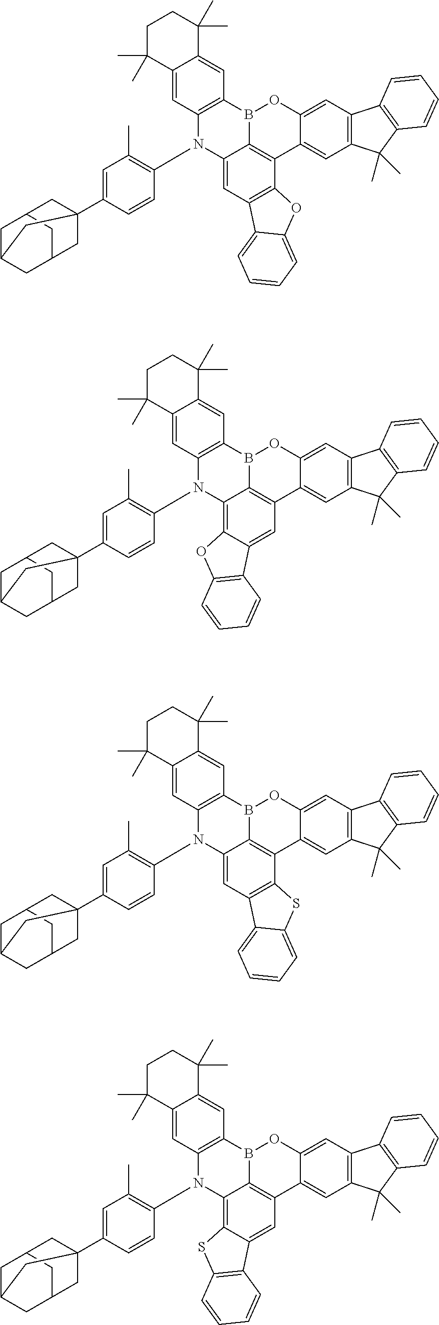 [SMILES: Cc1cc(C23CC4CC(CC(C4)C2)C3)ccc1N1c2cc3c(cc2B2Oc4cc5c(cc4-c4c2c1cc1c4oc2ccccc21)C(C)(C)c1ccccc1-5)C(C)(C)CCC3(C)C ; Cc1cc(C23CC4CC(CC(C4)C2)C3)ccc1N1c2cc3c(cc2B2Oc4cc5c(cc4-c4cc6c(oc7ccccc76)c1c42)C(C)(C)c1ccccc1-5)C(C)(C)CCC3(C)C ; Cc1cc(C23CC4CC(CC(C4)C2)C3)ccc1N1c2cc3c(cc2B2Oc4cc5c(cc4-c4c2c1cc1c4sc2ccccc21)C(C)(C)c1ccccc1-5)C(C)(C)CCC3(C)C ; Cc1cc(C23CC4CC(CC(C4)C2)C3)ccc1N1c2cc3c(cc2B2Oc4cc5c(cc4-c4cc6c(sc7ccccc76)c1c42)C(C)(C)c1ccccc1-5)C(C)(C)CCC3(C)C]

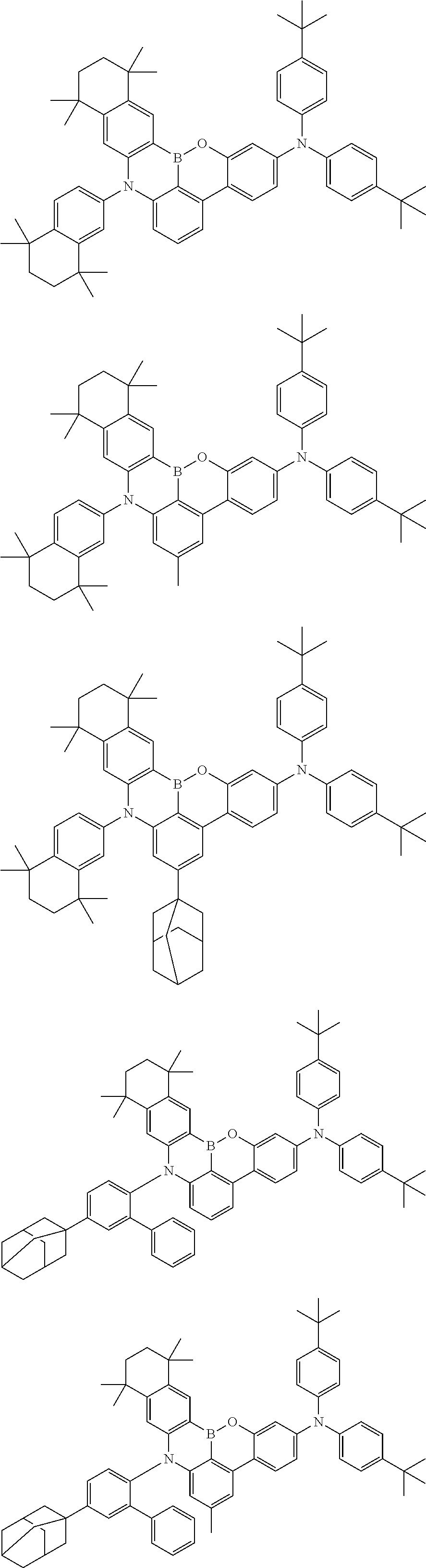

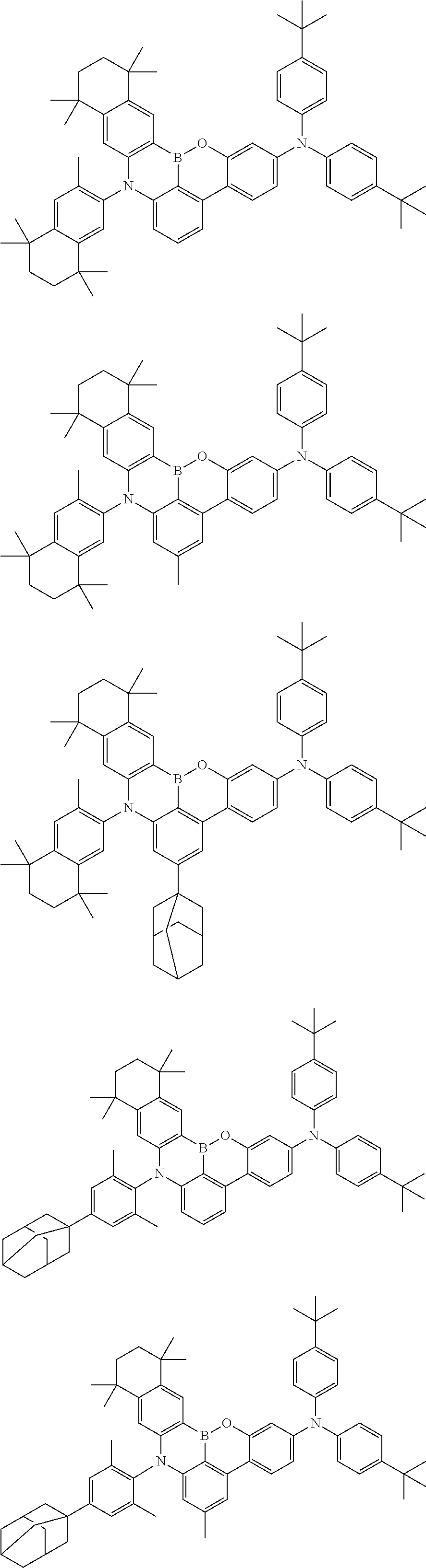

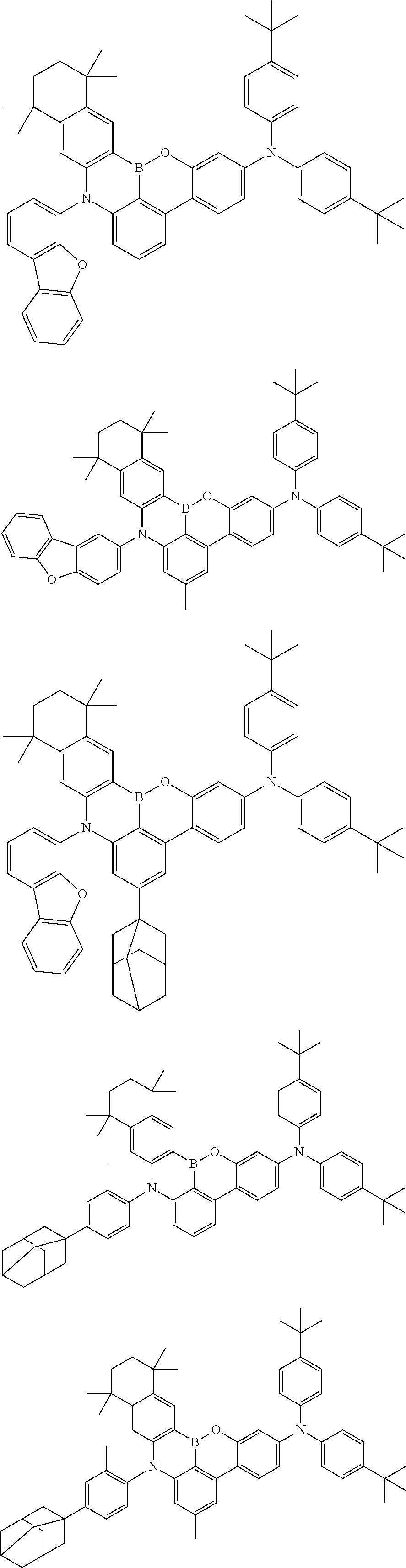

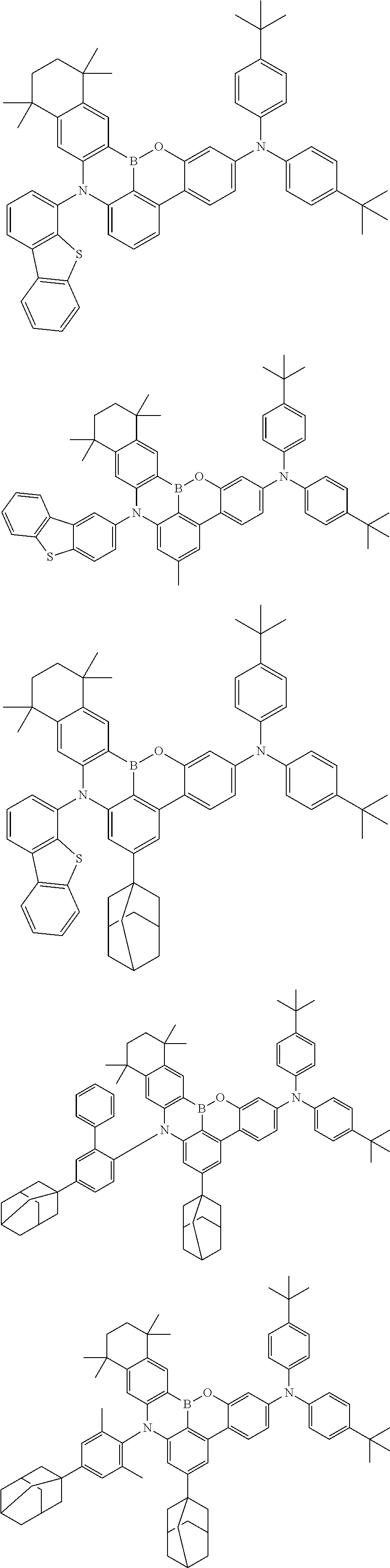

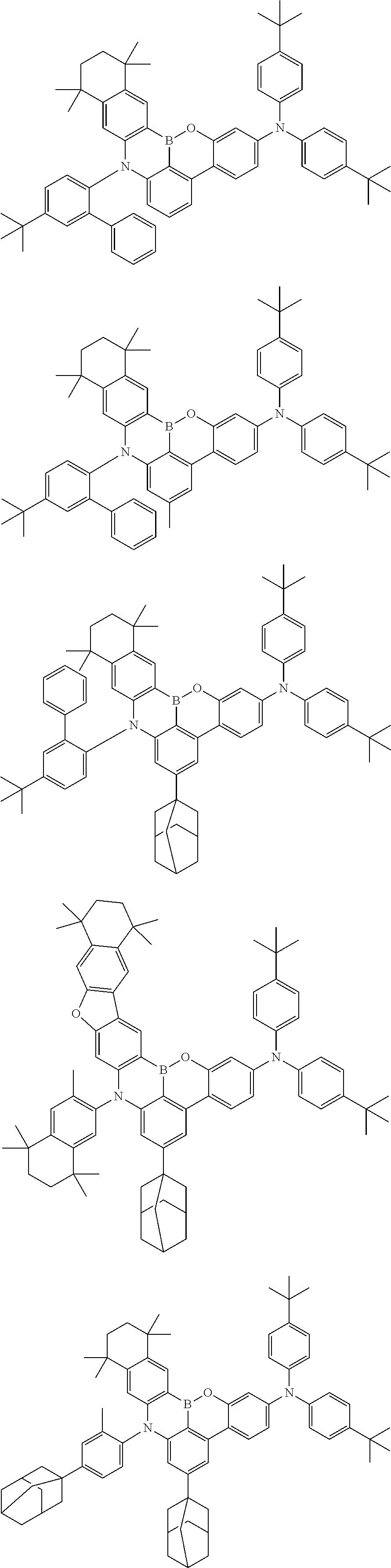

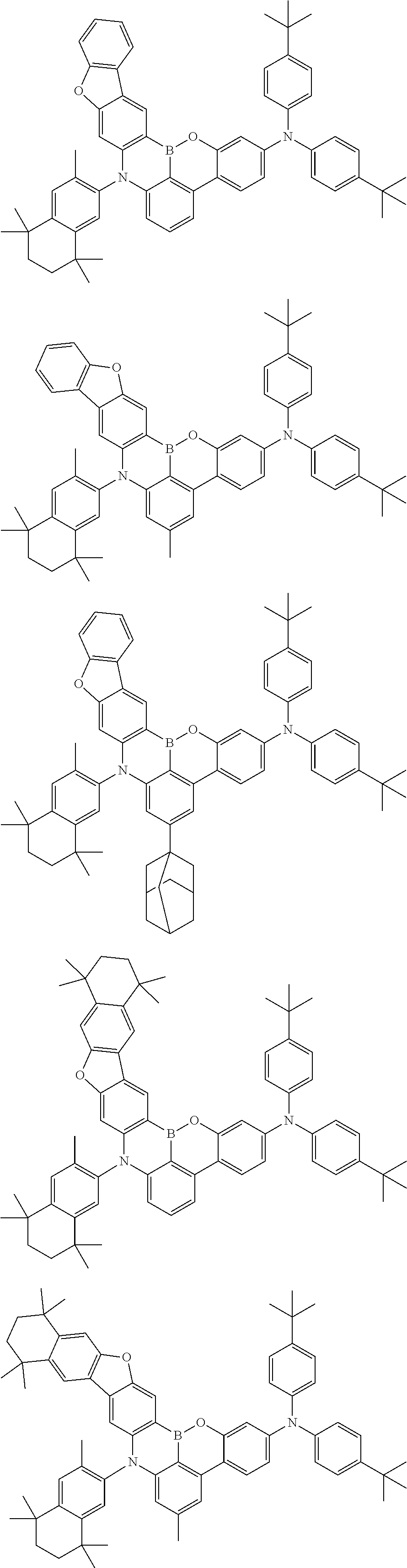

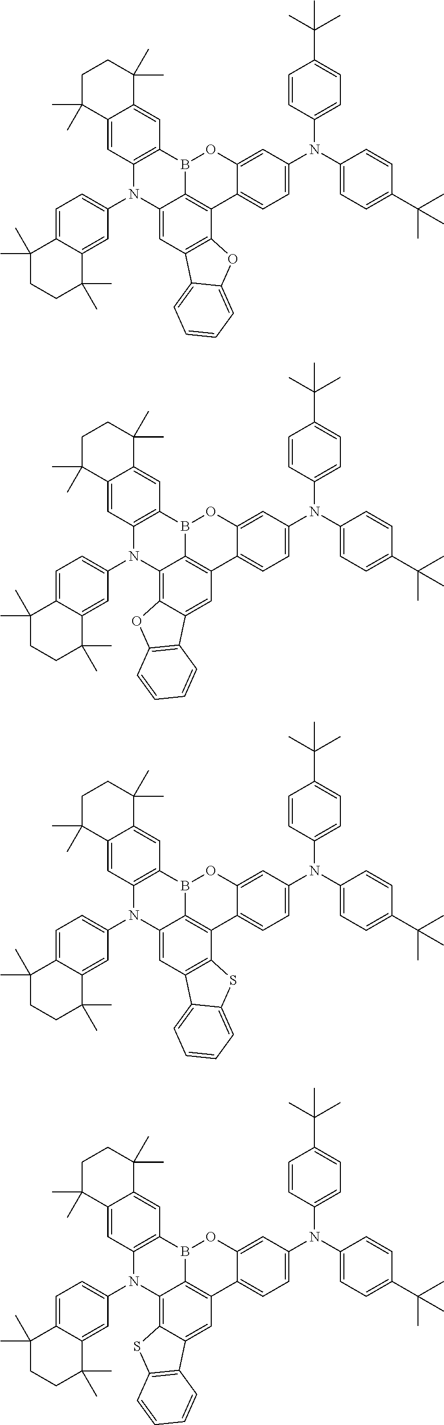

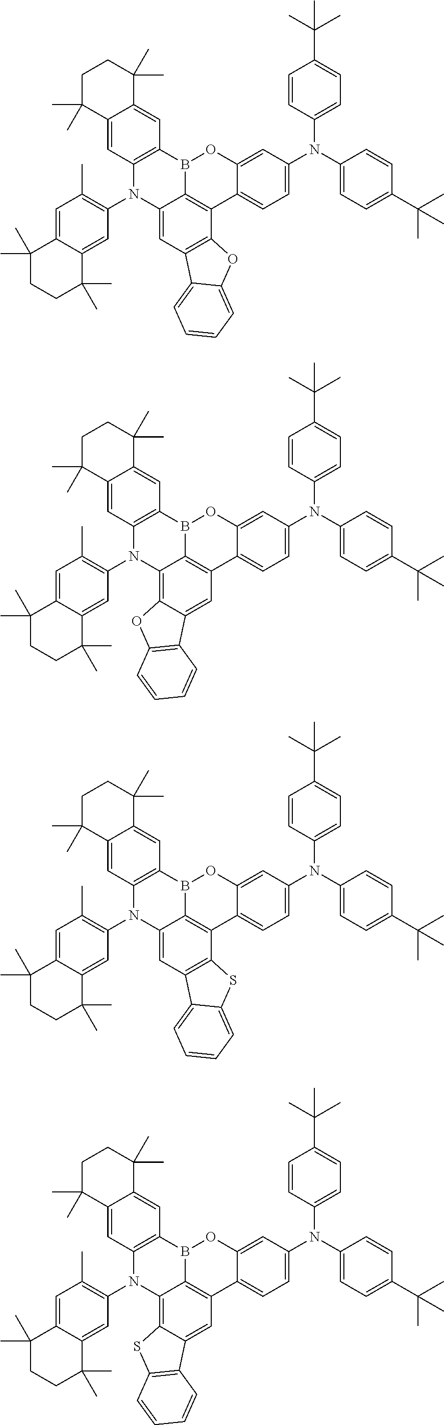

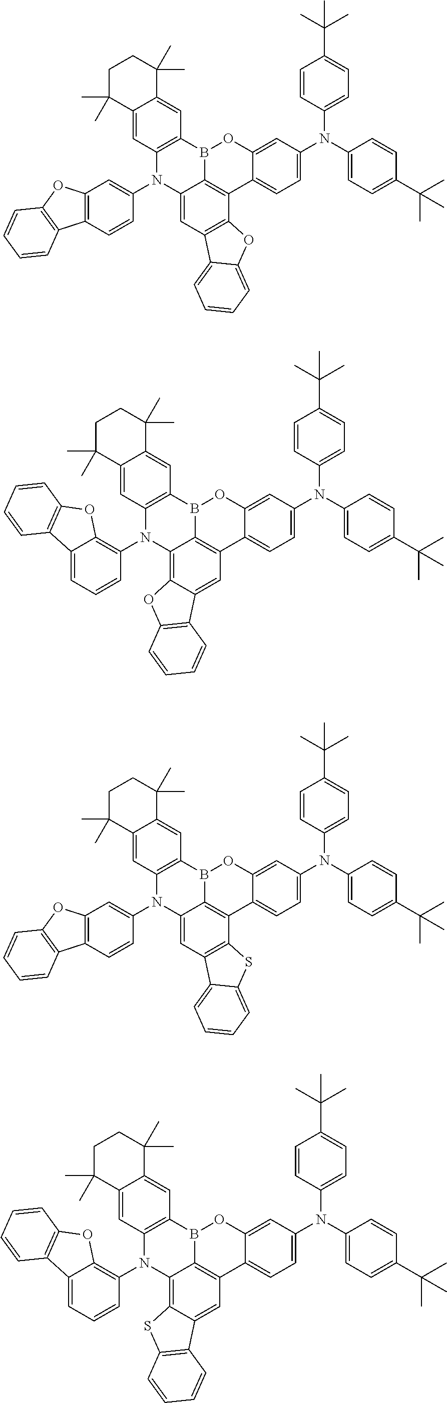

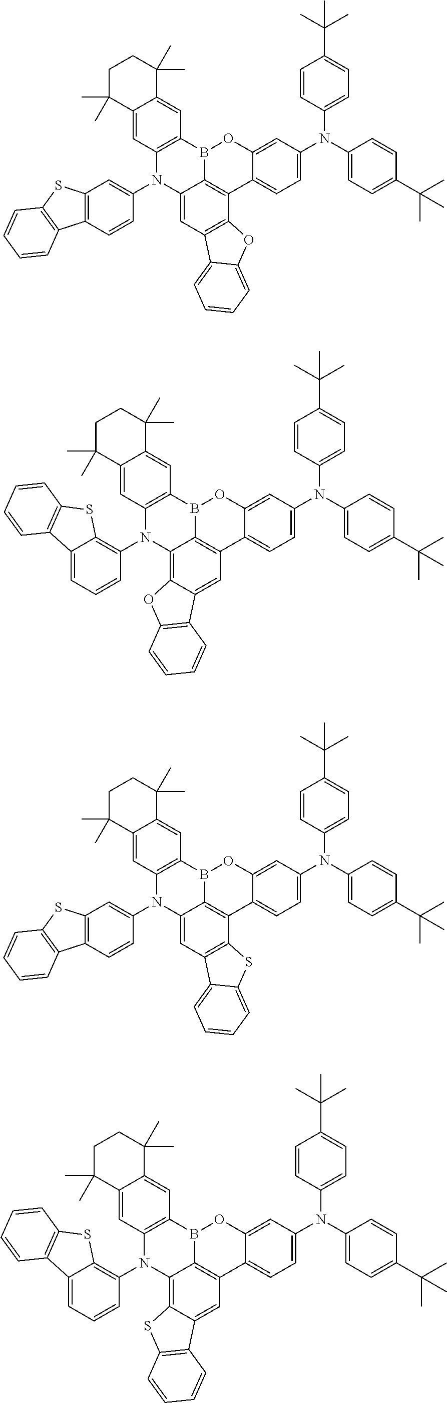

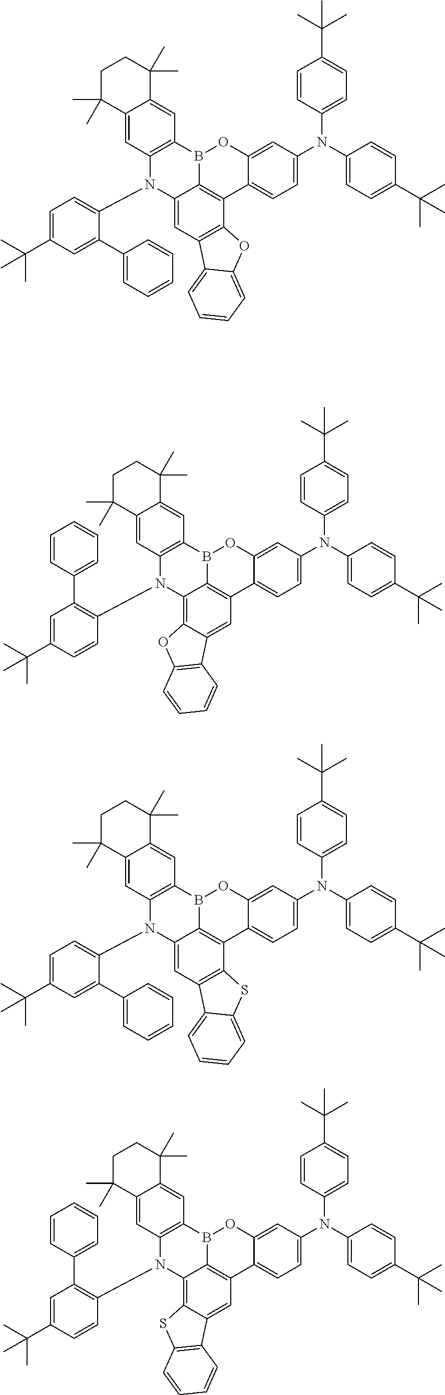

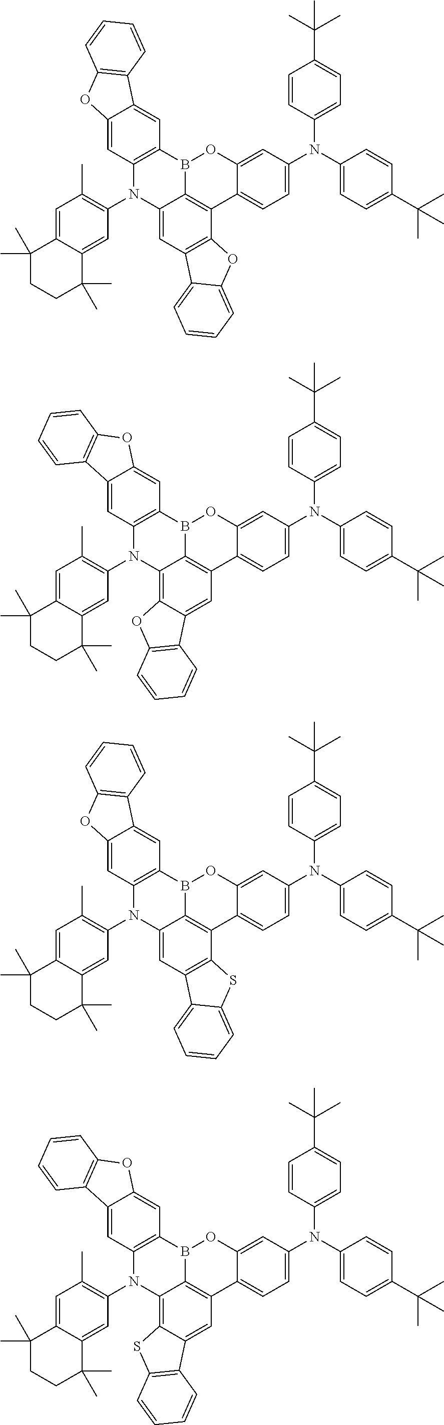

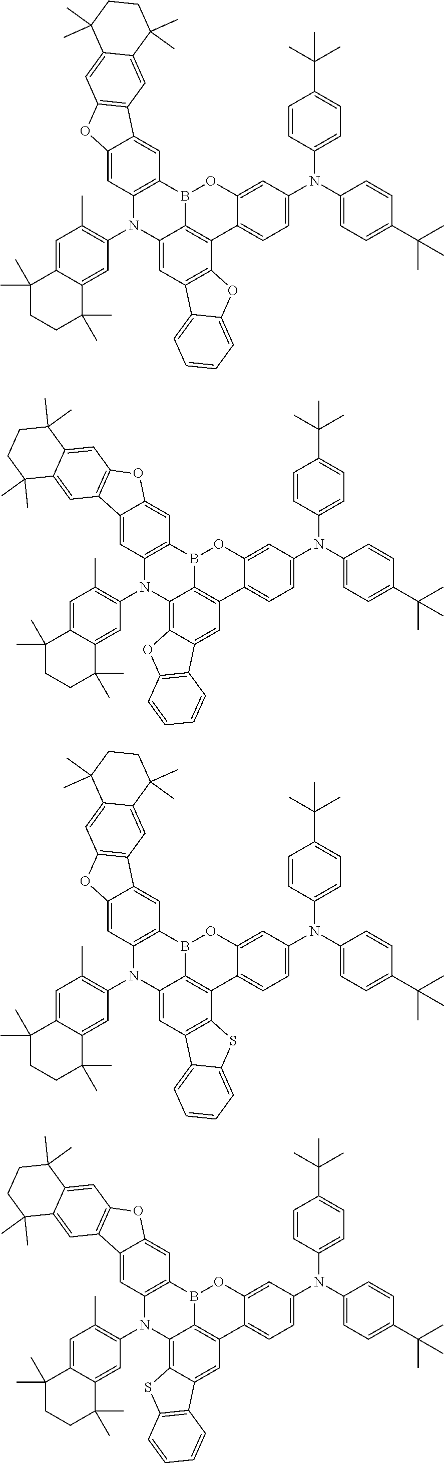

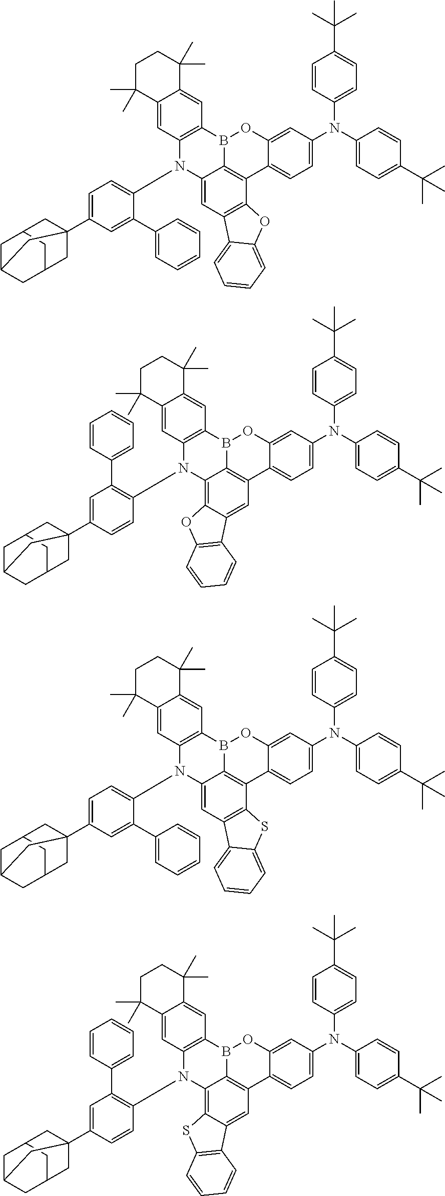

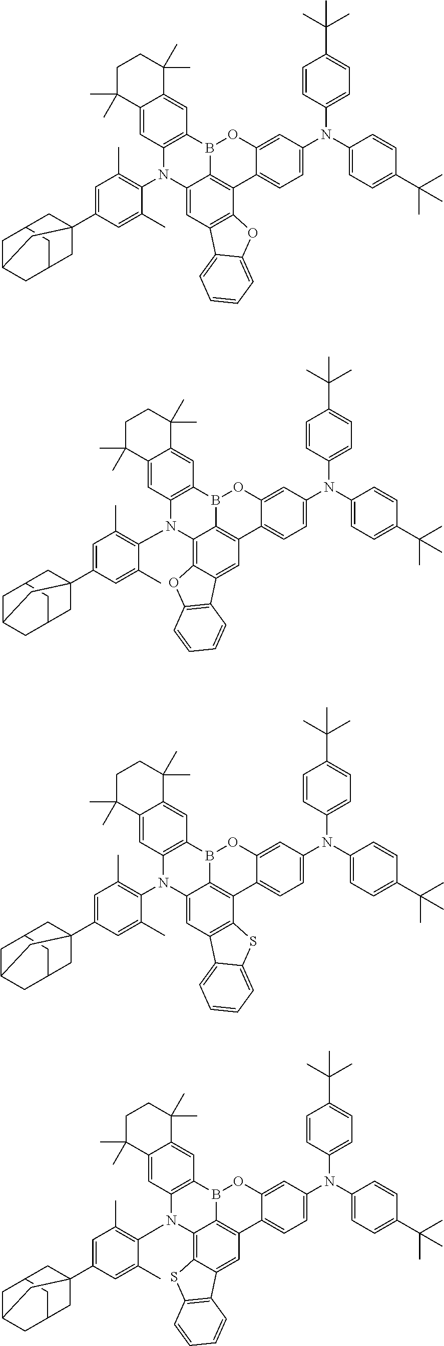

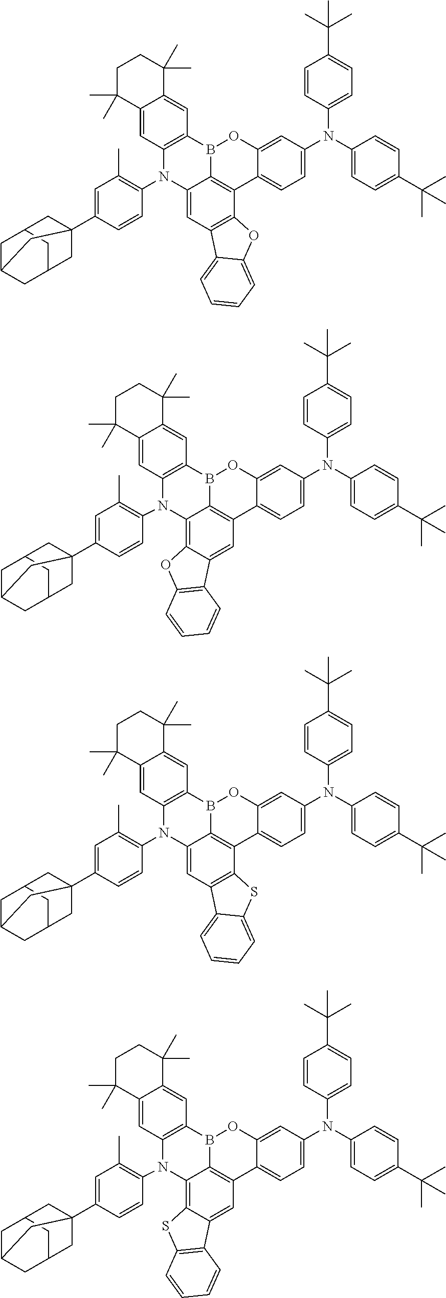

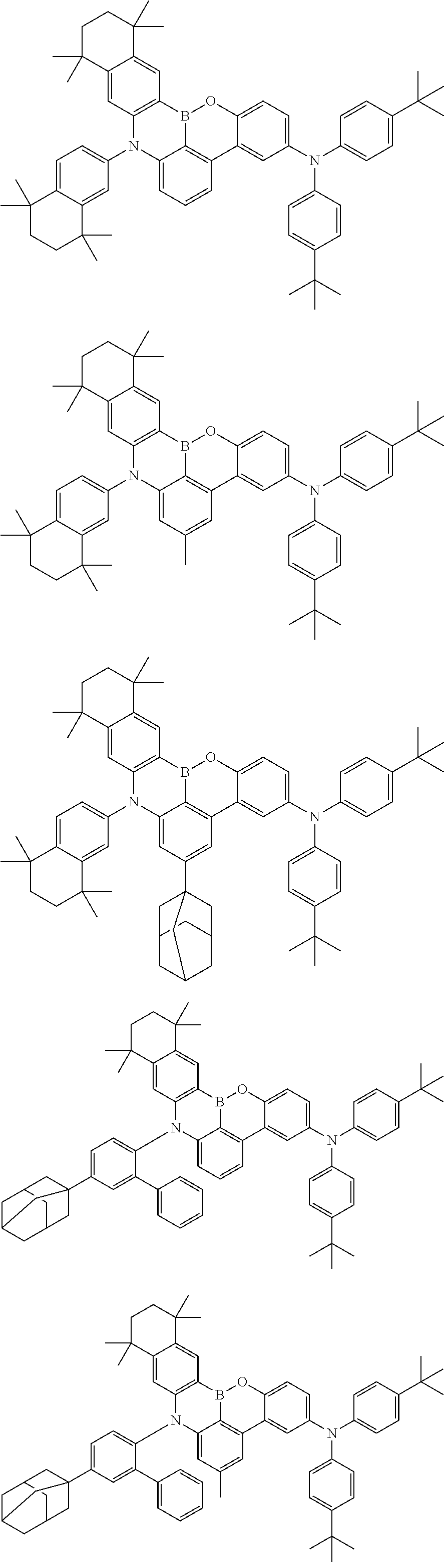

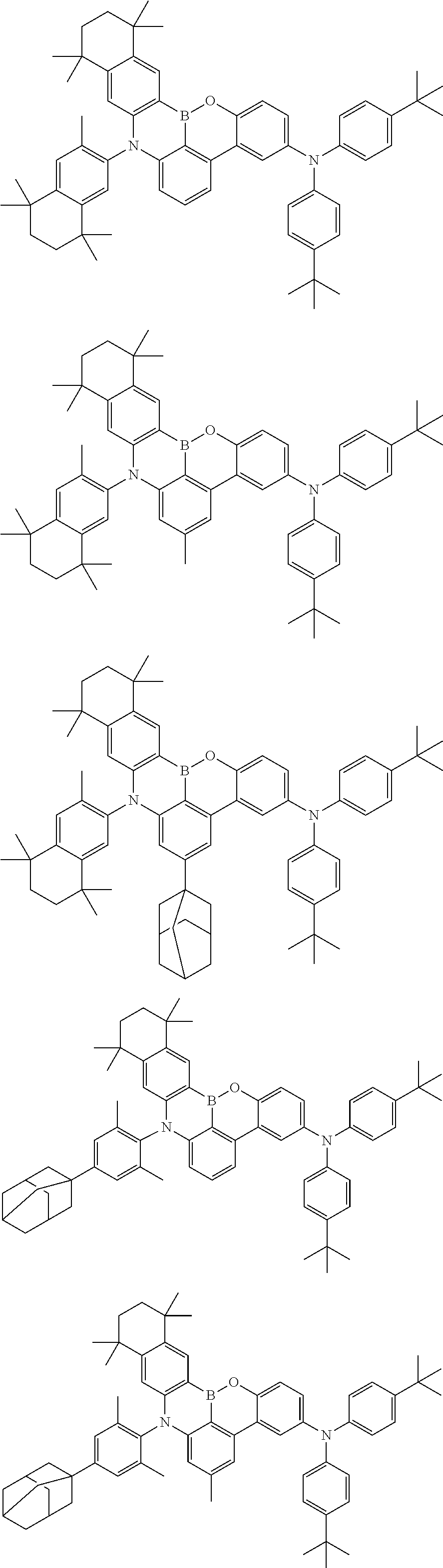

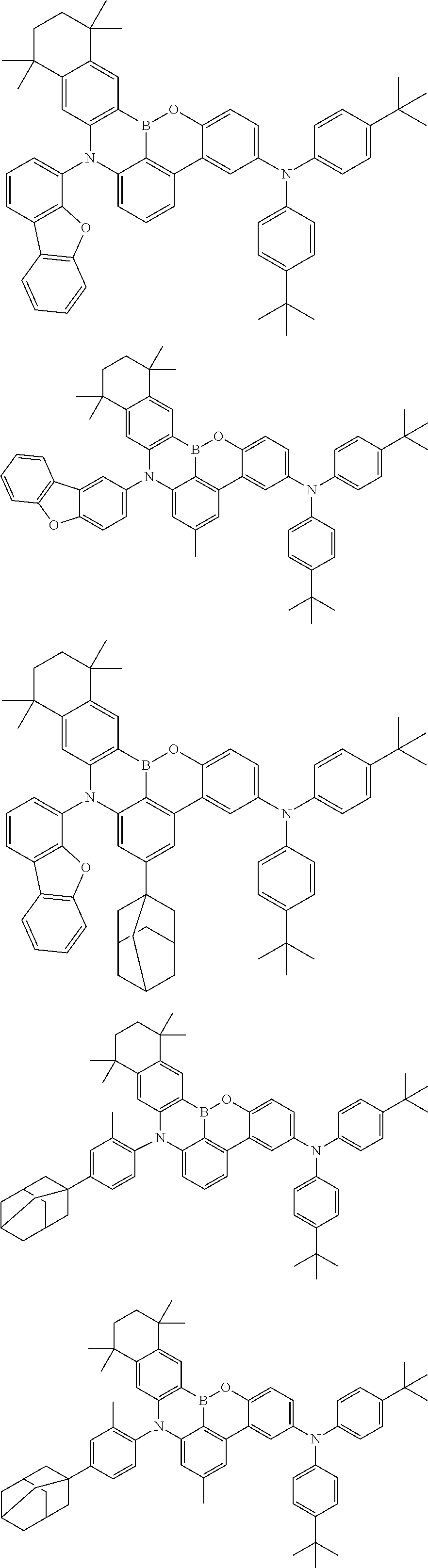

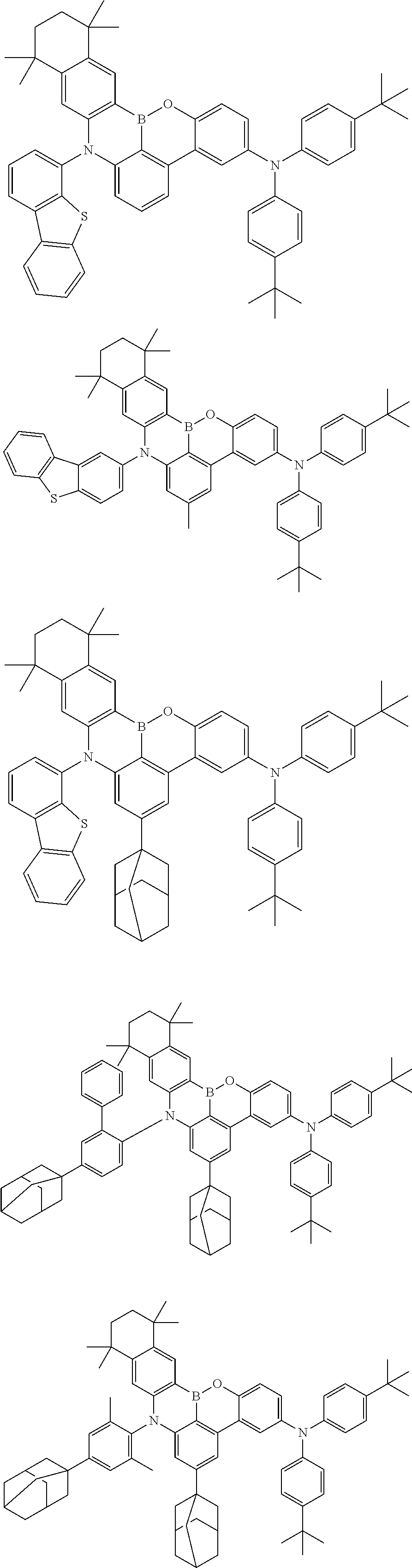

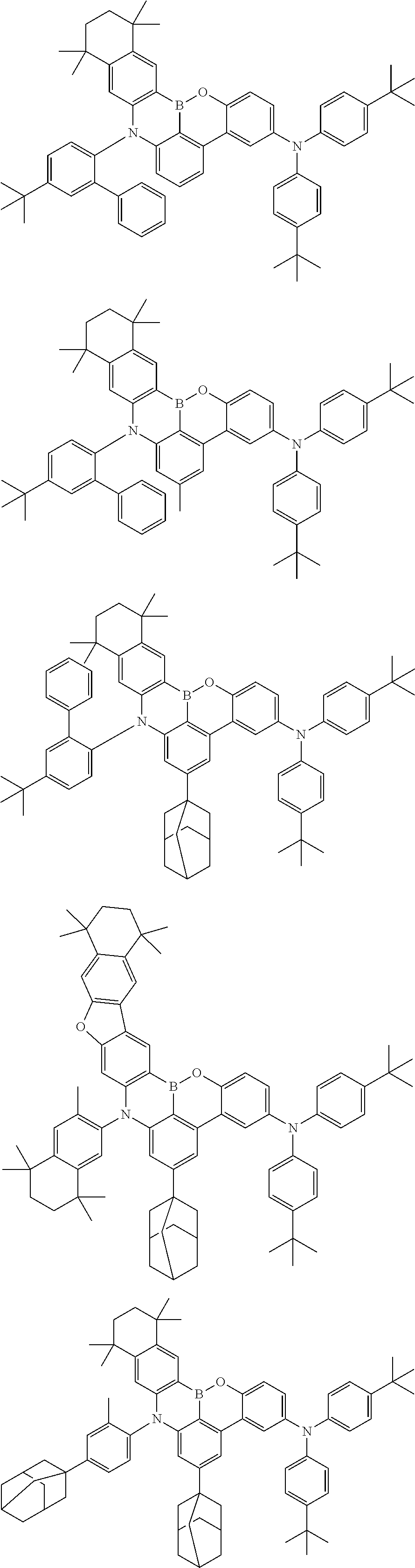

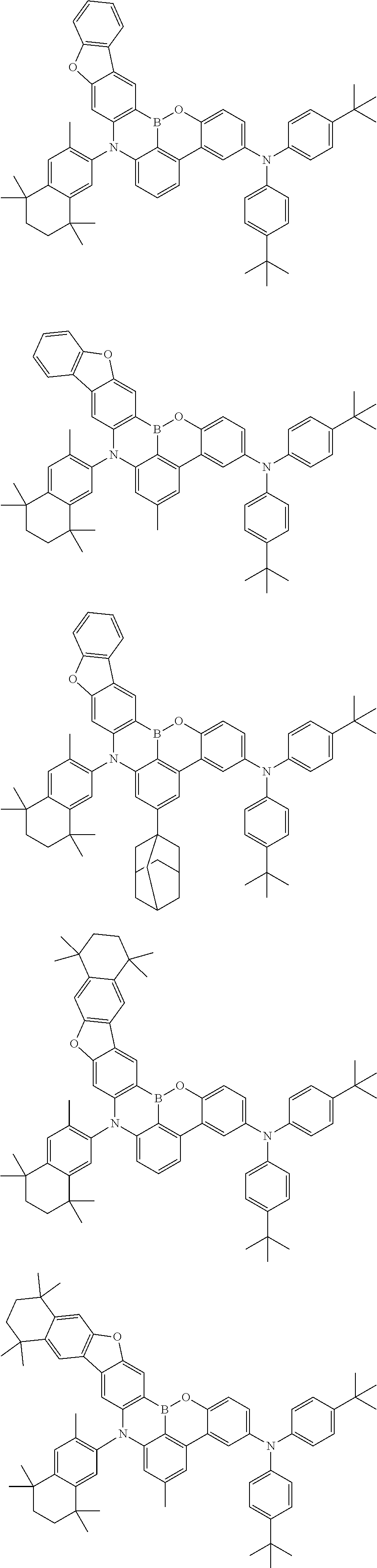

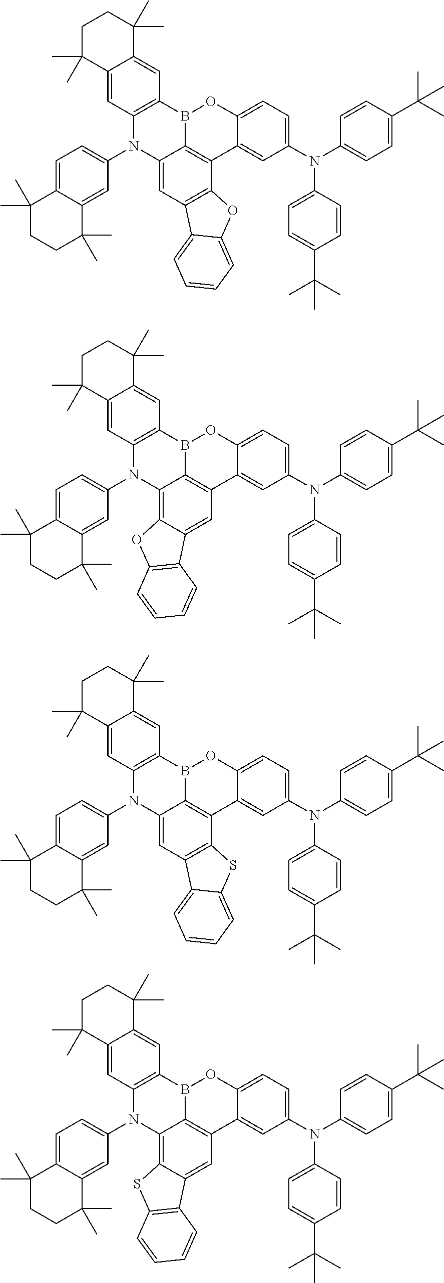

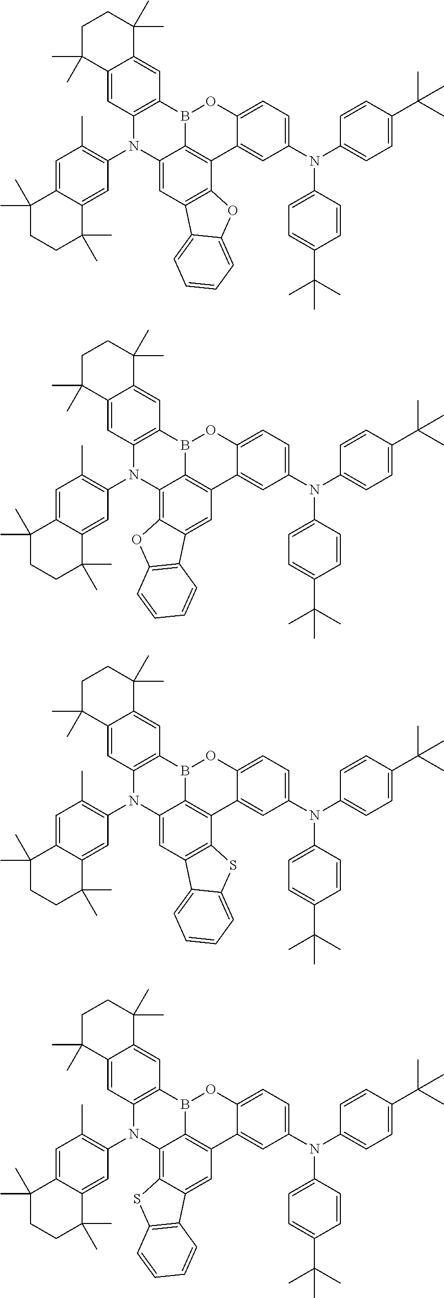

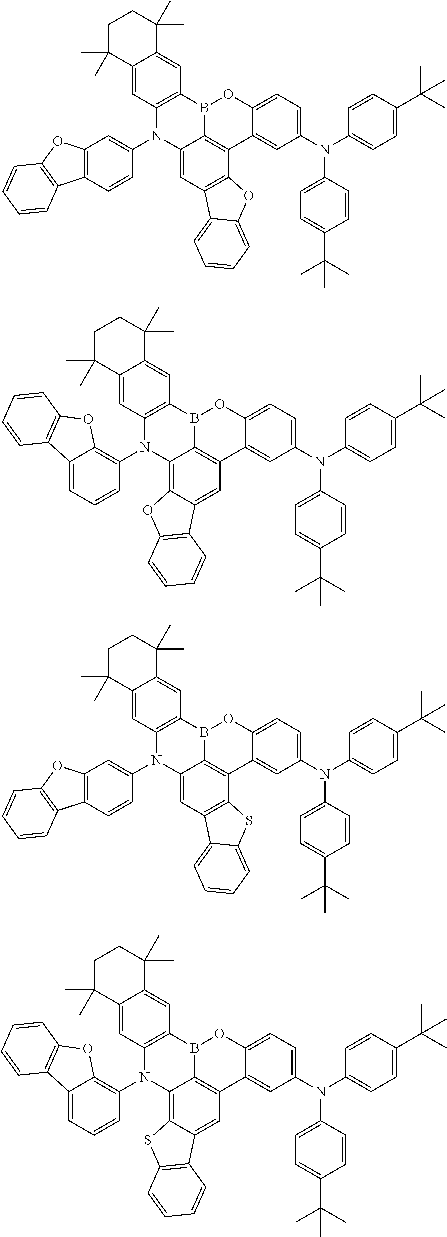

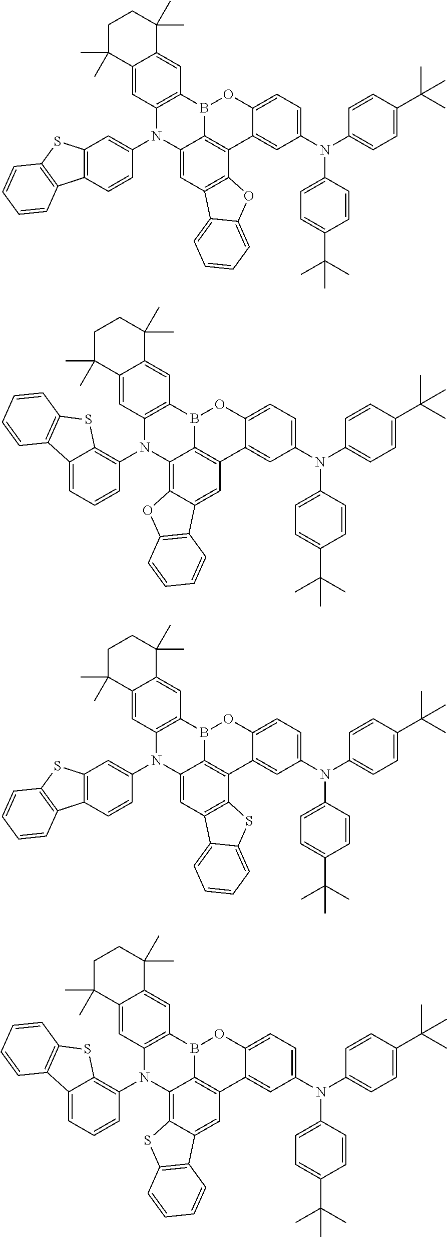

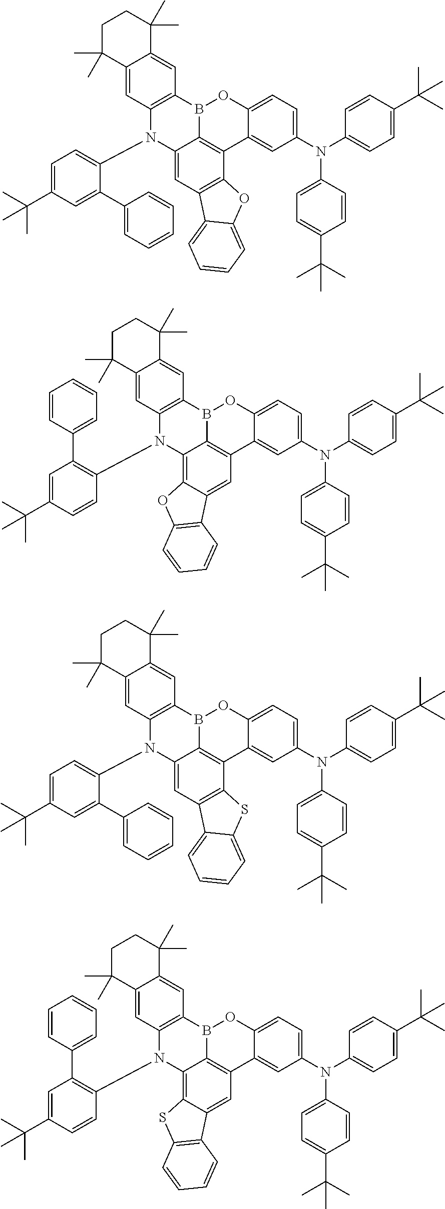

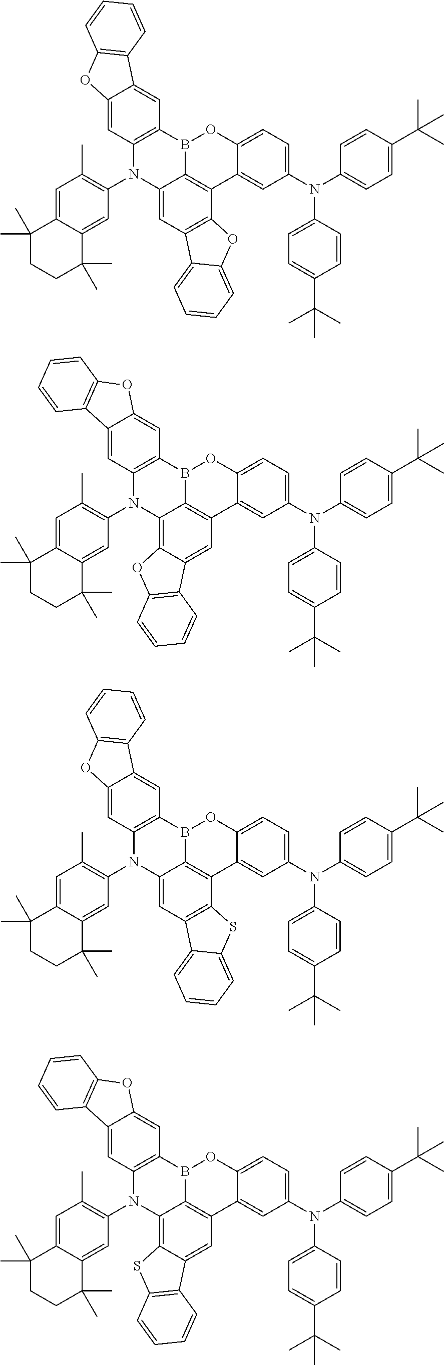

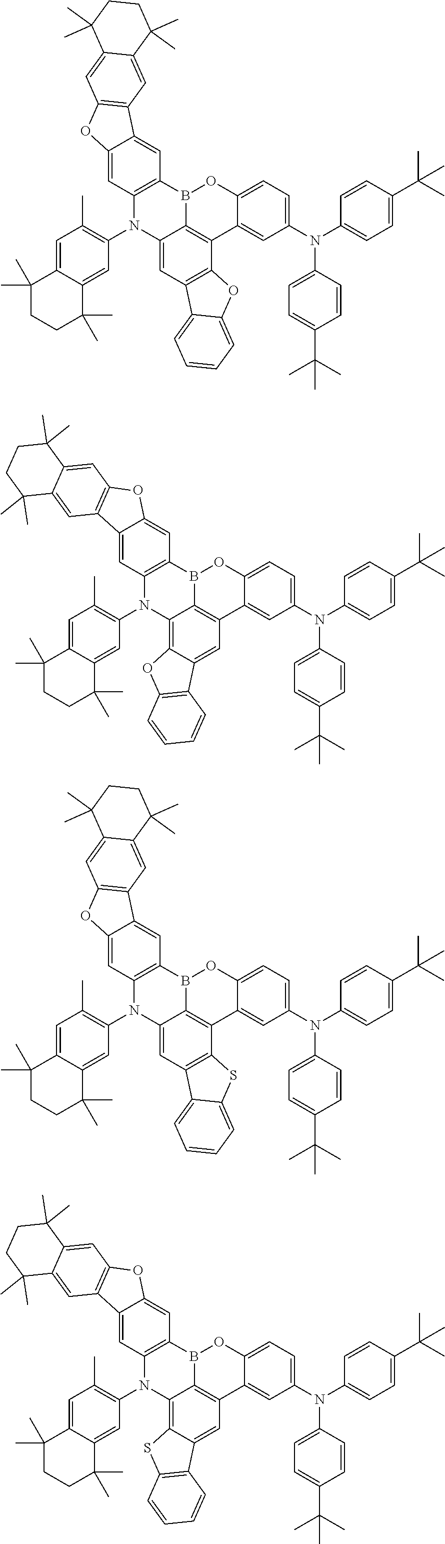

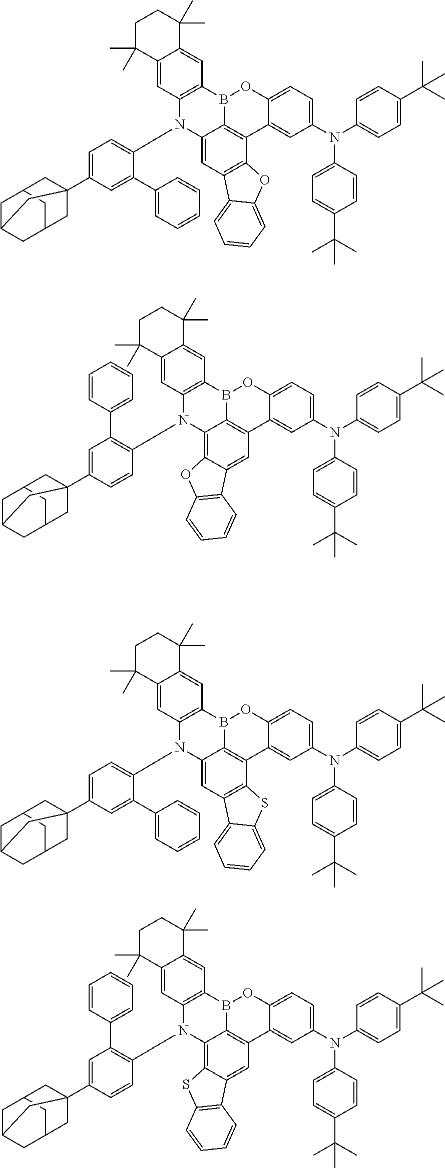

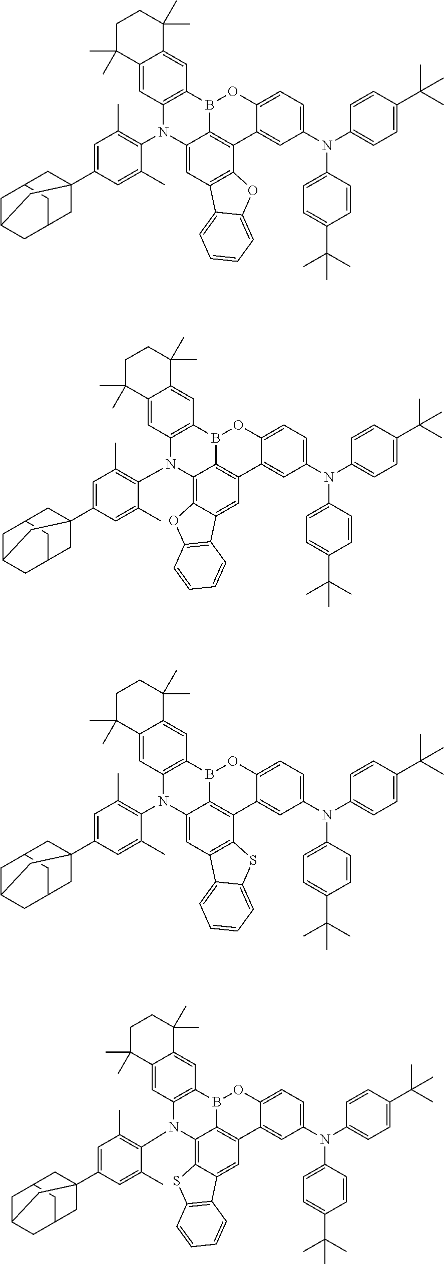

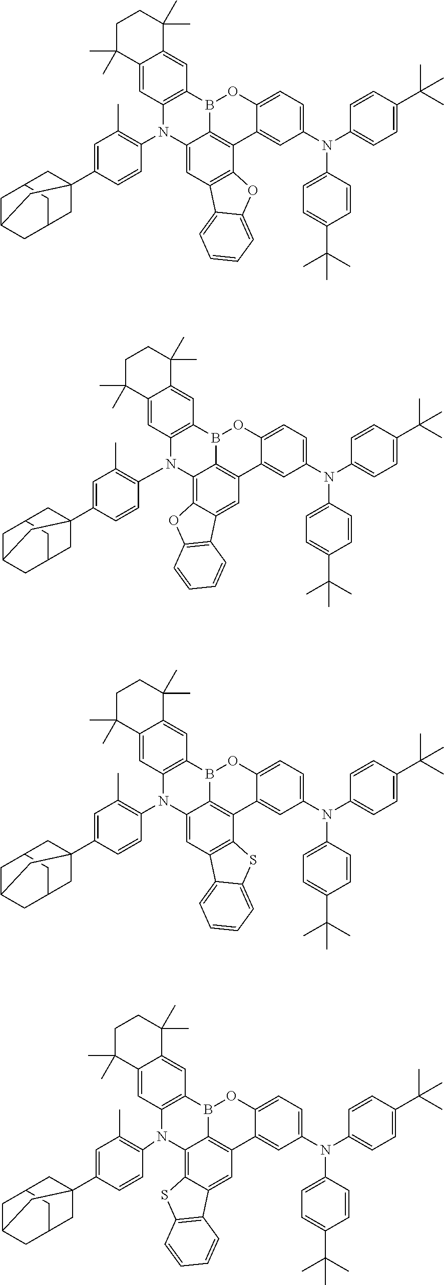

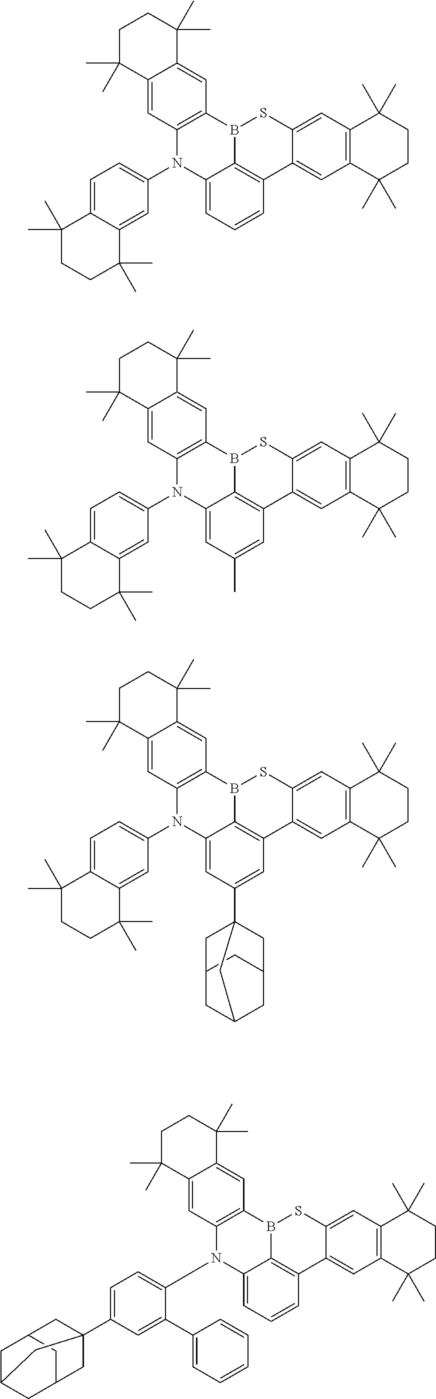 [SMILES: CC1(C)CCC(C)(C)c2cc(N3c4cc5c(cc4B4Sc6cc7c(cc6-c6cccc3c64)C(C)(C)CCC7(C)C)C(C)(C)CCC5(C)C)ccc21 ; Cc1cc2c3c(c1)N(c1ccc4c(c1)C(C)(C)CCC4(C)C)c1cc4c(cc1B3Sc1cc3c(cc1-2)C(C)(C)CCC3(C)C)C(C)(C)CCC4(C)C ; CC1(C)CCC(C)(C)c2cc(N3c4cc5c(cc4B4Sc6cc7c(cc6-c6cc(C89CC%10CC(CC(C%10)C8)C9)cc3c64)C(C)(C)CCC7(C)C)C(C)(C)CCC5(C)C)ccc21 ; CC1(C)CCC(C)(C)c2cc3c(cc21)SB1c2cc4c(cc2N(c2ccc(C56CC7CC(CC(C7)C5)C6)cc2-c2ccccc2)c2cccc-3c21)C(C)(C)CCC4(C)C]

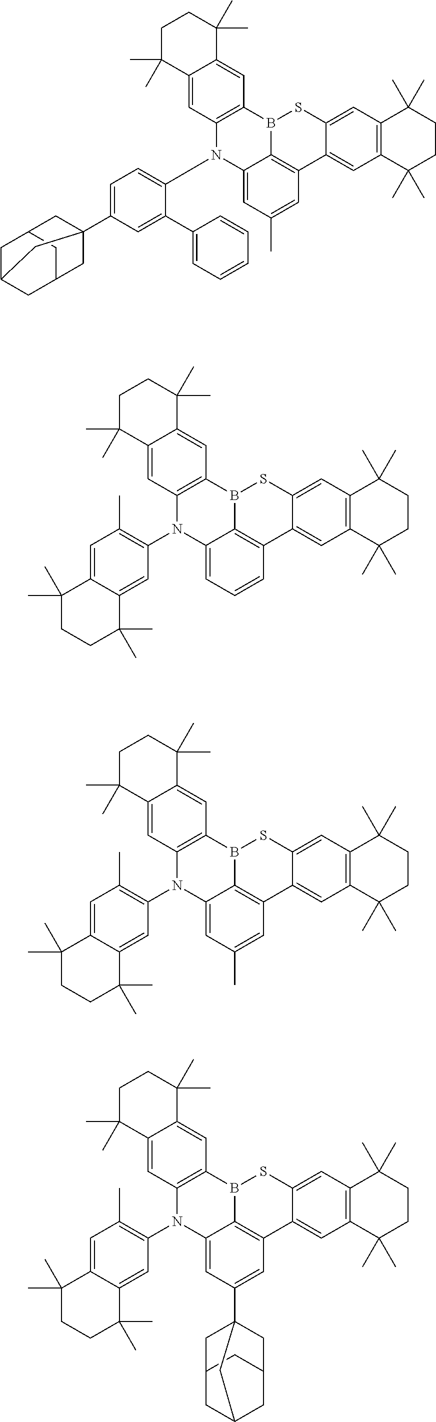 [SMILES: Cc1cc2c3c(c1)N(c1ccc(C45CC6CC(CC(C6)C4)C5)cc1-c1ccccc1)c1cc4c(cc1B3Sc1cc3c(cc1-2)C(C)(C)CCC3(C)C)C(C)(C)CCC4(C)C ; Cc1cc2c(cc1N1c3cc4c(cc3B3Sc5cc6c(cc5-c5cccc1c53)C(C)(C)CCC6(C)C)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Sc1cc3c(cc1-2)C(C)(C)CCC3(C)C)C(C)(C)CCC4(C)C ; Cc1cc2c(cc1N1c3cc4c(cc3B3Sc5cc6c(cc5-c5cc(C78CC9CC(CC(C9)C7)C8)cc1c53)C(C)(C)CCC6(C)C)C(C)(C)CCC4(C)C)C(C)(C)CCC2(C)C]

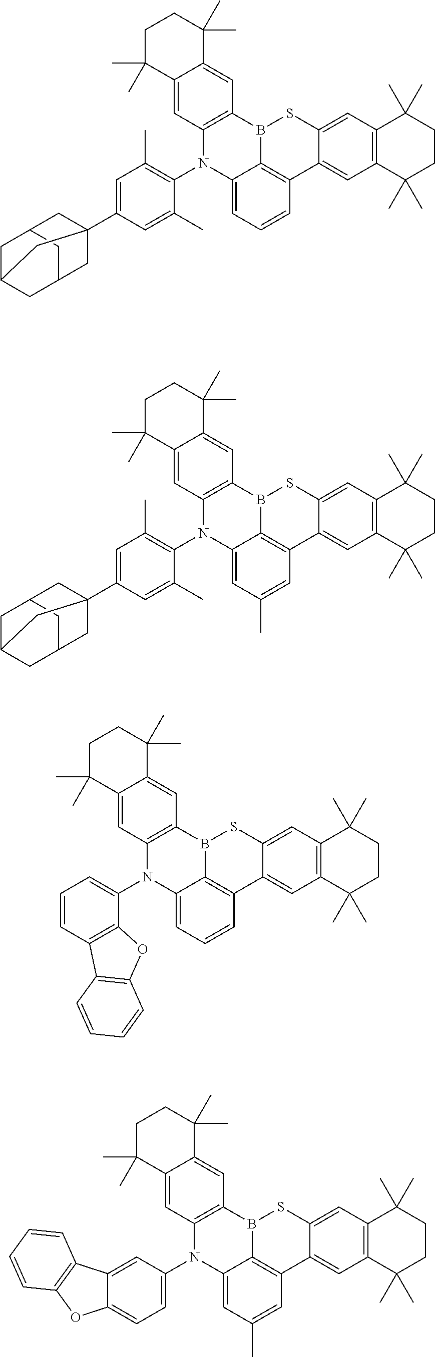 [SMILES: Cc1cc(C23CC4CC(CC(C4)C2)C3)cc(C)c1N1c2cc3c(cc2B2Sc4cc5c(cc4-c4cccc1c42)C(C)(C)CCC5(C)C)C(C)(C)CCC3(C)C ; Cc1cc2c3c(c1)N(c1c(C)cc(C45CC6CC(CC(C6)C4)C5)cc1C)c1cc4c(cc1B3Sc1cc3c(cc1-2)C(C)(C)CCC3(C)C)C(C)(C)CCC4(C)C ; CC1(C)CCC(C)(C)c2cc3c(cc21)SB1c2cc4c(cc2N(c2cccc5c2oc2ccccc25)c2cccc-3c21)C(C)(C)CCC4(C)C ; Cc1cc2c3c(c1)N(c1ccc4oc5ccccc5c4c1)c1cc4c(cc1B3Sc1cc3c(cc1-2)C(C)(C)CCC3(C)C)C(C)(C)CCC4(C)C]

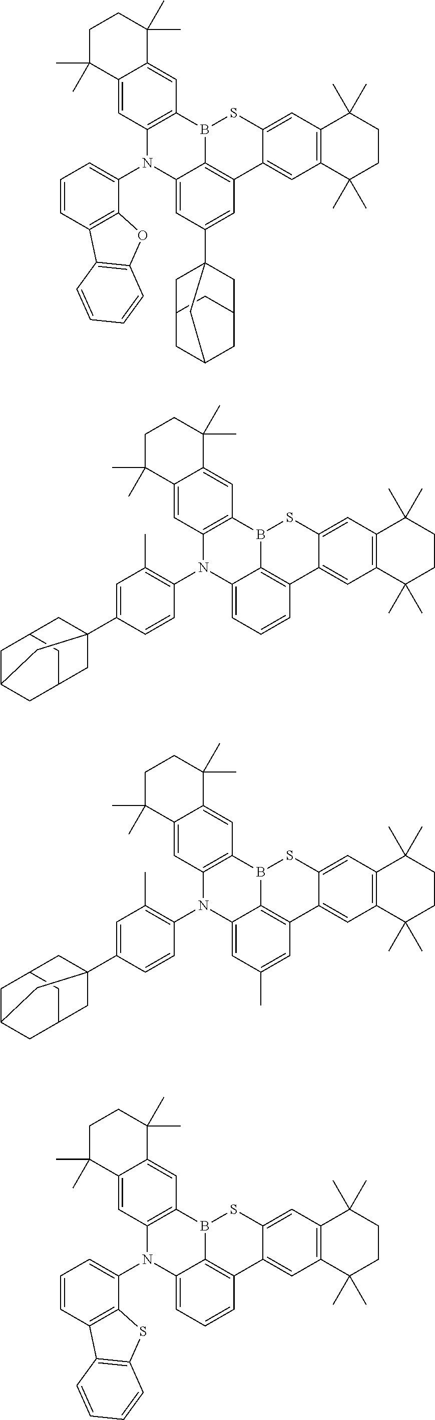

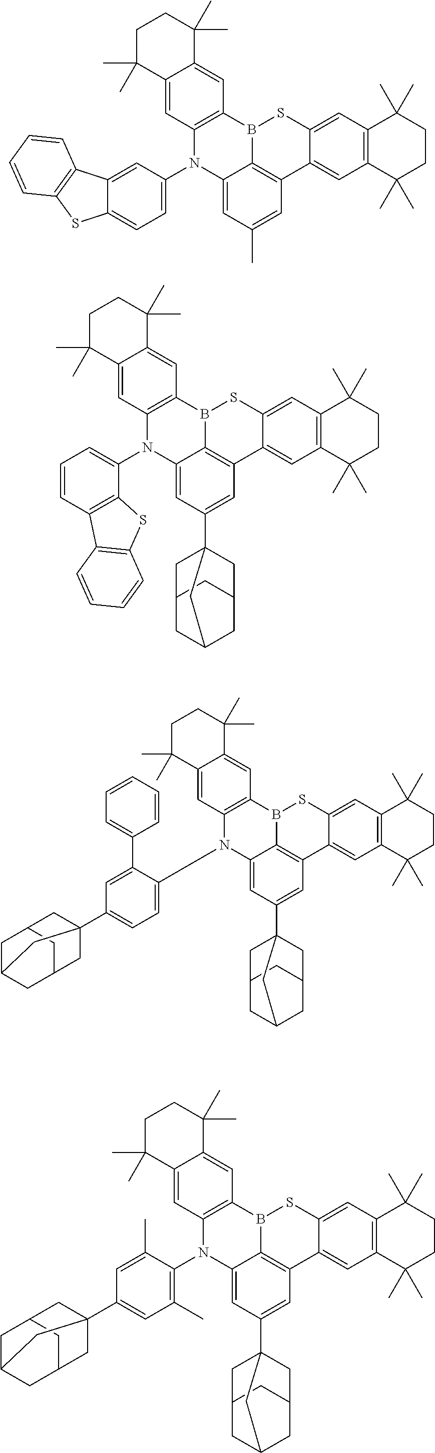 [SMILES: Cc1cc2c3c(c1)N(c1ccc4sc5ccccc5c4c1)c1cc4c(cc1B3Sc1cc3c(cc1-2)C(C)(C)CCC3(C)C)C(C)(C)CCC4(C)C ; CC1(C)CCC(C)(C)c2cc3c(cc21)SB1c2cc4c(cc2N(c2cccc5c2sc2ccccc25)c2cc(C56CC7CC(CC(C7)C5)C6)cc-3c21)C(C)(C)CCC4(C)C ; CC1(C)CCC(C)(C)c2cc3c(cc21)SB1c2cc4c(cc2N(c2ccc(C56CC7CC(CC(C7)C5)C6)cc2-c2ccccc2)c2cc(C56CC7CC(CC(C7)C5)C6)cc-3c21)C(C)(C)CCC4(C)C ; Cc1cc(C23CC4CC(CC(C4)C2)C3)cc(C)c1N1c2cc3c(cc2B2Sc4cc5c(cc4-c4cc(C67CC8CC(CC(C8)C6)C7)cc1c42)C(C)(C)CCC5(C)C)C(C)(C)CCC3(C)C]

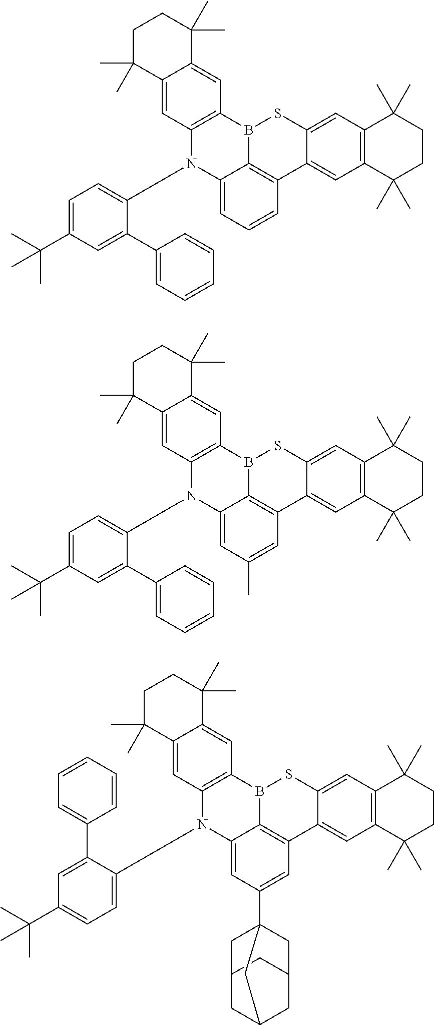

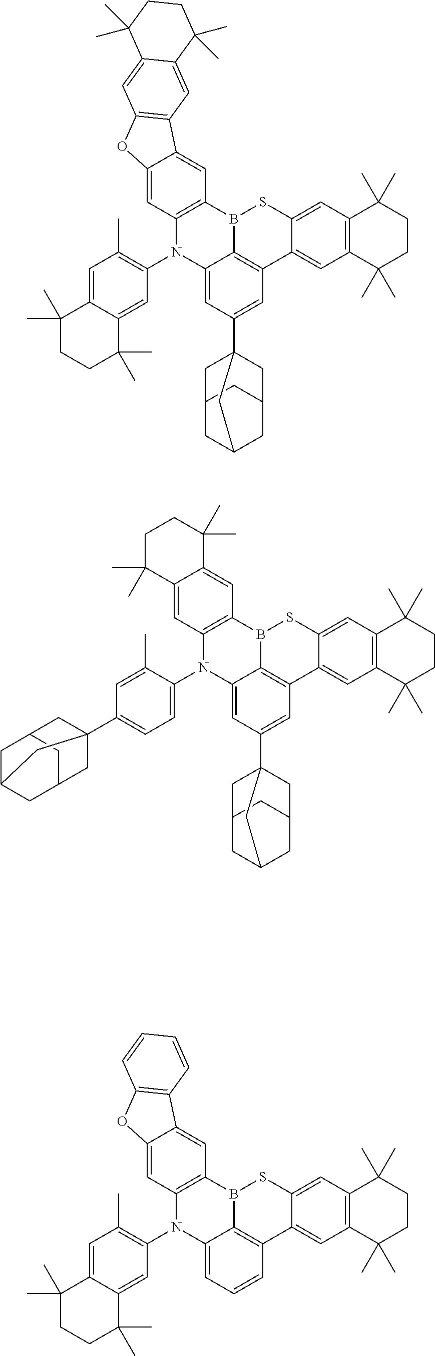 [SMILES: Cc1cc2c(cc1N1c3cc4oc5cc6c(cc5c4cc3B3Sc4cc5c(cc4-c4cc(C78CC9CC(CC(C9)C7)C8)cc1c43)C(C)(C)CCC5(C)C)C(C)(C)CCC6(C)C)C(C)(C)CCC2(C)C ; Cc1cc(C23CC4CC(CC(C4)C2)C3)ccc1N1c2cc3c(cc2B2Sc4cc5c(cc4-c4cc(C67CC8CC(CC(C8)C6)C7)cc1c42)C(C)(C)CCC5(C)C)C(C)(C)CCC3(C)C ; Cc1cc2c(cc1N1c3cc4oc5ccccc5c4cc3B3Sc4cc5c(cc4-c4cccc1c43)C(C)(C)CCC5(C)C)C(C)(C)CCC2(C)C]

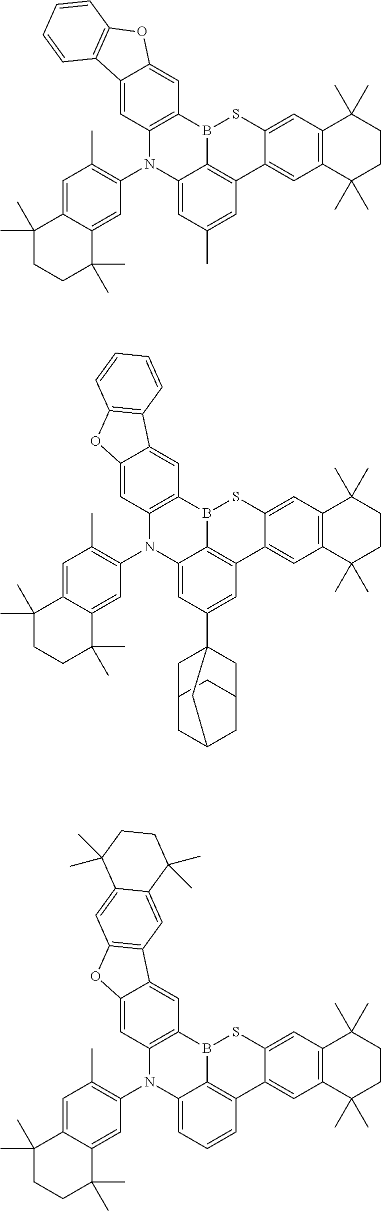 [SMILES: Cc1cc2c3c(c1)N(c1cc4c(cc1C)C(C)(C)CCC4(C)C)c1cc4c(cc1B3Sc1cc3c(cc1-2)C(C)(C)CCC3(C)C)oc1ccccc14 ; Cc1cc2c(cc1N1c3cc4oc5ccccc5c4cc3B3Sc4cc5c(cc4-c4cc(C67CC8CC(CC(C8)C6)C7)cc1c43)C(C)(C)CCC5(C)C)C(C)(C)CCC2(C)C ; Cc1cc2c(cc1N1c3cc4oc5cc6c(cc5c4cc3B3Sc4cc5c(cc4-c4cccc1c43)C(C)(C)CCC5(C)C)C(C)(C)CCC6(C)C)C(C)(C)CCC2(C)C]

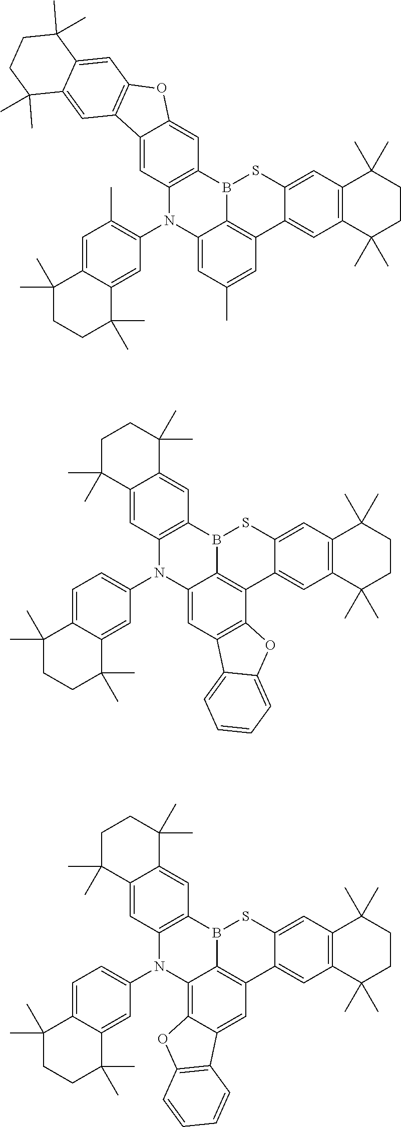 [SMILES: Cc1cc2c3c(c1)N(c1cc4c(cc1C)C(C)(C)CCC4(C)C)c1cc4c(cc1B3Sc1cc3c(cc1-2)C(C)(C)CCC3(C)C)oc1cc2c(cc14)C(C)(C)CCC2(C)C ; CC1(C)CCC(C)(C)c2cc(N3c4cc5c(cc4B4Sc6cc7c(cc6-c6c4c3cc3c6oc4ccccc43)C(C)(C)CCC7(C)C)C(C)(C)CCC5(C)C)ccc21 ; CC1(C)CCC(C)(C)c2cc(N3c4cc5c(cc4B4Sc6cc7c(cc6-c6cc8c(oc9ccccc98)c3c64)C(C)(C)CCC7(C)C)C(C)(C)CCC5(C)C)ccc21]

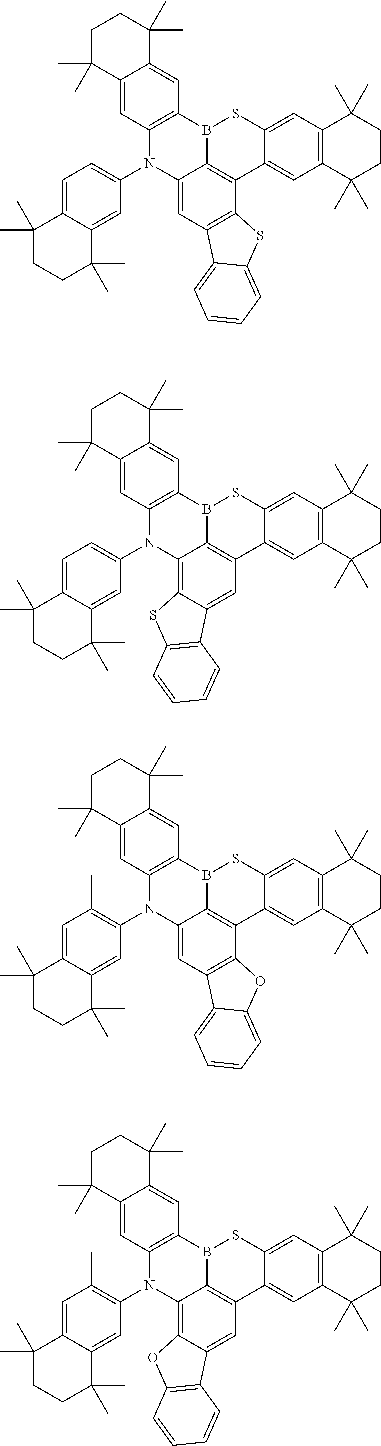

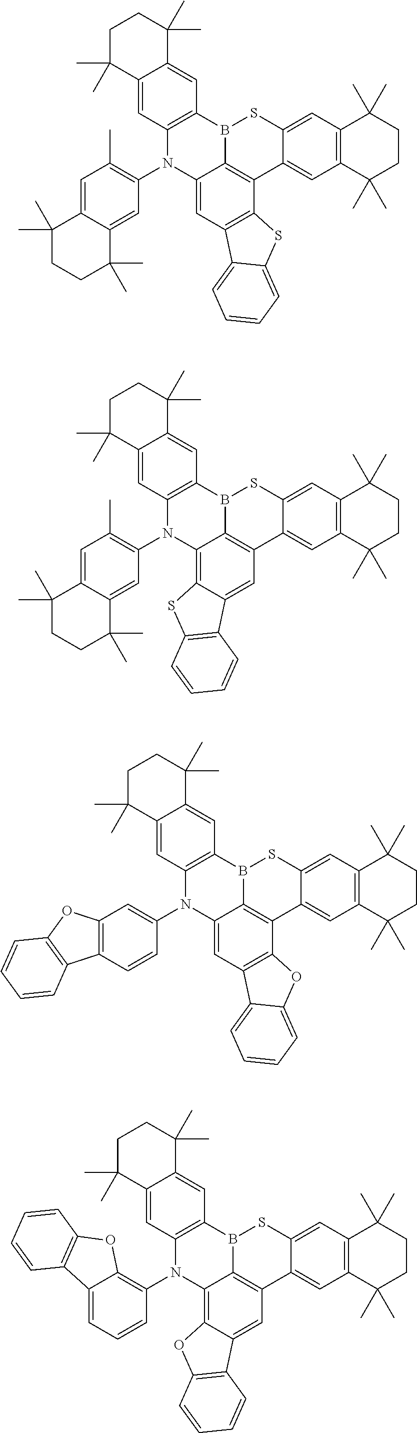 [SMILES: Cc1cc2c(cc1N1c3cc4c(cc3B3Sc5cc6c(cc5-c5c3c1cc1c5sc3ccccc31)C(C)(C)CCC6(C)C)C(C)(C)CCC4(C)C)C(C)(C)CCC2(C)C ; Cc1cc2c(cc1N1c3cc4c(cc3B3Sc5cc6c(cc5-c5cc7c(sc8ccccc87)c1c53)C(C)(C)CCC6(C)C)C(C)(C)CCC4(C)C)C(C)(C)CCC2(C)C ; CC1(C)CCC(C)(C)c2cc3c(cc21)SB1c2cc4c(cc2N(c2ccc5c(c2)oc2ccccc25)c2cc5c(oc6ccccc65)c-3c21)C(C)(C)CCC4(C)C ; CC1(C)CCC(C)(C)c2cc3c(cc21)SB1c2cc4c(cc2N(c2cccc5c2oc2ccccc25)c2c1c-3cc1c2oc2ccccc21)C(C)(C)CCC4(C)C]

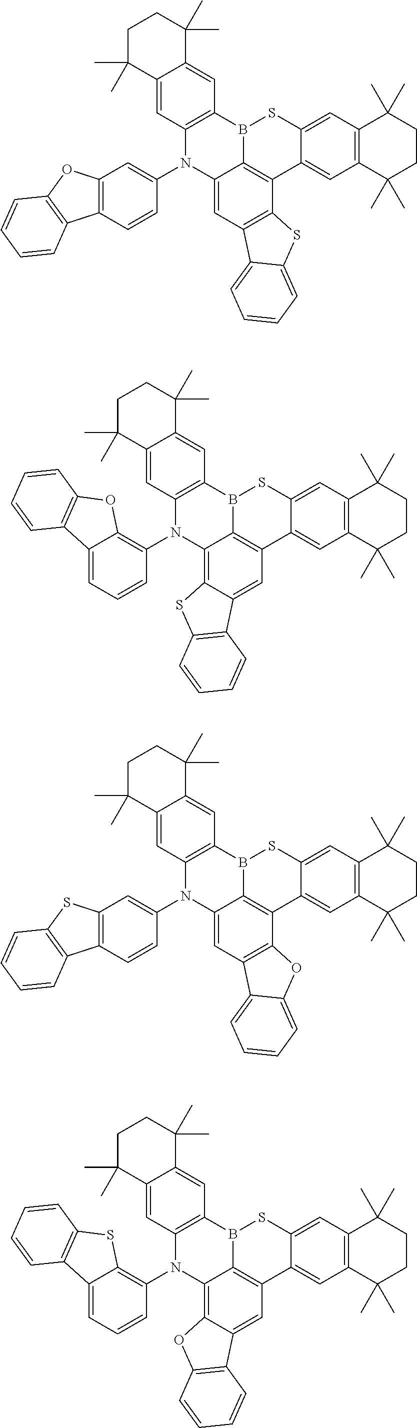

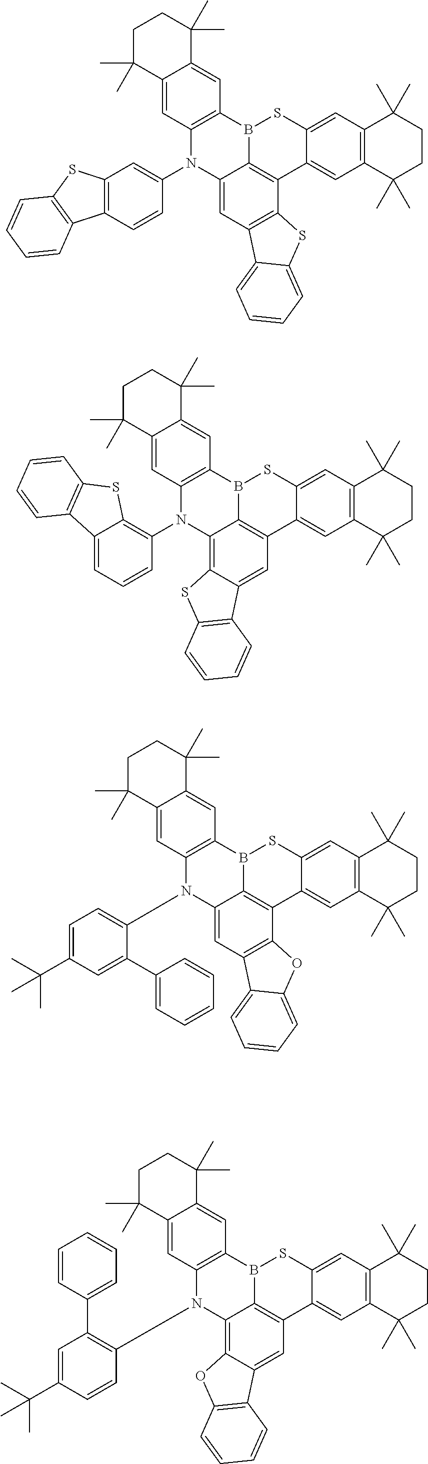 [SMILES: CC1(C)CCC(C)(C)c2cc3c(cc21)SB1c2cc4c(cc2N(c2ccc5c(c2)sc2ccccc25)c2cc5c(sc6ccccc65)c-3c21)C(C)(C)CCC4(C)C ; CC1(C)CCC(C)(C)c2cc3c(cc21)SB1c2cc4c(cc2N(c2cccc5c2sc2ccccc25)c2c1c-3cc1c2sc2ccccc21)C(C)(C)CCC4(C)C ; CC(C)(C)c1ccc(N2c3cc4c(cc3B3Sc5cc6c(cc5-c5c3c2cc2c5oc3ccccc32)C(C)(C)CCC6(C)C)C(C)(C)CCC4(C)C)c(-c2ccccc2)c1 ; CC(C)(C)c1ccc(N2c3cc4c(cc3B3Sc5cc6c(cc5-c5cc7c(oc8ccccc87)c2c53)C(C)(C)CCC6(C)C)C(C)(C)CCC4(C)C)c(-c2ccccc2)c1]

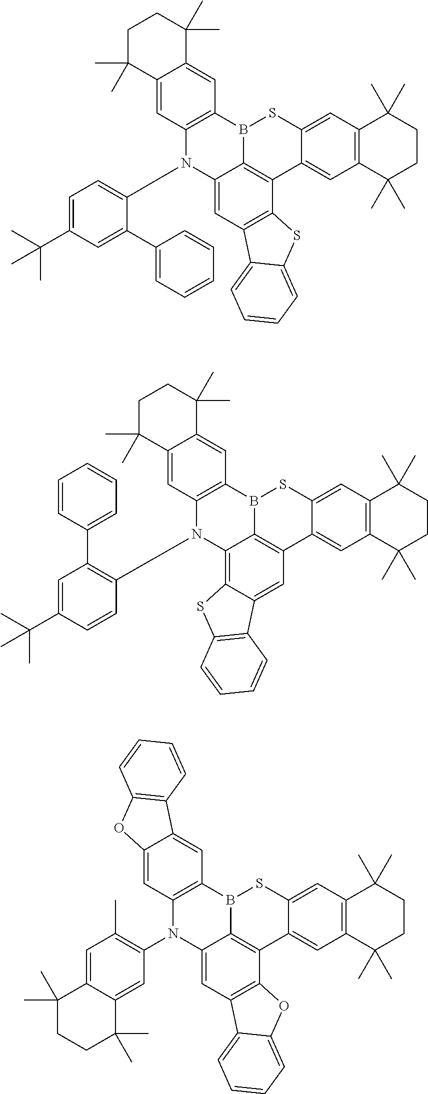 [SMILES: CC(C)(C)c1ccc(N2c3cc4c(cc3B3Sc5cc6c(cc5-c5c3c2cc2c5sc3ccccc32)C(C)(C)CCC6(C)C)C(C)(C)CCC4(C)C)c(-c2ccccc2)c1 ; CC(C)(C)c1ccc(N2c3cc4c(cc3B3Sc5cc6c(cc5-c5cc7c(sc8ccccc87)c2c53)C(C)(C)CCC6(C)C)C(C)(C)CCC4(C)C)c(-c2ccccc2)c1 ; Cc1cc2c(cc1N1c3cc4oc5ccccc5c4cc3B3Sc4cc5c(cc4-c4c3c1cc1c4oc3ccccc31)C(C)(C)CCC5(C)C)C(C)(C)CCC2(C)C]

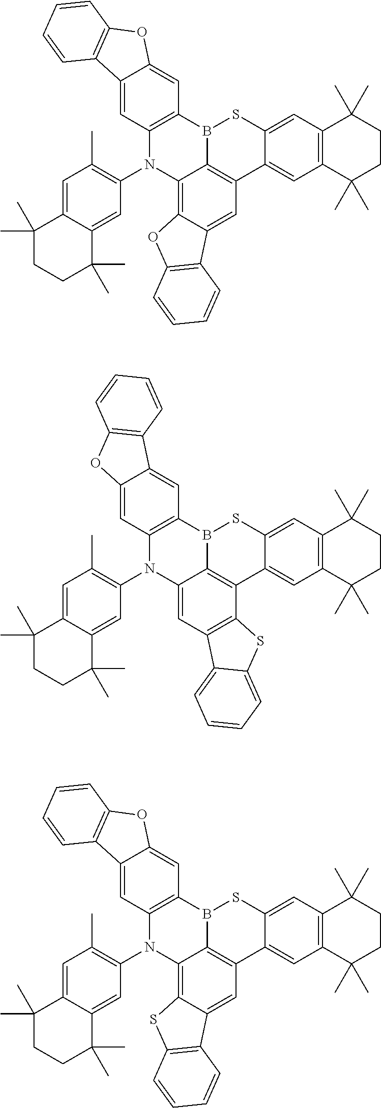 [SMILES: Cc1cc2c(cc1N1c3cc4c(cc3B3Sc5cc6c(cc5-c5cc7c(oc8ccccc87)c1c53)C(C)(C)CCC6(C)C)oc1ccccc14)C(C)(C)CCC2(C)C ; Cc1cc2c(cc1N1c3cc4oc5ccccc5c4cc3B3Sc4cc5c(cc4-c4c3c1cc1c4sc3ccccc31)C(C)(C)CCC5(C)C)C(C)(C)CCC2(C)C ; Cc1cc2c(cc1N1c3cc4c(cc3B3Sc5cc6c(cc5-c5cc7c(sc8ccccc87)c1c53)C(C)(C)CCC6(C)C)oc1ccccc14)C(C)(C)CCC2(C)C]

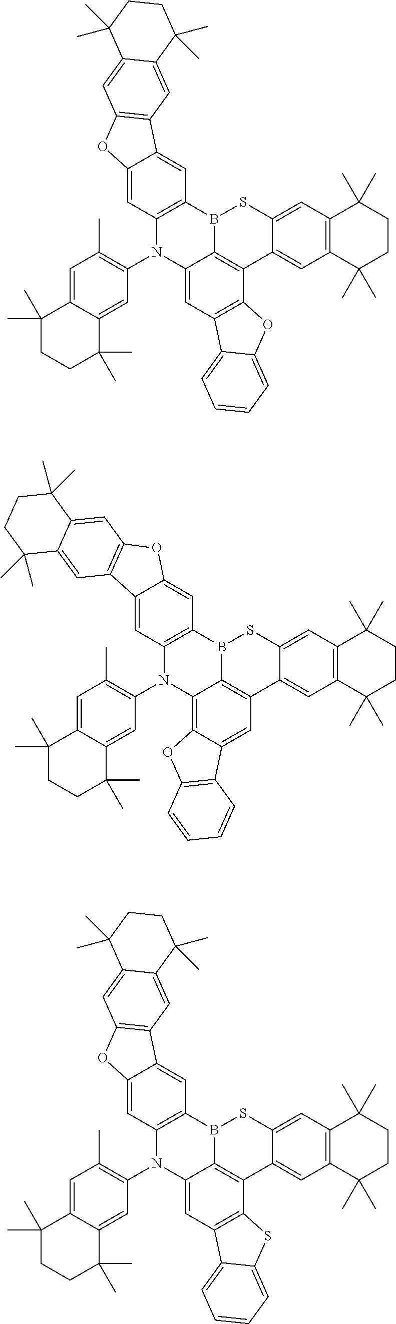 [SMILES: Cc1cc2c(cc1N1c3cc4oc5cc6c(cc5c4cc3B3Sc4cc5c(cc4-c4c3c1cc1c4oc3ccccc31)C(C)(C)CCC5(C)C)C(C)(C)CCC6(C)C)C(C)(C)CCC2(C)C ; Cc1cc2c(cc1N1c3cc4c(cc3B3Sc5cc6c(cc5-c5cc7c(oc8ccccc87)c1c53)C(C)(C)CCC6(C)C)oc1cc3c(cc14)C(C)(C)CCC3(C)C)C(C)(C)CCC2(C)C ; Cc1cc2c(cc1N1c3cc4oc5cc6c(cc5c4cc3B3Sc4cc5c(cc4-c4c3c1cc1c4sc3ccccc31)C(C)(C)CCC5(C)C)C(C)(C)CCC6(C)C)C(C)(C)CCC2(C)C]

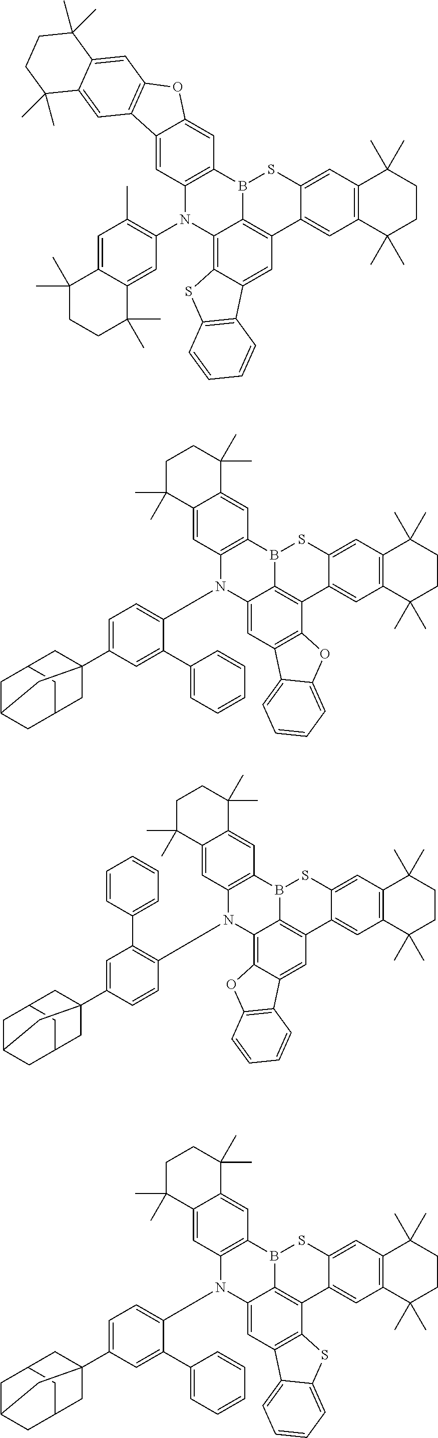 [SMILES: Cc1cc2c(cc1N1c3cc4c(cc3B3Sc5cc6c(cc5-c5cc7c(sc8ccccc87)c1c53)C(C)(C)CCC6(C)C)oc1cc3c(cc14)C(C)(C)CCC3(C)C)C(C)(C)CCC2(C)C ; CC1(C)CCC(C)(C)c2cc3c(cc21)SB1c2cc4c(cc2N(c2ccc(C56CC7CC(CC(C7)C5)C6)cc2-c2ccccc2)c2cc5c(oc6ccccc65)c-3c21)C(C)(C)CCC4(C)C ; CC1(C)CCC(C)(C)c2cc3c(cc21)SB1c2cc4c(cc2N(c2ccc(C56CC7CC(CC(C7)C5)C6)cc2-c2ccccc2)c2c1c-3cc1c2oc2ccccc21)C(C)(C)CCC4(C)C ; CC1(C)CCC(C)(C)c2cc3c(cc21)SB1c2cc4c(cc2N(c2ccc(C56CC7CC(CC(C7)C5)C6)cc2-c2ccccc2)c2cc5c(sc6ccccc65)c-3c21)C(C)(C)CCC4(C)C]

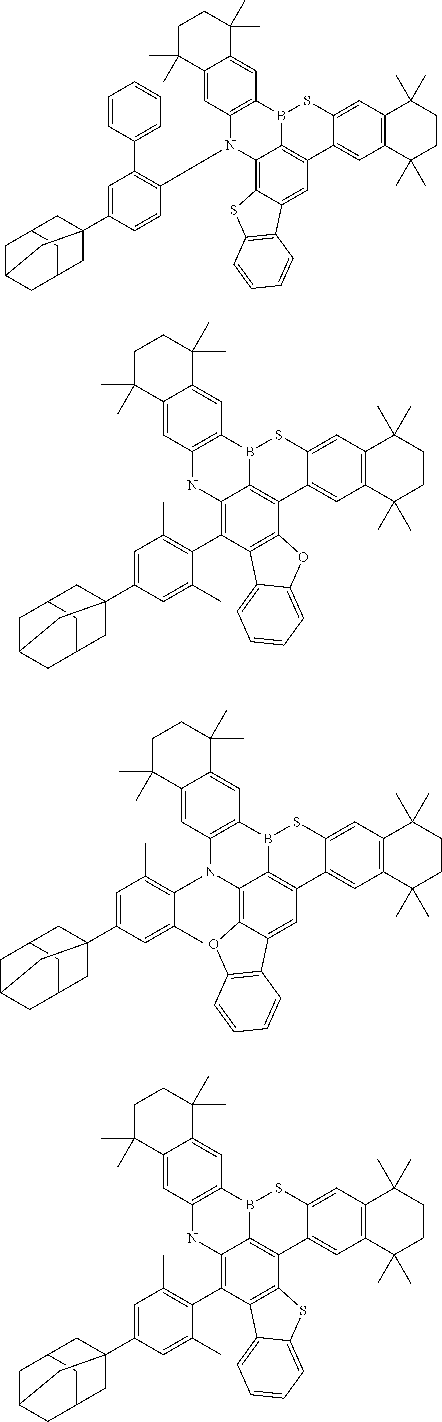 [SMILES: CC1(C)CCC(C)(C)c2cc3c(cc21)SB1c2cc4c(cc2N(c2ccc(C56CC7CC(CC(C7)C5)C6)cc2-c2ccccc2)c2c1c-3cc1c2sc2ccccc21)C(C)(C)CCC4(C)C ; Cc1cc(C23CC4CC(CC(C4)C2)C3)cc(C)c1-c1c2c3c(c4oc5ccccc5c14)-c1cc4c(cc1SB3c1cc3c(cc1N2)C(C)(C)CCC3(C)C)C(C)(C)CCC4(C)C ; Cc1cc(C23CC4CC(CC(C4)C2)C3)cc(C)c1N1c2cc3c(cc2B2Sc4cc5c(cc4-c4cc6c(oc7ccccc76)c1c42)C(C)(C)CCC5(C)C)C(C)(C)CCC3(C)C ; Cc1cc(C23CC4CC(CC(C4)C2)C3)cc(C)c1-c1c2c3c(c4sc5ccccc5c14)-c1cc4c(cc1SB3c1cc3c(cc1N2)C(C)(C)CCC3(C)C)C(C)(C)CCC4(C)C]

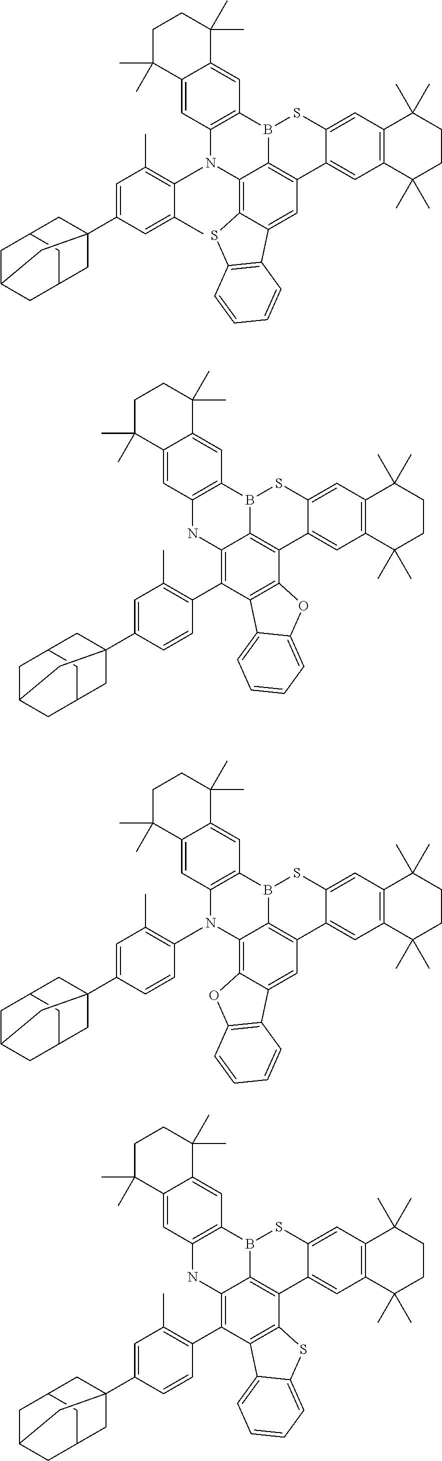

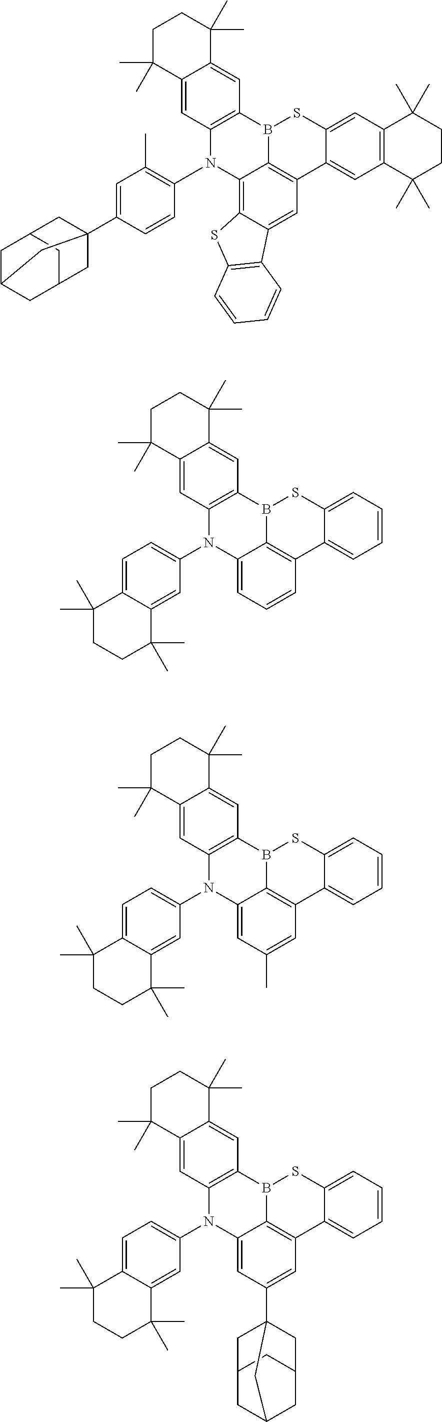 [SMILES: Cc1cc(C23CC4CC(CC(C4)C2)C3)ccc1N1c2cc3c(cc2B2Sc4cc5c(cc4-c4cc6c(sc7ccccc76)c1c42)C(C)(C)CCC5(C)C)C(C)(C)CCC3(C)C ; CC1(C)CCC(C)(C)c2cc(N3c4cc5c(cc4B4Sc6ccccc6-c6cccc3c64)C(C)(C)CCC5(C)C)ccc21 ; Cc1cc2c3c(c1)N(c1ccc4c(c1)C(C)(C)CCC4(C)C)c1cc4c(cc1B3Sc1ccccc1-2)C(C)(C)CCC4(C)C ; CC1(C)CCC(C)(C)c2cc(N3c4cc5c(cc4B4Sc6ccccc6-c6cc(C78CC9CC(CC(C9)C7)C8)cc3c64)C(C)(C)CCC5(C)C)ccc21]

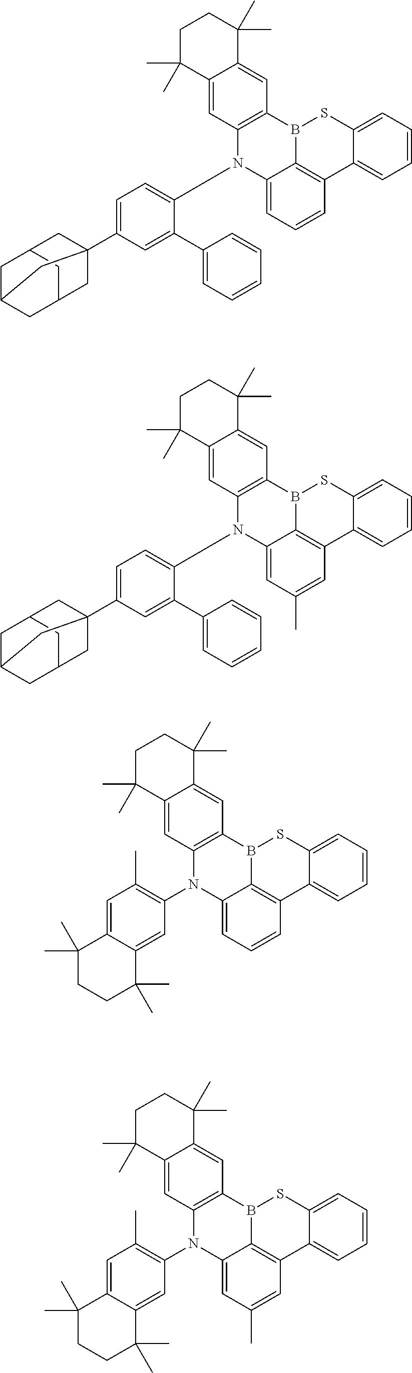 [SMILES: CC1(C)CCC(C)(C)c2cc3c(cc21)B1Sc2ccccc2-c2cccc(c21)N3c1ccc(C23CC4CC(CC(C4)C2)C3)cc1-c1ccccc1 ; Cc1cc2c3c(c1)N(c1ccc(C45CC6CC(CC(C6)C4)C5)cc1-c1ccccc1)c1cc4c(cc1B3Sc1ccccc1-2)C(C)(C)CCC4(C)C ; Cc1cc2c(cc1N1c3cc4c(cc3B3Sc5ccccc5-c5cccc1c53)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Sc1ccccc1-2)C(C)(C)CCC4(C)C]

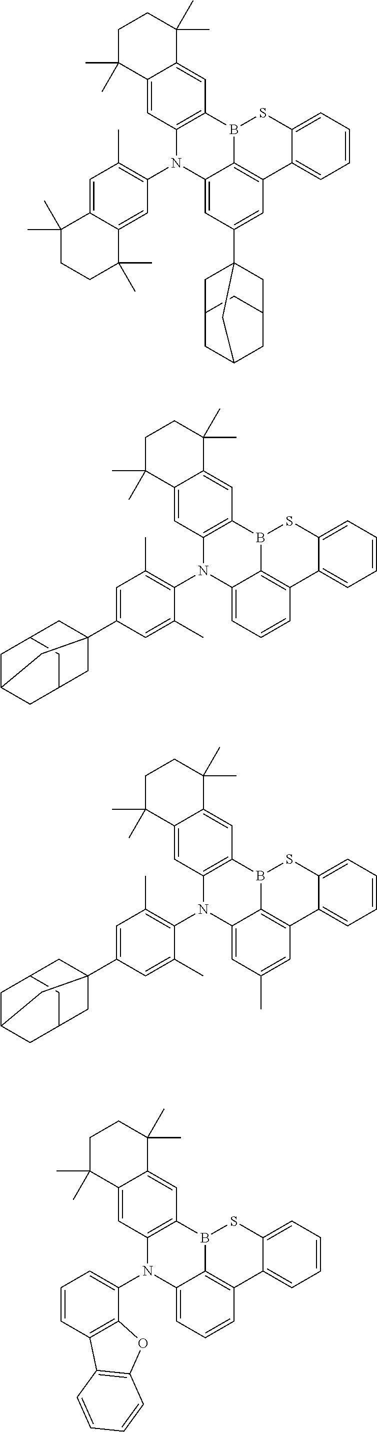 [SMILES: Cc1cc2c(cc1N1c3cc4c(cc3B3Sc5ccccc5-c5cc(C67CC8CC(CC(C8)C6)C7)cc1c53)C(C)(C)CCC4(C)C)C(C)(C)CCC2(C)C ; Cc1cc(C23CC4CC(CC(C4)C2)C3)cc(C)c1N1c2cc3c(cc2B2Sc4ccccc4-c4cccc1c42)C(C)(C)CCC3(C)C ; Cc1cc2c3c(c1)N(c1c(C)cc(C45CC6CC(CC(C6)C4)C5)cc1C)c1cc4c(cc1B3Sc1ccccc1-2)C(C)(C)CCC4(C)C ; CC1(C)CCC(C)(C)c2cc3c(cc21)B1Sc2ccccc2-c2cccc(c21)N3c1cccc2c1oc1ccccc12]

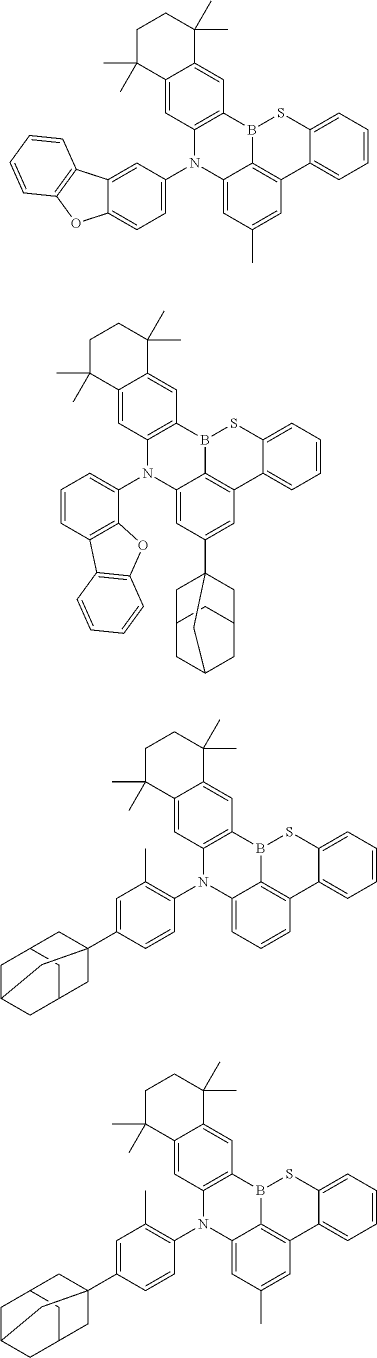 [SMILES: Cc1cc2c3c(c1)N(c1ccc4oc5ccccc5c4c1)c1cc4c(cc1B3Sc1ccccc1-2)C(C)(C)CCC4(C)C ; CC1(C)CCC(C)(C)c2cc3c(cc21)B1Sc2ccccc2-c2cc(C45CC6CC(CC(C6)C4)C5)cc(c21)N3c1cccc2c1oc1ccccc12 ; Cc1cc(C23CC4CC(CC(C4)C2)C3)ccc1N1c2cc3c(cc2B2Sc4ccccc4-c4cccc1c42)C(C)(C)CCC3(C)C ; Cc1cc2c3c(c1)N(c1ccc(C45CC6CC(CC(C6)C4)C5)cc1C)c1cc4c(cc1B3Sc1ccccc1-2)C(C)(C)CCC4(C)C]

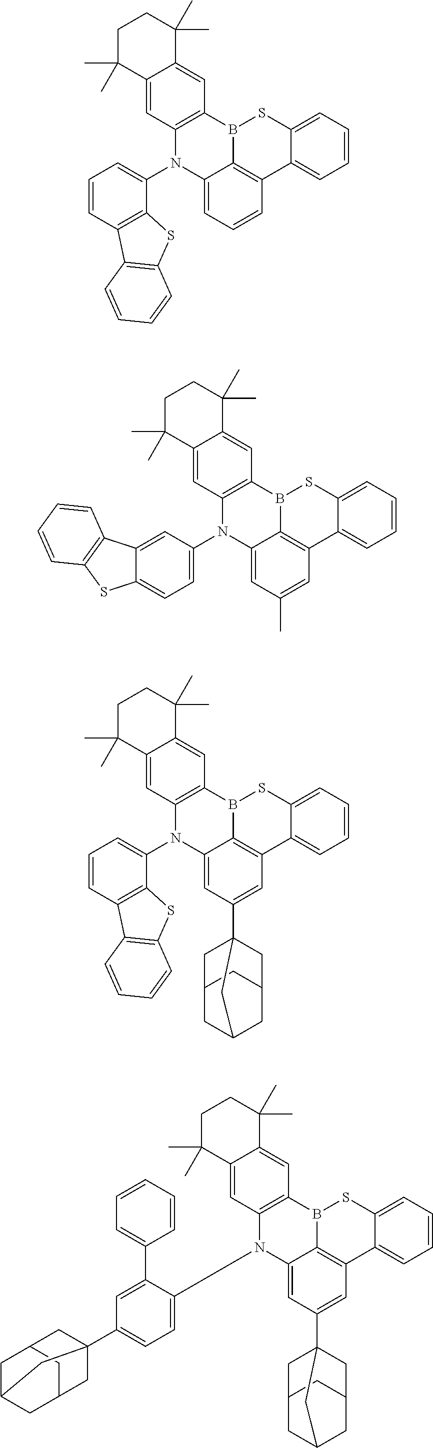 [SMILES: CC1(C)CCC(C)(C)c2cc3c(cc21)B1Sc2ccccc2-c2cccc(c21)N3c1cccc2c1sc1ccccc12 ; Cc1cc2c3c(c1)N(c1ccc4sc5ccccc5c4c1)c1cc4c(cc1B3Sc1ccccc1-2)C(C)(C)CCC4(C)C ; CC1(C)CCC(C)(C)c2cc3c(cc21)B1Sc2ccccc2-c2cc(C45CC6CC(CC(C6)C4)C5)cc(c21)N3c1cccc2c1sc1ccccc12 ; CC1(C)CCC(C)(C)c2cc3c(cc21)B1Sc2ccccc2-c2cc(C45CC6CC(CC(C6)C4)C5)cc(c21)N3c1ccc(C23CC4CC(CC(C4)C2)C3)cc1-c1ccccc1]

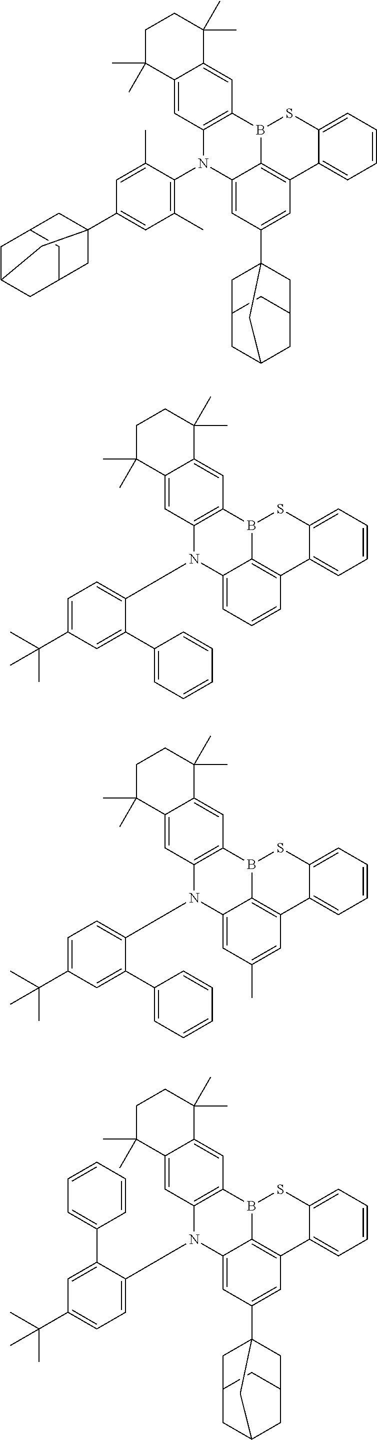

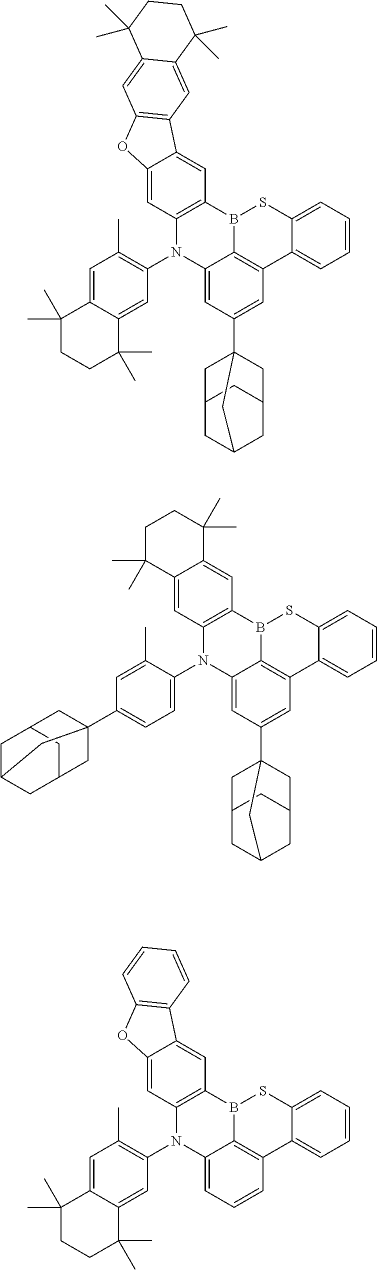 [SMILES: Cc1cc2c(cc1N1c3cc4oc5cc6c(cc5c4cc3B3Sc4ccccc4-c4cc(C57CC8CC(CC(C8)C5)C7)cc1c43)C(C)(C)CCC6(C)C)C(C)(C)CCC2(C)C ; Cc1cc(C23CC4CC(CC(C4)C2)C3)ccc1N1c2cc3c(cc2B2Sc4ccccc4-c4cc(C56CC7CC(CC(C7)C5)C6)cc1c42)C(C)(C)CCC3(C)C ; Cc1cc2c(cc1N1c3cc4oc5ccccc5c4cc3B3Sc4ccccc4-c4cccc1c43)C(C)(C)CCC2(C)C]

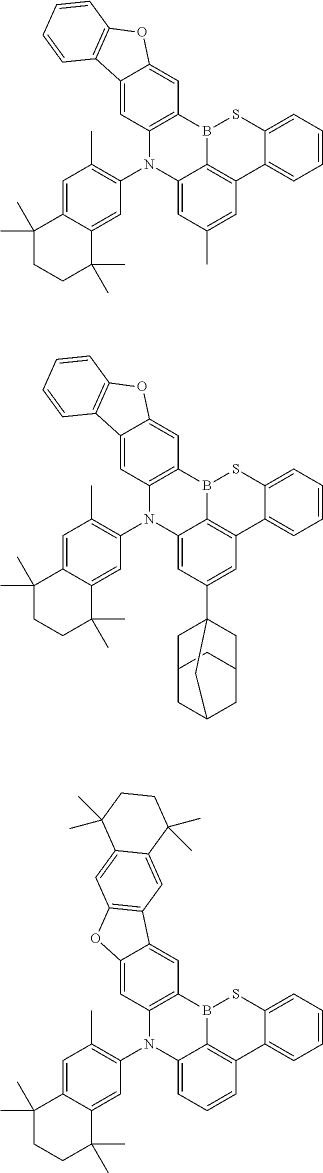 [SMILES: Cc1cc2c3c(c1)N(c1cc4c(cc1C)C(C)(C)CCC4(C)C)c1cc4c(cc1B3Sc1ccccc1-2)oc1ccccc14 ; Cc1cc2c(cc1N1c3cc4c(cc3B3Sc5ccccc5-c5cc(C67CC8CC(CC(C8)C6)C7)cc1c53)oc1ccccc14)C(C)(C)CCC2(C)C ; Cc1cc2c(cc1N1c3cc4oc5cc6c(cc5c4cc3B3Sc4ccccc4-c4cccc1c43)C(C)(C)CCC6(C)C)C(C)(C)CCC2(C)C]

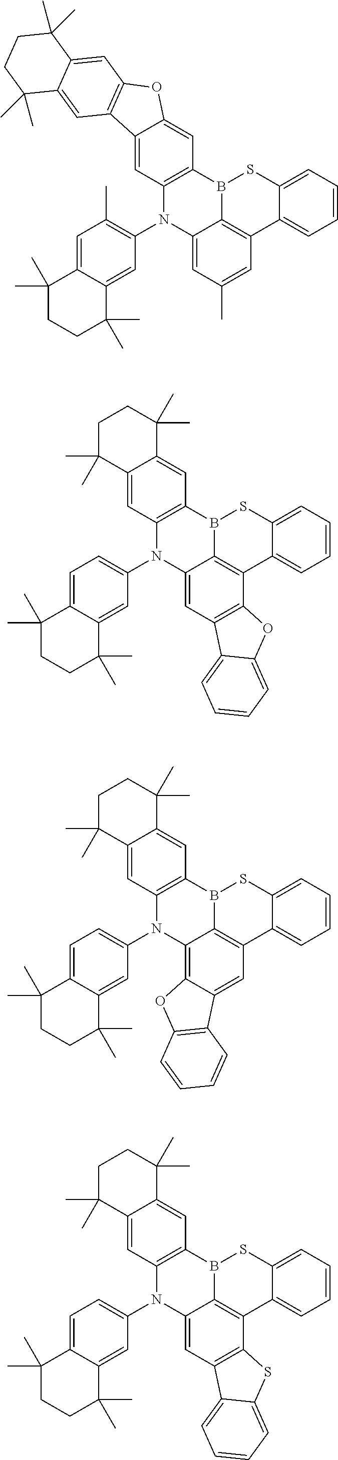 [SMILES: Cc1cc2c3c(c1)N(c1cc4c(cc1C)C(C)(C)CCC4(C)C)c1cc4c(cc1B3Sc1ccccc1-2)oc1cc2c(cc14)C(C)(C)CCC2(C)C ; CC1(C)CCC(C)(C)c2cc(N3c4cc5c(cc4B4Sc6ccccc6-c6c4c3cc3c6oc4ccccc43)C(C)(C)CCC5(C)C)ccc21 ; CC1(C)CCC(C)(C)c2cc(N3c4cc5c(cc4B4Sc6ccccc6-c6cc7c(oc8ccccc87)c3c64)C(C)(C)CCC5(C)C)ccc21 ; CC1(C)CCC(C)(C)c2cc(N3c4cc5c(cc4B4Sc6ccccc6-c6c4c3cc3c6sc4ccccc43)C(C)(C)CCC5(C)C)ccc21]

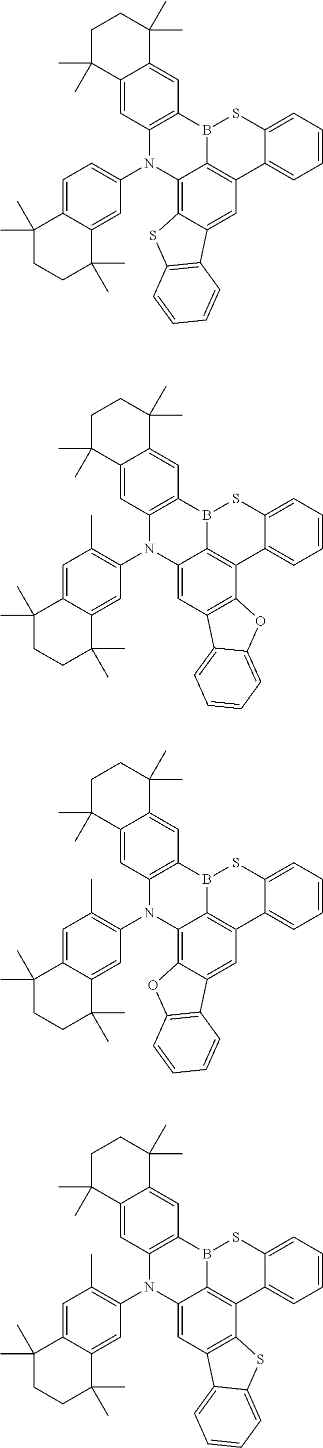 [SMILES: CC1(C)CCC(C)(C)c2cc(N3c4cc5c(cc4B4Sc6ccccc6-c6cc7c(sc8ccccc87)c3c64)C(C)(C)CCC5(C)C)ccc21 ; Cc1cc2c(cc1N1c3cc4c(cc3B3Sc5ccccc5-c5c3c1cc1c5oc3ccccc31)C(C)(C)CCC4(C)C)C(C)(C)CCC2(C)C ; Cc1cc2c(cc1N1c3cc4c(cc3B3Sc5ccccc5-c5cc6c(oc7ccccc76)c1c53)C(C)(C)CCC4(C)C)C(C)(C)CCC2(C)C ; Cc1cc2c(cc1N1c3cc4c(cc3B3Sc5ccccc5-c5c3c1cc1c5sc3ccccc31)C(C)(C)CCC4(C)C)C(C)(C)CCC2(C)C]

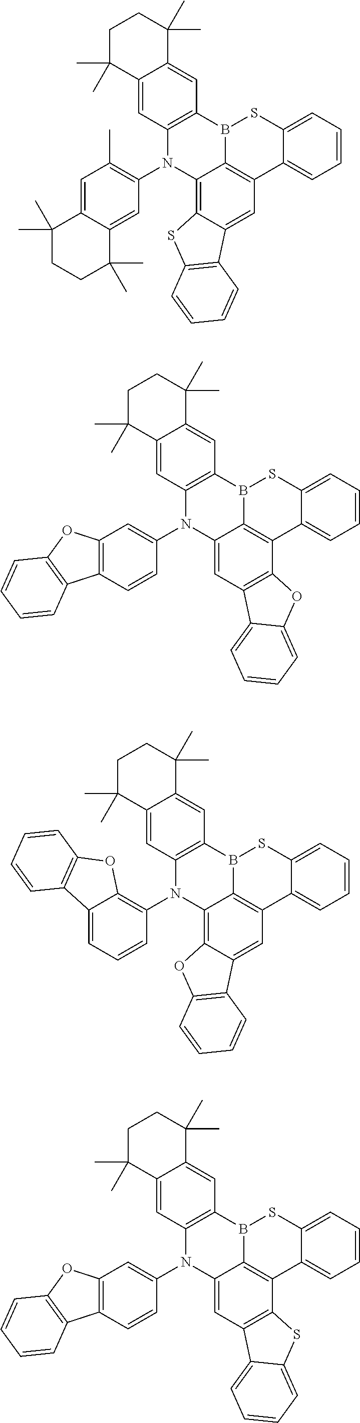

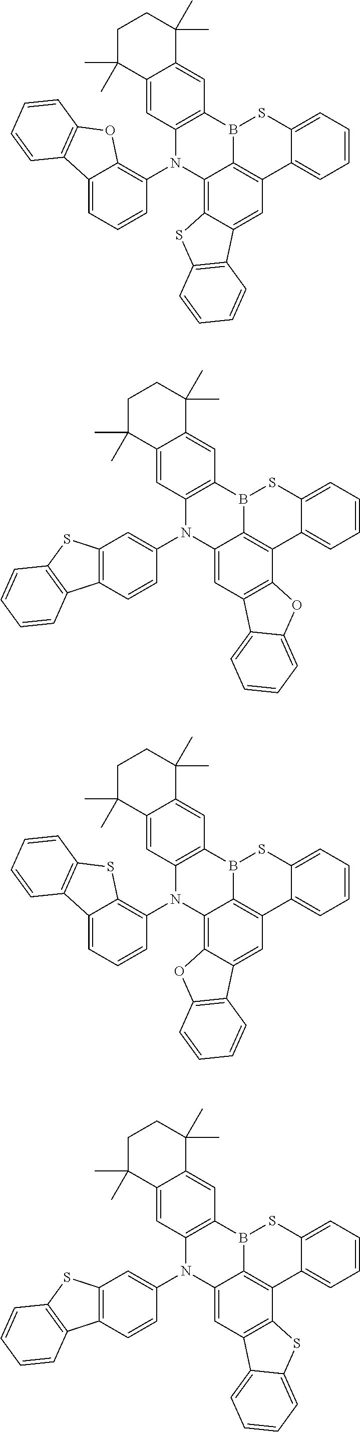 [SMILES: CC1(C)CCC(C)(C)c2cc3c(cc21)B1Sc2ccccc2-c2cc4c(sc5ccccc54)c(c21)N3c1cccc2c1oc1ccccc12 ; CC1(C)CCC(C)(C)c2cc3c(cc21)B1Sc2ccccc2-c2c1c(cc1c2oc2ccccc21)N3c1ccc2c(c1)sc1ccccc12 ; CC1(C)CCC(C)(C)c2cc3c(cc21)B1Sc2ccccc2-c2cc4c(oc5ccccc54)c(c21)N3c1cccc2c1sc1ccccc12 ; CC1(C)CCC(C)(C)c2cc3c(cc21)B1Sc2ccccc2-c2c1c(cc1c2sc2ccccc21)N3c1ccc2c(c1)sc1ccccc12]

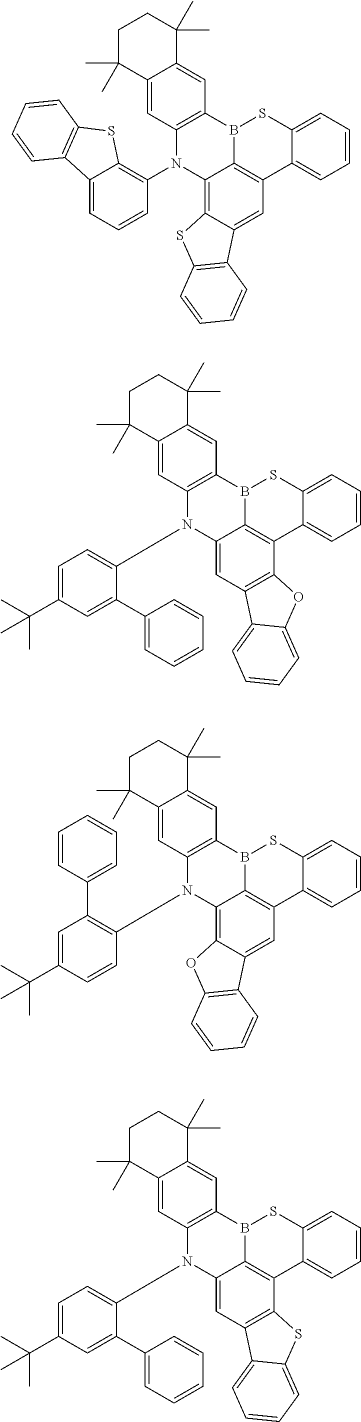

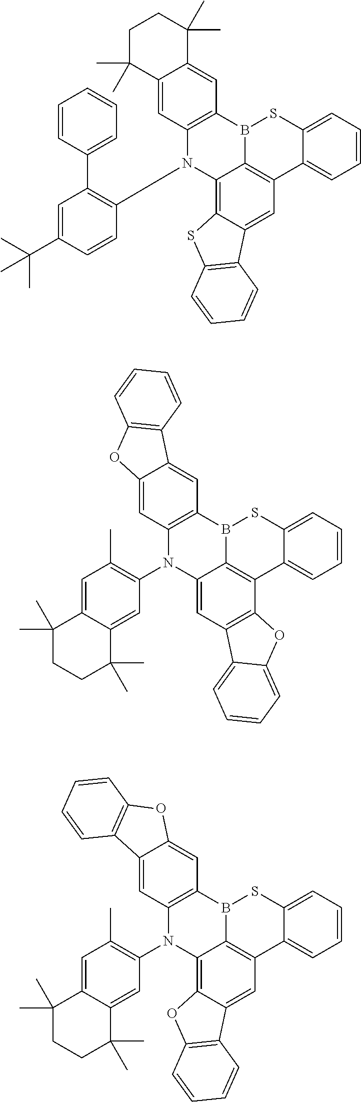 [SMILES: CC(C)(C)c1ccc(N2c3cc4c(cc3B3Sc5ccccc5-c5cc6c(sc7ccccc76)c2c53)C(C)(C)CCC4(C)C)c(-c2ccccc2)c1 ; Cc1cc2c(cc1N1c3cc4oc5ccccc5c4cc3B3Sc4ccccc4-c4c3c1cc1c4oc3ccccc31)C(C)(C)CCC2(C)C ; Cc1cc2c(cc1N1c3cc4c(cc3B3Sc5ccccc5-c5cc6c(oc7ccccc76)c1c53)oc1ccccc14)C(C)(C)CCC2(C)C]

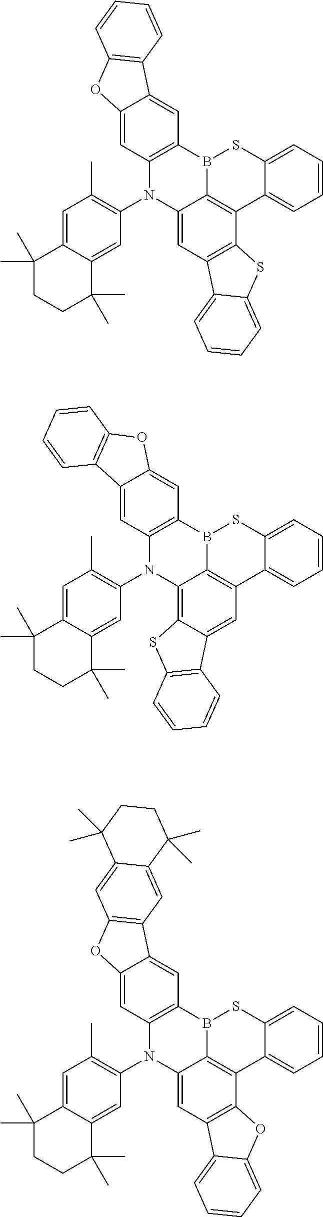 [SMILES: Cc1cc2c(cc1N1c3cc4oc5ccccc5c4cc3B3Sc4ccccc4-c4c3c1cc1c4sc3ccccc31)C(C)(C)CCC2(C)C ; Cc1cc2c(cc1N1c3cc4c(cc3B3Sc5ccccc5-c5cc6c(sc7ccccc76)c1c53)oc1ccccc14)C(C)(C)CCC2(C)C ; Cc1cc2c(cc1N1c3cc4oc5cc6c(cc5c4cc3B3Sc4ccccc4-c4c3c1cc1c4oc3ccccc31)C(C)(C)CCC6(C)C)C(C)(C)CCC2(C)C]

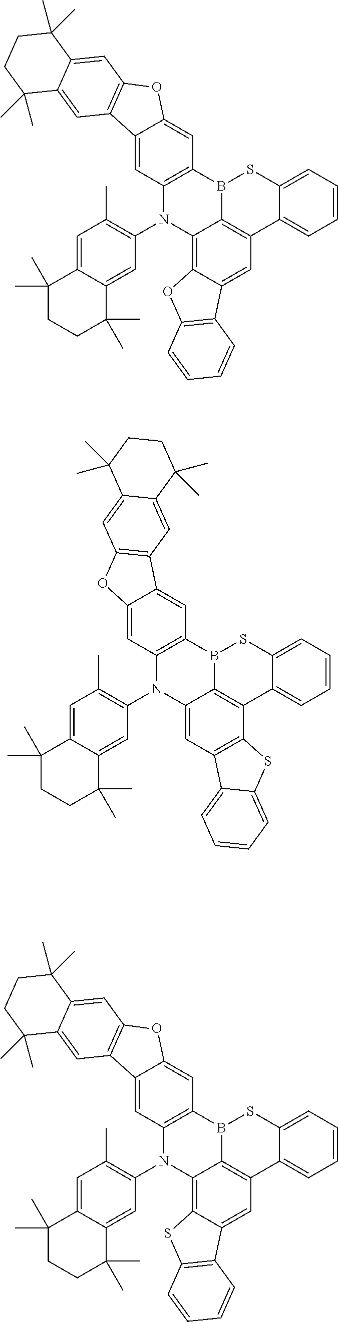 [SMILES: Cc1cc2c(cc1N1c3cc4c(cc3B3Sc5ccccc5-c5cc6c(oc7ccccc76)c1c53)oc1cc3c(cc14)C(C)(C)CCC3(C)C)C(C)(C)CCC2(C)C ; Cc1cc2c(cc1N1c3cc4oc5cc6c(cc5c4cc3B3Sc4ccccc4-c4c3c1cc1c4sc3ccccc31)C(C)(C)CCC6(C)C)C(C)(C)CCC2(C)C ; Cc1cc2c(cc1N1c3cc4c(cc3B3Sc5ccccc5-c5cc6c(sc7ccccc76)c1c53)oc1cc3c(cc14)C(C)(C)CCC3(C)C)C(C)(C)CCC2(C)C]

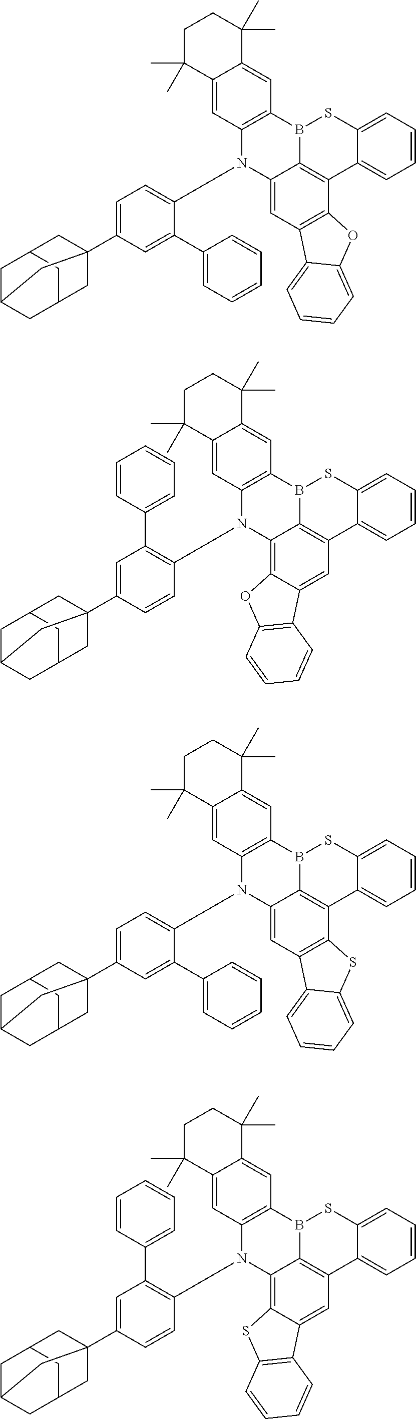

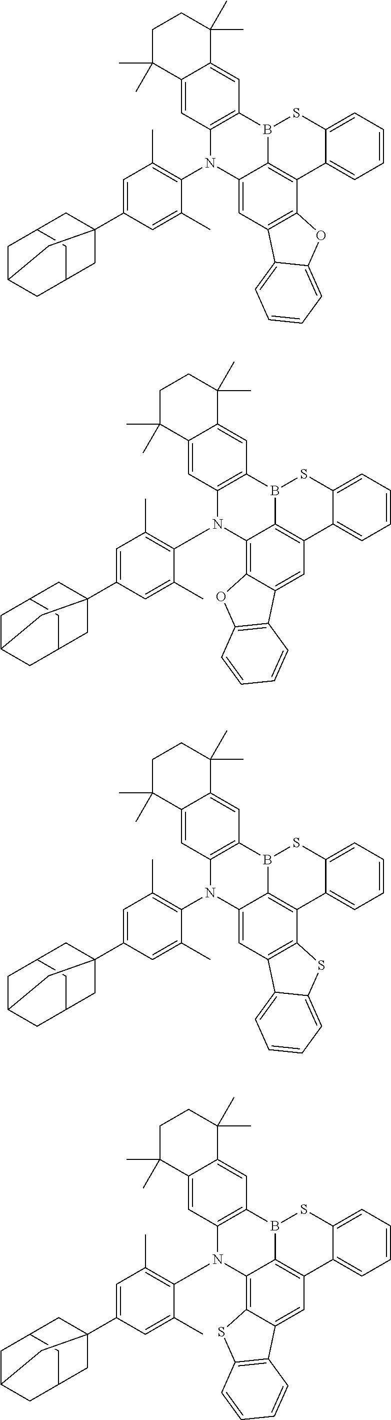 [SMILES: Cc1cc(C23CC4CC(CC(C4)C2)C3)cc(C)c1N1c2cc3c(cc2B2Sc4ccccc4-c4c2c1cc1c4oc2ccccc21)C(C)(C)CCC3(C)C ; Cc1cc(C23CC4CC(CC(C4)C2)C3)cc(C)c1N1c2cc3c(cc2B2Sc4ccccc4-c4cc5c(oc6ccccc65)c1c42)C(C)(C)CCC3(C)C ; Cc1cc(C23CC4CC(CC(C4)C2)C3)cc(C)c1N1c2cc3c(cc2B2Sc4ccccc4-c4c2c1cc1c4sc2ccccc21)C(C)(C)CCC3(C)C ; Cc1cc(C23CC4CC(CC(C4)C2)C3)cc(C)c1N1c2cc3c(cc2B2Sc4ccccc4-c4cc5c(sc6ccccc65)c1c42)C(C)(C)CCC3(C)C]

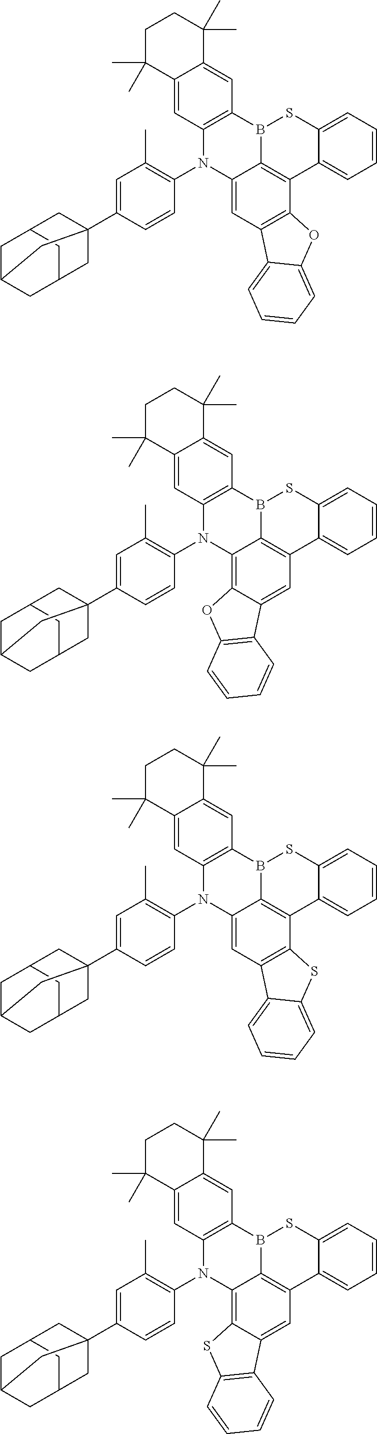

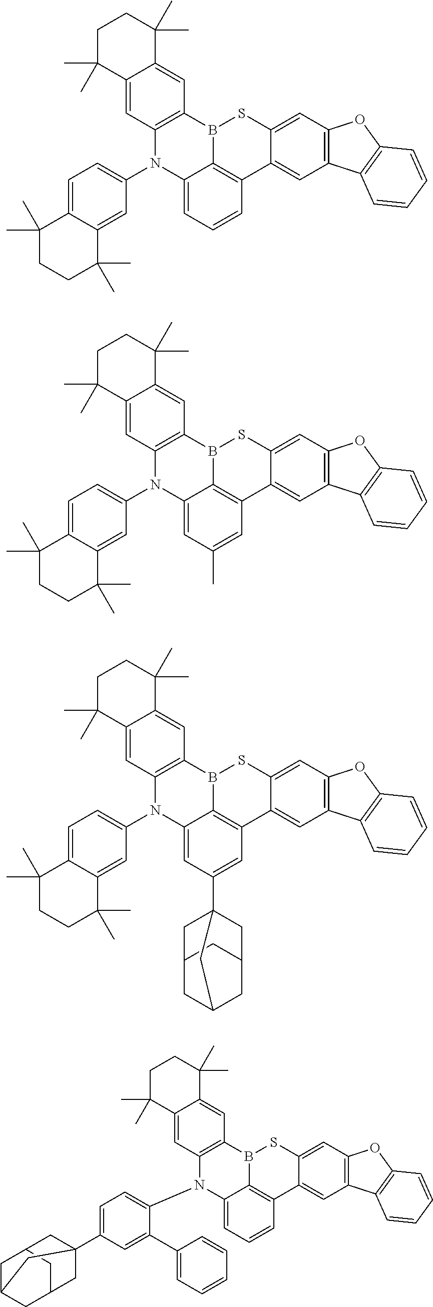

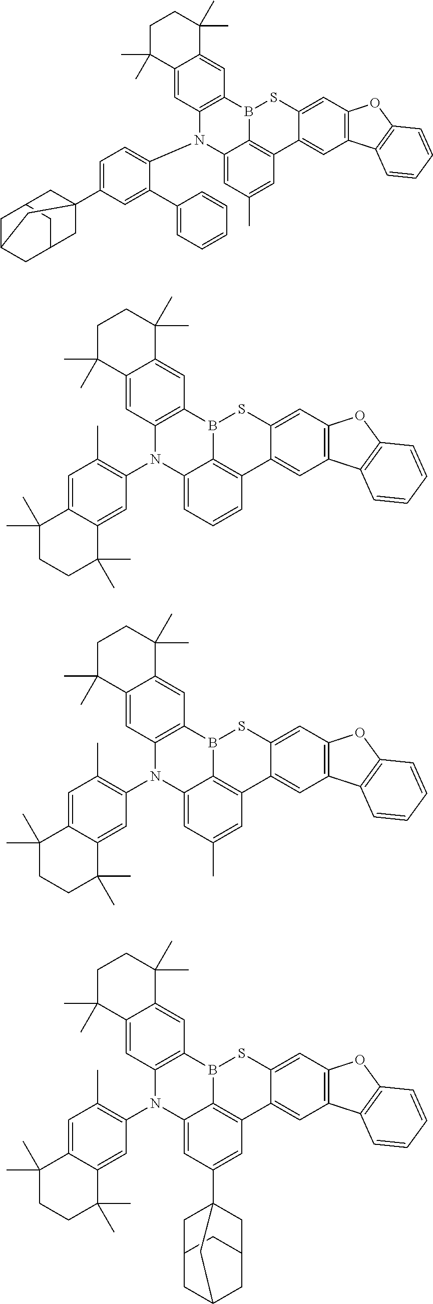

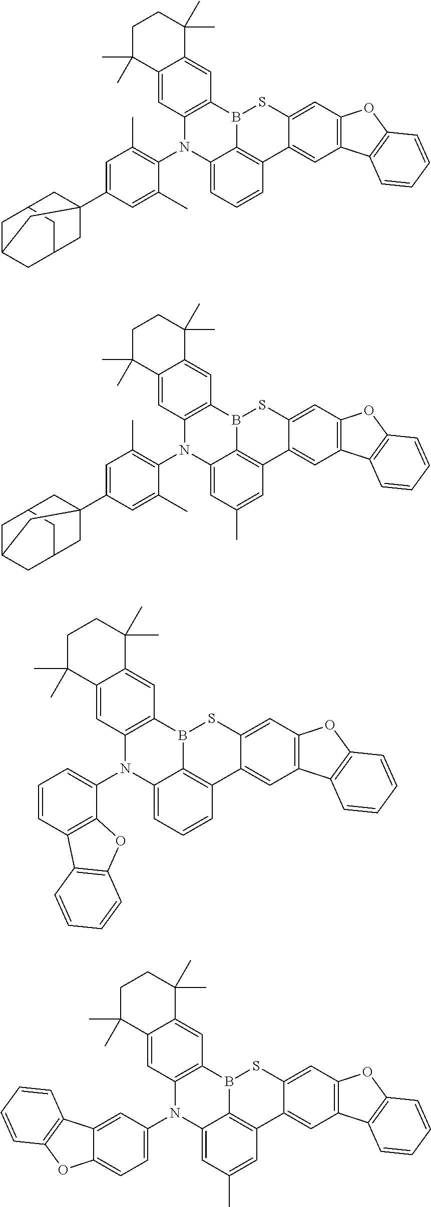 [SMILES: Cc1cc(C23CC4CC(CC(C4)C2)C3)cc(C)c1N1c2cc3c(cc2B2Sc4cc5oc6ccccc6c5cc4-c4cccc1c42)C(C)(C)CCC3(C)C ; Cc1cc2c3c(c1)N(c1c(C)cc(C45CC6CC(CC(C6)C4)C5)cc1C)c1cc4c(cc1B3Sc1cc3oc5ccccc5c3cc1-2)C(C)(C)CCC4(C)C ; CC1(C)CCC(C)(C)c2cc3c(cc21)B1Sc2cc4oc5ccccc5c4cc2-c2cccc(c21)N3c1cccc2c1oc1ccccc12 ; Cc1cc2c3c(c1)N(c1ccc4oc5ccccc5c4c1)c1cc4c(cc1B3Sc1cc3oc5ccccc5c3cc1-2)C(C)(C)CCC4(C)C]

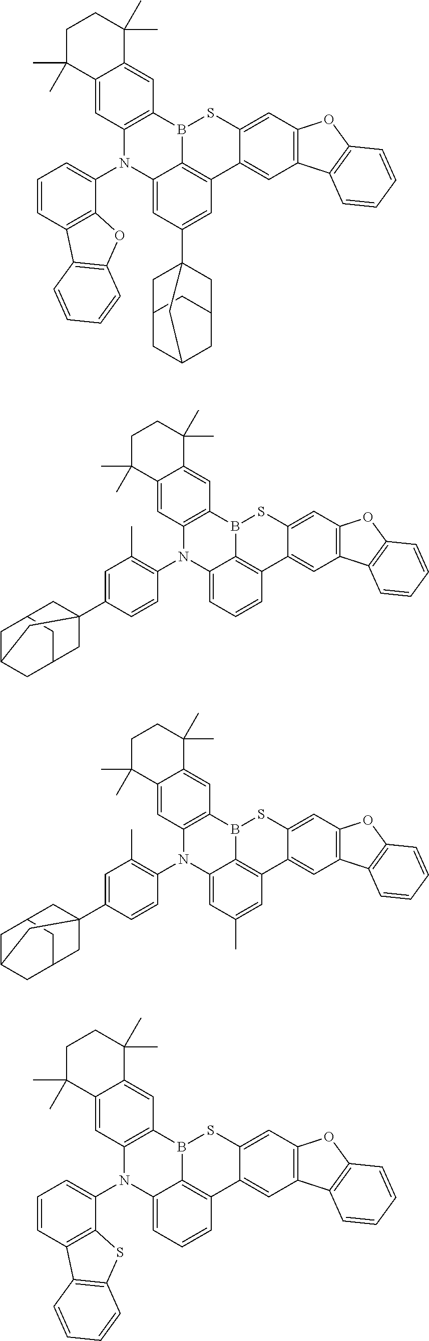 [SMILES: CC1(C)CCC(C)(C)c2cc3c(cc21)B1Sc2cc4oc5ccccc5c4cc2-c2cc(C45CC6CC(CC(C6)C4)C5)cc(c21)N3c1cccc2c1oc1ccccc12 ; Cc1cc(C23CC4CC(CC(C4)C2)C3)ccc1N1c2cc3c(cc2B2Sc4cc5oc6ccccc6c5cc4-c4cccc1c42)C(C)(C)CCC3(C)C ; Cc1cc2c3c(c1)N(c1ccc(C45CC6CC(CC(C6)C4)C5)cc1C)c1cc4c(cc1B3Sc1cc3oc5ccccc5c3cc1-2)C(C)(C)CCC4(C)C ; CC1(C)CCC(C)(C)c2cc3c(cc21)B1Sc2cc4oc5ccccc5c4cc2-c2cccc(c21)N3c1cccc2c1sc1ccccc12]

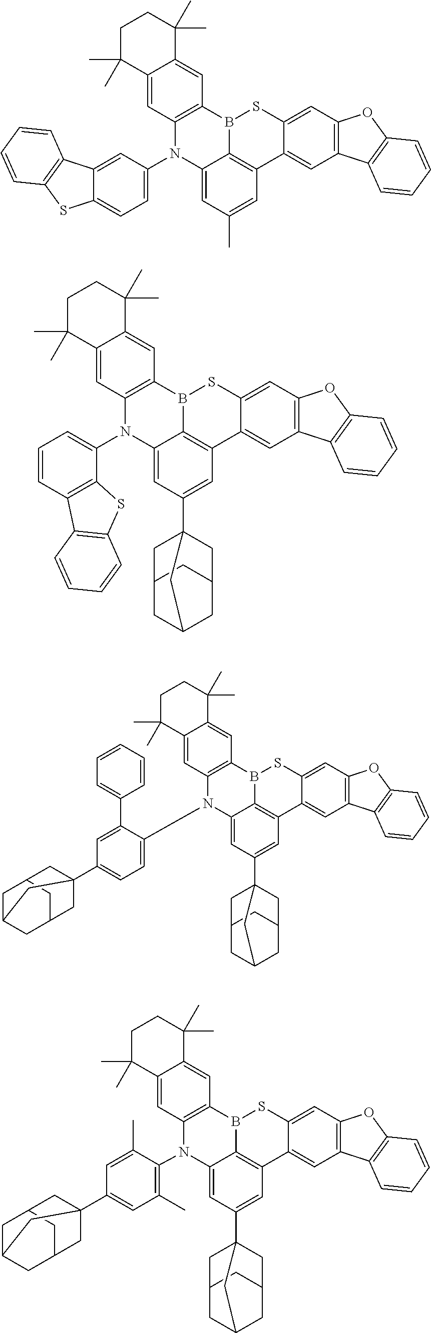 [SMILES: Cc1cc2c3c(c1)N(c1ccc4sc5ccccc5c4c1)c1cc4c(cc1B3Sc1cc3oc5ccccc5c3cc1-2)C(C)(C)CCC4(C)C ; CC1(C)CCC(C)(C)c2cc3c(cc21)B1Sc2cc4oc5ccccc5c4cc2-c2cc(C45CC6CC(CC(C6)C4)C5)cc(c21)N3c1cccc2c1sc1ccccc12 ; CC1(C)CCC(C)(C)c2cc3c(cc21)B1Sc2cc4oc5ccccc5c4cc2-c2cc(C45CC6CC(CC(C6)C4)C5)cc(c21)N3c1ccc(C23CC4CC(CC(C4)C2)C3)cc1-c1ccccc1 ; Cc1cc(C23CC4CC(CC(C4)C2)C3)cc(C)c1N1c2cc3c(cc2B2Sc4cc5oc6ccccc6c5cc4-c4cc(C56CC7CC(CC(C7)C5)C6)cc1c42)C(C)(C)CCC3(C)C]

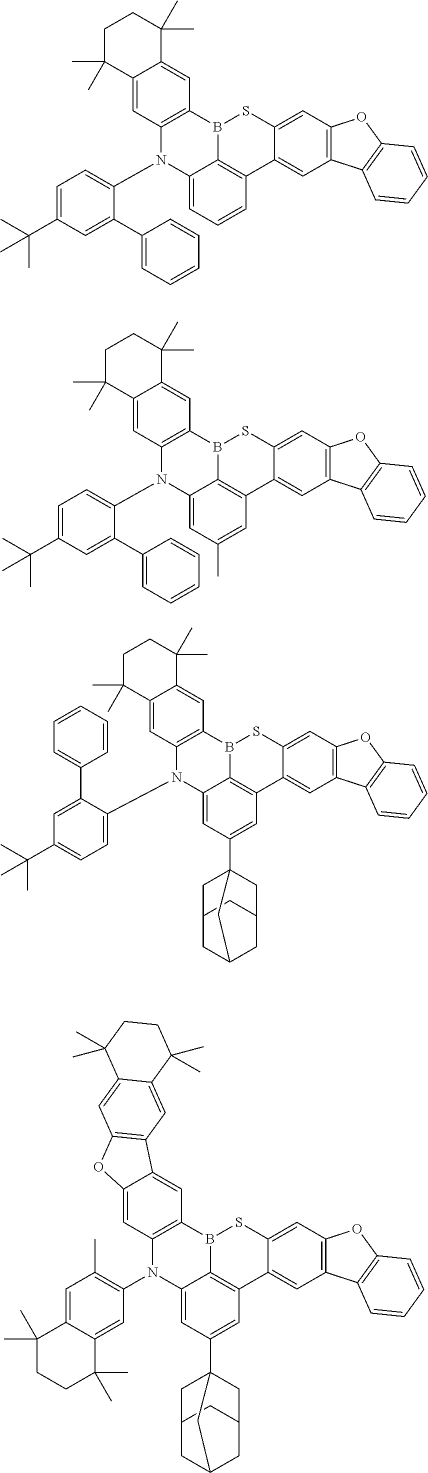

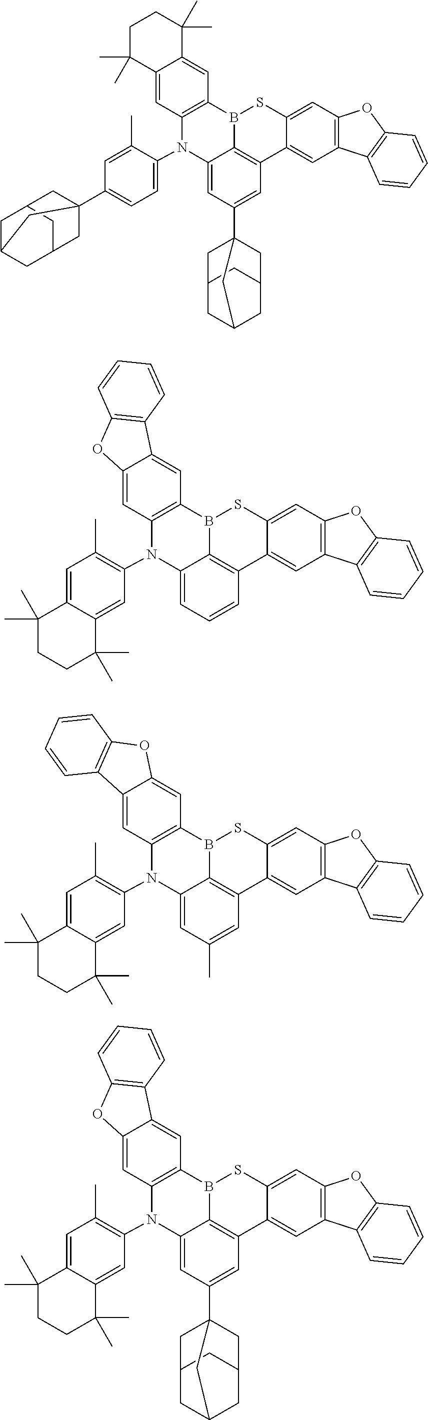

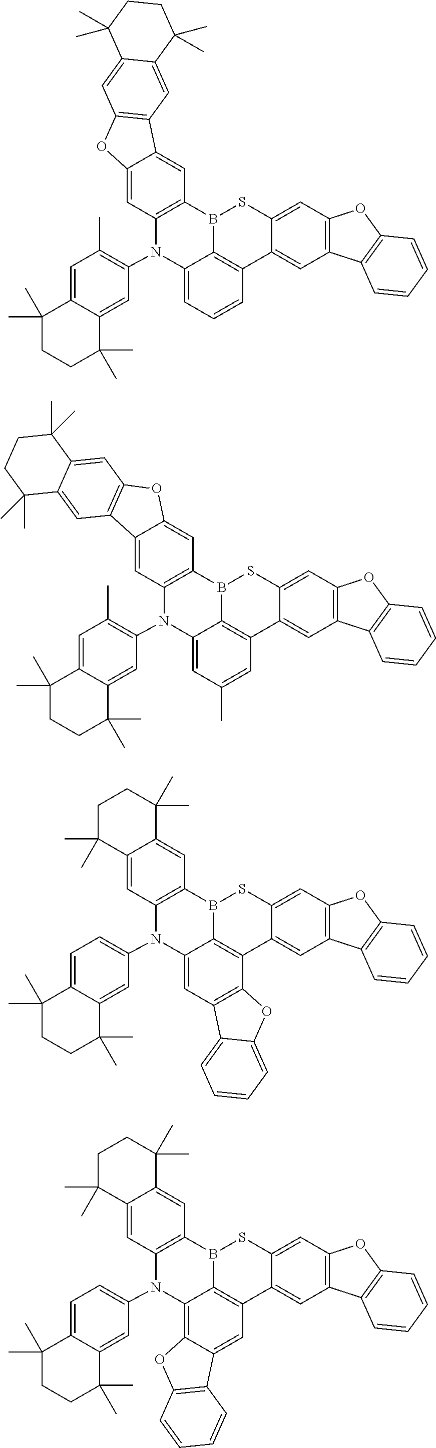

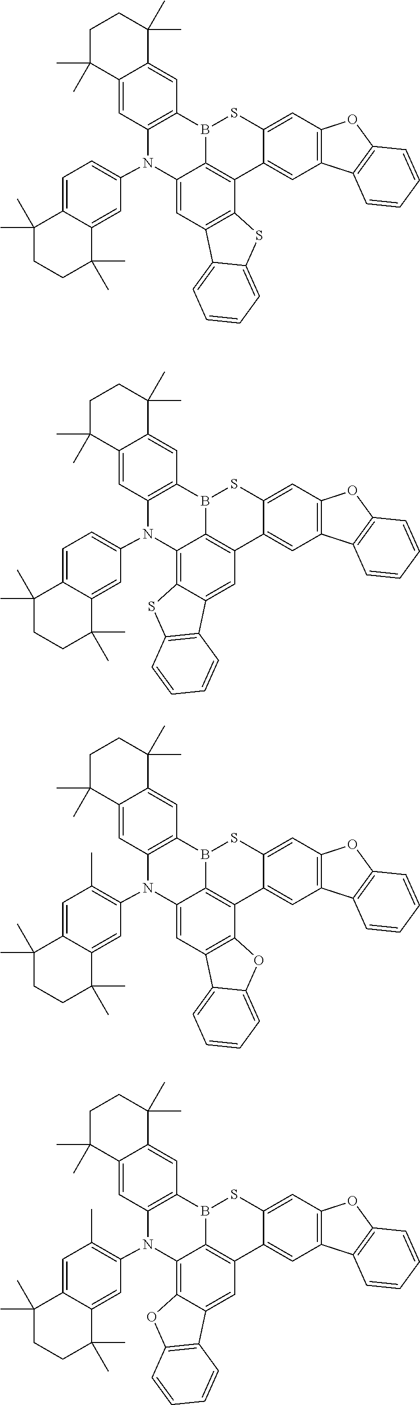

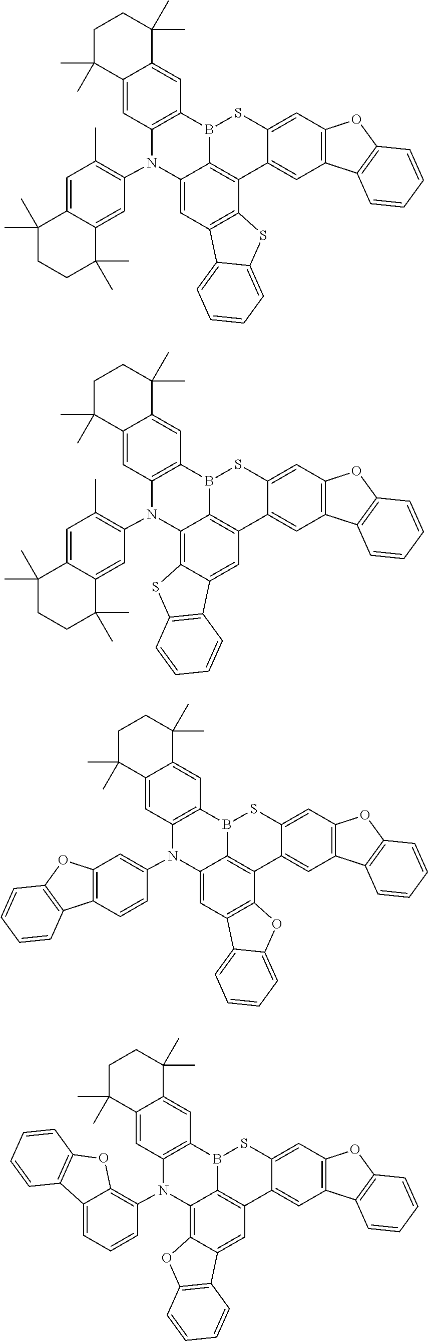

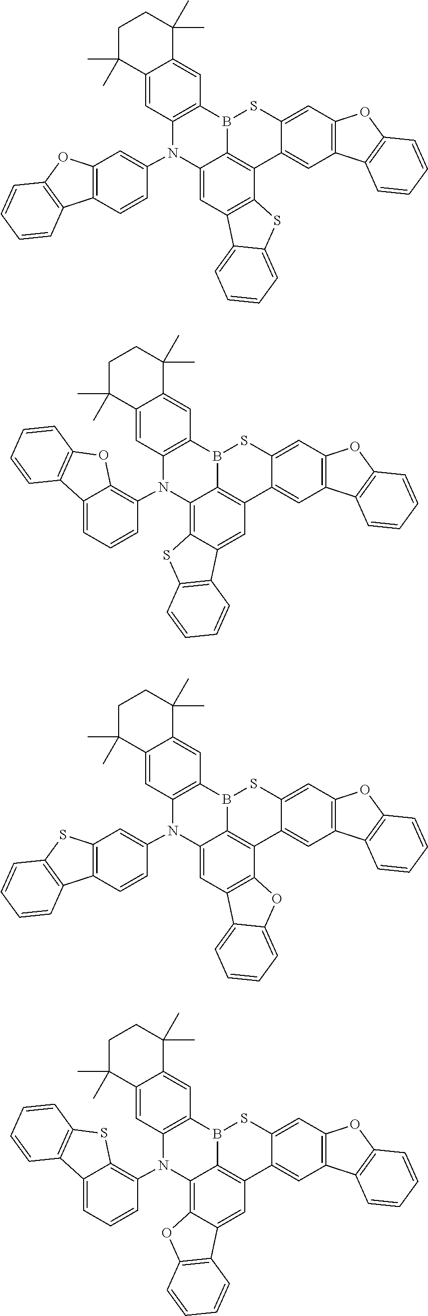

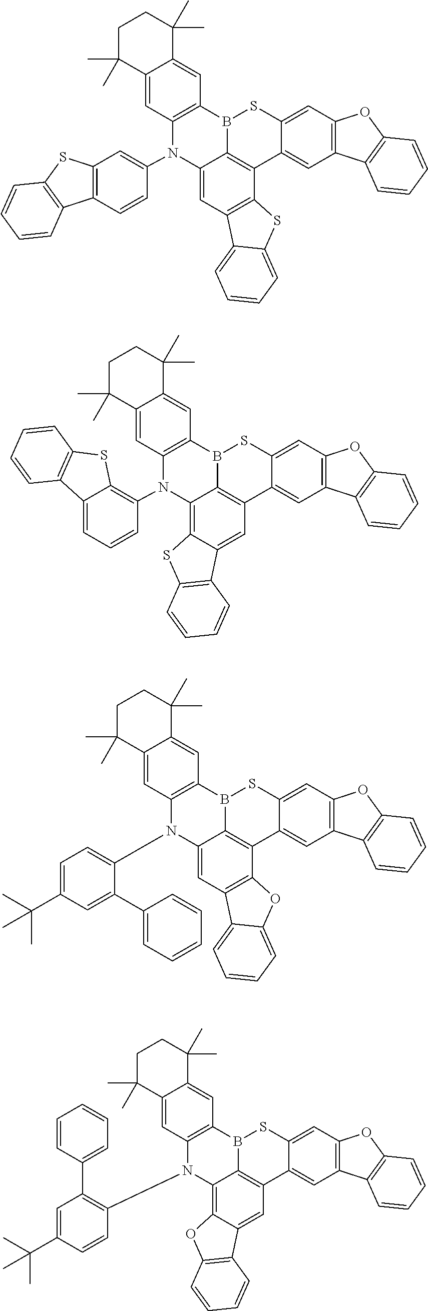

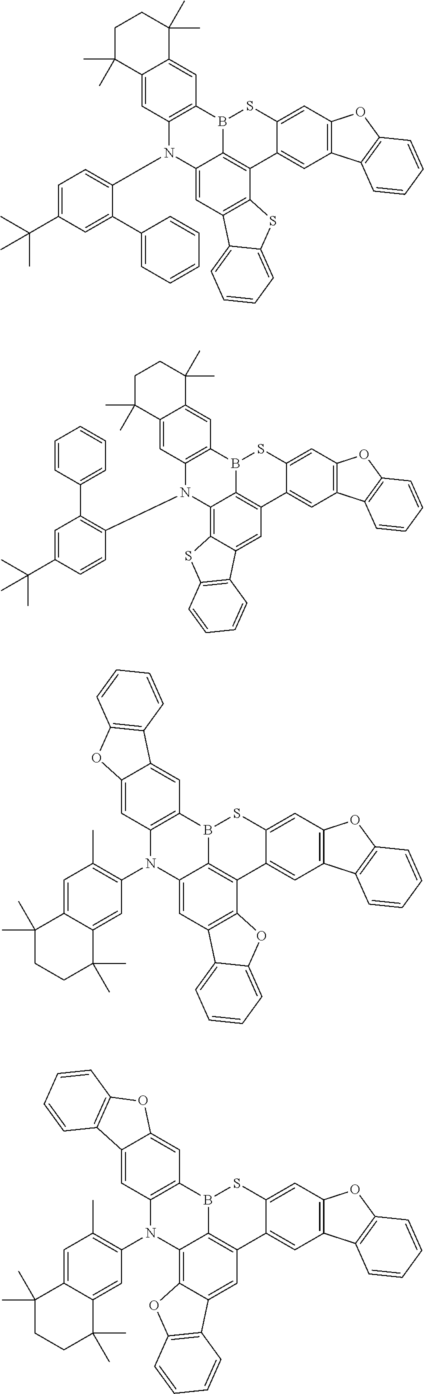 [SMILES: CC(C)(C)c1ccc(N2c3cc4c(cc3B3Sc5cc6oc7ccccc7c6cc5-c5c3c2cc2c5sc3ccccc32)C(C)(C)CCC4(C)C)c(-c2ccccc2)c1 ; CC(C)(C)c1ccc(N2c3cc4c(cc3B3Sc5cc6oc7ccccc7c6cc5-c5cc6c(sc7ccccc76)c2c53)C(C)(C)CCC4(C)C)c(-c2ccccc2)c1 ; Cc1cc2c(cc1N1c3cc4oc5ccccc5c4cc3B3Sc4cc5oc6ccccc6c5cc4-c4c3c1cc1c4oc3ccccc31)C(C)(C)CCC2(C)C ; Cc1cc2c(cc1N1c3cc4c(cc3B3Sc5cc6oc7ccccc7c6cc5-c5cc6c(oc7ccccc76)c1c53)oc1ccccc14)C(C)(C)CCC2(C)C]

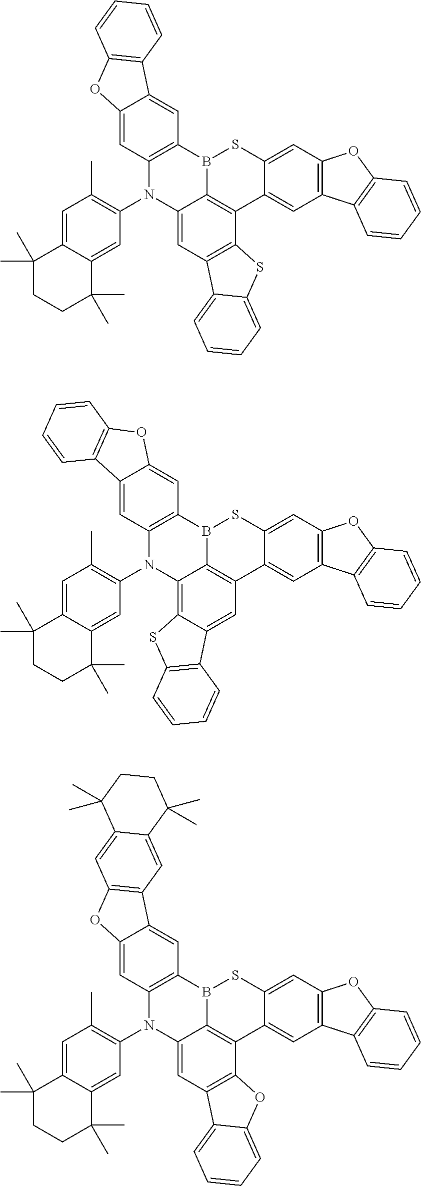 [SMILES: Cc1cc2c(cc1N1c3cc4oc5ccccc5c4cc3B3Sc4cc5oc6ccccc6c5cc4-c4c3c1cc1c4sc3ccccc31)C(C)(C)CCC2(C)C ; Cc1cc2c(cc1N1c3cc4c(cc3B3Sc5cc6oc7ccccc7c6cc5-c5cc6c(sc7ccccc76)c1c53)oc1ccccc14)C(C)(C)CCC2(C)C ; Cc1cc2c(cc1N1c3cc4oc5cc6c(cc5c4cc3B3Sc4cc5oc7ccccc7c5cc4-c4c3c1cc1c4oc3ccccc31)C(C)(C)CCC6(C)C)C(C)(C)CCC2(C)C]

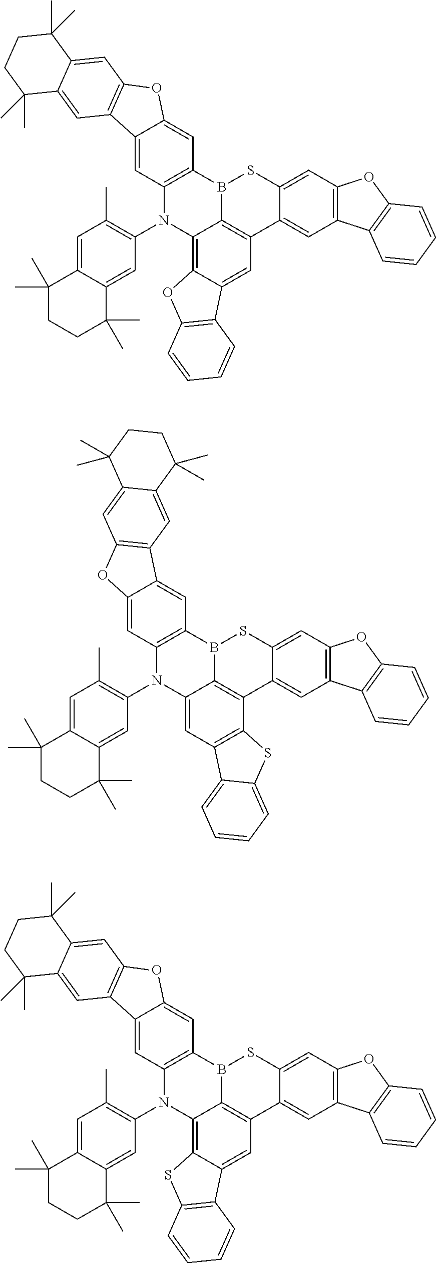 [SMILES: Cc1cc2c(cc1N1c3cc4c(cc3B3Sc5cc6oc7ccccc7c6cc5-c5cc6c(oc7ccccc76)c1c53)oc1cc3c(cc14)C(C)(C)CCC3(C)C)C(C)(C)CCC2(C)C ; Cc1cc2c(cc1N1c3cc4oc5cc6c(cc5c4cc3B3Sc4cc5oc7ccccc7c5cc4-c4c3c1cc1c4sc3ccccc31)C(C)(C)CCC6(C)C)C(C)(C)CCC2(C)C ; Cc1cc2c(cc1N1c3cc4c(cc3B3Sc5cc6oc7ccccc7c6cc5-c5cc6c(sc7ccccc76)c1c53)oc1cc3c(cc14)C(C)(C)CCC3(C)C)C(C)(C)CCC2(C)C]

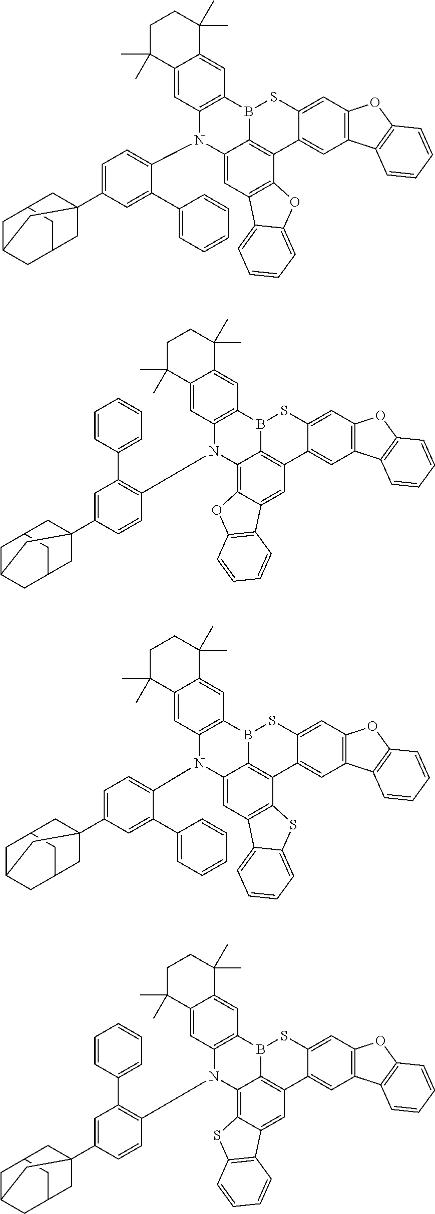 [SMILES: CC1(C)CCC(C)(C)c2cc3c(cc21)B1Sc2cc4oc5ccccc5c4cc2-c2c1c(cc1c2oc2ccccc21)N3c1ccc(C23CC4CC(CC(C4)C2)C3)cc1-c1ccccc1 ; CC1(C)CCC(C)(C)c2cc3c(cc21)B1Sc2cc4oc5ccccc5c4cc2-c2cc4c(oc5ccccc54)c(c21)N3c1ccc(C23CC4CC(CC(C4)C2)C3)cc1-c1ccccc1 ; CC1(C)CCC(C)(C)c2cc3c(cc21)B1Sc2cc4oc5ccccc5c4cc2-c2c1c(cc1c2sc2ccccc21)N3c1ccc(C23CC4CC(CC(C4)C2)C3)cc1-c1ccccc1 ; CC1(C)CCC(C)(C)c2cc3c(cc21)B1Sc2cc4oc5ccccc5c4cc2-c2cc4c(sc5ccccc54)c(c21)N3c1ccc(C23CC4CC(CC(C4)C2)C3)cc1-c1ccccc1]

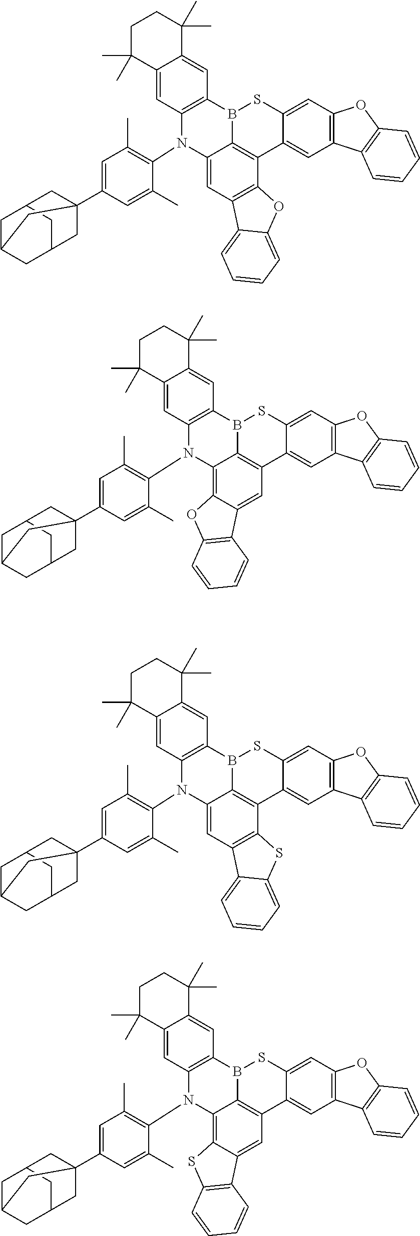 [SMILES: Cc1cc(C23CC4CC(CC(C4)C2)C3)cc(C)c1N1c2cc3c(cc2B2Sc4cc5oc6ccccc6c5cc4-c4c2c1cc1c4oc2ccccc21)C(C)(C)CCC3(C)C ; Cc1cc(C23CC4CC(CC(C4)C2)C3)cc(C)c1N1c2cc3c(cc2B2Sc4cc5oc6ccccc6c5cc4-c4cc5c(oc6ccccc65)c1c42)C(C)(C)CCC3(C)C ; Cc1cc(C23CC4CC(CC(C4)C2)C3)cc(C)c1N1c2cc3c(cc2B2Sc4cc5oc6ccccc6c5cc4-c4c2c1cc1c4sc2ccccc21)C(C)(C)CCC3(C)C ; Cc1cc(C23CC4CC(CC(C4)C2)C3)cc(C)c1N1c2cc3c(cc2B2Sc4cc5oc6ccccc6c5cc4-c4cc5c(sc6ccccc65)c1c42)C(C)(C)CCC3(C)C]

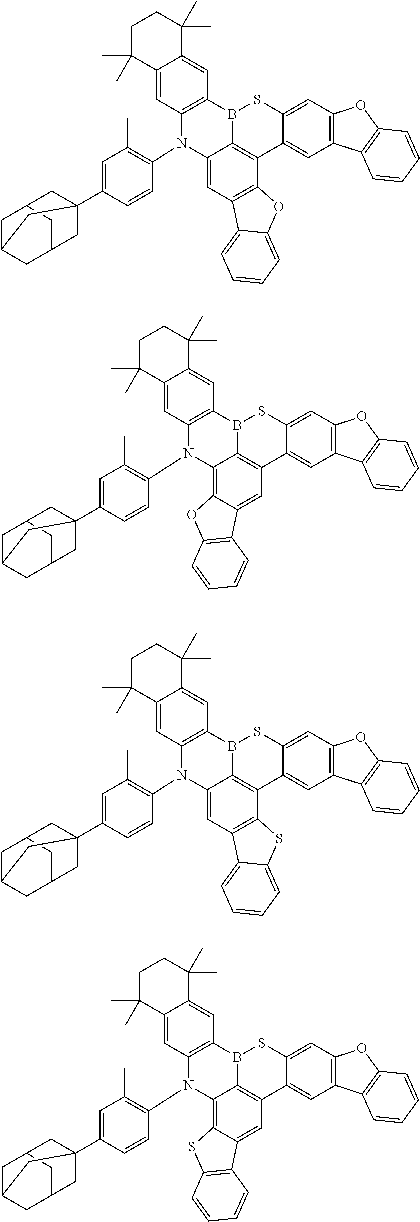 [SMILES: Cc1cc(C23CC4CC(CC(C4)C2)C3)ccc1N1c2cc3c(cc2B2Sc4cc5oc6ccccc6c5cc4-c4c2c1cc1c4oc2ccccc21)C(C)(C)CCC3(C)C ; Cc1cc(C23CC4CC(CC(C4)C2)C3)ccc1N1c2cc3c(cc2B2Sc4cc5oc6ccccc6c5cc4-c4cc5c(oc6ccccc65)c1c42)C(C)(C)CCC3(C)C ; Cc1cc(C23CC4CC(CC(C4)C2)C3)ccc1N1c2cc3c(cc2B2Sc4cc5oc6ccccc6c5cc4-c4c2c1cc1c4sc2ccccc21)C(C)(C)CCC3(C)C ; Cc1cc(C23CC4CC(CC(C4)C2)C3)ccc1N1c2cc3c(cc2B2Sc4cc5oc6ccccc6c5cc4-c4cc5c(sc6ccccc65)c1c42)C(C)(C)CCC3(C)C]

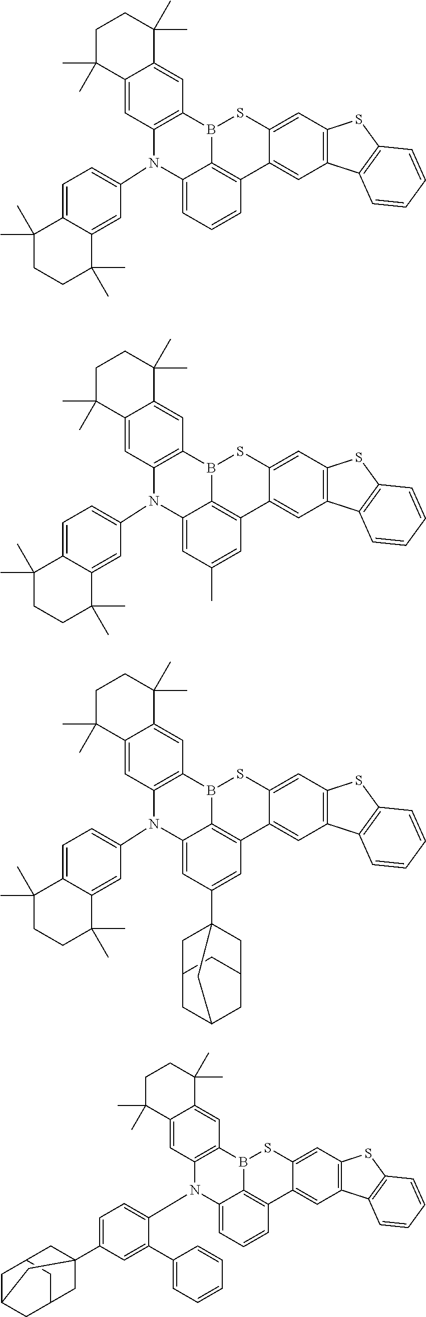

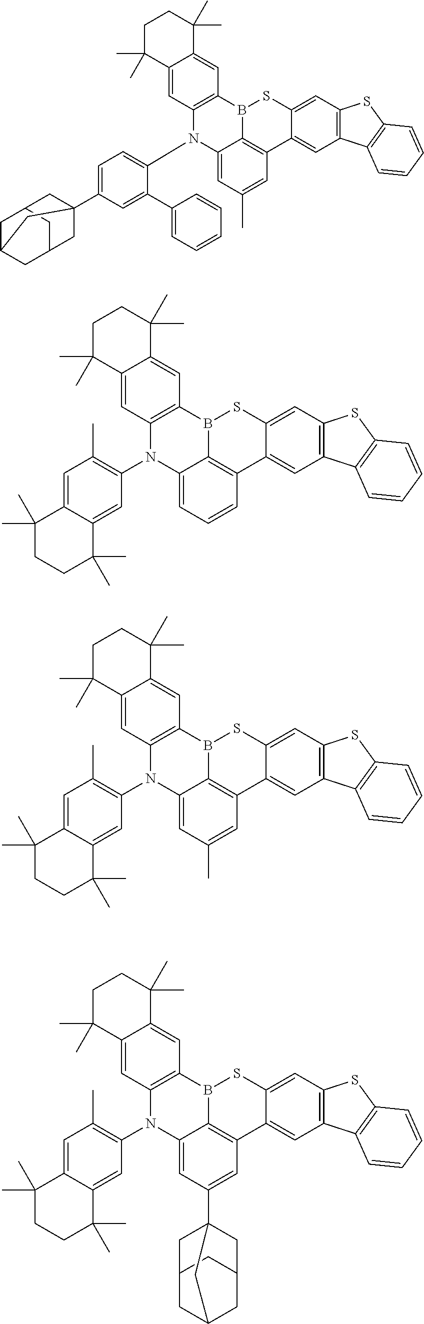

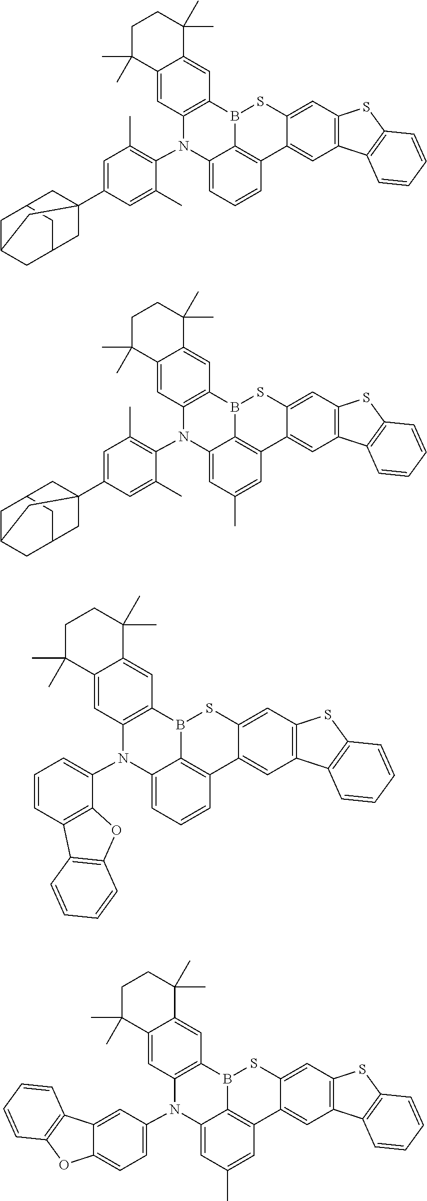 [SMILES: Cc1cc(C23CC4CC(CC(C4)C2)C3)cc(C)c1N1c2cc3c(cc2B2Sc4cc5sc6ccccc6c5cc4-c4cccc1c42)C(C)(C)CCC3(C)C ; Cc1cc2c3c(c1)N(c1c(C)cc(C45CC6CC(CC(C6)C4)C5)cc1C)c1cc4c(cc1B3Sc1cc3sc5ccccc5c3cc1-2)C(C)(C)CCC4(C)C ; CC1(C)CCC(C)(C)c2cc3c(cc21)B1Sc2cc4sc5ccccc5c4cc2-c2cccc(c21)N3c1cccc2c1oc1ccccc12 ; Cc1cc2c3c(c1)N(c1ccc4oc5ccccc5c4c1)c1cc4c(cc1B3Sc1cc3sc5ccccc5c3cc1-2)C(C)(C)CCC4(C)C]

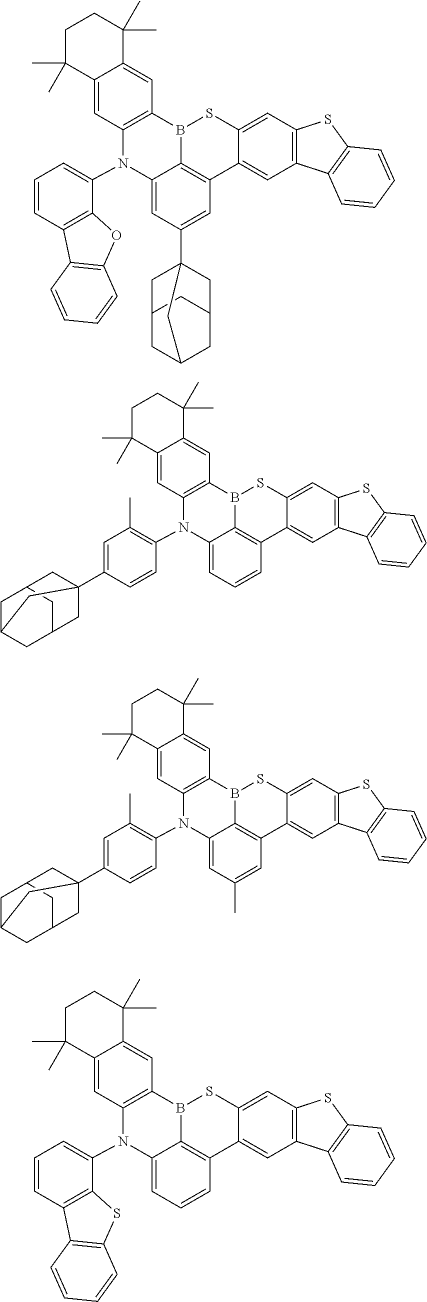

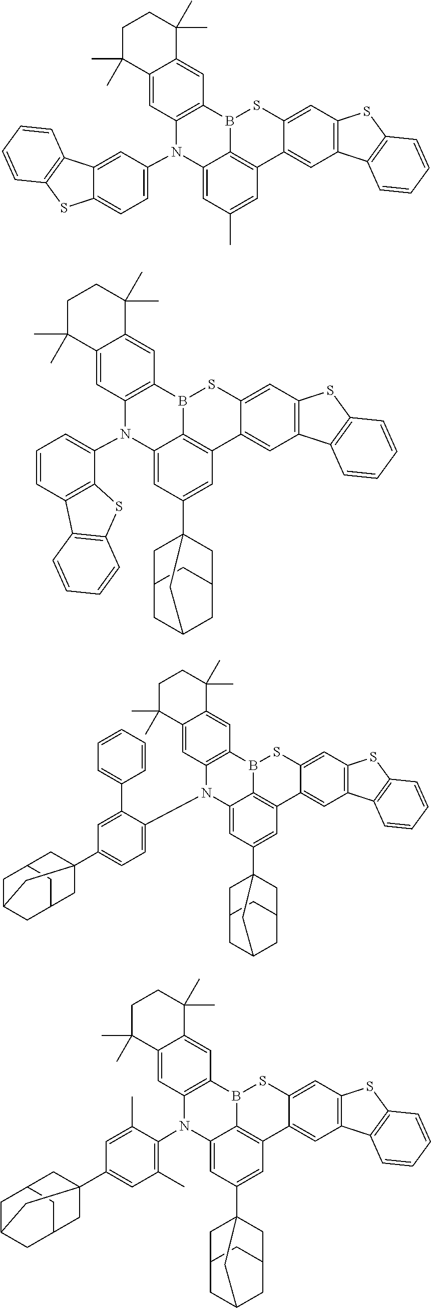

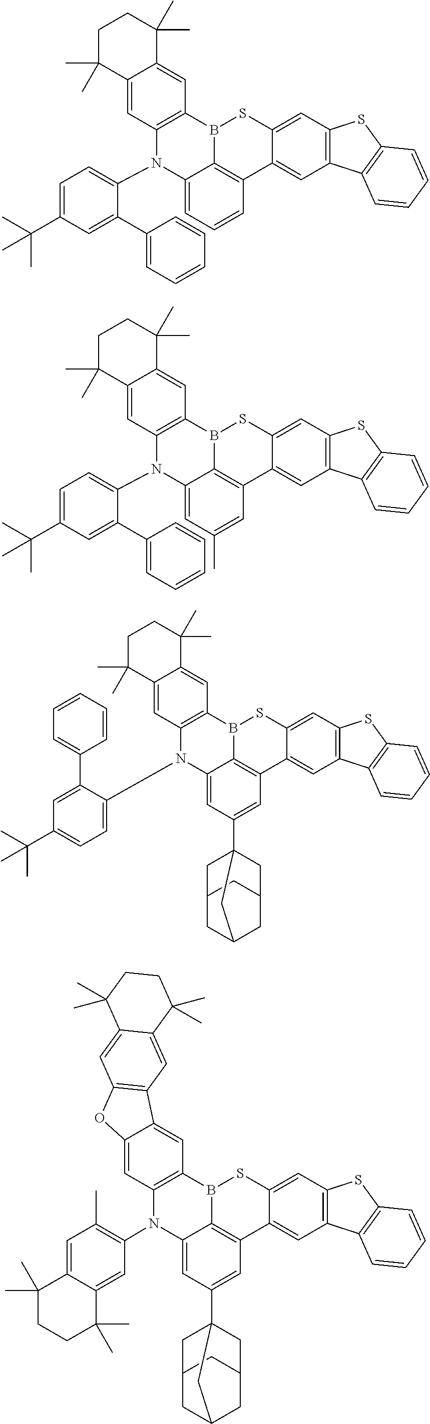

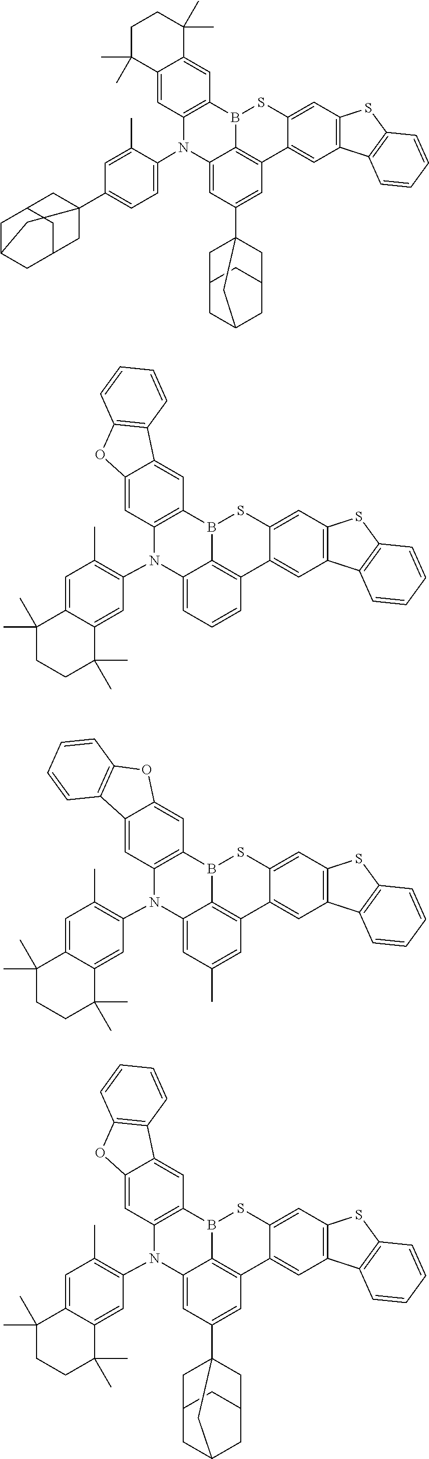

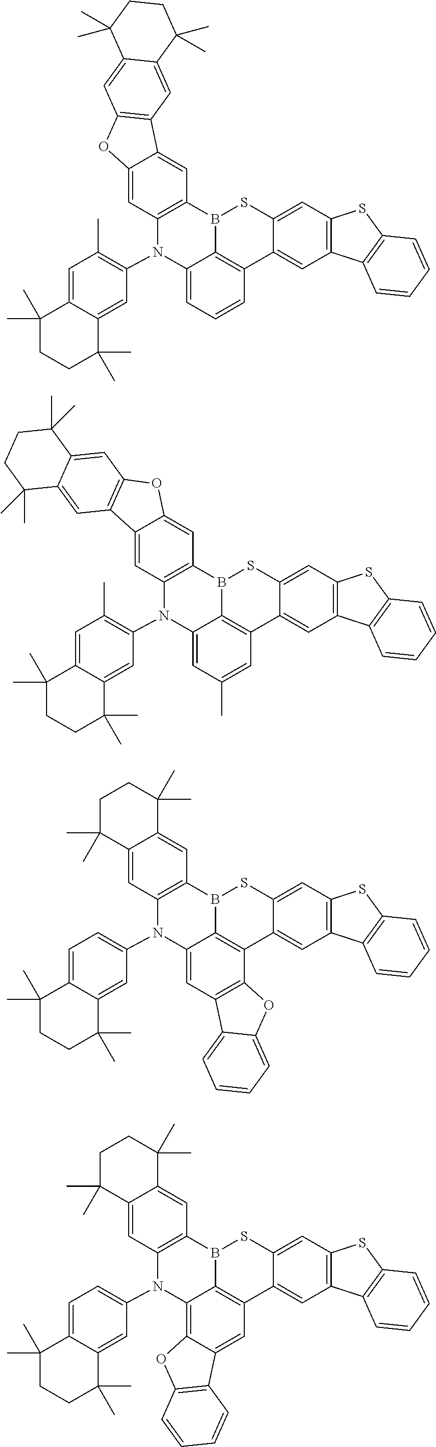

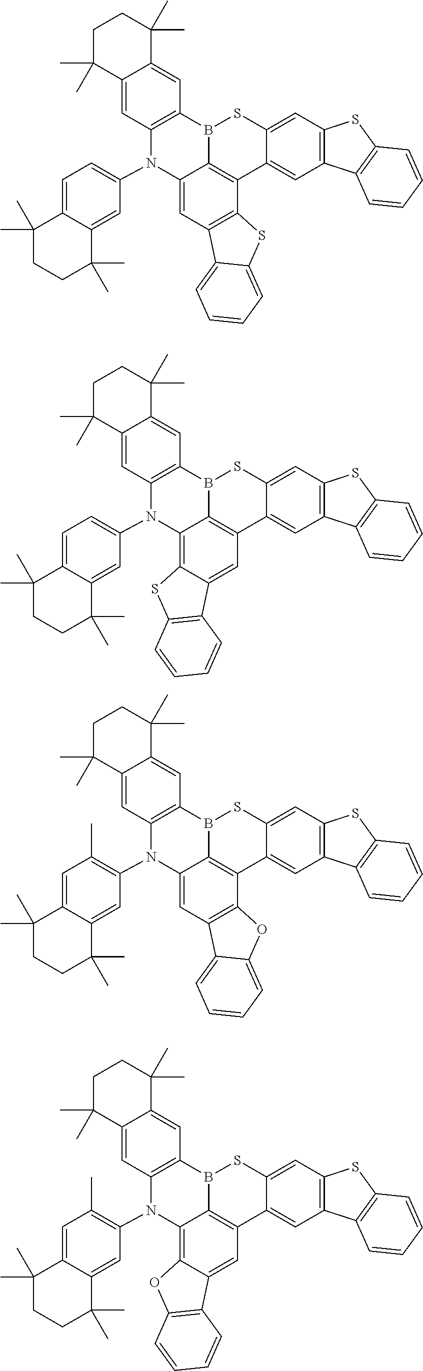

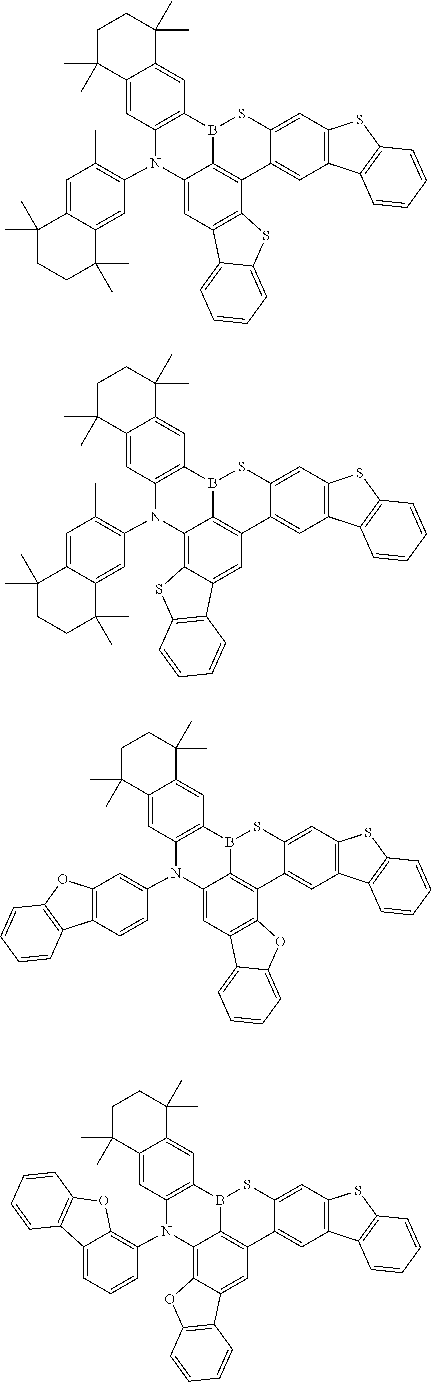

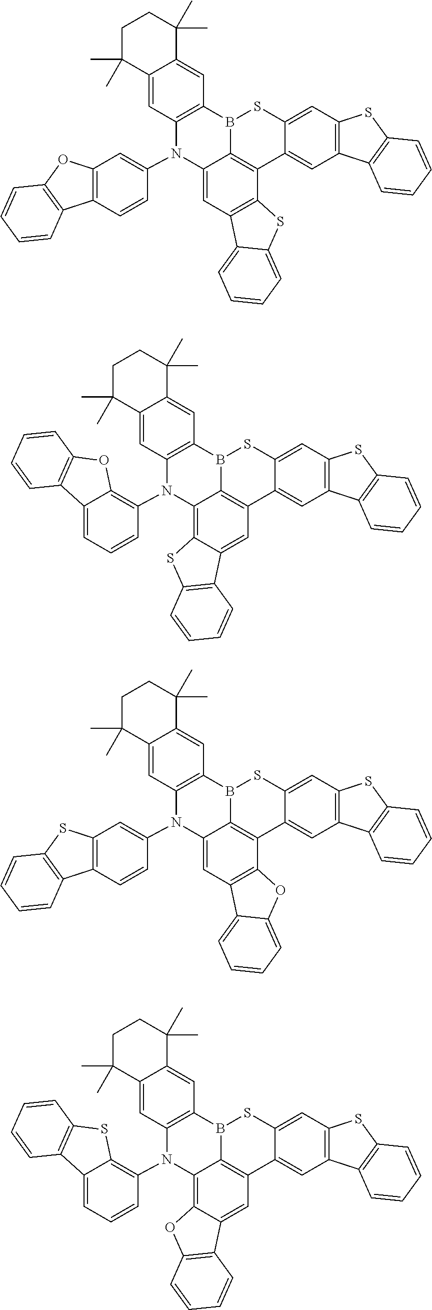

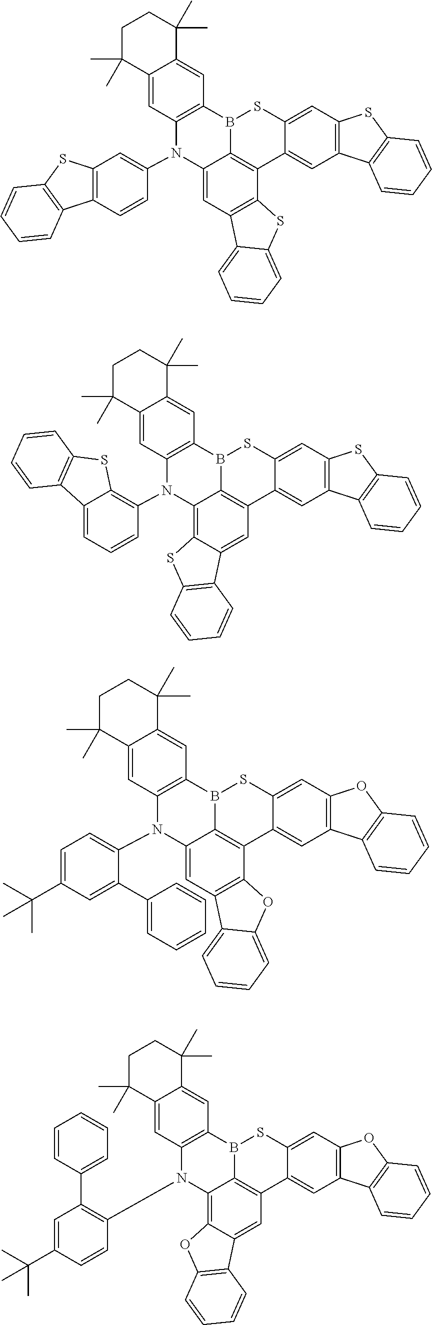

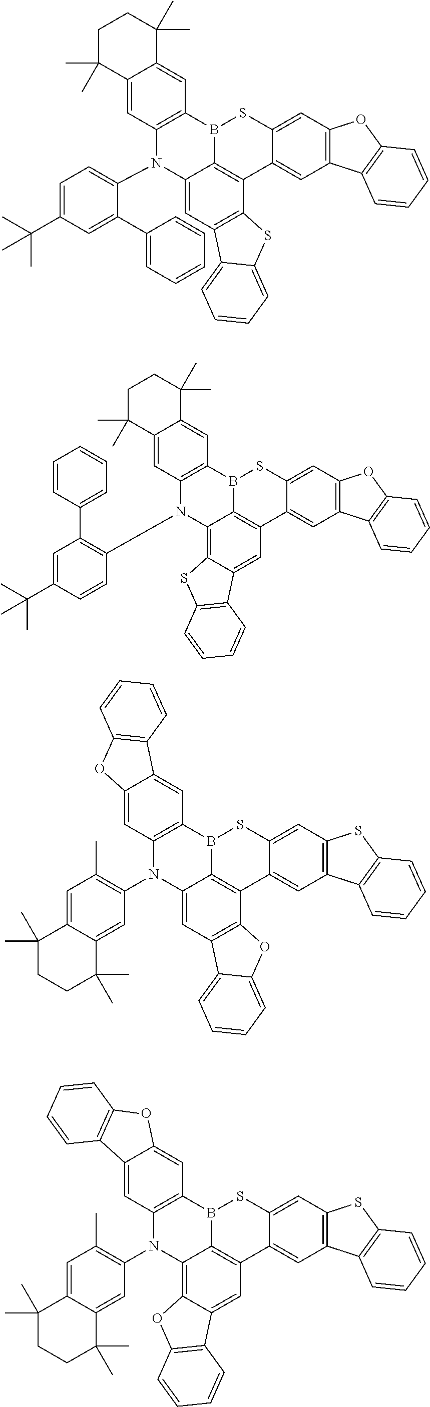 [SMILES: CC(C)(C)c1ccc(N2c3cc4c(cc3B3Sc5cc6oc7ccccc7c6cc5-c5c3c2cc2c5sc3ccccc32)C(C)(C)CCC4(C)C)c(-c2ccccc2)c1 ; CC(C)(C)c1ccc(N2c3cc4c(cc3B3Sc5cc6oc7ccccc7c6cc5-c5cc6c(sc7ccccc76)c2c53)C(C)(C)CCC4(C)C)c(-c2ccccc2)c1 ; Cc1cc2c(cc1N1c3cc4oc5ccccc5c4cc3B3Sc4cc5sc6ccccc6c5cc4-c4c3c1cc1c4oc3ccccc31)C(C)(C)CCC2(C)C ; Cc1cc2c(cc1N1c3cc4c(cc3B3Sc5cc6sc7ccccc7c6cc5-c5cc6c(oc7ccccc76)c1c53)oc1ccccc14)C(C)(C)CCC2(C)C]

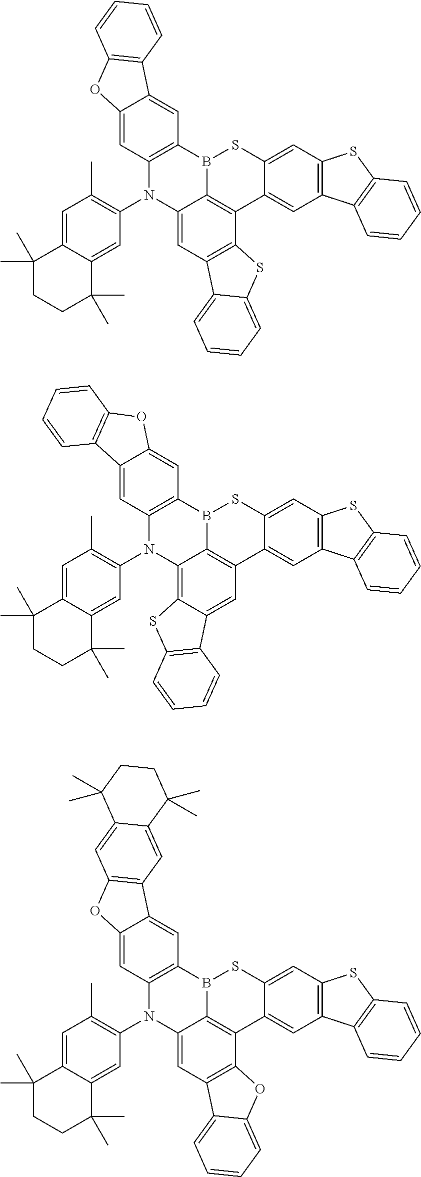 [SMILES: Cc1cc2c(cc1N1c3cc4oc5ccccc5c4cc3B3Sc4cc5sc6ccccc6c5cc4-c4c3c1cc1c4sc3ccccc31)C(C)(C)CCC2(C)C ; Cc1cc2c(cc1N1c3cc4c(cc3B3Sc5cc6sc7ccccc7c6cc5-c5cc6c(sc7ccccc76)c1c53)oc1ccccc14)C(C)(C)CCC2(C)C ; Cc1cc2c(cc1N1c3cc4oc5cc6c(cc5c4cc3B3Sc4cc5sc7ccccc7c5cc4-c4c3c1cc1c4oc3ccccc31)C(C)(C)CCC6(C)C)C(C)(C)CCC2(C)C]

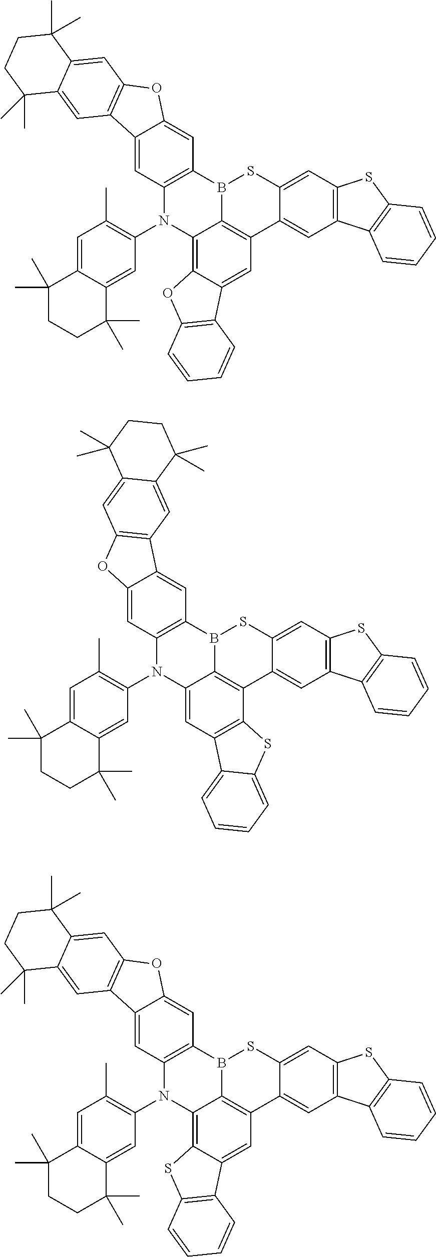 [SMILES: Cc1cc2c(cc1N1c3cc4c(cc3B3Sc5cc6sc7ccccc7c6cc5-c5cc6c(oc7ccccc76)c1c53)oc1cc3c(cc14)C(C)(C)CCC3(C)C)C(C)(C)CCC2(C)C ; Cc1cc2c(cc1N1c3cc4oc5cc6c(cc5c4cc3B3Sc4cc5sc7ccccc7c5cc4-c4c3c1cc1c4sc3ccccc31)C(C)(C)CCC6(C)C)C(C)(C)CCC2(C)C ; Cc1cc2c(cc1N1c3cc4c(cc3B3Sc5cc6sc7ccccc7c6cc5-c5cc6c(sc7ccccc76)c1c53)oc1cc3c(cc14)C(C)(C)CCC3(C)C)C(C)(C)CCC2(C)C]

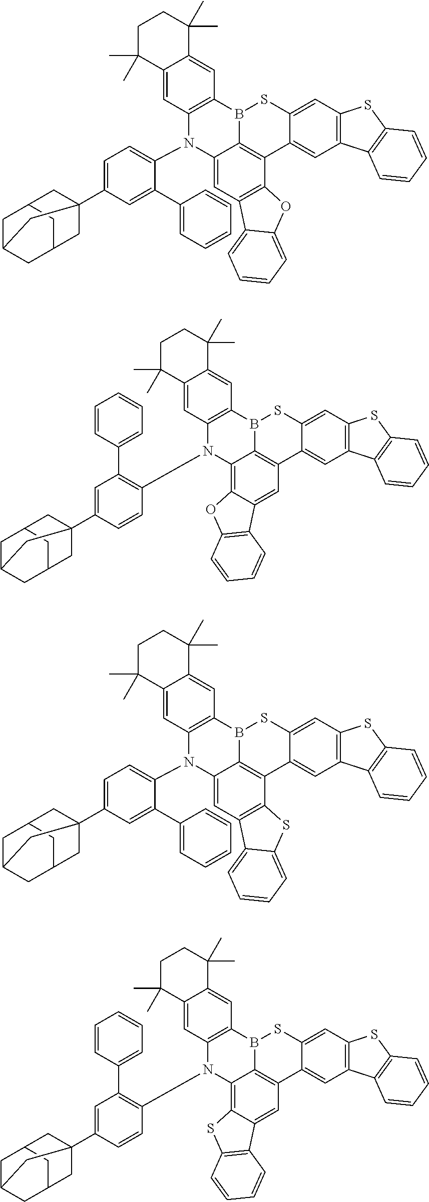 [SMILES: CC1(C)CCC(C)(C)c2cc3c(cc21)B1Sc2cc4sc5ccccc5c4cc2-c2c1c(cc1c2oc2ccccc21)N3c1ccc(C23CC4CC(CC(C4)C2)C3)cc1-c1ccccc1 ; CC1(C)CCC(C)(C)c2cc3c(cc21)B1Sc2cc4sc5ccccc5c4cc2-c2cc4c(oc5ccccc54)c(c21)N3c1ccc(C23CC4CC(CC(C4)C2)C3)cc1-c1ccccc1 ; CC1(C)CCC(C)(C)c2cc3c(cc21)B1Sc2cc4sc5ccccc5c4cc2-c2c1c(cc1c2sc2ccccc21)N3c1ccc(C23CC4CC(CC(C4)C2)C3)cc1-c1ccccc1 ; CC1(C)CCC(C)(C)c2cc3c(cc21)B1Sc2cc4sc5ccccc5c4cc2-c2cc4c(sc5ccccc54)c(c21)N3c1ccc(C23CC4CC(CC(C4)C2)C3)cc1-c1ccccc1]

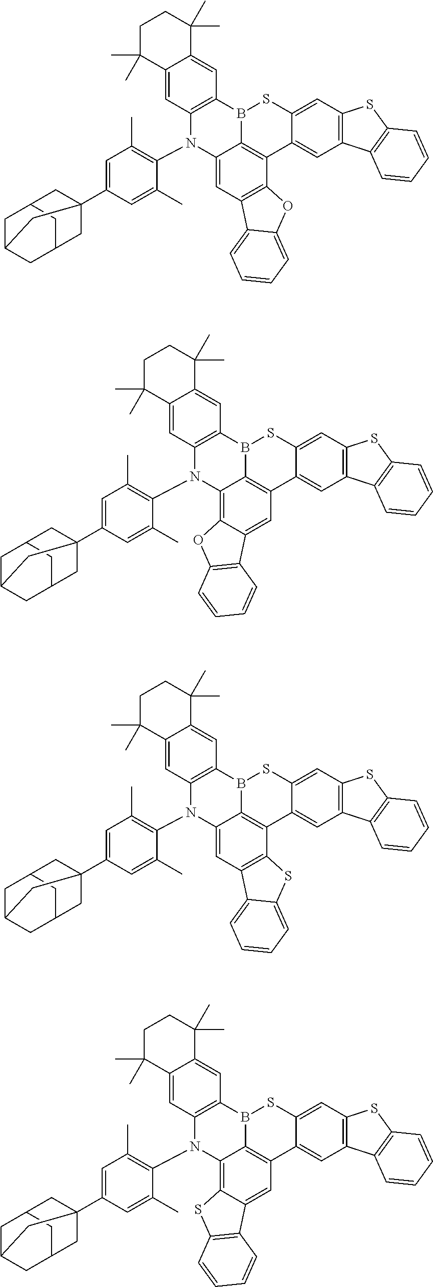 [SMILES: Cc1cc(C23CC4CC(CC(C4)C2)C3)cc(C)c1N1c2cc3c(cc2B2Sc4cc5sc6ccccc6c5cc4-c4c2c1cc1c4oc2ccccc21)C(C)(C)CCC3(C)C ; Cc1cc(C23CC4CC(CC(C4)C2)C3)cc(C)c1N1c2cc3c(cc2B2Sc4cc5sc6ccccc6c5cc4-c4cc5c(oc6ccccc65)c1c42)C(C)(C)CCC3(C)C ; Cc1cc(C23CC4CC(CC(C4)C2)C3)cc(C)c1N1c2cc3c(cc2B2Sc4cc5sc6ccccc6c5cc4-c4c2c1cc1c4sc2ccccc21)C(C)(C)CCC3(C)C ; Cc1cc(C23CC4CC(CC(C4)C2)C3)cc(C)c1N1c2cc3c(cc2B2Sc4cc5sc6ccccc6c5cc4-c4cc5c(sc6ccccc65)c1c42)C(C)(C)CCC3(C)C]

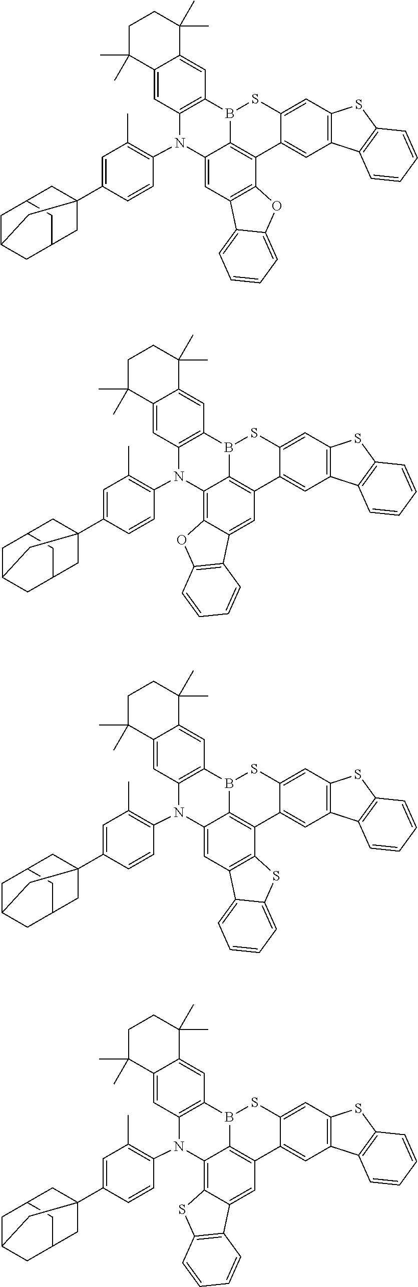 [SMILES: Cc1cc(C23CC4CC(CC(C4)C2)C3)ccc1N1c2cc3c(cc2B2Sc4cc5sc6ccccc6c5cc4-c4c2c1cc1c4oc2ccccc21)C(C)(C)CCC3(C)C ; Cc1cc(C23CC4CC(CC(C4)C2)C3)ccc1N1c2cc3c(cc2B2Sc4cc5sc6ccccc6c5cc4-c4cc5c(oc6ccccc65)c1c42)C(C)(C)CCC3(C)C ; Cc1cc(C23CC4CC(CC(C4)C2)C3)ccc1N1c2cc3c(cc2B2Sc4cc5sc6ccccc6c5cc4-c4c2c1cc1c4sc2ccccc21)C(C)(C)CCC3(C)C ; Cc1cc(C23CC4CC(CC(C4)C2)C3)ccc1N1c2cc3c(cc2B2Sc4cc5sc6ccccc6c5cc4-c4cc5c(sc6ccccc65)c1c42)C(C)(C)CCC3(C)C]

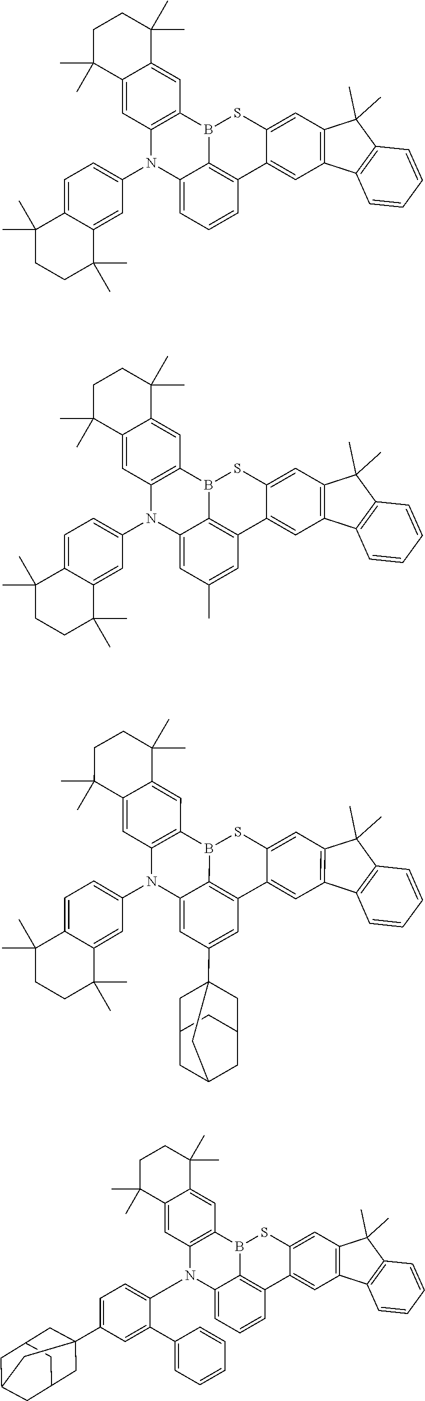

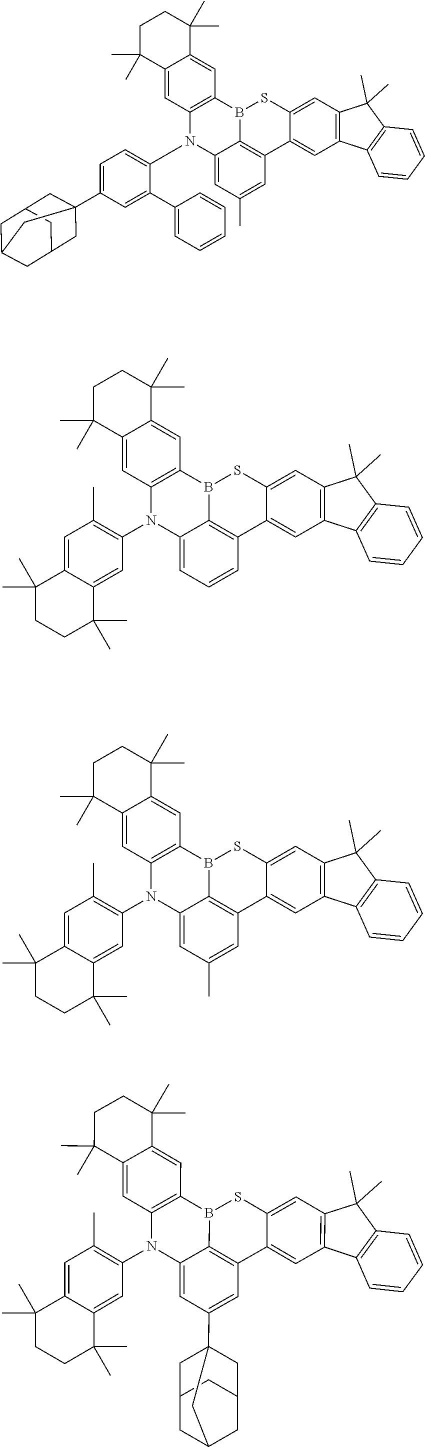

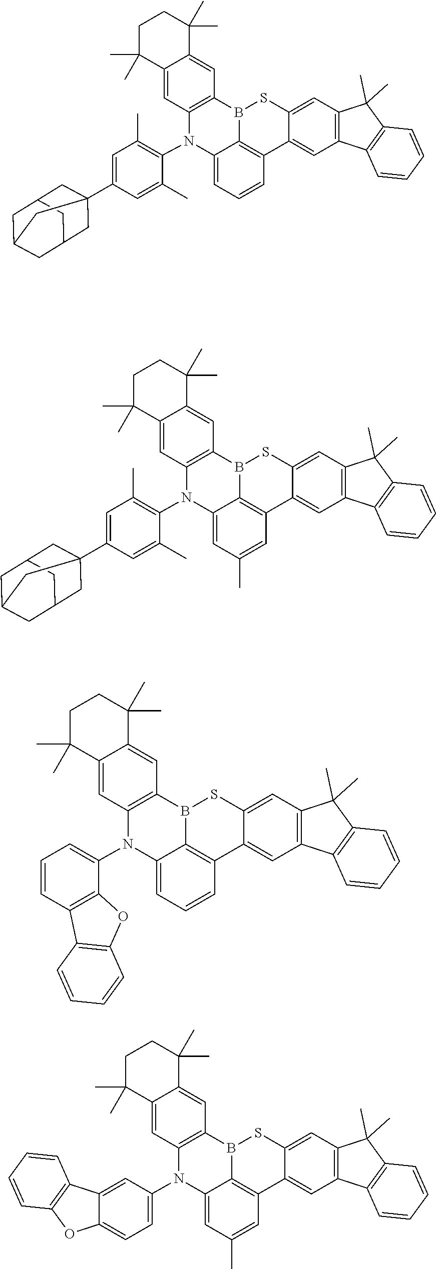 [SMILES: Cc1cc(C23CC4CC(CC(C4)C2)C3)cc(C)c1N1c2cc3c(cc2B2Sc4cc5c(cc4-c4cccc1c42)-c1ccccc1C5(C)C)C(C)(C)CCC3(C)C ; Cc1cc2c3c(c1)N(c1c(C)cc(C45CC6CC(CC(C6)C4)C5)cc1C)c1cc4c(cc1B3Sc1cc3c(cc1-2)-c1ccccc1C3(C)C)C(C)(C)CCC4(C)C ; CC1(C)CCC(C)(C)c2cc3c(cc21)B1Sc2cc4c(cc2-c2cccc(c21)N3c1cccc2c1oc1ccccc12)-c1ccccc1C4(C)C ; Cc1cc2c3c(c1)N(c1ccc4oc5ccccc5c4c1)c1cc4c(cc1B3Sc1cc3c(cc1-2)-c1ccccc1C3(C)C)C(C)(C)CCC4(C)C]

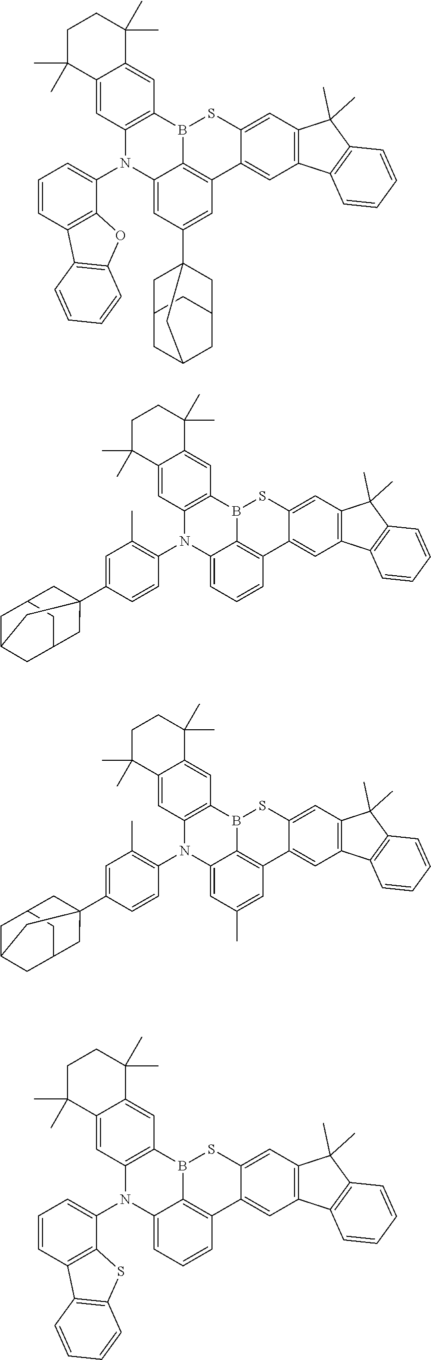

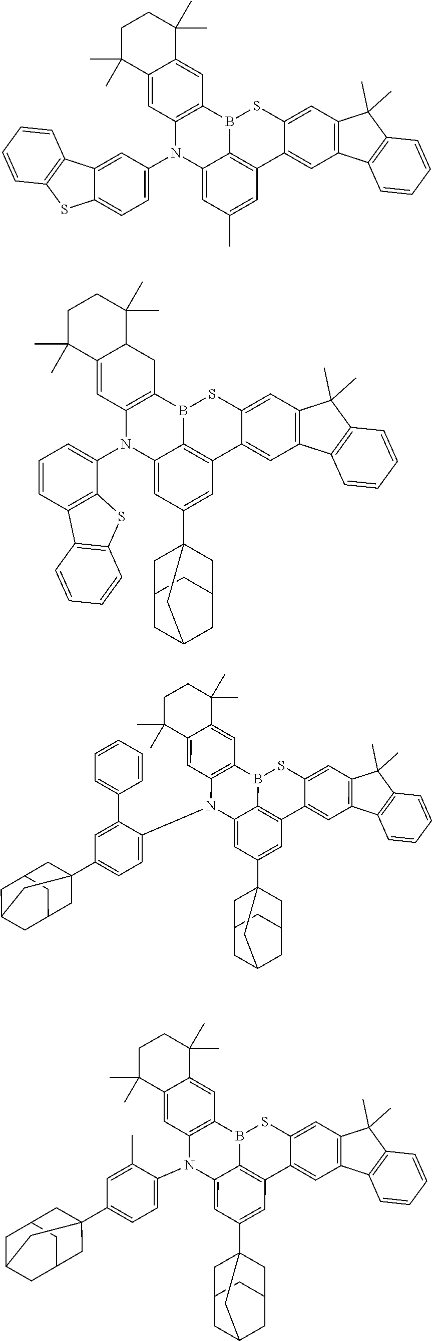

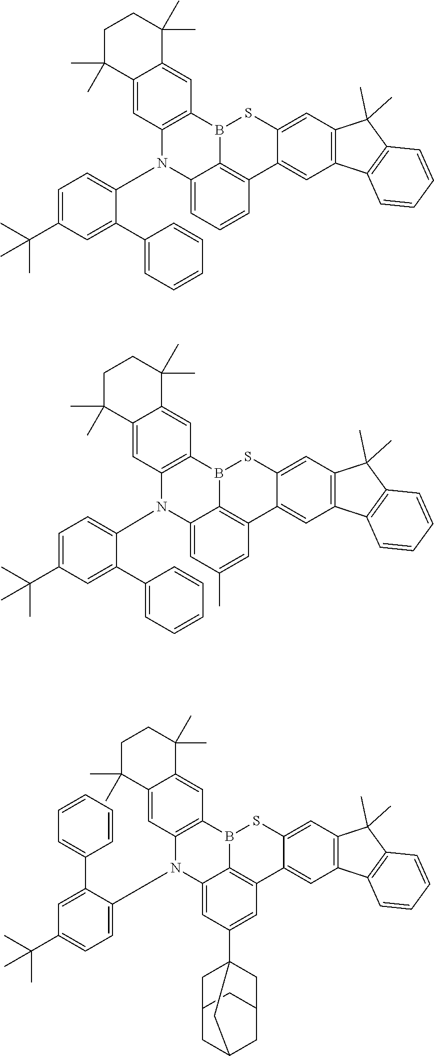 [SMILES: CC(C)(C)c1ccc(N2c3cc4c(cc3B3Sc5cc6c(cc5-c5cccc2c53)-c2ccccc2C6(C)C)C(C)(C)CCC4(C)C)c(-c2ccccc2)c1 ; Cc1cc2c3c(c1)N(c1ccc(C(C)(C)C)cc1-c1ccccc1)c1cc4c(cc1B3Sc1cc3c(cc1-2)-c1ccccc1C3(C)C)C(C)(C)CCC4(C)C ; CC(C)(C)c1ccc(N2c3cc4c(cc3B3Sc5cc6c(cc5-c5cc(C78CC9CC(CC(C9)C7)C8)cc2c53)-c2ccccc2C6(C)C)C(C)(C)CCC4(C)C)c(-c2ccccc2)c1]

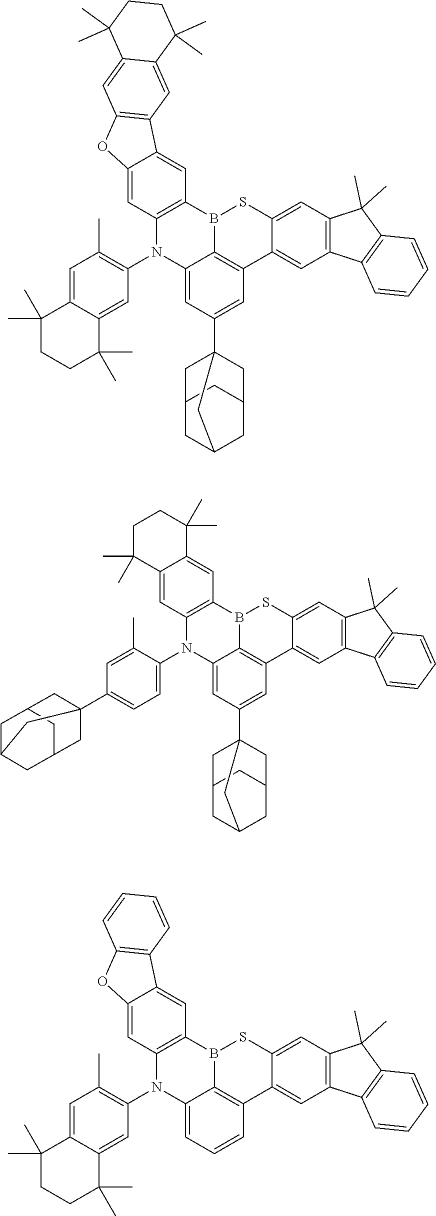 [SMILES: Cc1cc2c(cc1N1c3cc4oc5cc6c(cc5c4cc3B3Sc4cc5c(cc4-c4cc(C78CC9CC(CC(C9)C7)C8)cc1c43)-c1ccccc1C5(C)C)C(C)(C)CCC6(C)C)C(C)(C)CCC2(C)C ; Cc1cc(C23CC4CC(CC(C4)C2)C3)ccc1N1c2cc3c(cc2B2Sc4cc5c(cc4-c4cc(C67CC8CC(CC(C8)C6)C7)cc1c42)-c1ccccc1C5(C)C)C(C)(C)CCC3(C)C ; Cc1cc2c(cc1N1c3cc4oc5ccccc5c4cc3B3Sc4cc5c(cc4-c4cccc1c43)-c1ccccc1C5(C)C)C(C)(C)CCC2(C)C]

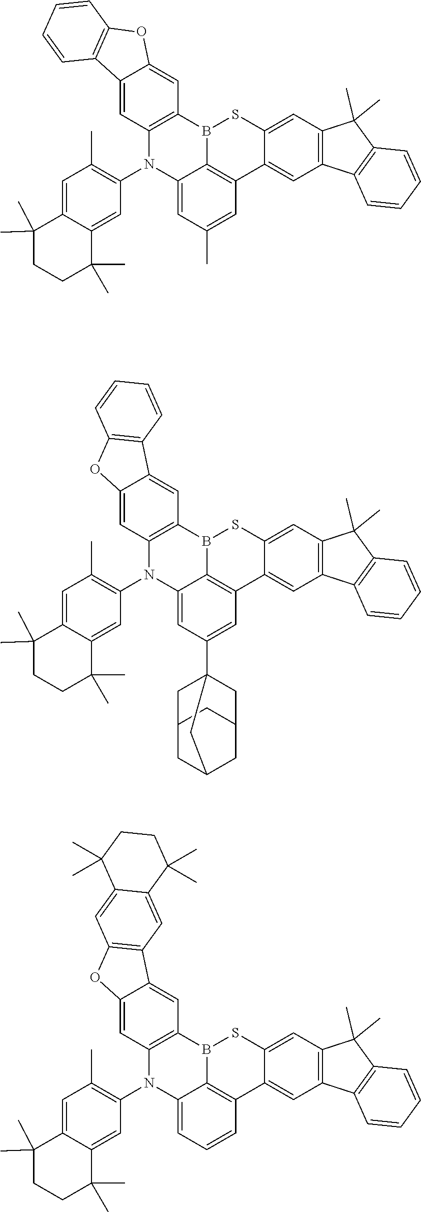 [SMILES: Cc1cc2c3c(c1)N(c1cc4c(cc1C)C(C)(C)CCC4(C)C)c1cc4c(cc1B3Sc1cc3c(cc1-2)-c1ccccc1C3(C)C)oc1ccccc14 ; Cc1cc2c(cc1N1c3cc4oc5ccccc5c4cc3B3Sc4cc5c(cc4-c4cc(C67CC8CC(CC(C8)C6)C7)cc1c43)-c1ccccc1C5(C)C)C(C)(C)CCC2(C)C ; Cc1cc2c(cc1N1c3cc4oc5cc6c(cc5c4cc3B3Sc4cc5c(cc4-c4cccc1c43)-c1ccccc1C5(C)C)C(C)(C)CCC6(C)C)C(C)(C)CCC2(C)C]

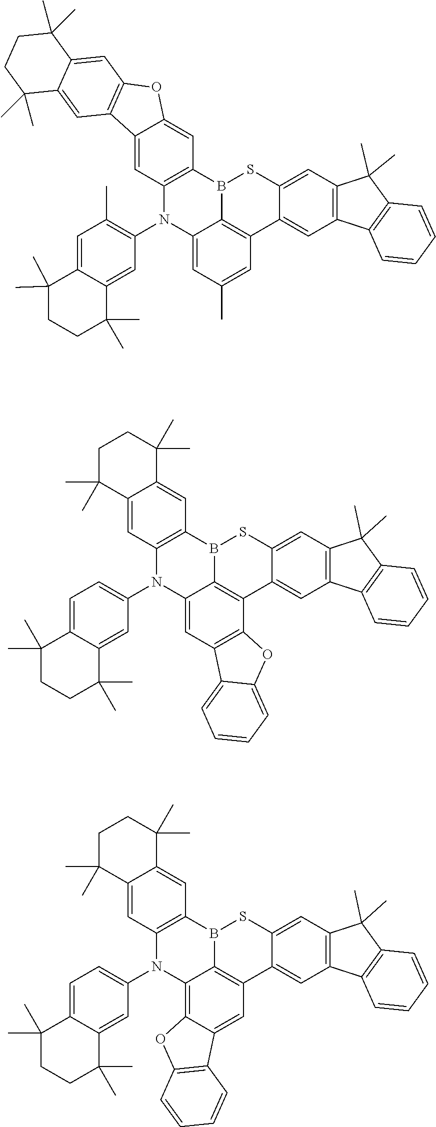 [SMILES: Cc1cc2c3c(c1)N(c1cc4c(cc1C)C(C)(C)CCC4(C)C)c1cc4c(cc1B3Sc1cc3c(cc1-2)-c1ccccc1C3(C)C)oc1cc2c(cc14)C(C)(C)CCC2(C)C ; CC1(C)CCC(C)(C)c2cc(N3c4cc5c(cc4B4Sc6cc7c(cc6-c6c4c3cc3c6oc4ccccc43)-c3ccccc3C7(C)C)C(C)(C)CCC5(C)C)ccc21 ; CC1(C)CCC(C)(C)c2cc(N3c4cc5c(cc4B4Sc6cc7c(cc6-c6cc8c(oc9ccccc98)c3c64)-c3ccccc3C7(C)C)C(C)(C)CCC5(C)C)ccc21]

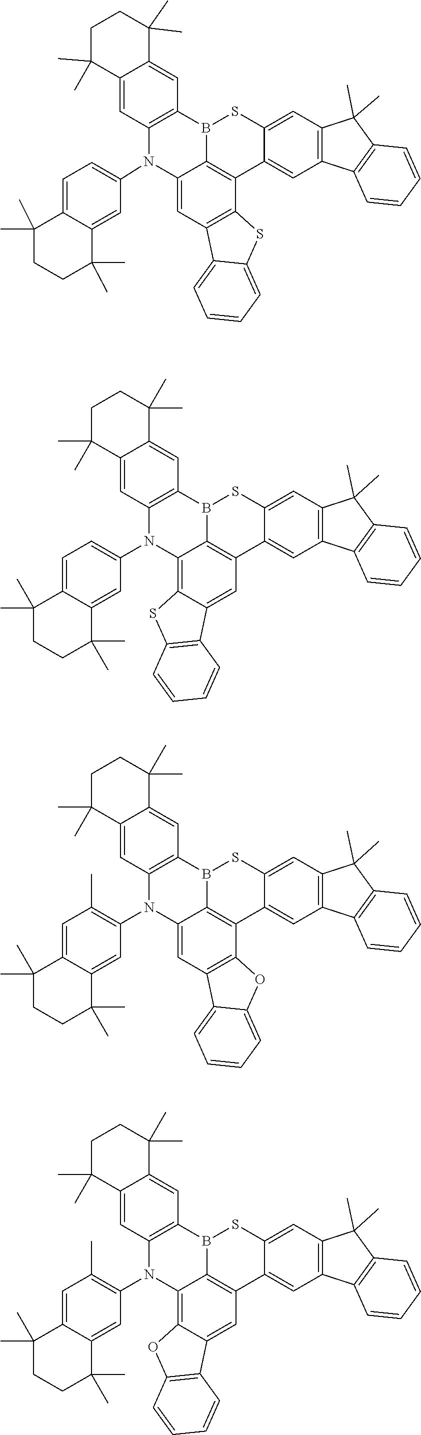

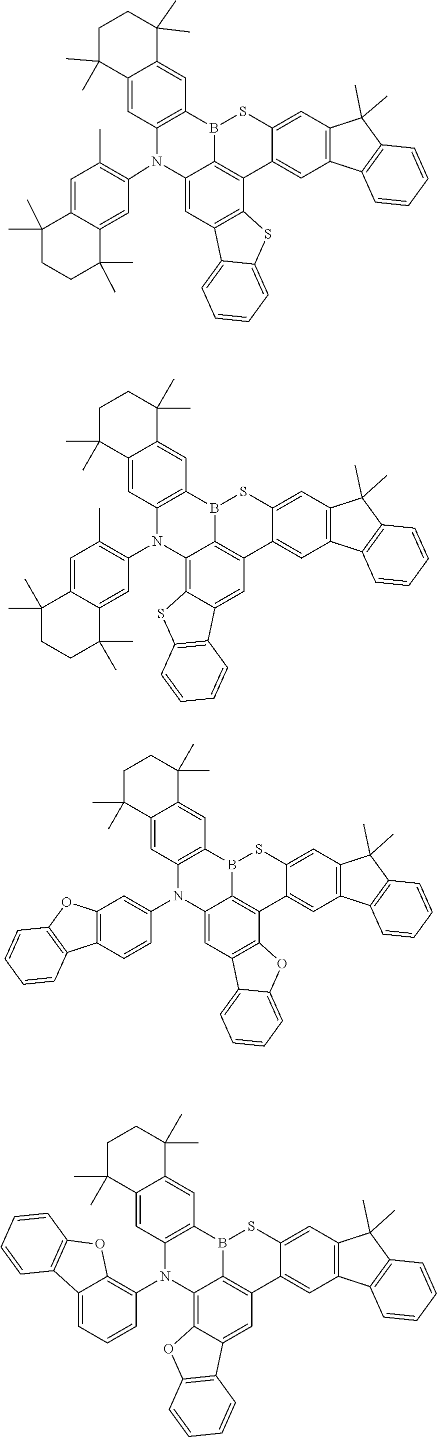

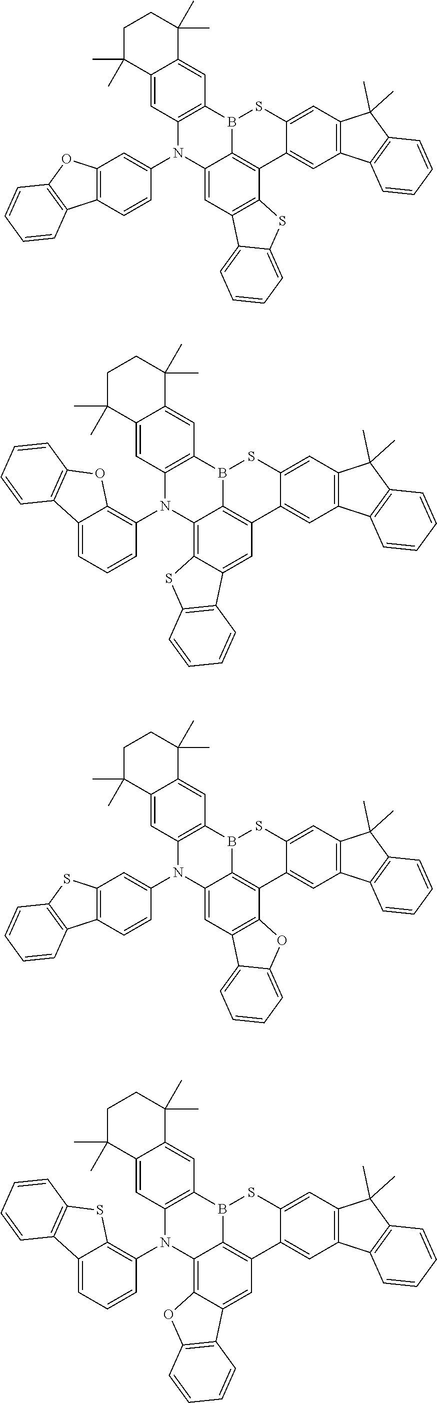

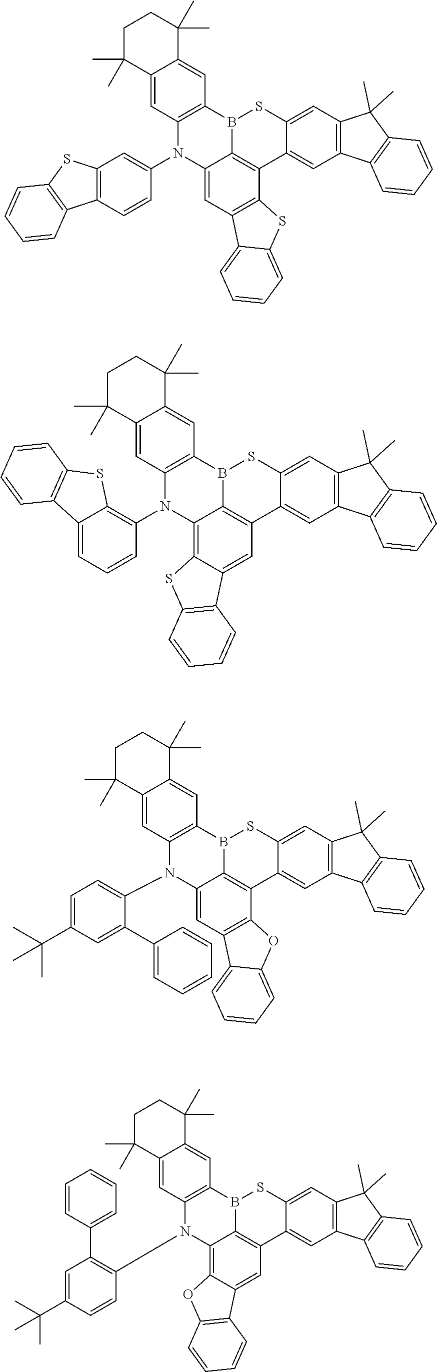

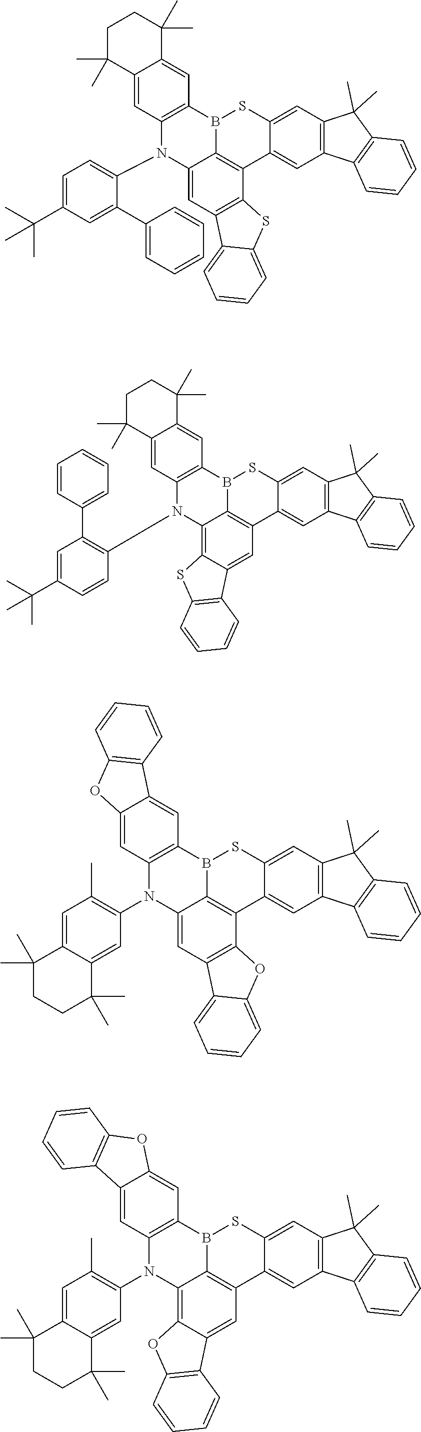 [SMILES: CC(C)(C)c1ccc(N2c3cc4c(cc3B3Sc5cc6c(cc5-c5c3c2cc2c5sc3ccccc32)-c2ccccc2C6(C)C)C(C)(C)CCC4(C)C)c(-c2ccccc2)c1 ; CC(C)(C)c1ccc(N2c3cc4c(cc3B3Sc5cc6c(cc5-c5cc7c(sc8ccccc87)c2c53)-c2ccccc2C6(C)C)C(C)(C)CCC4(C)C)c(-c2ccccc2)c1 ; Cc1cc2c(cc1N1c3cc4oc5ccccc5c4cc3B3Sc4cc5c(cc4-c4c3c1cc1c4oc3ccccc31)-c1ccccc1C5(C)C)C(C)(C)CCC2(C)C ; Cc1cc2c(cc1N1c3cc4c(cc3B3Sc5cc6c(cc5-c5cc7c(oc8ccccc87)c1c53)-c1ccccc1C6(C)C)oc1ccccc14)C(C)(C)CCC2(C)C]

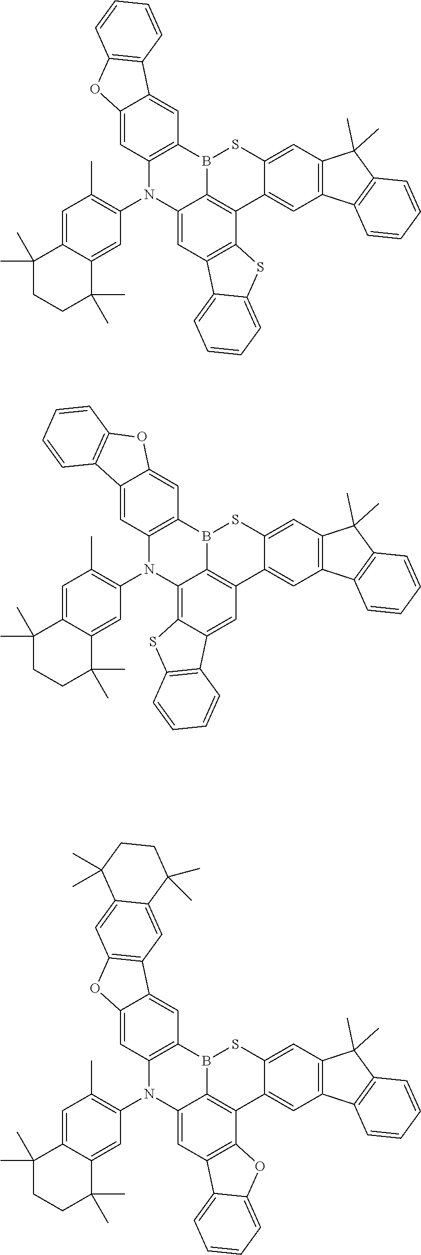 [SMILES: Cc1cc2c(cc1N1c3cc4oc5ccccc5c4cc3B3Sc4cc5c(cc4-c4c3c1cc1c4sc3ccccc31)-c1ccccc1C5(C)C)C(C)(C)CCC2(C)C ; Cc1cc2c(cc1N1c3cc4c(cc3B3Sc5cc6c(cc5-c5cc7c(sc8ccccc87)c1c53)-c1ccccc1C6(C)C)oc1ccccc14)C(C)(C)CCC2(C)C ; Cc1cc2c(cc1N1c3cc4oc5cc6c(cc5c4cc3B3Sc4cc5c(cc4-c4c3c1cc1c4oc3ccccc31)-c1ccccc1C5(C)C)C(C)(C)CCC6(C)C)C(C)(C)CCC2(C)C]

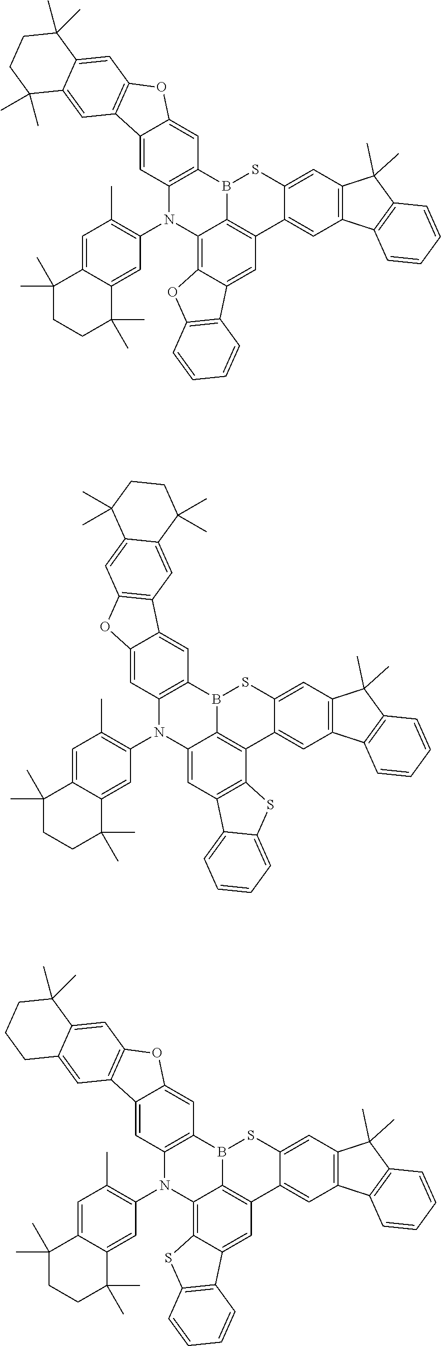 [SMILES: Cc1cc2c(cc1N1c3cc4c(cc3B3Sc5cc6c(cc5-c5cc7c(oc8ccccc87)c1c53)-c1ccccc1C6(C)C)oc1cc3c(cc14)C(C)(C)CCC3(C)C)C(C)(C)CCC2(C)C ; Cc1cc2c(cc1N1c3cc4oc5cc6c(cc5c4cc3B3Sc4cc5c(cc4-c4c3c1cc1c4sc3ccccc31)-c1ccccc1C5(C)C)C(C)(C)CCC6(C)C)C(C)(C)CCC2(C)C ; Cc1cc2c(cc1N1c3cc4c(cc3B3Sc5cc6c(cc5-c5cc7c(sc8ccccc87)c1c53)-c1ccccc1C6(C)C)oc1cc3c(cc14)CCCC3(C)C)C(C)(C)CCC2(C)C]

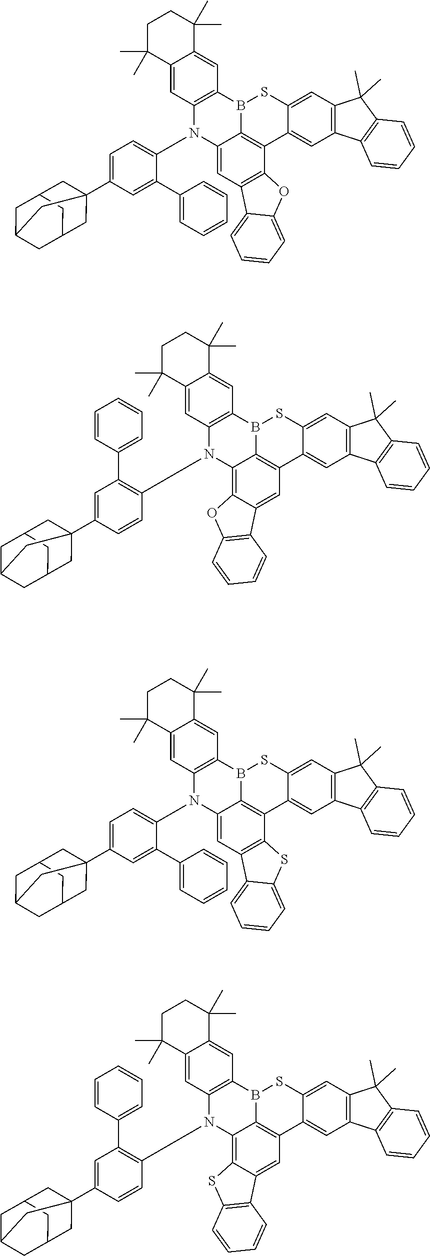

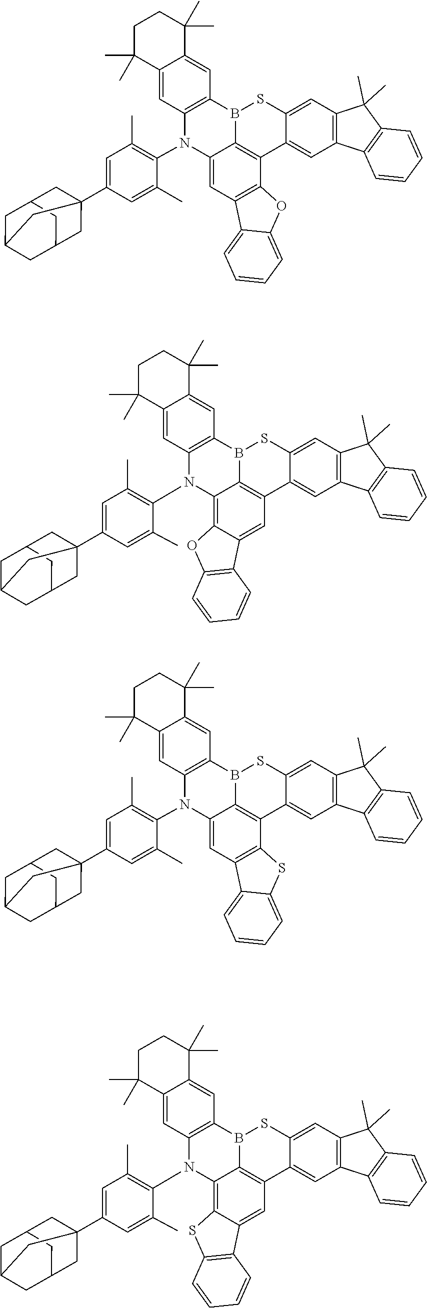

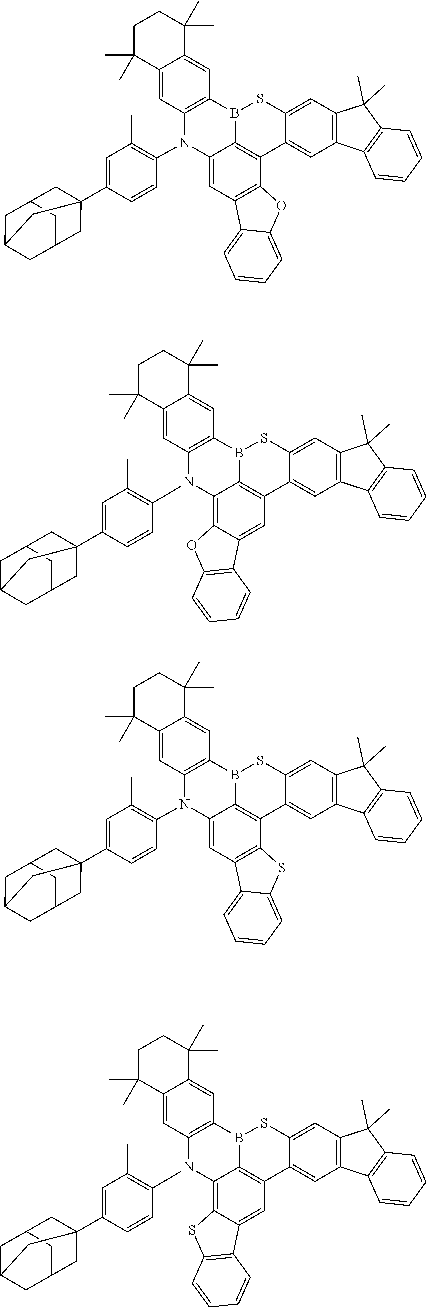

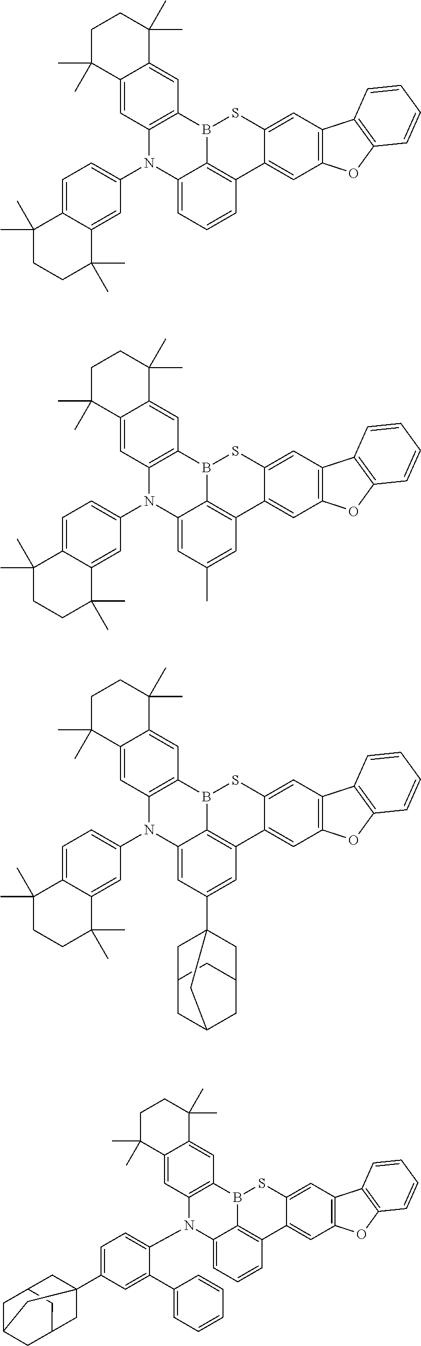 [SMILES: CC1(C)CCC(C)(C)c2cc(N3c4cc5c(cc4B4Sc6cc7c(cc6-c6cccc3c64)oc3ccccc37)C(C)(C)CCC5(C)C)ccc21 ; Cc1cc2c3c(c1)N(c1ccc4c(c1)C(C)(C)CCC4(C)C)c1cc4c(cc1B3Sc1cc3c(cc1-2)oc1ccccc13)C(C)(C)CCC4(C)C ; CC1(C)CCC(C)(C)c2cc(N3c4cc5c(cc4B4Sc6cc7c(cc6-c6cc(C89CC%10CC(CC(C%10)C8)C9)cc3c64)oc3ccccc37)C(C)(C)CCC5(C)C)ccc21 ; CC1(C)CCC(C)(C)c2cc3c(cc21)B1Sc2cc4c(cc2-c2cccc(c21)N3c1ccc(C23CC5CC(CC(C5)C2)C3)cc1-c1ccccc1)oc1ccccc14]

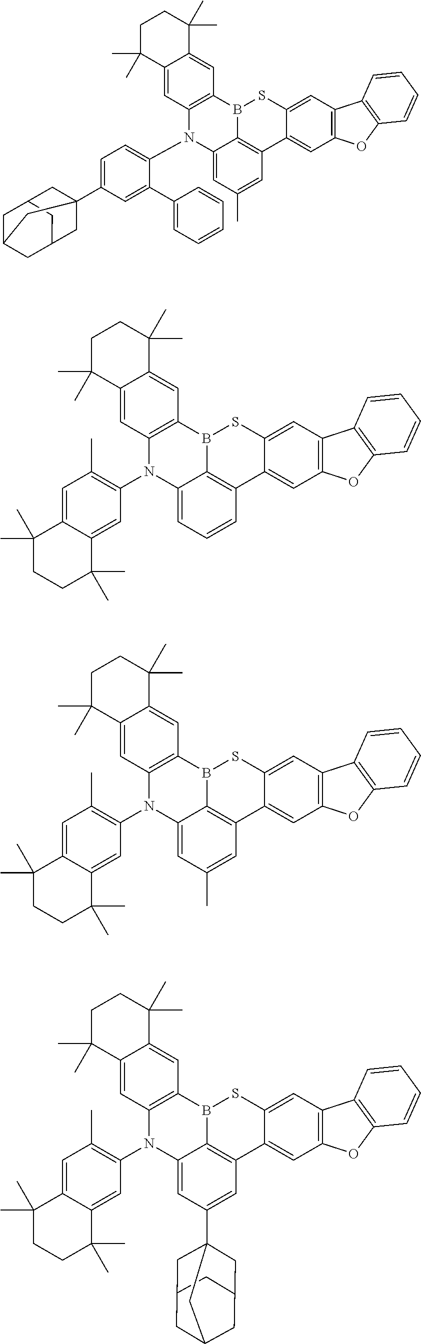 [SMILES: Cc1cc2c3c(c1)N(c1ccc(C45CC6CC(CC(C6)C4)C5)cc1-c1ccccc1)c1cc4c(cc1B3Sc1cc3c(cc1-2)oc1ccccc13)C(C)(C)CCC4(C)C ; Cc1cc2c(cc1N1c3cc4c(cc3B3Sc5cc6c(cc5-c5cccc1c53)oc1ccccc16)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Sc1cc3c(cc1-2)oc1ccccc13)C(C)(C)CCC4(C)C ; Cc1cc2c(cc1N1c3cc4c(cc3B3Sc5cc6c(cc5-c5cc(C78CC9CC(CC(C9)C7)C8)cc1c53)oc1ccccc16)C(C)(C)CCC4(C)C)C(C)(C)CCC2(C)C]

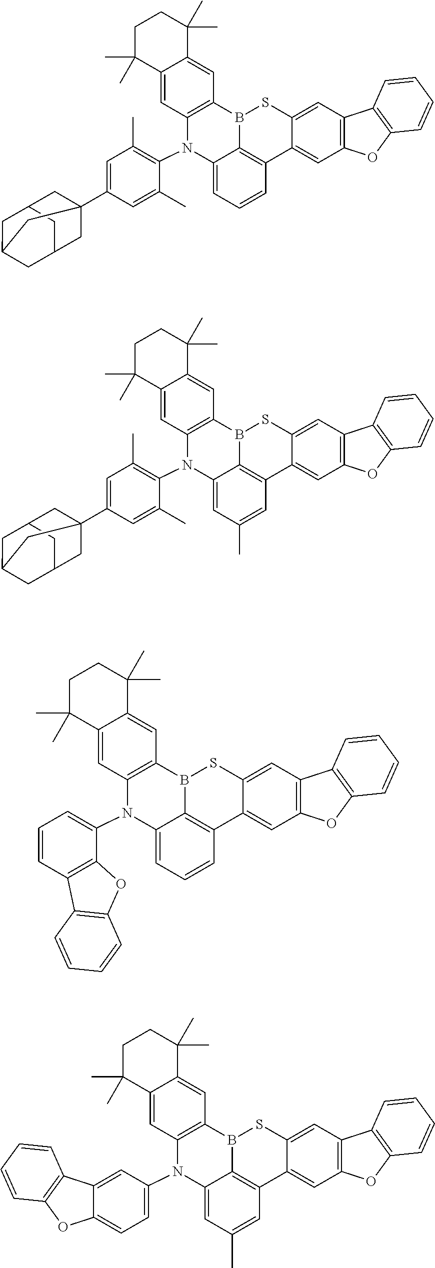 [SMILES: Cc1cc(C23CC4CC(CC(C4)C2)C3)cc(C)c1N1c2cc3c(cc2B2Sc4cc5c(cc4-c4cccc1c42)oc1ccccc15)C(C)(C)CCC3(C)C ; Cc1cc2c3c(c1)N(c1c(C)cc(C45CC6CC(CC(C6)C4)C5)cc1C)c1cc4c(cc1B3Sc1cc3c(cc1-2)oc1ccccc13)C(C)(C)CCC4(C)C ; CC1(C)CCC(C)(C)c2cc3c(cc21)B1Sc2cc4c(cc2-c2cccc(c21)N3c1cccc2c1oc1ccccc12)oc1ccccc14 ; Cc1cc2c3c(c1)N(c1ccc4oc5ccccc5c4c1)c1cc4c(cc1B3Sc1cc3c(cc1-2)oc1ccccc13)C(C)(C)CCC4(C)C]

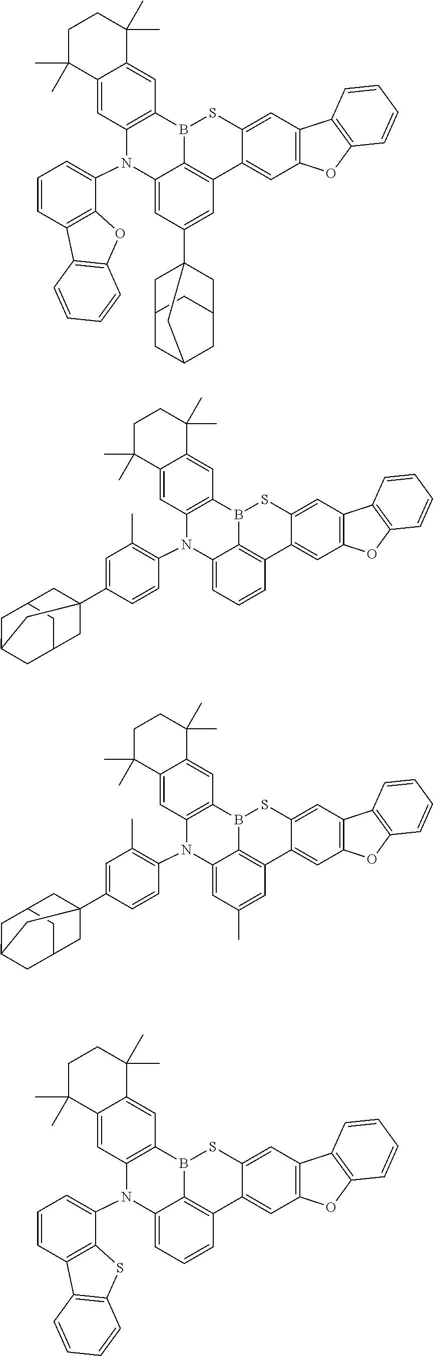

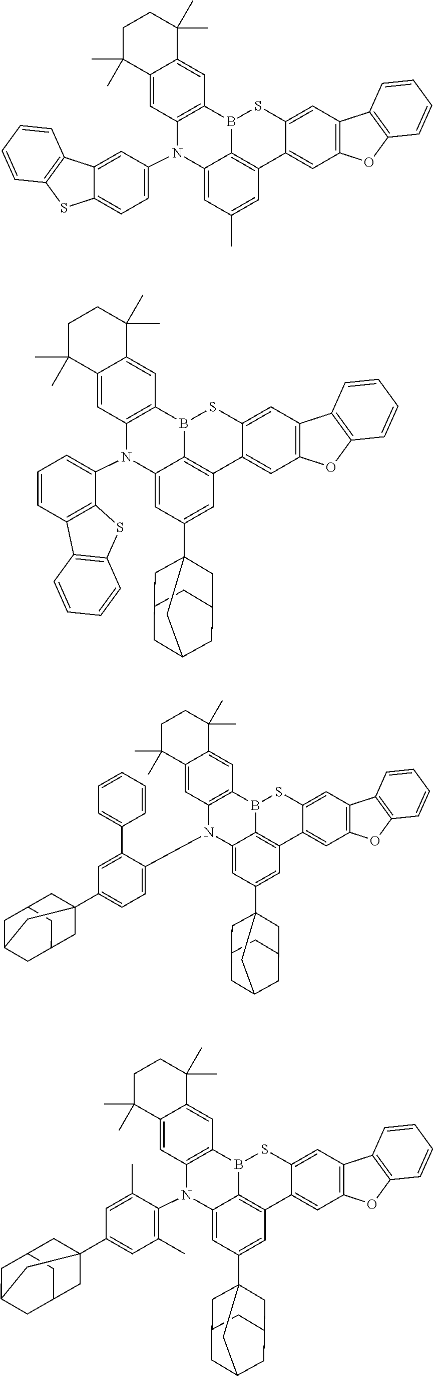 [SMILES: Cc1cc2c3c(c1)N(c1ccc4sc5ccccc5c4c1)c1cc4c(cc1B3Sc1cc3c(cc1-2)oc1ccccc13)C(C)(C)CCC4(C)C ; CC1(C)CCC(C)(C)c2cc3c(cc21)B1Sc2cc4c(cc2-c2cc(C56CC7CC(CC(C7)C5)C6)cc(c21)N3c1cccc2c1sc1ccccc12)oc1ccccc14 ; CC1(C)CCC(C)(C)c2cc3c(cc21)B1Sc2cc4c(cc2-c2cc(C56CC7CC(CC(C7)C5)C6)cc(c21)N3c1ccc(C23CC5CC(CC(C5)C2)C3)cc1-c1ccccc1)oc1ccccc14 ; Cc1cc(C23CC4CC(CC(C4)C2)C3)cc(C)c1N1c2cc3c(cc2B2Sc4cc5c(cc4-c4cc(C67CC8CC(CC(C8)C6)C7)cc1c42)oc1ccccc15)C(C)(C)CCC3(C)C]

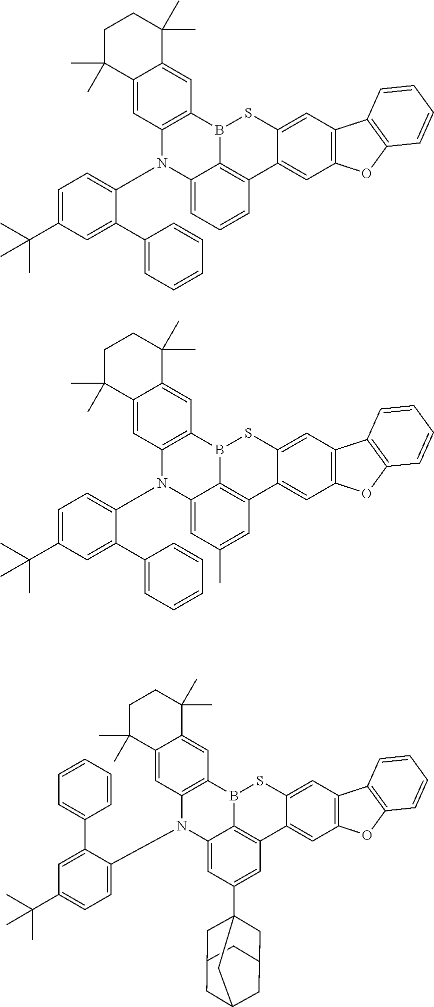

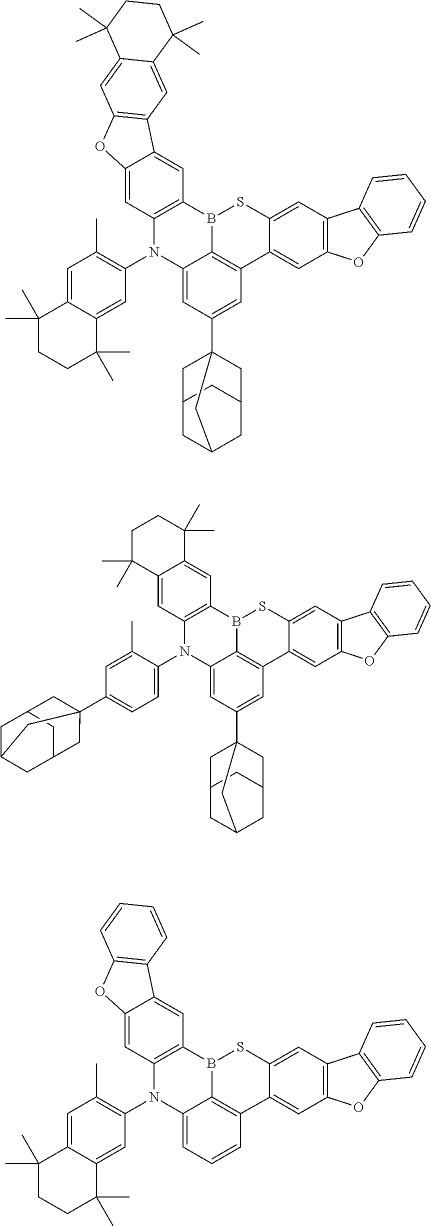 [SMILES: Cc1cc2c(cc1N1c3cc4oc5cc6c(cc5c4cc3B3Sc4cc5c(cc4-c4cc(C78CC9CC(CC(C9)C7)C8)cc1c43)oc1ccccc15)C(C)(C)CCC6(C)C)C(C)(C)CCC2(C)C ; Cc1cc(C23CC4CC(CC(C4)C2)C3)ccc1N1c2cc3c(cc2B2Sc4cc5c(cc4-c4cc(C67CC8CC(CC(C8)C6)C7)cc1c42)oc1ccccc15)C(C)(C)CCC3(C)C ; Cc1cc2c(cc1N1c3cc4oc5ccccc5c4cc3B3Sc4cc5c(cc4-c4cccc1c43)oc1ccccc15)C(C)(C)CCC2(C)C]

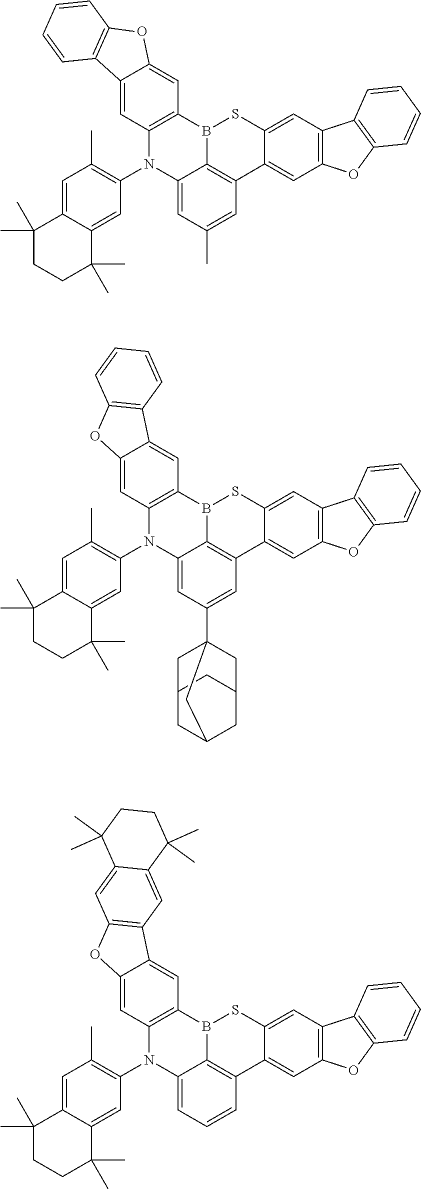 [SMILES: Cc1cc2c3c(c1)N(c1cc4c(cc1C)C(C)(C)CCC4(C)C)c1cc4c(cc1B3Sc1cc3c(cc1-2)oc1ccccc13)oc1ccccc14 ; Cc1cc2c(cc1N1c3cc4oc5ccccc5c4cc3B3Sc4cc5c(cc4-c4cc(C67CC8CC(CC(C8)C6)C7)cc1c43)oc1ccccc15)C(C)(C)CCC2(C)C ; Cc1cc2c(cc1N1c3cc4oc5cc6c(cc5c4cc3B3Sc4cc5c(cc4-c4cccc1c43)oc1ccccc15)C(C)(C)CCC6(C)C)C(C)(C)CCC2(C)C]

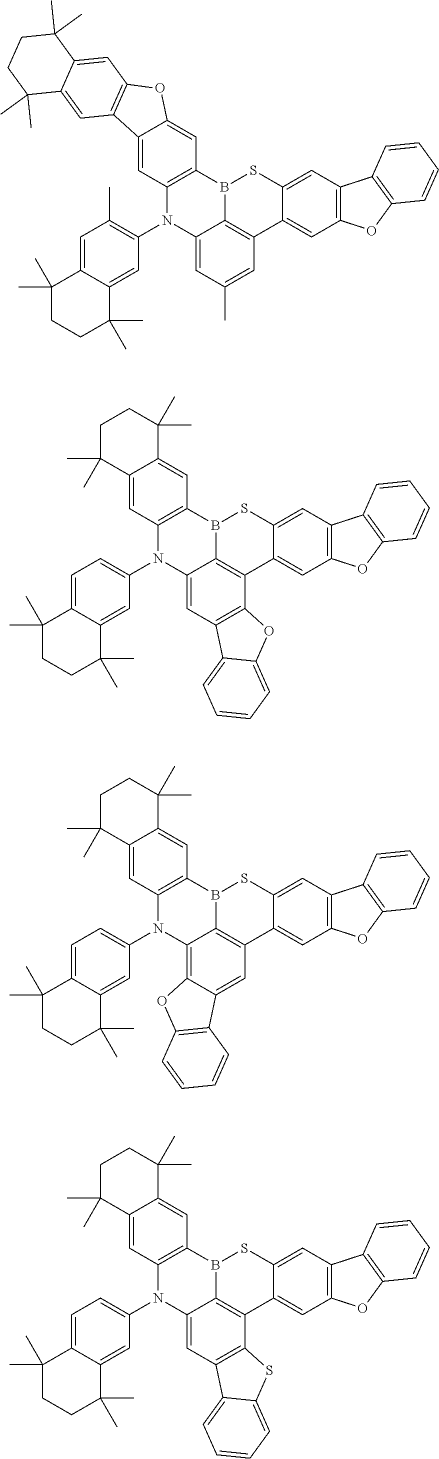 [SMILES: Cc1cc2c3c(c1)N(c1cc4c(cc1C)C(C)(C)CCC4(C)C)c1cc4c(cc1B3Sc1cc3c(cc1-2)oc1ccccc13)oc1cc2c(cc14)C(C)(C)CCC2(C)C ; CC1(C)CCC(C)(C)c2cc(N3c4cc5c(cc4B4Sc6cc7c(cc6-c6c4c3cc3c6oc4ccccc43)oc3ccccc37)C(C)(C)CCC5(C)C)ccc21 ; CC1(C)CCC(C)(C)c2cc(N3c4cc5c(cc4B4Sc6cc7c(cc6-c6cc8c(oc9ccccc98)c3c64)oc3ccccc37)C(C)(C)CCC5(C)C)ccc21 ; CC1(C)CCC(C)(C)c2cc(N3c4cc5c(cc4B4Sc6cc7c(cc6-c6c4c3cc3c6sc4ccccc43)oc3ccccc37)C(C)(C)CCC5(C)C)ccc21]

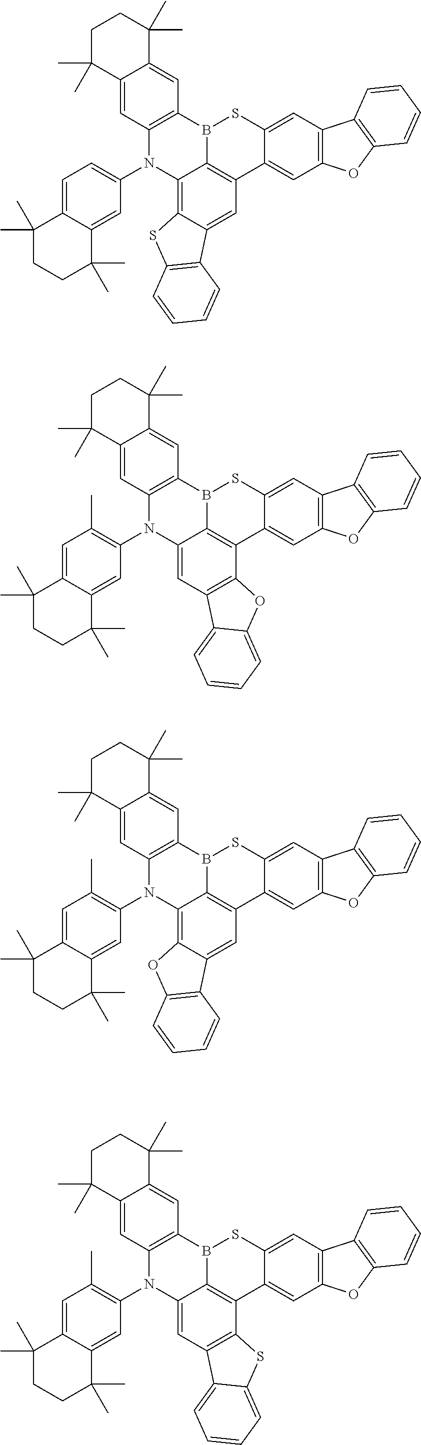

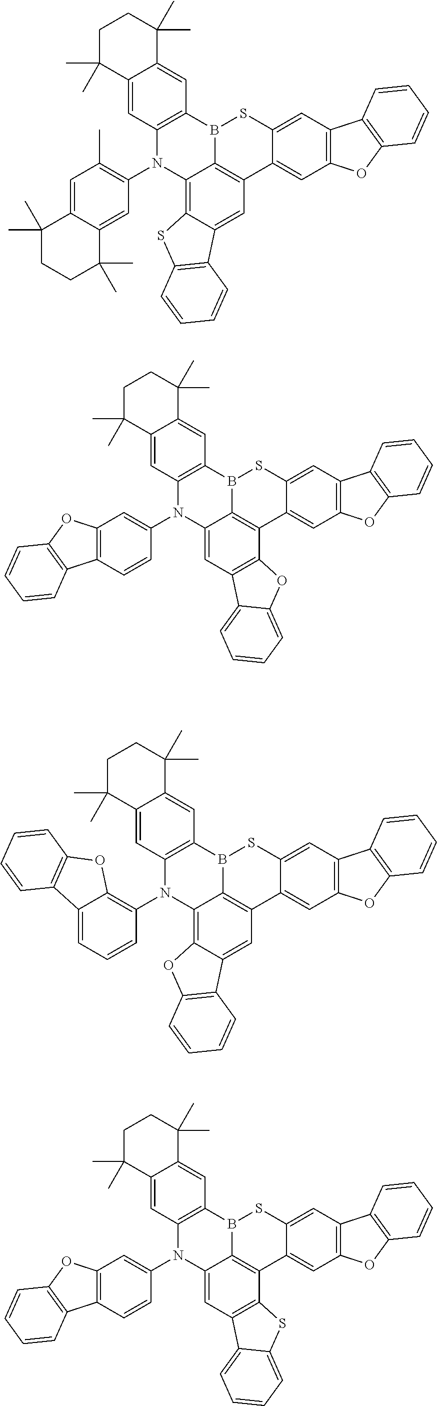

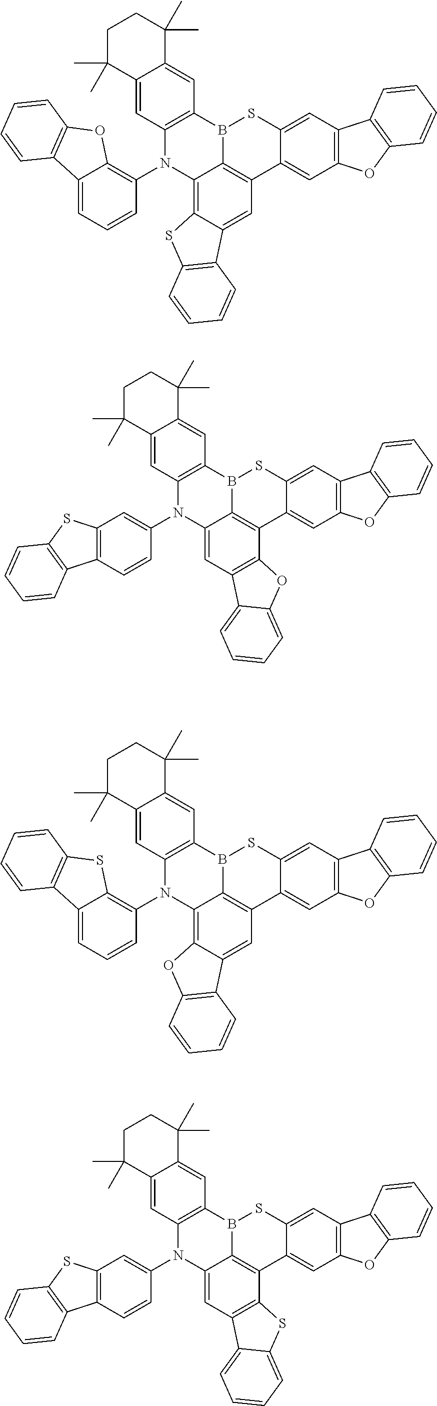

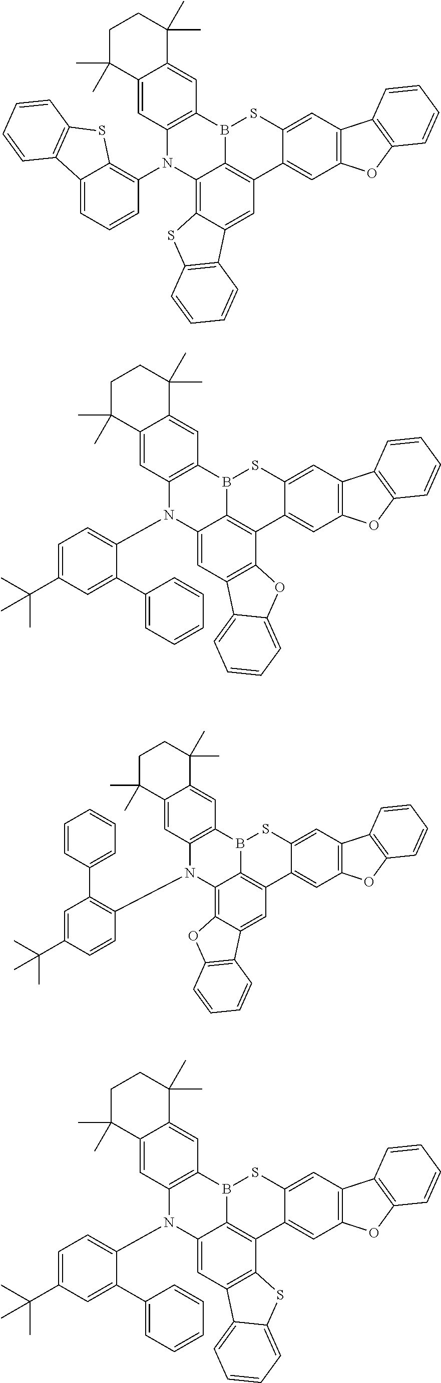

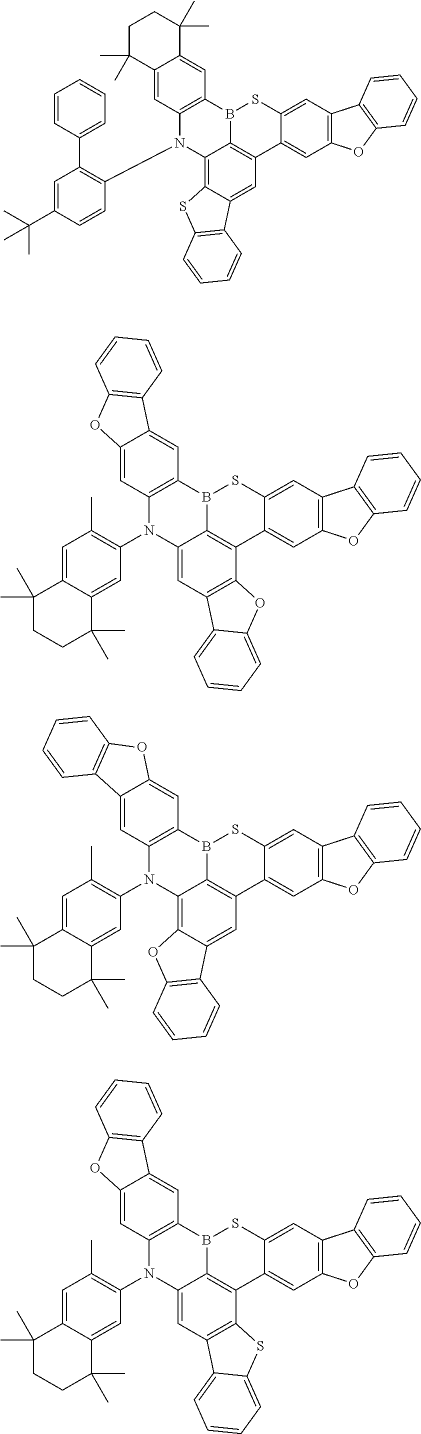 [SMILES: CC(C)(C)c1ccc(N2c3cc4c(cc3B3Sc5cc6c(cc5-c5cc7c(sc8ccccc87)c2c53)oc2ccccc26)C(C)(C)CCC4(C)C)c(-c2ccccc2)c1 ; Cc1cc2c(cc1N1c3cc4oc5ccccc5c4cc3B3Sc4cc5c(cc4-c4c3c1cc1c4oc3ccccc31)oc1ccccc15)C(C)(C)CCC2(C)C ; Cc1cc2c(cc1N1c3cc4c(cc3B3Sc5cc6c(cc5-c5cc7c(oc8ccccc87)c1c53)oc1ccccc16)oc1ccccc14)C(C)(C)CCC2(C)C ; Cc1cc2c(cc1N1c3cc4oc5ccccc5c4cc3B3Sc4cc5c(cc4-c4c3c1cc1c4sc3ccccc31)oc1ccccc15)C(C)(C)CCC2(C)C]

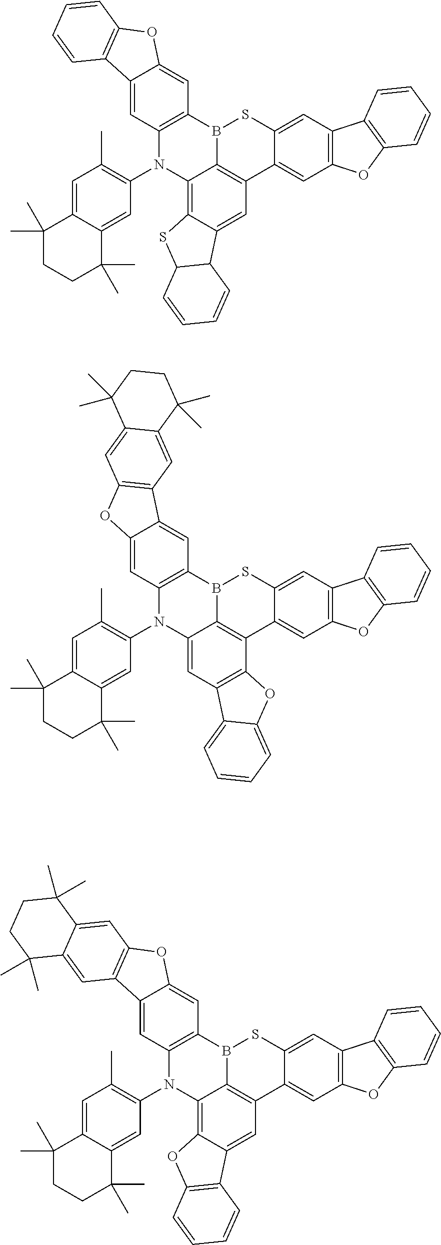 [SMILES: Cc1cc2c(cc1N1c3cc4c(cc3B3Sc5cc6c(cc5-c5cc7c(c1c53)SC1C=CC=CC71)oc1ccccc16)oc1ccccc14)C(C)(C)CCC2(C)C ; Cc1cc2c(cc1N1c3cc4oc5cc6c(cc5c4cc3B3Sc4cc5c(cc4-c4c3c1cc1c4oc3ccccc31)oc1ccccc15)C(C)(C)CCC6(C)C)C(C)(C)CCC2(C)C ; Cc1cc2c(cc1N1c3cc4c(cc3B3Sc5cc6c(cc5-c5cc7c(oc8ccccc87)c1c53)oc1ccccc16)oc1cc3c(cc14)C(C)(C)CCC3(C)C)C(C)(C)CCC2(C)C]

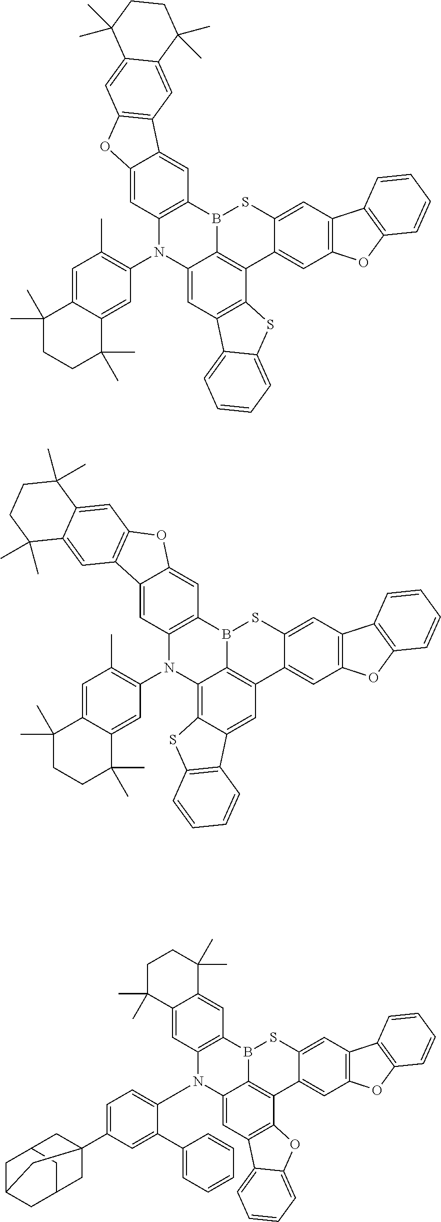 [SMILES: Cc1cc2c(cc1N1c3cc4oc5cc6c(cc5c4cc3B3Sc4cc5c(cc4-c4c3c1cc1c4sc3ccccc31)oc1ccccc15)C(C)(C)CCC6(C)C)C(C)(C)CCC2(C)C ; Cc1cc2c(cc1N1c3cc4c(cc3B3Sc5cc6c(cc5-c5cc7c(sc8ccccc87)c1c53)oc1ccccc16)oc1cc3c(cc14)C(C)(C)CCC3(C)C)C(C)(C)CCC2(C)C ; CC1(C)CCC(C)(C)c2cc3c(cc21)B1Sc2cc4c(cc2-c2c1c(cc1c2oc2ccccc21)N3c1ccc(C23CC5CC(CC(C5)C2)C3)cc1-c1ccccc1)oc1ccccc14]

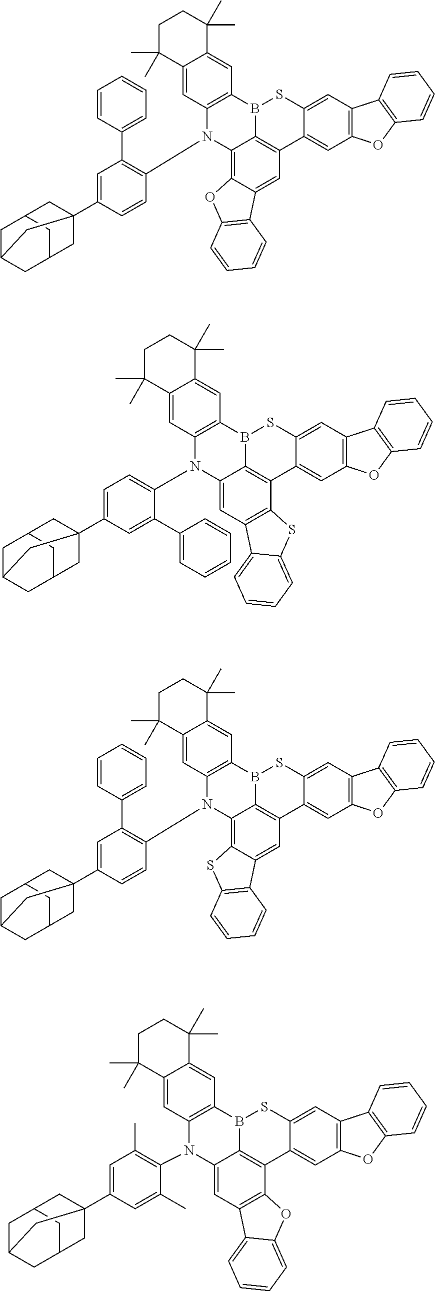 [SMILES: CC1(C)CCC(C)(C)c2cc3c(cc21)B1Sc2cc4c(cc2-c2cc5c(oc6ccccc65)c(c21)N3c1ccc(C23CC5CC(CC(C5)C2)C3)cc1-c1ccccc1)oc1ccccc14 ; CC1(C)CCC(C)(C)c2cc3c(cc21)B1Sc2cc4c(cc2-c2c1c(cc1c2sc2ccccc21)N3c1ccc(C23CC5CC(CC(C5)C2)C3)cc1-c1ccccc1)oc1ccccc14 ; CC1(C)CCC(C)(C)c2cc3c(cc21)B1Sc2cc4c(cc2-c2cc5c(sc6ccccc65)c(c21)N3c1ccc(C23CC5CC(CC(C5)C2)C3)cc1-c1ccccc1)oc1ccccc14 ; Cc1cc(C23CC4CC(CC(C4)C2)C3)cc(C)c1N1c2cc3c(cc2B2Sc4cc5c(cc4-c4c2c1cc1c4oc2ccccc21)oc1ccccc15)C(C)(C)CCC3(C)C]

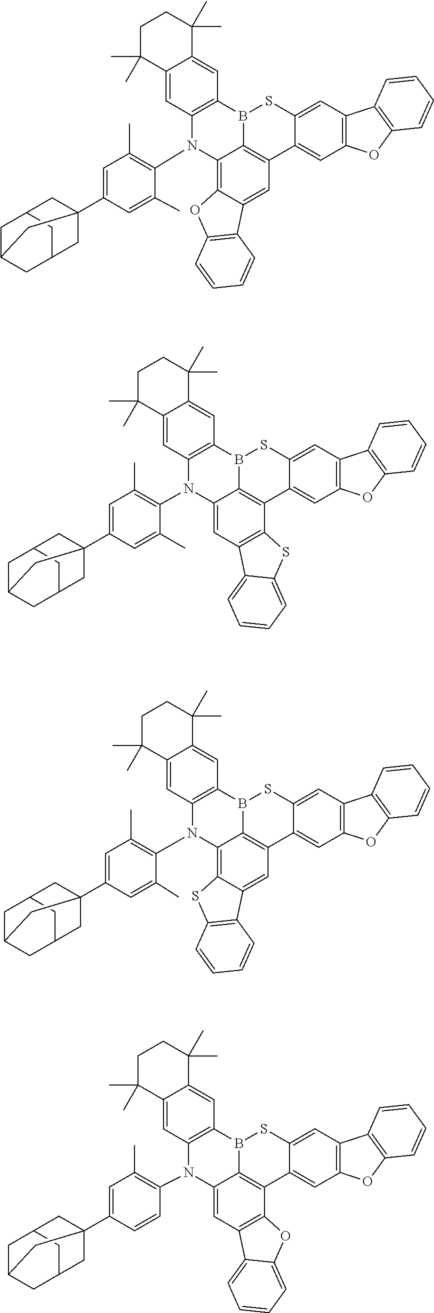 [SMILES: Cc1cc(C23CC4CC(CC(C4)C2)C3)cc(C)c1N1c2cc3c(cc2B2Sc4cc5c(cc4-c4cc6c(oc7ccccc76)c1c42)oc1ccccc15)C(C)(C)CCC3(C)C ; Cc1cc(C23CC4CC(CC(C4)C2)C3)cc(C)c1N1c2cc3c(cc2B2Sc4cc5c(cc4-c4c2c1cc1c4sc2ccccc21)oc1ccccc15)C(C)(C)CCC3(C)C ; Cc1cc(C23CC4CC(CC(C4)C2)C3)cc(C)c1N1c2cc3c(cc2B2Sc4cc5c(cc4-c4cc6c(sc7ccccc76)c1c42)oc1ccccc15)C(C)(C)CCC3(C)C ; Cc1cc(C23CC4CC(CC(C4)C2)C3)ccc1N1c2cc3c(cc2B2Sc4cc5c(cc4-c4c2c1cc1c4oc2ccccc21)oc1ccccc15)C(C)(C)CCC3(C)C]

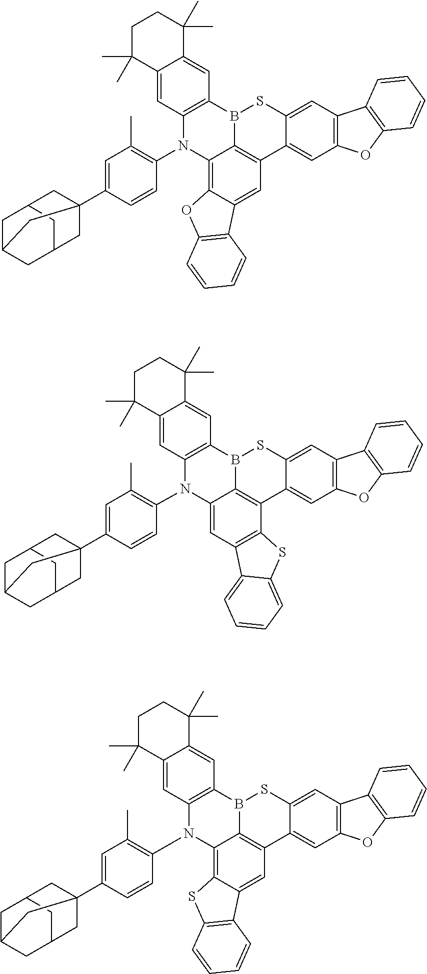 [SMILES: Cc1cc(C23CC4CC(CC(C4)C2)C3)ccc1N1c2cc3c(cc2B2Sc4cc5c(cc4-c4cc6c(oc7ccccc76)c1c42)oc1ccccc15)C(C)(C)CCC3(C)C ; Cc1cc(C23CC4CC(CC(C4)C2)C3)ccc1N1c2cc3c(cc2B2Sc4cc5c(cc4-c4c2c1cc1c4sc2ccccc21)oc1ccccc15)C(C)(C)CCC3(C)C ; Cc1cc(C23CC4CC(CC(C4)C2)C3)ccc1N1c2cc3c(cc2B2Sc4cc5c(cc4-c4cc6c(sc7ccccc76)c1c42)oc1ccccc15)C(C)(C)CCC3(C)C]

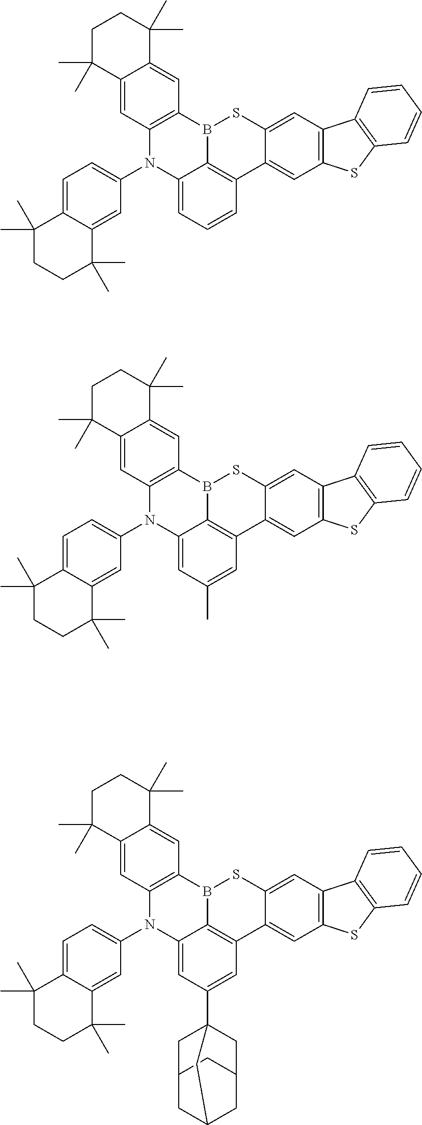 [SMILES: CC1(C)CCC(C)(C)c2cc(N3c4cc5c(cc4B4Sc6cc7c(cc6-c6cccc3c64)sc3ccccc37)C(C)(C)CCC5(C)C)ccc21 ; Cc1cc2c3c(c1)N(c1ccc4c(c1)C(C)(C)CCC4(C)C)c1cc4c(cc1B3Sc1cc3c(cc1-2)sc1ccccc13)C(C)(C)CCC4(C)C ; CC1(C)CCC(C)(C)c2cc(N3c4cc5c(cc4B4Sc6cc7c(cc6-c6cc(C89CC%10CC(CC(C%10)C8)C9)cc3c64)sc3ccccc37)C(C)(C)CCC5(C)C)ccc21]

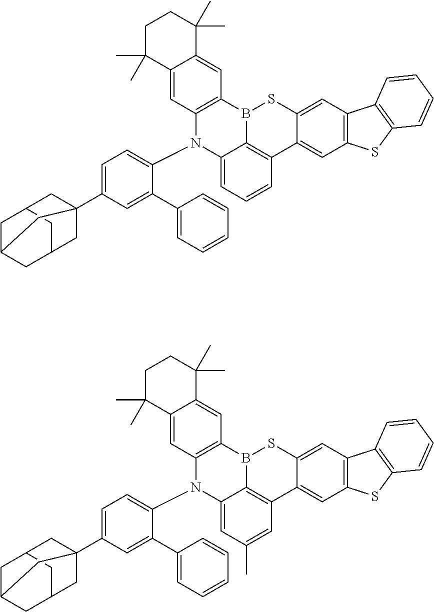 [SMILES: CC1(C)CCC(C)(C)c2cc3c(cc21)B1Sc2cc4c(cc2-c2cccc(c21)N3c1ccc(C23CC5CC(CC(C5)C2)C3)cc1-c1ccccc1)sc1ccccc14 ; Cc1cc2c3c(c1)N(c1ccc(C45CC6CC(CC(C6)C4)C5)cc1-c1ccccc1)c1cc4c(cc1B3Sc1cc3c(cc1-2)sc1ccccc13)C(C)(C)CCC4(C)C]

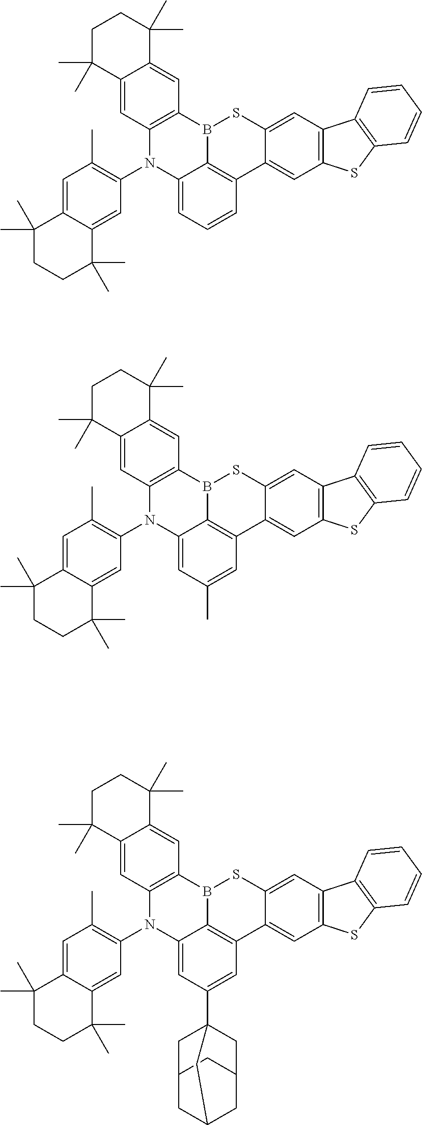 [SMILES: Cc1cc2c(cc1N1c3cc4c(cc3B3Sc5cc6c(cc5-c5cccc1c53)sc1ccccc16)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Sc1cc3c(cc1-2)sc1ccccc13)C(C)(C)CCC4(C)C ; Cc1cc2c(cc1N1c3cc4c(cc3B3Sc5cc6c(cc5-c5cc(C78CC9CC(CC(C9)C7)C8)cc1c53)sc1ccccc16)C(C)(C)CCC4(C)C)C(C)(C)CCC2(C)C]

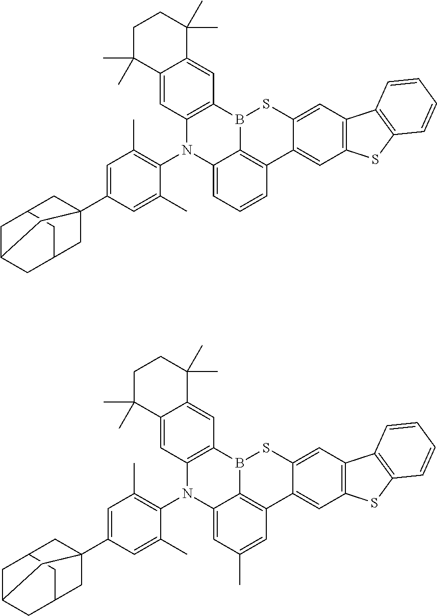 [SMILES: Cc1cc(C23CC4CC(CC(C4)C2)C3)cc(C)c1N1c2cc3c(cc2B2Sc4cc5c(cc4-c4cccc1c42)sc1ccccc15)C(C)(C)CCC3(C)C ; Cc1cc2c3c(c1)N(c1c(C)cc(C45CC6CC(CC(C6)C4)C5)cc1C)c1cc4c(cc1B3Sc1cc3c(cc1-2)sc1ccccc13)C(C)(C)CCC4(C)C]

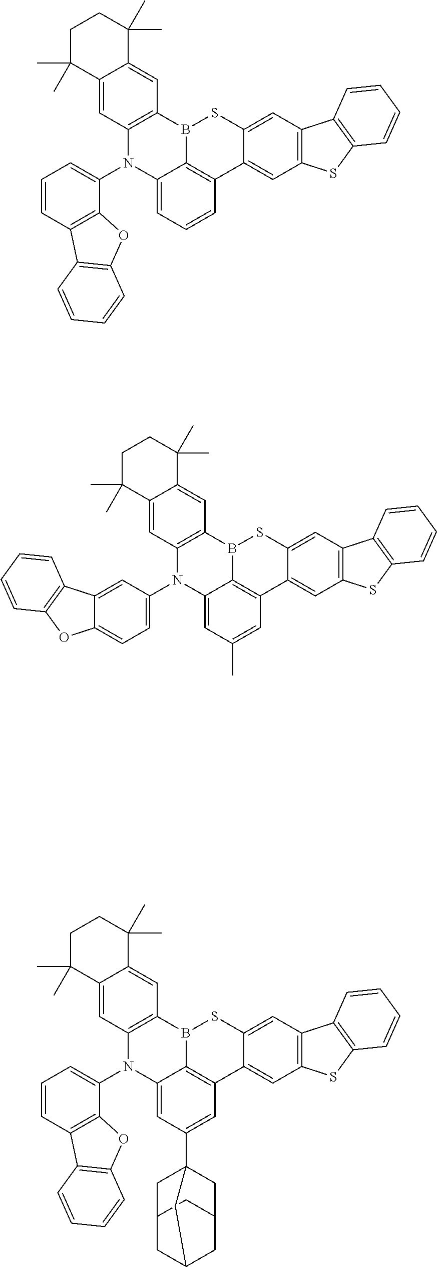 [SMILES: CC1(C)CCC(C)(C)c2cc3c(cc21)B1Sc2cc4c(cc2-c2cccc(c21)N3c1cccc2c1oc1ccccc12)sc1ccccc14 ; Cc1cc2c3c(c1)N(c1ccc4oc5ccccc5c4c1)c1cc4c(cc1B3Sc1cc3c(cc1-2)sc1ccccc13)C(C)(C)CCC4(C)C ; CC1(C)CCC(C)(C)c2cc3c(cc21)B1Sc2cc4c(cc2-c2cc(C56CC7CC(CC(C7)C5)C6)cc(c21)N3c1cccc2c1oc1ccccc12)sc1ccccc14]

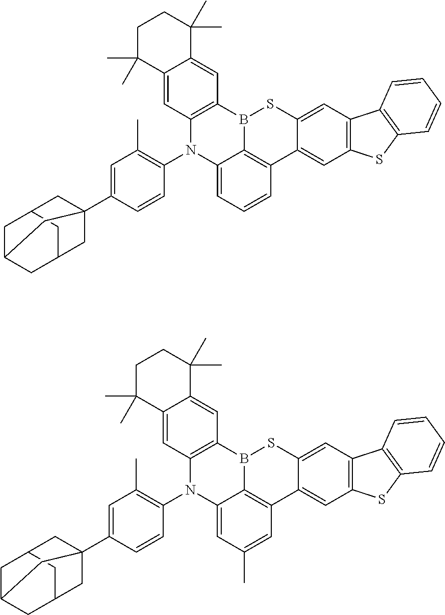 [SMILES: Cc1cc(C23CC4CC(CC(C4)C2)C3)ccc1N1c2cc3c(cc2B2Sc4cc5c(cc4-c4cccc1c42)sc1ccccc15)C(C)(C)CCC3(C)C ; Cc1cc2c3c(c1)N(c1ccc(C45CC6CC(CC(C6)C4)C5)cc1C)c1cc4c(cc1B3Sc1cc3c(cc1-2)sc1ccccc13)C(C)(C)CCC4(C)C]

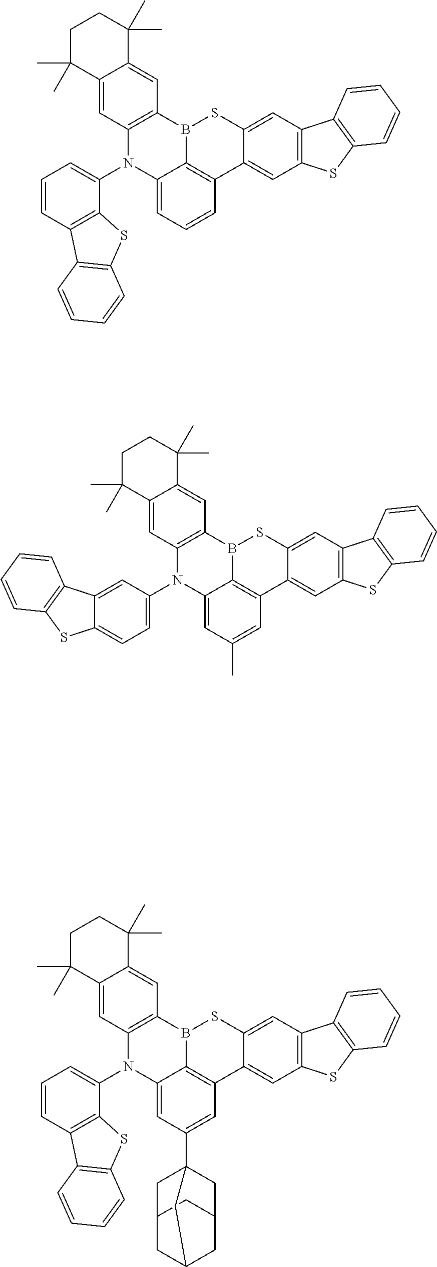 [SMILES: CC1(C)CCC(C)(C)c2cc3c(cc21)B1Sc2cc4c(cc2-c2cccc(c21)N3c1cccc2c1sc1ccccc12)sc1ccccc14 ; Cc1cc2c3c(c1)N(c1ccc4sc5ccccc5c4c1)c1cc4c(cc1B3Sc1cc3c(cc1-2)sc1ccccc13)C(C)(C)CCC4(C)C ; CC1(C)CCC(C)(C)c2cc3c(cc21)B1Sc2cc4c(cc2-c2cc(C56CC7CC(CC(C7)C5)C6)cc(c21)N3c1cccc2c1sc1ccccc12)sc1ccccc14]

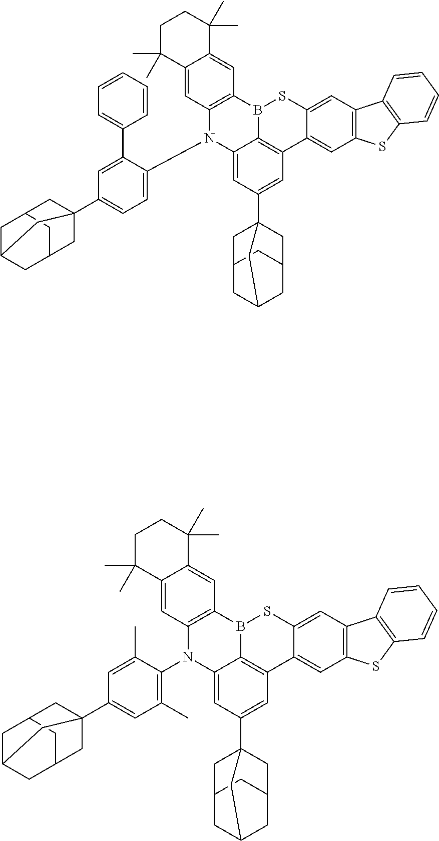 [SMILES: CC1(C)CCC(C)(C)c2cc3c(cc21)B1Sc2cc4c(cc2-c2cc(C56CC7CC(CC(C7)C5)C6)cc(c21)N3c1ccc(C23CC5CC(CC(C5)C2)C3)cc1-c1ccccc1)sc1ccccc14 ; Cc1cc(C23CC4CC(CC(C4)C2)C3)cc(C)c1N1c2cc3c(cc2B2Sc4cc5c(cc4-c4cc(C67CC8CC(CC(C8)C6)C7)cc1c42)sc1ccccc15)C(C)(C)CCC3(C)C]

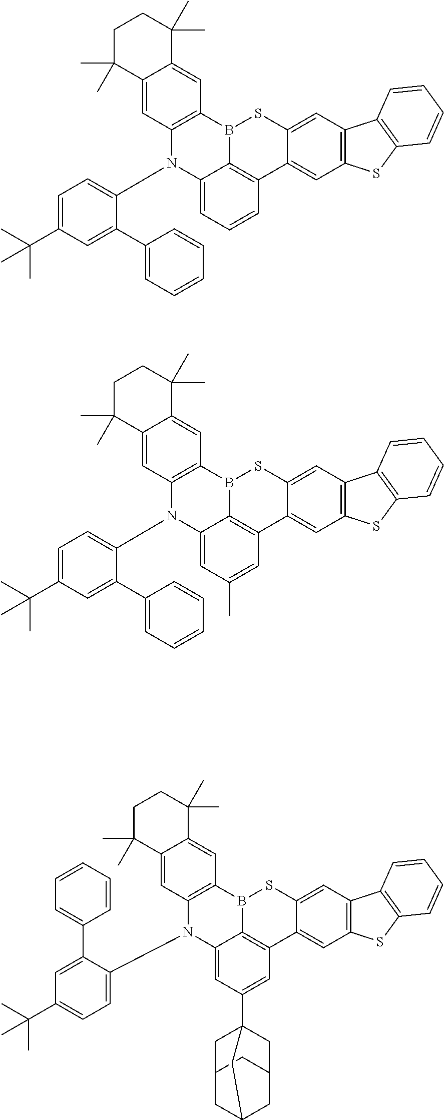 [SMILES: CC(C)(C)c1ccc(N2c3cc4c(cc3B3Sc5cc6c(cc5-c5cccc2c53)sc2ccccc26)C(C)(C)CCC4(C)C)c(-c2ccccc2)c1 ; Cc1cc2c3c(c1)N(c1ccc(C(C)(C)C)cc1-c1ccccc1)c1cc4c(cc1B3Sc1cc3c(cc1-2)sc1ccccc13)C(C)(C)CCC4(C)C ; CC(C)(C)c1ccc(N2c3cc4c(cc3B3Sc5cc6c(cc5-c5cc(C78CC9CC(CC(C9)C7)C8)cc2c53)sc2ccccc26)C(C)(C)CCC4(C)C)c(-c2ccccc2)c1]

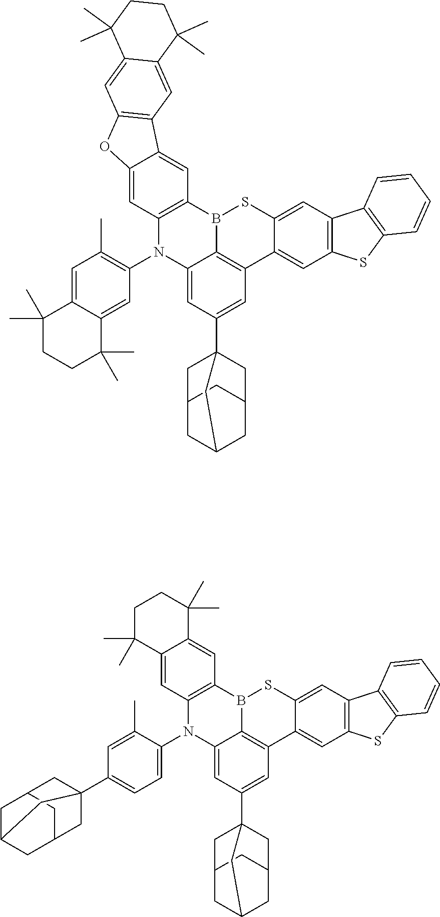 [SMILES: Cc1cc2c(cc1N1c3cc4oc5cc6c(cc5c4cc3B3Sc4cc5c(cc4-c4cc(C78CC9CC(CC(C9)C7)C8)cc1c43)sc1ccccc15)C(C)(C)CCC6(C)C)C(C)(C)CCC2(C)C ; Cc1cc(C23CC4CC(CC(C4)C2)C3)ccc1N1c2cc3c(cc2B2Sc4cc5c(cc4-c4cc(C67CC8CC(CC(C8)C6)C7)cc1c42)sc1ccccc15)C(C)(C)CCC3(C)C]

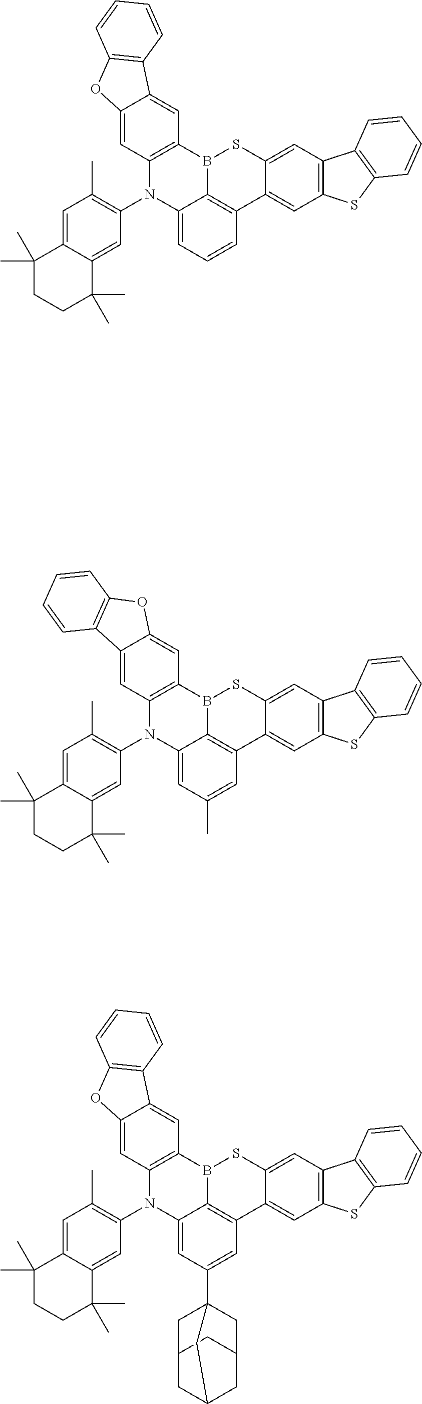 [SMILES: Cc1cc2c(cc1N1c3cc4oc5ccccc5c4cc3B3Sc4cc5c(cc4-c4cccc1c43)sc1ccccc15)C(C)(C)CCC2(C)C ; Cc1cc2c3c(c1)N(c1cc4c(cc1C)C(C)(C)CCC4(C)C)c1cc4c(cc1B3Sc1cc3c(cc1-2)sc1ccccc13)oc1ccccc14 ; Cc1cc2c(cc1N1c3cc4oc5ccccc5c4cc3B3Sc4cc5c(cc4-c4cc(C67CC8CC(CC(C8)C6)C7)cc1c43)sc1ccccc15)C(C)(C)CCC2(C)C]

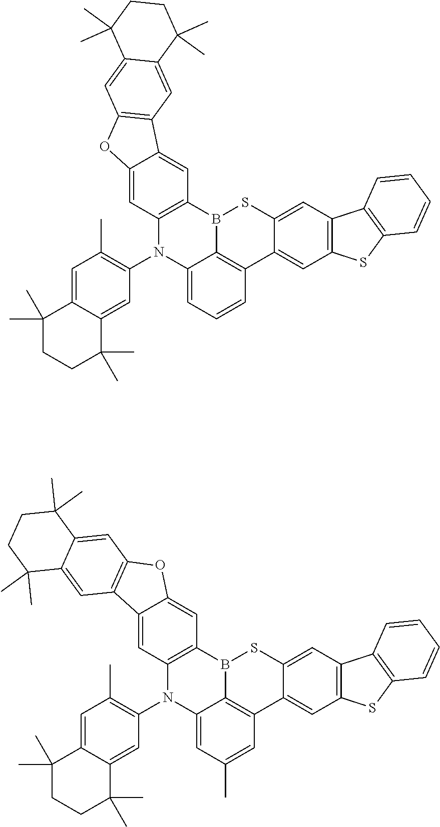 [SMILES: Cc1cc2c(cc1N1c3cc4oc5cc6c(cc5c4cc3B3Sc4cc5c(cc4-c4cccc1c43)sc1ccccc15)C(C)(C)CCC6(C)C)C(C)(C)CCC2(C)C ; Cc1cc2c3c(c1)N(c1cc4c(cc1C)C(C)(C)CCC4(C)C)c1cc4c(cc1B3Sc1cc3c(cc1-2)sc1ccccc13)oc1cc2c(cc14)C(C)(C)CCC2(C)C]

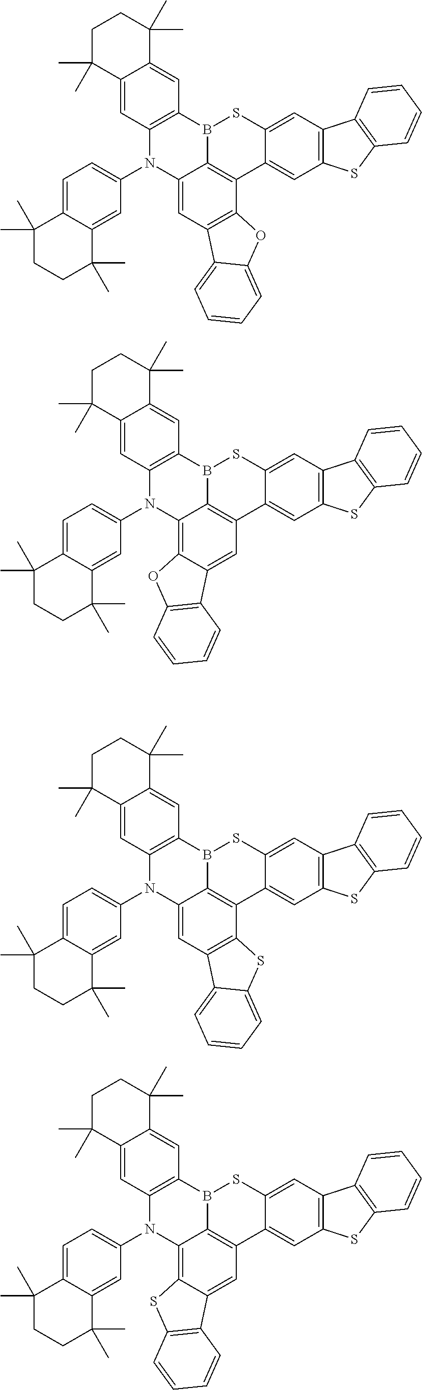 [SMILES: CC1(C)CCC(C)(C)c2cc(N3c4cc5c(cc4B4Sc6cc7c(cc6-c6c4c3cc3c6oc4ccccc43)sc3ccccc37)C(C)(C)CCC5(C)C)ccc21 ; CC1(C)CCC(C)(C)c2cc(N3c4cc5c(cc4B4Sc6cc7c(cc6-c6cc8c(oc9ccccc98)c3c64)sc3ccccc37)C(C)(C)CCC5(C)C)ccc21 ; CC1(C)CCC(C)(C)c2cc(N3c4cc5c(cc4B4Sc6cc7c(cc6-c6c4c3cc3c6sc4ccccc43)sc3ccccc37)C(C)(C)CCC5(C)C)ccc21 ; CC1(C)CCC(C)(C)c2cc(N3c4cc5c(cc4B4Sc6cc7c(cc6-c6cc8c(sc9ccccc98)c3c64)sc3ccccc37)C(C)(C)CCC5(C)C)ccc21]

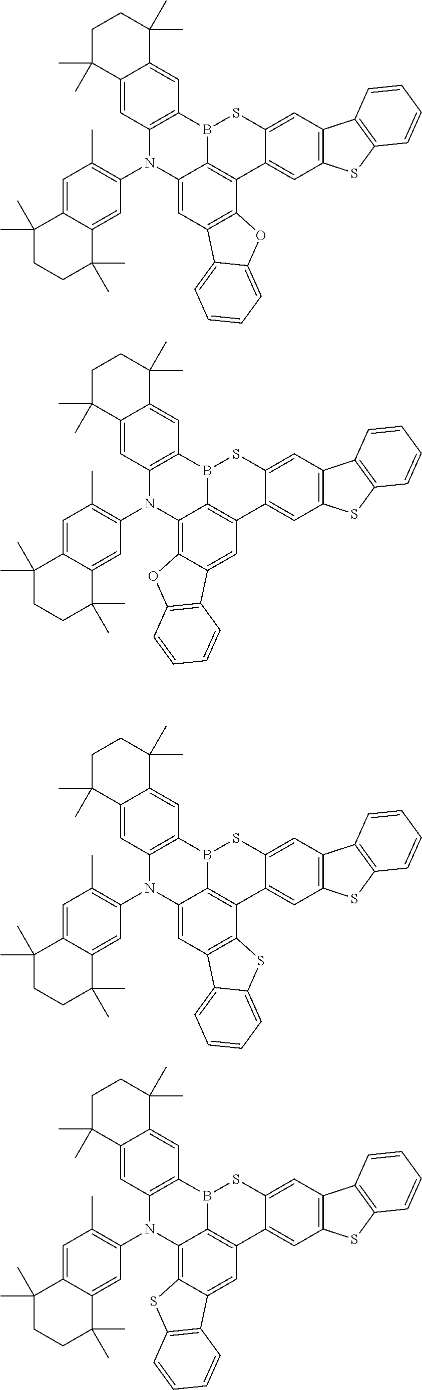 [SMILES: Cc1cc2c(cc1N1c3cc4c(cc3B3Sc5cc6c(cc5-c5c3c1cc1c5oc3ccccc31)sc1ccccc16)C(C)(C)CCC4(C)C)C(C)(C)CCC2(C)C ; Cc1cc2c(cc1N1c3cc4c(cc3B3Sc5cc6c(cc5-c5cc7c(oc8ccccc87)c1c53)sc1ccccc16)C(C)(C)CCC4(C)C)C(C)(C)CCC2(C)C ; Cc1cc2c(cc1N1c3cc4c(cc3B3Sc5cc6c(cc5-c5c3c1cc1c5sc3ccccc31)sc1ccccc16)C(C)(C)CCC4(C)C)C(C)(C)CCC2(C)C ; Cc1cc2c(cc1N1c3cc4c(cc3B3Sc5cc6c(cc5-c5cc7c(sc8ccccc87)c1c53)sc1ccccc16)C(C)(C)CCC4(C)C)C(C)(C)CCC2(C)C]

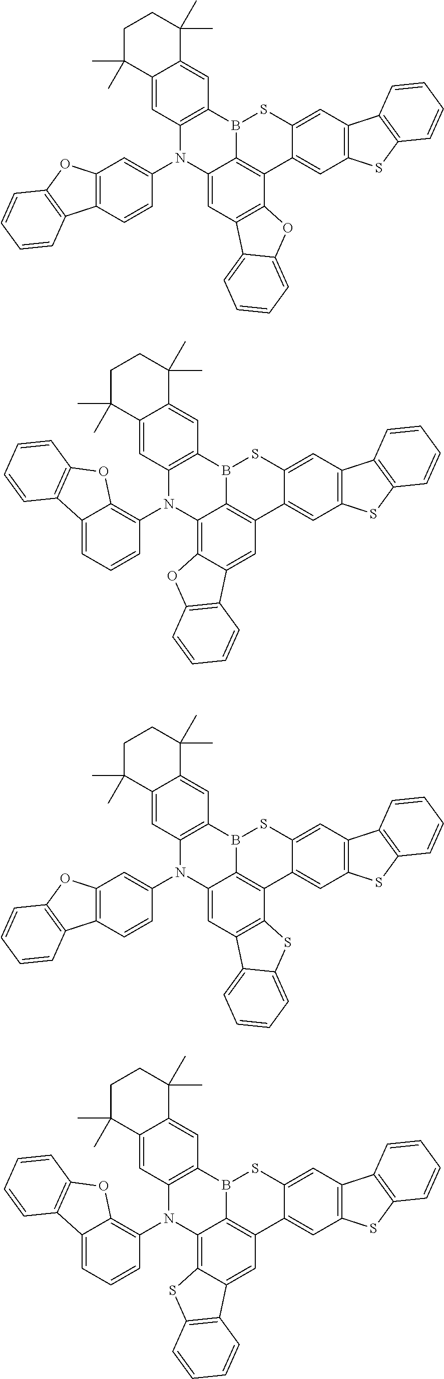 [SMILES: CC1(C)CCC(C)(C)c2cc3c(cc21)B1Sc2cc4c(cc2-c2c1c(cc1c2oc2ccccc21)N3c1ccc2c(c1)oc1ccccc12)sc1ccccc14 ; CC1(C)CCC(C)(C)c2cc3c(cc21)B1Sc2cc4c(cc2-c2cc5c(oc6ccccc65)c(c21)N3c1cccc2c1oc1ccccc12)sc1ccccc14 ; CC1(C)CCC(C)(C)c2cc3c(cc21)B1Sc2cc4c(cc2-c2c1c(cc1c2sc2ccccc21)N3c1ccc2c(c1)oc1ccccc12)sc1ccccc14 ; CC1(C)CCC(C)(C)c2cc3c(cc21)B1Sc2cc4c(cc2-c2cc5c(sc6ccccc65)c(c21)N3c1cccc2c1oc1ccccc12)sc1ccccc14]

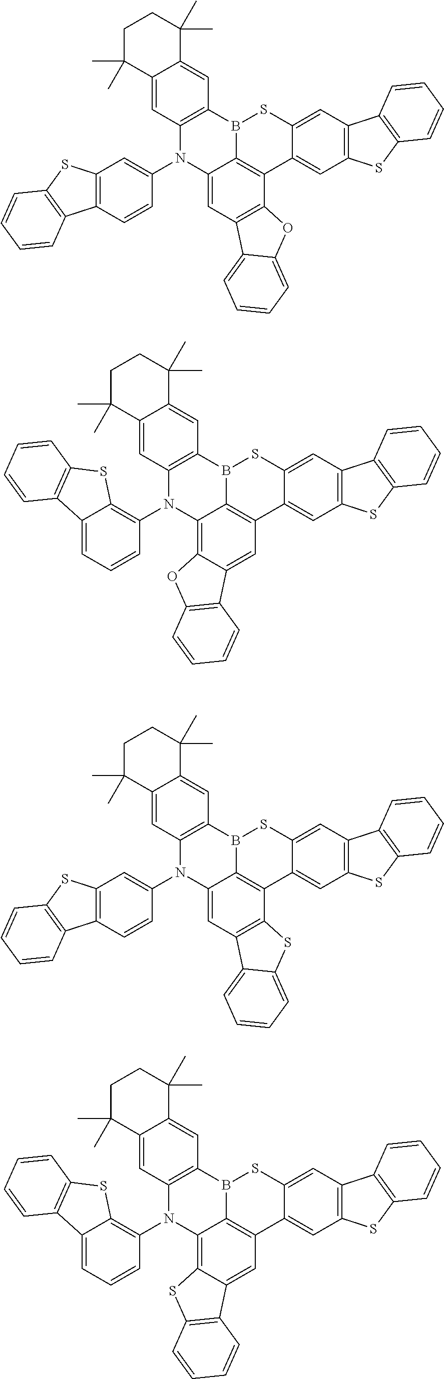 [SMILES: CC1(C)CCC(C)(C)c2cc3c(cc21)B1Sc2cc4c(cc2-c2c1c(cc1c2oc2ccccc21)N3c1ccc2c(c1)sc1ccccc12)sc1ccccc14 ; CC1(C)CCC(C)(C)c2cc3c(cc21)B1Sc2cc4c(cc2-c2cc5c(oc6ccccc65)c(c21)N3c1cccc2c1sc1ccccc12)sc1ccccc14 ; CC1(C)CCC(C)(C)c2cc3c(cc21)B1Sc2cc4c(cc2-c2c1c(cc1c2sc2ccccc21)N3c1ccc2c(c1)sc1ccccc12)sc1ccccc14 ; CC1(C)CCC(C)(C)c2cc3c(cc21)B1Sc2cc4c(cc2-c2cc5c(sc6ccccc65)c(c21)N3c1cccc2c1sc1ccccc12)sc1ccccc14]

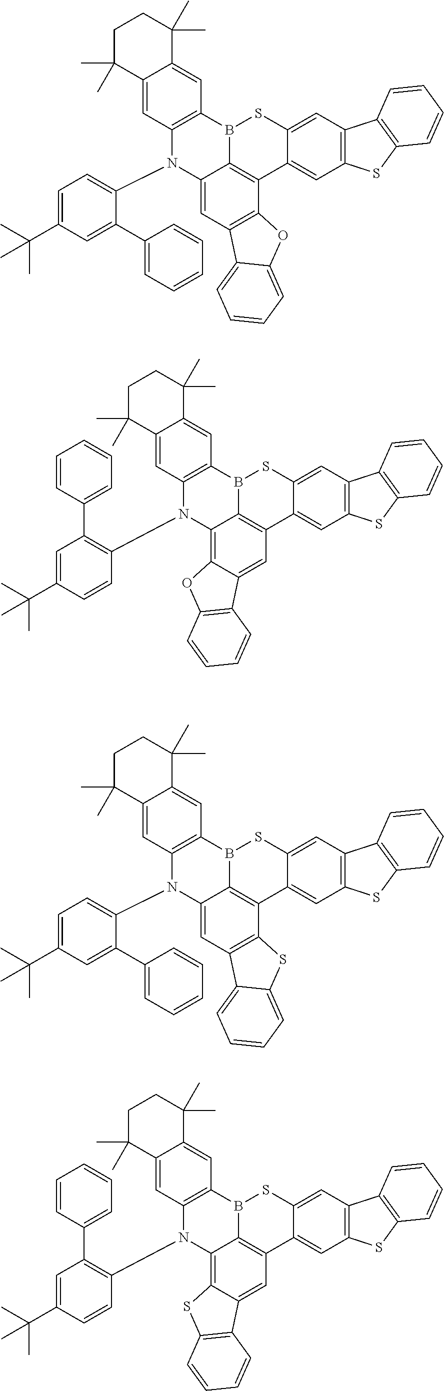 [SMILES: CC(C)(C)c1ccc(N2c3cc4c(cc3B3Sc5cc6c(cc5-c5c3c2cc2c5oc3ccccc32)sc2ccccc26)C(C)(C)CCC4(C)C)c(-c2ccccc2)c1 ; CC(C)(C)c1ccc(N2c3cc4c(cc3B3Sc5cc6c(cc5-c5cc7c(oc8ccccc87)c2c53)sc2ccccc26)C(C)(C)CCC4(C)C)c(-c2ccccc2)c1 ; CC(C)(C)c1ccc(N2c3cc4c(cc3B3Sc5cc6c(cc5-c5c3c2cc2c5sc3ccccc32)sc2ccccc26)C(C)(C)CCC4(C)C)c(-c2ccccc2)c1 ; CC(C)(C)c1ccc(N2c3cc4c(cc3B3Sc5cc6c(cc5-c5cc7c(sc8ccccc87)c2c53)sc2ccccc26)C(C)(C)CCC4(C)C)c(-c2ccccc2)c1]

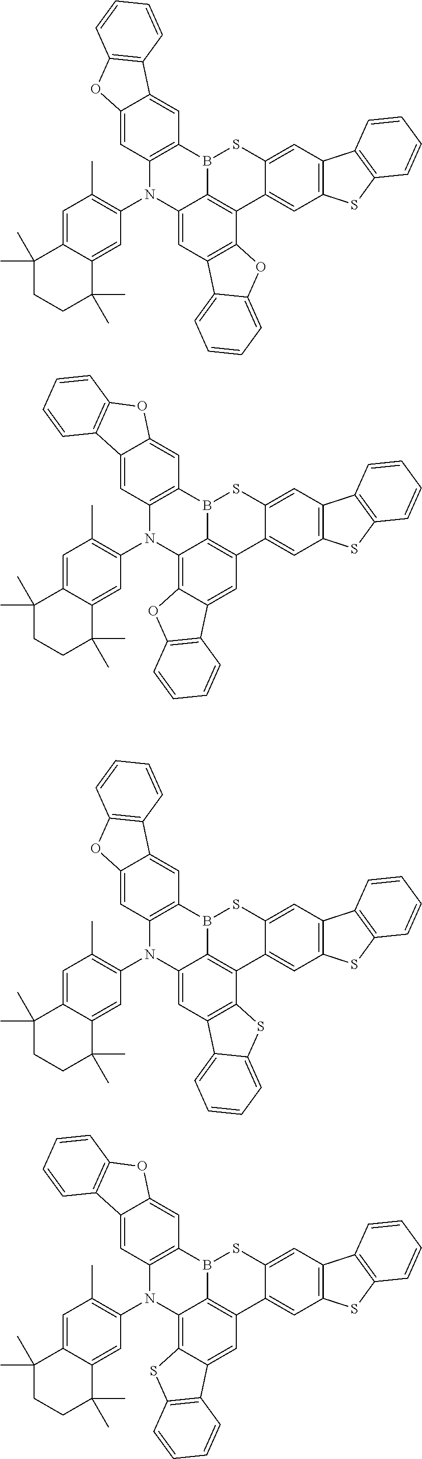 [SMILES: Cc1cc2c(cc1N1c3cc4oc5ccccc5c4cc3B3Sc4cc5c(cc4-c4c3c1cc1c4oc3ccccc31)sc1ccccc15)C(C)(C)CCC2(C)C ; Cc1cc2c(cc1N1c3cc4c(cc3B3Sc5cc6c(cc5-c5cc7c(oc8ccccc87)c1c53)sc1ccccc16)oc1ccccc14)C(C)(C)CCC2(C)C ; Cc1cc2c(cc1N1c3cc4oc5ccccc5c4cc3B3Sc4cc5c(cc4-c4c3c1cc1c4sc3ccccc31)sc1ccccc15)C(C)(C)CCC2(C)C ; Cc1cc2c(cc1N1c3cc4c(cc3B3Sc5cc6c(cc5-c5cc7c(sc8ccccc87)c1c53)sc1ccccc16)oc1ccccc14)C(C)(C)CCC2(C)C]

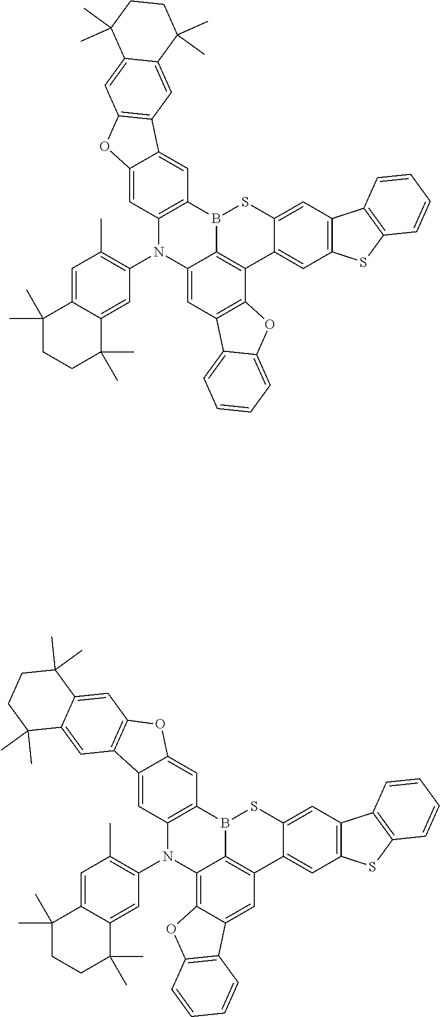 [SMILES: Cc1cc2c(cc1N1c3cc4oc5cc6c(cc5c4cc3B3Sc4cc5c(cc4-c4c3c1cc1c4oc3ccccc31)sc1ccccc15)C(C)(C)CCC6(C)C)C(C)(C)CCC2(C)C ; Cc1cc2c(cc1N1c3cc4c(cc3B3Sc5cc6c(cc5-c5cc7c(oc8ccccc87)c1c53)sc1ccccc16)oc1cc3c(cc14)C(C)(C)CCC3(C)C)C(C)(C)CCC2(C)C]

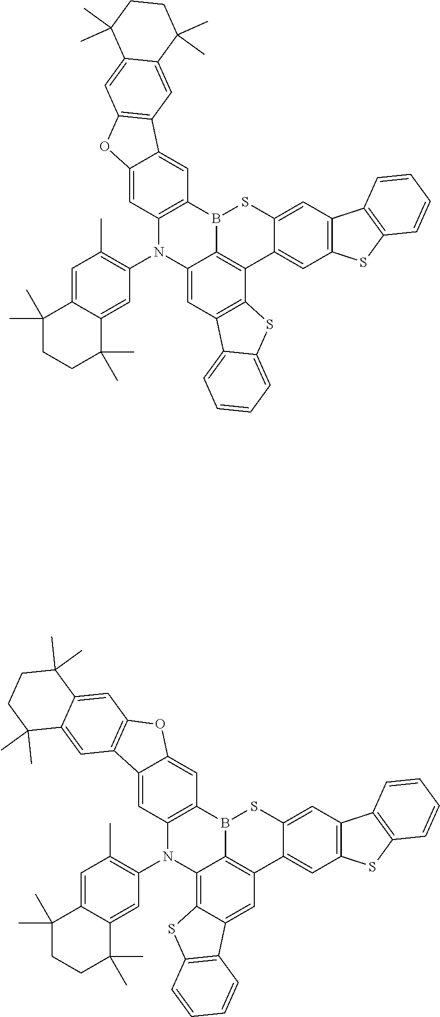 [SMILES: Cc1cc2c(cc1N1c3cc4oc5cc6c(cc5c4cc3B3Sc4cc5c(cc4-c4c3c1cc1c4sc3ccccc31)sc1ccccc15)C(C)(C)CCC6(C)C)C(C)(C)CCC2(C)C ; Cc1cc2c(cc1N1c3cc4c(cc3B3Sc5cc6c(cc5-c5cc7c(sc8ccccc87)c1c53)sc1ccccc16)oc1cc3c(cc14)C(C)(C)CCC3(C)C)C(C)(C)CCC2(C)C]

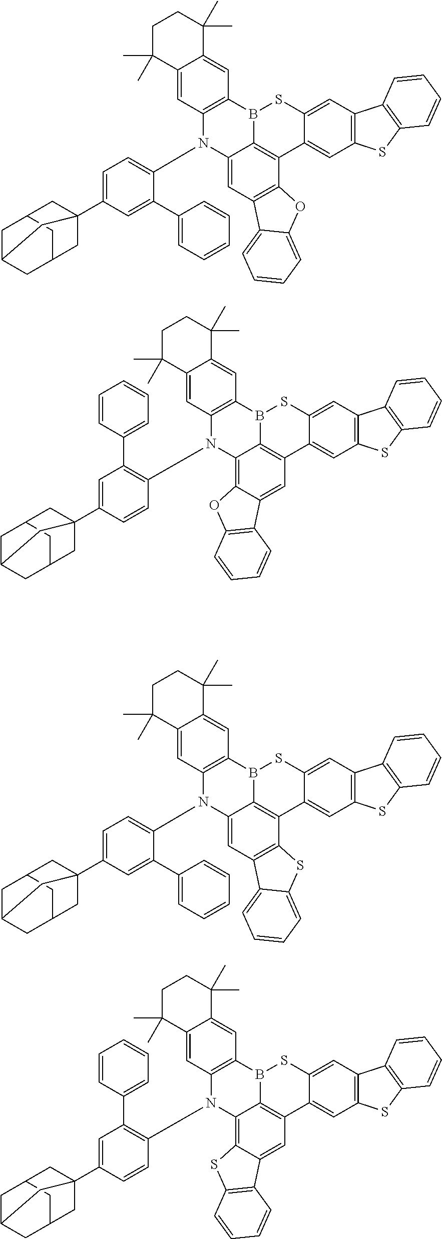

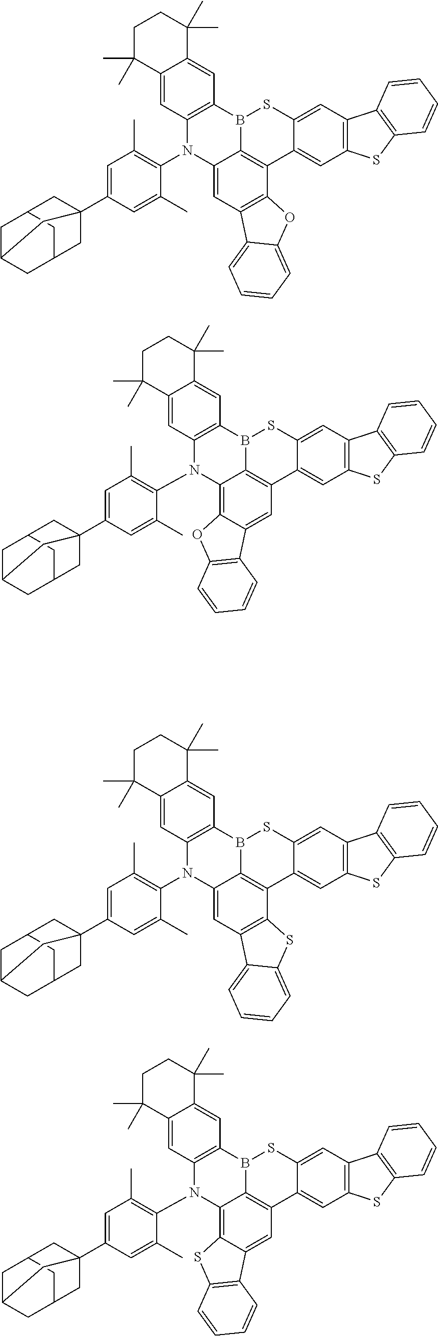 [SMILES: Cc1cc(C23CC4CC(CC(C4)C2)C3)cc(C)c1N1c2cc3c(cc2B2Sc4cc5c(cc4-c4c2c1cc1c4oc2ccccc21)sc1ccccc15)C(C)(C)CCC3(C)C ; Cc1cc(C23CC4CC(CC(C4)C2)C3)cc(C)c1N1c2cc3c(cc2B2Sc4cc5c(cc4-c4cc6c(oc7ccccc76)c1c42)sc1ccccc15)C(C)(C)CCC3(C)C ; Cc1cc(C23CC4CC(CC(C4)C2)C3)cc(C)c1N1c2cc3c(cc2B2Sc4cc5c(cc4-c4c2c1cc1c4sc2ccccc21)sc1ccccc15)C(C)(C)CCC3(C)C ; Cc1cc(C23CC4CC(CC(C4)C2)C3)cc(C)c1N1c2cc3c(cc2B2Sc4cc5c(cc4-c4cc6c(sc7ccccc76)c1c42)sc1ccccc15)C(C)(C)CCC3(C)C]

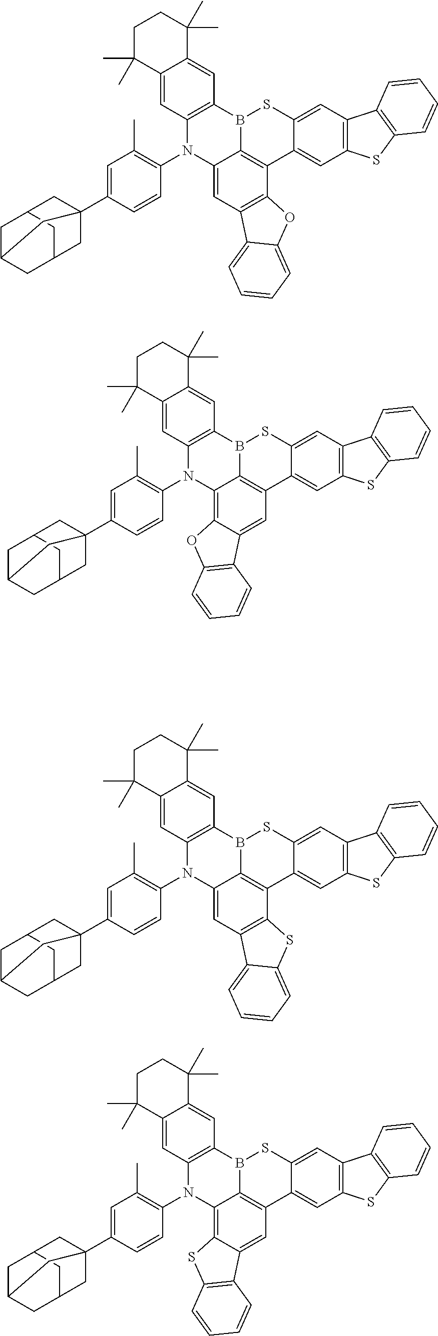 [SMILES: Cc1cc(C23CC4CC(CC(C4)C2)C3)ccc1N1c2cc3c(cc2B2Sc4cc5c(cc4-c4c2c1cc1c4oc2ccccc21)sc1ccccc15)C(C)(C)CCC3(C)C ; Cc1cc(C23CC4CC(CC(C4)C2)C3)ccc1N1c2cc3c(cc2B2Sc4cc5c(cc4-c4cc6c(oc7ccccc76)c1c42)sc1ccccc15)C(C)(C)CCC3(C)C ; Cc1cc(C23CC4CC(CC(C4)C2)C3)ccc1N1c2cc3c(cc2B2Sc4cc5c(cc4-c4c2c1cc1c4sc2ccccc21)sc1ccccc15)C(C)(C)CCC3(C)C ; Cc1cc(C23CC4CC(CC(C4)C2)C3)ccc1N1c2cc3c(cc2B2Sc4cc5c(cc4-c4cc6c(sc7ccccc76)c1c42)sc1ccccc15)C(C)(C)CCC3(C)C]

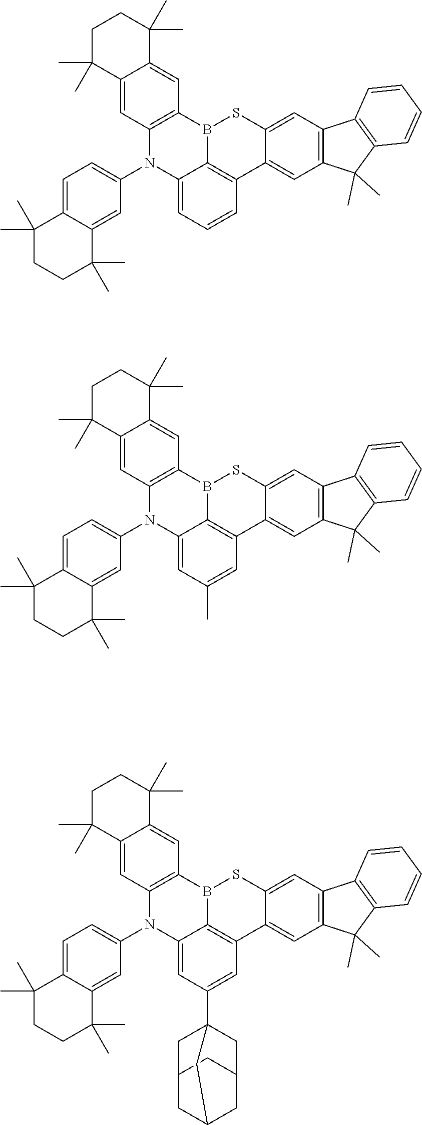 [SMILES: CC1(C)CCC(C)(C)c2cc(N3c4cc5c(cc4B4Sc6cc7c(cc6-c6cccc3c64)C(C)(C)c3ccccc3-7)C(C)(C)CCC5(C)C)ccc21 ; Cc1cc2c3c(c1)N(c1ccc4c(c1)C(C)(C)CCC4(C)C)c1cc4c(cc1B3Sc1cc3c(cc1-2)C(C)(C)c1ccccc1-3)C(C)(C)CCC4(C)C ; CC1(C)CCC(C)(C)c2cc(N3c4cc5c(cc4B4Sc6cc7c(cc6-c6cc(C89CC%10CC(CC(C%10)C8)C9)cc3c64)C(C)(C)c3ccccc3-7)C(C)(C)CCC5(C)C)ccc21]

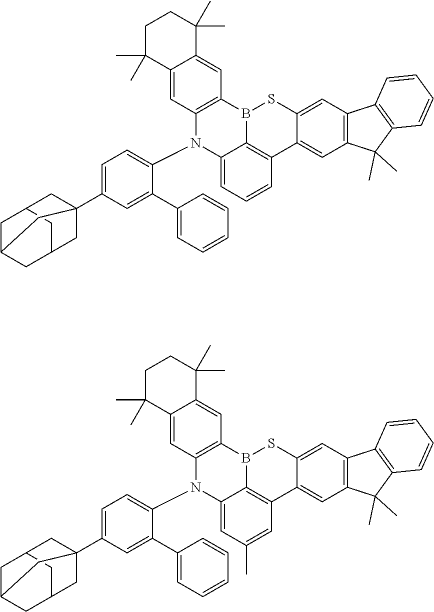 [SMILES: CC1(C)CCC(C)(C)c2cc3c(cc21)B1Sc2cc4c(cc2-c2cccc(c21)N3c1ccc(C23CC5CC(CC(C5)C2)C3)cc1-c1ccccc1)C(C)(C)c1ccccc1-4 ; Cc1cc2c3c(c1)N(c1ccc(C45CC6CC(CC(C6)C4)C5)cc1-c1ccccc1)c1cc4c(cc1B3Sc1cc3c(cc1-2)C(C)(C)c1ccccc1-3)C(C)(C)CCC4(C)C]

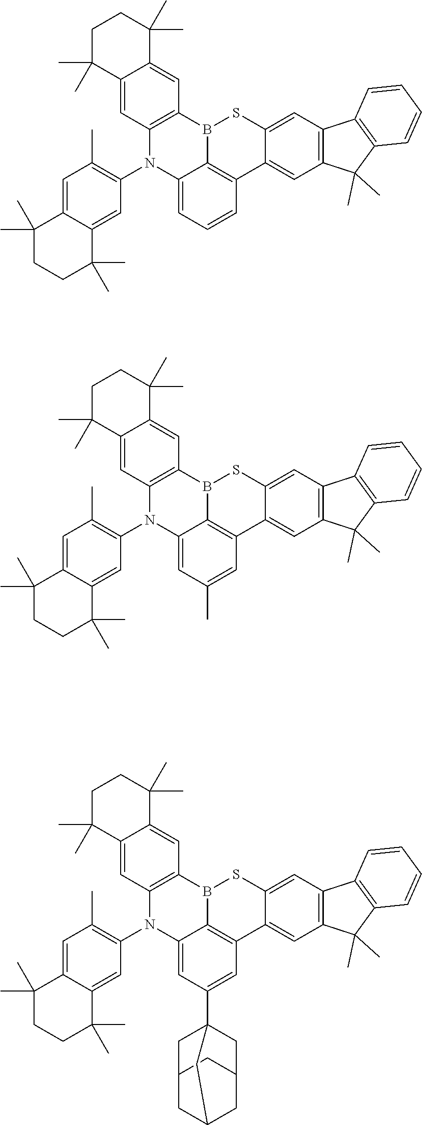 [SMILES: Cc1cc2c(cc1N1c3cc4c(cc3B3Sc5cc6c(cc5-c5cccc1c53)C(C)(C)c1ccccc1-6)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Sc1cc3c(cc1-2)C(C)(C)c1ccccc1-3)C(C)(C)CCC4(C)C ; Cc1cc2c(cc1N1c3cc4c(cc3B3Sc5cc6c(cc5-c5cc(C78CC9CC(CC(C9)C7)C8)cc1c53)C(C)(C)c1ccccc1-6)C(C)(C)CCC4(C)C)C(C)(C)CCC2(C)C]

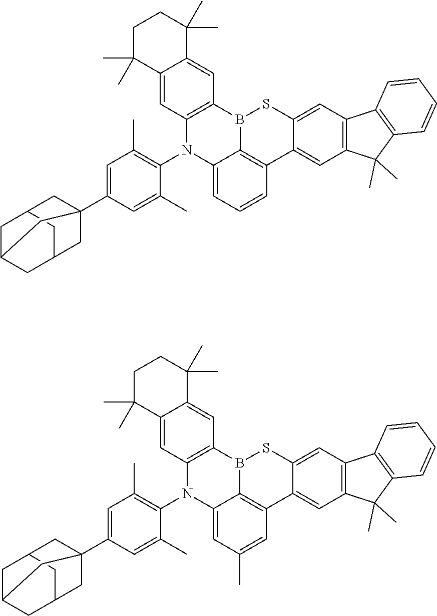 [SMILES: Cc1cc(C23CC4CC(CC(C4)C2)C3)cc(C)c1N1c2cc3c(cc2B2Sc4cc5c(cc4-c4cccc1c42)C(C)(C)c1ccccc1-5)C(C)(C)CCC3(C)C ; Cc1cc2c3c(c1)N(c1c(C)cc(C45CC6CC(CC(C6)C4)C5)cc1C)c1cc4c(cc1B3Sc1cc3c(cc1-2)C(C)(C)c1ccccc1-3)C(C)(C)CCC4(C)C]

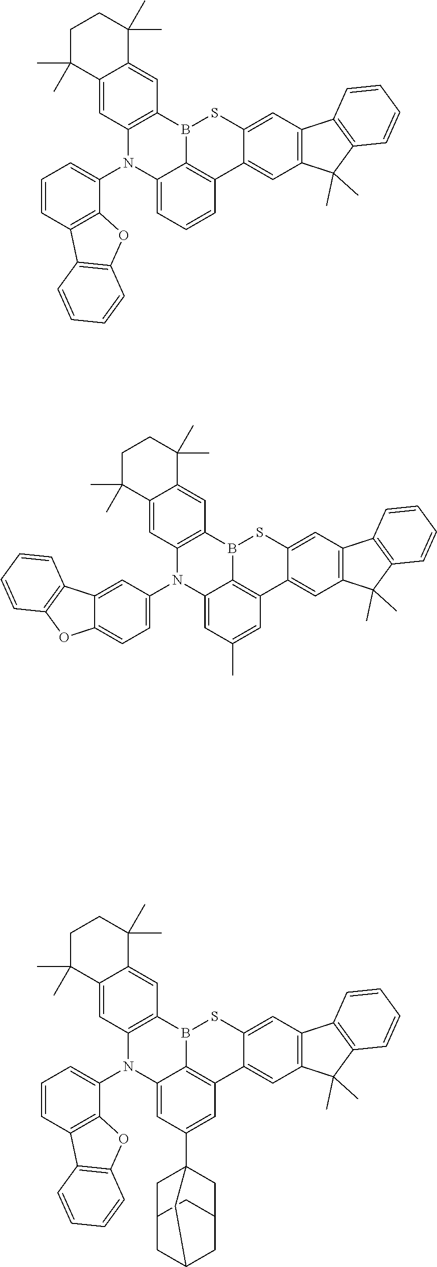 [SMILES: CC1(C)CCC(C)(C)c2cc3c(cc21)B1Sc2cc4c(cc2-c2cccc(c21)N3c1cccc2c1oc1ccccc12)C(C)(C)c1ccccc1-4 ; Cc1cc2c3c(c1)N(c1ccc4oc5ccccc5c4c1)c1cc4c(cc1B3Sc1cc3c(cc1-2)C(C)(C)c1ccccc1-3)C(C)(C)CCC4(C)C ; CC1(C)CCC(C)(C)c2cc3c(cc21)B1Sc2cc4c(cc2-c2cc(C56CC7CC(CC(C7)C5)C6)cc(c21)N3c1cccc2c1oc1ccccc12)C(C)(C)c1ccccc1-4]

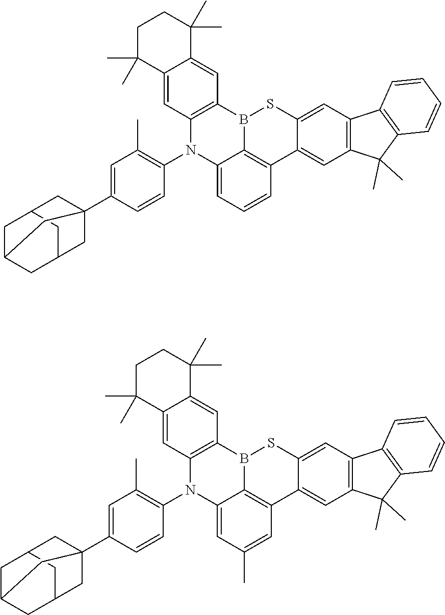 [SMILES: Cc1cc(C23CC4CC(CC(C4)C2)C3)ccc1N1c2cc3c(cc2B2Sc4cc5c(cc4-c4cccc1c42)C(C)(C)c1ccccc1-5)C(C)(C)CCC3(C)C ; Cc1cc2c3c(c1)N(c1ccc(C45CC6CC(CC(C6)C4)C5)cc1C)c1cc4c(cc1B3Sc1cc3c(cc1-2)C(C)(C)c1ccccc1-3)C(C)(C)CCC4(C)C]

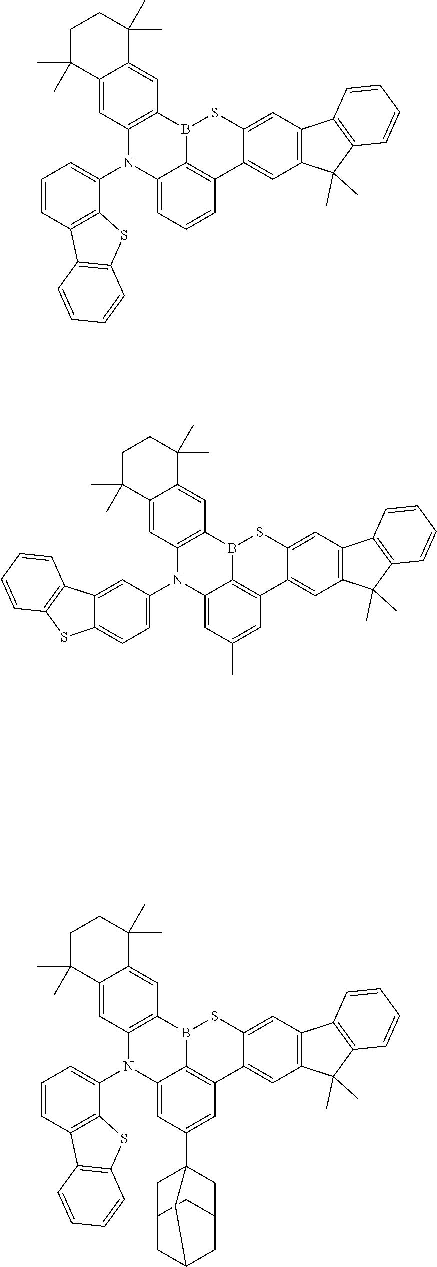 [SMILES: CC1(C)CCC(C)(C)c2cc3c(cc21)B1Sc2cc4c(cc2-c2cccc(c21)N3c1cccc2c1sc1ccccc12)C(C)(C)c1ccccc1-4 ; Cc1cc2c3c(c1)N(c1ccc4sc5ccccc5c4c1)c1cc4c(cc1B3Sc1cc3c(cc1-2)C(C)(C)c1ccccc1-3)C(C)(C)CCC4(C)C ; CC1(C)CCC(C)(C)c2cc3c(cc21)B1Sc2cc4c(cc2-c2cc(C56CC7CC(CC(C7)C5)C6)cc(c21)N3c1cccc2c1sc1ccccc12)C(C)(C)c1ccccc1-4]

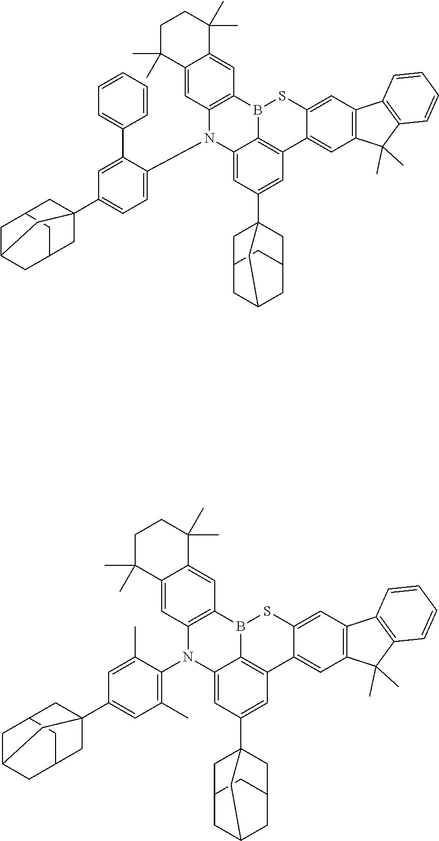 [SMILES: CC1(C)CCC(C)(C)c2cc3c(cc21)B1Sc2cc4c(cc2-c2cc(C56CC7CC(CC(C7)C5)C6)cc(c21)N3c1ccc(C23CC5CC(CC(C5)C2)C3)cc1-c1ccccc1)C(C)(C)c1ccccc1-4 ; Cc1cc(C23CC4CC(CC(C4)C2)C3)cc(C)c1N1c2cc3c(cc2B2Sc4cc5c(cc4-c4cc(C67CC8CC(CC(C8)C6)C7)cc1c42)C(C)(C)c1ccccc1-5)C(C)(C)CCC3(C)C]

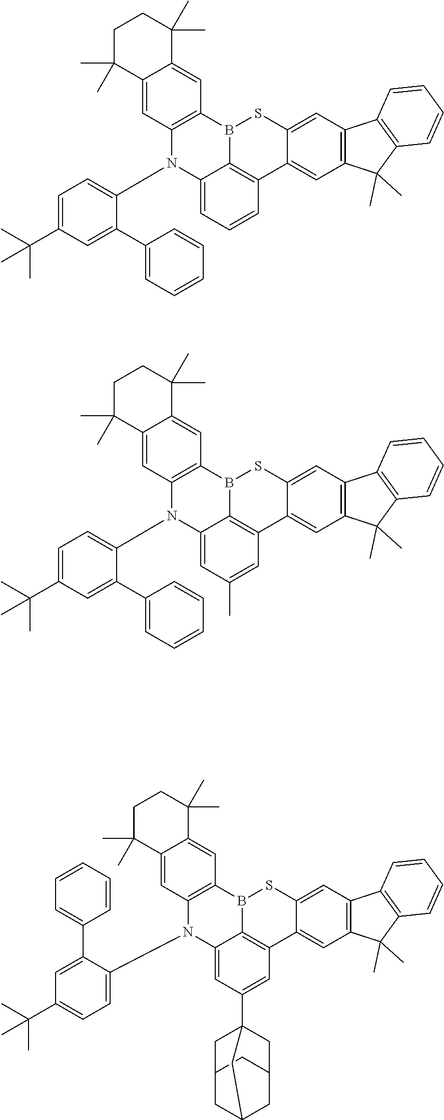 [SMILES: CC(C)(C)c1ccc(N2c3cc4c(cc3B3Sc5cc6c(cc5-c5cccc2c53)C(C)(C)c2ccccc2-6)C(C)(C)CCC4(C)C)c(-c2ccccc2)c1 ; Cc1cc2c3c(c1)N(c1ccc(C(C)(C)C)cc1-c1ccccc1)c1cc4c(cc1B3Sc1cc3c(cc1-2)C(C)(C)c1ccccc1-3)C(C)(C)CCC4(C)C ; CC(C)(C)c1ccc(N2c3cc4c(cc3B3Sc5cc6c(cc5-c5cc(C78CC9CC(CC(C9)C7)C8)cc2c53)C(C)(C)c2ccccc2-6)C(C)(C)CCC4(C)C)c(-c2ccccc2)c1]

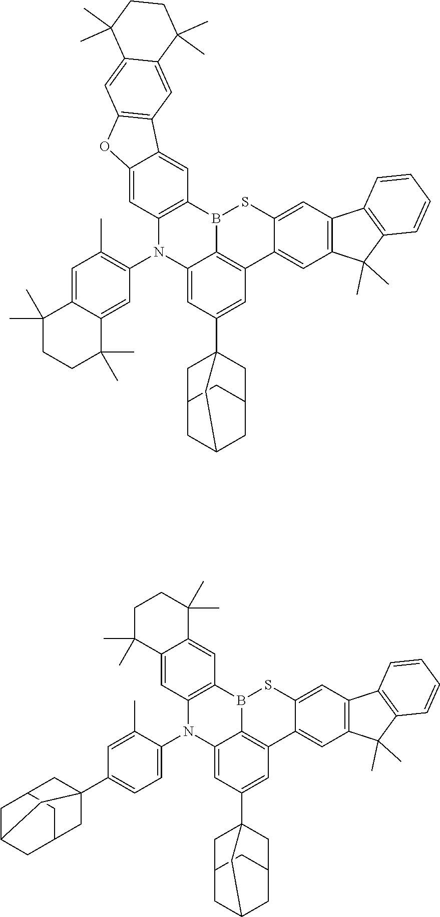 [SMILES: Cc1cc2c(cc1N1c3cc4oc5cc6c(cc5c4cc3B3Sc4cc5c(cc4-c4cc(C78CC9CC(CC(C9)C7)C8)cc1c43)C(C)(C)c1ccccc1-5)C(C)(C)CCC6(C)C)C(C)(C)CCC2(C)C ; Cc1cc(C23CC4CC(CC(C4)C2)C3)ccc1N1c2cc3c(cc2B2Sc4cc5c(cc4-c4cc(C67CC8CC(CC(C8)C6)C7)cc1c42)C(C)(C)c1ccccc1-5)C(C)(C)CCC3(C)C]

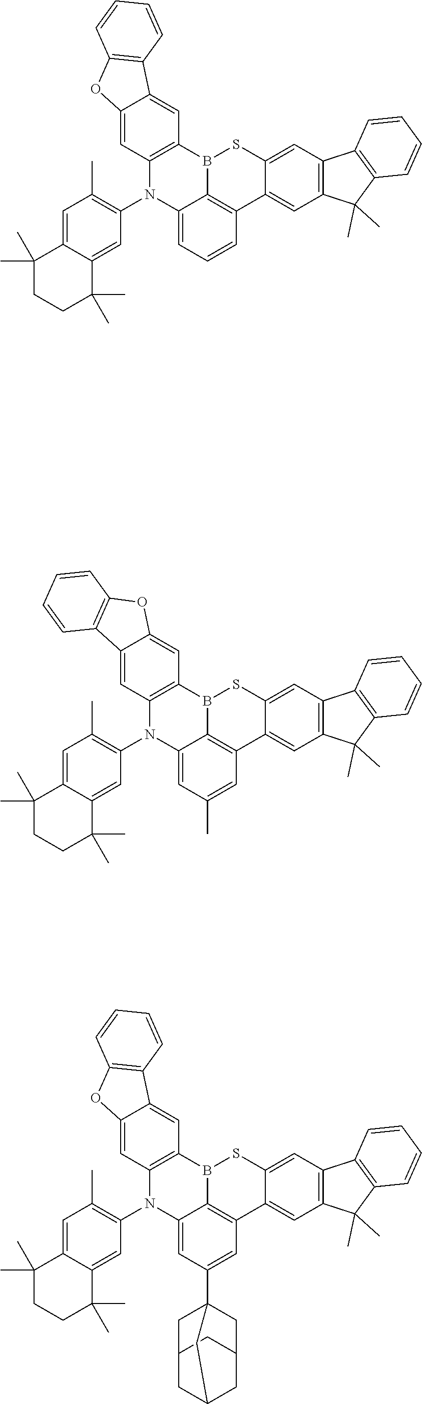 [SMILES: Cc1cc2c(cc1N1c3cc4oc5ccccc5c4cc3B3Sc4cc5c(cc4-c4cccc1c43)C(C)(C)c1ccccc1-5)C(C)(C)CCC2(C)C ; Cc1cc2c3c(c1)N(c1cc4c(cc1C)C(C)(C)CCC4(C)C)c1cc4c(cc1B3Sc1cc3c(cc1-2)C(C)(C)c1ccccc1-3)oc1ccccc14 ; Cc1cc2c(cc1N1c3cc4oc5ccccc5c4cc3B3Sc4cc5c(cc4-c4cc(C67CC8CC(CC(C8)C6)C7)cc1c43)C(C)(C)c1ccccc1-5)C(C)(C)CCC2(C)C]

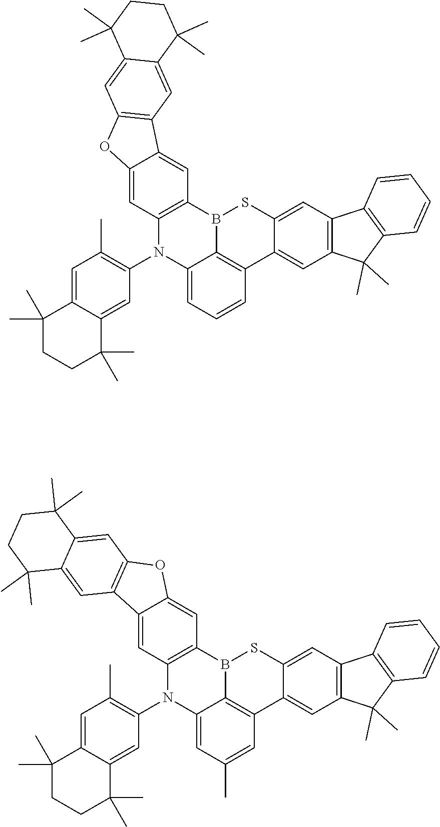 [SMILES: Cc1cc2c(cc1N1c3cc4oc5cc6c(cc5c4cc3B3Sc4cc5c(cc4-c4cccc1c43)C(C)(C)c1ccccc1-5)C(C)(C)CCC6(C)C)C(C)(C)CCC2(C)C ; Cc1cc2c3c(c1)N(c1cc4c(cc1C)C(C)(C)CCC4(C)C)c1cc4c(cc1B3Sc1cc3c(cc1-2)C(C)(C)c1ccccc1-3)oc1cc2c(cc14)C(C)(C)CCC2(C)C]

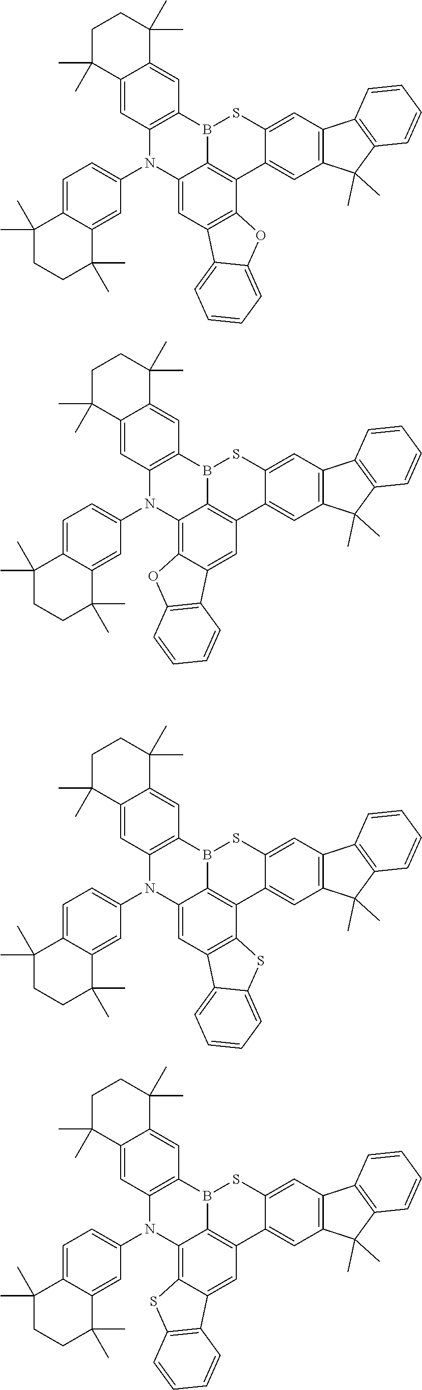 [SMILES: CC1(C)CCC(C)(C)c2cc(N3c4cc5c(cc4B4Sc6cc7c(cc6-c6c4c3cc3c6oc4ccccc43)C(C)(C)c3ccccc3-7)C(C)(C)CCC5(C)C)ccc21 ; CC1(C)CCC(C)(C)c2cc(N3c4cc5c(cc4B4Sc6cc7c(cc6-c6cc8c(oc9ccccc98)c3c64)C(C)(C)c3ccccc3-7)C(C)(C)CCC5(C)C)ccc21 ; CC1(C)CCC(C)(C)c2cc(N3c4cc5c(cc4B4Sc6cc7c(cc6-c6c4c3cc3c6sc4ccccc43)C(C)(C)c3ccccc3-7)C(C)(C)CCC5(C)C)ccc21 ; CC1(C)CCC(C)(C)c2cc(N3c4cc5c(cc4B4Sc6cc7c(cc6-c6cc8c(sc9ccccc98)c3c64)C(C)(C)c3ccccc3-7)C(C)(C)CCC5(C)C)ccc21]

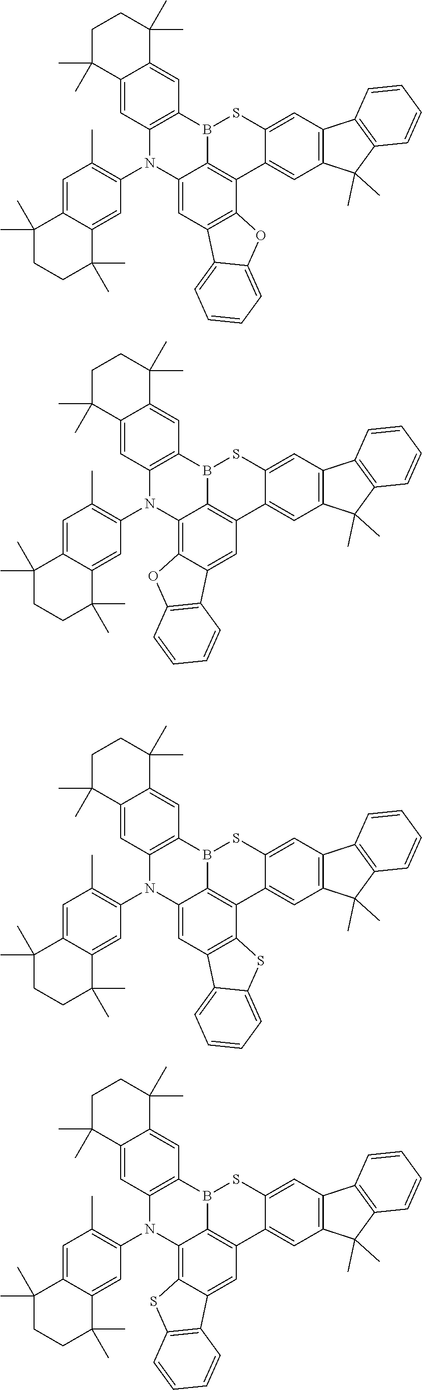 [SMILES: Cc1cc2c(cc1N1c3cc4c(cc3B3Sc5cc6c(cc5-c5c3c1cc1c5oc3ccccc31)C(C)(C)c1ccccc1-6)C(C)(C)CCC4(C)C)C(C)(C)CCC2(C)C ; Cc1cc2c(cc1N1c3cc4c(cc3B3Sc5cc6c(cc5-c5cc7c(oc8ccccc87)c1c53)C(C)(C)c1ccccc1-6)C(C)(C)CCC4(C)C)C(C)(C)CCC2(C)C ; Cc1cc2c(cc1N1c3cc4c(cc3B3Sc5cc6c(cc5-c5c3c1cc1c5sc3ccccc31)C(C)(C)c1ccccc1-6)C(C)(C)CCC4(C)C)C(C)(C)CCC2(C)C ; Cc1cc2c(cc1N1c3cc4c(cc3B3Sc5cc6c(cc5-c5cc7c(sc8ccccc87)c1c53)C(C)(C)c1ccccc1-6)C(C)(C)CCC4(C)C)C(C)(C)CCC2(C)C]

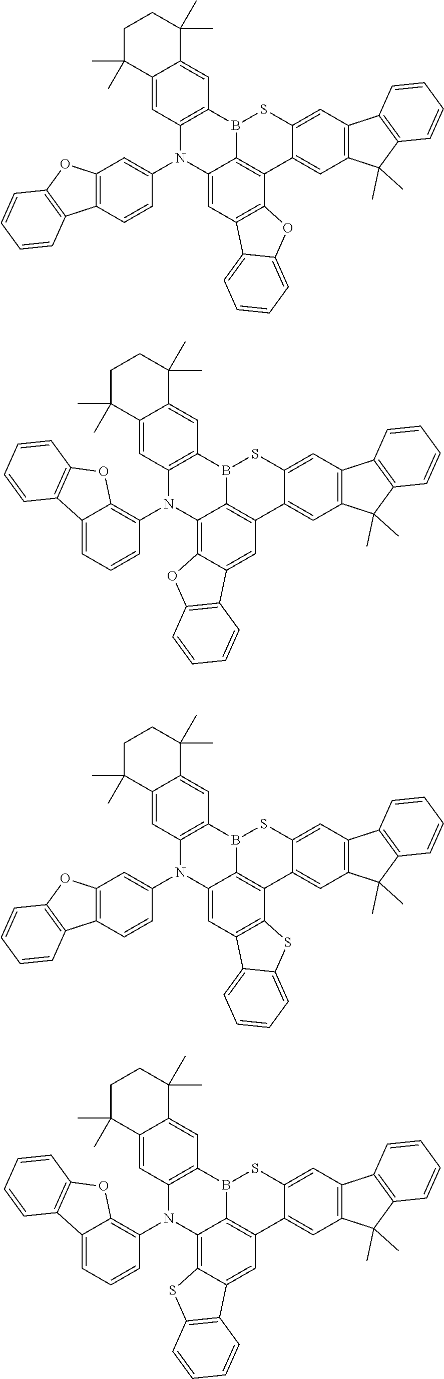 [SMILES: CC1(C)CCC(C)(C)c2cc3c(cc21)B1Sc2cc4c(cc2-c2c1c(cc1c2oc2ccccc21)N3c1ccc2c(c1)oc1ccccc12)C(C)(C)c1ccccc1-4 ; CC1(C)CCC(C)(C)c2cc3c(cc21)B1Sc2cc4c(cc2-c2cc5c(oc6ccccc65)c(c21)N3c1cccc2c1oc1ccccc12)C(C)(C)c1ccccc1-4 ; CC1(C)CCC(C)(C)c2cc3c(cc21)B1Sc2cc4c(cc2-c2c1c(cc1c2sc2ccccc21)N3c1ccc2c(c1)oc1ccccc12)C(C)(C)c1ccccc1-4 ; CC1(C)CCC(C)(C)c2cc3c(cc21)B1Sc2cc4c(cc2-c2cc5c(sc6ccccc65)c(c21)N3c1cccc2c1oc1ccccc12)C(C)(C)c1ccccc1-4]

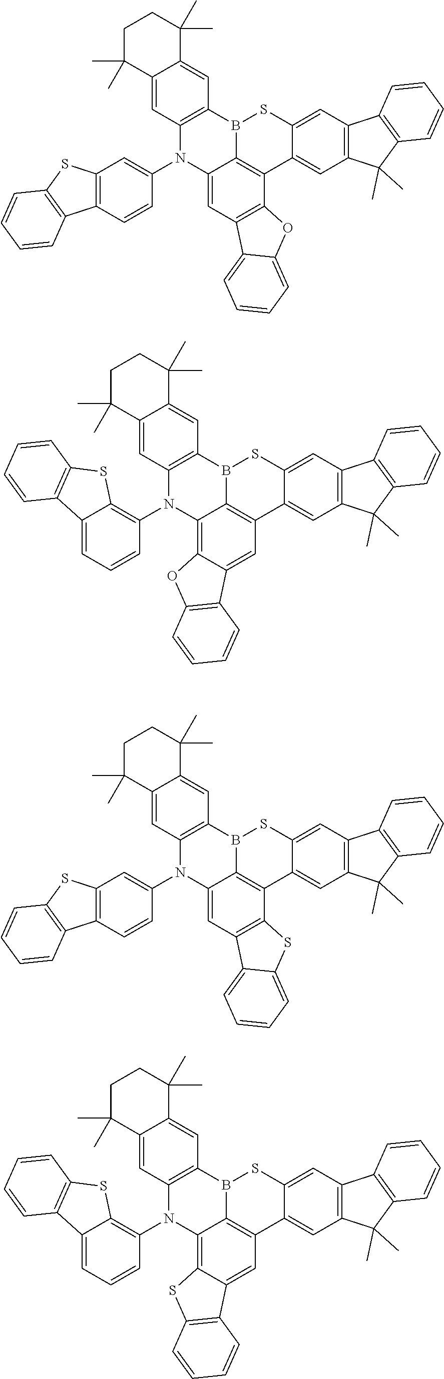 [SMILES: CC1(C)CCC(C)(C)c2cc3c(cc21)B1Sc2cc4c(cc2-c2c1c(cc1c2oc2ccccc21)N3c1ccc2c(c1)sc1ccccc12)C(C)(C)c1ccccc1-4 ; CC1(C)CCC(C)(C)c2cc3c(cc21)B1Sc2cc4c(cc2-c2cc5c(oc6ccccc65)c(c21)N3c1cccc2c1sc1ccccc12)C(C)(C)c1ccccc1-4 ; CC1(C)CCC(C)(C)c2cc3c(cc21)B1Sc2cc4c(cc2-c2c1c(cc1c2sc2ccccc21)N3c1ccc2c(c1)sc1ccccc12)C(C)(C)c1ccccc1-4 ; CC1(C)CCC(C)(C)c2cc3c(cc21)B1Sc2cc4c(cc2-c2cc5c(sc6ccccc65)c(c21)N3c1cccc2c1sc1ccccc12)C(C)(C)c1ccccc1-4]

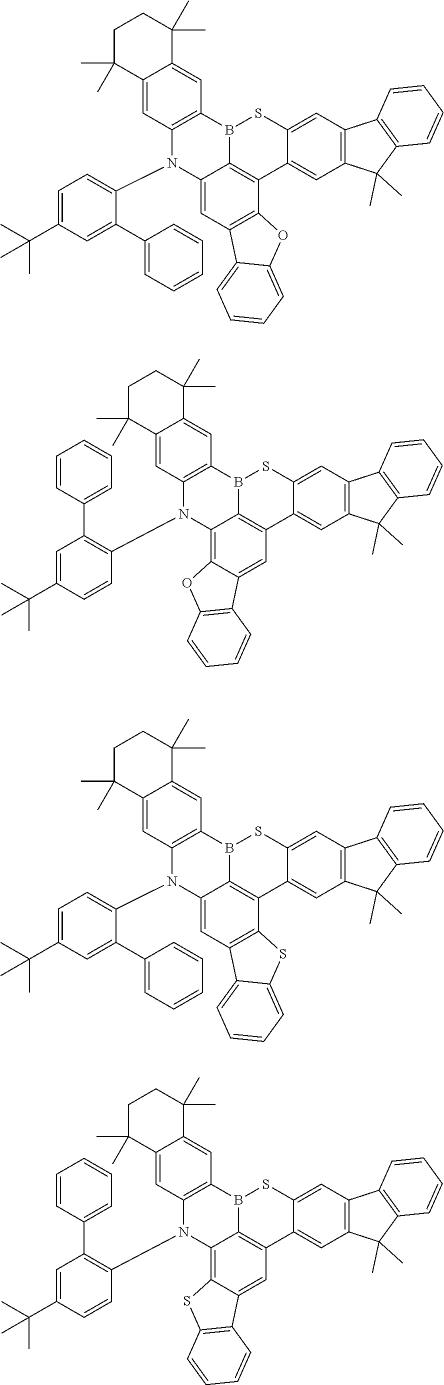 [SMILES: CC(C)(C)c1ccc(N2c3cc4c(cc3B3Sc5cc6c(cc5-c5c3c2cc2c5oc3ccccc32)C(C)(C)c2ccccc2-6)C(C)(C)CCC4(C)C)c(-c2ccccc2)c1 ; CC(C)(C)c1ccc(N2c3cc4c(cc3B3Sc5cc6c(cc5-c5cc7c(oc8ccccc87)c2c53)C(C)(C)c2ccccc2-6)C(C)(C)CCC4(C)C)c(-c2ccccc2)c1 ; CC(C)(C)c1ccc(N2c3cc4c(cc3B3Sc5cc6c(cc5-c5c3c2cc2c5sc3ccccc32)C(C)(C)c2ccccc2-6)C(C)(C)CCC4(C)C)c(-c2ccccc2)c1 ; CC(C)(C)c1ccc(N2c3cc4c(cc3B3Sc5cc6c(cc5-c5cc7c(sc8ccccc87)c2c53)C(C)(C)c2ccccc2-6)C(C)(C)CCC4(C)C)c(-c2ccccc2)c1]

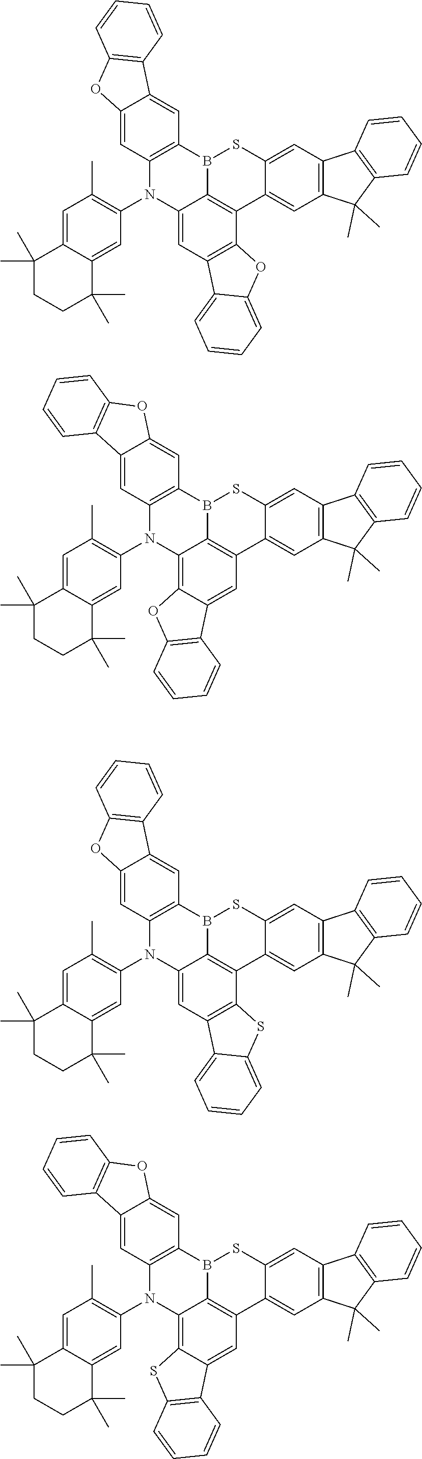 [SMILES: Cc1cc2c(cc1N1c3cc4oc5ccccc5c4cc3B3Sc4cc5c(cc4-c4c3c1cc1c4oc3ccccc31)C(C)(C)c1ccccc1-5)C(C)(C)CCC2(C)C ; Cc1cc2c(cc1N1c3cc4c(cc3B3Sc5cc6c(cc5-c5cc7c(oc8ccccc87)c1c53)C(C)(C)c1ccccc1-6)oc1ccccc14)C(C)(C)CCC2(C)C ; Cc1cc2c(cc1N1c3cc4oc5ccccc5c4cc3B3Sc4cc5c(cc4-c4c3c1cc1c4sc3ccccc31)C(C)(C)c1ccccc1-5)C(C)(C)CCC2(C)C ; Cc1cc2c(cc1N1c3cc4c(cc3B3Sc5cc6c(cc5-c5cc7c(sc8ccccc87)c1c53)C(C)(C)c1ccccc1-6)oc1ccccc14)C(C)(C)CCC2(C)C]

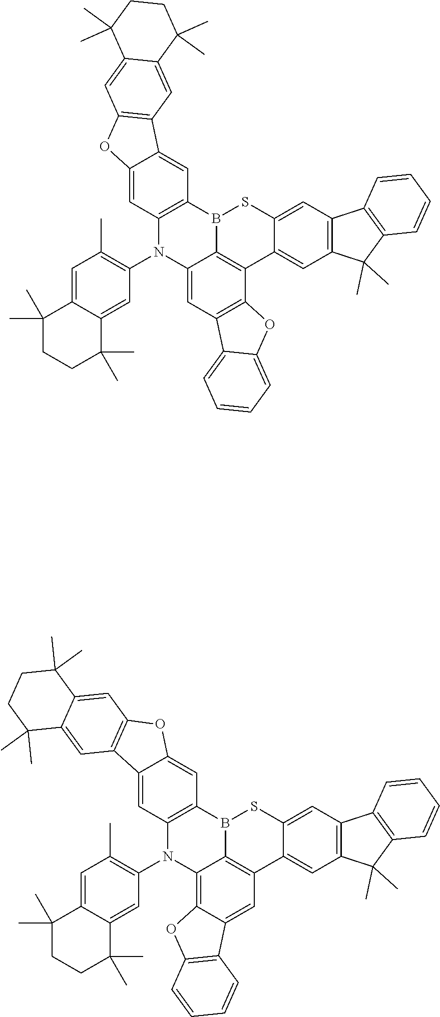 [SMILES: Cc1cc2c(cc1N1c3cc4oc5cc6c(cc5c4cc3B3Sc4cc5c(cc4-c4c3c1cc1c4oc3ccccc31)C(C)(C)c1ccccc1-5)C(C)(C)CCC6(C)C)C(C)(C)CCC2(C)C ; Cc1cc2c(cc1N1c3cc4c(cc3B3Sc5cc6c(cc5-c5cc7c(oc8ccccc87)c1c53)C(C)(C)c1ccccc1-6)oc1cc3c(cc14)C(C)(C)CCC3(C)C)C(C)(C)CCC2(C)C]

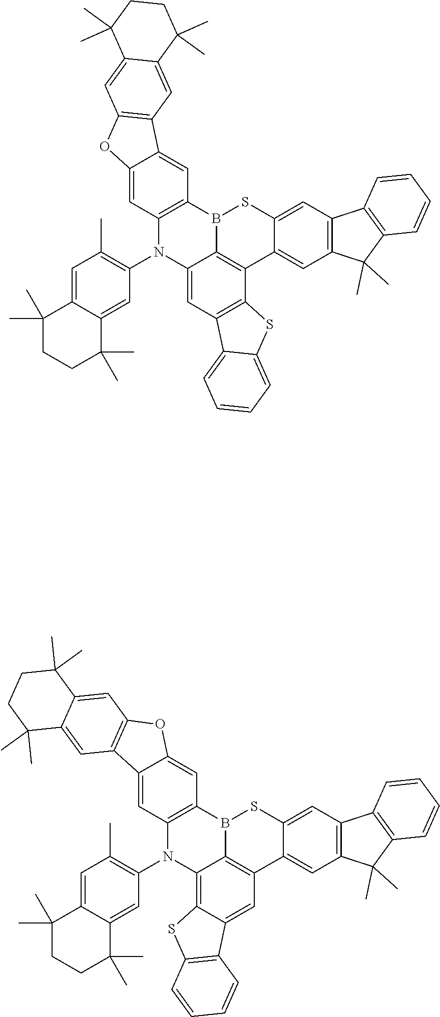 [SMILES: Cc1cc2c(cc1N1c3cc4oc5cc6c(cc5c4cc3B3Sc4cc5c(cc4-c4c3c1cc1c4sc3ccccc31)C(C)(C)c1ccccc1-5)C(C)(C)CCC6(C)C)C(C)(C)CCC2(C)C ; Cc1cc2c(cc1N1c3cc4c(cc3B3Sc5cc6c(cc5-c5cc7c(sc8ccccc87)c1c53)C(C)(C)c1ccccc1-6)oc1cc3c(cc14)C(C)(C)CCC3(C)C)C(C)(C)CCC2(C)C]

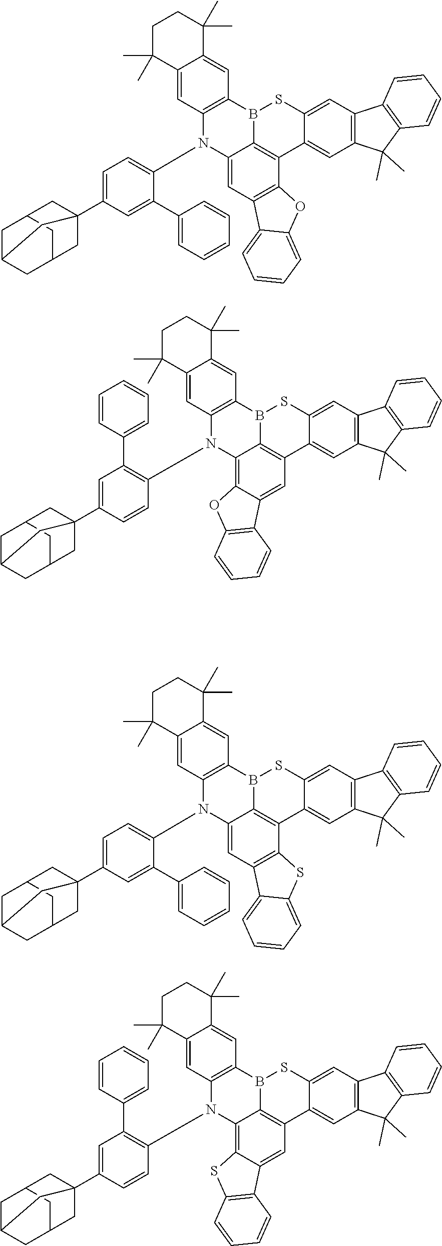

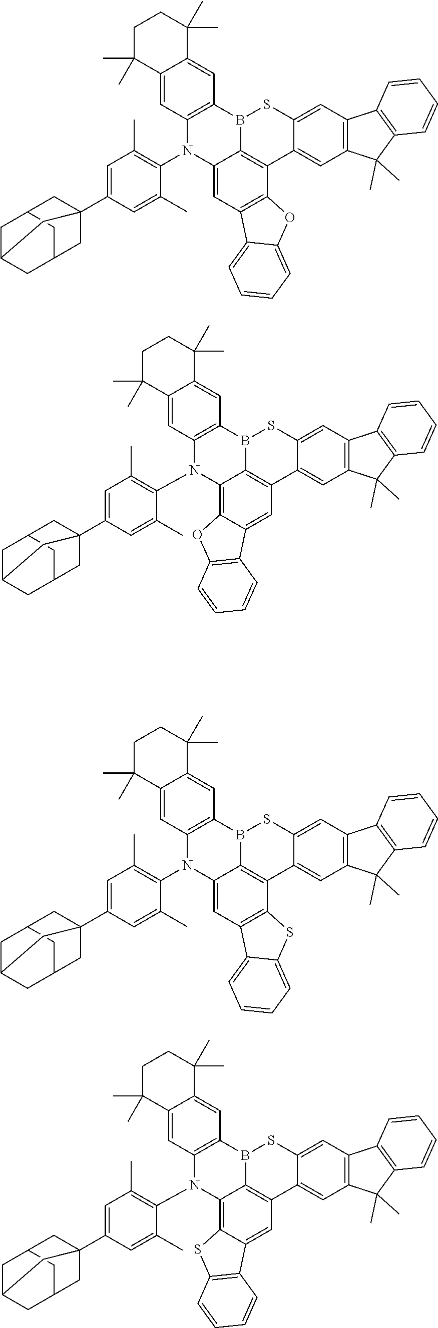 [SMILES: Cc1cc(C23CC4CC(CC(C4)C2)C3)cc(C)c1N1c2cc3c(cc2B2Sc4cc5c(cc4-c4c2c1cc1c4oc2ccccc21)C(C)(C)c1ccccc1-5)C(C)(C)CCC3(C)C ; Cc1cc(C23CC4CC(CC(C4)C2)C3)cc(C)c1N1c2cc3c(cc2B2Sc4cc5c(cc4-c4cc6c(oc7ccccc76)c1c42)C(C)(C)c1ccccc1-5)C(C)(C)CCC3(C)C ; Cc1cc(C23CC4CC(CC(C4)C2)C3)cc(C)c1N1c2cc3c(cc2B2Sc4cc5c(cc4-c4c2c1cc1c4sc2ccccc21)C(C)(C)c1ccccc1-5)C(C)(C)CCC3(C)C ; Cc1cc(C23CC4CC(CC(C4)C2)C3)cc(C)c1N1c2cc3c(cc2B2Sc4cc5c(cc4-c4cc6c(sc7ccccc76)c1c42)C(C)(C)c1ccccc1-5)C(C)(C)CCC3(C)C]

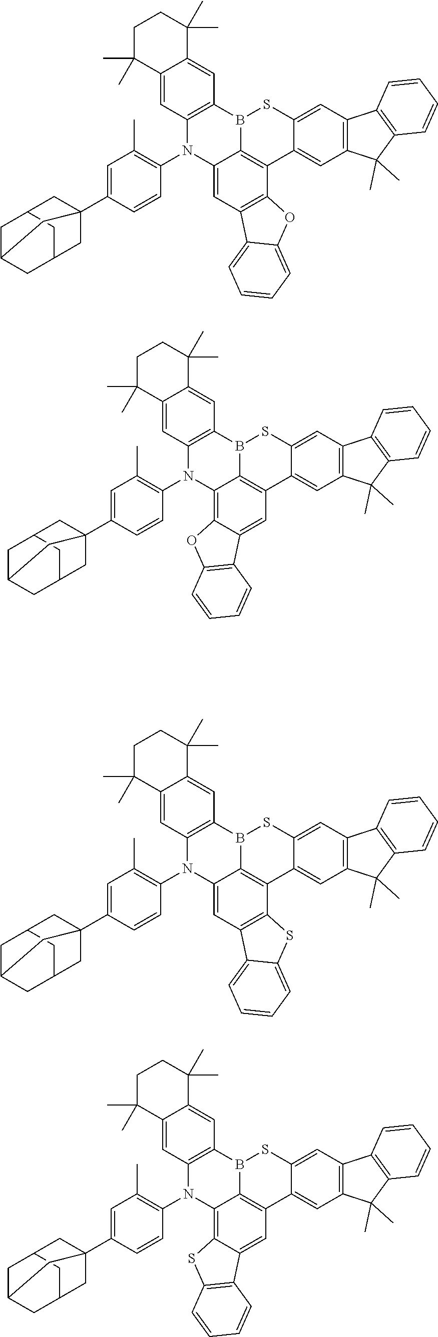 [SMILES: Cc1cc(C23CC4CC(CC(C4)C2)C3)ccc1N1c2cc3c(cc2B2Sc4cc5c(cc4-c4c2c1cc1c4oc2ccccc21)C(C)(C)c1ccccc1-5)C(C)(C)CCC3(C)C ; Cc1cc(C23CC4CC(CC(C4)C2)C3)ccc1N1c2cc3c(cc2B2Sc4cc5c(cc4-c4cc6c(oc7ccccc76)c1c42)C(C)(C)c1ccccc1-5)C(C)(C)CCC3(C)C ; Cc1cc(C23CC4CC(CC(C4)C2)C3)ccc1N1c2cc3c(cc2B2Sc4cc5c(cc4-c4c2c1cc1c4sc2ccccc21)C(C)(C)c1ccccc1-5)C(C)(C)CCC3(C)C ; Cc1cc(C23CC4CC(CC(C4)C2)C3)ccc1N1c2cc3c(cc2B2Sc4cc5c(cc4-c4cc6c(sc7ccccc76)c1c42)C(C)(C)c1ccccc1-5)C(C)(C)CCC3(C)C]

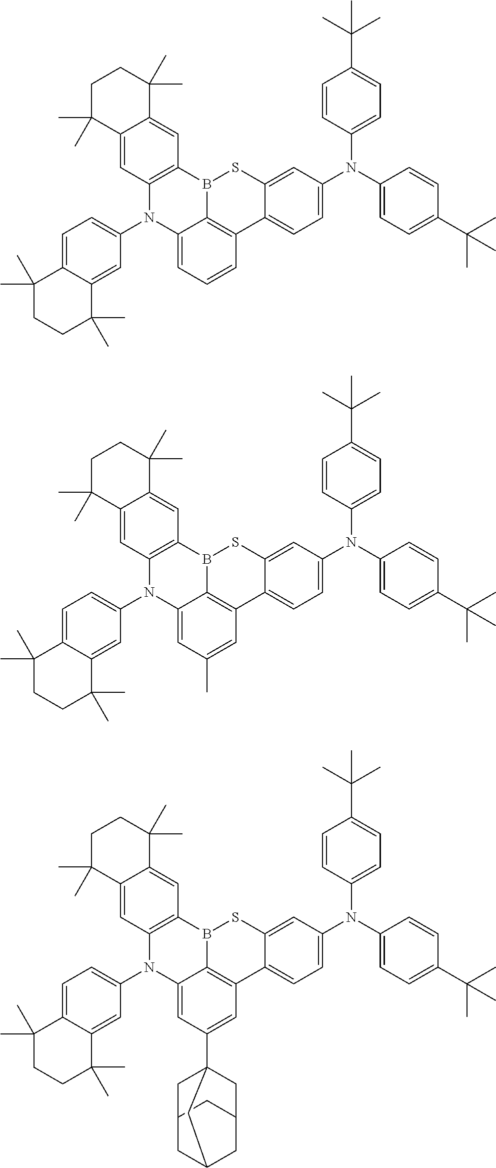

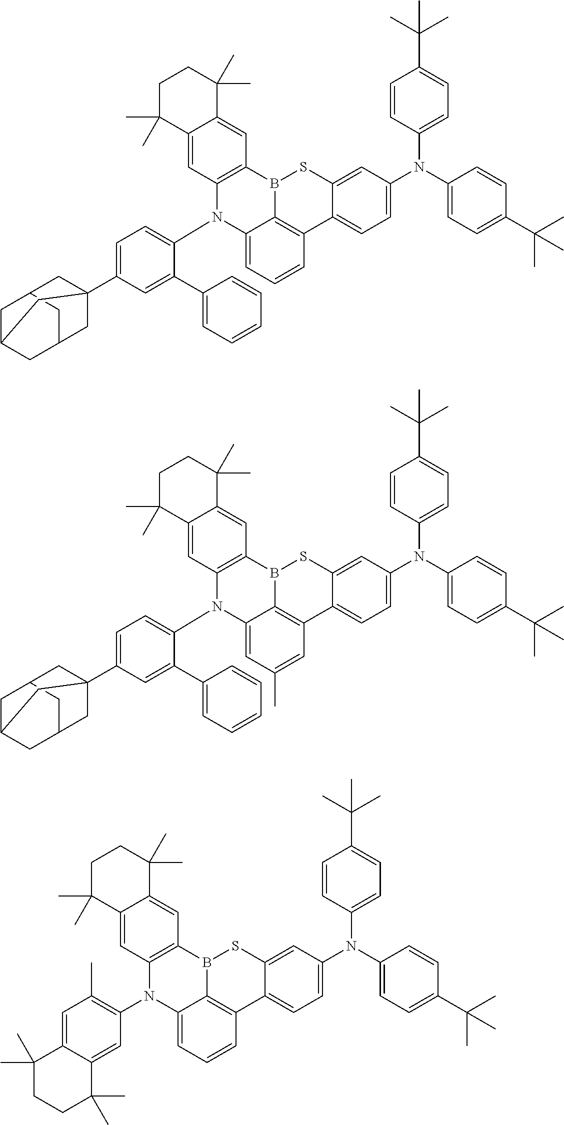

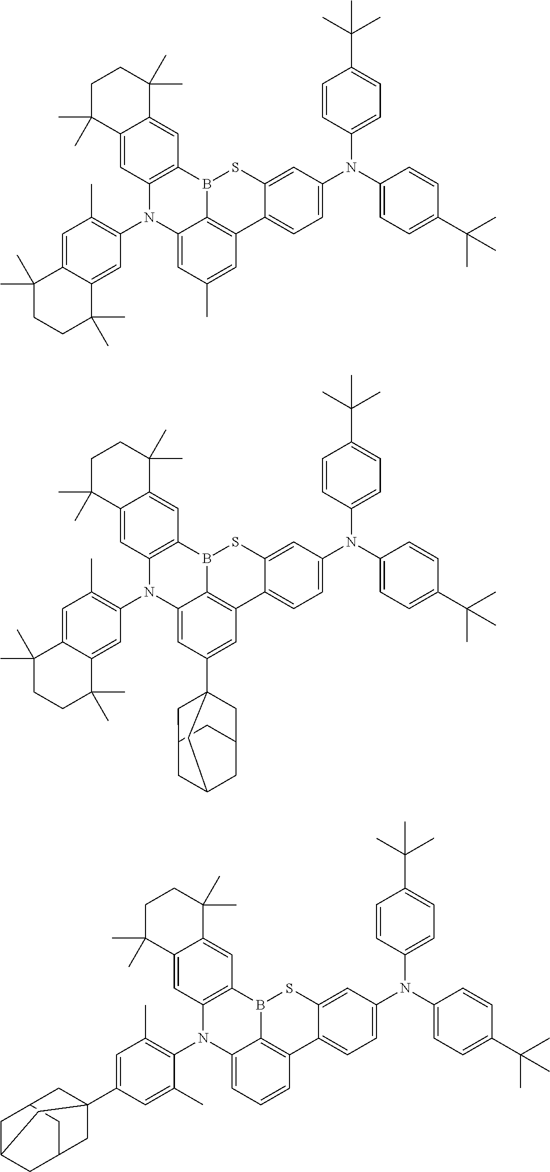

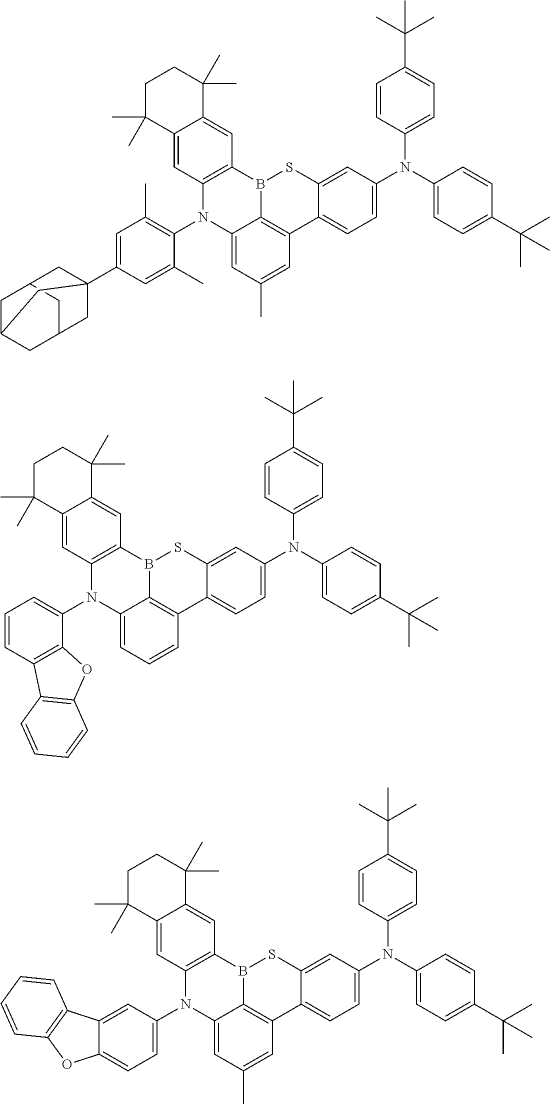

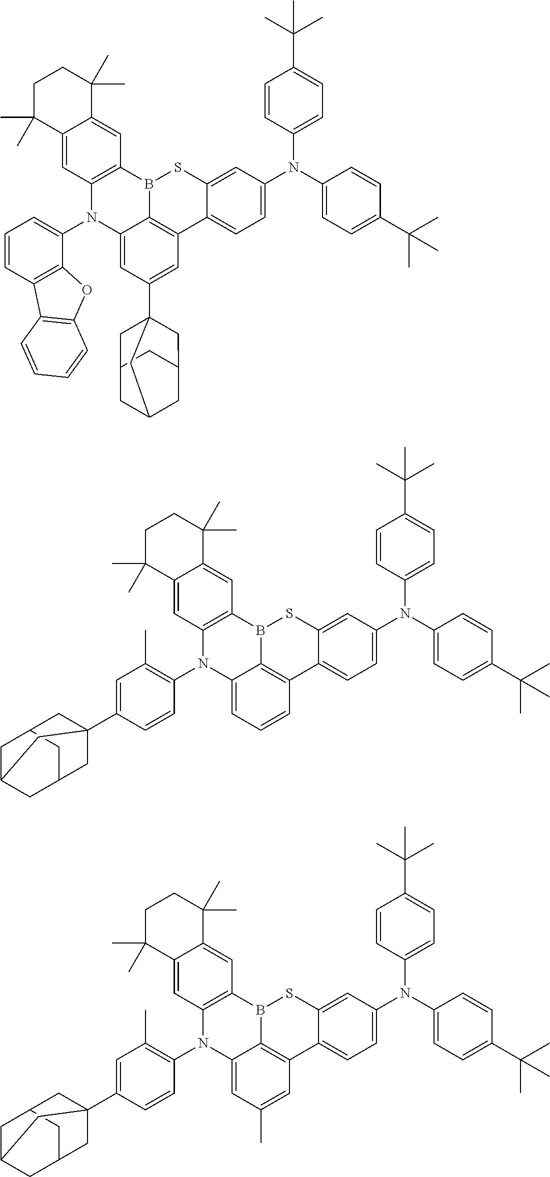 [SMILES: CC(C)(C)c1ccc(N(c2ccc(C(C)(C)C)cc2)c2ccc3c(c2)SB2c4cc5c(cc4N(c4cccc6c4oc4ccccc46)c4cc(C67CC8CC(CC(C8)C6)C7)cc-3c42)C(C)(C)CCC5(C)C)cc1 ; Cc1cc(C23CC4CC(CC(C4)C2)C3)ccc1N1c2cc3c(cc2B2Sc4cc(N(c5ccc(C(C)(C)C)cc5)c5ccc(C(C)(C)C)cc5)ccc4-c4cccc1c42)C(C)(C)CCC3(C)C ; Cc1cc2c3c(c1)N(c1ccc(C45CC6CC(CC(C6)C4)C5)cc1C)c1cc4c(cc1B3Sc1cc(N(c3ccc(C(C)(C)C)cc3)c3ccc(C(C)(C)C)cc3)ccc1-2)C(C)(C)CCC4(C)C]

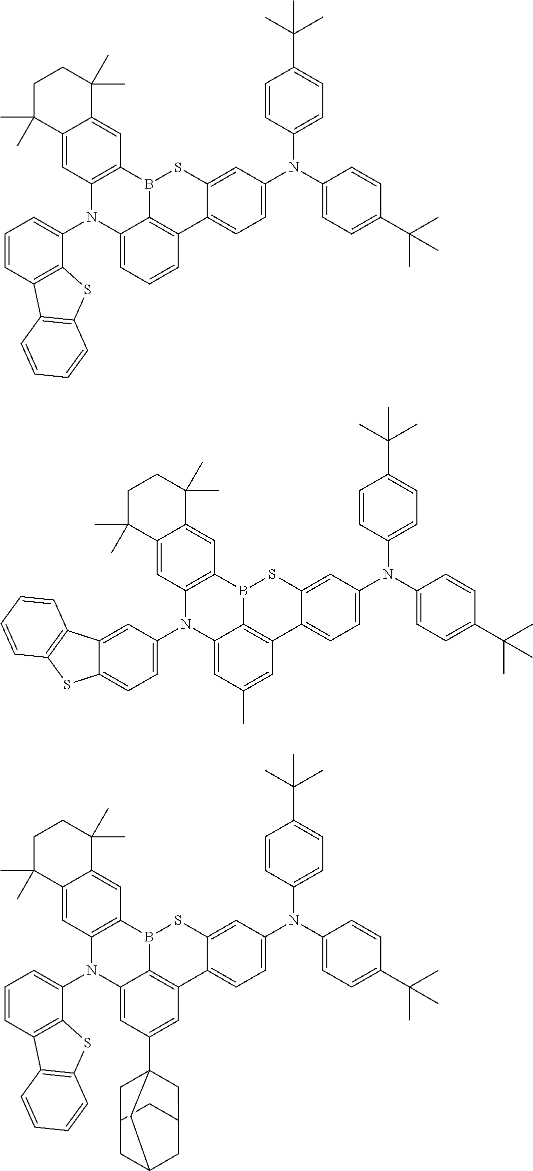

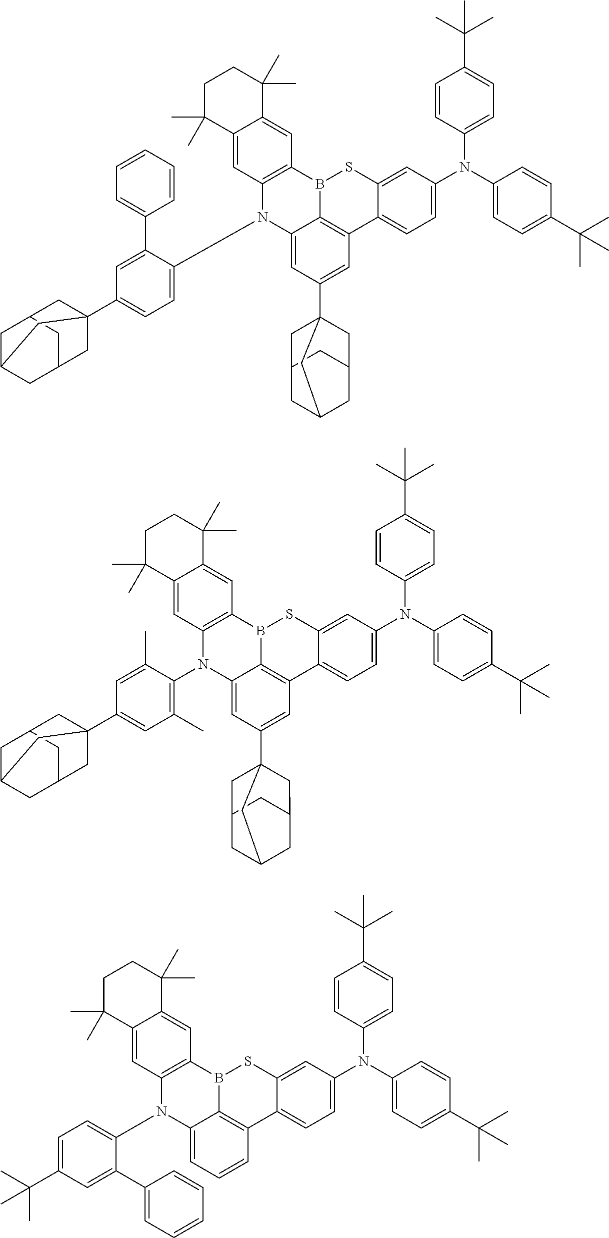

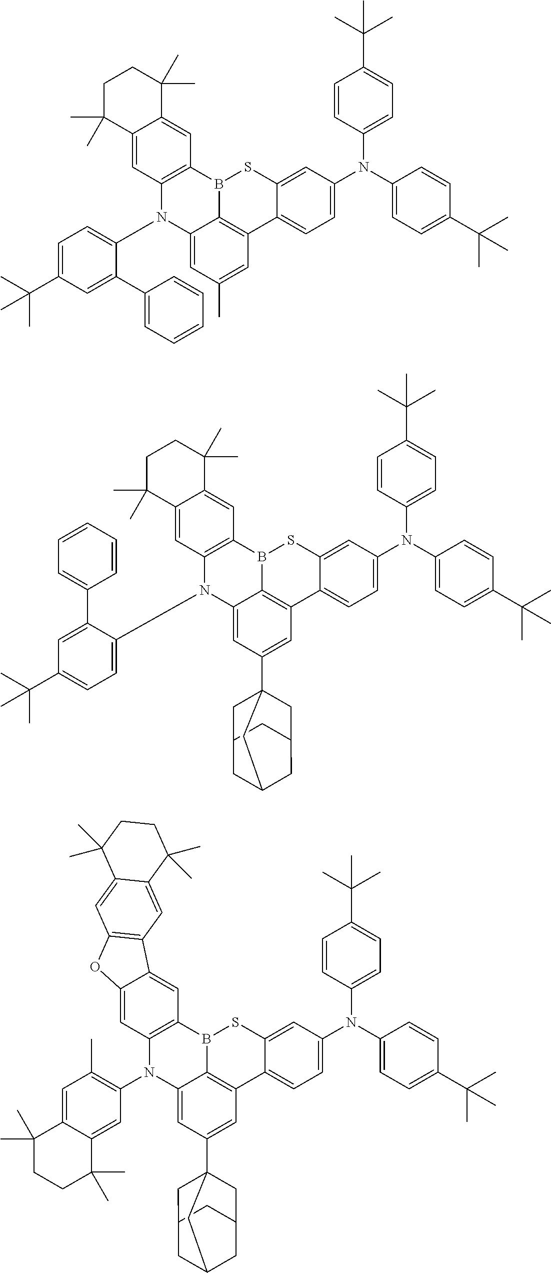

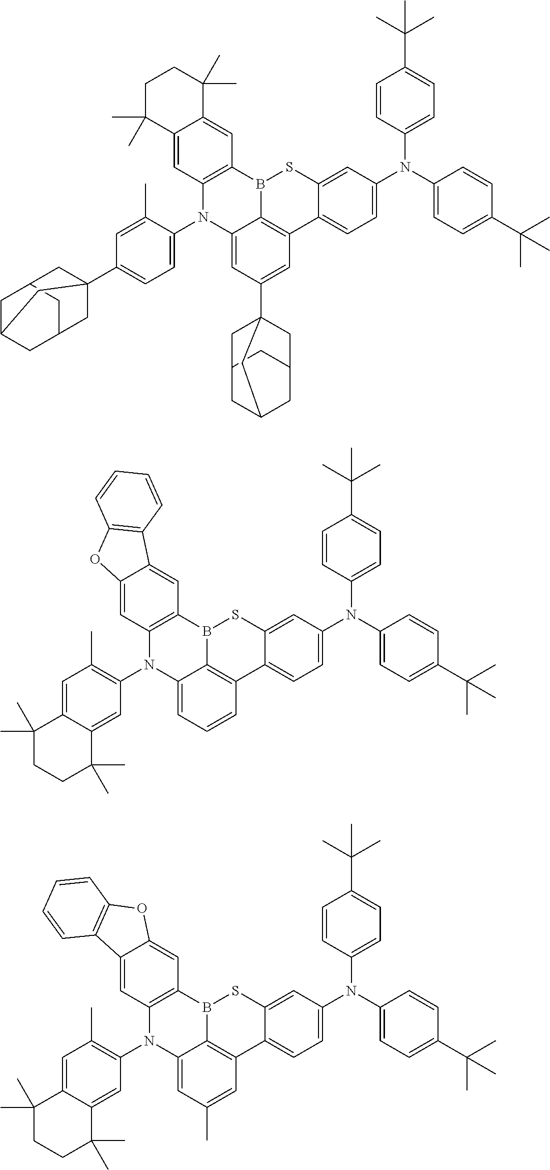

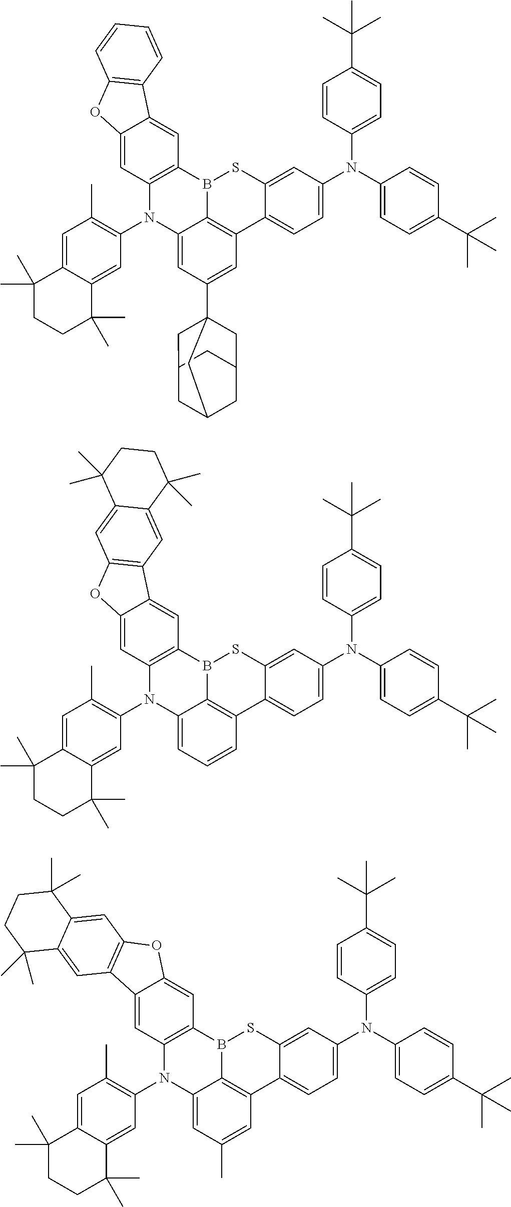

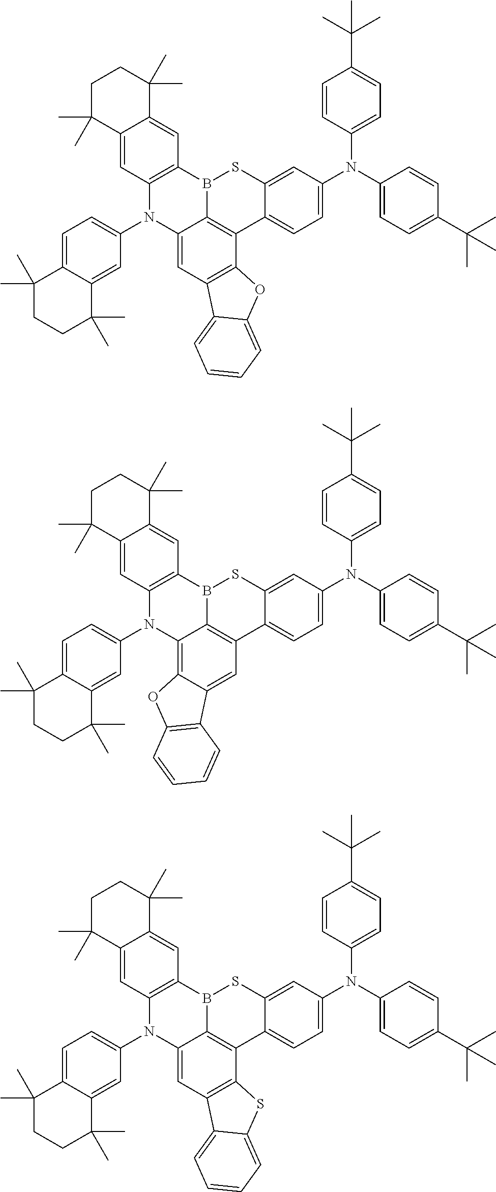

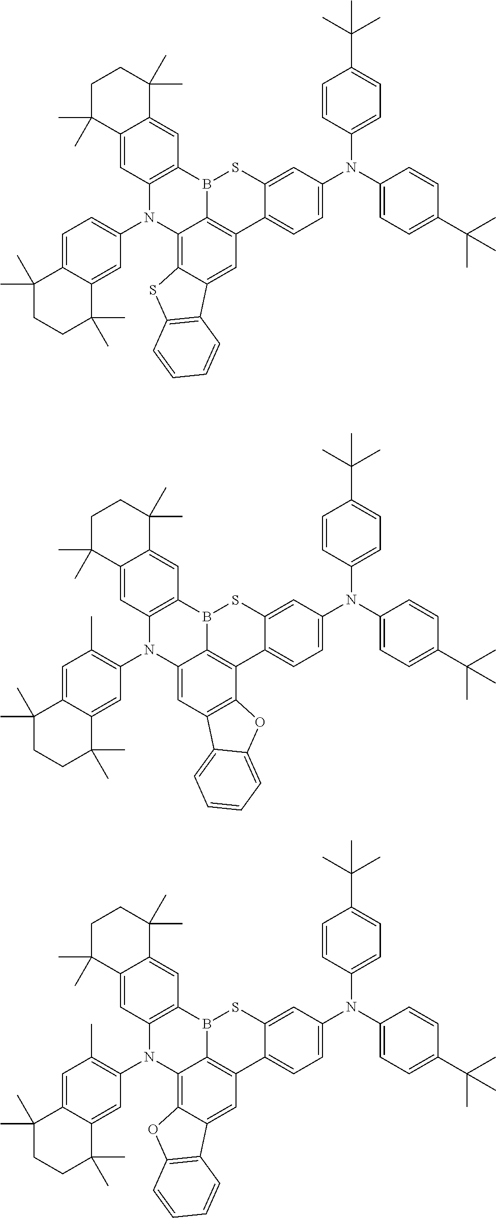

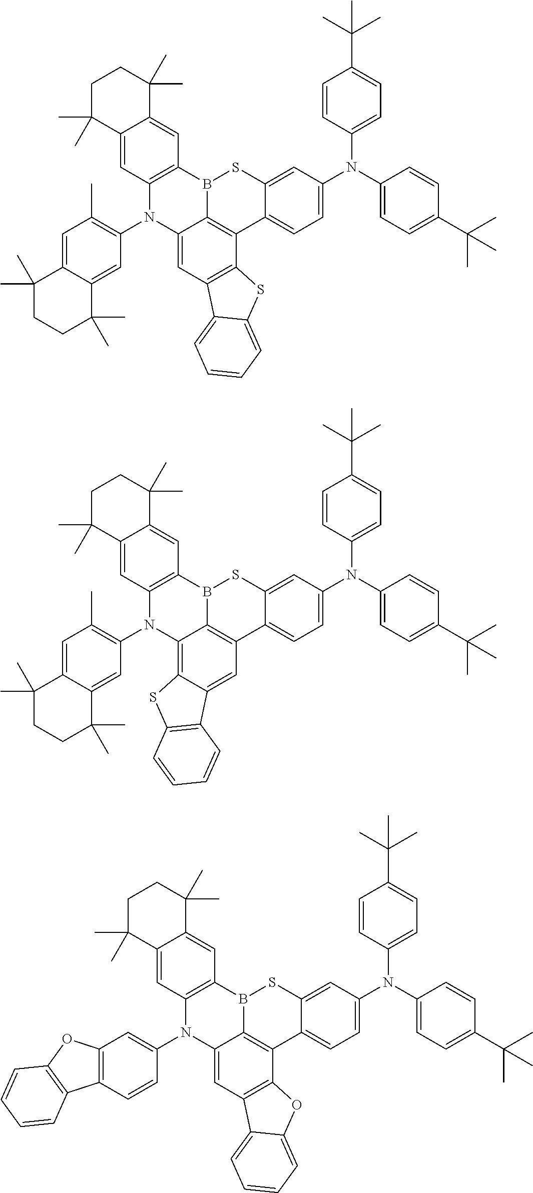

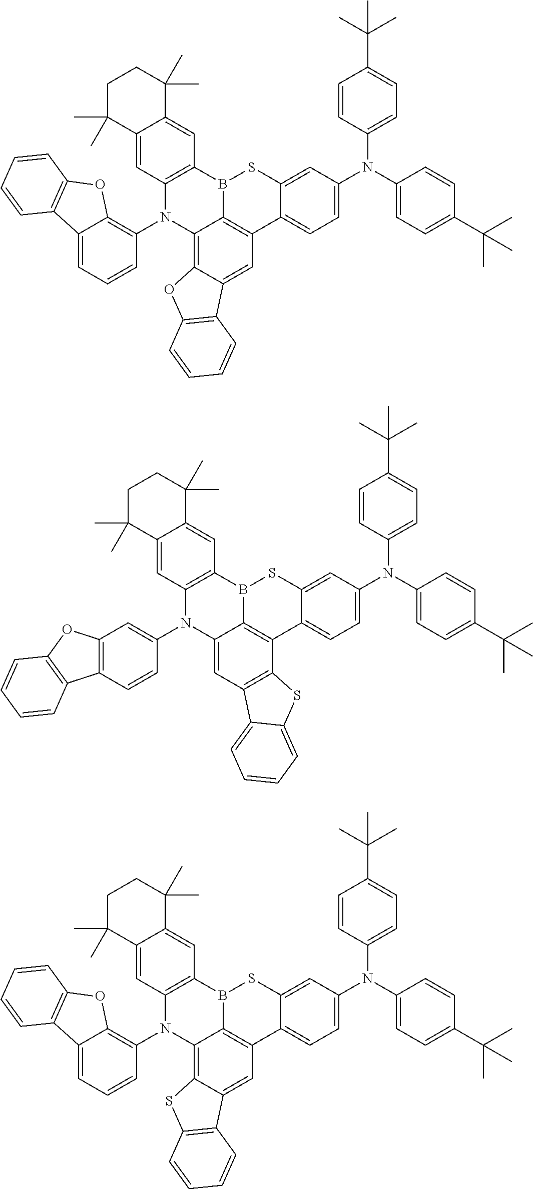 [SMILES: CC(C)(C)c1ccc(N(c2ccc(C(C)(C)C)cc2)c2ccc3c(c2)SB2c4cc5c(cc4N(c4cccc6c4oc4ccccc46)c4c2c-3cc2c4oc3ccccc32)C(C)(C)CCC5(C)C)cc1 ; CC(C)(C)c1ccc(N(c2ccc(C(C)(C)C)cc2)c2ccc3c(c2)SB2c4cc5c(cc4N(c4ccc6c(c4)oc4ccccc46)c4cc6c(sc7ccccc76)c-3c42)C(C)(C)CCC5(C)C)cc1 ; CC(C)(C)c1ccc(N(c2ccc(C(C)(C)C)cc2)c2ccc3c(c2)SB2c4cc5c(cc4N(c4cccc6c4oc4ccccc46)c4c2c-3cc2c4sc3ccccc32)C(C)(C)CCC5(C)C)cc1]

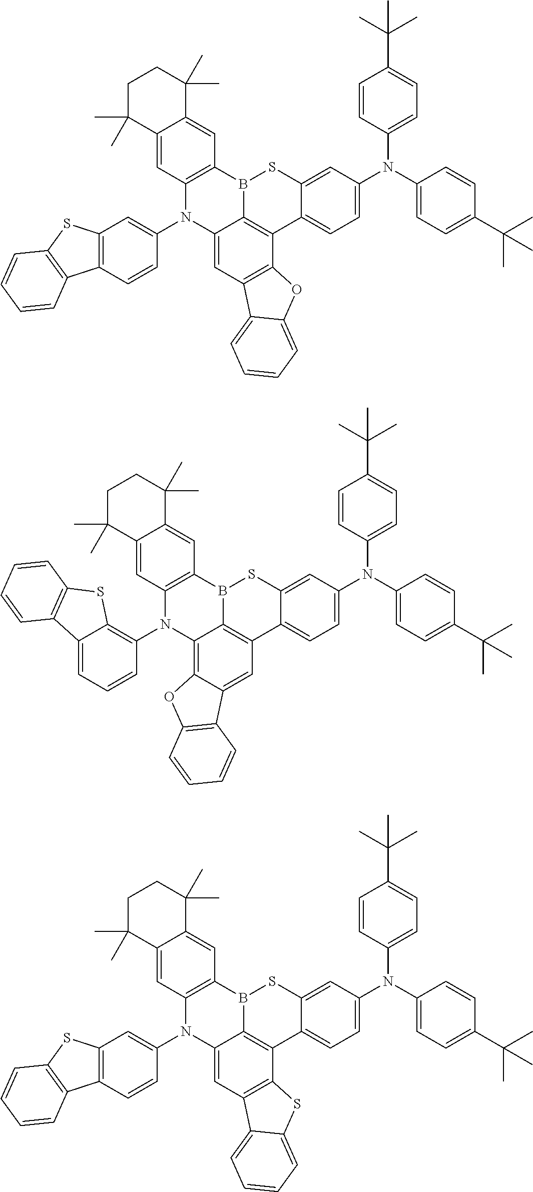 [SMILES: CC(C)(C)c1ccc(N(c2ccc(C(C)(C)C)cc2)c2ccc3c(c2)SB2c4cc5c(cc4N(c4ccc6c(c4)sc4ccccc46)c4cc6c(oc7ccccc76)c-3c42)C(C)(C)CCC5(C)C)cc1 ; CC(C)(C)c1ccc(N(c2ccc(C(C)(C)C)cc2)c2ccc3c(c2)SB2c4cc5c(cc4N(c4cccc6c4sc4ccccc46)c4c2c-3cc2c4oc3ccccc32)C(C)(C)CCC5(C)C)cc1 ; CC(C)(C)c1ccc(N(c2ccc(C(C)(C)C)cc2)c2ccc3c(c2)SB2c4cc5c(cc4N(c4ccc6c(c4)sc4ccccc46)c4cc6c(sc7ccccc76)c-3c42)C(C)(C)CCC5(C)C)cc1]

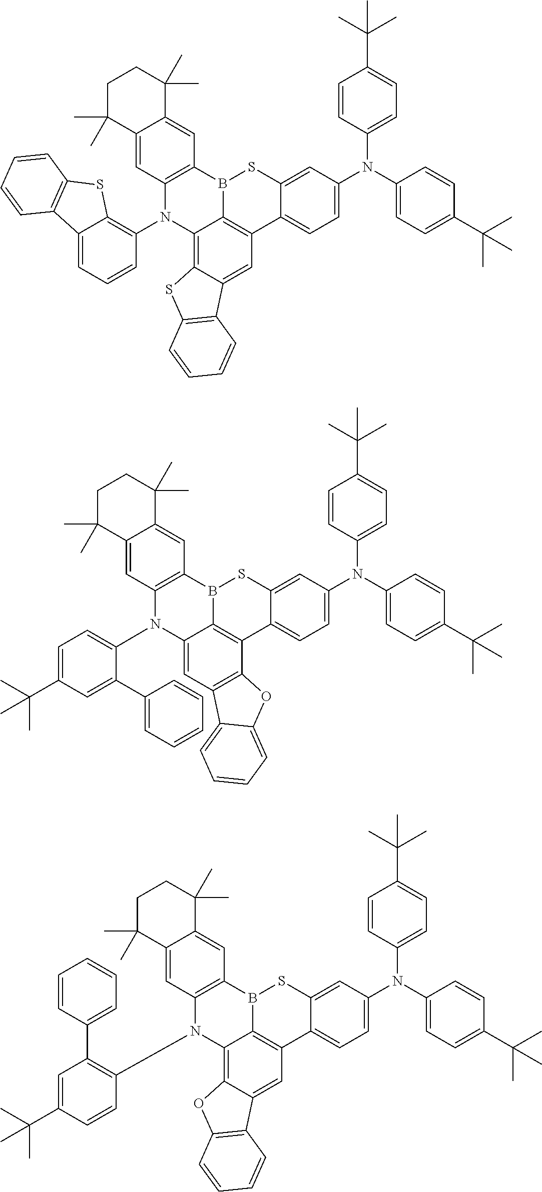

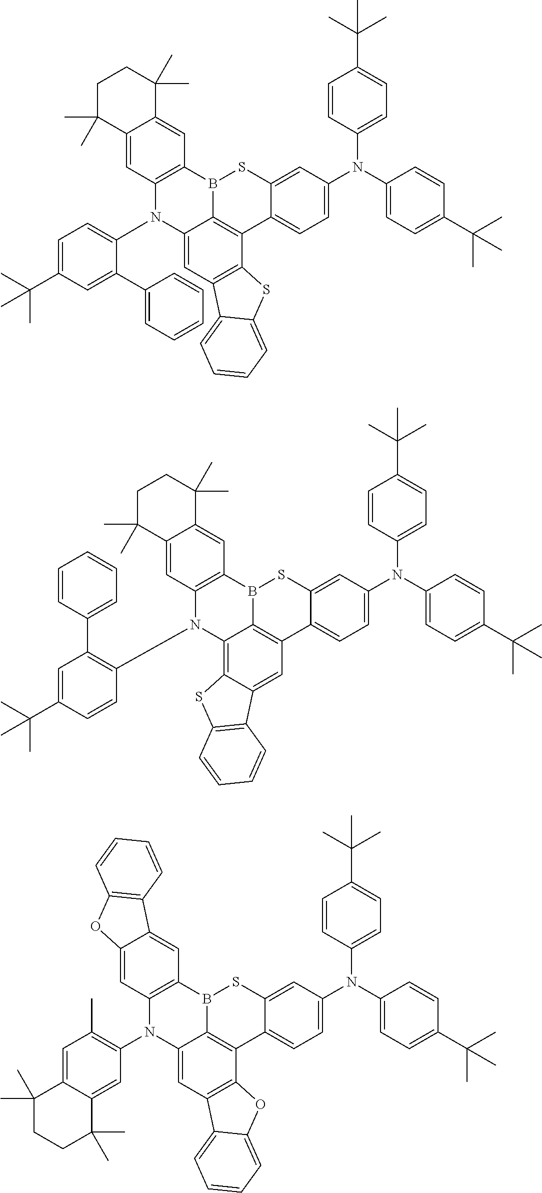

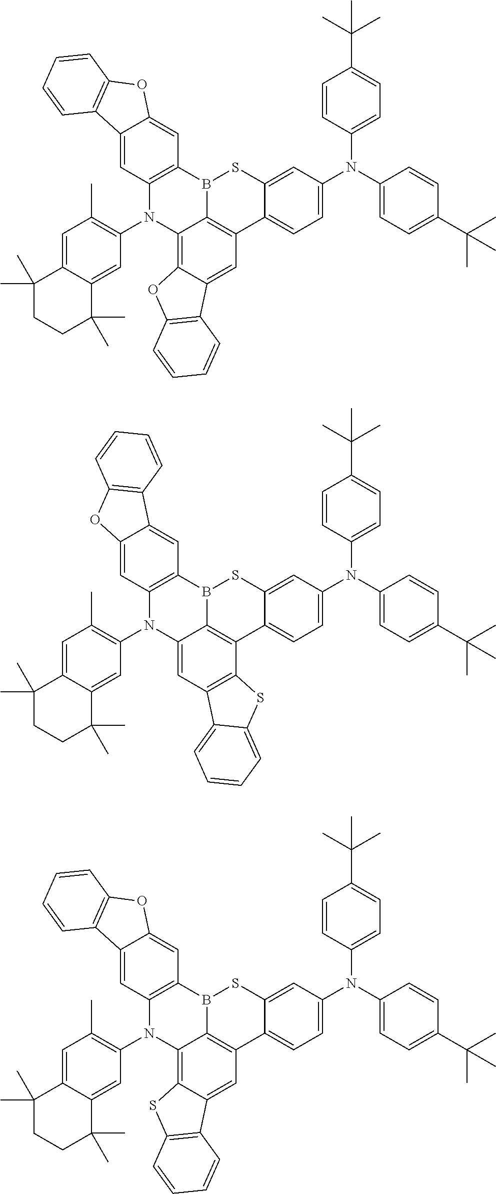

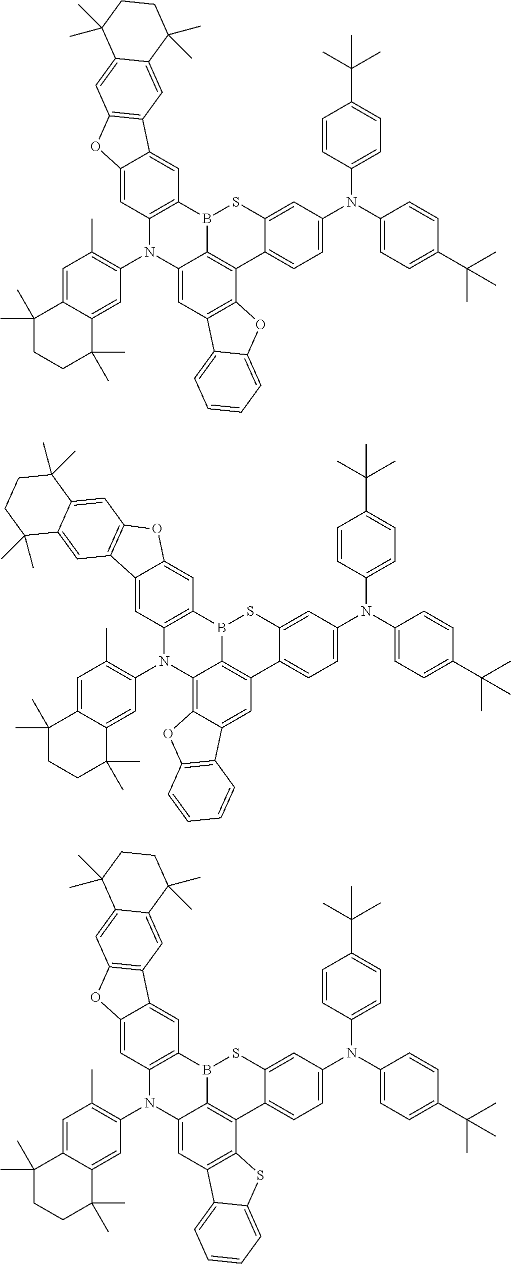

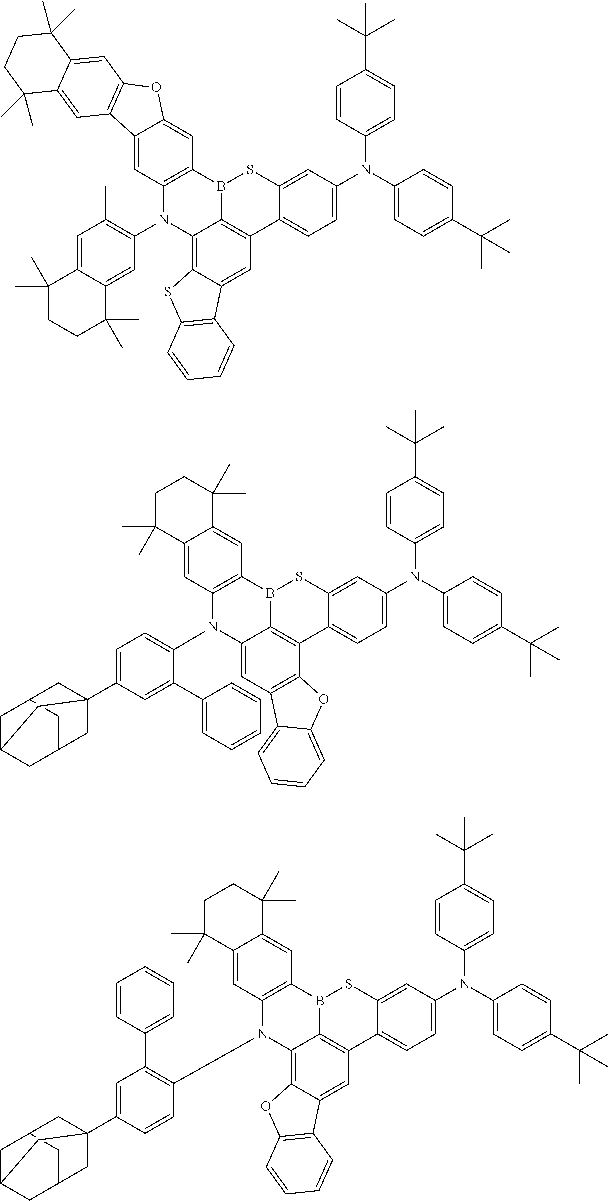 [SMILES: Cc1cc2c(cc1N1c3cc4c(cc3B3Sc5cc(N(c6ccc(C(C)(C)C)cc6)c6ccc(C(C)(C)C)cc6)ccc5-c5cc6c(sc7ccccc76)c1c53)oc1cc3c(cc14)C(C)(C)CCC3(C)C)C(C)(C)CCC2(C)C ; CC(C)(C)c1ccc(N(c2ccc(C(C)(C)C)cc2)c2ccc3c(c2)SB2c4cc5c(cc4N(c4ccc(C67CC8CC(CC(C8)C6)C7)cc4-c4ccccc4)c4cc6c(oc7ccccc76)c-3c42)C(C)(C)CCC5(C)C)cc1 ; CC(C)(C)c1ccc(N(c2ccc(C(C)(C)C)cc2)c2ccc3c(c2)SB2c4cc5c(cc4N(c4ccc(C67CC8CC(CC(C8)C6)C7)cc4-c4ccccc4)c4c2c-3cc2c4oc3ccccc32)C(C)(C)CCC5(C)C)cc1]

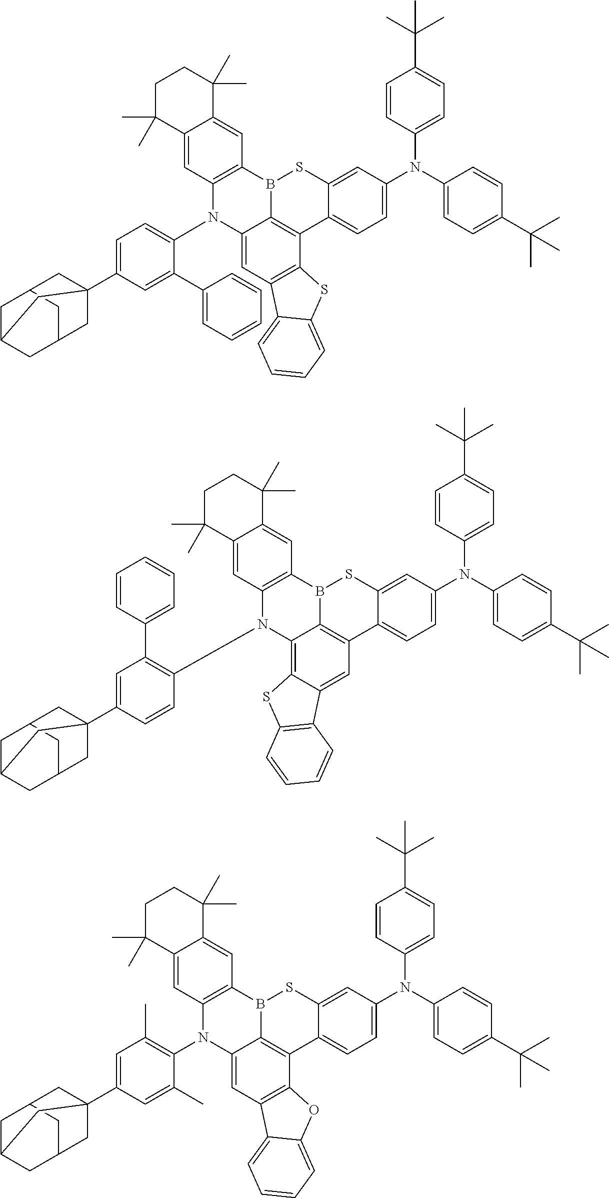 [SMILES: CC(C)(C)c1ccc(N(c2ccc(C(C)(C)C)cc2)c2ccc3c(c2)SB2c4cc5c(cc4N(c4ccc(C67CC8CC(CC(C8)C6)C7)cc4-c4ccccc4)c4cc6c(sc7ccccc76)c-3c42)C(C)(C)CCC5(C)C)cc1 ; CC(C)(C)c1ccc(N(c2ccc(C(C)(C)C)cc2)c2ccc3c(c2)SB2c4cc5c(cc4N(c4ccc(C67CC8CC(CC(C8)C6)C7)cc4-c4ccccc4)c4c2c-3cc2c4sc3ccccc32)C(C)(C)CCC5(C)C)cc1 ; Cc1cc(C23CC4CC(CC(C4)C2)C3)cc(C)c1N1c2cc3c(cc2B2Sc4cc(N(c5ccc(C(C)(C)C)cc5)c5ccc(C(C)(C)C)cc5)ccc4-c4c2c1cc1c4oc2ccccc21)C(C)(C)CCC3(C)C]

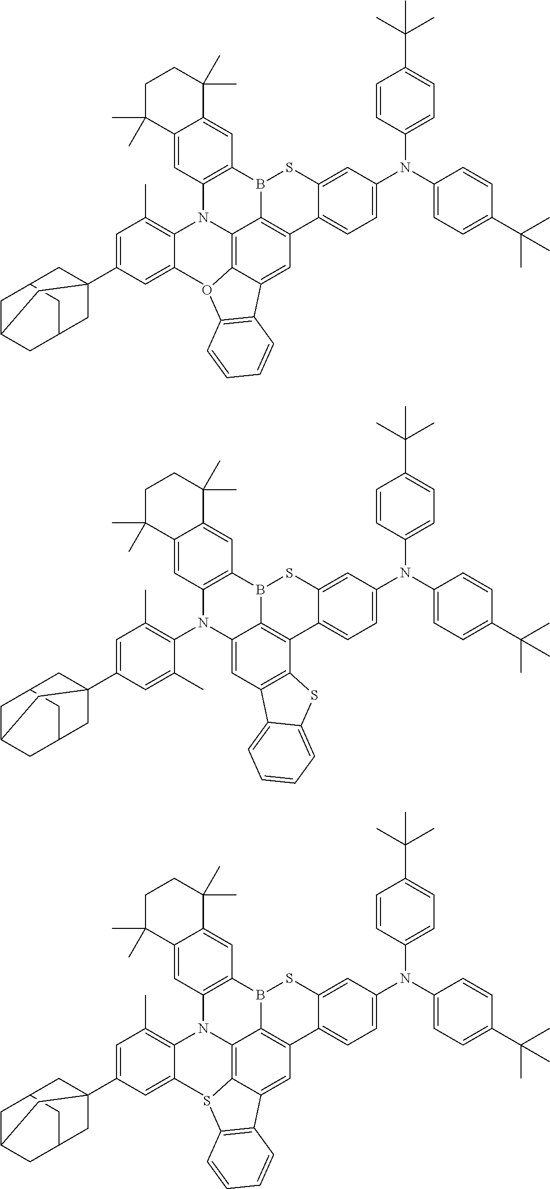 [SMILES: Cc1cc(C23CC4CC(CC(C4)C2)C3)cc(C)c1N1c2cc3c(cc2B2Sc4cc(N(c5ccc(C(C)(C)C)cc5)c5ccc(C(C)(C)C)cc5)ccc4-c4cc5c(oc6ccccc65)c1c42)C(C)(C)CCC3(C)C ; Cc1cc(C23CC4CC(CC(C4)C2)C3)cc(C)c1N1c2cc3c(cc2B2Sc4cc(N(c5ccc(C(C)(C)C)cc5)c5ccc(C(C)(C)C)cc5)ccc4-c4c2c1cc1c4sc2ccccc21)C(C)(C)CCC3(C)C ; Cc1cc(C23CC4CC(CC(C4)C2)C3)cc(C)c1N1c2cc3c(cc2B2Sc4cc(N(c5ccc(C(C)(C)C)cc5)c5ccc(C(C)(C)C)cc5)ccc4-c4cc5c(sc6ccccc65)c1c42)C(C)(C)CCC3(C)C]

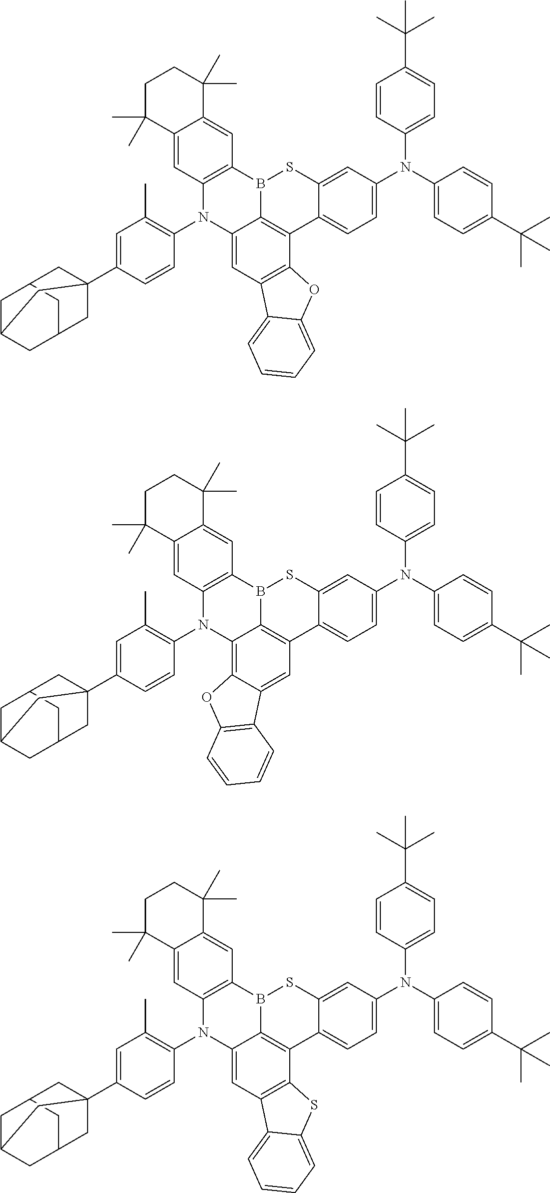 [SMILES: Cc1cc(C23CC4CC(CC(C4)C2)C3)ccc1N1c2cc3c(cc2B2Sc4cc(N(c5ccc(C(C)(C)C)cc5)c5ccc(C(C)(C)C)cc5)ccc4-c4c2c1cc1c4oc2ccccc21)C(C)(C)CCC3(C)C ; Cc1cc(C23CC4CC(CC(C4)C2)C3)ccc1N1c2cc3c(cc2B2Sc4cc(N(c5ccc(C(C)(C)C)cc5)c5ccc(C(C)(C)C)cc5)ccc4-c4cc5c(oc6ccccc65)c1c42)C(C)(C)CCC3(C)C ; Cc1cc(C23CC4CC(CC(C4)C2)C3)ccc1N1c2cc3c(cc2B2Sc4cc(N(c5ccc(C(C)(C)C)cc5)c5ccc(C(C)(C)C)cc5)ccc4-c4c2c1cc1c4sc2ccccc21)C(C)(C)CCC3(C)C]

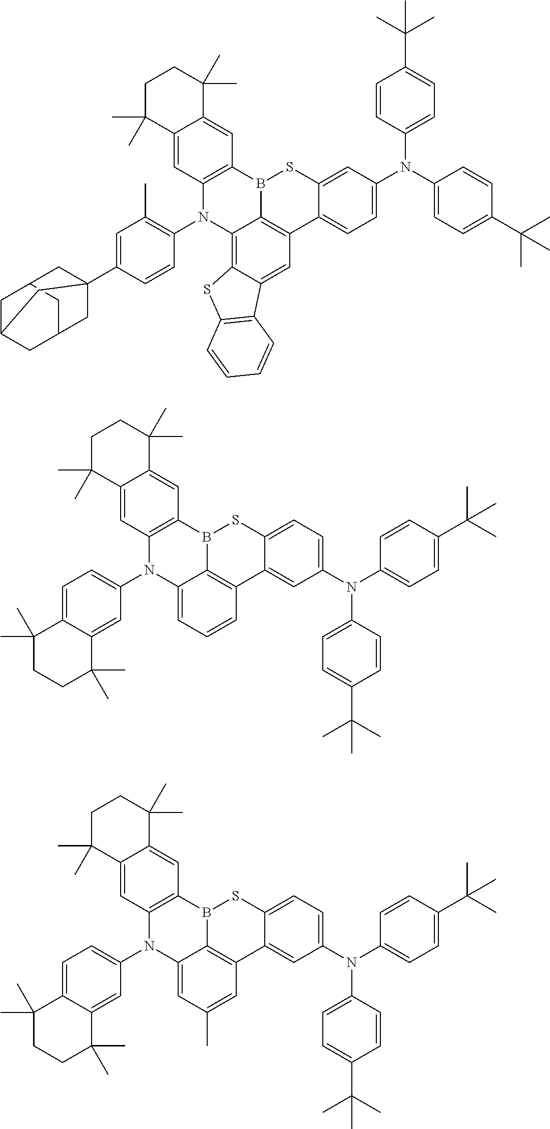

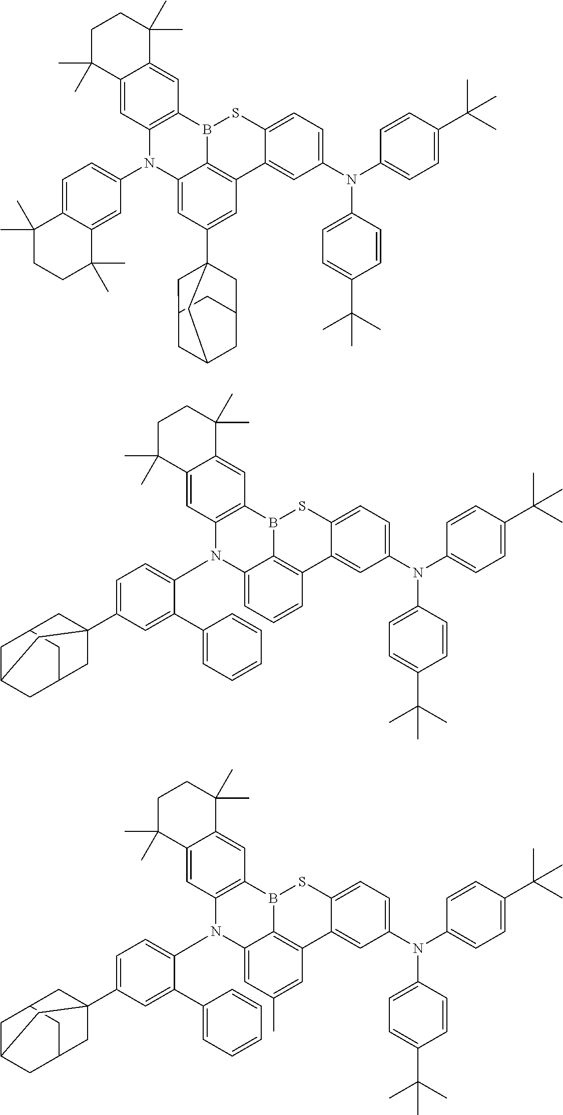

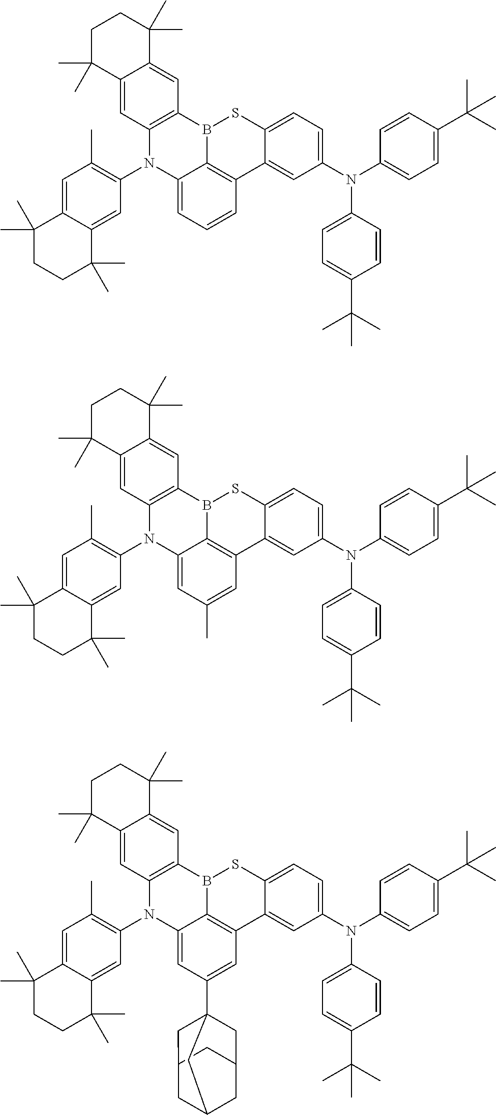

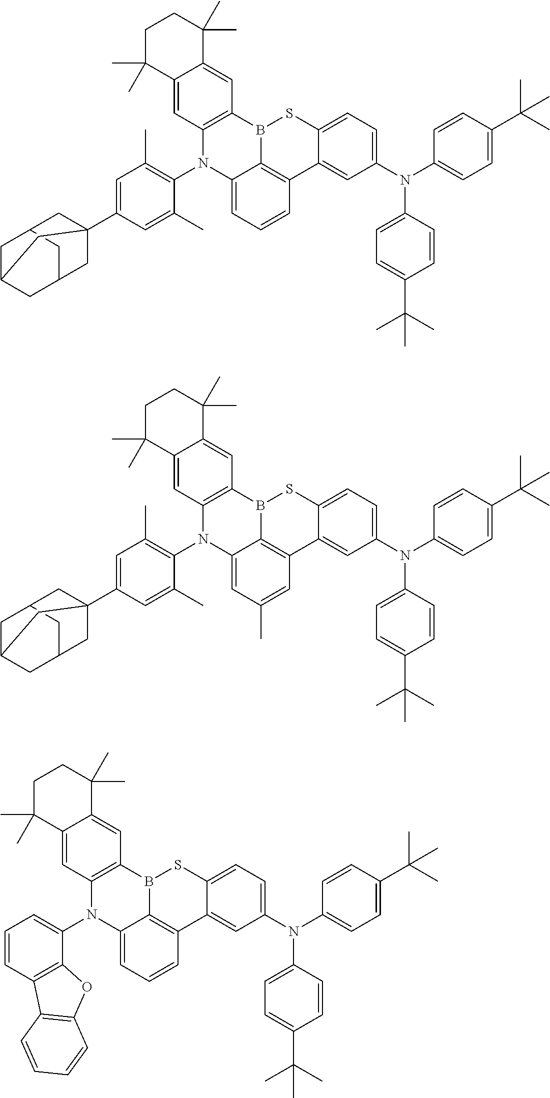

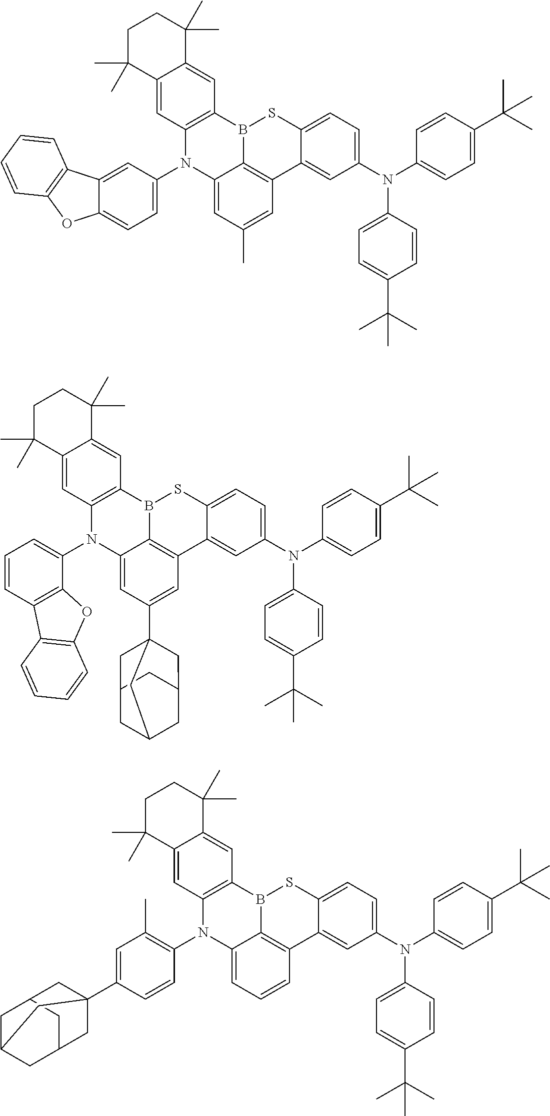

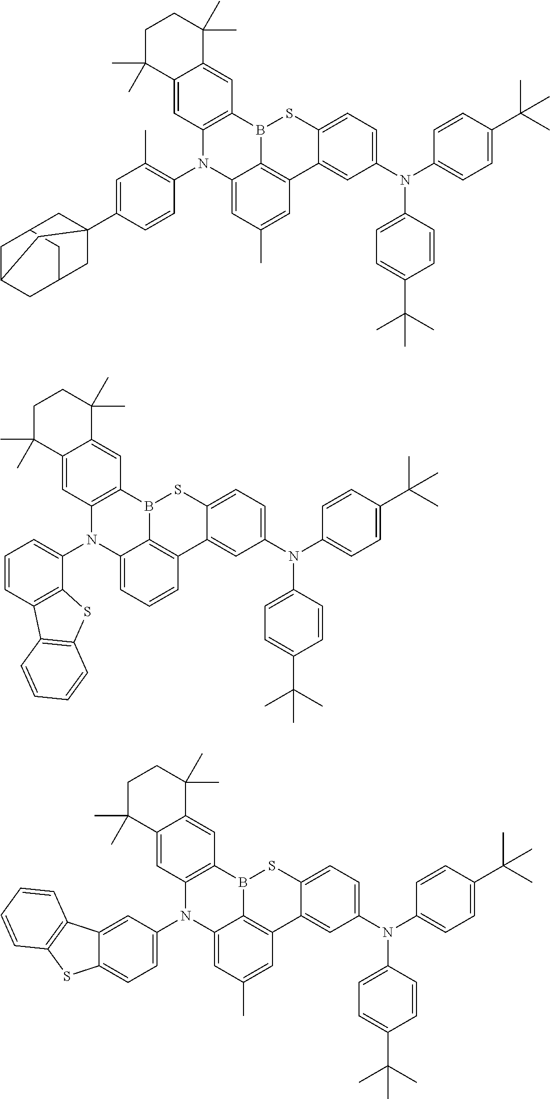

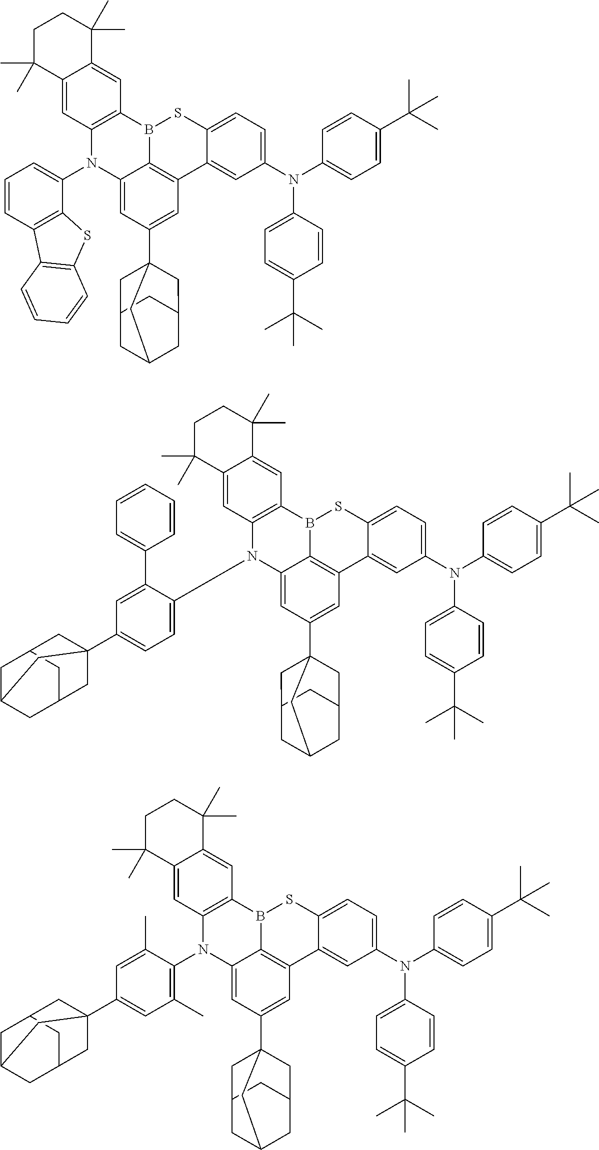 [SMILES: CC(C)(C)c1ccc(N(c2ccc(C(C)(C)C)cc2)c2ccc3c(c2)-c2cc(C45CC6CC(CC(C6)C4)C5)cc4c2B(S3)c2cc3c(cc2N4c2cccc4c2sc2ccccc24)C(C)(C)CCC3(C)C)cc1 ; CC(C)(C)c1ccc(N(c2ccc(C(C)(C)C)cc2)c2ccc3c(c2)-c2cc(C45CC6CC(CC(C6)C4)C5)cc4c2B(S3)c2cc3c(cc2N4c2ccc(C45CC6CC(CC(C6)C4)C5)cc2-c2ccccc2)C(C)(C)CCC3(C)C)cc1 ; Cc1cc(C23CC4CC(CC(C4)C2)C3)cc(C)c1N1c2cc3c(cc2B2Sc4ccc(N(c5ccc(C(C)(C)C)cc5)c5ccc(C(C)(C)C)cc5)cc4-c4cc(C56CC7CC(CC(C7)C5)C6)cc1c42)C(C)(C)CCC3(C)C]

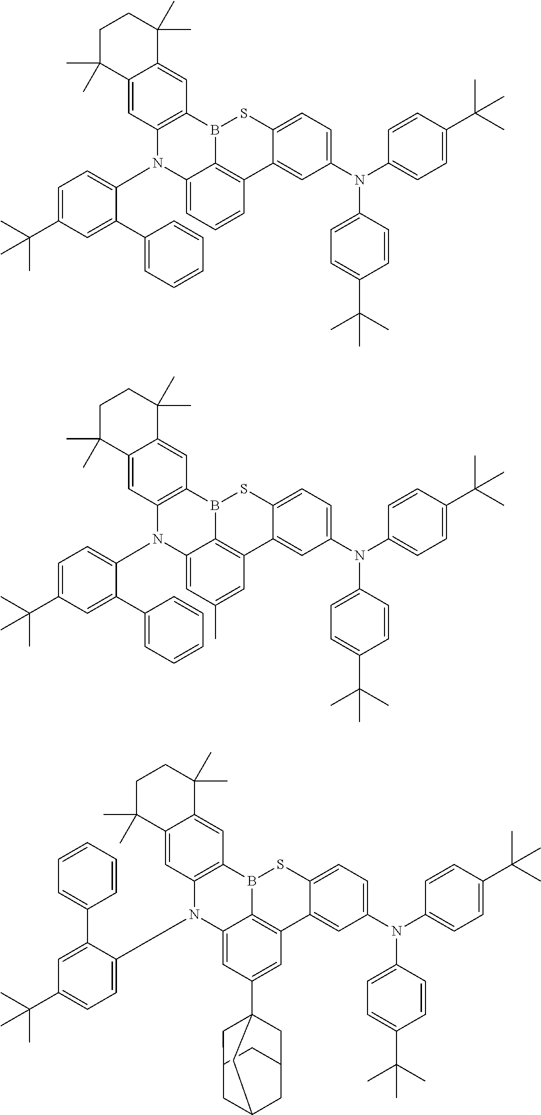

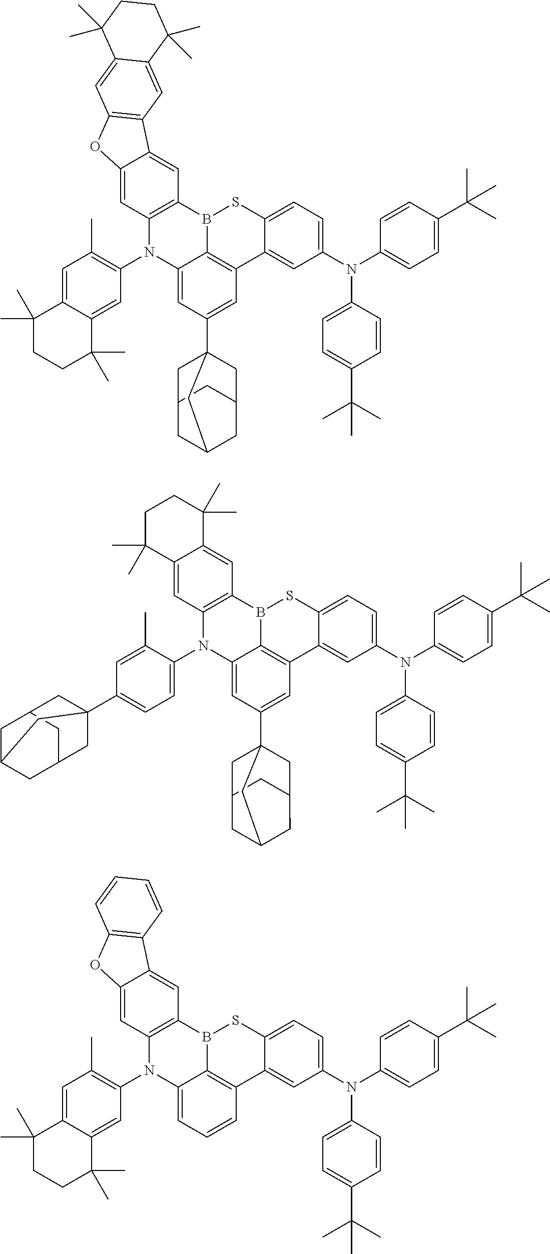

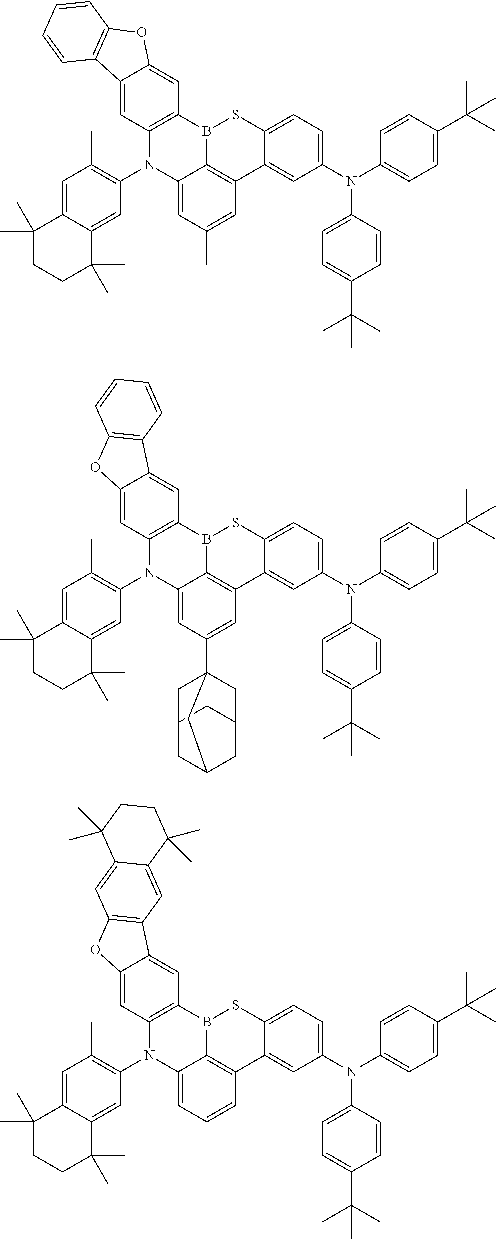

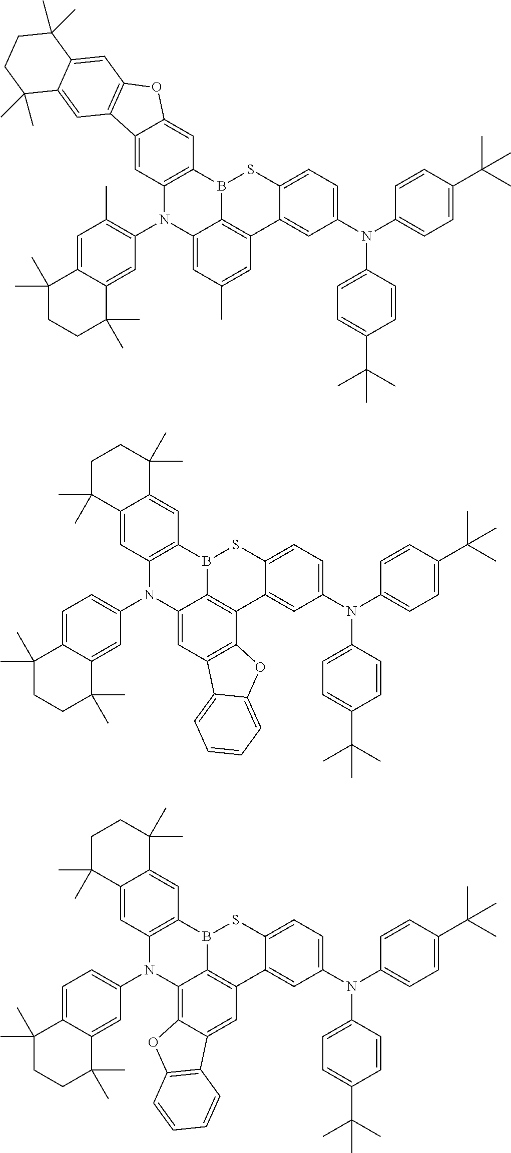

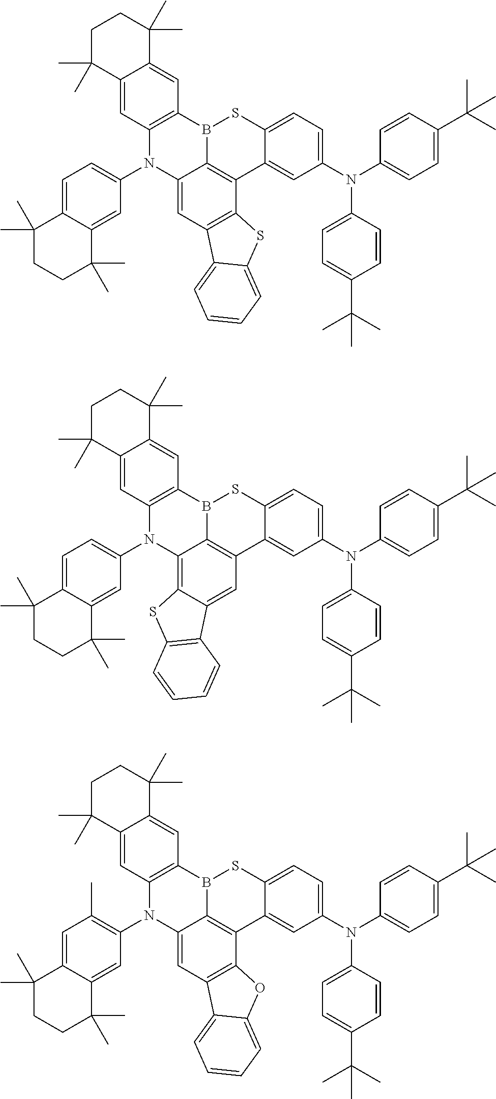

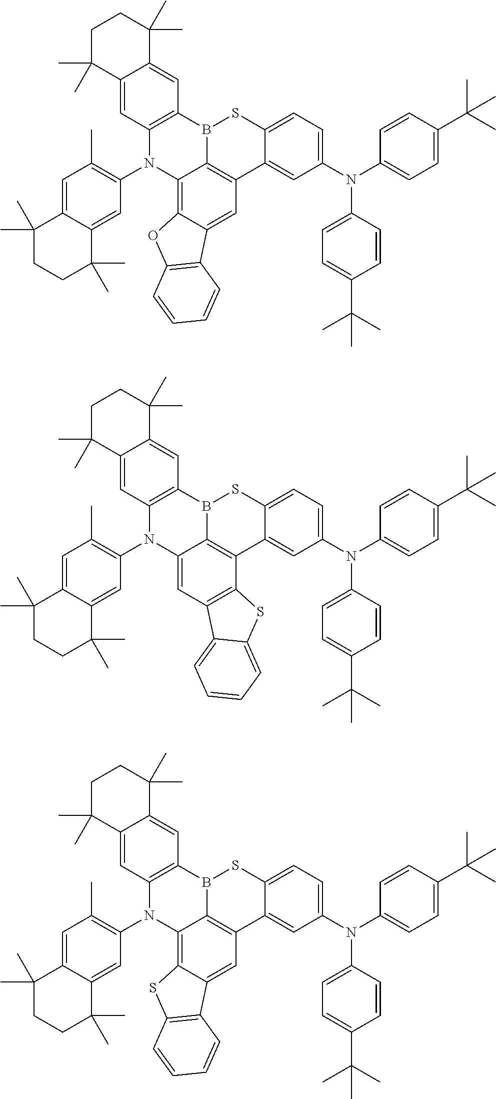

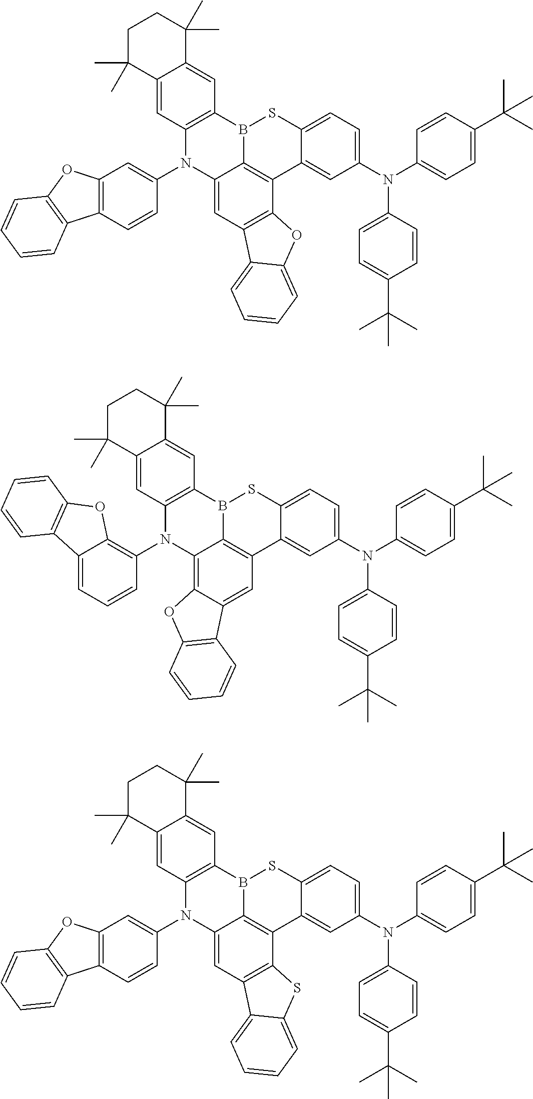 [SMILES: CC(C)(C)c1ccc(N(c2ccc(C(C)(C)C)cc2)c2ccc3c(c2)-c2c4c(cc5c2oc2ccccc25)N(c2ccc5c(c2)oc2ccccc25)c2cc5c(cc2B4S3)C(C)(C)CCC5(C)C)cc1 ; CC(C)(C)c1ccc(N(c2ccc(C(C)(C)C)cc2)c2ccc3c(c2)-c2cc4c(oc5ccccc54)c4c2B(S3)c2cc3c(cc2N4c2cccc4c2oc2ccccc24)C(C)(C)CCC3(C)C)cc1 ; CC(C)(C)c1ccc(N(c2ccc(C(C)(C)C)cc2)c2ccc3c(c2)-c2c4c(cc5c2sc2ccccc25)N(c2ccc5c(c2)oc2ccccc25)c2cc5c(cc2B4S3)C(C)(C)CCC5(C)C)cc1]

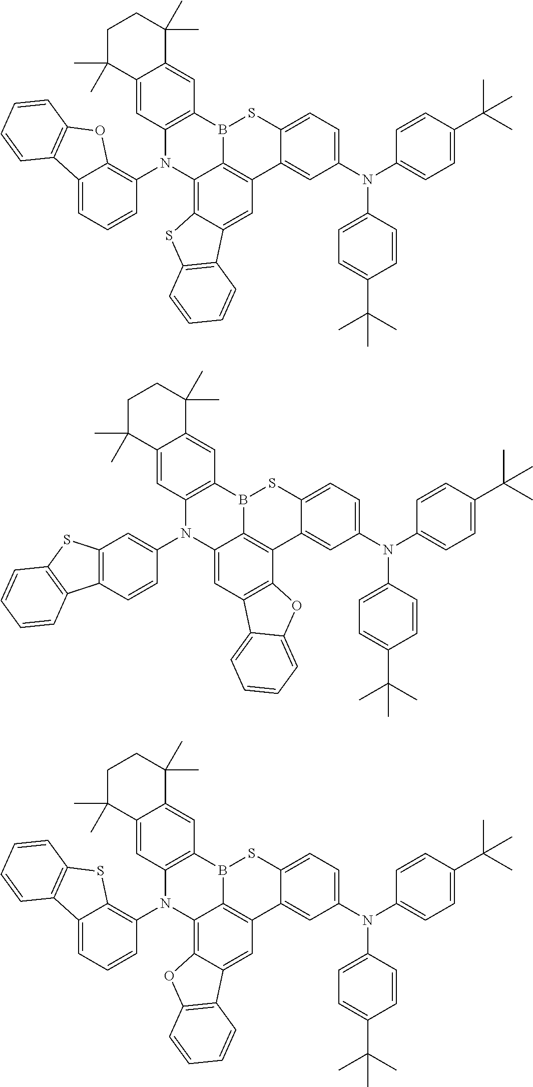 [SMILES: CC(C)(C)c1ccc(N(c2ccc(C(C)(C)C)cc2)c2ccc3c(c2)-c2cc4c(sc5ccccc54)c4c2B(S3)c2cc3c(cc2N4c2cccc4c2oc2ccccc24)C(C)(C)CCC3(C)C)cc1 ; CC(C)(C)c1ccc(N(c2ccc(C(C)(C)C)cc2)c2ccc3c(c2)-c2c4c(cc5c2oc2ccccc25)N(c2ccc5c(c2)sc2ccccc25)c2cc5c(cc2B4S3)C(C)(C)CCC5(C)C)cc1 ; CC(C)(C)c1ccc(N(c2ccc(C(C)(C)C)cc2)c2ccc3c(c2)-c2cc4c(oc5ccccc54)c4c2B(S3)c2cc3c(cc2N4c2cccc4c2sc2ccccc24)C(C)(C)CCC3(C)C)cc1]

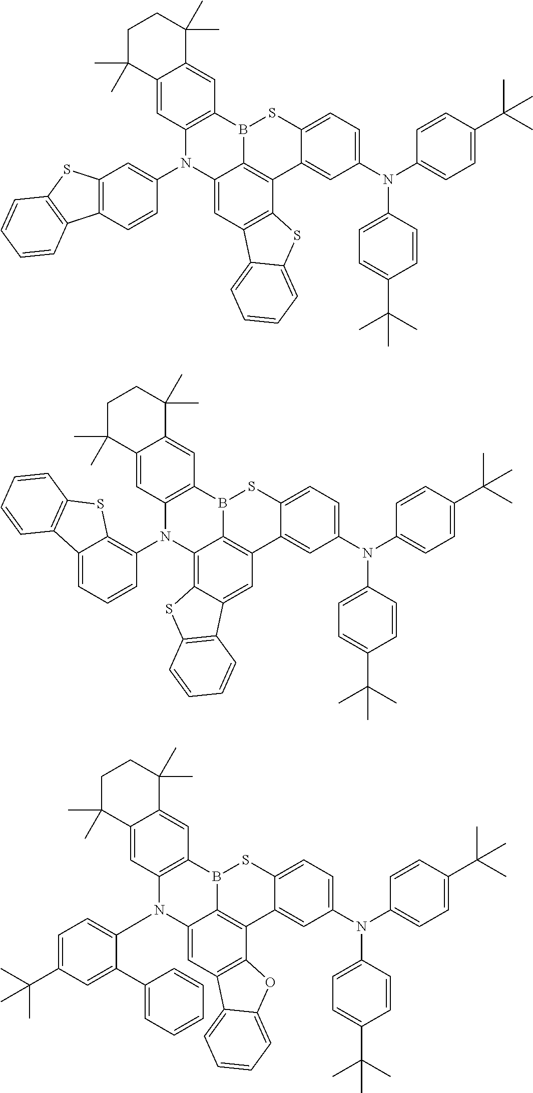

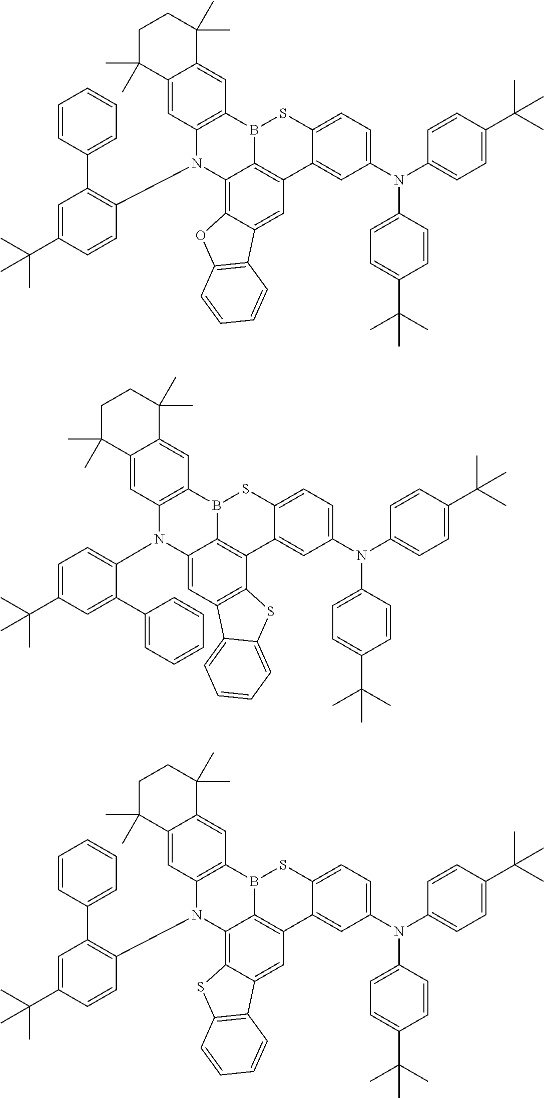

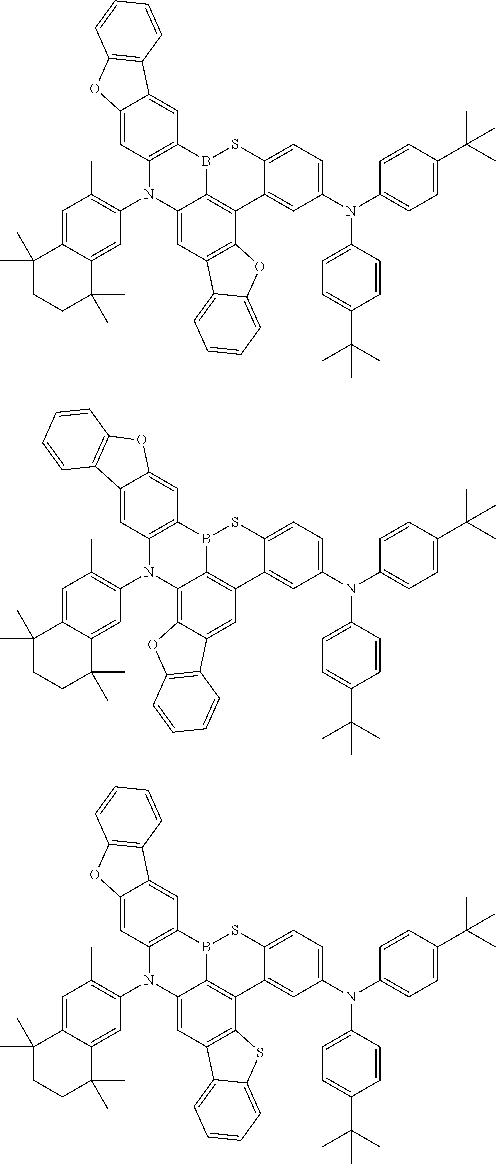

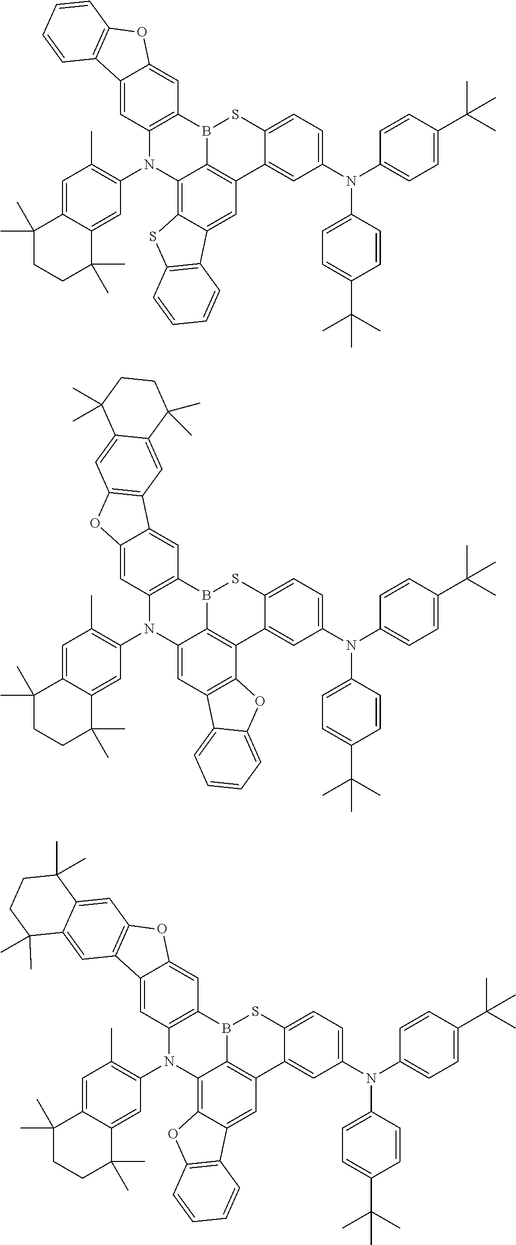

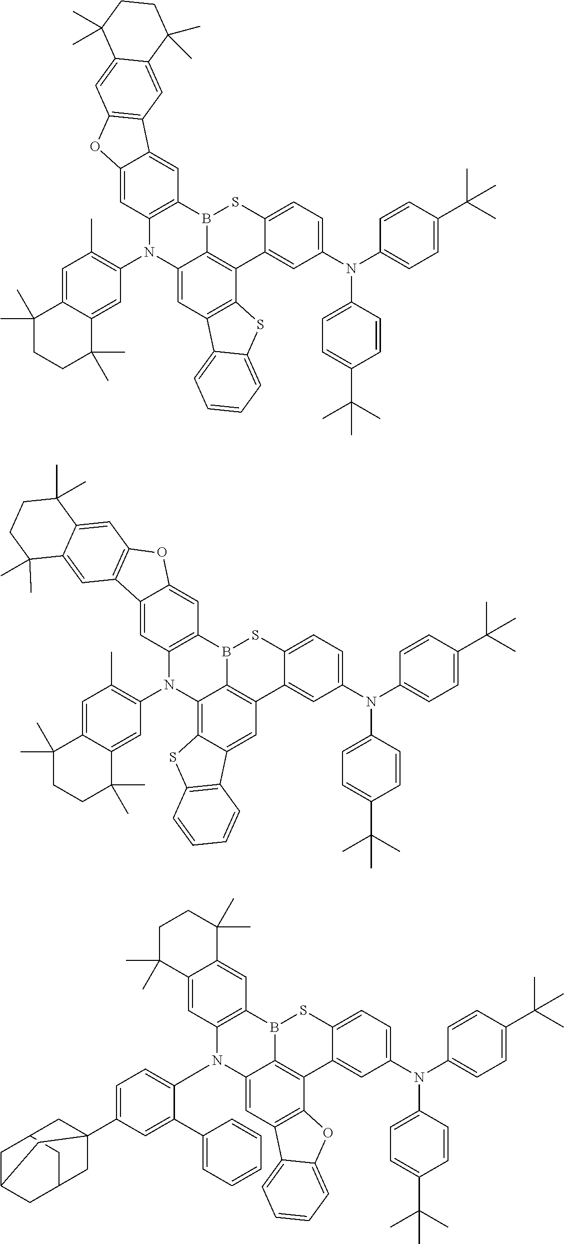

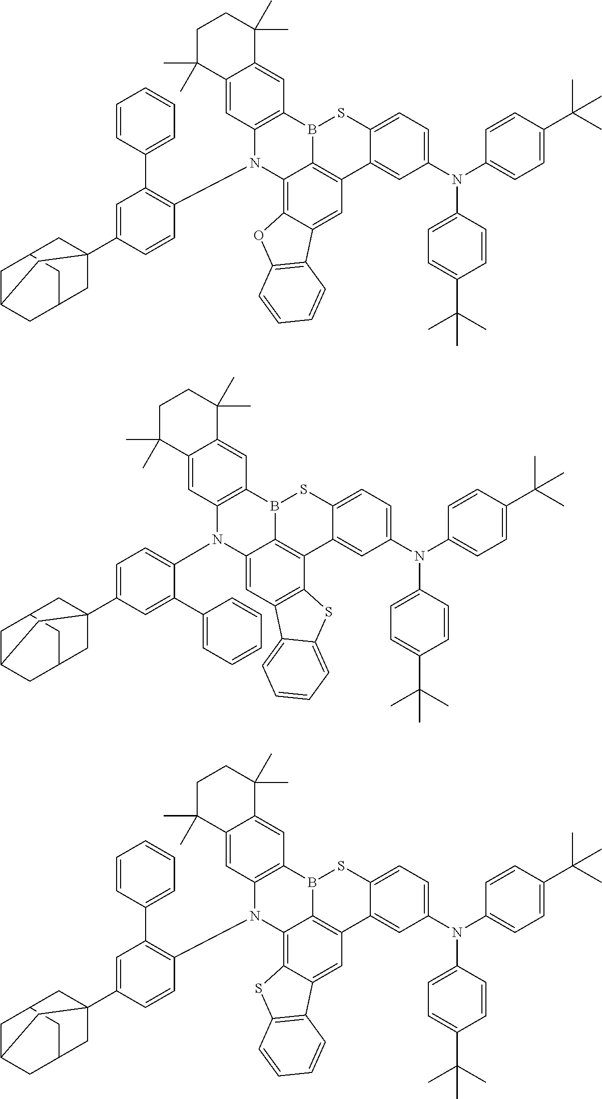 [SMILES: CC(C)(C)c1ccc(N(c2ccc(C(C)(C)C)cc2)c2ccc3c(c2)-c2cc4c(oc5ccccc54)c4c2B(S3)c2cc3c(cc2N4c2ccc(C45CC6CC(CC(C6)C4)C5)cc2-c2ccccc2)C(C)(C)CCC3(C)C)cc1 ; CC(C)(C)c1ccc(N(c2ccc(C(C)(C)C)cc2)c2ccc3c(c2)-c2c4c(cc5c2sc2ccccc25)N(c2ccc(C56CC7CC(CC(C7)C5)C6)cc2-c2ccccc2)c2cc5c(cc2B4S3)C(C)(C)CCC5(C)C)cc1 ; CC(C)(C)c1ccc(N(c2ccc(C(C)(C)C)cc2)c2ccc3c(c2)-c2cc4c(sc5ccccc54)c4c2B(S3)c2cc3c(cc2N4c2ccc(C45CC6CC(CC(C6)C4)C5)cc2-c2ccccc2)C(C)(C)CCC3(C)C)cc1]

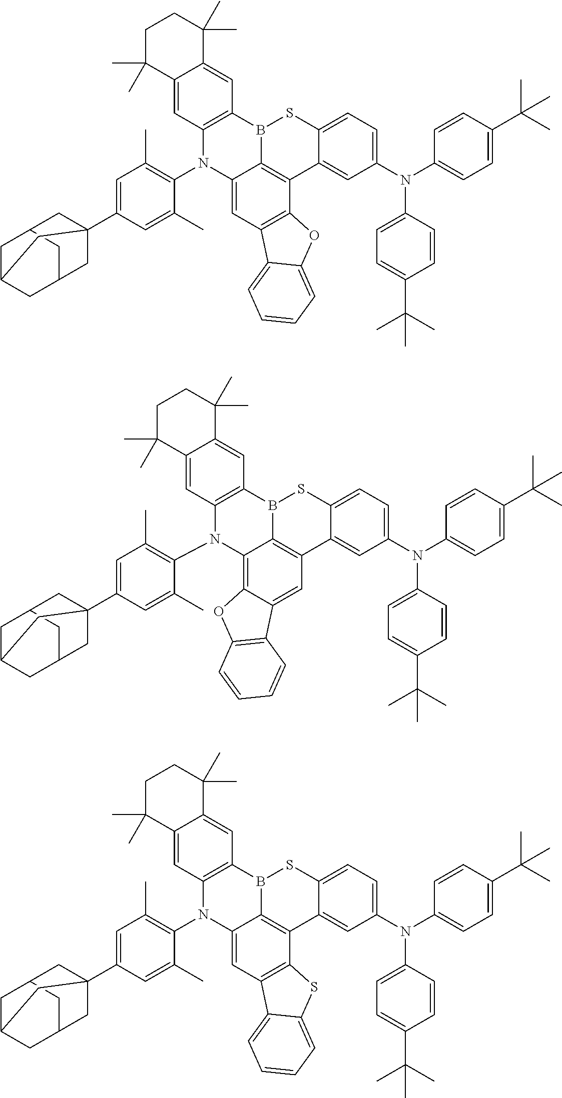 [SMILES: Cc1cc(C23CC4CC(CC(C4)C2)C3)cc(C)c1N1c2cc3c(cc2B2Sc4ccc(N(c5ccc(C(C)(C)C)cc5)c5ccc(C(C)(C)C)cc5)cc4-c4c2c1cc1c4oc2ccccc21)C(C)(C)CCC3(C)C ; Cc1cc(C23CC4CC(CC(C4)C2)C3)cc(C)c1N1c2cc3c(cc2B2Sc4ccc(N(c5ccc(C(C)(C)C)cc5)c5ccc(C(C)(C)C)cc5)cc4-c4cc5c(oc6ccccc65)c1c42)C(C)(C)CCC3(C)C ; Cc1cc(C23CC4CC(CC(C4)C2)C3)cc(C)c1N1c2cc3c(cc2B2Sc4ccc(N(c5ccc(C(C)(C)C)cc5)c5ccc(C(C)(C)C)cc5)cc4-c4c2c1cc1c4sc2ccccc21)C(C)(C)CCC3(C)C]

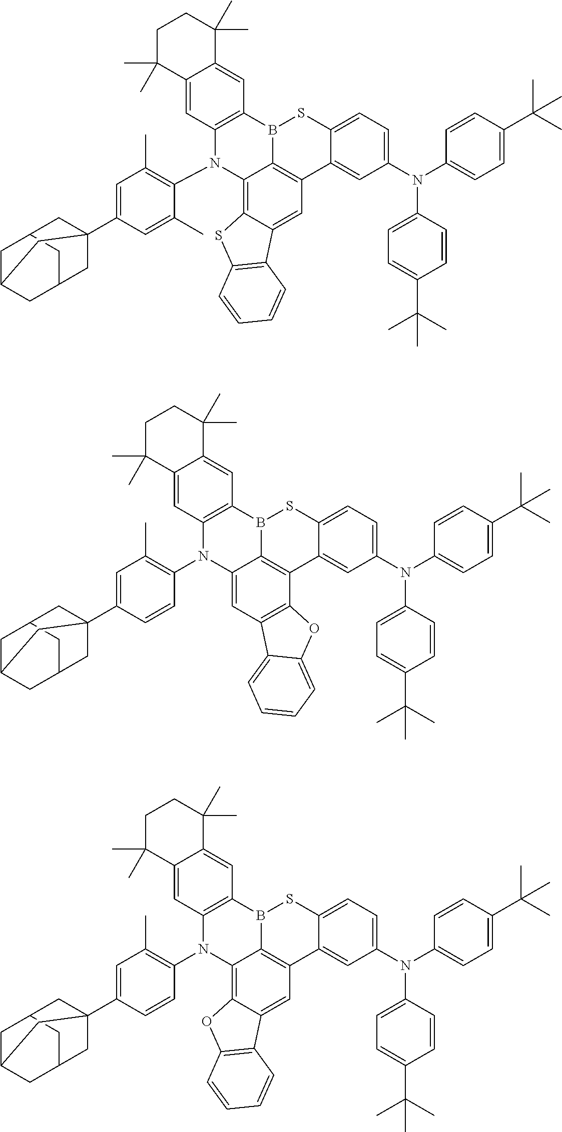 [SMILES: Cc1cc(C23CC4CC(CC(C4)C2)C3)cc(C)c1N1c2cc3c(cc2B2Sc4ccc(N(c5ccc(C(C)(C)C)cc5)c5ccc(C(C)(C)C)cc5)cc4-c4cc5c(sc6ccccc65)c1c42)C(C)(C)CCC3(C)C ; Cc1cc(C23CC4CC(CC(C4)C2)C3)ccc1N1c2cc3c(cc2B2Sc4ccc(N(c5ccc(C(C)(C)C)cc5)c5ccc(C(C)(C)C)cc5)cc4-c4c2c1cc1c4oc2ccccc21)C(C)(C)CCC3(C)C ; Cc1cc(C23CC4CC(CC(C4)C2)C3)ccc1N1c2cc3c(cc2B2Sc4ccc(N(c5ccc(C(C)(C)C)cc5)c5ccc(C(C)(C)C)cc5)cc4-c4cc5c(oc6ccccc65)c1c42)C(C)(C)CCC3(C)C]

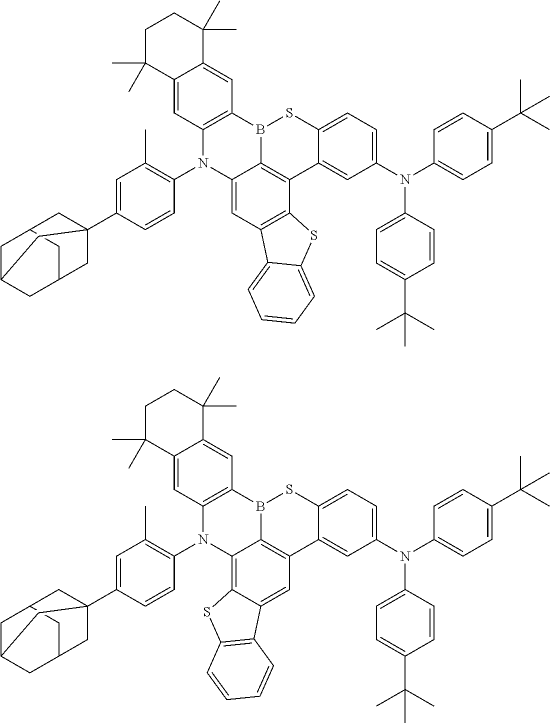 [SMILES: Cc1cc(C23CC4CC(CC(C4)C2)C3)ccc1N1c2cc3c(cc2B2Sc4ccc(N(c5ccc(C(C)(C)C)cc5)c5ccc(C(C)(C)C)cc5)cc4-c4c2c1cc1c4sc2ccccc21)C(C)(C)CCC3(C)C ; Cc1cc(C23CC4CC(CC(C4)C2)C3)ccc1N1c2cc3c(cc2B2Sc4ccc(N(c5ccc(C(C)(C)C)cc5)c5ccc(C(C)(C)C)cc5)cc4-c4cc5c(sc6ccccc65)c1c42)C(C)(C)CCC3(C)C]

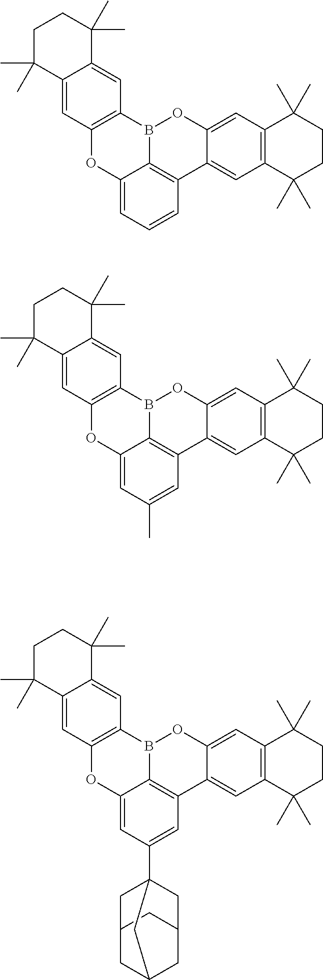 [SMILES: CC1(C)CCC(C)(C)c2cc3c(cc21)Oc1cccc2c1B3Oc1cc3c(cc1-2)C(C)(C)CCC3(C)C ; Cc1cc2c3c(c1)-c1cc4c(cc1OB3c1cc3c(cc1O2)C(C)(C)CCC3(C)C)C(C)(C)CCC4(C)C ; CC1(C)CCC(C)(C)c2cc3c(cc21)Oc1cc(C24CC5CC(CC(C5)C2)C4)cc2c1B3Oc1cc3c(cc1-2)C(C)(C)CCC3(C)C]

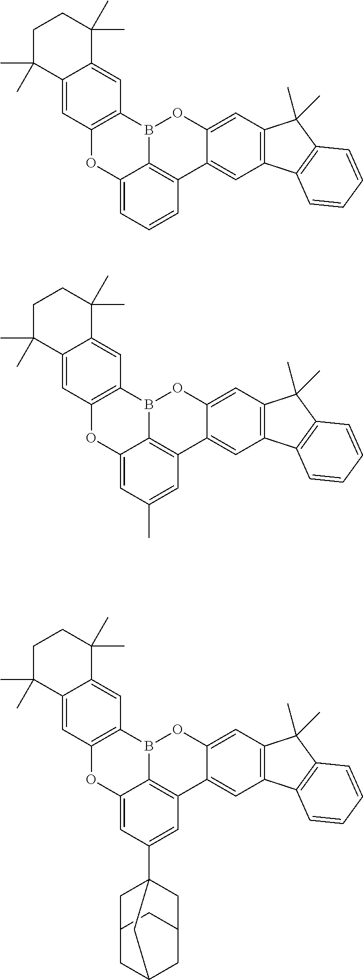 [SMILES: CC1(C)CCC(C)(C)c2cc3c(cc21)Oc1cccc2c1B3Oc1cc3c(cc1-2)-c1ccccc1C3(C)C ; Cc1cc2c3c(c1)-c1cc4c(cc1OB3c1cc3c(cc1O2)C(C)(C)CCC3(C)C)C(C)(C)c1ccccc1-4 ; CC1(C)CCC(C)(C)c2cc3c(cc21)Oc1cc(C24CC5CC(CC(C5)C2)C4)cc2c1B3Oc1cc3c(cc1-2)-c1ccccc1C3(C)C]

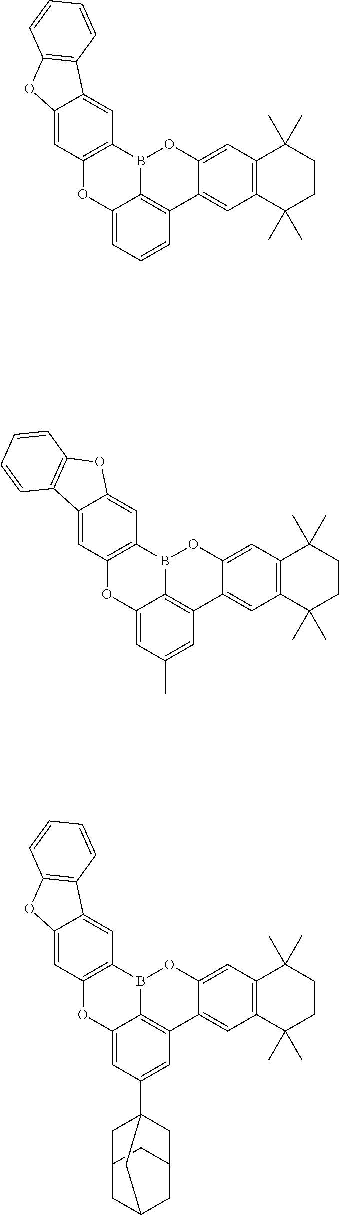 [SMILES: CC1(C)CCC(C)(C)c2cc3c(cc21)OB1c2cc4c(cc2Oc2cccc-3c21)oc1ccccc14 ; Cc1cc2c3c(c1)-c1cc4c(cc1OB3c1cc3oc5ccccc5c3cc1O2)C(C)(C)CCC4(C)C ; CC1(C)CCC(C)(C)c2cc3c(cc21)OB1c2cc4c(cc2Oc2cc(C56CC7CC(CC(C7)C5)C6)cc-3c21)oc1ccccc14]

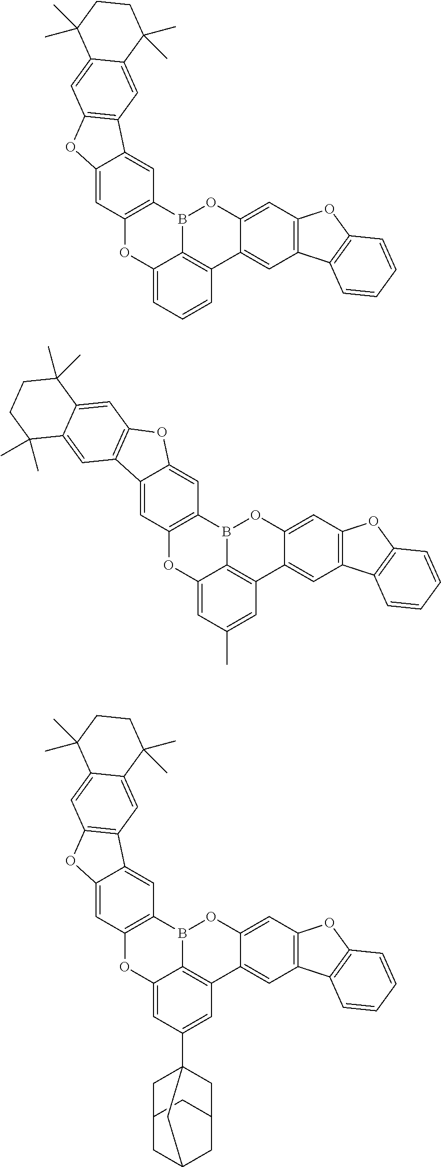 [SMILES: CC1(C)CCC(C)(C)c2cc3c(cc21)oc1cc2c(cc13)B1Oc3cc4oc5ccccc5c4cc3-c3cccc(c31)O2 ; Cc1cc2c3c(c1)-c1cc4c(cc1OB3c1cc3oc5cc6c(cc5c3cc1O2)C(C)(C)CCC6(C)C)oc1ccccc14 ; CC1(C)CCC(C)(C)c2cc3c(cc21)oc1cc2c(cc13)B1Oc3cc4oc5ccccc5c4cc3-c3cc(C45CC6CC(CC(C6)C4)C5)cc(c31)O2]

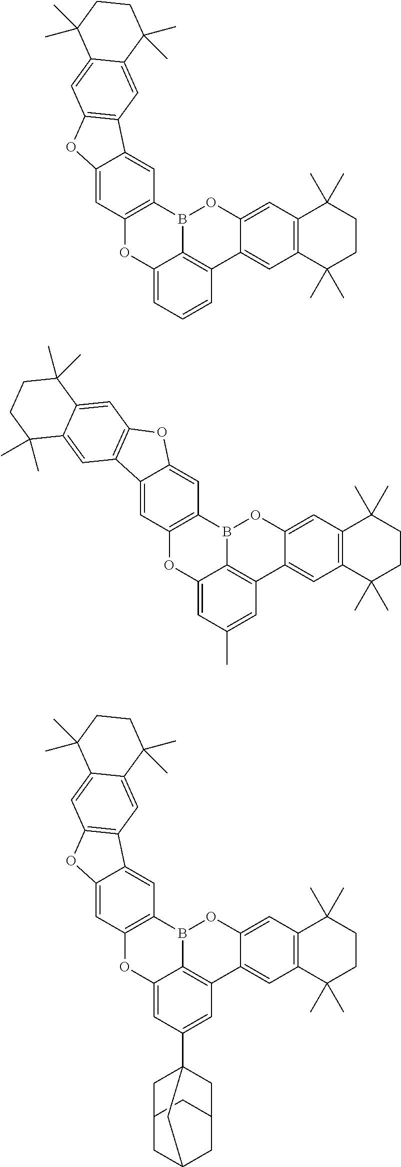 [SMILES: CC1(C)CCC(C)(C)c2cc3c(cc21)OB1c2cc4c(cc2Oc2cccc-3c21)oc1cc2c(cc14)C(C)(C)CCC2(C)C ; Cc1cc2c3c(c1)-c1cc4c(cc1OB3c1cc3oc5cc6c(cc5c3cc1O2)C(C)(C)CCC6(C)C)C(C)(C)CCC4(C)C ; CC1(C)CCC(C)(C)c2cc3c(cc21)OB1c2cc4c(cc2Oc2cc(C56CC7CC(CC(C7)C5)C6)cc-3c21)oc1cc2c(cc14)C(C)(C)CCC2(C)C]

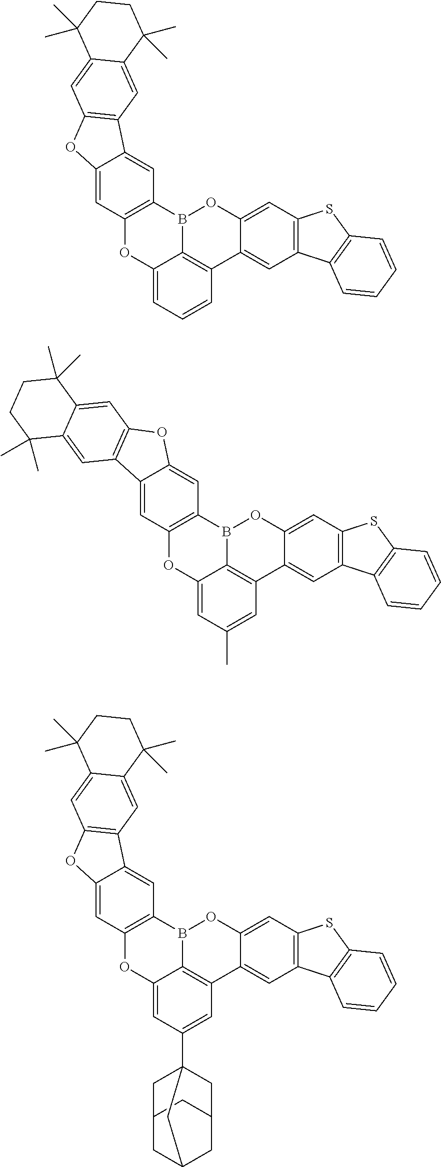 [SMILES: CC1(C)CCC(C)(C)c2cc3c(cc21)oc1cc2c(cc13)B1Oc3cc4sc5ccccc5c4cc3-c3cccc(c31)O2 ; Cc1cc2c3c(c1)-c1cc4c(cc1OB3c1cc3oc5cc6c(cc5c3cc1O2)C(C)(C)CCC6(C)C)sc1ccccc14 ; CC1(C)CCC(C)(C)c2cc3c(cc21)oc1cc2c(cc13)B1Oc3cc4sc5ccccc5c4cc3-c3cc(C45CC6CC(CC(C6)C4)C5)cc(c31)O2]

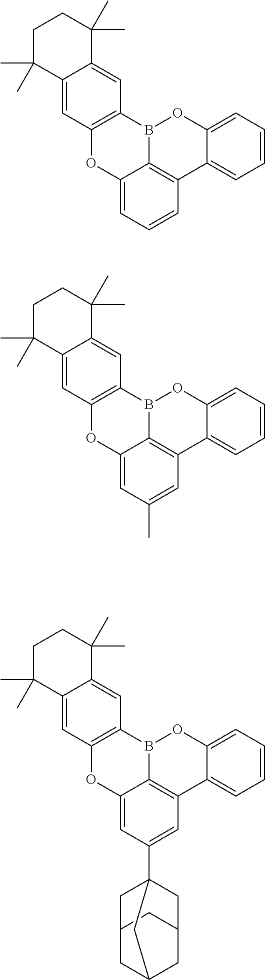 [SMILES: CC1(C)CCC(C)(C)c2cc3c(cc21)Oc1cccc2c1B3Oc1ccccc1-2 ; Cc1cc2c3c(c1)-c1ccccc1OB3c1cc3c(cc1O2)C(C)(C)CCC3(C)C ; CC1(C)CCC(C)(C)c2cc3c(cc21)Oc1cc(C24CC5CC(CC(C5)C2)C4)cc2c1B3Oc1ccccc1-2]

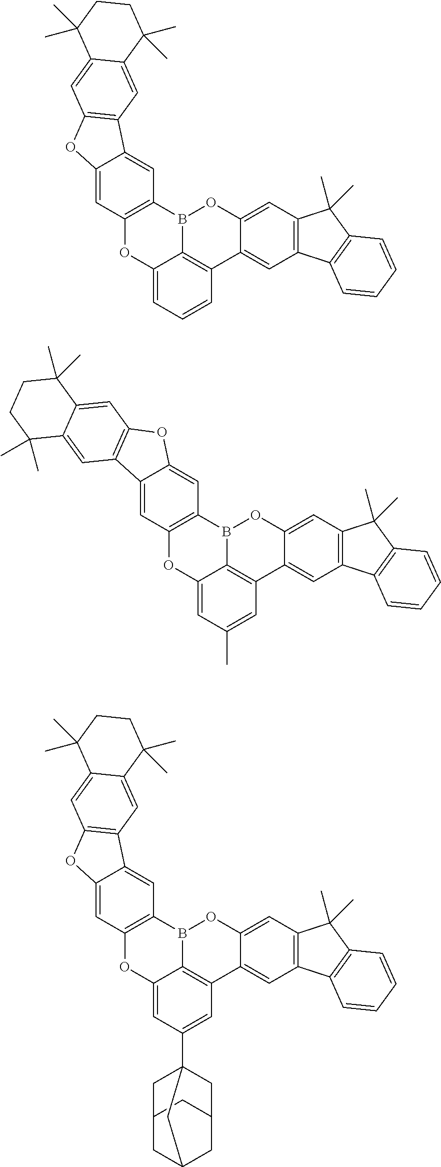 [SMILES: CC1(C)CCC(C)(C)c2cc3c(cc21)oc1cc2c(cc13)B1Oc3cc4c(cc3-c3cccc(c31)O2)-c1ccccc1C4(C)C ; Cc1cc2c3c(c1)-c1cc4c(cc1OB3c1cc3oc5cc6c(cc5c3cc1O2)C(C)(C)CCC6(C)C)C(C)(C)c1ccccc1-4 ; CC1(C)CCC(C)(C)c2cc3c(cc21)oc1cc2c(cc13)B1Oc3cc4c(cc3-c3cc(C56CC7CC(CC(C7)C5)C6)cc(c31)O2)-c1ccccc1C4(C)C]

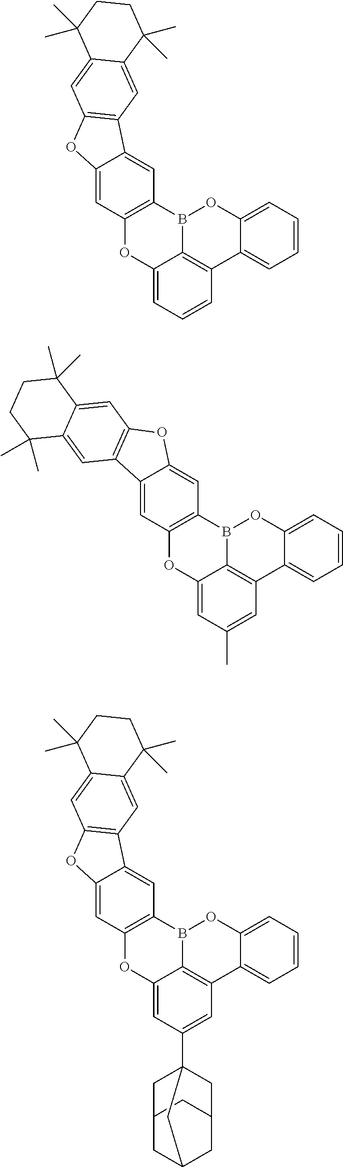 [SMILES: CC1(C)CCC(C)(C)c2cc3c(cc21)oc1cc2c(cc13)B1Oc3ccccc3-c3cccc(c31)O2 ; Cc1cc2c3c(c1)-c1ccccc1OB3c1cc3oc4cc5c(cc4c3cc1O2)C(C)(C)CCC5(C)C ; CC1(C)CCC(C)(C)c2cc3c(cc21)oc1cc2c(cc13)B1Oc3ccccc3-c3cc(C45CC6CC(CC(C6)C4)C5)cc(c31)O2]

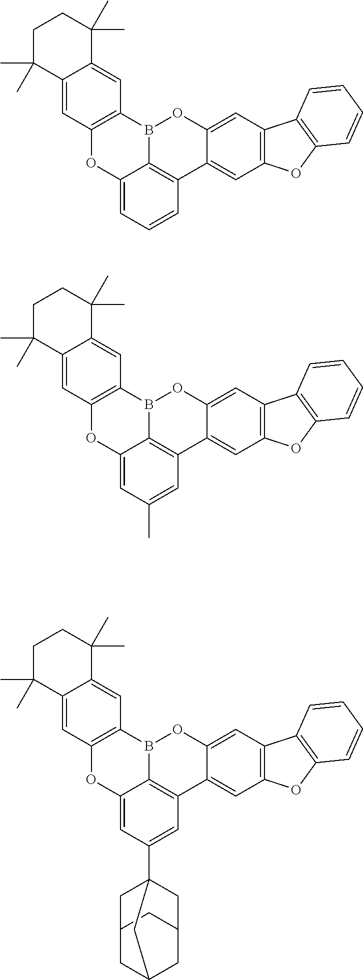 [SMILES: CC1(C)CCC(C)(C)c2cc3c(cc21)Oc1cccc2c1B3Oc1cc3c(cc1-2)oc1ccccc13 ; Cc1cc2c3c(c1)-c1cc4oc5ccccc5c4cc1OB3c1cc3c(cc1O2)C(C)(C)CCC3(C)C ; CC1(C)CCC(C)(C)c2cc3c(cc21)Oc1cc(C24CC5CC(CC(C5)C2)C4)cc2c1B3Oc1cc3c(cc1-2)oc1ccccc13]

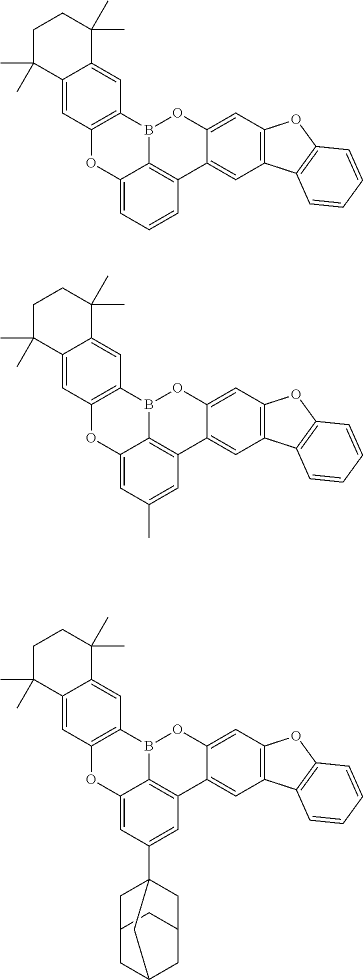 [SMILES: CC1(C)CCC(C)(C)c2cc3c(cc21)Oc1cccc2c1B3Oc1cc3oc4ccccc4c3cc1-2 ; Cc1cc2c3c(c1)-c1cc4c(cc1OB3c1cc3c(cc1O2)C(C)(C)CCC3(C)C)oc1ccccc14 ; CC1(C)CCC(C)(C)c2cc3c(cc21)Oc1cc(C24CC5CC(CC(C5)C2)C4)cc2c1B3Oc1cc3oc4ccccc4c3cc1-2]

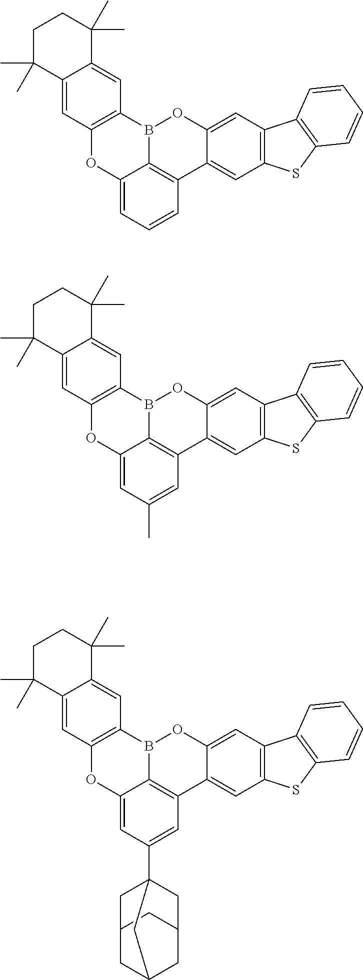 [SMILES: CC1(C)CCC(C)(C)c2cc3c(cc21)Oc1cccc2c1B3Oc1cc3c(cc1-2)sc1ccccc13 ; Cc1cc2c3c(c1)-c1cc4sc5ccccc5c4cc1OB3c1cc3c(cc1O2)C(C)(C)CCC3(C)C ; CC1(C)CCC(C)(C)c2cc3c(cc21)Oc1cc(C24CC5CC(CC(C5)C2)C4)cc2c1B3Oc1cc3c(cc1-2)sc1ccccc13]

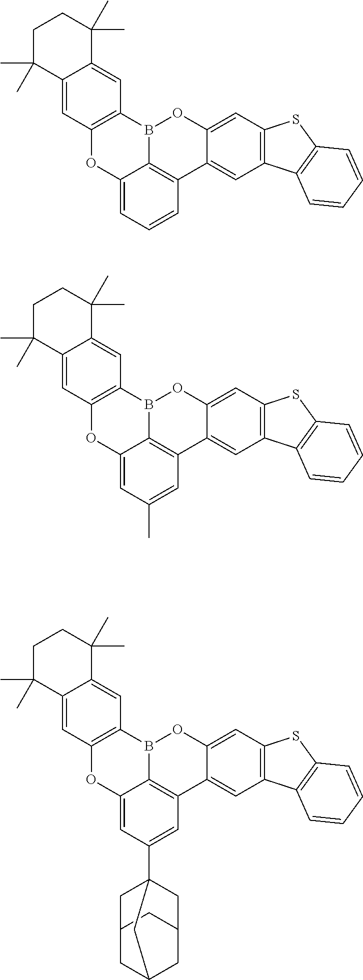 [SMILES: CC1(C)CCC(C)(C)c2cc3c(cc21)Oc1cccc2c1B3Oc1cc3sc4ccccc4c3cc1-2 ; Cc1cc2c3c(c1)-c1cc4c(cc1OB3c1cc3c(cc1O2)C(C)(C)CCC3(C)C)sc1ccccc14 ; CC1(C)CCC(C)(C)c2cc3c(cc21)Oc1cc(C24CC5CC(CC(C5)C2)C4)cc2c1B3Oc1cc3sc4ccccc4c3cc1-2]

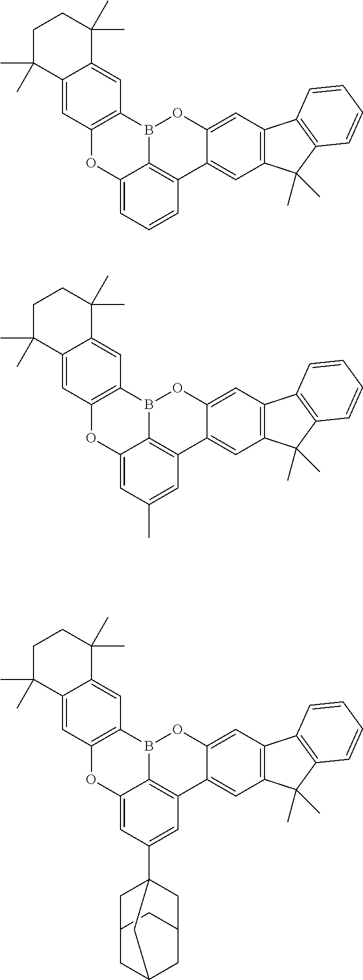 [SMILES: CC1(C)CCC(C)(C)c2cc3c(cc21)Oc1cccc2c1B3Oc1cc3c(cc1-2)C(C)(C)c1ccccc1-3 ; Cc1cc2c3c(c1)-c1cc4c(cc1OB3c1cc3c(cc1O2)C(C)(C)CCC3(C)C)-c1ccccc1C4(C)C ; CC1(C)CCC(C)(C)c2cc3c(cc21)Oc1cc(C24CC5CC(CC(C5)C2)C4)cc2c1B3Oc1cc3c(cc1-2)C(C)(C)c1ccccc1-3]

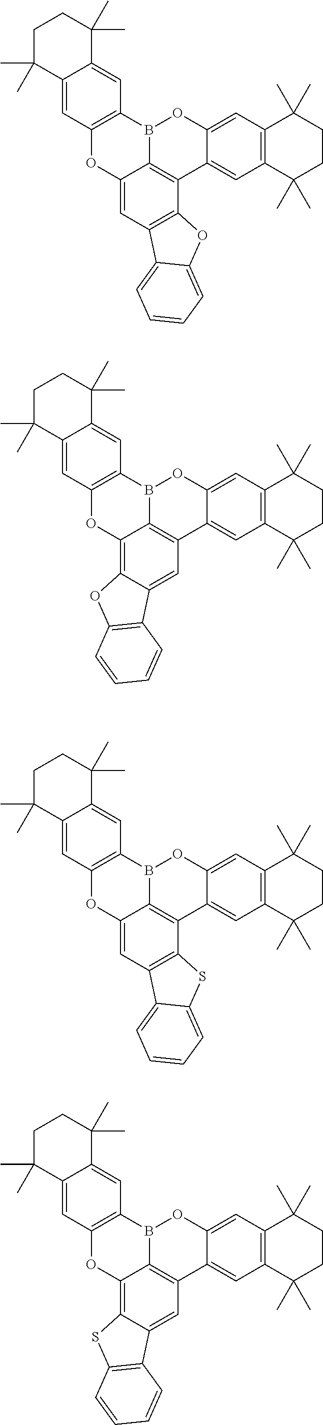 [SMILES: CC1(C)CCC(C)(C)c2cc3c(cc21)Oc1cc2c(oc4ccccc42)c2c1B3Oc1cc3c(cc1-2)C(C)(C)CCC3(C)C ; CC1(C)CCC(C)(C)c2cc3c(cc21)Oc1c2c(cc4c1oc1ccccc14)-c1cc4c(cc1OB32)C(C)(C)CCC4(C)C ; CC1(C)CCC(C)(C)c2cc3c(cc21)Oc1cc2c(sc4ccccc42)c2c1B3Oc1cc3c(cc1-2)C(C)(C)CCC3(C)C ; CC1(C)CCC(C)(C)c2cc3c(cc21)Oc1c2c(cc4c1sc1ccccc14)-c1cc4c(cc1OB32)C(C)(C)CCC4(C)C]

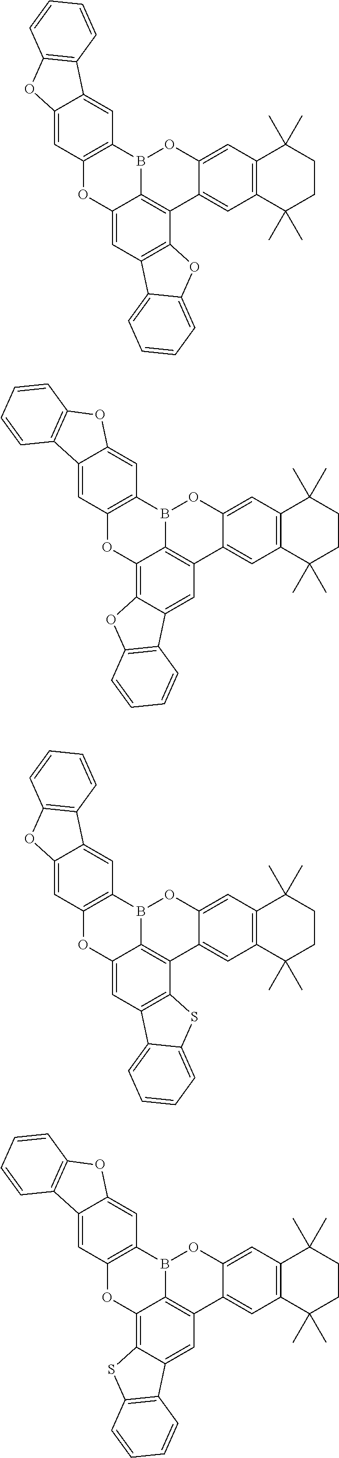 [SMILES: CC1(C)CCC(C)(C)c2cc3c(cc21)OB1c2cc4c(cc2Oc2cc5c(oc6ccccc65)c-3c21)oc1ccccc14 ; CC1(C)CCC(C)(C)c2cc3c(cc21)OB1c2cc4oc5ccccc5c4cc2Oc2c1c-3cc1c2oc2ccccc21 ; CC1(C)CCC(C)(C)c2cc3c(cc21)OB1c2cc4c(cc2Oc2cc5c(sc6ccccc65)c-3c21)oc1ccccc14 ; CC1(C)CCC(C)(C)c2cc3c(cc21)OB1c2cc4oc5ccccc5c4cc2Oc2c1c-3cc1c2sc2ccccc21]

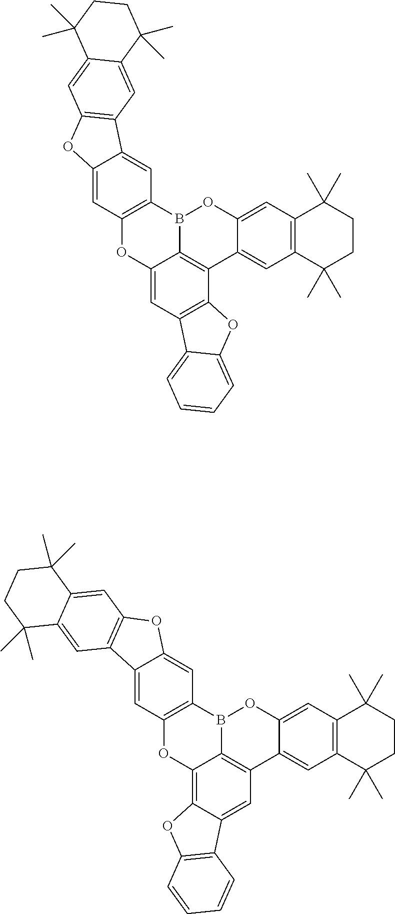 [SMILES: CC1(C)CCC(C)(C)c2cc3c(cc21)OB1c2cc4c(cc2Oc2cc5c(oc6ccccc65)c-3c21)oc1cc2c(cc14)C(C)(C)CCC2(C)C ; CC1(C)CCC(C)(C)c2cc3c(cc21)OB1c2cc4oc5cc6c(cc5c4cc2Oc2c1c-3cc1c2oc2ccccc21)C(C)(C)CCC6(C)C]

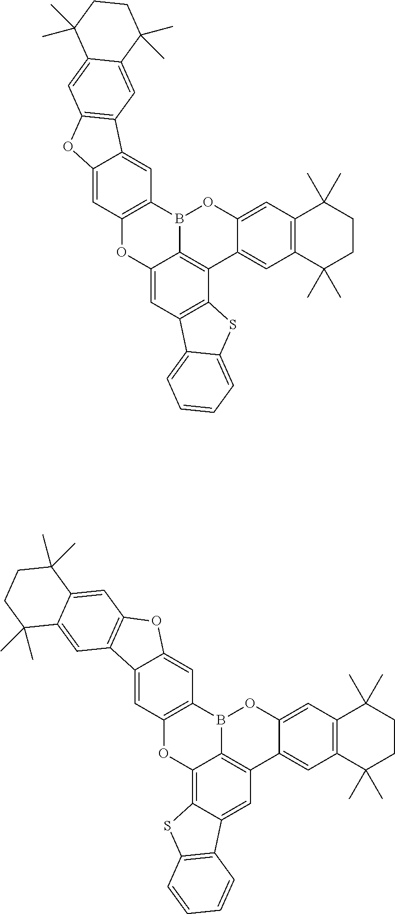 [SMILES: CC1(C)CCC(C)(C)c2cc3c(cc21)OB1c2cc4c(cc2Oc2cc5c(sc6ccccc65)c-3c21)oc1cc2c(cc14)C(C)(C)CCC2(C)C ; CC1(C)CCC(C)(C)c2cc3c(cc21)OB1c2cc4oc5cc6c(cc5c4cc2Oc2c1c-3cc1c2sc2ccccc21)C(C)(C)CCC6(C)C]

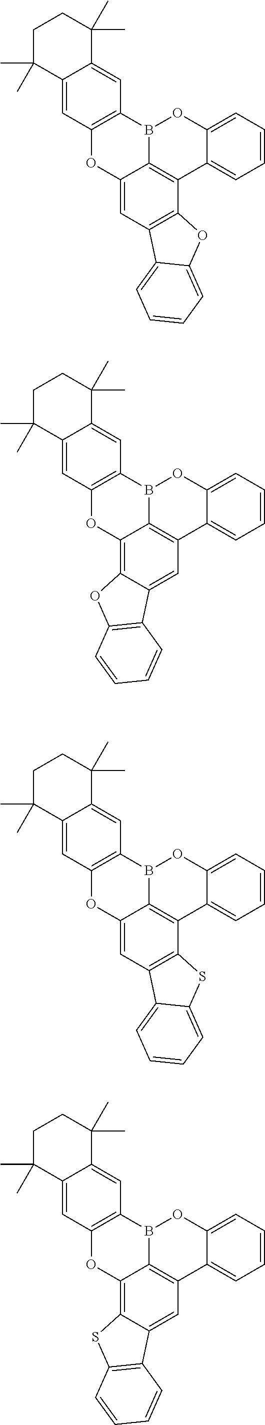 [SMILES: CC1(C)CCC(C)(C)c2cc3c(cc21)Oc1cc2c(oc4ccccc42)c2c1B3Oc1ccccc1-2 ; CC1(C)CCC(C)(C)c2cc3c(cc21)Oc1c2c(cc4c1oc1ccccc14)-c1ccccc1OB32 ; CC1(C)CCC(C)(C)c2cc3c(cc21)Oc1cc2c(sc4ccccc42)c2c1B3Oc1ccccc1-2 ; CC1(C)CCC(C)(C)c2cc3c(cc21)Oc1c2c(cc4c1sc1ccccc14)-c1ccccc1OB32]

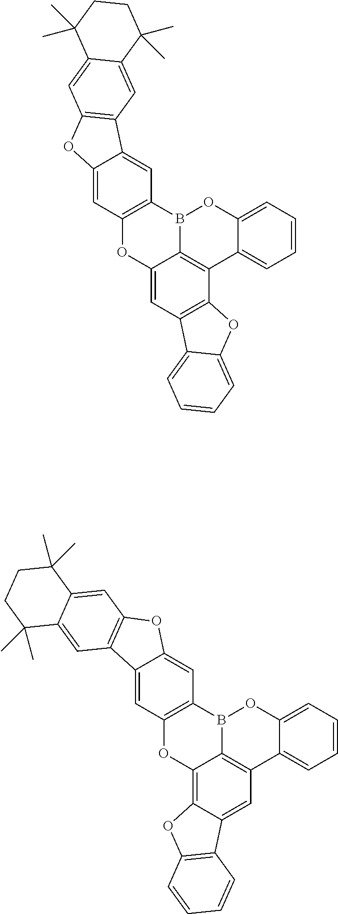 [SMILES: CC1(C)CCC(C)(C)c2cc3c(cc21)oc1cc2c(cc13)B1Oc3ccccc3-c3c1c(cc1c3oc3ccccc31)O2 ; CC1(C)CCC(C)(C)c2cc3c(cc21)oc1cc2c(cc13)Oc1c3c(cc4c1oc1ccccc14)-c1ccccc1OB23]

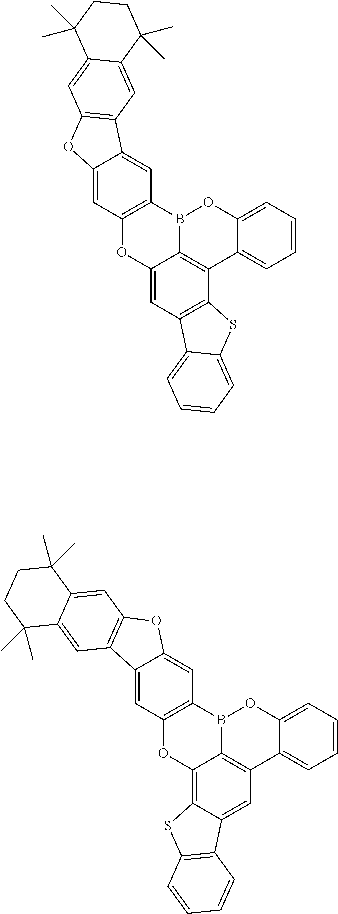 [SMILES: CC1(C)CCC(C)(C)c2cc3c(cc21)oc1cc2c(cc13)B1Oc3ccccc3-c3c1c(cc1c3sc3ccccc31)O2 ; CC1(C)CCC(C)(C)c2cc3c(cc21)oc1cc2c(cc13)Oc1c3c(cc4c1sc1ccccc14)-c1ccccc1OB23]

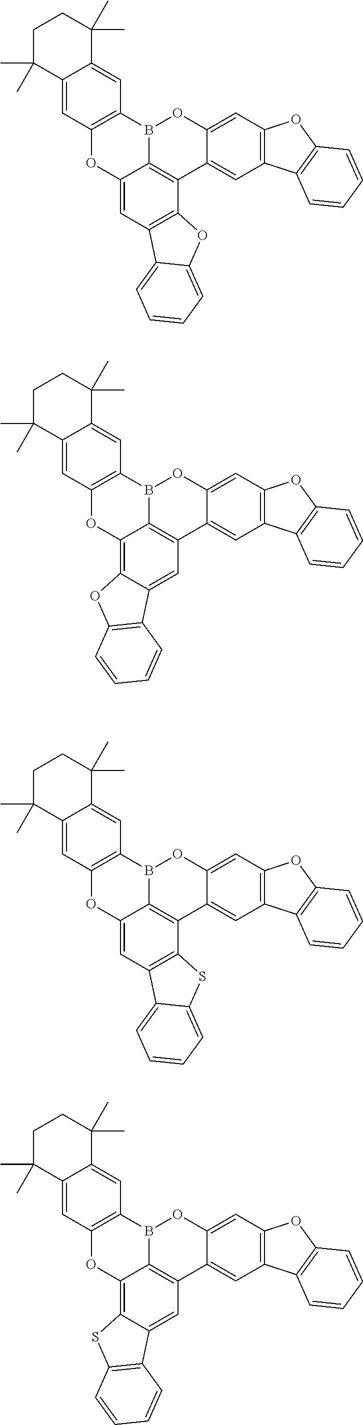 [SMILES: CC1(C)CCC(C)(C)c2cc3c(cc21)Oc1cc2c(oc4ccccc42)c2c1B3Oc1cc3oc4ccccc4c3cc1-2 ; CC1(C)CCC(C)(C)c2cc3c(cc21)Oc1c2c(cc4c1oc1ccccc14)-c1cc4c(cc1OB32)oc1ccccc14 ; CC1(C)CCC(C)(C)c2cc3c(cc21)Oc1cc2c(sc4ccccc42)c2c1B3Oc1cc3oc4ccccc4c3cc1-2 ; CC1(C)CCC(C)(C)c2cc3c(cc21)Oc1c2c(cc4c1sc1ccccc14)-c1cc4c(cc1OB32)oc1ccccc14]

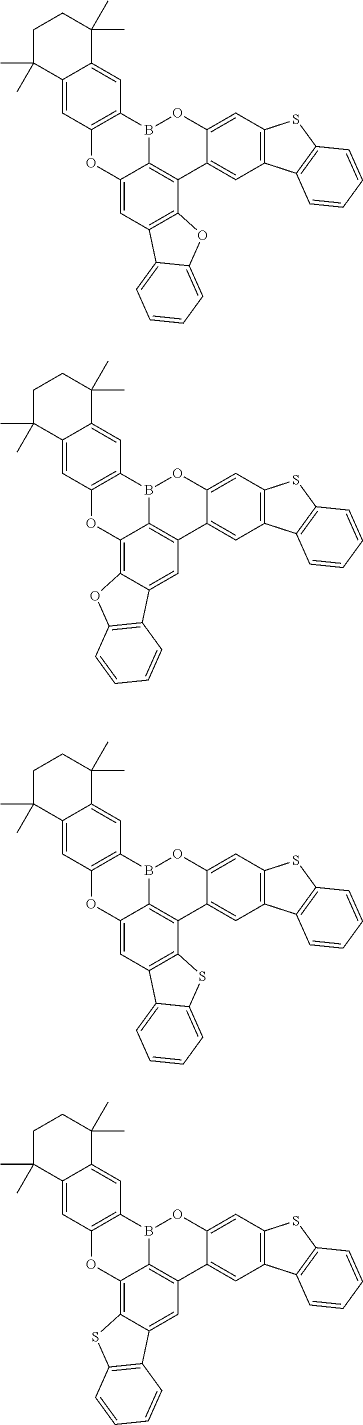 [SMILES: CC1(C)CCC(C)(C)c2cc3c(cc21)Oc1cc2c(oc4ccccc42)c2c1B3Oc1cc3sc4ccccc4c3cc1-2 ; CC1(C)CCC(C)(C)c2cc3c(cc21)Oc1c2c(cc4c1oc1ccccc14)-c1cc4c(cc1OB32)sc1ccccc14 ; CC1(C)CCC(C)(C)c2cc3c(cc21)Oc1cc2c(sc4ccccc42)c2c1B3Oc1cc3sc4ccccc4c3cc1-2 ; CC1(C)CCC(C)(C)c2cc3c(cc21)Oc1c2c(cc4c1sc1ccccc14)-c1cc4c(cc1OB32)sc1ccccc14]

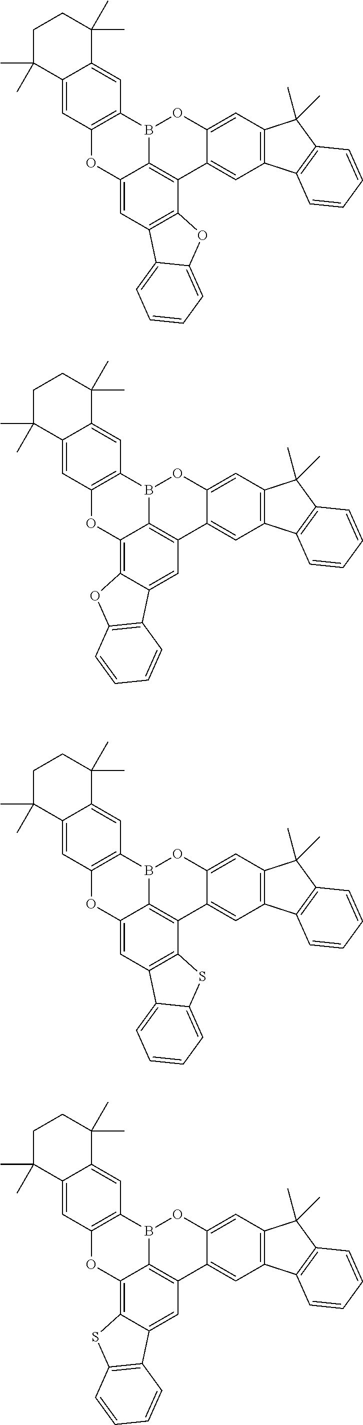 [SMILES: CC1(C)CCC(C)(C)c2cc3c(cc21)Oc1cc2c(oc4ccccc42)c2c1B3Oc1cc3c(cc1-2)-c1ccccc1C3(C)C ; CC1(C)CCC(C)(C)c2cc3c(cc21)Oc1c2c(cc4c1oc1ccccc14)-c1cc4c(cc1OB32)C(C)(C)c1ccccc1-4 ; CC1(C)CCC(C)(C)c2cc3c(cc21)Oc1cc2c(sc4ccccc42)c2c1B3Oc1cc3c(cc1-2)-c1ccccc1C3(C)C ; CC1(C)CCC(C)(C)c2cc3c(cc21)Oc1c2c(cc4c1sc1ccccc14)-c1cc4c(cc1OB32)C(C)(C)c1ccccc1-4]

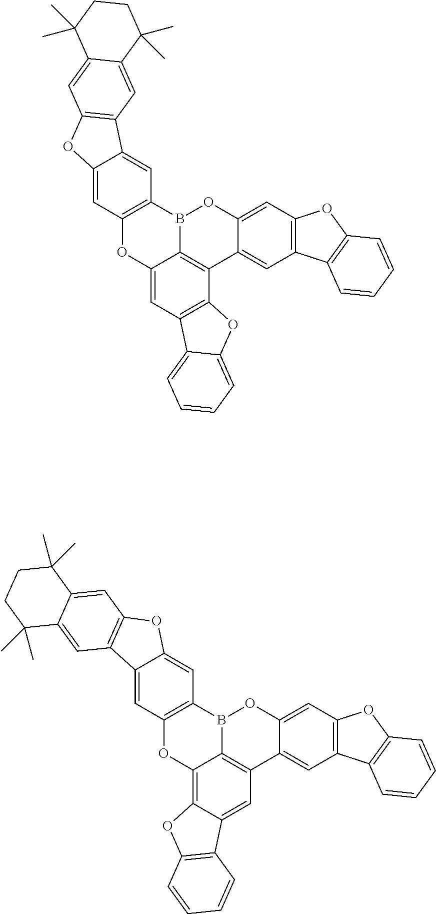 [SMILES: CC1(C)CCC(C)(C)c2cc3c(cc21)oc1cc2c(cc13)B1Oc3cc4oc5ccccc5c4cc3-c3c1c(cc1c3oc3ccccc31)O2 ; CC1(C)CCC(C)(C)c2cc3c(cc21)oc1cc2c(cc13)Oc1c3c(cc4c1oc1ccccc14)-c1cc4c(cc1OB23)oc1ccccc14]

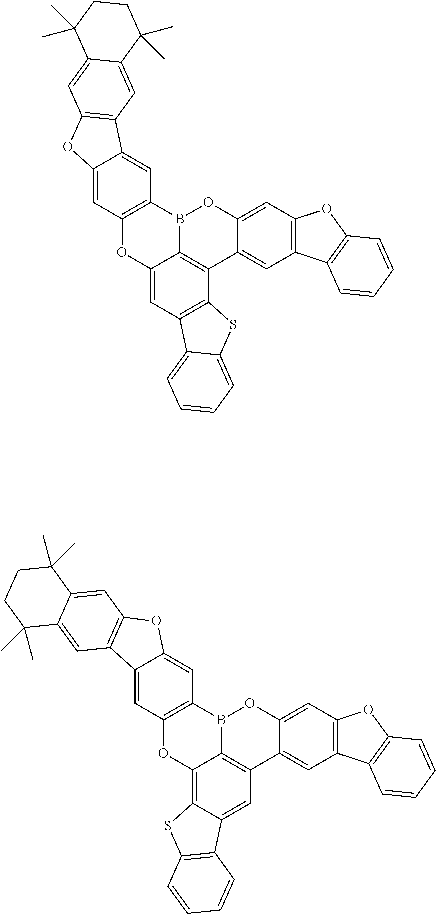 [SMILES: CC1(C)CCC(C)(C)c2cc3c(cc21)oc1cc2c(cc13)B1Oc3cc4oc5ccccc5c4cc3-c3c1c(cc1c3sc3ccccc31)O2 ; CC1(C)CCC(C)(C)c2cc3c(cc21)oc1cc2c(cc13)Oc1c3c(cc4c1sc1ccccc14)-c1cc4c(cc1OB23)oc1ccccc14]

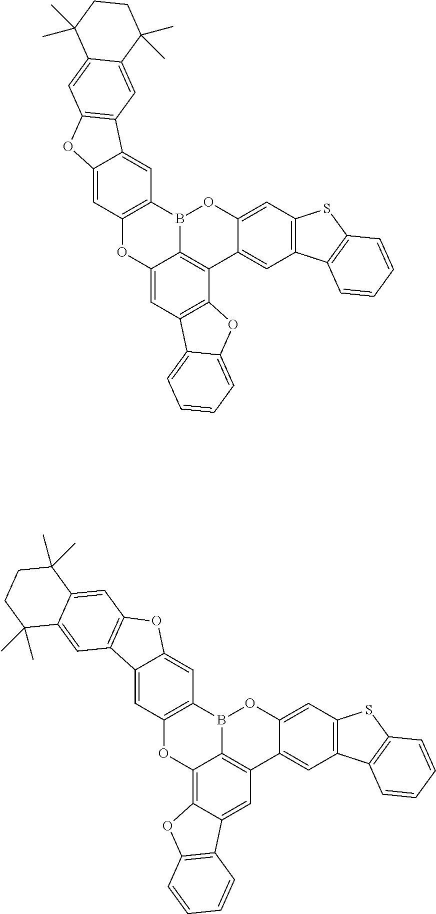 [SMILES: CC1(C)CCC(C)(C)c2cc3c(cc21)oc1cc2c(cc13)B1Oc3cc4sc5ccccc5c4cc3-c3c1c(cc1c3oc3ccccc31)O2 ; CC1(C)CCC(C)(C)c2cc3c(cc21)oc1cc2c(cc13)Oc1c3c(cc4c1oc1ccccc14)-c1cc4c(cc1OB23)sc1ccccc14]

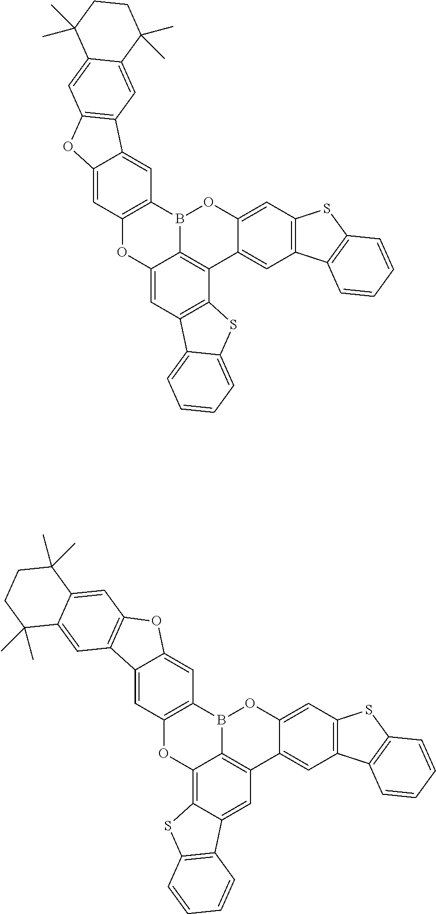 [SMILES: CC1(C)CCC(C)(C)c2cc3c(cc21)oc1cc2c(cc13)B1Oc3cc4sc5ccccc5c4cc3-c3c1c(cc1c3sc3ccccc31)O2 ; CC1(C)CCC(C)(C)c2cc3c(cc21)oc1cc2c(cc13)Oc1c3c(cc4c1sc1ccccc14)-c1cc4c(cc1OB23)sc1ccccc14]

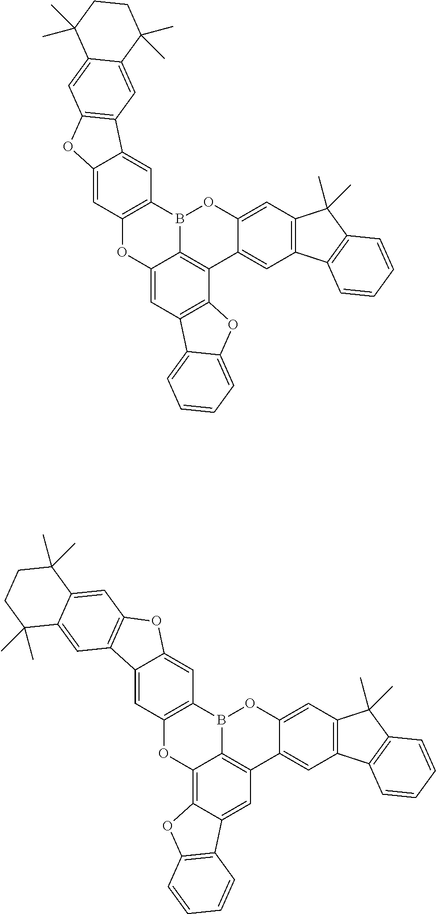 [SMILES: CC1(C)CCC(C)(C)c2cc3c(cc21)oc1cc2c(cc13)B1Oc3cc4c(cc3-c3c1c(cc1c3oc3ccccc31)O2)-c1ccccc1C4(C)C ; CC1(C)CCC(C)(C)c2cc3c(cc21)oc1cc2c(cc13)Oc1c3c(cc4c1oc1ccccc14)-c1cc4c(cc1OB23)C(C)(C)c1ccccc1-4]

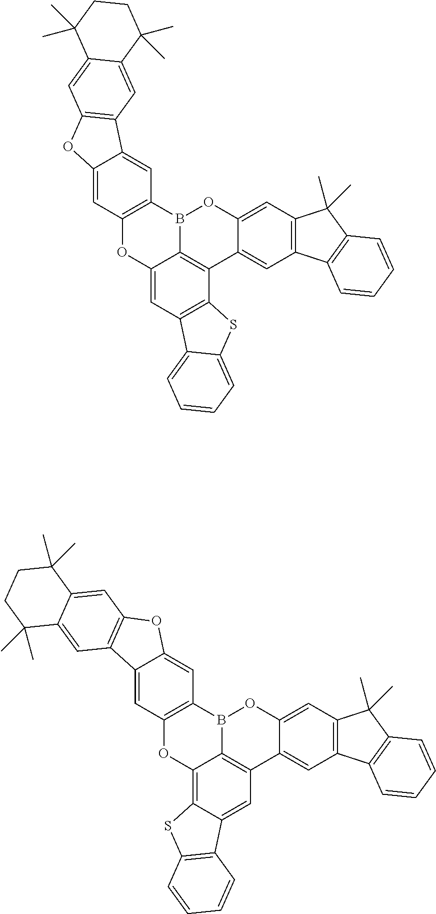 [SMILES: CC1(C)CCC(C)(C)c2cc3c(cc21)oc1cc2c(cc13)B1Oc3cc4c(cc3-c3c1c(cc1c3sc3ccccc31)O2)-c1ccccc1C4(C)C ; CC1(C)CCC(C)(C)c2cc3c(cc21)oc1cc2c(cc13)Oc1c3c(cc4c1sc1ccccc14)-c1cc4c(cc1OB23)C(C)(C)c1ccccc1-4]

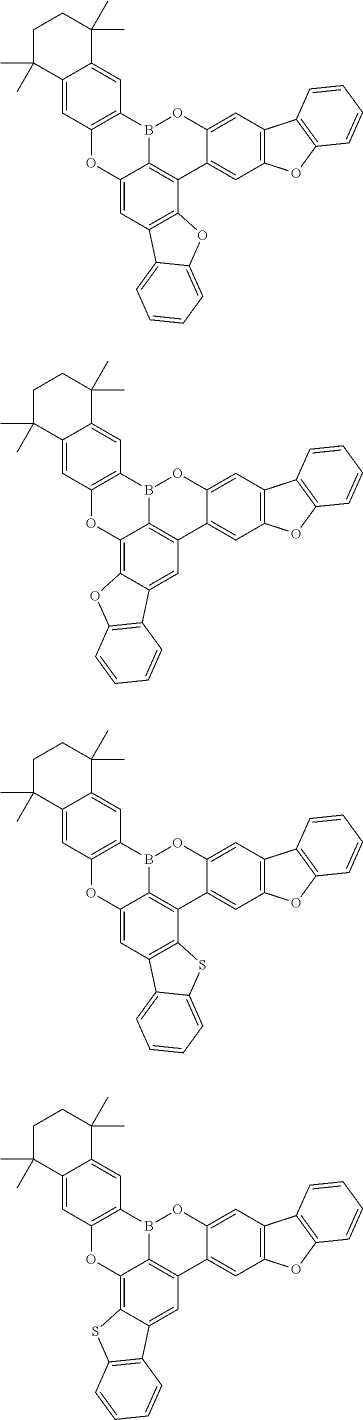 [SMILES: CC1(C)CCC(C)(C)c2cc3c(cc21)Oc1cc2c(oc4ccccc42)c2c1B3Oc1cc3c(cc1-2)oc1ccccc13 ; CC1(C)CCC(C)(C)c2cc3c(cc21)Oc1c2c(cc4c1oc1ccccc14)-c1cc4oc5ccccc5c4cc1OB32 ; CC1(C)CCC(C)(C)c2cc3c(cc21)Oc1cc2c(sc4ccccc42)c2c1B3Oc1cc3c(cc1-2)oc1ccccc13 ; CC1(C)CCC(C)(C)c2cc3c(cc21)Oc1c2c(cc4c1sc1ccccc14)-c1cc4oc5ccccc5c4cc1OB32]

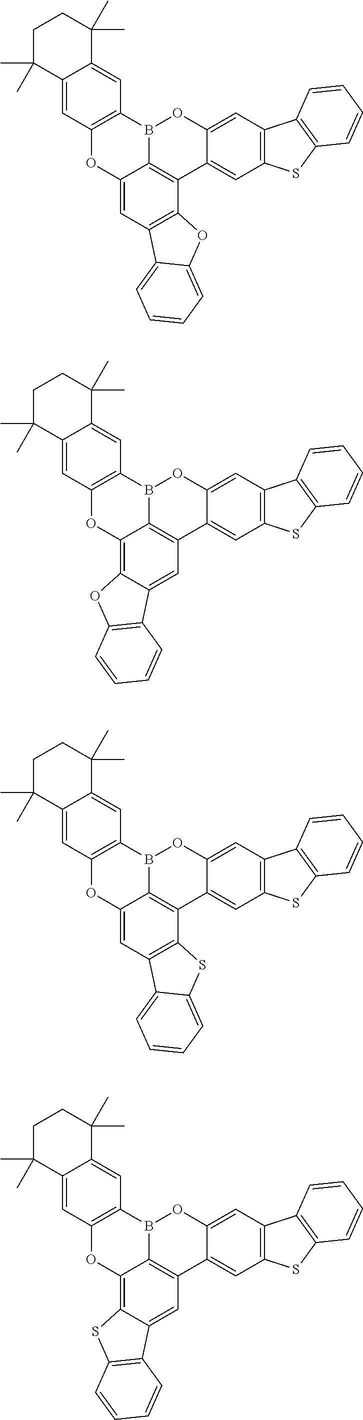 [SMILES: CC1(C)CCC(C)(C)c2cc3c(cc21)Oc1cc2c(oc4ccccc42)c2c1B3Oc1cc3c(cc1-2)sc1ccccc13 ; CC1(C)CCC(C)(C)c2cc3c(cc21)Oc1c2c(cc4c1oc1ccccc14)-c1cc4sc5ccccc5c4cc1OB32 ; CC1(C)CCC(C)(C)c2cc3c(cc21)Oc1cc2c(sc4ccccc42)c2c1B3Oc1cc3c(cc1-2)sc1ccccc13 ; CC1(C)CCC(C)(C)c2cc3c(cc21)Oc1c2c(cc4c1sc1ccccc14)-c1cc4sc5ccccc5c4cc1OB32]

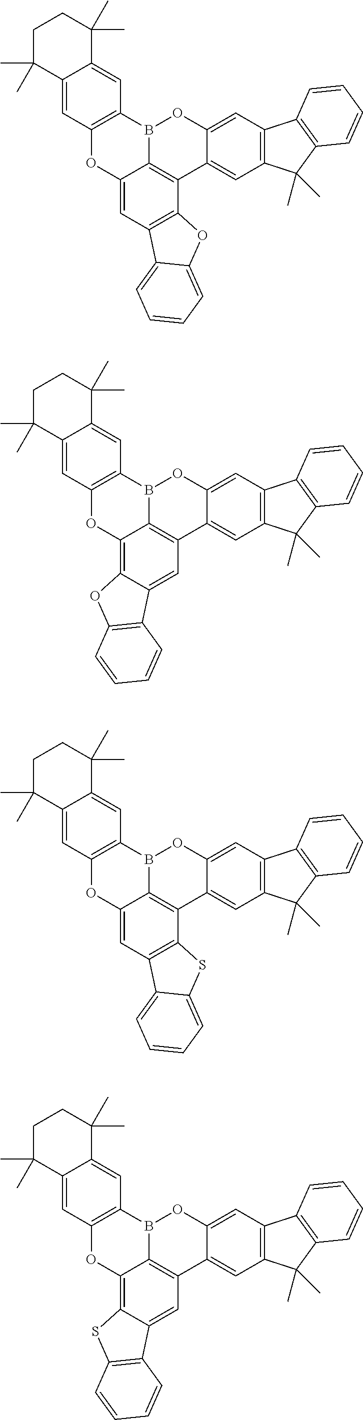 [SMILES: CC1(C)CCC(C)(C)c2cc3c(cc21)Oc1cc2c(oc4ccccc42)c2c1B3Oc1cc3c(cc1-2)C(C)(C)c1ccccc1-3 ; CC1(C)CCC(C)(C)c2cc3c(cc21)Oc1c2c(cc4c1oc1ccccc14)-c1cc4c(cc1OB32)-c1ccccc1C4(C)C ; CC1(C)CCC(C)(C)c2cc3c(cc21)Oc1cc2c(sc4ccccc42)c2c1B3Oc1cc3c(cc1-2)C(C)(C)c1ccccc1-3 ; CC1(C)CCC(C)(C)c2cc3c(cc21)Oc1c2c(cc4c1sc1ccccc14)-c1cc4c(cc1OB32)-c1ccccc1C4(C)C]

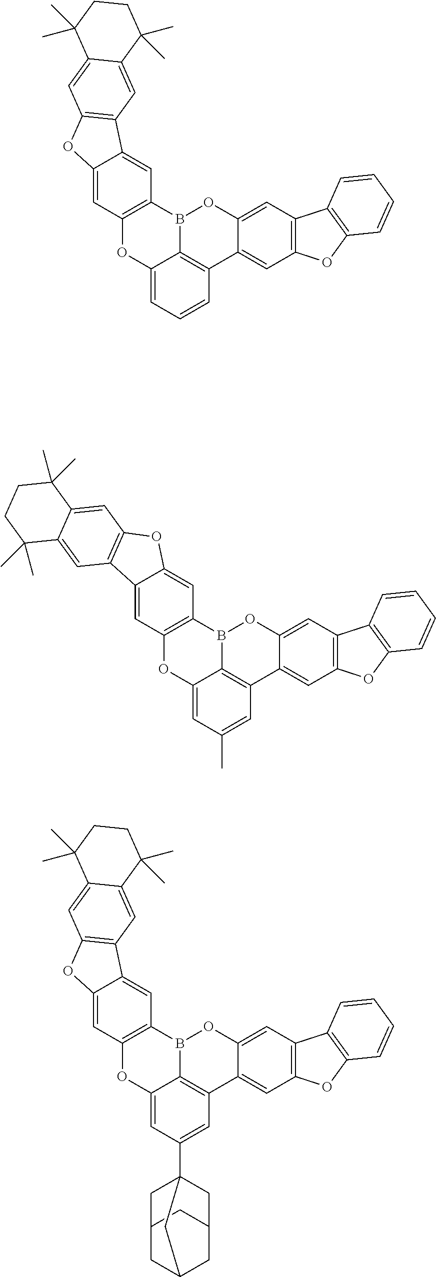 [SMILES: CC1(C)CCC(C)(C)c2cc3c(cc21)oc1cc2c(cc13)B1Oc3cc4c(cc3-c3cccc(c31)O2)oc1ccccc14 ; Cc1cc2c3c(c1)-c1cc4oc5ccccc5c4cc1OB3c1cc3oc4cc5c(cc4c3cc1O2)C(C)(C)CCC5(C)C ; CC1(C)CCC(C)(C)c2cc3c(cc21)oc1cc2c(cc13)B1Oc3cc4c(cc3-c3cc(C56CC7CC(CC(C7)C5)C6)cc(c31)O2)oc1ccccc14]

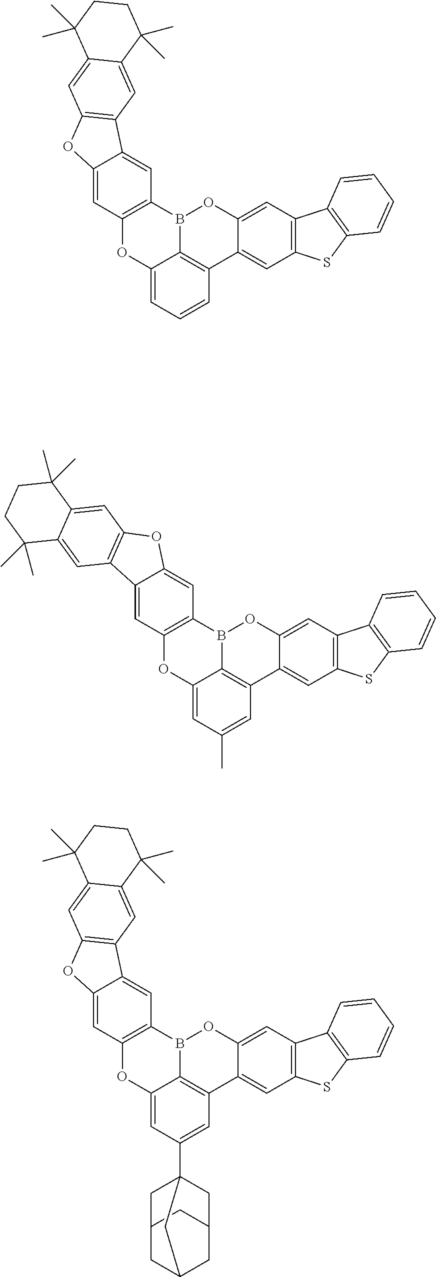 [SMILES: CC1(C)CCC(C)(C)c2cc3c(cc21)oc1cc2c(cc13)B1Oc3cc4c(cc3-c3cccc(c31)O2)sc1ccccc14 ; Cc1cc2c3c(c1)-c1cc4sc5ccccc5c4cc1OB3c1cc3oc4cc5c(cc4c3cc1O2)C(C)(C)CCC5(C)C ; CC1(C)CCC(C)(C)c2cc3c(cc21)oc1cc2c(cc13)B1Oc3cc4c(cc3-c3cc(C56CC7CC(CC(C7)C5)C6)cc(c31)O2)sc1ccccc14]

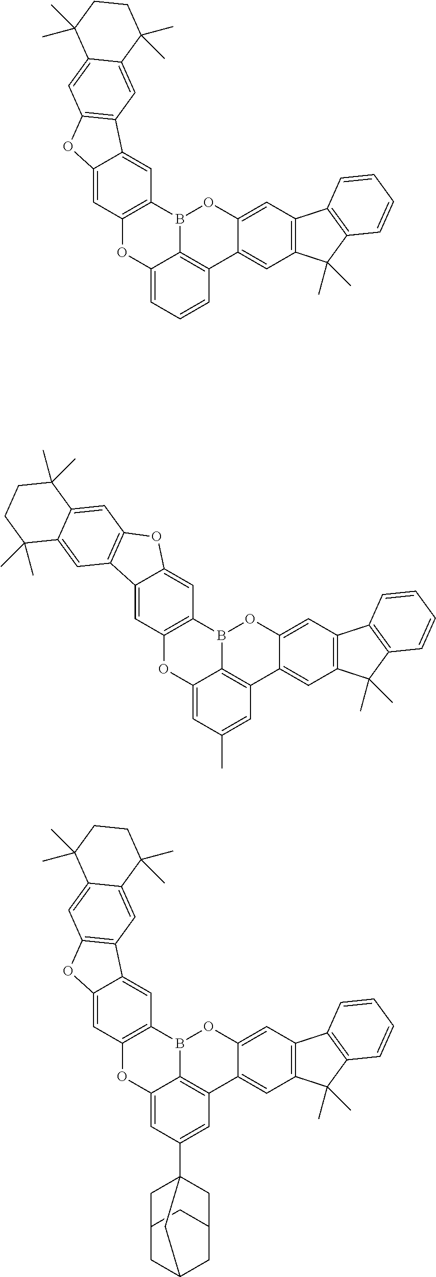 [SMILES: CC1(C)CCC(C)(C)c2cc3c(cc21)oc1cc2c(cc13)B1Oc3cc4c(cc3-c3cccc(c31)O2)C(C)(C)c1ccccc1-4 ; Cc1cc2c3c(c1)-c1cc4c(cc1OB3c1cc3oc5cc6c(cc5c3cc1O2)C(C)(C)CCC6(C)C)-c1ccccc1C4(C)C ; CC1(C)CCC(C)(C)c2cc3c(cc21)oc1cc2c(cc13)B1Oc3cc4c(cc3-c3cc(C56CC7CC(CC(C7)C5)C6)cc(c31)O2)C(C)(C)c1ccccc1-4]

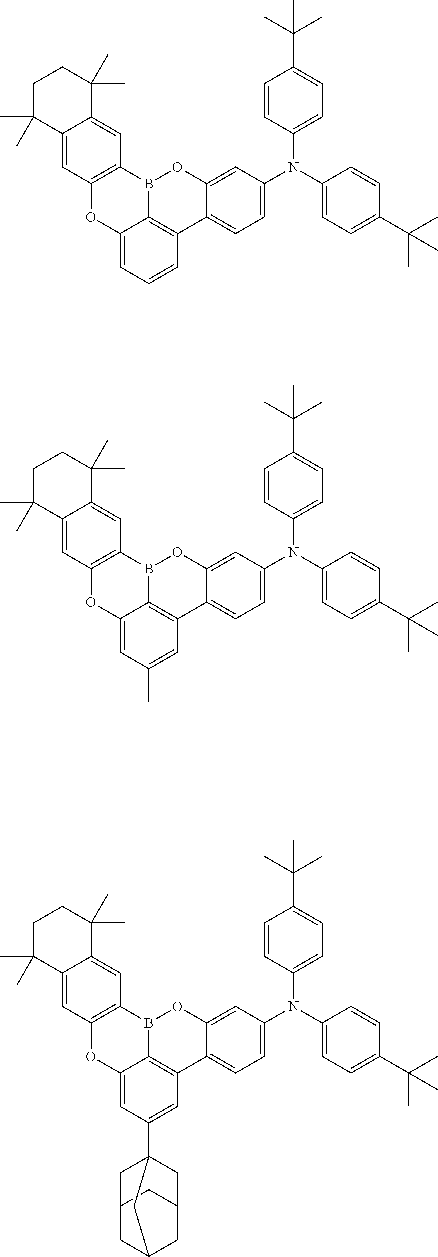

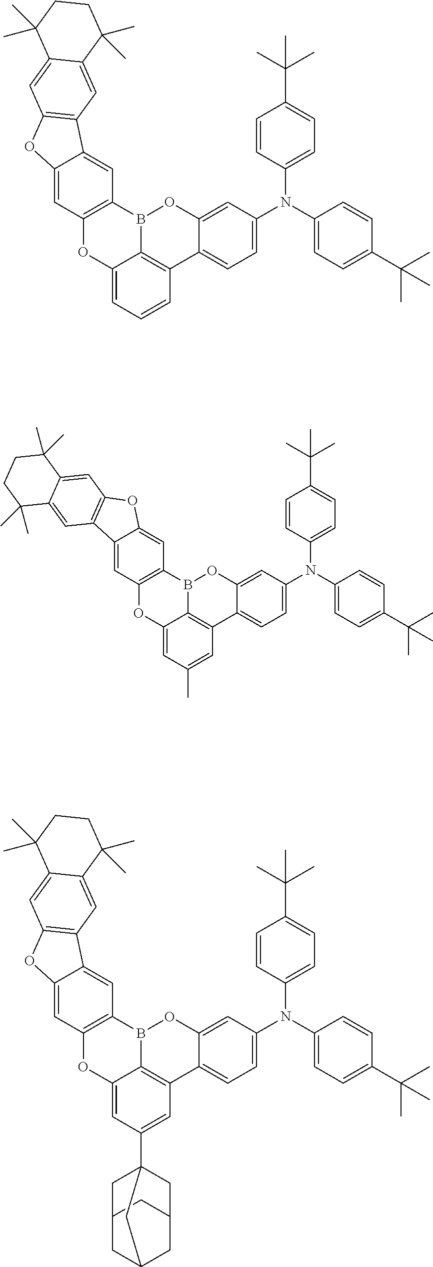

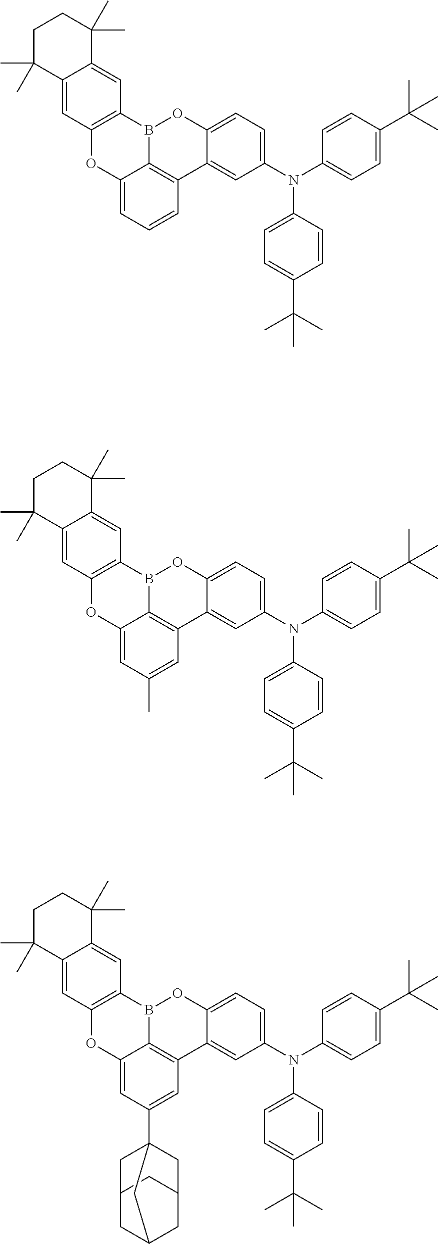

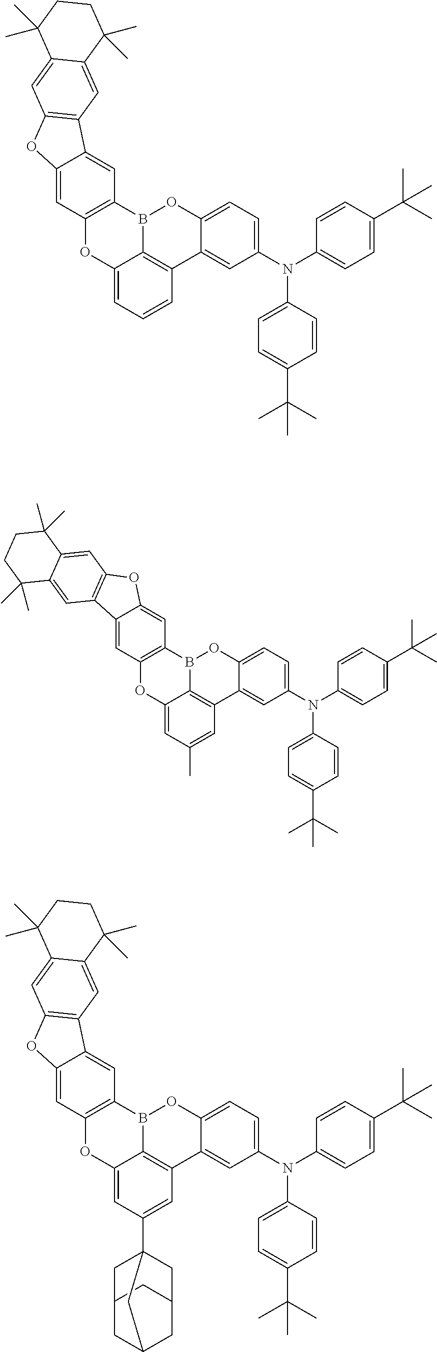

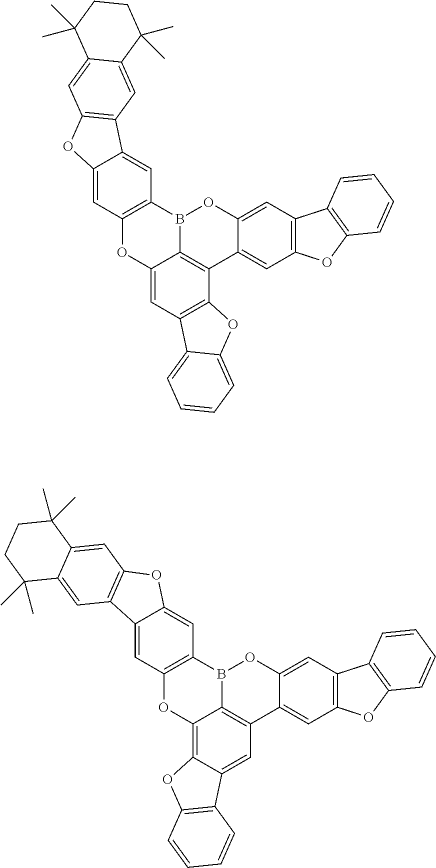 [SMILES: CC1(C)CCC(C)(C)c2cc3c(cc21)oc1cc2c(cc13)B1Oc3cc4c(cc3-c3c1c(cc1c3oc3ccccc31)O2)oc1ccccc14 ; CC1(C)CCC(C)(C)c2cc3c(cc21)oc1cc2c(cc13)Oc1c3c(cc4c1oc1ccccc14)-c1cc4oc5ccccc5c4cc1OB23]

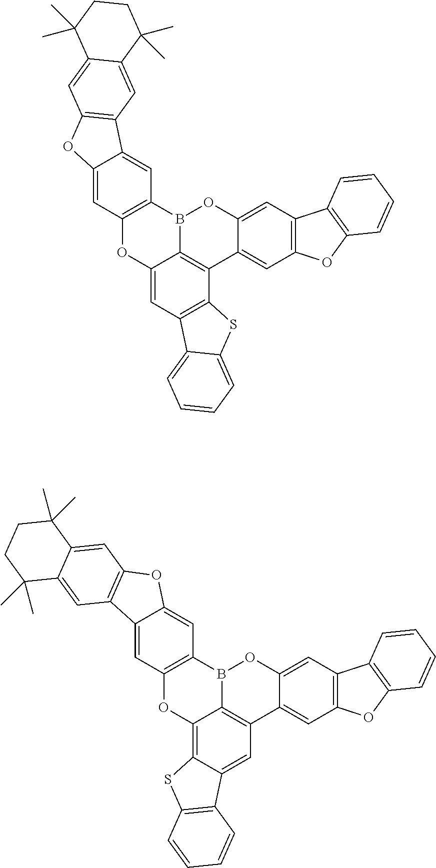 [SMILES: CC1(C)CCC(C)(C)c2cc3c(cc21)oc1cc2c(cc13)B1Oc3cc4c(cc3-c3c1c(cc1c3sc3ccccc31)O2)oc1ccccc14 ; CC1(C)CCC(C)(C)c2cc3c(cc21)oc1cc2c(cc13)Oc1c3c(cc4c1sc1ccccc14)-c1cc4oc5ccccc5c4cc1OB23]

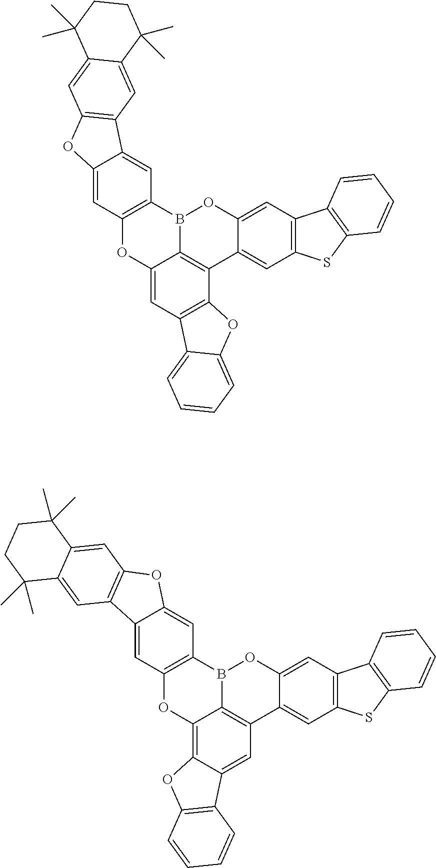 [SMILES: CC1(C)CCC(C)(C)c2cc3c(cc21)oc1cc2c(cc13)B1Oc3cc4c(cc3-c3c1c(cc1c3oc3ccccc31)O2)sc1ccccc14 ; CC1(C)CCC(C)(C)c2cc3c(cc21)oc1cc2c(cc13)Oc1c3c(cc4c1oc1ccccc14)-c1cc4sc5ccccc5c4cc1OB23]

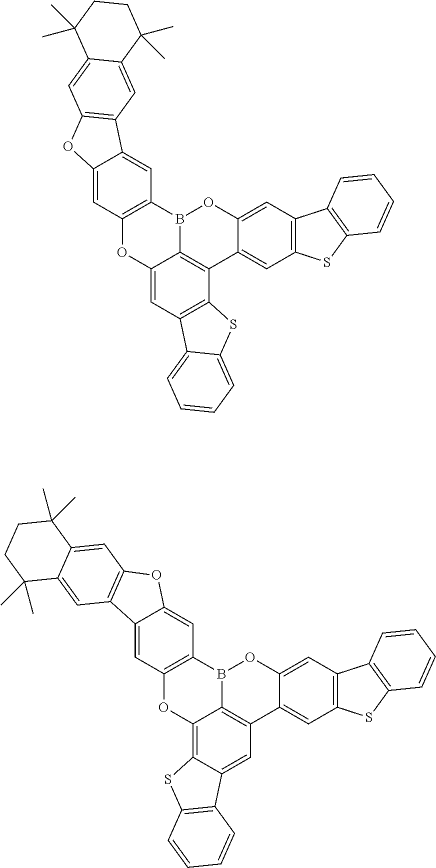 [SMILES: CC1(C)CCC(C)(C)c2cc3c(cc21)oc1cc2c(cc13)B1Oc3cc4c(cc3-c3c1c(cc1c3sc3ccccc31)O2)sc1ccccc14 ; CC1(C)CCC(C)(C)c2cc3c(cc21)oc1cc2c(cc13)Oc1c3c(cc4c1sc1ccccc14)-c1cc4sc5ccccc5c4cc1OB23]

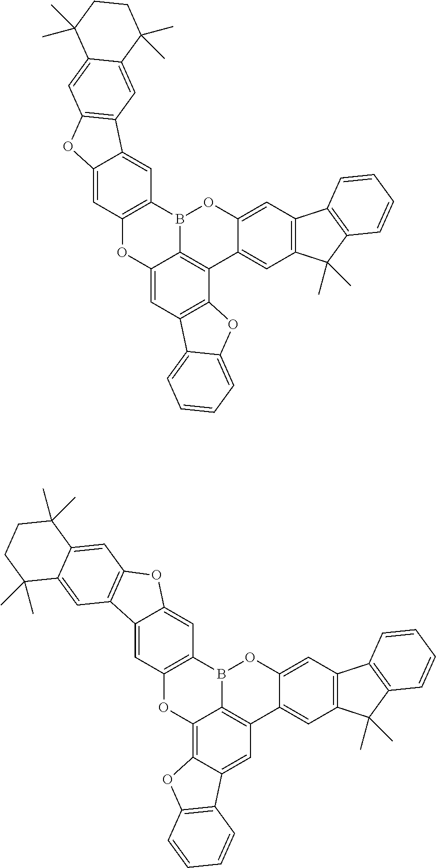 [SMILES: CC1(C)CCC(C)(C)c2cc3c(cc21)oc1cc2c(cc13)B1Oc3cc4c(cc3-c3c1c(cc1c3oc3ccccc31)O2)C(C)(C)c1ccccc1-4 ; CC1(C)CCC(C)(C)c2cc3c(cc21)oc1cc2c(cc13)Oc1c3c(cc4c1oc1ccccc14)-c1cc4c(cc1OB23)-c1ccccc1C4(C)C]

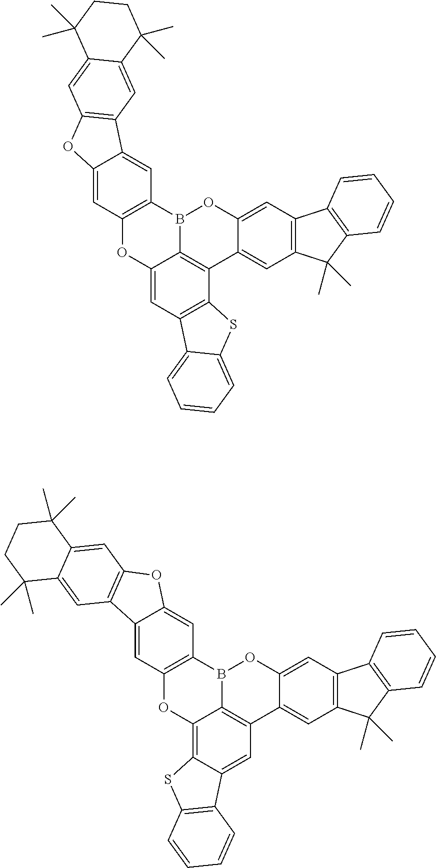 [SMILES: CC1(C)CCC(C)(C)c2cc3c(cc21)oc1cc2c(cc13)B1Oc3cc4c(cc3-c3c1c(cc1c3sc3ccccc31)O2)C(C)(C)c1ccccc1-4 ; CC1(C)CCC(C)(C)c2cc3c(cc21)oc1cc2c(cc13)Oc1c3c(cc4c1sc1ccccc14)-c1cc4c(cc1OB23)-c1ccccc1C4(C)C]

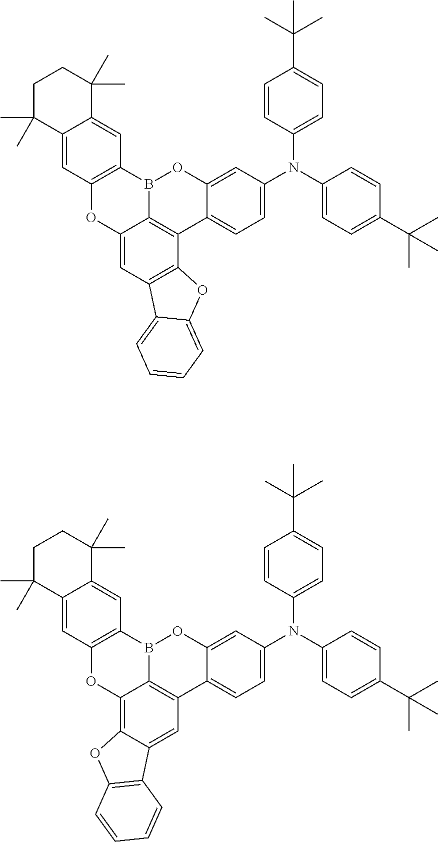

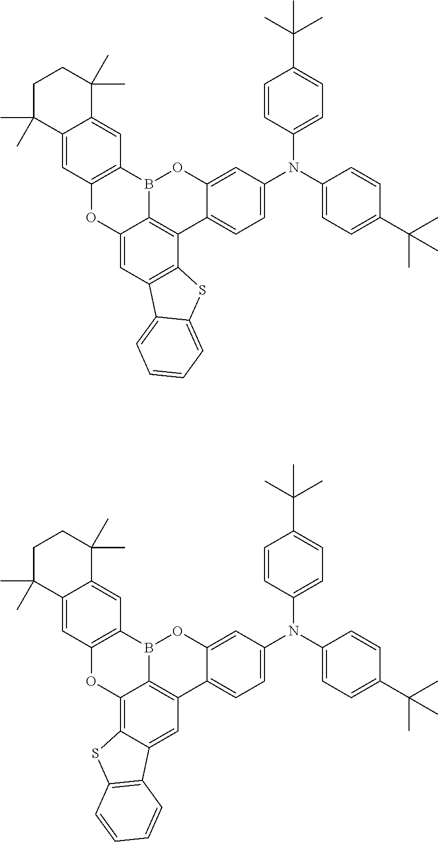

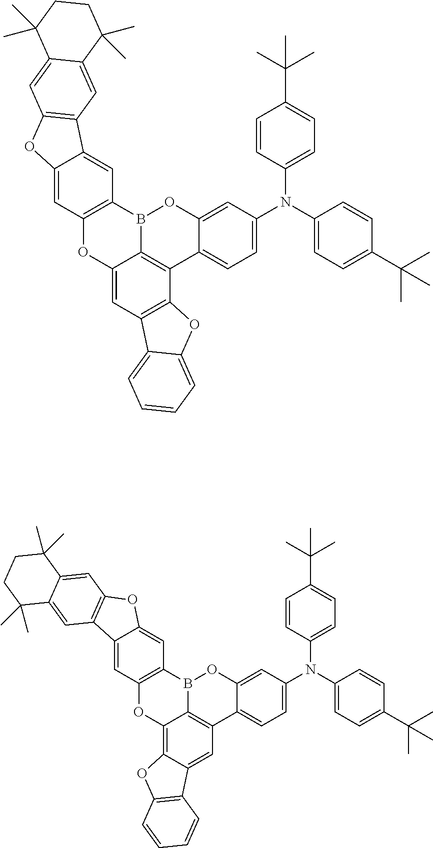

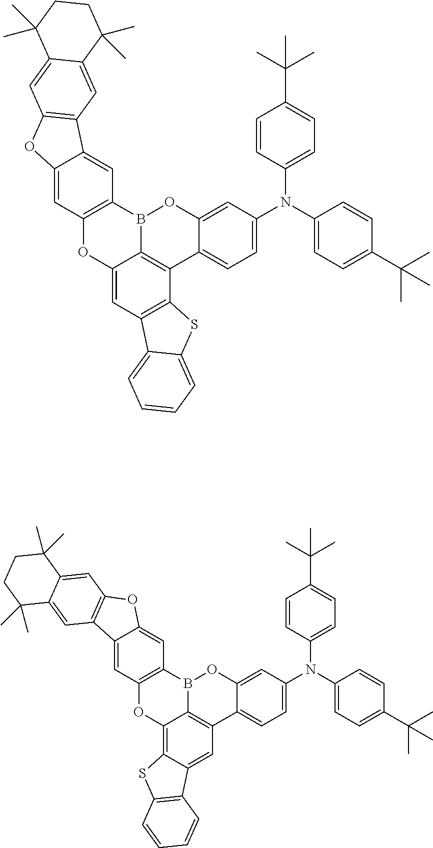

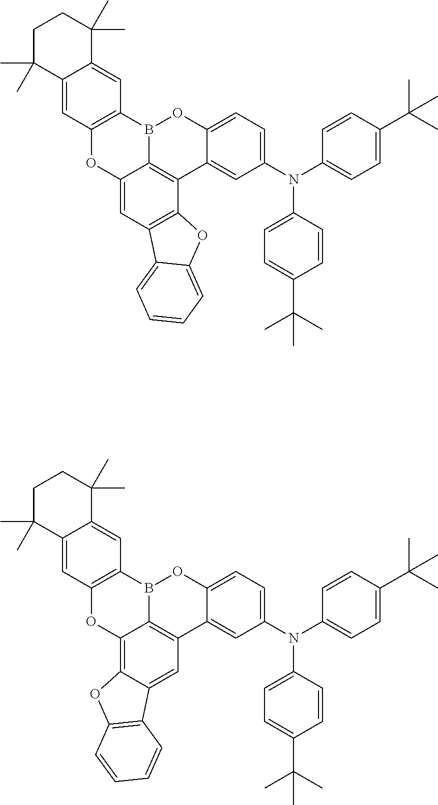

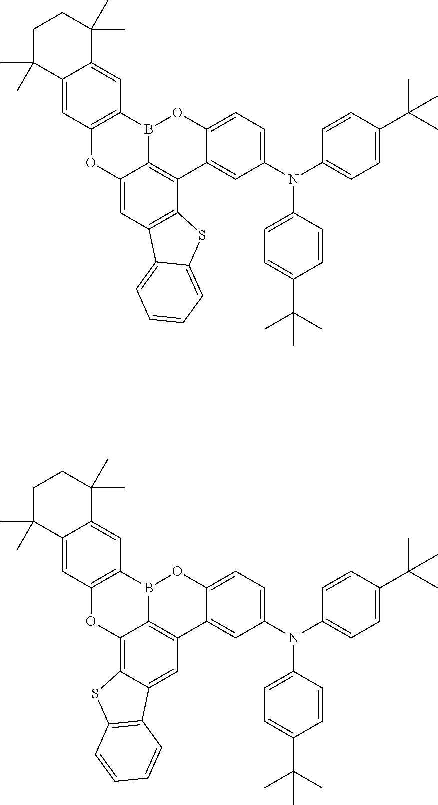

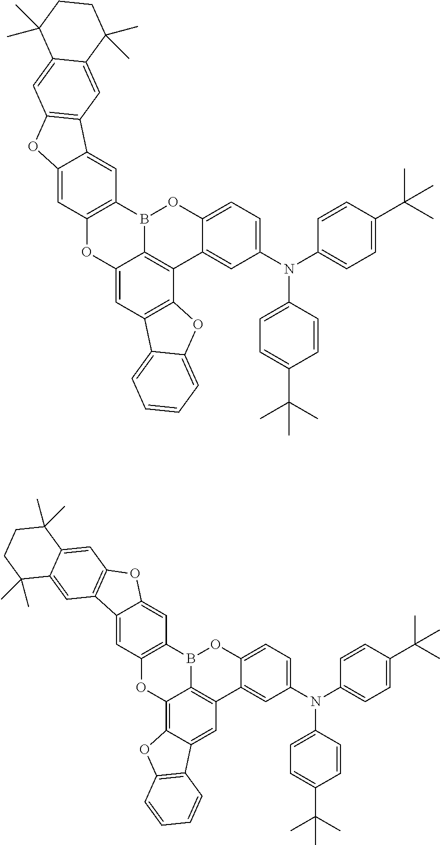

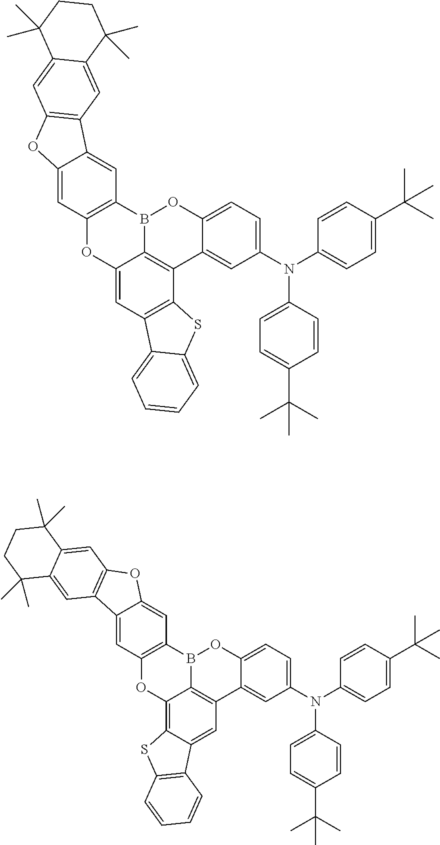

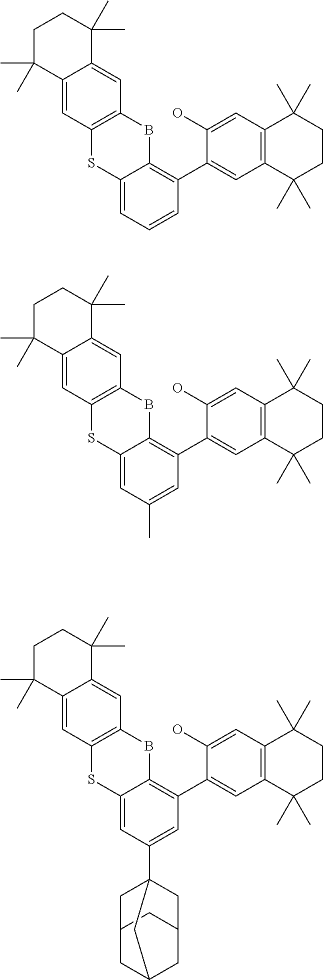

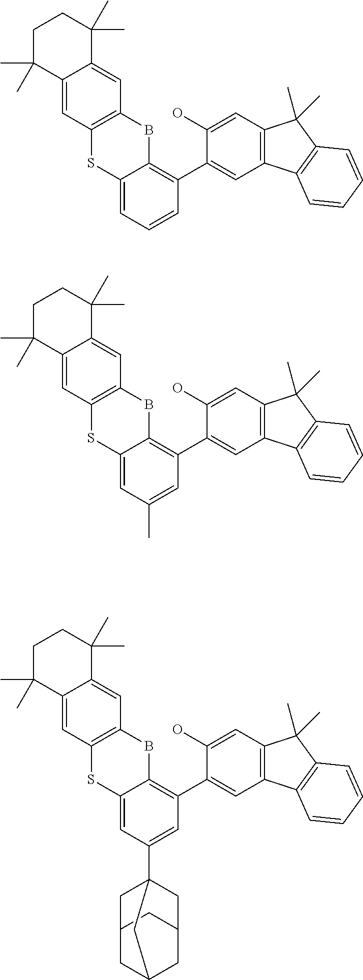

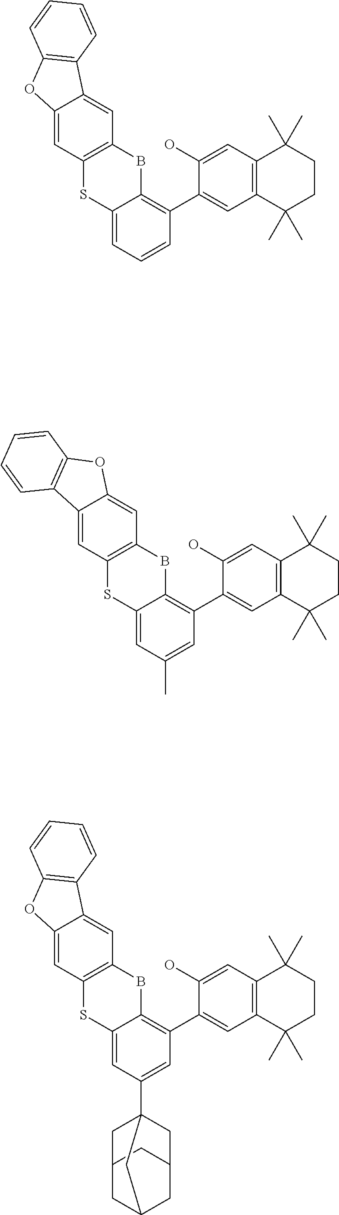

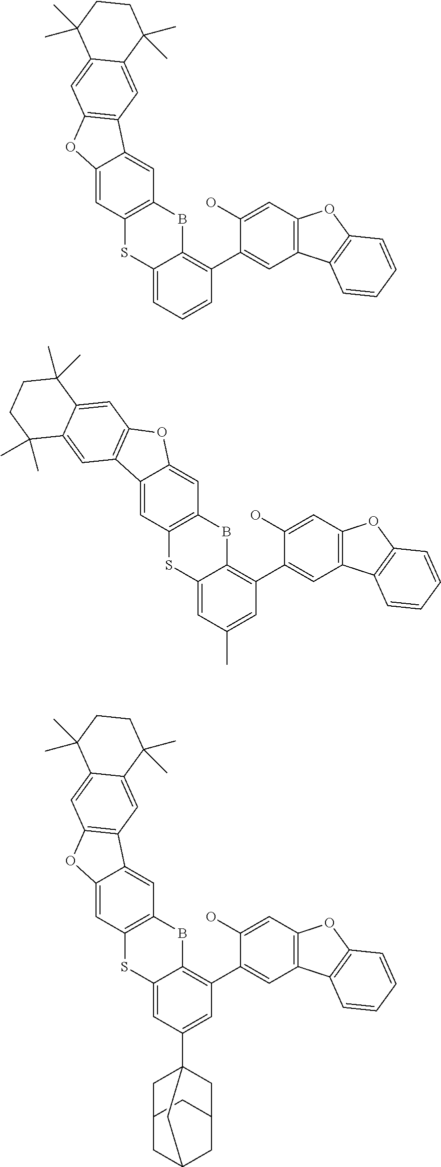

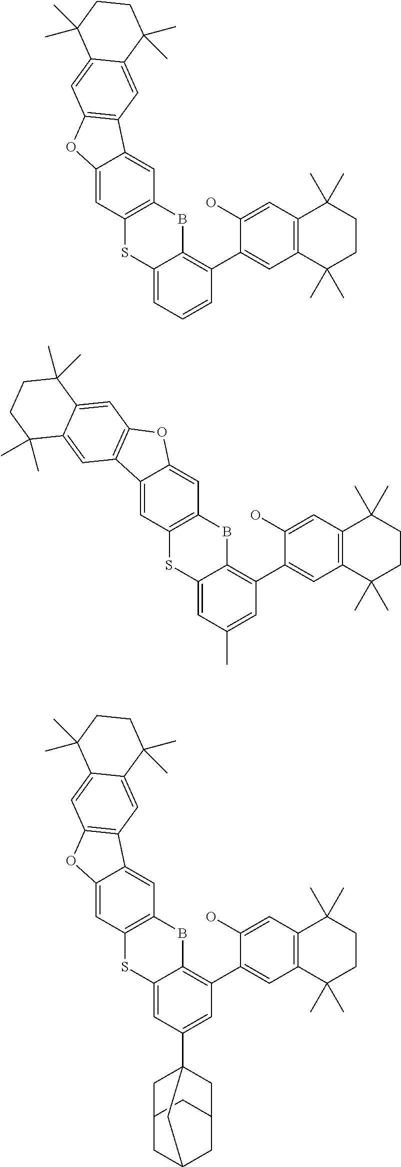

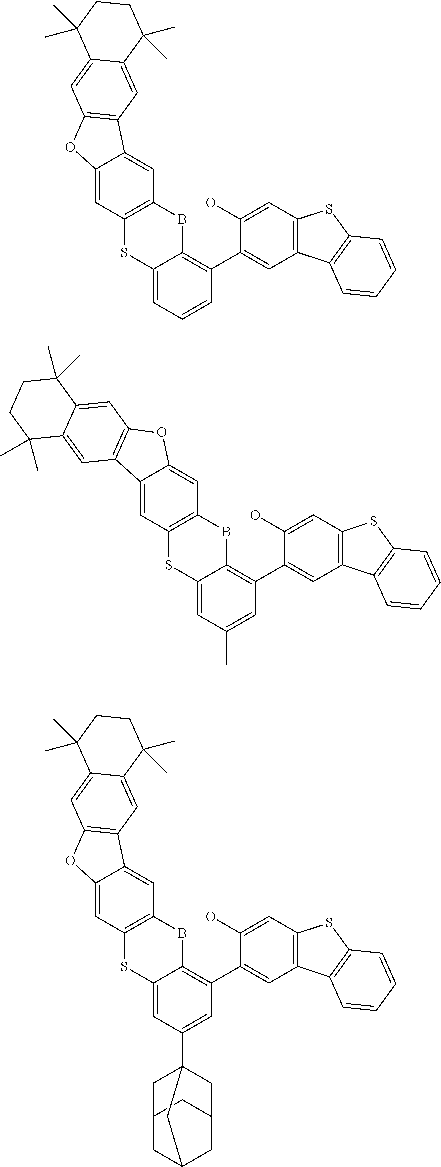

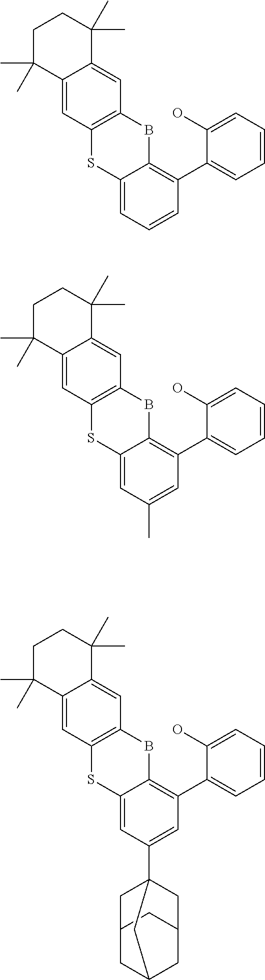

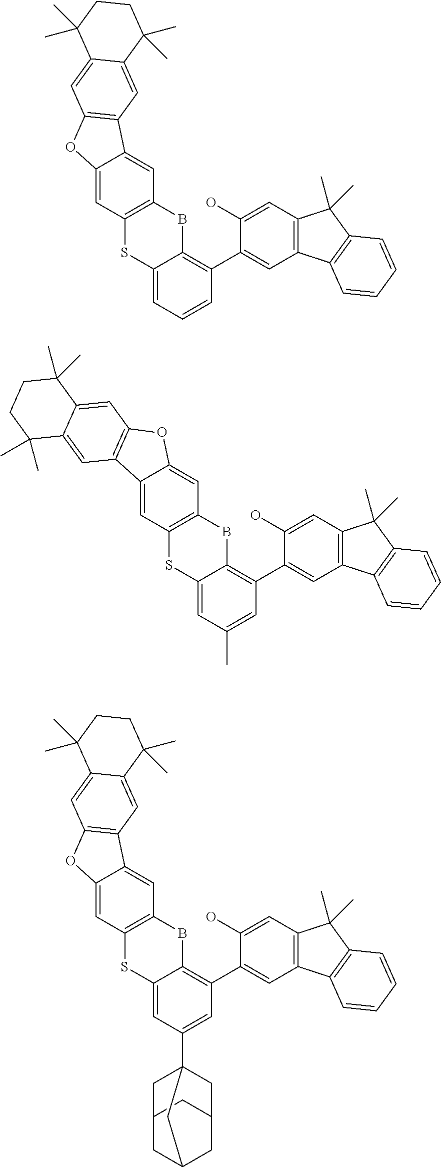

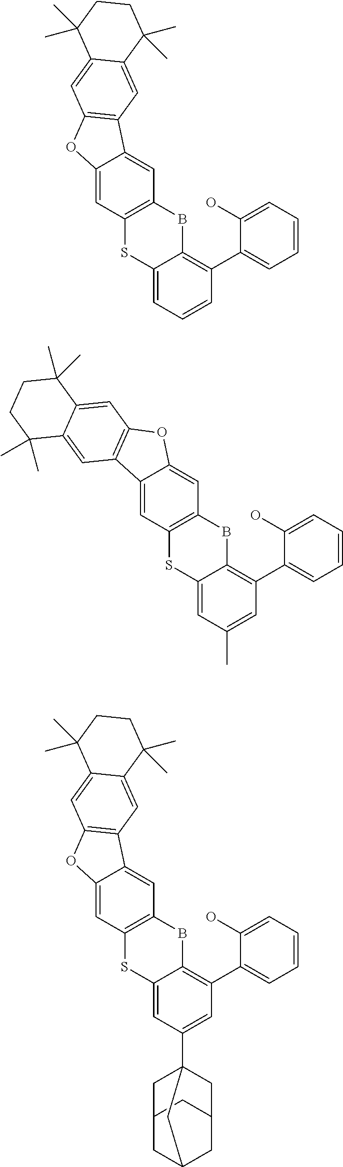

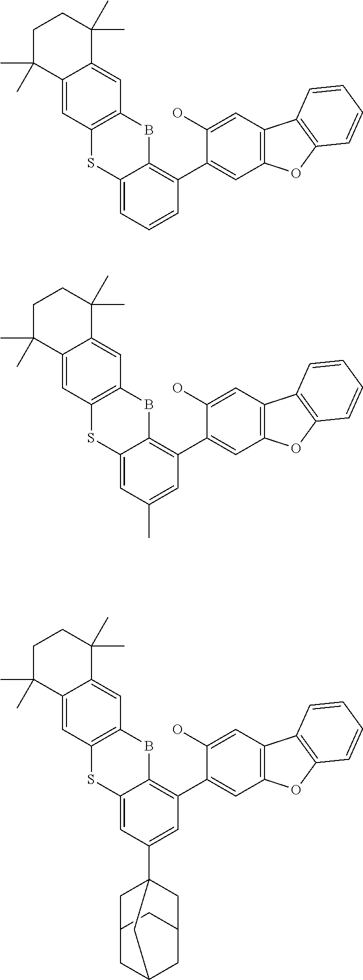

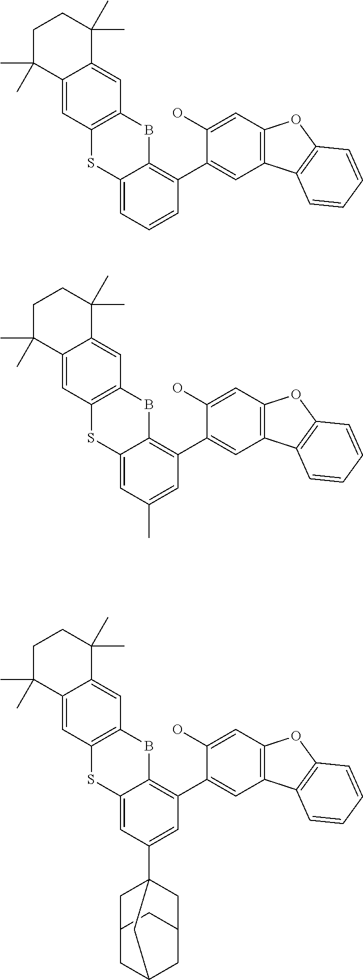

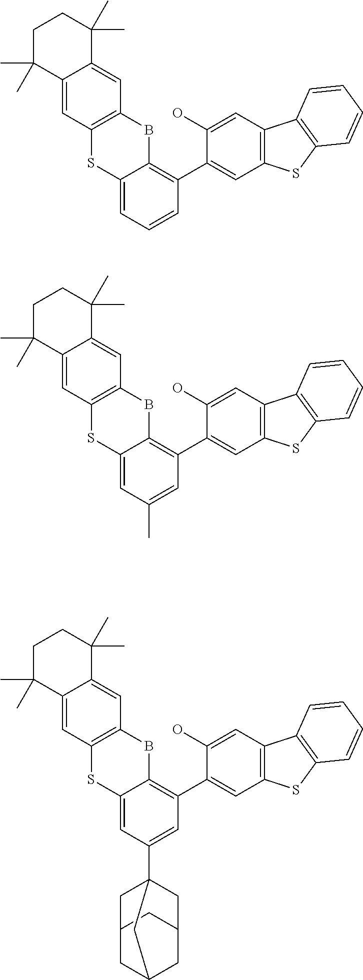

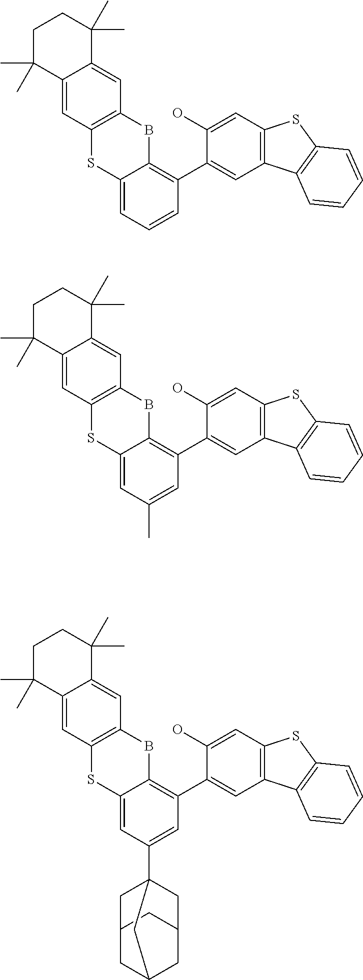

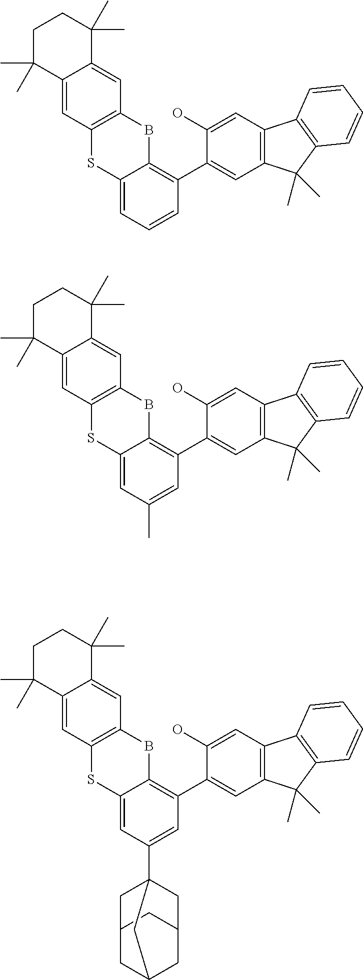

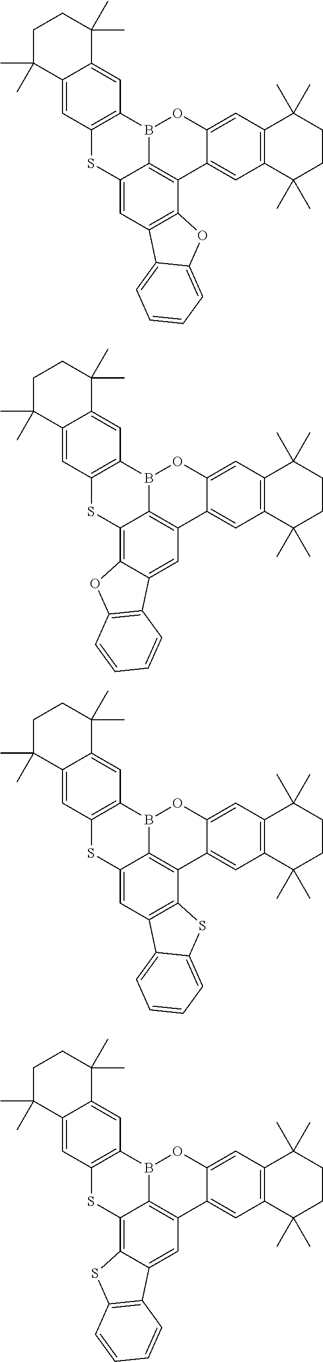

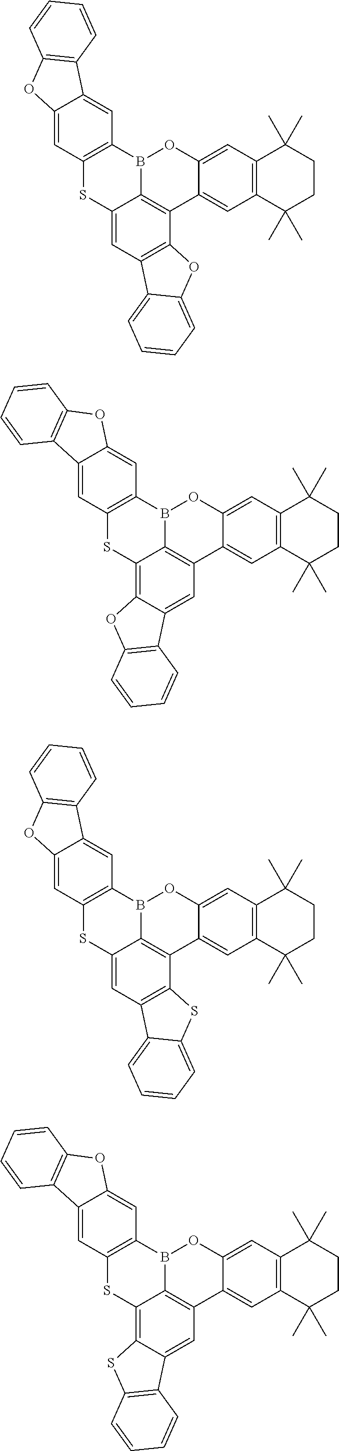 [SMILES: CC1(C)CCC(C)(C)c2cc3c(cc21)OB1c2cc4c(cc2Sc2cc5c(oc6ccccc65)c-3c21)oc1ccccc14 ; CC1(C)CCC(C)(C)c2cc3c(cc21)OB1c2cc4oc5ccccc5c4cc2Sc2c1c-3cc1c2oc2ccccc21 ; CC1(C)CCC(C)(C)c2cc3c(cc21)OB1c2cc4c(cc2Sc2cc5c(sc6ccccc65)c-3c21)oc1ccccc14 ; CC1(C)CCC(C)(C)c2cc3c(cc21)OB1c2cc4oc5ccccc5c4cc2Sc2c1c-3cc1c2sc2ccccc21]

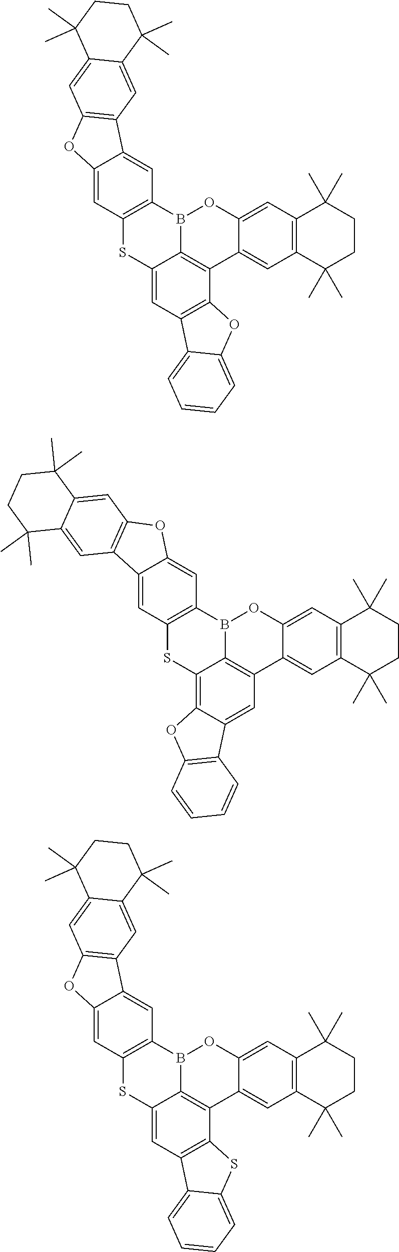 [SMILES: CC1(C)CCC(C)(C)c2cc3c(cc21)OB1c2cc4c(cc2Sc2cc5c(oc6ccccc65)c-3c21)oc1cc2c(cc14)C(C)(C)CCC2(C)C ; CC1(C)CCC(C)(C)c2cc3c(cc21)OB1c2cc4oc5cc6c(cc5c4cc2Sc2c1c-3cc1c2oc2ccccc21)C(C)(C)CCC6(C)C ; CC1(C)CCC(C)(C)c2cc3c(cc21)OB1c2cc4c(cc2Sc2cc5c(sc6ccccc65)c-3c21)oc1cc2c(cc14)C(C)(C)CCC2(C)C]

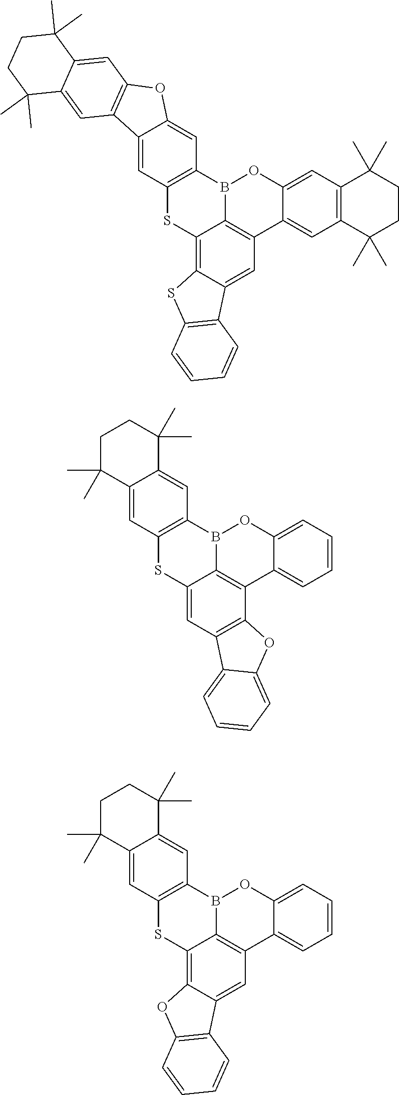

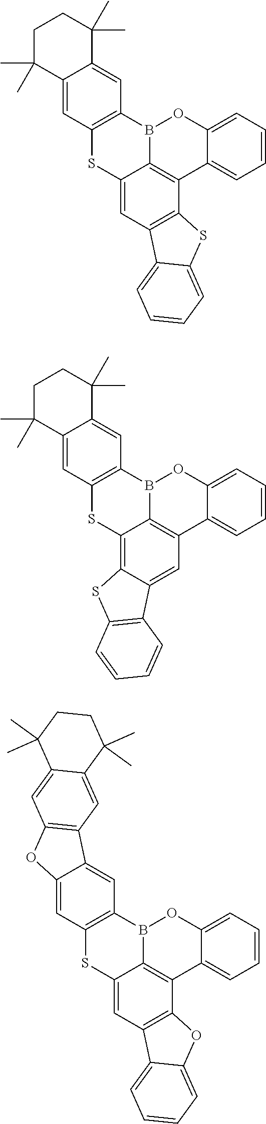

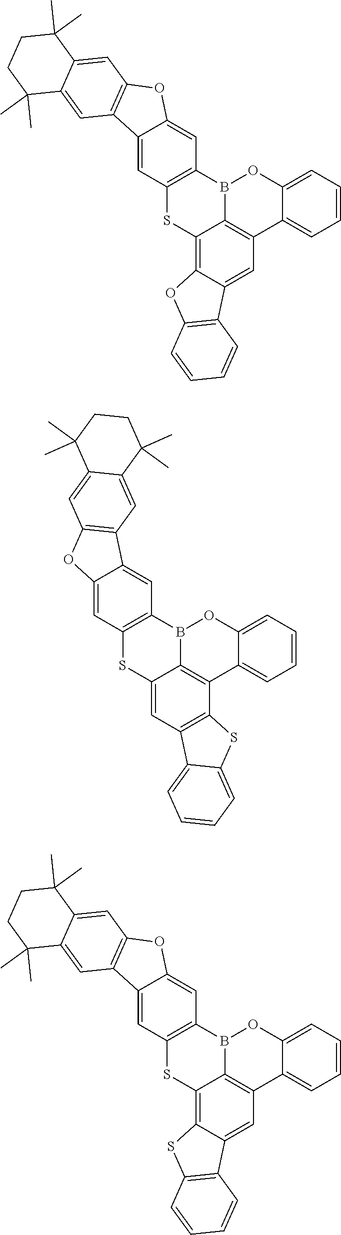 [SMILES: CC1(C)CCC(C)(C)c2cc3c(cc21)oc1cc2c(cc13)Sc1c3c(cc4c1oc1ccccc14)-c1ccccc1OB23 ; CC1(C)CCC(C)(C)c2cc3c(cc21)oc1cc2c(cc13)B1Oc3ccccc3-c3c1c(cc1c3sc3ccccc31)S2 ; CC1(C)CCC(C)(C)c2cc3c(cc21)oc1cc2c(cc13)Sc1c3c(cc4c1sc1ccccc14)-c1ccccc1OB23]

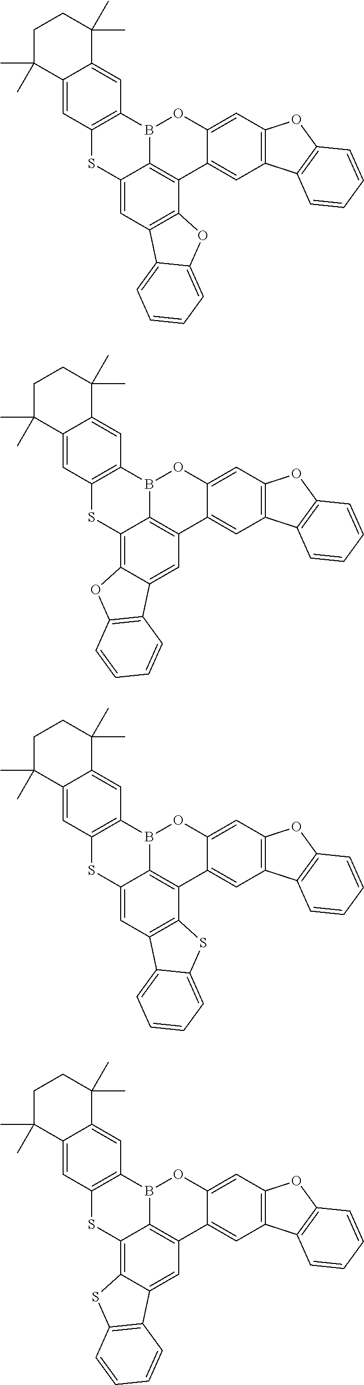

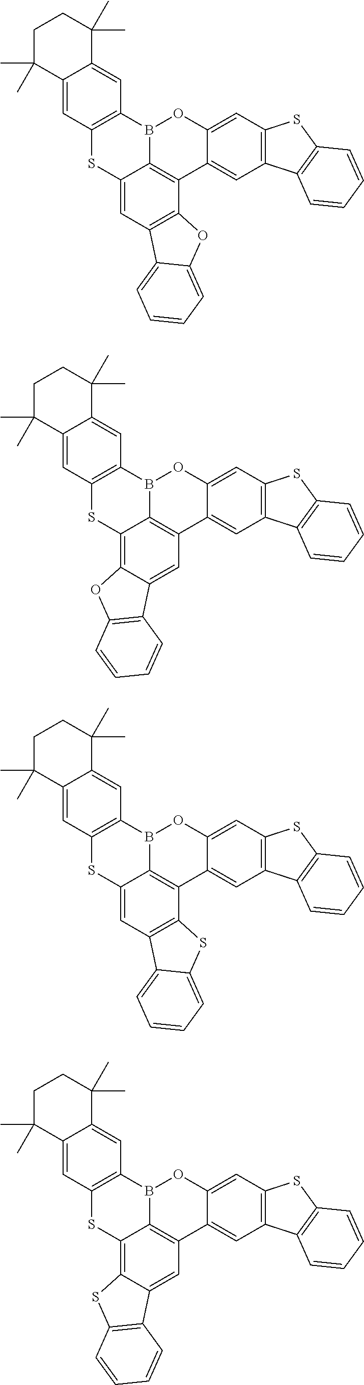

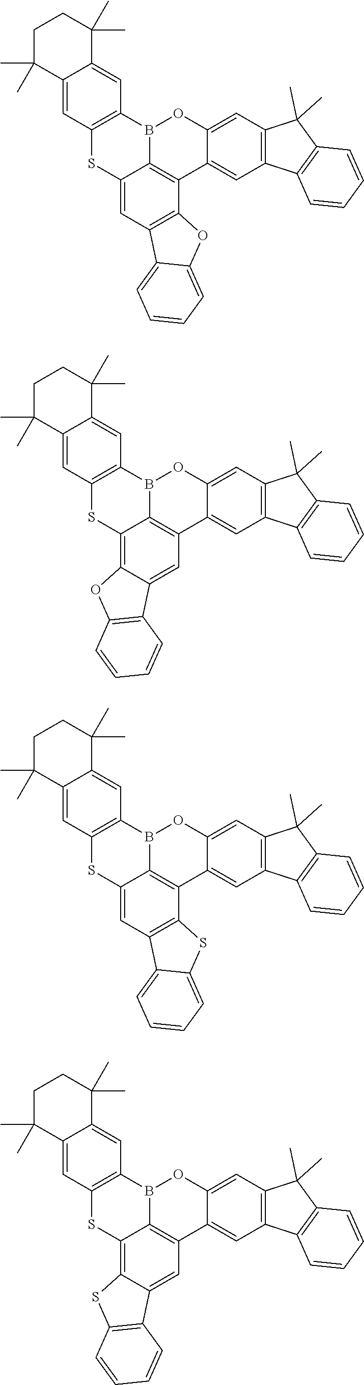

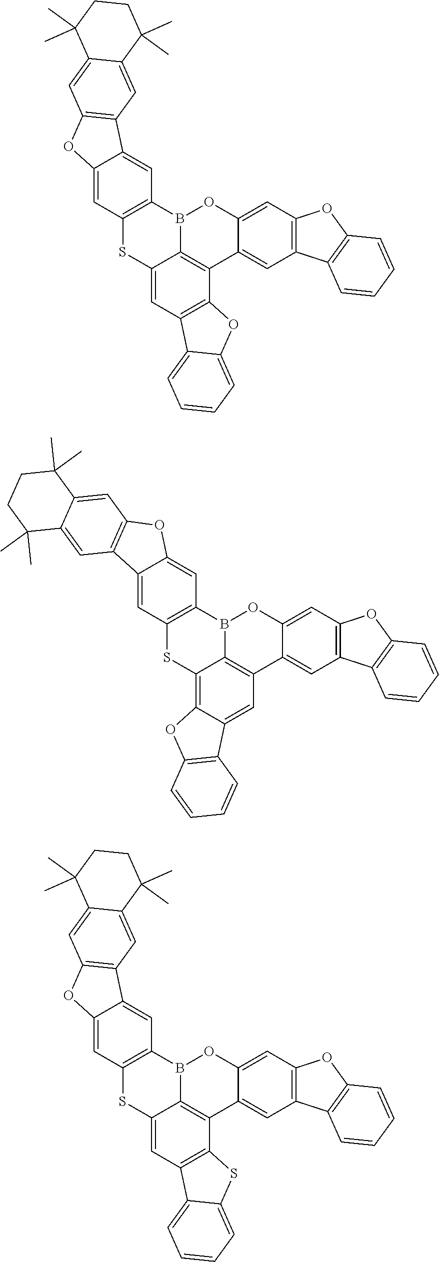 [SMILES: CC1(C)CCC(C)(C)c2cc3c(cc21)oc1cc2c(cc13)B1Oc3cc4oc5ccccc5c4cc3-c3c1c(cc1c3oc3ccccc31)S2 ; CC1(C)CCC(C)(C)c2cc3c(cc21)oc1cc2c(cc13)Sc1c3c(cc4c1oc1ccccc14)-c1cc4c(cc1OB23)oc1ccccc14 ; CC1(C)CCC(C)(C)c2cc3c(cc21)oc1cc2c(cc13)B1Oc3cc4oc5ccccc5c4cc3-c3c1c(cc1c3sc3ccccc31)S2]

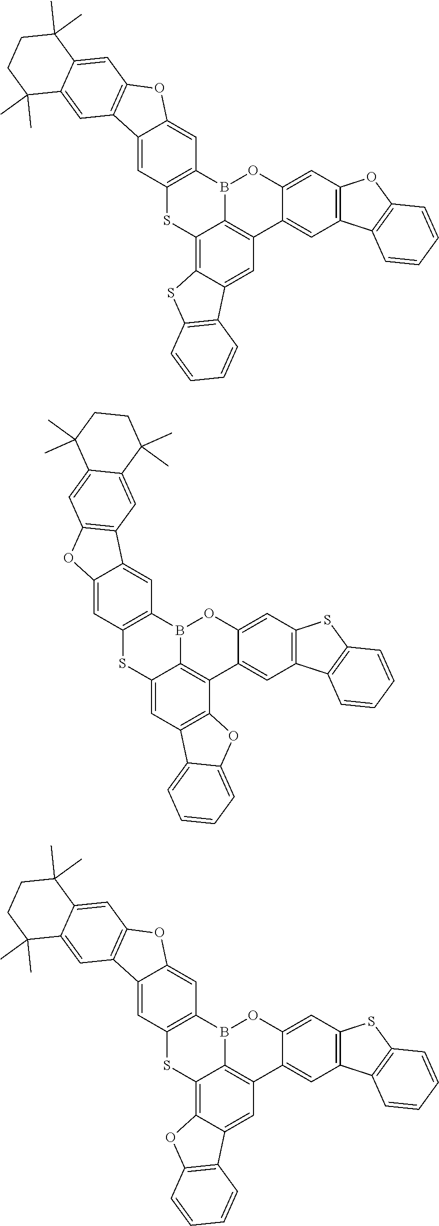 [SMILES: CC1(C)CCC(C)(C)c2cc3c(cc21)oc1cc2c(cc13)Sc1c3c(cc4c1sc1ccccc14)-c1cc4c(cc1OB23)oc1ccccc14 ; CC1(C)CCC(C)(C)c2cc3c(cc21)oc1cc2c(cc13)B1Oc3cc4sc5ccccc5c4cc3-c3c1c(cc1c3oc3ccccc31)S2 ; CC1(C)CCC(C)(C)c2cc3c(cc21)oc1cc2c(cc13)Sc1c3c(cc4c1oc1ccccc14)-c1cc4c(cc1OB23)sc1ccccc14]

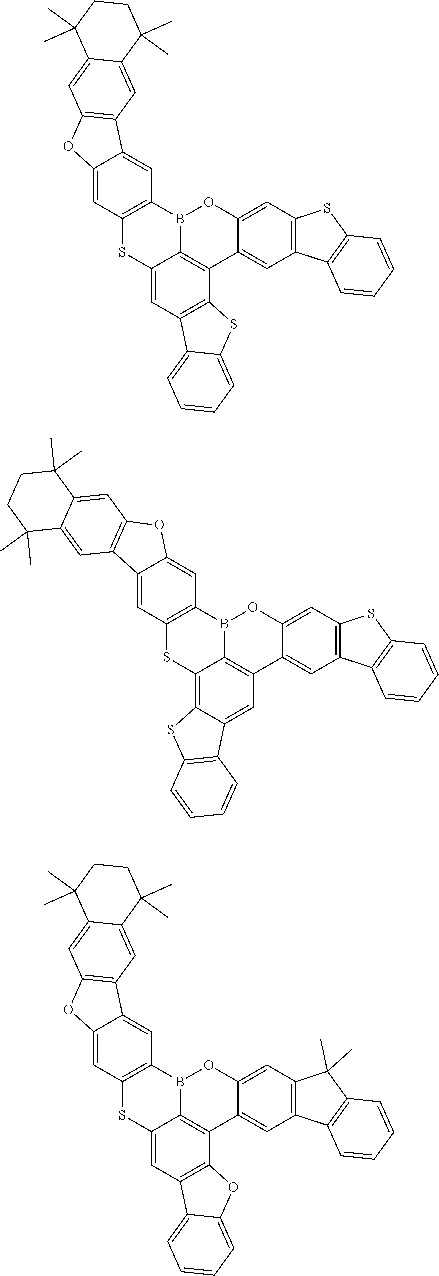 [SMILES: CC1(C)CCC(C)(C)c2cc3c(cc21)oc1cc2c(cc13)B1Oc3cc4sc5ccccc5c4cc3-c3c1c(cc1c3sc3ccccc31)S2 ; CC1(C)CCC(C)(C)c2cc3c(cc21)oc1cc2c(cc13)Sc1c3c(cc4c1sc1ccccc14)-c1cc4c(cc1OB23)sc1ccccc14 ; CC1(C)CCC(C)(C)c2cc3c(cc21)oc1cc2c(cc13)B1Oc3cc4c(cc3-c3c1c(cc1c3oc3ccccc31)S2)-c1ccccc1C4(C)C]

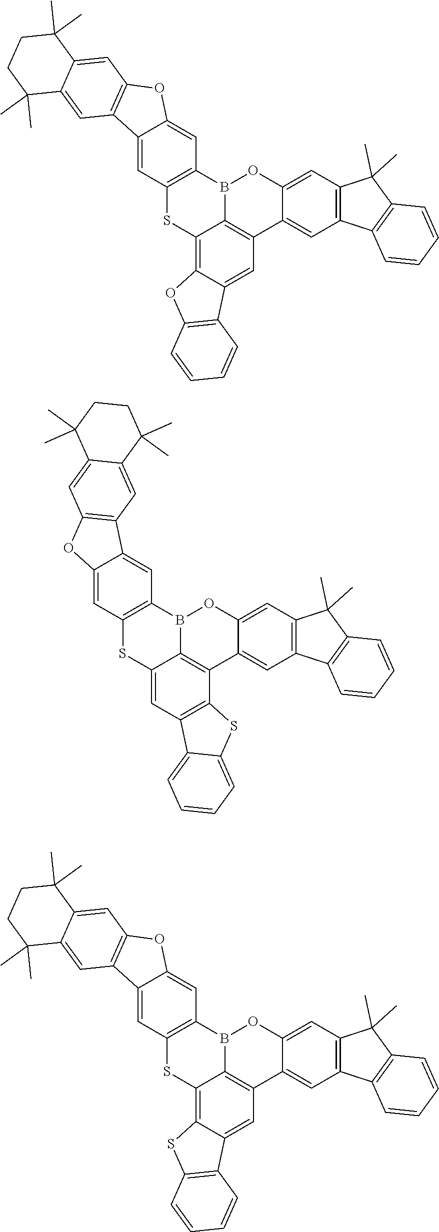

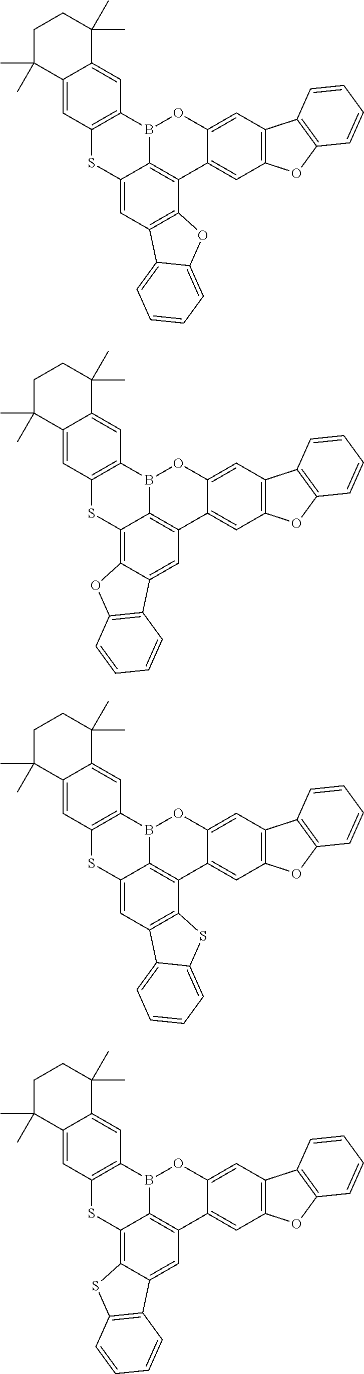

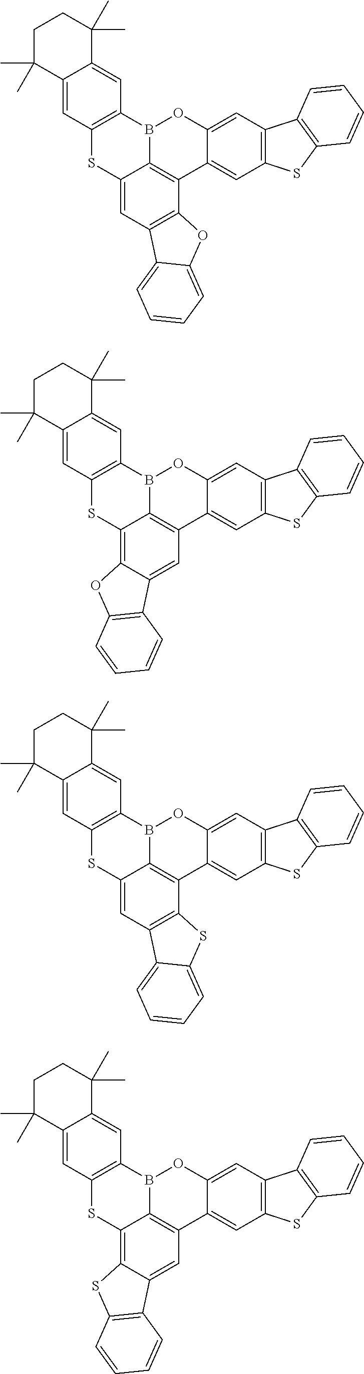

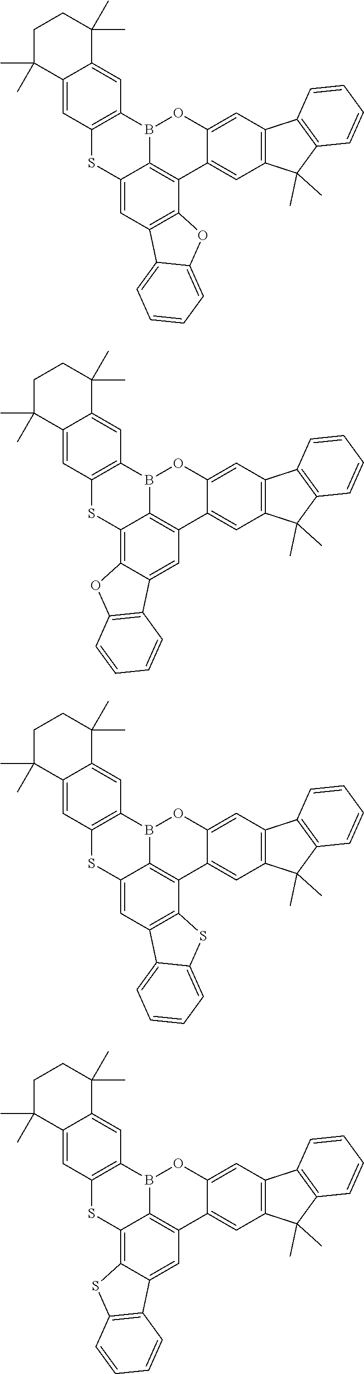

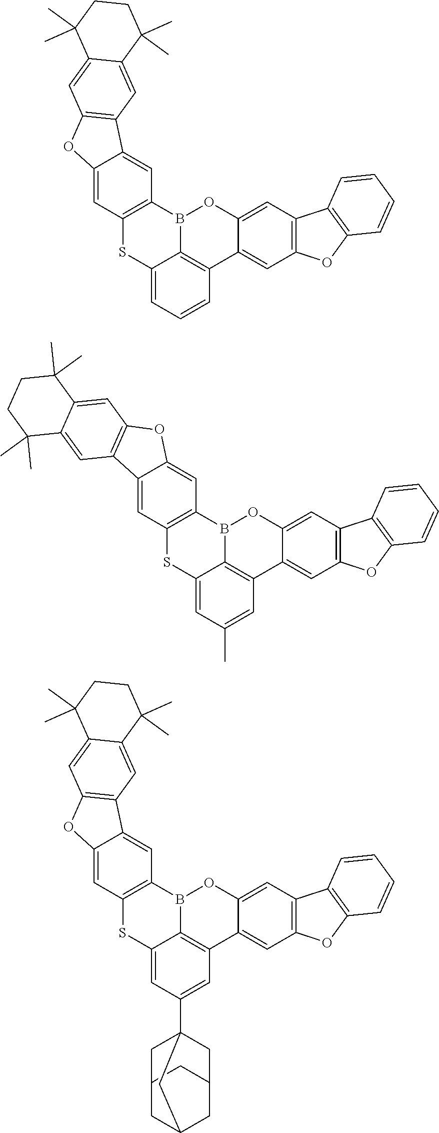 [SMILES: CC1(C)CCC(C)(C)c2cc3c(cc21)oc1cc2c(cc13)B1Oc3cc4c(cc3-c3cccc(c31)S2)oc1ccccc14 ; Cc1cc2c3c(c1)-c1cc4oc5ccccc5c4cc1OB3c1cc3oc4cc5c(cc4c3cc1S2)C(C)(C)CCC5(C)C ; CC1(C)CCC(C)(C)c2cc3c(cc21)oc1cc2c(cc13)B1Oc3cc4c(cc3-c3cc(C56CC7CC(CC(C7)C5)C6)cc(c31)S2)oc1ccccc14]

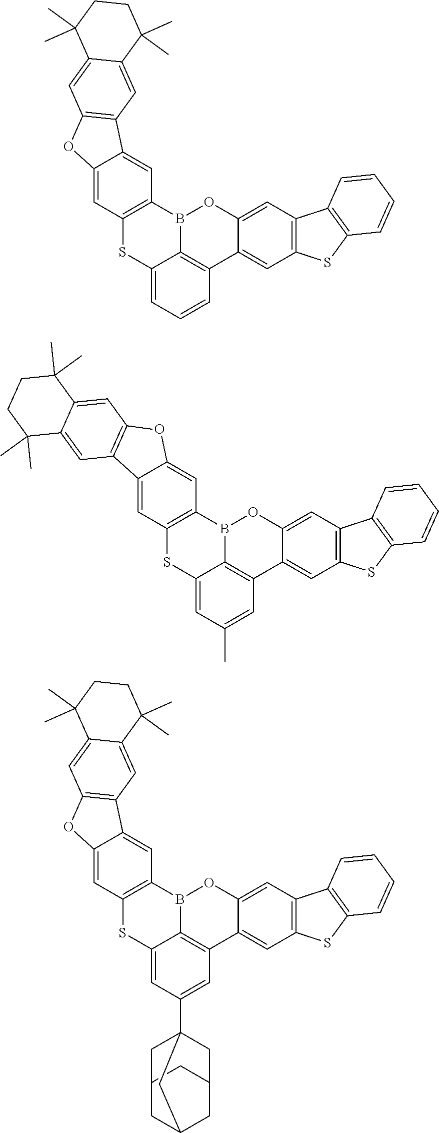 [SMILES: CC1(C)CCC(C)(C)c2cc3c(cc21)oc1cc2c(cc13)B1Oc3cc4c(cc3-c3cccc(c31)S2)sc1ccccc14 ; Cc1cc2c3c(c1)-c1cc4sc5ccccc5c4cc1OB3c1cc3oc4cc5c(cc4c3cc1S2)C(C)(C)CCC5(C)C ; CC1(C)CCC(C)(C)c2cc3c(cc21)oc1cc2c(cc13)B1Oc3cc4c(cc3-c3cc(C56CC7CC(CC(C7)C5)C6)cc(c31)S2)sc1ccccc14]

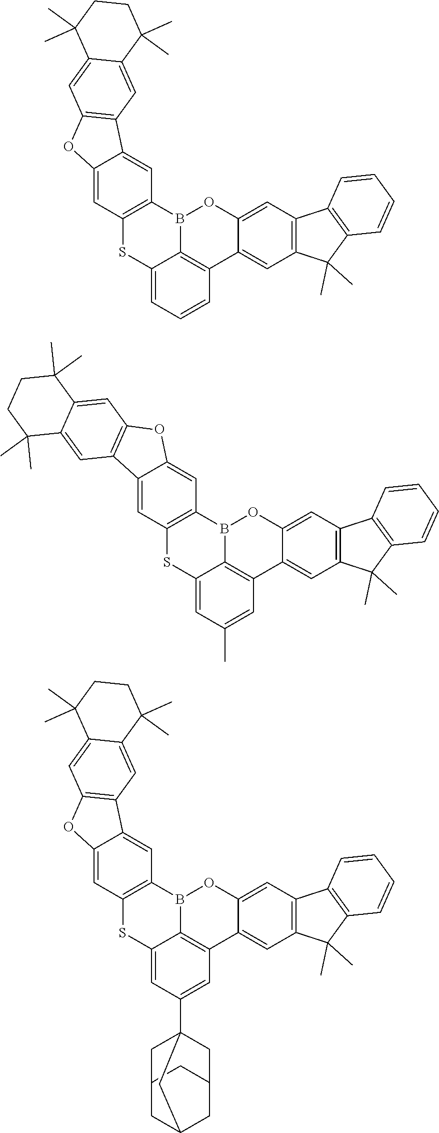 [SMILES: CC1(C)CCC(C)(C)c2cc3c(cc21)oc1cc2c(cc13)B1Oc3cc4c(cc3-c3cccc(c31)S2)C(C)(C)c1ccccc1-4 ; Cc1cc2c3c(c1)-c1cc4c(cc1OB3c1cc3oc5cc6c(cc5c3cc1S2)C(C)(C)CCC6(C)C)-c1ccccc1C4(C)C ; CC1(C)CCC(C)(C)c2cc3c(cc21)oc1cc2c(cc13)B1Oc3cc4c(cc3-c3cc(C56CC7CC(CC(C7)C5)C6)cc(c31)S2)C(C)(C)c1ccccc1-4]

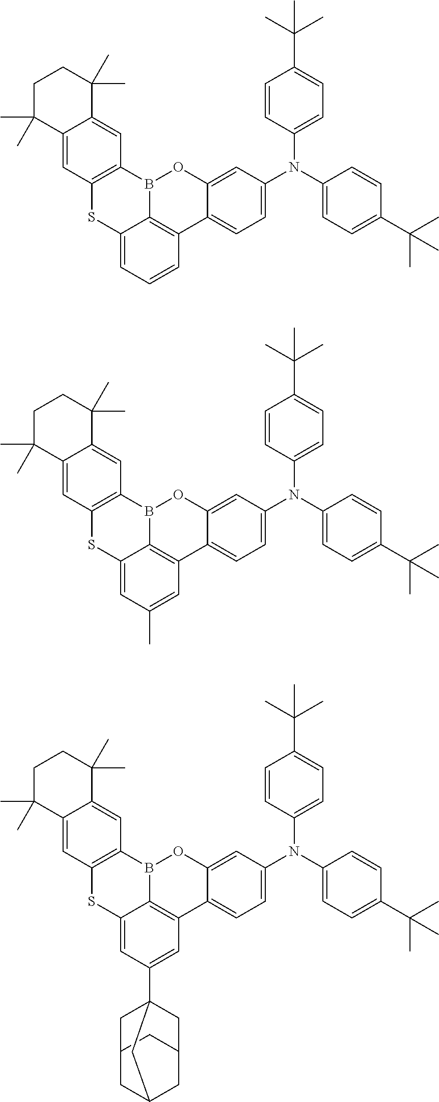

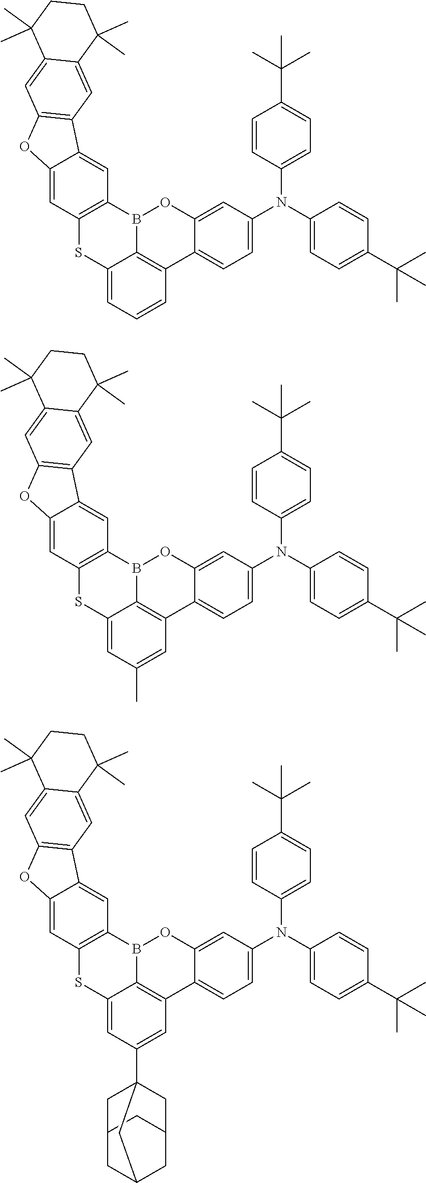

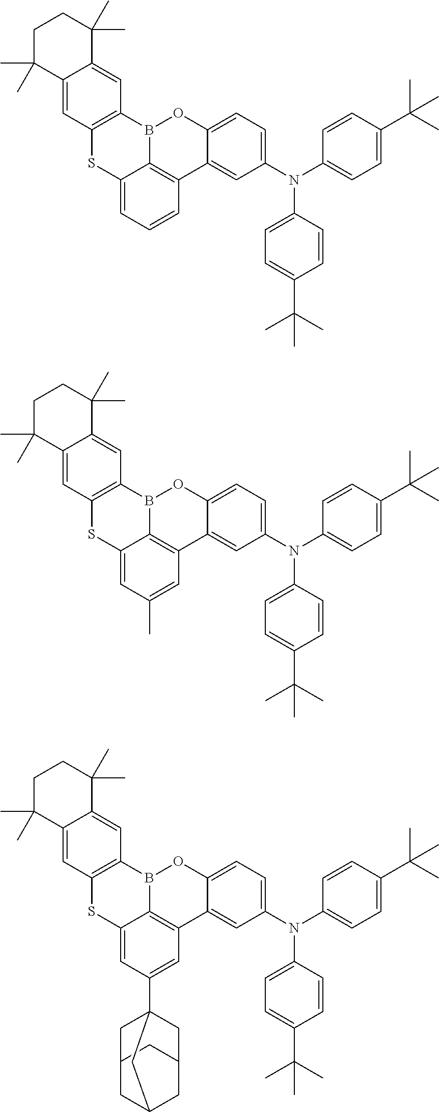

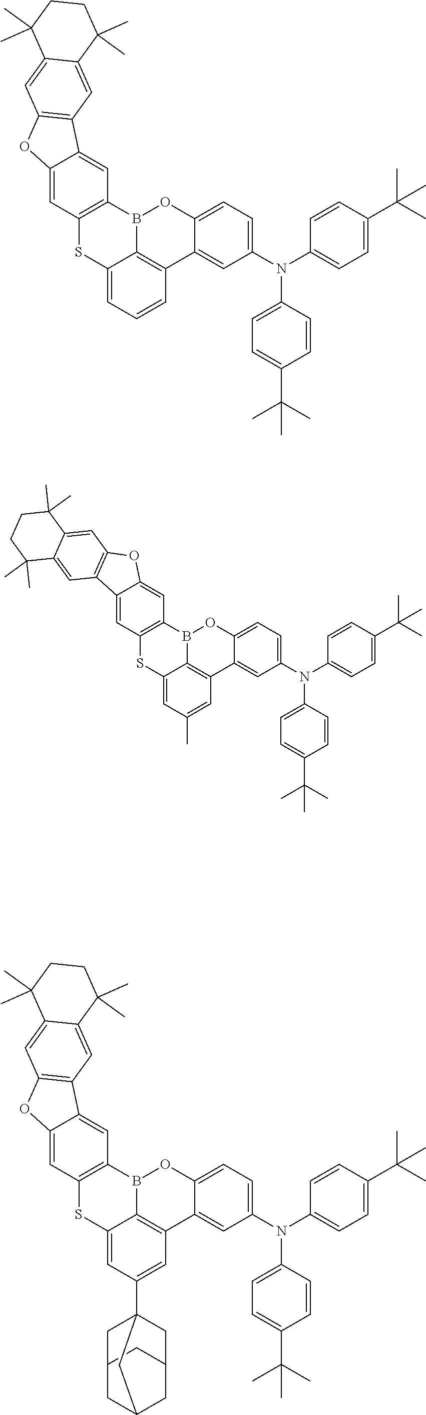

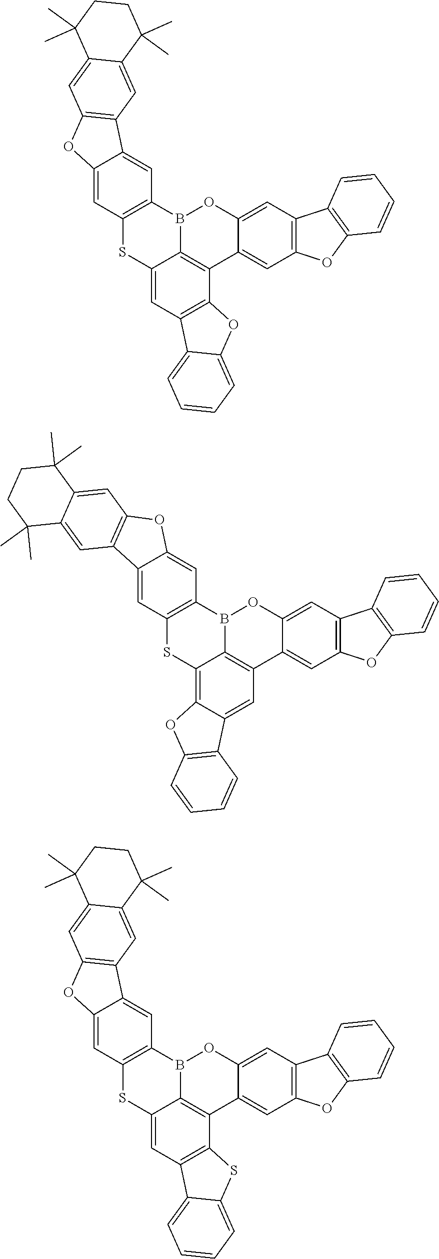 [SMILES: CC1(C)CCC(C)(C)c2cc3c(cc21)oc1cc2c(cc13)B1Oc3cc4c(cc3-c3c1c(cc1c3oc3ccccc31)S2)oc1ccccc14 ; CC1(C)CCC(C)(C)c2cc3c(cc21)oc1cc2c(cc13)Sc1c3c(cc4c1oc1ccccc14)-c1cc4oc5ccccc5c4cc1OB23 ; CC1(C)CCC(C)(C)c2cc3c(cc21)oc1cc2c(cc13)B1Oc3cc4c(cc3-c3c1c(cc1c3sc3ccccc31)S2)oc1ccccc14]

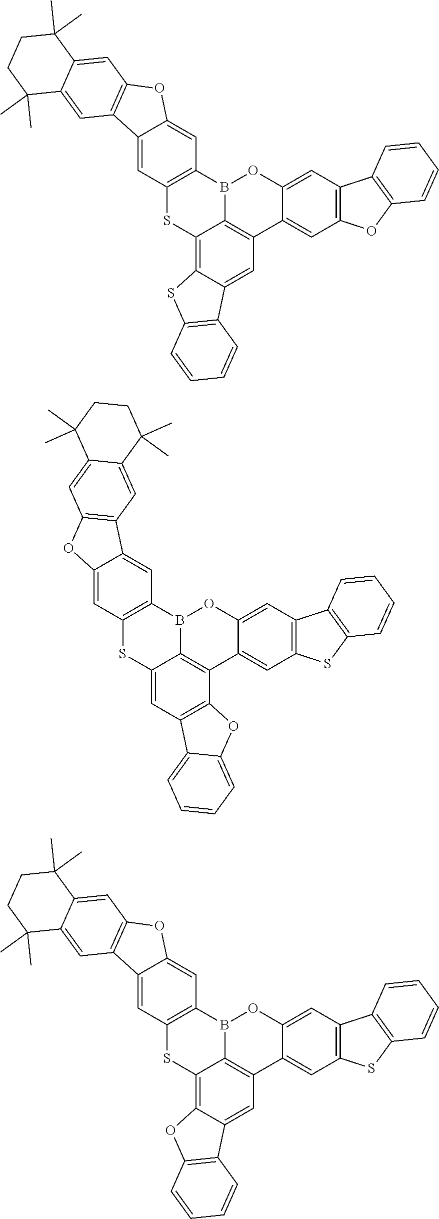

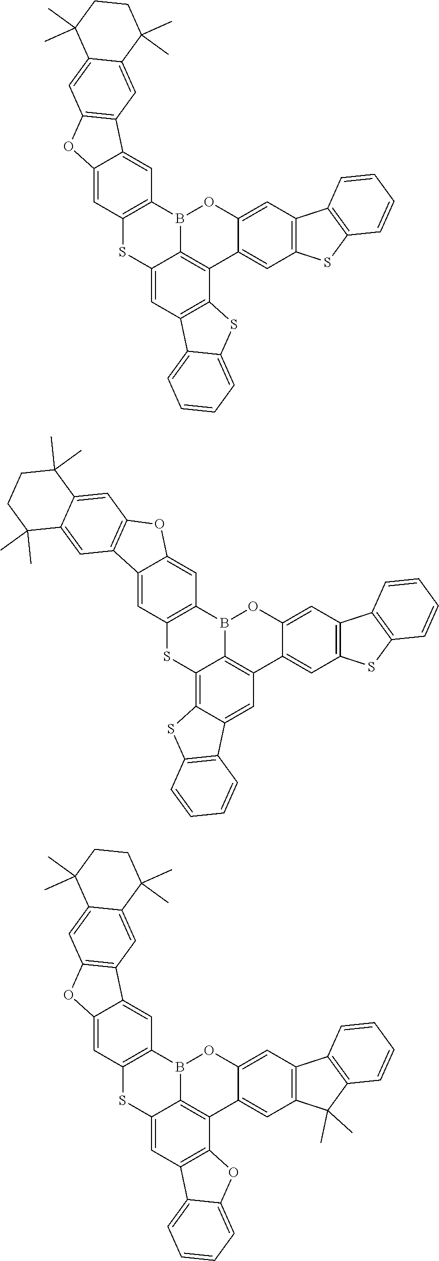 [SMILES: CC1(C)CCC(C)(C)c2cc3c(cc21)oc1cc2c(cc13)B1Oc3cc4c(cc3-c3c1c(cc1c3sc3ccccc31)S2)sc1ccccc14 ; CC1(C)CCC(C)(C)c2cc3c(cc21)oc1cc2c(cc13)Sc1c3c(cc4c1sc1ccccc14)-c1cc4sc5ccccc5c4cc1OB23 ; CC1(C)CCC(C)(C)c2cc3c(cc21)oc1cc2c(cc13)B1Oc3cc4c(cc3-c3c1c(cc1c3oc3ccccc31)S2)C(C)(C)c1ccccc1-4]

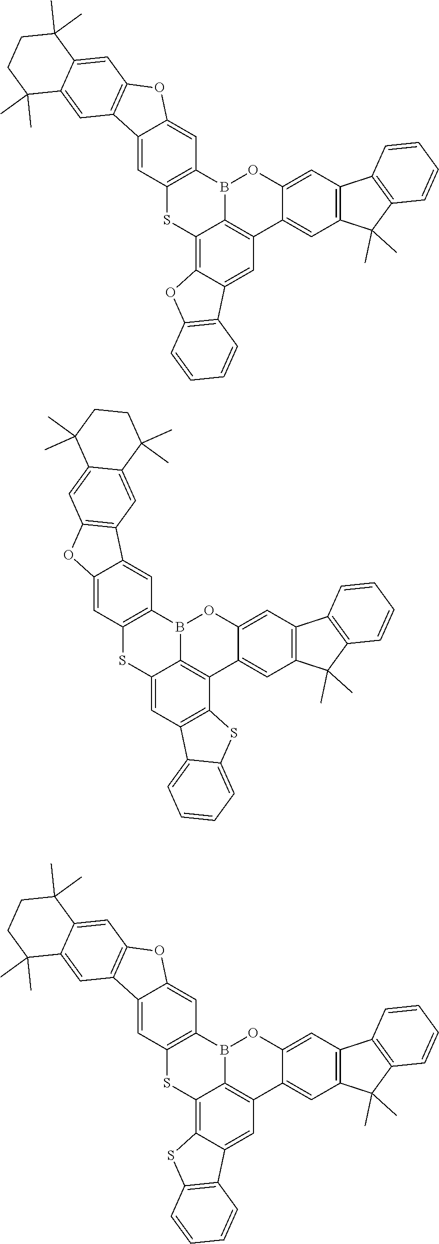 [SMILES: CC1(C)CCC(C)(C)c2cc3c(cc21)oc1cc2c(cc13)Sc1c3c(cc4c1oc1ccccc14)-c1cc4c(cc1OB23)-c1ccccc1C4(C)C ; CC1(C)CCC(C)(C)c2cc3c(cc21)oc1cc2c(cc13)B1Oc3cc4c(cc3-c3c1c(cc1c3sc3ccccc31)S2)C(C)(C)c1ccccc1-4 ; CC1(C)CCC(C)(C)c2cc3c(cc21)oc1cc2c(cc13)Sc1c3c(cc4c1sc1ccccc14)-c1cc4c(cc1OB23)-c1ccccc1C4(C)C]

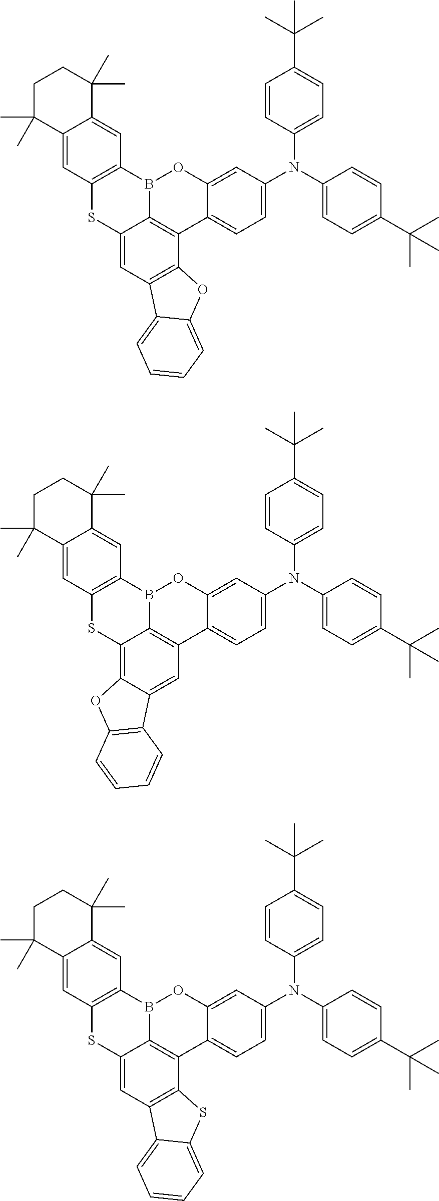

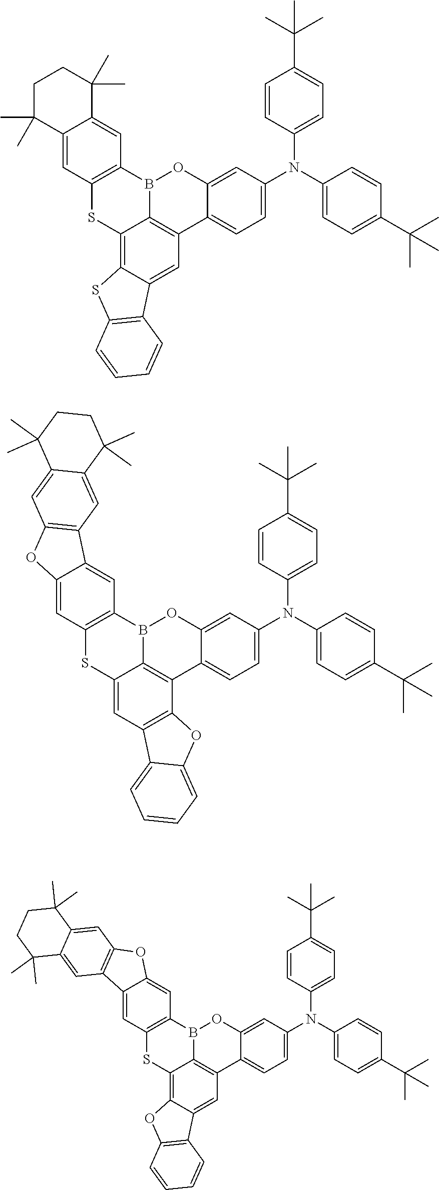

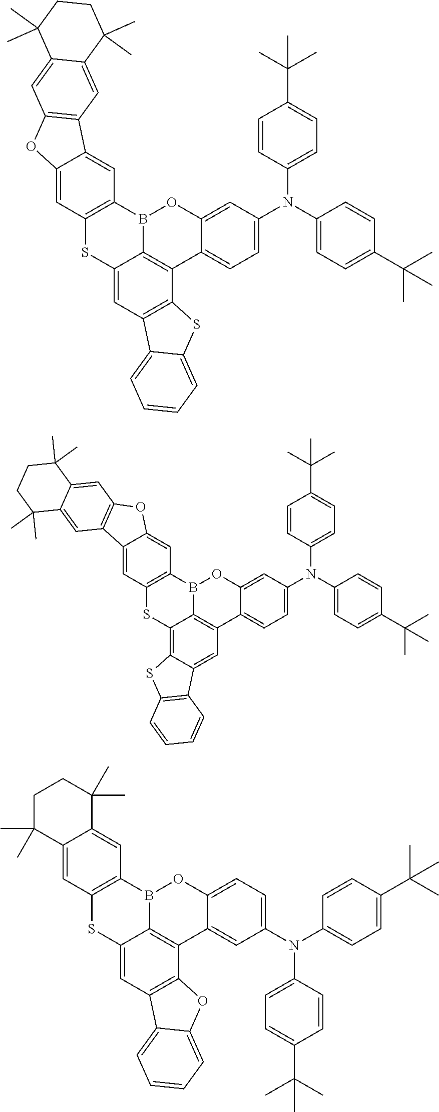

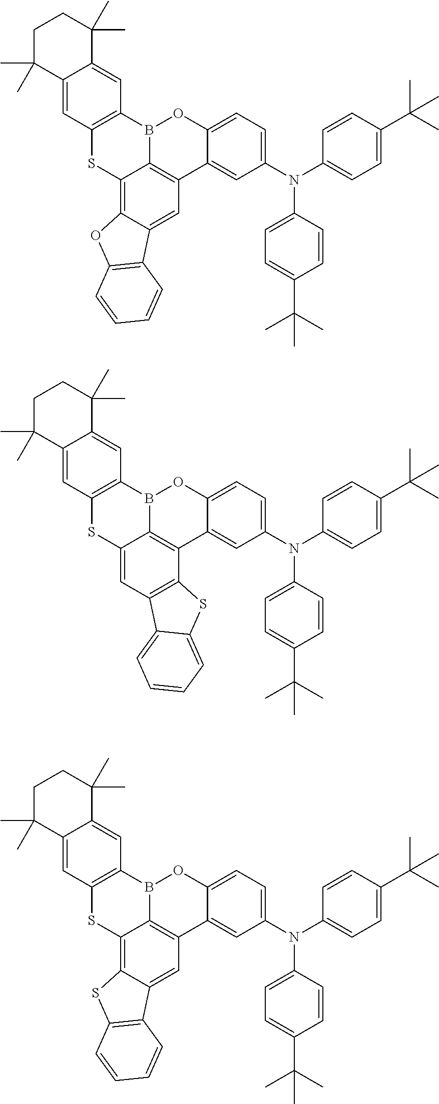

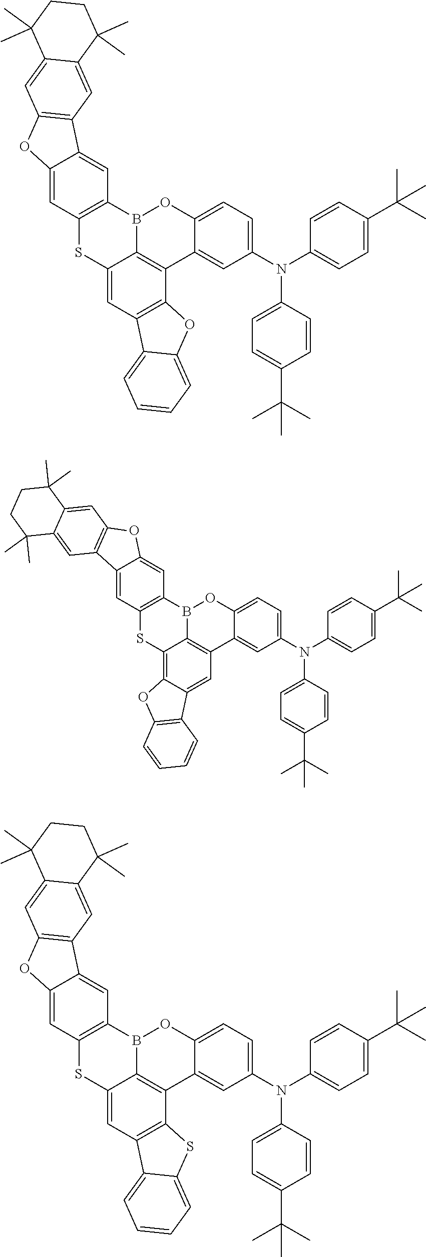

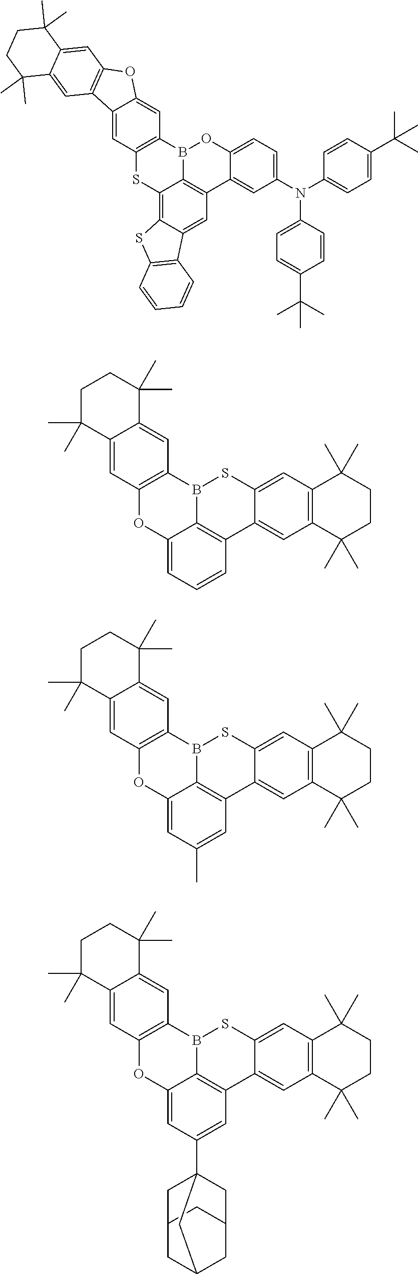

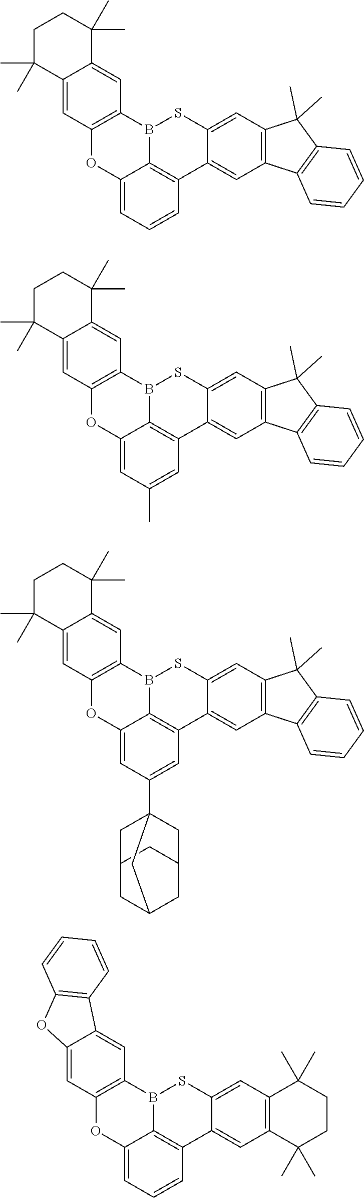 [SMILES: CC1(C)CCC(C)(C)c2cc3c(cc21)Oc1cccc2c1B3Sc1cc3c(cc1-2)-c1ccccc1C3(C)C ; Cc1cc2c3c(c1)-c1cc4c(cc1SB3c1cc3c(cc1O2)C(C)(C)CCC3(C)C)C(C)(C)c1ccccc1-4 ; CC1(C)CCC(C)(C)c2cc3c(cc21)Oc1cc(C24CC5CC(CC(C5)C2)C4)cc2c1B3Sc1cc3c(cc1-2)-c1ccccc1C3(C)C ; CC1(C)CCC(C)(C)c2cc3c(cc21)SB1c2cc4c(cc2Oc2cccc-3c21)oc1ccccc14]

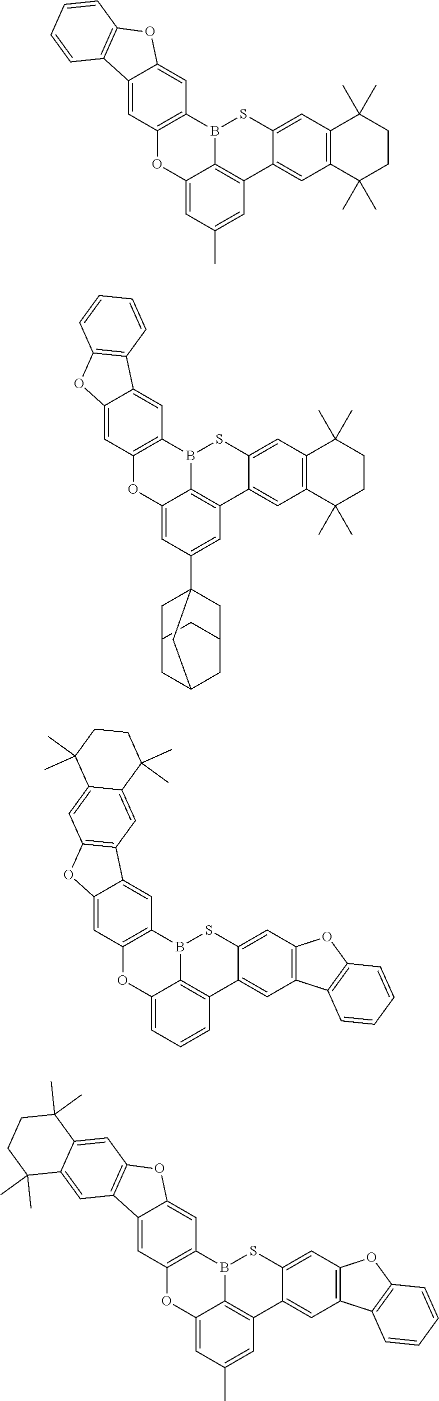 [SMILES: Cc1cc2c3c(c1)-c1cc4c(cc1SB3c1cc3oc5ccccc5c3cc1O2)C(C)(C)CCC4(C)C ; CC1(C)CCC(C)(C)c2cc3c(cc21)SB1c2cc4c(cc2Oc2cc(C56CC7CC(CC(C7)C5)C6)cc-3c21)oc1ccccc14 ; CC1(C)CCC(C)(C)c2cc3c(cc21)oc1cc2c(cc13)B1Sc3cc4oc5ccccc5c4cc3-c3cccc(c31)O2 ; Cc1cc2c3c(c1)-c1cc4c(cc1SB3c1cc3oc5cc6c(cc5c3cc1O2)C(C)(C)CCC6(C)C)oc1ccccc14]

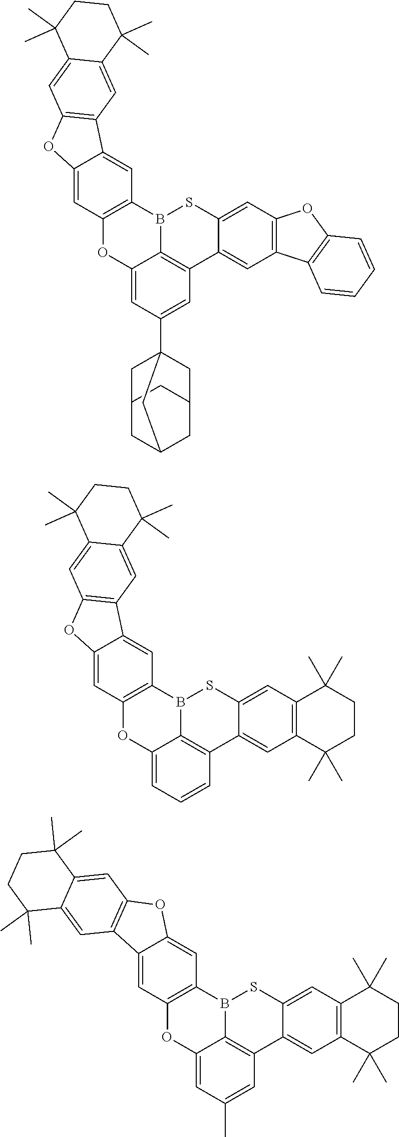 [SMILES: CC1(C)CCC(C)(C)c2cc3c(cc21)oc1cc2c(cc13)B1Sc3cc4oc5ccccc5c4cc3-c3cc(C45CC6CC(CC(C6)C4)C5)cc(c31)O2 ; CC1(C)CCC(C)(C)c2cc3c(cc21)SB1c2cc4c(cc2Oc2cccc-3c21)oc1cc2c(cc14)C(C)(C)CCC2(C)C ; Cc1cc2c3c(c1)-c1cc4c(cc1SB3c1cc3oc5cc6c(cc5c3cc1O2)C(C)(C)CCC6(C)C)C(C)(C)CCC4(C)C]

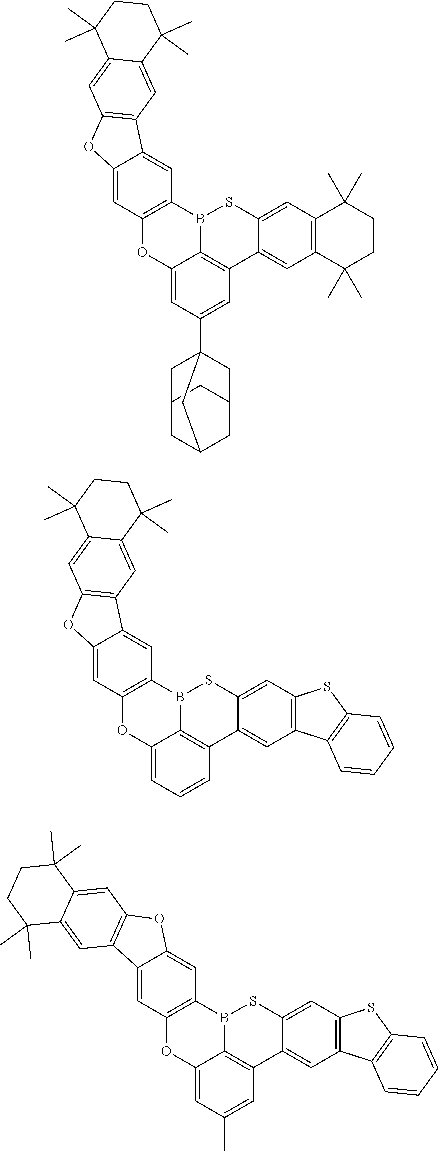 [SMILES: CC1(C)CCC(C)(C)c2cc3c(cc21)SB1c2cc4c(cc2Oc2cc(C56CC7CC(CC(C7)C5)C6)cc-3c21)oc1cc2c(cc14)C(C)(C)CCC2(C)C ; CC1(C)CCC(C)(C)c2cc3c(cc21)oc1cc2c(cc13)B1Sc3cc4sc5ccccc5c4cc3-c3cccc(c31)O2 ; Cc1cc2c3c(c1)-c1cc4c(cc1SB3c1cc3oc5cc6c(cc5c3cc1O2)C(C)(C)CCC6(C)C)sc1ccccc14]

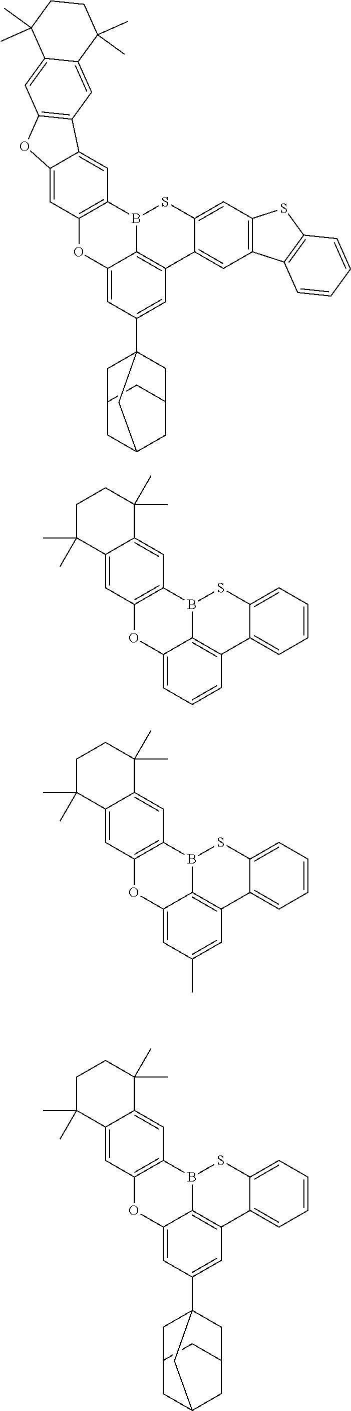

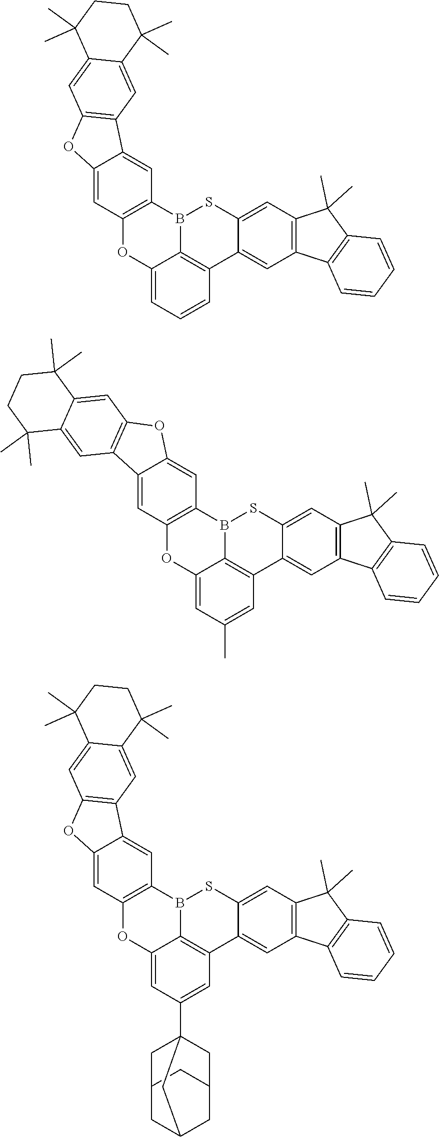 [SMILES: CC1(C)CCC(C)(C)c2cc3c(cc21)oc1cc2c(cc13)B1Sc3cc4c(cc3-c3cccc(c31)O2)-c1ccccc1C4(C)C ; Cc1cc2c3c(c1)-c1cc4c(cc1SB3c1cc3oc5cc6c(cc5c3cc1O2)C(C)(C)CCC6(C)C)C(C)(C)c1ccccc1-4 ; CC1(C)CCC(C)(C)c2cc3c(cc21)oc1cc2c(cc13)B1Sc3cc4c(cc3-c3cc(C56CC7CC(CC(C7)C5)C6)cc(c31)O2)-c1ccccc1C4(C)C]

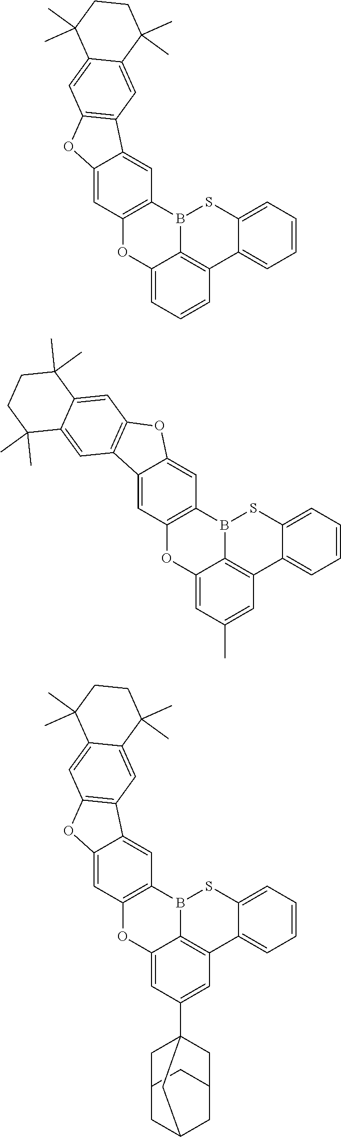 [SMILES: CC1(C)CCC(C)(C)c2cc3c(cc21)oc1cc2c(cc13)B1Sc3ccccc3-c3cccc(c31)O2 ; Cc1cc2c3c(c1)-c1ccccc1SB3c1cc3oc4cc5c(cc4c3cc1O2)C(C)(C)CCC5(C)C ; CC1(C)CCC(C)(C)c2cc3c(cc21)oc1cc2c(cc13)B1Sc3ccccc3-c3cc(C45CC6CC(CC(C6)C4)C5)cc(c31)O2]

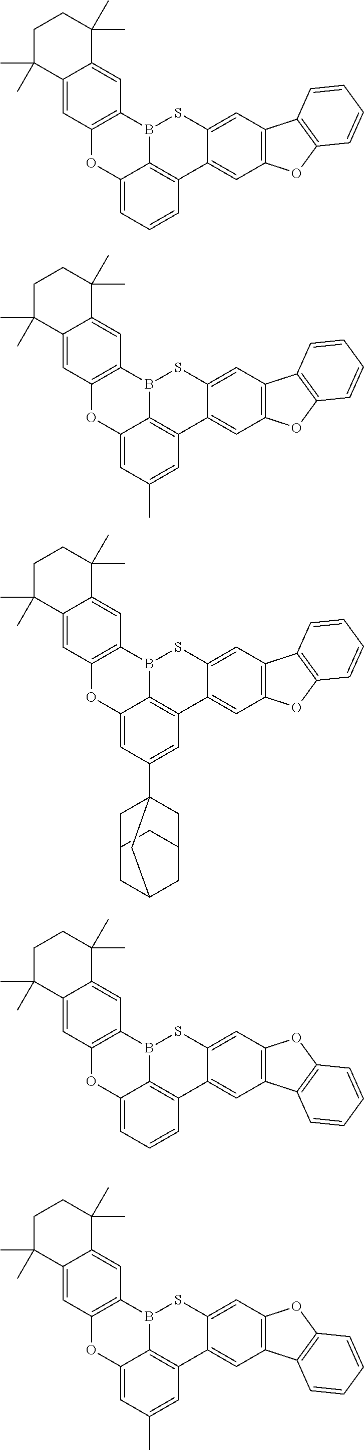

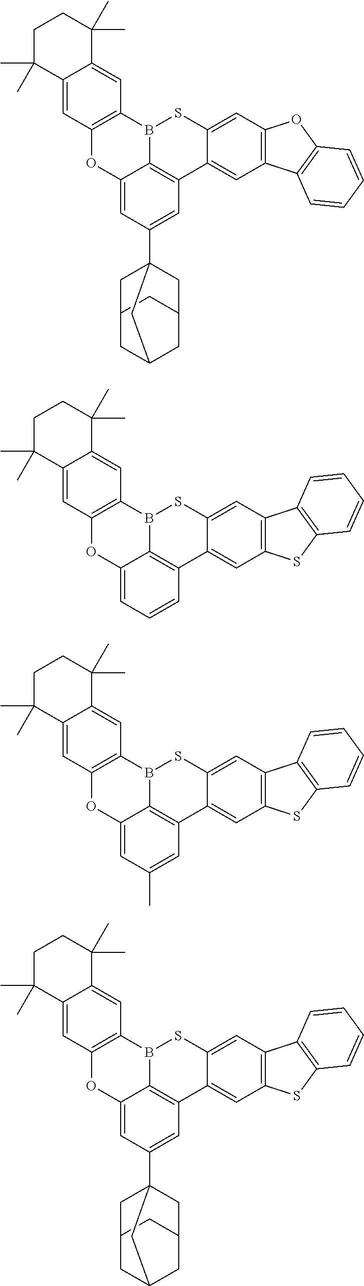

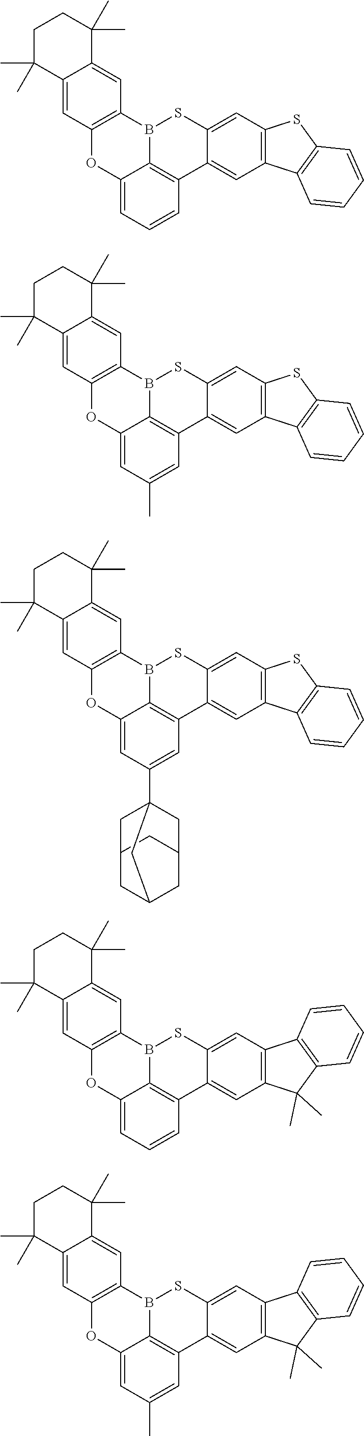

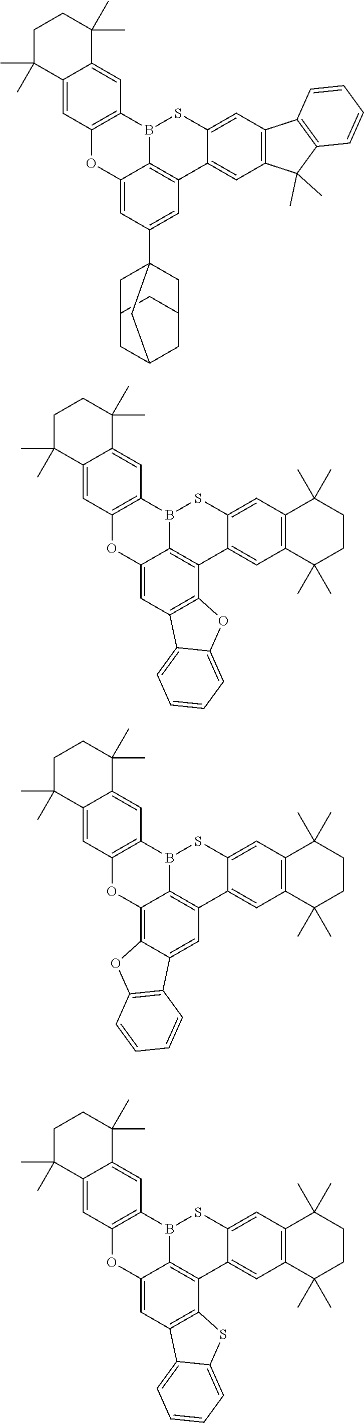

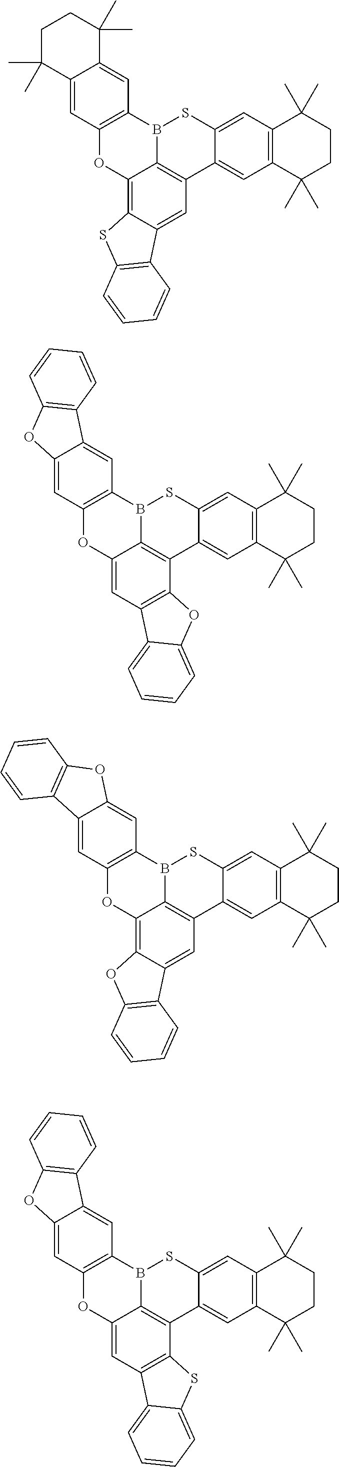 [SMILES: CC1(C)CCC(C)(C)c2cc3c(cc21)Oc1c2c(cc4c1sc1ccccc14)-c1cc4c(cc1SB32)C(C)(C)CCC4(C)C ; CC1(C)CCC(C)(C)c2cc3c(cc21)SB1c2cc4c(cc2Oc2cc5c(oc6ccccc65)c-3c21)oc1ccccc14 ; CC1(C)CCC(C)(C)c2cc3c(cc21)SB1c2cc4oc5ccccc5c4cc2Oc2c1c-3cc1c2oc2ccccc21 ; CC1(C)CCC(C)(C)c2cc3c(cc21)SB1c2cc4c(cc2Oc2cc5c(sc6ccccc65)c-3c21)oc1ccccc14]

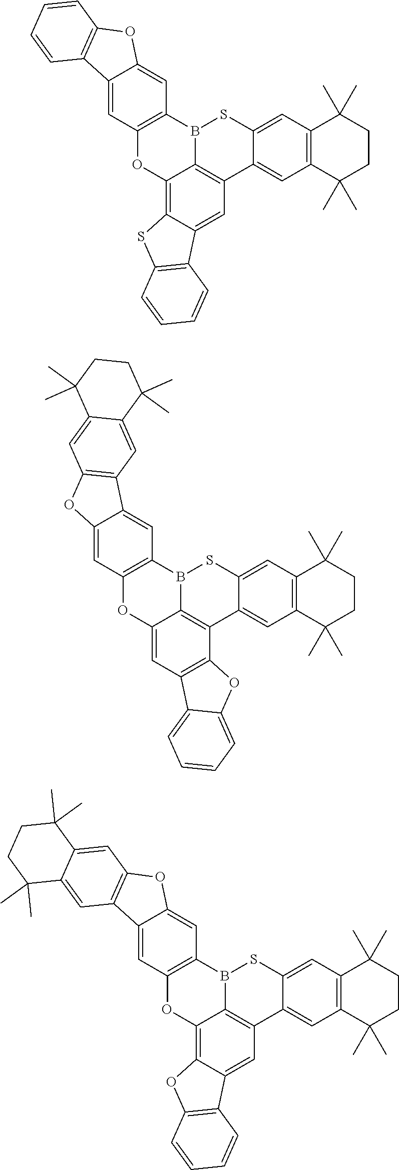 [SMILES: CC1(C)CCC(C)(C)c2cc3c(cc21)SB1c2cc4oc5ccccc5c4cc2Oc2c1c-3cc1c2sc2ccccc21 ; CC1(C)CCC(C)(C)c2cc3c(cc21)SB1c2cc4c(cc2Oc2cc5c(oc6ccccc65)c-3c21)oc1cc2c(cc14)C(C)(C)CCC2(C)C ; CC1(C)CCC(C)(C)c2cc3c(cc21)SB1c2cc4oc5cc6c(cc5c4cc2Oc2c1c-3cc1c2oc2ccccc21)C(C)(C)CCC6(C)C]

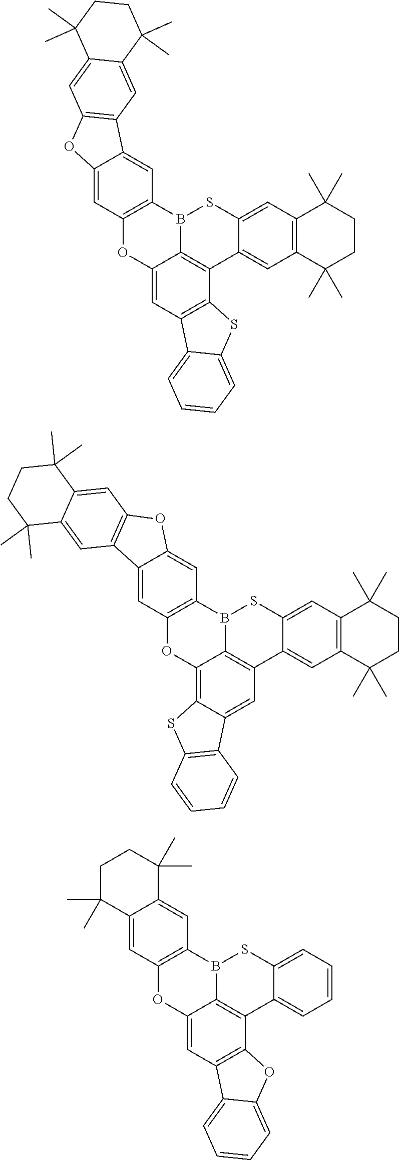

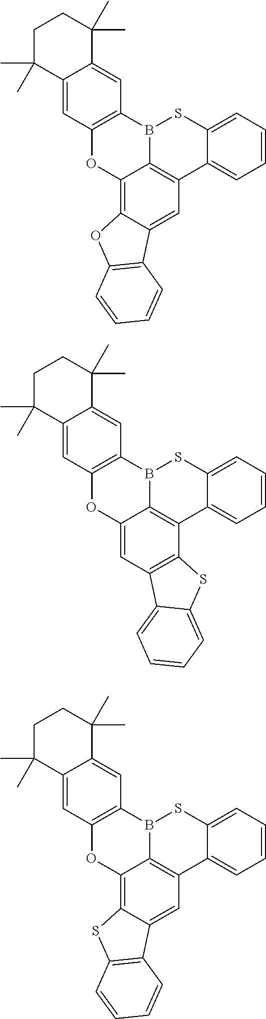

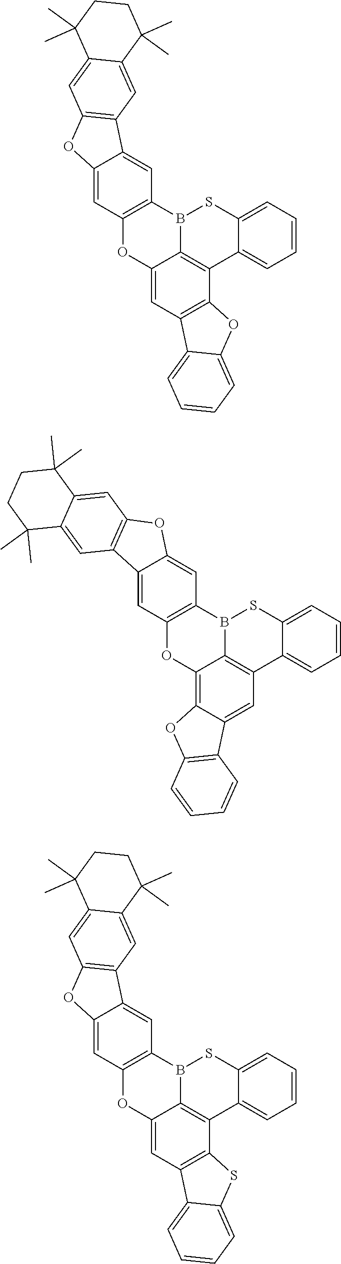 [SMILES: CC1(C)CCC(C)(C)c2cc3c(cc21)oc1cc2c(cc13)B1Sc3ccccc3-c3c1c(cc1c3oc3ccccc31)O2 ; CC1(C)CCC(C)(C)c2cc3c(cc21)oc1cc2c(cc13)Oc1c3c(cc4c1oc1ccccc14)-c1ccccc1SB23 ; CC1(C)CCC(C)(C)c2cc3c(cc21)oc1cc2c(cc13)B1Sc3ccccc3-c3c1c(cc1c3sc3ccccc31)O2]

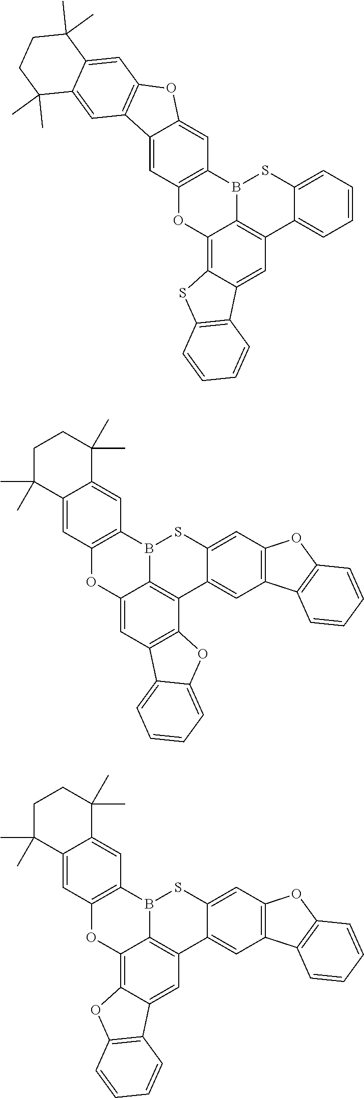 [SMILES: CC1(C)CCC(C)(C)c2cc3c(cc21)oc1cc2c(cc13)Oc1c3c(cc4c1sc1ccccc14)-c1ccccc1SB23 ; CC1(C)CCC(C)(C)c2cc3c(cc21)Oc1cc2c(oc4ccccc42)c2c1B3Sc1cc3oc4ccccc4c3cc1-2 ; CC1(C)CCC(C)(C)c2cc3c(cc21)Oc1c2c(cc4c1oc1ccccc14)-c1cc4c(cc1SB32)oc1ccccc14]

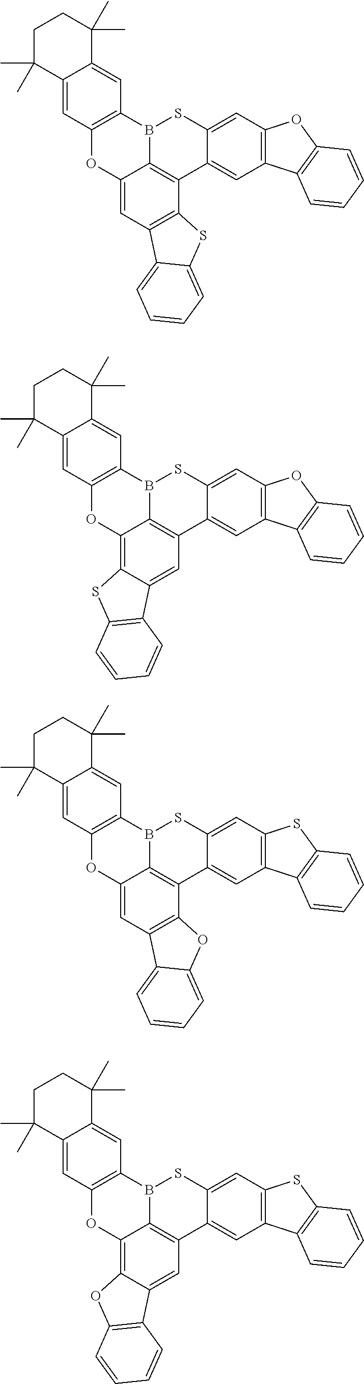

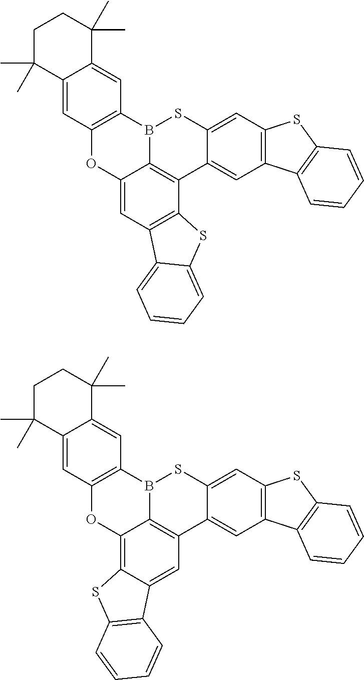 [SMILES: CC1(C)CCC(C)(C)c2cc3c(cc21)Oc1cc2c(sc4ccccc42)c2c1B3Sc1cc3sc4ccccc4c3cc1-2 ; CC1(C)CCC(C)(C)c2cc3c(cc21)Oc1c2c(cc4c1sc1ccccc14)-c1cc4c(cc1SB32)sc1ccccc14]

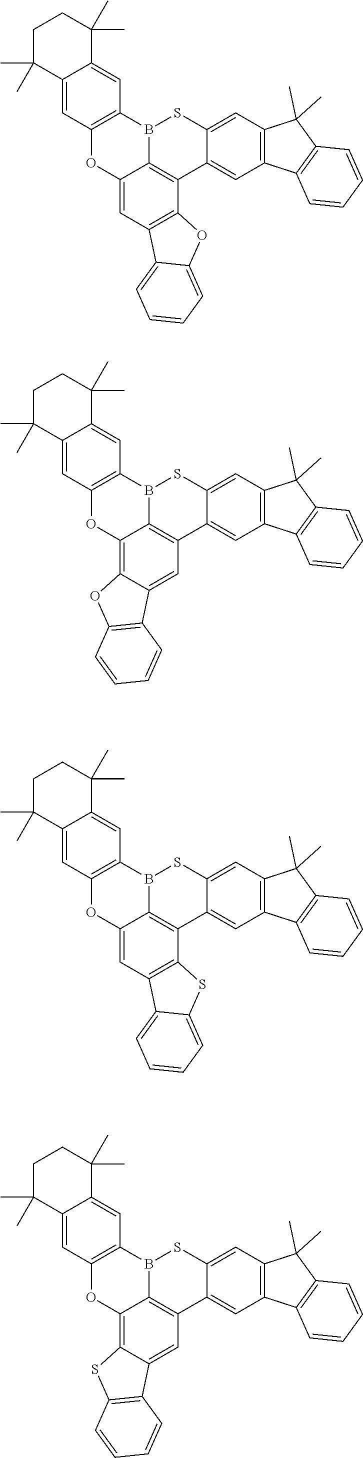 [SMILES: CC1(C)CCC(C)(C)c2cc3c(cc21)Oc1cc2c(oc4ccccc42)c2c1B3Sc1cc3c(cc1-2)-c1ccccc1C3(C)C ; CC1(C)CCC(C)(C)c2cc3c(cc21)Oc1c2c(cc4c1oc1ccccc14)-c1cc4c(cc1SB32)C(C)(C)c1ccccc1-4 ; CC1(C)CCC(C)(C)c2cc3c(cc21)Oc1cc2c(sc4ccccc42)c2c1B3Sc1cc3c(cc1-2)-c1ccccc1C3(C)C ; CC1(C)CCC(C)(C)c2cc3c(cc21)Oc1c2c(cc4c1sc1ccccc14)-c1cc4c(cc1SB32)C(C)(C)c1ccccc1-4]

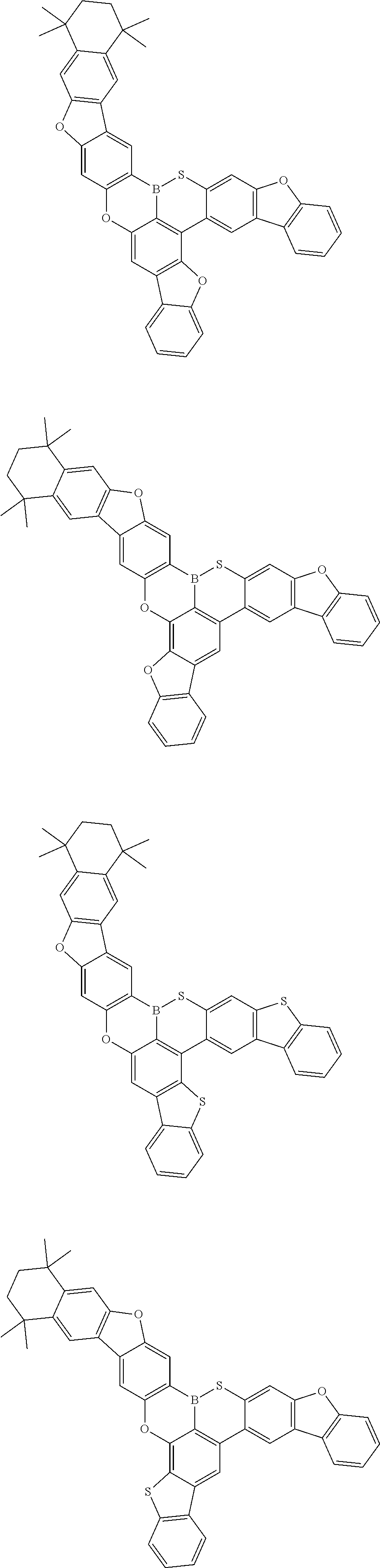 [SMILES: CC1(C)CCC(C)(C)c2cc3c(cc21)oc1cc2c(cc13)B1Sc3cc4oc5ccccc5c4cc3-c3c1c(cc1c3oc3ccccc31)O2 ; CC1(C)CCC(C)(C)c2cc3c(cc21)oc1cc2c(cc13)Oc1c3c(cc4c1oc1ccccc14)-c1cc4c(cc1SB23)oc1ccccc14 ; CC1(C)CCC(C)(C)c2cc3c(cc21)oc1cc2c(cc13)B1Sc3cc4sc5ccccc5c4cc3-c3c1c(cc1c3sc3ccccc31)O2 ; CC1(C)CCC(C)(C)c2cc3c(cc21)oc1cc2c(cc13)Oc1c3c(cc4c1sc1ccccc14)-c1cc4c(cc1SB23)oc1ccccc14]

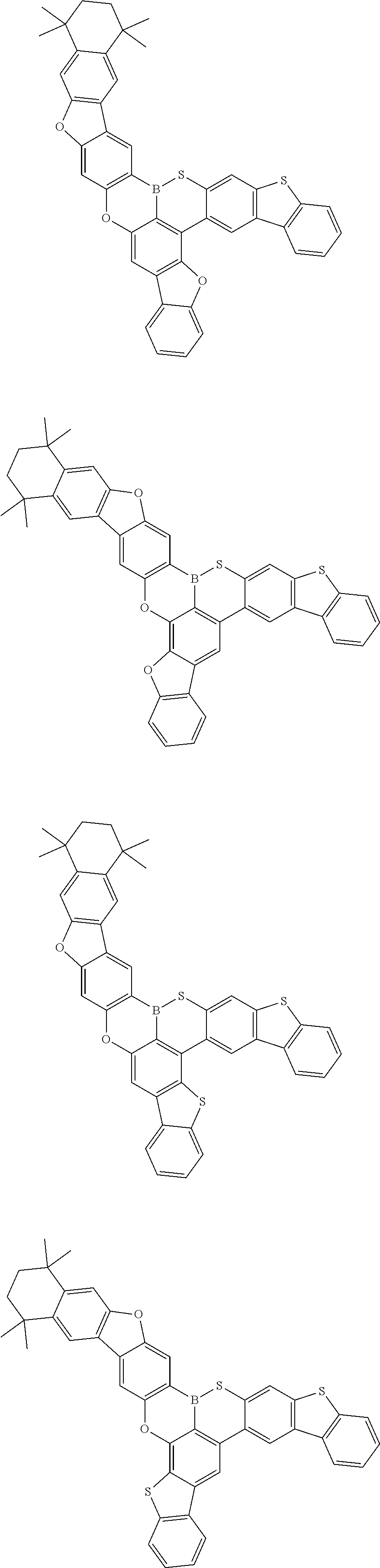 [SMILES: CC1(C)CCC(C)(C)c2cc3c(cc21)oc1cc2c(cc13)B1Sc3cc4sc5ccccc5c4cc3-c3c1c(cc1c3oc3ccccc31)O2 ; CC1(C)CCC(C)(C)c2cc3c(cc21)oc1cc2c(cc13)Oc1c3c(cc4c1oc1ccccc14)-c1cc4c(cc1SB23)sc1ccccc14 ; CC1(C)CCC(C)(C)c2cc3c(cc21)oc1cc2c(cc13)B1Sc3cc4sc5ccccc5c4cc3-c3c1c(cc1c3sc3ccccc31)O2 ; CC1(C)CCC(C)(C)c2cc3c(cc21)oc1cc2c(cc13)Oc1c3c(cc4c1sc1ccccc14)-c1cc4c(cc1SB23)sc1ccccc14]

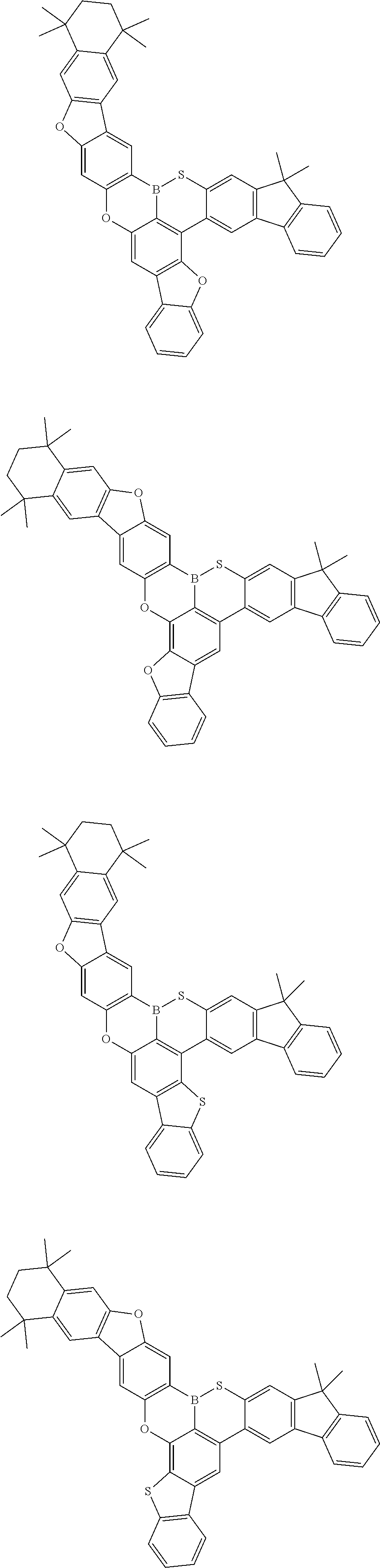 [SMILES: CC1(C)CCC(C)(C)c2cc3c(cc21)oc1cc2c(cc13)B1Sc3cc4c(cc3-c3c1c(cc1c3oc3ccccc31)O2)-c1ccccc1C4(C)C ; CC1(C)CCC(C)(C)c2cc3c(cc21)oc1cc2c(cc13)Oc1c3c(cc4c1oc1ccccc14)-c1cc4c(cc1SB23)C(C)(C)c1ccccc1-4 ; CC1(C)CCC(C)(C)c2cc3c(cc21)oc1cc2c(cc13)B1Sc3cc4c(cc3-c3c1c(cc1c3sc3ccccc31)O2)-c1ccccc1C4(C)C ; CC1(C)CCC(C)(C)c2cc3c(cc21)oc1cc2c(cc13)Oc1c3c(cc4c1sc1ccccc14)-c1cc4c(cc1SB23)C(C)(C)c1ccccc1-4]

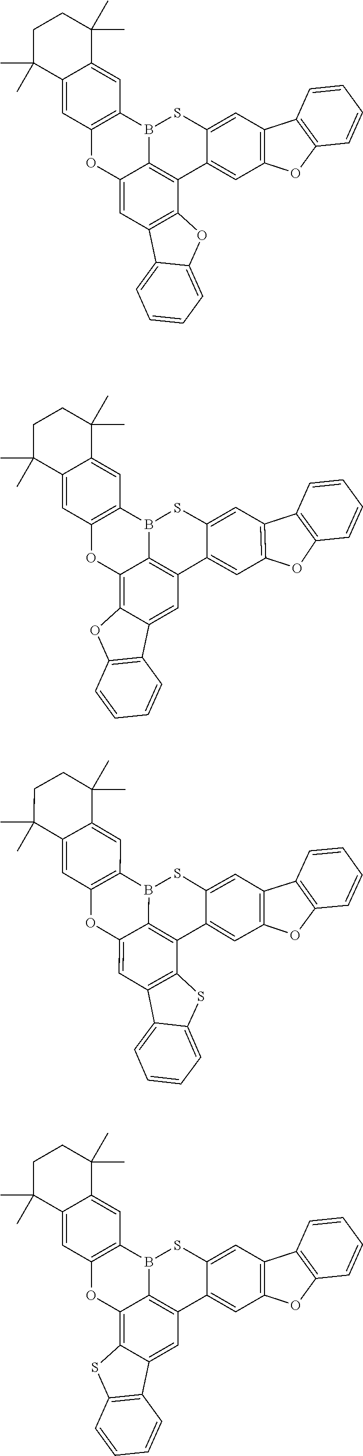

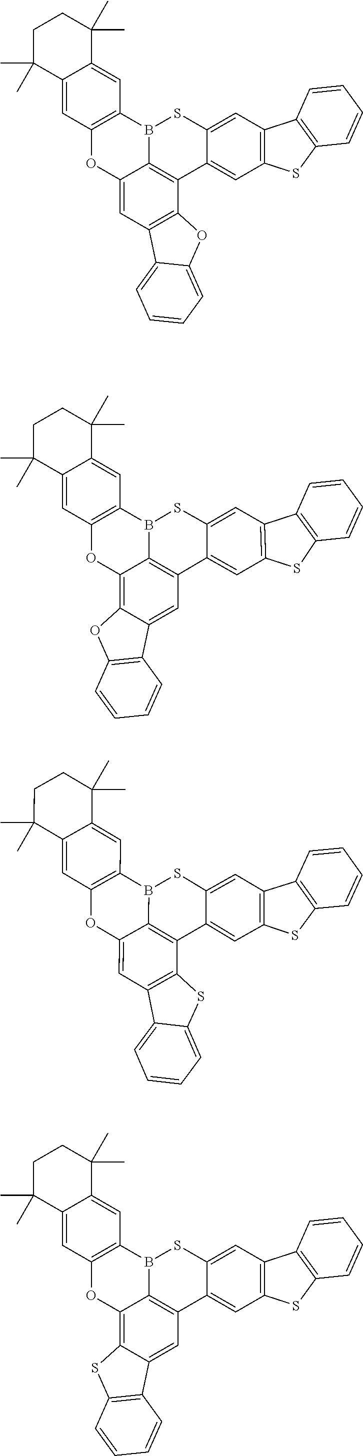

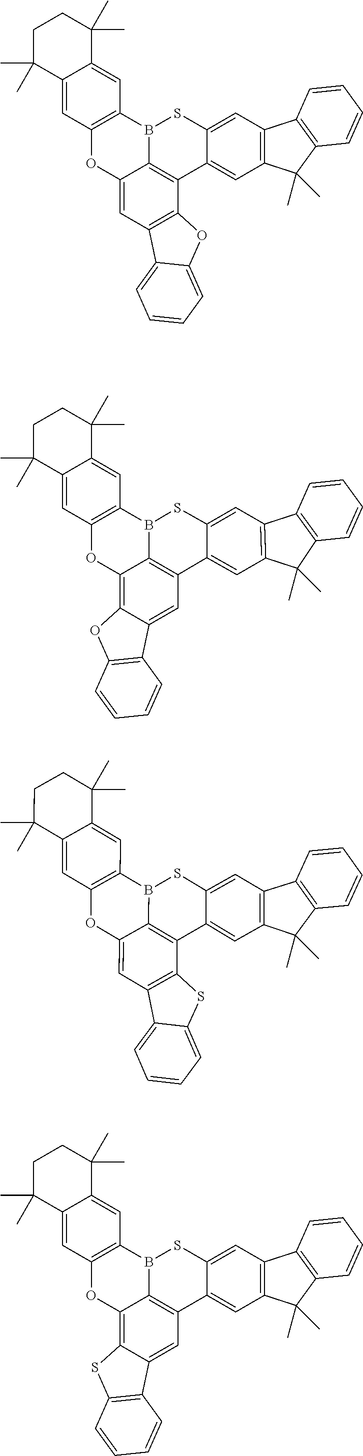

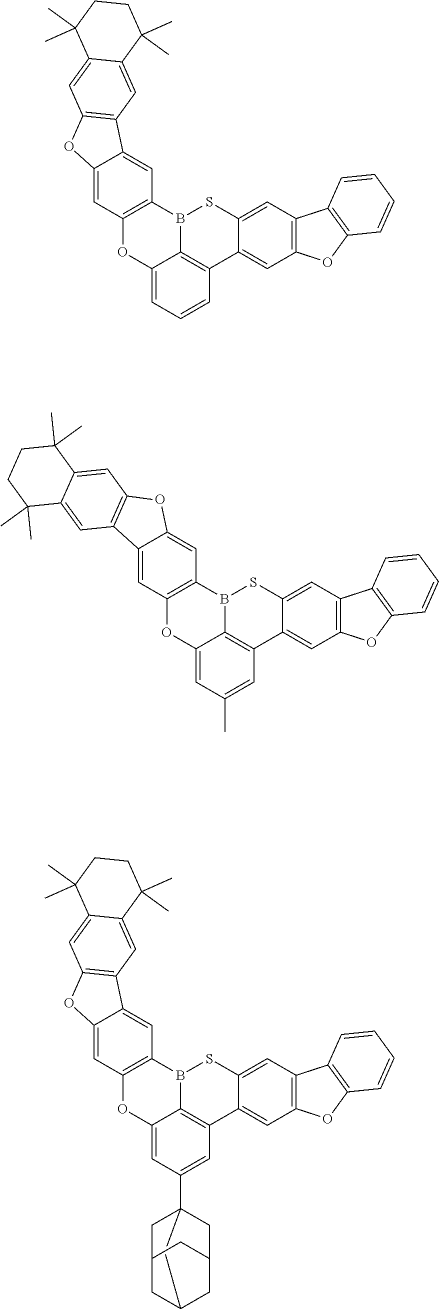 [SMILES: CC1(C)CCC(C)(C)c2cc3c(cc21)oc1cc2c(cc13)B1Sc3cc4c(cc3-c3cccc(c31)O2)oc1ccccc14 ; Cc1cc2c3c(c1)-c1cc4oc5ccccc5c4cc1SB3c1cc3oc4cc5c(cc4c3cc1O2)C(C)(C)CCC5(C)C ; CC1(C)CCC(C)(C)c2cc3c(cc21)oc1cc2c(cc13)B1Sc3cc4c(cc3-c3cc(C56CC7CC(CC(C7)C5)C6)cc(c31)O2)oc1ccccc14]

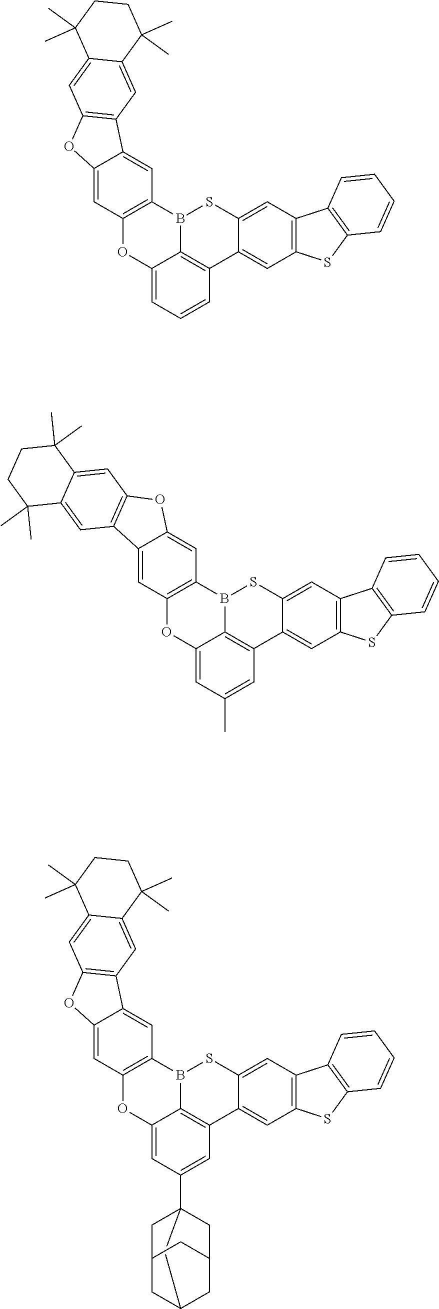 [SMILES: CC1(C)CCC(C)(C)c2cc3c(cc21)oc1cc2c(cc13)B1Sc3cc4c(cc3-c3cccc(c31)O2)sc1ccccc14 ; Cc1cc2c3c(c1)-c1cc4sc5ccccc5c4cc1SB3c1cc3oc4cc5c(cc4c3cc1O2)C(C)(C)CCC5(C)C ; CC1(C)CCC(C)(C)c2cc3c(cc21)oc1cc2c(cc13)B1Sc3cc4c(cc3-c3cc(C56CC7CC(CC(C7)C5)C6)cc(c31)O2)sc1ccccc14]

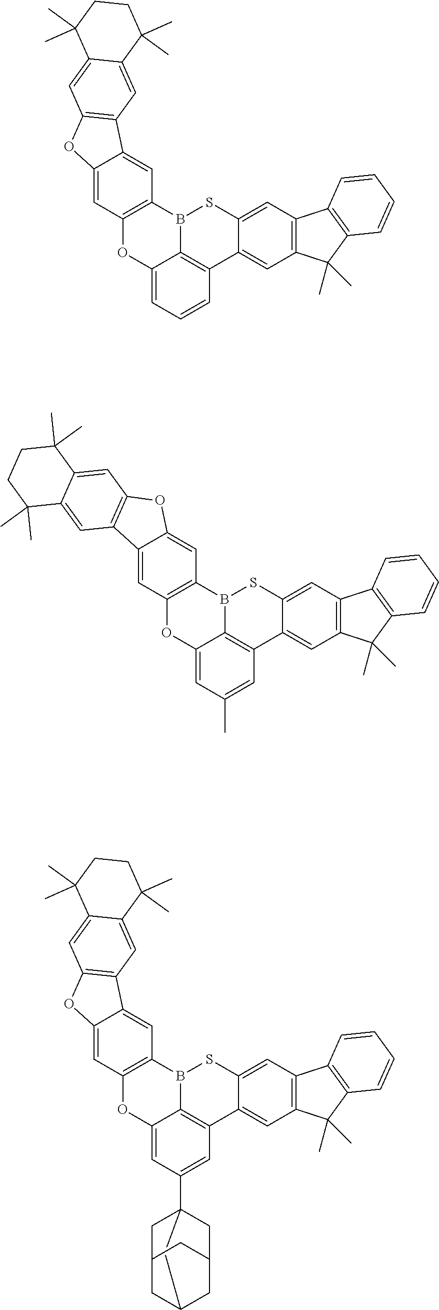 [SMILES: CC1(C)CCC(C)(C)c2cc3c(cc21)oc1cc2c(cc13)B1Sc3cc4c(cc3-c3cccc(c31)O2)C(C)(C)c1ccccc1-4 ; Cc1cc2c3c(c1)-c1cc4c(cc1SB3c1cc3oc5cc6c(cc5c3cc1O2)C(C)(C)CCC6(C)C)-c1ccccc1C4(C)C ; CC1(C)CCC(C)(C)c2cc3c(cc21)oc1cc2c(cc13)B1Sc3cc4c(cc3-c3cc(C56CC7CC(CC(C7)C5)C6)cc(c31)O2)C(C)(C)c1ccccc1-4]

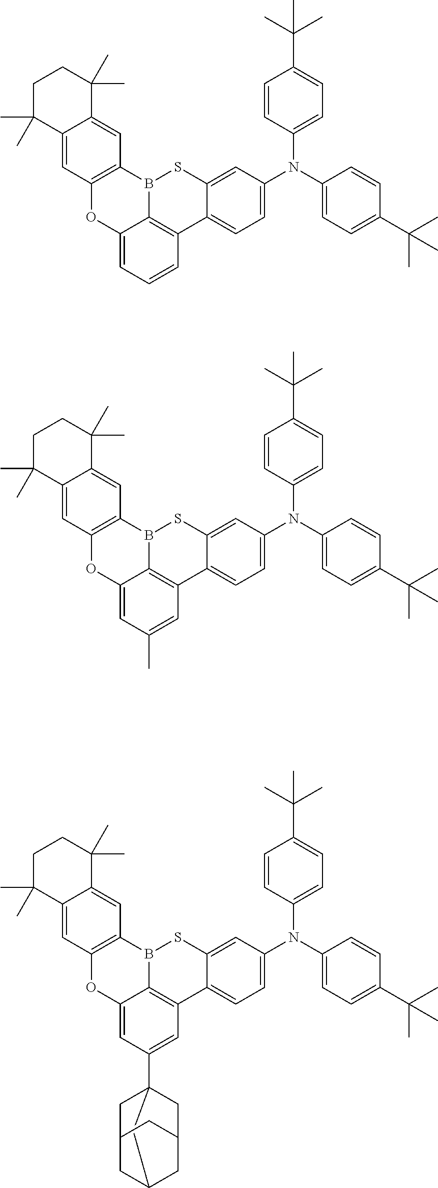

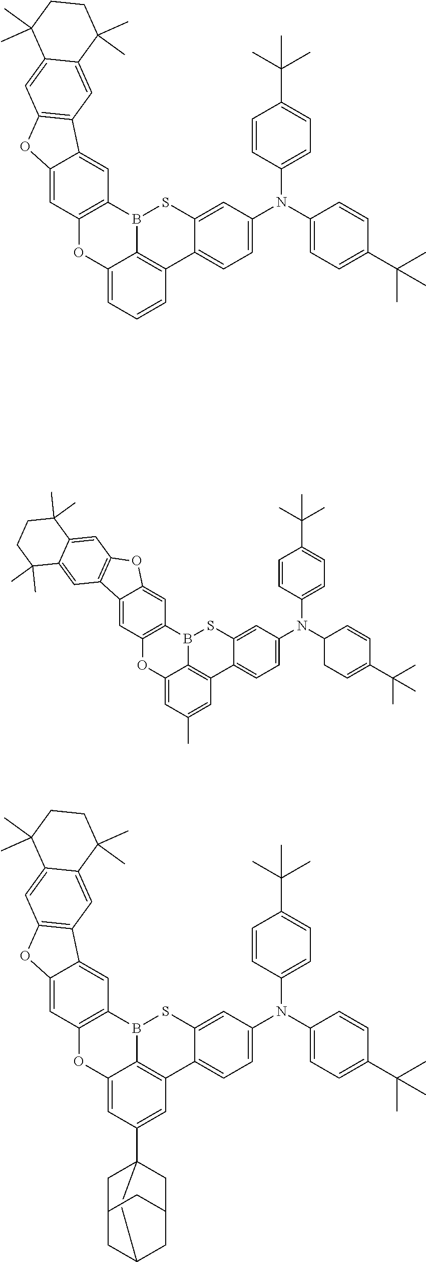

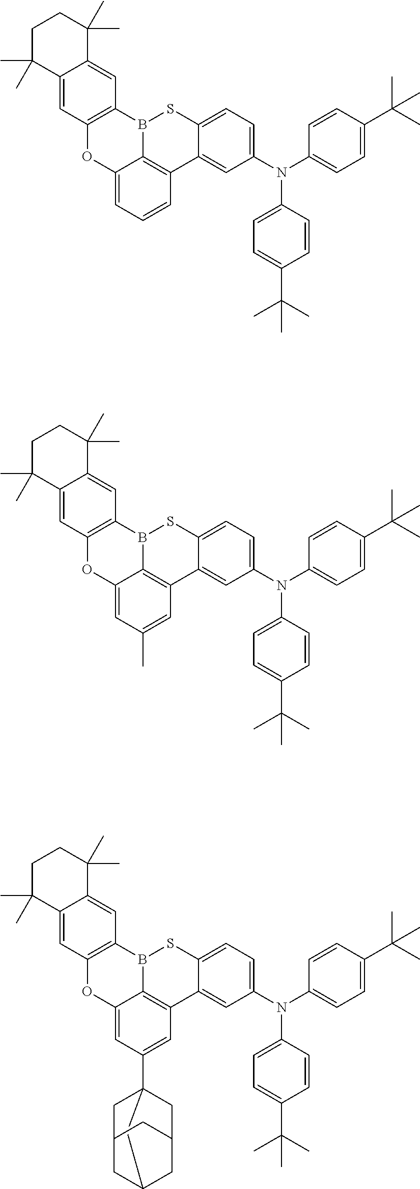

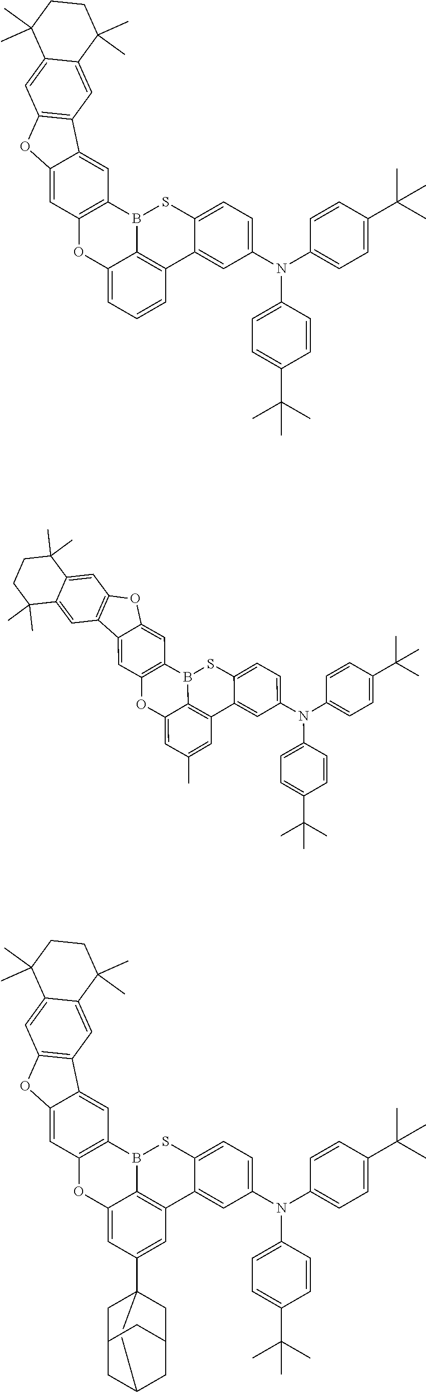

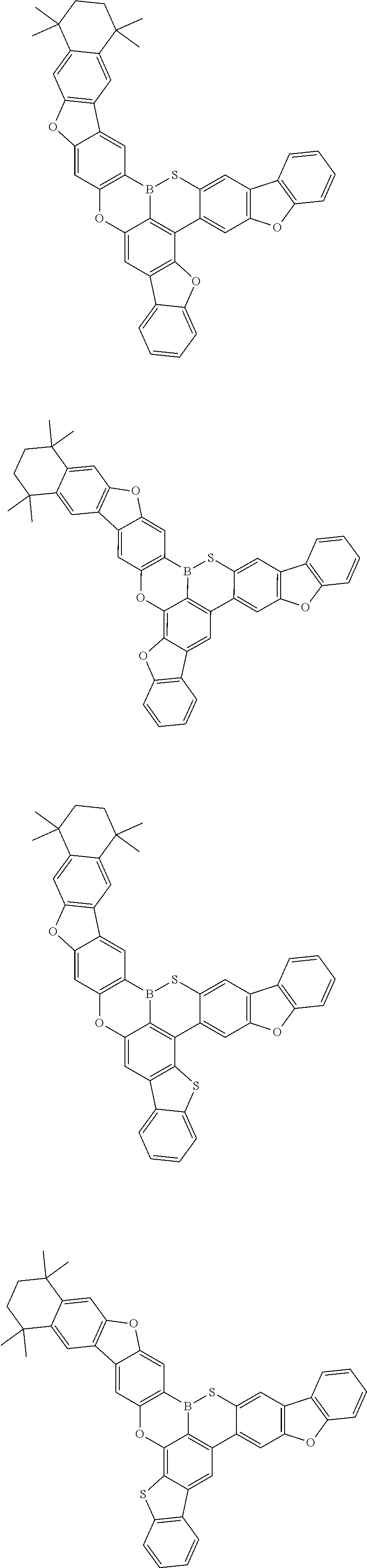 [SMILES: CC1(C)CCC(C)(C)c2cc3c(cc21)oc1cc2c(cc13)B1Sc3cc4c(cc3-c3c1c(cc1c3oc3ccccc31)O2)oc1ccccc14 ; CC1(C)CCC(C)(C)c2cc3c(cc21)oc1cc2c(cc13)Oc1c3c(cc4c1oc1ccccc14)-c1cc4oc5ccccc5c4cc1SB23 ; CC1(C)CCC(C)(C)c2cc3c(cc21)oc1cc2c(cc13)B1Sc3cc4c(cc3-c3c1c(cc1c3sc3ccccc31)O2)oc1ccccc14 ; CC1(C)CCC(C)(C)c2cc3c(cc21)oc1cc2c(cc13)Oc1c3c(cc4c1sc1ccccc14)-c1cc4oc5ccccc5c4cc1SB23]

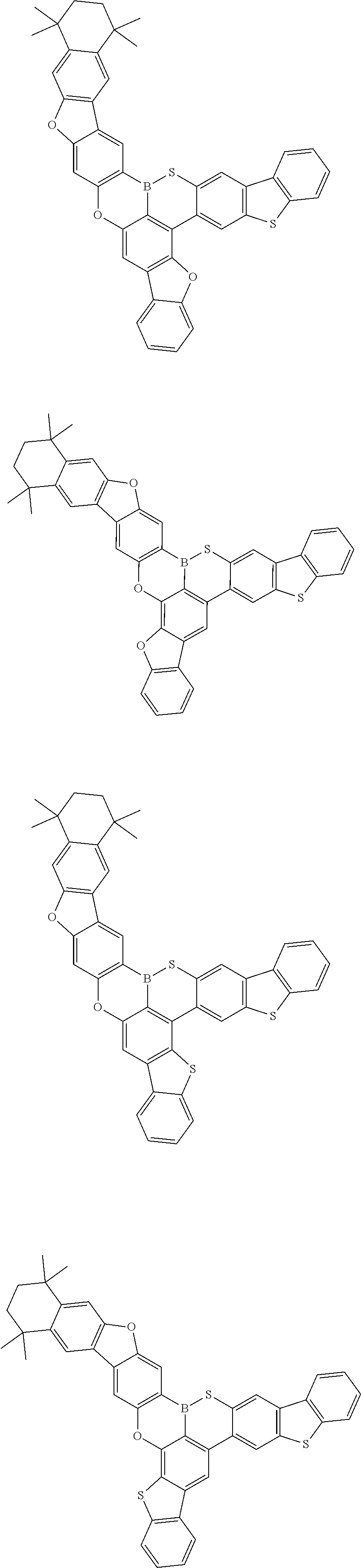 [SMILES: CC1(C)CCC(C)(C)c2cc3c(cc21)oc1cc2c(cc13)B1Sc3cc4c(cc3-c3c1c(cc1c3oc3ccccc31)O2)sc1ccccc14 ; CC1(C)CCC(C)(C)c2cc3c(cc21)oc1cc2c(cc13)Oc1c3c(cc4c1oc1ccccc14)-c1cc4sc5ccccc5c4cc1SB23 ; CC1(C)CCC(C)(C)c2cc3c(cc21)oc1cc2c(cc13)B1Sc3cc4c(cc3-c3c1c(cc1c3sc3ccccc31)O2)sc1ccccc14 ; CC1(C)CCC(C)(C)c2cc3c(cc21)oc1cc2c(cc13)Oc1c3c(cc4c1sc1ccccc14)-c1cc4sc5ccccc5c4cc1SB23]

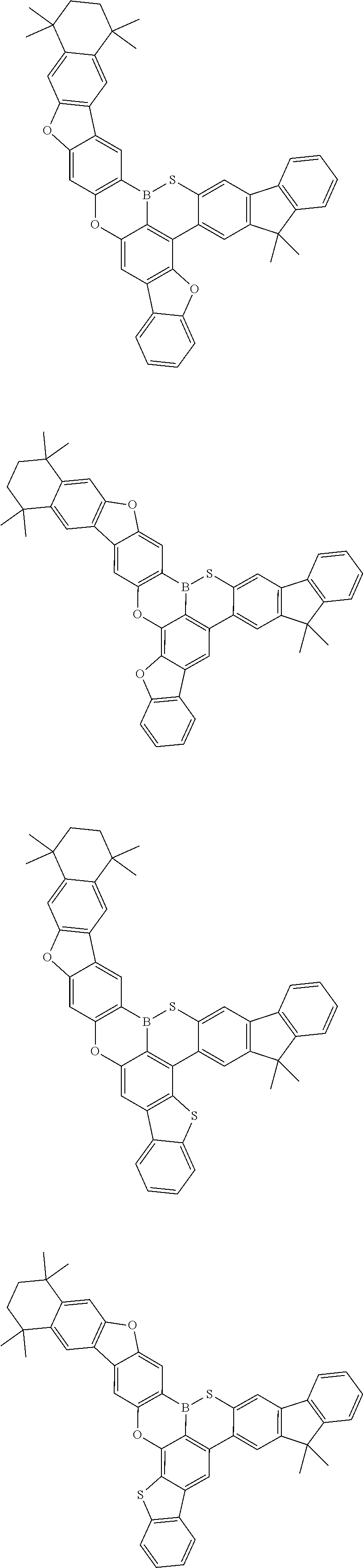 [SMILES: CC1(C)CCC(C)(C)c2cc3c(cc21)oc1cc2c(cc13)B1Sc3cc4c(cc3-c3c1c(cc1c3oc3ccccc31)O2)C(C)(C)c1ccccc1-4 ; CC1(C)CCC(C)(C)c2cc3c(cc21)oc1cc2c(cc13)Oc1c3c(cc4c1oc1ccccc14)-c1cc4c(cc1SB23)-c1ccccc1C4(C)C ; CC1(C)CCC(C)(C)c2cc3c(cc21)oc1cc2c(cc13)B1Sc3cc4c(cc3-c3c1c(cc1c3sc3ccccc31)O2)C(C)(C)c1ccccc1-4 ; CC1(C)CCC(C)(C)c2cc3c(cc21)oc1cc2c(cc13)Oc1c3c(cc4c1sc1ccccc14)-c1cc4c(cc1SB23)-c1ccccc1C4(C)C]

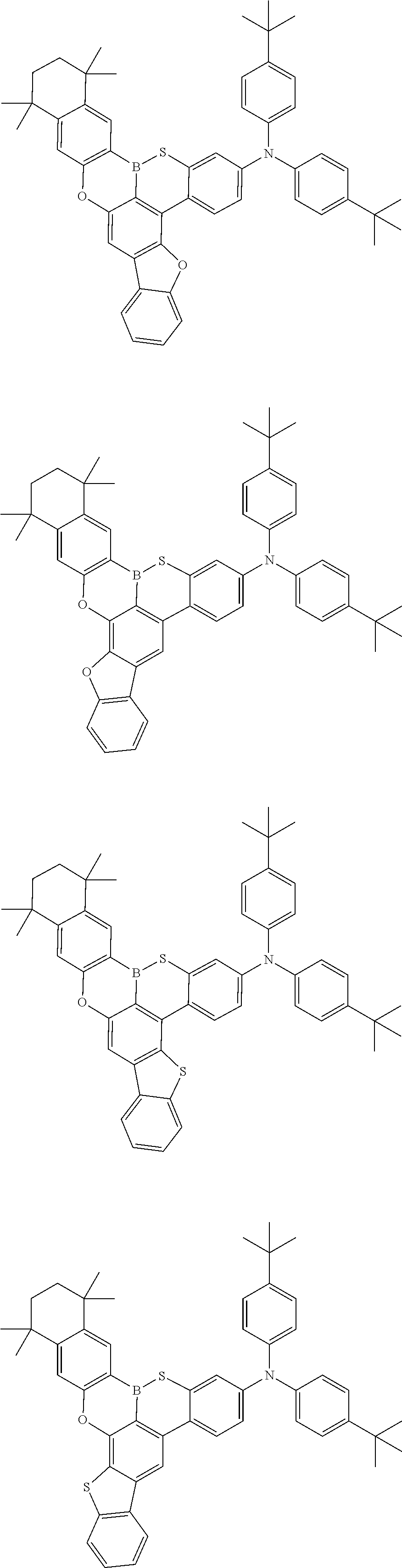

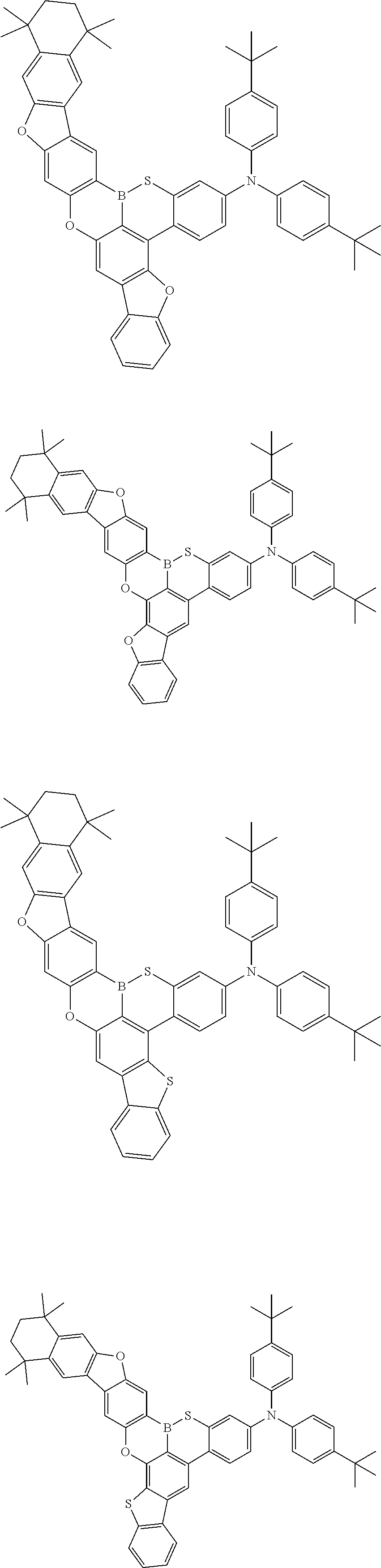

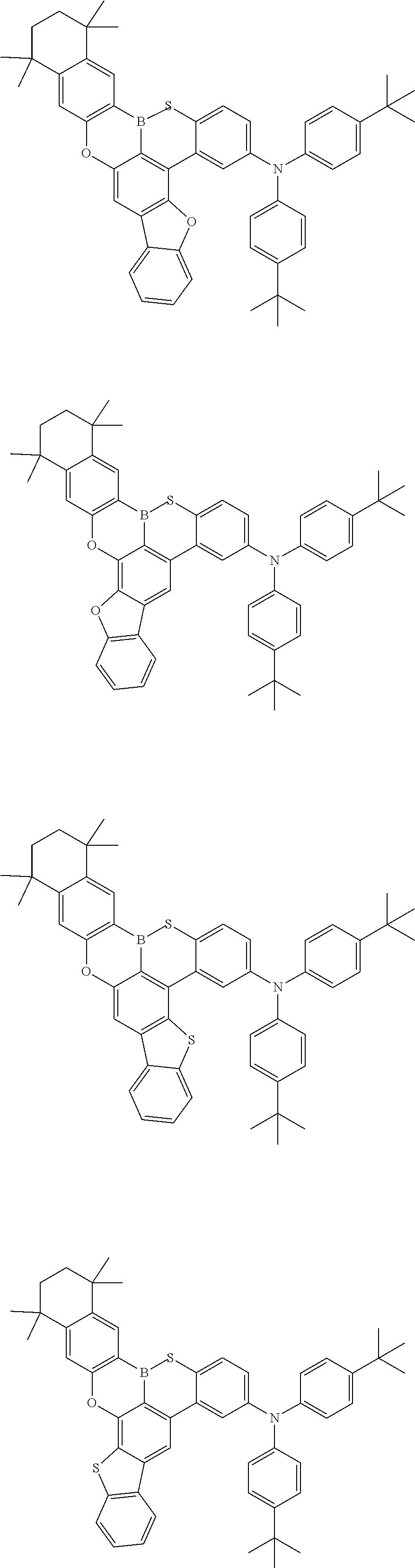

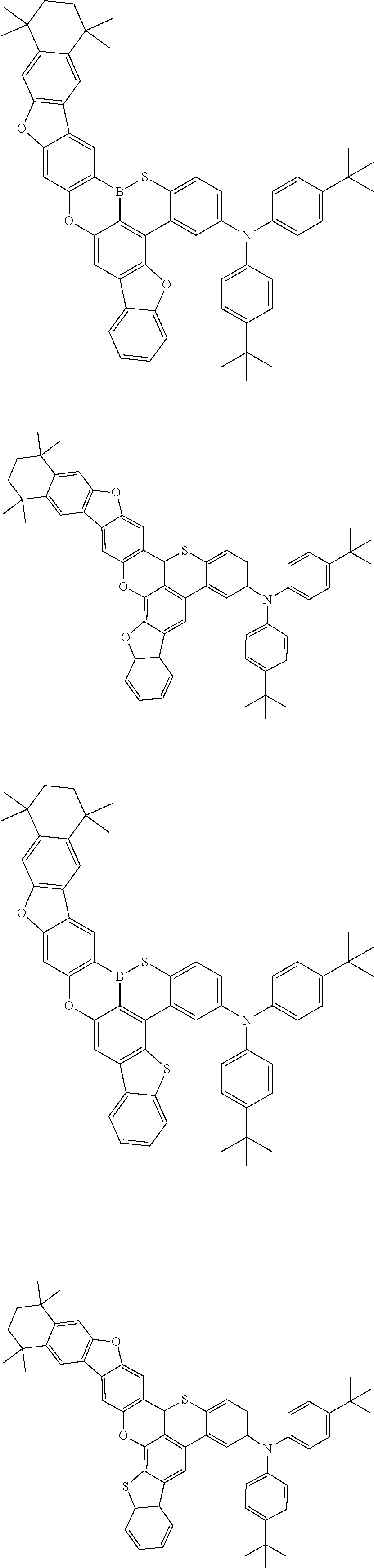

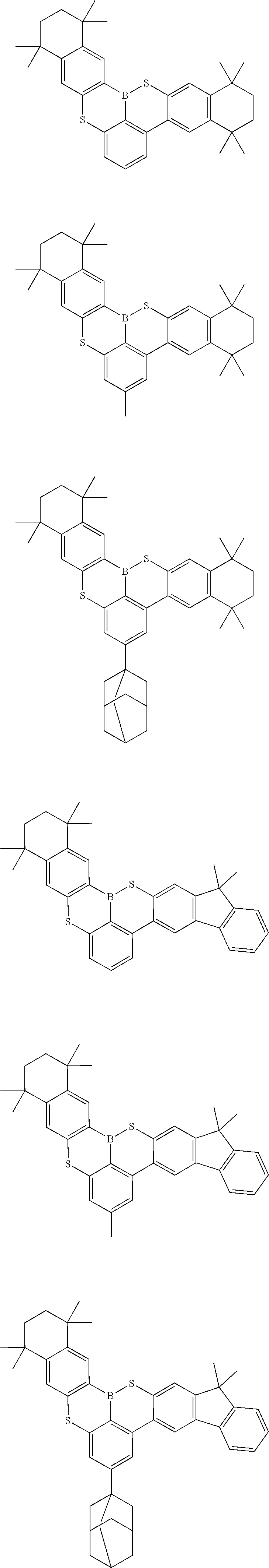 [SMILES: CC1(C)CCC(C)(C)c2cc3c(cc21)Sc1cccc2c1B3Sc1cc3c(cc1-2)C(C)(C)CCC3(C)C ; Cc1cc2c3c(c1)-c1cc4c(cc1SB3c1cc3c(cc1S2)C(C)(C)CCC3(C)C)C(C)(C)CCC4(C)C ; CC1(C)CCC(C)(C)c2cc3c(cc21)Sc1cc(C24CC5CC(CC(C5)C2)C4)cc2c1B3Sc1cc3c(cc1-2)C(C)(C)CCC3(C)C ; CC1(C)CCC(C)(C)c2cc3c(cc21)Sc1cccc2c1B3Sc1cc3c(cc1-2)-c1ccccc1C3(C)C ; Cc1cc2c3c(c1)-c1cc4c(cc1SB3c1cc3c(cc1S2)C(C)(C)CCC3(C)C)C(C)(C)c1ccccc1-4 ; CC1(C)CCC(C)(C)c2cc3c(cc21)Sc1cc(C24CC5CC(CC(C5)C2)C4)cc2c1B3Sc1cc3c(cc1-2)-c1ccccc1C3(C)C]

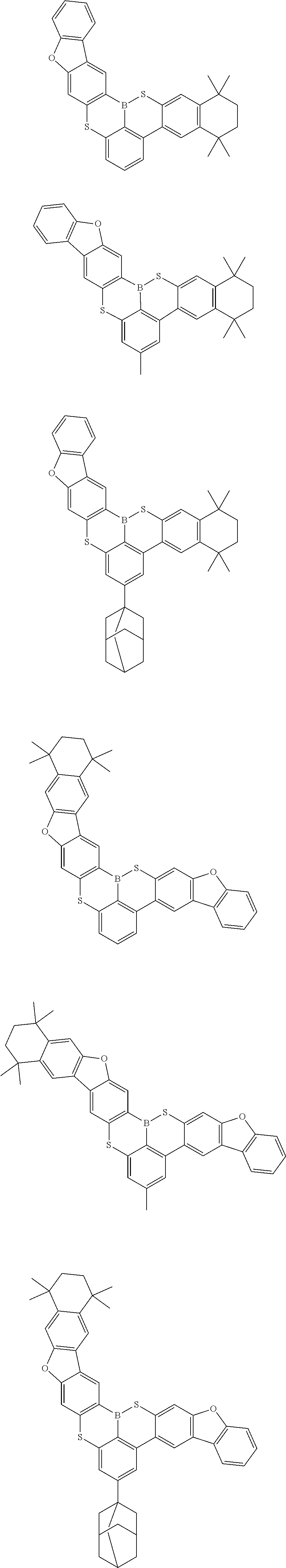 [SMILES: CC1(C)CCC(C)(C)c2cc3c(cc21)SB1c2cc4c(cc2Sc2cccc-3c21)oc1ccccc14 ; Cc1cc2c3c(c1)-c1cc4c(cc1SB3c1cc3oc5ccccc5c3cc1S2)C(C)(C)CCC4(C)C ; CC1(C)CCC(C)(C)c2cc3c(cc21)SB1c2cc4c(cc2Sc2cc(C56CC7CC(CC(C7)C5)C6)cc-3c21)oc1ccccc14 ; CC1(C)CCC(C)(C)c2cc3c(cc21)oc1cc2c(cc13)B1Sc3cc4oc5ccccc5c4cc3-c3cccc(c31)S2 ; Cc1cc2c3c(c1)-c1cc4c(cc1SB3c1cc3oc5cc6c(cc5c3cc1S2)C(C)(C)CCC6(C)C)oc1ccccc14 ; CC1(C)CCC(C)(C)c2cc3c(cc21)oc1cc2c(cc13)B1Sc3cc4oc5ccccc5c4cc3-c3cc(C45CC6CC(CC(C6)C4)C5)cc(c31)S2]

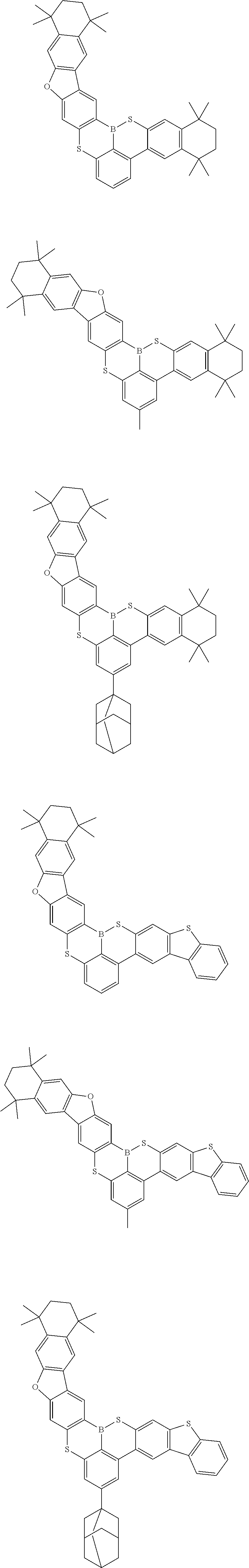

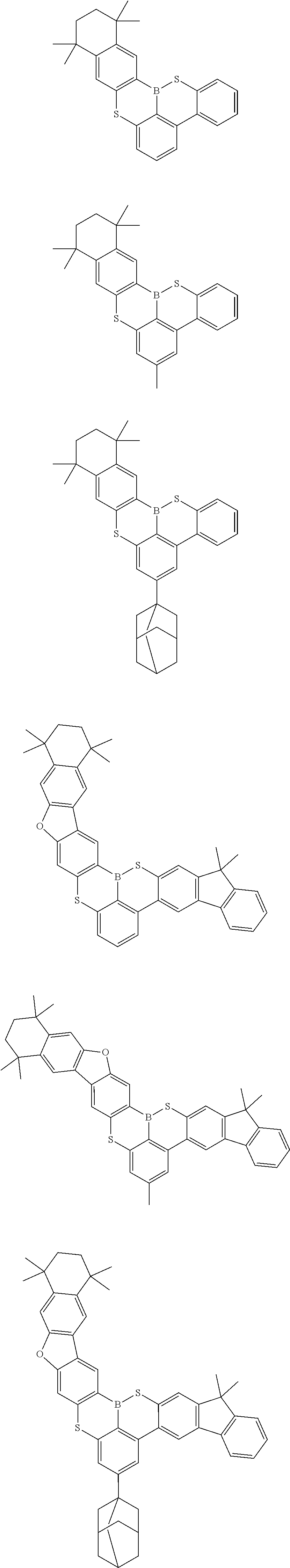

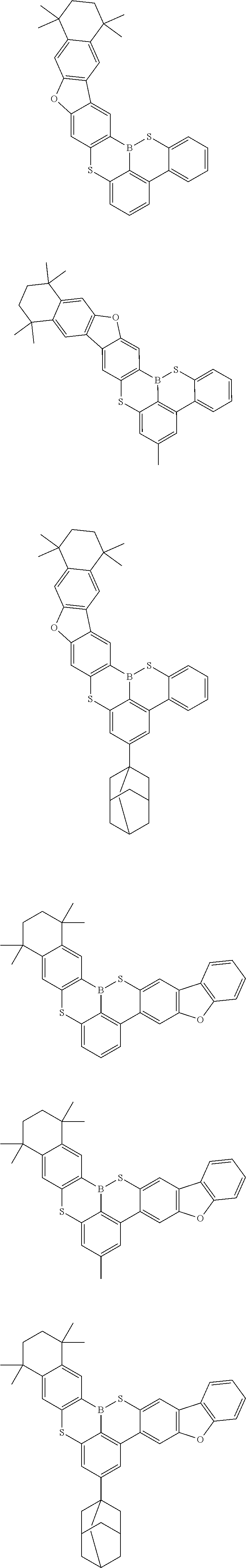

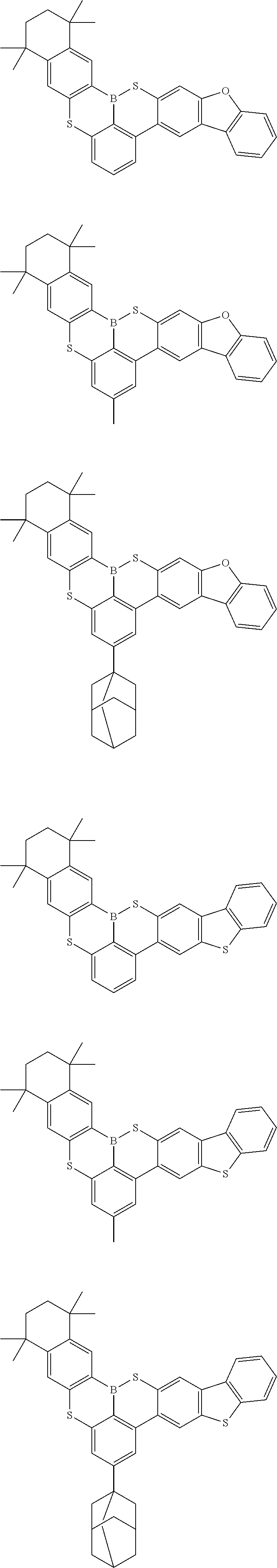 [SMILES: CC1(C)CCC(C)(C)c2cc3c(cc21)Sc1cccc2c1B3Sc1cc3oc4ccccc4c3cc1-2 ; Cc1cc2c3c(c1)-c1cc4c(cc1SB3c1cc3c(cc1S2)C(C)(C)CCC3(C)C)oc1ccccc14 ; CC1(C)CCC(C)(C)c2cc3c(cc21)Sc1cc(C24CC5CC(CC(C5)C2)C4)cc2c1B3Sc1cc3oc4ccccc4c3cc1-2 ; CC1(C)CCC(C)(C)c2cc3c(cc21)Sc1cccc2c1B3Sc1cc3c(cc1-2)sc1ccccc13 ; Cc1cc2c3c(c1)-c1cc4sc5ccccc5c4cc1SB3c1cc3c(cc1S2)C(C)(C)CCC3(C)C ; CC1(C)CCC(C)(C)c2cc3c(cc21)Sc1cc(C24CC5CC(CC(C5)C2)C4)cc2c1B3Sc1cc3c(cc1-2)sc1ccccc13]

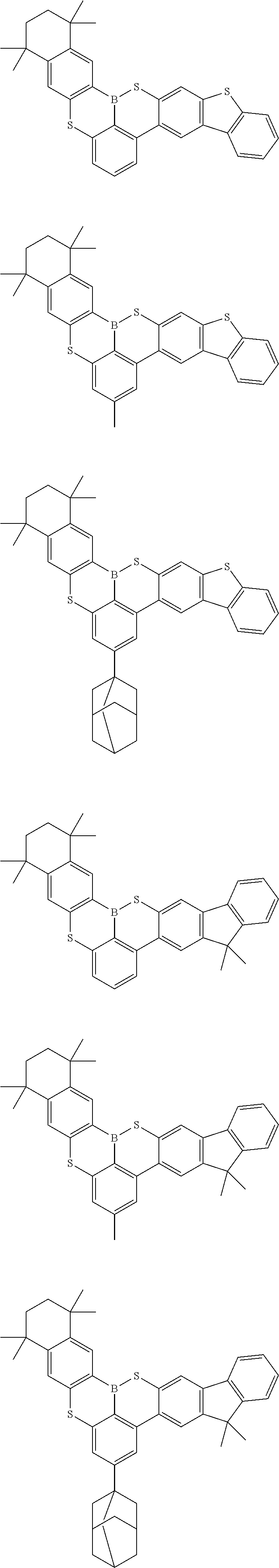 [SMILES: CC1(C)CCC(C)(C)c2cc3c(cc21)Sc1cccc2c1B3Sc1cc3sc4ccccc4c3cc1-2 ; Cc1cc2c3c(c1)-c1cc4c(cc1SB3c1cc3c(cc1S2)C(C)(C)CCC3(C)C)sc1ccccc14 ; CC1(C)CCC(C)(C)c2cc3c(cc21)Sc1cc(C24CC5CC(CC(C5)C2)C4)cc2c1B3Sc1cc3sc4ccccc4c3cc1-2 ; CC1(C)CCC(C)(C)c2cc3c(cc21)Sc1cccc2c1B3Sc1cc3c(cc1-2)C(C)(C)c1ccccc1-3 ; Cc1cc2c3c(c1)-c1cc4c(cc1SB3c1cc3c(cc1S2)C(C)(C)CCC3(C)C)-c1ccccc1C4(C)C ; CC1(C)CCC(C)(C)c2cc3c(cc21)Sc1cc(C24CC5CC(CC(C5)C2)C4)cc2c1B3Sc1cc3c(cc1-2)C(C)(C)c1ccccc1-3]

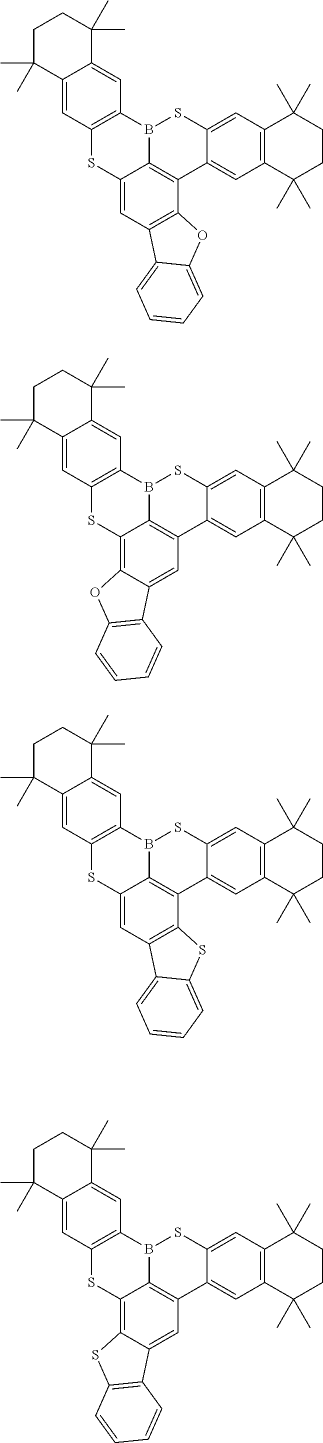

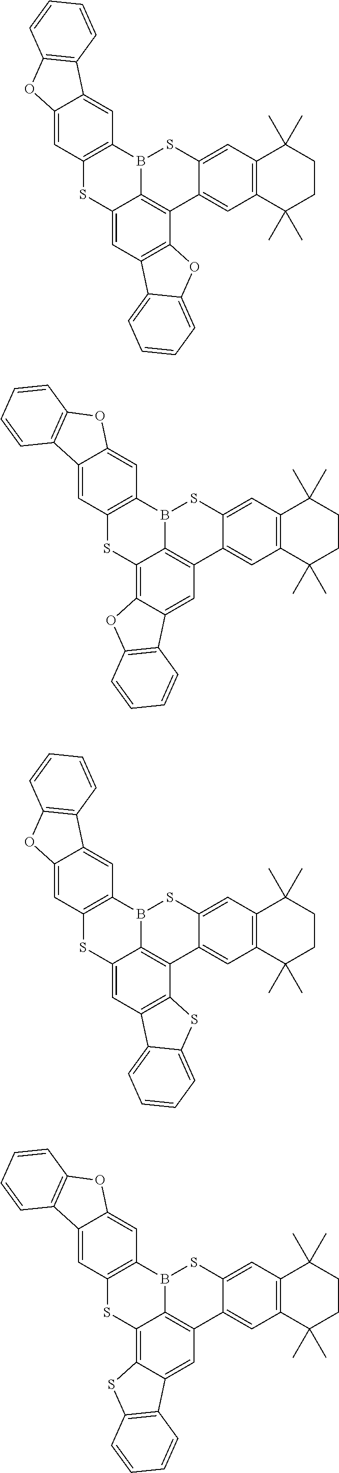

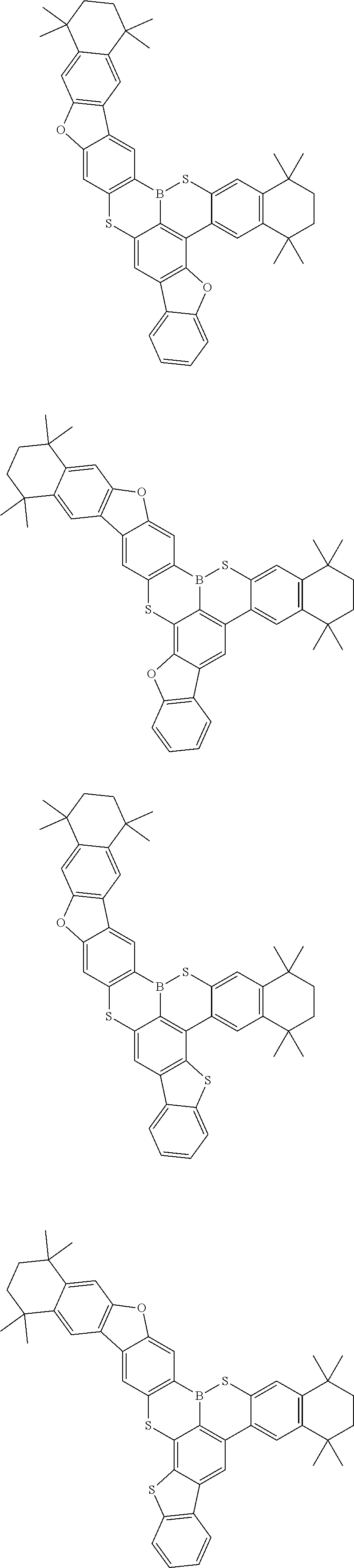 [SMILES: CC1(C)CCC(C)(C)c2cc3c(cc21)SB1c2cc4c(cc2Sc2cc5c(oc6ccccc65)c-3c21)oc1cc2c(cc14)C(C)(C)CCC2(C)C ; CC1(C)CCC(C)(C)c2cc3c(cc21)SB1c2cc4oc5cc6c(cc5c4cc2Sc2c1c-3cc1c2oc2ccccc21)C(C)(C)CCC6(C)C ; CC1(C)CCC(C)(C)c2cc3c(cc21)SB1c2cc4c(cc2Sc2cc5c(sc6ccccc65)c-3c21)oc1cc2c(cc14)C(C)(C)CCC2(C)C ; CC1(C)CCC(C)(C)c2cc3c(cc21)SB1c2cc4oc5cc6c(cc5c4cc2Sc2c1c-3cc1c2sc2ccccc21)C(C)(C)CCC6(C)C]

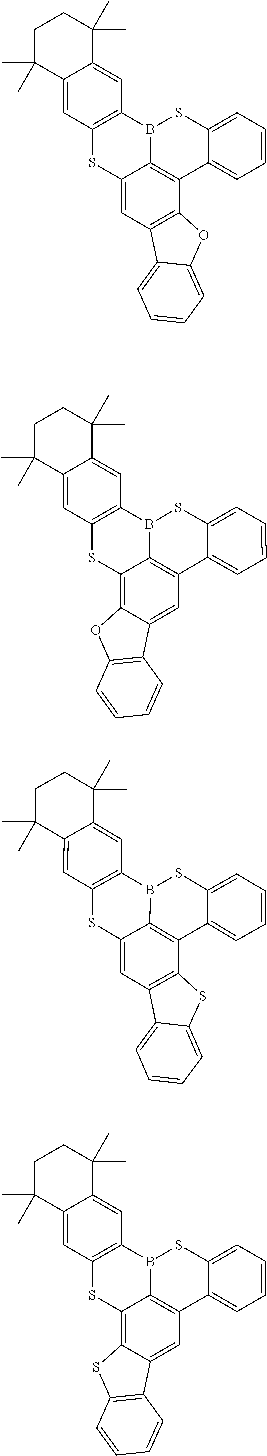

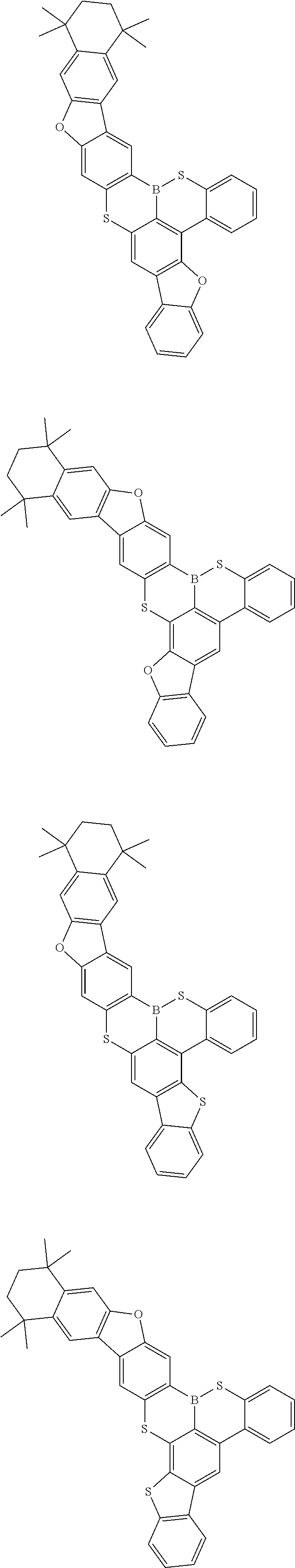 [SMILES: CC1(C)CCC(C)(C)c2cc3c(cc21)oc1cc2c(cc13)B1Sc3ccccc3-c3c1c(cc1c3oc3ccccc31)S2 ; CC1(C)CCC(C)(C)c2cc3c(cc21)oc1cc2c(cc13)Sc1c3c(cc4c1oc1ccccc14)-c1ccccc1SB23 ; CC1(C)CCC(C)(C)c2cc3c(cc21)oc1cc2c(cc13)B1Sc3ccccc3-c3c1c(cc1c3sc3ccccc31)S2 ; CC1(C)CCC(C)(C)c2cc3c(cc21)oc1cc2c(cc13)Sc1c3c(cc4c1sc1ccccc14)-c1ccccc1SB23]

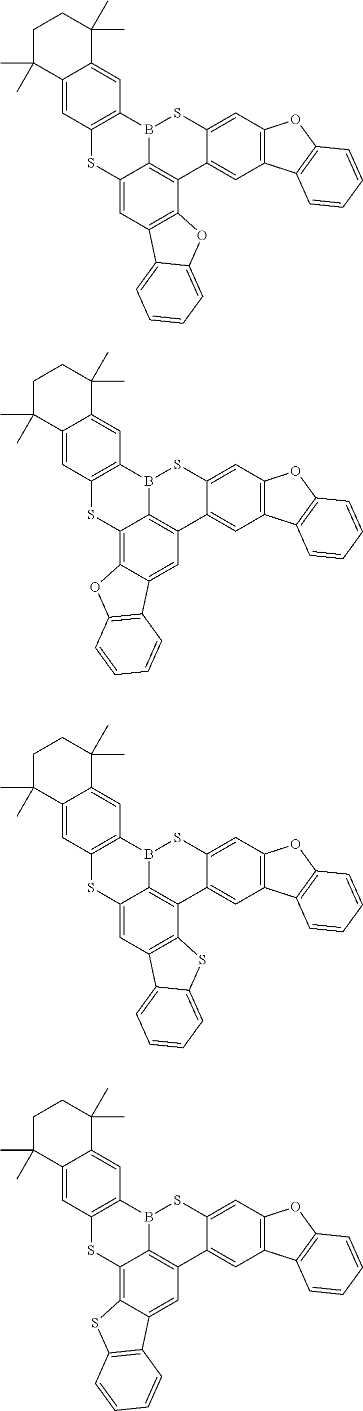 [SMILES: CC1(C)CCC(C)(C)c2cc3c(cc21)Sc1cc2c(oc4ccccc42)c2c1B3Sc1cc3oc4ccccc4c3cc1-2 ; CC1(C)CCC(C)(C)c2cc3c(cc21)Sc1c2c(cc4c1oc1ccccc14)-c1cc4c(cc1SB32)oc1ccccc14 ; CC1(C)CCC(C)(C)c2cc3c(cc21)Sc1cc2c(sc4ccccc42)c2c1B3Sc1cc3oc4ccccc4c3cc1-2 ; CC1(C)CCC(C)(C)c2cc3c(cc21)Sc1c2c(cc4c1sc1ccccc14)-c1cc4c(cc1SB32)oc1ccccc14]

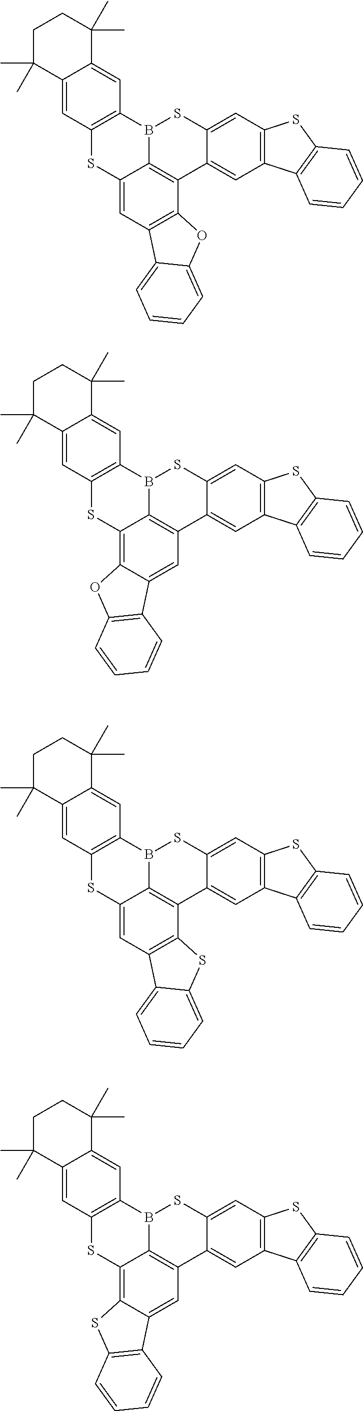 [SMILES: CC1(C)CCC(C)(C)c2cc3c(cc21)Sc1cc2c(oc4ccccc42)c2c1B3Sc1cc3sc4ccccc4c3cc1-2 ; CC1(C)CCC(C)(C)c2cc3c(cc21)Sc1c2c(cc4c1oc1ccccc14)-c1cc4c(cc1SB32)sc1ccccc14 ; CC1(C)CCC(C)(C)c2cc3c(cc21)Sc1cc2c(sc4ccccc42)c2c1B3Sc1cc3sc4ccccc4c3cc1-2 ; CC1(C)CCC(C)(C)c2cc3c(cc21)Sc1c2c(cc4c1sc1ccccc14)-c1cc4c(cc1SB32)sc1ccccc14]

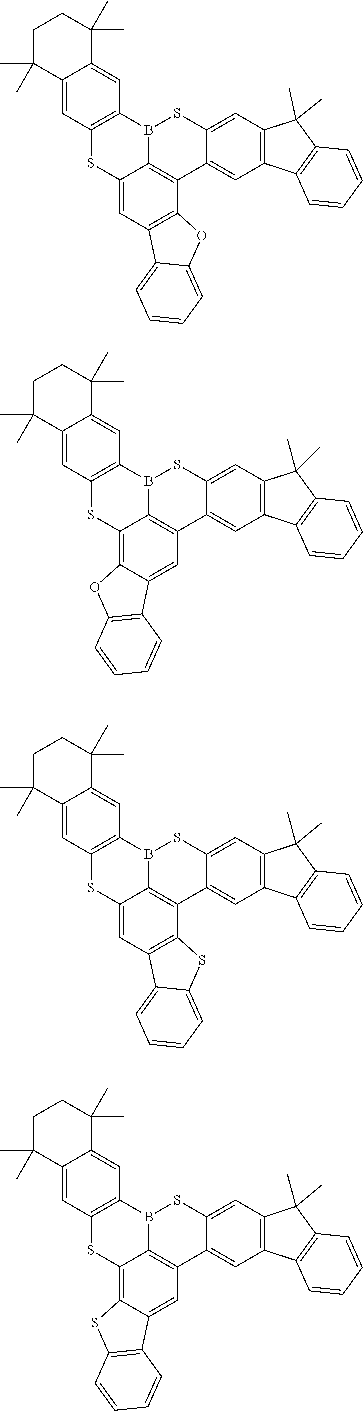 [SMILES: CC1(C)CCC(C)(C)c2cc3c(cc21)Sc1cc2c(oc4ccccc42)c2c1B3Sc1cc3c(cc1-2)-c1ccccc1C3(C)C ; CC1(C)CCC(C)(C)c2cc3c(cc21)Sc1c2c(cc4c1oc1ccccc14)-c1cc4c(cc1SB32)C(C)(C)c1ccccc1-4 ; CC1(C)CCC(C)(C)c2cc3c(cc21)Sc1cc2c(sc4ccccc42)c2c1B3Sc1cc3c(cc1-2)-c1ccccc1C3(C)C ; CC1(C)CCC(C)(C)c2cc3c(cc21)Sc1c2c(cc4c1sc1ccccc14)-c1cc4c(cc1SB32)C(C)(C)c1ccccc1-4]

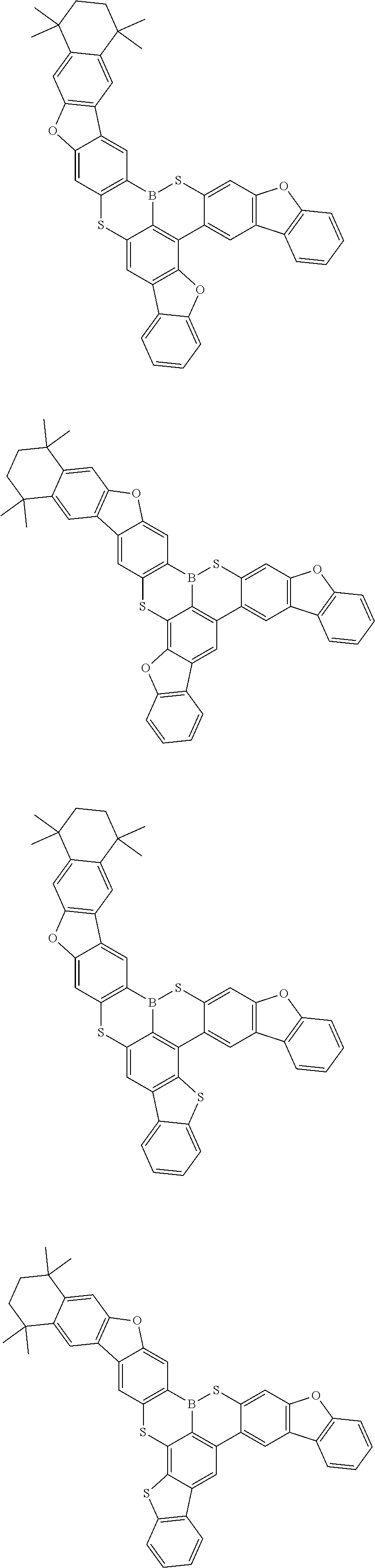

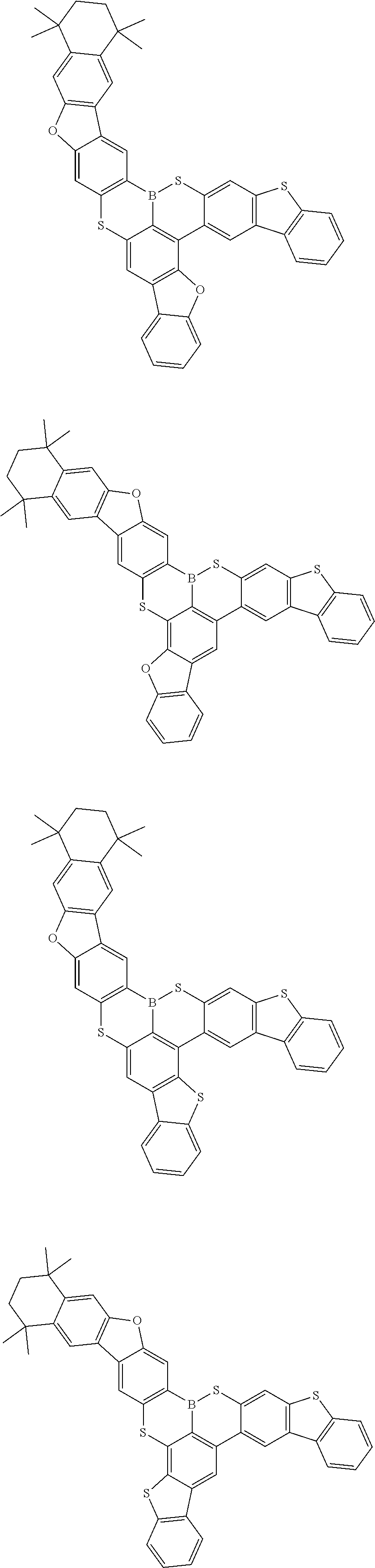

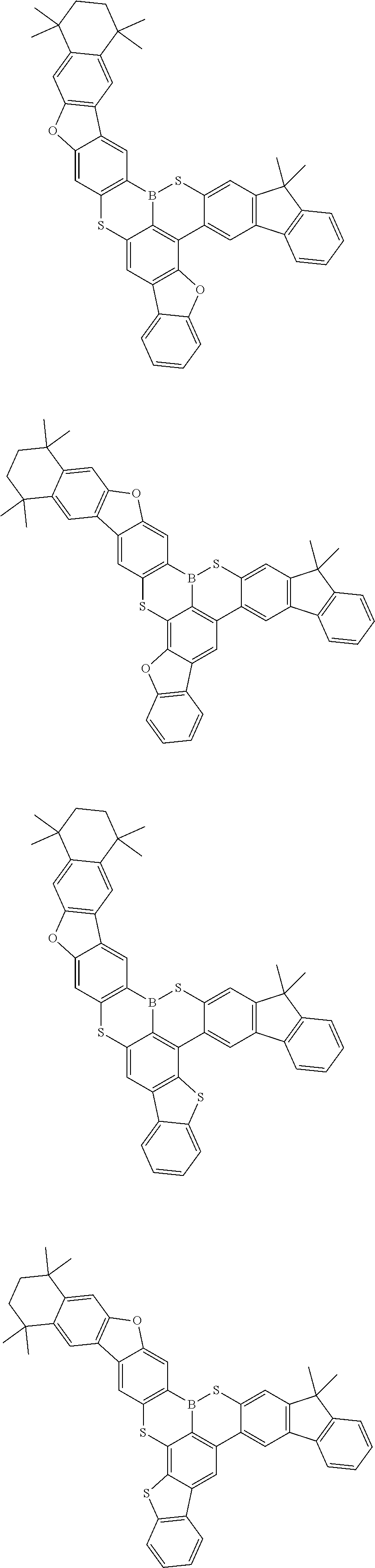

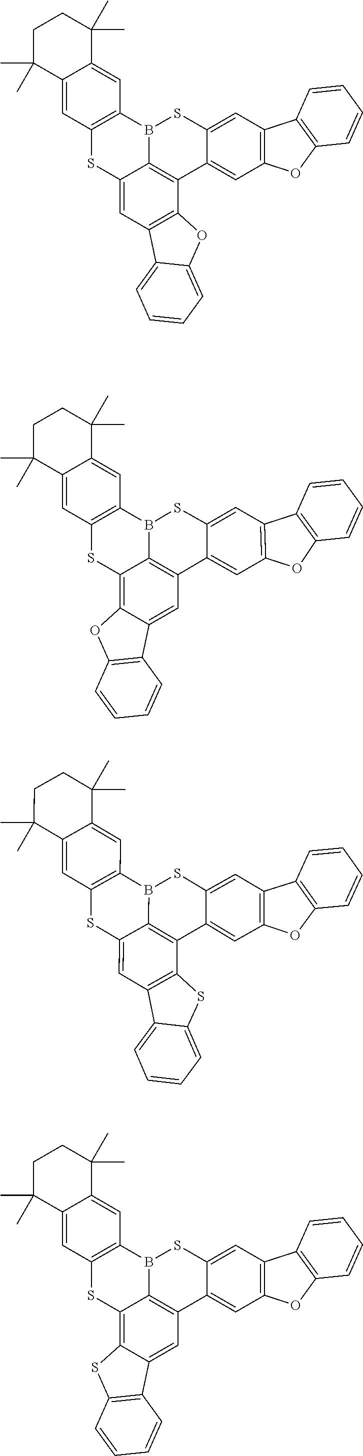

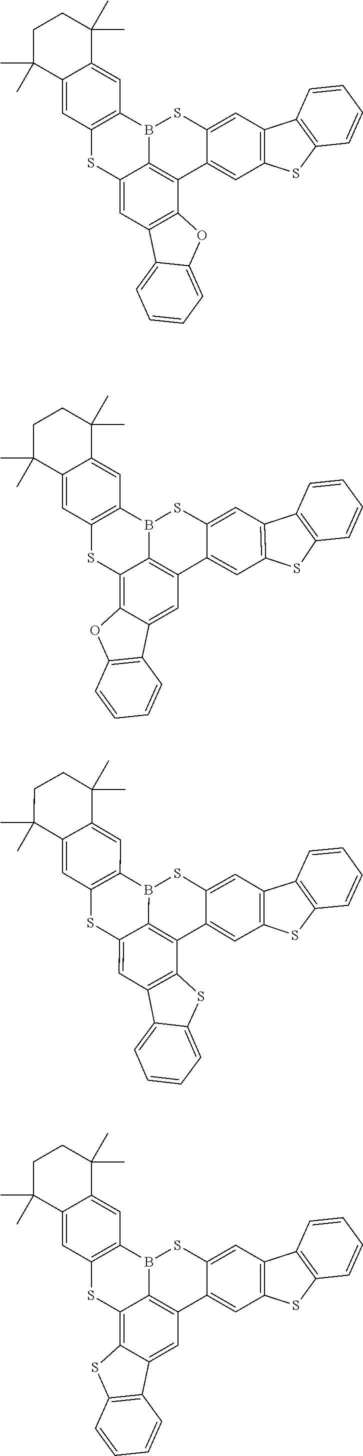

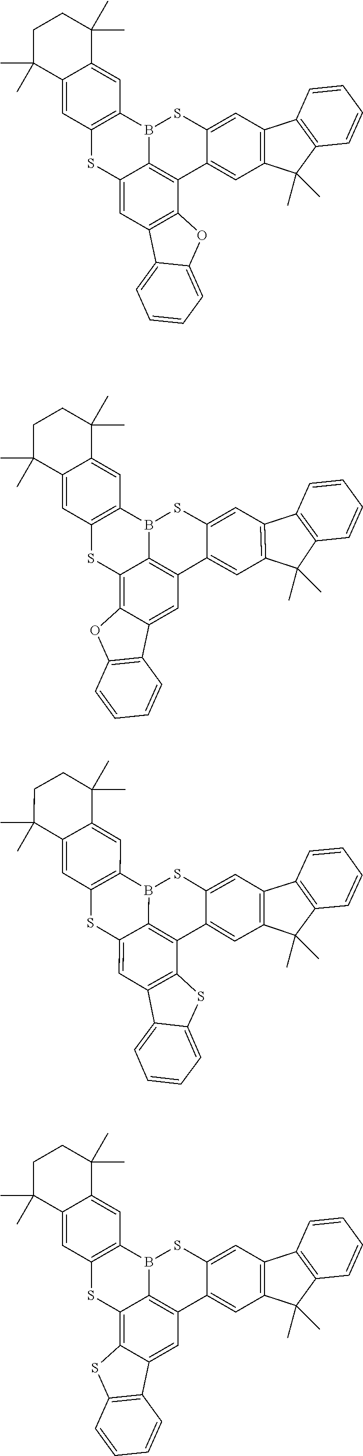

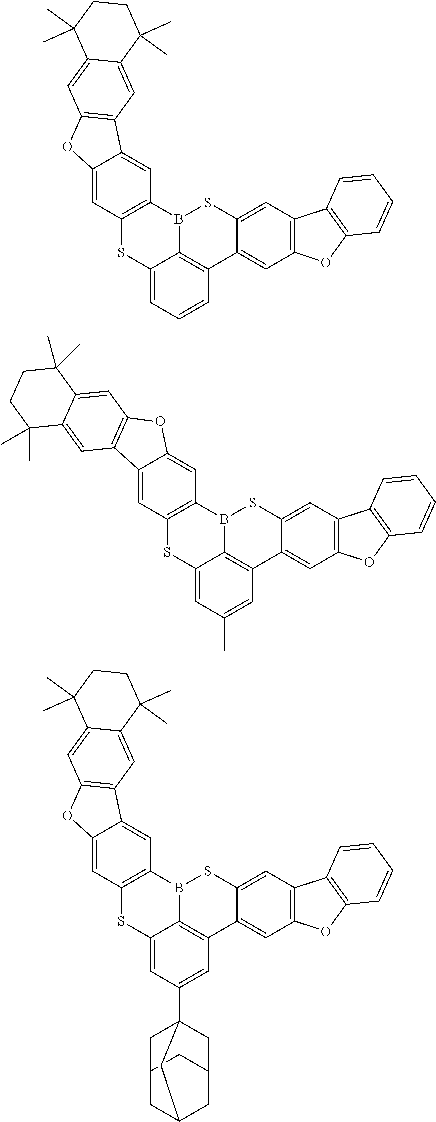

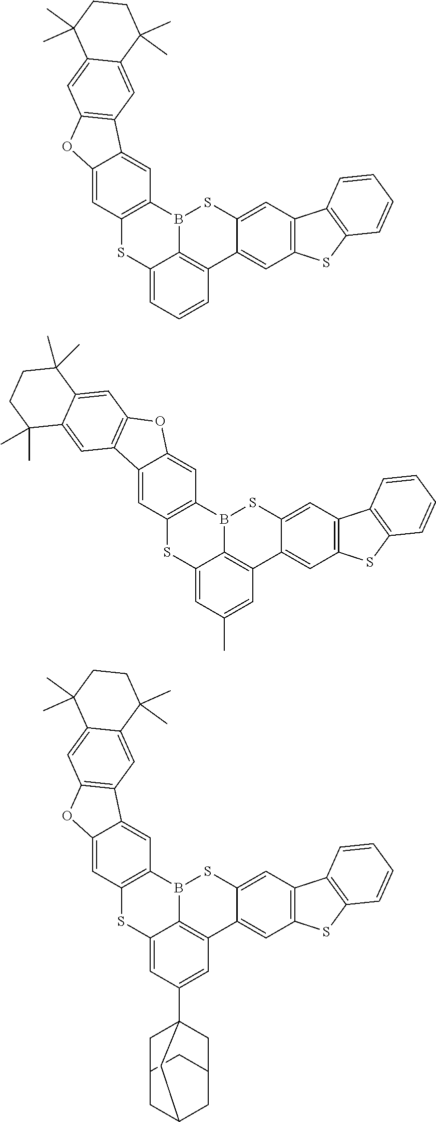

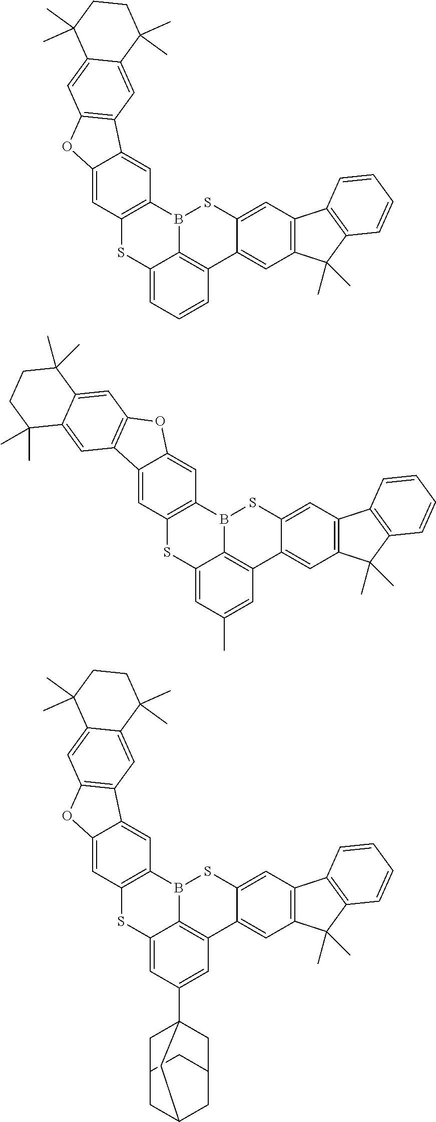

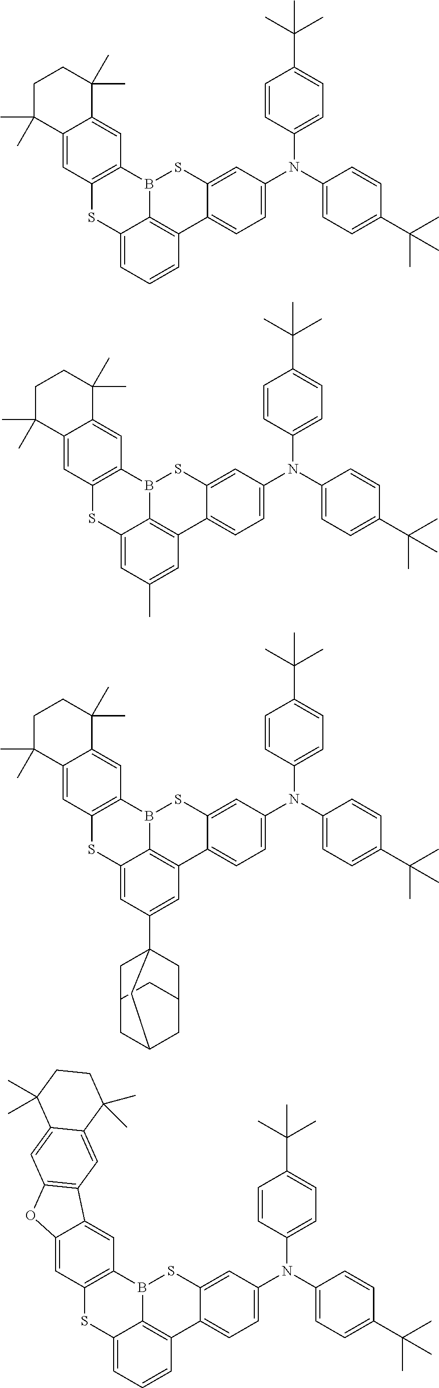

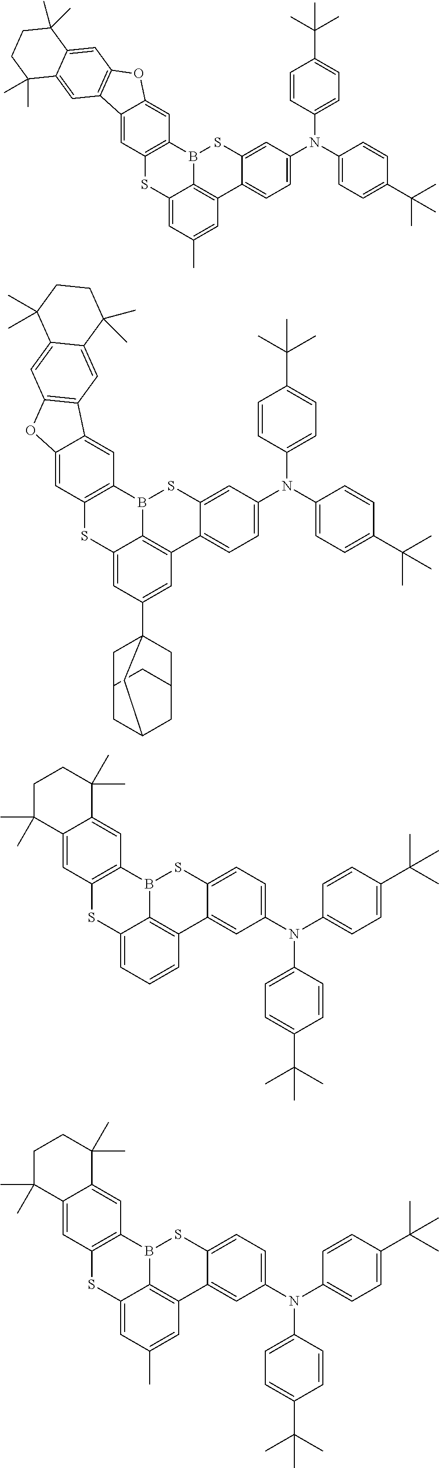

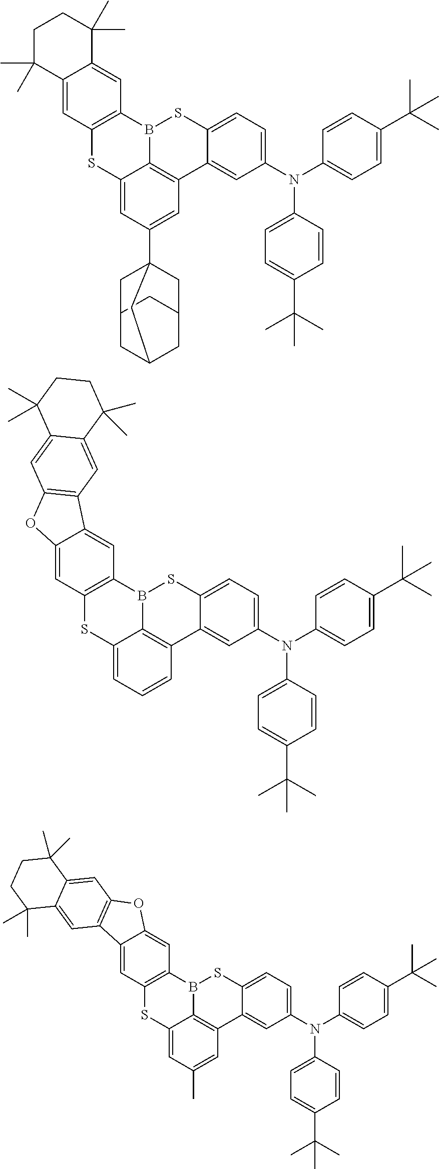

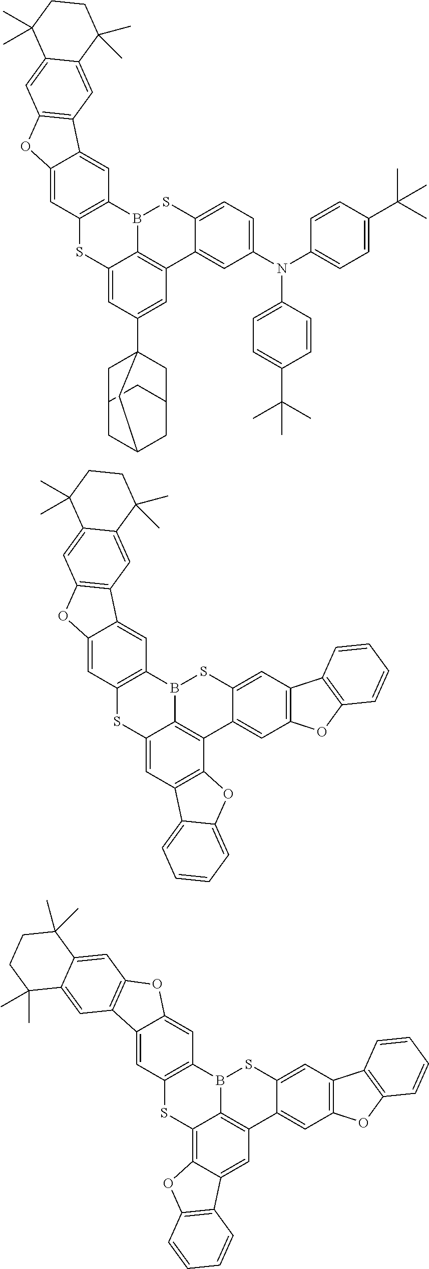

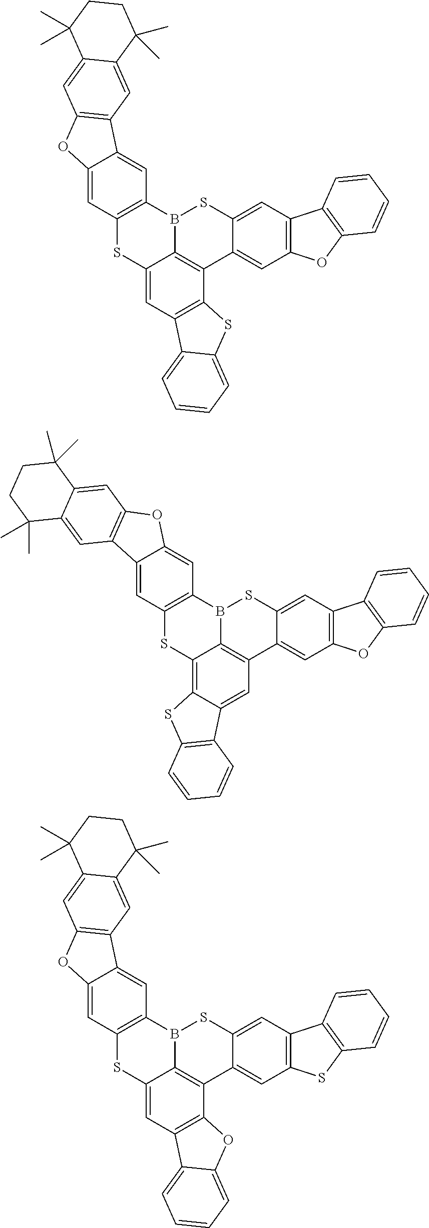

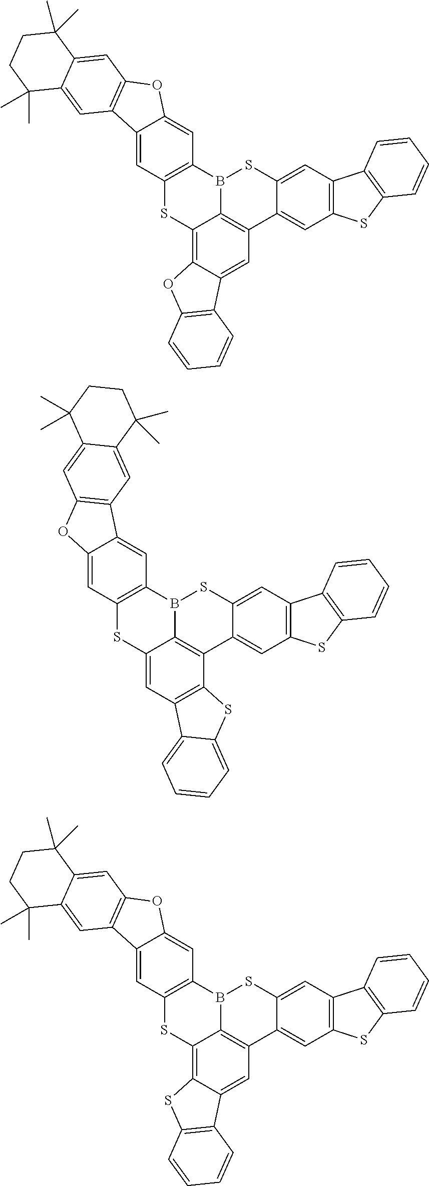

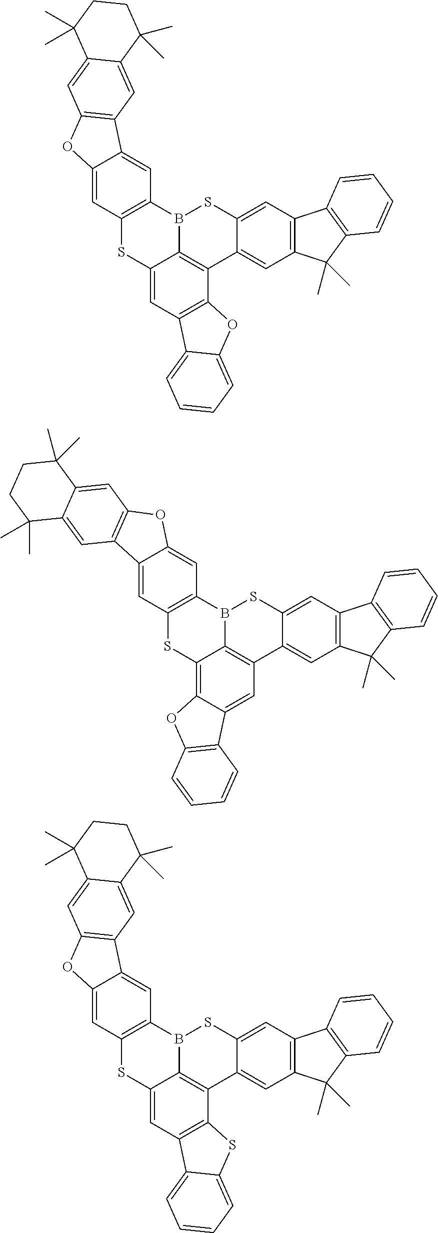

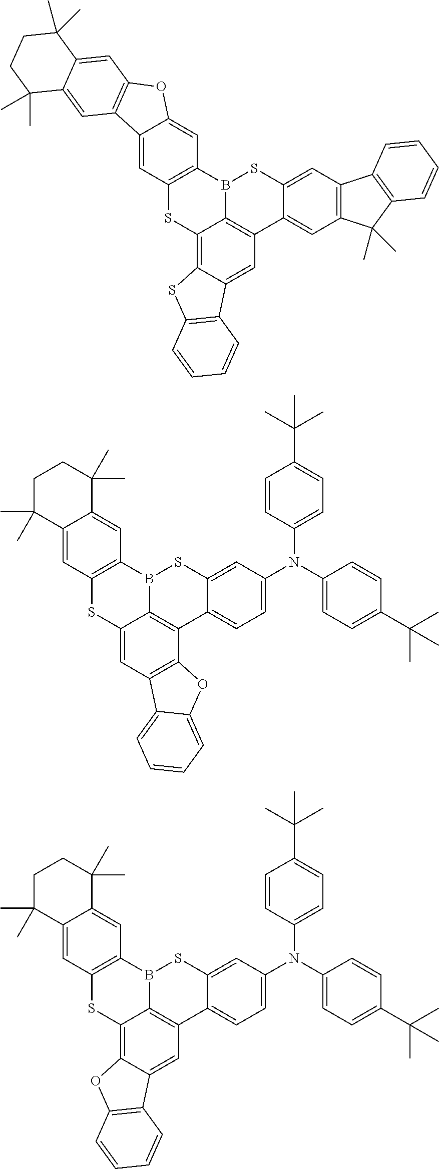

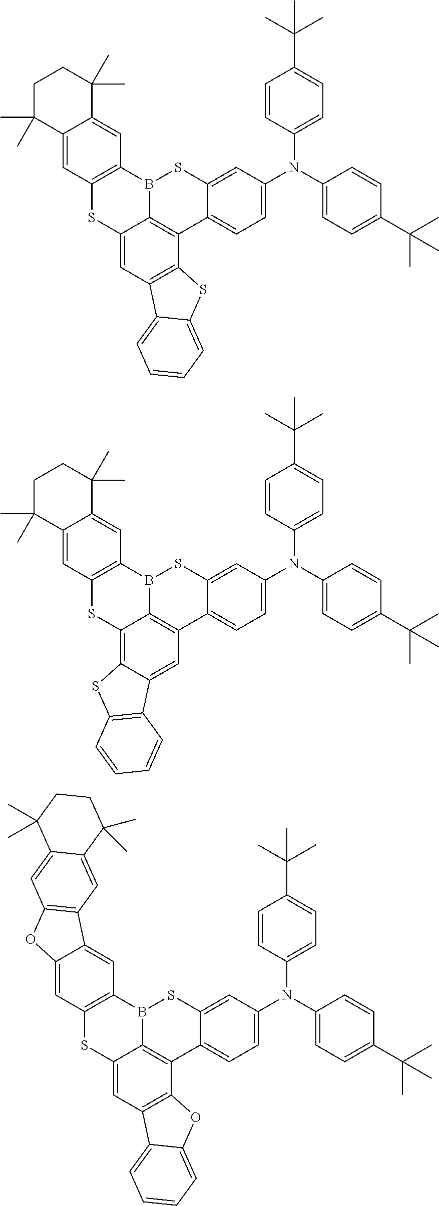

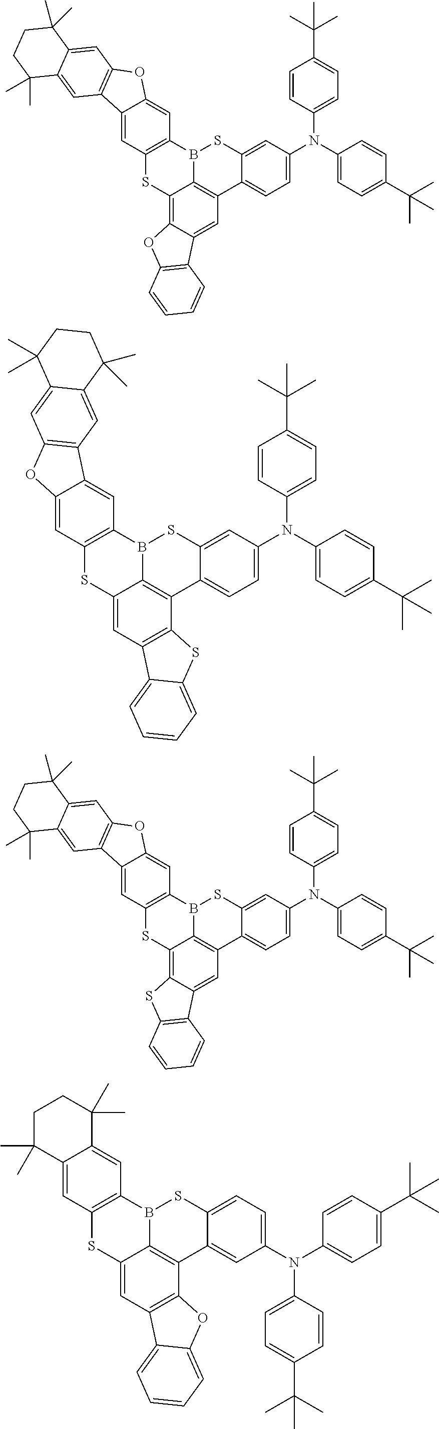

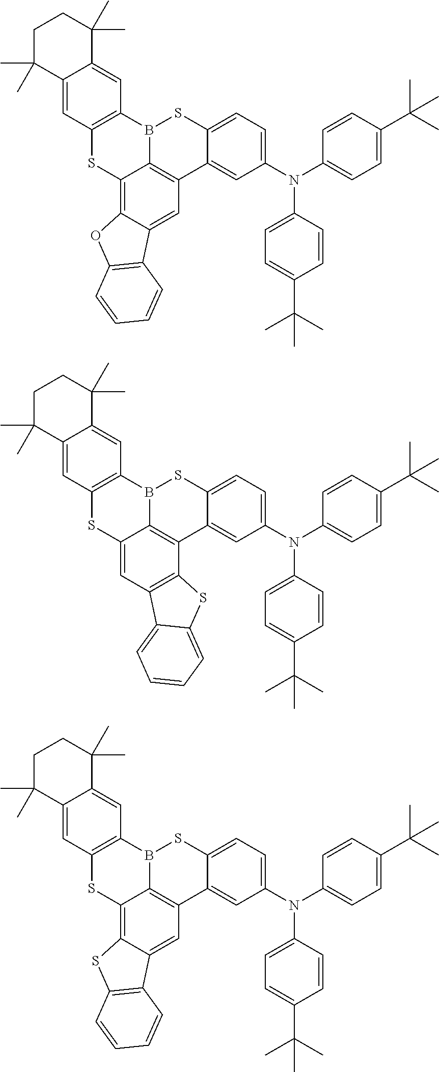

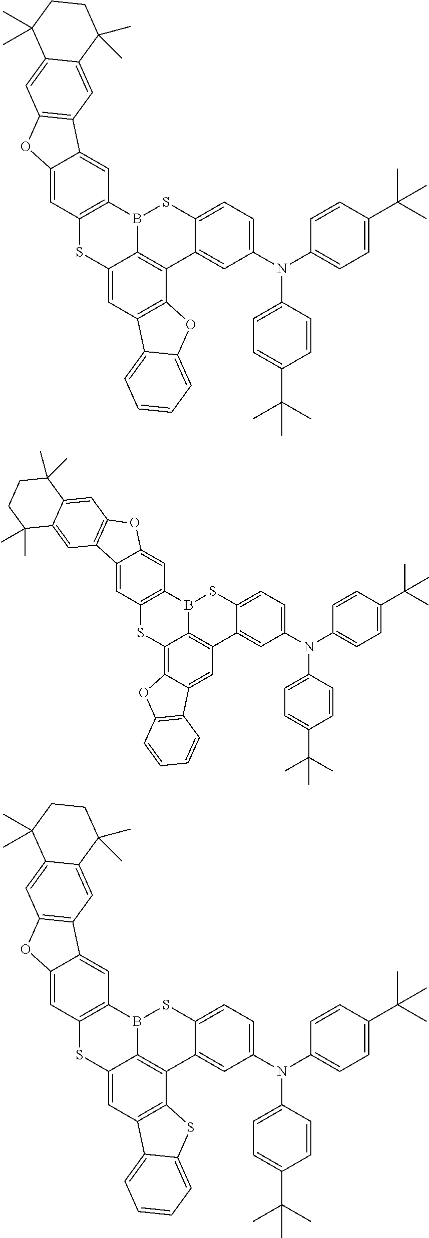

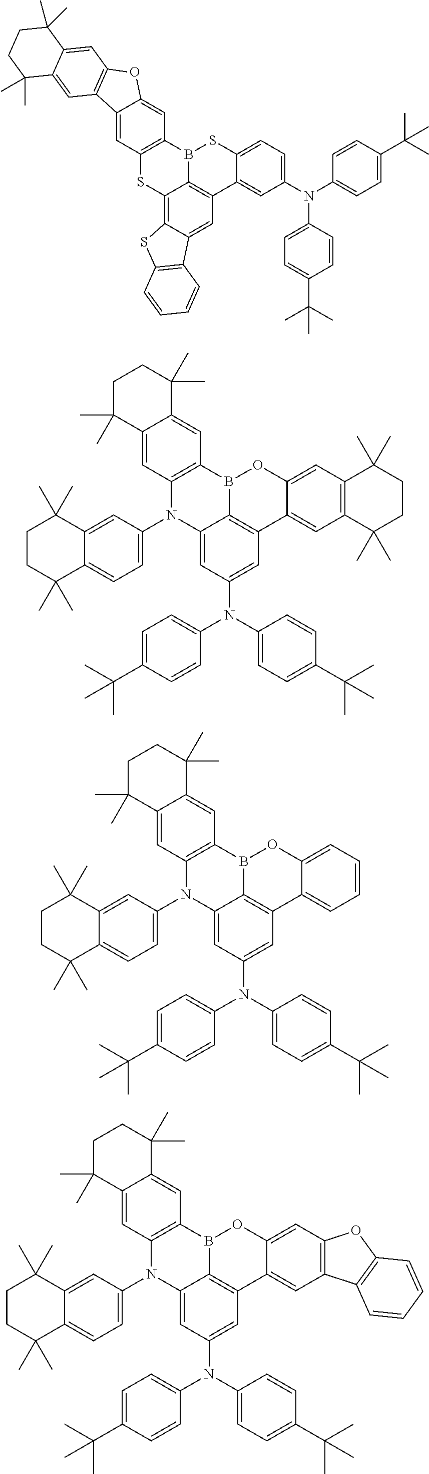

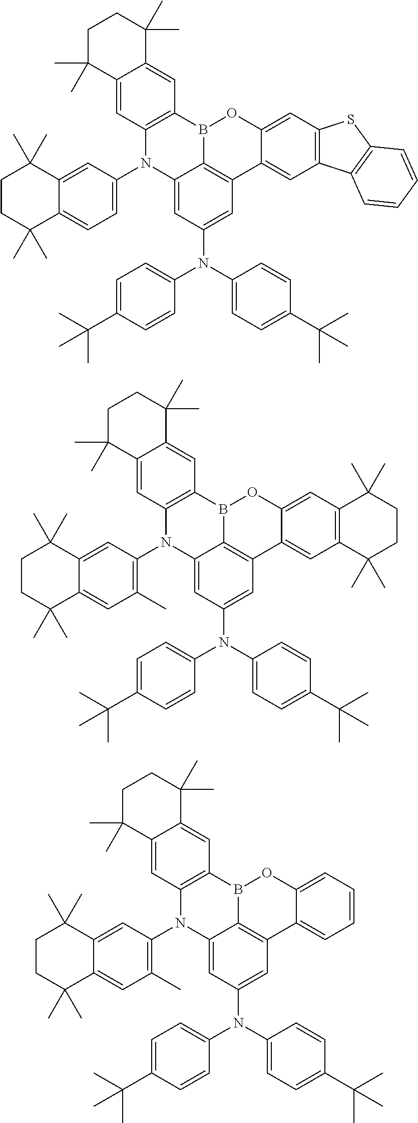

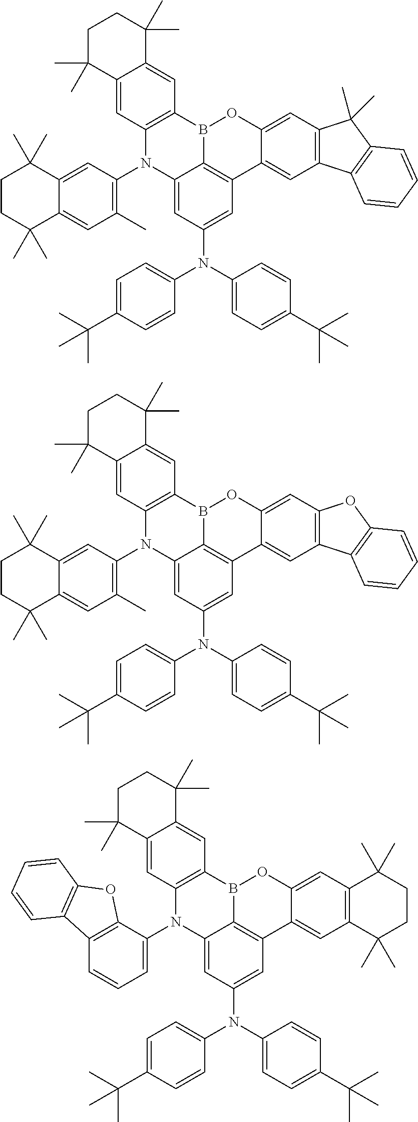

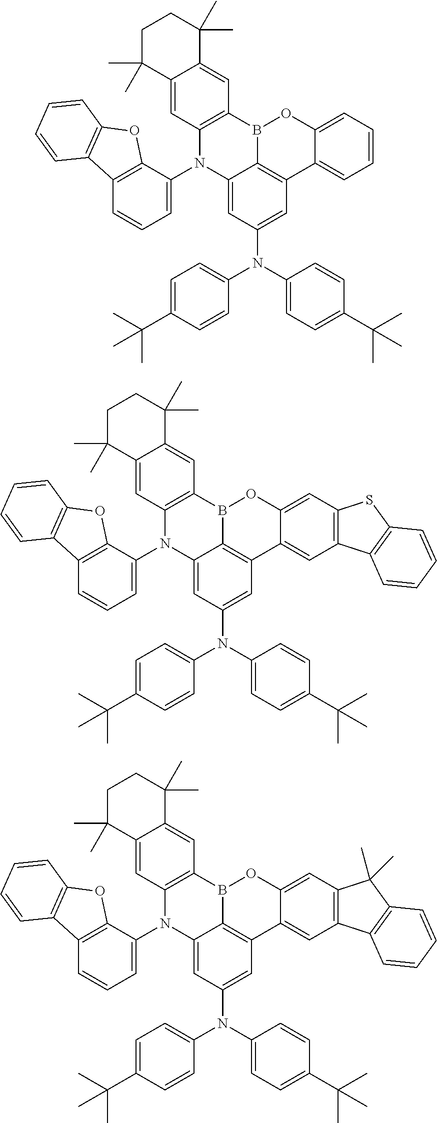

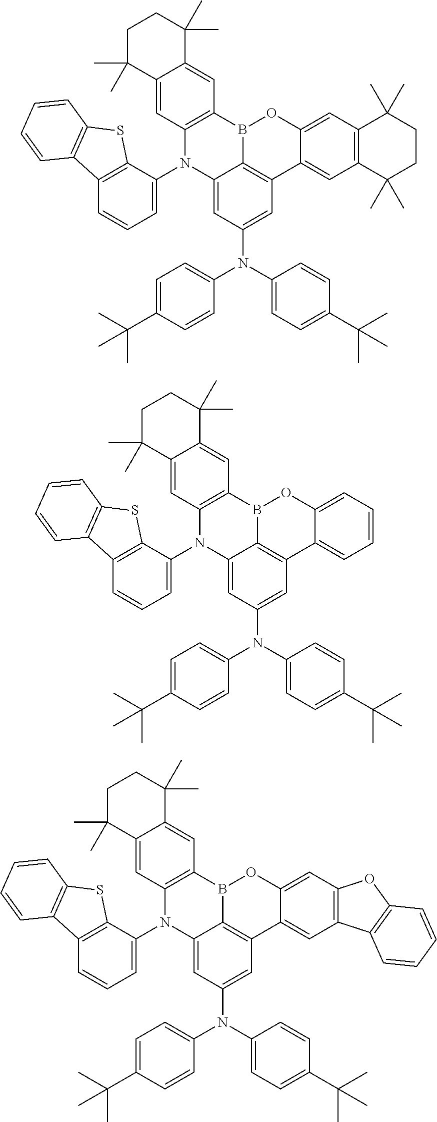

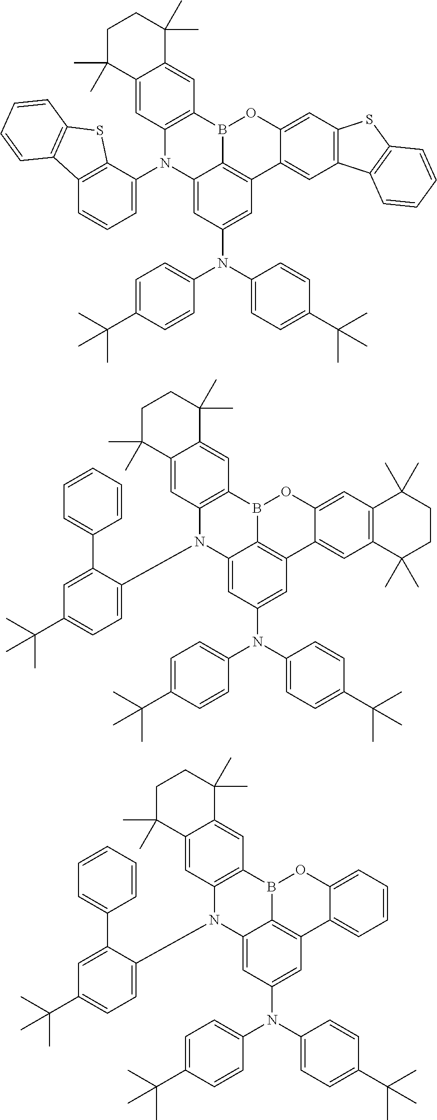

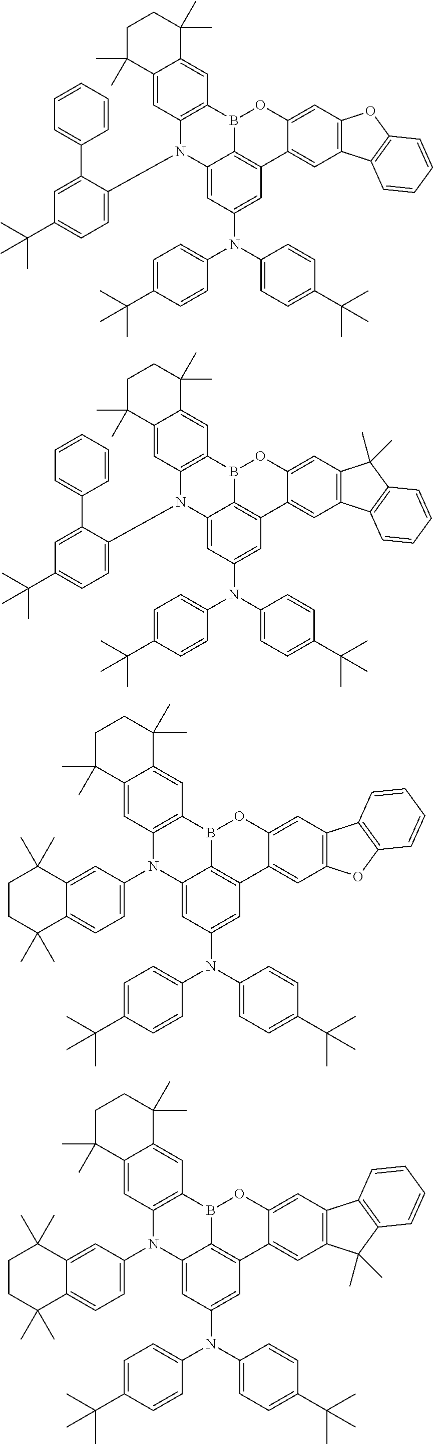

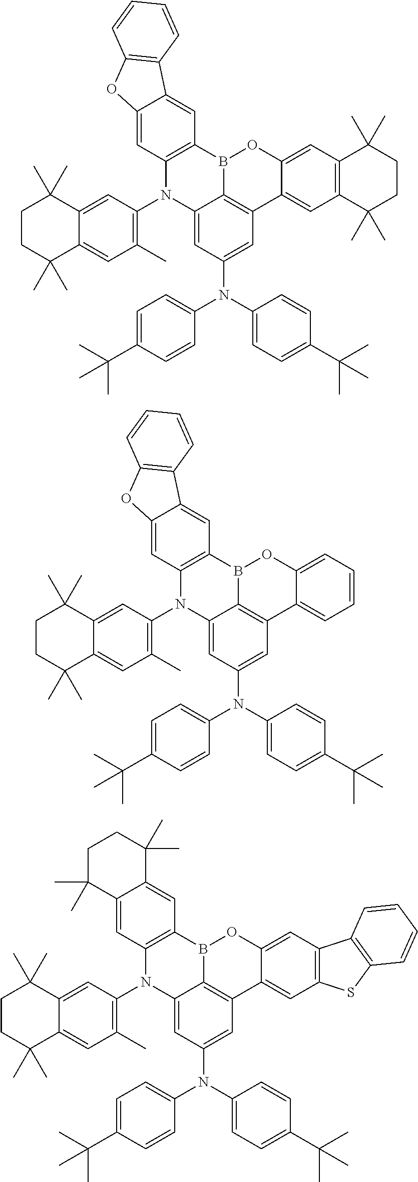

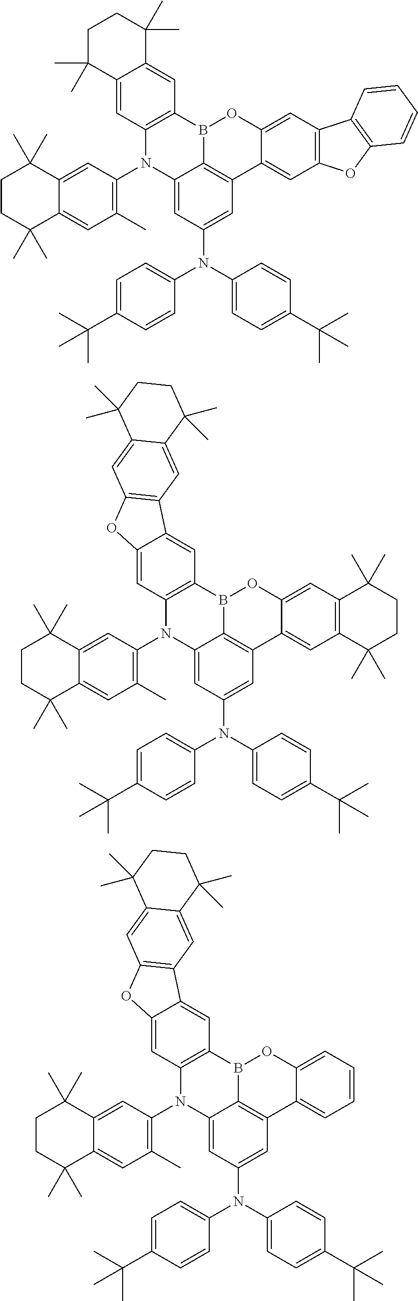

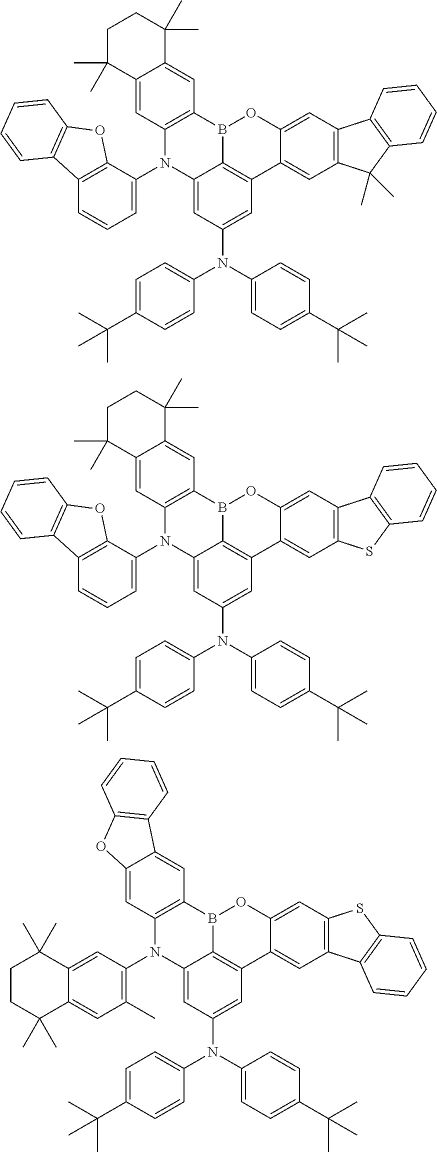

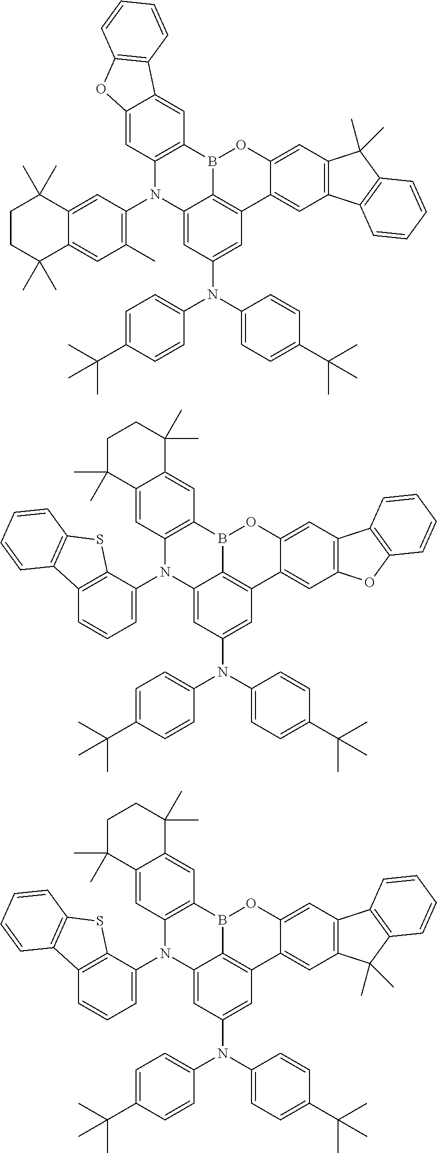

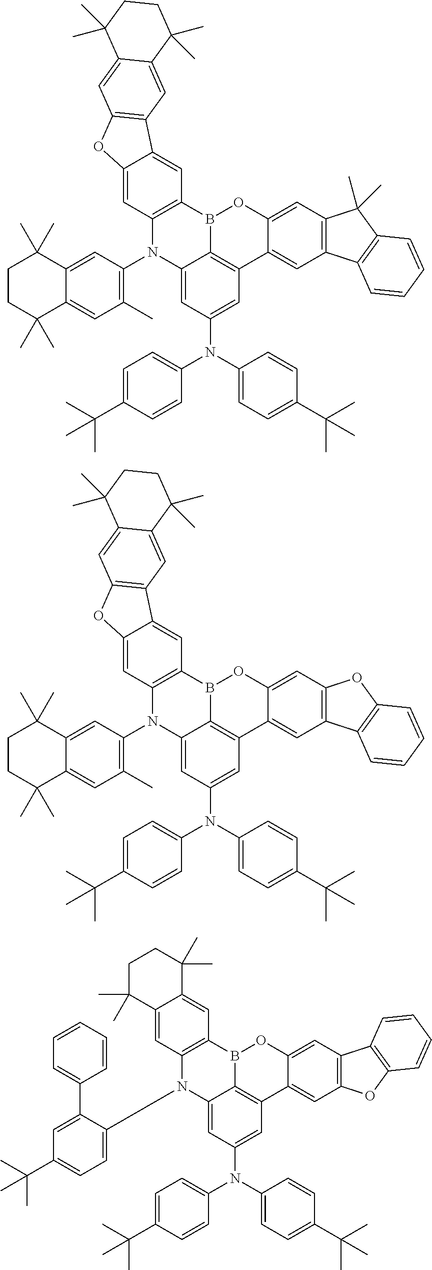

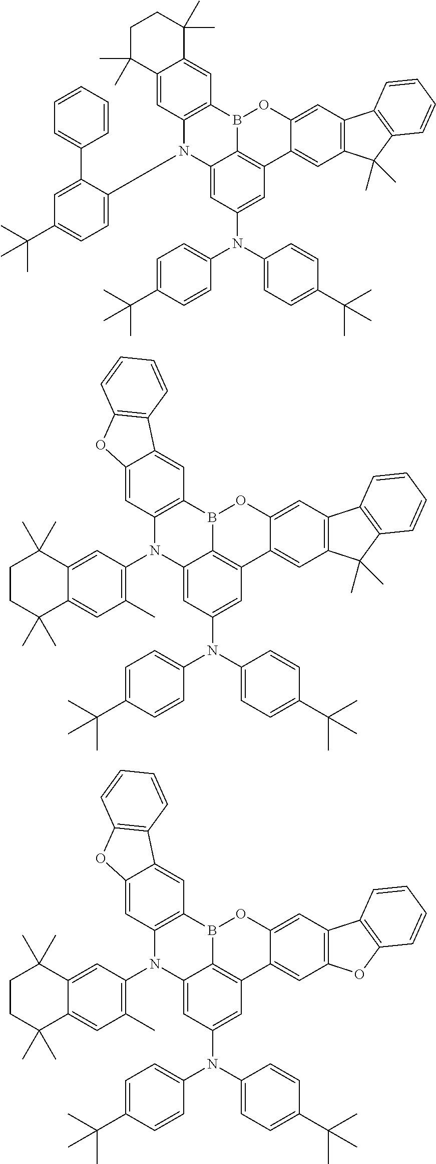

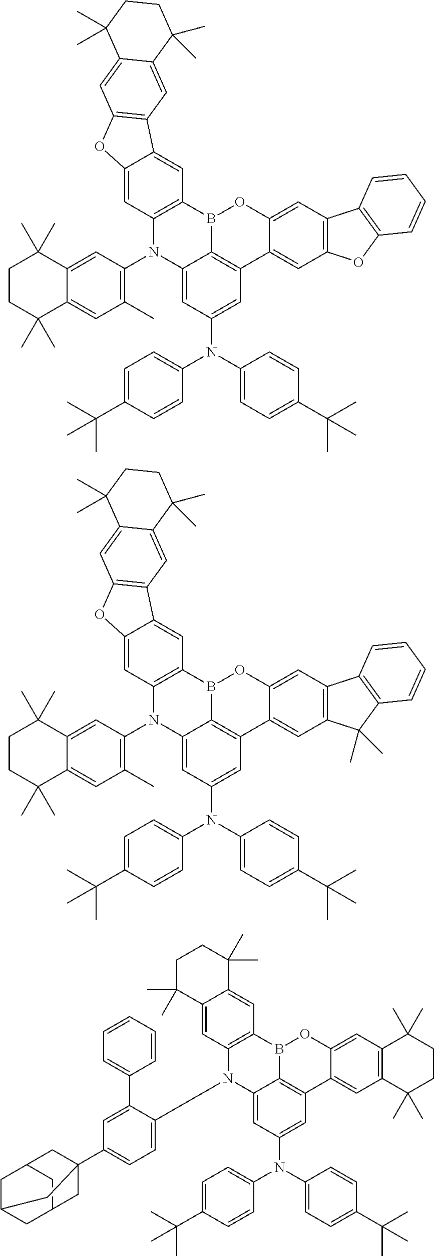

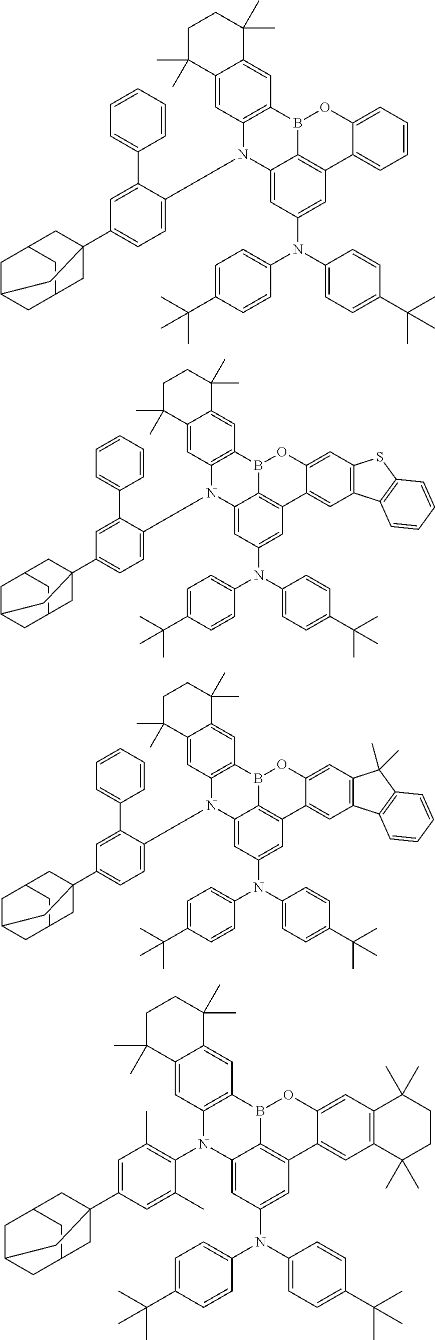

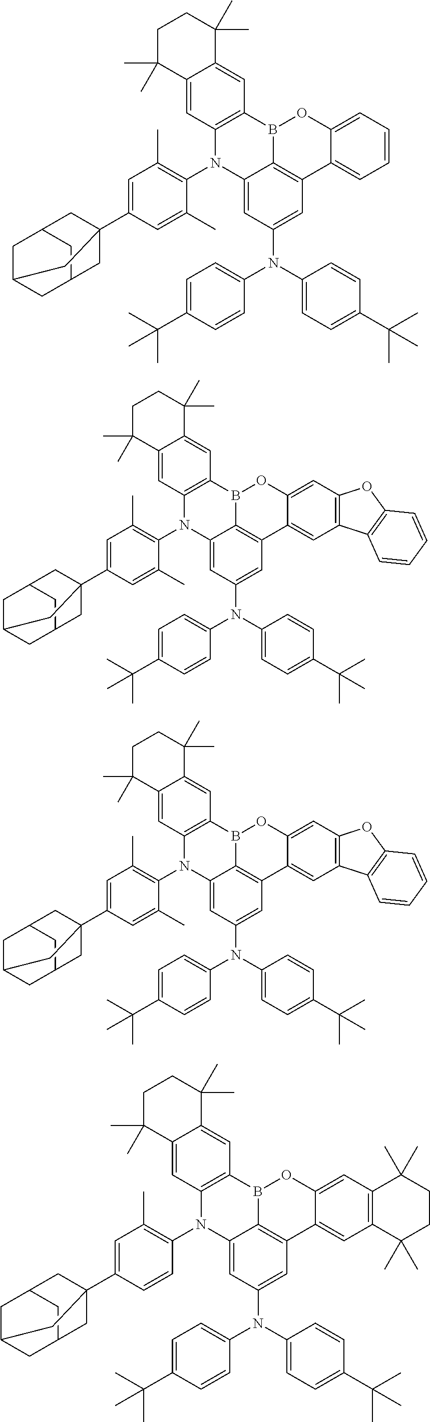

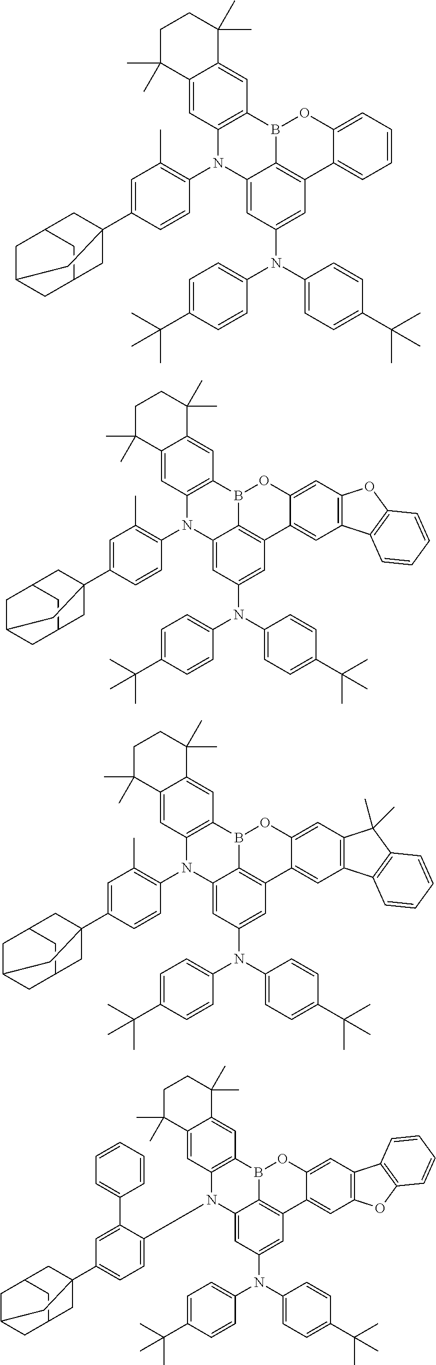

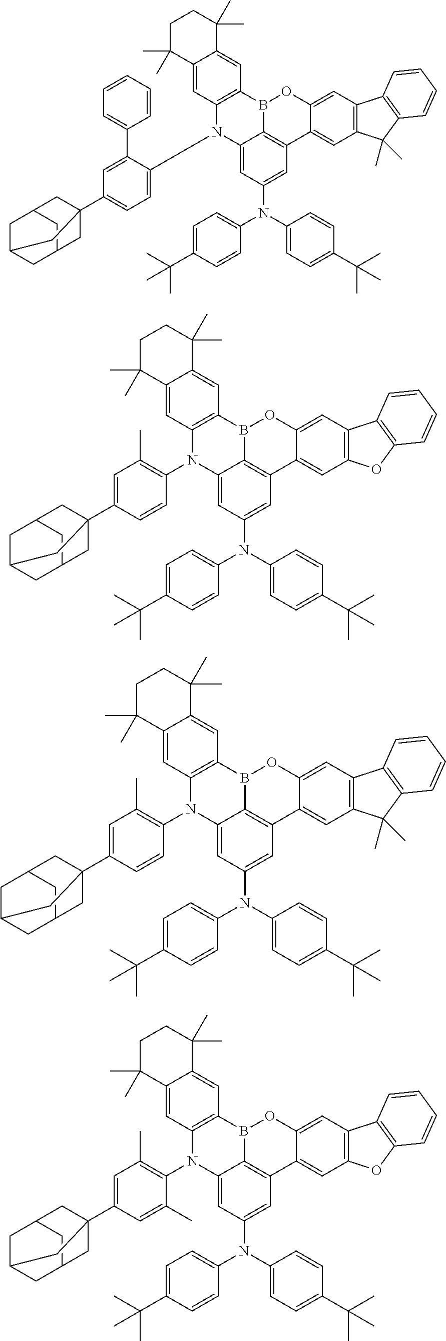

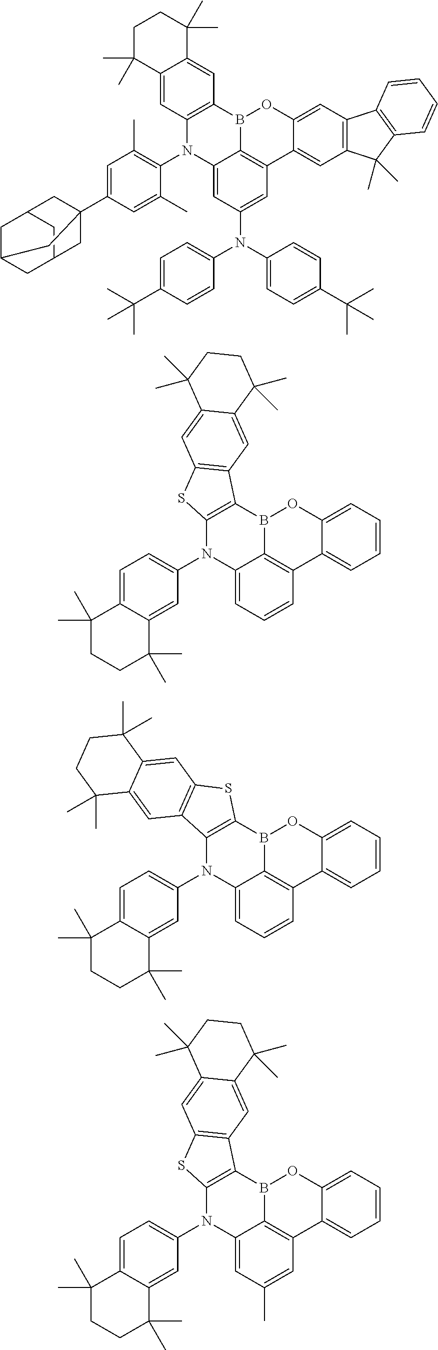

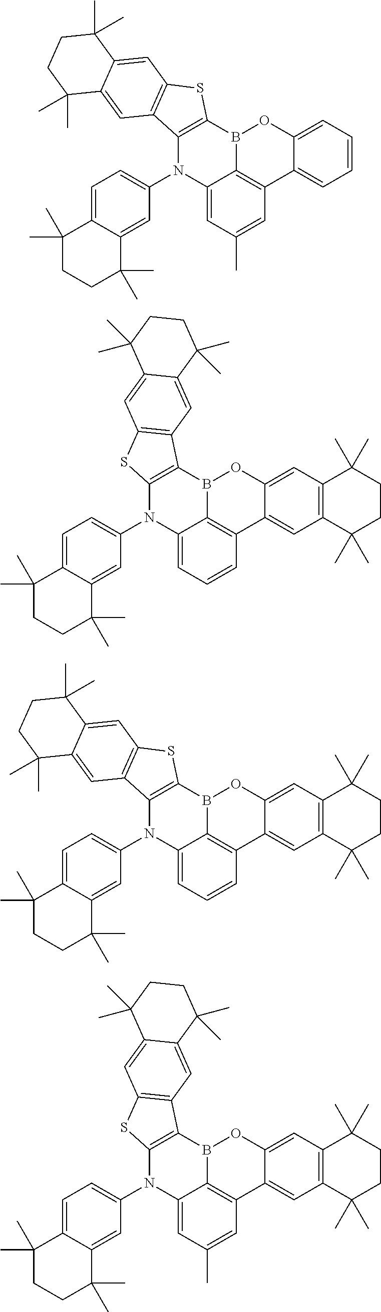

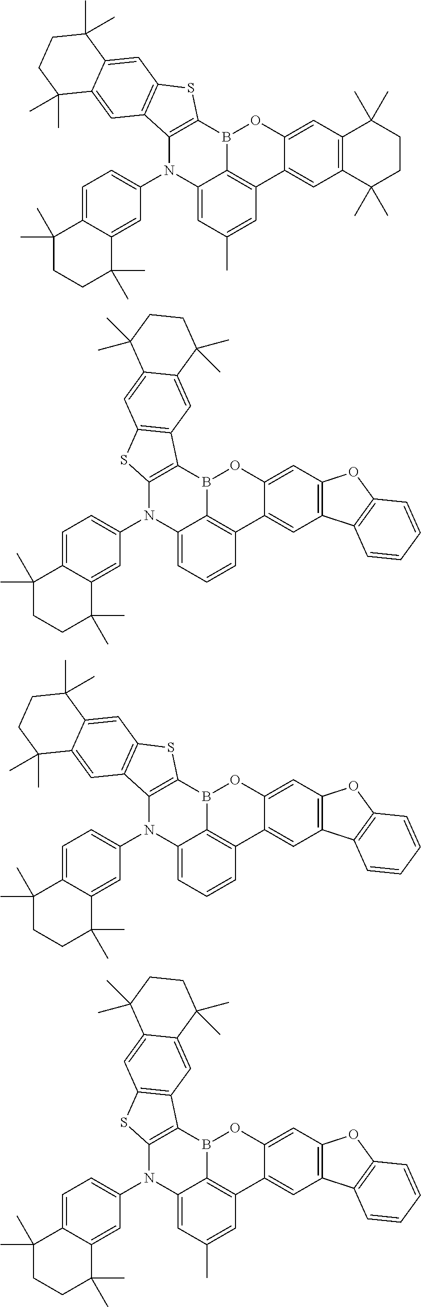

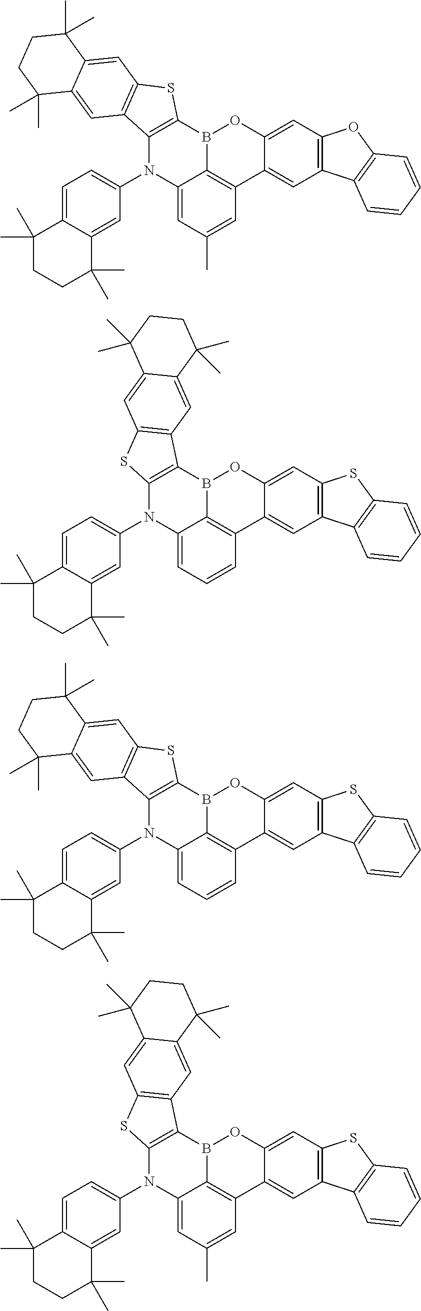

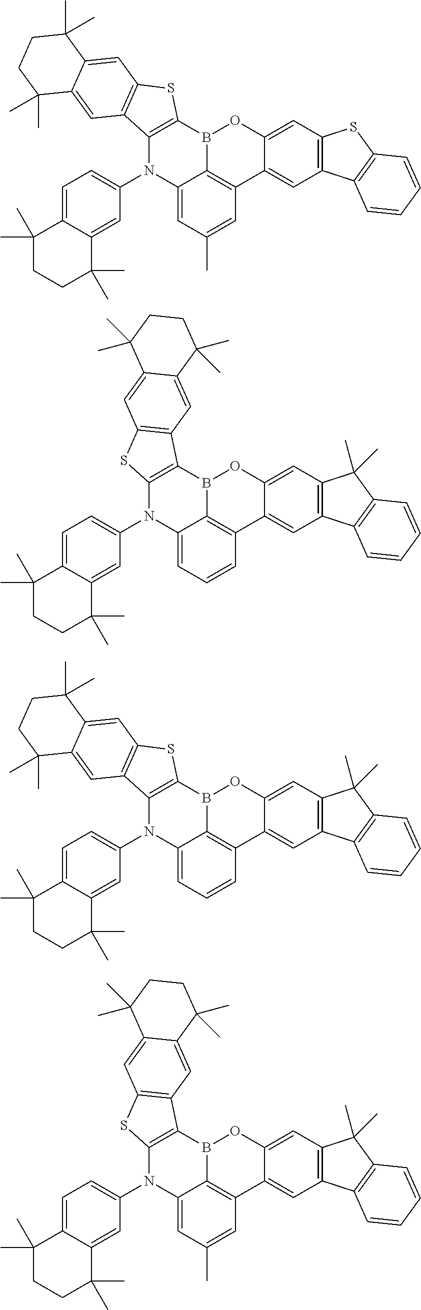

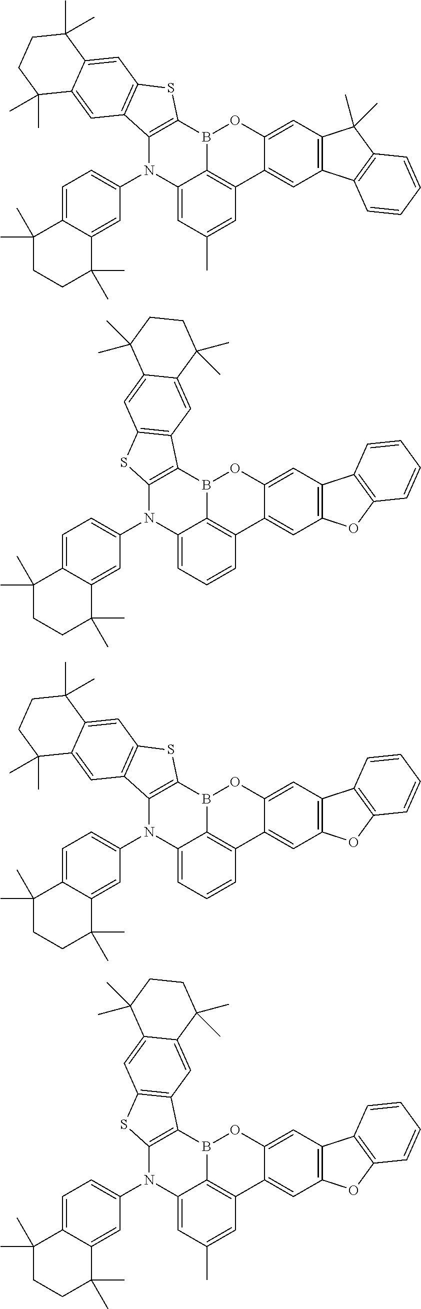

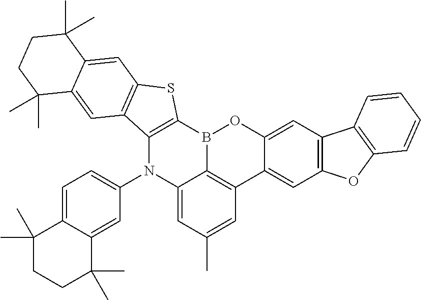

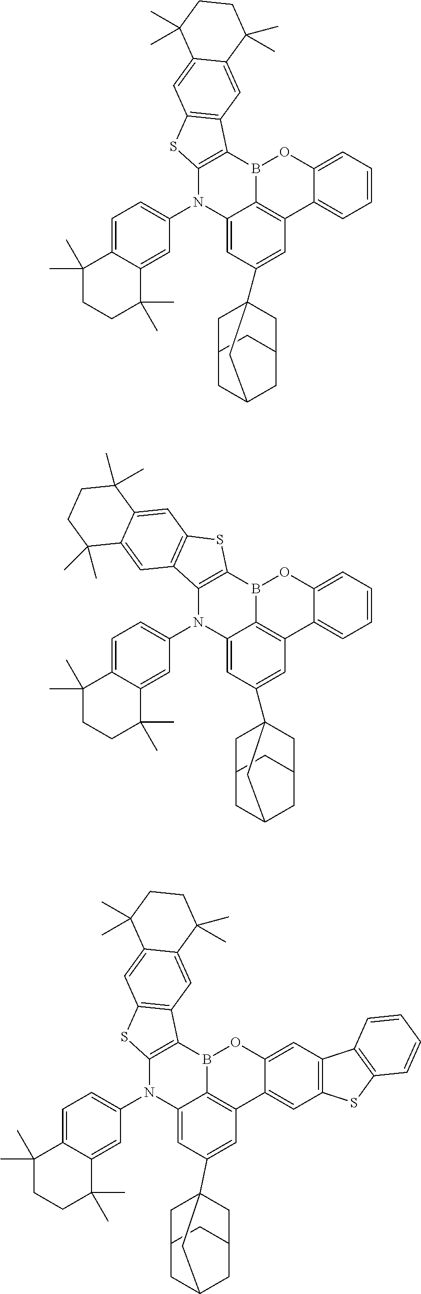 [SMILES: CC1(C)CCC(C)(C)c2cc(N3c4cc(C56CC7CC(CC(C7)C5)C6)cc5c4B(Oc4ccccc4-5)c4c3sc3cc5c(cc43)C(C)(C)CCC5(C)C)ccc21 ; CC1(C)CCC(C)(C)c2cc(N3c4cc(C56CC7CC(CC(C7)C5)C6)cc5c4B(Oc4ccccc4-5)c4sc5cc6c(cc5c43)C(C)(C)CCC6(C)C)ccc21 ; CC1(C)CCC(C)(C)c2cc(N3c4cc(C56CC7CC(CC(C7)C5)C6)cc5c4B(Oc4cc6c(cc4-5)sc4ccccc46)c4c3sc3cc5c(cc43)C(C)(C)CCC5(C)C)ccc21]

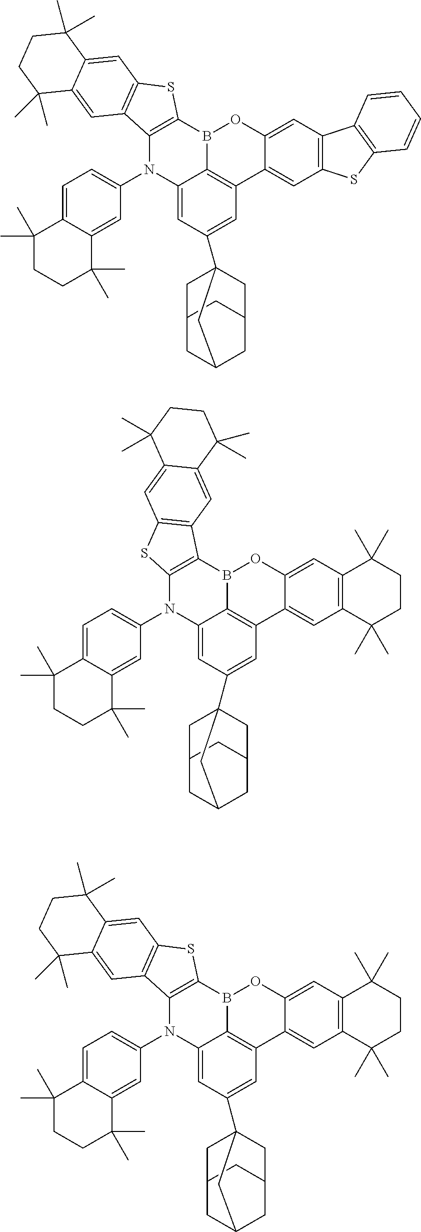

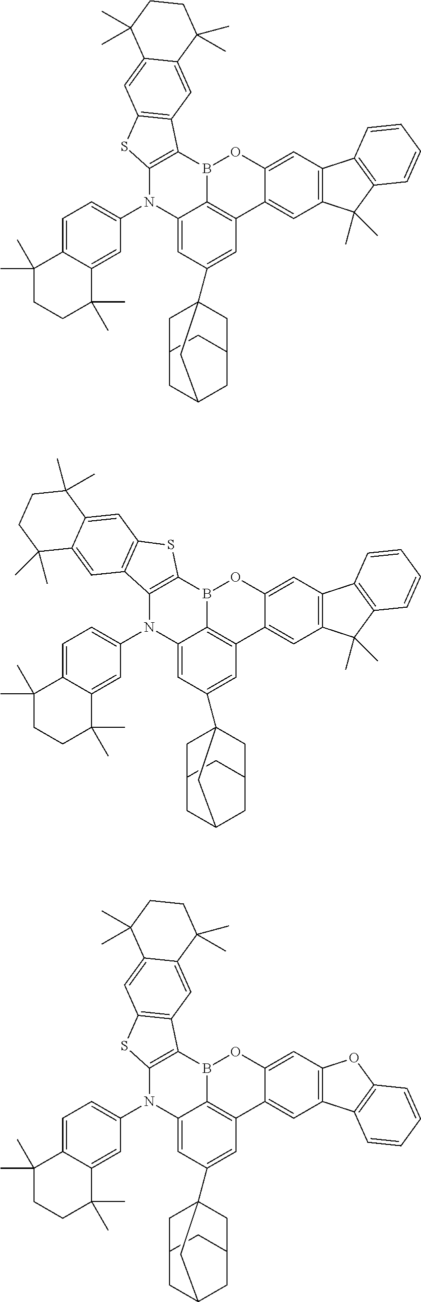 [SMILES: CC1(C)CCC(C)(C)c2cc(N3c4cc(C56CC7CC(CC(C7)C5)C6)cc5c4B(Oc4cc6c(cc4-5)C(C)(C)c4ccccc4-6)c4c3sc3cc5c(cc43)C(C)(C)CCC5(C)C)ccc21 ; CC1(C)CCC(C)(C)c2cc(N3c4cc(C56CC7CC(CC(C7)C5)C6)cc5c4B(Oc4cc6c(cc4-5)C(C)(C)c4ccccc4-6)c4sc5cc6c(cc5c43)C(C)(C)CCC6(C)C)ccc21 ; CC1(C)CCC(C)(C)c2cc(N3c4cc(C56CC7CC(CC(C7)C5)C6)cc5c4B(Oc4cc6oc7ccccc7c6cc4-5)c4c3sc3cc5c(cc43)C(C)(C)CCC5(C)C)ccc21]

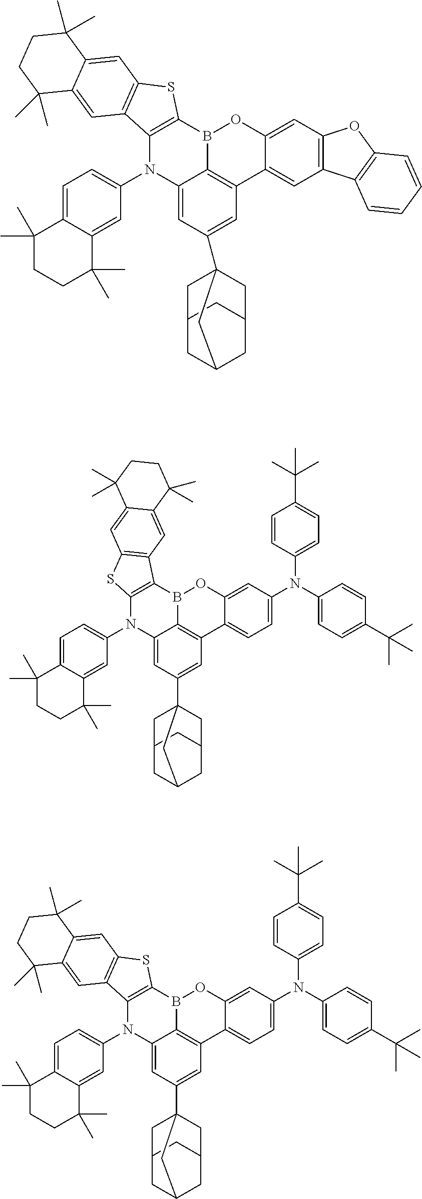

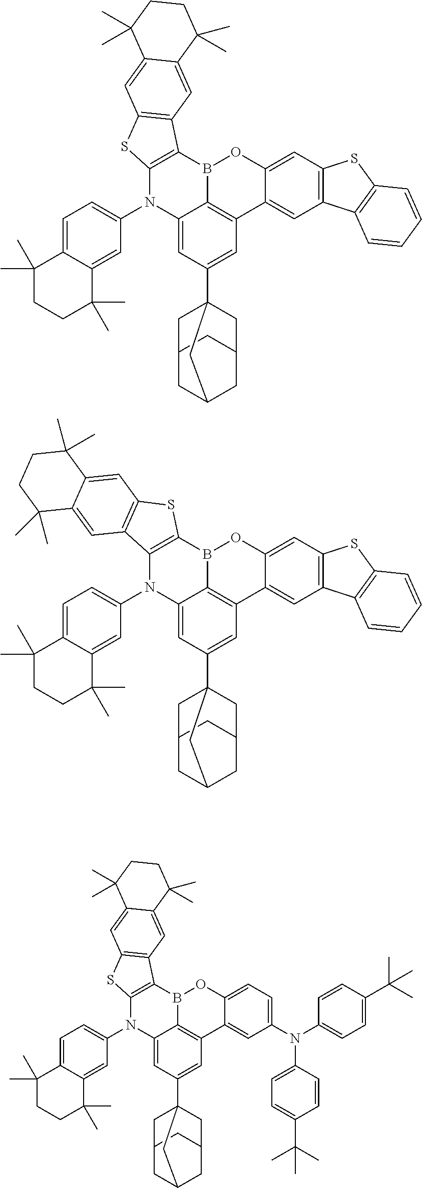 [SMILES: CC1(C)CCC(C)(C)c2cc(N3c4cc(C56CC7CC(CC(C7)C5)C6)cc5c4B(Oc4cc6sc7ccccc7c6cc4-5)c4c3sc3cc5c(cc43)C(C)(C)CCC5(C)C)ccc21 ; CC1(C)CCC(C)(C)c2cc(N3c4cc(C56CC7CC(CC(C7)C5)C6)cc5c4B(Oc4cc6sc7ccccc7c6cc4-5)c4sc5cc6c(cc5c43)C(C)(C)CCC6(C)C)ccc21 ; CC(C)(C)c1ccc(N(c2ccc(C(C)(C)C)cc2)c2ccc3c(c2)-c2cc(C45CC6CC(CC(C6)C4)C5)cc4c2B(O3)c2c(sc3cc5c(cc23)C(C)(C)CCC5(C)C)N4c2ccc3c(c2)C(C)(C)CCC3(C)C)cc1]

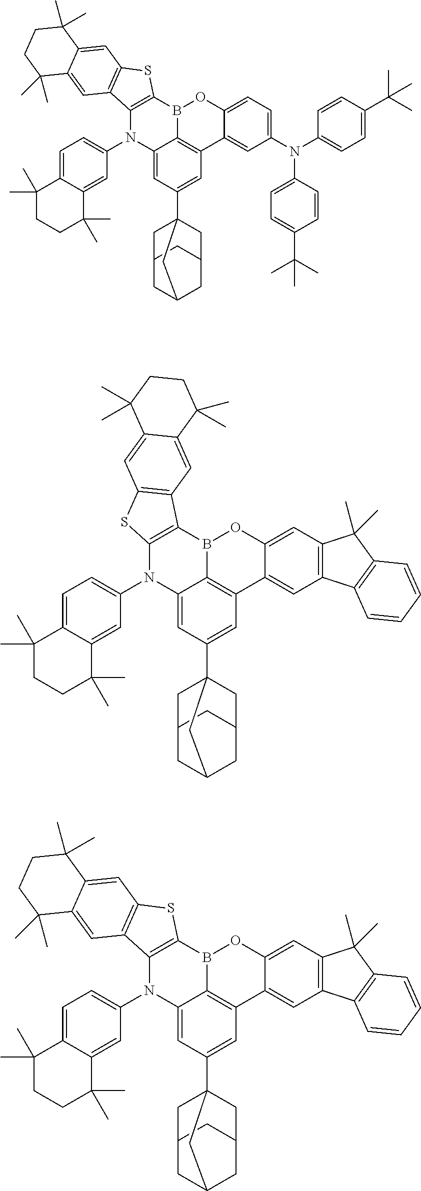

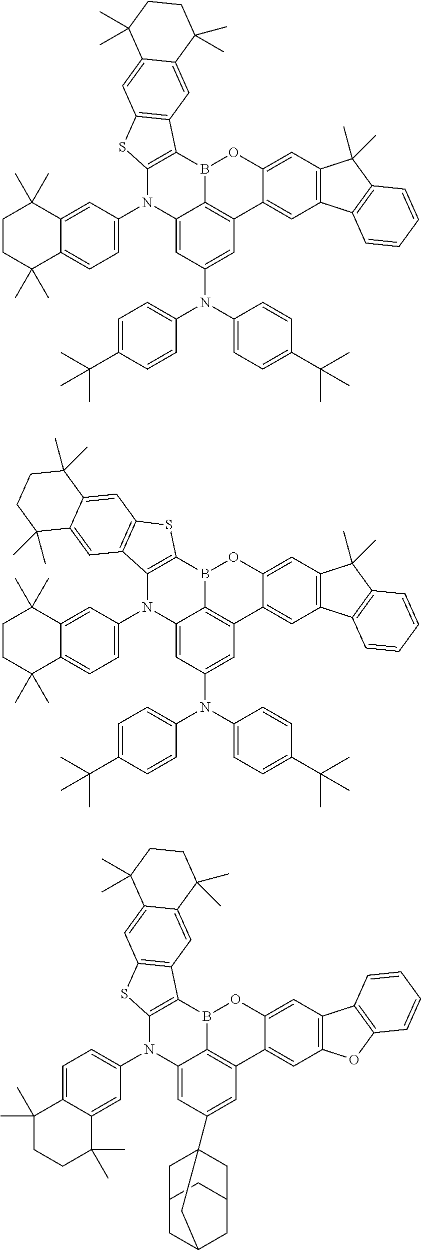

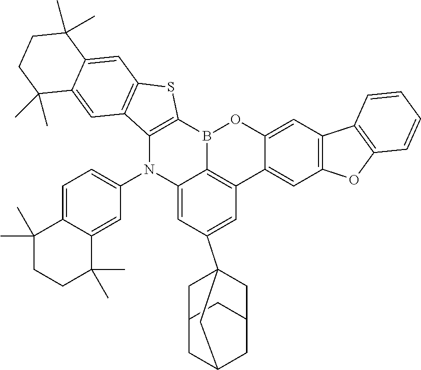 [SMILES: CC1(C)CCC(C)(C)c2cc(N3c4cc(C56CC7CC(CC(C7)C5)C6)cc5c4B(Oc4cc6c(cc4-5)oc4ccccc46)c4sc5cc6c(cc5c43)C(C)(C)CCC6(C)C)ccc21]

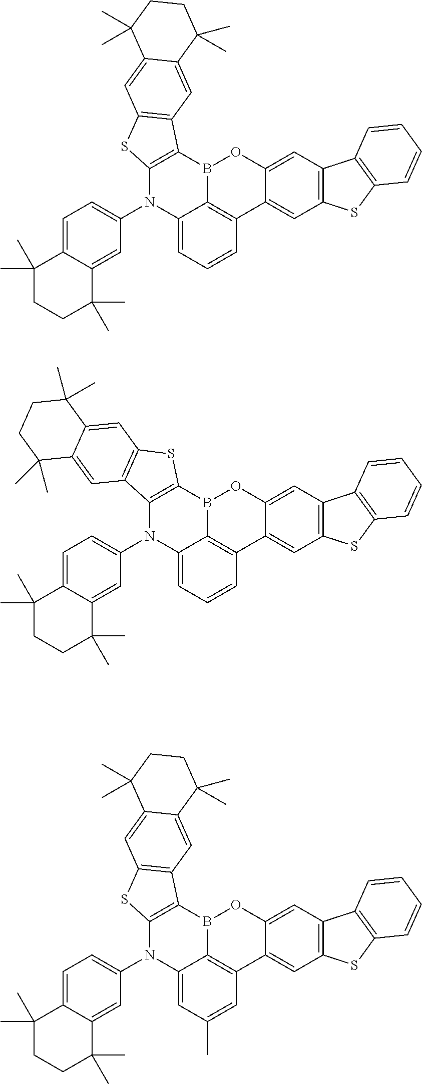 [SMILES: CC1(C)CCC(C)(C)c2cc(N3c4cccc5c4B(Oc4cc6c(cc4-5)sc4ccccc46)c4c3sc3cc5c(cc43)C(C)(C)CCC5(C)C)ccc21 ; CC1(C)CCC(C)(C)c2cc(N3c4cccc5c4B(Oc4cc6c(cc4-5)sc4ccccc46)c4sc5cc6c(cc5c43)C(C)(C)CCC6(C)C)ccc21 ; Cc1cc2c3c(c1)N(c1ccc4c(c1)C(C)(C)CCC4(C)C)c1sc4cc5c(cc4c1B3Oc1cc3c(cc1-2)sc1ccccc13)C(C)(C)CCC5(C)C]

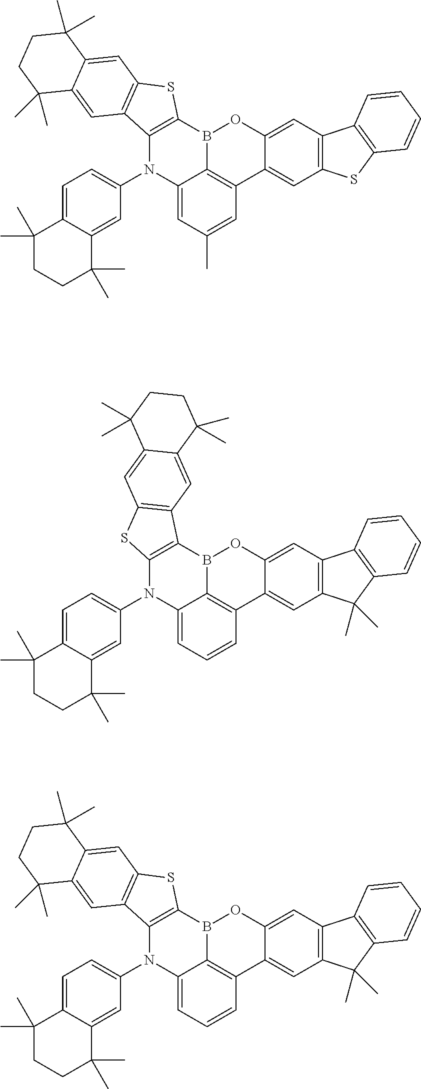 [SMILES: Cc1cc2c3c(c1)N(c1ccc4c(c1)C(C)(C)CCC4(C)C)c1c(sc4cc5c(cc14)C(C)(C)CCC5(C)C)B3Oc1cc3c(cc1-2)sc1ccccc13 ; CC1(C)CCC(C)(C)c2cc(N3c4cccc5c4B(Oc4cc6c(cc4-5)C(C)(C)c4ccccc4-6)c4c3sc3cc5c(cc43)C(C)(C)CCC5(C)C)ccc21 ; CC1(C)CCC(C)(C)c2cc(N3c4cccc5c4B(Oc4cc6c(cc4-5)C(C)(C)c4ccccc4-6)c4sc5cc6c(cc5c43)C(C)(C)CCC6(C)C)ccc21]

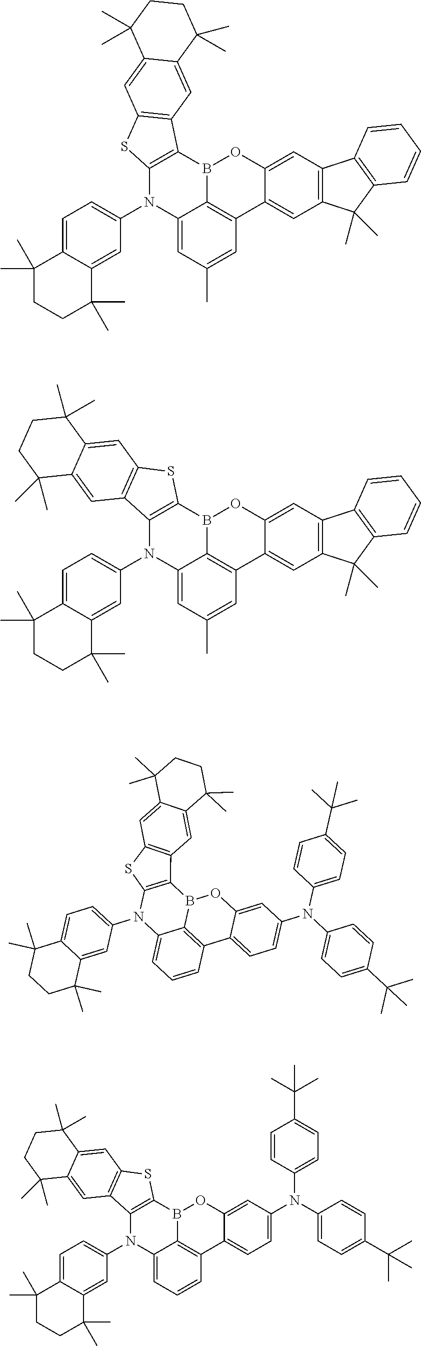

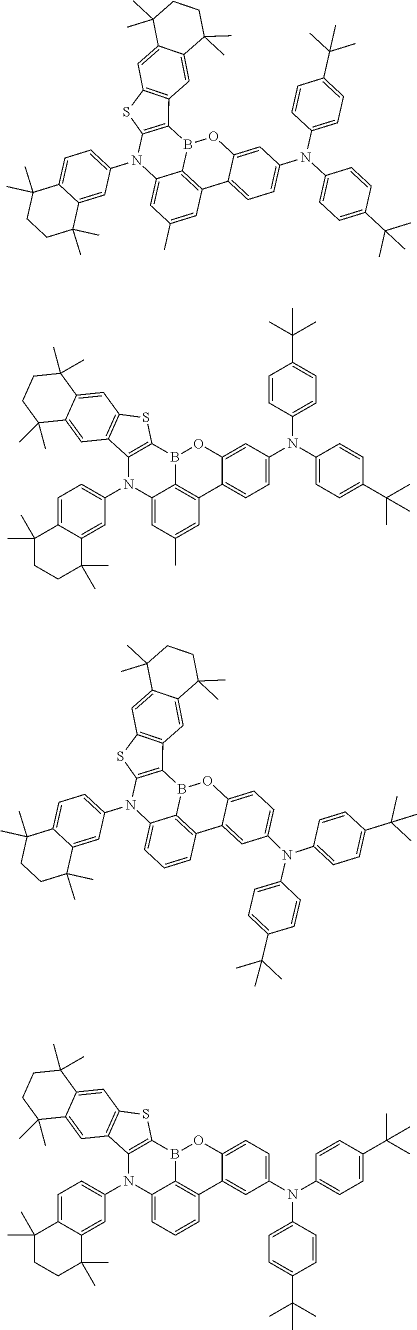

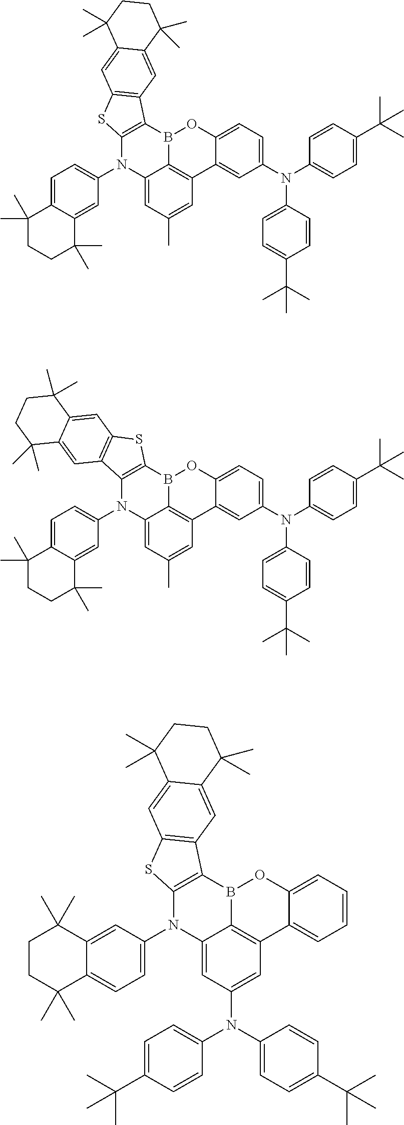

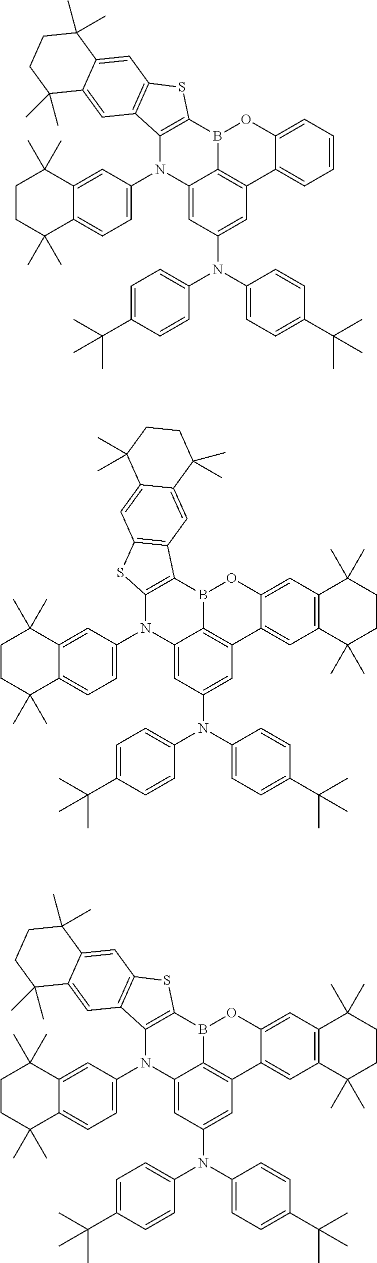 [SMILES: CC(C)(C)c1ccc(N(c2ccc(C(C)(C)C)cc2)c2cc3c4c(c2)N(c2ccc5c(c2)C(C)(C)CCC5(C)C)c2c(sc5cc6c(cc25)C(C)(C)CCC6(C)C)B4Oc2ccccc2-3)cc1 ; CC(C)(C)c1ccc(N(c2ccc(C(C)(C)C)cc2)c2cc3c4c(c2)N(c2ccc5c(c2)C(C)(C)CCC5(C)C)c2sc5cc6c(cc5c2B4Oc2cc4c(cc2-3)C(C)(C)CCC4(C)C)C(C)(C)CCC6(C)C)cc1 ; CC(C)(C)c1ccc(N(c2ccc(C(C)(C)C)cc2)c2cc3c4c(c2)N(c2ccc5c(c2)C(C)(C)CCC5(C)C)c2c(sc5cc6c(cc25)C(C)(C)CCC6(C)C)B4Oc2cc4c(cc2-3)C(C)(C)CCC4(C)C)cc1]

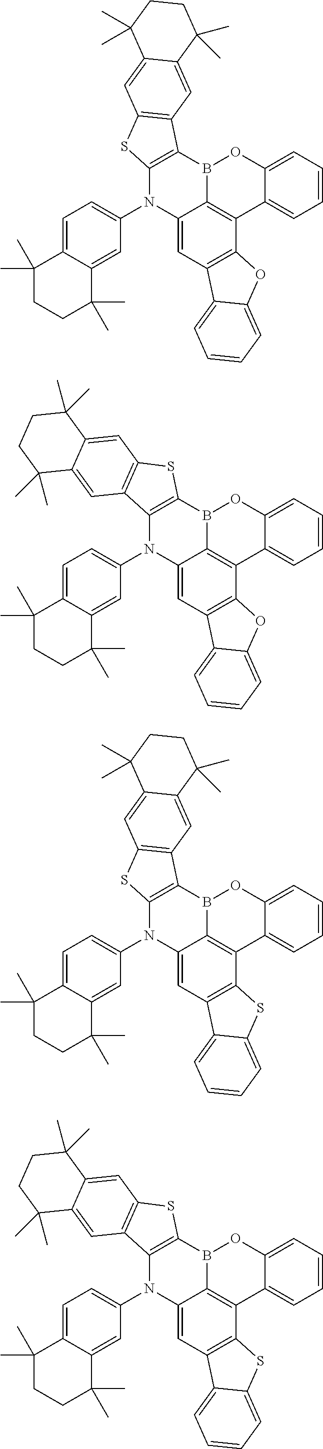

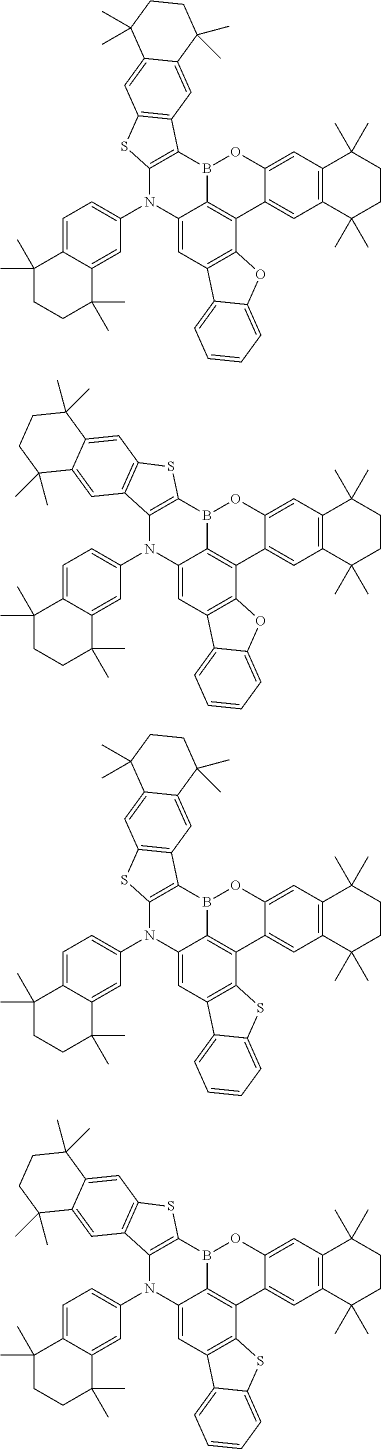

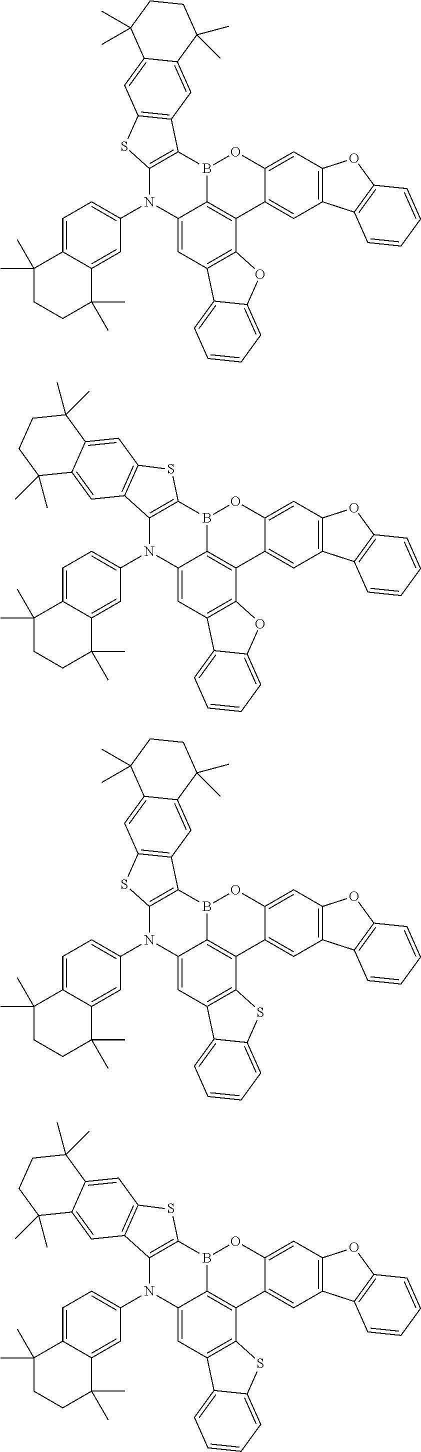

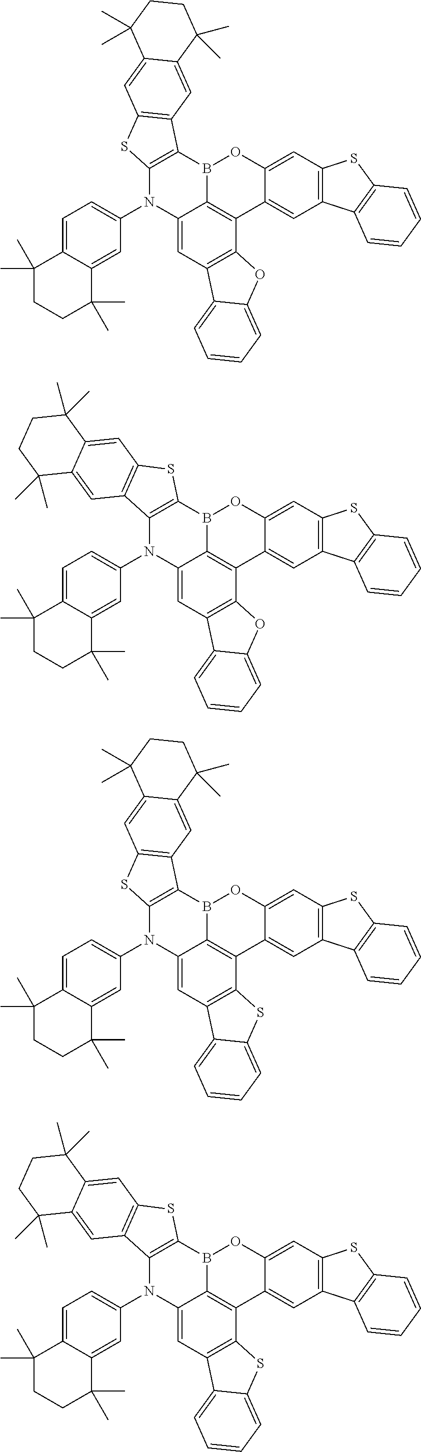

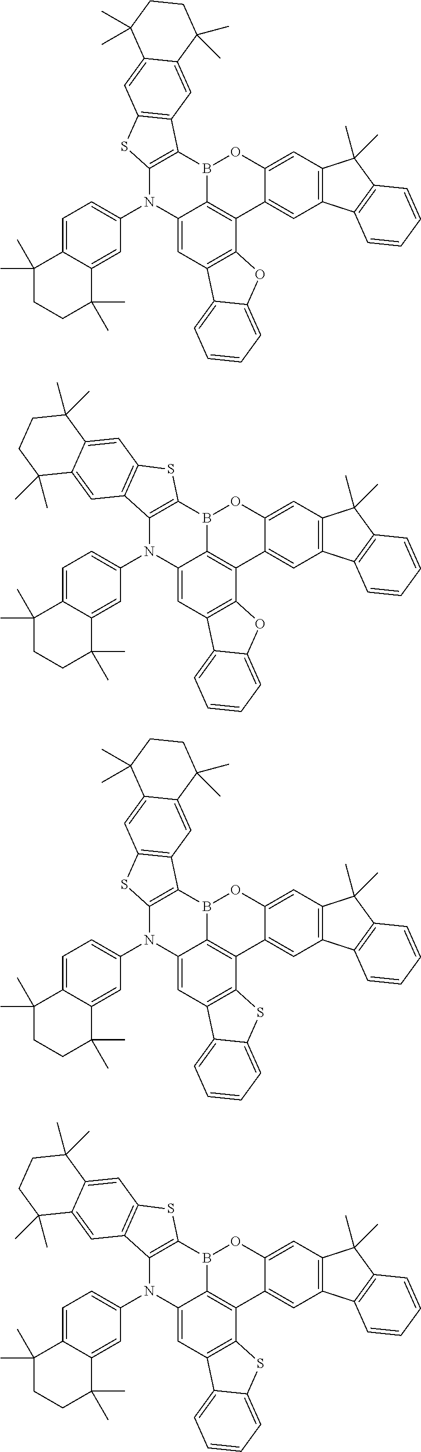

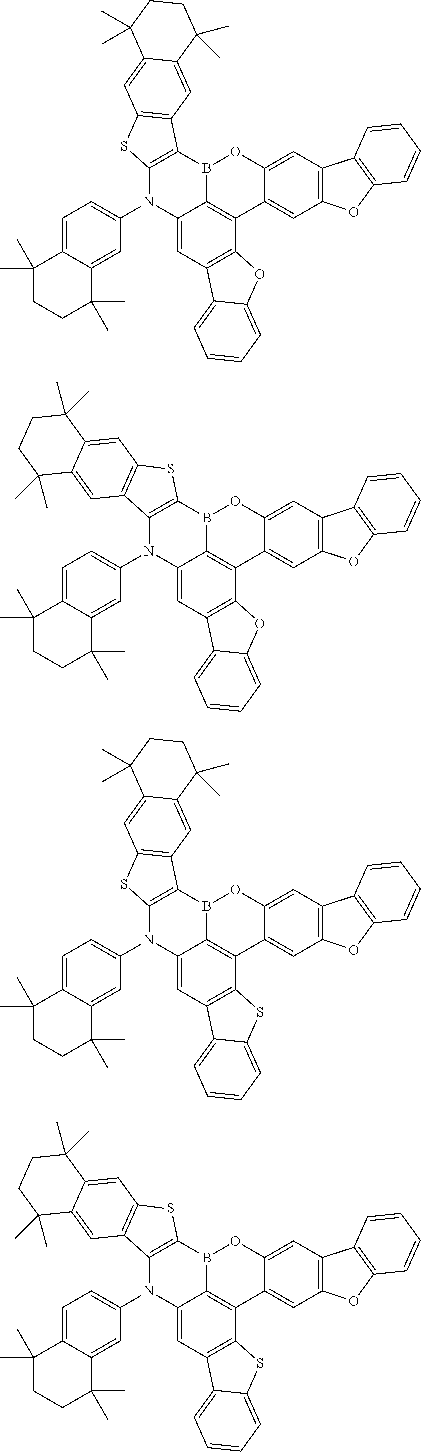

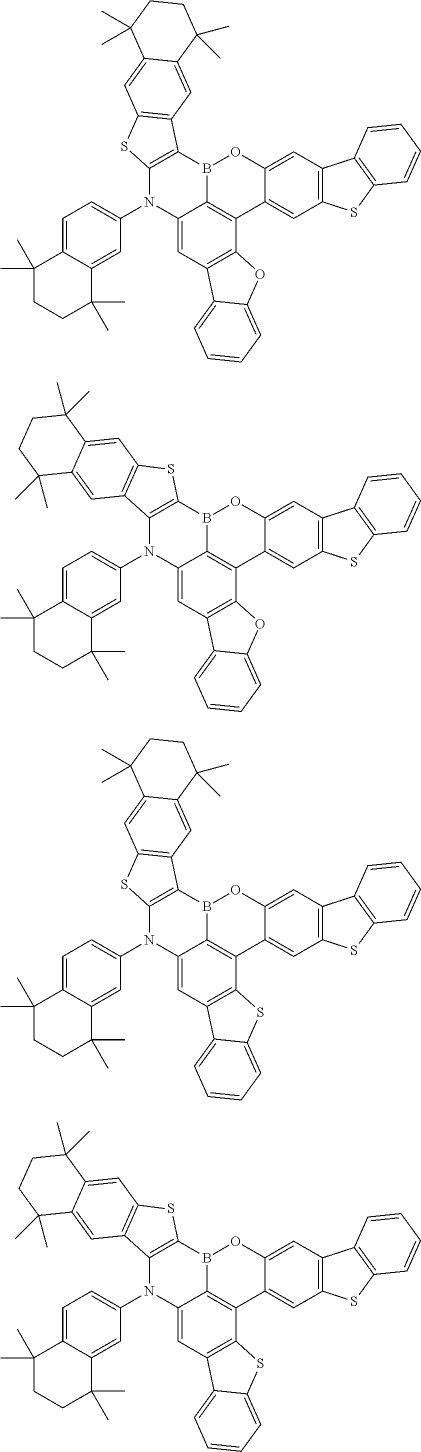

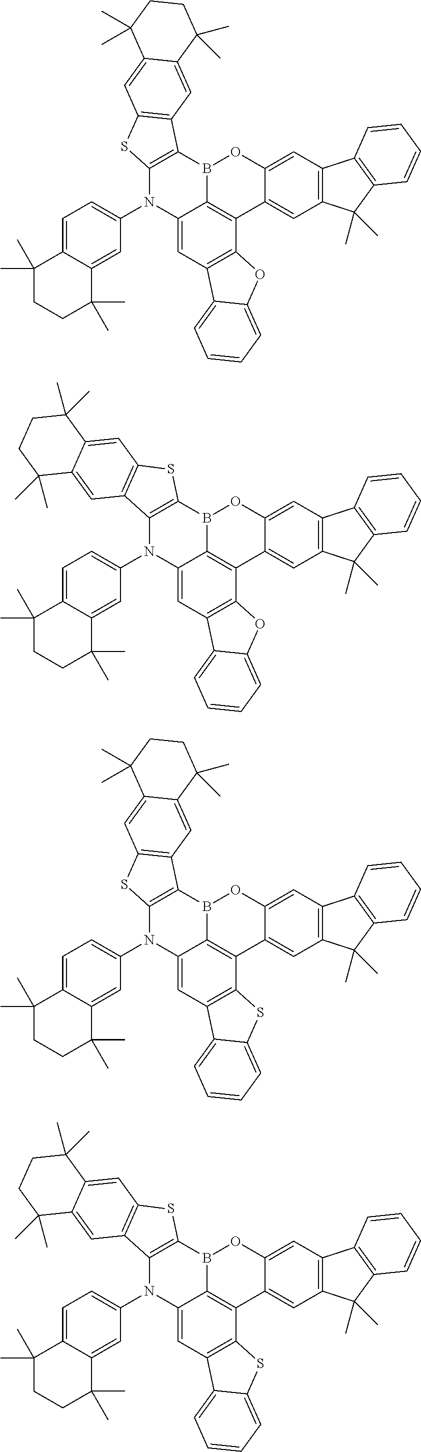

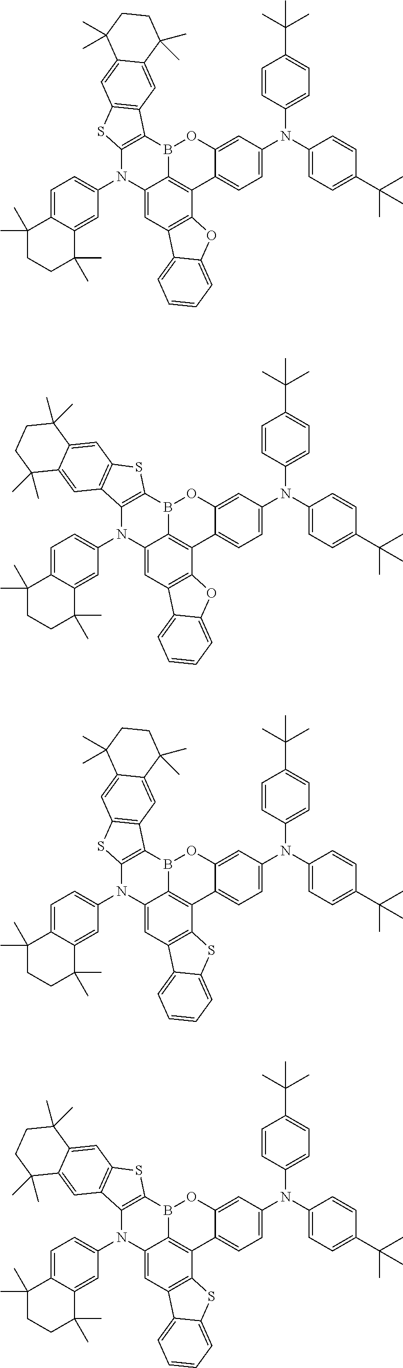

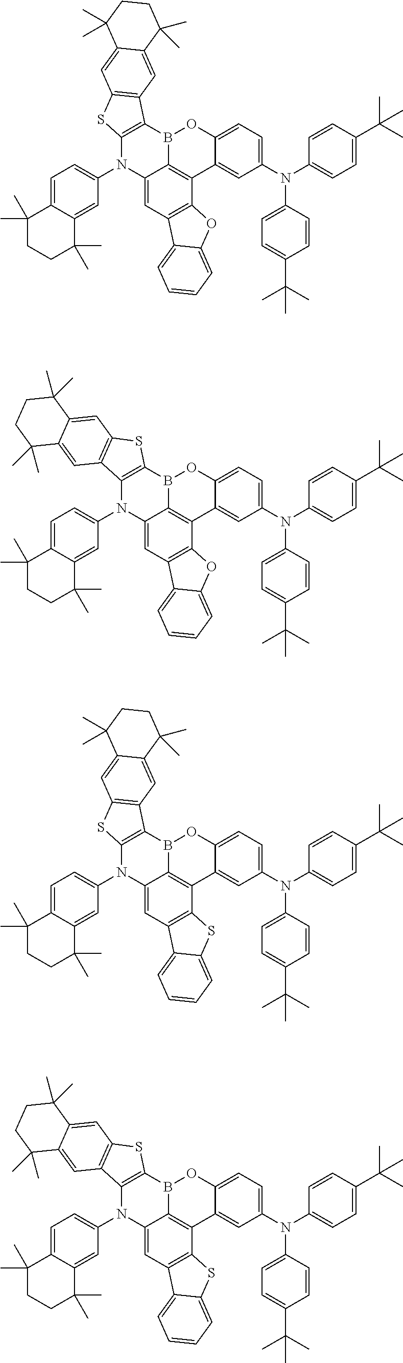

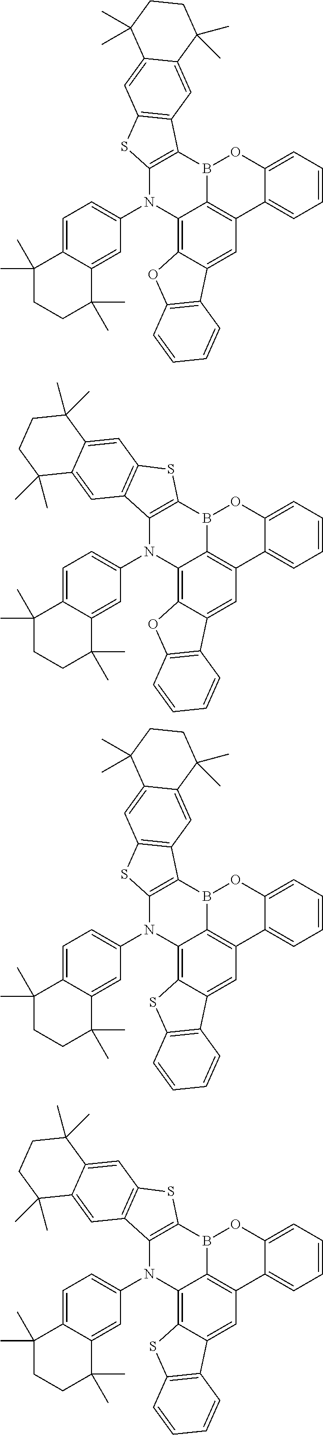

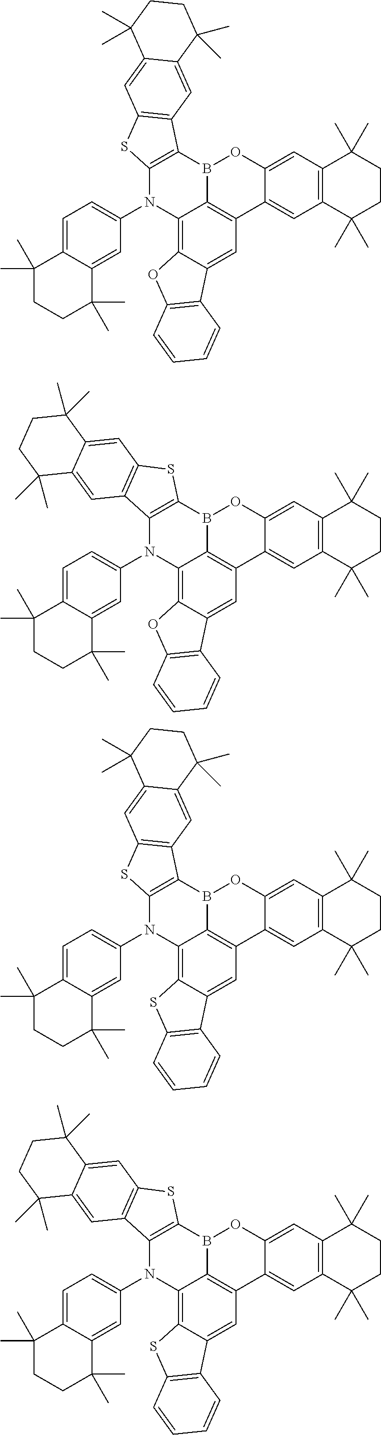

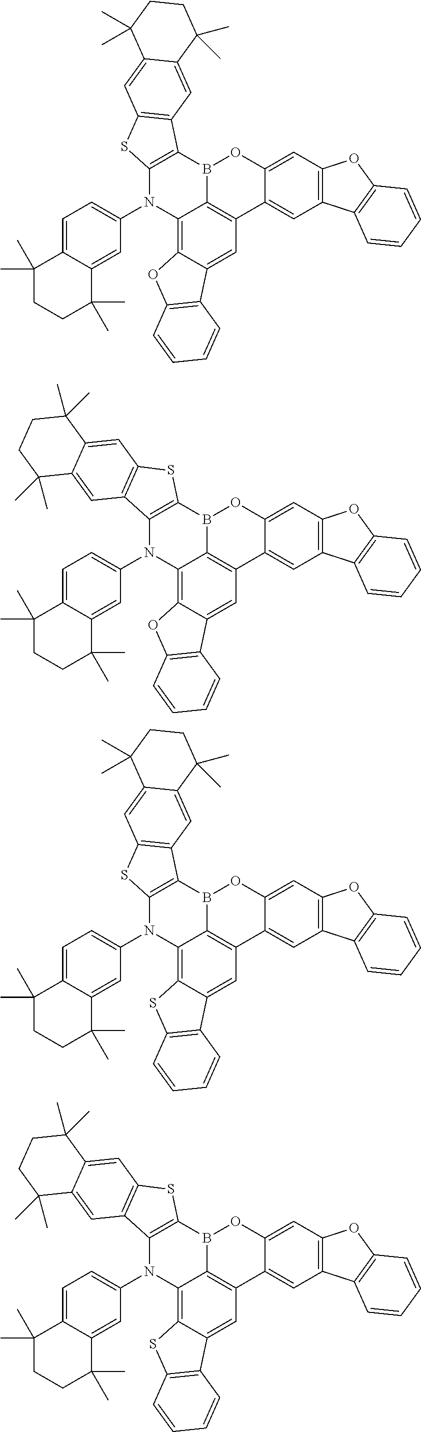

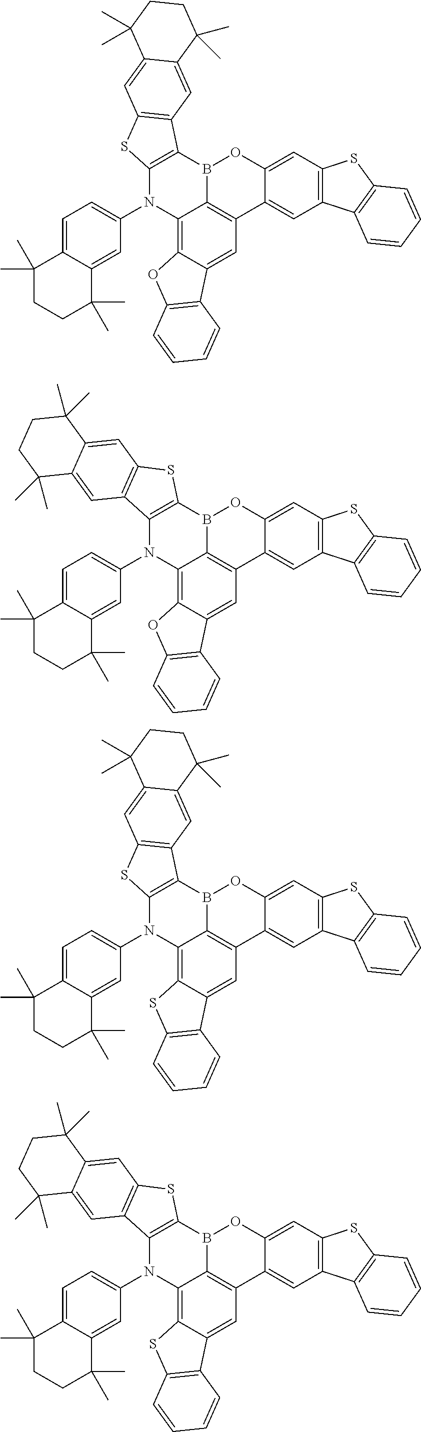

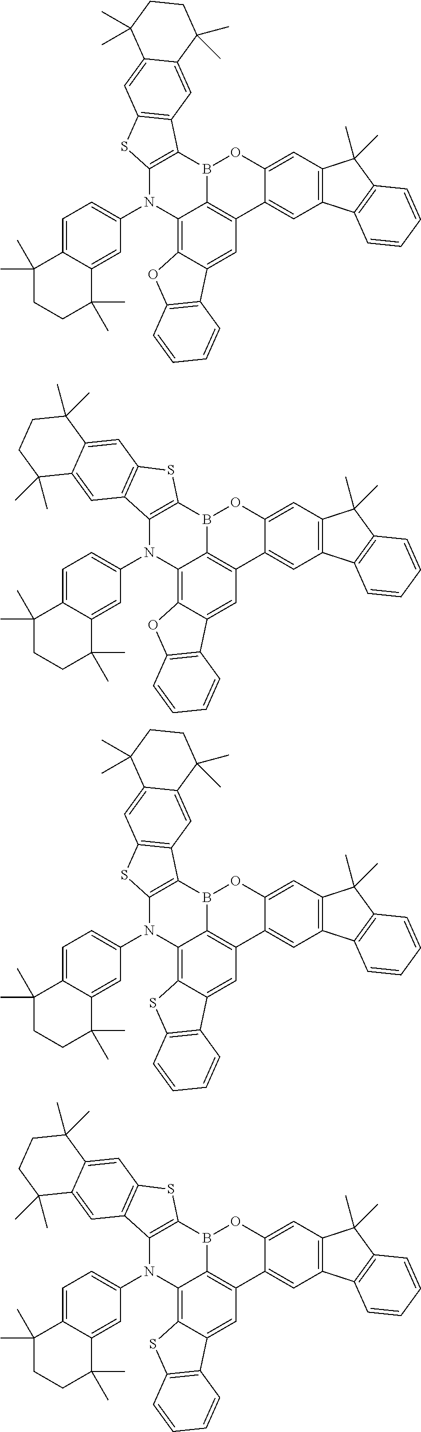

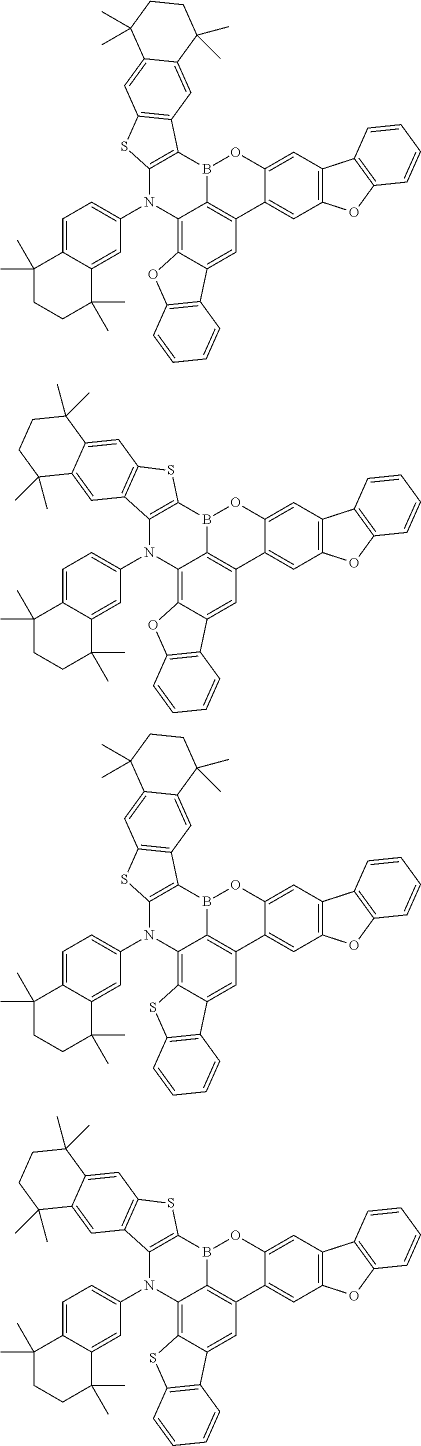

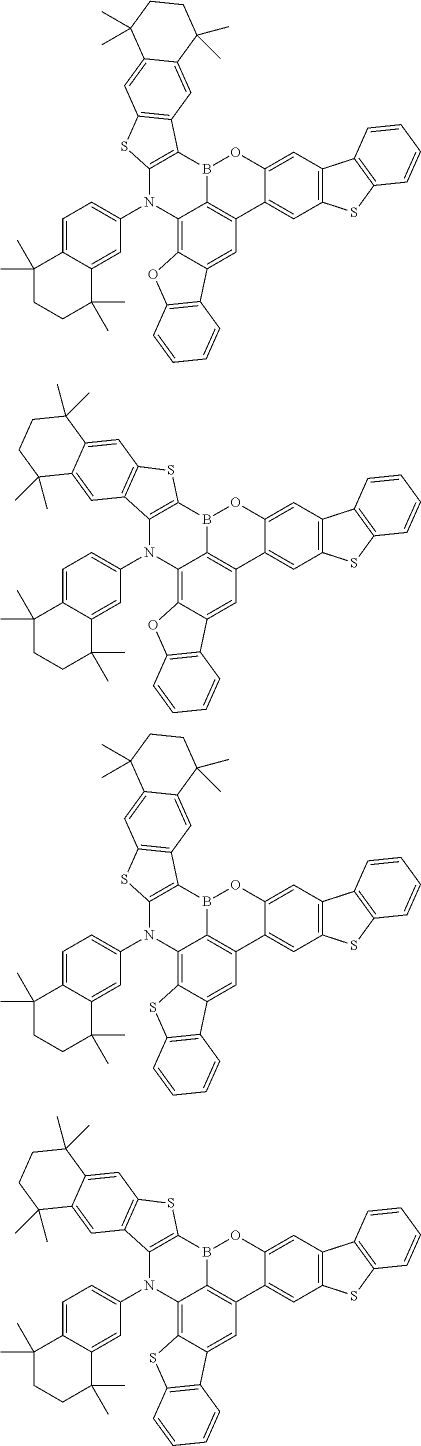

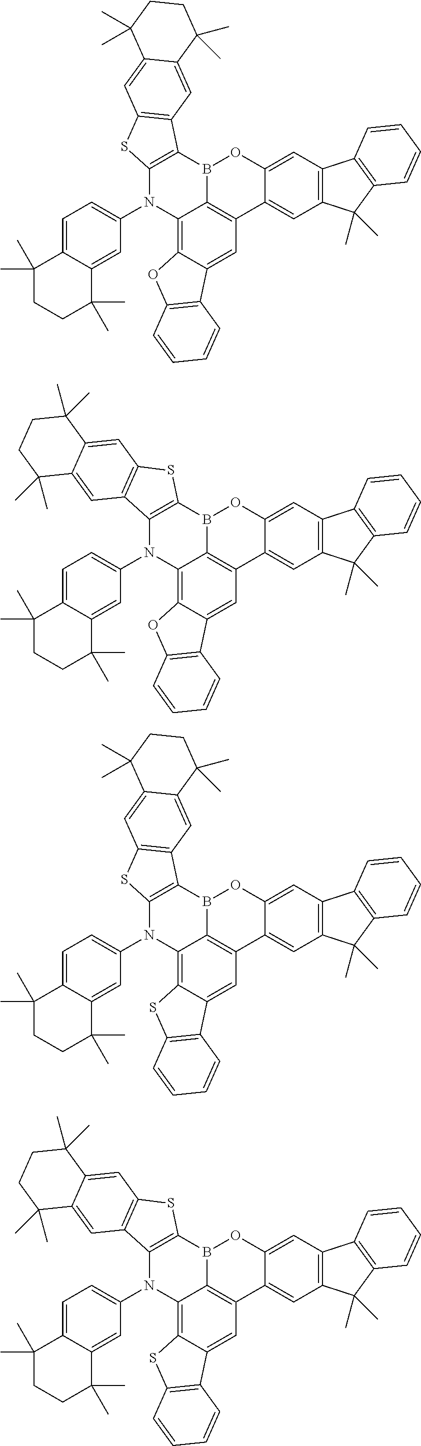

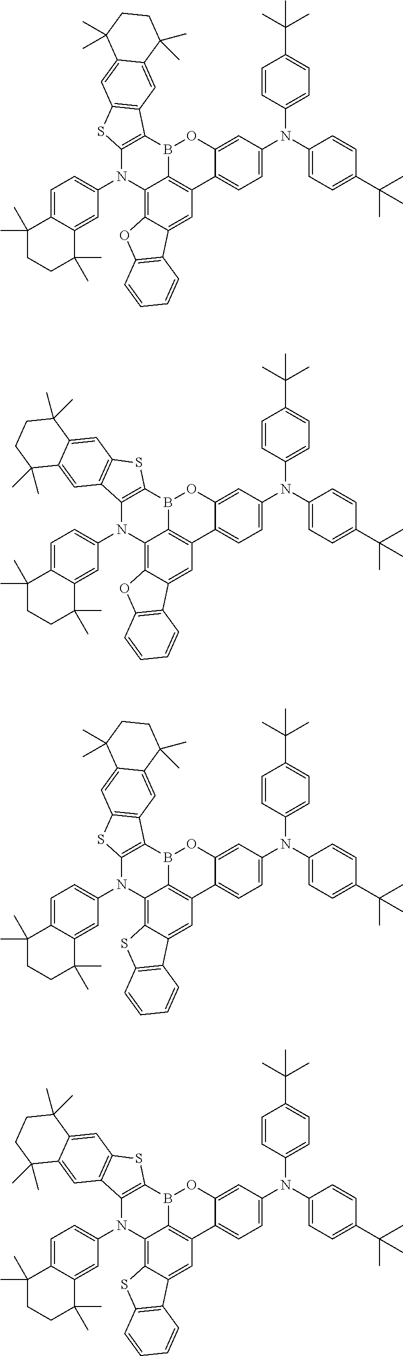

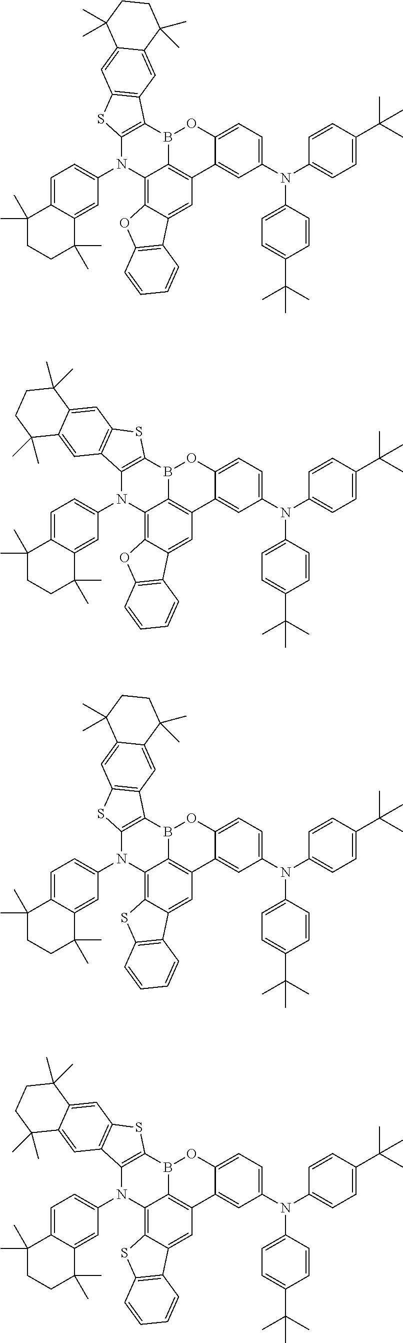

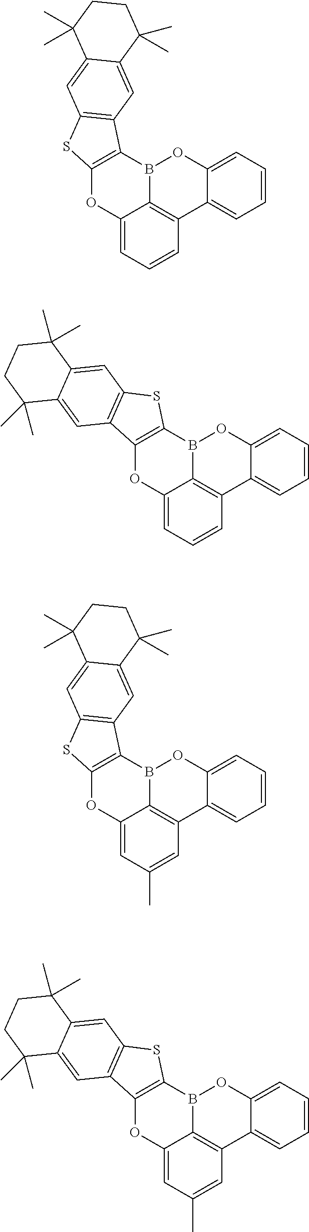 [SMILES: CC1(C)CCC(C)(C)c2cc3c4c(sc3cc21)Oc1cccc2c1B4Oc1ccccc1-2 ; CC1(C)CCC(C)(C)c2cc3c4c(sc3cc21)B1Oc2ccccc2-c2cccc(c21)O4 ; Cc1cc2c3c(c1)-c1ccccc1OB3c1c(sc3cc4c(cc13)C(C)(C)CCC4(C)C)O2 ; Cc1cc2c3c(c1)-c1ccccc1OB3c1sc3cc4c(cc3c1O2)C(C)(C)CCC4(C)C]

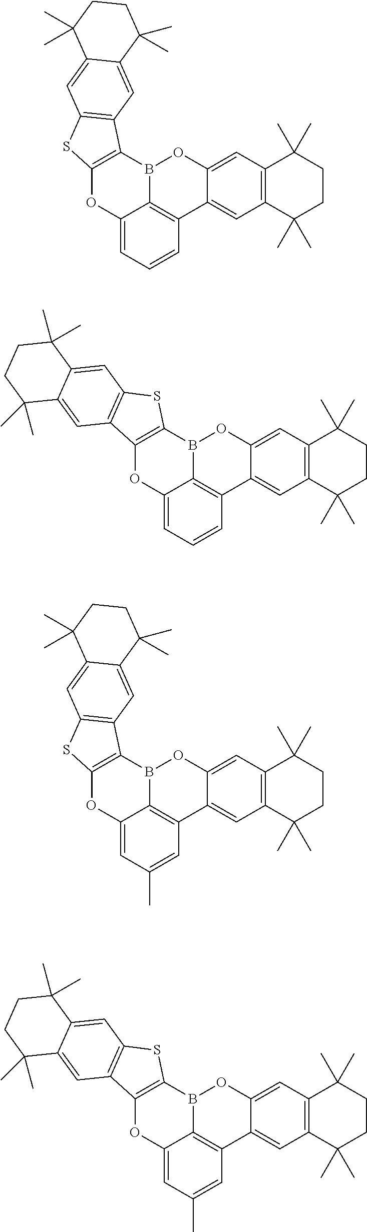 [SMILES: CC1(C)CCC(C)(C)c2cc3c(cc21)OB1c2c(cccc2-3)Oc2sc3cc4c(cc3c21)C(C)(C)CCC4(C)C ; CC1(C)CCC(C)(C)c2cc3c(cc21)OB1c2sc4cc5c(cc4c2Oc2cccc-3c21)C(C)(C)CCC5(C)C ; Cc1cc2c3c(c1)-c1cc4c(cc1OB3c1c(sc3cc5c(cc13)C(C)(C)CCC5(C)C)O2)C(C)(C)CCC4(C)C ; Cc1cc2c3c(c1)-c1cc4c(cc1OB3c1sc3cc5c(cc3c1O2)C(C)(C)CCC5(C)C)C(C)(C)CCC4(C)C]

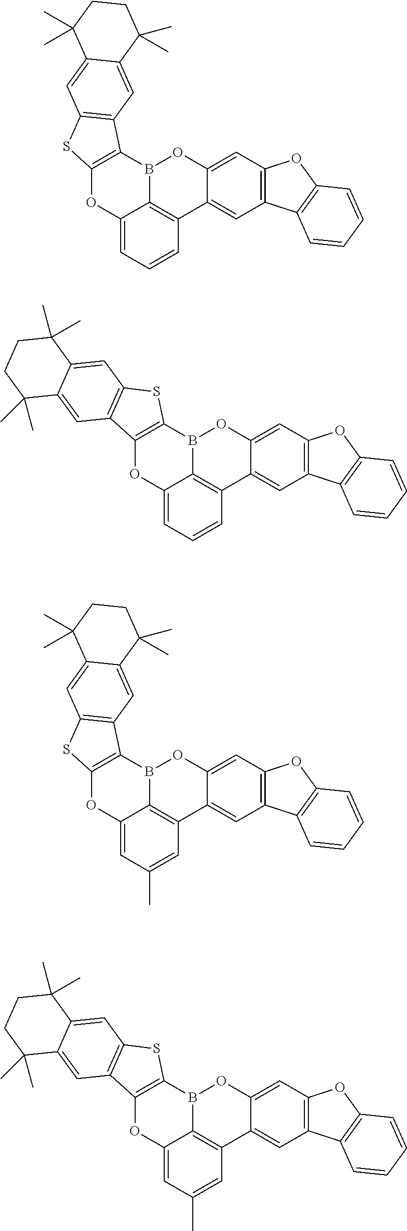 [SMILES: CC1(C)CCC(C)(C)c2cc3c4c(sc3cc21)Oc1cccc2c1B4Oc1cc3oc4ccccc4c3cc1-2 ; CC1(C)CCC(C)(C)c2cc3c4c(sc3cc21)B1Oc2cc3oc5ccccc5c3cc2-c2cccc(c21)O4 ; Cc1cc2c3c(c1)-c1cc4c(cc1OB3c1c(sc3cc5c(cc13)C(C)(C)CCC5(C)C)O2)oc1ccccc14 ; Cc1cc2c3c(c1)-c1cc4c(cc1OB3c1sc3cc5c(cc3c1O2)C(C)(C)CCC5(C)C)oc1ccccc14]

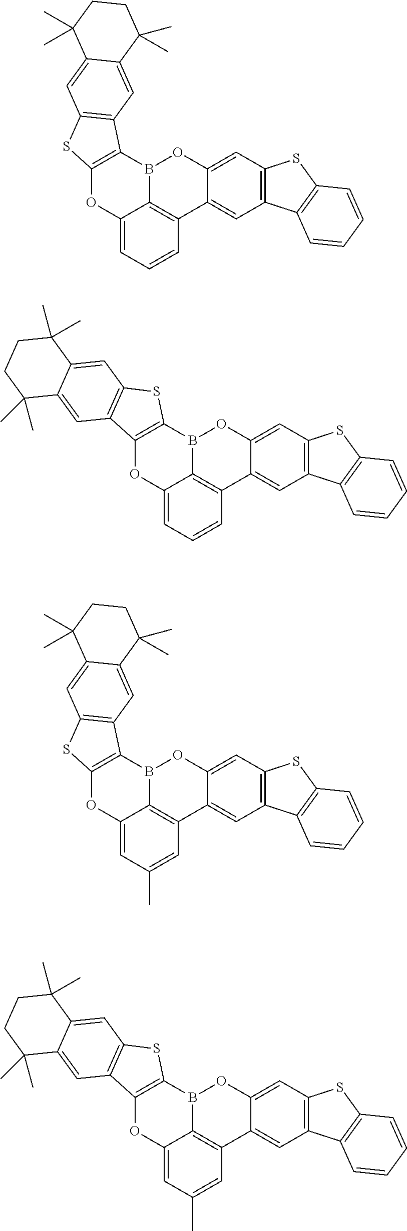 [SMILES: CC1(C)CCC(C)(C)c2cc3c4c(sc3cc21)Oc1cccc2c1B4Oc1cc3sc4ccccc4c3cc1-2 ; CC1(C)CCC(C)(C)c2cc3c4c(sc3cc21)B1Oc2cc3sc5ccccc5c3cc2-c2cccc(c21)O4 ; Cc1cc2c3c(c1)-c1cc4c(cc1OB3c1c(sc3cc5c(cc13)C(C)(C)CCC5(C)C)O2)sc1ccccc14 ; Cc1cc2c3c(c1)-c1cc4c(cc1OB3c1sc3cc5c(cc3c1O2)C(C)(C)CCC5(C)C)sc1ccccc14]

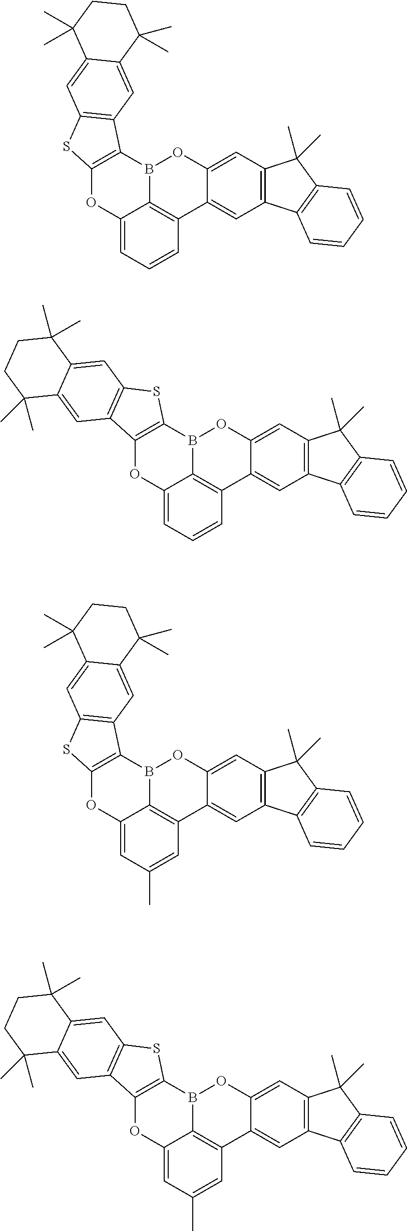 [SMILES: CC1(C)CCC(C)(C)c2cc3c4c(sc3cc21)Oc1cccc2c1B4Oc1cc3c(cc1-2)-c1ccccc1C3(C)C ; CC1(C)CCC(C)(C)c2cc3c4c(sc3cc21)B1Oc2cc3c(cc2-c2cccc(c21)O4)-c1ccccc1C3(C)C ; Cc1cc2c3c(c1)-c1cc4c(cc1OB3c1c(sc3cc5c(cc13)C(C)(C)CCC5(C)C)O2)C(C)(C)c1ccccc1-4 ; Cc1cc2c3c(c1)-c1cc4c(cc1OB3c1sc3cc5c(cc3c1O2)C(C)(C)CCC5(C)C)C(C)(C)c1ccccc1-4]

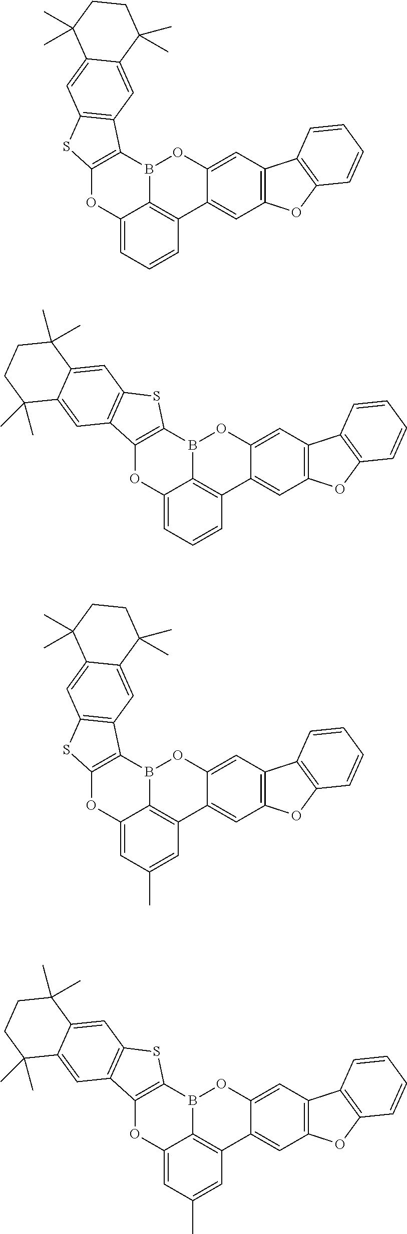 [SMILES: CC1(C)CCC(C)(C)c2cc3c4c(sc3cc21)Oc1cccc2c1B4Oc1cc3c(cc1-2)oc1ccccc13 ; CC1(C)CCC(C)(C)c2cc3c4c(sc3cc21)B1Oc2cc3c(cc2-c2cccc(c21)O4)oc1ccccc13 ; Cc1cc2c3c(c1)-c1cc4oc5ccccc5c4cc1OB3c1c(sc3cc4c(cc13)C(C)(C)CCC4(C)C)O2 ; Cc1cc2c3c(c1)-c1cc4oc5ccccc5c4cc1OB3c1sc3cc4c(cc3c1O2)C(C)(C)CCC4(C)C]

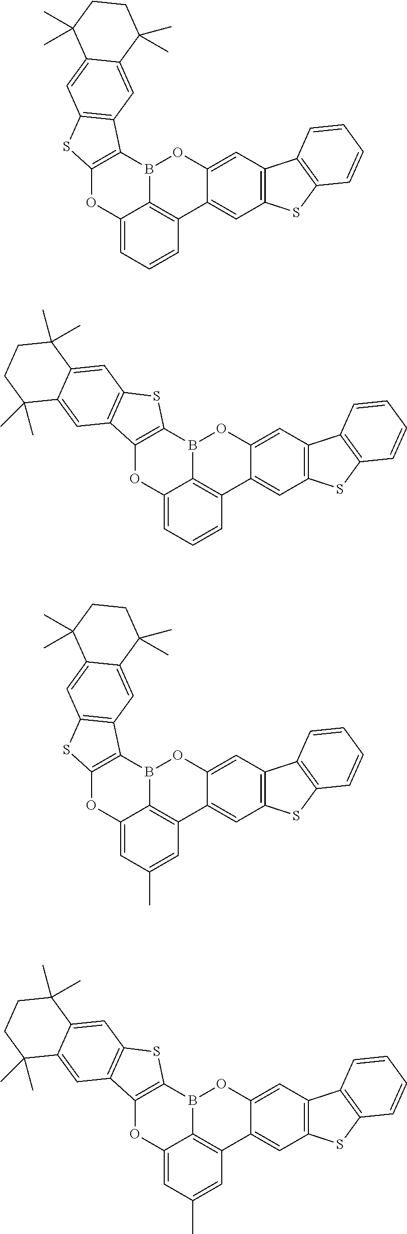 [SMILES: CC1(C)CCC(C)(C)c2cc3c4c(sc3cc21)Oc1cccc2c1B4Oc1cc3c(cc1-2)sc1ccccc13 ; CC1(C)CCC(C)(C)c2cc3c4c(sc3cc21)B1Oc2cc3c(cc2-c2cccc(c21)O4)sc1ccccc13 ; Cc1cc2c3c(c1)-c1cc4sc5ccccc5c4cc1OB3c1c(sc3cc4c(cc13)C(C)(C)CCC4(C)C)O2 ; Cc1cc2c3c(c1)-c1cc4sc5ccccc5c4cc1OB3c1sc3cc4c(cc3c1O2)C(C)(C)CCC4(C)C]

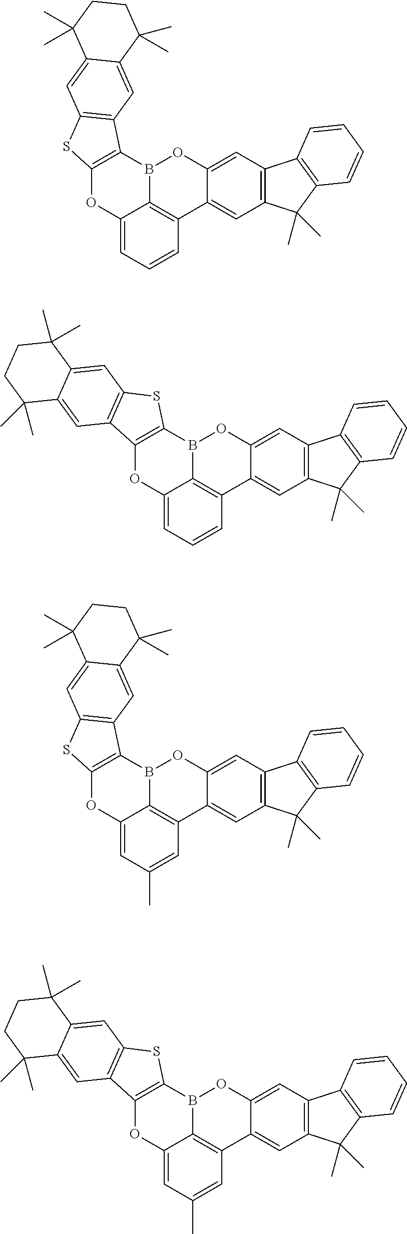 [SMILES: CC1(C)CCC(C)(C)c2cc3c4c(sc3cc21)Oc1cccc2c1B4Oc1cc3c(cc1-2)C(C)(C)c1ccccc1-3 ; CC1(C)CCC(C)(C)c2cc3c4c(sc3cc21)B1Oc2cc3c(cc2-c2cccc(c21)O4)C(C)(C)c1ccccc1-3 ; Cc1cc2c3c(c1)-c1cc4c(cc1OB3c1c(sc3cc5c(cc13)C(C)(C)CCC5(C)C)O2)-c1ccccc1C4(C)C ; Cc1cc2c3c(c1)-c1cc4c(cc1OB3c1sc3cc5c(cc3c1O2)C(C)(C)CCC5(C)C)-c1ccccc1C4(C)C]

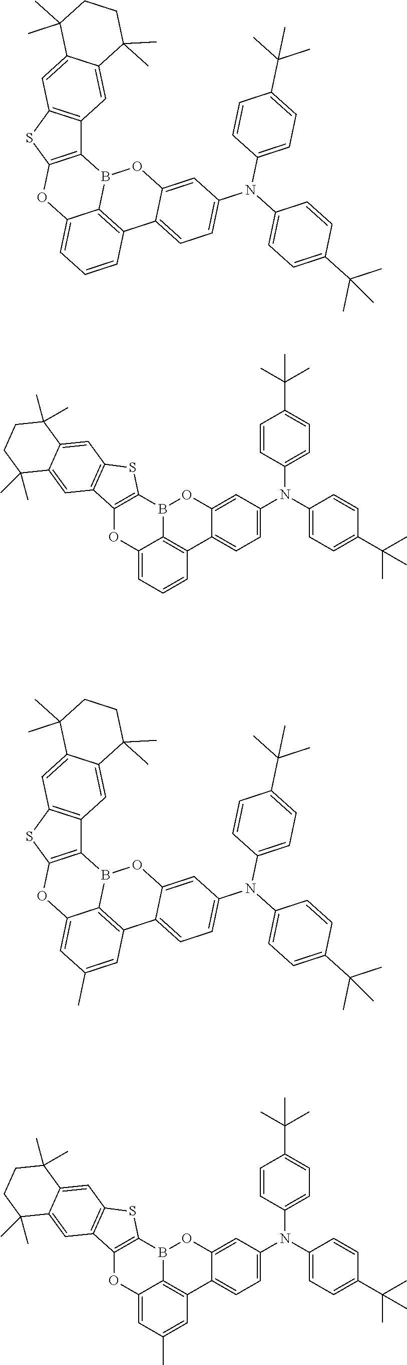

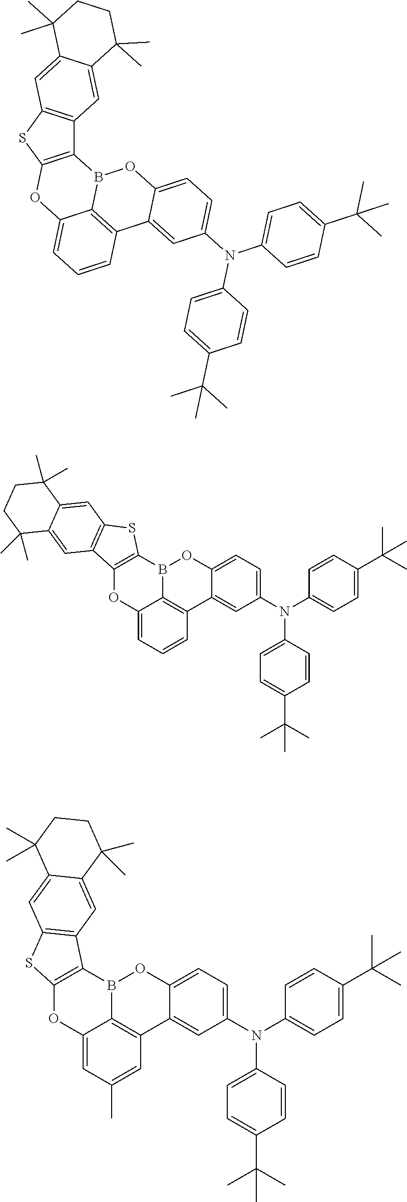

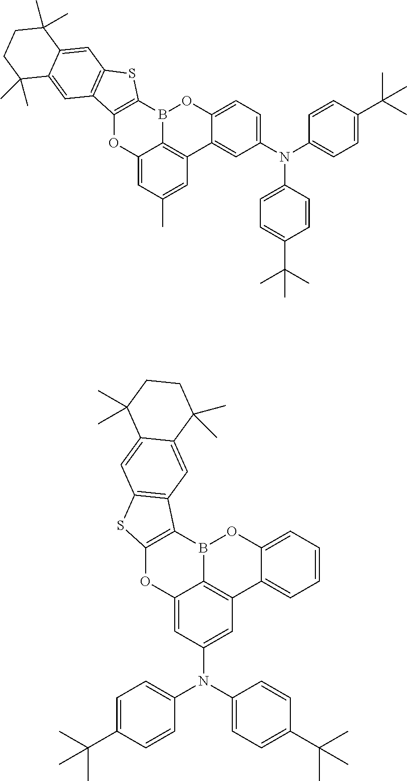

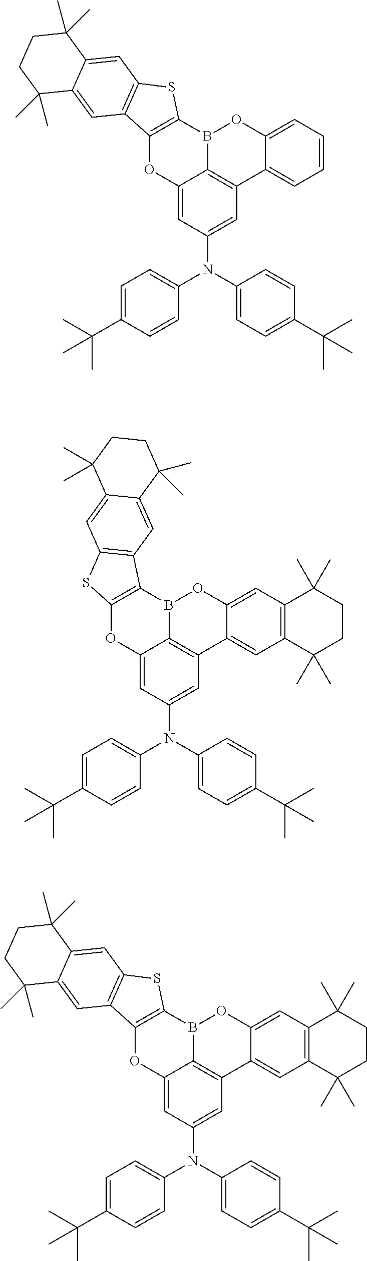

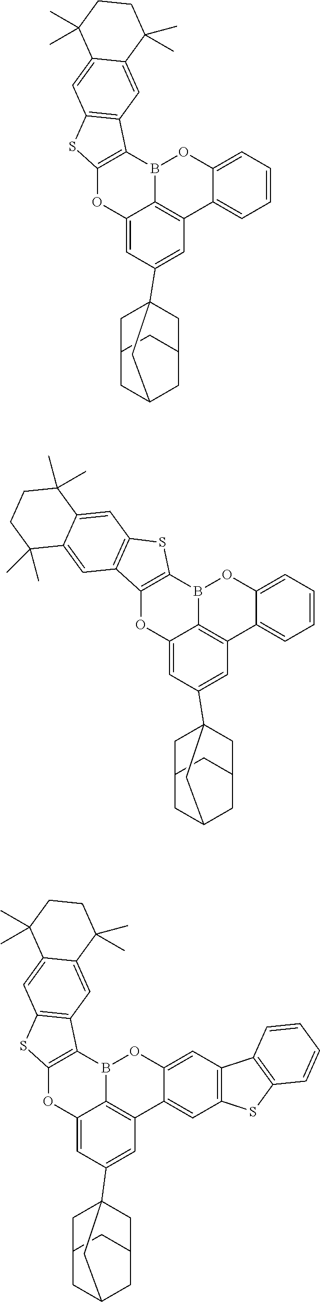 [SMILES: CC1(C)CCC(C)(C)c2cc3c4c(sc3cc21)Oc1cc(C23CC5CC(CC(C5)C2)C3)cc2c1B4Oc1ccccc1-2 ; CC1(C)CCC(C)(C)c2cc3c4c(sc3cc21)B1Oc2ccccc2-c2cc(C35CC6CC(CC(C6)C3)C5)cc(c21)O4 ; CC1(C)CCC(C)(C)c2cc3c4c(sc3cc21)Oc1cc(C23CC5CC(CC(C5)C2)C3)cc2c1B4Oc1cc3c(cc1-2)sc1ccccc13]

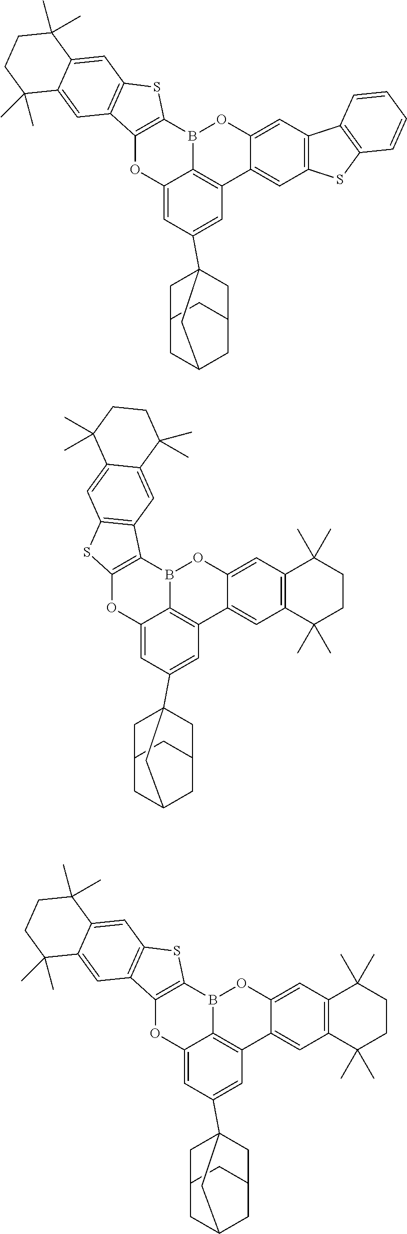 [SMILES: CC1(C)CCC(C)(C)c2cc3c4c(sc3cc21)B1Oc2cc3c(cc2-c2cc(C56CC7CC(CC(C7)C5)C6)cc(c21)O4)sc1ccccc13 ; CC1(C)CCC(C)(C)c2cc3c(cc21)OB1c2c(cc(C45CC6CC(CC(C6)C4)C5)cc2-3)Oc2sc3cc4c(cc3c21)C(C)(C)CCC4(C)C ; CC1(C)CCC(C)(C)c2cc3c(cc21)OB1c2sc4cc5c(cc4c2Oc2cc(C46CC7CC(CC(C7)C4)C6)cc-3c21)C(C)(C)CCC5(C)C]

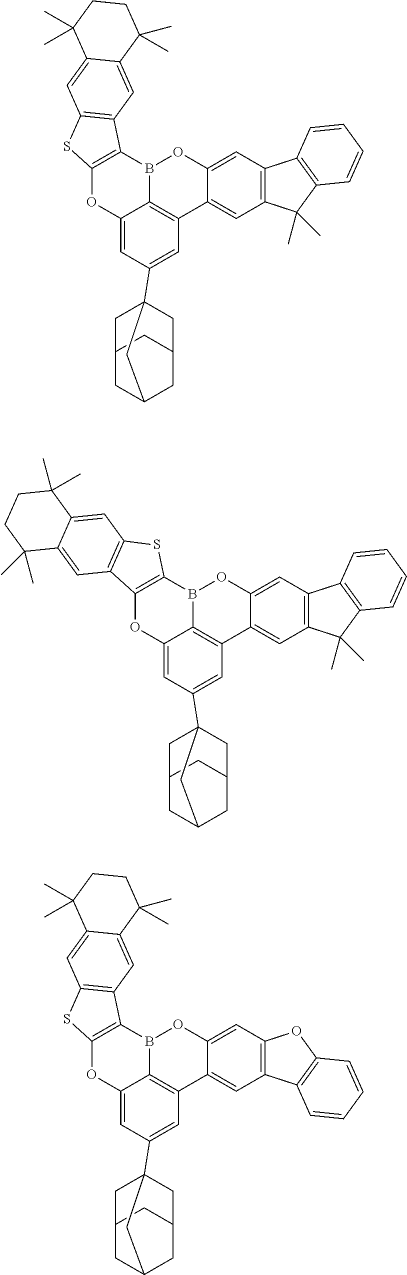 [SMILES: CC1(C)CCC(C)(C)c2cc3c4c(sc3cc21)Oc1cc(C23CC5CC(CC(C5)C2)C3)cc2c1B4Oc1cc3c(cc1-2)C(C)(C)c1ccccc1-3 ; CC1(C)CCC(C)(C)c2cc3c4c(sc3cc21)B1Oc2cc3c(cc2-c2cc(C56CC7CC(CC(C7)C5)C6)cc(c21)O4)C(C)(C)c1ccccc1-3 ; CC1(C)CCC(C)(C)c2cc3c4c(sc3cc21)Oc1cc(C23CC5CC(CC(C5)C2)C3)cc2c1B4Oc1cc3oc4ccccc4c3cc1-2]

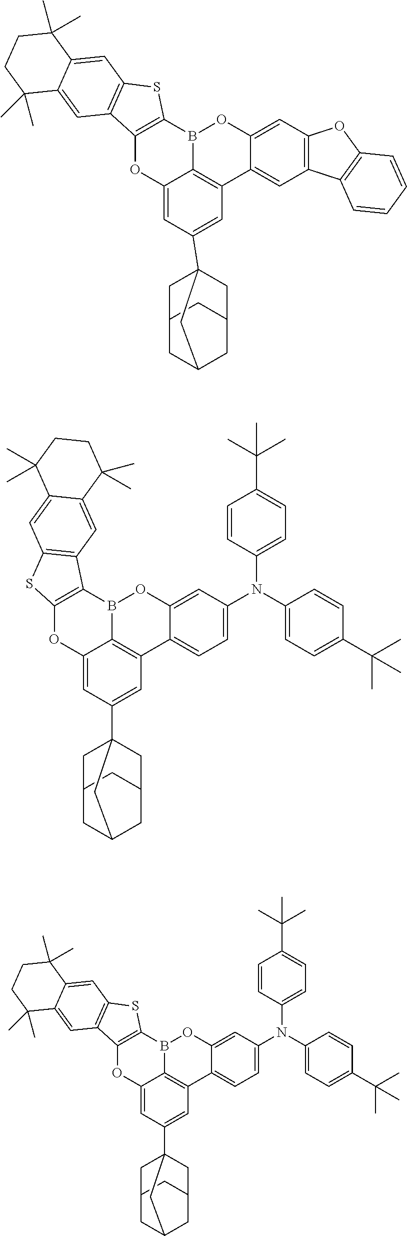

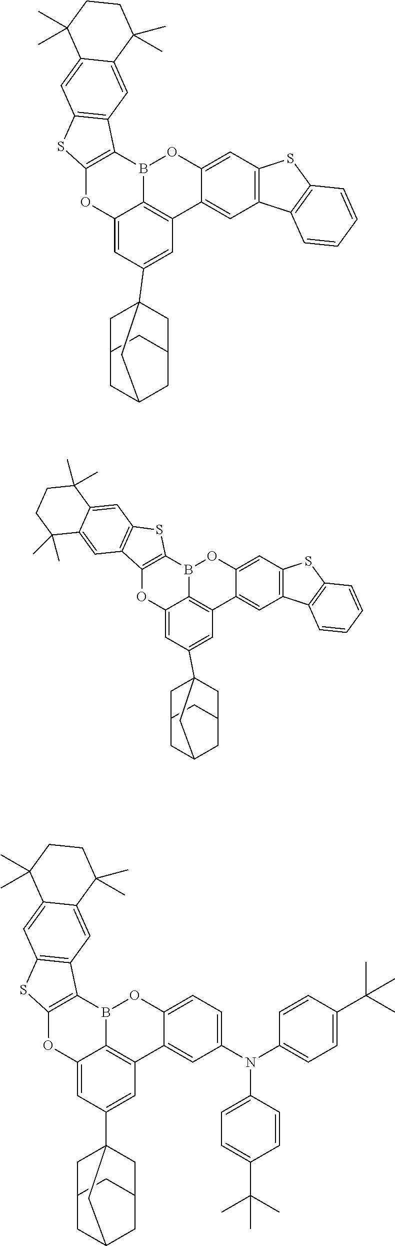 [SMILES: CC1(C)CCC(C)(C)c2cc3c4c(sc3cc21)Oc1cc(C23CC5CC(CC(C5)C2)C3)cc2c1B4Oc1cc3sc4ccccc4c3cc1-2 ; CC1(C)CCC(C)(C)c2cc3c4c(sc3cc21)B1Oc2cc3sc5ccccc5c3cc2-c2cc(C35CC6CC(CC(C6)C3)C5)cc(c21)O4 ; CC(C)(C)c1ccc(N(c2ccc(C(C)(C)C)cc2)c2ccc3c(c2)-c2cc(C45CC6CC(CC(C6)C4)C5)cc4c2B(O3)c2c(sc3cc5c(cc23)C(C)(C)CCC5(C)C)O4)cc1]

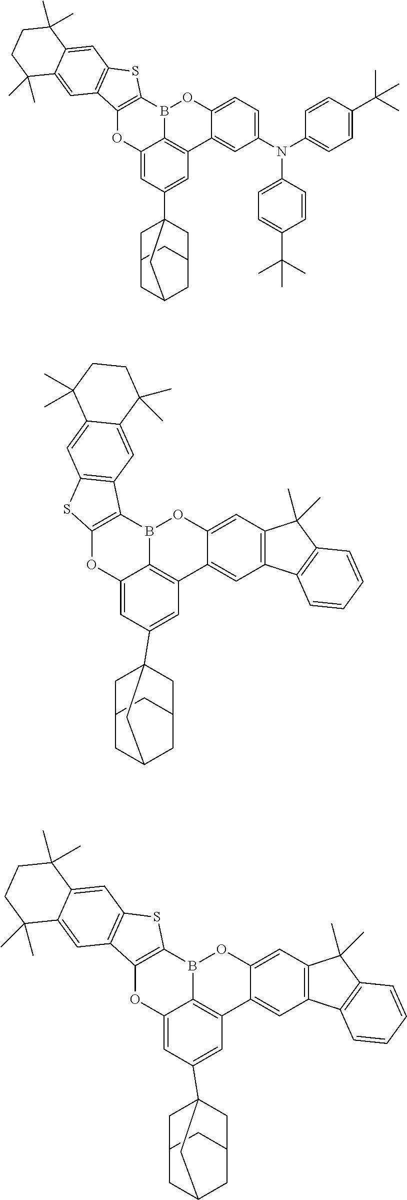

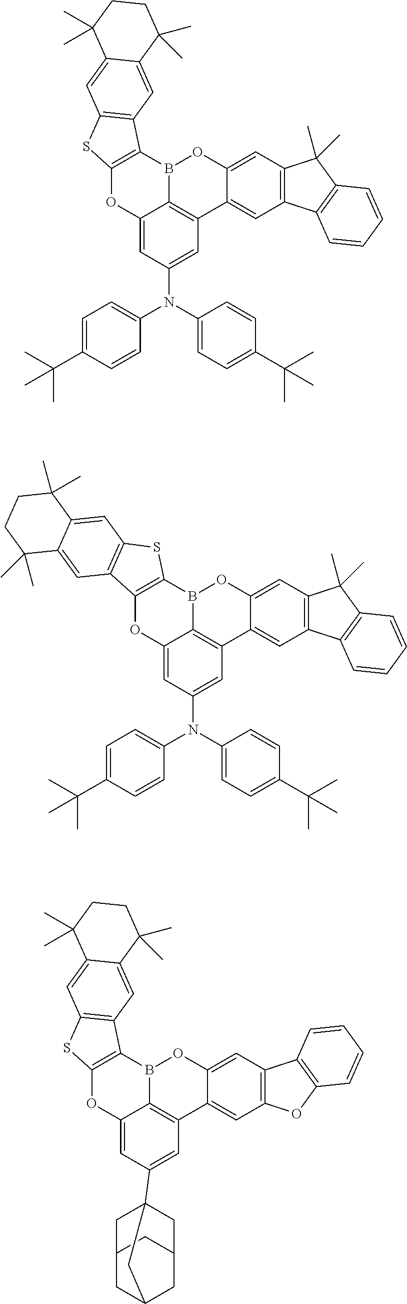 [SMILES: CC(C)(C)c1ccc(N(c2ccc(C(C)(C)C)cc2)c2cc3c4c(c2)-c2cc5c(cc2OB4c2c(sc4cc6c(cc24)C(C)(C)CCC6(C)C)O3)C(C)(C)c2ccccc2-5)cc1 ; CC(C)(C)c1ccc(N(c2ccc(C(C)(C)C)cc2)c2cc3c4c(c2)-c2cc5c(cc2OB4c2sc4cc6c(cc4c2O3)C(C)(C)CCC6(C)C)C(C)(C)c2ccccc2-5)cc1 ; CC1(C)CCC(C)(C)c2cc3c4c(sc3cc21)Oc1cc(C23CC5CC(CC(C5)C2)C3)cc2c1B4Oc1cc3c(cc1-2)oc1ccccc13]

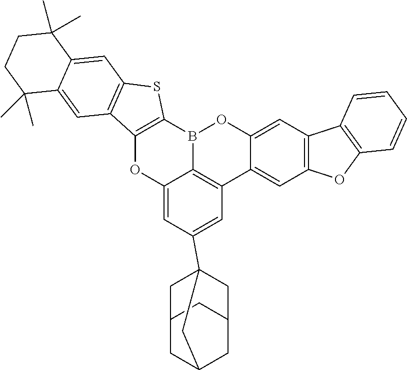 [SMILES: CC1(C)CCC(C)(C)c2cc3c4c(sc3cc21)B1Oc2cc3c(cc2-c2cc(C56CC7CC(CC(C7)C5)C6)cc(c21)O4)oc1ccccc13]

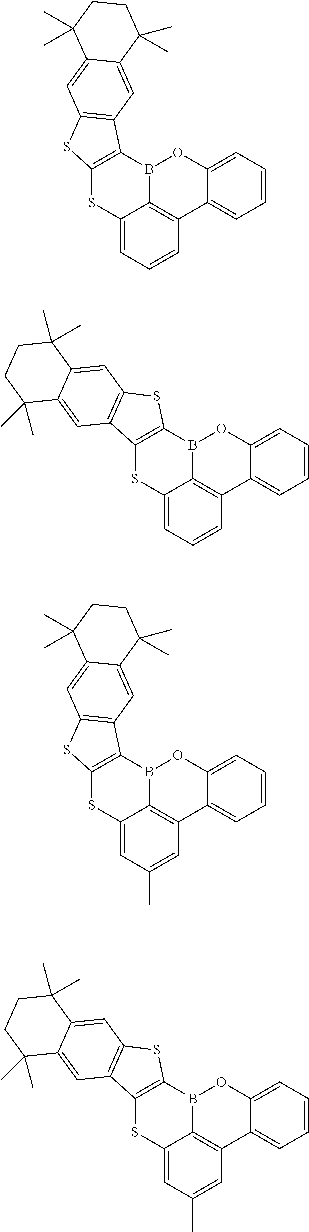 [SMILES: CC1(C)CCC(C)(C)c2cc3c4c(sc3cc21)Sc1cccc2c1B4Oc1ccccc1-2 ; CC1(C)CCC(C)(C)c2cc3c4c(sc3cc21)B1Oc2ccccc2-c2cccc(c21)S4 ; Cc1cc2c3c(c1)-c1ccccc1OB3c1c(sc3cc4c(cc13)C(C)(C)CCC4(C)C)S2 ; Cc1cc2c3c(c1)-c1ccccc1OB3c1sc3cc4c(cc3c1S2)C(C)(C)CCC4(C)C]

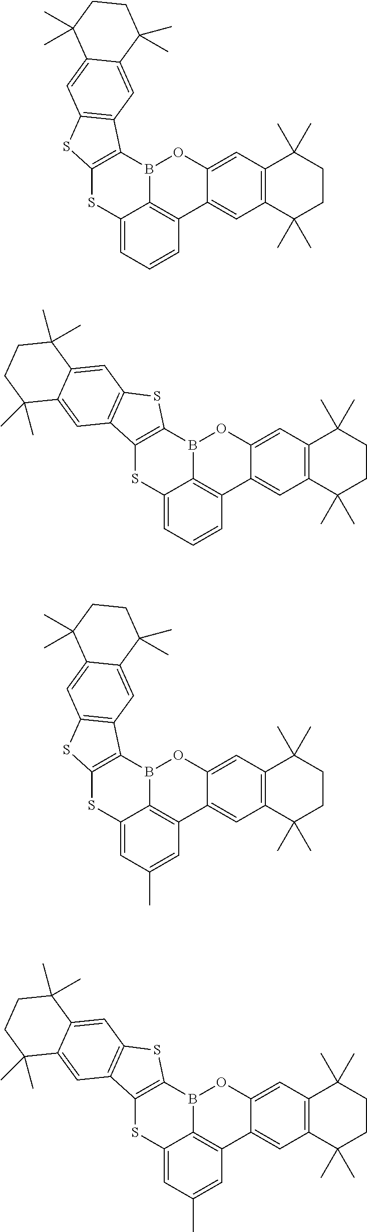 [SMILES: CC1(C)CCC(C)(C)c2cc3c(cc21)OB1c2c(cccc2-3)Sc2sc3cc4c(cc3c21)C(C)(C)CCC4(C)C ; CC1(C)CCC(C)(C)c2cc3c(cc21)OB1c2sc4cc5c(cc4c2Sc2cccc-3c21)C(C)(C)CCC5(C)C ; Cc1cc2c3c(c1)-c1cc4c(cc1OB3c1c(sc3cc5c(cc13)C(C)(C)CCC5(C)C)S2)C(C)(C)CCC4(C)C ; Cc1cc2c3c(c1)-c1cc4c(cc1OB3c1sc3cc5c(cc3c1S2)C(C)(C)CCC5(C)C)C(C)(C)CCC4(C)C]

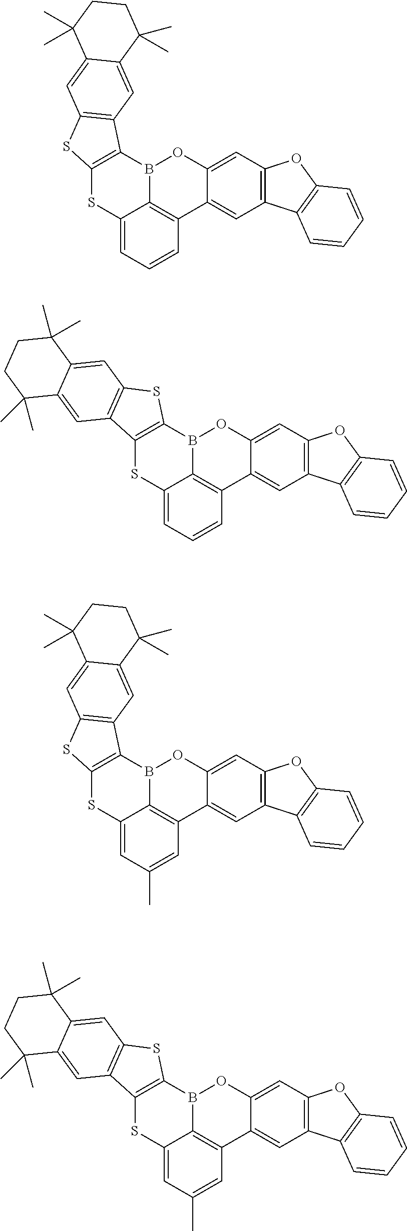 [SMILES: CC1(C)CCC(C)(C)c2cc3c4c(sc3cc21)Sc1cccc2c1B4Oc1cc3oc4ccccc4c3cc1-2 ; CC1(C)CCC(C)(C)c2cc3c4c(sc3cc21)B1Oc2cc3oc5ccccc5c3cc2-c2cccc(c21)S4 ; Cc1cc2c3c(c1)-c1cc4c(cc1OB3c1c(sc3cc5c(cc13)C(C)(C)CCC5(C)C)S2)oc1ccccc14 ; Cc1cc2c3c(c1)-c1cc4c(cc1OB3c1sc3cc5c(cc3c1S2)C(C)(C)CCC5(C)C)oc1ccccc14]

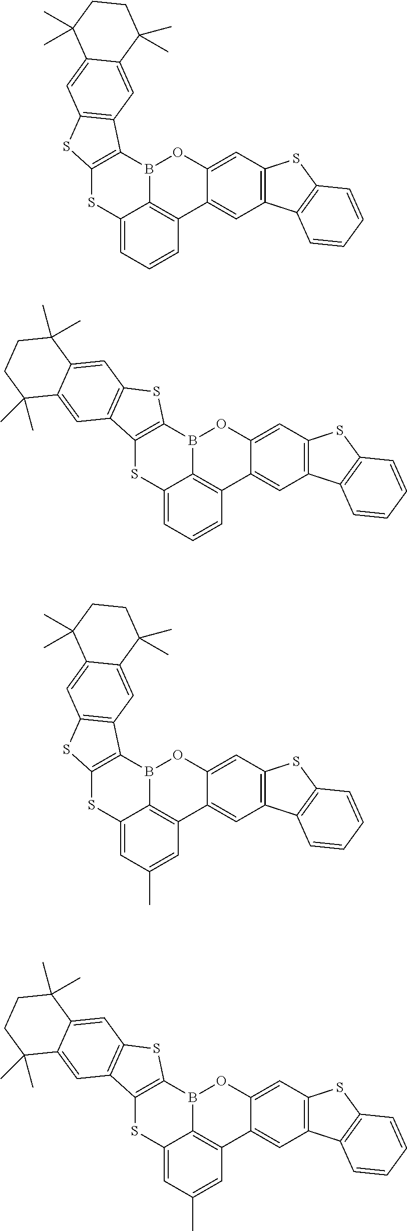 [SMILES: CC1(C)CCC(C)(C)c2cc3c4c(sc3cc21)Sc1cccc2c1B4Oc1cc3sc4ccccc4c3cc1-2 ; CC1(C)CCC(C)(C)c2cc3c4c(sc3cc21)B1Oc2cc3sc5ccccc5c3cc2-c2cccc(c21)S4 ; Cc1cc2c3c(c1)-c1cc4c(cc1OB3c1c(sc3cc5c(cc13)C(C)(C)CCC5(C)C)S2)sc1ccccc14 ; Cc1cc2c3c(c1)-c1cc4c(cc1OB3c1sc3cc5c(cc3c1S2)C(C)(C)CCC5(C)C)sc1ccccc14]

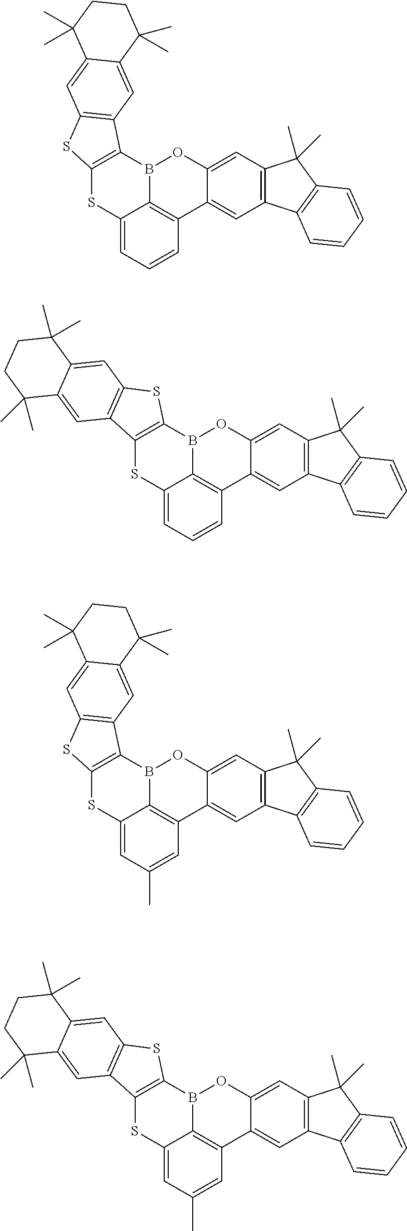 [SMILES: CC1(C)CCC(C)(C)c2cc3c4c(sc3cc21)Sc1cccc2c1B4Oc1cc3c(cc1-2)-c1ccccc1C3(C)C ; CC1(C)CCC(C)(C)c2cc3c4c(sc3cc21)B1Oc2cc3c(cc2-c2cccc(c21)S4)-c1ccccc1C3(C)C ; Cc1cc2c3c(c1)-c1cc4c(cc1OB3c1c(sc3cc5c(cc13)C(C)(C)CCC5(C)C)S2)C(C)(C)c1ccccc1-4 ; Cc1cc2c3c(c1)-c1cc4c(cc1OB3c1sc3cc5c(cc3c1S2)C(C)(C)CCC5(C)C)C(C)(C)c1ccccc1-4]

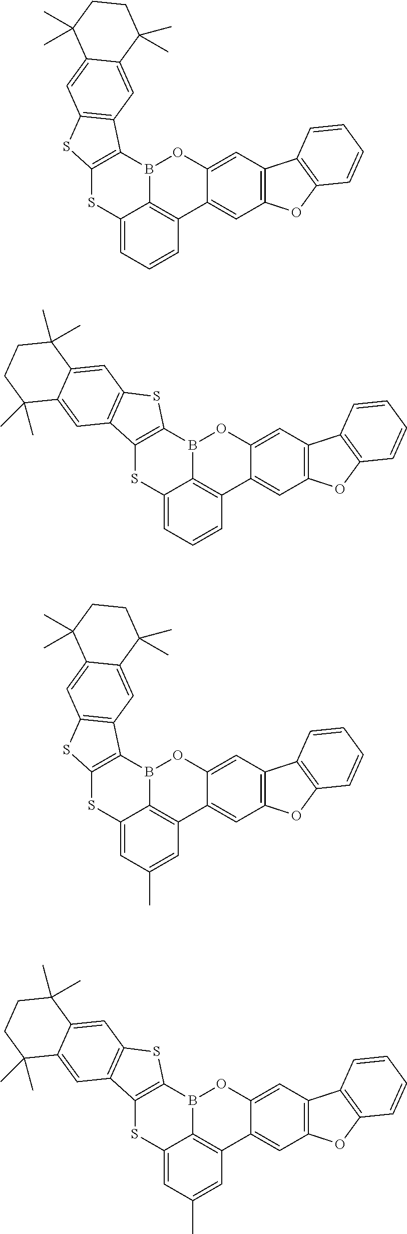 [SMILES: CC1(C)CCC(C)(C)c2cc3c4c(sc3cc21)Sc1cccc2c1B4Oc1cc3c(cc1-2)oc1ccccc13 ; CC1(C)CCC(C)(C)c2cc3c4c(sc3cc21)B1Oc2cc3c(cc2-c2cccc(c21)S4)oc1ccccc13 ; Cc1cc2c3c(c1)-c1cc4oc5ccccc5c4cc1OB3c1c(sc3cc4c(cc13)C(C)(C)CCC4(C)C)S2 ; Cc1cc2c3c(c1)-c1cc4oc5ccccc5c4cc1OB3c1sc3cc4c(cc3c1S2)C(C)(C)CCC4(C)C]

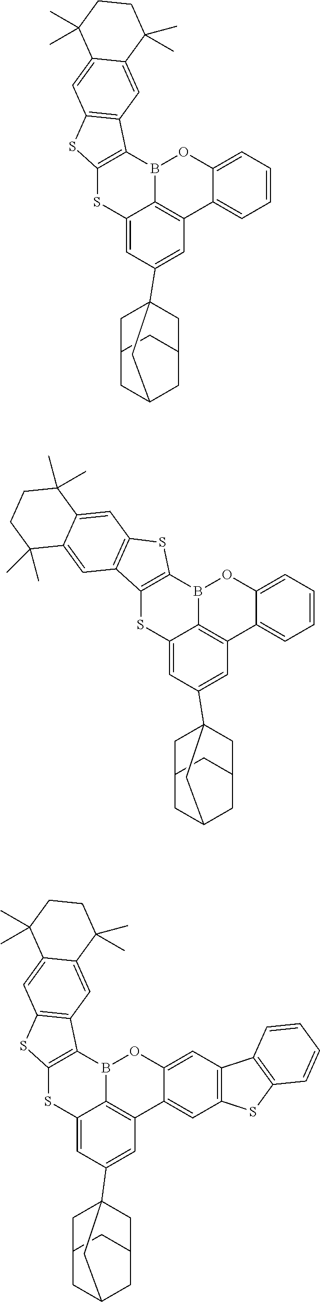 [SMILES: CC1(C)CCC(C)(C)c2cc3c4c(sc3cc21)Sc1cc(C23CC5CC(CC(C5)C2)C3)cc2c1B4Oc1ccccc1-2 ; CC1(C)CCC(C)(C)c2cc3c4c(sc3cc21)B1Oc2ccccc2-c2cc(C35CC6CC(CC(C6)C3)C5)cc(c21)S4 ; CC1(C)CCC(C)(C)c2cc3c4c(sc3cc21)Sc1cc(C23CC5CC(CC(C5)C2)C3)cc2c1B4Oc1cc3c(cc1-2)sc1ccccc13]

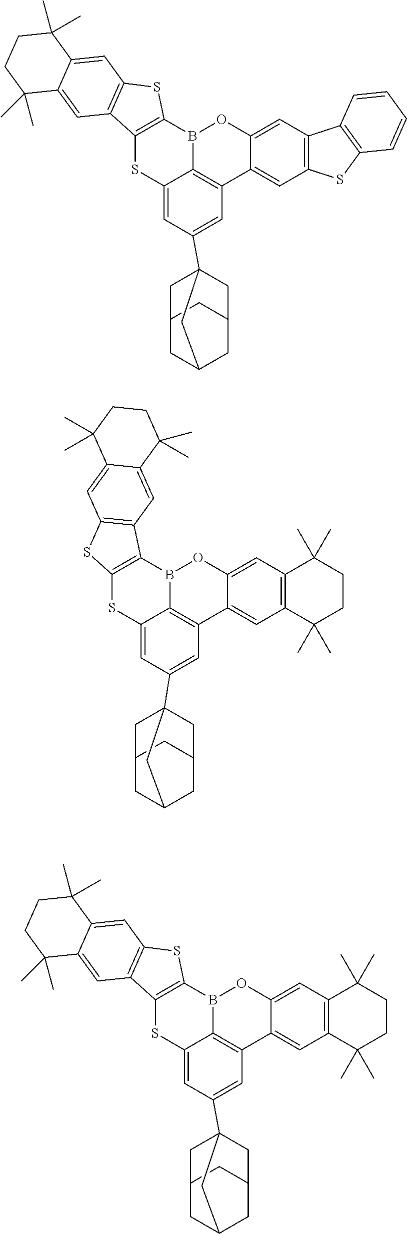 [SMILES: CC1(C)CCC(C)(C)c2cc3c4c(sc3cc21)B1Oc2cc3c(cc2-c2cc(C56CC7CC(CC(C7)C5)C6)cc(c21)S4)sc1ccccc13 ; CC1(C)CCC(C)(C)c2cc3c(cc21)OB1c2c(cc(C45CC6CC(CC(C6)C4)C5)cc2-3)Sc2sc3cc4c(cc3c21)C(C)(C)CCC4(C)C ; CC1(C)CCC(C)(C)c2cc3c(cc21)OB1c2sc4cc5c(cc4c2Sc2cc(C46CC7CC(CC(C7)C4)C6)cc-3c21)C(C)(C)CCC5(C)C]

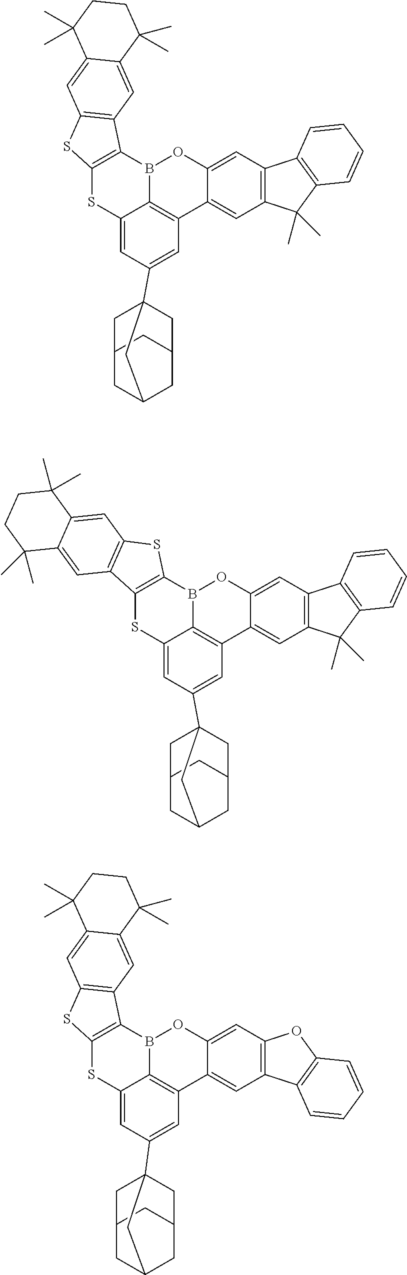 [SMILES: CC1(C)CCC(C)(C)c2cc3c4c(sc3cc21)Sc1cc(C23CC5CC(CC(C5)C2)C3)cc2c1B4Oc1cc3c(cc1-2)C(C)(C)c1ccccc1-3 ; CC1(C)CCC(C)(C)c2cc3c4c(sc3cc21)B1Oc2cc3c(cc2-c2cc(C56CC7CC(CC(C7)C5)C6)cc(c21)S4)C(C)(C)c1ccccc1-3 ; CC1(C)CCC(C)(C)c2cc3c4c(sc3cc21)Sc1cc(C23CC5CC(CC(C5)C2)C3)cc2c1B4Oc1cc3oc4ccccc4c3cc1-2]

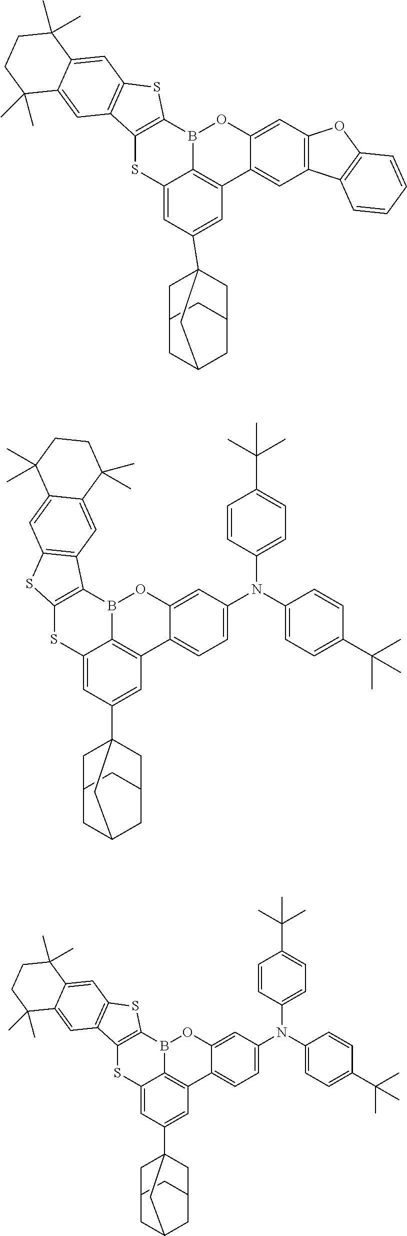

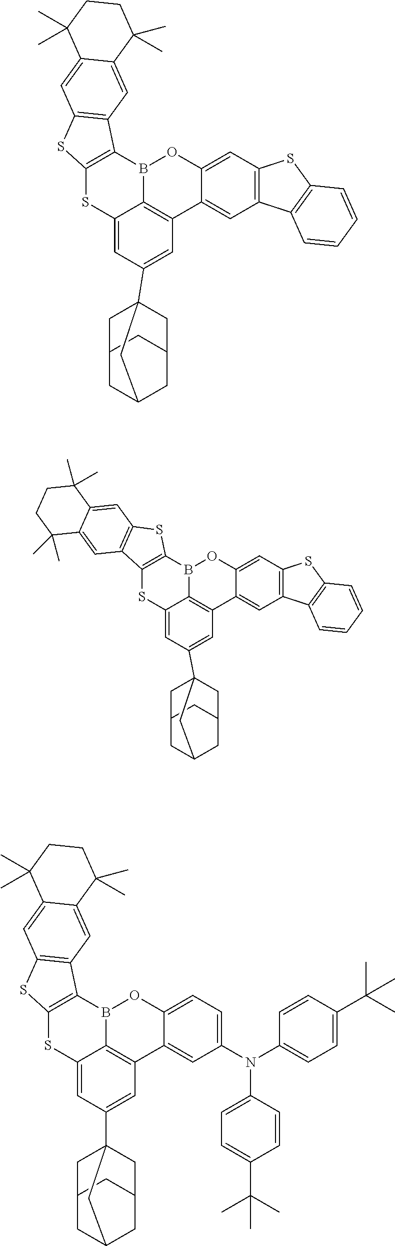 [SMILES: CC1(C)CCC(C)(C)c2cc3c4c(sc3cc21)Sc1cc(C23CC5CC(CC(C5)C2)C3)cc2c1B4Oc1cc3sc4ccccc4c3cc1-2 ; CC1(C)CCC(C)(C)c2cc3c4c(sc3cc21)B1Oc2cc3sc5ccccc5c3cc2-c2cc(C35CC6CC(CC(C6)C3)C5)cc(c21)S4 ; CC(C)(C)c1ccc(N(c2ccc(C(C)(C)C)cc2)c2ccc3c(c2)-c2cc(C45CC6CC(CC(C6)C4)C5)cc4c2B(O3)c2c(sc3cc5c(cc23)C(C)(C)CCC5(C)C)S4)cc1]

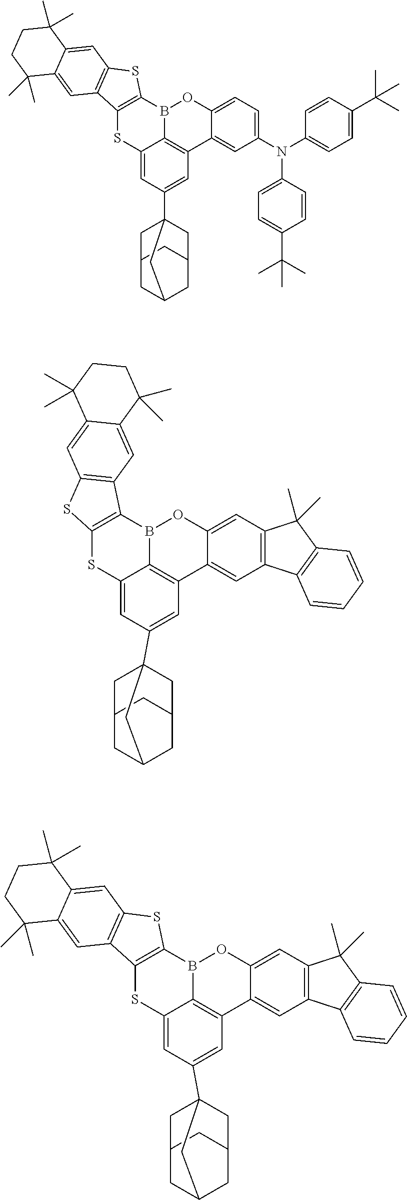

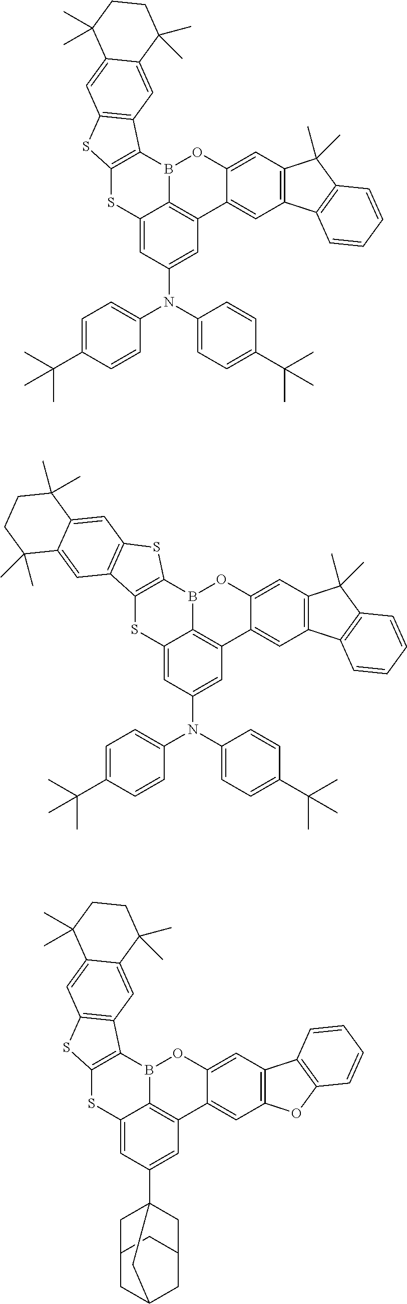 [SMILES: CC(C)(C)c1ccc(N(c2ccc(C(C)(C)C)cc2)c2cc3c4c(c2)-c2cc5c(cc2OB4c2c(sc4cc6c(cc24)C(C)(C)CCC6(C)C)S3)C(C)(C)c2ccccc2-5)cc1 ; CC(C)(C)c1ccc(N(c2ccc(C(C)(C)C)cc2)c2cc3c4c(c2)-c2cc5c(cc2OB4c2sc4cc6c(cc4c2S3)C(C)(C)CCC6(C)C)C(C)(C)c2ccccc2-5)cc1 ; CC1(C)CCC(C)(C)c2cc3c4c(sc3cc21)Sc1cc(C23CC5CC(CC(C5)C2)C3)cc2c1B4Oc1cc3c(cc1-2)oc1ccccc13]

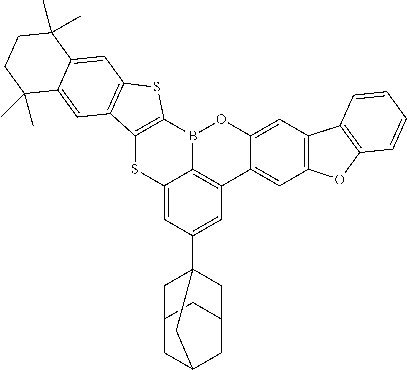 [SMILES: CC1(C)CCC(C)(C)c2cc3c4c(sc3cc21)B1Oc2cc3c(cc2-c2cc(C56CC7CC(CC(C7)C5)C6)cc(c21)S4)oc1ccccc13]

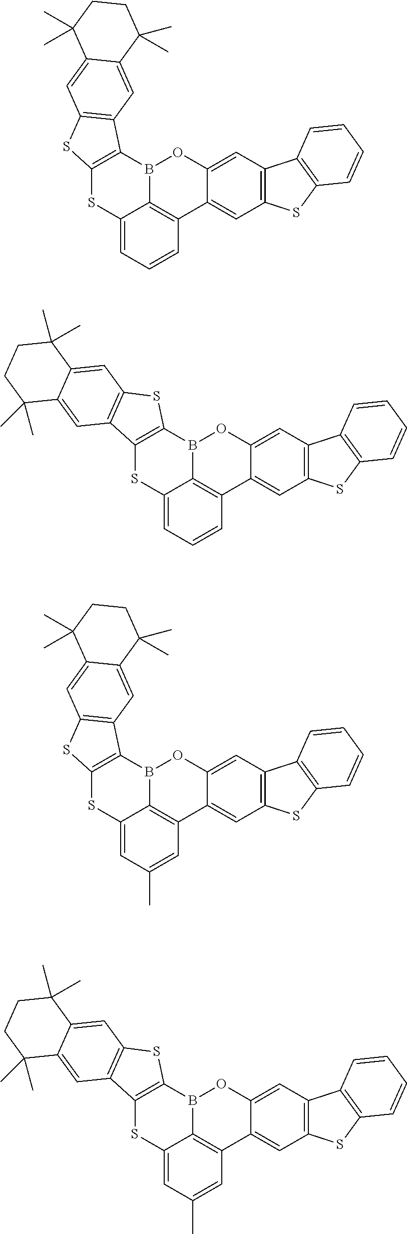 [SMILES: CC1(C)CCC(C)(C)c2cc3c4c(sc3cc21)Sc1cccc2c1B4Oc1cc3c(cc1-2)sc1ccccc13 ; CC1(C)CCC(C)(C)c2cc3c4c(sc3cc21)B1Oc2cc3c(cc2-c2cccc(c21)S4)sc1ccccc13 ; Cc1cc2c3c(c1)-c1cc4sc5ccccc5c4cc1OB3c1c(sc3cc4c(cc13)C(C)(C)CCC4(C)C)S2 ; Cc1cc2c3c(c1)-c1cc4sc5ccccc5c4cc1OB3c1sc3cc4c(cc3c1S2)C(C)(C)CCC4(C)C]

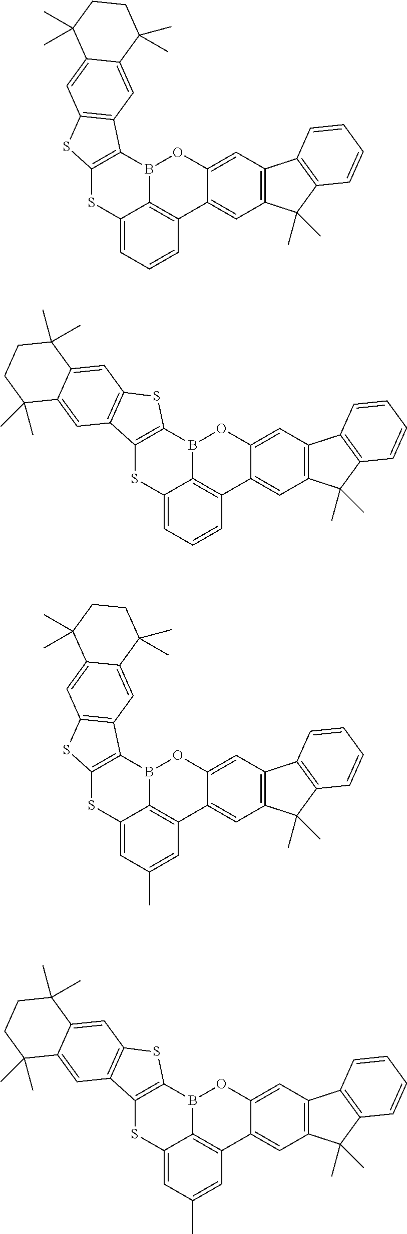 [SMILES: CC1(C)CCC(C)(C)c2cc3c4c(sc3cc21)Sc1cccc2c1B4Oc1cc3c(cc1-2)C(C)(C)c1ccccc1-3 ; CC1(C)CCC(C)(C)c2cc3c4c(sc3cc21)B1Oc2cc3c(cc2-c2cccc(c21)S4)C(C)(C)c1ccccc1-3 ; Cc1cc2c3c(c1)-c1cc4c(cc1OB3c1c(sc3cc5c(cc13)C(C)(C)CCC5(C)C)S2)-c1ccccc1C4(C)C ; Cc1cc2c3c(c1)-c1cc4c(cc1OB3c1sc3cc5c(cc3c1S2)C(C)(C)CCC5(C)C)-c1ccccc1C4(C)C]

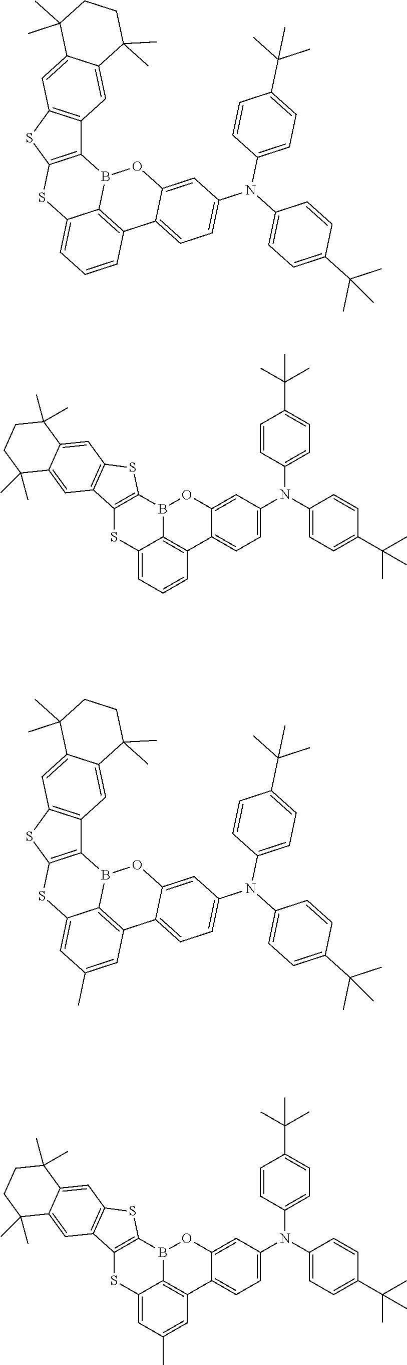

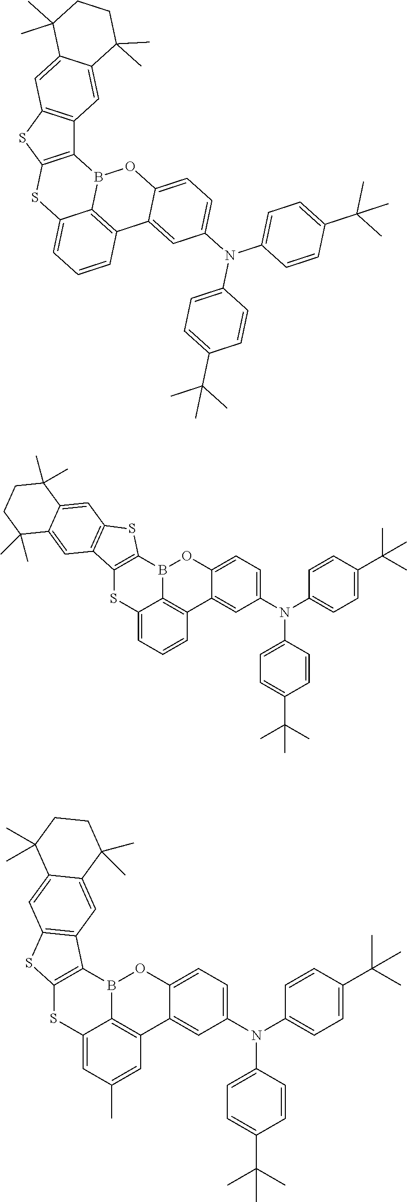

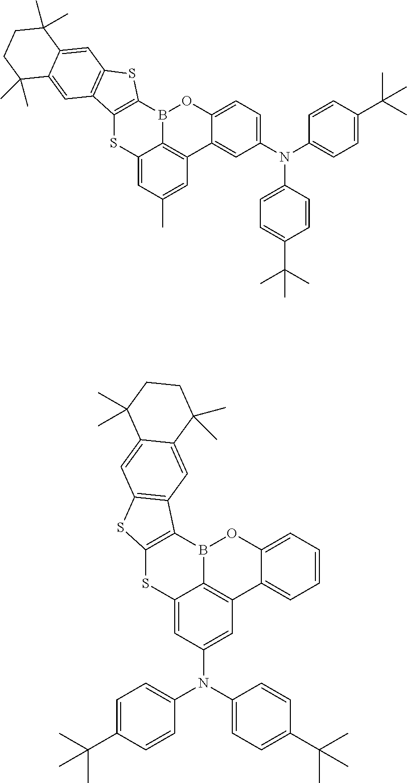

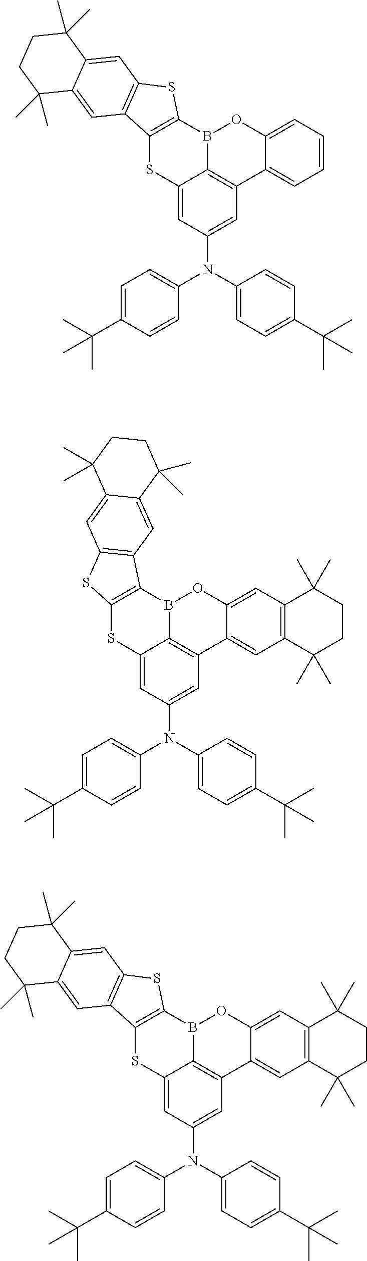

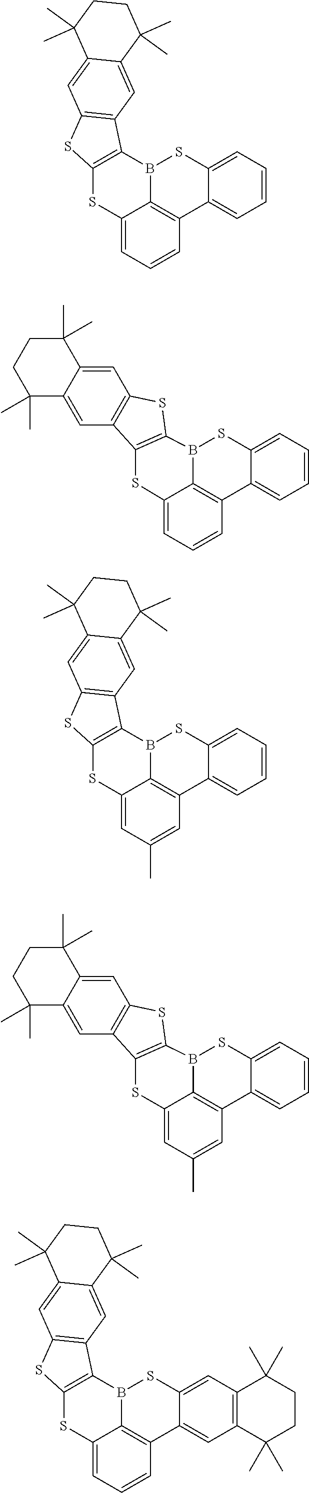

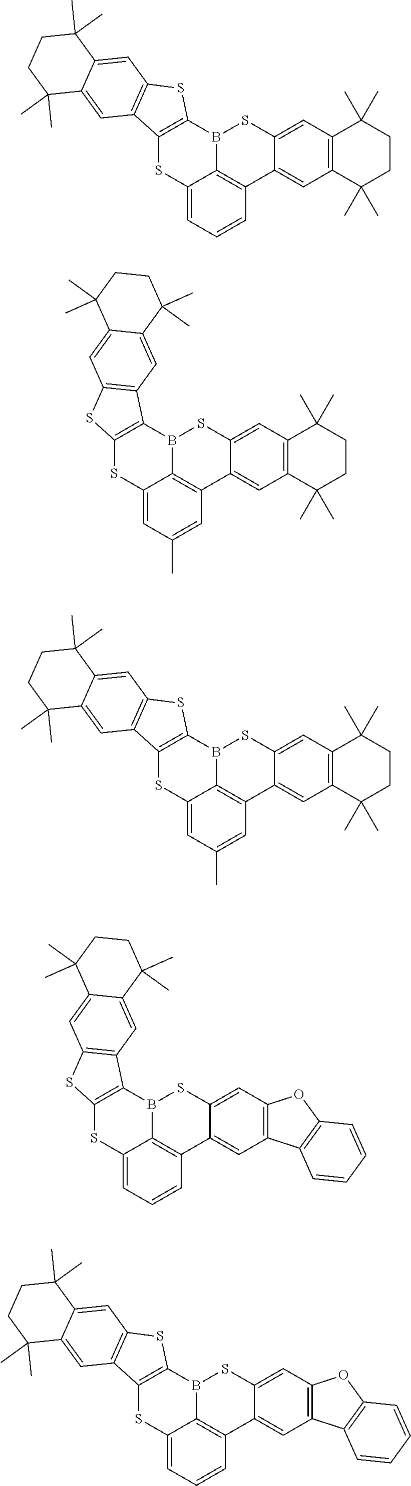

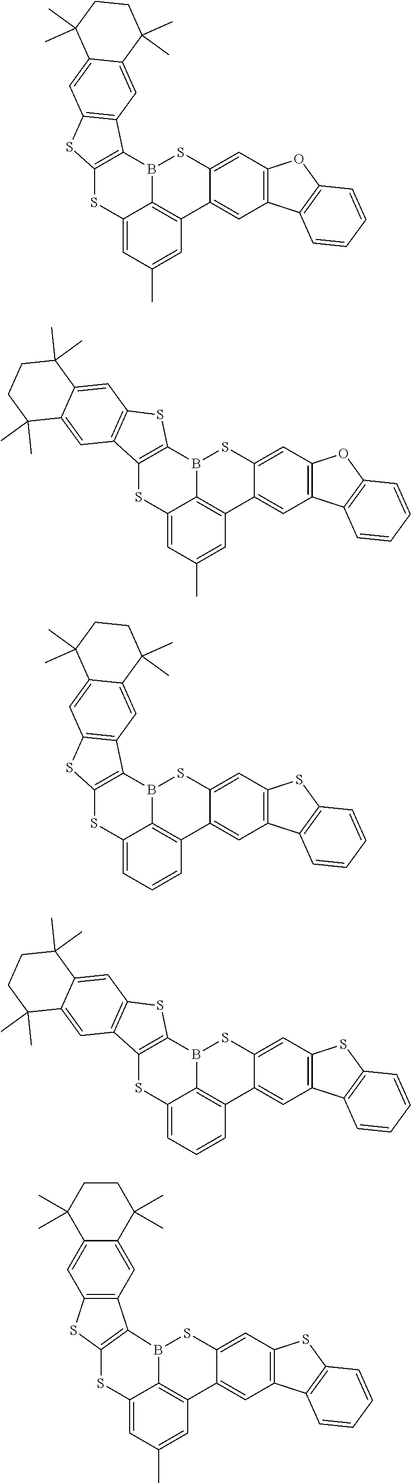

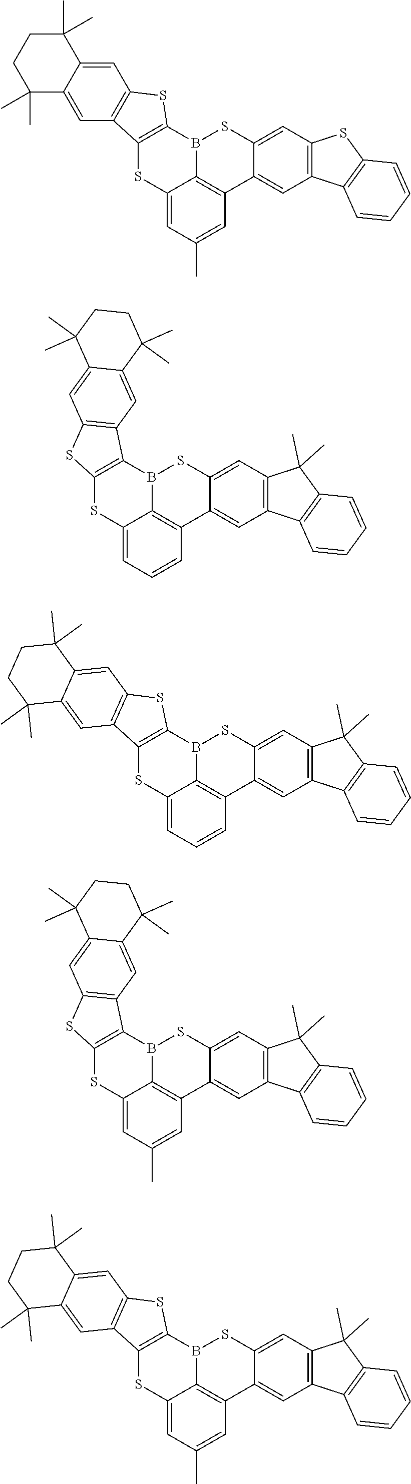

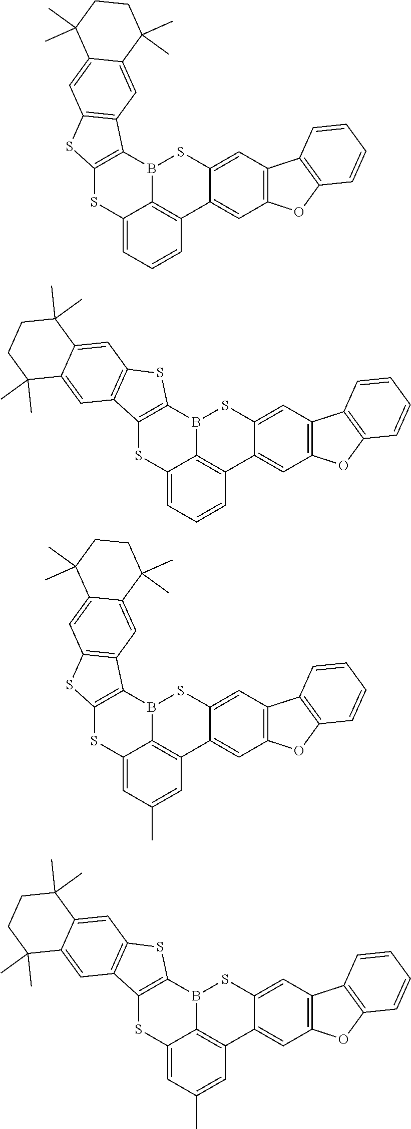

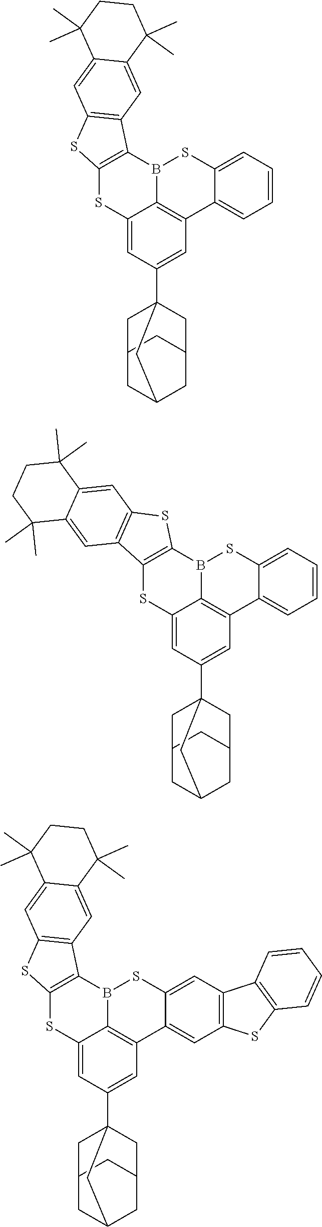 [SMILES: CC1(C)CCC(C)(C)c2cc3c4c(sc3cc21)Sc1cc(C23CC5CC(CC(C5)C2)C3)cc2c1B4Sc1ccccc1-2 ; CC1(C)CCC(C)(C)c2cc3c4c(sc3cc21)B1Sc2ccccc2-c2cc(C35CC6CC(CC(C6)C3)C5)cc(c21)S4 ; CC1(C)CCC(C)(C)c2cc3c4c(sc3cc21)Sc1cc(C23CC5CC(CC(C5)C2)C3)cc2c1B4Sc1cc3c(cc1-2)sc1ccccc13]

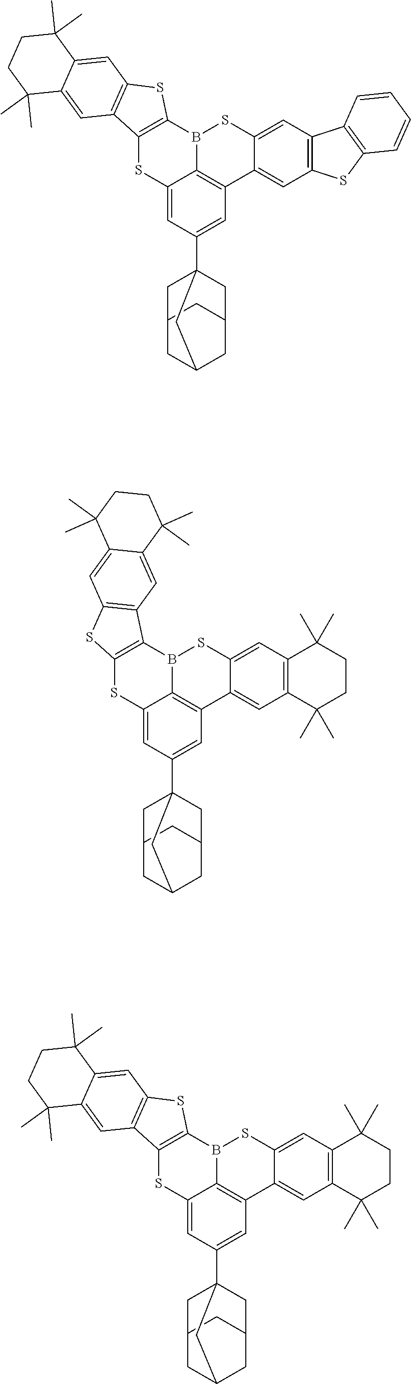

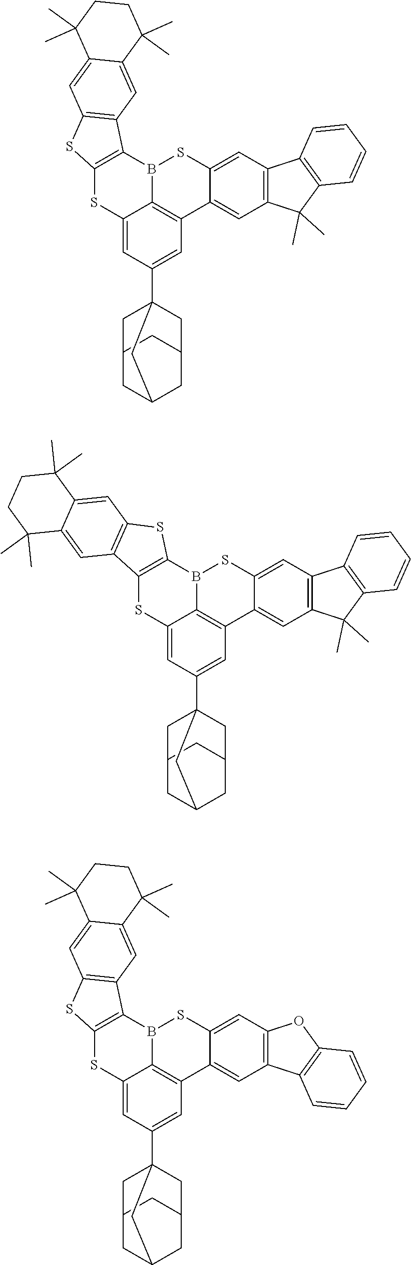 [SMILES: CC1(C)CCC(C)(C)c2cc3c4c(sc3cc21)Sc1cc(C23CC5CC(CC(C5)C2)C3)cc2c1B4Sc1cc3c(cc1-2)C(C)(C)c1ccccc1-3 ; CC1(C)CCC(C)(C)c2cc3c4c(sc3cc21)B1Sc2cc3c(cc2-c2cc(C56CC7CC(CC(C7)C5)C6)cc(c21)S4)C(C)(C)c1ccccc1-3 ; CC1(C)CCC(C)(C)c2cc3c4c(sc3cc21)Sc1cc(C23CC5CC(CC(C5)C2)C3)cc2c1B4Sc1cc3oc4ccccc4c3cc1-2]

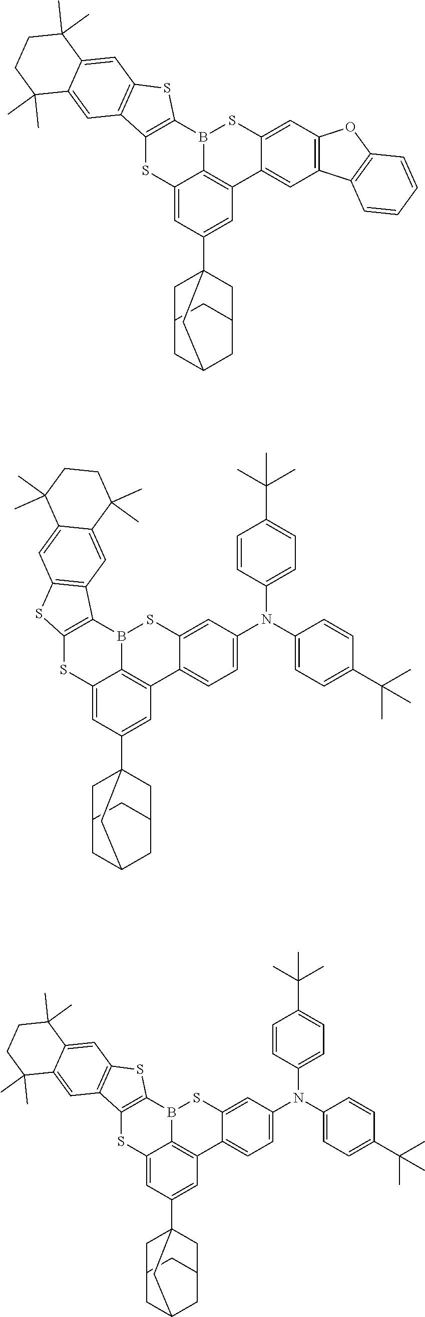

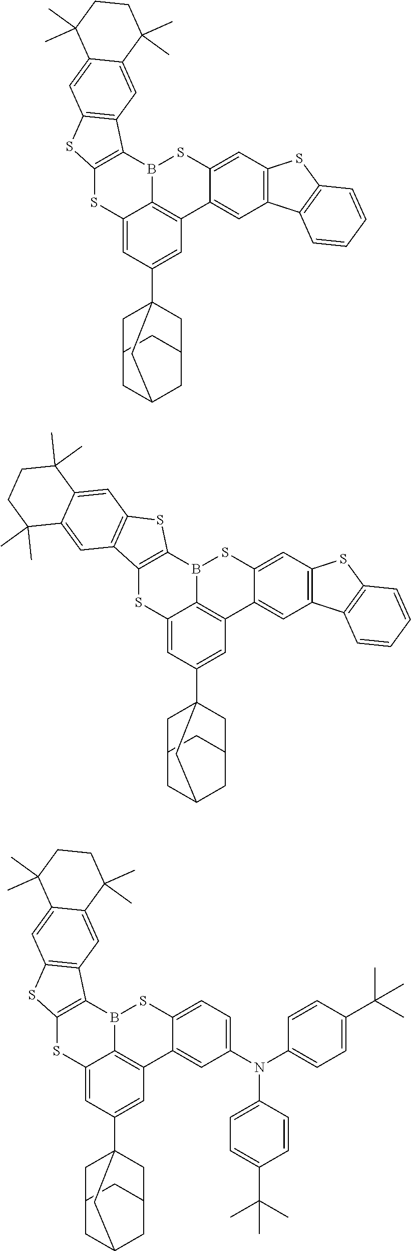

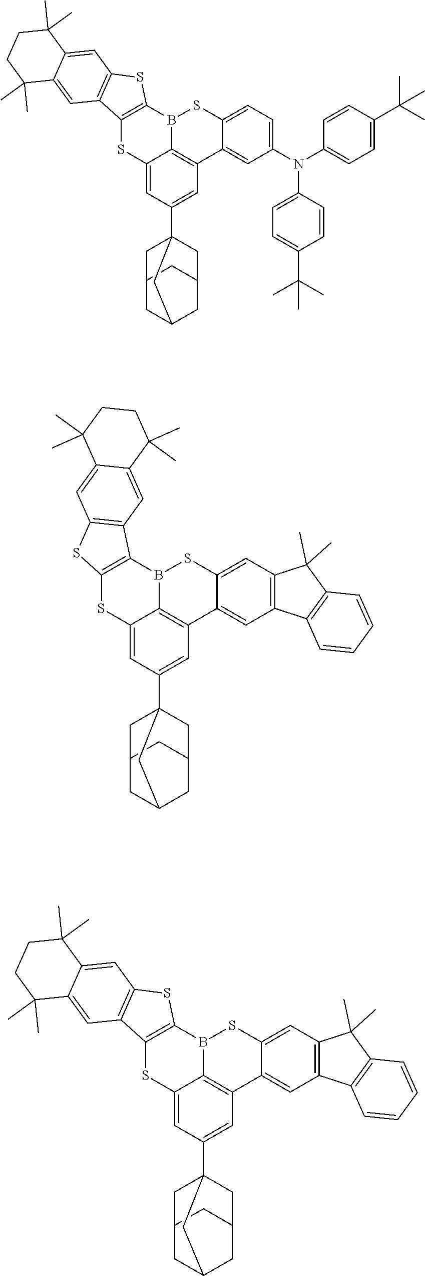

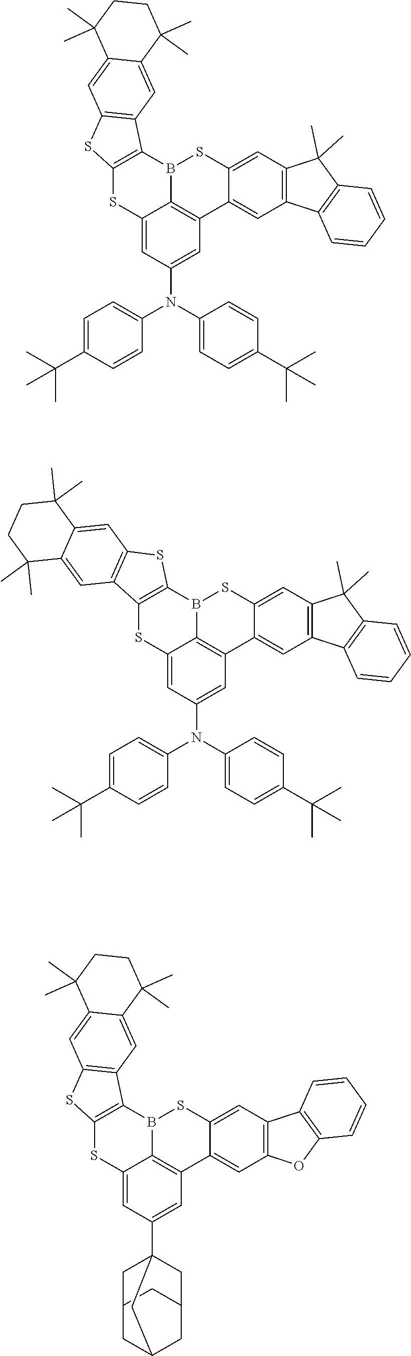 [SMILES: CC(C)(C)c1ccc(N(c2ccc(C(C)(C)C)cc2)c2cc3c4c(c2)-c2cc5c(cc2SB4c2c(sc4cc6c(cc24)C(C)(C)CCC6(C)C)S3)C(C)(C)c2ccccc2-5)cc1 ; CC(C)(C)c1ccc(N(c2ccc(C(C)(C)C)cc2)c2cc3c4c(c2)-c2cc5c(cc2SB4c2sc4cc6c(cc4c2S3)C(C)(C)CCC6(C)C)C(C)(C)c2ccccc2-5)cc1 ; CC1(C)CCC(C)(C)c2cc3c4c(sc3cc21)Sc1cc(C23CC5CC(CC(C5)C2)C3)cc2c1B4Sc1cc3c(cc1-2)oc1ccccc13]

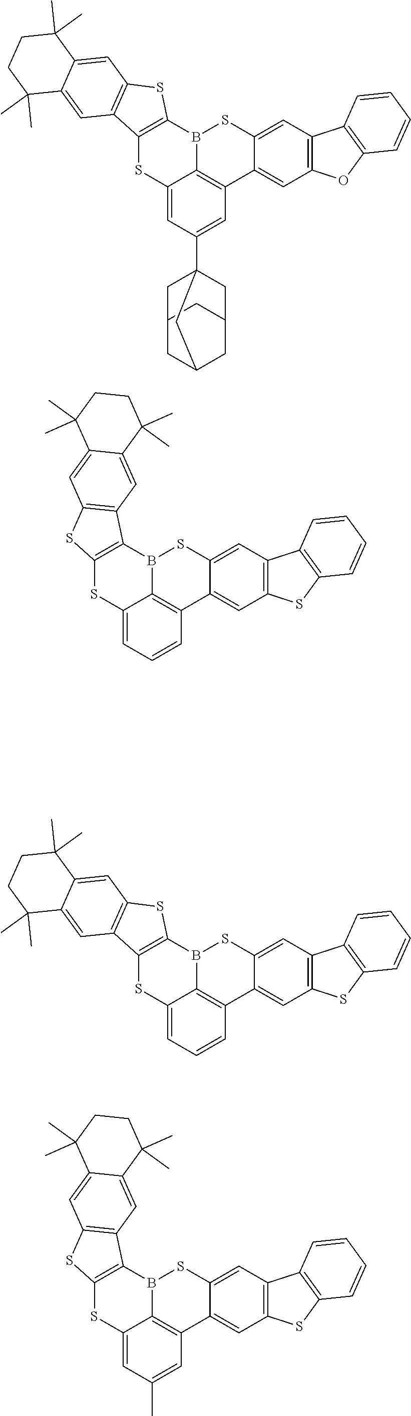 [SMILES: CC1(C)CCC(C)(C)c2cc3c4c(sc3cc21)B1Sc2cc3c(cc2-c2cc(C56CC7CC(CC(C7)C5)C6)cc(c21)S4)oc1ccccc13 ; CC1(C)CCC(C)(C)c2cc3c4c(sc3cc21)Sc1cccc2c1B4Sc1cc3c(cc1-2)sc1ccccc13 ; CC1(C)CCC(C)(C)c2cc3c4c(sc3cc21)B1Sc2cc3c(cc2-c2cccc(c21)S4)sc1ccccc13 ; Cc1cc2c3c(c1)-c1cc4sc5ccccc5c4cc1SB3c1c(sc3cc4c(cc13)C(C)(C)CCC4(C)C)S2]

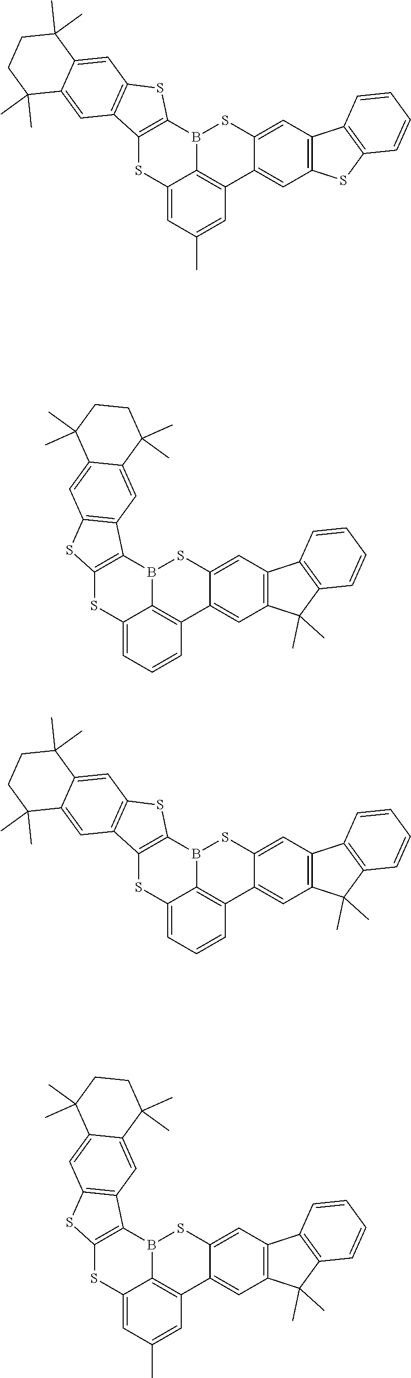 [SMILES: Cc1cc2c3c(c1)-c1cc4sc5ccccc5c4cc1SB3c1sc3cc4c(cc3c1S2)C(C)(C)CCC4(C)C ; CC1(C)CCC(C)(C)c2cc3c4c(sc3cc21)Sc1cccc2c1B4Sc1cc3c(cc1-2)C(C)(C)c1ccccc1-3 ; CC1(C)CCC(C)(C)c2cc3c4c(sc3cc21)B1Sc2cc3c(cc2-c2cccc(c21)S4)C(C)(C)c1ccccc1-3 ; Cc1cc2c3c(c1)-c1cc4c(cc1SB3c1c(sc3cc5c(cc13)C(C)(C)CCC5(C)C)S2)-c1ccccc1C4(C)C]

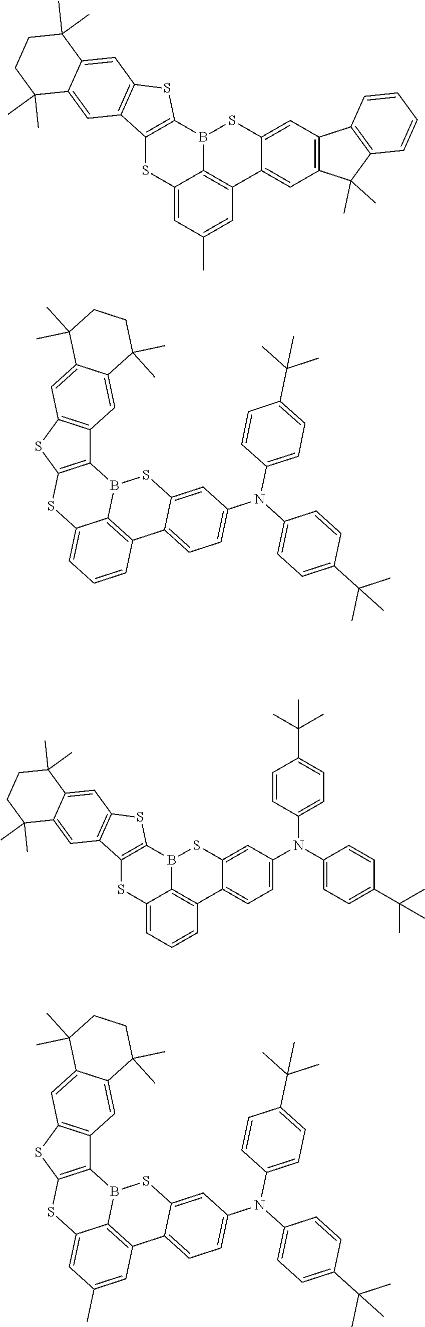

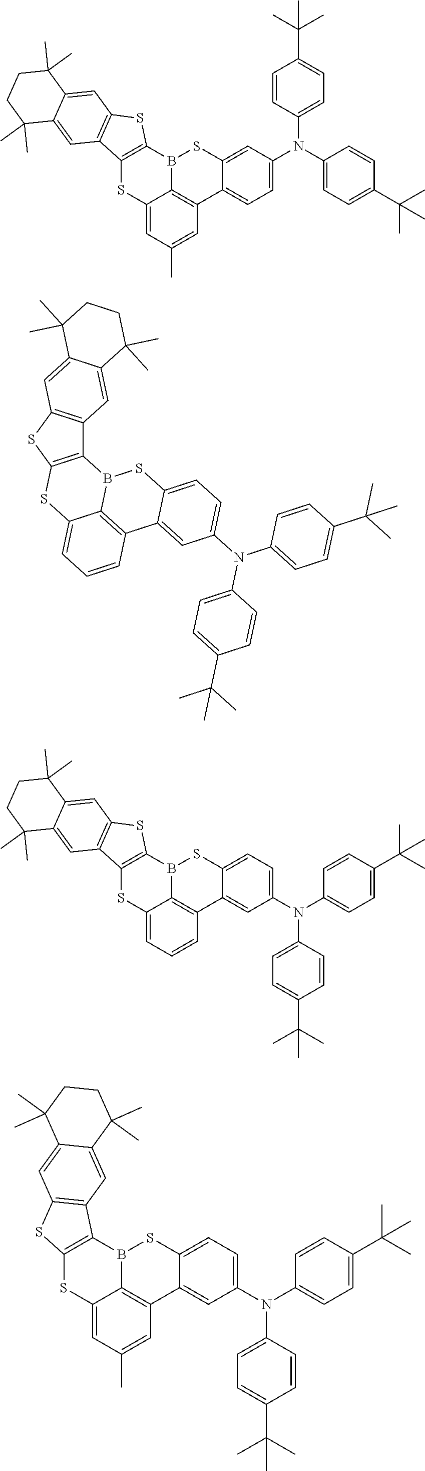

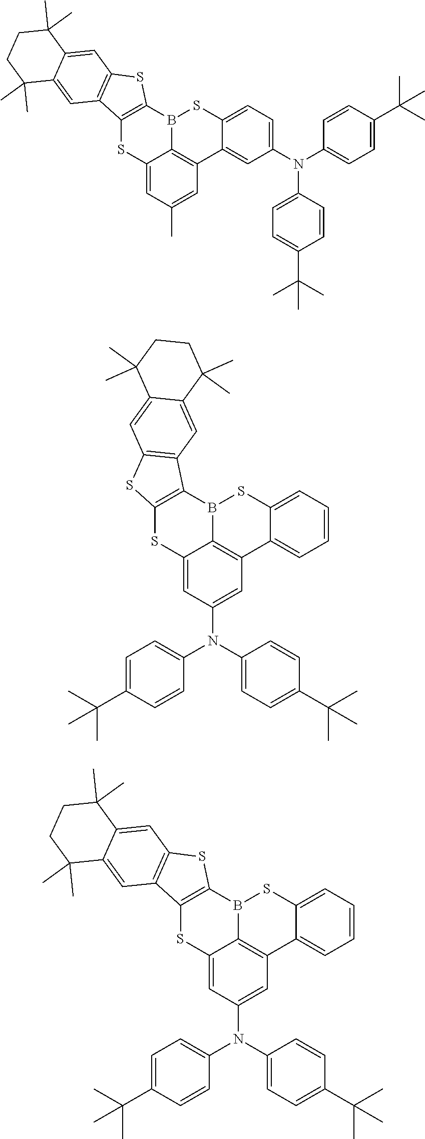

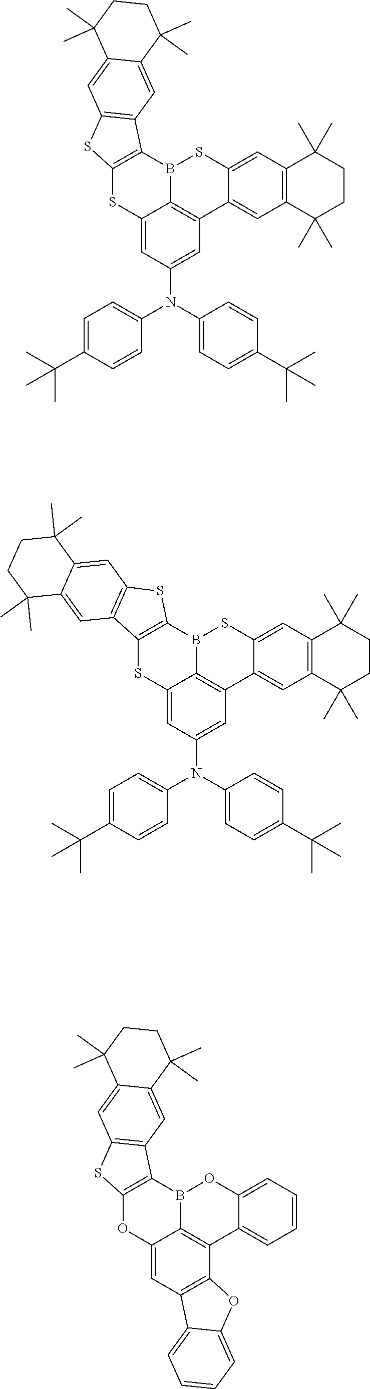 [SMILES: CC(C)(C)c1ccc(N(c2ccc(C(C)(C)C)cc2)c2cc3c4c(c2)-c2cc5c(cc2SB4c2c(sc4cc6c(cc24)C(C)(C)CCC6(C)C)S3)C(C)(C)CCC5(C)C)cc1 ; CC(C)(C)c1ccc(N(c2ccc(C(C)(C)C)cc2)c2cc3c4c(c2)-c2cc5c(cc2SB4c2sc4cc6c(cc4c2S3)C(C)(C)CCC6(C)C)C(C)(C)CCC5(C)C)cc1 ; CC1(C)CCC(C)(C)c2cc3c4c(sc3cc21)Oc1cc2c(oc3ccccc32)c2c1B4Oc1ccccc1-2]

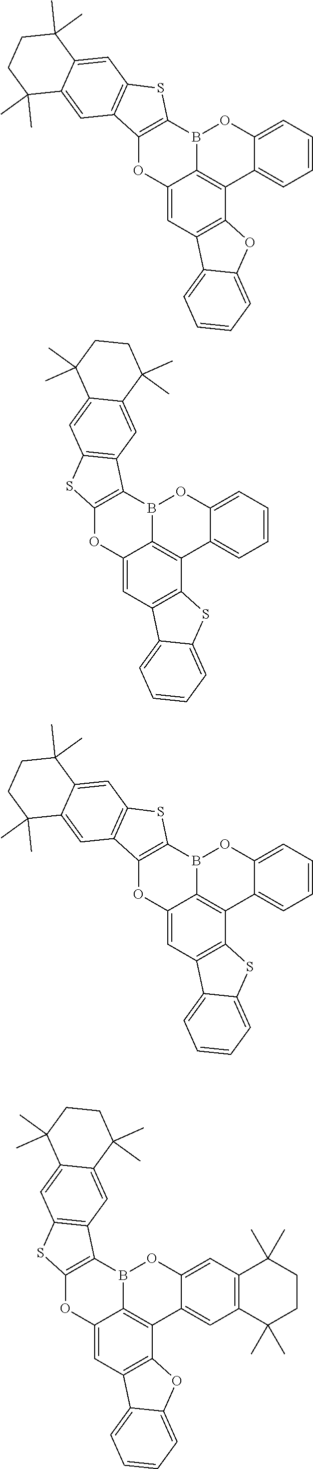

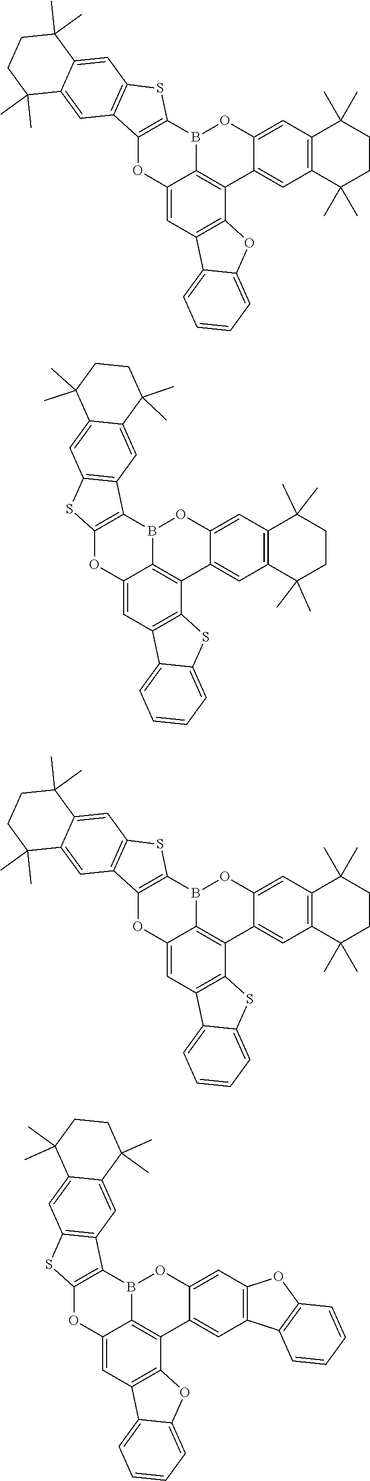 [SMILES: CC1(C)CCC(C)(C)c2cc3c(cc21)OB1c2sc4cc5c(cc4c2Oc2cc4c(oc6ccccc64)c-3c21)C(C)(C)CCC5(C)C ; CC1(C)CCC(C)(C)c2cc3c(cc21)OB1c2c(cc4c(sc5ccccc54)c2-3)Oc2sc3cc4c(cc3c21)C(C)(C)CCC4(C)C ; CC1(C)CCC(C)(C)c2cc3c(cc21)OB1c2sc4cc5c(cc4c2Oc2cc4c(sc6ccccc64)c-3c21)C(C)(C)CCC5(C)C ; CC1(C)CCC(C)(C)c2cc3c4c(sc3cc21)Oc1cc2c(oc3ccccc32)c2c1B4Oc1cc3oc4ccccc4c3cc1-2]

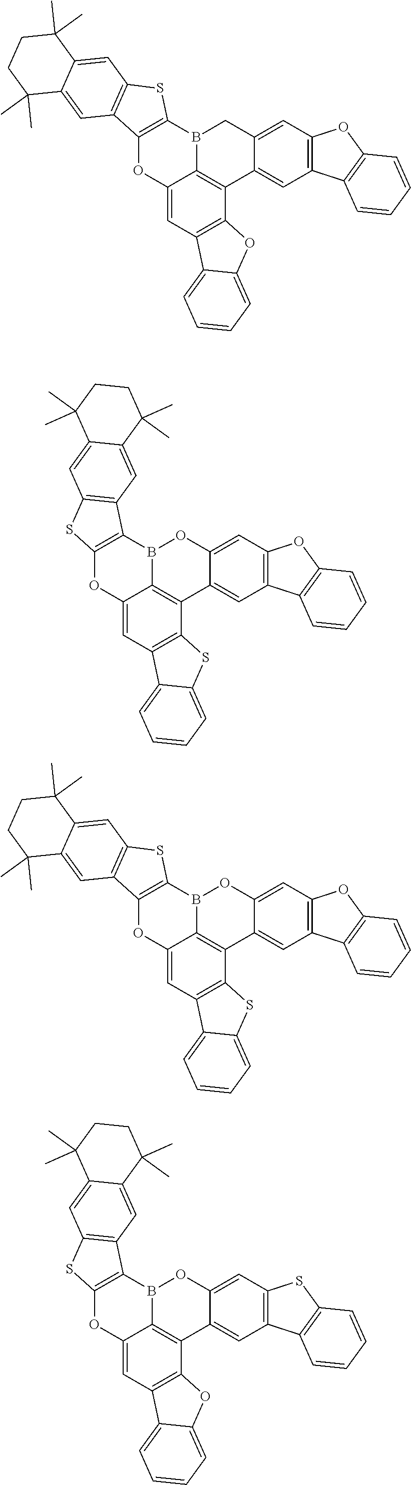 [SMILES: CC1(C)CCC(C)(C)c2cc3c4c(sc3cc21)B1Cc2cc3oc5ccccc5c3cc2-c2c1c(cc1c2oc2ccccc21)O4 ; CC1(C)CCC(C)(C)c2cc3c4c(sc3cc21)Oc1cc2c(sc3ccccc32)c2c1B4Oc1cc3oc4ccccc4c3cc1-2 ; CC1(C)CCC(C)(C)c2cc3c4c(sc3cc21)B1Oc2cc3oc5ccccc5c3cc2-c2c1c(cc1c2sc2ccccc21)O4 ; CC1(C)CCC(C)(C)c2cc3c4c(sc3cc21)Oc1cc2c(oc3ccccc32)c2c1B4Oc1cc3sc4ccccc4c3cc1-2]

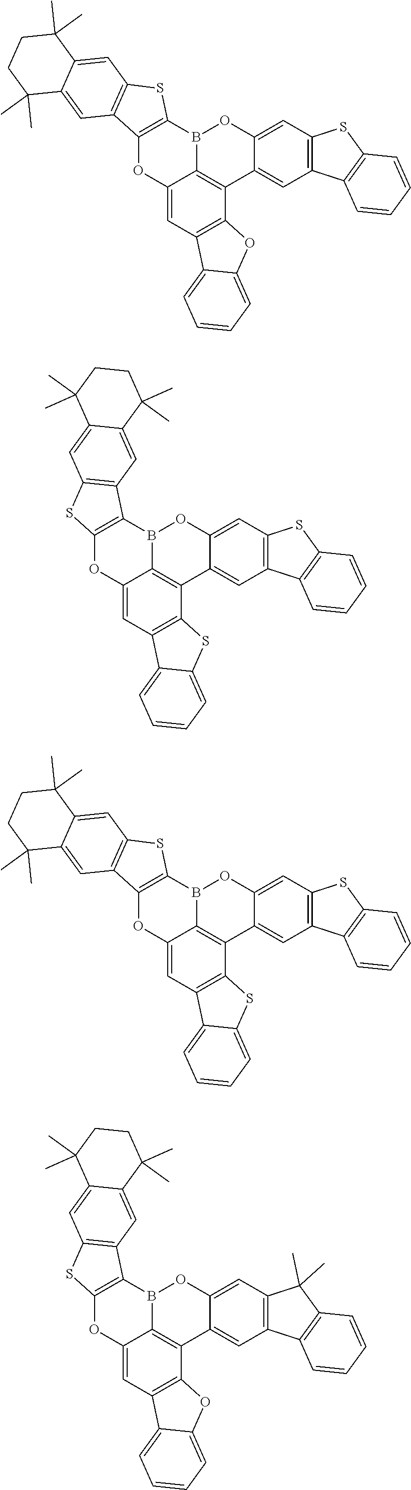 [SMILES: CC1(C)CCC(C)(C)c2cc3c4c(sc3cc21)B1Oc2cc3sc5ccccc5c3cc2-c2c1c(cc1c2oc2ccccc21)O4 ; CC1(C)CCC(C)(C)c2cc3c4c(sc3cc21)Oc1cc2c(sc3ccccc32)c2c1B4Oc1cc3sc4ccccc4c3cc1-2 ; CC1(C)CCC(C)(C)c2cc3c4c(sc3cc21)B1Oc2cc3sc5ccccc5c3cc2-c2c1c(cc1c2sc2ccccc21)O4 ; CC1(C)CCC(C)(C)c2cc3c4c(sc3cc21)Oc1cc2c(oc3ccccc32)c2c1B4Oc1cc3c(cc1-2)-c1ccccc1C3(C)C]

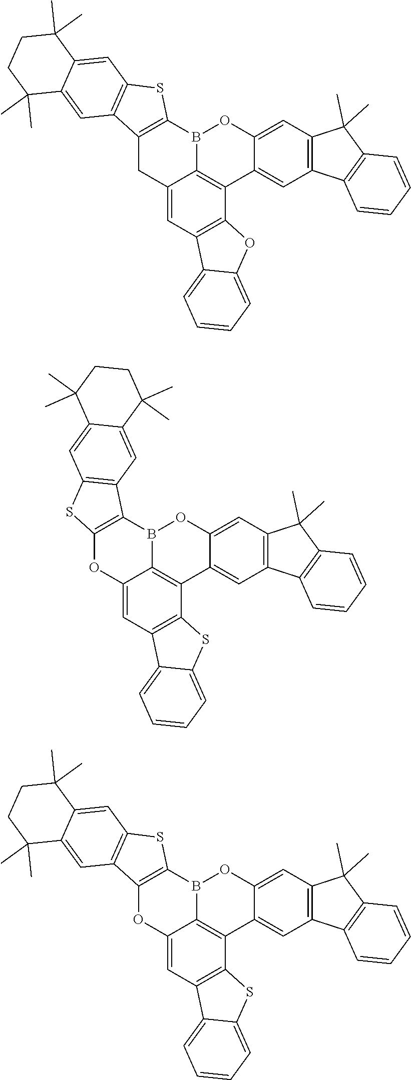

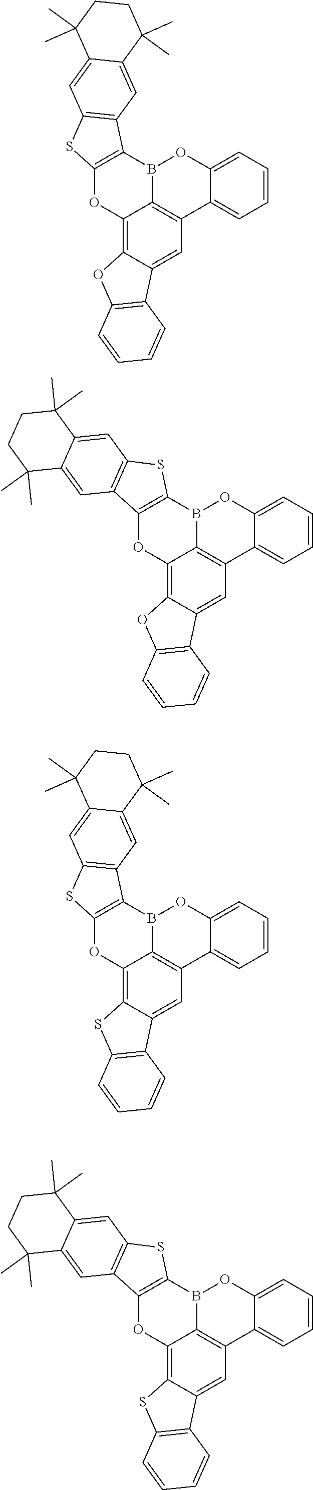

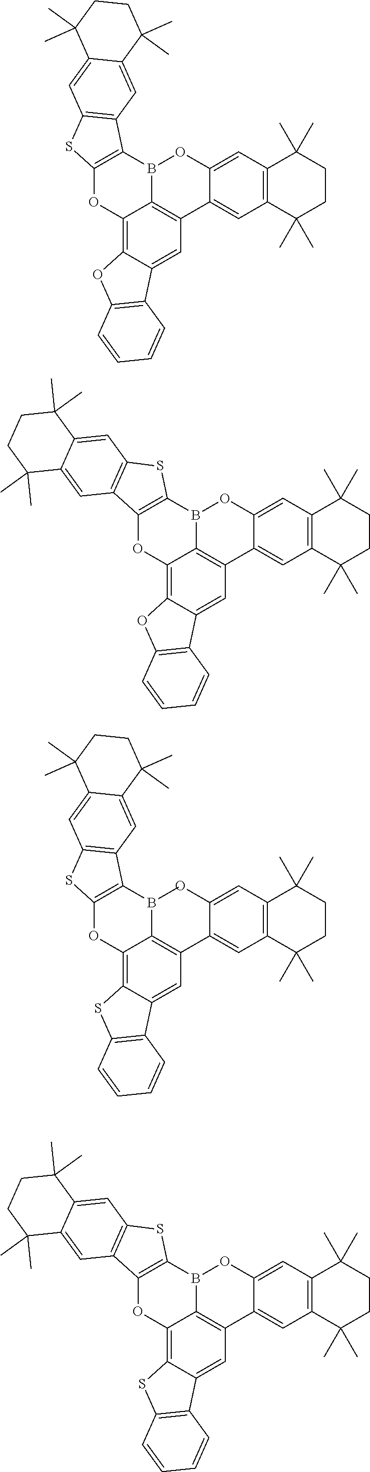

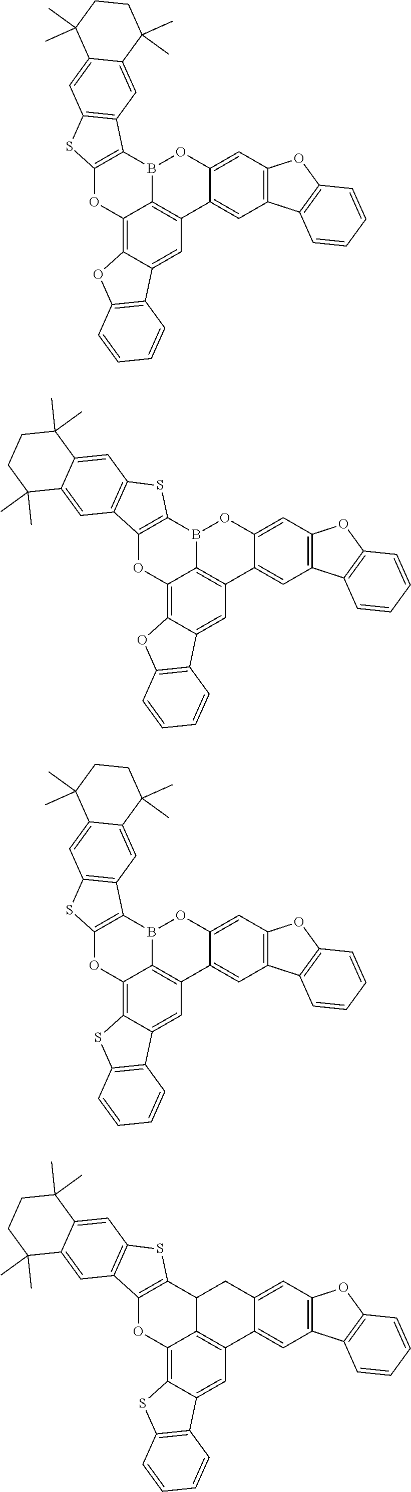 [SMILES: CC1(C)CCC(C)(C)c2cc3c4c(sc3cc21)Oc1c2c(cc3c1oc1ccccc13)-c1cc3c(cc1OB24)oc1ccccc13 ; CC1(C)CCC(C)(C)c2cc3c4c(sc3cc21)B1Oc2cc3oc5ccccc5c3cc2-c2cc3c(oc5ccccc53)c(c21)O4 ; CC1(C)CCC(C)(C)c2cc3c4c(sc3cc21)Oc1c2c(cc3c1sc1ccccc13)-c1cc3c(cc1OB24)oc1ccccc13 ; CC1(C)CCC(C)(C)c2cc3c4c(sc3cc21)C1Cc2cc3oc5ccccc5c3cc2-c2cc3c(sc5ccccc53)c(c21)O4]

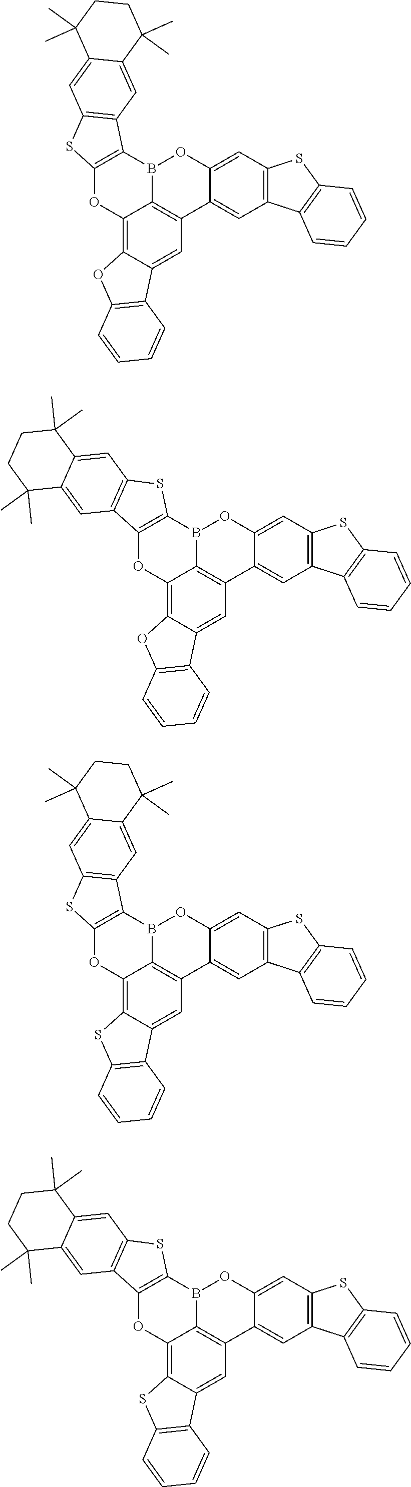 [SMILES: CC1(C)CCC(C)(C)c2cc3c4c(sc3cc21)Oc1c2c(cc3c1oc1ccccc13)-c1cc3c(cc1OB24)sc1ccccc13 ; CC1(C)CCC(C)(C)c2cc3c4c(sc3cc21)B1Oc2cc3sc5ccccc5c3cc2-c2cc3c(oc5ccccc53)c(c21)O4 ; CC1(C)CCC(C)(C)c2cc3c4c(sc3cc21)Oc1c2c(cc3c1sc1ccccc13)-c1cc3c(cc1OB24)sc1ccccc13 ; CC1(C)CCC(C)(C)c2cc3c4c(sc3cc21)B1Oc2cc3sc5ccccc5c3cc2-c2cc3c(sc5ccccc53)c(c21)O4]

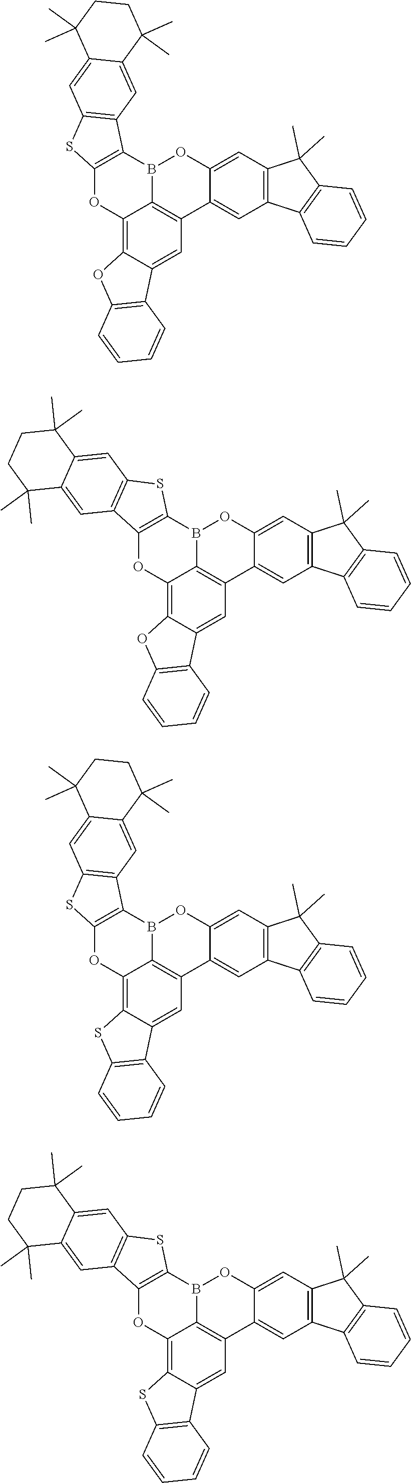 [SMILES: CC1(C)CCC(C)(C)c2cc3c4c(sc3cc21)Oc1c2c(cc3c1oc1ccccc13)-c1cc3c(cc1OB24)C(C)(C)c1ccccc1-3 ; CC1(C)CCC(C)(C)c2cc3c4c(sc3cc21)B1Oc2cc3c(cc2-c2cc5c(oc6ccccc65)c(c21)O4)-c1ccccc1C3(C)C ; CC1(C)CCC(C)(C)c2cc3c4c(sc3cc21)Oc1c2c(cc3c1sc1ccccc13)-c1cc3c(cc1OB24)C(C)(C)c1ccccc1-3 ; CC1(C)CCC(C)(C)c2cc3c4c(sc3cc21)B1Oc2cc3c(cc2-c2cc5c(sc6ccccc65)c(c21)O4)-c1ccccc1C3(C)C]

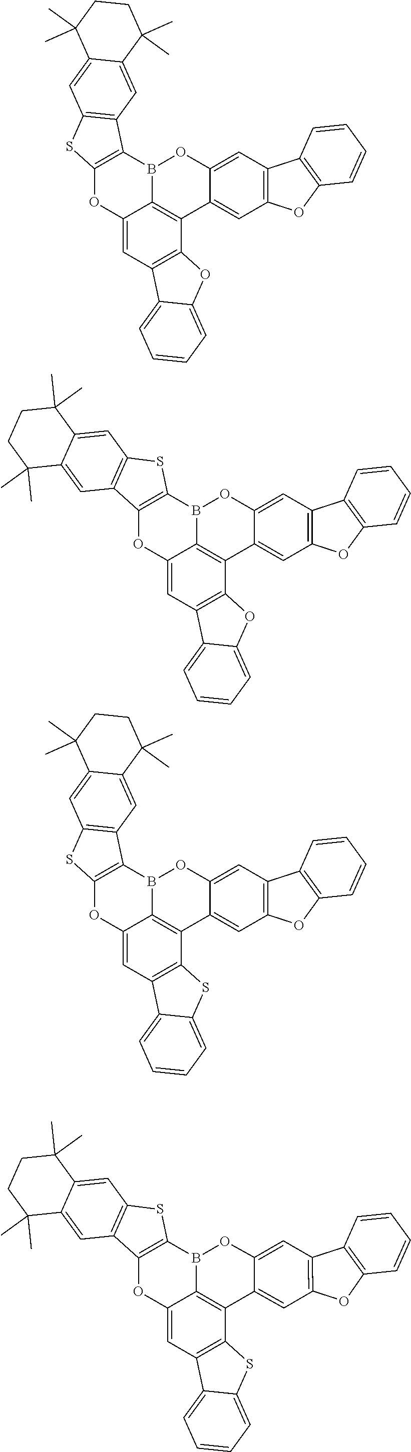

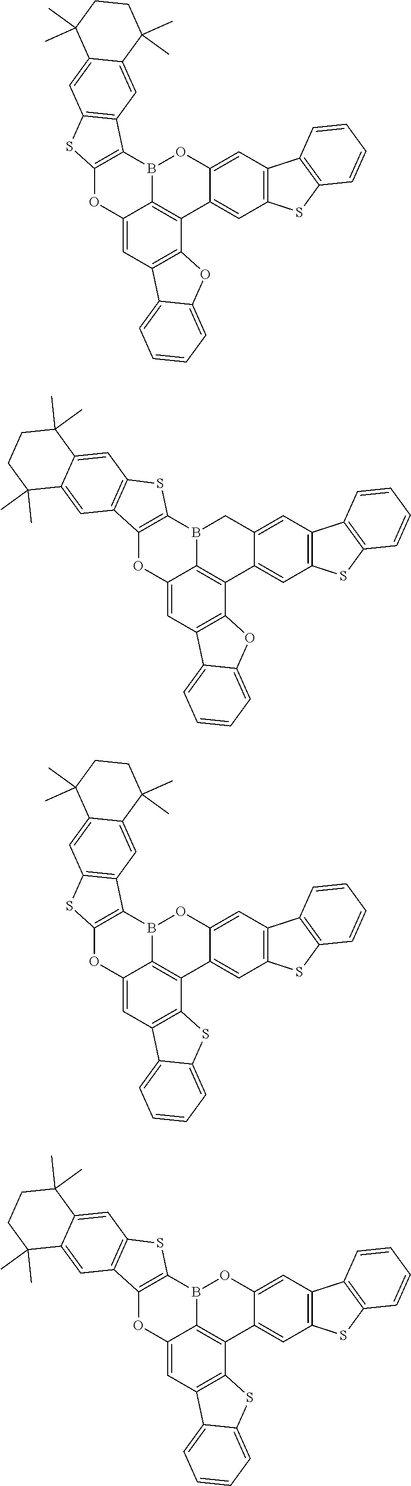

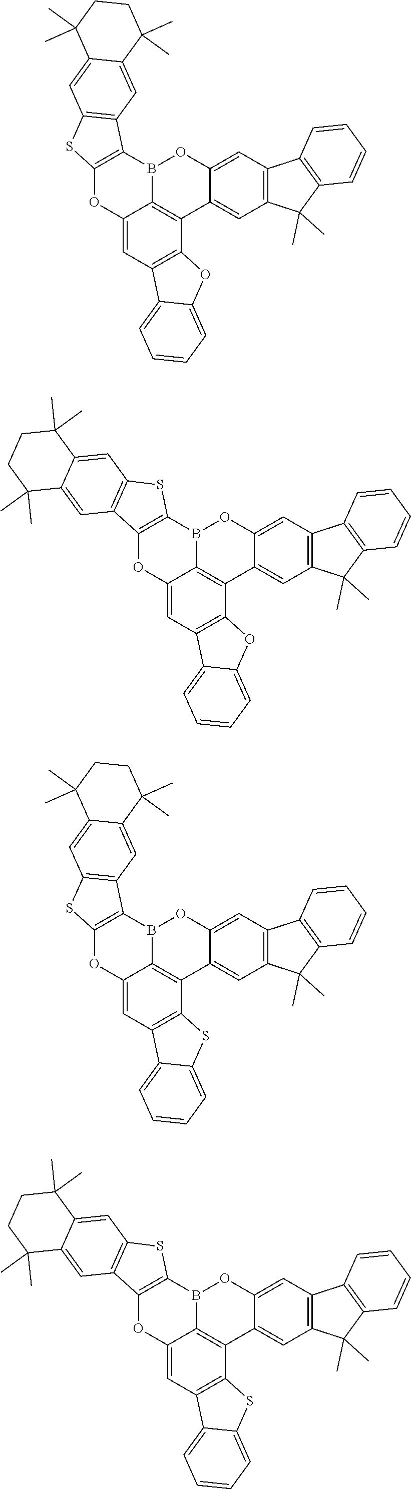 [SMILES: CC1(C)CCC(C)(C)c2cc3c4c(sc3cc21)Oc1cc2c(oc3ccccc32)c2c1B4Oc1cc3c(cc1-2)C(C)(C)c1ccccc1-3 ; CC1(C)CCC(C)(C)c2cc3c4c(sc3cc21)B1Oc2cc3c(cc2-c2c1c(cc1c2oc2ccccc21)O4)C(C)(C)c1ccccc1-3 ; CC1(C)CCC(C)(C)c2cc3c4c(sc3cc21)Oc1cc2c(sc3ccccc32)c2c1B4Oc1cc3c(cc1-2)C(C)(C)c1ccccc1-3 ; CC1(C)CCC(C)(C)c2cc3c4c(sc3cc21)B1Oc2cc3c(cc2-c2c1c(cc1c2sc2ccccc21)O4)C(C)(C)c1ccccc1-3]

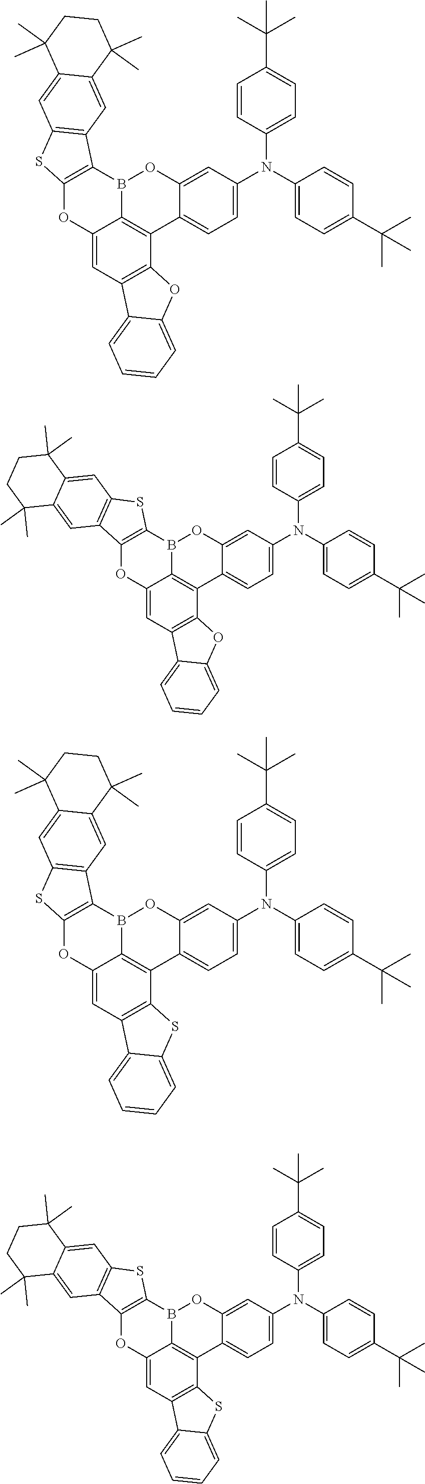

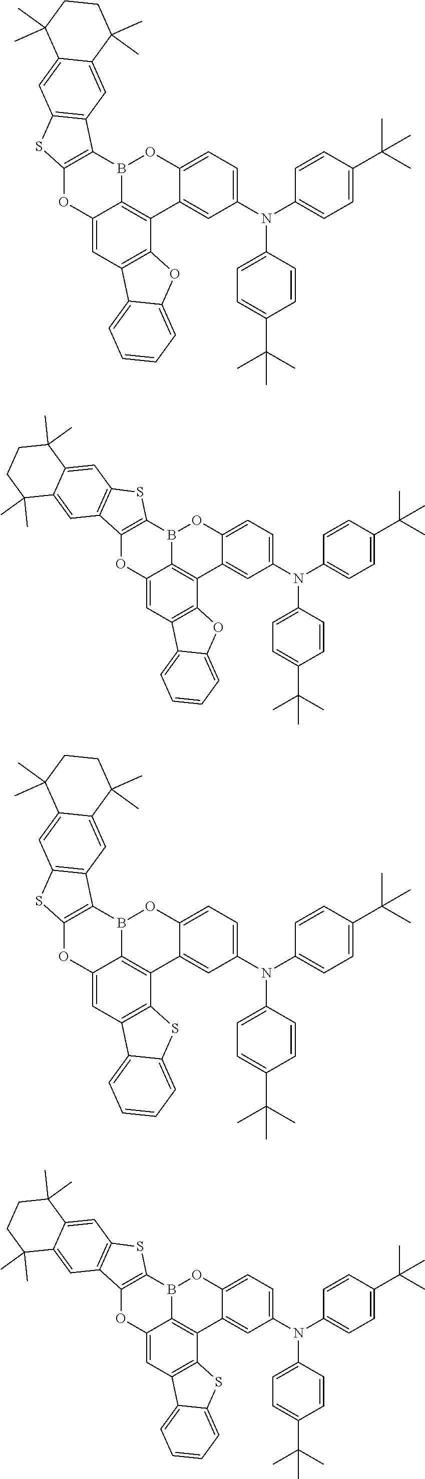

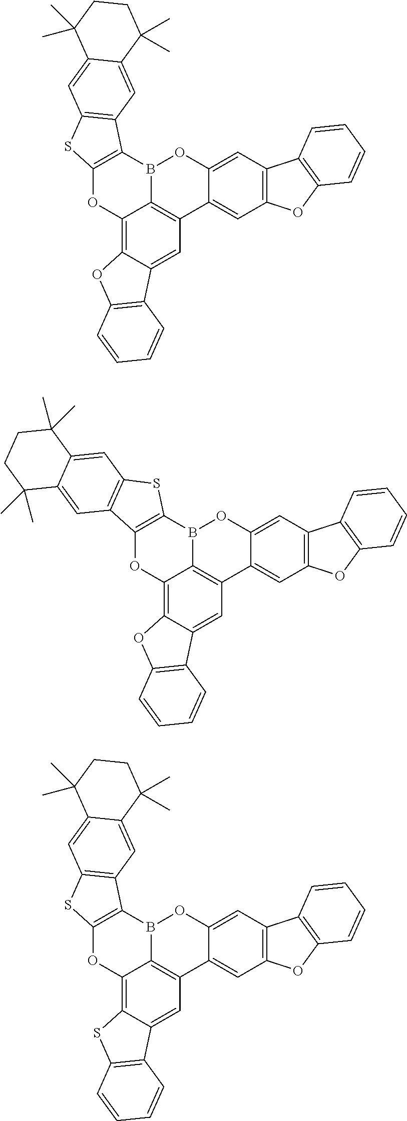 [SMILES: CC1(C)CCC(C)(C)c2cc3c4c(sc3cc21)Oc1c2c(cc3c1oc1ccccc13)-c1cc3oc5ccccc5c3cc1OB24 ; CC1(C)CCC(C)(C)c2cc3c4c(sc3cc21)B1Oc2cc3c(cc2-c2cc5c(oc6ccccc65)c(c21)O4)oc1ccccc13 ; CC1(C)CCC(C)(C)c2cc3c4c(sc3cc21)Oc1c2c(cc3c1sc1ccccc13)-c1cc3oc5ccccc5c3cc1OB24]

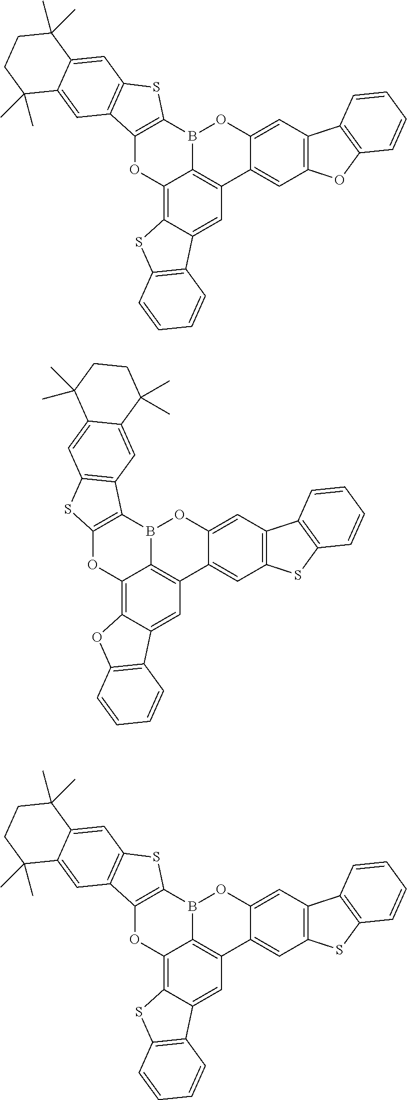 [SMILES: CC1(C)CCC(C)(C)c2cc3c4c(sc3cc21)B1Oc2cc3c(cc2-c2cc5c(sc6ccccc65)c(c21)O4)oc1ccccc13 ; CC1(C)CCC(C)(C)c2cc3c4c(sc3cc21)Oc1c2c(cc3c1oc1ccccc13)-c1cc3sc5ccccc5c3cc1OB24 ; CC1(C)CCC(C)(C)c2cc3c4c(sc3cc21)B1Oc2cc3c(cc2-c2cc5c(sc6ccccc65)c(c21)O4)sc1ccccc13]

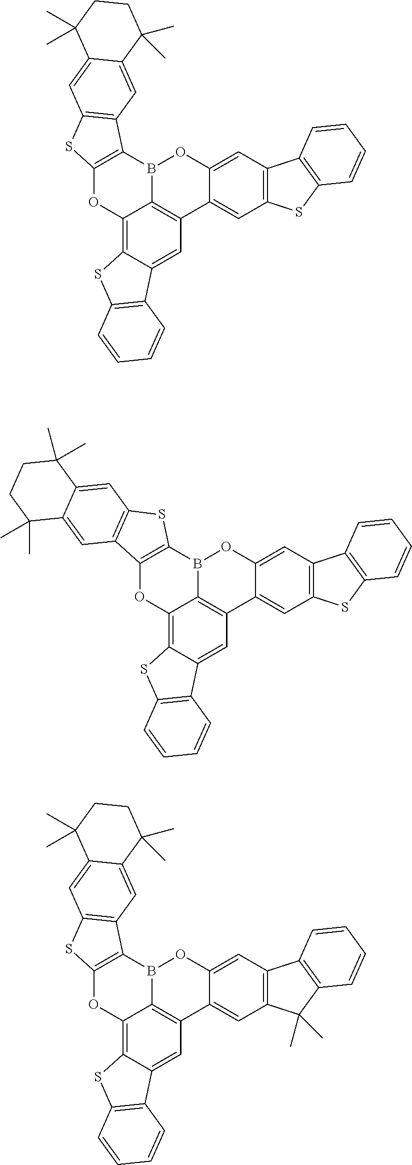 [SMILES: CC1(C)CCC(C)(C)c2cc3c4c(sc3cc21)Oc1c2c(cc3c1sc1ccccc13)-c1cc3sc5ccccc5c3cc1OB24 ; CC1(C)CCC(C)(C)c2cc3c4c(sc3cc21)B1Oc2cc3c(cc2-c2cc5c(sc6ccccc65)c(c21)O4)sc1ccccc13 ; CC1(C)CCC(C)(C)c2cc3c4c(sc3cc21)Oc1c2c(cc3c1sc1ccccc13)-c1cc3c(cc1OB24)-c1ccccc1C3(C)C]

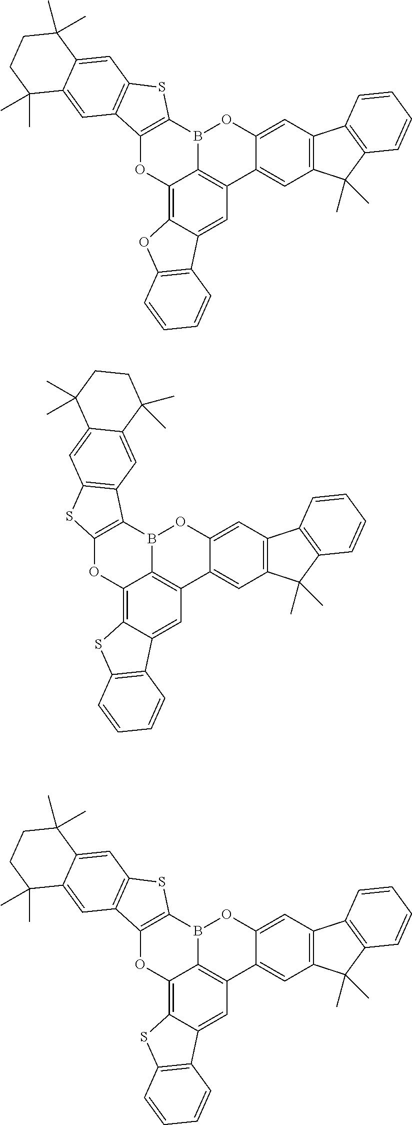 [SMILES: CC1(C)CCC(C)(C)c2cc3c4c(sc3cc21)B1Oc2cc3c(cc2-c2cc5c(oc6ccccc65)c(c21)O4)C(C)(C)c1ccccc1-3 ; CC1(C)CCC(C)(C)c2cc3c4c(sc3cc21)Oc1c2c(cc3c1sc1ccccc13)-c1cc3c(cc1OB24)-c1ccccc1C3(C)C ; CC1(C)CCC(C)(C)c2cc3c4c(sc3cc21)B1Oc2cc3c(cc2-c2cc5c(sc6ccccc65)c(c21)O4)C(C)(C)c1ccccc1-3]

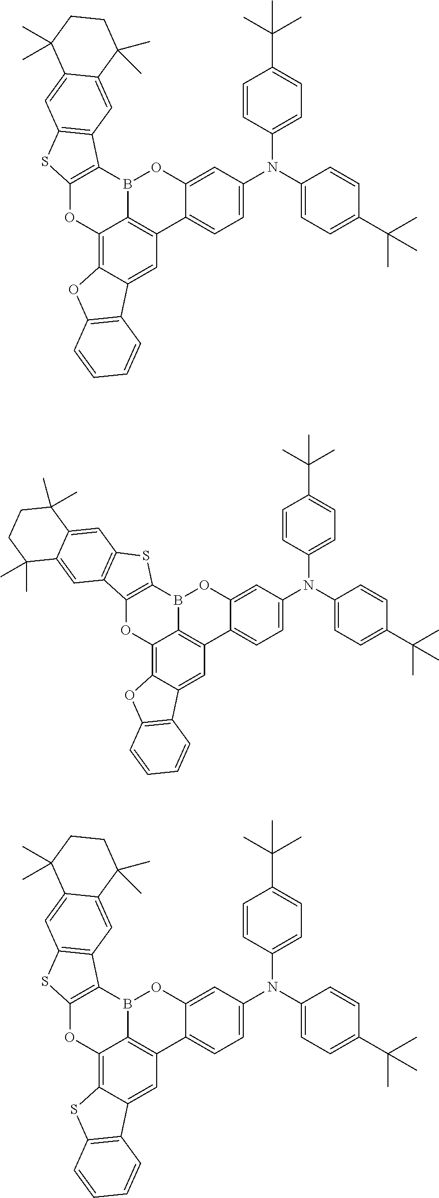

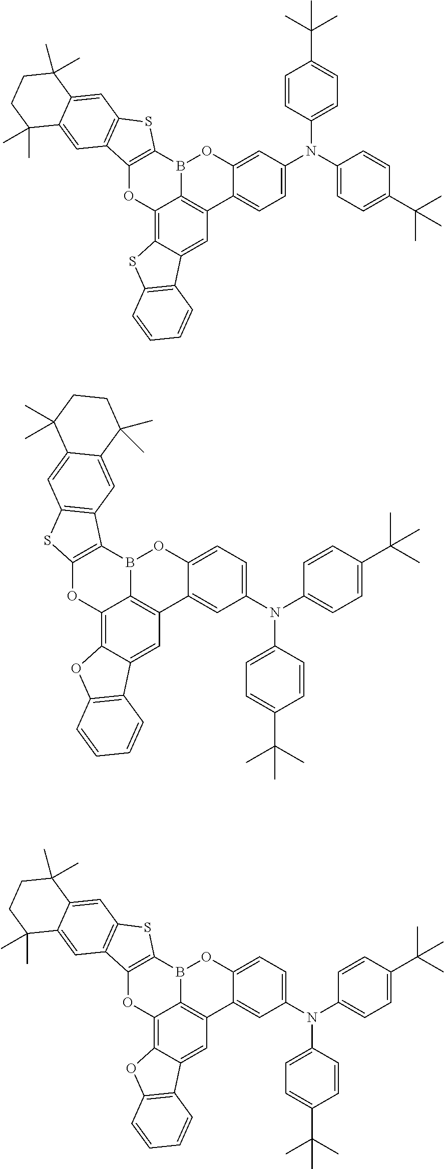

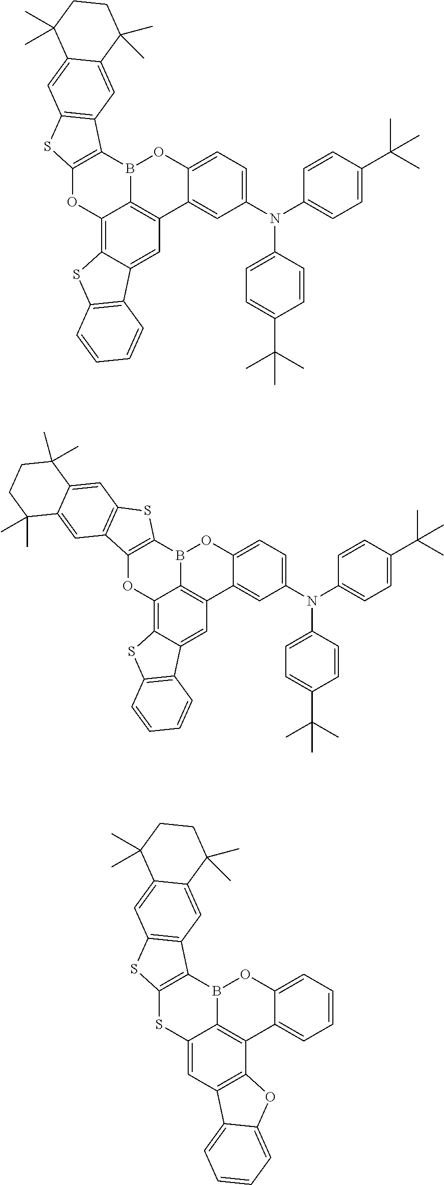

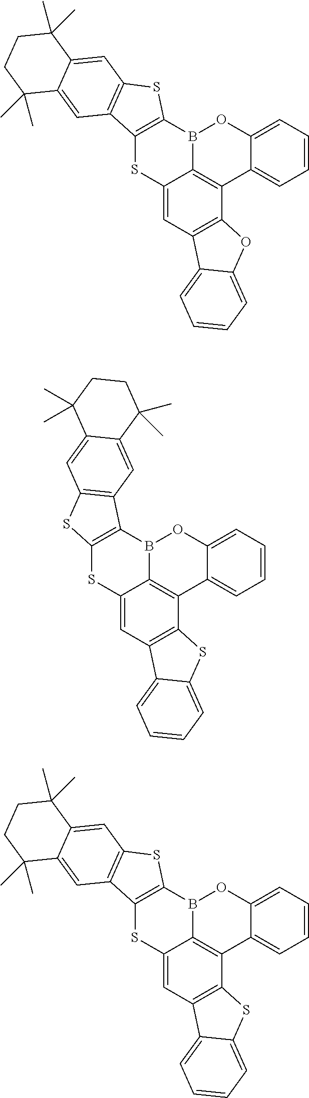 [SMILES: CC1(C)CCC(C)(C)c2cc3c4c(sc3cc21)B1Oc2ccccc2-c2c1c(cc1c2oc2ccccc21)S4 ; CC1(C)CCC(C)(C)c2cc3c4c(sc3cc21)Sc1cc2c(sc3ccccc32)c2c1B4Oc1ccccc1-2 ; CC1(C)CCC(C)(C)c2cc3c4c(sc3cc21)B1Oc2ccccc2-c2c1c(cc1c2sc2ccccc21)S4]

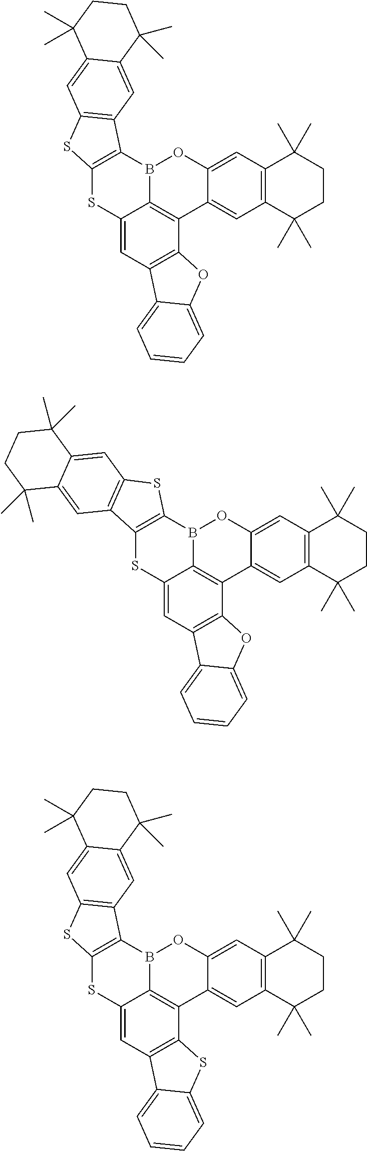 [SMILES: CC1(C)CCC(C)(C)c2cc3c(cc21)OB1c2c(cc4c(oc5ccccc54)c2-3)Sc2sc3cc4c(cc3c21)C(C)(C)CCC4(C)C ; CC1(C)CCC(C)(C)c2cc3c(cc21)OB1c2sc4cc5c(cc4c2Sc2cc4c(oc6ccccc64)c-3c21)C(C)(C)CCC5(C)C ; CC1(C)CCC(C)(C)c2cc3c(cc21)OB1c2c(cc4c(sc5ccccc54)c2-3)Sc2sc3cc4c(cc3c21)C(C)(C)CCC4(C)C]

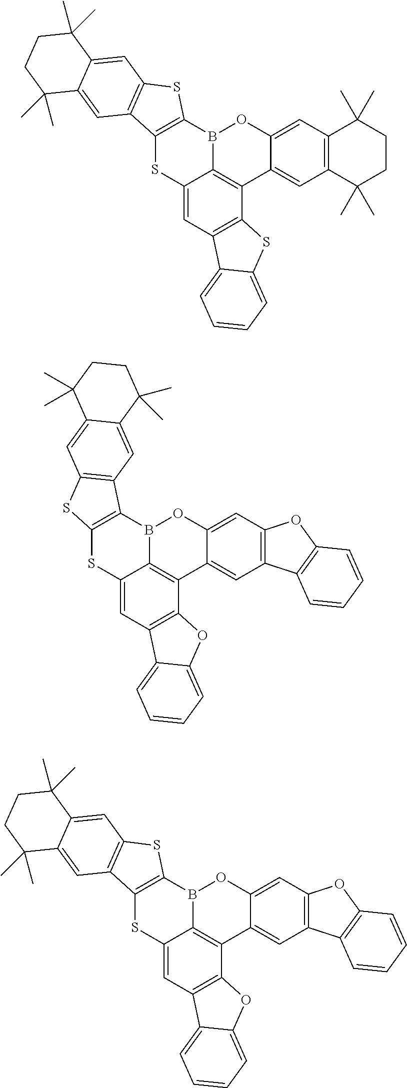 [SMILES: CC1(C)CCC(C)(C)c2cc3c(cc21)OB1c2sc4cc5c(cc4c2Sc2cc4c(sc6ccccc64)c-3c21)C(C)(C)CCC5(C)C ; CC1(C)CCC(C)(C)c2cc3c4c(sc3cc21)Sc1cc2c(oc3ccccc32)c2c1B4Oc1cc3oc4ccccc4c3cc1-2 ; CC1(C)CCC(C)(C)c2cc3c4c(sc3cc21)B1Oc2cc3oc5ccccc5c3cc2-c2c1c(cc1c2oc2ccccc21)S4]

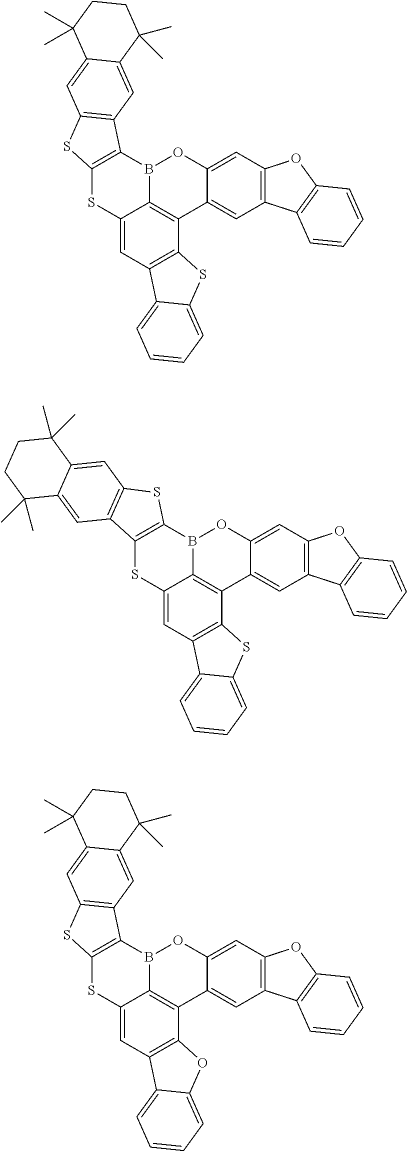 [SMILES: CC1(C)CCC(C)(C)c2cc3c4c(sc3cc21)Sc1cc2c(sc3ccccc32)c2c1B4Oc1cc3oc4ccccc4c3cc1-2 ; CC1(C)CCC(C)(C)c2cc3c4c(sc3cc21)B1Oc2cc3oc5ccccc5c3cc2-c2c1c(cc1c2sc2ccccc21)S4 ; CC1(C)CCC(C)(C)c2cc3c4c(sc3cc21)Sc1cc2c(oc3ccccc32)c2c1B4Oc1cc3oc4ccccc4c3cc1-2]

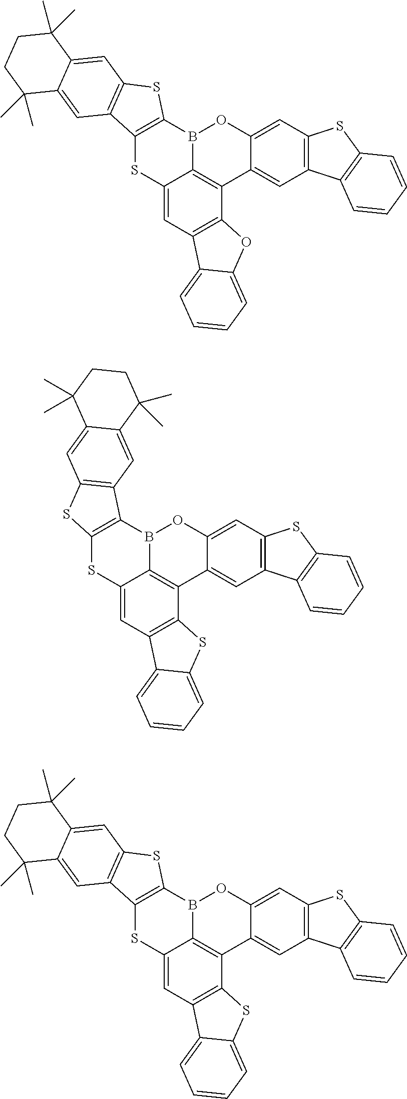 [SMILES: CC1(C)CCC(C)(C)c2cc3c4c(sc3cc21)B1Oc2cc3sc5ccccc5c3cc2-c2c1c(cc1c2oc2ccccc21)S4 ; CC1(C)CCC(C)(C)c2cc3c4c(sc3cc21)Sc1cc2c(sc3ccccc32)c2c1B4Oc1cc3sc4ccccc4c3cc1-2 ; CC1(C)CCC(C)(C)c2cc3c4c(sc3cc21)B1Oc2cc3sc5ccccc5c3cc2-c2c1c(cc1c2sc2ccccc21)S4]

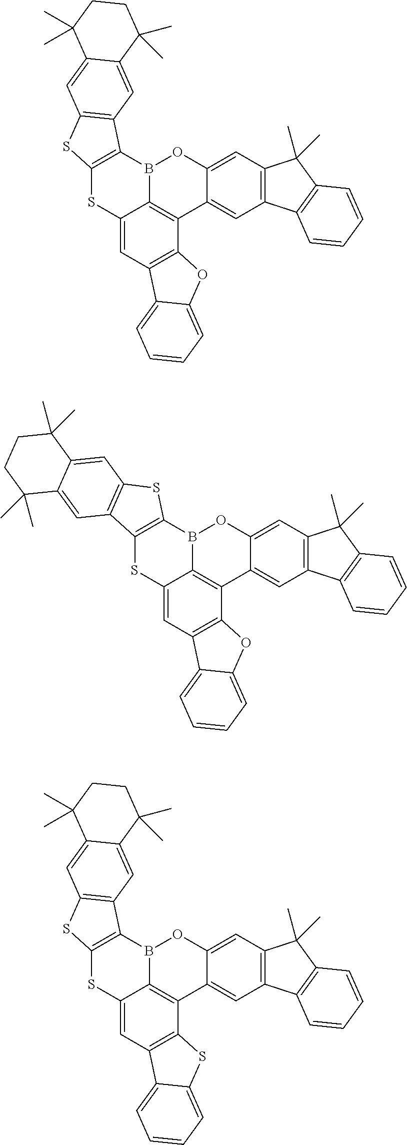 [SMILES: CC1(C)CCC(C)(C)c2cc3c4c(sc3cc21)Sc1cc2c(oc3ccccc32)c2c1B4Oc1cc3c(cc1-2)-c1ccccc1C3(C)C ; CC1(C)CCC(C)(C)c2cc3c4c(sc3cc21)B1Oc2cc3c(cc2-c2c1c(cc1c2oc2ccccc21)S4)-c1ccccc1C3(C)C ; CC1(C)CCC(C)(C)c2cc3c4c(sc3cc21)Sc1cc2c(sc3ccccc32)c2c1B4Oc1cc3c(cc1-2)-c1ccccc1C3(C)C]

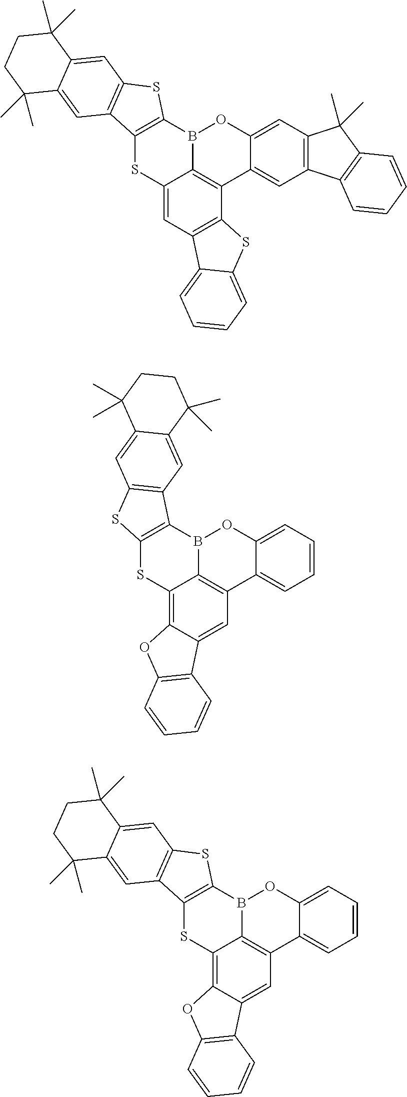 [SMILES: CC1(C)CCC(C)(C)c2cc3c4c(sc3cc21)B1Oc2cc3c(cc2-c2c1c(cc1c2sc2ccccc21)S4)-c1ccccc1C3(C)C ; CC1(C)CCC(C)(C)c2cc3c4c(sc3cc21)Sc1c2c(cc3c1oc1ccccc13)-c1ccccc1OB24 ; CC1(C)CCC(C)(C)c2cc3c4c(sc3cc21)B1Oc2ccccc2-c2cc3c(oc5ccccc53)c(c21)S4]

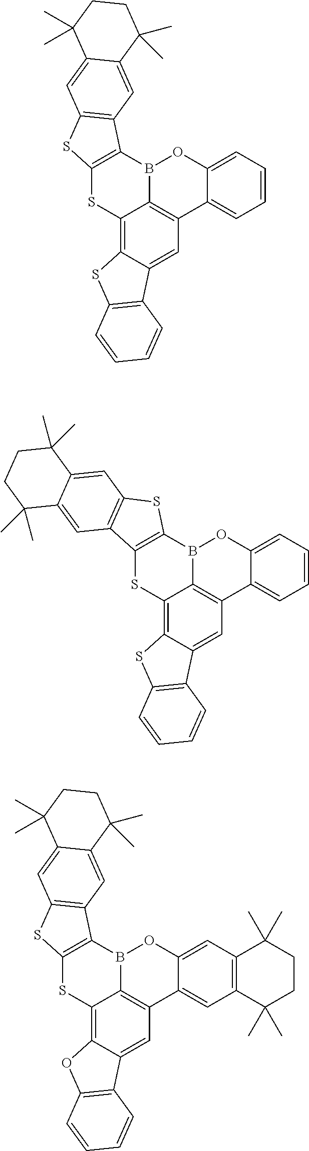 [SMILES: CC1(C)CCC(C)(C)c2cc3c4c(sc3cc21)Sc1c2c(cc3c1sc1ccccc13)-c1ccccc1OB24 ; CC1(C)CCC(C)(C)c2cc3c4c(sc3cc21)B1Oc2ccccc2-c2cc3c(sc5ccccc53)c(c21)S4 ; CC1(C)CCC(C)(C)c2cc3c(cc21)OB1c2c-3cc3c(oc4ccccc43)c2Sc2sc3cc4c(cc3c21)C(C)(C)CCC4(C)C]

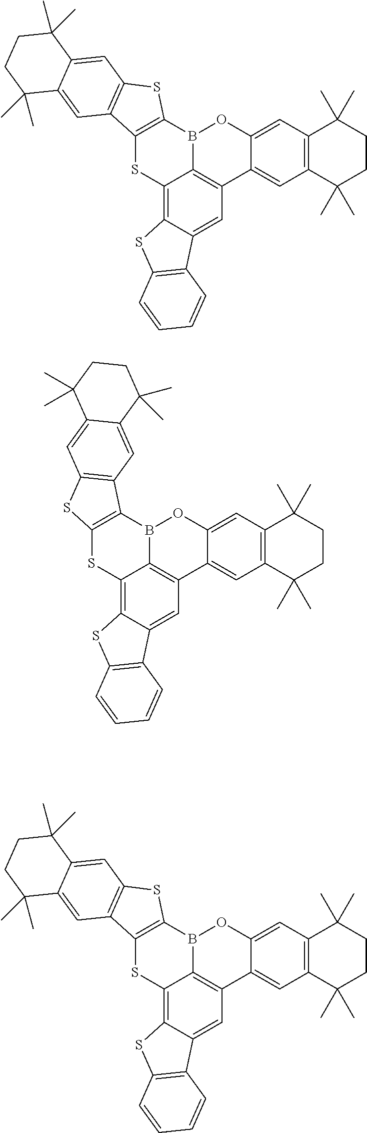 [SMILES: CC1(C)CCC(C)(C)c2cc3c(cc21)OB1c2sc4cc5c(cc4c2Sc2c1c-3cc1c2sc2ccccc21)C(C)(C)CCC5(C)C ; CC1(C)CCC(C)(C)c2cc3c(cc21)OB1c2c-3cc3c(sc4ccccc43)c2Sc2sc3cc4c(cc3c21)C(C)(C)CCC4(C)C ; CC1(C)CCC(C)(C)c2cc3c(cc21)OB1c2sc4cc5c(cc4c2Sc2c1c-3cc1c2sc2ccccc21)C(C)(C)CCC5(C)C]

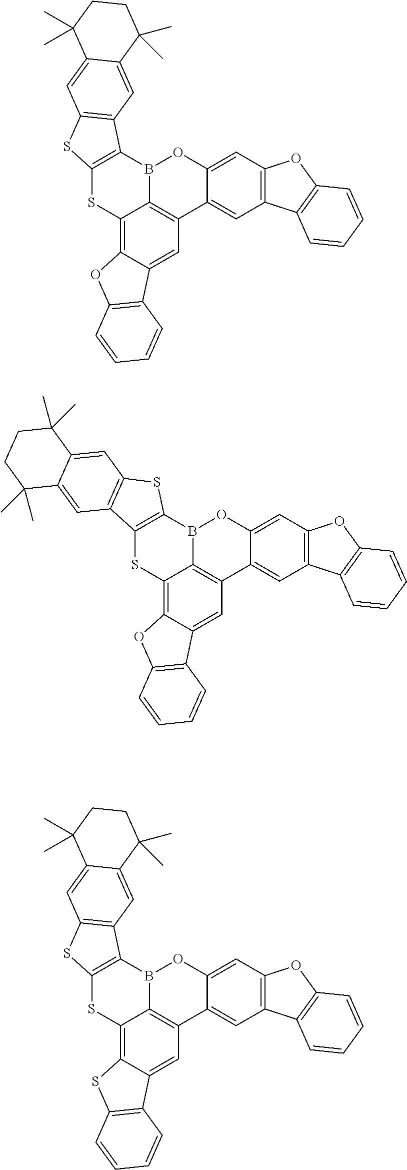 [SMILES: CC1(C)CCC(C)(C)c2cc3c4c(sc3cc21)Sc1c2c(cc3c1oc1ccccc13)-c1cc3c(cc1OB24)oc1ccccc13 ; CC1(C)CCC(C)(C)c2cc3c4c(sc3cc21)B1Oc2cc3oc5ccccc5c3cc2-c2cc3c(oc5ccccc53)c(c21)S4 ; CC1(C)CCC(C)(C)c2cc3c4c(sc3cc21)Sc1c2c(cc3c1sc1ccccc13)-c1cc3c(cc1OB24)oc1ccccc13]

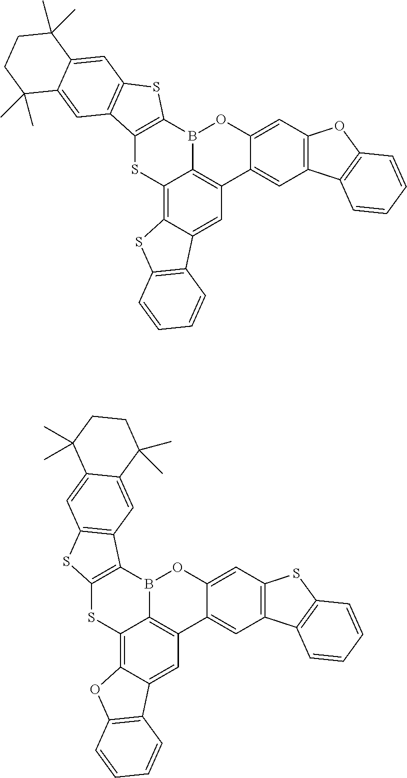 [SMILES: CC1(C)CCC(C)(C)c2cc3c4c(sc3cc21)B1Oc2cc3oc5ccccc5c3cc2-c2cc3c(sc5ccccc53)c(c21)S4 ; CC1(C)CCC(C)(C)c2cc3c4c(sc3cc21)Sc1c2c(cc3c1oc1ccccc13)-c1cc3c(cc1OB24)sc1ccccc13]

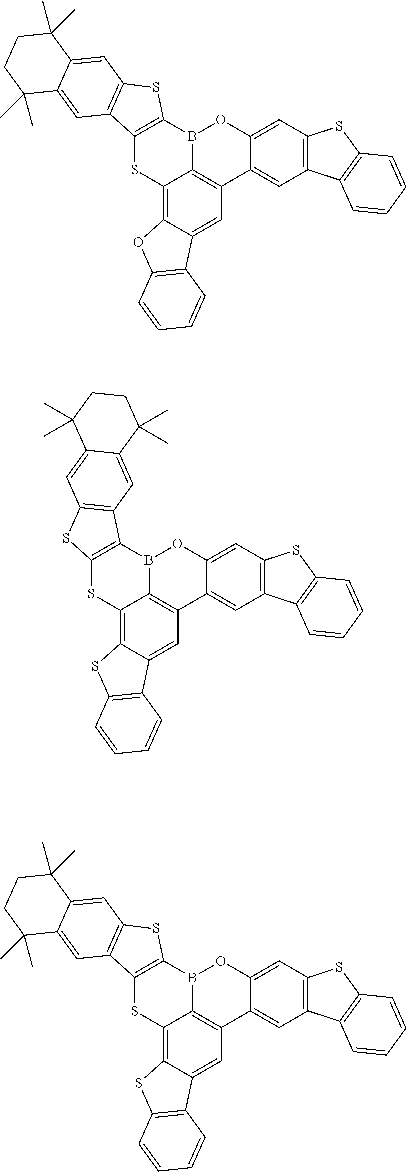 [SMILES: CC1(C)CCC(C)(C)c2cc3c4c(sc3cc21)B1Oc2cc3sc5ccccc5c3cc2-c2cc3c(oc5ccccc53)c(c21)S4 ; CC1(C)CCC(C)(C)c2cc3c4c(sc3cc21)Sc1c2c(cc3c1sc1ccccc13)-c1cc3c(cc1OB24)sc1ccccc13 ; CC1(C)CCC(C)(C)c2cc3c4c(sc3cc21)B1Oc2cc3sc5ccccc5c3cc2-c2cc3c(sc5ccccc53)c(c21)S4]

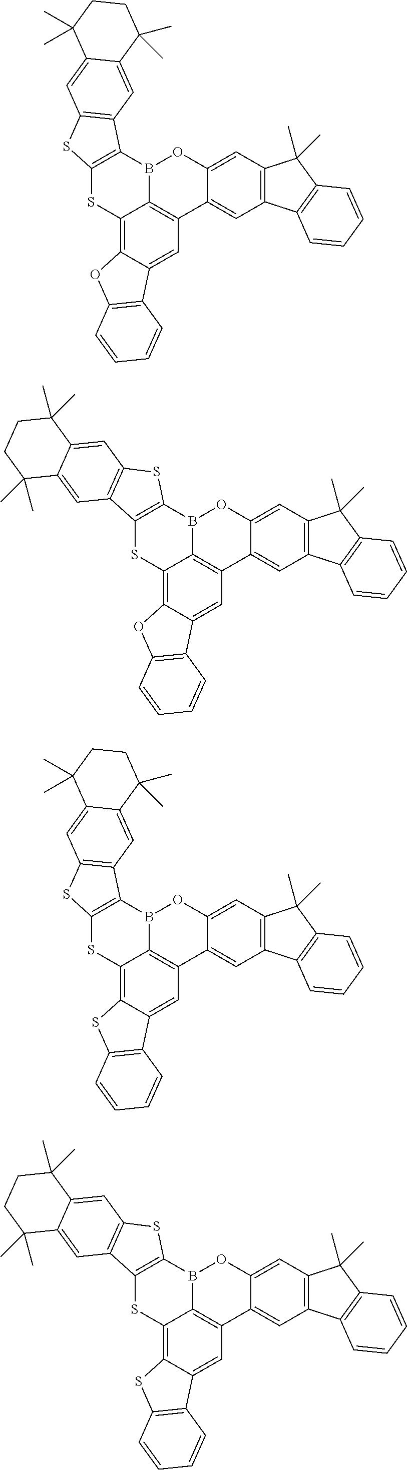 [SMILES: CC1(C)CCC(C)(C)c2cc3c4c(sc3cc21)Sc1c2c(cc3c1oc1ccccc13)-c1cc3c(cc1OB24)C(C)(C)c1ccccc1-3 ; CC1(C)CCC(C)(C)c2cc3c4c(sc3cc21)B1Oc2cc3c(cc2-c2cc5c(oc6ccccc65)c(c21)S4)-c1ccccc1C3(C)C ; CC1(C)CCC(C)(C)c2cc3c4c(sc3cc21)Sc1c2c(cc3c1sc1ccccc13)-c1cc3c(cc1OB24)C(C)(C)c1ccccc1-3 ; CC1(C)CCC(C)(C)c2cc3c4c(sc3cc21)B1Oc2cc3c(cc2-c2cc5c(sc6ccccc65)c(c21)S4)-c1ccccc1C3(C)C]

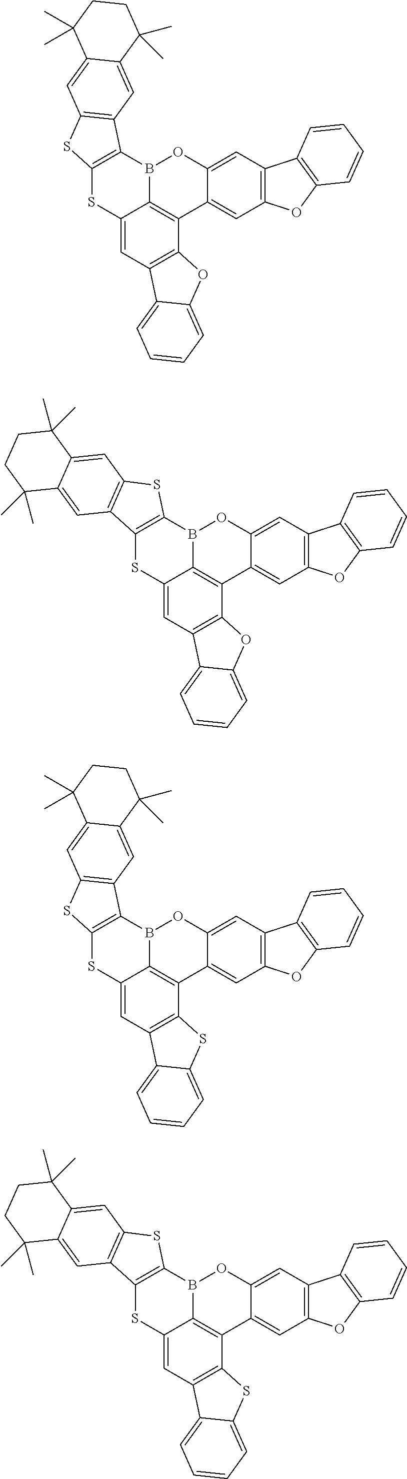 [SMILES: CC1(C)CCC(C)(C)c2cc3c4c(sc3cc21)Sc1cc2c(oc3ccccc32)c2c1B4Oc1cc3c(cc1-2)oc1ccccc13 ; CC1(C)CCC(C)(C)c2cc3c4c(sc3cc21)B1Oc2cc3c(cc2-c2c1c(cc1c2oc2ccccc21)S4)oc1ccccc13 ; CC1(C)CCC(C)(C)c2cc3c4c(sc3cc21)Sc1cc2c(sc3ccccc32)c2c1B4Oc1cc3c(cc1-2)oc1ccccc13 ; CC1(C)CCC(C)(C)c2cc3c4c(sc3cc21)B1Oc2cc3c(cc2-c2c1c(cc1c2sc2ccccc21)S4)oc1ccccc13]

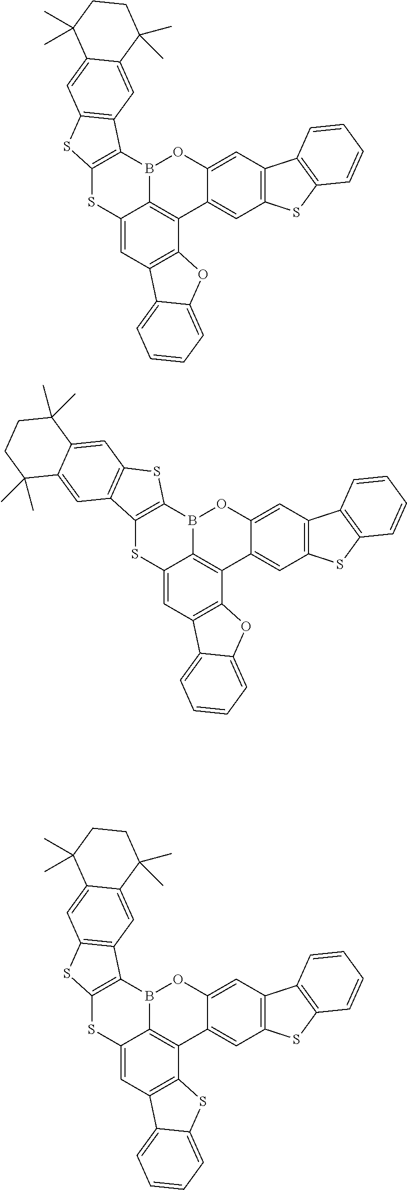 [SMILES: CC1(C)CCC(C)(C)c2cc3c4c(sc3cc21)Sc1cc2c(oc3ccccc32)c2c1B4Oc1cc3c(cc1-2)sc1ccccc13 ; CC1(C)CCC(C)(C)c2cc3c4c(sc3cc21)B1Oc2cc3c(cc2-c2c1c(cc1c2oc2ccccc21)S4)sc1ccccc13 ; CC1(C)CCC(C)(C)c2cc3c4c(sc3cc21)Sc1cc2c(sc3ccccc32)c2c1B4Oc1cc3c(cc1-2)sc1ccccc13]

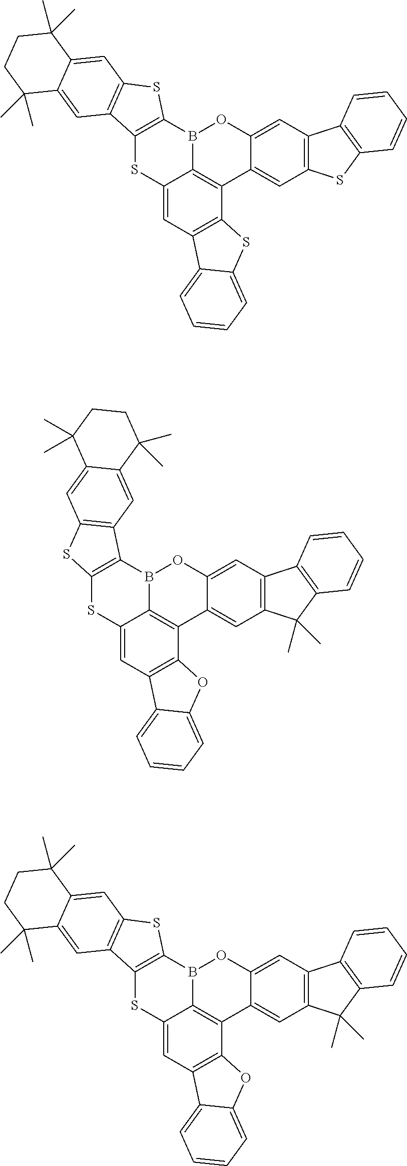 [SMILES: CC1(C)CCC(C)(C)c2cc3c4c(sc3cc21)B1Oc2cc3c(cc2-c2c1c(cc1c2sc2ccccc21)S4)sc1ccccc13 ; CC1(C)CCC(C)(C)c2cc3c4c(sc3cc21)Sc1cc2c(oc3ccccc32)c2c1B4Oc1cc3c(cc1-2)C(C)(C)c1ccccc1-3 ; CC1(C)CCC(C)(C)c2cc3c4c(sc3cc21)B1Oc2cc3c(cc2-c2c1c(cc1c2oc2ccccc21)S4)C(C)(C)c1ccccc1-3]

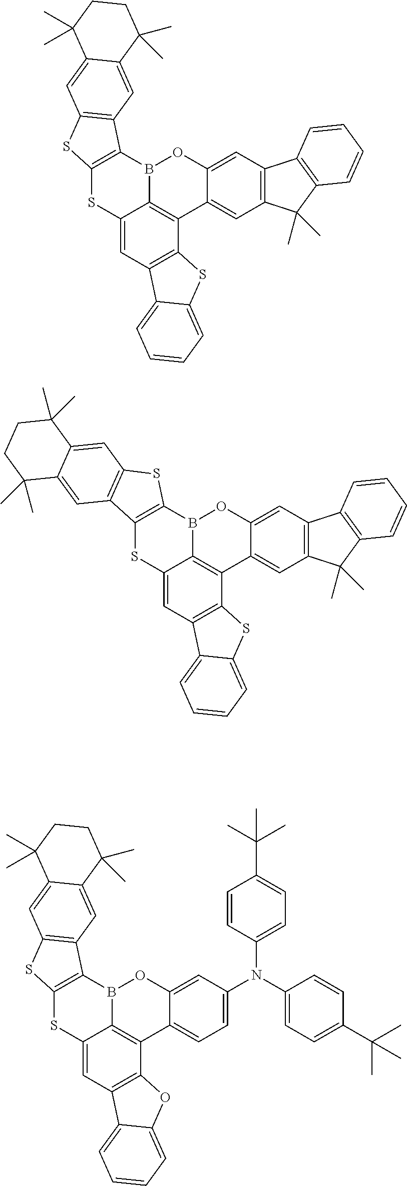 [SMILES: CC1(C)CCC(C)(C)c2cc3c4c(sc3cc21)Sc1cc2c(sc3ccccc32)c2c1B4Oc1cc3c(cc1-2)C(C)(C)c1ccccc1-3 ; CC1(C)CCC(C)(C)c2cc3c4c(sc3cc21)B1Oc2cc3c(cc2-c2c1c(cc1c2sc2ccccc21)S4)C(C)(C)c1ccccc1-3 ; CC(C)(C)c1ccc(N(c2ccc(C(C)(C)C)cc2)c2ccc3c(c2)OB2c4c(cc5c(oc6ccccc65)c4-3)Sc3sc4cc5c(cc4c32)C(C)(C)CCC5(C)C)cc1]

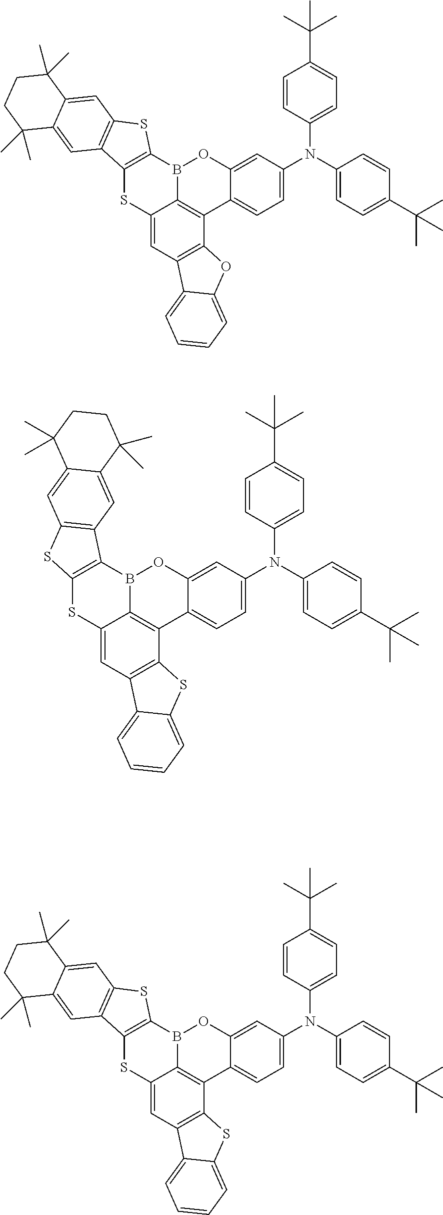

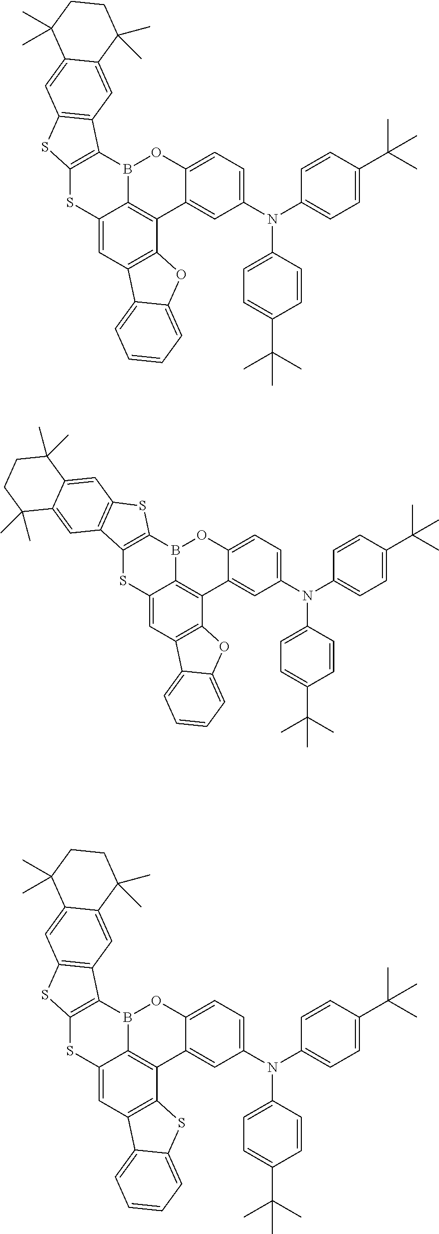

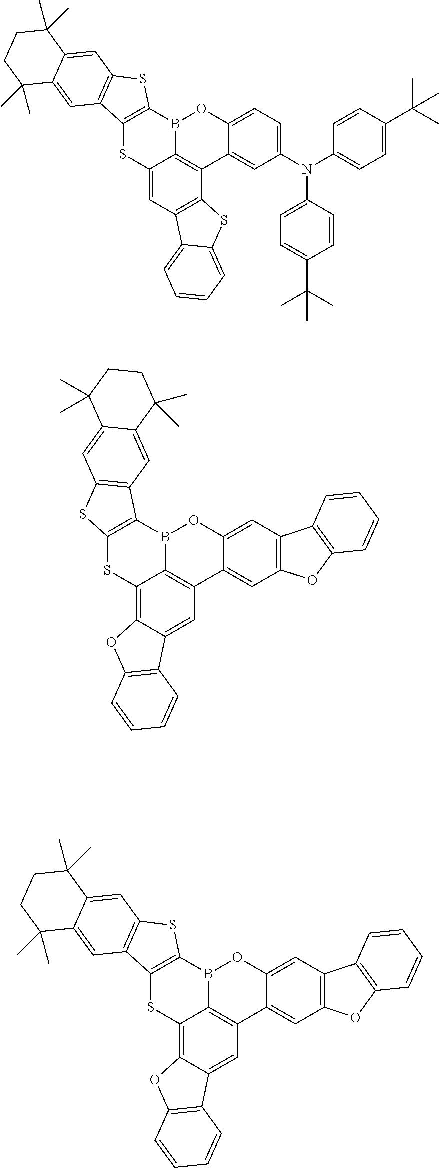

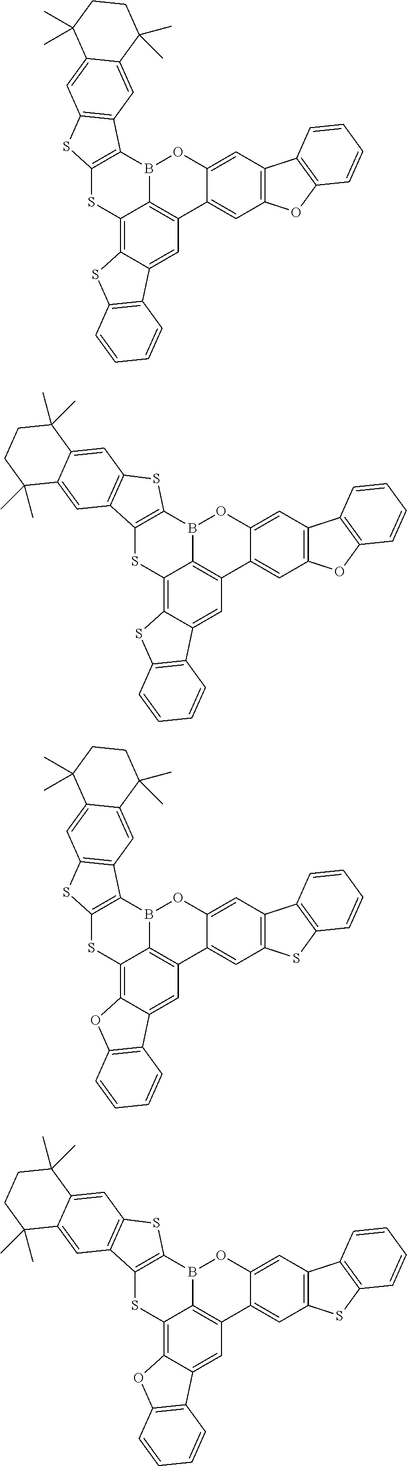

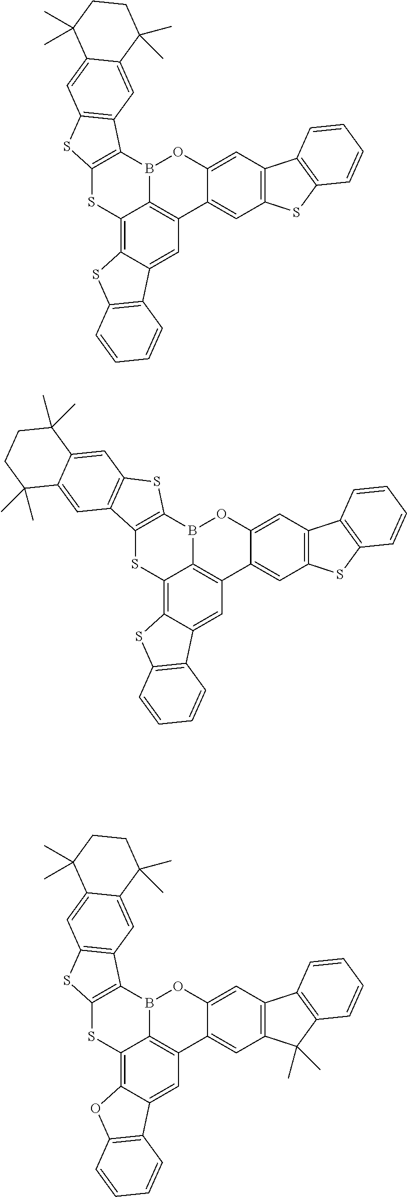 [SMILES: CC1(C)CCC(C)(C)c2cc3c4c(sc3cc21)Sc1c2c(cc3c1sc1ccccc13)-c1cc3sc5ccccc5c3cc1OB24 ; CC1(C)CCC(C)(C)c2cc3c4c(sc3cc21)B1Oc2cc3c(cc2-c2cc5c(sc6ccccc65)c(c21)S4)sc1ccccc13 ; CC1(C)CCC(C)(C)c2cc3c4c(sc3cc21)Sc1c2c(cc3c1oc1ccccc13)-c1cc3c(cc1OB24)-c1ccccc1C3(C)C]

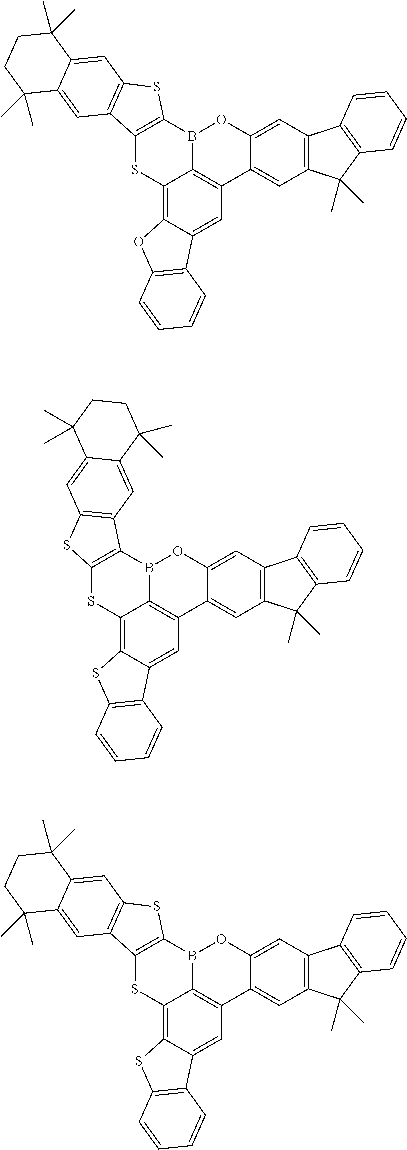 [SMILES: CC1(C)CCC(C)(C)c2cc3c4c(sc3cc21)B1Oc2cc3c(cc2-c2cc5c(oc6ccccc65)c(c21)S4)C(C)(C)c1ccccc1-3 ; CC1(C)CCC(C)(C)c2cc3c4c(sc3cc21)Sc1c2c(cc3c1sc1ccccc13)-c1cc3c(cc1OB24)-c1ccccc1C3(C)C ; CC1(C)CCC(C)(C)c2cc3c4c(sc3cc21)B1Oc2cc3c(cc2-c2cc5c(sc6ccccc65)c(c21)S4)C(C)(C)c1ccccc1-3]

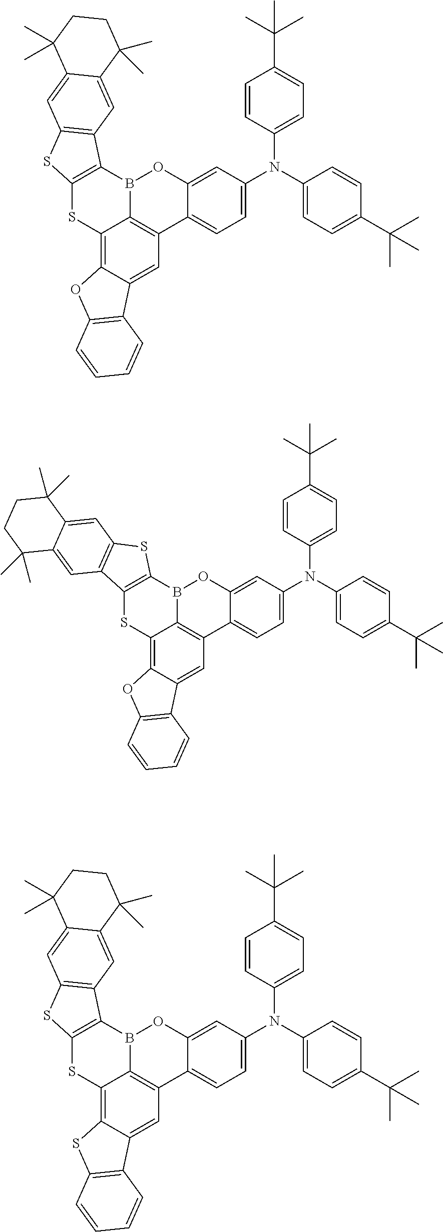

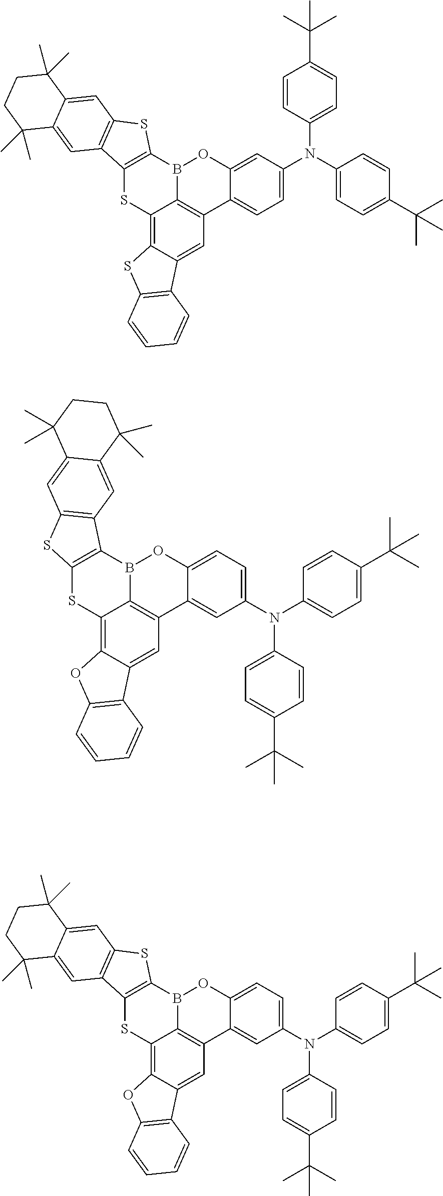

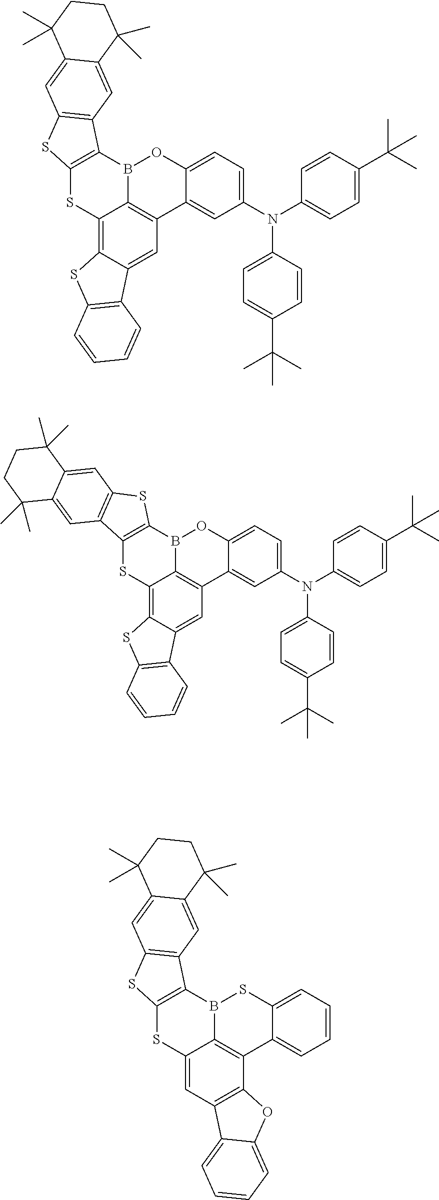

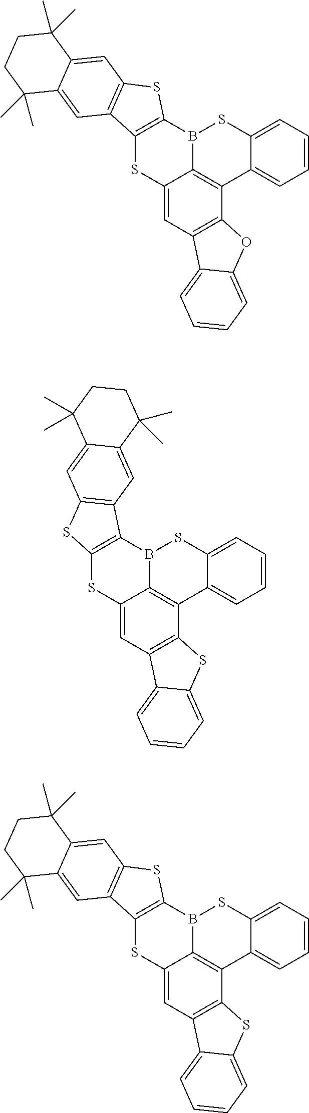 [SMILES: CC1(C)CCC(C)(C)c2cc3c4c(sc3cc21)B1Sc2ccccc2-c2c1c(cc1c2oc2ccccc21)S4 ; CC1(C)CCC(C)(C)c2cc3c4c(sc3cc21)Sc1cc2c(sc3ccccc32)c2c1B4Sc1ccccc1-2 ; CC1(C)CCC(C)(C)c2cc3c4c(sc3cc21)B1Sc2ccccc2-c2c1c(cc1c2sc2ccccc21)S4]

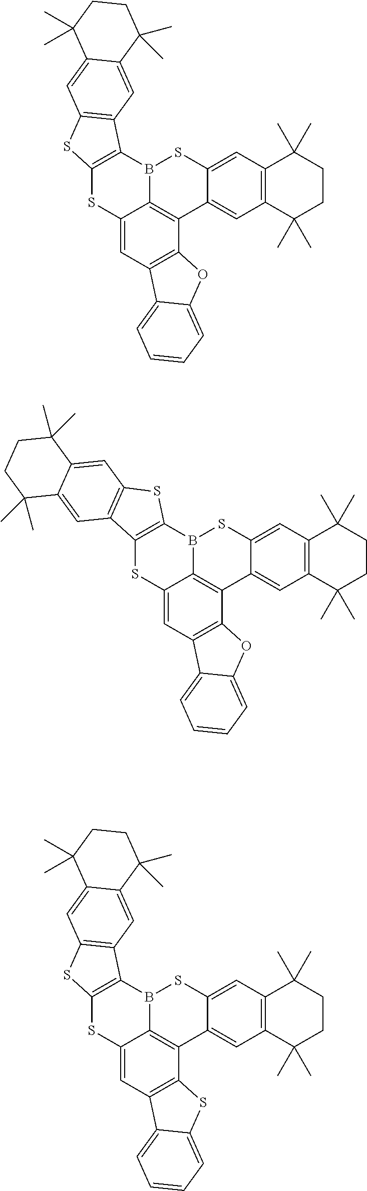 [SMILES: CC1(C)CCC(C)(C)c2cc3c(cc21)SB1c2c(cc4c(oc5ccccc54)c2-3)Sc2sc3cc4c(cc3c21)C(C)(C)CCC4(C)C ; CC1(C)CCC(C)(C)c2cc3c(cc21)SB1c2sc4cc5c(cc4c2Sc2cc4c(oc6ccccc64)c-3c21)C(C)(C)CCC5(C)C ; CC1(C)CCC(C)(C)c2cc3c(cc21)SB1c2c(cc4c(sc5ccccc54)c2-3)Sc2sc3cc4c(cc3c21)C(C)(C)CCC4(C)C]

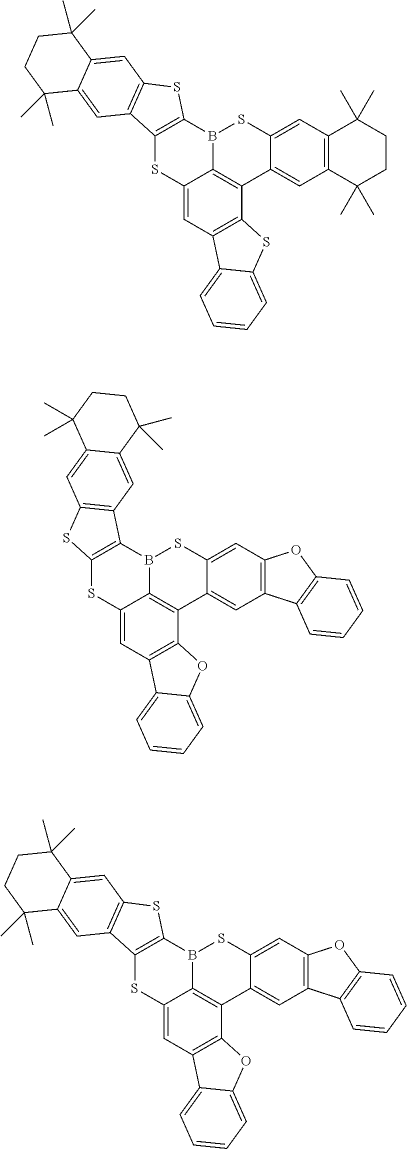 [SMILES: CC1(C)CCC(C)(C)c2cc3c(cc21)SB1c2sc4cc5c(cc4c2Sc2cc4c(sc6ccccc64)c-3c21)C(C)(C)CCC5(C)C ; CC1(C)CCC(C)(C)c2cc3c4c(sc3cc21)Sc1cc2c(oc3ccccc32)c2c1B4Sc1cc3oc4ccccc4c3cc1-2 ; CC1(C)CCC(C)(C)c2cc3c4c(sc3cc21)B1Sc2cc3oc5ccccc5c3cc2-c2c1c(cc1c2oc2ccccc21)S4]

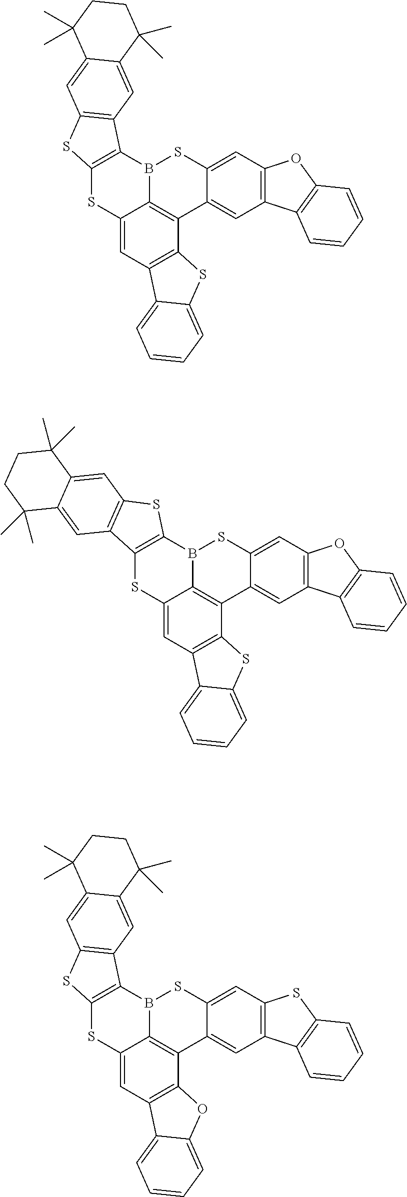 [SMILES: CC1(C)CCC(C)(C)c2cc3c4c(sc3cc21)Sc1cc2c(sc3ccccc32)c2c1B4Sc1cc3oc4ccccc4c3cc1-2 ; CC1(C)CCC(C)(C)c2cc3c4c(sc3cc21)B1Sc2cc3oc5ccccc5c3cc2-c2c1c(cc1c2sc2ccccc21)S4 ; CC1(C)CCC(C)(C)c2cc3c4c(sc3cc21)Sc1cc2c(oc3ccccc32)c2c1B4Sc1cc3sc4ccccc4c3cc1-2]

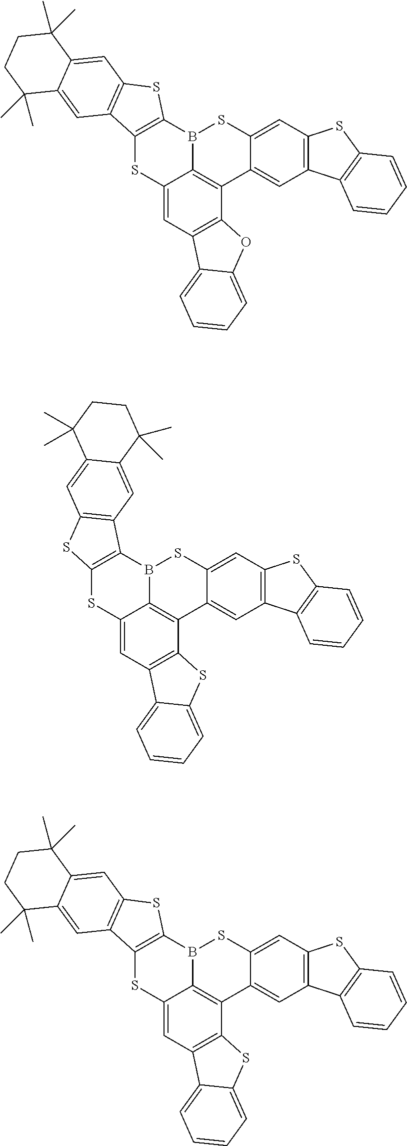 [SMILES: CC1(C)CCC(C)(C)c2cc3c4c(sc3cc21)B1Sc2cc3sc5ccccc5c3cc2-c2c1c(cc1c2oc2ccccc21)S4 ; CC1(C)CCC(C)(C)c2cc3c4c(sc3cc21)Sc1cc2c(sc3ccccc32)c2c1B4Sc1cc3sc4ccccc4c3cc1-2 ; CC1(C)CCC(C)(C)c2cc3c4c(sc3cc21)B1Sc2cc3sc5ccccc5c3cc2-c2c1c(cc1c2sc2ccccc21)S4]

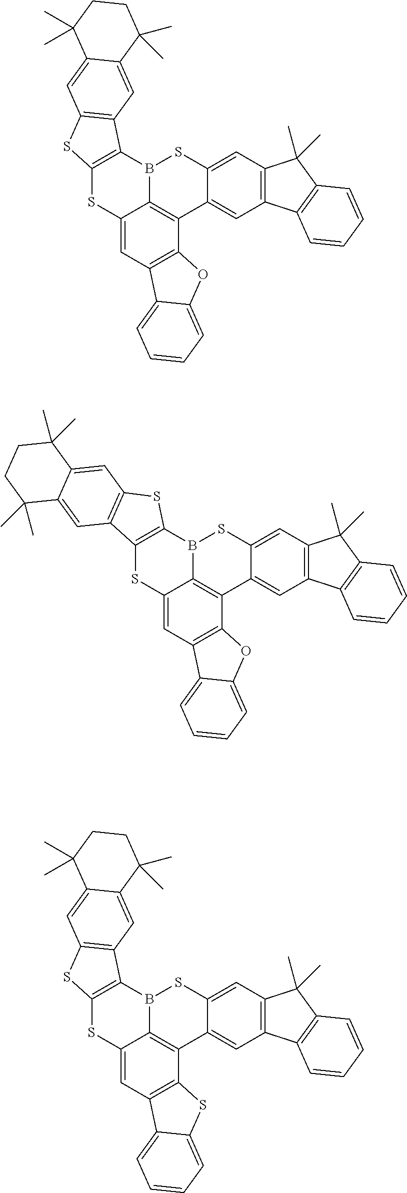 [SMILES: CC1(C)CCC(C)(C)c2cc3c4c(sc3cc21)Sc1cc2c(oc3ccccc32)c2c1B4Sc1cc3c(cc1-2)-c1ccccc1C3(C)C ; CC1(C)CCC(C)(C)c2cc3c4c(sc3cc21)B1Sc2cc3c(cc2-c2c1c(cc1c2oc2ccccc21)S4)-c1ccccc1C3(C)C ; CC1(C)CCC(C)(C)c2cc3c4c(sc3cc21)Sc1cc2c(sc3ccccc32)c2c1B4Sc1cc3c(cc1-2)-c1ccccc1C3(C)C]

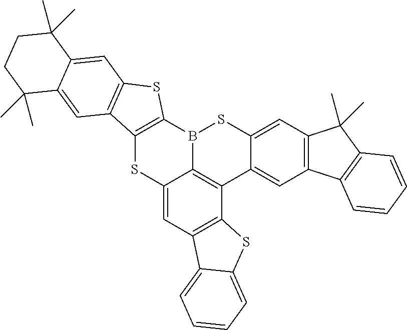 [SMILES: CC1(C)CCC(C)(C)c2cc3c4c(sc3cc21)B1Sc2cc3c(cc2-c2c1c(cc1c2sc2ccccc21)S4)-c1ccccc1C3(C)C]

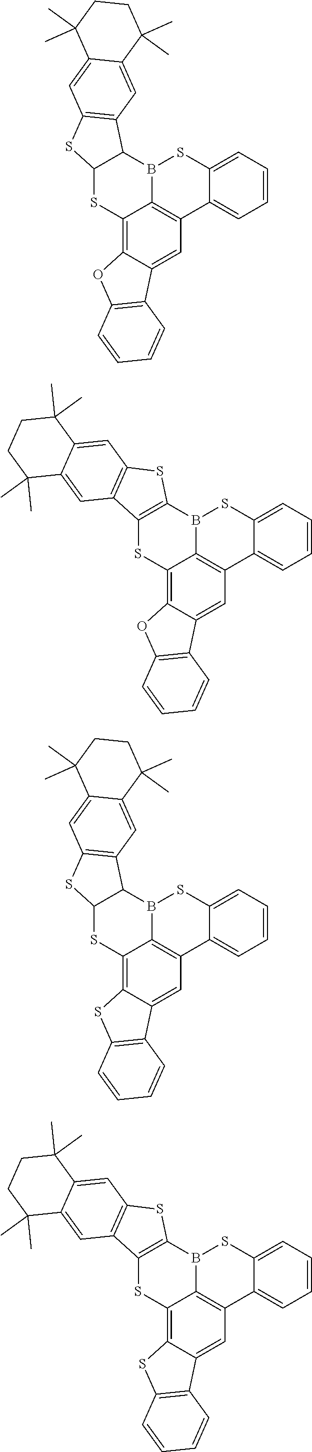

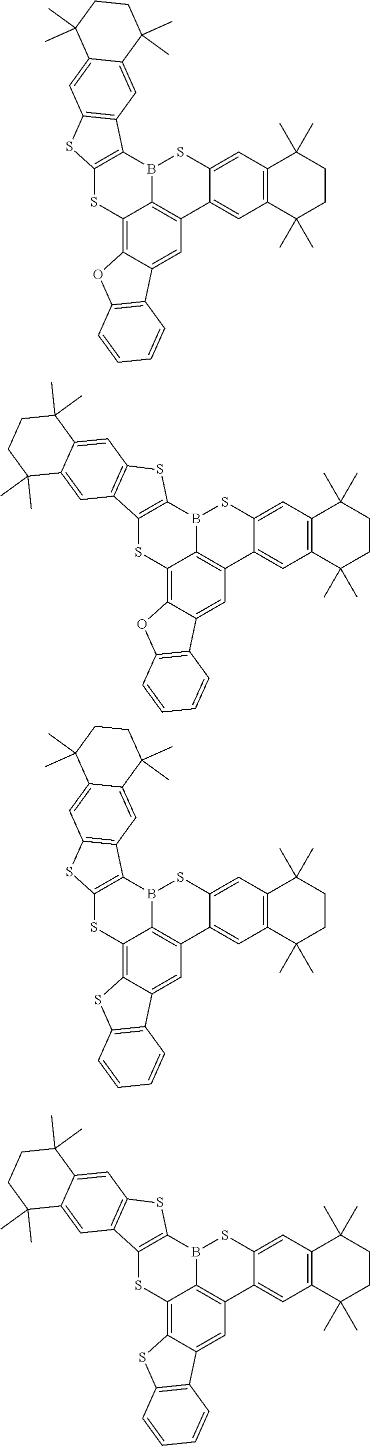

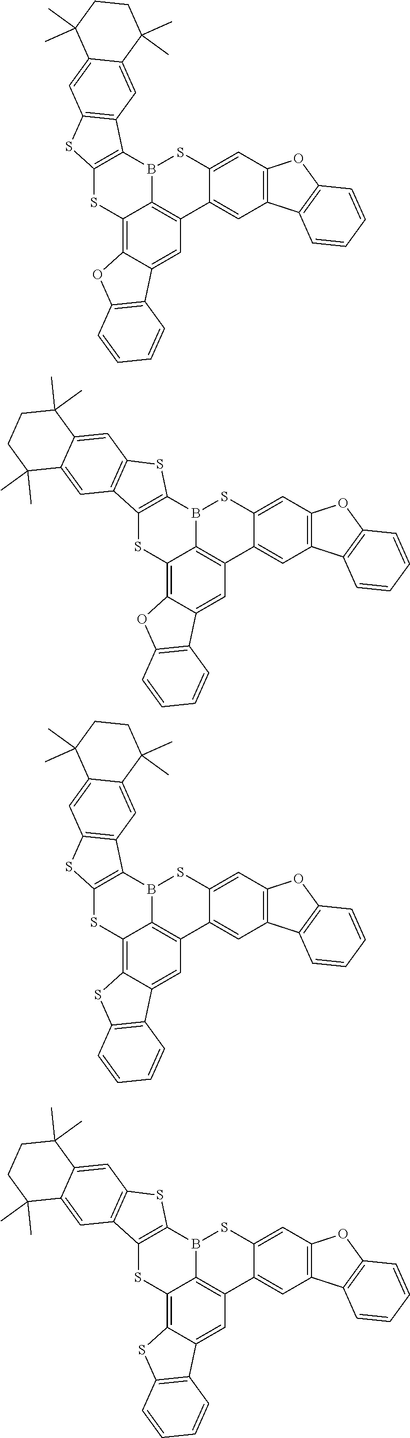

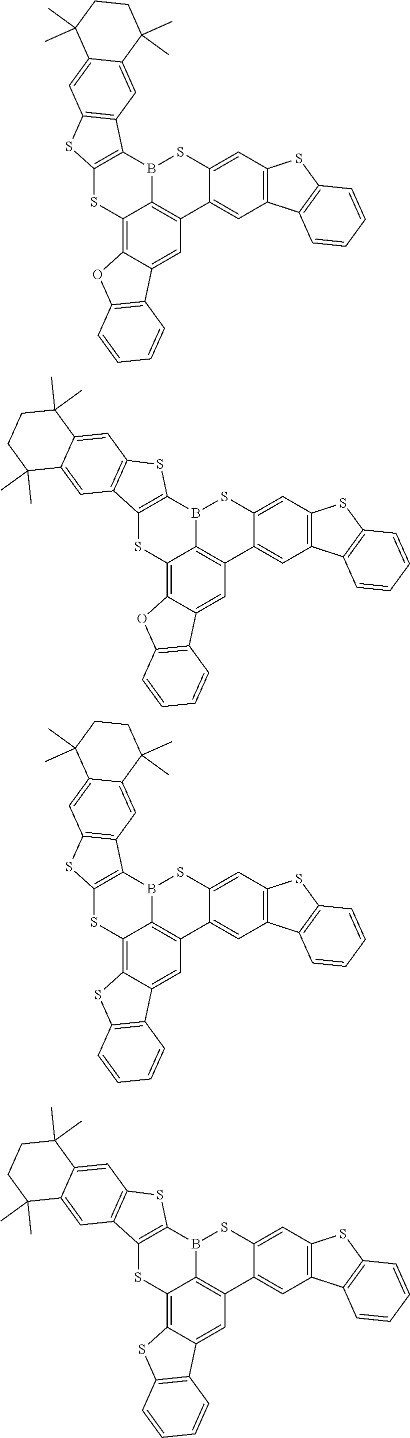

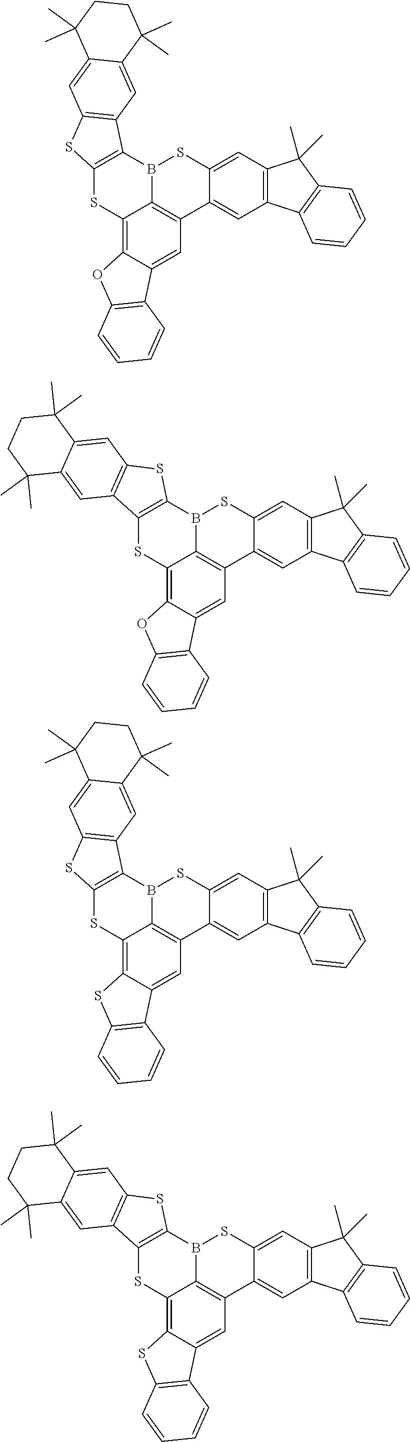

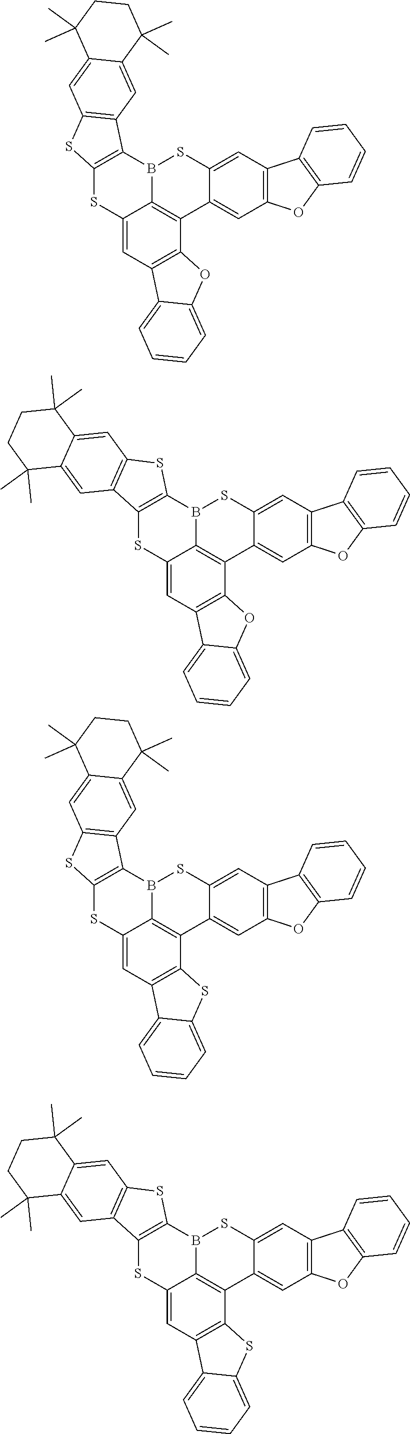

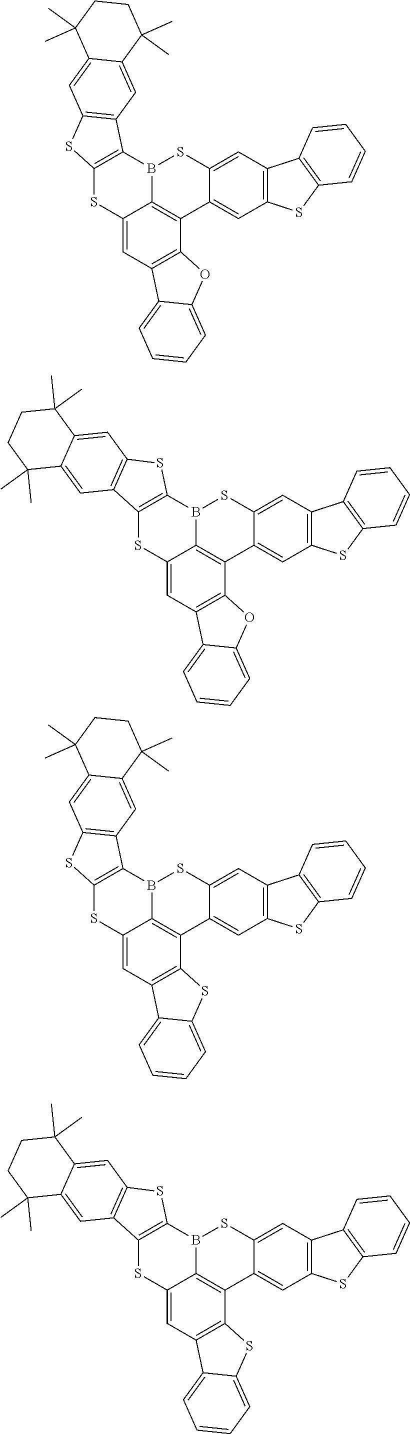

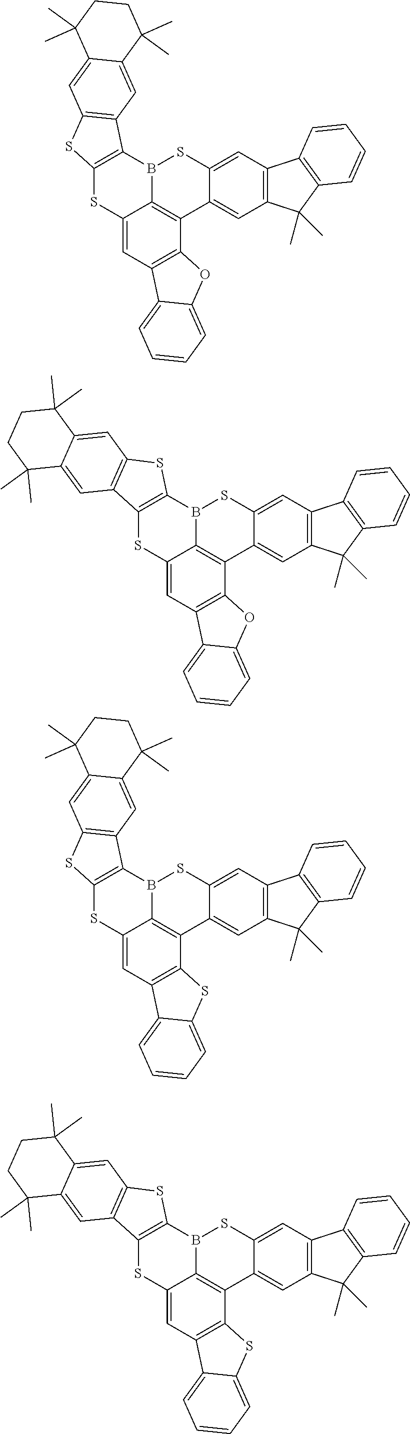

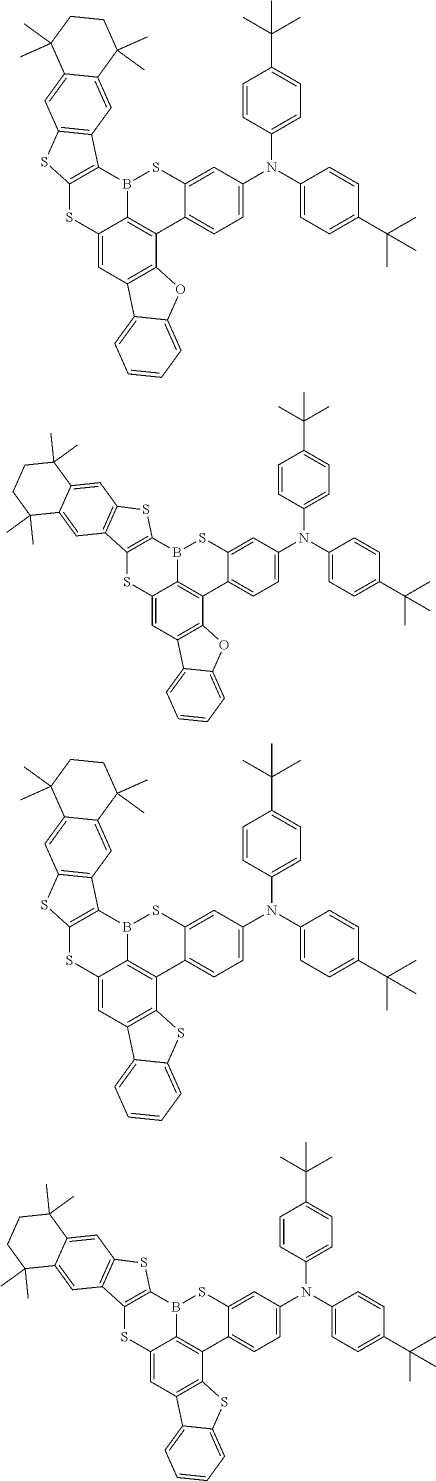

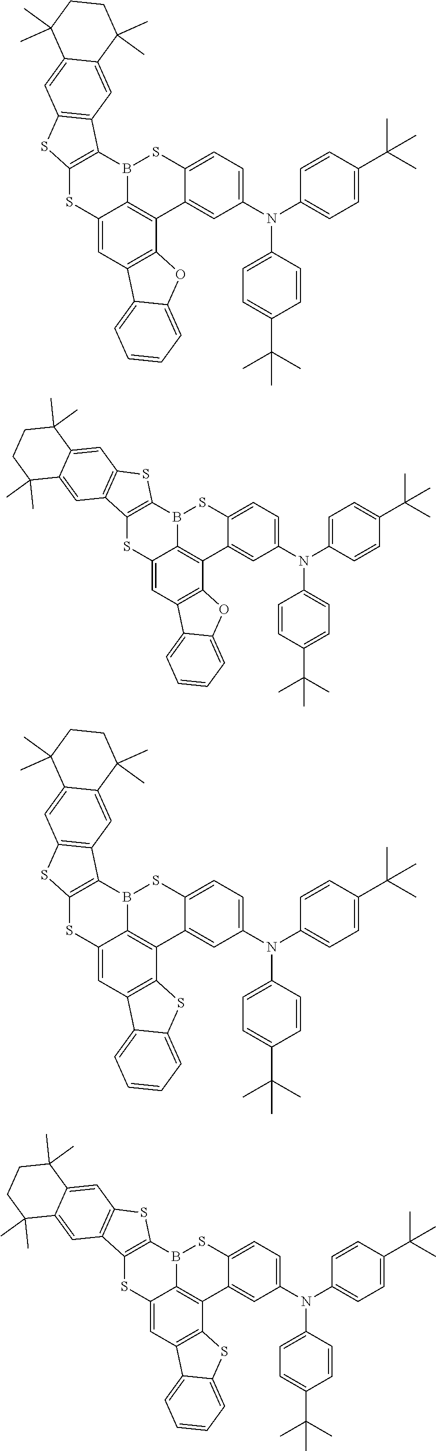

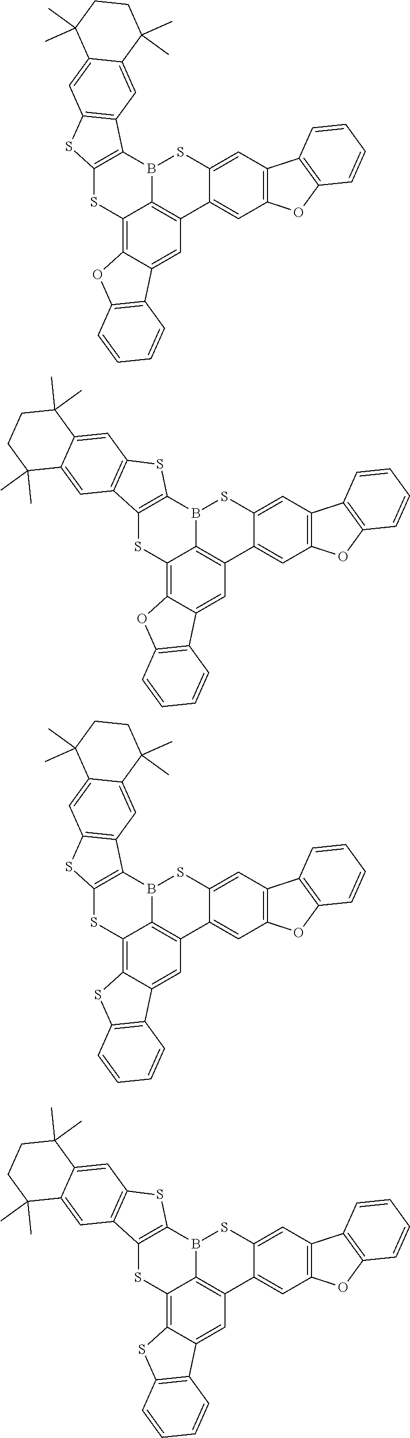

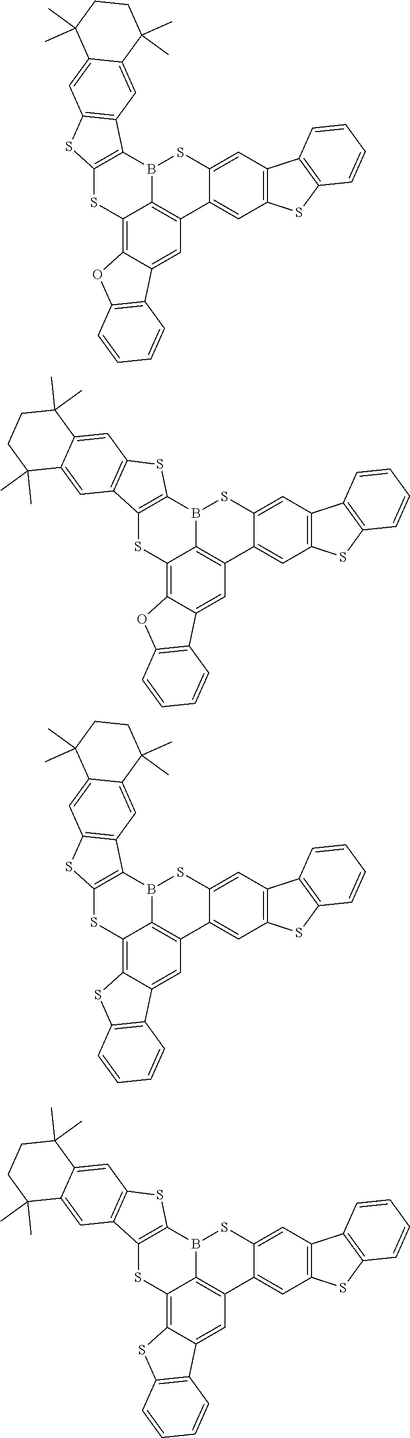

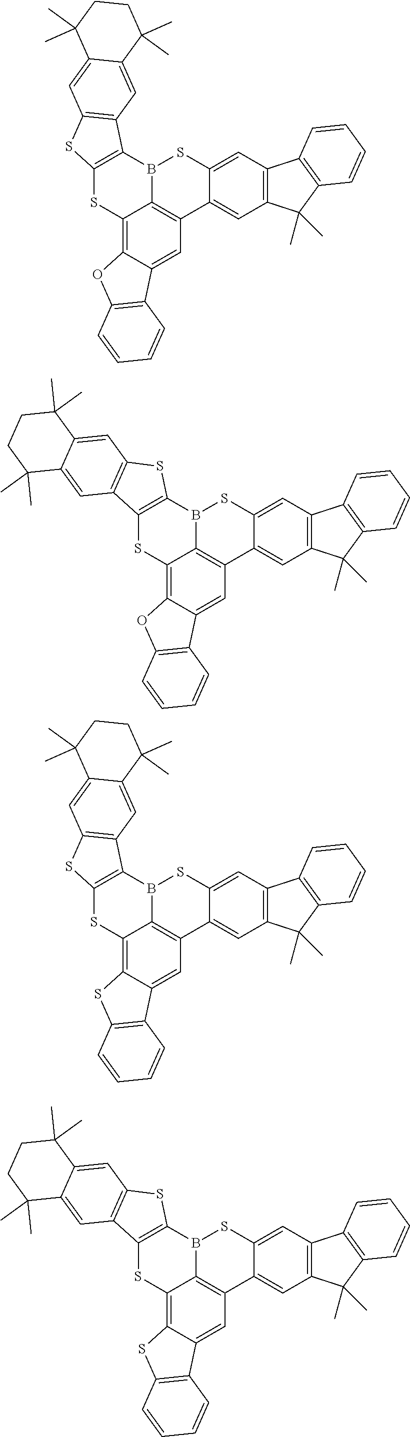

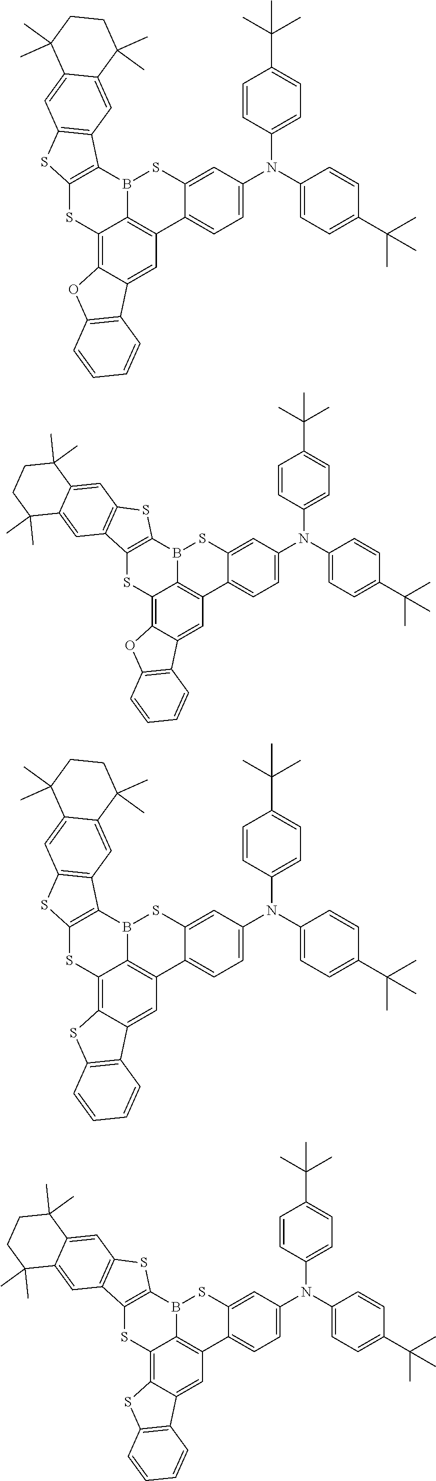

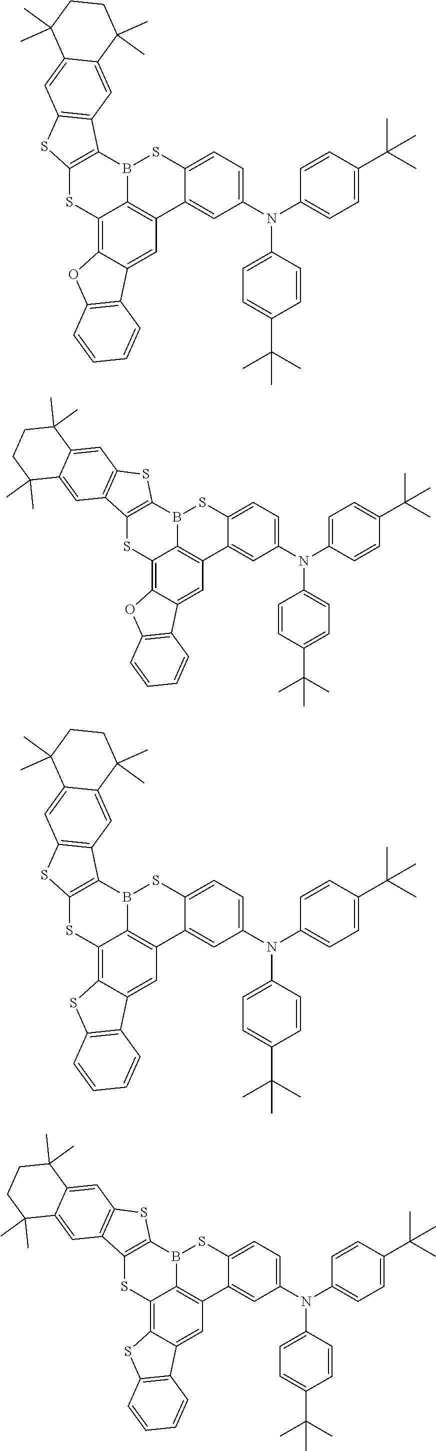

The substituent of the compound represented by Chemical Formula 1 according to an exemplary embodiment of the present specification may be bonded by a method known in the art, and the type and position of the substituent or the number of substituents may be changed according to the technology known in the art.

In the present specification, compounds having various energy band gaps may be synthesized by introducing various substituents into the core structure of the compound represented by Chemical Formula 1. Further, in the present specification, by introducing various substituents into the core structures having the structure described above, a narrow full width at half maximum may be achieved, and the HOMO and LUMO energy levels of the compound may also be adjusted.

In addition, the present specification provides an organic light emitting device including the above-described compound.

The organic light emitting device according to the present specification is an organic light emitting device including: a positive electrode; a negative electrode; and an organic material layer having one or more layers provided between the positive electrode and the negative electrode, in which one or more layers of the organic material layer include the above-described compound represented by Chemical Formula 1.

The organic material layer of the organic light emitting device of the present specification may be composed of a single-layered structure, but may also be composed of a multi-layered structure in which two or more organic material layers are stacked. For example, the organic light emitting device of the present invention may have a structure including one or more layers of a hole transport layer, a hole injection layer, an electron blocking layer, a hole transport and injection layer, an electron transport layer, an electron injection layer, a hole blocking layer, and an electron transport and injection layer as organic material layers. However, the structure of the organic light emitting device of the present specification is not limited thereto, and may include a fewer or greater number of organic material layers.

In the organic light emitting device of the present specification, the organic light emitting device includes a light emitting layer, and the light emitting layer may include the compound.

For example, the compound of Chemical Formula 1 may be included as a dopant of the light emitting layer. In this case, X in the compound may be NR.

In an exemplary embodiment of the present invention, the light emitting layer includes a dopant and a host.

In an exemplary embodiment of the present invention, the light emitting layer includes the dopant and the host at a mass ratio of 1:99 to 5:95.

In an exemplary embodiment of the present invention, the light emitting layer includes the compound of Chemical Formula 1 as a dopant.

In an exemplary embodiment of the present invention, the light emitting layer includes the compound of Chemical Formula 1 as a blue dopant.

In an exemplary embodiment of the present invention, the light emitting layer includes a host.

The organic light emitting device according to an exemplary embodiment of the present specification includes a light emitting layer, and the light emitting layer includes the compound represented by Chemical Formula 1 and a compound represented by the following Chemical Formula H.

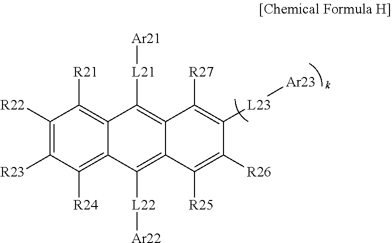

In Chemical Formula H,
L21 to L23 are the same as or different from each other, and are each independently a direct bond; a substituted or unsubstituted arylene group; or a substituted or unsubstituted heteroarylene group,
R21 to R27 are the same as or different from each other, and are each independently hydrogen; deuterium; a substituted or unsubstituted alkyl group; a substituted or unsubstituted cycloalkyl group; a substituted or unsubstituted silyl group; a substituted or unsubstituted aryl group; or a substituted or unsubstituted heteroaryl group,
Ar21 to Ar23 are the same as or different from each other, and are each independently deuterium; a substituted or unsubstituted aryl group; or a substituted or unsubstituted heteroaryl group, and
k is 0 or 1.

In an exemplary embodiment of the present specification, when k is 0, hydrogen or deuterium is linked to the position of -L23-Ar23.

In an exemplary embodiment of the present specification, L21 to L23 are the same as or different from each other, and are each independently a direct bond; a substituted or unsubstituted C6-C30 arylene group; or a C2-C30 heteroarylene group which is substituted or unsubstituted and includes N, O, or S.

In an exemplary embodiment of the present specification, L21 to L23 are the same as or different from each other, and are each independently a direct bond; a C6-C30 arylene group; or a C2-C30 heteroarylene group including N, O, or S, and the arylene group or heteroarylene group is unsubstituted or substituted with a C1-C10 alkyl group, a C6-C30 aryl group, or a C2-C30 heteroaryl group.

In an exemplary embodiment of the present specification, L21 to L23 are the same as or different from each other, and are each independently a direct bond; a substituted or unsubstituted phenylene group; a substituted or unsubstituted biphenylene group; a substituted or unsubstituted naphthylene group; a substituted or unsubstituted divalent dibenzofuran group; or a substituted or unsubstituted divalent dibenzothiophene group.

In an exemplary embodiment of the present specification, Ar21 to Ar23 are the same as or different from each other, and are each independently deuterium; a substituted or unsubstituted C6-C30 aryl group; or a substituted or unsubstituted C2-C30 heteroaryl group.

In an exemplary embodiment of the present specification, Ar21 to Ar23 are the same as or different from each other, and are each independently deuterium; a C6-C30 aryl group unsubstituted or substituted with deuterium; or a C2-C30 heteroaryl group unsubstituted or substituted with deuterium.

In an exemplary embodiment of the present specification, Ar21 to Ar23 are the same as or different from each other, and are each independently deuterium; a substituted or unsubstituted monocyclic to tetracyclic aryl group; or a substituted or unsubstituted monocyclic to tetracyclic heteroaryl group.

In an exemplary embodiment of the present specification, Ar21 to Ar23 are the same as or different from each other, and are each independently deuterium; a monocyclic to tetracyclic aryl group unsubstituted or substituted with deuterium; or a monocyclic to tetracyclic heteroaryl group unsubstituted or substituted with deuterium.

In an exemplary embodiment of the present specification, Ar21 to Ar23 are the same as or different from each other, and are each independently deuterium; a substituted or unsubstituted phenyl group; a substituted or unsubstituted biphenyl group; a substituted or unsubstituted terphenyl group; a substituted or unsubstituted naphthyl group; a substituted or unsubstituted anthracene group; a substituted or unsubstituted phenanthryl group; a substituted or unsubstituted phenalene group; a substituted or unsubstituted fluorenyl group; a substituted or unsubstituted benzofluorenyl group; a substituted or unsubstituted furan group; a substituted or unsubstituted thiophene group; a substituted or unsubstituted dibenzofuran group; a substituted or unsubstituted naphthobenzofuran group; a substituted or unsubstituted dibenzothiophene group; or a substituted or unsubstituted naphthobenzothiophene group.

In an exemplary embodiment of the present specification, Ar21 and Ar22 are different from each other.

In an exemplary embodiment of the present specification, Ar21 is a substituted or unsubstituted aryl group, and Ar22 is a substituted or unsubstituted aryl group.

In an exemplary embodiment of the present specification, Ar21 is a substituted or unsubstituted aryl group, and Ar22 is a substituted or unsubstituted heteroaryl group.

In an exemplary embodiment of the present specification, Ar21 is an aryl group which is unsubstituted or substituted with deuterium, and Ar22 is an aryl group which is unsubstituted or substituted with deuterium.

In an exemplary embodiment of the present specification, Ar21 is an aryl group which is unsubstituted or substituted with deuterium, and Ar22 is a heteroaryl group which is unsubstituted or substituted with deuterium.

In an exemplary embodiment of the present specification, R21 to R27 are the same as or different from each other, and are each independently hydrogen or deuterium.

In an exemplary embodiment of the present specification, R21 to R27 are hydrogen.

In an exemplary embodiment of the present specification, R21 to R27 are deuterium.

In an exemplary embodiment of the present specification, Chemical Formula H is represented by the following Chemical Formula H01.

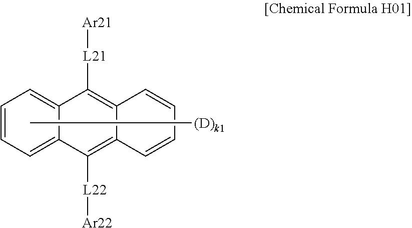

In Chemical Formula H01,
the definitions of L21, L22, Ar21 and Ar22 are the same as those defined in Chemical Formula H, D means deuterium, and k1 is 0 to 8.

In an exemplary embodiment of the present specification, the compound represented by Chemical Formula H is any one selected from the following compounds.

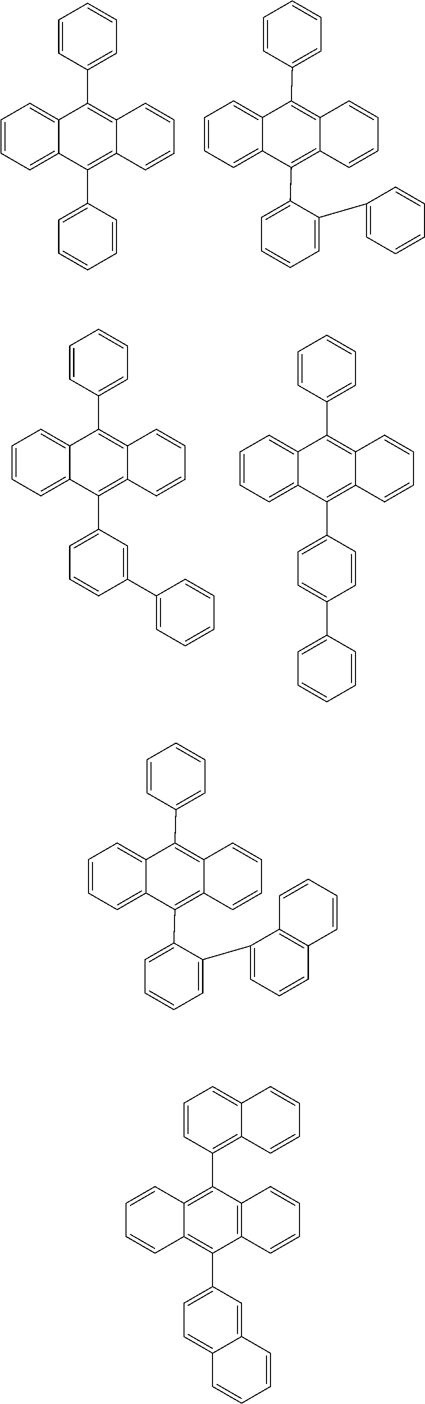

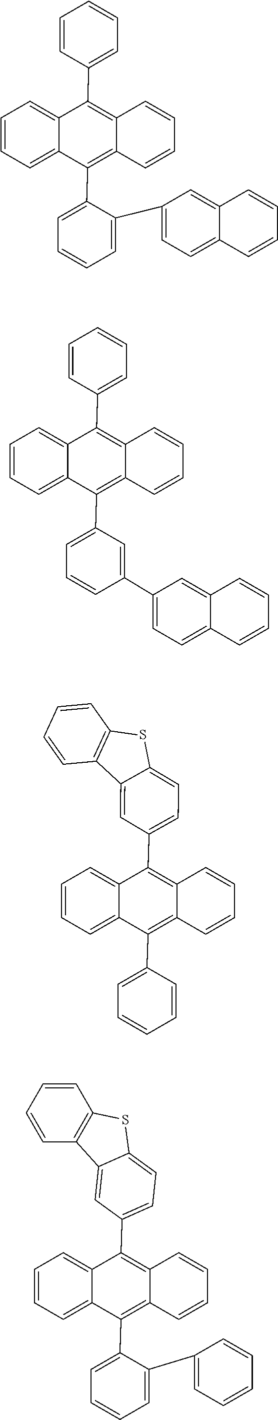

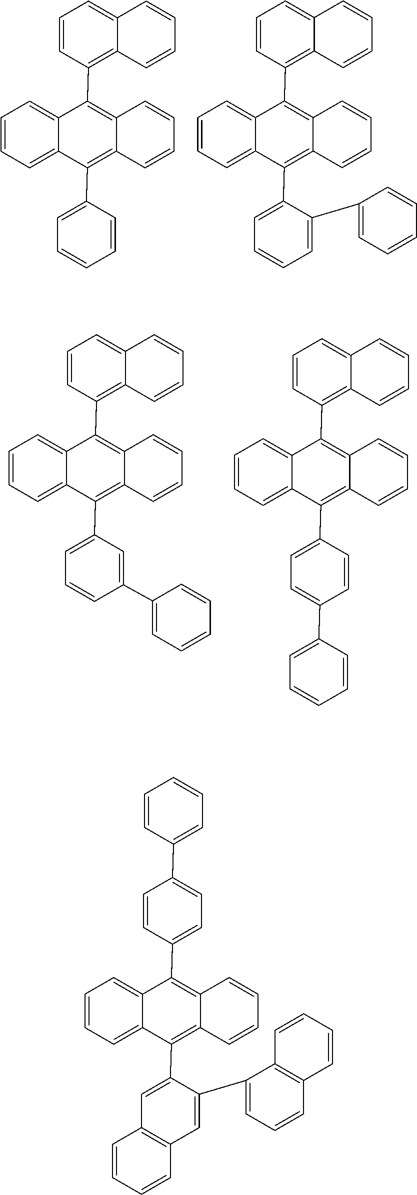

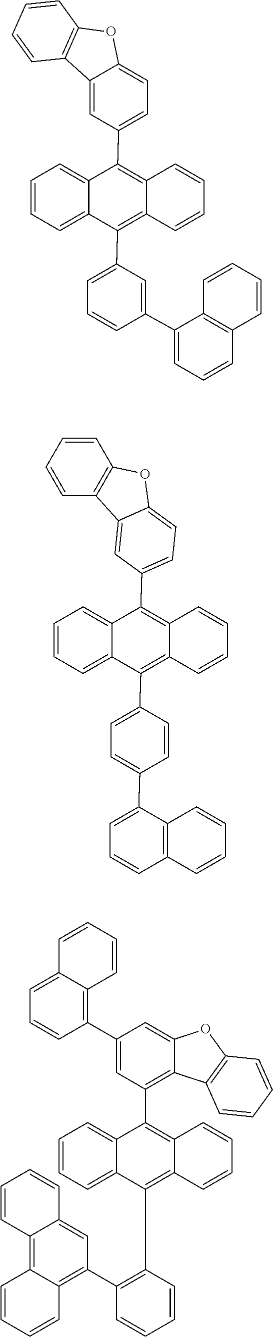 [SMILES: c1cc(-c2cccc3ccccc23)cc(-c2c3ccccc3c(-c3ccc4oc5ccccc5c4c3)c3ccccc23)c1 ; c1ccc2c(-c3ccc(-c4c5ccccc5c(-c5ccc6oc7ccccc7c6c5)c5ccccc45)cc3)cccc2c1 ; c1ccc(-c2cc3ccccc3c3ccccc23)c(-c2c3ccccc3c(-c3cc(-c4cccc5ccccc45)cc4oc5ccccc5c34)c3ccccc23)c1]

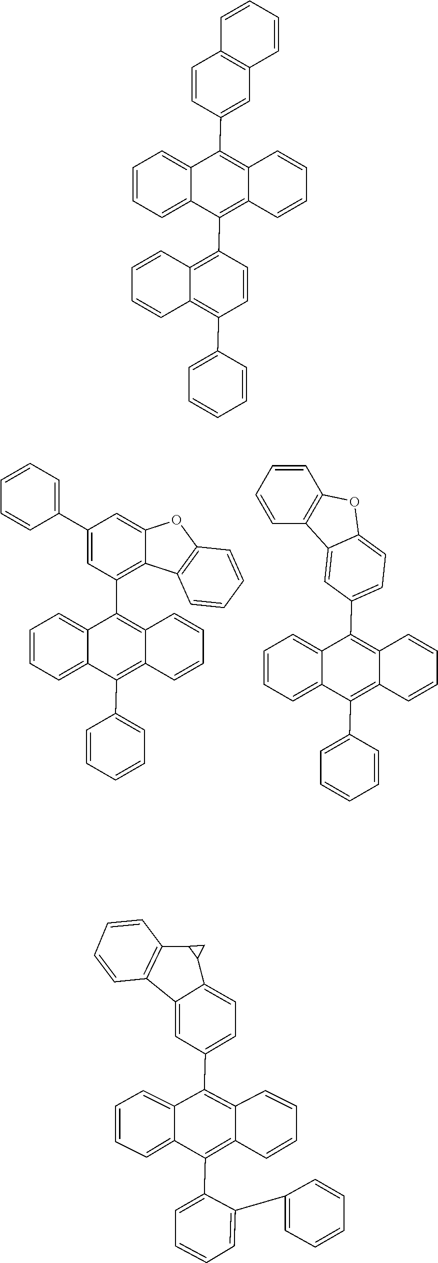

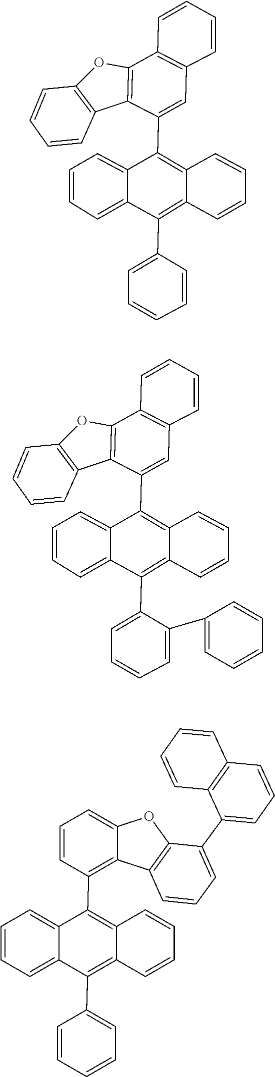

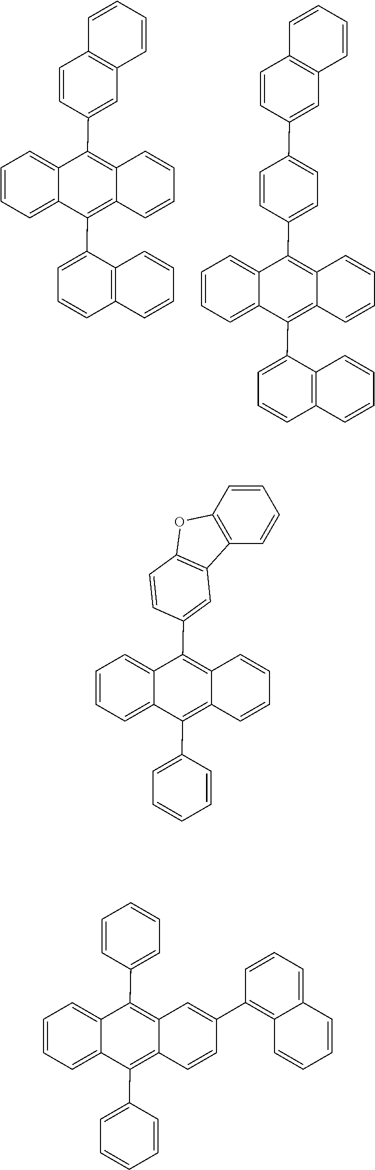

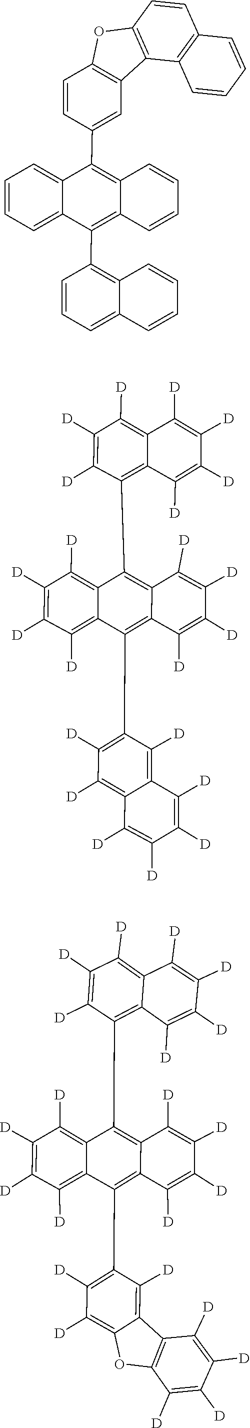 [SMILES: c1ccc2c(-c3c4ccccc4c(-c4ccc5oc6ccc7ccccc7c6c5c4)c4ccccc34)cccc2c1 ; [2H]c1c([2H])c([2H])c2c([2H])c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c2c1[2H] ; [2H]c1c([2H])c([2H])c2c(oc3c([2H])c([2H])c(-c4c5c([2H])c([2H])c([2H])c([2H])c5c(-c5c([2H])c([2H])c([2H])c6c([2H])c([2H])c([2H])c([2H])c56)c5c([2H])c([2H])c([2H])c([2H])c45)c([2H])c32)c1[2H]]

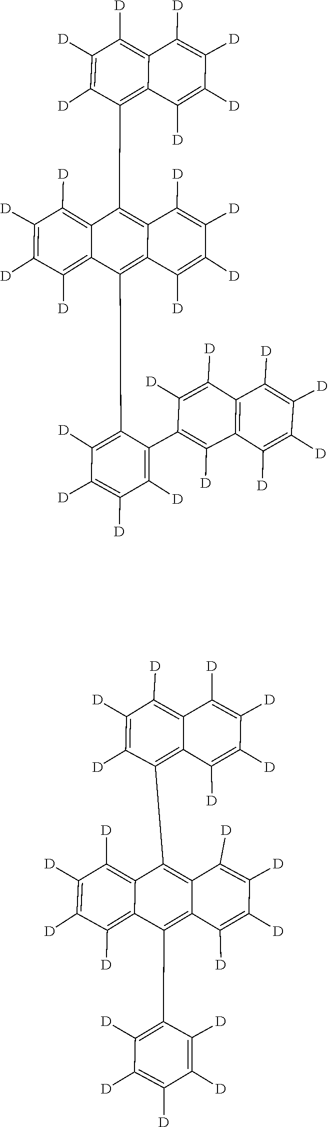 [SMILES: [2H]c1c([2H])c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c(-c2c([2H])c([2H])c3c([2H])c([2H])c([2H])c([2H])c3c2[2H])c1[2H] ; [2H]c1c([2H])c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c([2H])c1[2H]]

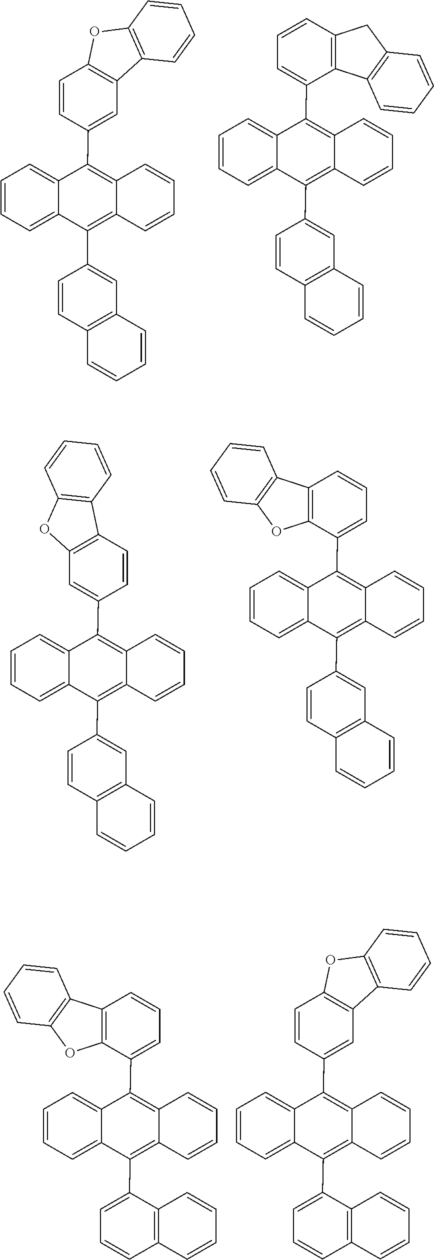

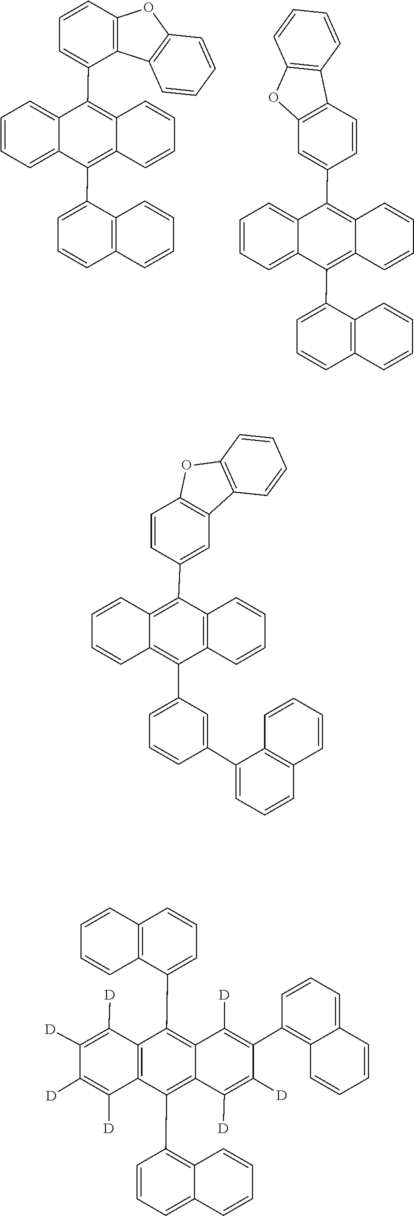 [SMILES: c1ccc2c(-c3c4ccccc4c(-c4cccc5oc6ccccc6c45)c4ccccc34)cccc2c1 ; c1ccc2c(-c3c4ccccc4c(-c4ccc5c(c4)oc4ccccc45)c4ccccc34)cccc2c1 ; c1cc(-c2cccc3ccccc23)cc(-c2c3ccccc3c(-c3ccc4oc5ccccc5c4c3)c3ccccc23)c1 ; [2H]c1c([2H])c([2H])c2c(-c3cccc4ccccc34)c3c([2H])c(-c4cccc5ccccc45)c([2H])c([2H])c3c(-c3cccc4ccccc34)c2c1[2H]]

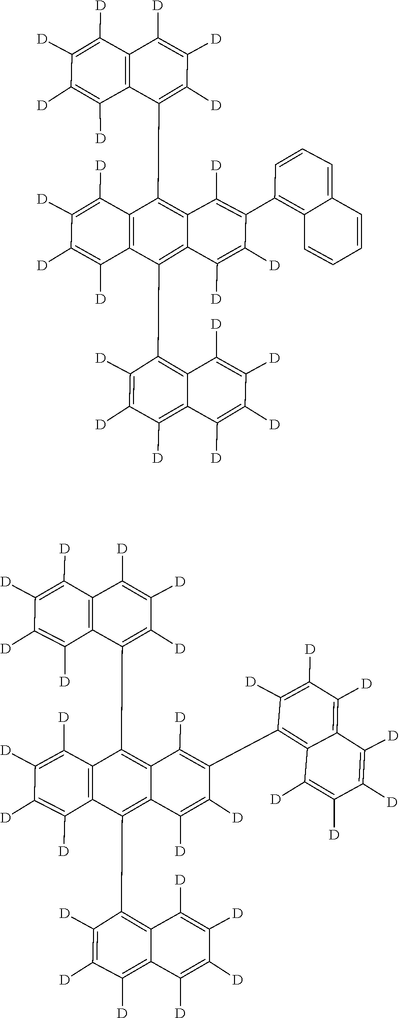 [SMILES: [2H]c1c([2H])c([2H])c2c(-c3c4c([2H])c([2H])c([2H])c([2H])c4c(-c4c([2H])c([2H])c([2H])c5c([2H])c([2H])c([2H])c([2H])c45)c4c([2H])c(-c5cccc6ccccc56)c([2H])c([2H])c34)c([2H])c([2H])c([2H])c2c1[2H] ; [2H]c1c([2H])c([2H])c2c(-c3c([2H])c([2H])c4c(-c5c([2H])c([2H])c([2H])c6c([2H])c([2H])c([2H])c([2H])c56)c5c([2H])c([2H])c([2H])c([2H])c5c(-c5c([2H])c([2H])c([2H])c6c([2H])c([2H])c([2H])c([2H])c56)c4c3[2H])c([2H])c([2H])c([2H])c2c1[2H]]

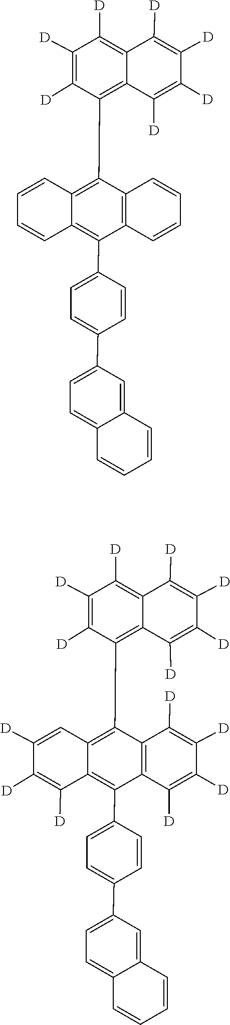 [SMILES: [2H]c1c([2H])c([2H])c2c(-c3c4ccccc4c(-c4ccc(-c5ccc6ccccc6c5)cc4)c4ccccc34)c([2H])c([2H])c([2H])c2c1[2H] ; [2H]c1cc2c(-c3c([2H])c([2H])c([2H])c4c([2H])c([2H])c([2H])c([2H])c34)c3c([2H])c([2H])c([2H])c([2H])c3c(-c3ccc(-c4ccc5ccccc5c4)cc3)c2c([2H])c1[2H]]

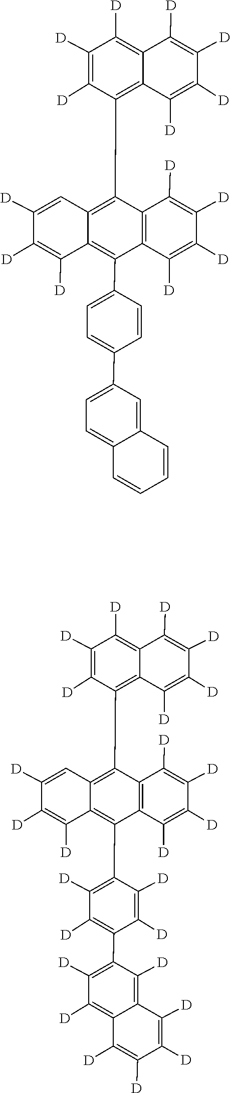 [SMILES: [2H]c1cc2c(-c3c([2H])c([2H])c([2H])c4c([2H])c([2H])c([2H])c([2H])c34)c3c([2H])c([2H])c([2H])c([2H])c3c(-c3ccc(-c4ccc5ccccc5c4)cc3)c2c([2H])c1[2H] ; [2H]c1cc2c(-c3c([2H])c([2H])c([2H])c4c([2H])c([2H])c([2H])c([2H])c34)c3c([2H])c([2H])c([2H])c([2H])c3c(-c3c([2H])c([2H])c(-c4c([2H])c([2H])c5c([2H])c([2H])c([2H])c([2H])c5c4[2H])c([2H])c3[2H])c2c([2H])c1[2H]]

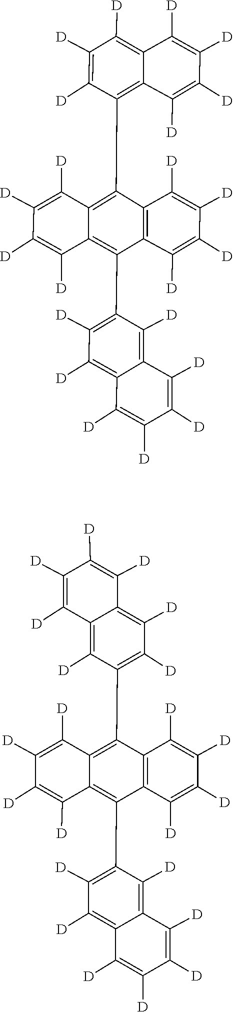 [SMILES: [2H]c1c([2H])c([2H])c2c([2H])c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c2c1[2H] ; [2H]c1c([2H])c([2H])c2c([2H])c(-c3c4c([2H])c([2H])c([2H])c([2H])c4c(-c4c([2H])c([2H])c5c([2H])c([2H])c([2H])c([2H])c5c4[2H])c4c([2H])c([2H])c([2H])c([2H])c34)c([2H])c([2H])c2c1[2H]]

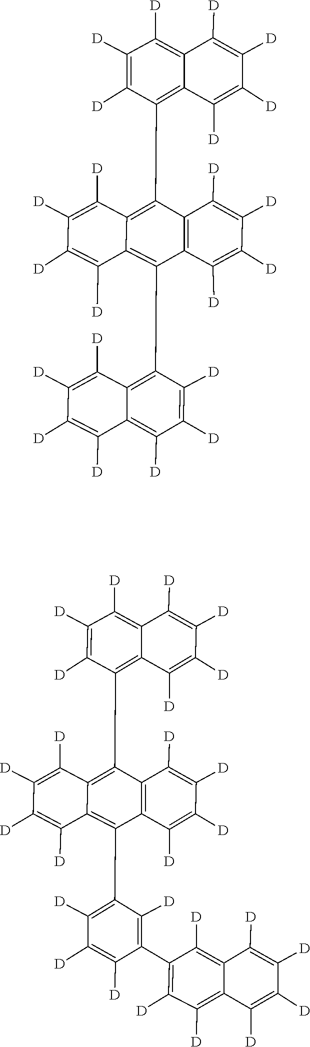 [SMILES: [2H]c1c([2H])c([2H])c2c(-c3c4c([2H])c([2H])c([2H])c([2H])c4c(-c4c([2H])c([2H])c([2H])c5c([2H])c([2H])c([2H])c([2H])c45)c4c([2H])c([2H])c([2H])c([2H])c34)c([2H])c([2H])c([2H])c2c1[2H] ; [2H]c1c([2H])c(-c2c([2H])c([2H])c3c([2H])c([2H])c([2H])c([2H])c3c2[2H])c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c1[2H]]

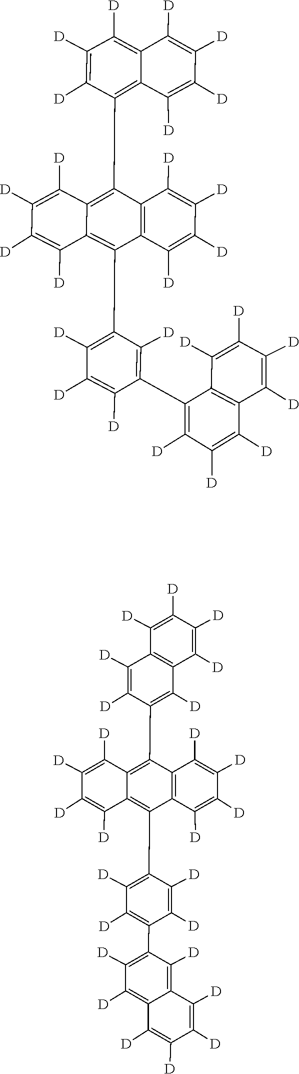 [SMILES: [2H]c1c([2H])c(-c2c([2H])c([2H])c([2H])c3c([2H])c([2H])c([2H])c([2H])c23)c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c1[2H] ; [2H]c1c([2H])c(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c([2H])c([2H])c1-c1c([2H])c([2H])c2c([2H])c([2H])c([2H])c([2H])c2c1[2H]]

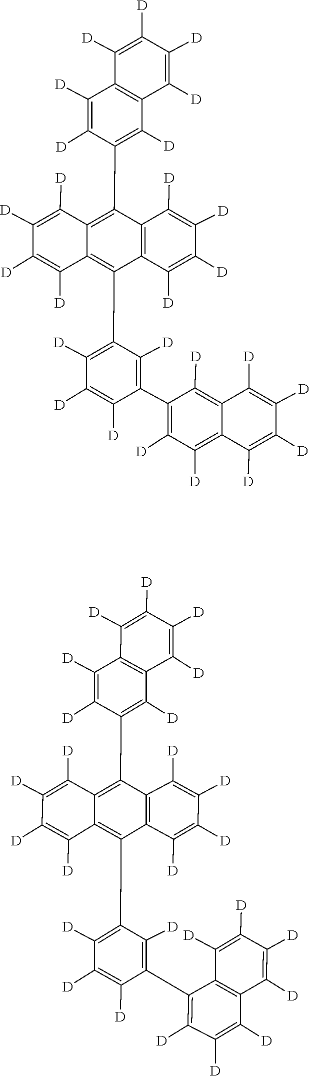 [SMILES: [2H]c1c([2H])c(-c2c([2H])c([2H])c3c([2H])c([2H])c([2H])c([2H])c3c2[2H])c([2H])c(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c1[2H] ; [2H]c1c([2H])c(-c2c([2H])c([2H])c([2H])c3c([2H])c([2H])c([2H])c([2H])c23)c([2H])c(-c2c3c([2H])c([2H])c([2H])c([2H])c3c(-c3c([2H])c([2H])c4c([2H])c([2H])c([2H])c([2H])c4c3[2H])c3c([2H])c([2H])c([2H])c([2H])c23)c1[2H]]

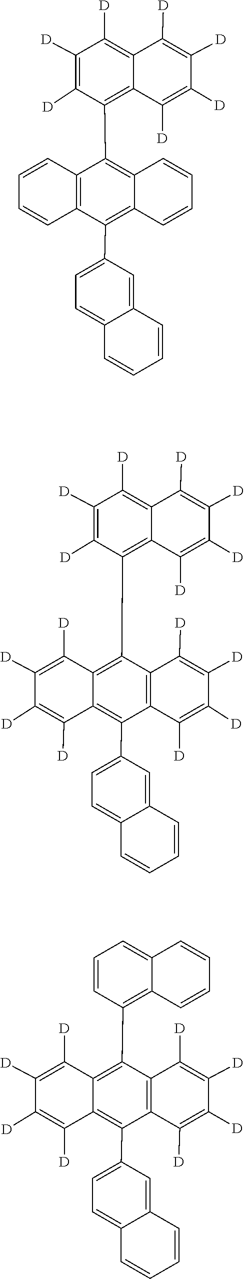 [SMILES: [2H]c1c([2H])c([2H])c2c(-c3c4ccccc4c(-c4ccc5ccccc5c4)c4ccccc34)c([2H])c([2H])c([2H])c2c1[2H] ; [2H]c1c([2H])c([2H])c2c(-c3c4c([2H])c([2H])c([2H])c([2H])c4c(-c4ccc5ccccc5c4)c4c([2H])c([2H])c([2H])c([2H])c34)c([2H])c([2H])c([2H])c2c1[2H] ; [2H]c1c([2H])c([2H])c2c(-c3cccc4ccccc34)c3c([2H])c([2H])c([2H])c([2H])c3c(-c3ccc4ccccc4c3)c2c1[2H]]

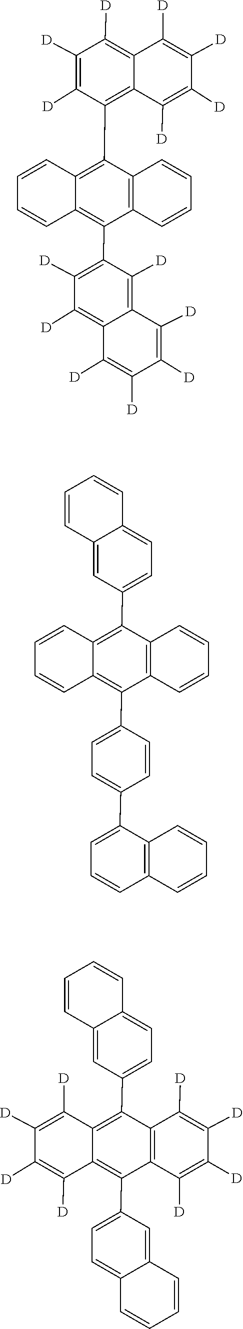

The organic light emitting device of the present specification may further include an organic material layer having one or more layers of a hole transport layer, a hole injection layer, an electron blocking layer, an electron injection and transport layer, an electron transport layer, an electron injection layer, a hole blocking layer, and a hole injection and transport layer.

In an exemplary embodiment of the present specification, the organic light emitting device may be a normal type organic light emitting device in which a positive electrode, an organic material layer having one or more layers, and a negative electrode are sequentially stacked on a substrate.

In an exemplary embodiment of the present specification, the organic light emitting device may be an inverted type organic light emitting device in which a negative electrode, one or more organic material layers, and a positive electrode are sequentially stacked on a substrate.

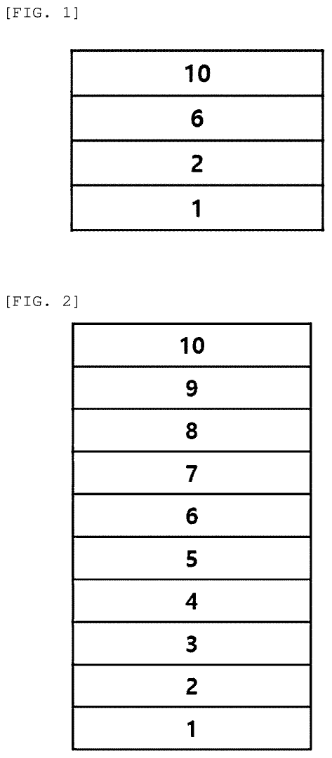

The structure of the organic light emitting device of the present specification may have a structure illustrated in FIGS. 1 and 2, but is not limited thereto.

FIG. 1 exemplifies the structure of an organic light emitting device in which a substrate 1, a positive electrode 2, a light emitting layer 6, and a negative electrode 10 are sequentially stacked. In the structure described above, the compound may be included in the light emitting layer 6.

FIG. 2 exemplifies the structure of an organic light emitting device in which a substrate 1, a positive electrode 2, a hole injection layer 3, a hole transport layer 4, an electron blocking layer 5, a light emitting layer 6, a first electron transport layer 7, a second electron transport layer 8, an electron injection layer 9 and a negative electrode 10 are sequentially stacked. In the structure described above, the compound may be included in any one of the hole injection layer 3, the hole transport layer 4, the electron blocking layer 5, the light emitting layer 6, the first electron transport layer 7, and the second electron transport layer 8, for example, the light emitting layer 6.

The organic light emitting device of the present specification may be manufactured by the materials and methods known in the art, except that one or more layers of the organic material layers include the compound, that is, the compound represented by Chemical Formula 1.

When the organic light emitting device includes a plurality of organic material layers, the organic material layer may be formed of the same material or different materials.

For example, the organic light emitting device according to the present specification may be manufactured by depositing a metal or a metal oxide having conductivity, or an alloy thereof on a substrate to form a positive electrode, forming an organic material layer including a hole injection layer, a hole transport layer, a light emitting layer, an electron blocking layer, an electron transport layer, and an electron injection layer thereon, and then depositing a material, which may be used as a negative electrode, thereon, by using a physical vapor deposition (PVD) method such as sputtering or e-beam evaporation. In addition to the method described above, an organic light emitting device may also be made by sequentially depositing a negative electrode material, an organic material layer, and a positive electrode material on a substrate.

The positive electrode is an electrode which injects holes, and as a positive electrode material, materials having a high work function are usually preferred so as to facilitate the injection of holes into an organic material layer. Specific examples of the positive electrode material capable of being used in the present disclosure include metals such as vanadium, chromium, copper, zinc and gold, or alloys thereof; metal oxides such as zinc oxide, indium oxide, indium tin oxide (ITO) and indium zinc oxide (IZO); combinations of metals and oxides such as ZnO:Al or SnO₂:Sb; conductive polymers such as poly(3-methylthiophene), poly[3,4-(ethylene-1,2-dioxy)thiophene] (PEDOT), polypyrrole and polyaniline, but are not limited thereto.

The negative electrode is an electrode injecting electrons, and as the negative electrode material, materials having small work function are normally preferred so that electron injection to an organic material layer is smooth. Specific examples of a negative electrode material include: a metal such as magnesium, calcium, sodium, potassium, titanium, indium, yttrium, lithium, gadolinium, aluminum, silver, tin, and lead, or an alloy thereof; a multi-layer structured material, such as LiF/Al or LiO₂/Al, and the like, but are not limited thereto.

The hole injection layer is a layer which serves to facilitate the injection of holes from a positive electrode to a light emitting layer, and a hole injection material is preferably a material which may proficiently accept holes from a positive electrode at a low voltage, and the highest occupied molecular orbital (HOMO) of the hole injection material is preferably a value between the work function of the positive electrode material and the HOMO of the neighboring organic material layer. Specific examples of the hole injection material include metal porphyrin, oligothiophene, arylamine-based organic materials, hexanitrile hexaazatriphenylene-based organic materials, quinacridone-based organic materials, perylene-based organic materials, anthraquinone, polyaniline-based and polythiophene-based conductive polymers, and the like, but are not limited thereto.

According to an exemplary embodiment of the present specification, the hole injection layer may include a compound represented by the following Chemical Formula HI-1, but is not limited thereto.

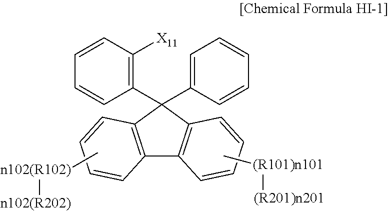

In Chemical Formula HI-1,
X11 is any one of NR301; O; and S,
R301 is hydrogen; deuterium; or a substituted or unsubstituted aryl group,
R101 and R102 are the same as or different from each other, and are each independently hydrogen; deuterium; a substituted or unsubstituted aryl group; or a substituted or unsubstituted heteroaryl group,
R201 and R202 are the same as or different from each other, and are each independently hydrogen; deuterium; a substituted or unsubstituted amine group; or a substituted or unsubstituted aryl group,
n101 and n102 are each an integer from 1 to 4, and when n101 and n102 are each 2 or higher, R101 and R102 are each the same as or different from each other, and
n201 and n202 are each an integer from 1 to 8, and when n201 and n202 are each 2 or higher, R201 and R202 are each the same as or different from each other.

In an exemplary embodiment of the present specification, X11 is NR301.

In an exemplary embodiment of the present specification, R301 is hydrogen; deuterium; a substituted or unsubstituted phenyl group; or a substituted or unsubstituted biphenyl group.

In an exemplary embodiment of the present specification, R301 is hydrogen; deuterium; or a substituted or unsubstituted phenyl group.

In an exemplary embodiment of the present specification, R101 and R102 are the same as or different from each other, and are each independently hydrogen; deuterium; or a substituted or unsubstituted heteroaryl group.

In an exemplary embodiment of the present specification, R101 and R102 are the same as or different from each other, and are each independently hydrogen; deuterium; a substituted or unsubstituted benzofuran group; a substituted or unsubstituted dibenzofuran group; a substituted or unsubstituted benzothiophene group; a substituted or unsubstituted dibenzothiophene group; or a substituted or unsubstituted carbazole group.

In an exemplary embodiment of the present specification, R101 and R102 are the same as or different from each other, and are each independently hydrogen; deuterium; or a carbazole group unsubstituted or substituted with deuterium.

In an exemplary embodiment of the present specification, R201 and R202 are the same as or different from each other, and are each independently hydrogen; deuterium; a substituted or unsubstituted C1 to C20 alkylamine group; a substituted or unsubstituted C6 to C20 arylamine group; or a substituted or unsubstituted C6 to C20 aryl group.

In an exemplary embodiment of the present specification, R201 and R202 are the same as or different from each other, and are each independently hydrogen; deuterium; or a C6 to C12 arylamine group unsubstituted or substituted with deuterium.

In an exemplary embodiment of the present specification, the hole injection layer may include the compound represented by Chemical Formula HI-1 and a hexanitrile hexaazatriphenylene-based organic material together.

In an exemplary embodiment of the present specification, the hexanitrile hexaazatriphenylene-based organic material included in the hole injection layer may be hexanitrile hexaazatriphenylene (HAT-CN) in which a nitrile group is substituted.

The hole transport layer may perform a role of smoothly transporting holes. A hole transport material is suitably a material having high hole mobility which may accept holes from a positive electrode or a hole injection layer and transfer the holes to a light emitting layer. Specific examples thereof include arylamine-based organic materials, conductive polymers, block copolymers having both conjugated portions and non-conjugated portions, and the like, but are not limited thereto.

In an exemplary embodiment of the present specification, the hole transport layer may include a compound represented by the following Chemical Formula HT-1, but is not limited thereto.

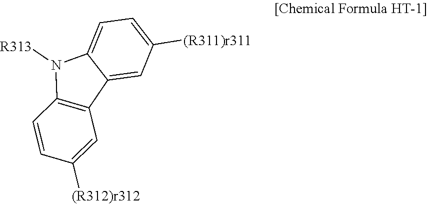

In Chemical Formula HT-1,
R311 to R313 are the same as or different from each other, and are each independently any one selected from the group consisting of hydrogen; deuterium; a substituted or unsubstituted amine group; a substituted or unsubstituted aryl group; a substituted or unsubstituted heteroaryl group; and a combination thereof,
r311 is an integer from 1 to 4, and when r311 is 2 or higher, two or more R311's are the same as or different from each other, and
r312 is an integer from 1 to 4, and when r312 is 2 or higher, two or more R312's are the same as or different from each other.

In an exemplary embodiment of the present specification, R311 may be hydrogen; deuterium; or a substituted or unsubstituted amine group.

In an exemplary embodiment of the present specification, R311 may be an amine group unsubstituted or substituted with one or more selected from the group consisting of hydrogen, deuterium, a phenyl group, a naphthyl group, a carbazole group, and a combination thereof.

In an exemplary embodiment of the present specification, R312 may be hydrogen; deuterium; or a substituted or unsubstituted heteroaryl group.

In an exemplary embodiment of the present specification, R312 may be hydrogen; deuterium; a substituted or unsubstituted dibenzofuranyl group; a substituted or unsubstituted dibenzothiophenyl group; or a substituted or unsubstituted carbazole group.

In an exemplary embodiment of the present specification, R312 may be a carbazole group.

In an exemplary embodiment of the present specification, R313 may be hydrogen; deuterium; or a substituted or unsubstituted aryl group.

In an exemplary embodiment of the present specification, R313 may be hydrogen; deuterium; a substituted or unsubstituted phenyl group or a substituted or unsubstituted naphthyl group.

In an exemplary embodiment of the present specification, R313 may be a phenyl group.

An electron blocking layer may be provided between the hole transport layer and the light emitting layer. The electron blocking layer is a layer which may improve the service life and efficiency of a device by preventing electrons injected from an electron injection layer from passing through a light emitting layer and entering a hole injection layer. The electron blocking layer may be formed between the light emitting layer and the hole injection layer, between the light emitting layer and the hole transport layer, or between the light emitting layer and the layer which injects and transports holes simultaneously, and known materials can be used without limitation.

In an exemplary embodiment of the present specification, the hole blocking material may include a compound represented by the following Chemical Formula HT-2, but is not limited thereto.

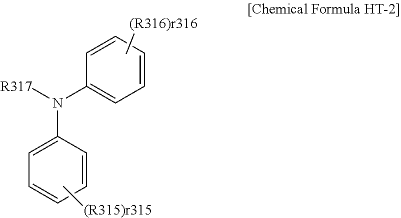

In Chemical Formula HT-2,
R315 to R317 are the same as or different from each other, and are each independently any one selected from the group consisting of hydrogen; deuterium; a substituted or unsubstituted amine group; a substituted or unsubstituted aryl group; a substituted or unsubstituted heteroaryl group; and a combination thereof, or are bonded to an adjacent group to form a substituted or unsubstituted ring,
r315 is an integer from 1 to 5, and when r315 is 2 or higher, two or more R315's are the same as or different from each other, and
r316 is an integer from 1 to 5, and when r316 is 2 or higher, two or more R316's are the same as or different from each other.

In an exemplary embodiment of the present specification, R317 may be any one selected from the group consisting of a substituted or unsubstituted aryl group; a substituted or unsubstituted heteroaryl group; and a combination thereof.

In an exemplary embodiment of the present specification, R317 may be any one selected from the group consisting of a substituted or unsubstituted carbazole group; a substituted or unsubstituted phenyl group; a substituted or unsubstituted biphenyl group; a substituted or unsubstituted triphenylene group; and a combination thereof.

In an exemplary embodiment of the present specification, R317 may be a biphenyl group unsubstituted or substituted with one or more selected from the group consisting of hydrogen, deuterium, a phenyl group, and a carbazole group.

In an exemplary embodiment of the present specification, R315 and R316 are the same as or different from each other, and are each independently a substituted or unsubstituted amine group; or a substituted or unsubstituted aryl group, or may be bonded to an adjacent group to form a substituted or unsubstituted ring.

In an exemplary embodiment of the present specification, R315 and R316 are the same as or different from each other, and may be each independently a substituted or unsubstituted phenyl group; a substituted or unsubstituted alkylamine group; or a substituted or unsubstituted arylamine group.

In an exemplary embodiment of the present specification, R315 may be a phenyl group.

In an exemplary embodiment of the present specification, R316 may be a diphenylamine group.

The light emitting layer may emit red, green, or blue light, and may be composed of a phosphorescent material or a fluorescent material. The light emitting material is a material which may accept holes and electrons from a hole transport layer and an electron transport layer, respectively, and combine the holes and the electrons to emit light in a visible ray region, and is preferably a material having high quantum efficiency to fluorescence or phosphorescence. The above-described compound of Chemical Formula 1 may be used as a material for the light emitting layer, and specific examples thereof include: 8-hydroxy-quinoline aluminum complexes (Alq₃); carbazole-based compounds; dimerized styryl compounds; BAlq; 10-hydroxybenzoquinoline-metal compounds; benzoxazole-based, benzothiazole-based and benzimidazole-based compounds; poly(p-phenylenevinylene) (PPV)-based polymers; spiro compounds; polyfluorene; rubrene; and the like, but are not limited thereto. Examples of the host material for a light emitting layer include a fused aromatic ring derivative, a hetero ring-containing compound, or the like. Specifically, examples of the fused aromatic ring derivatives include anthracene derivatives, pyrene derivatives, naphthalene derivatives, pentacene derivatives, phenanthrene compounds, fluoranthene compounds, and the like, and examples of the hetero ring-containing compounds include carbazole derivatives, dibenzofuran derivatives, ladder-type furan compounds, pyrimidine derivatives, and the like, but the examples thereof are not limited thereto.

When the light emitting layer emits red light, phosphorescent materials such as bis(1-phenylisoquinoline)acetylacetonate iridium (PIQIr(acac)), bis(1-phenylquinoline)acetylacetonate iridium (PQIr(acac)), tris(1-phenylquinoline)iridium (PQIr) or octaethylporphyrin platinum (PtOEP), or fluorescent materials such as tris(8-hydroxyquinolino)aluminum (Alq₃) may be used as the light emitting dopant, however, the light emitting dopant is not limited thereto. When the light emitting layer emits green light, it is possible to use a phosphorescent material such as fac tris(2-phenylpyridine)iridium (Ir(ppy)₃), or a fluorescent material such as tris(8-hydroxyquinolino)aluminum (Alq₃), as the light emitting dopant, but the light emitting dopant is not limited thereto. When the light emitting layer emits blue light, phosphorescent materials such as (4,6-F2ppy)₂Irpic, or fluorescent materials such as spiro-DPVBi, spiro-6P, distyrylbenzene (DSB), distyrylarylene (DSA), PFO-based polymers or PPV-based polymers may be used as the light emitting dopant, however, the light emitting dopant is not limited thereto.

A hole blocking layer may be provided between the electron transport layer and the light emitting layer, and materials known in the art may be used.

The electron transport layer may perform a role of smoothly transporting electrons. As the electron transport material, materials capable of favorably receiving electrons from a negative electrode, moving the electrons to a light emitting layer, and having high mobility for the electrons are suited. Specific examples thereof include: Al complexes of the above-described compound or 8-hydroxyquinoline; complexes including Alq₃; organic radical compounds; hydroxyflavone-metal complexes; and the like, but are not limited thereto.

In an exemplary embodiment of the present specification, the electron transport material may include a compound represented by the following Chemical Formula ET-1 or Chemical Formula ET-2, but is not limited thereto.

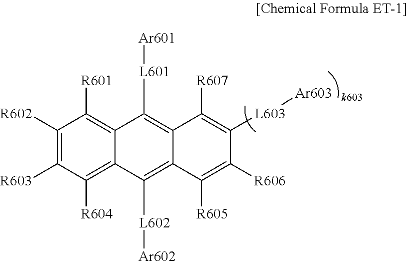

In Chemical Formula ET-1,
R601 to R607 are the same as or different from each other, and are each independently hydrogen; or deuterium,
L601 to L603 are the same as or different from each other, and are each independently a direct bond; or a substituted or unsubstituted arylene group,
Ar601 to Ar603 are the same as or different from each other, and are each independently a substituted or unsubstituted aryl group; or a substituted or unsubstituted heteroaryl group, and
k603 is 0 or 1.

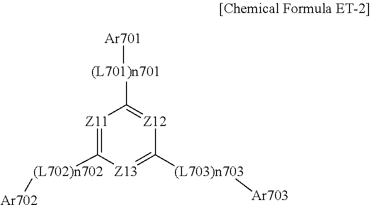

In Chemical Formula ET-2,
Z11 to Z13 are the same as or different from each other, and are each independently N or CH,
L701 to L703 are the same as or different from each other, and are each independently a direct bond; or a substituted or unsubstituted arylene group,
Ar701 to Ar703 are the same as or different from each other, and are each independently a substituted or unsubstituted aryl group; or a substituted or unsubstituted heteroaryl group, and
n701 to n703 are each an integer from 0 to 2, and when n701 to n703 are each 2, L701 to L703 are the same as or different from each other.

In an exemplary embodiment of the present specification, R601 to R607 are all hydrogen or all deuterium.

In an exemplary embodiment of the present specification, L601 to L603 are the same as or different from each other, and are each independently a direct bond; or a substituted or unsubstituted phenylene group.

In an exemplary embodiment of the present specification, Ar601 and Ar602 are the same as or different from each other, and are each independently a substituted or unsubstituted phenyl group; a substituted or unsubstituted biphenyl group; or a substituted or unsubstituted naphthyl group.

In an exemplary embodiment of the present specification, Ar601 and Ar602 are the same as or different from each other, and are each independently a substituted or unsubstituted phenyl group; or a substituted or unsubstituted naphthyl group.

In an exemplary embodiment of the present specification, Ar603 is a substituted or unsubstituted heteroaryl group.

In an exemplary embodiment of the present specification, Ar603 is a benzimidazole group unsubstituted or substituted with one or more selected from the group consisting of hydrogen, deuterium, and a phenyl group.

In an exemplary embodiment of the present specification, Z11 to Z13 are all N.

In an exemplary embodiment of the present specification, L701 to L703 are the same as or different from each other, and are each independently a direct bond; a substituted or unsubstituted phenylene group; or a substituted or unsubstituted biphenylene group.

In an exemplary embodiment of the present specification, Ar701 to Ar703 are the same as or different from each other, and are each independently a substituted or unsubstituted phenyl group; or a substituted or unsubstituted carbazole group.

In an exemplary embodiment of the present specification, the electron transport layer may include a first electron transport layer and a second electron transport layer, and at least one of the first electron transport layer and the second electron transport layer may include the compound represented by Chemical Formula ET-1 or Chemical Formula ET-2.

In an exemplary embodiment of the present specification, the electron transport layer may include a first electron transport layer and a second electron transport layer, and the first electron transport layer may include the compound represented by Chemical Formula ET-1.

In an exemplary embodiment of the present specification, the electron transport layer may include a first electron transport layer and a second electron transport layer, and the second electron transport layer may include the compound represented by Chemical Formula ET-1.

In an exemplary embodiment of the present specification, the electron transport layer may include a first electron transport layer and a second electron transport layer, and the second electron transport layer may include the compound represented by Chemical Formula ET-1 and may further include lithium quinolate (Liq).

In an exemplary embodiment of the present specification, the electron transport layer may include a first electron transport layer and a second electron transport layer, and the second electron transport layer may include the compound represented by Chemical Formula ET-1 and lithium quinolate (Liq), and may include the compound represented by Chemical Formula ET-1 and lithium quinolate (Liq) at a weight ratio of 1:1.

In an exemplary embodiment of the present specification, the electron transport layer may include a first electron transport layer and a second electron transport layer, and in this case, the first electron transport layer may be provided between the light emitting layer and the second electron transport layer.

The electron injection layer may perform a role of smoothly injecting electrons. An electron injection material is preferably a compound which has a capability of transporting electrons, an effect of injecting electrons from a negative electrode, and an excellent effect of injecting electrons into a light emitting layer or a light emitting material, prevents excitons produced from a light emitting layer from moving to a hole injection layer, and is also excellent in the ability to form a thin film. Specific examples thereof include fluorenone, anthraquinodimethane, diphenoquinone, thiopyran dioxide, oxazole, oxadiazole, triazole, imidazole, perylene tetracarboxylic acid, fluorenylidene methane, anthrone or the like, and derivatives thereof, metal complex compounds, nitrogen-containing 5-membered ring derivatives, and the like, but are not limited thereto.

The metal complex compound includes 8-hydroxyquinolinato lithium, bis(8-hydroxyquinolinato)zinc, bis(8-hydroxyquinolinato)copper, bis(8-hydroxyquinolinato)manganese, tris(8-hydroxyquinolinato)aluminum, tris(2-methyl-8-hydroxyquinolinato)aluminum, tris(8-hydroxyquinolinato)gallium, bis(10-hydroxybenzo[h]quinolinato)beryllium, bis(10-hydroxybenzo[h]quinolinato)zinc, bis(2-methyl-8-quinolinato)chlorogallium, bis(2-methyl-8-quinolinato) (o-cresolato)gallium, bis(2-methyl-8-quinolinato) (1-naphtholato)aluminum, bis(2-methyl-8-quinolinato) (2-naphtholato)gallium and the like, but is not limited thereto.

In an exemplary embodiment of the present specification, the electron injection material may include lithium quinolate (Liq), but is not limited thereto.

The hole blocking layer is a layer which blocks holes from reaching a negative electrode, and may be generally formed under the same conditions as those of the hole injection layer. Specific examples thereof include oxadiazole derivatives or triazole derivatives, phenanthroline derivatives, BCP, aluminum complexes, and the like, but are not limited thereto.

The organic light emitting device according to the present disclosure may be a top-emission type, a bottom-emission type or a dual-emission type depending on the materials used.

### EXAMPLES

Hereinafter, the present specification will be described in detail with reference to Examples for specifically describing the present specification. However, the Examples according to the present specification may be modified in various forms, and it is not interpreted that the scope of the present application is limited to the Examples described in detail below. The Examples of the present application are provided to explain the present specification more completely to a person with ordinary skill in the art.

### Preparation Examples of Compound 1 (F-1)

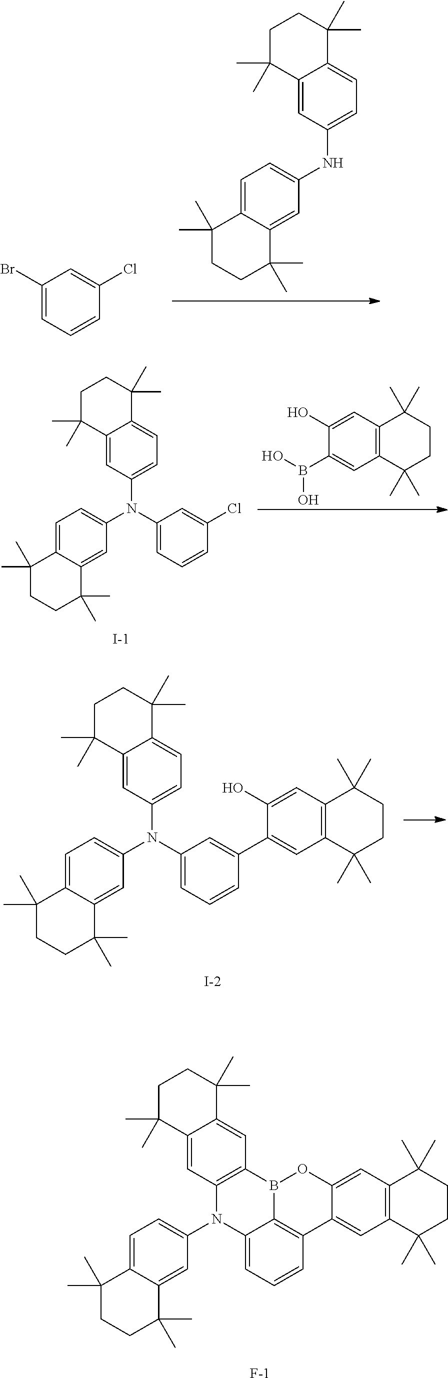

### Synthesis of I-1

After 30 g of 1-bromo-3-chlorobenzene, 61 g of bis(5,5,8,8-tetramethyl-5,6,7,8-tetrahydronaphthalen-2-yl)amine, 1.6 g of [bis(tri-tert-butylphosphine)palladium(0)], 30 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 57 g of I-1. (Yield 73%, Mass [M+]=501)

### Synthesis of I-2

After 25 g of I-1, 12.5 g of (3-hydroxy-5,5,8,8-tetramethyl-5,6,7,8-tetrahydronaphthalen-2-yl)boronic acid, 21 g of K₂CO₃, 0.5 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 26 g of I-2. (Yield 72%, Mass [M+]=669)

### Synthesis of F-1

After 20 g of I-2, 20 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.5 g of F-1. (Yield 37%, Mass [M+]=677)

### Preparation Examples of Compound 2 (F-2)

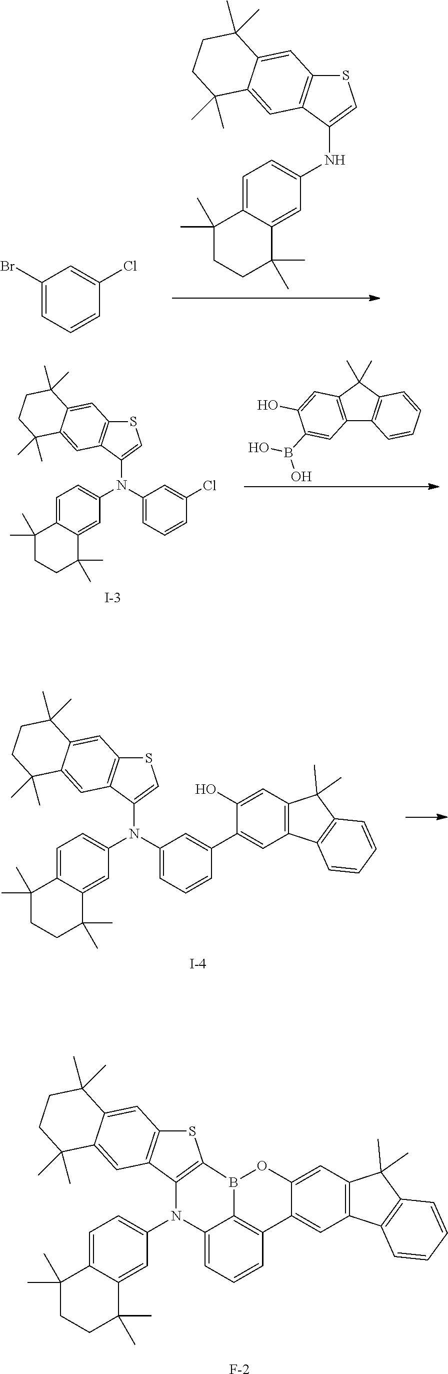

### Synthesis of I-3

After 30 g of 1-bromo-3-chlorobenzene, 70 g of 5,5,8,8-tetramethyl-N-(5,5,8,8-tetramethyl-5,6,7,8-tetrahydronaphthalen-2-yl)-5,6,7,8-tetrahydronaphtho[2,3-b]thiophene-3-amine, 1.6 g of [bis(tri-tert-butylphosphine)palladium(0)], 30 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 62 g of I-3. (Yield 71%, Mass [M+]=557)

### Synthesis of I-4

After 25 g of I-3, 11.4 g of (2-hydroxy-9,9-dimethyl-9H-fluoren-3-yl)boronic acid, 19 g of K₂CO₃, 0.5 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the residue in toluene, followed by treatment with MgSO₄ (anhydrous) and filtration. The filtered solution was recrystallized to obtain 23 g of I-4. (Yield 70%, Mass [M+]=731)

### Synthesis of F-2

After 20 g of I-4, 18.2 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.2 g of F-2. (Yield 36%, Mass [M+]=739)

### Preparation Examples of Compound 3 (F-3)

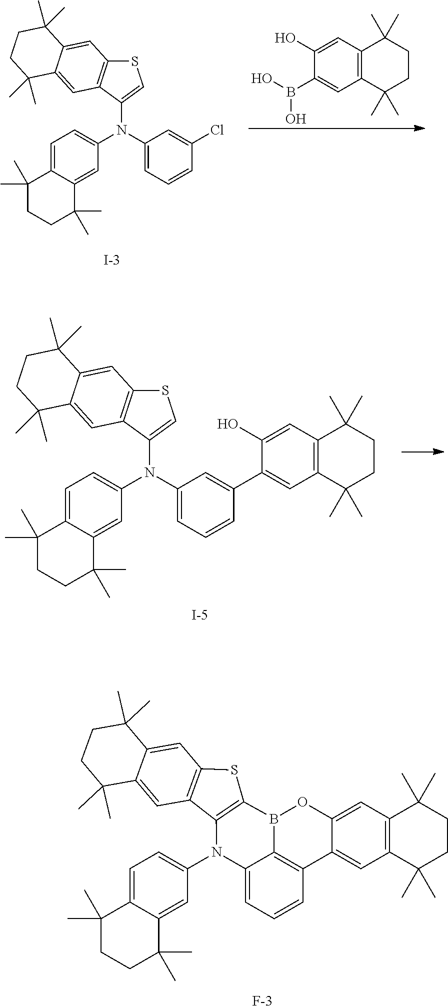

### Synthesis of I-5

After 25 g of I-3, 11.2 g of (3-hydroxy-5,5,8,8-tetramethyl-5,6,7,8-tetrahydronaphthalen-2-yl)boronic acid, 19 g of K₂CO₃, 0.5 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the residue in toluene, followed by treatment with MgSO₄ (anhydrous) and filtration. The filtered solution was recrystallized to obtain 25 g of I-5. (Yield 77%, Mass [M+]=725)

### Synthesis of F-3

After 20 g of I-5, 18.4 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.3 g of F-3. (Yield 36%, Mass [M+]=733)

### Preparation Examples of Compound 4 (F-4)

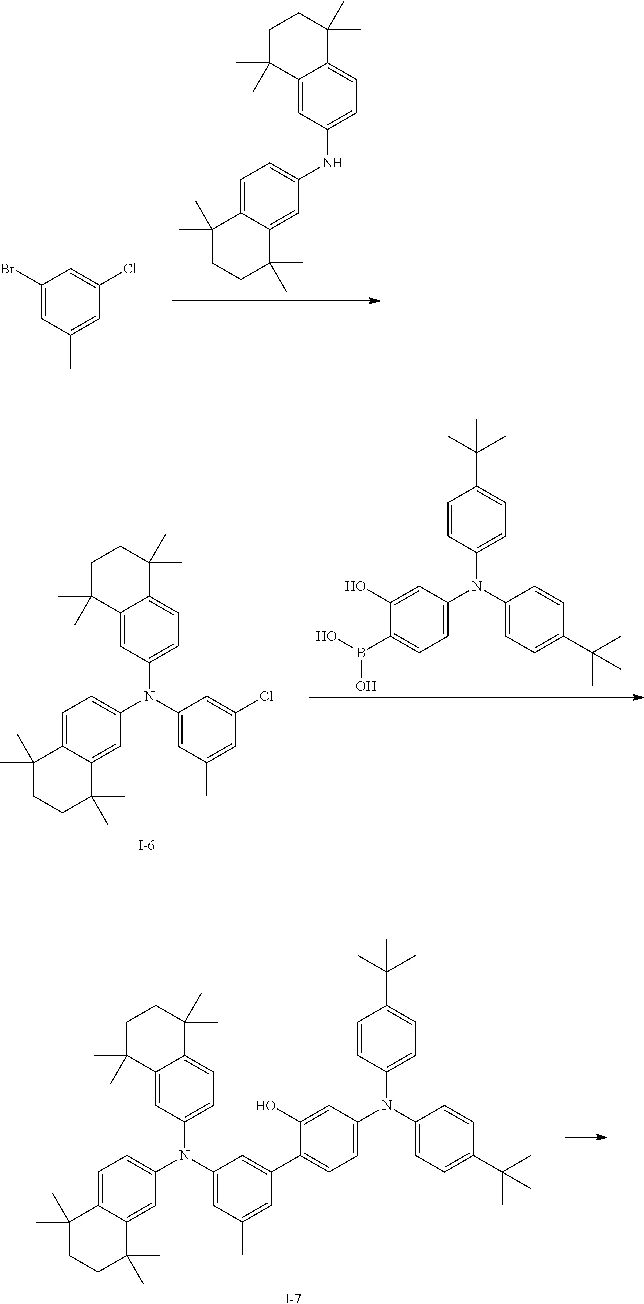

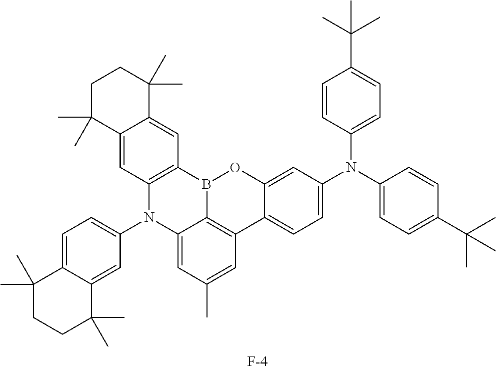

### Synthesis of I-6

After 30 g of 1-bromo-3-chloro-5-methylbenzene, 65 g of bis(5,5,8,8-tetramethyl-5,6,7,8-tetrahydronaphthalen-2-yl)amine, 1.5 g of [bis(tri-tert-butylphosphine)palladium(0)], 28 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 55 g of I-6. (Yield 73%, Mass [M+]=515)

### Synthesis of I-7

After 25 g of 1-6, 20.3 g of (4-(bis(4-(tert-butyl)phenyl)amino)-2-hydroxyphenyl)boronic acid, 21 g of K₂CO₃, 0.5 g of [bis(tri-tert-butylphosphine)palladium(0)], 500 mL of tetrahydrofuran, and 250 mL of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 30 g of I-7. (Yield 72%, Mass [M+]=852)

### Synthesis of F-4

After 20 g of I-7, 15.6 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.4 g of F-4. (Yield 37%, Mass [M+]=860)

### Preparation Examples of Compound 5 (F-5)

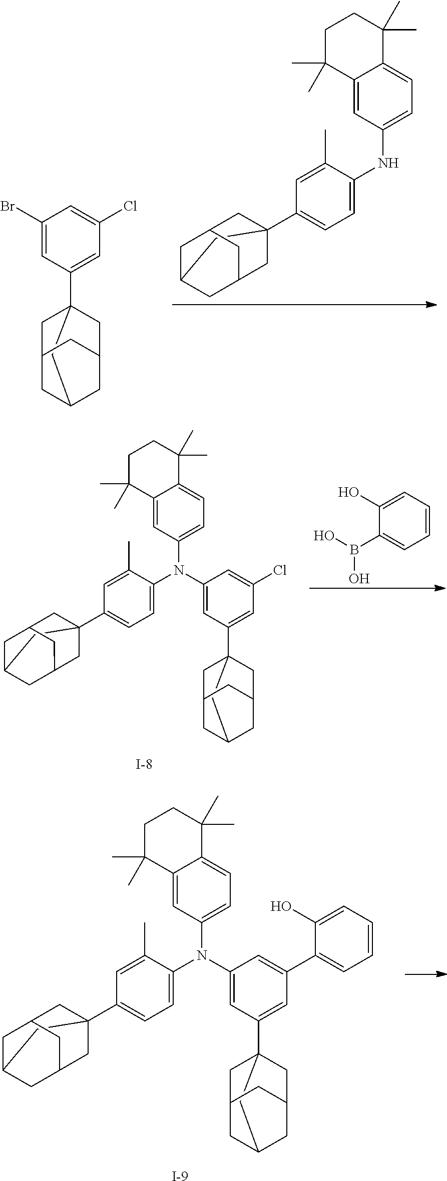

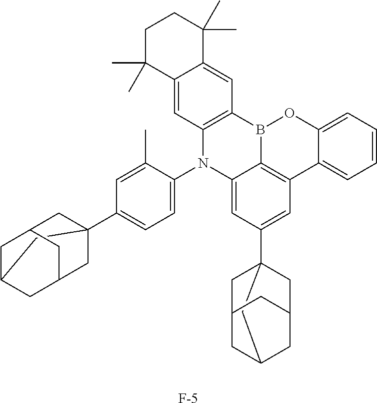

### Synthesis of I-8

After 30 g of 1-(3-bromo-5-chlorophenyl)adamantane, 40 g of N-(4-(adamantan-1-yl)-2-methylphenyl)-5,5,8,8-tetramethyl-5,6,7,8-tetrahydronaphthalen-2-amine, 0.9 g of [bis(tri-tert-butylphosphine)palladium(0)], 18 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 46 g of I-8. (Yield 74%, Mass [M+]=673)

### Synthesis of I-9

After 25 g of 1-8, 5.2 g of (2-hydroxyphenyl)boronic acid, 16 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 21 g of I-9. (Yield 77%, Mass [M+]=731)

### Synthesis of F-5

After 20 g of I-9, 18.3 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.5 g of F-5. (Yield 37%, Mass [M+]=739)

### Preparation Examples of Compound 6 (F-6)

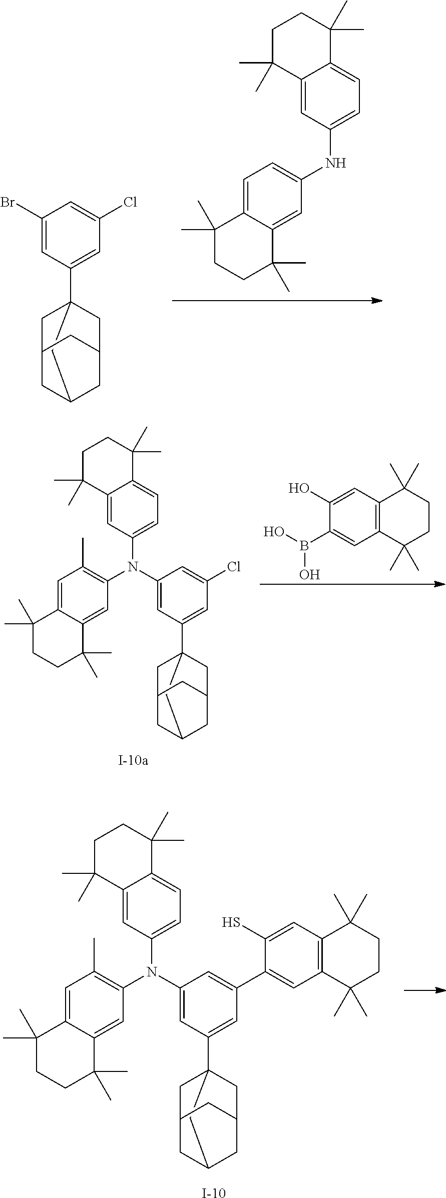

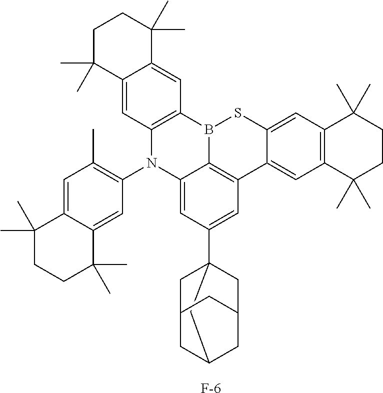

### Synthesis of I-10a

After 30 g of 1-(3-bromo-5-chlorophenyl) adamantane, 37.2 g of bis(5,5,8,8-tetramethyl-5,6,7,8-tetrahydronaphthalen-2-yl)amine, 0.9 g of [bis(tri-tert-butylphosphine)palladium(0)], 18 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 43 g of I-10a. (Yield 72%, Mass [M+]=649)

### Synthesis of I-10

After 25 g of I-10a, 9.9 g of (3-mercapto-5,5,8,8-tetramethyl-5,6,7,8-tetrahydronaphthalen-2-yl)boronic acid, 16 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 23 g of I-10. (Yield 74%, Mass [M+]=833)

### Synthesis of F-6

After 20 g of I-10, 16 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.4 g of F-6. (Yield 37%, Mass [M+]=841)

### Preparation Examples of Compound 7 (F-7)

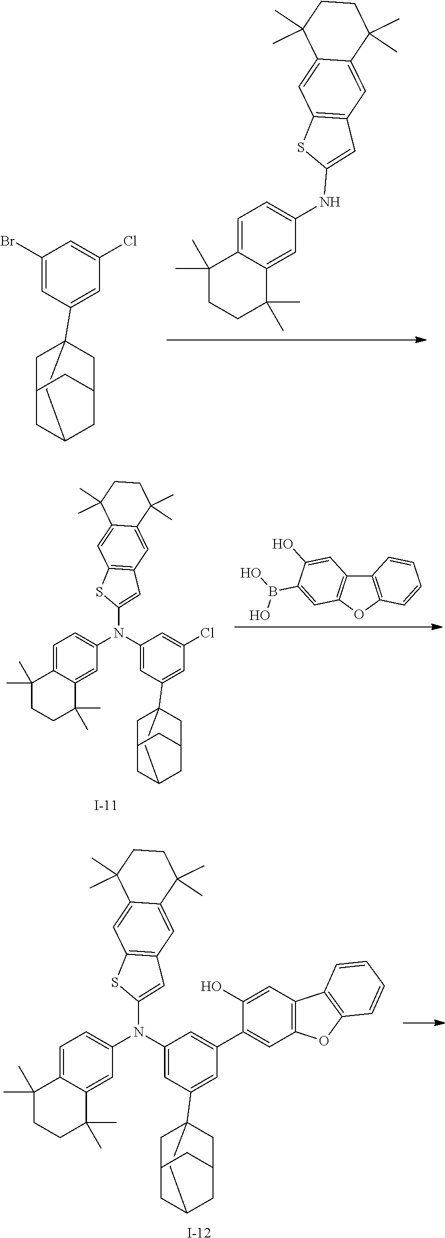

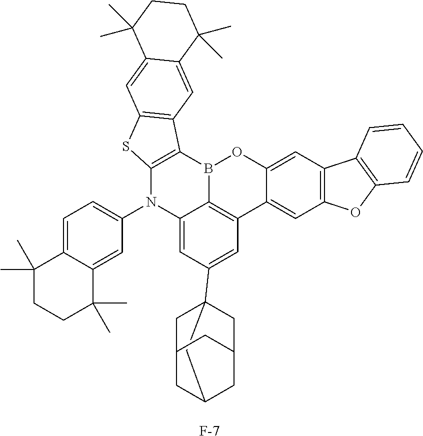

### Synthesis of I-11

After 30 g of 1-(3-bromo-5-chlorophenyl)adamantane, 41.1 g of 5,5,8,8-tetramethyl-N-(5,5,8,8-tetramethyl-5,6,7,8-tetrahydronaphthalen-2-yl)-5,6,7,8-tetrahydronaphtho[2,3-b]thiophene-2-amine, 0.9 g of [bis(tri-tert-butylphosphine)palladium(0)], 18 g of sodium-tert-butoxide, and 600 ml of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 45 g of I-11. (Yield 71%, Mass [M+]=691)

### Synthesis of I-12

After 25 g of I-11, 8.3 g of (2-hydroxydibenzo[b,d]furan-3-yl)boronic acid, 15 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 23 g of I-12. (Yield 76%, Mass [M+]=833)

### Synthesis of F-7

After 20 g of 1-12, 16 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.3 g of F-7. (Yield 36%, Mass [M+]=847)

### Preparation Examples of Compound 8 (F-8)

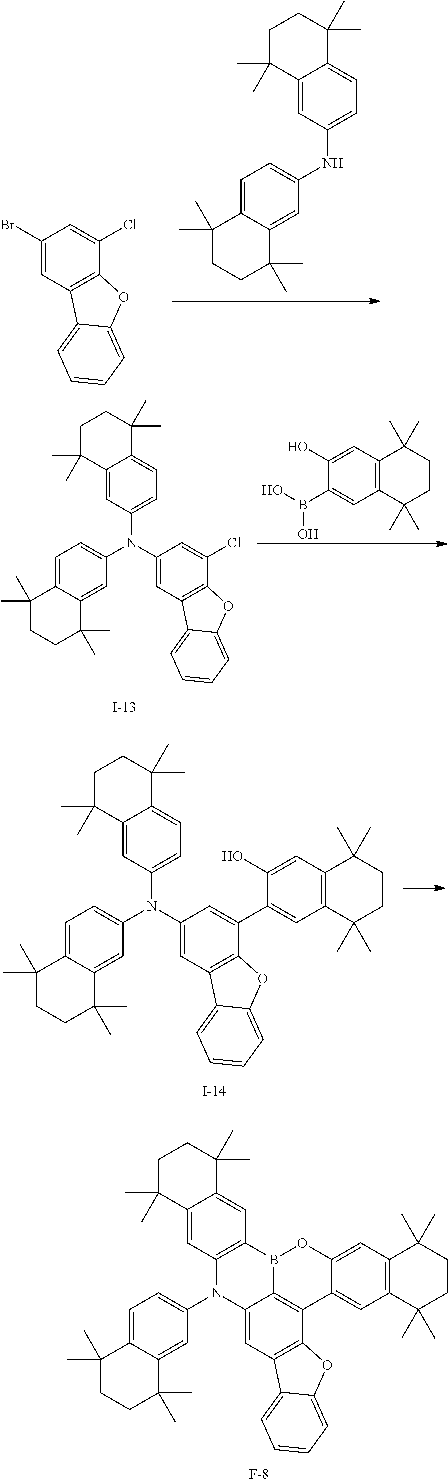

### Synthesis of I-13

After 30 g of 2-bromo-4-chlorodibenzo[b,d]furan, 41.5 g of bis(5,5,8,8-tetramethyl-5,6,7,8-tetrahydronaphthalen-2-yl)amine, 1 g of [bis(tri-tert-butylphosphine)palladium(0)], 21 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 46 g of I-13. (Yield 73%, Mass [M+]=591)

### Synthesis of I-14

After 25 g of I-13, 10.5 g of (3-hydroxy-5,5,8,8-tetramethyl-5,6,7,8-tetrahydronaphthalen-2-yl)boronic acid, 18 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 24 g of I-14. (Yield 75%, Mass [M+]=759)

### Synthesis of F-8

After 20 g of I-14, 18 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.4 g of F-8. (Yield 37%, Mass [M+]=767)

### Preparation Examples of Compound 9 (F-9)

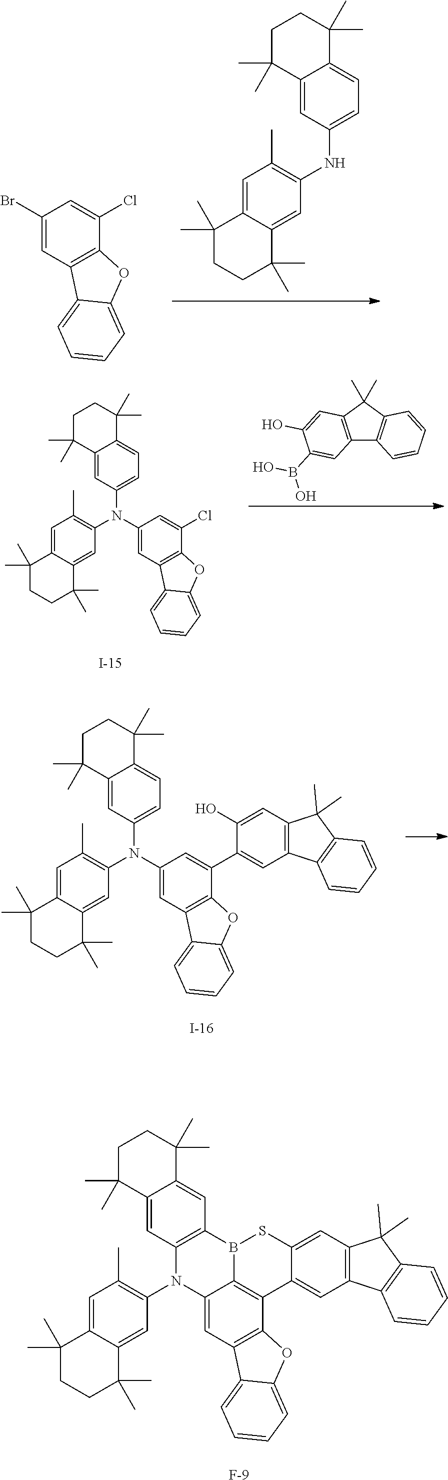

### Synthesis of I-15

After 30 g of 2-bromo-4-chlorodibenzo[b,d]furan, 43 g of 3,5,5,8,8-pentamethyl-N-(5,5,8,8-tetramethyl-5,6,7,8-tetrahydronaphthalen-2-yl)-5,6,7,8-tetrahydronaphthalen-2-amine, 1 g of [bis(tri-tert-butylphosphine)palladium(0)], 21 g of sodium-tert-butoxide, and 600 ml of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 46 g of I-15. (Yield 71%, Mass [M+]=605)

### Synthesis of I-16

After 25 g of I-15, 11.2 g of (2-mercapto-9,9-dimethyl-9H-fluoren-3-yl)boronic acid, 18 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 25 g of I-16. (Yield 76%, Mass [M+]=795)

### Synthesis of F-9

20 g of I-16, 17 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.3 g of F-9. (Yield 36%, Mass [M+]=803)

### Preparation Examples of Compound 10 (F-10)

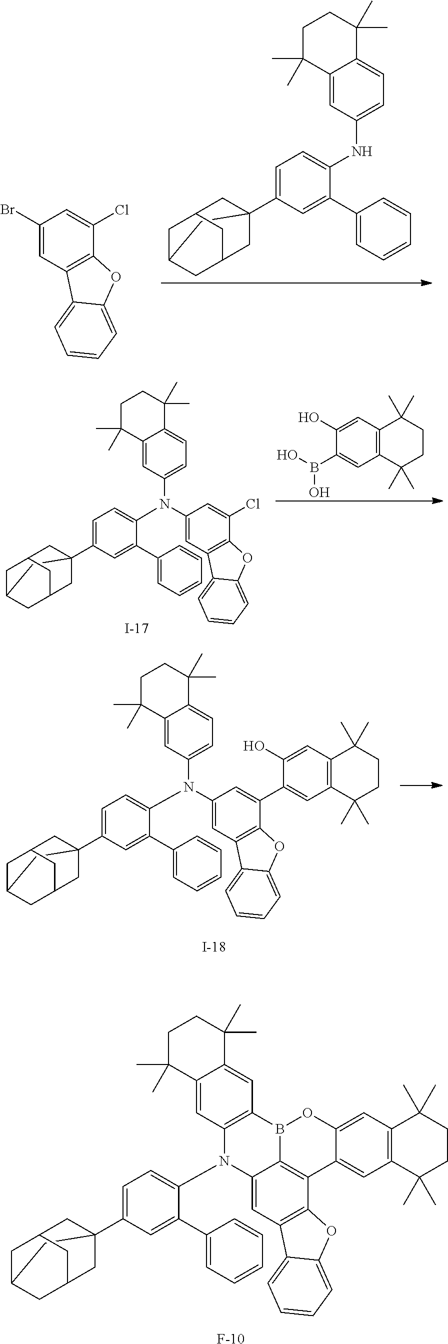

### Synthesis of I-17

After 30 g of 2-bromo-4-chlorodibenzo[b,d]furan, 52 g of N-(5-(adamantan-1-yl)-[1,1′-biphenyl]-2-yl)-5,5,8,8-tetramethyl-5,6,7,8-tetrahydronaphthalen-2-amine, 1 g of [bis(tri-tert-butylphosphine)palladium(0)], 21 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 52 g of I-17. (Yield 71%, Mass [M+]=691)

### Synthesis of I-18

After 25 g of 1-17, 9 g of (3-hydroxy-5,5,8,8-tetramethyl-5,6,7,8-tetrahydronaphthalen-2-yl)boronic acid, 15 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 24 g of I-18. (Yield 77%, Mass [M+]=860)

### Synthesis of F-10

After 20 g of I-18, 15.5 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.4 g of F-10. (Yield 37%, Mass [M+]=867)

### Preparation Examples of Compound 11 (F-11)

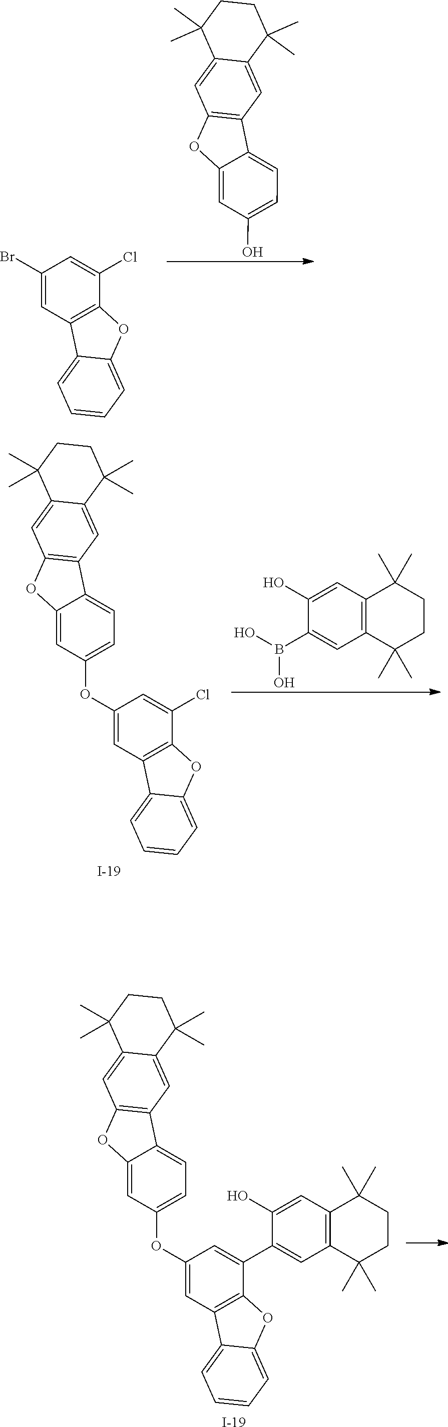

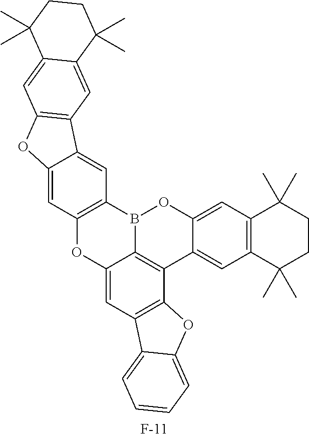

### Synthesis of I-19

After 30 g of 2-bromo-4-chlorodibenzo[b,d]furan, 31.4 g of 7,7,10,10-tetramethyl-7,8,9,10-tetrahydronaphtho[2,3-b]benzofuran-3-ol, 1 g of [bis(tri-tert-butylphosphine)palladium(0)], 21 g of sodium-tert-butoxide, and 600 ml of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 38 g of I-19. (Yield 72%, Mass [M+]=496)

### Synthesis of I-20

After 25 g of 1-19, 12.5 g of (3-hydroxy-5,5,8,8-tetramethyl-5,6,7,8-tetrahydronaphthalen-2-yl)boronic acid, 21 g of K₂CO₃, 0.5 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 25 g of I-20. (Yield 75%, Mass [M+]=664)

### Synthesis of F-11

After 20 g of 1-20, 20 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.3 g of F-11. (Yield 36%, Mass [M+]=672)

### Preparation Examples of Compound 12 (F-12)

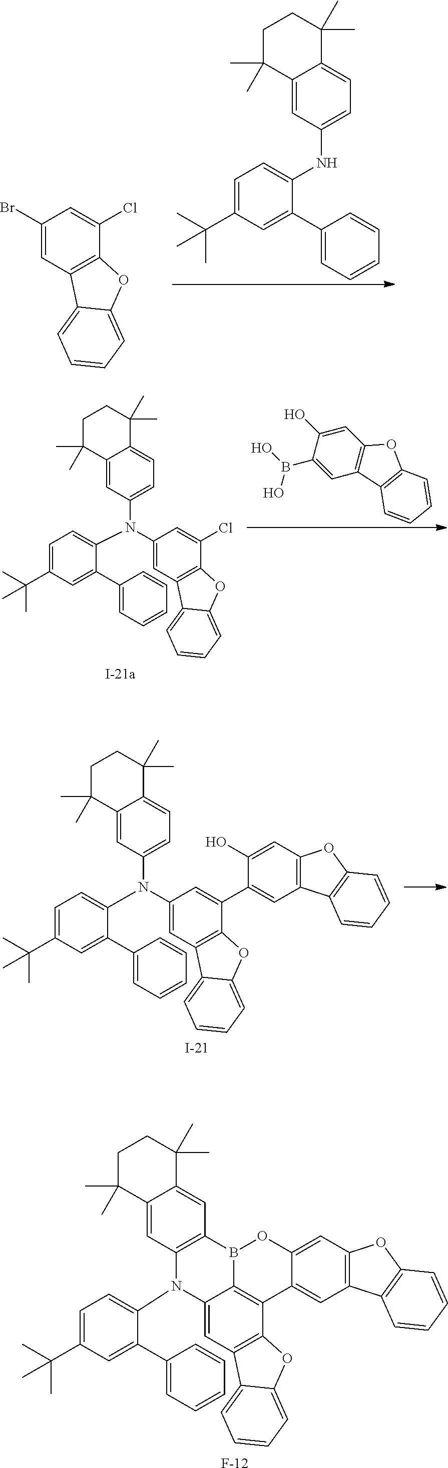

### Synthesis of I-21a

After 30 g of 2-bromo-4-chlorodibenzo[b,d]furan, 43.9 g of N-(5-(tert-butyl)-[1,1′-biphenyl]-2-yl)-5,5,8,8-tetramethyl-5,6,7,8-tetrahydronaphthalen-2-amine, 1.1 g of [bis(tri-tert-butylphosphine)palladium(0)], 20.5 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 50 g of I-21a. (Yield 77%, Mass [M+]=613)

### Synthesis of I-21

After 25 g of I-21a, 9.4 g of (3-hydroxydibenzo[b,d]furan-2-yl)boronic acid, 17 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 23 g of I-21. (Yield 74%, Mass [M+]=761)

### Synthesis of F-12

After 20 g of I-21, 17.5 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.4 g of F-12. (Yield 37%, Mass [M+]=769)

### Preparation Examples of Compound 13 (F-13)

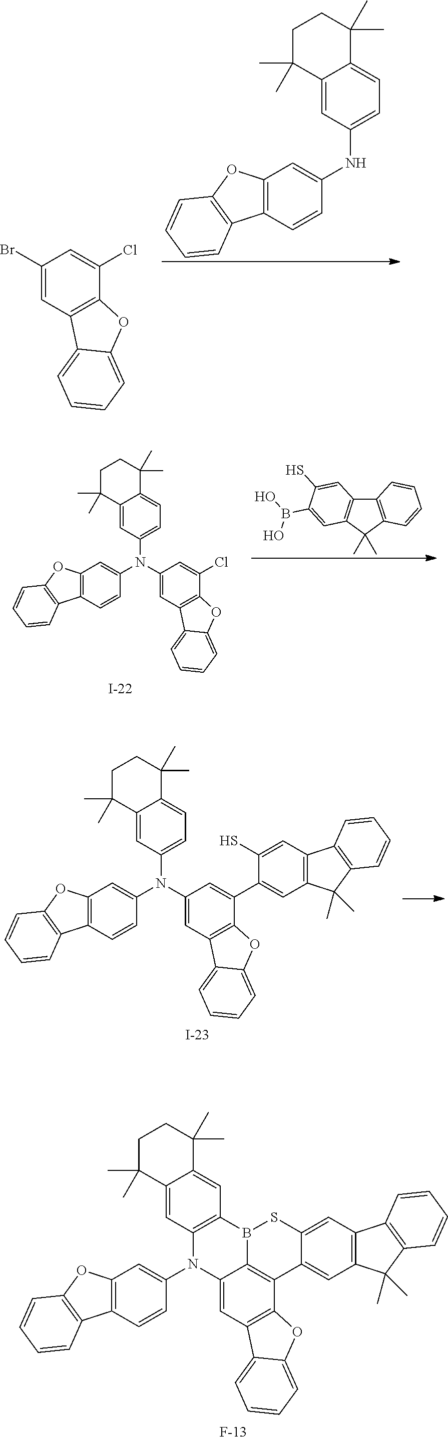

### Synthesis of I-22

After 30 g of 2-bromo-4-chlorodibenzo[b,d]furan, 40 g of N-(5,5,8,8-tetramethyl-5,6,7,8-tetrahydronaphthalen-2-yl)dibenzo[b,d]furan-3-amine, 1.1 g of [bis(tri-tert-butylphosphine)palladium(0)], 21 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 43 g of I-22. (Yield 71%, Mass [M+]=571)

### Synthesis of I-23

After 25 g of I-22, 11.8 g of (3-mercapto-9,9-dimethyl-9H-fluoren-2-yl)boronic acid, 19 g of K₂CO₃, 0.5 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 24 g of I-23. (Yield 72%, Mass [M+]=761)

### Synthesis of F-13

After 20 g of 1-23, 18 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.3 g of F-13.

### Preparation Examples of Compound 14 (F-14)

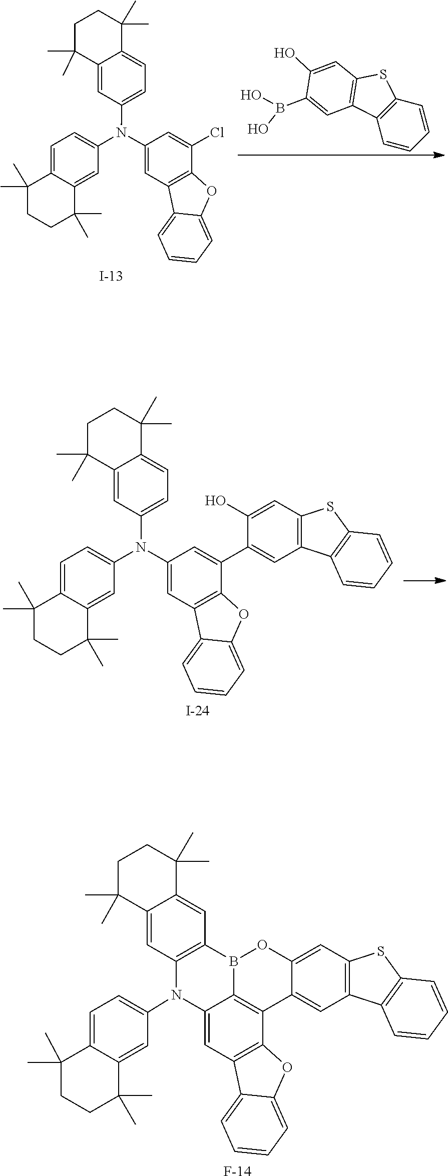

### Synthesis of I-24

After 25 g of 1-13, 10 g of (3-hydroxydibenzo[b,d]thiophen-2-yl)boronic acid, 17 g of K₂CO₃, 0.5 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 23 g of I-24. (Yield 75%, Mass [M+]=755)

### Synthesis of F-14

After 20 g of I-24, 18 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.4 g of F-14. (Yield 37%, Mass [M+]=763)

### Preparation Examples of Compound 15 (F-15)

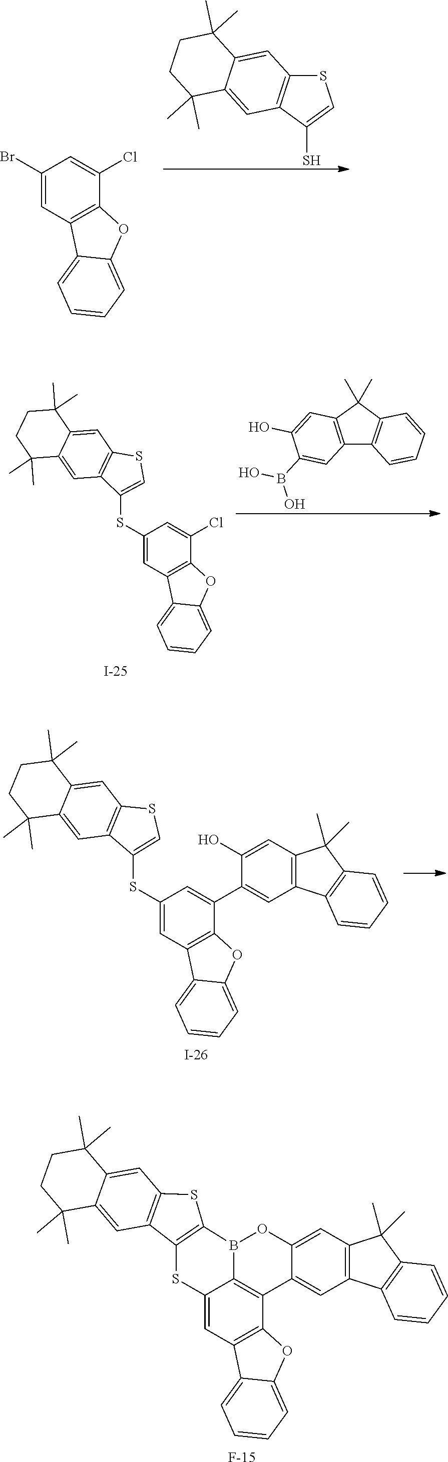

### Synthesis of I-25

After 30 g of 2-bromo-4-chlorodibenzo[b,d]furan, 29.5 g of 5,5,8,8-tetramethyl-5,6,7,8-tetrahydronaphtho[2,3-b]thiophene-3-thiol, 1.1 g of [bis(tri-tert-butylphosphine)palladium(0)], 21 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 36 g of I-25. (Yield 71%, Mass [M+]=478)

### Synthesis of I-26

After 25 g of 1-25, 13.3 g of (2-hydroxy-9,9-dimethyl-9H-fluoren-3-yl)boronic acid, 22 g of K₂CO₃, 0.5 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 26 g of I-26. (Yield 76%, Mass [M+]=652)

### Synthesis of F-15

After 20 g of I-26, 21 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.5 g of F-15. (Yield 37%, Mass [M+]=660)

### Preparation Examples of Compound 16 (F-16)

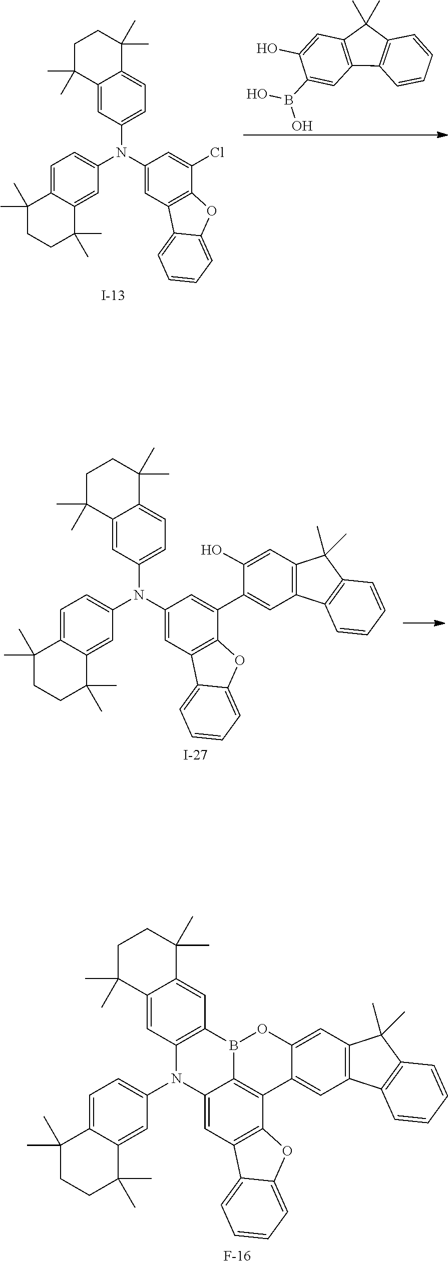

### Synthesis of I-27

After 25 g of I-13, 10.8 g of (2-hydroxy-9,9-dimethyl-9H-fluoren-3-yl)boronic acid, 18 g of K₂CO₃, 0.5 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 22 g of I-27. (Yield 68%, Mass [M+]=765)

### Synthesis of F-16

After 20 g of 1-27, 18 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.7 g of F-16. (Yield 38%, Mass [M+]=773)

### Preparation Examples of Compound 17 (F-17)

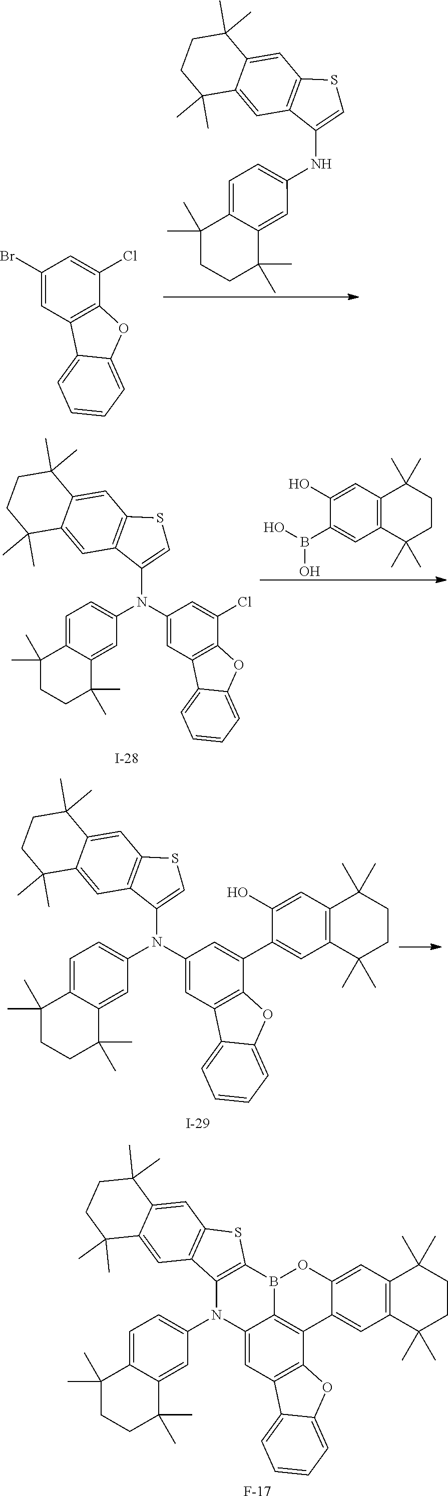

### Synthesis of I-28

After 30 g of 2-bromo-4-chlorodibenzo[b,d]furan, 47.5 g of 5,5,8,8-tetramethyl-N-(5,5,8,8-tetramethyl-5,6,7,8-tetrahydronaphthalen-2-yl)-5,6,7,8-tetrahydronaphtho[2,3-b]thiophene-3-amine, 1.1 g of [bis(tri-tert-butylphosphine)palladium(0)], 21 g of sodium-tert-butoxide, and 600 ml of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 51 g of I-28. (Yield 74%, Mass [M+]=647)

### Synthesis of I-29

After 25 g of I-28, 9.6 g of (3-hydroxy-5,5,8,8-tetramethyl-5,6,7,8-tetrahydronaphthalen-2-yl)boronic acid, 16 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 23 g of I-29. (Yield 73%, Mass [M+]=815)

### Synthesis of F-17

After 20 g of 1-29, 17 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.2 g of F-17. (Yield 36%, Mass [M+]=823)

### Preparation Examples of Compound 18 (F-18)

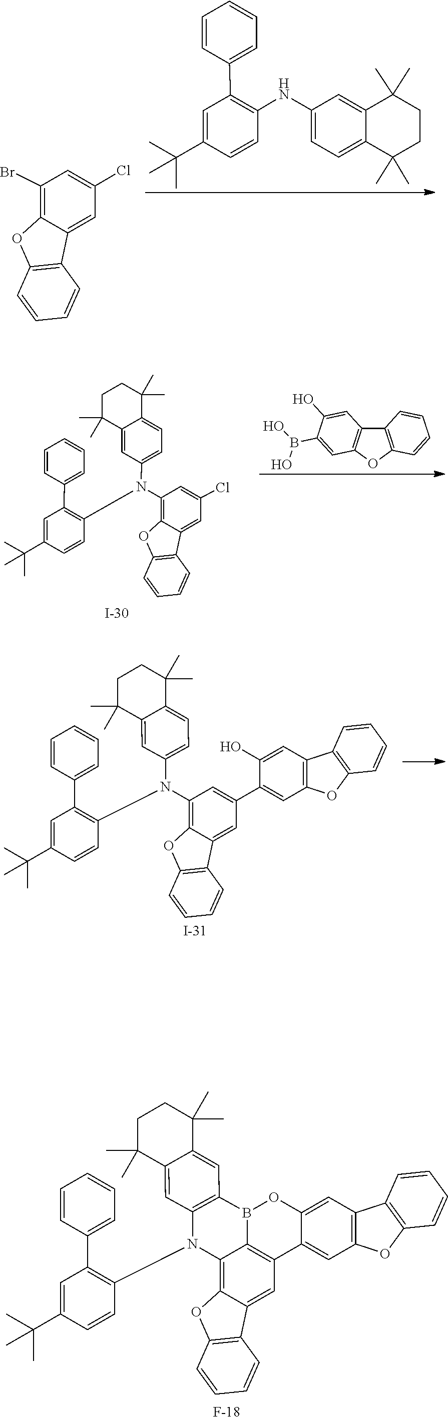

### Synthesis of I-30

After 30 g of 4-bromo-2-chlorodibenzo[b,d]furan, 43.9 g of N-(5-(tert-butyl)-[1,1′-biphenyl]-2-yl)-5,5,8,8-tetramethyl-5,6,7,8-tetrahydronaphthalen-2-amine, 1.1 g of [bis(tri-tert-butylphosphine)palladium(0)], 21 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 50 g of I-30. (Yield 77%, Mass [M+]=613)

### Synthesis of I-31

After 25 g of 1-30, 9.3 g of (2-hydroxydibenzo[b,d]furan-3-yl)boronic acid, 17 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 24 g of I-31. (Yield 77%, Mass [M+]=761)

### Synthesis of F-18

After 20 g of I-31, 18 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.3 g of F-18.

### Preparation Examples of Compound 19 (F-19)

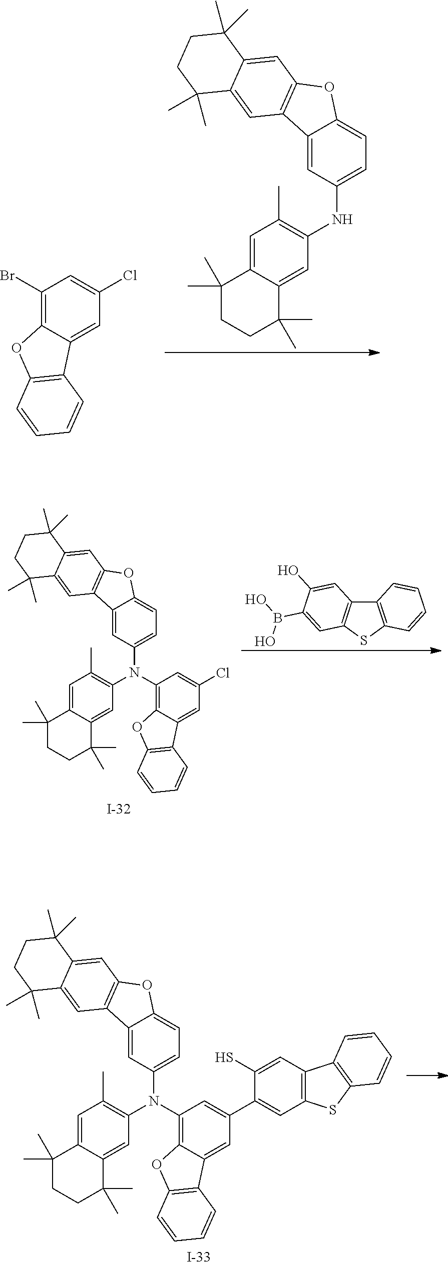

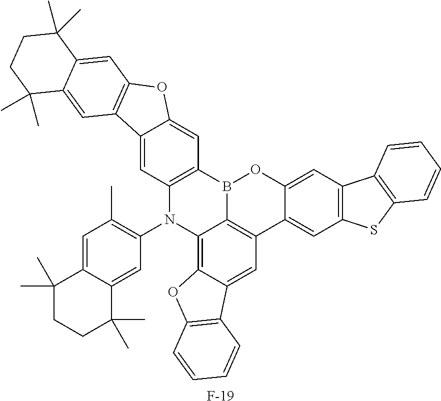

### Synthesis of I-32

After 30 g of 4-bromo-2-chlorodibenzo[b,d]furan, 53 g of 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-2-amine, 1.1 g of [bis(tri-tert-butylphosphine)palladium(0)], 21 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 52 g of I-32. (Yield 70%, Mass [M+]=695)

### Synthesis of I-33

After 25 g of 1-32, 8.8 g of (2-hydroxydibenzo[b,d]thiophen-3-yl)boronic acid, 15 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 23 g of I-33. (Yield 74%, Mass [M+]=859)

### Synthesis of F-19

After 20 g of I-33, 16 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.4 g of F-19. (Yield 37%, Mass [M+]=867)

### Preparation Examples of Compound 20 (F-20)

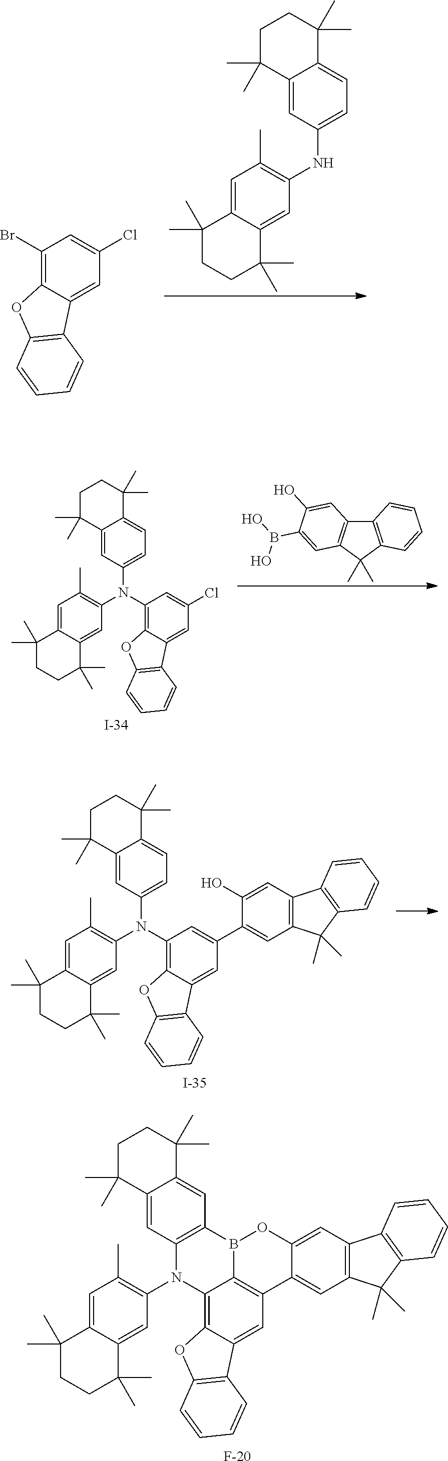

### Synthesis of I-34

After 30 g of 4-bromo-2-chlorodibenzo[b,d]furan, 43 g of 3,5,5,8,8-pentamethyl-N-(5,5,8,8-tetramethyl-5,6,7,8-tetrahydronaphthalen-2-yl)-5,6,7,8-tetrahydronaphthalen-2-amine, 1.1 g of [bis(tri-tert-butylphosphine)palladium(0)], 21 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 46 g of I-34. (Yield 71%, Mass [M+]=605)

### Synthesis of I-35

After 25 g of 1-34, 11 g of (3-hydroxy-9,9-dimethyl-9H-fluoren-2-yl)boronic acid, 18 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 25 g of I-35. (Yield 75%, Mass [M+]=779)

### Synthesis of F-20

After 20 g of I-35, 17 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.3 g of F-20. (Yield 36%, Mass [M+]=787)

### Preparation Examples of Compound 21 (F-21)

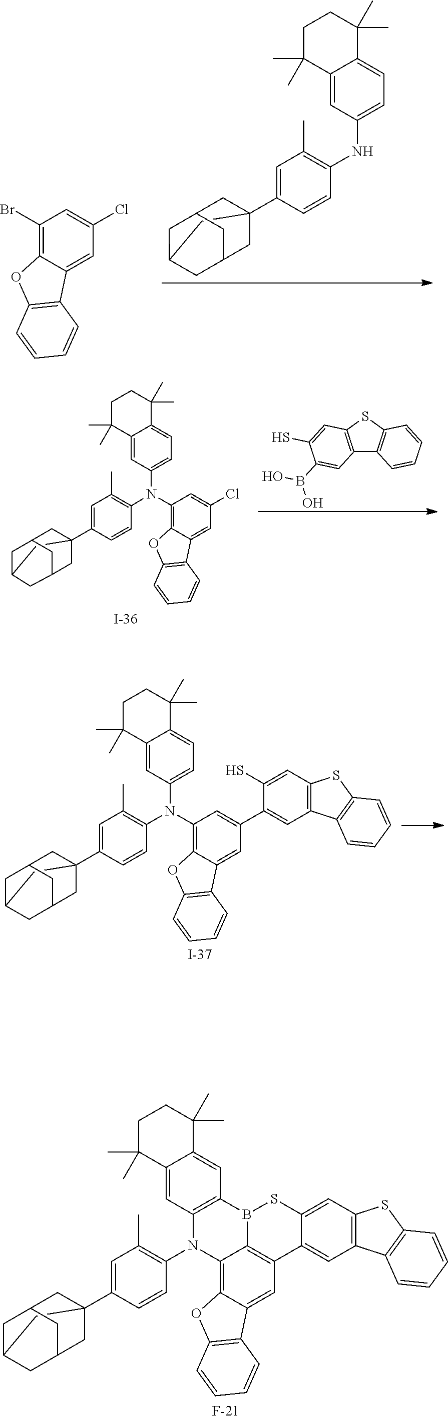

### Synthesis of I-36

After 30 g of 4-bromo-2-chlorodibenzo[b,d]furan, 45 g of N-(4-(adamantan-1-yl)-2-methylphenyl)-5,5,8,8-tetramethyl-5,6,7,8-tetrahydronaphthalen-2-amine, 1.1 g of [bis(tri-tert-butylphosphine)palladium(0)], 21 g of sodium-tert-butoxide, and 600 ml of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 49 g of I-36. (Yield 73%, Mass [M+]=629)

### Synthesis of I-37

After 25 g of 1-36, 10.4 g of (3-mercaptodibenzo[b,d]thiophen-2-yl)boronic acid, 17 g of K₂CO₃, 0.4 g of [bis(tri-tert-butylphosphine)palladium(0)], 500 mL of tetrahydrofuran, and 250 mL of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 23 g of I-37. (Yield 72%, Mass [M+]=809)

### Synthesis of F-21

After 20 g of 1-37, 17 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.4 g of F-21. (Yield 37%, Mass [M+]=817)

### Preparation Examples of Compound 22 (F-22)

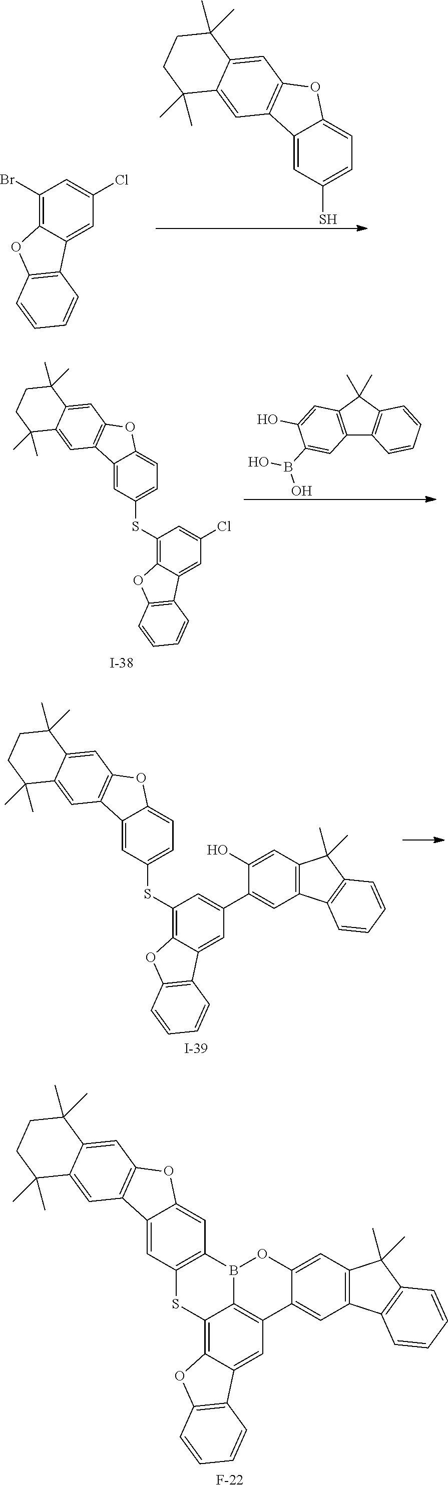

### Synthesis of I-38

After 30 g of 4-bromo-2-chlorodibenzo[b,d]furan, 33.1 g of 7,7,10,10-tetramethyl-7,8,9,10-tetrahydronaphtho[2,3-b]benzofuran-2-thiol, 1.1 g of [bis(tri-tert-butylphosphine)palladium(0)], 21 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 42 g of I-38. (Yield 77%, Mass [M+]=512)

### Synthesis of I-39

After 25 g of 1-38, 12.4 g of (2-hydroxy-9,9-dimethyl-9H-fluoren-3-yl)boronic acid, 20.3 g of K₂CO₃, 0.5 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 25 g of I-39. (Yield 78%, Mass [M+]=686)

### Synthesis of F-22

After 20 g of I-39, 19.5 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.2 g of F-22. (Yield 36%, Mass [M+]=694)

### Preparation Examples of Compound 23 (F-23)

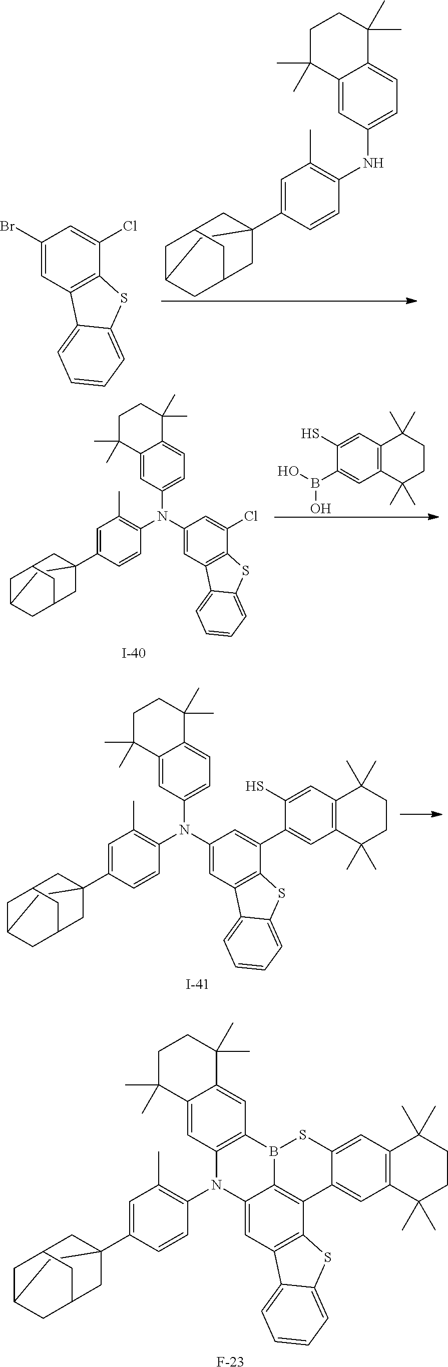

### Synthesis of I-40

After 30 g of 2-bromo-4-chlorodibenzo[b,d]thiophene, 43.1 g of N-(4-(adamantan-1-yl)-2-methylphenyl)-5,5,8,8-tetramethyl-5,6,7,8-tetrahydronaphthalen-2-amine, 1.1 g of [bis(tri-tert-butylphosphine)palladium(0)], 20 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 46 g of I-40. (Yield 71%, Mass [M+]=645)

### Synthesis of I-41

After 25 g of I-40, 10.3 g of (3-mercapto-5,5,8,8-tetramethyl-5,6,7,8-tetrahydronaphthalen-2-yl)boronic acid, 16.1 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 24 g of I-41. (Yield 75%, Mass [M+]=829)

### Synthesis of F-23

After 20 g of I-41, 16.1 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.3 g of F-23. (Yield 36%, Mass [M+]=837)

### Preparation Examples of Compound 24 (F-24)

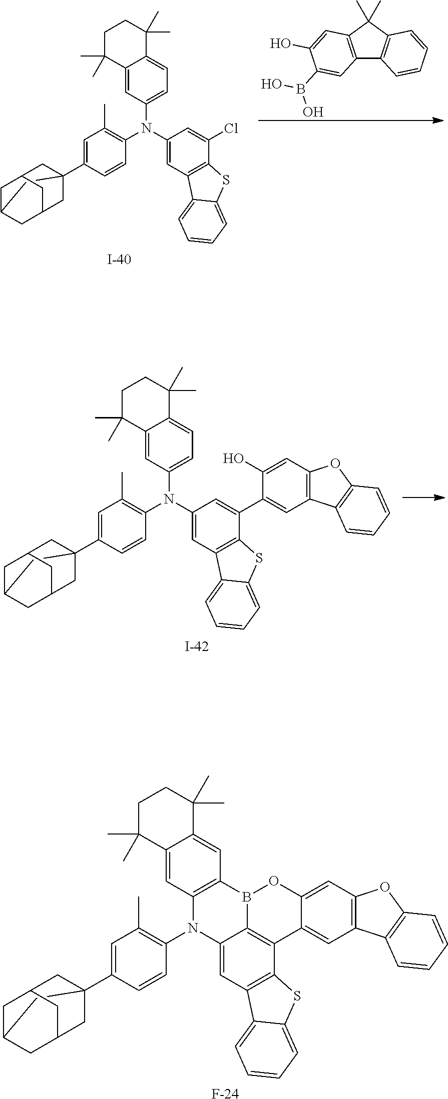

### Synthesis of I-42

After 25 g of 1-40, 8.9 g of (3-hydroxydibenzo[b,d]furan-2-yl)boronic acid, 16.1 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 23 g of I-42. (Yield 75%, Mass [M+]=793)

### Synthesis of F-24

After 20 g of I-42, 16.8 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.4 g of F-24. (Yield 37%, Mass [M+]=801)

### Preparation Examples of Compound 25 (F-25)

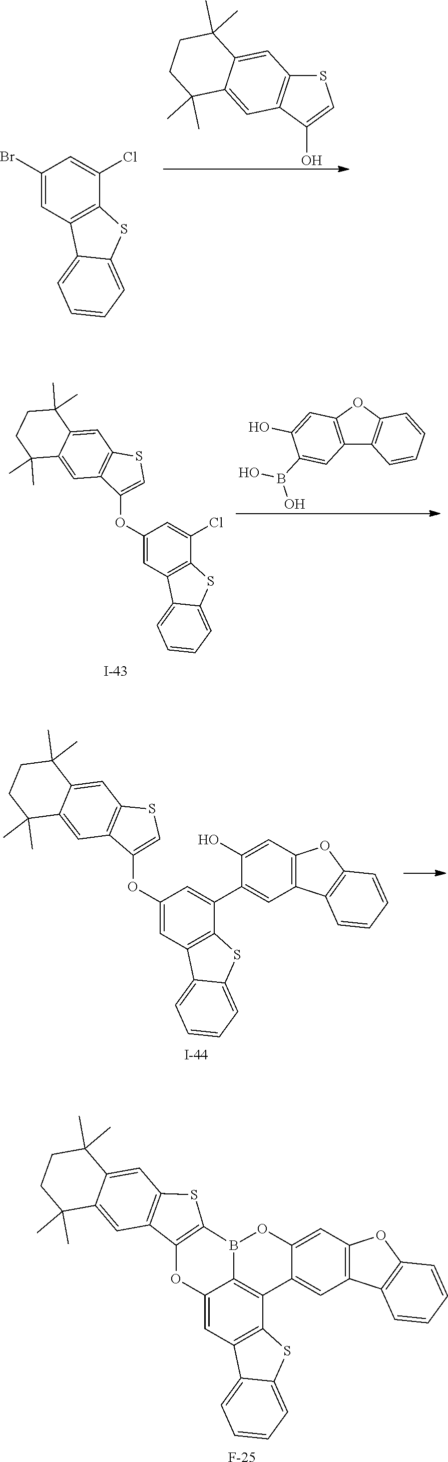

### Synthesis of I-43

After 30 g of 2-bromo-4-chlorodibenzo[b,d]thiophene, 26.3 g of 5,5,8,8-tetramethyl-5,6,7,8-tetrahydronaphtho[2,3-b]thiophene-3-ol, 1.1 g of [bis(tri-tert-butylphosphine)palladium(0)], 20 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 35 g of I-43. (Yield 73%, Mass [M+]=478)

### Synthesis of I-44

After 25 g of 1-43, 12 g of (3-hydroxydibenzo[b,d]furan-2-yl)boronic acid, 22 g of K₂CO₃, 0.5 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 24 g of I-44. (Yield 73%, Mass [M+]=626)

### Synthesis of F-25

After 20 g of I-44, 21.3 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.3 g of F-25. (Yield 36%, Mass [M+]=634)

### Preparation Examples of Compound 26 (F-26)

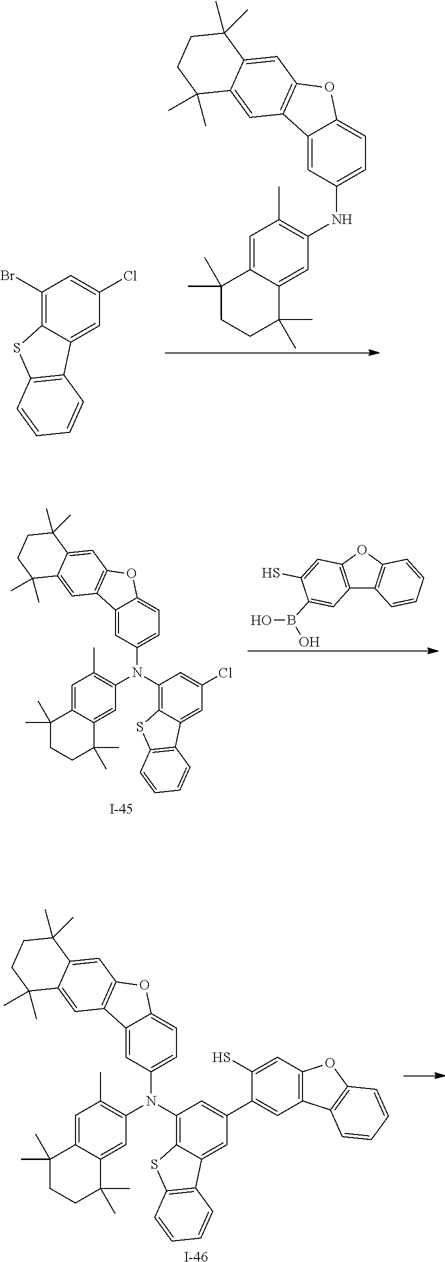

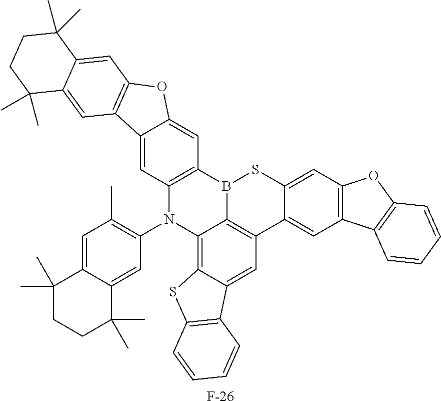

### Synthesis of I-45

After 30 g of 4-bromo-2-chlorodibenzo[b,d]thiophene, 49.8 g of 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-2-amine, 1.1 g of [bis(tri-tert-butylphosphine)palladium(0)], 20 g of sodium-tert-butoxide, and 600 ml of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 55 g of I-45. (Yield 77%, Mass [M+]=711)

### Synthesis of I-46

After 25 g of I-45, 8.6 g of (3-mercaptodibenzo[b,d]furan-2-yl)boronic acid, 15 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 23 g of I-46. (Yield 75%, Mass [M+]=875)

### Synthesis of F-26

After 20 g of I-46, 15.2 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.4 g of F-26. (Yield 37%, Mass [M+]=883)

### Preparation Examples of Compound 27 (F-27)

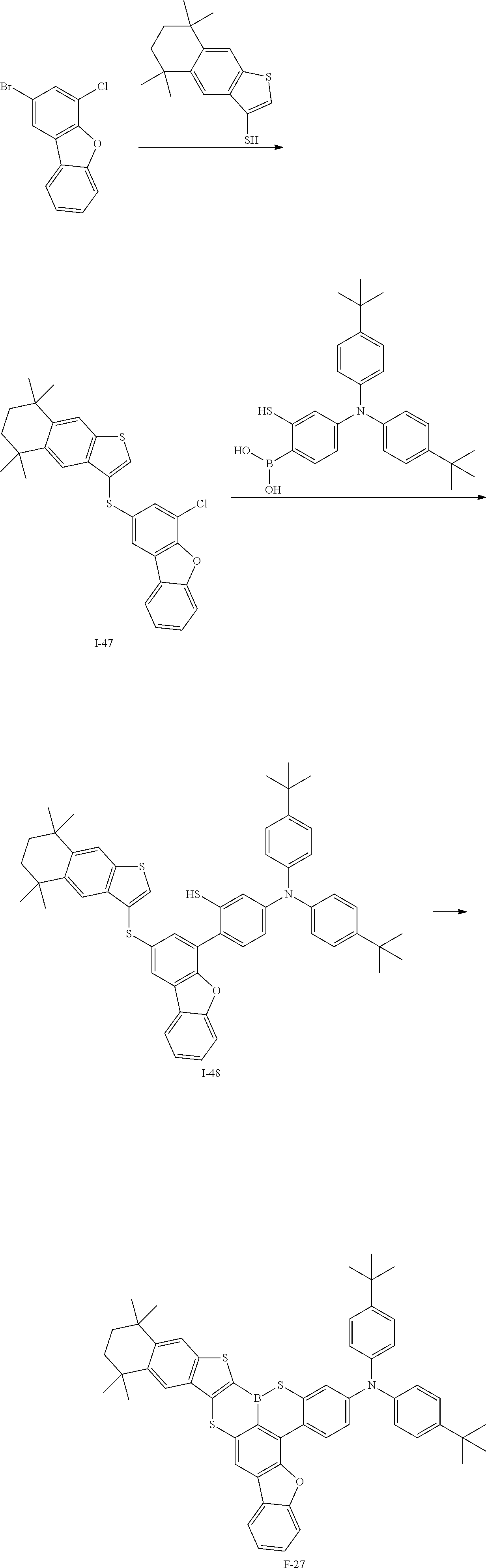

### Synthesis of I-47

After 30 g of 2-bromo-4-chlorodibenzo[b,d]furan, 29.5 g of 5,5,8,8-tetramethyl-5,6,7,8-tetrahydronaphtho[2,3-b]thiophene-3-thiol, 1.1 g of [bis(tri-tert-butylphosphine)palladium(0)], 20.5 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 37 g of I-47. (Yield 73%, Mass [M+]=478)

### Synthesis of I-48

After 25 g of I-47, 22.7 g of (4-(bis(4-(tert-butyl)phenyl)amino)-2-mercaptophenyl)boronic acid, 21.7 g of K₂CO₃, 0.5 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 31 g of I-48. (Yield 71%, Mass [M+]=831)

### Synthesis of F-27

After 20 g of I-48, 16 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.5 g of F-27. (Yield 37%, Mass [M+]=839)

### Preparation Examples of Compound 28 (F-28)

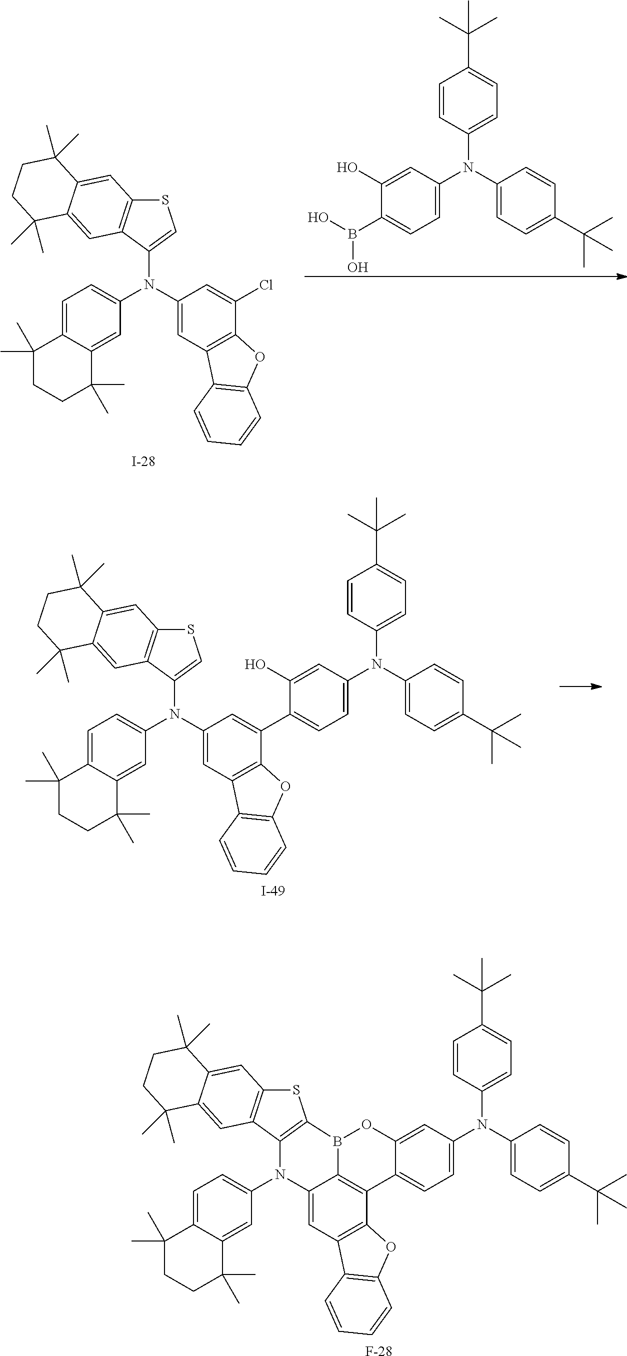

### Synthesis of I-49

After 25 g of I-28, 16.8 g of (4-(bis(4-(tert-butyl)phenyl)amino)-2-hydroxyphenyl)boronic acid, 16 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 29 g of I-49. (Yield 76%, Mass [M+]=984)

### Synthesis of F-28

After 20 g of I-49, 13.5 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.3 g of F-28. (Yield 36%, Mass [M+]=992)

### Preparation Examples of Compound 29 (F-29)

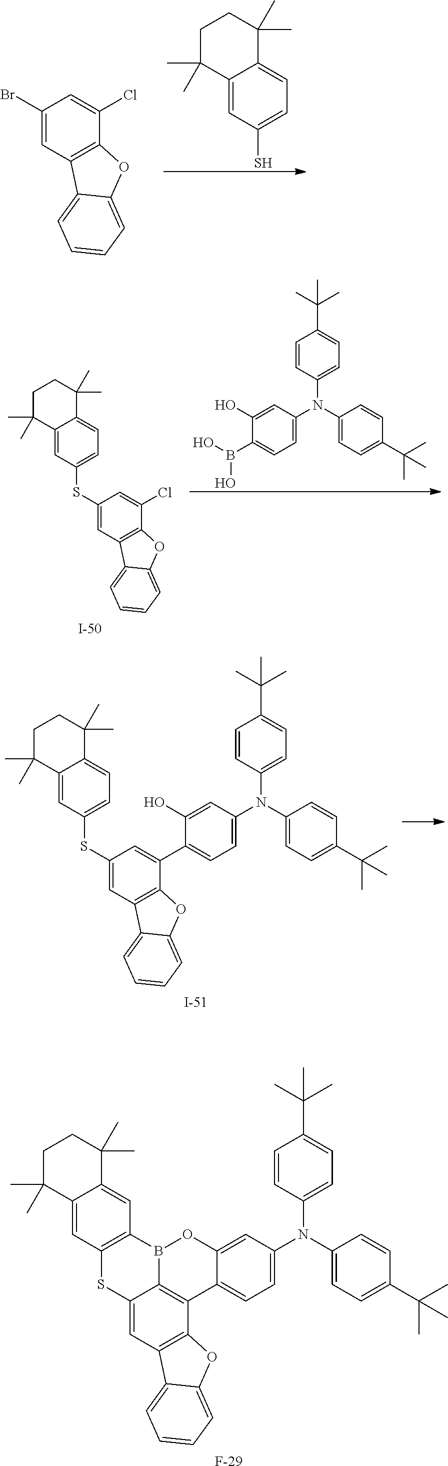

### Synthesis of I-50

After 30 g of 2-bromo-4-chlorodibenzo[b,d]furan, 23.5 g of 5,5,8,8-tetramethyl-5,6,7,8-tetrahydronaphthalene-2-thiol, 1.1 g of [bis(tri-tert-butylphosphine)palladium(0)], 20.5 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 33 g of I-50. (Yield 74%, Mass [M+]=422)

### Synthesis of I-51

After 25 g of I-50, 25.7 g of (4-(bis(4-(tert-butyl)phenyl)amino)-2-hydroxyphenyl)boronic acid, 24.6 g of K₂CO₃, 0.6 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 33 g of I-51. (Yield 73%, Mass [M+]=759)

### Synthesis of F-29

After 20 g of I-51, 17.6 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.2 g of F-29. (Yield 36%, Mass [M+]=767)

### Preparation Examples of Compound 30 (F-30)

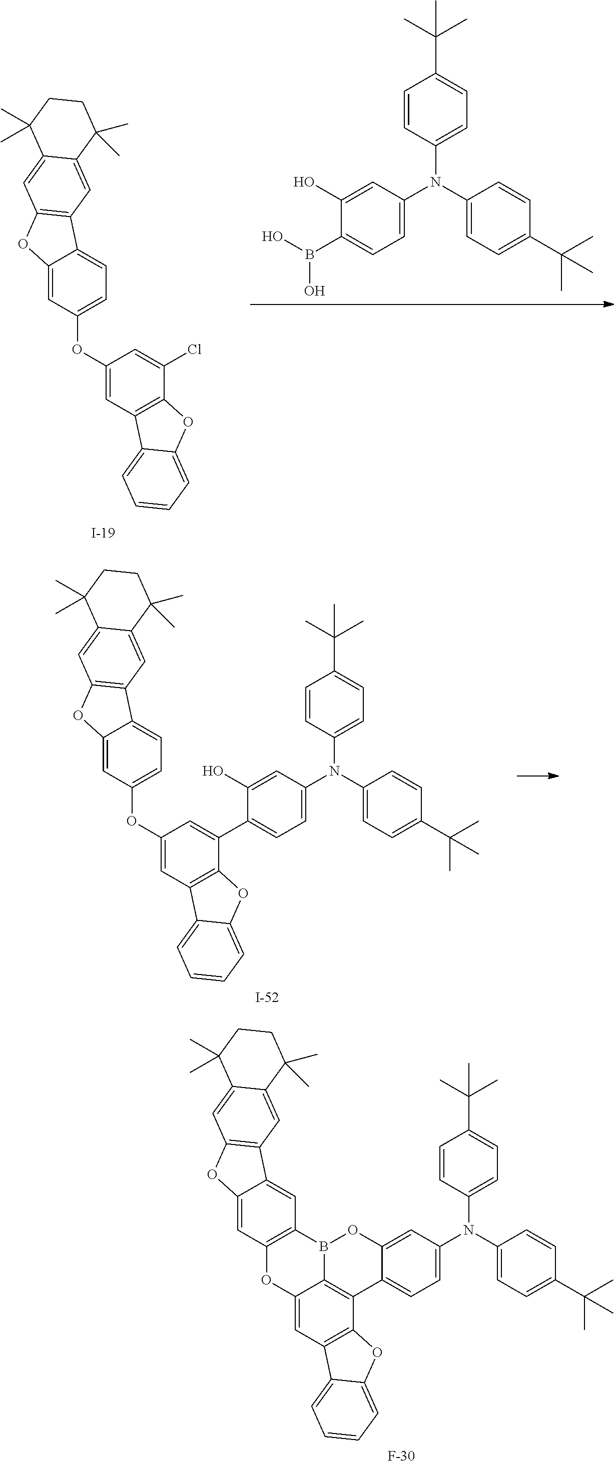

### Synthesis of I-52

After 25 g of I-19, 21.9 g of (4-(bis(4-(tert-butyl)phenyl)amino)-2-hydroxyphenyl)boronic acid, 20.9 g of K₂CO₃, 0.5 g of [bis(tri-tert-butylphosphine)palladium(0)], 500 mL of tetrahydrofuran, and 250 mL of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 32 g of I-52. (Yield 76%, Mass [M+]=833)

### Synthesis of F-30

After 20 g of I-52, 16 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.2 g of F-30. (Yield 36%, Mass [M+]=841)

### Preparation Examples of Compound 31 (F-31)

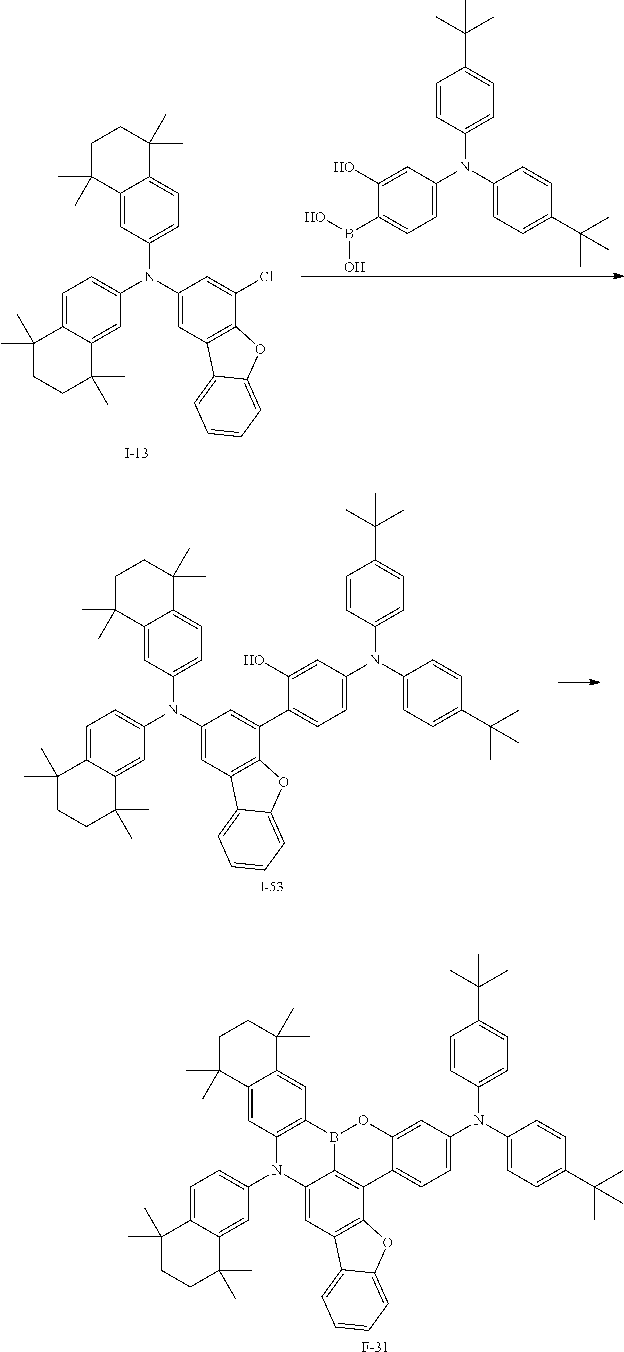

### Synthesis of I-53

After 25 g of I-13, 18.4 g of (4-(bis(4-(tert-butyl)phenyl)amino)-2-hydroxyphenyl)boronic acid, 17.6 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 29 g of I-53. (Yield 74%, Mass [M+]=928)

### Synthesis of F-31

After 20 g of I-53, 14.4 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.3 g of F-31. (Yield 36%, Mass [M+]=936)

### Preparation Examples of Compound 32 (F-32)

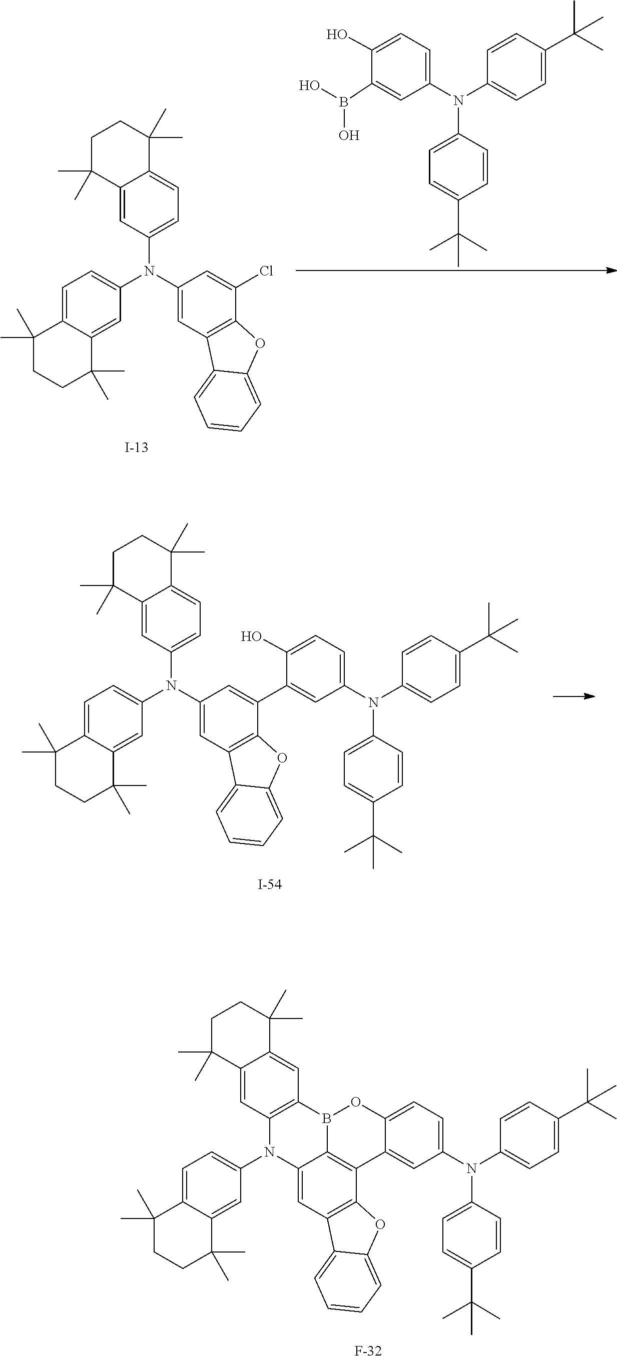

### Synthesis of I-54

After 25 g of I-13, 17.7 g of (5-(bis(4-(tert-butyl)phenyl)amino)-2-hydroxyphenyl)boronic acid, 17.6 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 28 g of I-54. (Yield 71%, Mass [M+]=928)

### Synthesis of F-32

After 20 g of I-54, 14.4 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.4 g of F-32. (Yield 37%, Mass [M+]=936)

### Preparation Examples of Compound 33 (F-33)

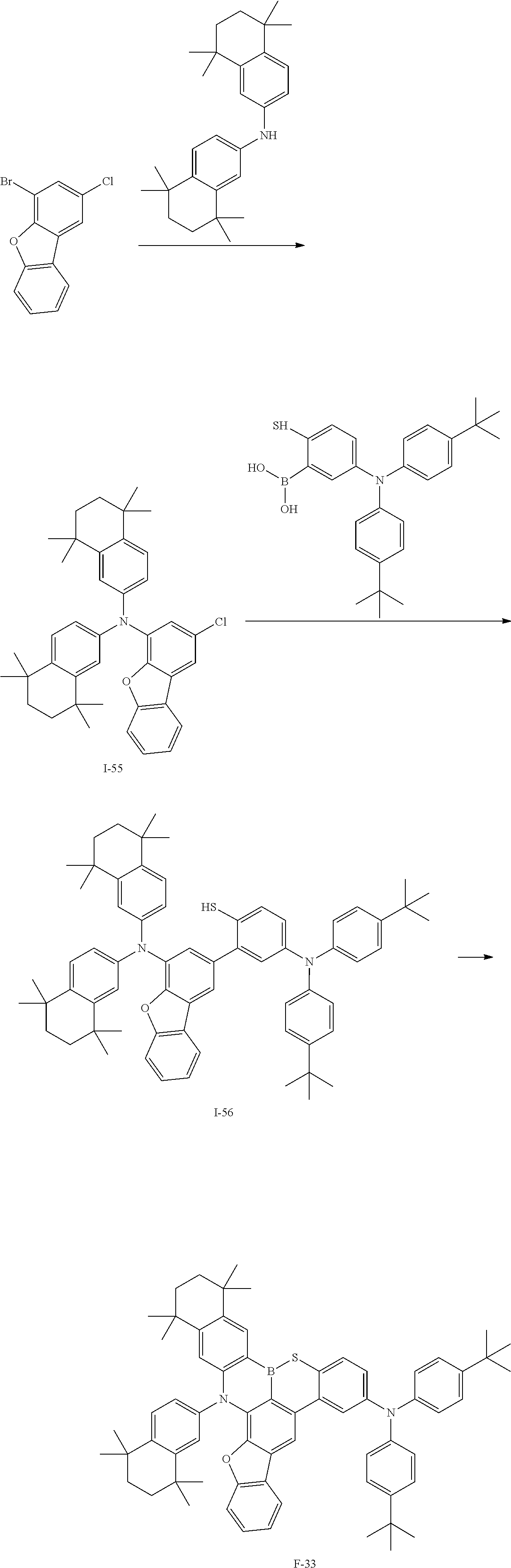

### Synthesis of I-55

After 30 g of 4-bromo-2-chlorodibenzo[b,d]furan, 41.5 g of bis(5,5,8,8-tetramethyl-5,6,7,8-tetrahydronaphthalen-2-yl)amine, 1.1 g of [bis(tri-tert-butylphosphine)palladium(0)], 20.5 g of sodium-tert-butoxide, and 600 ml of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 44 g of I-55. (Yield 70%, Mass [M+]=591)

### Synthesis of I-56

After 25 g of I-55, 18.4 g of (5-(bis(4-(tert-butyl)phenyl)amino)-2-mercaptophenyl)boronic acid, 27.6 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 29 g of I-56. (Yield 73%, Mass [M+]=944)

### Synthesis of F-33

After 20 g of I-56, 14.1 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.4 g of F-33. (Yield 37%, Mass [M+]=952)

### Preparation Examples of Compound 34 (F-34)

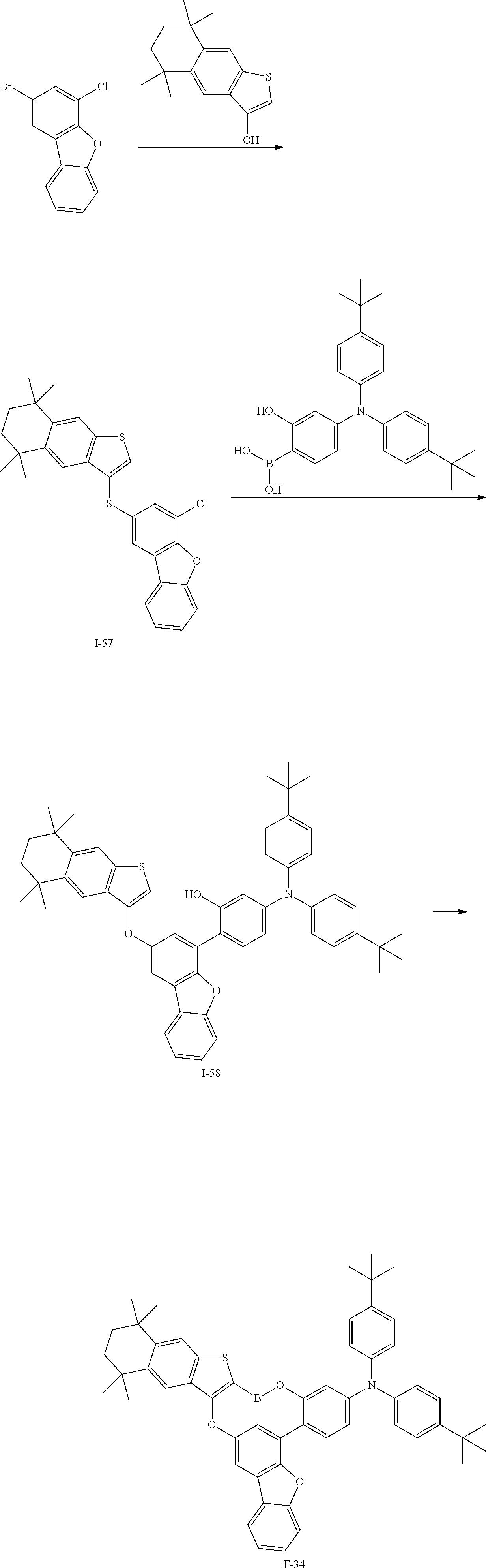

### Synthesis of I-57

After 30 g of 2-bromo-4-chlorodibenzo[b,d]furan, 27.8 g of 5,5,8,8-tetramethyl-5,6,7,8-tetrahydronaphtho[2,3-b]thiophene-3-ol, 1.1 g of [bis(tri-tert-butylphosphine)palladium(0)], 20.5 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 37 g of I-57. (Yield 75%, Mass [M+]=462)

### Synthesis of I-58

After 25 g of I-57, 22.6 g of (4-(bis(4-(tert-butyl)phenyl)amino)-2-hydroxyphenyl)boronic acid, 22.5 g of K₂CO₃, 0.6 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 32 g of I-58. (Yield 74%, Mass [M+]=799)

### Synthesis of F-34

After 20 g of I-58, 16.7 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.4 g of F-34. (Yield 37%, Mass [M+]=807)

### Preparation Examples of Compound 35 (F-35)

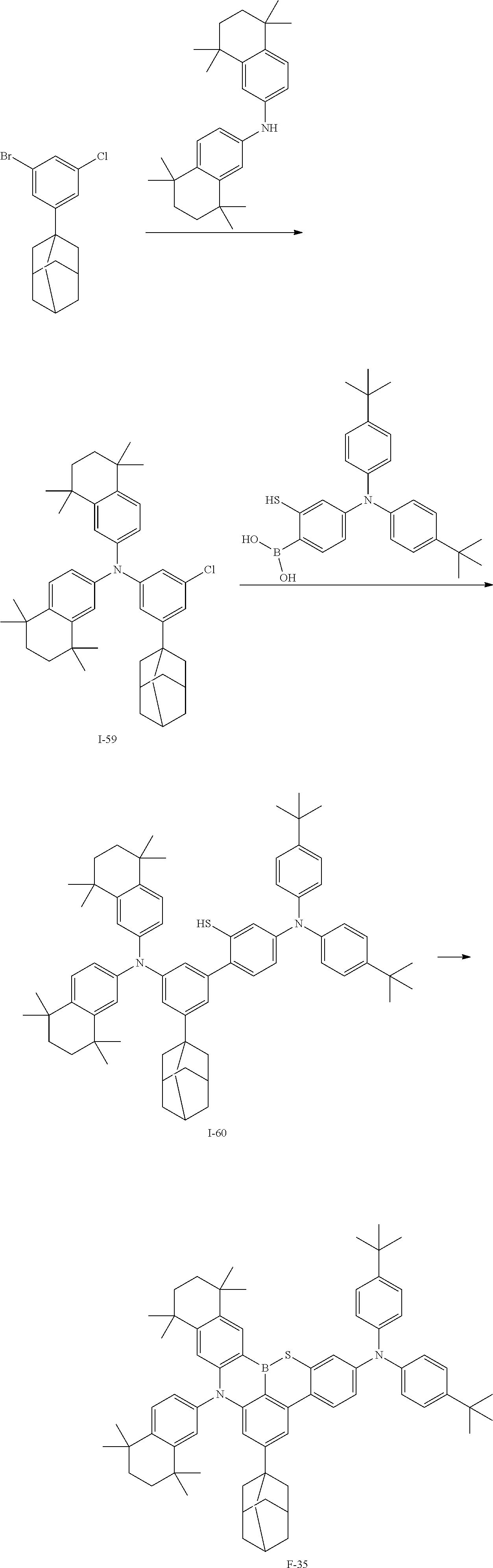

### Synthesis of I-59

After 30 g of 1-(3-bromo-5-chlorophenyl) adamantane, 35.9 g of bis(5,5,8,8-tetramethyl-5,6,7,8-tetrahydronaphthalen-2-yl)amine, 0.9 g of [bis(tri-tert-butylphosphine)palladium(0)], 17.7 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 41 g of I-59. (Yield 70%, Mass [M+]=635)

### Synthesis of I-60

After 25 g of I-59, 17.1 g of (4-(bis(4-(tert-butyl)phenyl)amino)-2-mercaptophenyl)boronic acid, 16.3 g of K₂CO₃, 0.4 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 29 g of I-60. (Yield 75%, Mass [M+]=989)

### Synthesis of F-35

After 20 g of I-60, 13.5 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.5 g of F-35. (Yield 37%, Mass [M+]=996)

### Preparation Examples of Compound 36 (F-36)

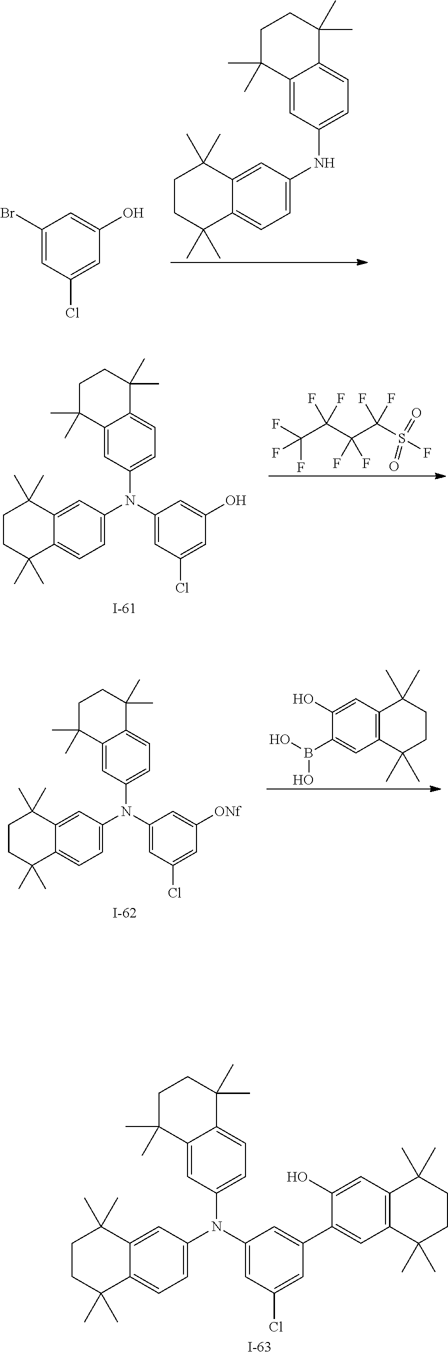

### Synthesis of I-61

After 40 g of 3-bromo-5-chlorophenol, 75.1 g of bis(5,5,8,8-tetramethyl-5,6,7,8-tetrahydronaphthalen-2-yl)amine, 2 g of [bis(tri-tert-butylphosphine)palladium(0)], 37.1 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 72 g of I-61. (Yield 72%, Mass [M+]=517)

### Synthesis of I-62

After 40 g of I-61, 35.1 g of 1,1,2,2,3,3,4,4,4-nonafluorobutane-1-sulfonyl fluoride, 32.1 g of K₂CO₃, 500 mL of tetrahydrofuran, and 250 ml of water were put into a container, the resulting mixture was heated under reflux and stirred for 3 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 52 g of I-62. (Yield 84%, Mass [M+]=799)

### Synthesis of I-63

After 40 g of I-62, 12.4 g of (3-hydroxy-5,5,8,8-tetramethyl-5,6,7,8-tetrahydronaphthalen-2-yl)boronic acid, 20.8 g of K₂CO₃, 0.5 g of [bis(tri-tert-butylphosphine)palladium(0)], 600 mL of tetrahydrofuran, and 300 mL of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 25 g of I-63. (Yield 71%, Mass [M+]=989)

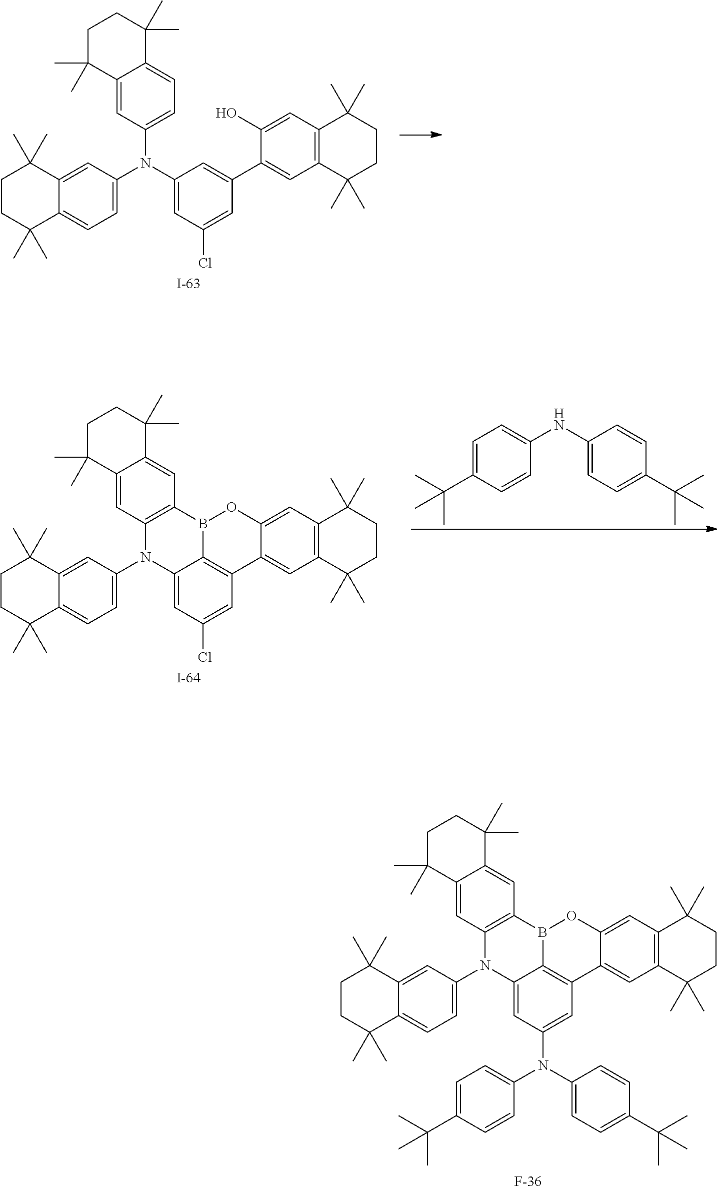

### Synthesis of I-64

After 20 g of 1-63, 19 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.6 g of I-64. (Yield 38%, Mass [M+]=711)

### Synthesis of F-36

After 7 g of I-64, 2.5 g of bis(4-(tert-butyl)phenyl)amine, 0.1 g of [bis(tri-tert-butylphosphine)palladium(0)], 2 g of sodium-tert-butoxide, and 100 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 6.7 g of F-36. (Yield 71%, Mass [M+]=956)

### Preparation Examples of Compound 37 (F-37)

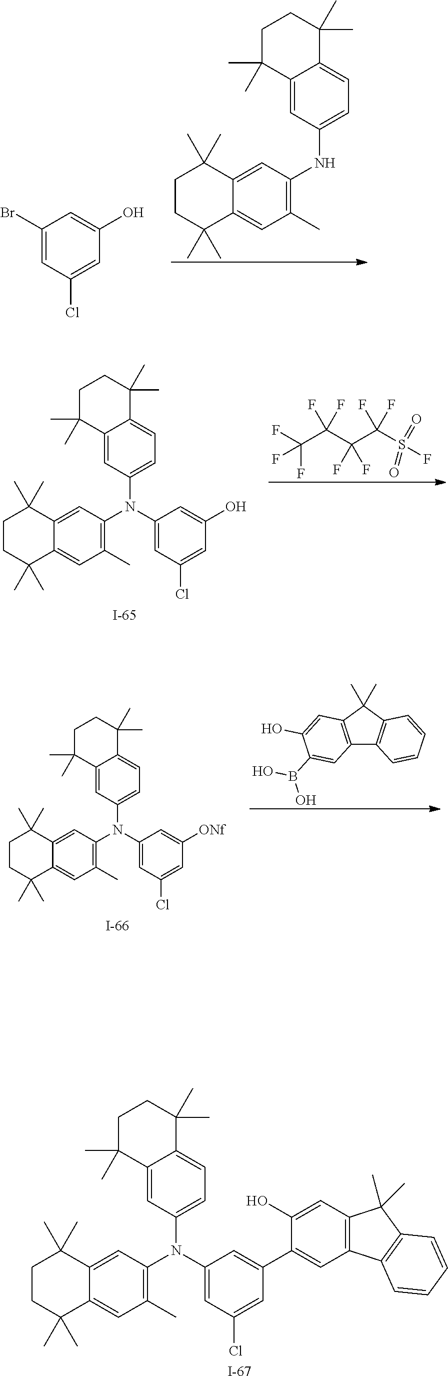

### Synthesis of I-65

After 40 g of 3-bromo-5-chlorophenol, 77.8 g of 3,5,5,8,8-pentamethyl-N-(5,5,8,8-tetramethyl-5,6,7,8-tetrahydronaphthalen-2-yl)-5,6,7,8-tetrahydronaphthalen-2-amine, 2 g of [bis(tri-tert-butylphosphine)palladium(0)], 37.1 g of sodium-tert-butoxide, and 600 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 73 g of I-65. (Yield 70%, Mass [M+]=540)

### Synthesis of I-66

After 40 g of I-65, 33.6 g of 1,1,2,2,3,3,4,4,4-nonafluorobutane-1-sulfonyl fluoride, 31 g of K₂CO₃, 500 mL of tetrahydrofuran, and 250 ml of water were put into a container, the resulting mixture was heated under reflux and stirred for 3 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 51 g of I-66. (Yield 85%, Mass [M+]=814)

### Synthesis of I-67

After 40 g of I-66, 12.5 g of (2-hydroxy-9,9-dimethyl-9H-fluoren-3-yl)boronic acid, 20.4 g of K₂CO₃, 0.5 g of [bis(tri-tert-butylphosphine)palladium(0)], 600 mL of tetrahydrofuran, and 300 mL of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 26 g of I-67. (Yield 73%, Mass [M+]=723)

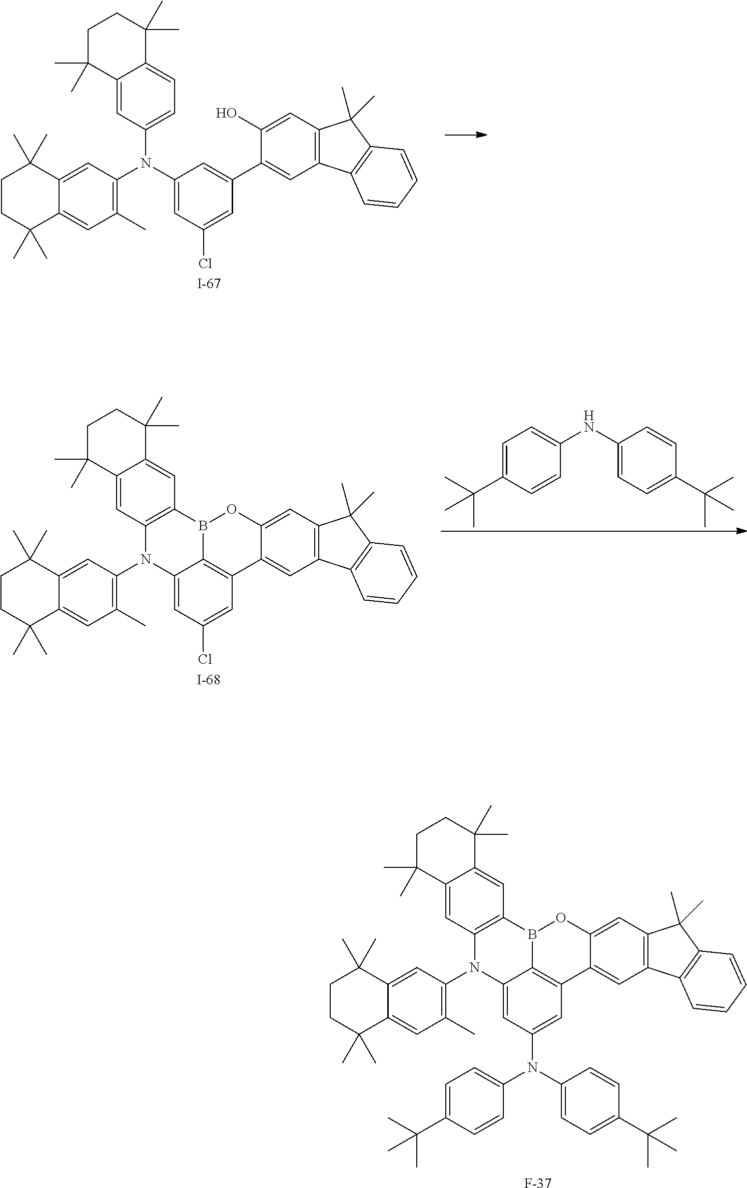

### Synthesis of I-68

After 20 g of I-67, 18.4 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.5 g of I-68. (Yield 37%, Mass [M+]=731)

### Synthesis of F-37

After 7 g of I-68, 2.5 g of bis(4-(tert-butyl)phenyl)amine, 0.05 g of [bis(tri-tert-butylphosphine)palladium(0)], 2 g of sodium-tert-butoxide, and 100 mL of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 6.8 g of F-37. (Yield 73%, Mass [M+]=976)

### Preparation Examples of Compound 38 (F-38)

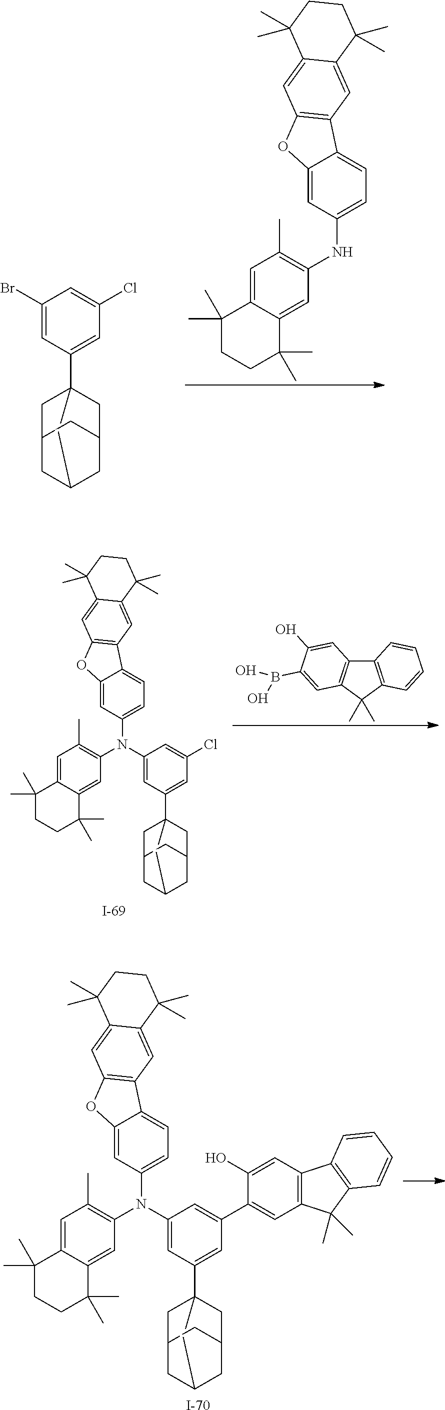

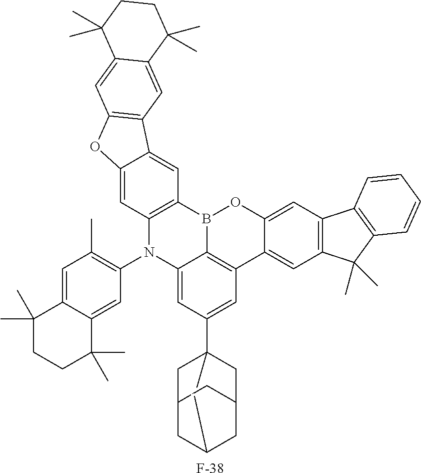

### Synthesis of I-69

After 30 g of 1-(3-bromo-5-chlorophenyl)adamantane, 45.5 g of 7,7,10,10-tetramethyl-N-(3,5,5,8,8-pentamethyl-5,6,7,8-tetrahydronaphthalen-2-yl)-7,8,9,10-tetrahydronaphtho[2,3-b]benzofuran-3-amine, 0.9 g of [bis(tri-tert-butylphosphine)palladium(0)], 17.7 g of sodium-tert-butoxide, and 600 ml of toluene were put into a container under a nitrogen atmosphere, the resulting mixture was heated under reflux and stirred for 8 hours. After the reaction was terminated, the reaction solution was separated, and then treated with MgSO₄ (anhydrous), and filtered. The filtered solution was recrystallized to obtain 51 g of I-69. (Yield 75%, Mass [M+]=740)

### Synthesis of I-70

After 25 g of I-69, 8.6 g of (3-hydroxy-9,9-dimethyl-9H-fluoren-2-yl)boronic acid, 14 g of K₂CO₃, 0.05 g of [bis(tri-tert-butylphosphine)palladium(0)], 500 mL of tetrahydrofuran, and 250 ml of water were put into a container, the resulting mixture was heated under reflux and stirred for 8 hours. After the reaction was terminated, all the solvent was removed, and the reaction solution was separated by dissolving the resulting product in toluene, followed by treatment with MgSO₄ (anhydrous) and filtration. The filtered solution was recrystallized to obtain 22 g of I-70. (Yield 71%, Mass [M+]=913)

### Synthesis of F-38

After 20 g of I-70, 14.6 g of boron triiodide, and 200 mL of dichlorobenzene were put into a container under a nitrogen atmosphere, the resulting mixture was heated under reflux and stirred for 8 hours. After the reaction was terminated, solutions were separated by adding the resulting product to water, and then treated with MgSO₄ (anhydrous) and filtered. The filtered solution was removed, and then recrystallized to obtain 7.3 g of F-38. (Yield 36%, Mass [M+]=921)

### Example 1

A glass substrate thinly coated with indium tin oxide (ITO) to have a thickness of 1, 400 Å was put into distilled water in which a detergent was dissolved, and ultrasonically washed. In this case, a product manufactured by Fischer Co., was used as the detergent, and distilled water, which had been filtered twice with a filter manufactured by Millipore Co., was used as the distilled water. After the ITO was washed for 30 minutes, ultrasonic washing was conducted twice repeatedly using distilled water for 10 minutes. After the washing using distilled water was completed, ultrasonic washing was conducted by using isopropyl alcohol, acetone, and methanol solvents, and the resulting product was dried and then transported to a plasma washing machine. Furthermore, the substrate was cleaned by using oxygen plasma for 5 minutes, and then was transported to a vacuum deposition machine.

The following compounds HI-A and HAT-CN were thermally vacuum deposited to have a thickness of 650 Å and 50 Å, respectively, on the ITO transparent electrode prepared as described, thereby forming a hole injection layer. The following compound HT-A was vacuum deposited to have a thickness of 600 Å on the hole injection layer, thereby forming a hole transport layer. The following compound HT-B was vacuum deposited to have a thickness of 50 Å on the hole transport layer, thereby forming an electron blocking layer. Subsequently, 2 parts by weight of Compound F-1 according to Chemical Formula 1 of the present application as a light emitting dopant based on 100 parts by weight of the light emitting layer and the following compound BH were vacuum deposited to have a thickness of 200 Å as a host on the electron blocking layer, thereby forming a light emitting layer. Next, the following compound ET-A as a first electron transport layer was vacuum deposited to have a thickness of 50 Å on the light emitting layer, and subsequently, the following compounds ET-B and LiQ were vacuum deposited at a weight ratio of 1:1, thereby forming a second electron transport layer having a thickness of 360 Å. LiQ was vacuum deposited to have a thickness of 5 Å on the second electron transport layer, thereby forming an electron injection layer. Aluminum and silver were deposited at a weight ratio of 10:1 to have a thickness of 220 Å on the electron injection layer, and aluminum was deposited to have a thickness of 1,000 Å thereon, thereby forming a negative electrode.

In the aforementioned procedure, the deposition rate of the organic materials was maintained at 0.4 to 0.9 Å/sec, the deposition rate of aluminum of the negative electrode was maintained at 2 Å/sec, and the degree of vacuum during the deposition was maintained at 1×10⁻⁷ to 5×10⁻⁸ torr, thereby manufacturing an organic light emitting device.

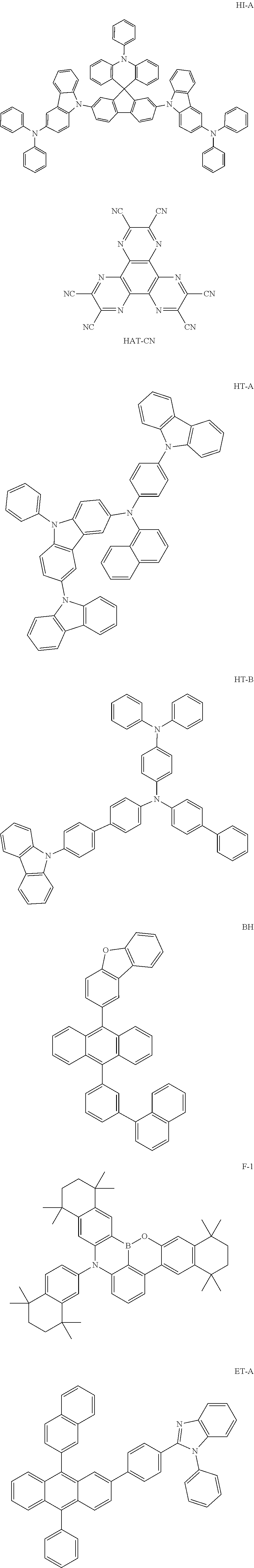

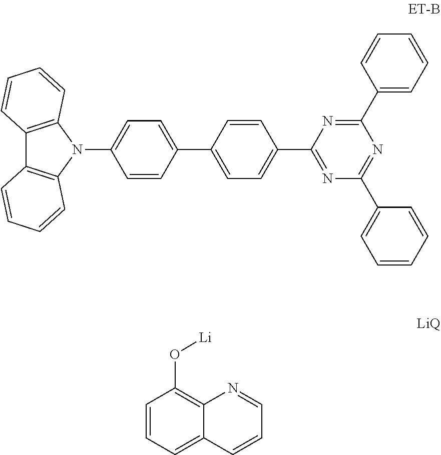

### Examples 2 to 38

Organic light emitting devices of Examples 2 to 38 were manufactured in the same manner as in Example 1, except that the compounds in the following Table 1 were used instead of Compound F-1 in Example 1. The voltage, efficiency, and service life of the organic light emitting devices manufactured in Examples 2 to 37 and Comparative Examples 1 to 3 were measured, and the results are shown in the following Table 1.

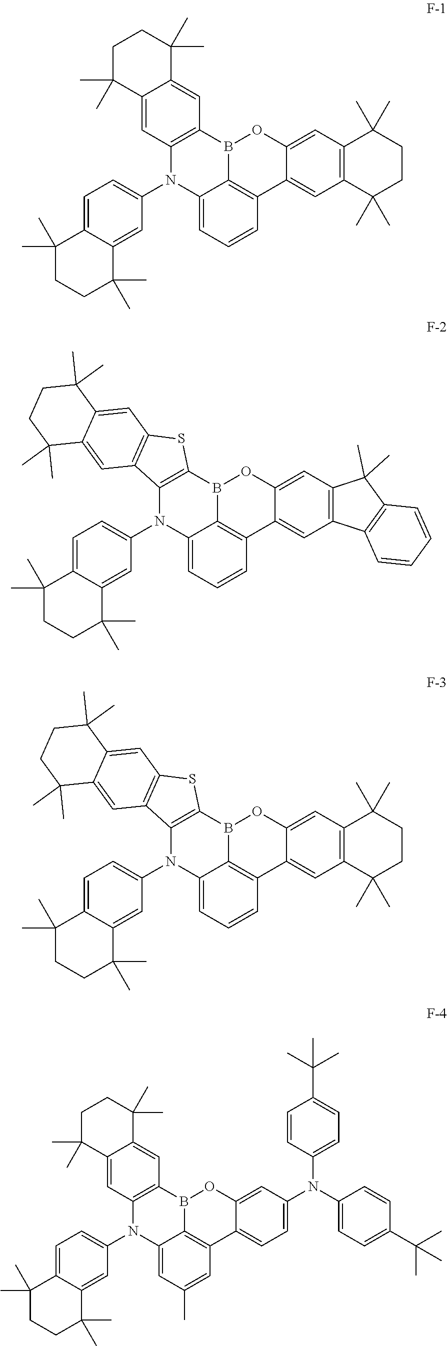 [SMILES: CC1(C)CCC(C)(C)c2cc(N3c4cc5c(cc4B4Oc6cc7c(cc6-c6cccc3c64)C(C)(C)CCC7(C)C)C(C)(C)CCC5(C)C)ccc21 ; CC1(C)CCC(C)(C)c2cc(N3c4cccc5c4B(Oc4cc6c(cc4-5)-c4ccccc4C6(C)C)c4sc5cc6c(cc5c43)C(C)(C)CCC6(C)C)ccc21 ; CC1(C)CCC(C)(C)c2cc(N3c4cccc5c4B(Oc4cc6c(cc4-5)C(C)(C)CCC6(C)C)c4sc5cc6c(cc5c43)C(C)(C)CCC6(C)C)ccc21 ; Cc1cc2c3c(c1)N(c1ccc4c(c1)C(C)(C)CCC4(C)C)c1cc4c(cc1B3Oc1cc(N(c3ccc(C(C)(C)C)cc3)c3ccc(C(C)(C)C)cc3)ccc1-2)C(C)(C)CCC4(C)C]

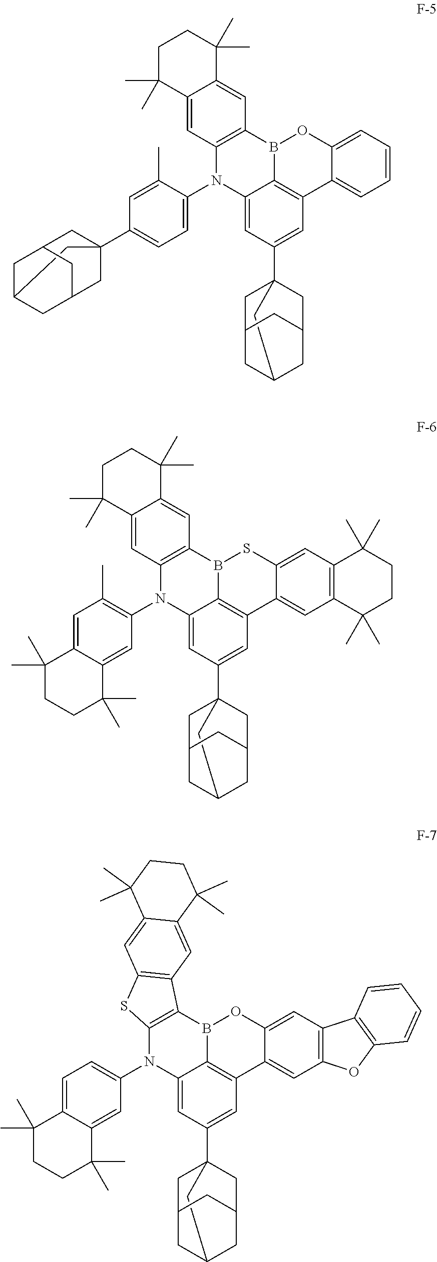

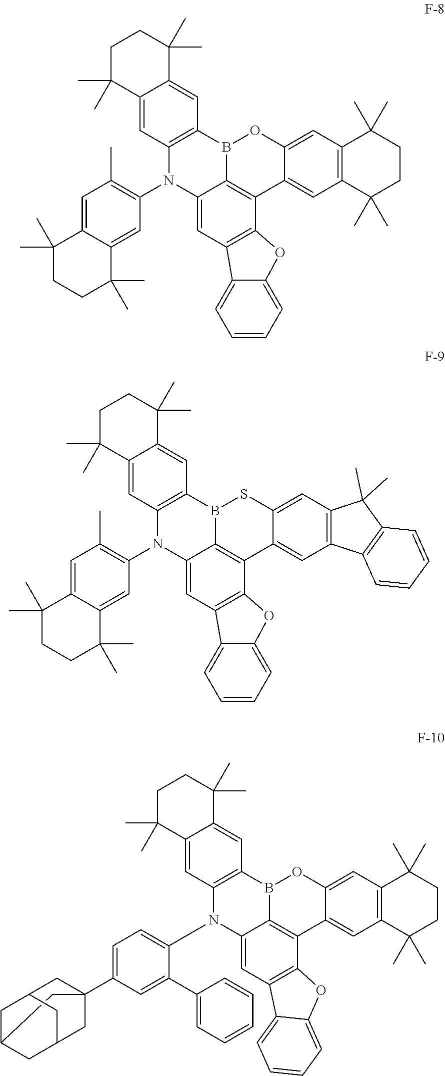 [SMILES: Cc1cc2c(cc1N1c3cc4c(cc3B3Oc5cc6c(cc5-c5c3c1cc1c5oc3ccccc31)C(C)(C)CCC6(C)C)C(C)(C)CCC4(C)C)C(C)(C)CCC2(C)C ; Cc1cc2c(cc1N1c3cc4c(cc3B3Sc5cc6c(cc5-c5c3c1cc1c5oc3ccccc31)-c1ccccc1C6(C)C)C(C)(C)CCC4(C)C)C(C)(C)CCC2(C)C ; CC1(C)CCC(C)(C)c2cc3c(cc21)OB1c2cc4c(cc2N(c2ccc(C56CC7CC(CC(C7)C5)C6)cc2-c2ccccc2)c2cc5c(oc6ccccc65)c-3c21)C(C)(C)CCC4(C)C]

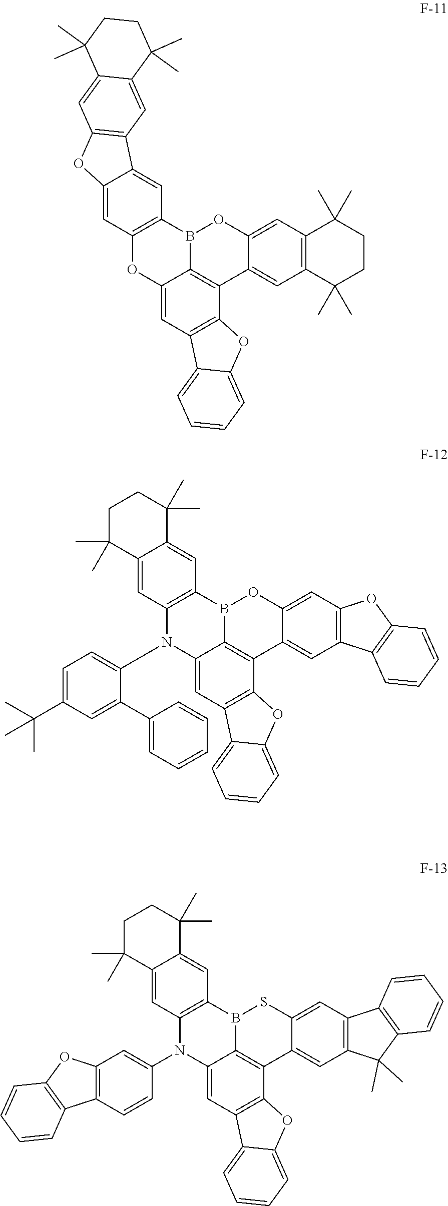 [SMILES: CC1(C)CCC(C)(C)c2cc3c(cc21)OB1c2cc4c(cc2Oc2cc5c(oc6ccccc65)c-3c21)oc1cc2c(cc14)C(C)(C)CCC2(C)C ; CC(C)(C)c1ccc(N2c3cc4c(cc3B3Oc5cc6oc7ccccc7c6cc5-c5c3c2cc2c5oc3ccccc32)C(C)(C)CCC4(C)C)c(-c2ccccc2)c1 ; CC1(C)CCC(C)(C)c2cc3c(cc21)B1Sc2cc4c(cc2-c2c1c(cc1c2oc2ccccc21)N3c1ccc2c(c1)oc1ccccc12)C(C)(C)c1ccccc1-4]

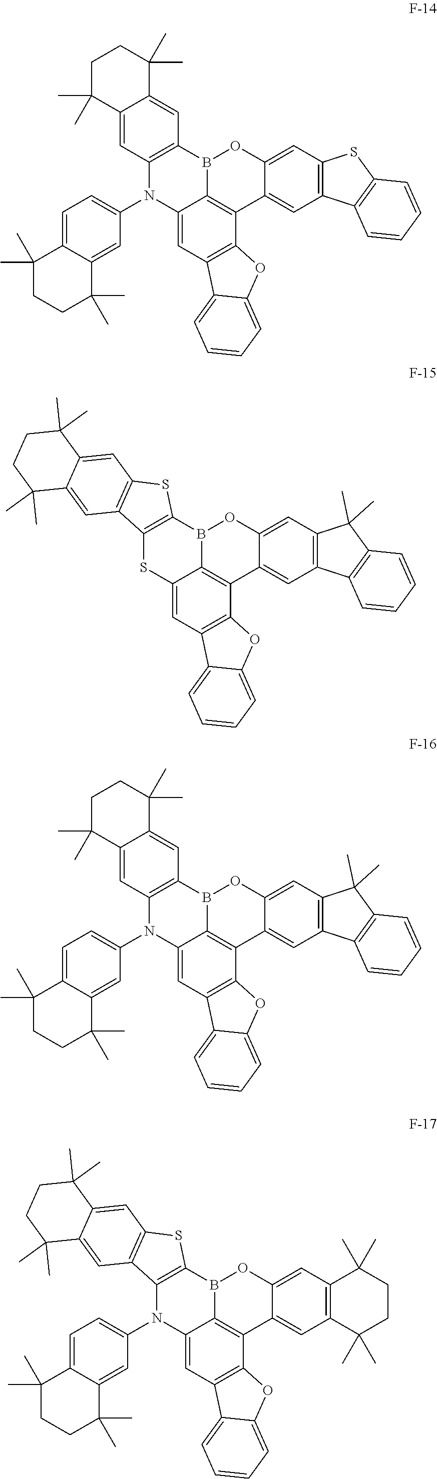

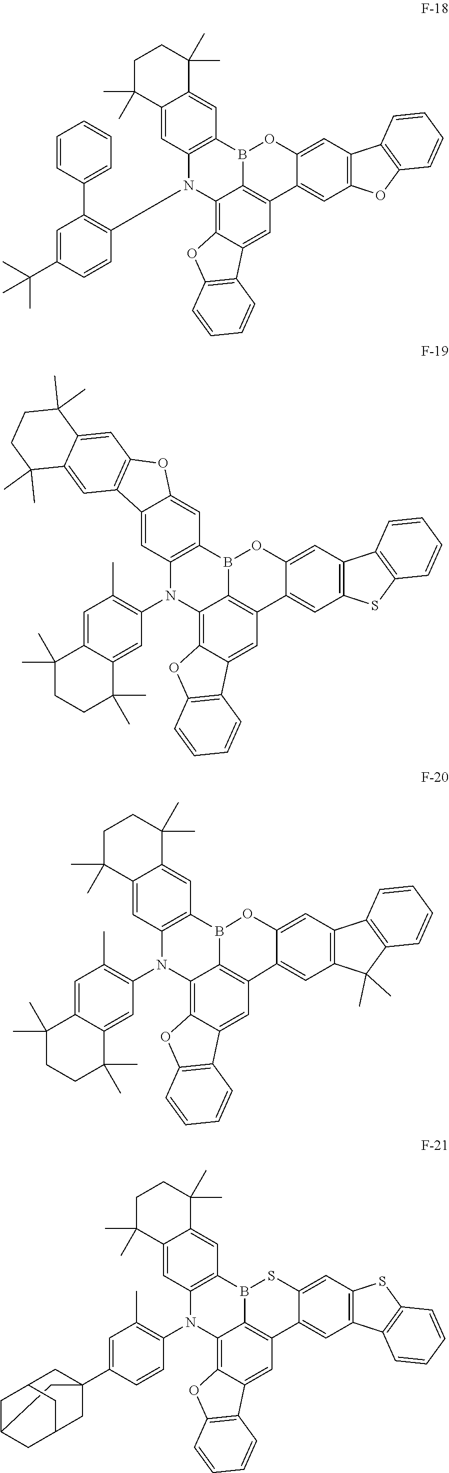

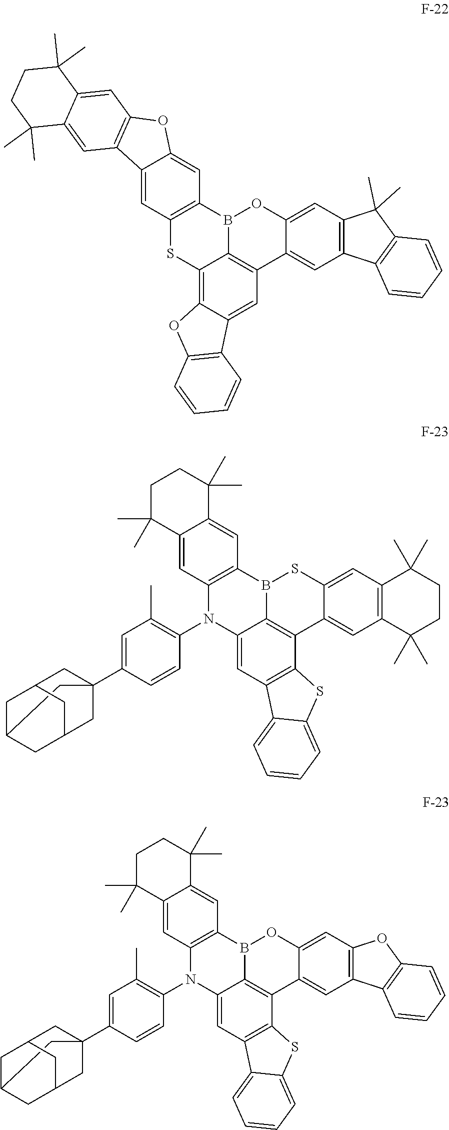

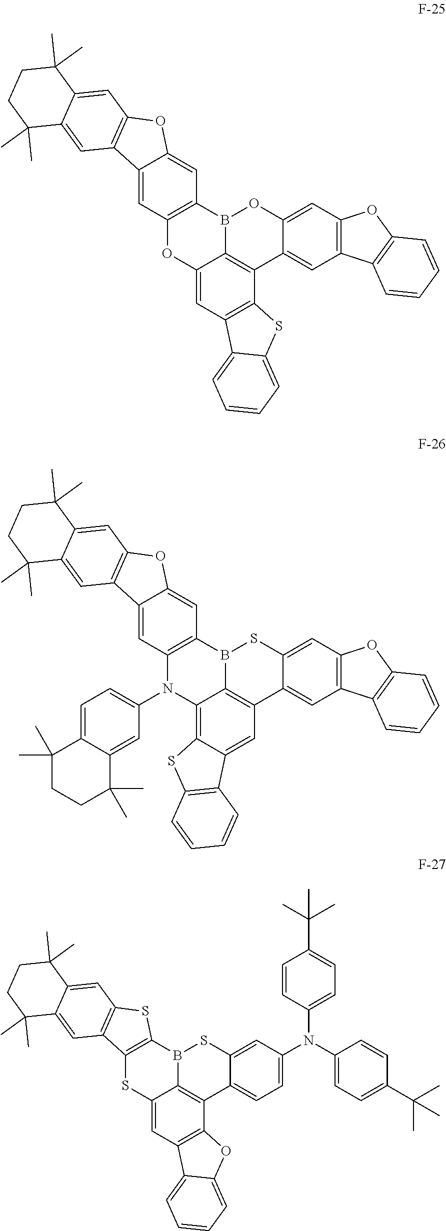

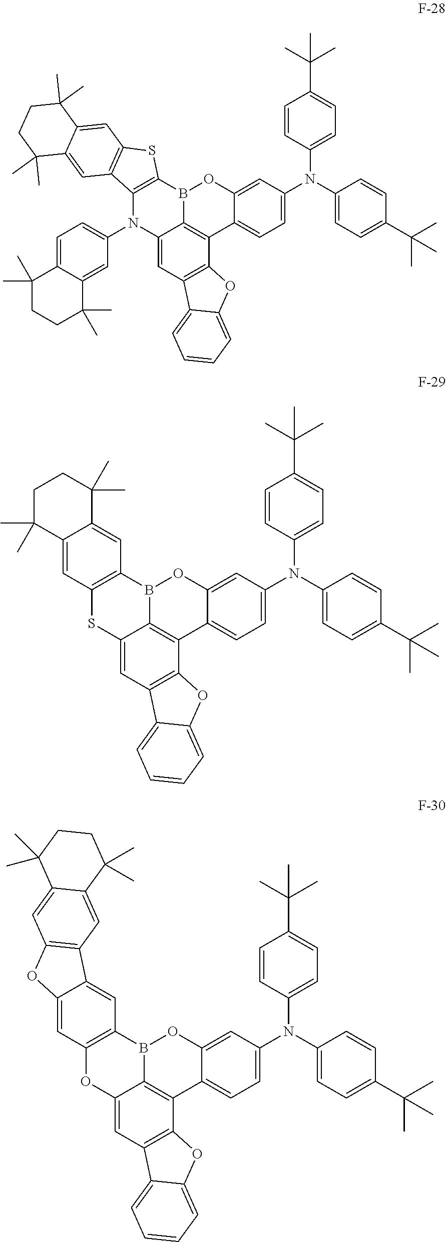

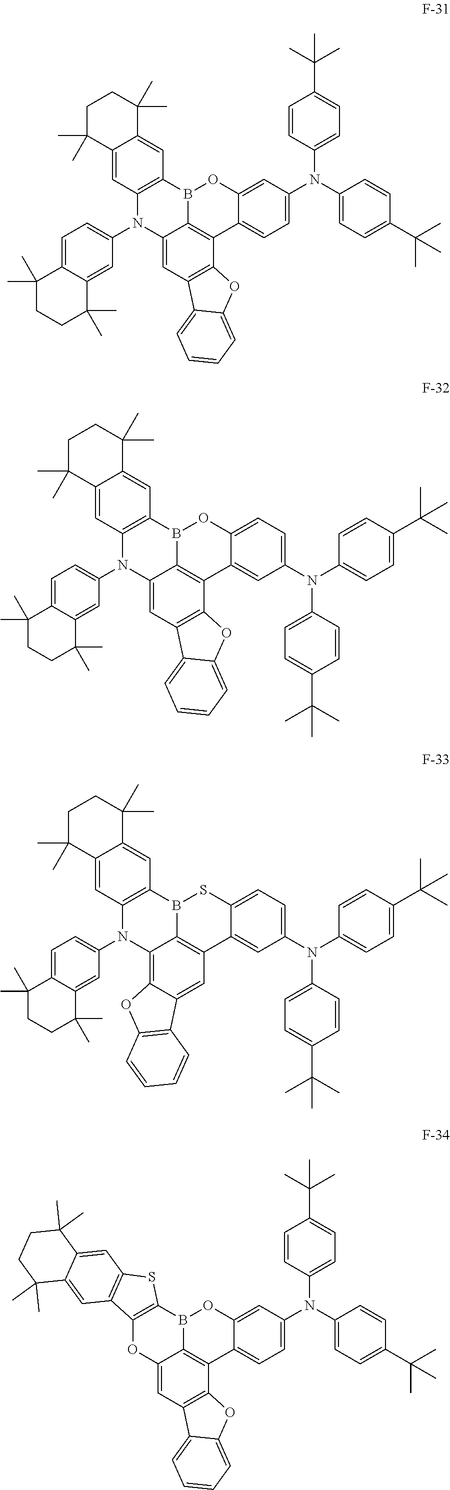

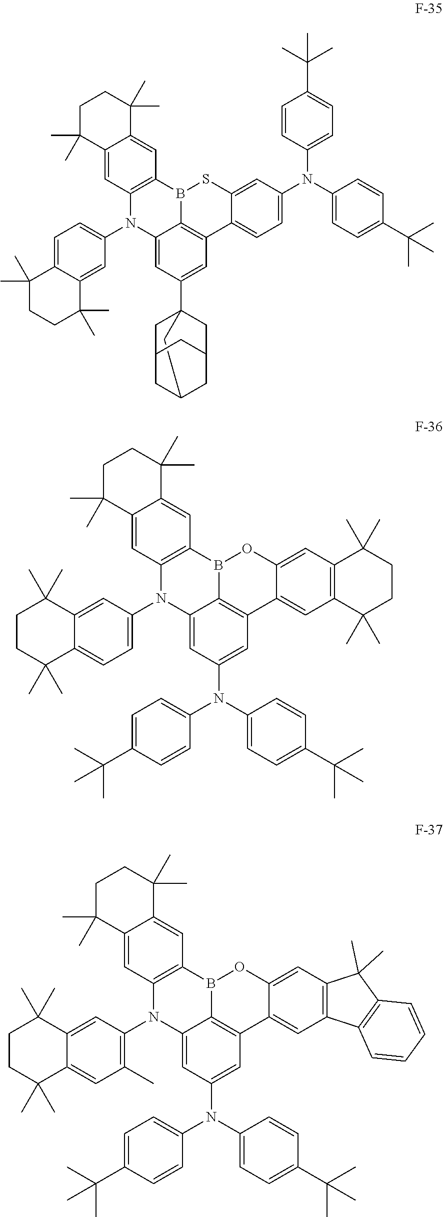

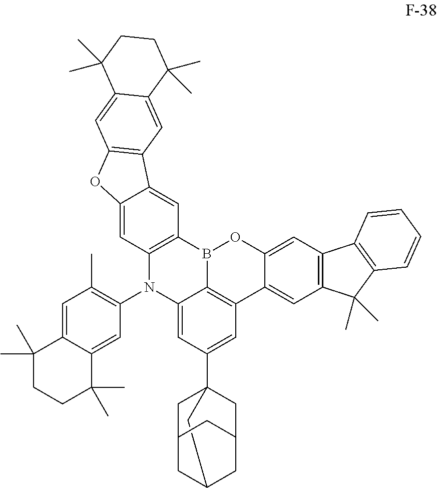

### Comparative Examples 1 to 6

Organic light emitting devices of Comparative Examples 1 to 6 were manufactured in the same manner as in Example 1, except that the compounds in the following Table 1 were used instead of Compound F-1 in Example 1.

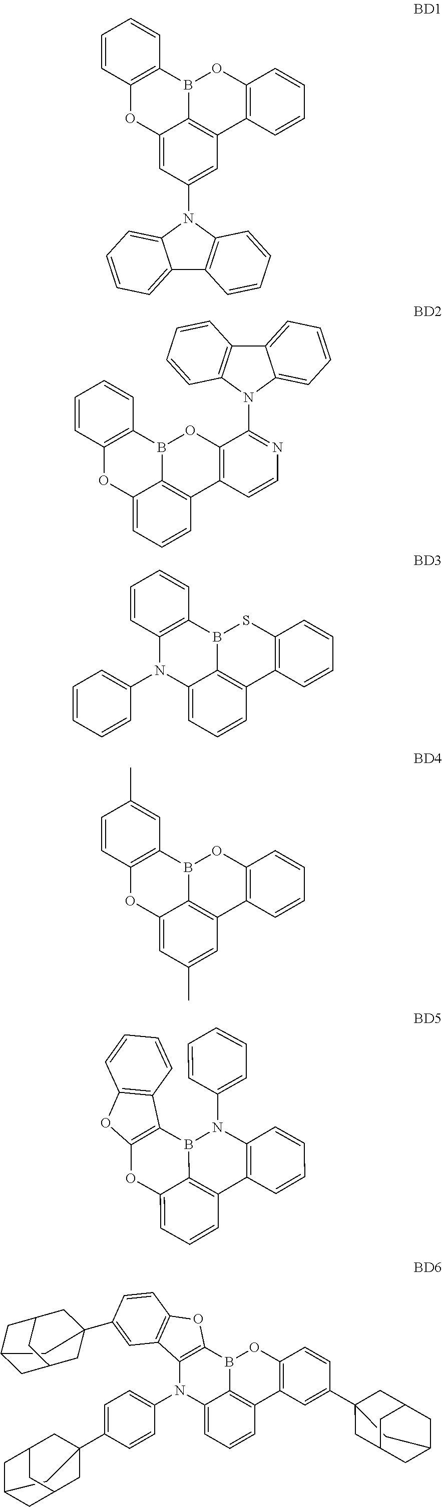

The voltage, efficiency, and service life of the organic light emitting devices manufactured in Examples 1 to 38 and Comparative Examples 1 to 6 were measured, and the results are shown in the following Table 1.

TABLE 1

| | Voltage | Efficiency | Service life |
|---|---|---|---|
| Material | (V) | (CB) | T95 (hr) |
| Example 1 (Compound 1) | 3.52 | 180 | 220 |
| Example 2 (Compound 2) | 3.53 | 181 | 222 |
| Example 3 (Compound 3) | 3.51 | 181 | 221 |
| Example 4 (Compound 4) | 3.40 | 191 | 230 |
| Example 5 (Compound 5) | 3.52 | 182 | 220 |
| Example 6 (Compound 6) | 3.45 | 191 | 231 |
| Example 7 (Compound 7) | 3.46 | 190 | 233 |
| Example 8 (Compound 8) | 3.41 | 193 | 231 |
| Example 9 (Compound 9) | 3.47 | 192 | 234 |
| Example 10 (Compound 10) | 3.45 | 190 | 235 |
| Example 11 (Compound 11) | 3.54 | 180 | 220 |
| Example 12 (Compound 12) | 3.51 | 184 | 223 |
| Example 13 (Compound 13) | 3.55 | 183 | 221 |
| Example 14 (Compound 14) | 3.45 | 192 | 231 |
| Example 15 (Compound 15) | 3.52 | 181 | 224 |
| Example 16 (Compound 16) | 3.43 | 194 | 233 |
| Example 17 (Compound 17) | 3.44 | 192 | 231 |
| Example 18 (Compound 18) | 3.55 | 182 | 221 |
| Example 19 (Compound 19) | 3.45 | 193 | 234 |
| Example 20 (Compound 20) | 3.44 | 191 | 230 |
| Example 21 (Compound 21) | 3.45 | 194 | 235 |
| Example 22 (Compound 22) | 3.52 | 185 | 223 |
| Example 23 (Compound 23) | 3.43 | 191 | 235 |
| Example 24 (Compound 24) | 3.45 | 194 | 231 |
| Example 25 (Compound 25) | 3.51 | 182 | 225 |
| Example 26 (Compound 26) | 3.45 | 194 | 232 |
| Example 27 (Compound 27) | 3.46 | 194 | 233 |
| Example 28 (Compound 28) | 3.41 | 196 | 237 |
| Example 29 (Compound 29) | 3.47 | 193 | 234 |
| Example 30 (Compound 30) | 3.46 | 194 | 232 |
| Example 31 (Compound 31) | 3.42 | 198 | 238 |
| Example 32 (Compound 32) | 3.43 | 196 | 237 |
| Example 33 (Compound 33) | 3.41 | 195 | 238 |
| Example 34 (Compound 34) | 3.46 | 193 | 234 |
| Example 35 (Compound 35) | 3.41 | 198 | 238 |
| Example 36 (Compound 36) | 3.41 | 197 | 236 |
| Example 37 (Compound 37) | 3.42 | 196 | 235 |
| Example 38 (Compound 38) | 3.45 | 191 | 234 |
| Comparative Example 1 | 4.22 | 143 | 145 |
| (BD1) | | | |
| Comparative Example 2 | 4.53 | 141 | 123 |
| (BD2) | | | |
| Comparative Example 3 | 4.12 | 138 | 133 |
| (BD3) | | | |
| Comparative Example 4 | 4.31 | 139 | 136 |
| (BD4) | | | |
| Comparative Example 5 | 4.41 | 141 | 152 |
| (BD5) | | | |
| Comparative Example 6 | 4.05 | 152 | 150 |
| (BD6) | | | |

According to Table 1 above, it can be confirmed that the organic light emitting devices of Comparative Examples 1 and 2 using Comparative Example Compounds BD1 and BD2 in which one or more of Ar1 to Ar3, in Chemical Formula 1 of the present application are a hetero ring including nitrogen (N) as a heteroelement, have a voltage remarkably higher than that of Examples 1 to 38 of the present application.

It can be confirmed that the organic light emitting devices of Comparative Examples 3 and 6 using Comparative Example Compounds BD3 and BD6, which include a substituted N atom (NR) corresponding to the position of X in Chemical Formula 1 of the present application, that do not include a ring, in which at least one substituted or unsubstituted aliphatic hydrocarbon ring is fused, have high voltage, low efficiency, and deteriorated service life characteristics compared to Examples 1 to 38 of the present application.

It can be confirmed that the organic light emitting device of Comparative Example 4 using Comparative Example Compound BD4, in which at least one of Ar1, Ar2, and Ar3 of Chemical Formula 1 of the present application does not include a hetero ring; or a substituted or unsubstituted aliphatic hydrocarbon ring, has remarkably deteriorated efficiency and device characteristics compared to Examples 1 to 38 of the present application.

It can be confirmed that the organic light emitting device of Comparative Example 5 using Comparative Example Compound BD5, in which Y in Chemical Formula 1 of the present application is N and the core structure of Chemical Formula 1 of the present application is different, has a remarkably high voltage and deteriorated efficiency and device characteristics compared to Examples 1 to 38 of the present application.

In conclusion, it could be confirmed that the organic light emitting devices of Examples 1 to 38 using the compound according to Chemical Formula 1 of the present specification have remarkably excellent voltage, efficiency, and service life characteristics compared to the organic light emitting devices of Comparative Examples 1 to 6.

### Explanation of Reference Numerals and Symbols

1: Substrate
2: Positive electrode
3: Hole injection layer
4: Hole Transport layer
5: Electron blocking layer
6: Light Emitting Layer
7: First electron transport layer
8: Second electron transport layer
9: Electron injection layer
10: Negative electrode

1. A compound represented by the following Chemical Formula 1: 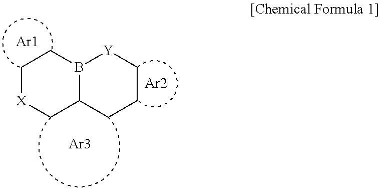
wherein, in Chemical Formula 1:
X is NR, O, or S;
Y is O or S;
Ar1, Ar2 and Ar3 are the same as or different from each other, and are each independently a substituted or unsubstituted monocyclic or polycyclic hydrocarbon ring, or a substituted or unsubstituted monocyclic or polycyclic hetero ring, provided that at least one of Ar1, Ar2 and Ar3 includes a hetero ring or a substituted or unsubstituted aliphatic hydrocarbon ring, and further, when X is NR, at least one of R, Ar1, Ar2 and Ar3 includes a ring in which substituted or unsubstituted aliphatic hydrocarbon rings are fused, fused;
when X is NR, at least one of Ar1 and Ar3 is optionally bonded to R to form a ring, and Ar2 and Ar3 are optionally bonded to each other to form a ring; and
R is hydrogen, deuterium, a substituted or unsubstituted alkyl group, a substituted or unsubstituted aryl group, or a substituted or unsubstituted heteroaryl group.

2. The compound of claim 1, wherein Ar1, Ar2 and Ar3 are the same as or different from each other, and are each independently a substituted or unsubstituted aromatic hydrocarbon ring; a substituted or unsubstituted fused ring of an aromatic hydrocarbon ring and an aliphatic hydrocarbon ring; a substituted or unsubstituted hetero ring; a substituted or unsubstituted fused ring of a hetero ring and an aromatic hydrocarbon ring; or a substituted or unsubstituted fused ring of a hetero ring, an aromatic hydrocarbon ring and an aliphatic hydrocarbon ring, and at least one of Ar1, Ar2 and Ar3 is a substituted or unsubstituted fused ring of an aromatic hydrocarbon ring and an aliphatic hydrocarbon ring, a substituted or unsubstituted hetero ring, a substituted or unsubstituted fused ring of a hetero ring and an aromatic hydrocarbon ring, or a substituted or unsubstituted fused ring of a hetero ring, an aromatic hydrocarbon ring and an aliphatic hydrocarbon ring.

3. The compound of claim 1, wherein Ar1, Ar2 and Ar3 are the same as or different from each other, and are each independently a substituted or unsubstituted aromatic hydrocarbon ring; a substituted or unsubstituted fused ring of an aromatic hydrocarbon ring and an aliphatic hydrocarbon ring; a substituted or unsubstituted hetero ring comprising O or S as a heteroelement; a substituted or unsubstituted fused ring of a hetero ring comprising O or S as a heteroelement and an aromatic hydrocarbon ring; or a substituted or unsubstituted fused ring of a hetero ring comprising O or S as a heteroelement, an aromatic hydrocarbon ring and an aliphatic hydrocarbon ring; and at least one of Ar1, Ar2 and Ar3 is a substituted or unsubstituted fused ring of an aromatic hydrocarbon ring and an aliphatic hydrocarbon ring; a substituted or unsubstituted hetero ring comprising O or S as a heteroelement; a substituted or unsubstituted fused ring of a hetero ring comprising O or S as a heteroelement and an aromatic hydrocarbon ring; or a substituted or unsubstituted fused ring of a hetero ring comprising O or S as a heteroelement, an aromatic hydrocarbon ring and an aliphatic hydrocarbon ring.

4. The compound of claim 1, wherein Ar1, Ar2 and Ar3 are the same as or different from each other, and are each independently substituted or unsubstituted benzene, substituted or unsubstituted tetrahydronaphthalene, substituted or unsubstituted fluorene, substituted or unsubstituted furan, substituted or unsubstituted benzofuran, substituted or unsubstituted dibenzofuran, substituted or unsubstituted tetrahydronaphthofuran, substituted or unsubstituted tetrahydrobenzonaphthofuran, substituted or unsubstituted thiophene, substituted or unsubstituted benzothiophene, substituted or unsubstituted dibenzothiophene, substituted or unsubstituted tetrahydronaphthothiophene, or substituted or unsubstituted tetrahydrobenzonaphthothiophene, and at least one of Ar1, Ar2 and Ar3 is substituted or unsubstituted tetrahydronaphthalene, substituted or unsubstituted furan, substituted or unsubstituted benzofuran, substituted or unsubstituted dibenzofuran, substituted or unsubstituted tetrahydronaphthofuran, substituted or unsubstituted tetrahydrobenzonaphthofuran, substituted or unsubstituted thiophene, substituted or unsubstituted benzothiophene, or substituted or unsubstituted dibenzothiophene, substituted or unsubstituted tetrahydronaphthothiophene, or substituted or unsubstituted tetrahydrobenzonaphthothiophene.

5. The compound of claim 1, wherein at least one of Ar1, Ar2 and Ar3 comprises a substituted or unsubstituted tetrahydronaphthalene, or X is NR and R comprises substituted or unsubstituted tetrahydronaphthalene.

6. The compound of claim 1, wherein at least one of Ar1 and Ar2 is a substituted or unsubstituted tetrahydronaphthalene, or X is NR and R is substituted or unsubstituted tetrahydronaphthalene, or at least one of Ar1 and Ar2 is a hetero ring in which a substituted or unsubstituted tetrahydronaphthalene is fused.

7. The compound of claim 1, wherein Chemical Formula 1 is represented by any one of the following Chemical Formulae 11 to 13: 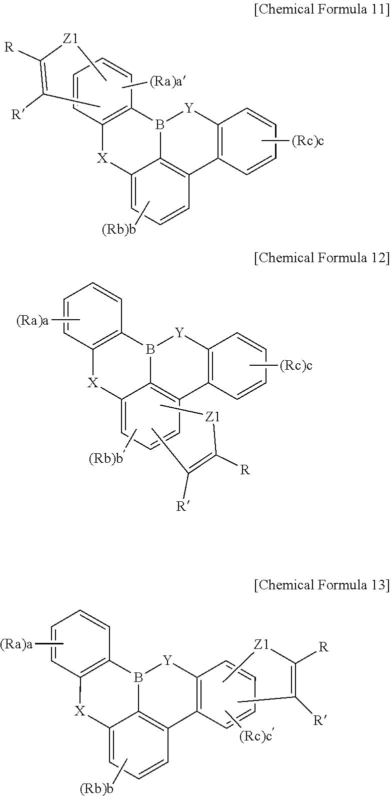
wherein in Chemical Formulae 11 to 13:
X and Y are the same as those defined in Chemical Formula 1;
Z1 is CRxRy, O or S; and
Ra to Rc, Rx, Ry, R and R′ are the same as or different from each other, and are each independently hydrogen, deuterium, a substituted or unsubstituted alkyl group, a substituted or unsubstituted aryl group, or a substituted or unsubstituted heteroaryl group, or are linked to adjacent groups to form a substituted or unsubstituted ring, a and c are each an integer from 0 to 4, b is an integer from 0 to 3, a′ and c′ are each an integer from 0 to 2, and b′ is 0 or 1.

8. The compound of claim 7, wherein Chemical Formula 1 is represented by any one of the following Chemical Formulae 21 to 23: 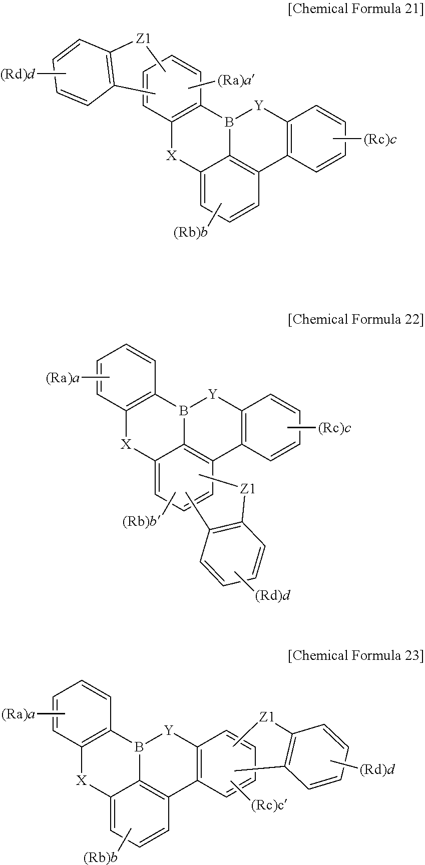
wherein in Chemical Formulae 21 to 23:
X, Y, Z1, Ra to Rc, a, b, c, a′, b′ and c′ are the same as those described above; and
the Rds are the same as or different from each other, and are each independently hydrogen, deuterium, a substituted or unsubstituted alkyl group, a substituted or unsubstituted aryl group, or a substituted or unsubstituted heteroaryl group, or are linked to adjacent groups to form a substituted or unsubstituted ring, and d is an integer from 0 to 4.

9. The compound of claim 8, wherein Chemical Formula 1 is represented by any one of the following Chemical Formulae 31 to 34: 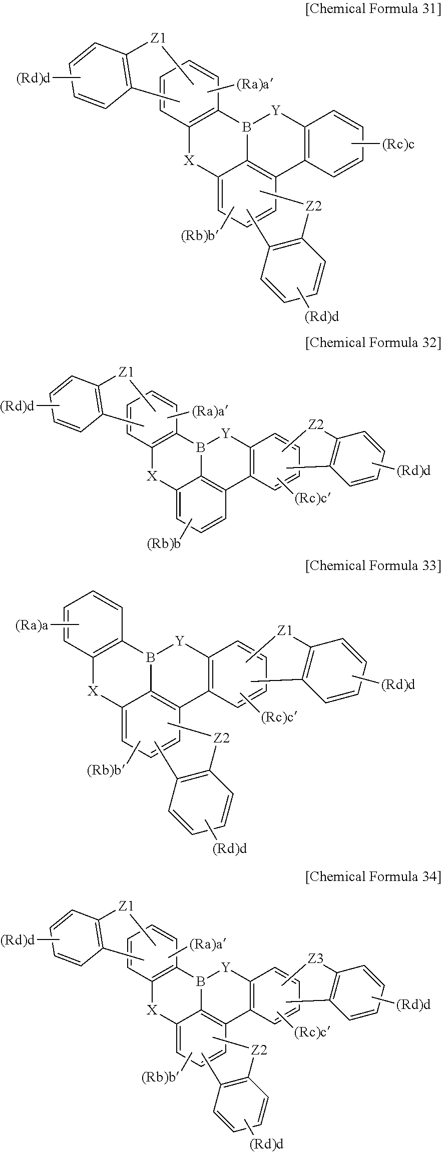
wherein in Chemical Formulae 31 to 34:
X, Y, Z1, Ra to Rd, a, b, c, d, a′, b′ and c′ are the same as those described above; and
Z2 and Z3 are the same as or different from each other, and are each independently CRxRy, O or S, and the definitions of Rx and Ry are the same as those described above.

10. The compound of claim 1, wherein Chemical Formula 1 is represented by any one of the following Chemical Formulae 41 to 43: 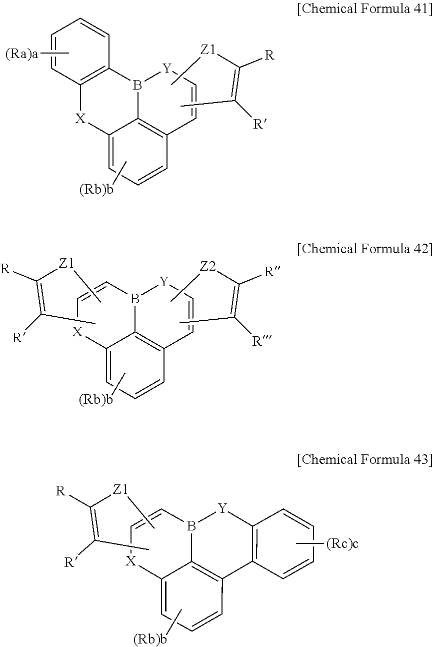
wherein in Chemical Formulae 41 to 43:
X and Y are the same as those defined in Chemical Formula 1;
Z1 and Z2 are each independently CRxRy, O or S; and
Ra to Rc, Rx, Ry, R, R′, R″ and R′″ are the same as or different from each other, and are each independently hydrogen, deuterium, a substituted or unsubstituted alkyl group, a substituted or unsubstituted aryl group, or a substituted or unsubstituted heteroaryl group, or are linked to adjacent groups to form a substituted or unsubstituted ring, a and c are each an integer from 0 to 4, and b is an integer from 0 to 3.

11. The compound of claim 10, wherein R and R′ of Chemical Formula 43 are bonded to each other to form a substituted or unsubstituted benzene, or a substituted or unsubstituted tetrahydronaphthalene.

12. The compound of claim 1, wherein the compound represented by Chemical Formula 1 is any one of the following compounds:

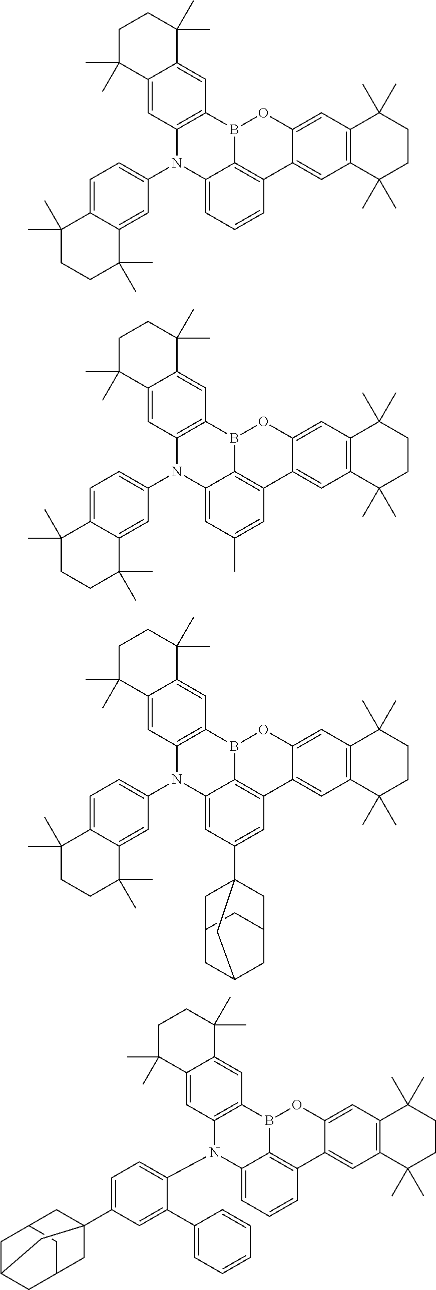

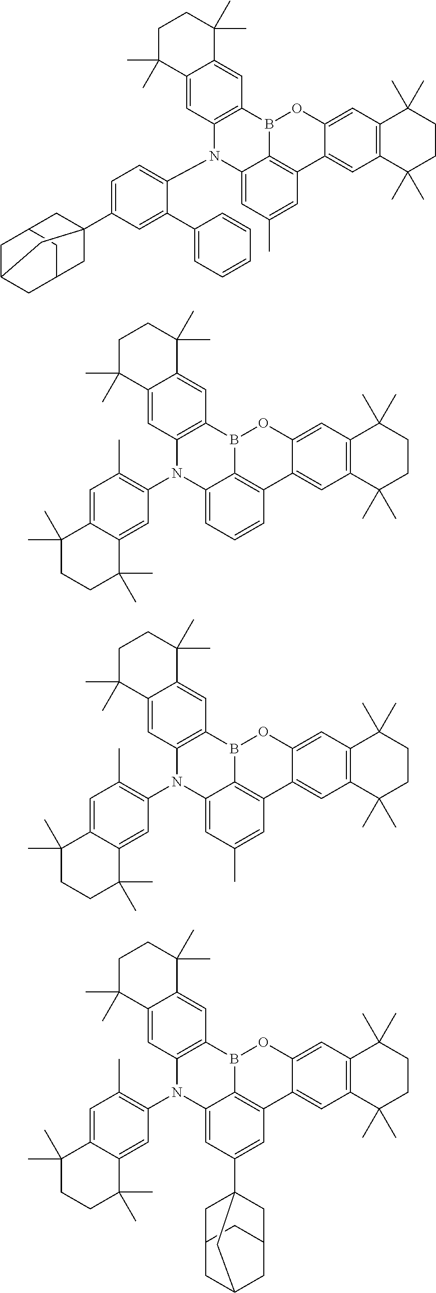

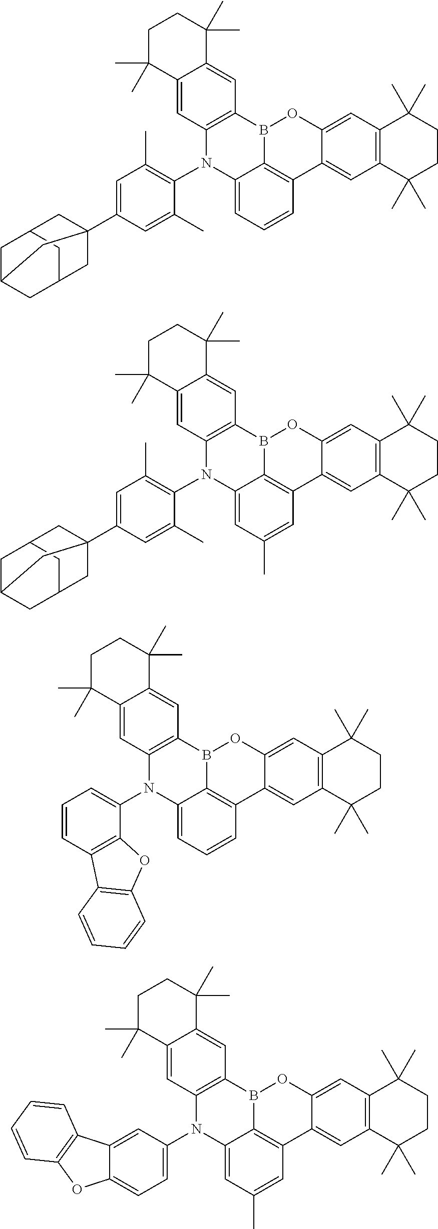 [SMILES: Cc1cc(C23CC4CC(CC(C4)C2)C3)cc(C)c1N1c2cc3c(cc2B2Oc4cc5c(cc4-c4cccc1c42)C(C)(C)CCC5(C)C)C(C)(C)CCC3(C)C ; Cc1cc2c3c(c1)N(c1c(C)cc(C45CC6CC(CC(C6)C4)C5)cc1C)c1cc4c(cc1B3Oc1cc3c(cc1-2)C(C)(C)CCC3(C)C)C(C)(C)CCC4(C)C ; CC1(C)CCC(C)(C)c2cc3c(cc21)OB1c2cc4c(cc2N(c2cccc5c2oc2ccccc25)c2cccc-3c21)C(C)(C)CCC4(C)C ; Cc1cc2c3c(c1)N(c1ccc4oc5ccccc5c4c1)c1cc4c(cc1B3Oc1cc3c(cc1-2)C(C)(C)CCC3(C)C)C(C)(C)CCC4(C)C]

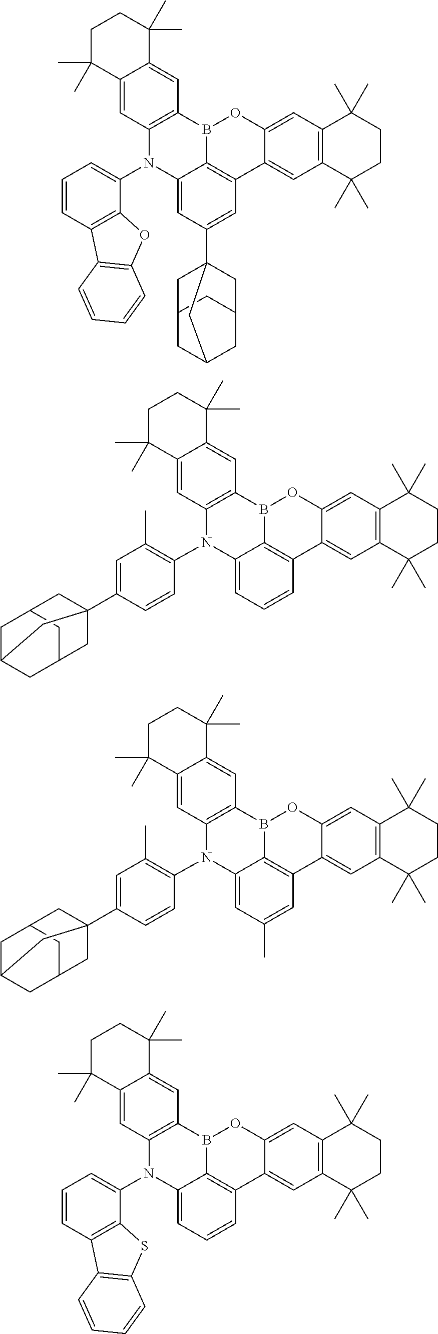

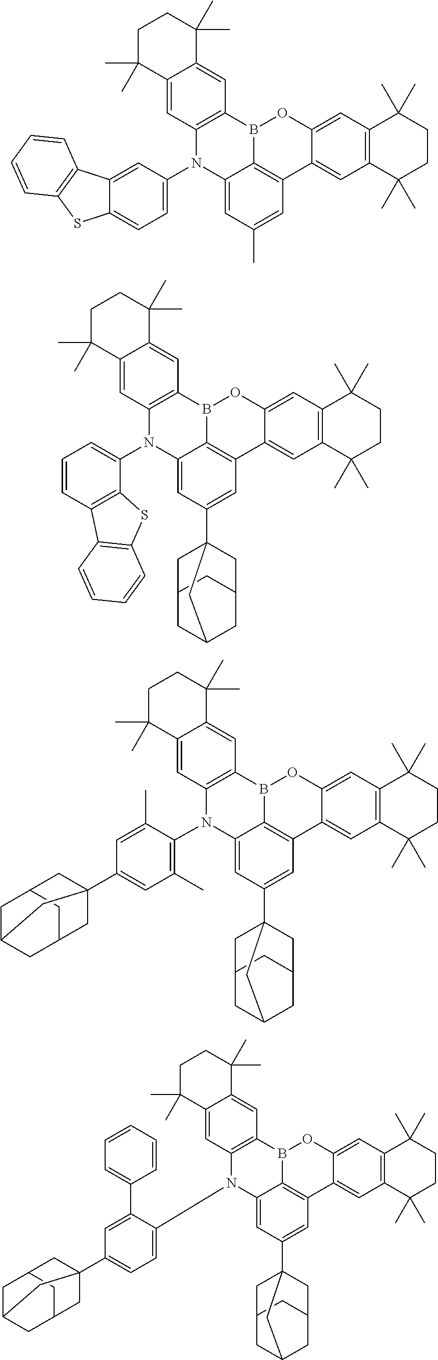

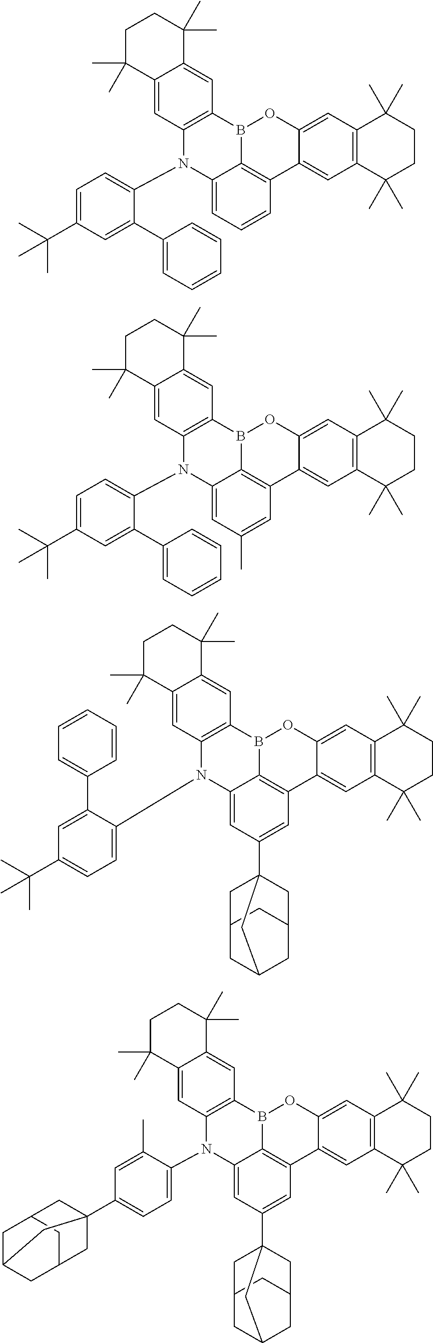

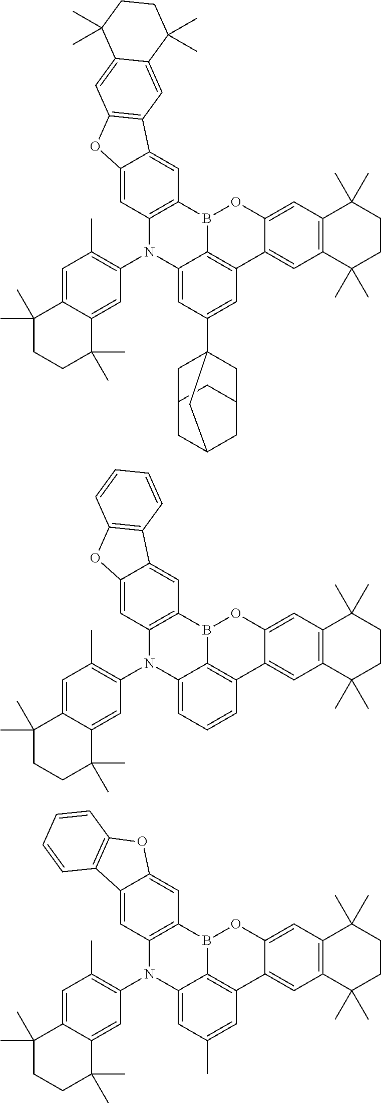

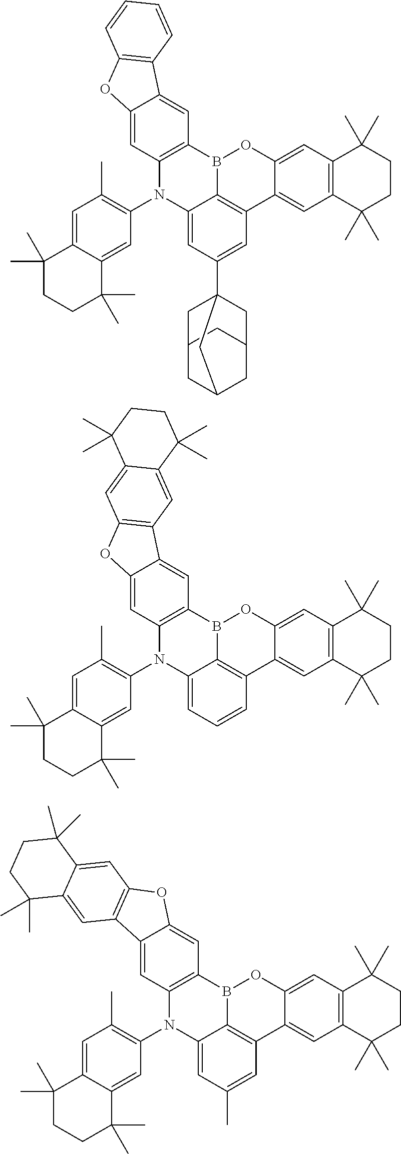

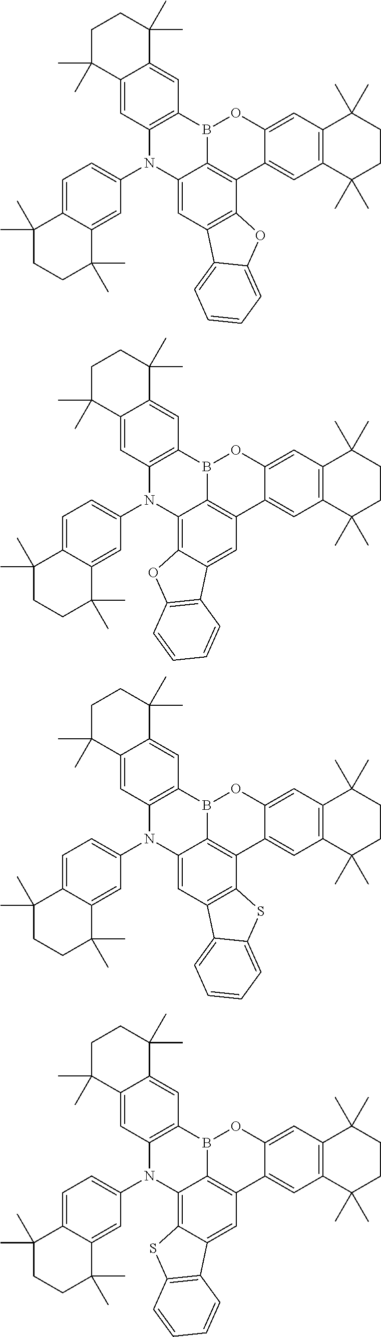

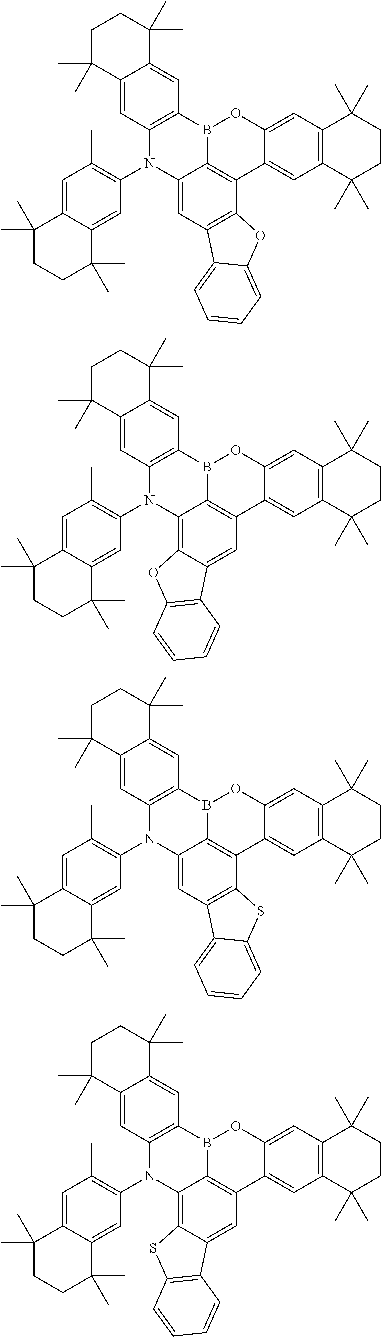

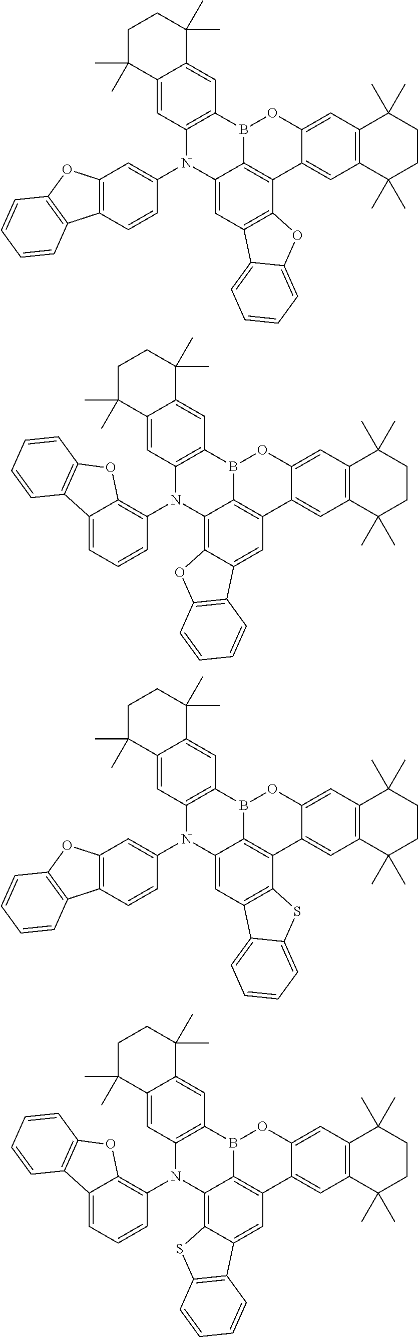

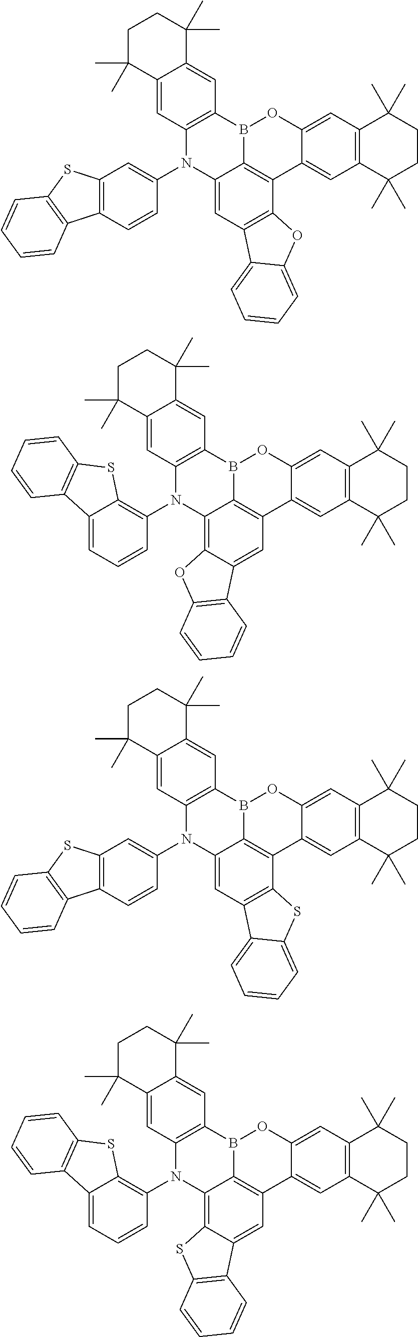

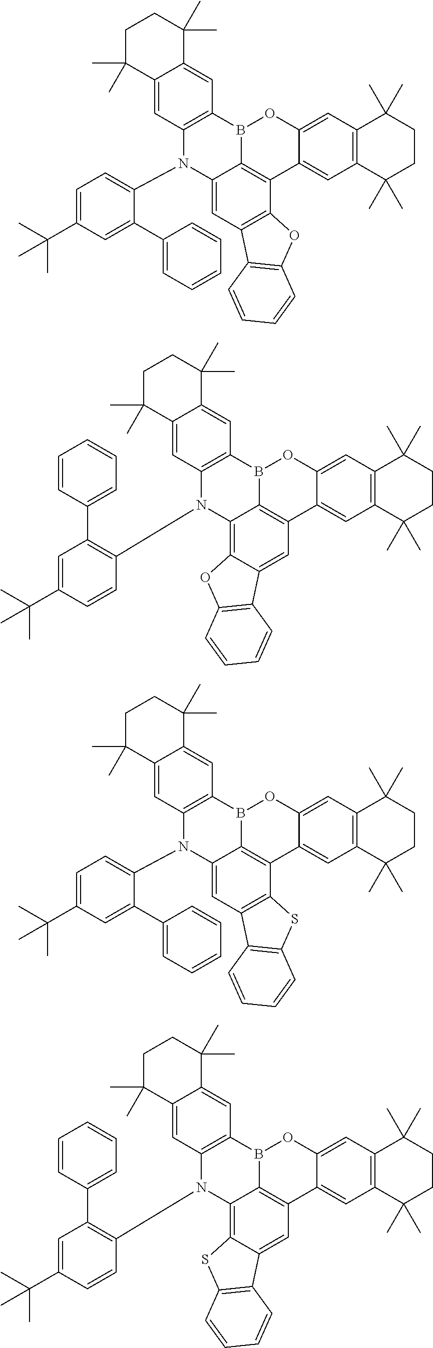

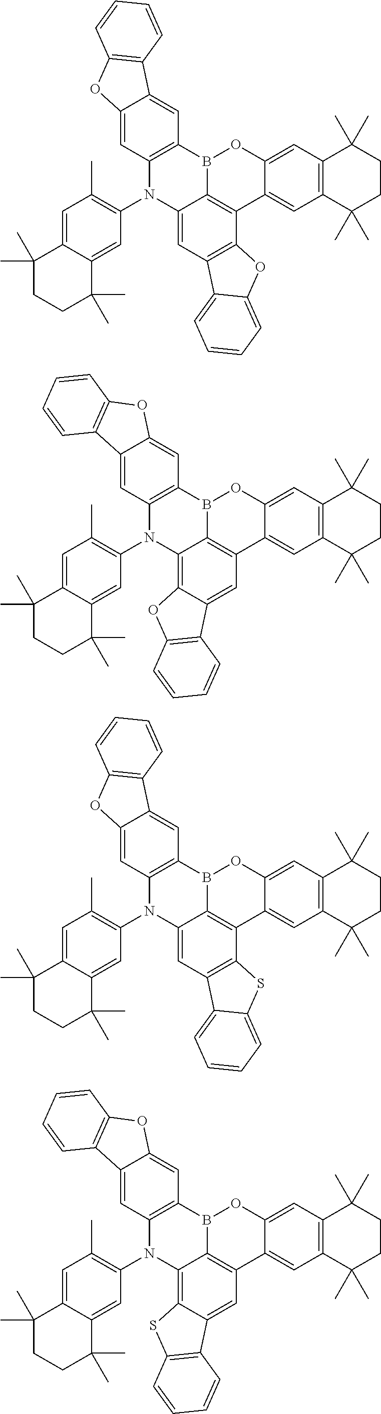

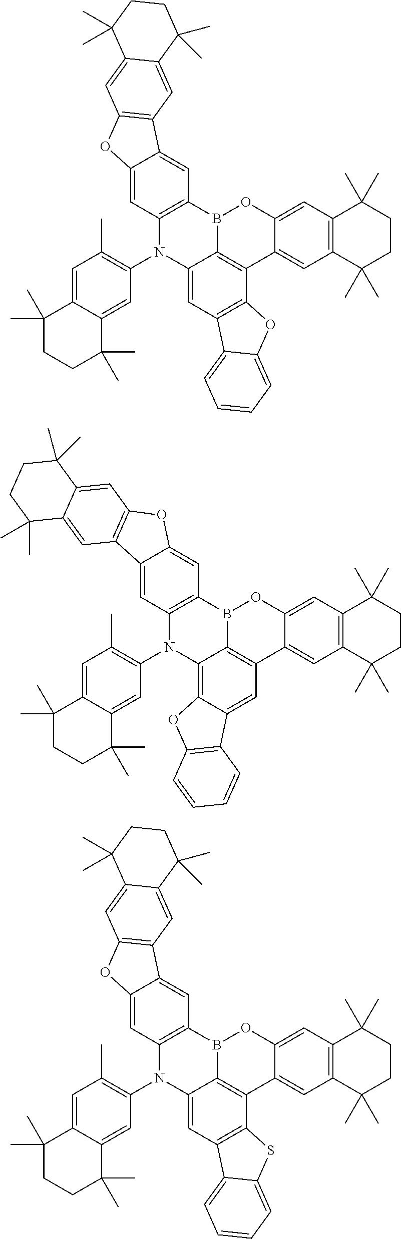

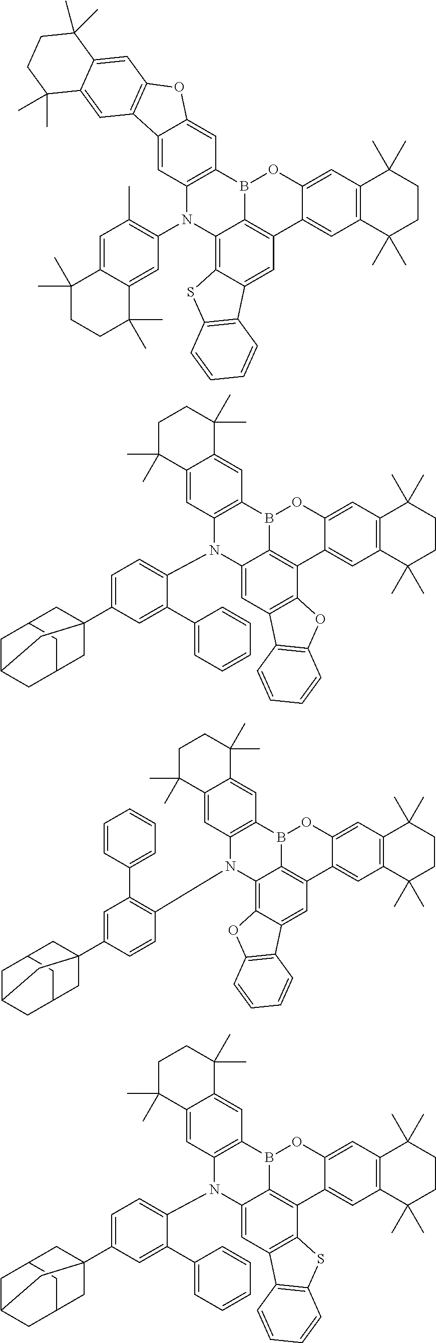

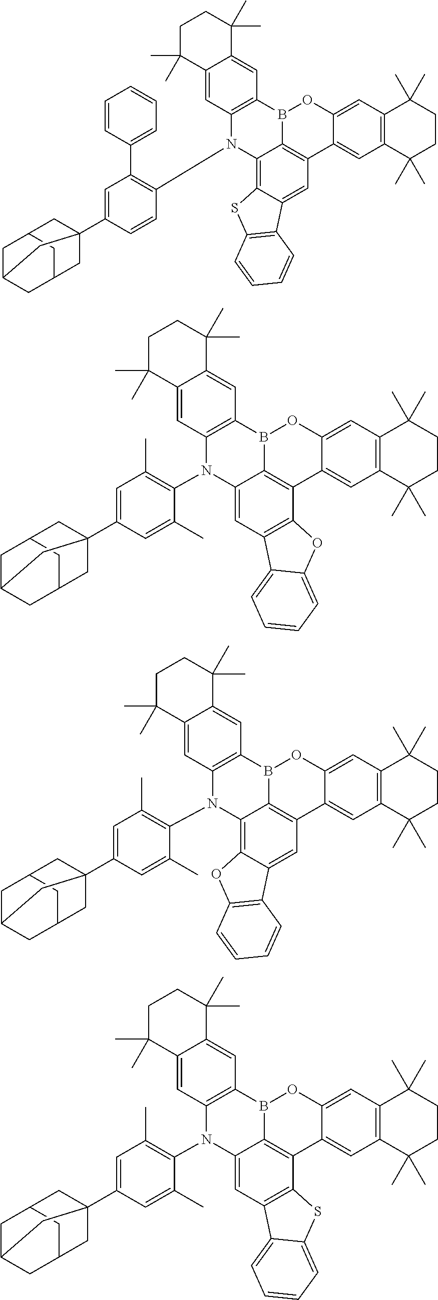

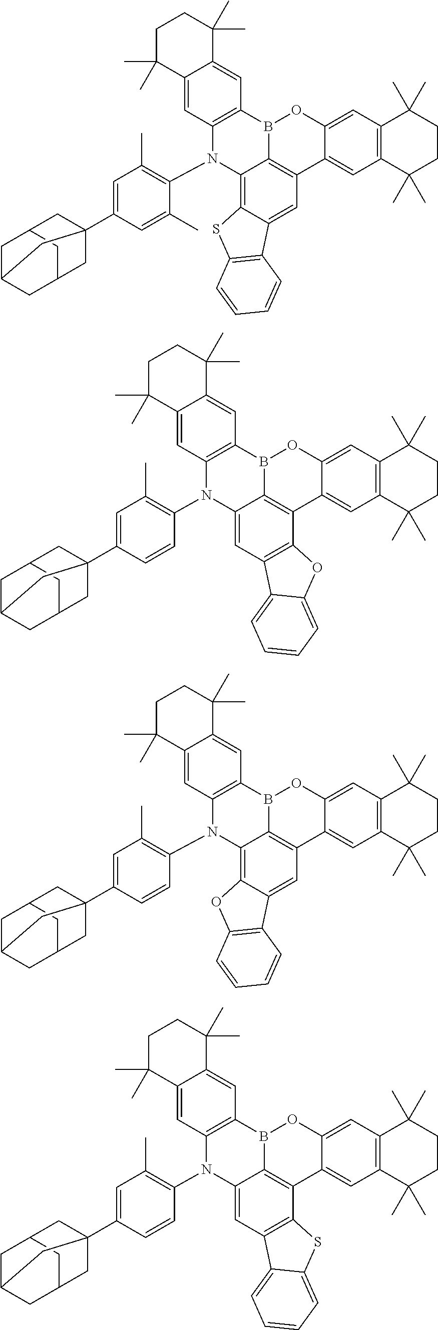

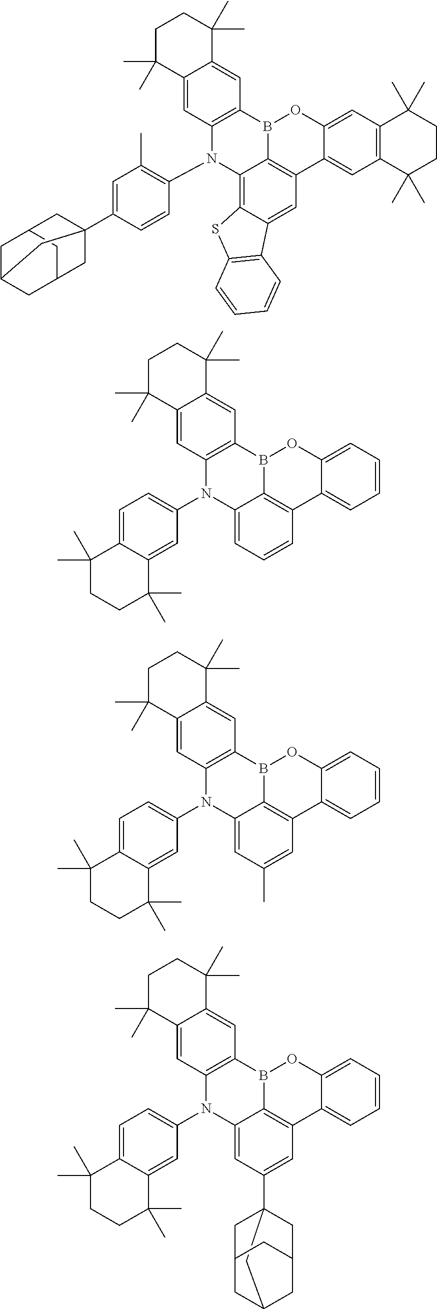

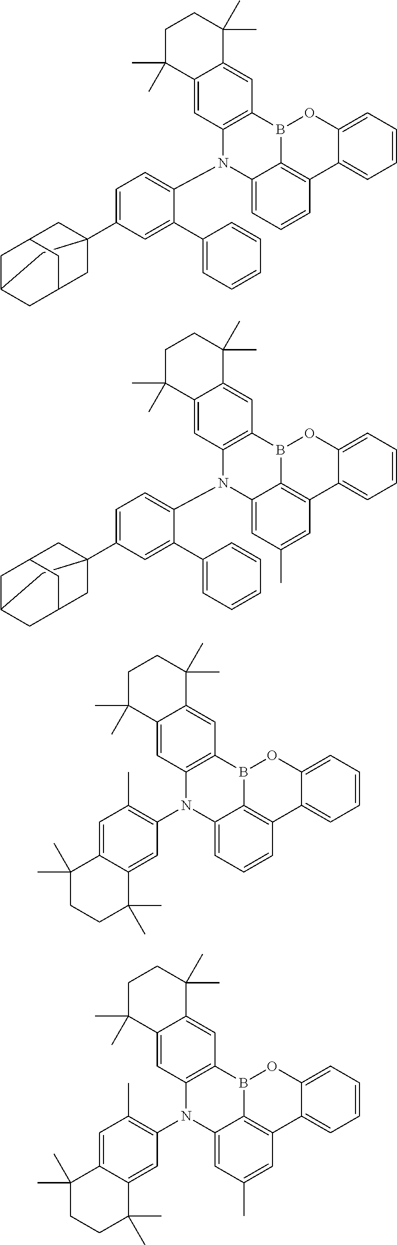

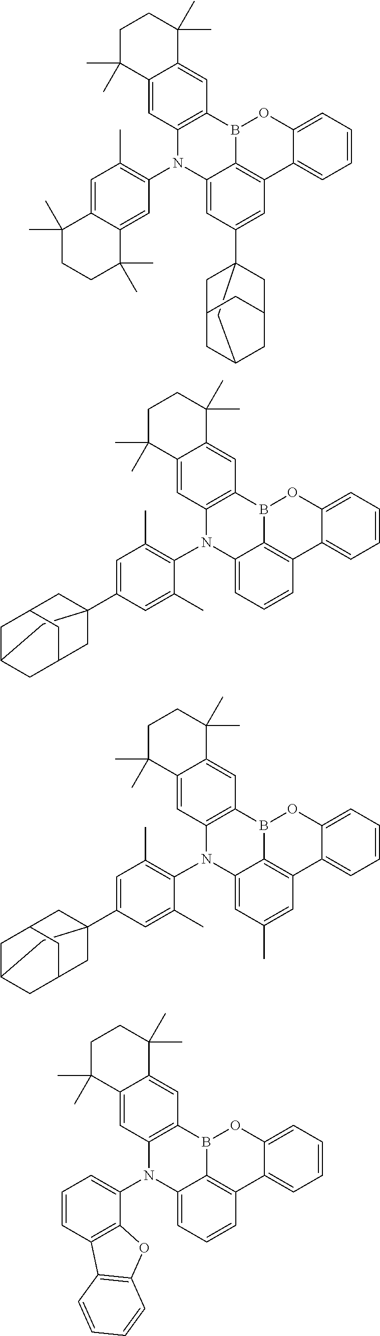

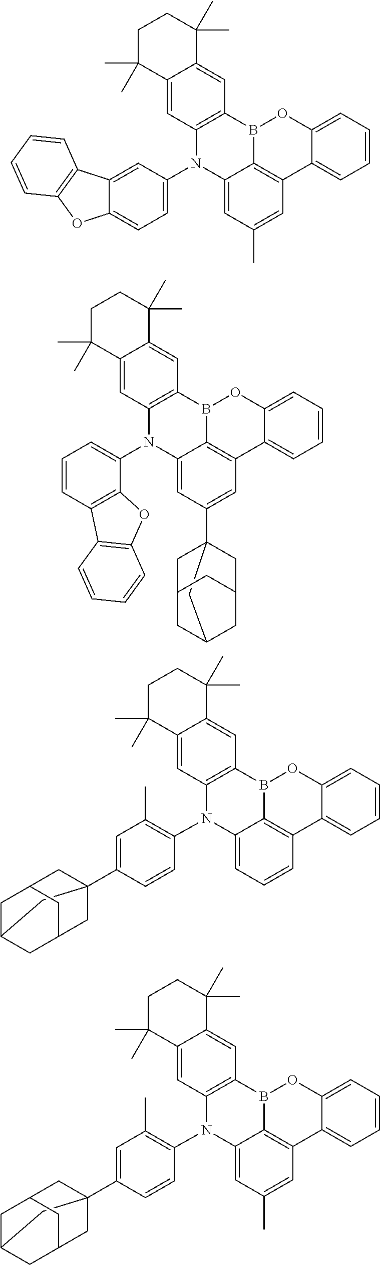

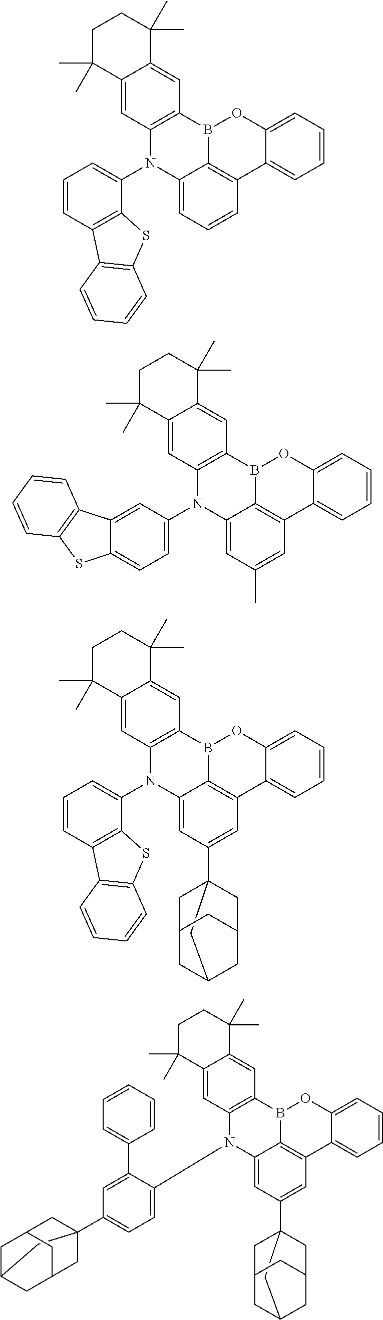

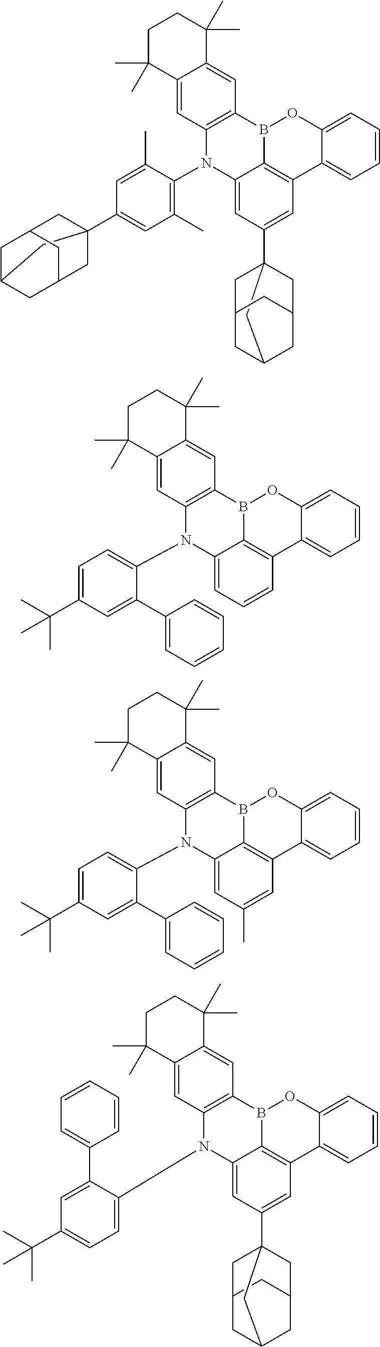

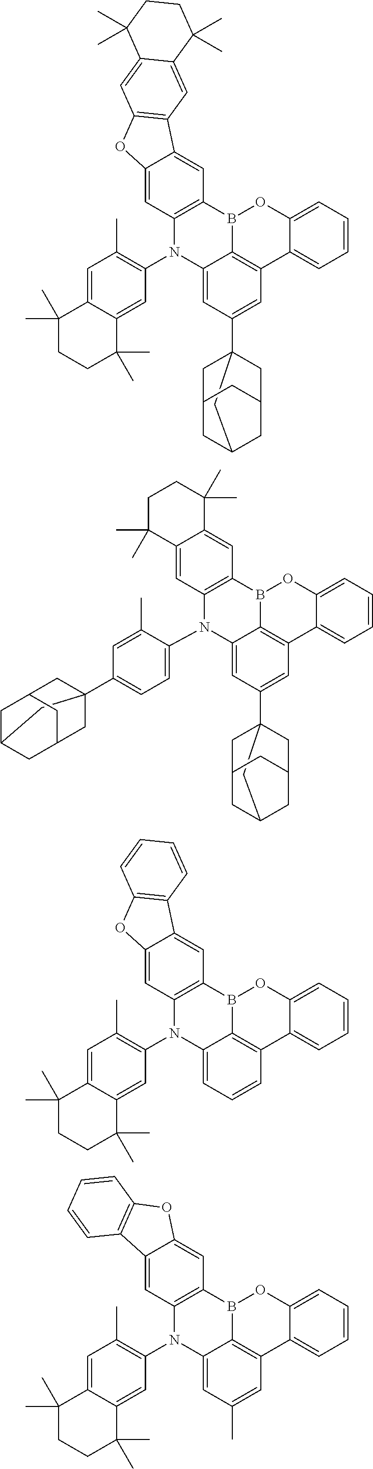

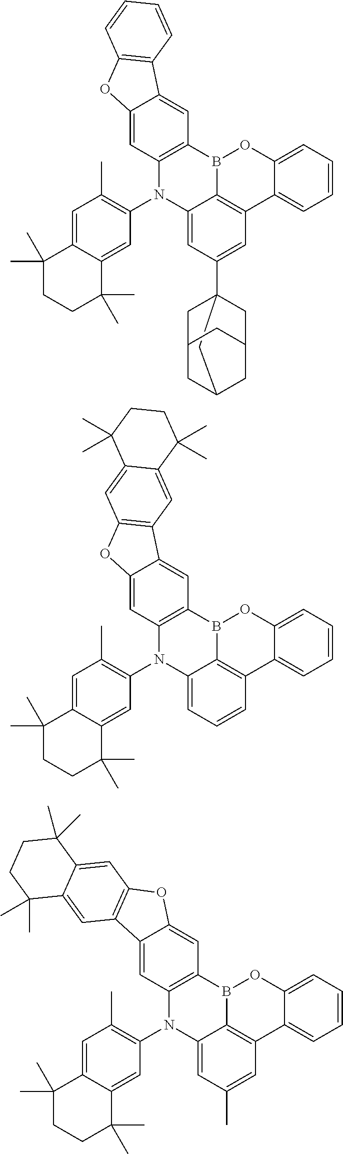

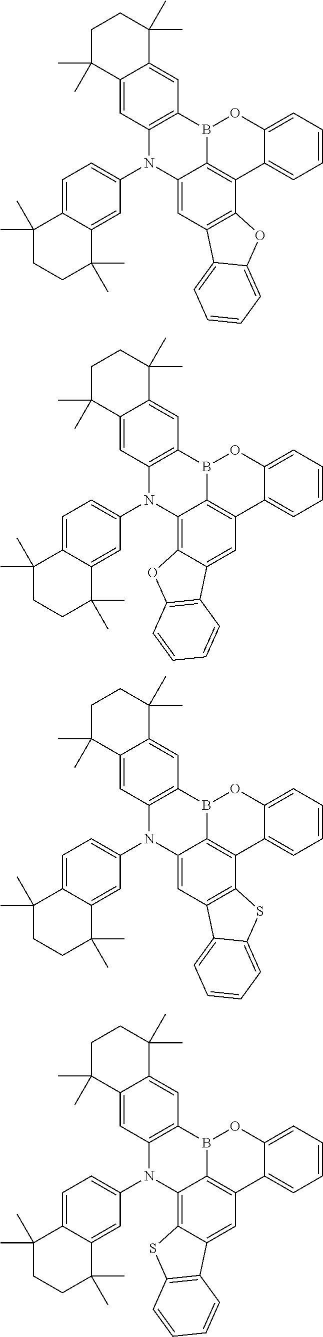

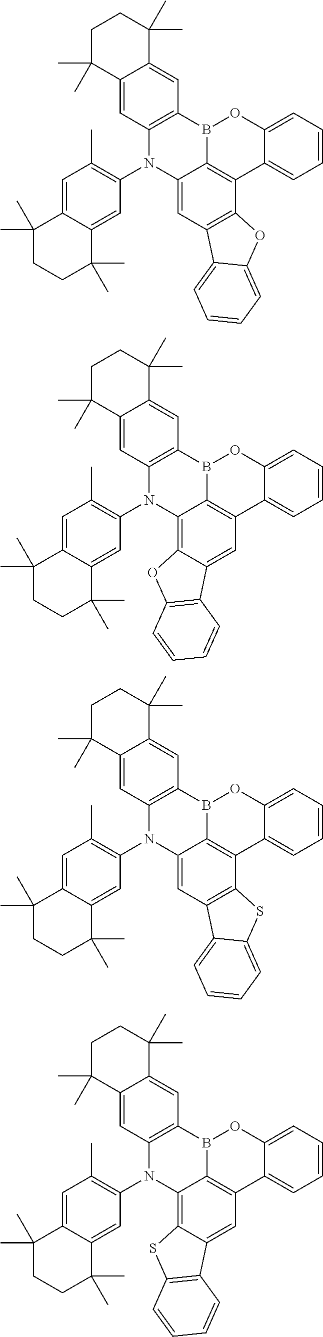

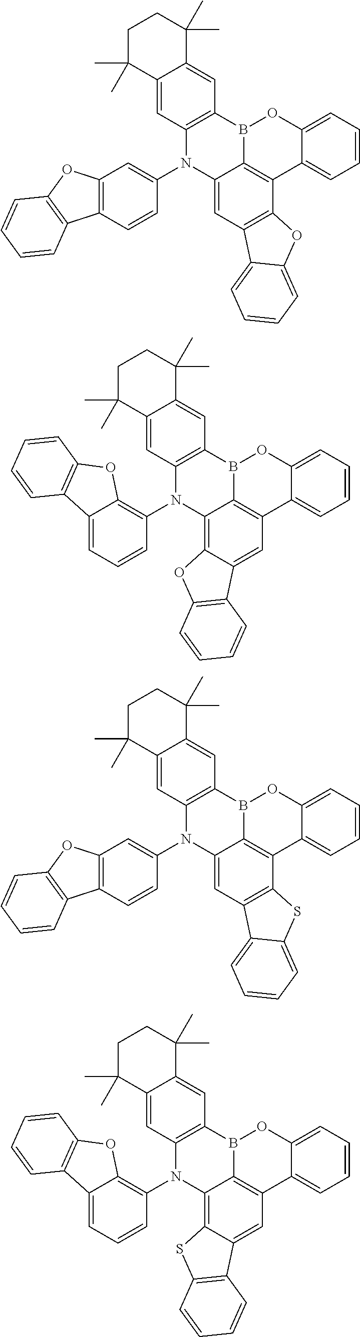

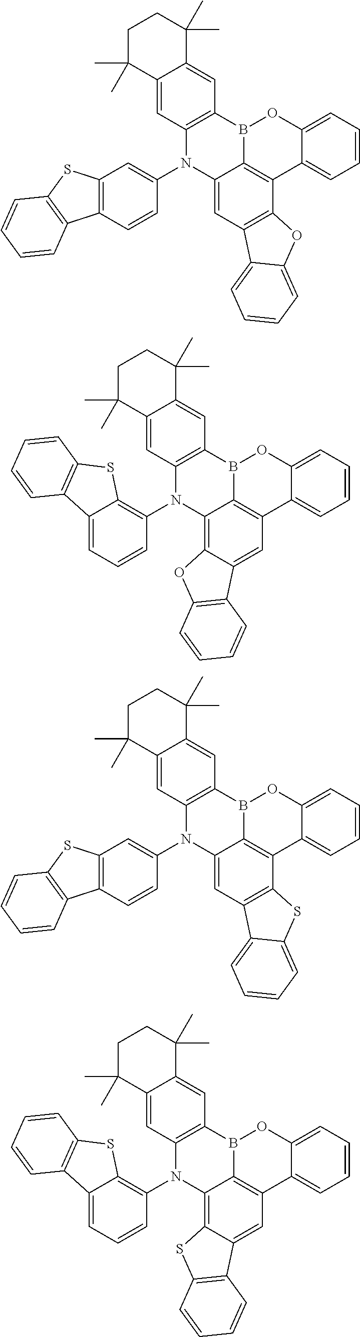

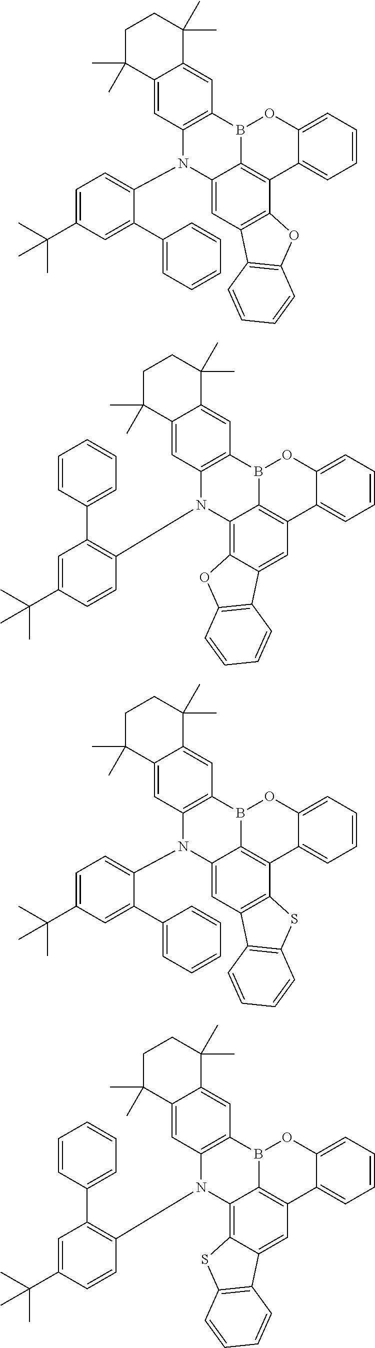

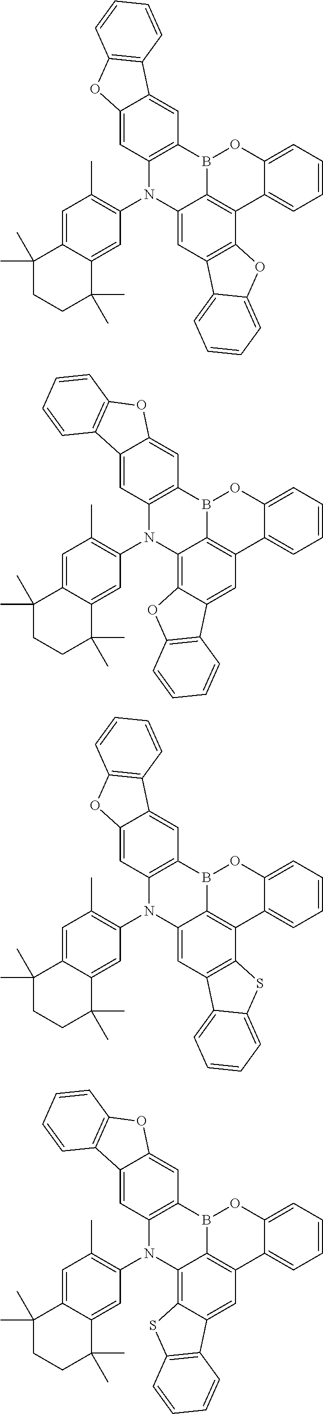

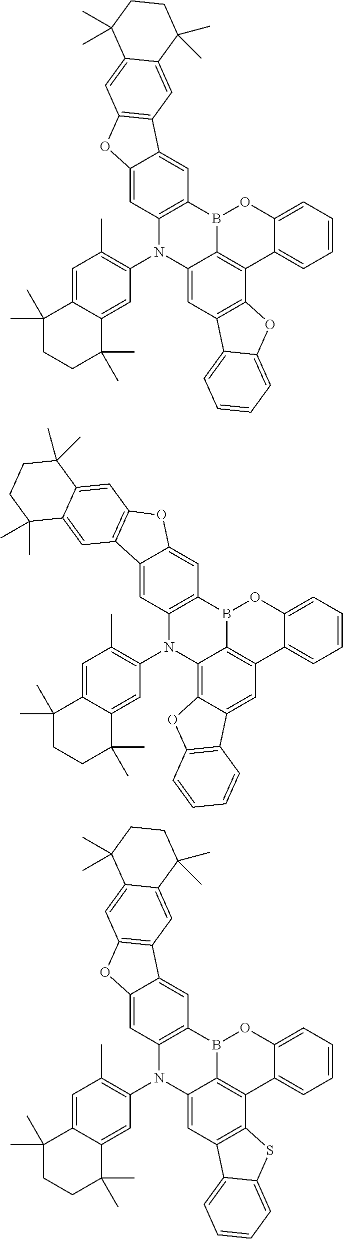

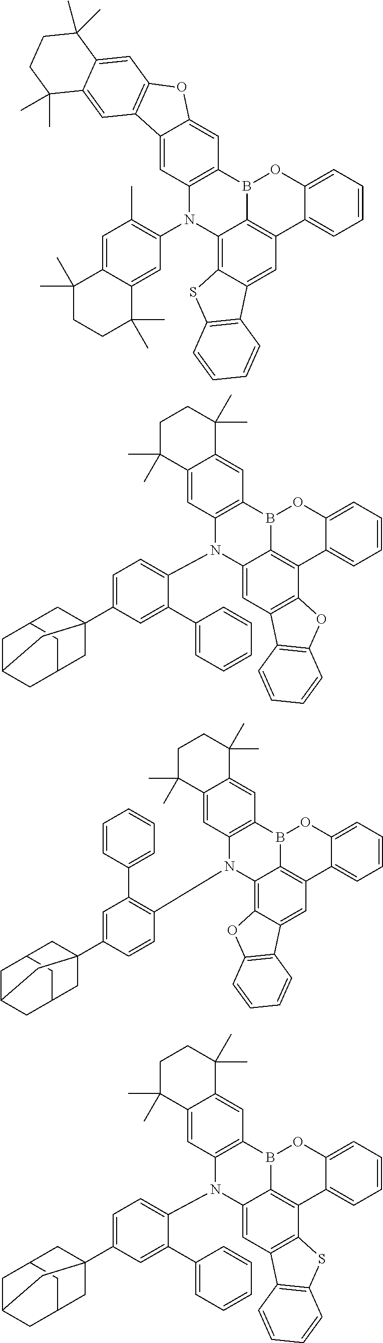

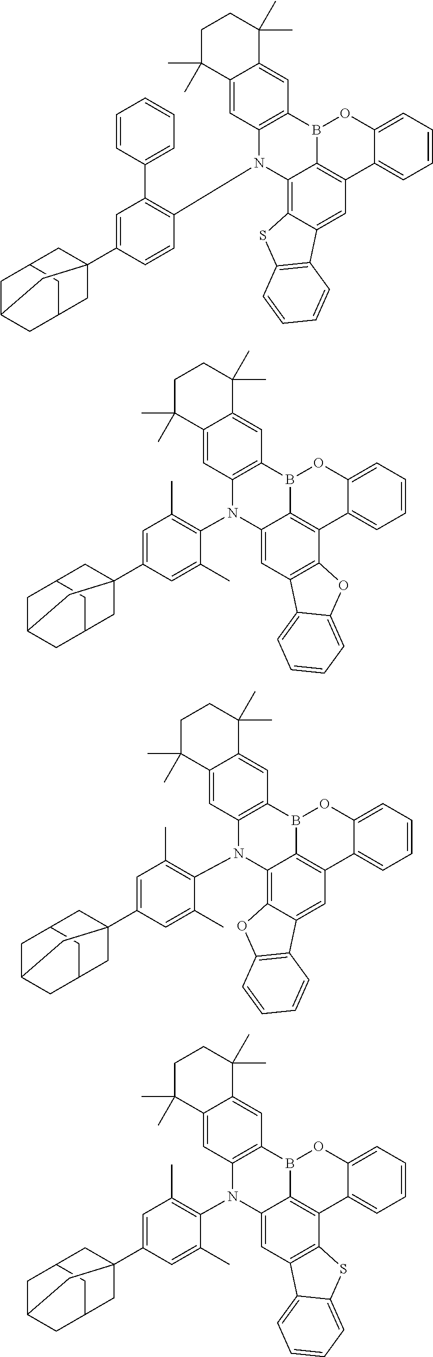

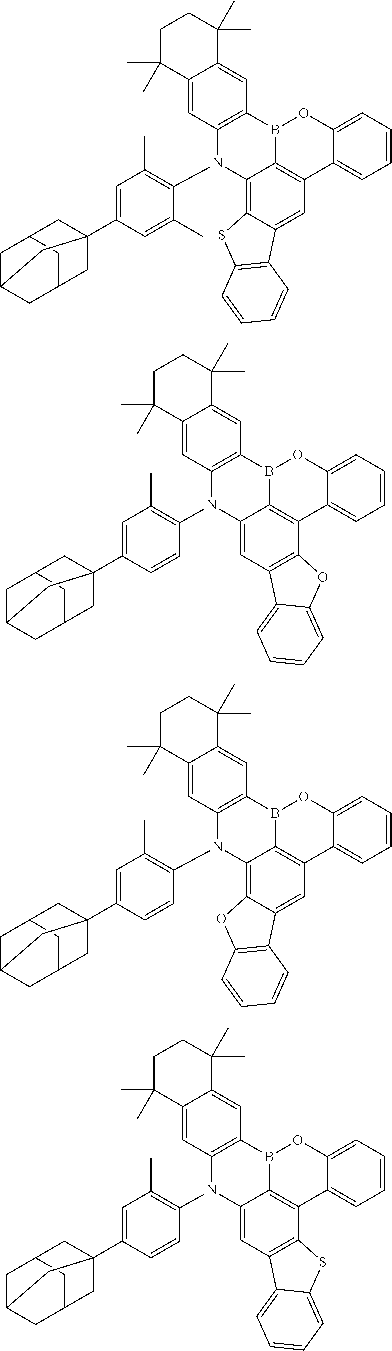

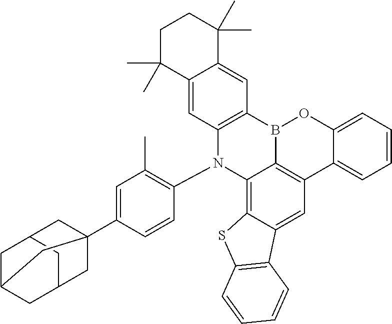 [SMILES: Cc1cc(C23CC4CC(CC(C4)C2)C3)ccc1N1c2cc3c(cc2B2Oc4ccccc4-c4cc5c(sc6ccccc65)c1c42)C(C)(C)CCC3(C)C]

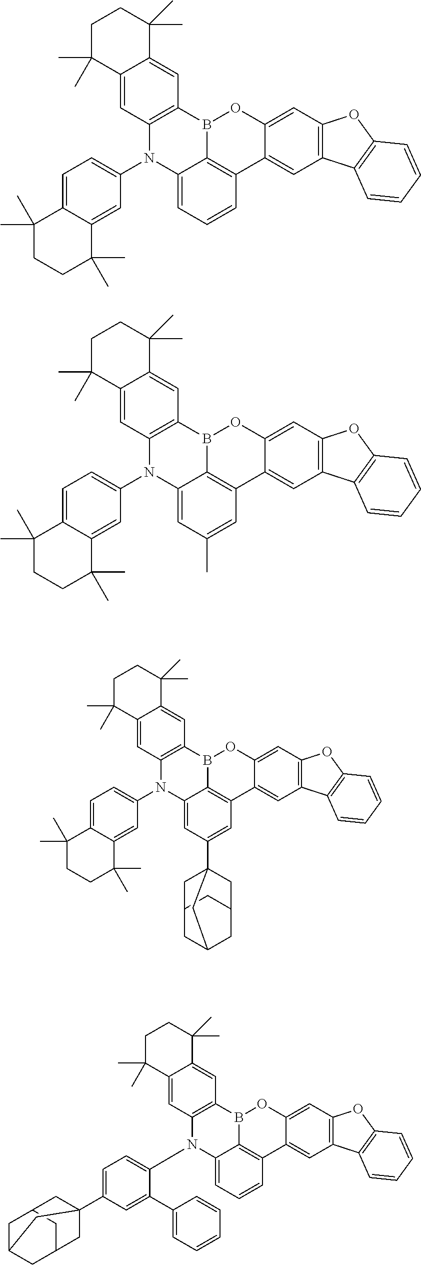

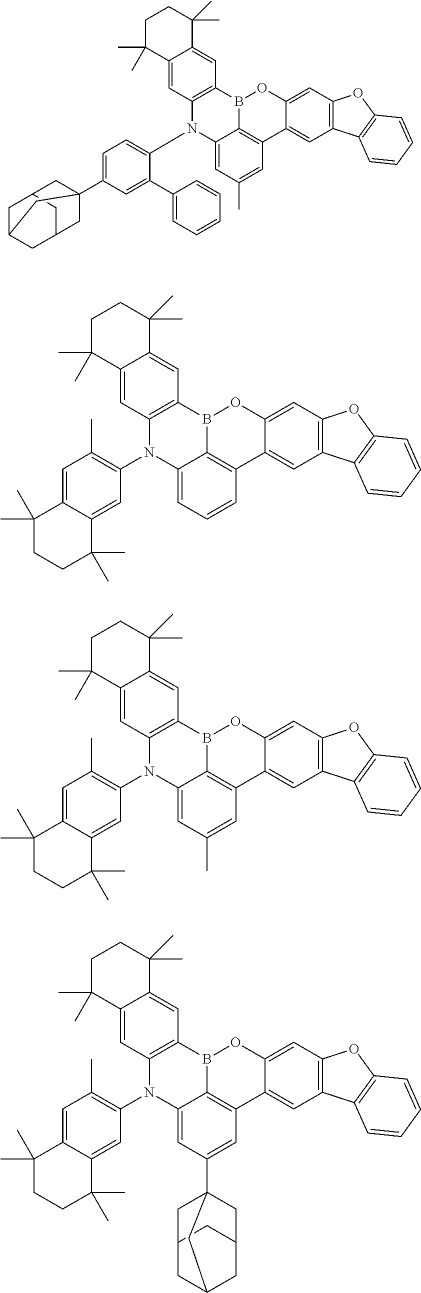

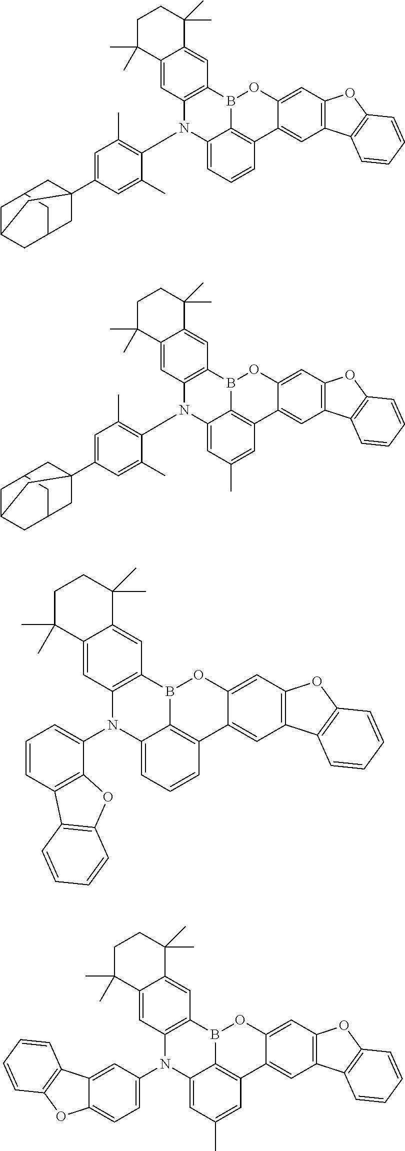 [SMILES: Cc1cc(C23CC4CC(CC(C4)C2)C3)cc(C)c1N1c2cc3c(cc2B2Oc4cc5oc6ccccc6c5cc4-c4cccc1c42)C(C)(C)CCC3(C)C ; Cc1cc2c3c(c1)N(c1c(C)cc(C45CC6CC(CC(C6)C4)C5)cc1C)c1cc4c(cc1B3Oc1cc3oc5ccccc5c3cc1-2)C(C)(C)CCC4(C)C ; CC1(C)CCC(C)(C)c2cc3c(cc21)B1Oc2cc4oc5ccccc5c4cc2-c2cccc(c21)N3c1cccc2c1oc1ccccc12 ; Cc1cc2c3c(c1)N(c1ccc4oc5ccccc5c4c1)c1cc4c(cc1B3Oc1cc3oc5ccccc5c3cc1-2)C(C)(C)CCC4(C)C]

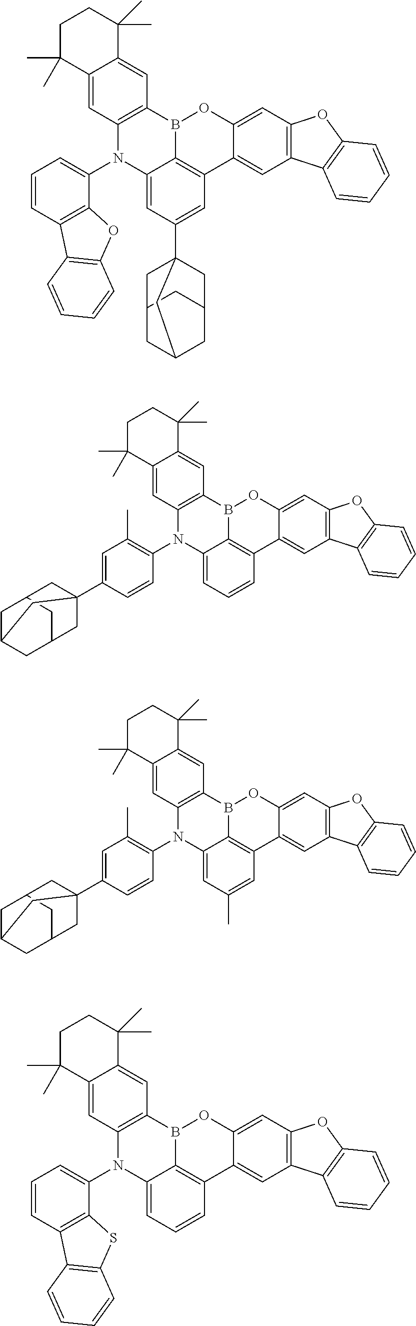 [SMILES: CC1(C)CCC(C)(C)c2cc3c(cc21)B1Oc2cc4oc5ccccc5c4cc2-c2cc(C45CC6CC(CC(C6)C4)C5)cc(c21)N3c1cccc2c1oc1ccccc12 ; Cc1cc(C23CC4CC(CC(C4)C2)C3)ccc1N1c2cc3c(cc2B2Oc4cc5oc6ccccc6c5cc4-c4cccc1c42)C(C)(C)CCC3(C)C ; Cc1cc2c3c(c1)N(c1ccc(C45CC6CC(CC(C6)C4)C5)cc1C)c1cc4c(cc1B3Oc1cc3oc5ccccc5c3cc1-2)C(C)(C)CCC4(C)C ; CC1(C)CCC(C)(C)c2cc3c(cc21)B1Oc2cc4oc5ccccc5c4cc2-c2cccc(c21)N3c1cccc2c1sc1ccccc12]

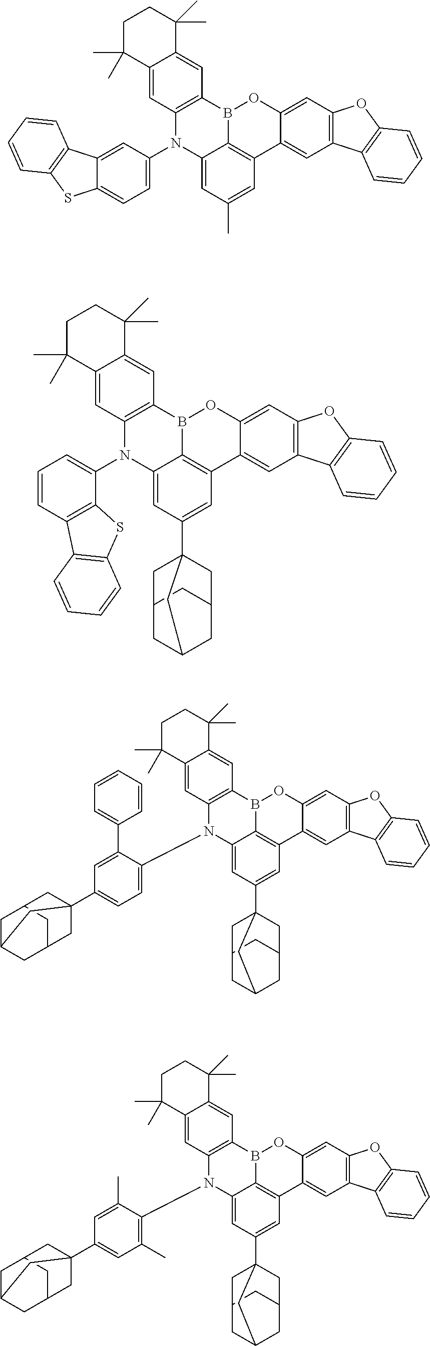 [SMILES: Cc1cc2c3c(c1)N(c1ccc4sc5ccccc5c4c1)c1cc4c(cc1B3Oc1cc3oc5ccccc5c3cc1-2)C(C)(C)CCC4(C)C ; CC1(C)CCC(C)(C)c2cc3c(cc21)B1Oc2cc4oc5ccccc5c4cc2-c2cc(C45CC6CC(CC(C6)C4)C5)cc(c21)N3c1cccc2c1sc1ccccc12 ; CC1(C)CCC(C)(C)c2cc3c(cc21)B1Oc2cc4oc5ccccc5c4cc2-c2cc(C45CC6CC(CC(C6)C4)C5)cc(c21)N3c1ccc(C23CC4CC(CC(C4)C2)C3)cc1-c1ccccc1 ; Cc1cc(C23CC4CC(CC(C4)C2)C3)cc(C)c1N1c2cc3c(cc2B2Oc4cc5oc6ccccc6c5cc4-c4cc(C56CC7CC(CC(C7)C5)C6)cc1c42)C(C)(C)CCC3(C)C]

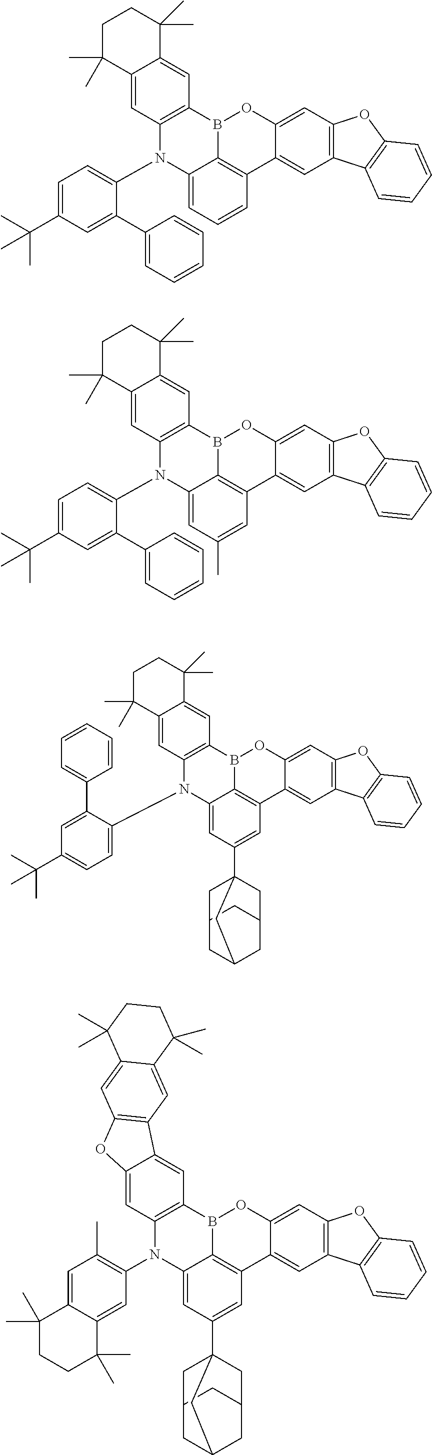

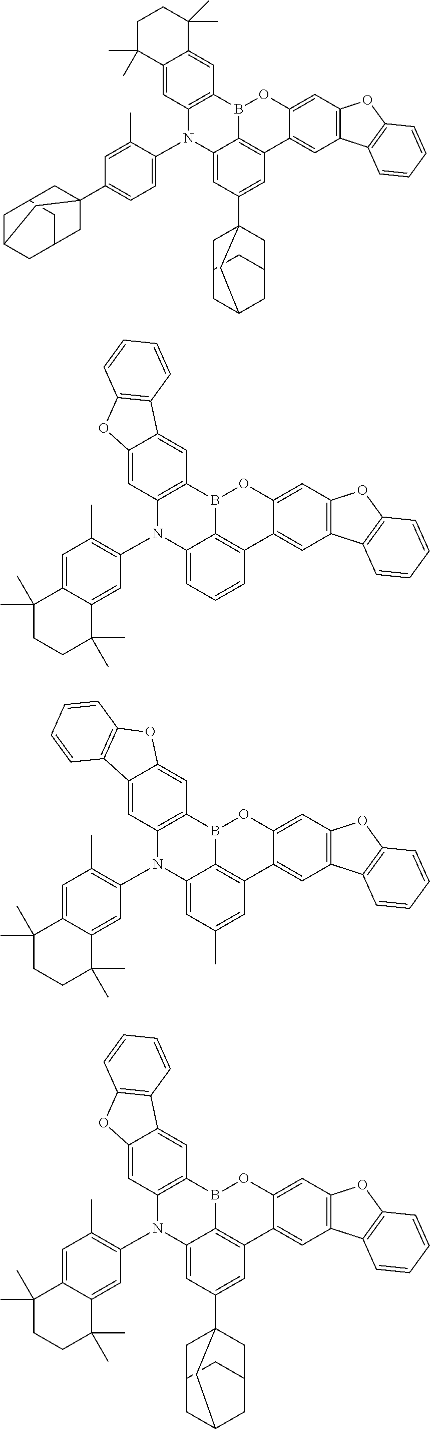

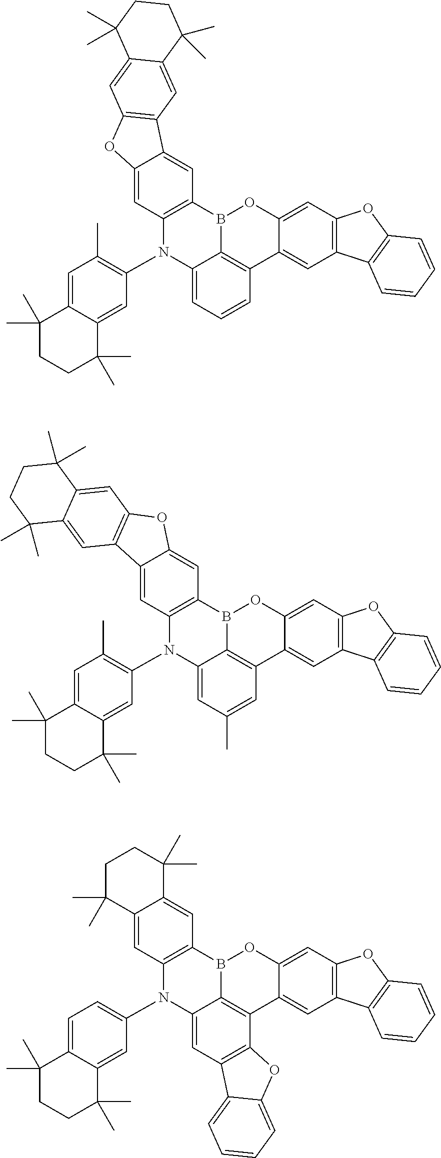 [SMILES: Cc1cc2c(cc1N1c3cc4oc5cc6c(cc5c4cc3B3Oc4cc5oc7ccccc7c5cc4-c4cccc1c43)C(C)(C)CCC6(C)C)C(C)(C)CCC2(C)C ; Cc1cc2c3c(c1)N(c1cc4c(cc1C)C(C)(C)CCC4(C)C)c1cc4c(cc1B3Oc1cc3oc5ccccc5c3cc1-2)oc1cc2c(cc14)C(C)(C)CCC2(C)C ; CC1(C)CCC(C)(C)c2cc(N3c4cc5c(cc4B4Oc6cc7oc8ccccc8c7cc6-c6c4c3cc3c6oc4ccccc43)C(C)(C)CCC5(C)C)ccc21]

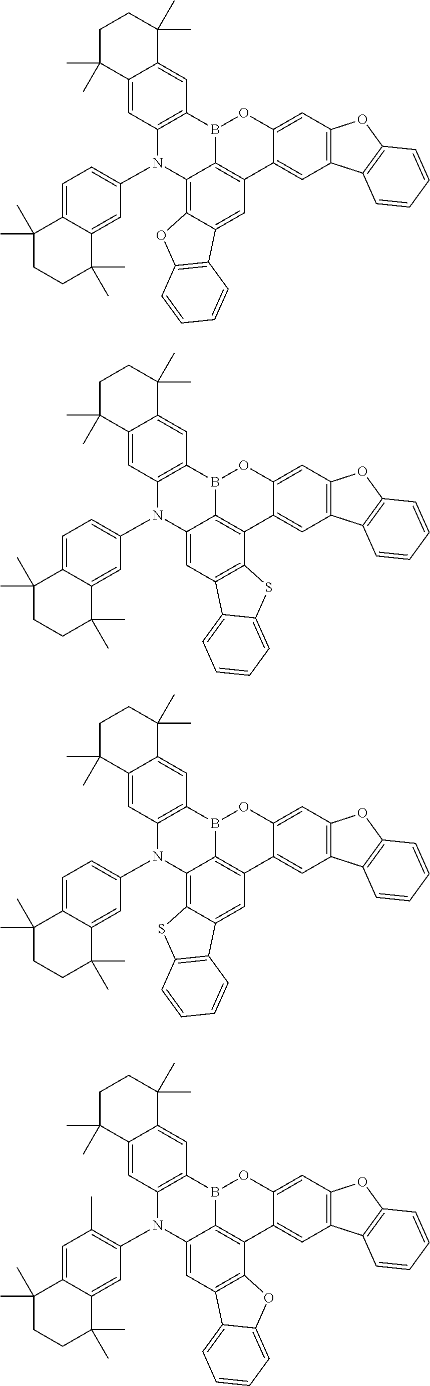

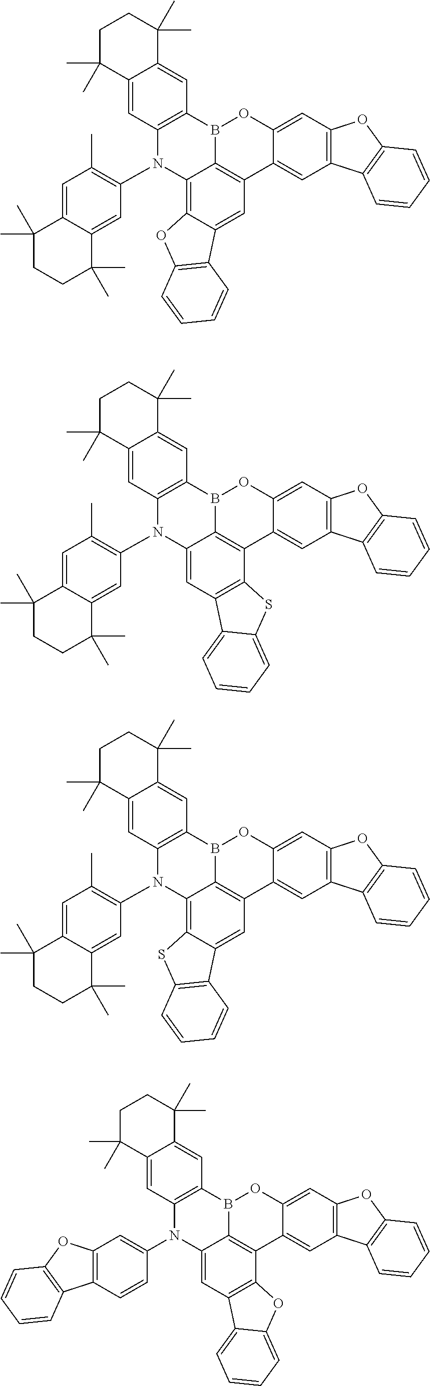

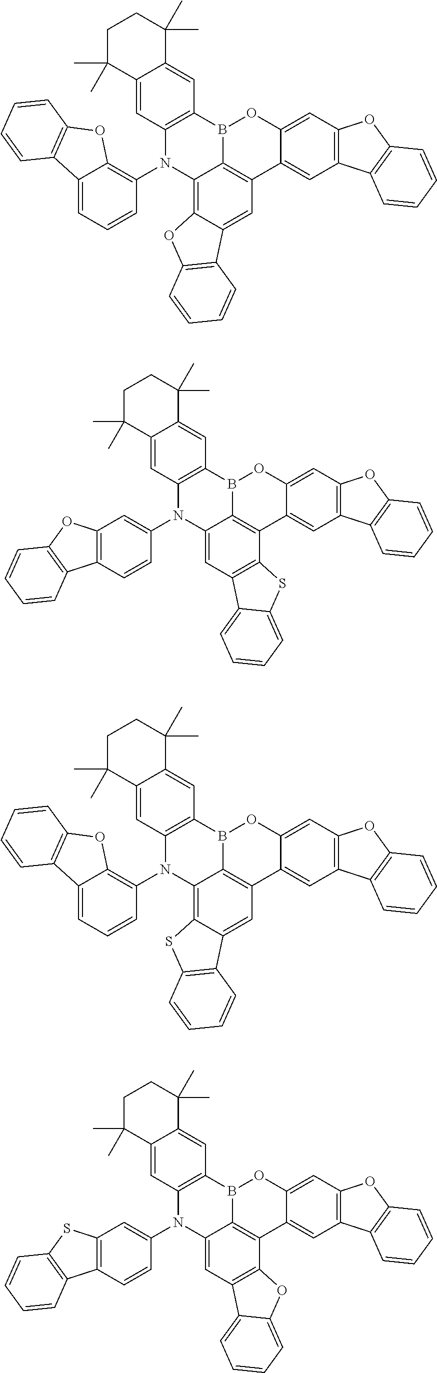

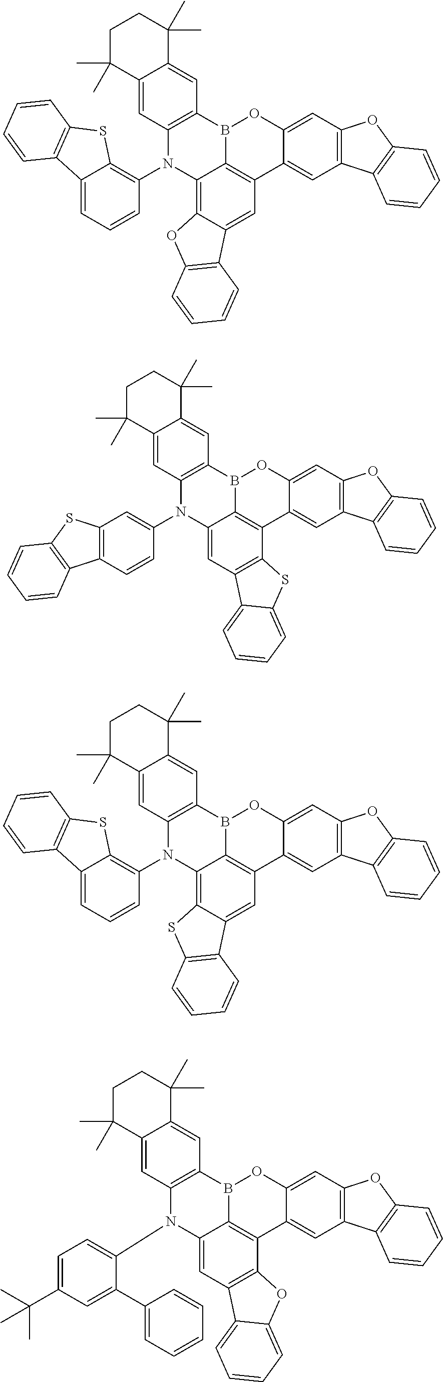

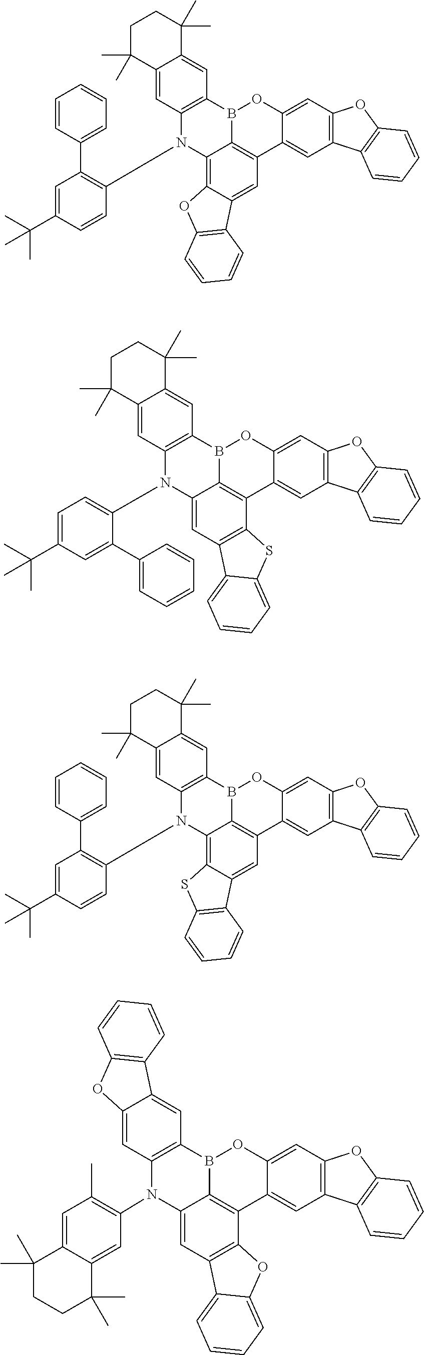 [SMILES: CC(C)(C)c1ccc(N2c3cc4c(cc3B3Oc5cc6oc7ccccc7c6cc5-c5cc6c(oc7ccccc76)c2c53)C(C)(C)CCC4(C)C)c(-c2ccccc2)c1 ; CC(C)(C)c1ccc(N2c3cc4c(cc3B3Oc5cc6oc7ccccc7c6cc5-c5c3c2cc2c5sc3ccccc32)C(C)(C)CCC4(C)C)c(-c2ccccc2)c1 ; CC(C)(C)c1ccc(N2c3cc4c(cc3B3Oc5cc6oc7ccccc7c6cc5-c5cc6c(sc7ccccc76)c2c53)C(C)(C)CCC4(C)C)c(-c2ccccc2)c1 ; Cc1cc2c(cc1N1c3cc4oc5ccccc5c4cc3B3Oc4cc5oc6ccccc6c5cc4-c4c3c1cc1c4oc3ccccc31)C(C)(C)CCC2(C)C]

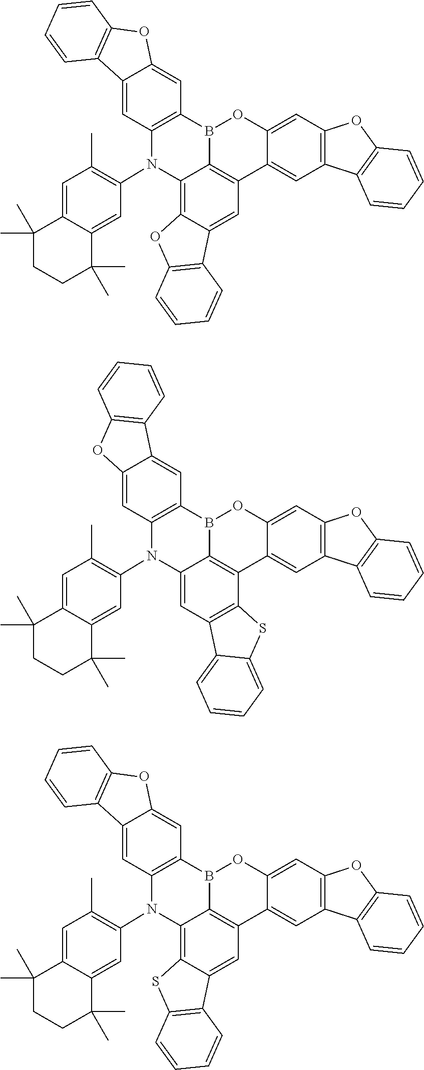 [SMILES: Cc1cc2c(cc1N1c3cc4c(cc3B3Oc5cc6oc7ccccc7c6cc5-c5cc6c(oc7ccccc76)c1c53)oc1ccccc14)C(C)(C)CCC2(C)C ; Cc1cc2c(cc1N1c3cc4oc5ccccc5c4cc3B3Oc4cc5oc6ccccc6c5cc4-c4c3c1cc1c4sc3ccccc31)C(C)(C)CCC2(C)C ; Cc1cc2c(cc1N1c3cc4c(cc3B3Oc5cc6oc7ccccc7c6cc5-c5cc6c(sc7ccccc76)c1c53)oc1ccccc14)C(C)(C)CCC2(C)C]

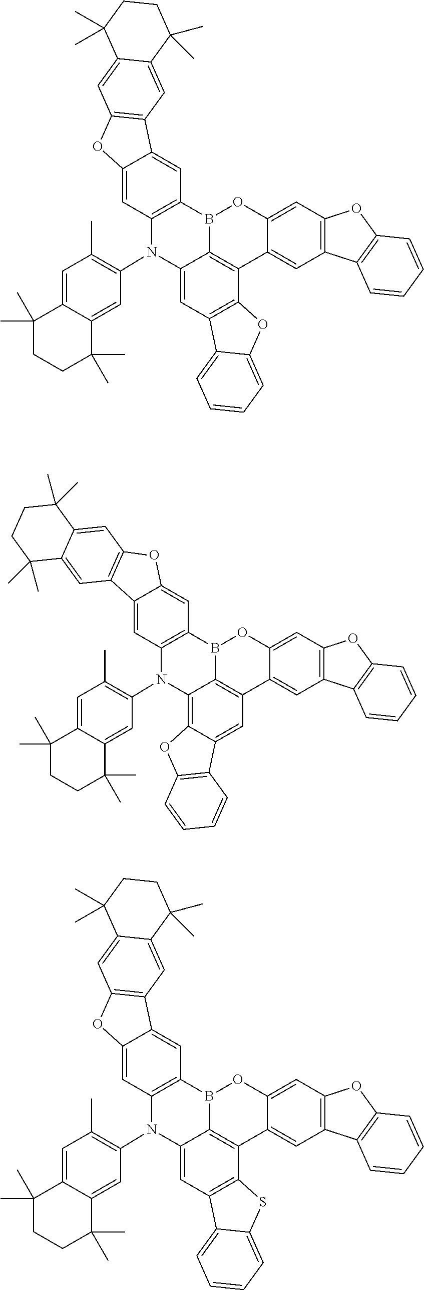 [SMILES: Cc1cc2c(cc1N1c3cc4oc5cc6c(cc5c4cc3B3Oc4cc5oc7ccccc7c5cc4-c4c3c1cc1c4oc3ccccc31)C(C)(C)CCC6(C)C)C(C)(C)CCC2(C)C ; Cc1cc2c(cc1N1c3cc4c(cc3B3Oc5cc6oc7ccccc7c6cc5-c5cc6c(oc7ccccc76)c1c53)oc1cc3c(cc14)C(C)(C)CCC3(C)C)C(C)(C)CCC2(C)C ; Cc1cc2c(cc1N1c3cc4oc5cc6c(cc5c4cc3B3Oc4cc5oc7ccccc7c5cc4-c4c3c1cc1c4sc3ccccc31)C(C)(C)CCC6(C)C)C(C)(C)CCC2(C)C]

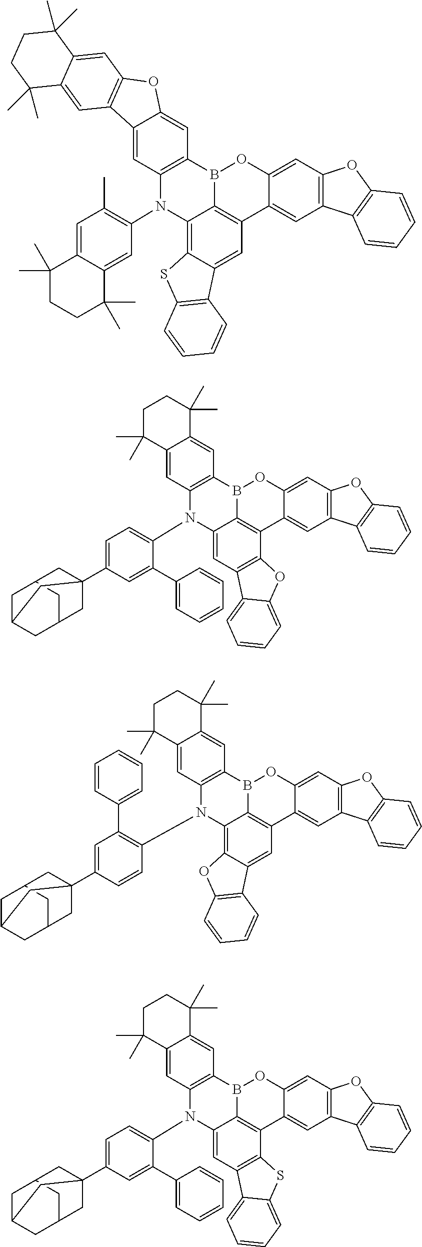

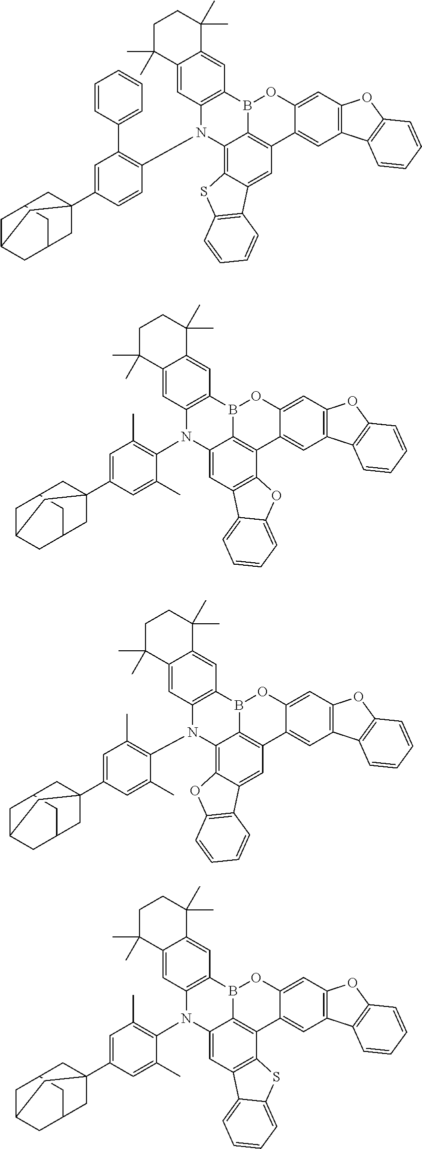

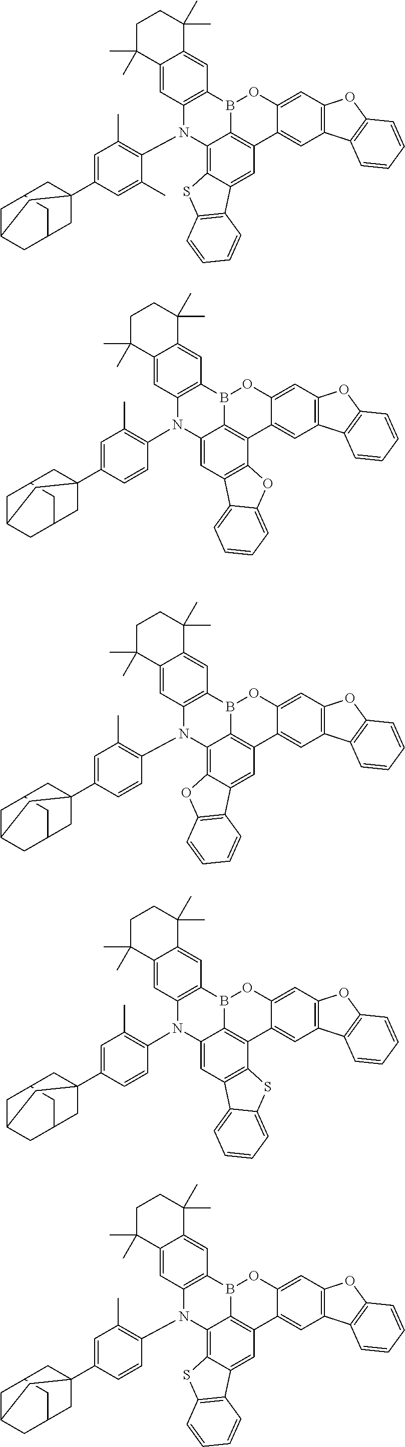

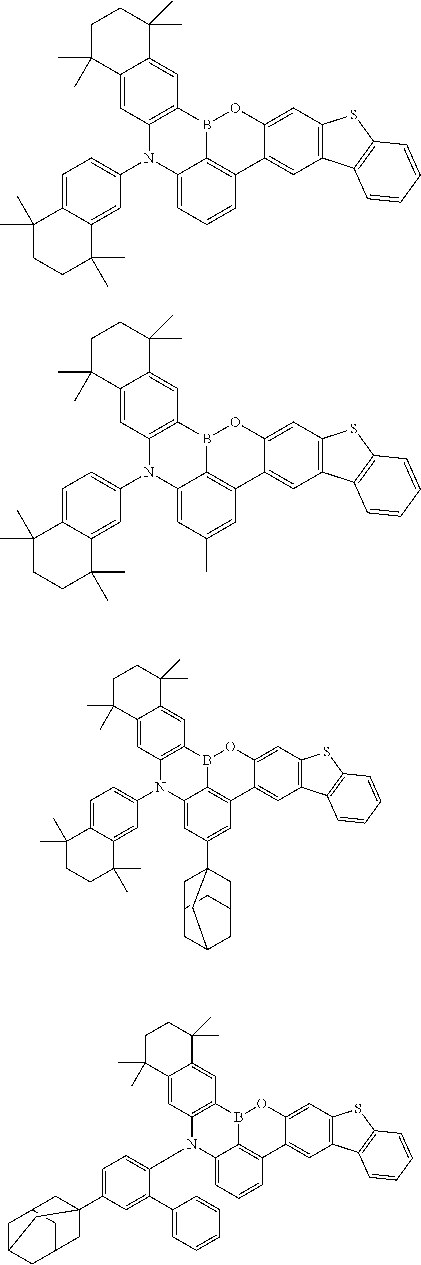

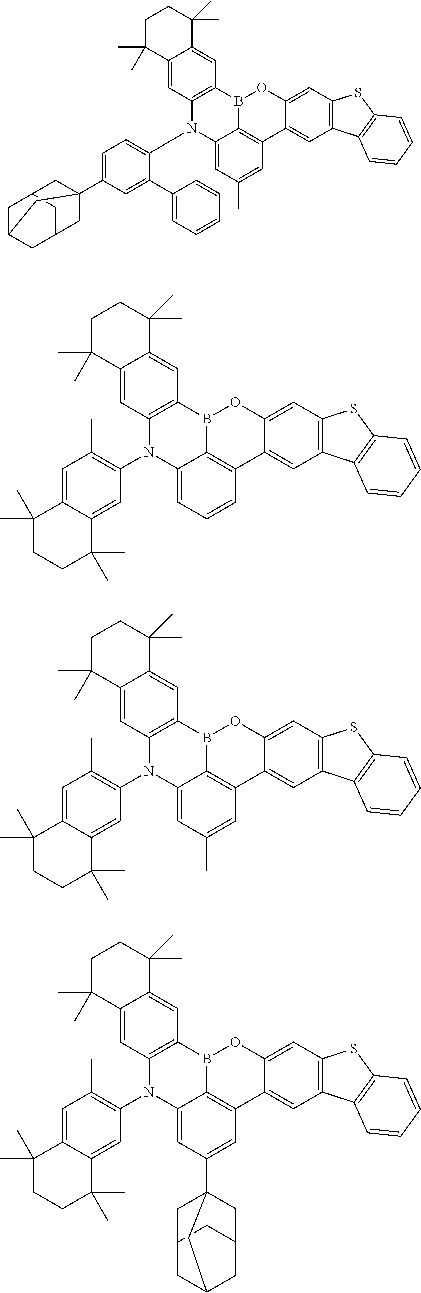

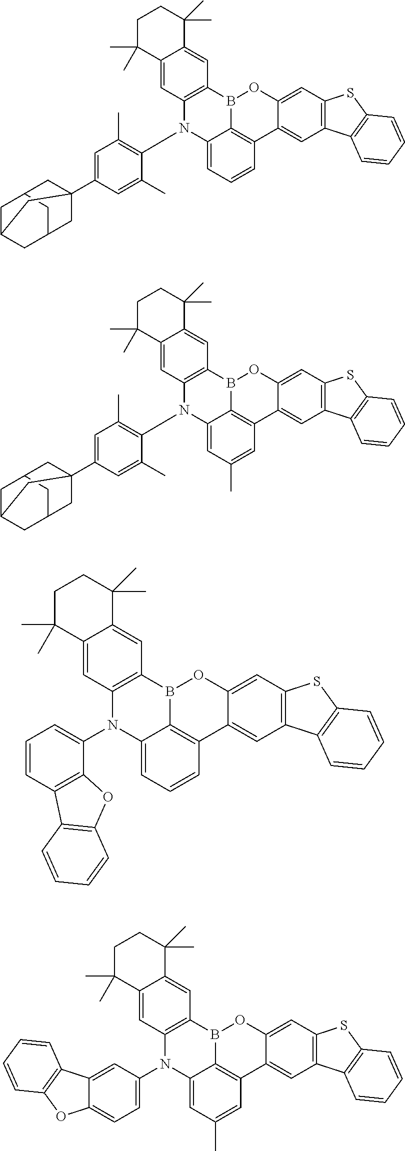 [SMILES: Cc1cc(C23CC4CC(CC(C4)C2)C3)cc(C)c1N1c2cc3c(cc2B2Oc4cc5sc6ccccc6c5cc4-c4cccc1c42)C(C)(C)CCC3(C)C ; Cc1cc2c3c(c1)N(c1c(C)cc(C45CC6CC(CC(C6)C4)C5)cc1C)c1cc4c(cc1B3Oc1cc3sc5ccccc5c3cc1-2)C(C)(C)CCC4(C)C ; CC1(C)CCC(C)(C)c2cc3c(cc21)B1Oc2cc4sc5ccccc5c4cc2-c2cccc(c21)N3c1cccc2c1oc1ccccc12 ; Cc1cc2c3c(c1)N(c1ccc4oc5ccccc5c4c1)c1cc4c(cc1B3Oc1cc3sc5ccccc5c3cc1-2)C(C)(C)CCC4(C)C]

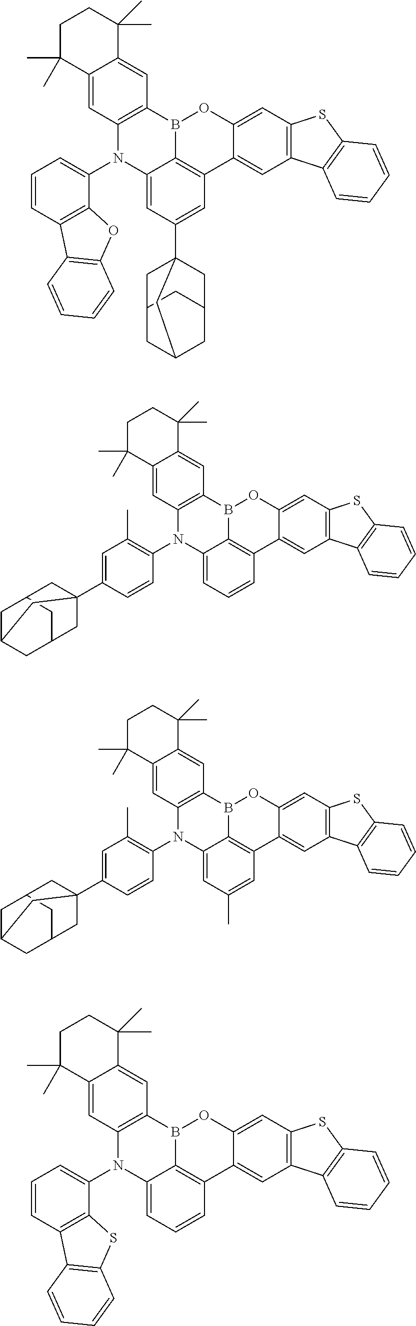 [SMILES: CC1(C)CCC(C)(C)c2cc3c(cc21)B1Oc2cc4sc5ccccc5c4cc2-c2cc(C45CC6CC(CC(C6)C4)C5)cc(c21)N3c1cccc2c1oc1ccccc12 ; Cc1cc(C23CC4CC(CC(C4)C2)C3)ccc1N1c2cc3c(cc2B2Oc4cc5sc6ccccc6c5cc4-c4cccc1c42)C(C)(C)CCC3(C)C ; Cc1cc2c3c(c1)N(c1ccc(C45CC6CC(CC(C6)C4)C5)cc1C)c1cc4c(cc1B3Oc1cc3sc5ccccc5c3cc1-2)C(C)(C)CCC4(C)C ; CC1(C)CCC(C)(C)c2cc3c(cc21)B1Oc2cc4sc5ccccc5c4cc2-c2cccc(c21)N3c1cccc2c1sc1ccccc12]

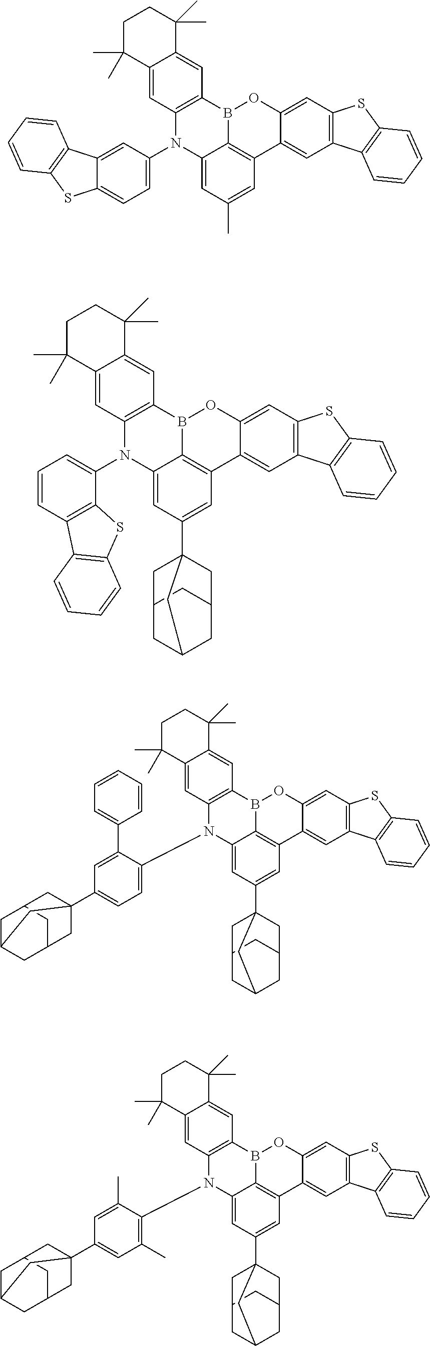 [SMILES: Cc1cc2c3c(c1)N(c1ccc4sc5ccccc5c4c1)c1cc4c(cc1B3Oc1cc3sc5ccccc5c3cc1-2)C(C)(C)CCC4(C)C ; CC1(C)CCC(C)(C)c2cc3c(cc21)B1Oc2cc4sc5ccccc5c4cc2-c2cc(C45CC6CC(CC(C6)C4)C5)cc(c21)N3c1cccc2c1sc1ccccc12 ; CC1(C)CCC(C)(C)c2cc3c(cc21)B1Oc2cc4sc5ccccc5c4cc2-c2cc(C45CC6CC(CC(C6)C4)C5)cc(c21)N3c1ccc(C23CC4CC(CC(C4)C2)C3)cc1-c1ccccc1 ; Cc1cc(C23CC4CC(CC(C4)C2)C3)cc(C)c1N1c2cc3c(cc2B2Oc4cc5sc6ccccc6c5cc4-c4cc(C56CC7CC(CC(C7)C5)C6)cc1c42)C(C)(C)CCC3(C)C]

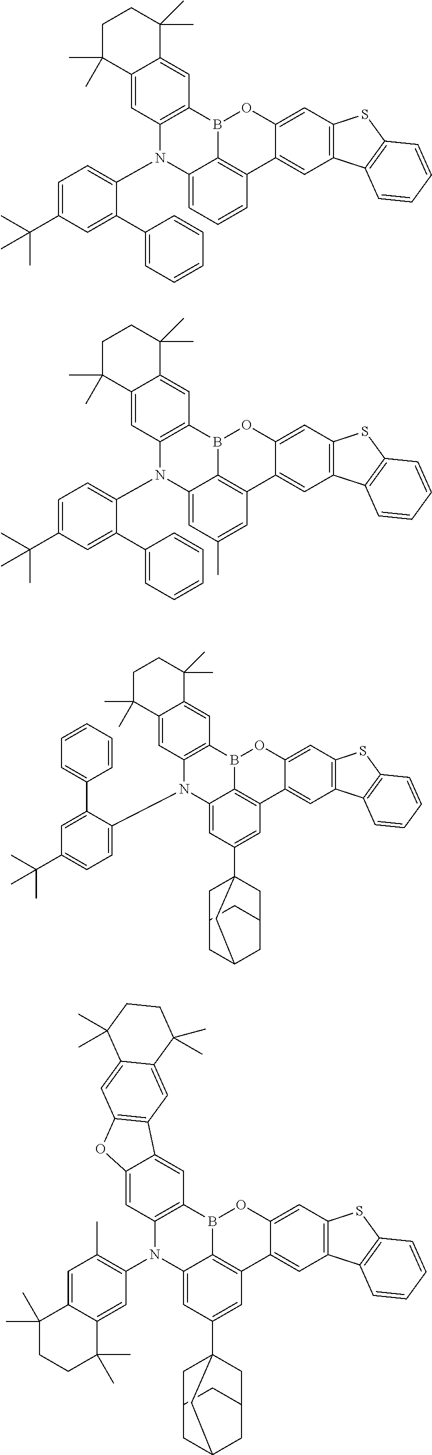

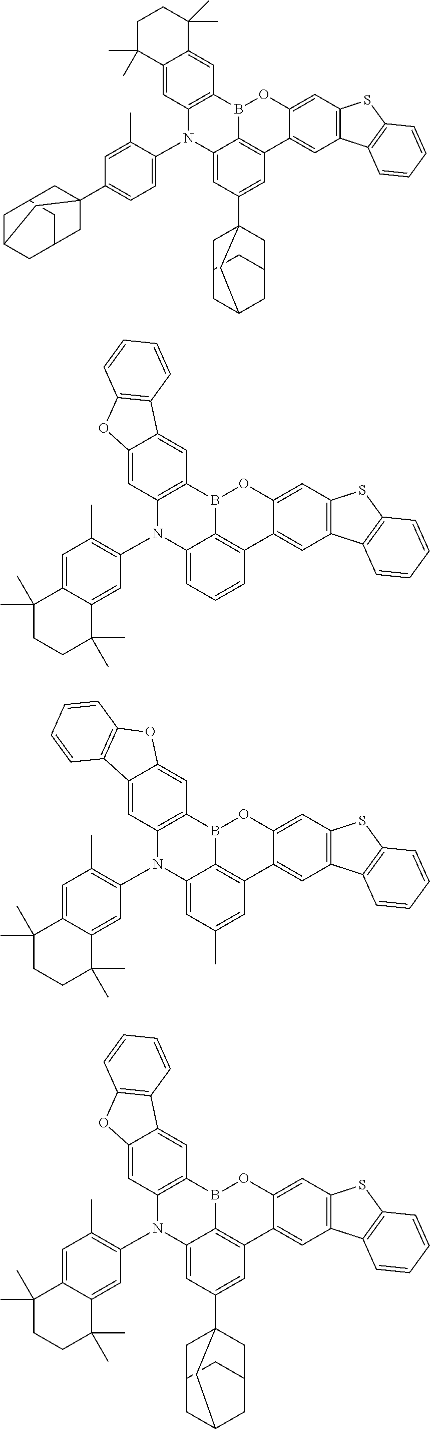

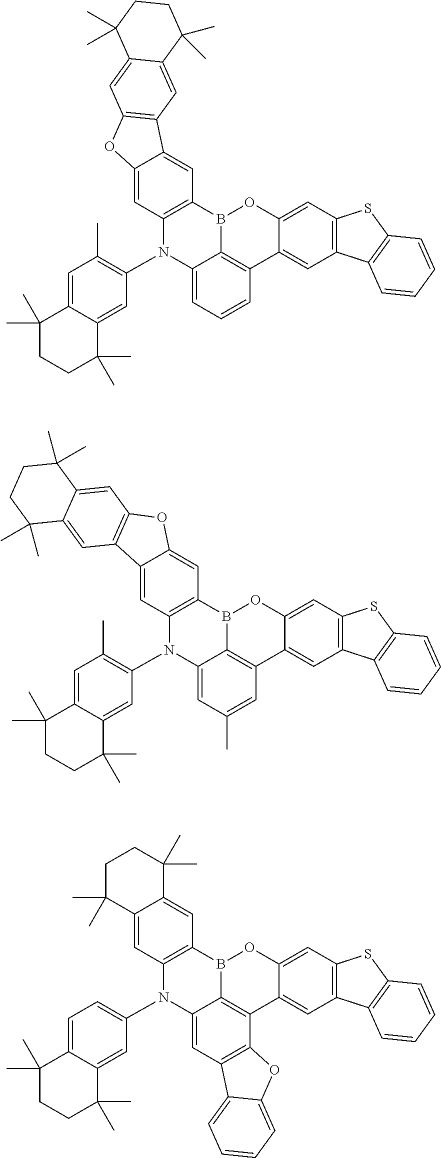 [SMILES: Cc1cc2c(cc1N1c3cc4oc5cc6c(cc5c4cc3B3Oc4cc5sc7ccccc7c5cc4-c4cccc1c43)C(C)(C)CCC6(C)C)C(C)(C)CCC2(C)C ; Cc1cc2c3c(c1)N(c1cc4c(cc1C)C(C)(C)CCC4(C)C)c1cc4c(cc1B3Oc1cc3sc5ccccc5c3cc1-2)oc1cc2c(cc14)C(C)(C)CCC2(C)C ; CC1(C)CCC(C)(C)c2cc(N3c4cc5c(cc4B4Oc6cc7sc8ccccc8c7cc6-c6c4c3cc3c6oc4ccccc43)C(C)(C)CCC5(C)C)ccc21]

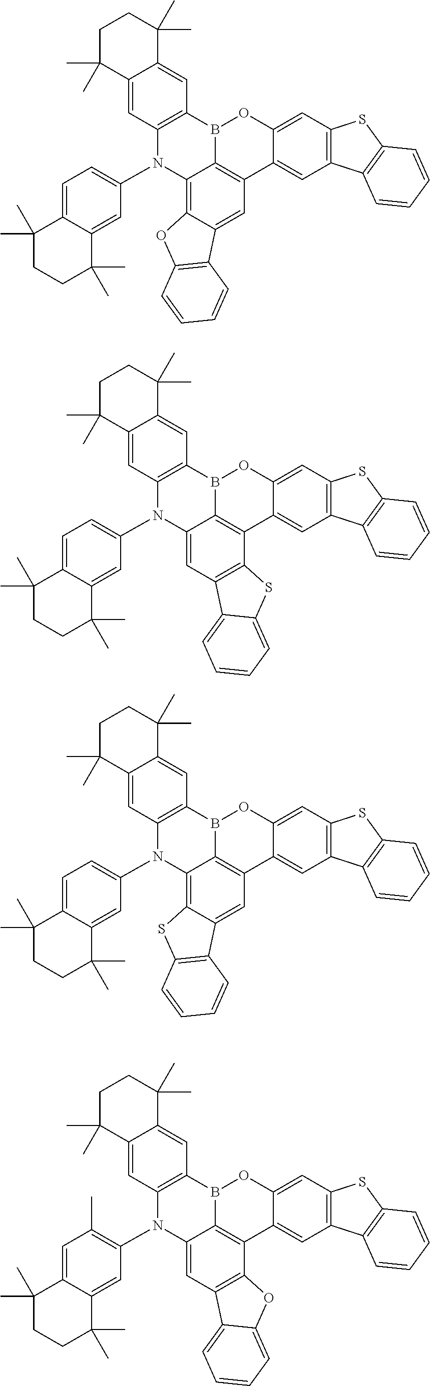

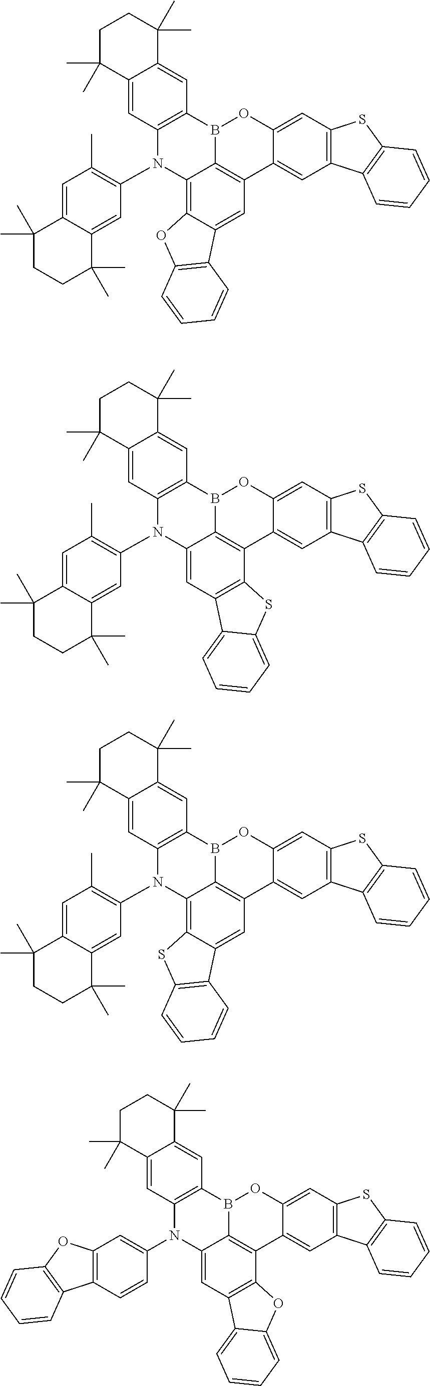

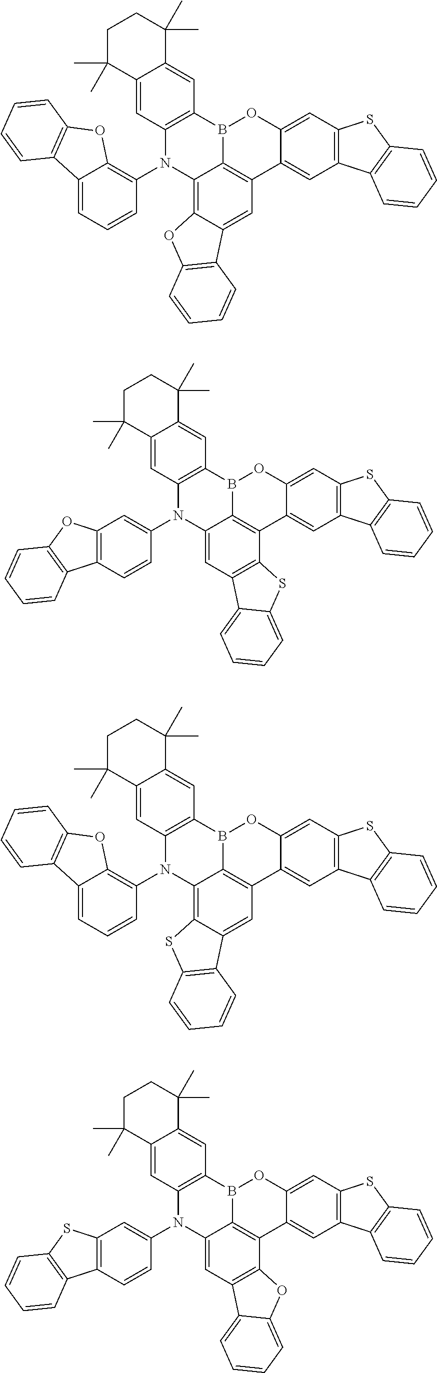

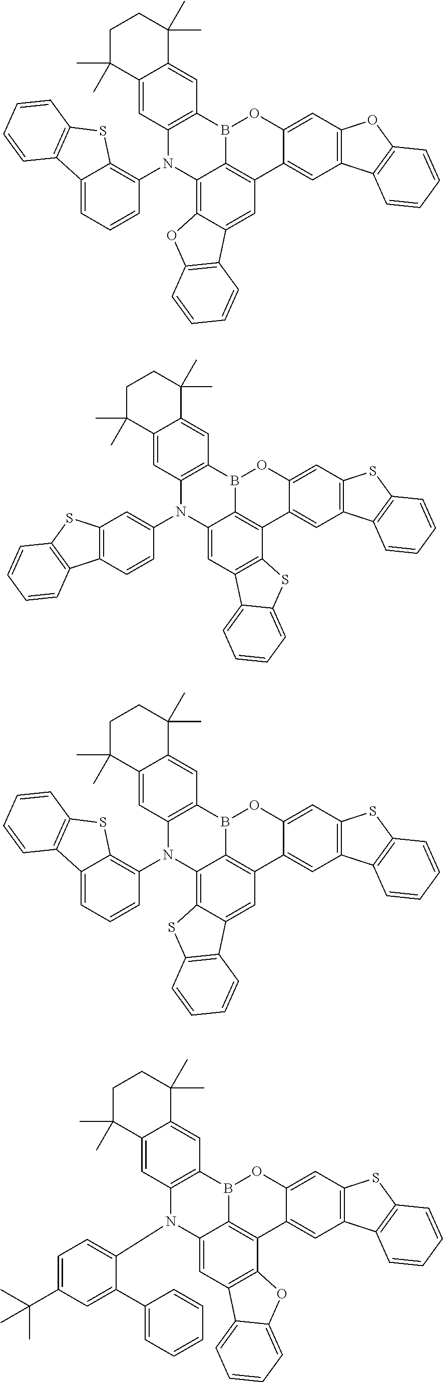

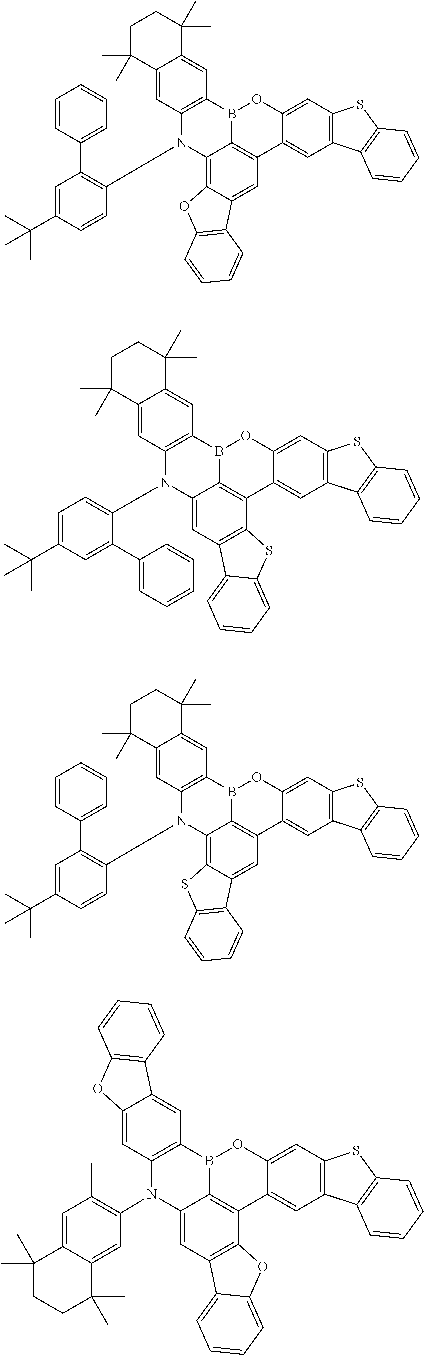 [SMILES: CC(C)(C)c1ccc(N2c3cc4c(cc3B3Oc5cc6sc7ccccc7c6cc5-c5cc6c(oc7ccccc76)c2c53)C(C)(C)CCC4(C)C)c(-c2ccccc2)c1 ; CC(C)(C)c1ccc(N2c3cc4c(cc3B3Oc5cc6sc7ccccc7c6cc5-c5c3c2cc2c5sc3ccccc32)C(C)(C)CCC4(C)C)c(-c2ccccc2)c1 ; CC(C)(C)c1ccc(N2c3cc4c(cc3B3Oc5cc6sc7ccccc7c6cc5-c5cc6c(sc7ccccc76)c2c53)C(C)(C)CCC4(C)C)c(-c2ccccc2)c1 ; Cc1cc2c(cc1N1c3cc4oc5ccccc5c4cc3B3Oc4cc5sc6ccccc6c5cc4-c4c3c1cc1c4oc3ccccc31)C(C)(C)CCC2(C)C]

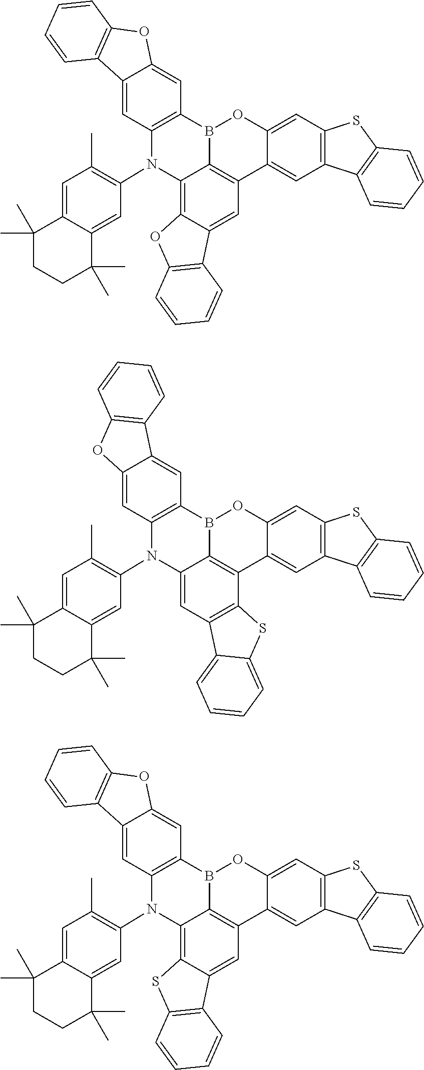 [SMILES: Cc1cc2c(cc1N1c3cc4c(cc3B3Oc5cc6sc7ccccc7c6cc5-c5cc6c(oc7ccccc76)c1c53)oc1ccccc14)C(C)(C)CCC2(C)C ; Cc1cc2c(cc1N1c3cc4oc5ccccc5c4cc3B3Oc4cc5sc6ccccc6c5cc4-c4c3c1cc1c4sc3ccccc31)C(C)(C)CCC2(C)C ; Cc1cc2c(cc1N1c3cc4c(cc3B3Oc5cc6sc7ccccc7c6cc5-c5cc6c(sc7ccccc76)c1c53)oc1ccccc14)C(C)(C)CCC2(C)C]

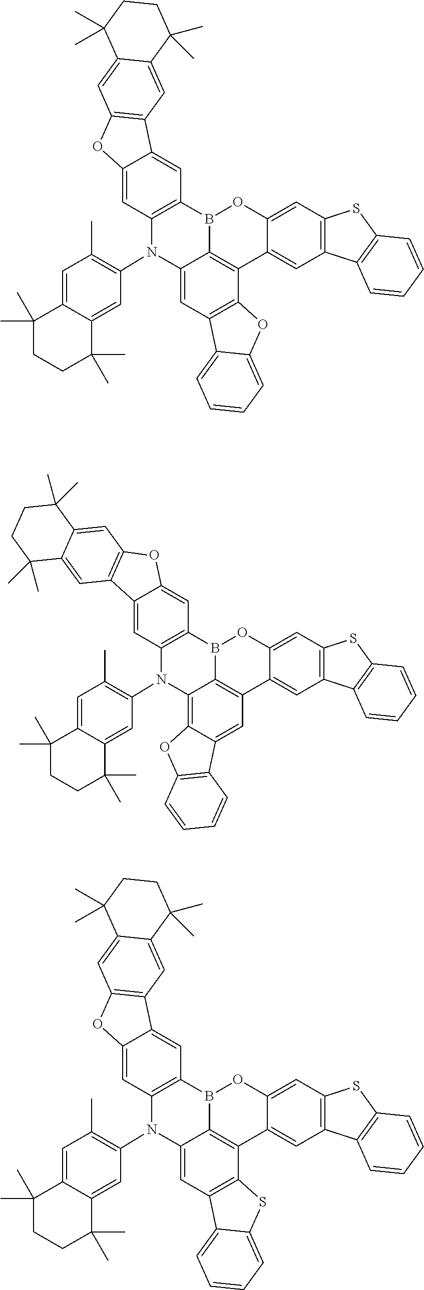 [SMILES: Cc1cc2c(cc1N1c3cc4oc5cc6c(cc5c4cc3B3Oc4cc5sc7ccccc7c5cc4-c4c3c1cc1c4oc3ccccc31)C(C)(C)CCC6(C)C)C(C)(C)CCC2(C)C ; Cc1cc2c(cc1N1c3cc4c(cc3B3Oc5cc6sc7ccccc7c6cc5-c5cc6c(oc7ccccc76)c1c53)oc1cc3c(cc14)C(C)(C)CCC3(C)C)C(C)(C)CCC2(C)C ; Cc1cc2c(cc1N1c3cc4oc5cc6c(cc5c4cc3B3Oc4cc5sc7ccccc7c5cc4-c4c3c1cc1c4sc3ccccc31)C(C)(C)CCC6(C)C)C(C)(C)CCC2(C)C]

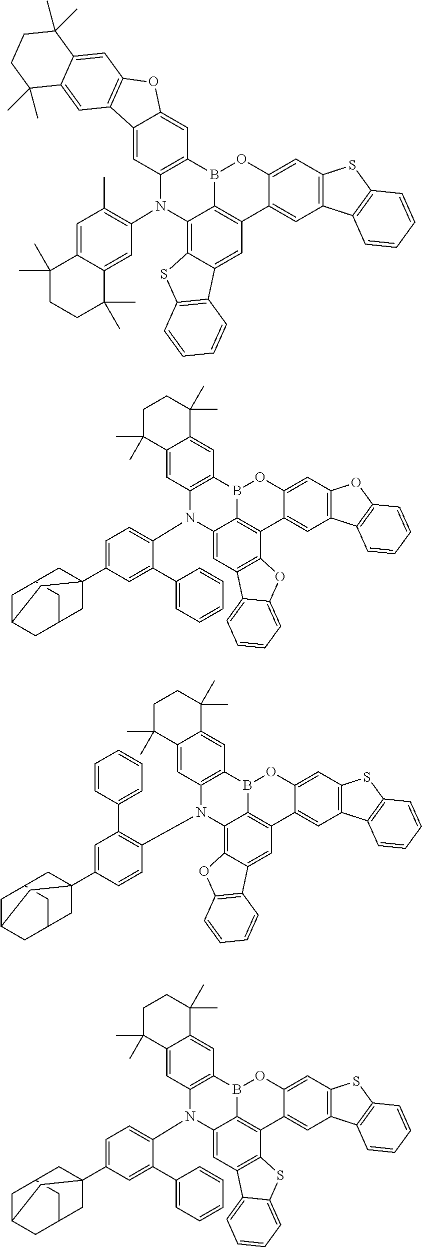

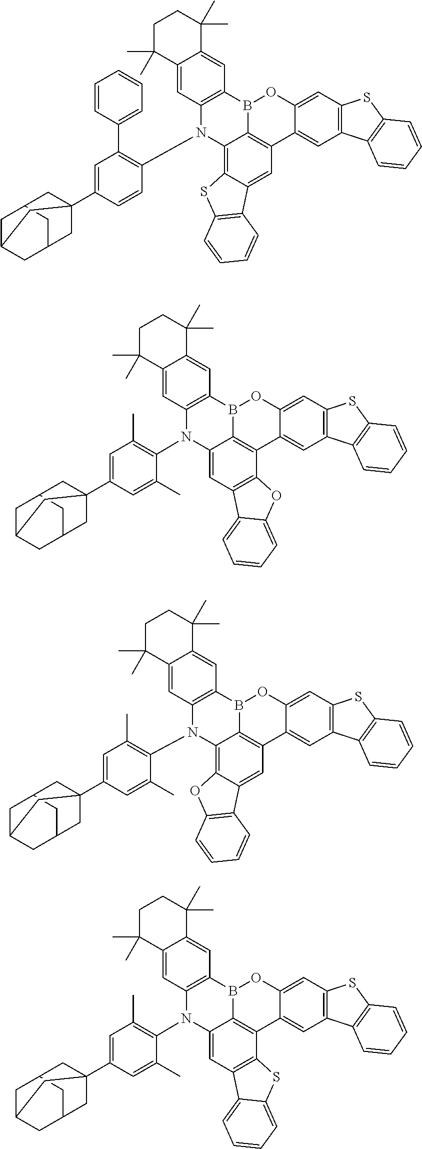

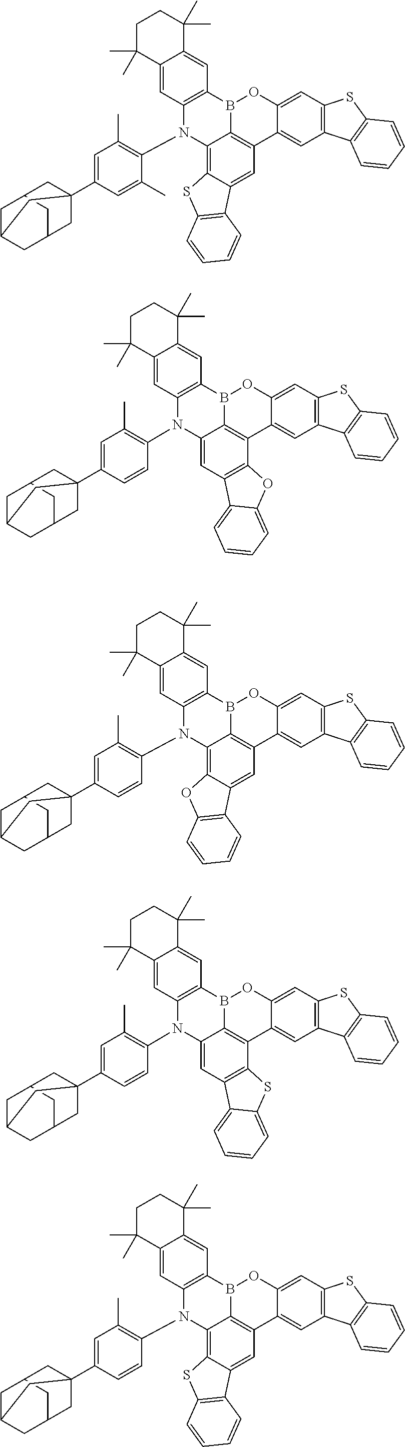

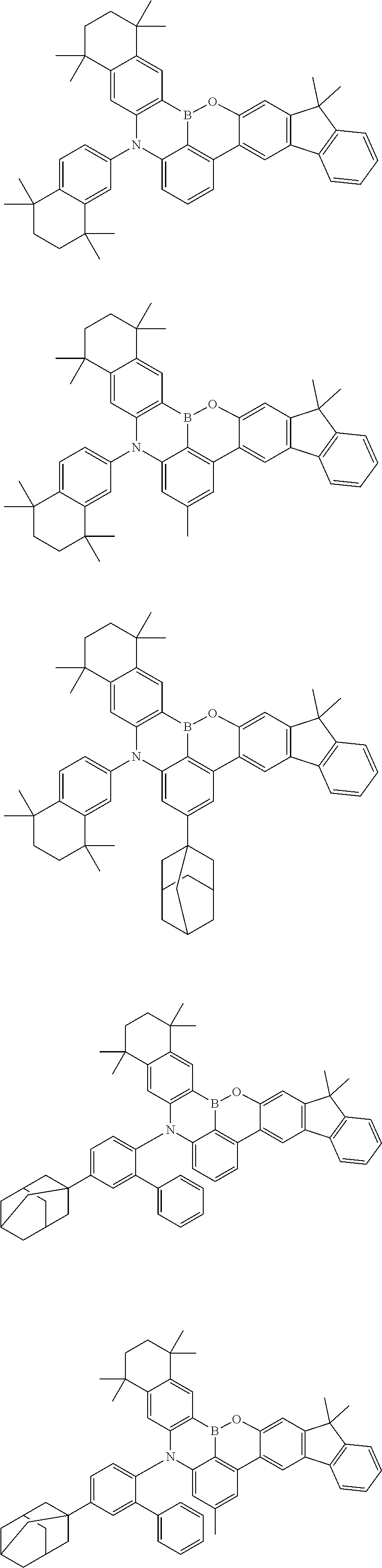

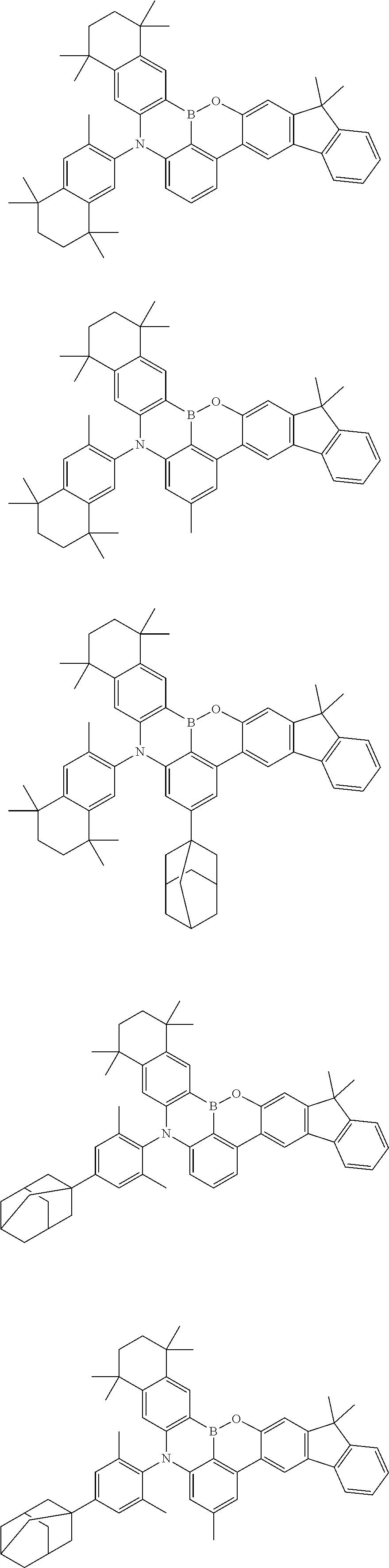

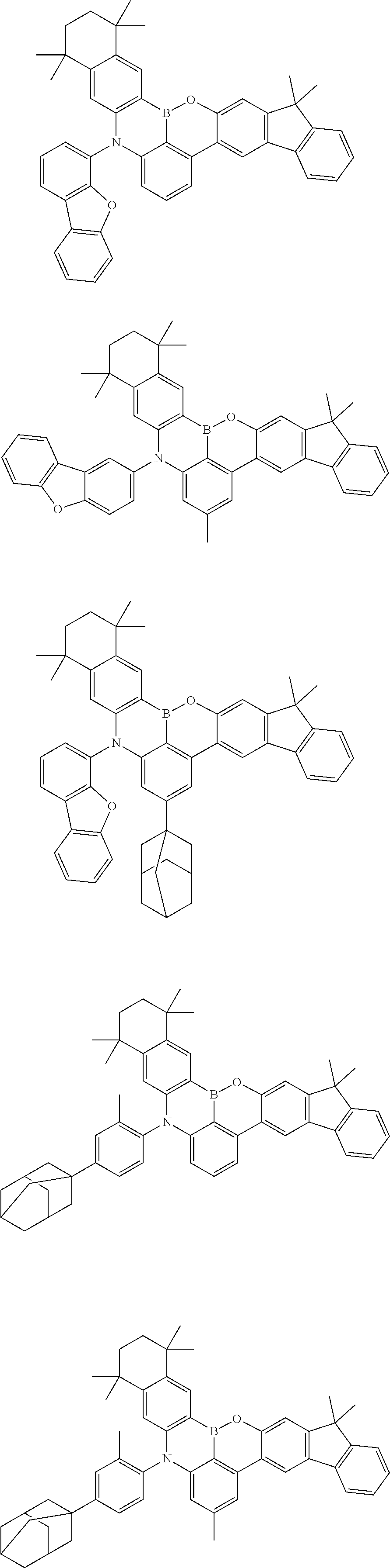

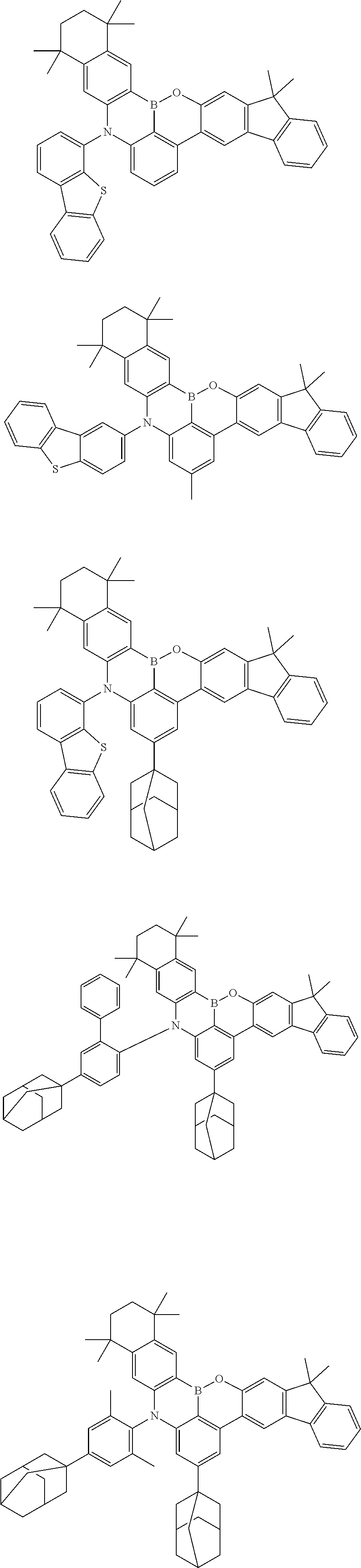

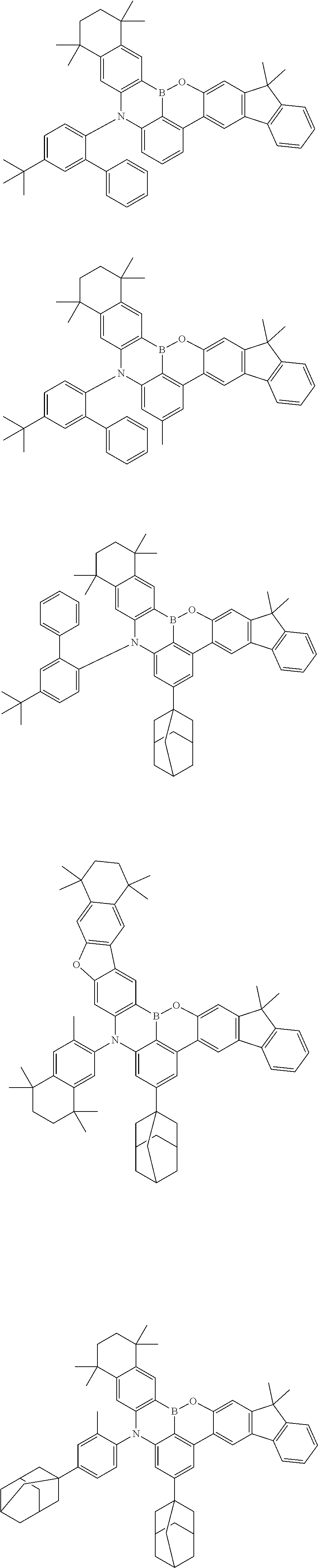

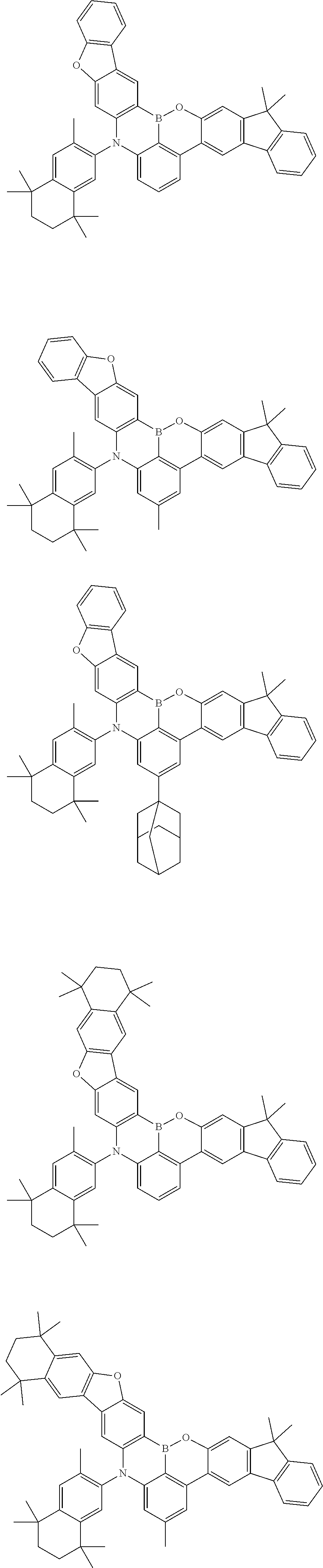

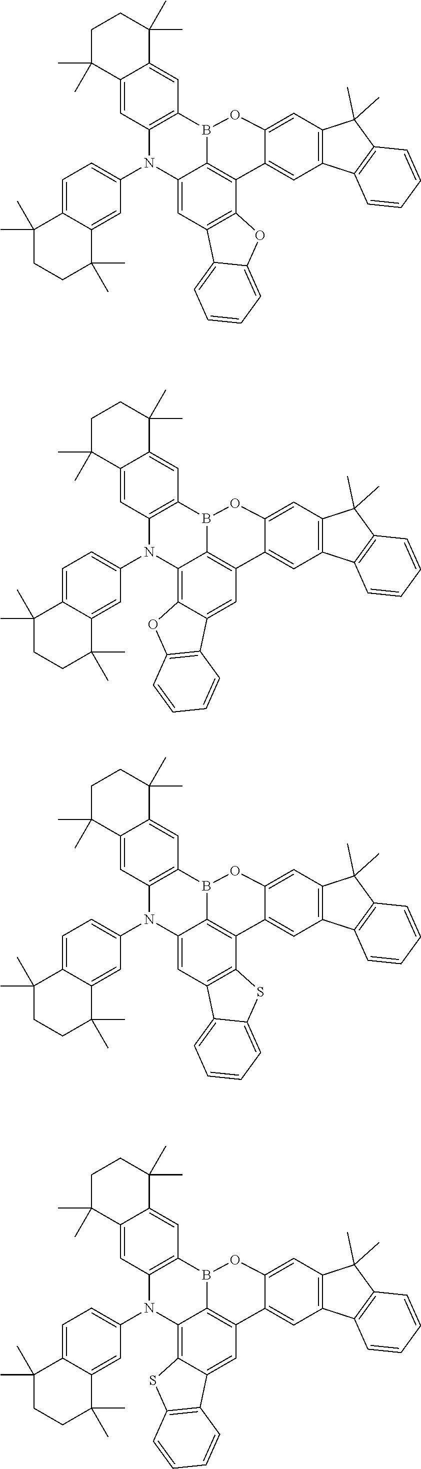

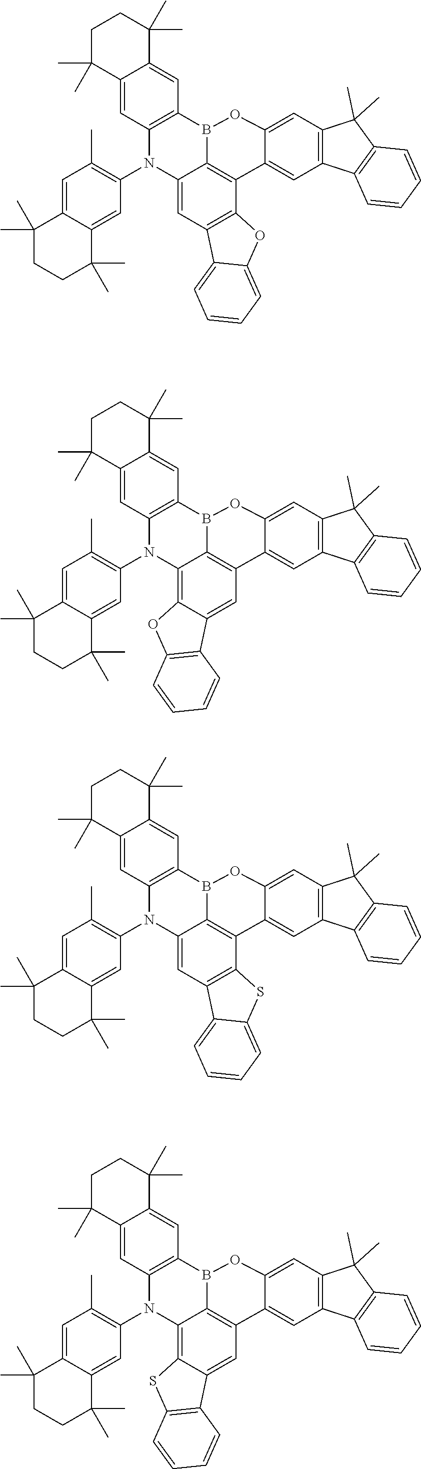

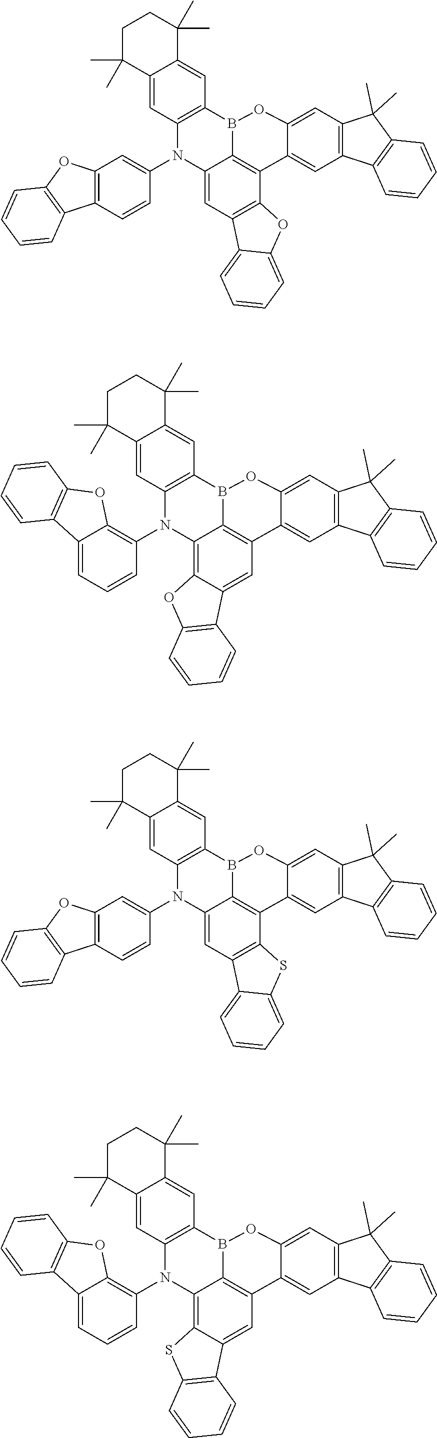 [SMILES: CC1(C)CCC(C)(C)c2cc3c(cc21)B1Oc2cc4c(cc2-c2c1c(cc1c2oc2ccccc21)N3c1ccc2c(c1)oc1ccccc12)-c1ccccc1C4(C)C ; CC1(C)CCC(C)(C)c2cc3c(cc21)B1Oc2cc4c(cc2-c2cc5c(oc6ccccc65)c(c21)N3c1cccc2c1oc1ccccc12)-c1ccccc1C4(C)C ; CC1(C)CCC(C)(C)c2cc3c(cc21)B1Oc2cc4c(cc2-c2c1c(cc1c2sc2ccccc21)N3c1ccc2c(c1)oc1ccccc12)-c1ccccc1C4(C)C ; CC1(C)CCC(C)(C)c2cc3c(cc21)B1Oc2cc4c(cc2-c2cc5c(sc6ccccc65)c(c21)N3c1cccc2c1oc1ccccc12)-c1ccccc1C4(C)C]

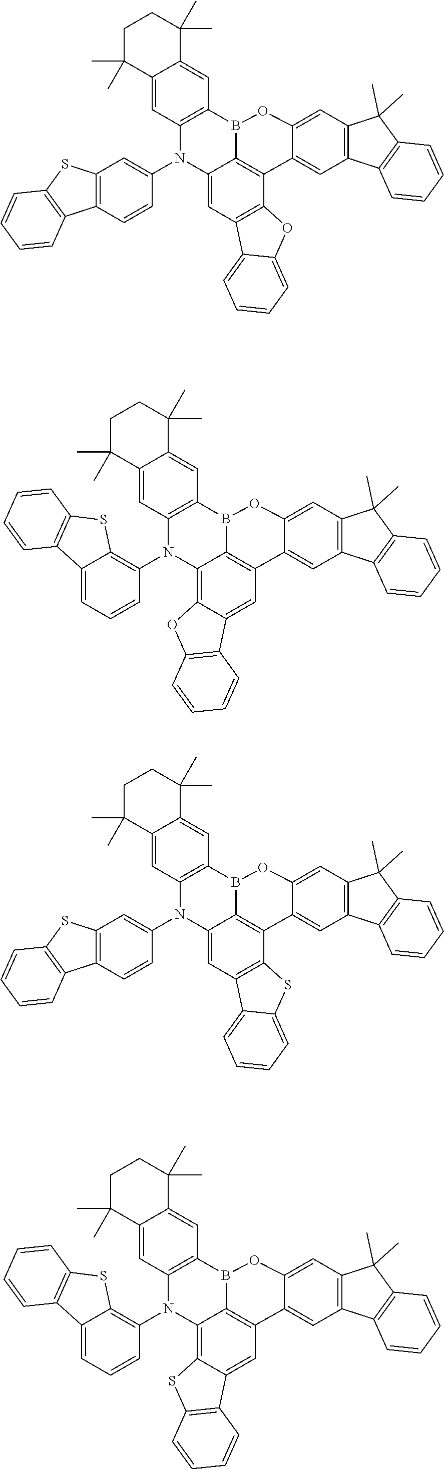

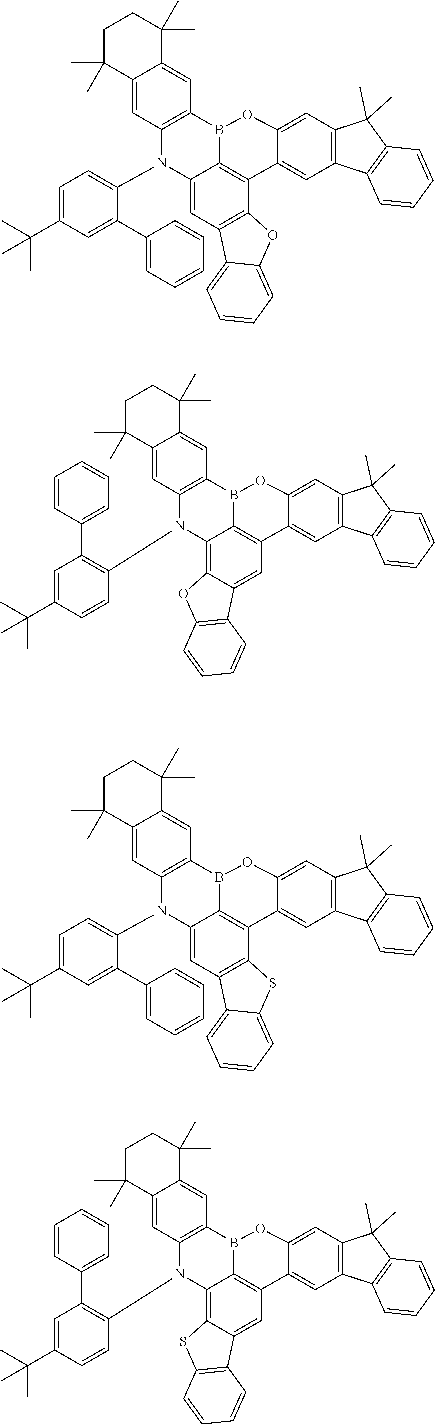

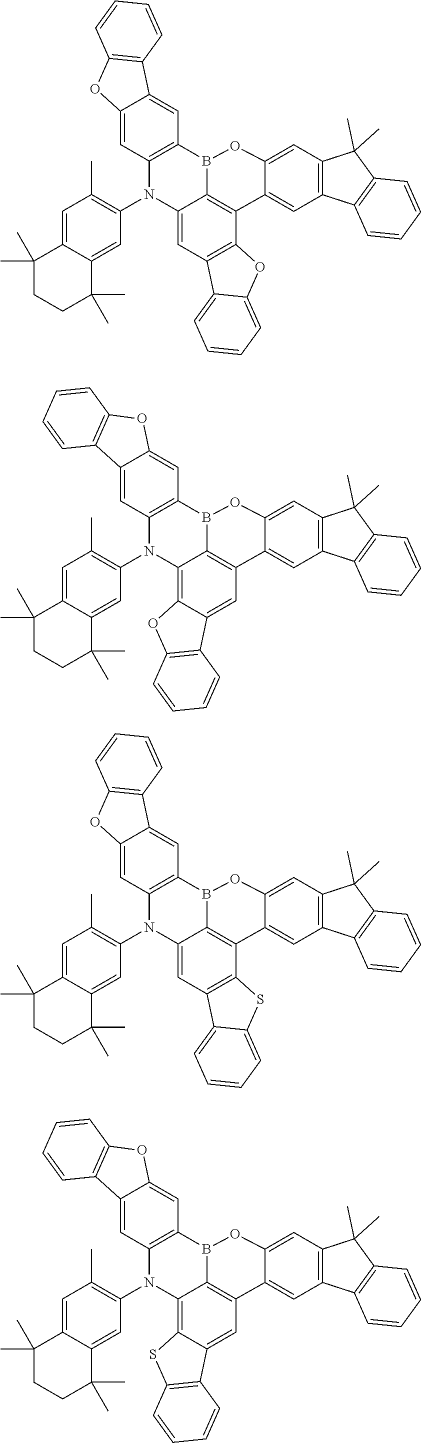

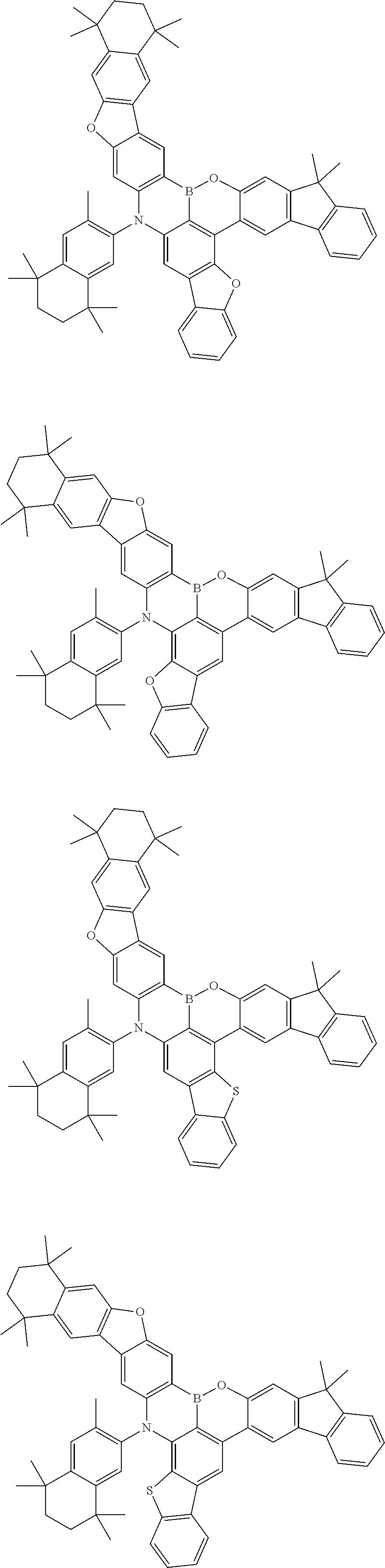

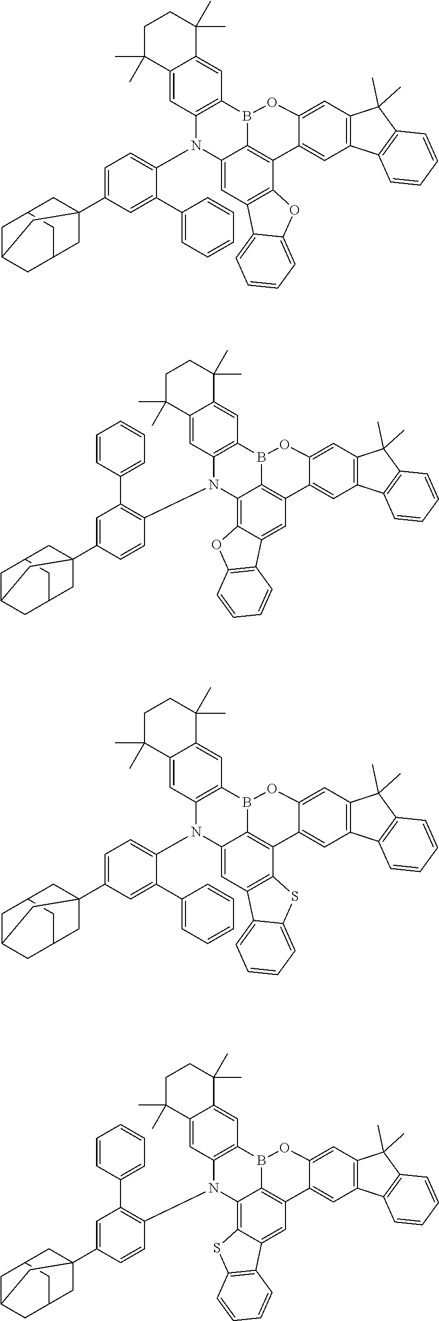

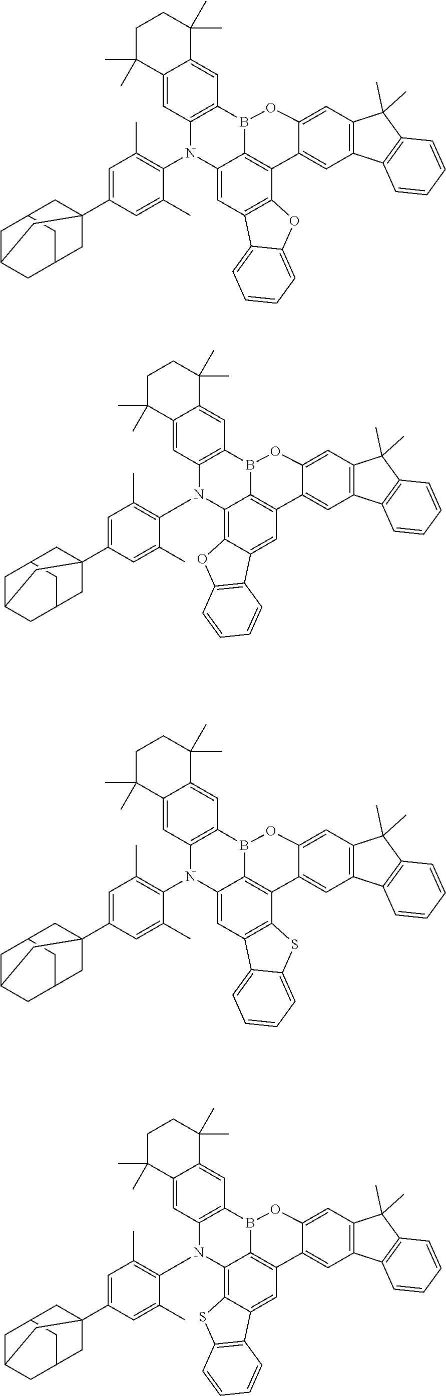

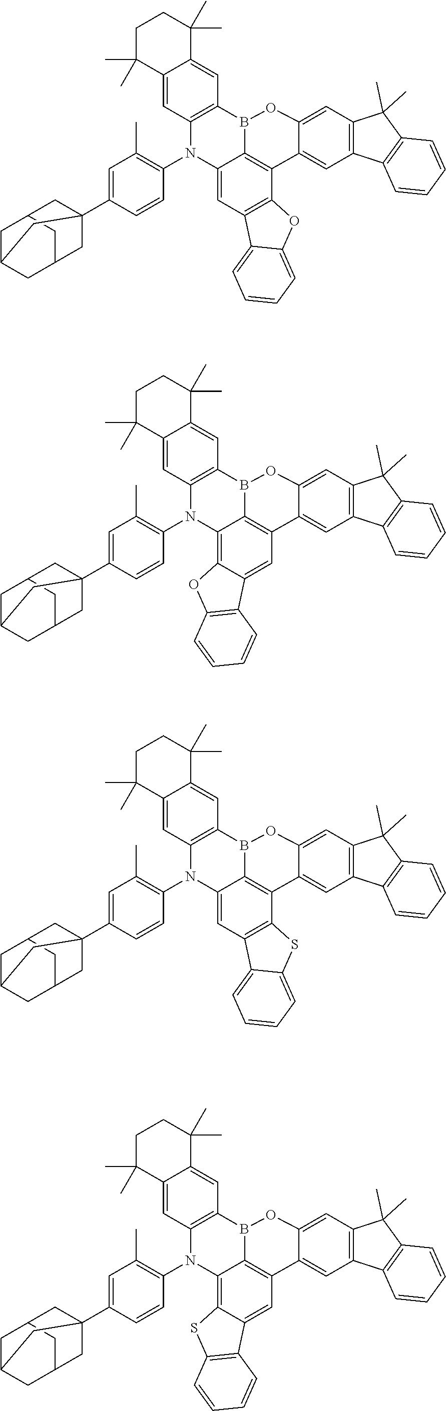

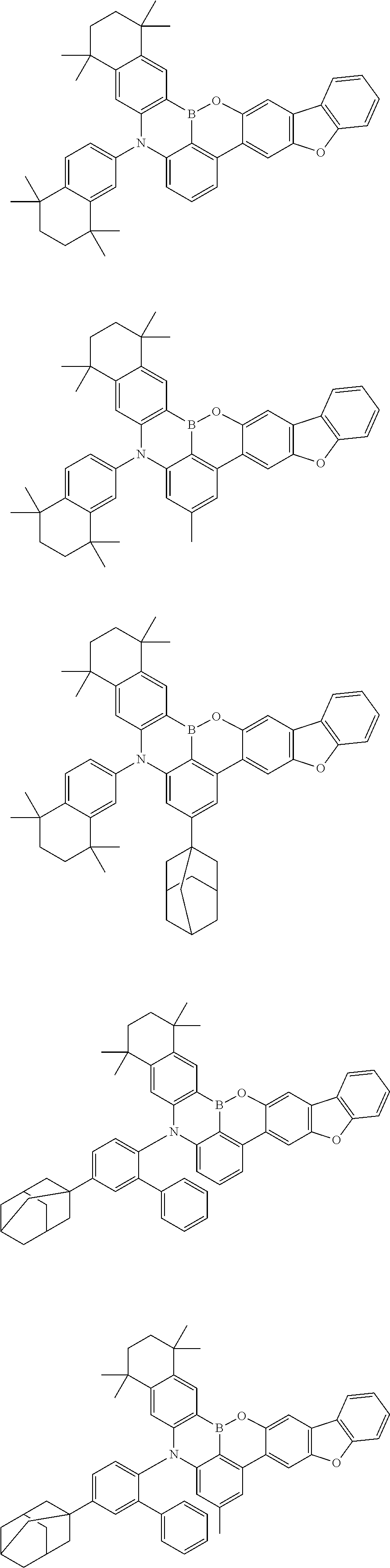

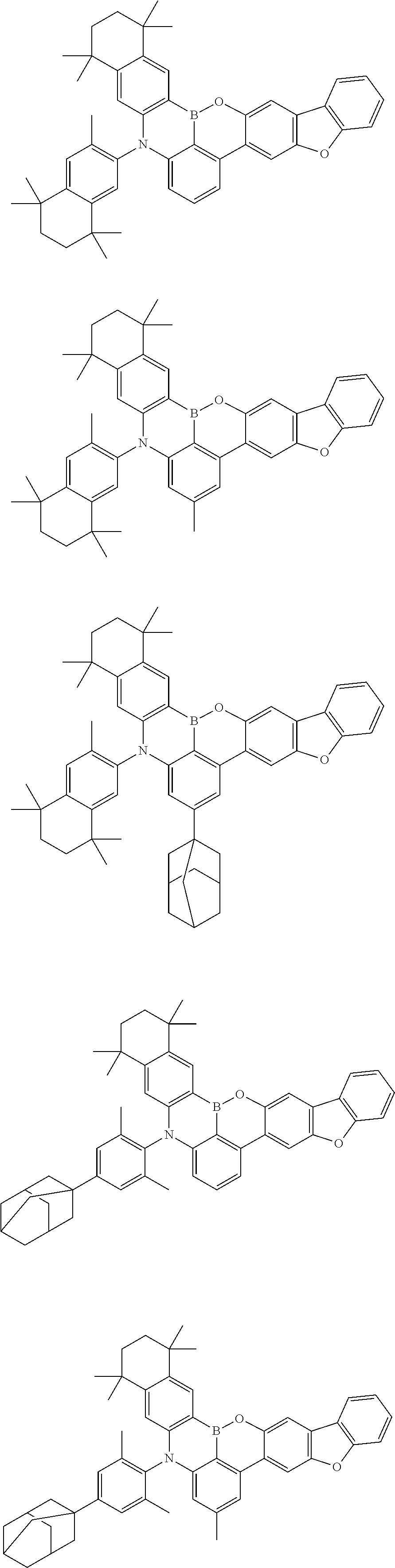

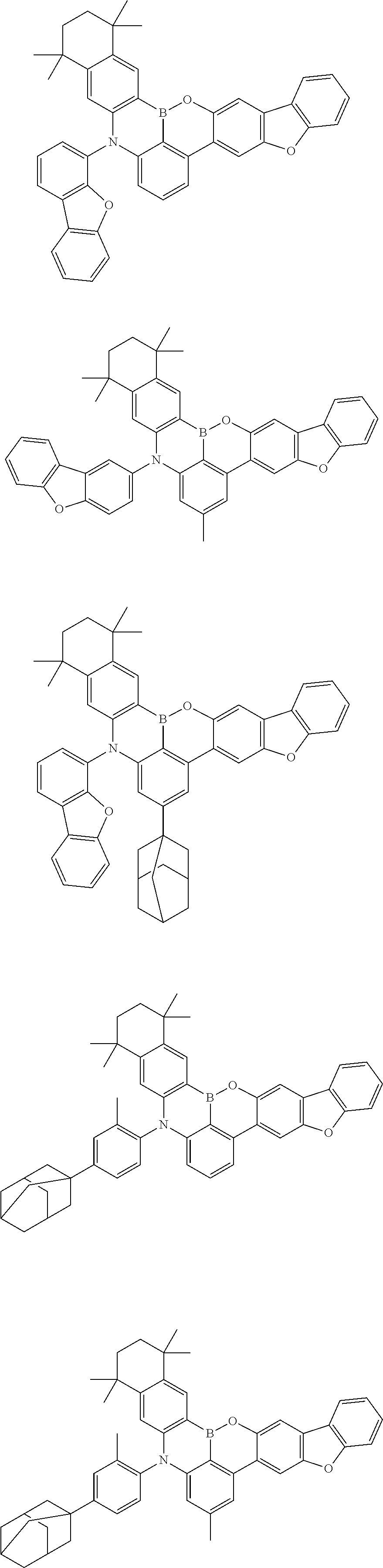

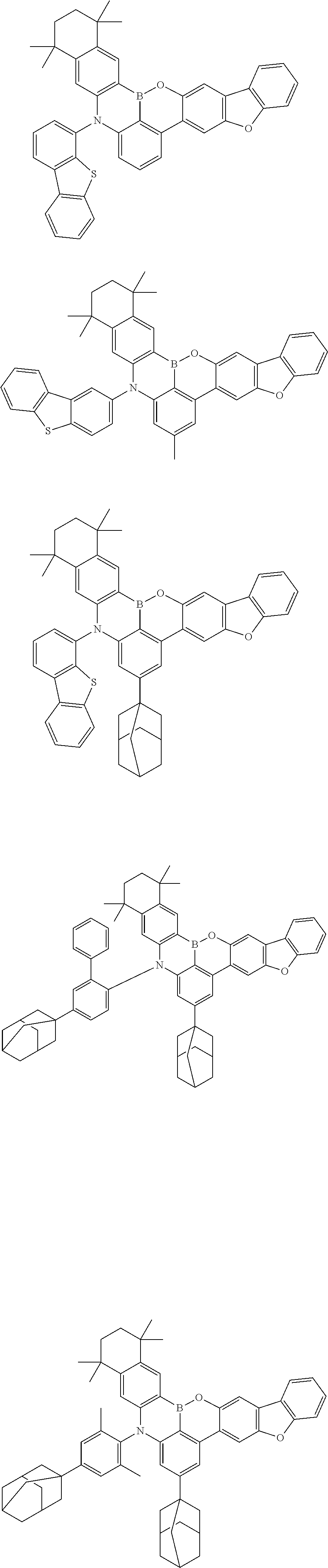

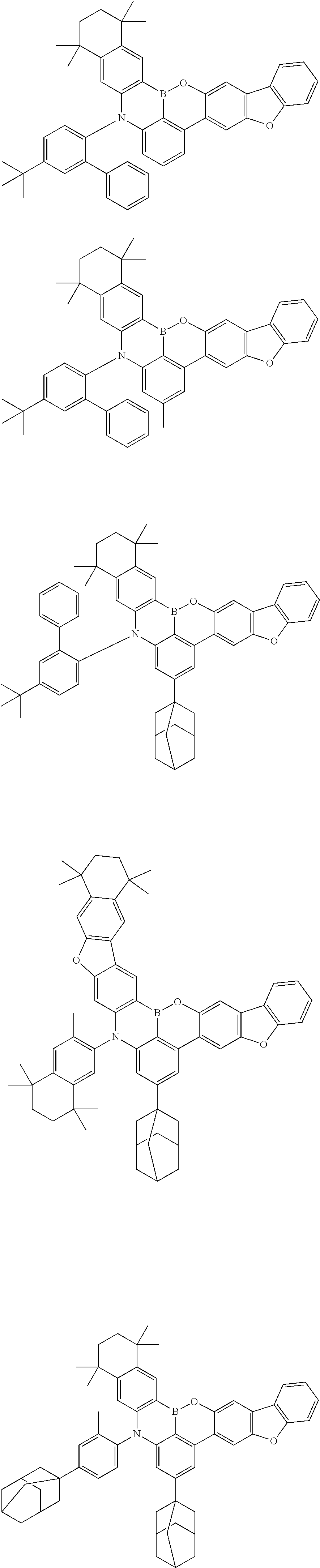

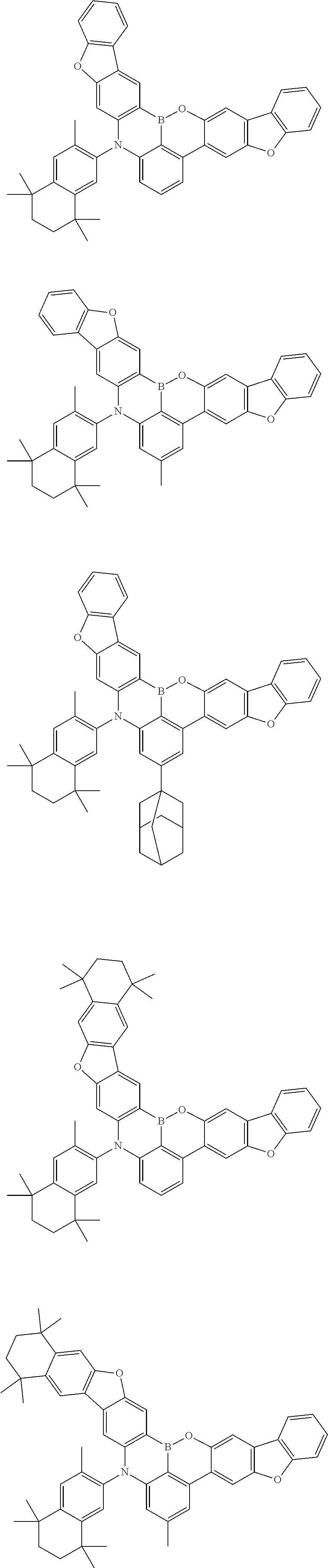

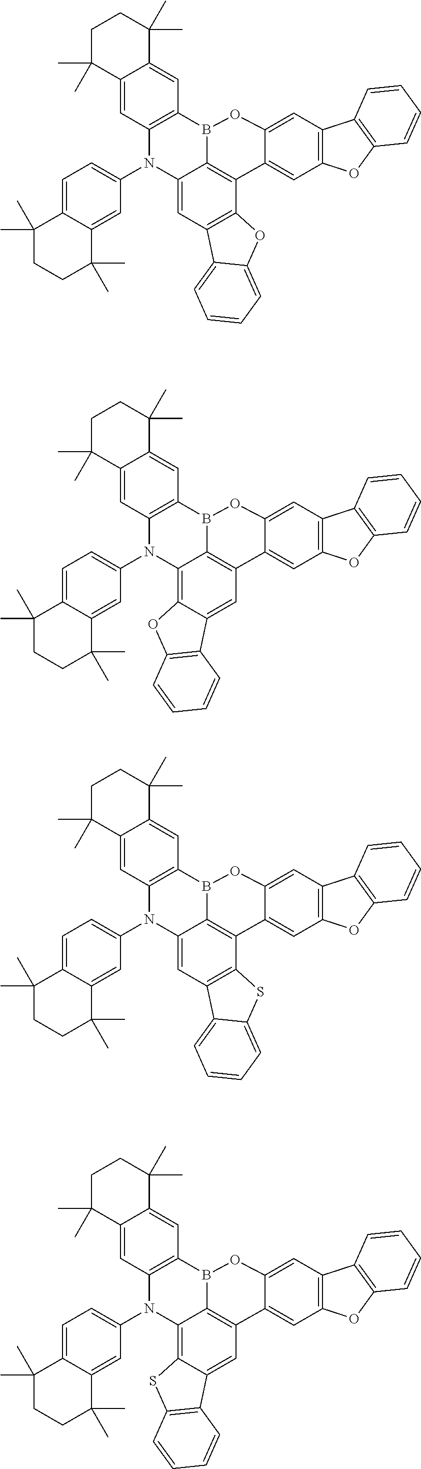

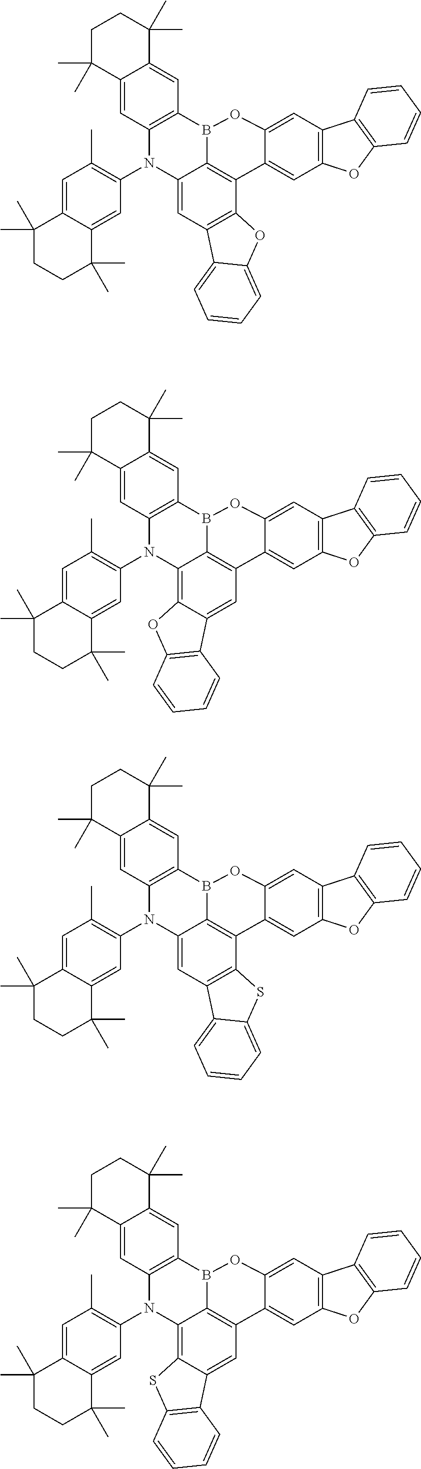

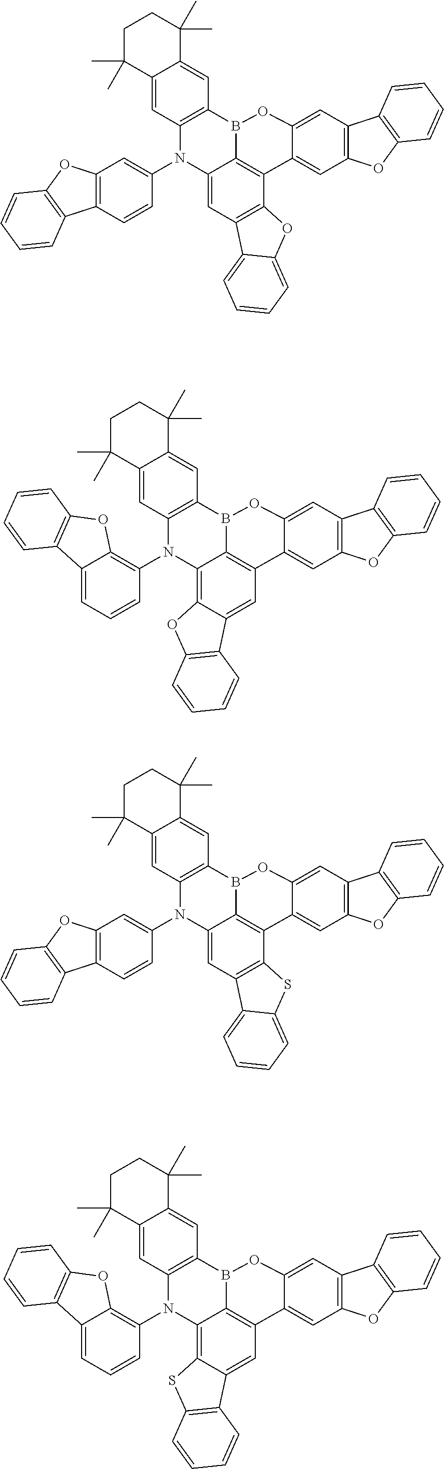

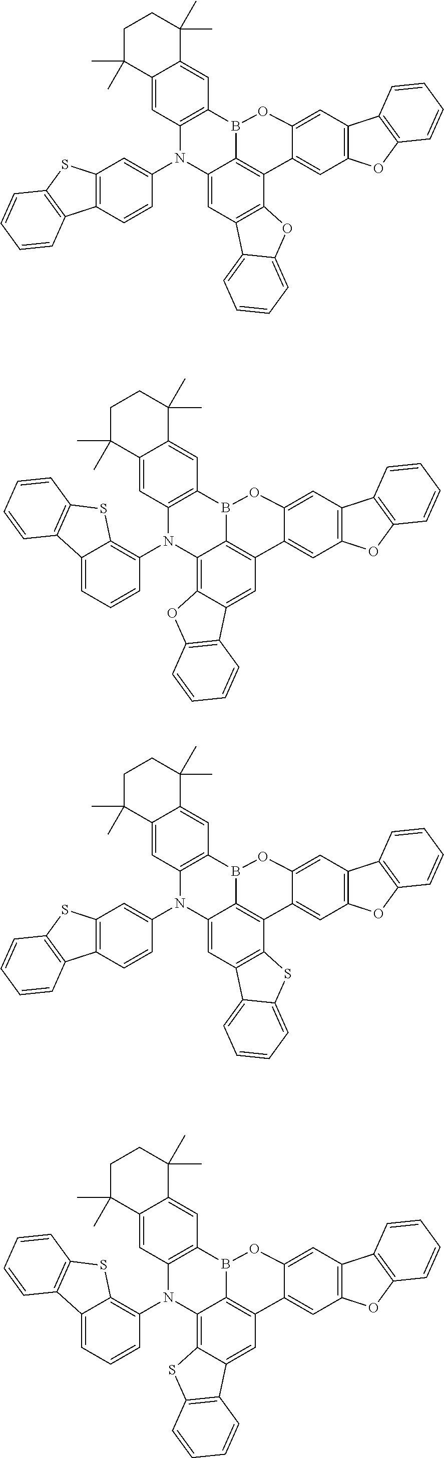

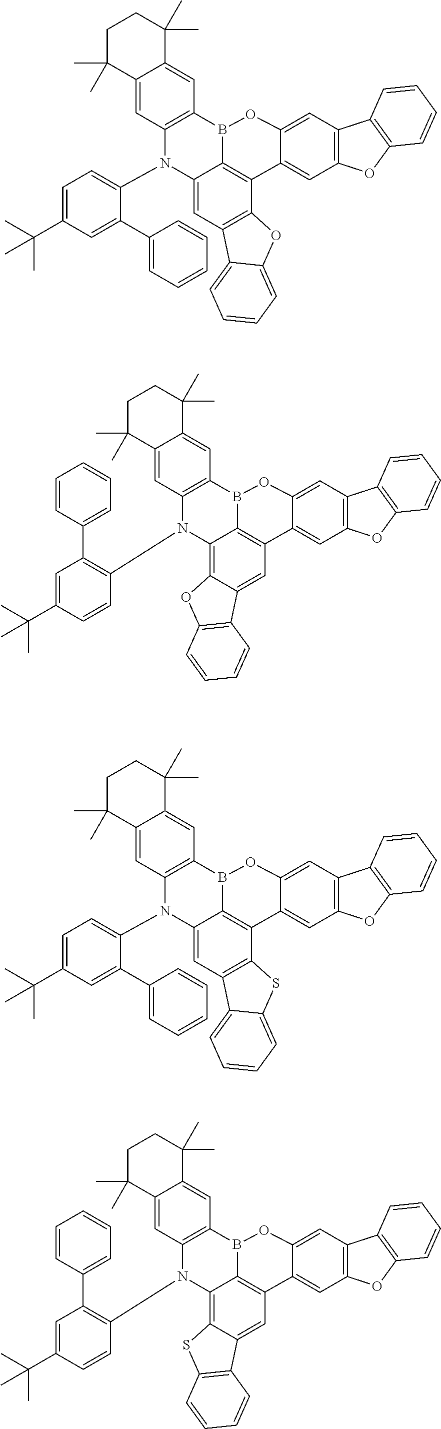

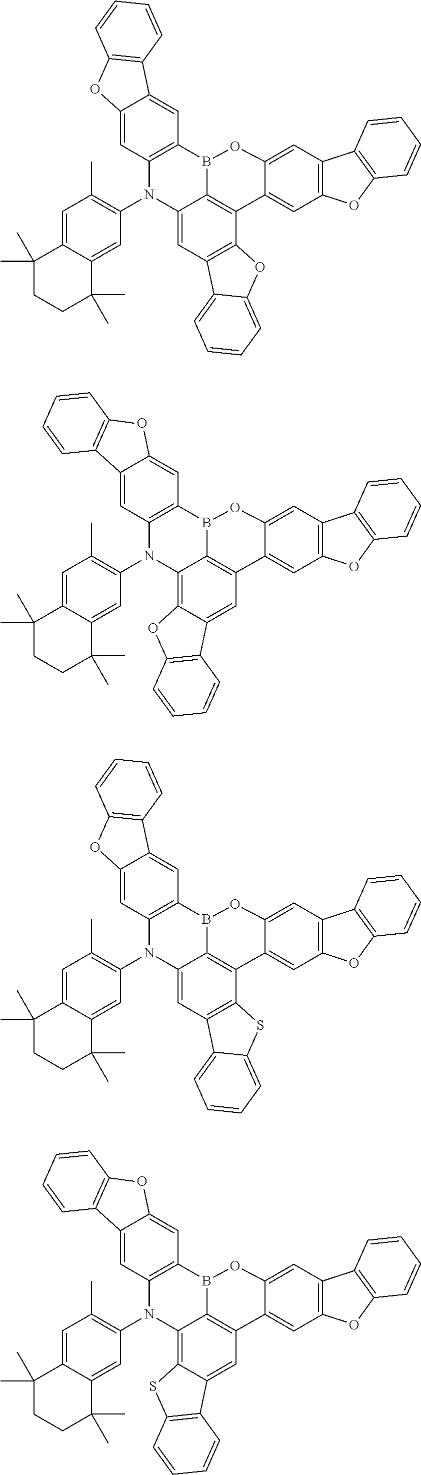

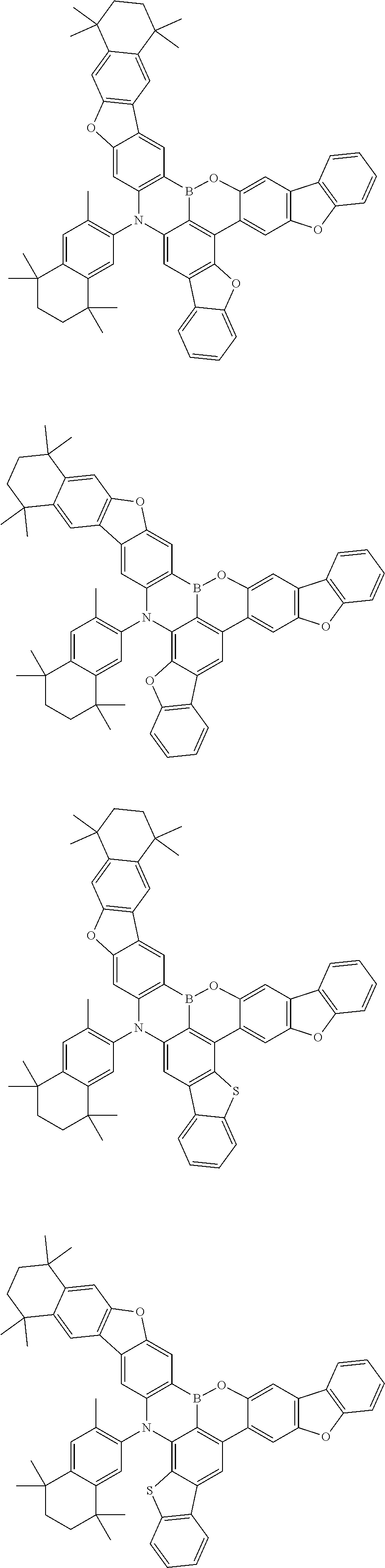

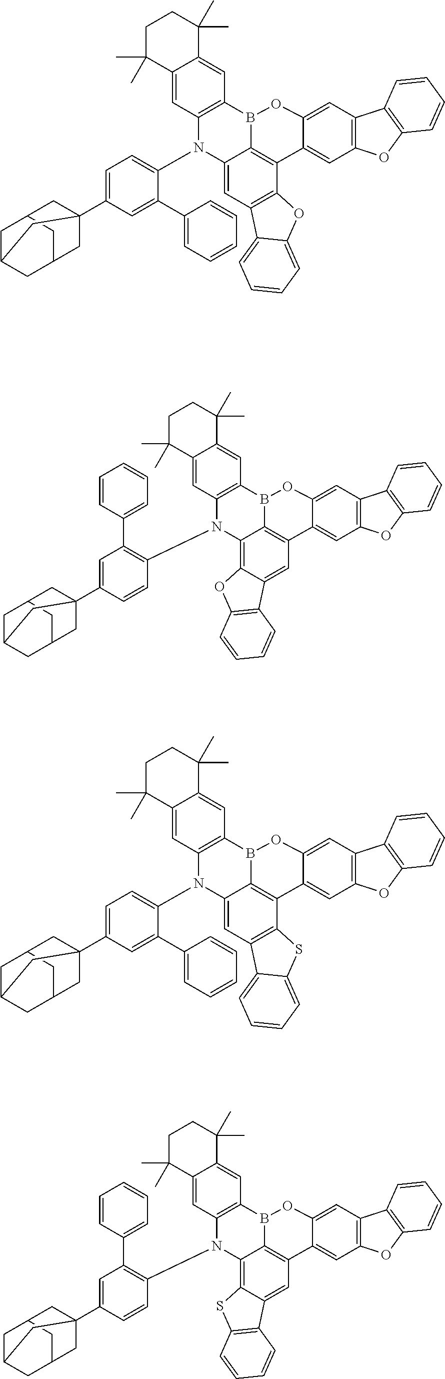

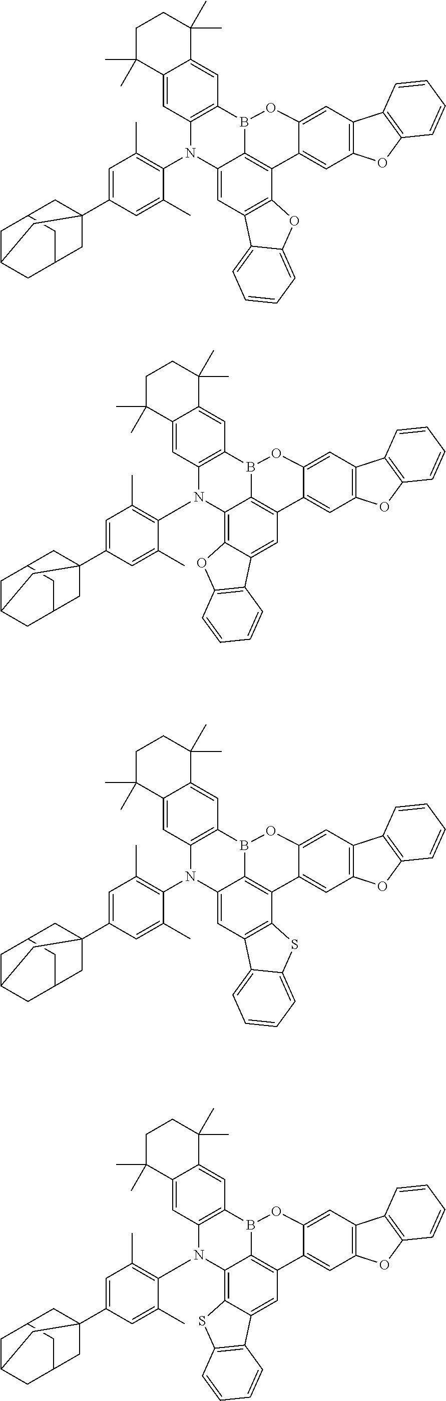

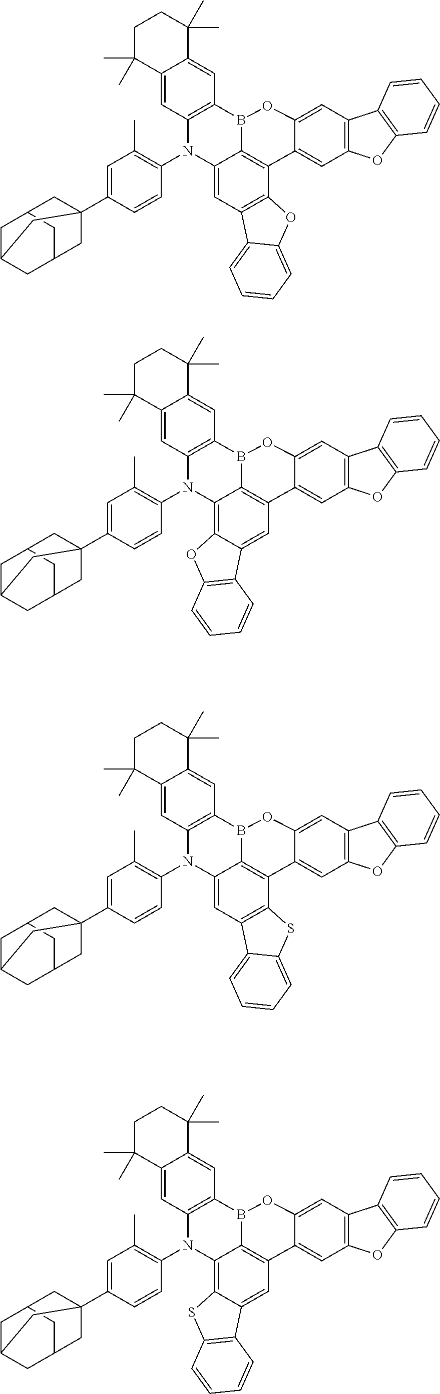

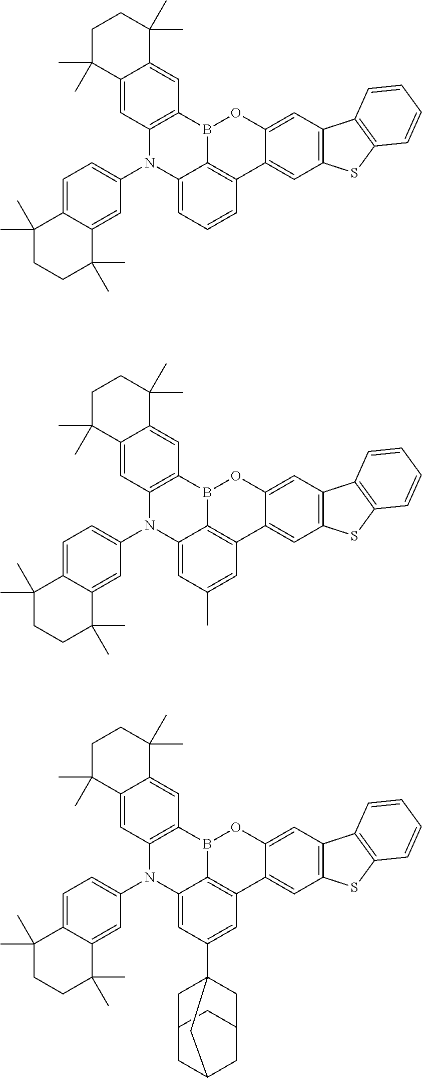 [SMILES: CC1(C)CCC(C)(C)c2cc(N3c4cc5c(cc4B4Oc6cc7c(cc6-c6cccc3c64)sc3ccccc37)C(C)(C)CCC5(C)C)ccc21 ; Cc1cc2c3c(c1)N(c1ccc4c(c1)C(C)(C)CCC4(C)C)c1cc4c(cc1B3Oc1cc3c(cc1-2)sc1ccccc13)C(C)(C)CCC4(C)C ; CC1(C)CCC(C)(C)c2cc(N3c4cc5c(cc4B4Oc6cc7c(cc6-c6cc(C89CC%10CC(CC(C%10)C8)C9)cc3c64)sc3ccccc37)C(C)(C)CCC5(C)C)ccc21]

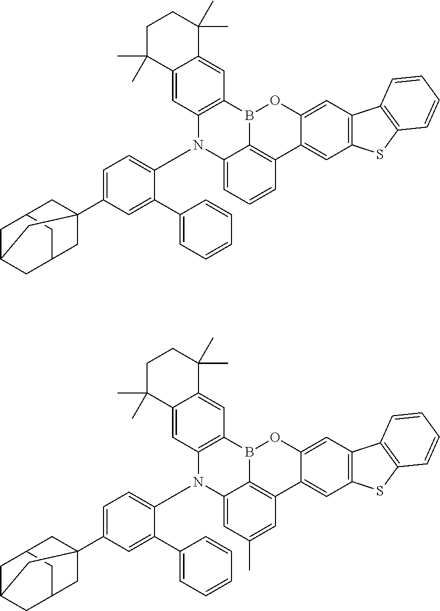 [SMILES: CC1(C)CCC(C)(C)c2cc3c(cc21)B1Oc2cc4c(cc2-c2cccc(c21)N3c1ccc(C23CC5CC(CC(C5)C2)C3)cc1-c1ccccc1)sc1ccccc14 ; Cc1cc2c3c(c1)N(c1ccc(C45CC6CC(CC(C6)C4)C5)cc1-c1ccccc1)c1cc4c(cc1B3Oc1cc3c(cc1-2)sc1ccccc13)C(C)(C)CCC4(C)C]

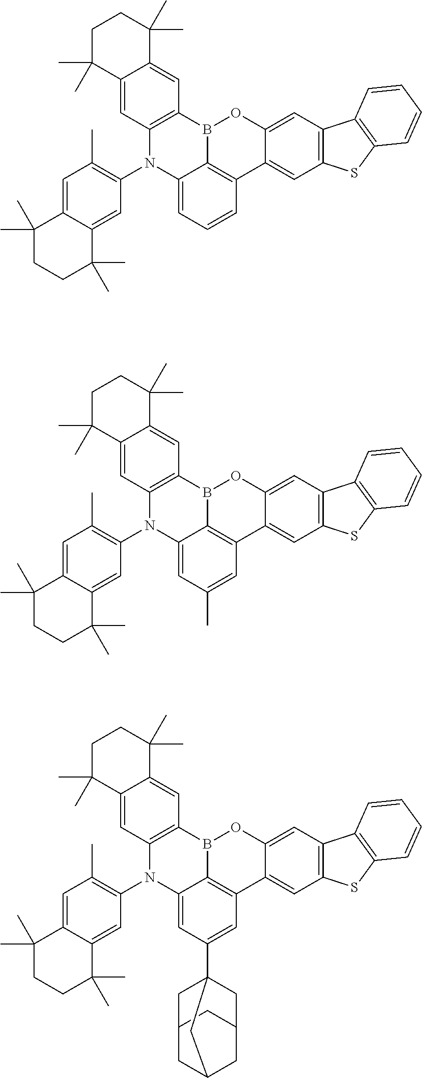 [SMILES: Cc1cc2c(cc1N1c3cc4c(cc3B3Oc5cc6c(cc5-c5cccc1c53)sc1ccccc16)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Oc1cc3c(cc1-2)sc1ccccc13)C(C)(C)CCC4(C)C ; Cc1cc2c(cc1N1c3cc4c(cc3B3Oc5cc6c(cc5-c5cc(C78CC9CC(CC(C9)C7)C8)cc1c53)sc1ccccc16)C(C)(C)CCC4(C)C)C(C)(C)CCC2(C)C]

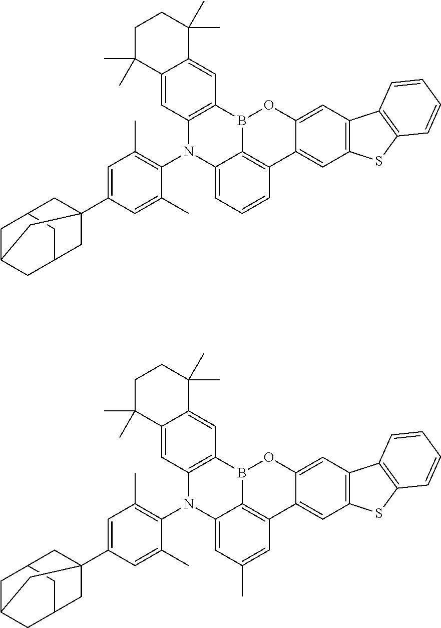 [SMILES: Cc1cc(C23CC4CC(CC(C4)C2)C3)cc(C)c1N1c2cc3c(cc2B2Oc4cc5c(cc4-c4cccc1c42)sc1ccccc15)C(C)(C)CCC3(C)C ; Cc1cc2c3c(c1)N(c1c(C)cc(C45CC6CC(CC(C6)C4)C5)cc1C)c1cc4c(cc1B3Oc1cc3c(cc1-2)sc1ccccc13)C(C)(C)CCC4(C)C]

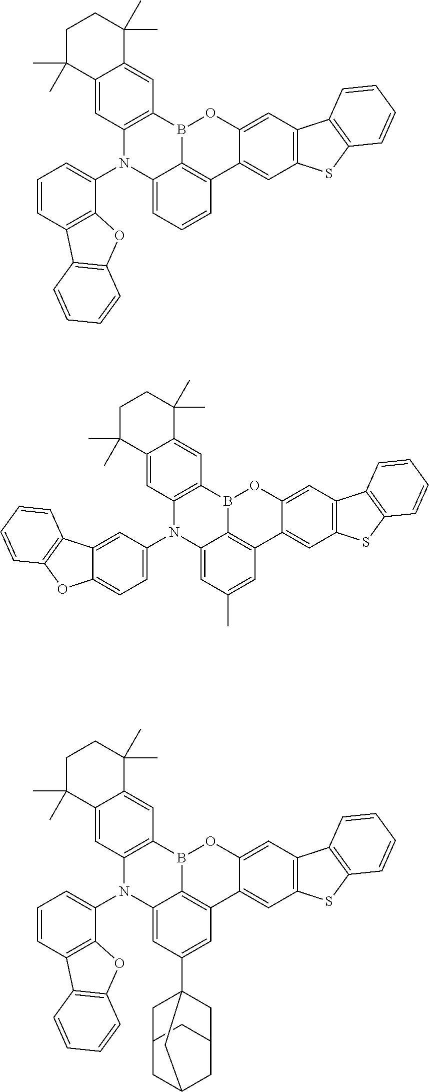 [SMILES: CC1(C)CCC(C)(C)c2cc3c(cc21)B1Oc2cc4c(cc2-c2cccc(c21)N3c1cccc2c1oc1ccccc12)sc1ccccc14 ; Cc1cc2c3c(c1)N(c1ccc4oc5ccccc5c4c1)c1cc4c(cc1B3Oc1cc3c(cc1-2)sc1ccccc13)C(C)(C)CCC4(C)C ; CC1(C)CCC(C)(C)c2cc3c(cc21)B1Oc2cc4c(cc2-c2cc(C56CC7CC(CC(C7)C5)C6)cc(c21)N3c1cccc2c1oc1ccccc12)sc1ccccc14]

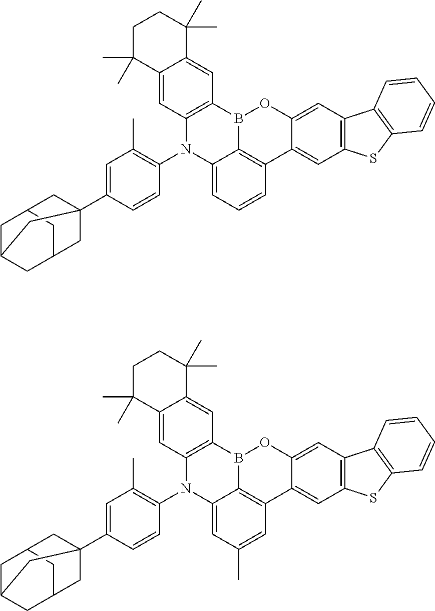 [SMILES: Cc1cc(C23CC4CC(CC(C4)C2)C3)ccc1N1c2cc3c(cc2B2Oc4cc5c(cc4-c4cccc1c42)sc1ccccc15)C(C)(C)CCC3(C)C ; Cc1cc2c3c(c1)N(c1ccc(C45CC6CC(CC(C6)C4)C5)cc1C)c1cc4c(cc1B3Oc1cc3c(cc1-2)sc1ccccc13)C(C)(C)CCC4(C)C]

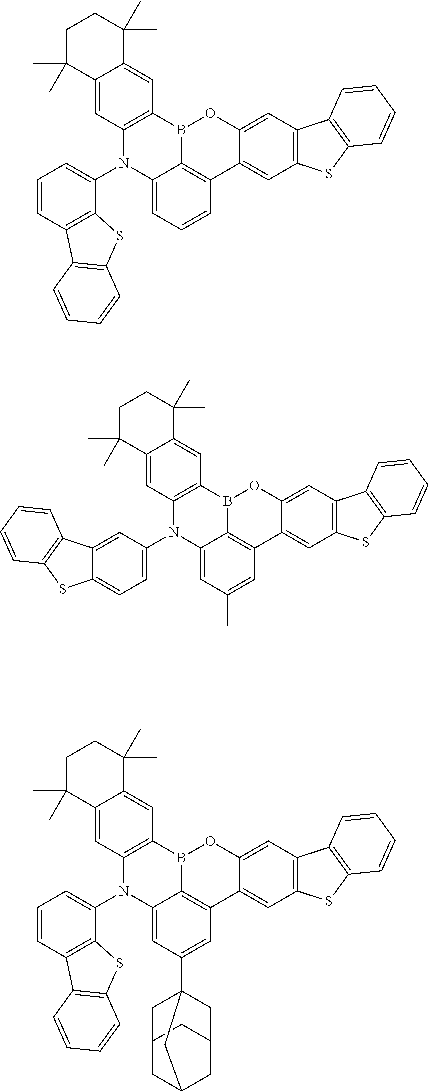 [SMILES: CC1(C)CCC(C)(C)c2cc3c(cc21)B1Oc2cc4c(cc2-c2cccc(c21)N3c1cccc2c1sc1ccccc12)sc1ccccc14 ; Cc1cc2c3c(c1)N(c1ccc4sc5ccccc5c4c1)c1cc4c(cc1B3Oc1cc3c(cc1-2)sc1ccccc13)C(C)(C)CCC4(C)C ; CC1(C)CCC(C)(C)c2cc3c(cc21)B1Oc2cc4c(cc2-c2cc(C56CC7CC(CC(C7)C5)C6)cc(c21)N3c1cccc2c1sc1ccccc12)sc1ccccc14]

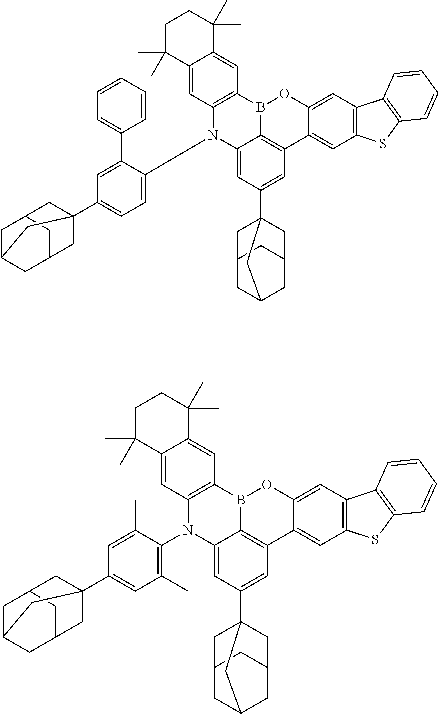 [SMILES: CC1(C)CCC(C)(C)c2cc3c(cc21)B1Oc2cc4c(cc2-c2cc(C56CC7CC(CC(C7)C5)C6)cc(c21)N3c1ccc(C23CC5CC(CC(C5)C2)C3)cc1-c1ccccc1)sc1ccccc14 ; Cc1cc(C23CC4CC(CC(C4)C2)C3)cc(C)c1N1c2cc3c(cc2B2Oc4cc5c(cc4-c4cc(C67CC8CC(CC(C8)C6)C7)cc1c42)sc1ccccc15)C(C)(C)CCC3(C)C]

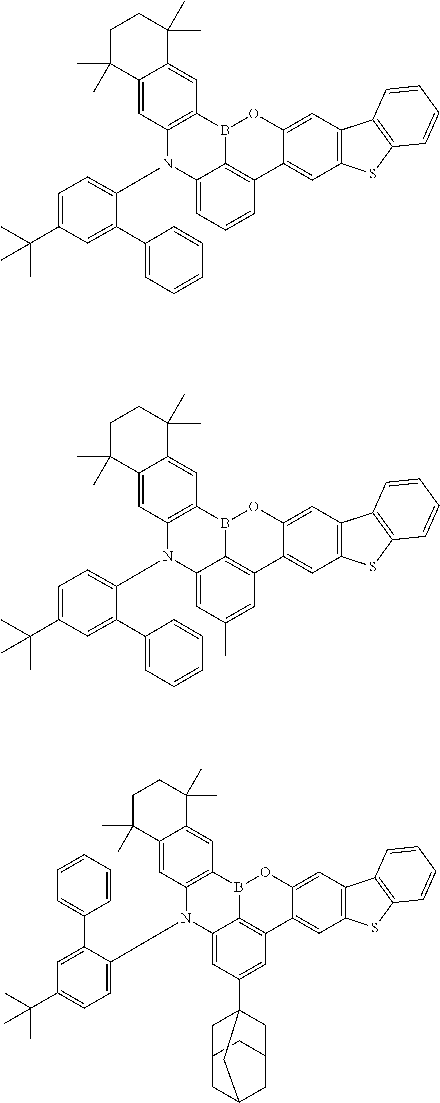 [SMILES: CC(C)(C)c1ccc(N2c3cc4c(cc3B3Oc5cc6c(cc5-c5cccc2c53)sc2ccccc26)C(C)(C)CCC4(C)C)c(-c2ccccc2)c1 ; Cc1cc2c3c(c1)N(c1ccc(C(C)(C)C)cc1-c1ccccc1)c1cc4c(cc1B3Oc1cc3c(cc1-2)sc1ccccc13)C(C)(C)CCC4(C)C ; CC(C)(C)c1ccc(N2c3cc4c(cc3B3Oc5cc6c(cc5-c5cc(C78CC9CC(CC(C9)C7)C8)cc2c53)sc2ccccc26)C(C)(C)CCC4(C)C)c(-c2ccccc2)c1]

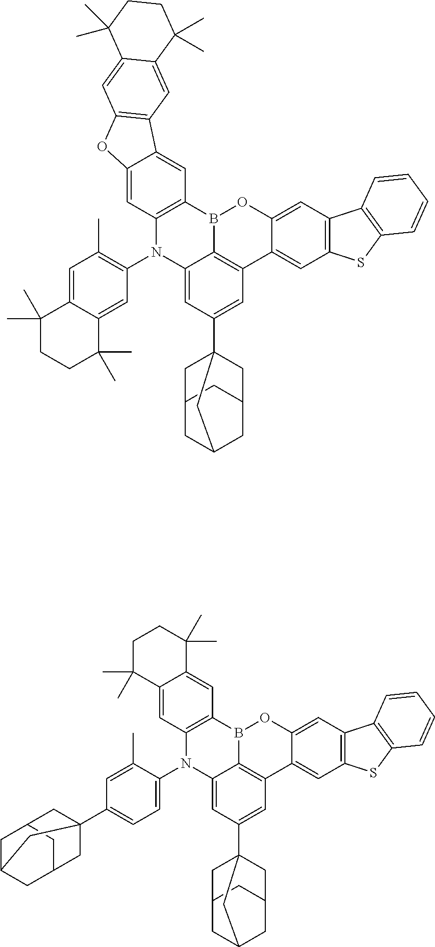 [SMILES: Cc1cc2c(cc1N1c3cc4oc5cc6c(cc5c4cc3B3Oc4cc5c(cc4-c4cc(C78CC9CC(CC(C9)C7)C8)cc1c43)sc1ccccc15)C(C)(C)CCC6(C)C)C(C)(C)CCC2(C)C ; Cc1cc(C23CC4CC(CC(C4)C2)C3)ccc1N1c2cc3c(cc2B2Oc4cc5c(cc4-c4cc(C67CC8CC(CC(C8)C6)C7)cc1c42)sc1ccccc15)C(C)(C)CCC3(C)C]

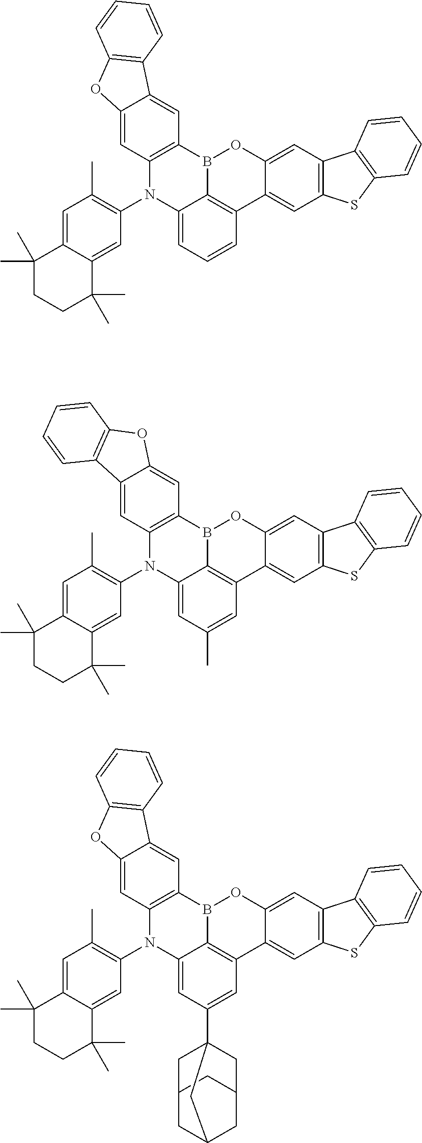 [SMILES: Cc1cc2c(cc1N1c3cc4oc5ccccc5c4cc3B3Oc4cc5c(cc4-c4cccc1c43)sc1ccccc15)C(C)(C)CCC2(C)C ; Cc1cc2c3c(c1)N(c1cc4c(cc1C)C(C)(C)CCC4(C)C)c1cc4c(cc1B3Oc1cc3c(cc1-2)sc1ccccc13)oc1ccccc14 ; Cc1cc2c(cc1N1c3cc4oc5ccccc5c4cc3B3Oc4cc5c(cc4-c4cc(C67CC8CC(CC(C8)C6)C7)cc1c43)sc1ccccc15)C(C)(C)CCC2(C)C]

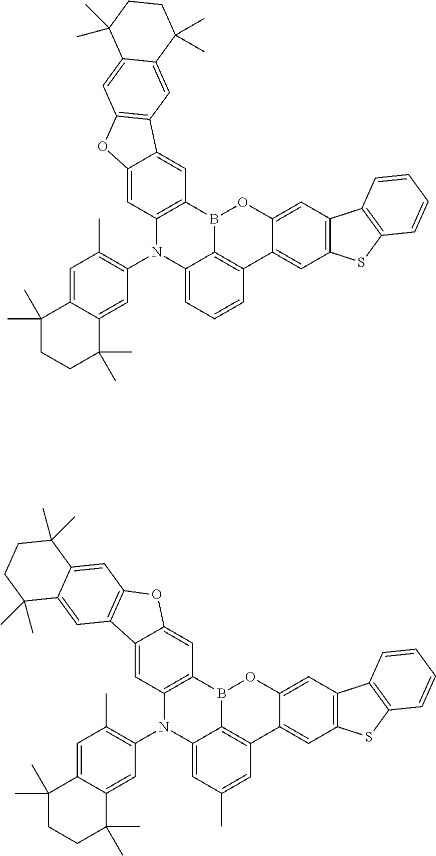 [SMILES: Cc1cc2c(cc1N1c3cc4oc5cc6c(cc5c4cc3B3Oc4cc5c(cc4-c4cccc1c43)sc1ccccc15)C(C)(C)CCC6(C)C)C(C)(C)CCC2(C)C ; Cc1cc2c3c(c1)N(c1cc4c(cc1C)C(C)(C)CCC4(C)C)c1cc4c(cc1B3Oc1cc3c(cc1-2)sc1ccccc13)oc1cc2c(cc14)C(C)(C)CCC2(C)C]

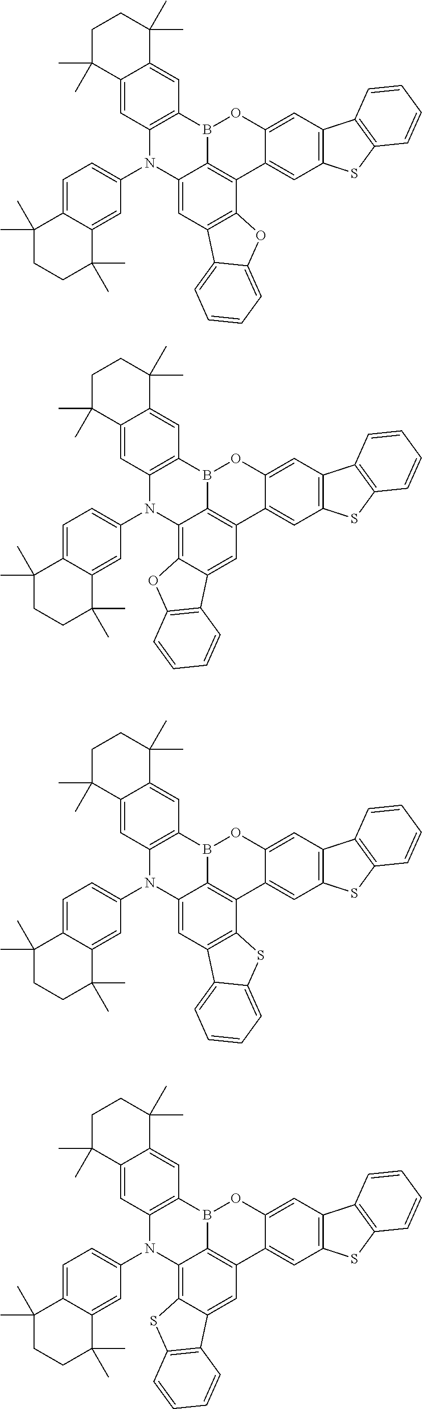 [SMILES: CC1(C)CCC(C)(C)c2cc(N3c4cc5c(cc4B4Oc6cc7c(cc6-c6c4c3cc3c6oc4ccccc43)sc3ccccc37)C(C)(C)CCC5(C)C)ccc21 ; CC1(C)CCC(C)(C)c2cc(N3c4cc5c(cc4B4Oc6cc7c(cc6-c6cc8c(oc9ccccc98)c3c64)sc3ccccc37)C(C)(C)CCC5(C)C)ccc21 ; CC1(C)CCC(C)(C)c2cc(N3c4cc5c(cc4B4Oc6cc7c(cc6-c6c4c3cc3c6sc4ccccc43)sc3ccccc37)C(C)(C)CCC5(C)C)ccc21 ; CC1(C)CCC(C)(C)c2cc(N3c4cc5c(cc4B4Oc6cc7c(cc6-c6cc8c(sc9ccccc98)c3c64)sc3ccccc37)C(C)(C)CCC5(C)C)ccc21]

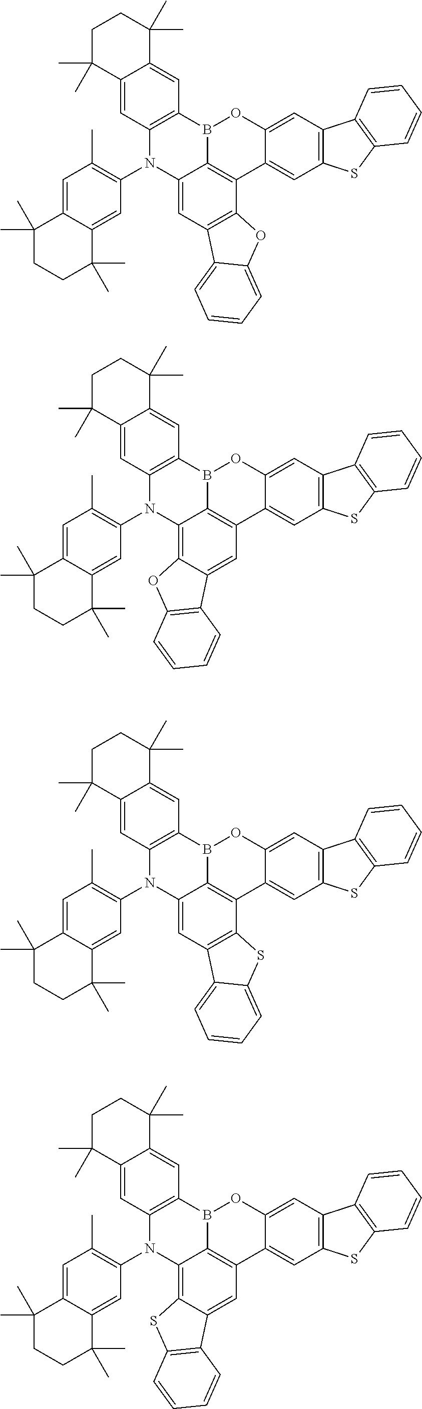 [SMILES: Cc1cc2c(cc1N1c3cc4c(cc3B3Oc5cc6c(cc5-c5c3c1cc1c5oc3ccccc31)sc1ccccc16)C(C)(C)CCC4(C)C)C(C)(C)CCC2(C)C ; Cc1cc2c(cc1N1c3cc4c(cc3B3Oc5cc6c(cc5-c5cc7c(oc8ccccc87)c1c53)sc1ccccc16)C(C)(C)CCC4(C)C)C(C)(C)CCC2(C)C ; Cc1cc2c(cc1N1c3cc4c(cc3B3Oc5cc6c(cc5-c5c3c1cc1c5sc3ccccc31)sc1ccccc16)C(C)(C)CCC4(C)C)C(C)(C)CCC2(C)C ; Cc1cc2c(cc1N1c3cc4c(cc3B3Oc5cc6c(cc5-c5cc7c(sc8ccccc87)c1c53)sc1ccccc16)C(C)(C)CCC4(C)C)C(C)(C)CCC2(C)C]

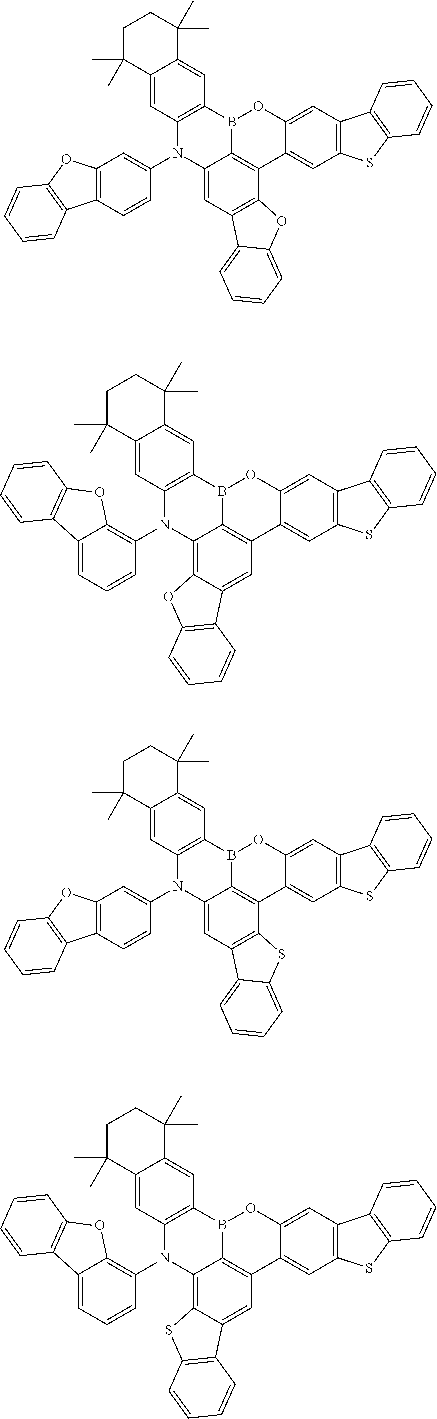 [SMILES: CC1(C)CCC(C)(C)c2cc3c(cc21)B1Oc2cc4c(cc2-c2c1c(cc1c2oc2ccccc21)N3c1ccc2c(c1)oc1ccccc12)sc1ccccc14 ; CC1(C)CCC(C)(C)c2cc3c(cc21)B1Oc2cc4c(cc2-c2cc5c(oc6ccccc65)c(c21)N3c1cccc2c1oc1ccccc12)sc1ccccc14 ; CC1(C)CCC(C)(C)c2cc3c(cc21)B1Oc2cc4c(cc2-c2c1c(cc1c2sc2ccccc21)N3c1ccc2c(c1)oc1ccccc12)sc1ccccc14 ; CC1(C)CCC(C)(C)c2cc3c(cc21)B1Oc2cc4c(cc2-c2cc5c(sc6ccccc65)c(c21)N3c1cccc2c1oc1ccccc12)sc1ccccc14]

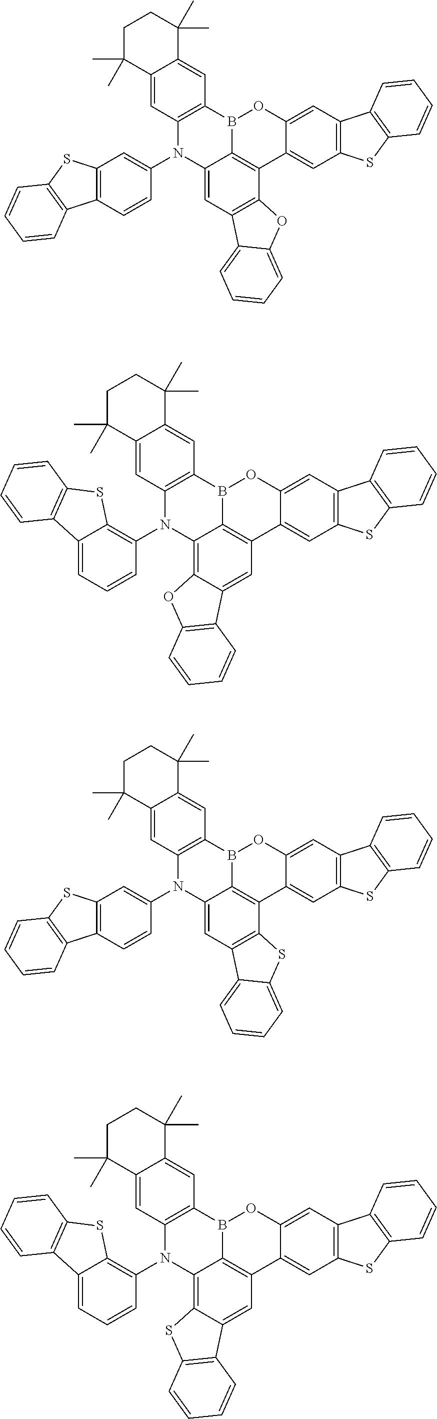 [SMILES: CC1(C)CCC(C)(C)c2cc3c(cc21)B1Oc2cc4c(cc2-c2c1c(cc1c2oc2ccccc21)N3c1ccc2c(c1)sc1ccccc12)sc1ccccc14 ; CC1(C)CCC(C)(C)c2cc3c(cc21)B1Oc2cc4c(cc2-c2cc5c(oc6ccccc65)c(c21)N3c1cccc2c1sc1ccccc12)sc1ccccc14 ; CC1(C)CCC(C)(C)c2cc3c(cc21)B1Oc2cc4c(cc2-c2c1c(cc1c2sc2ccccc21)N3c1ccc2c(c1)sc1ccccc12)sc1ccccc14 ; CC1(C)CCC(C)(C)c2cc3c(cc21)B1Oc2cc4c(cc2-c2cc5c(sc6ccccc65)c(c21)N3c1cccc2c1sc1ccccc12)sc1ccccc14]

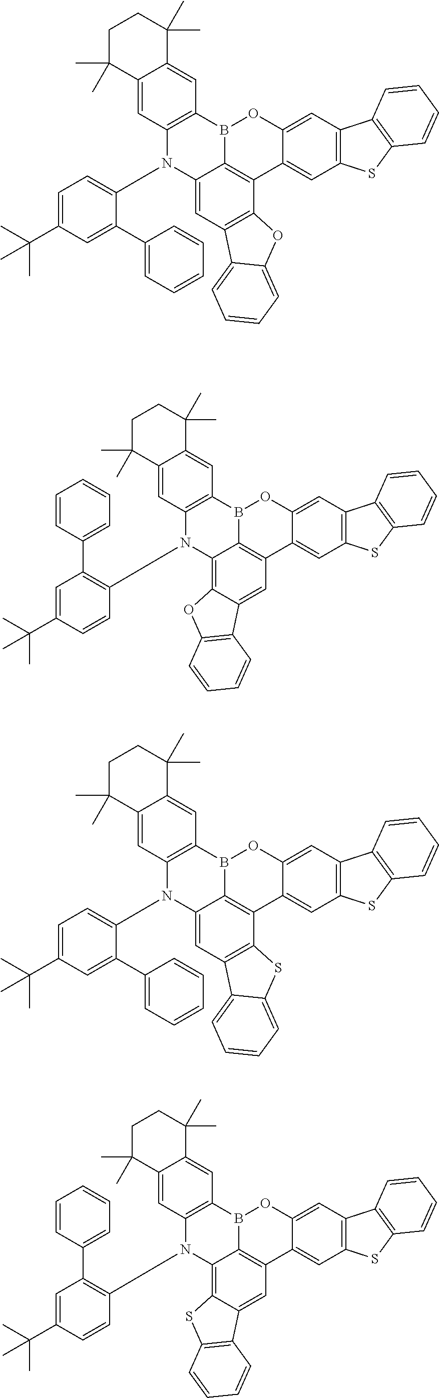 [SMILES: CC(C)(C)c1ccc(N2c3cc4c(cc3B3Oc5cc6c(cc5-c5c3c2cc2c5oc3ccccc32)sc2ccccc26)C(C)(C)CCC4(C)C)c(-c2ccccc2)c1 ; CC(C)(C)c1ccc(N2c3cc4c(cc3B3Oc5cc6c(cc5-c5cc7c(oc8ccccc87)c2c53)sc2ccccc26)C(C)(C)CCC4(C)C)c(-c2ccccc2)c1 ; CC(C)(C)c1ccc(N2c3cc4c(cc3B3Oc5cc6c(cc5-c5c3c2cc2c5sc3ccccc32)sc2ccccc26)C(C)(C)CCC4(C)C)c(-c2ccccc2)c1 ; CC(C)(C)c1ccc(N2c3cc4c(cc3B3Oc5cc6c(cc5-c5cc7c(sc8ccccc87)c2c53)sc2ccccc26)C(C)(C)CCC4(C)C)c(-c2ccccc2)c1]

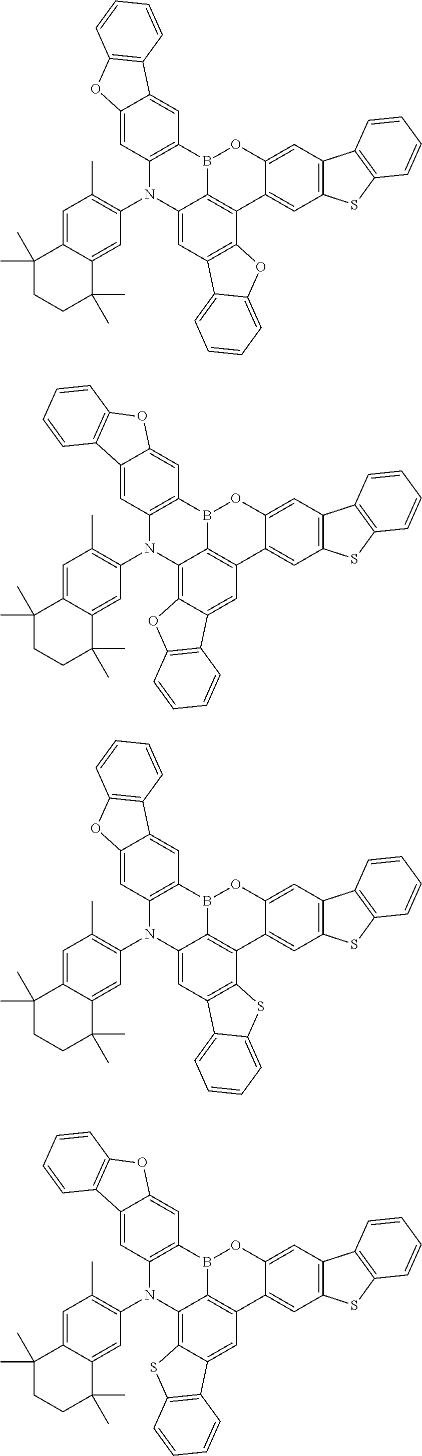

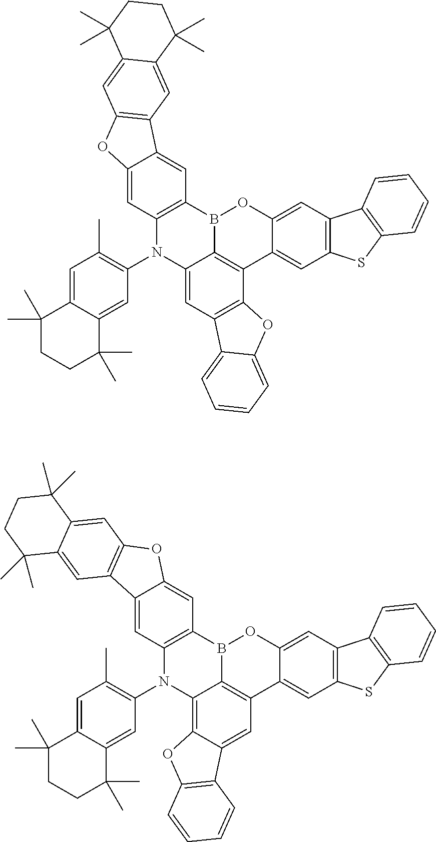 [SMILES: Cc1cc2c(cc1N1c3cc4oc5cc6c(cc5c4cc3B3Oc4cc5c(cc4-c4c3c1cc1c4oc3ccccc31)sc1ccccc15)C(C)(C)CCC6(C)C)C(C)(C)CCC2(C)C ; Cc1cc2c(cc1N1c3cc4c(cc3B3Oc5cc6c(cc5-c5cc7c(oc8ccccc87)c1c53)sc1ccccc16)oc1cc3c(cc14)C(C)(C)CCC3(C)C)C(C)(C)CCC2(C)C]

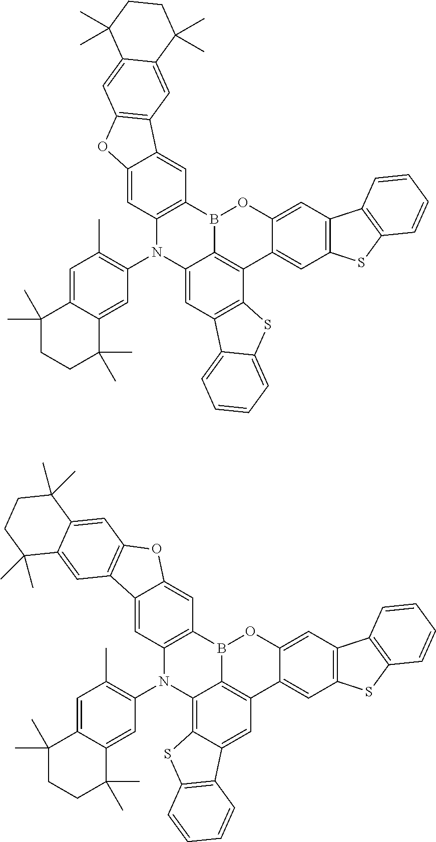 [SMILES: Cc1cc2c(cc1N1c3cc4oc5cc6c(cc5c4cc3B3Oc4cc5c(cc4-c4c3c1cc1c4sc3ccccc31)sc1ccccc15)C(C)(C)CCC6(C)C)C(C)(C)CCC2(C)C ; Cc1cc2c(cc1N1c3cc4c(cc3B3Oc5cc6c(cc5-c5cc7c(sc8ccccc87)c1c53)sc1ccccc16)oc1cc3c(cc14)C(C)(C)CCC3(C)C)C(C)(C)CCC2(C)C]

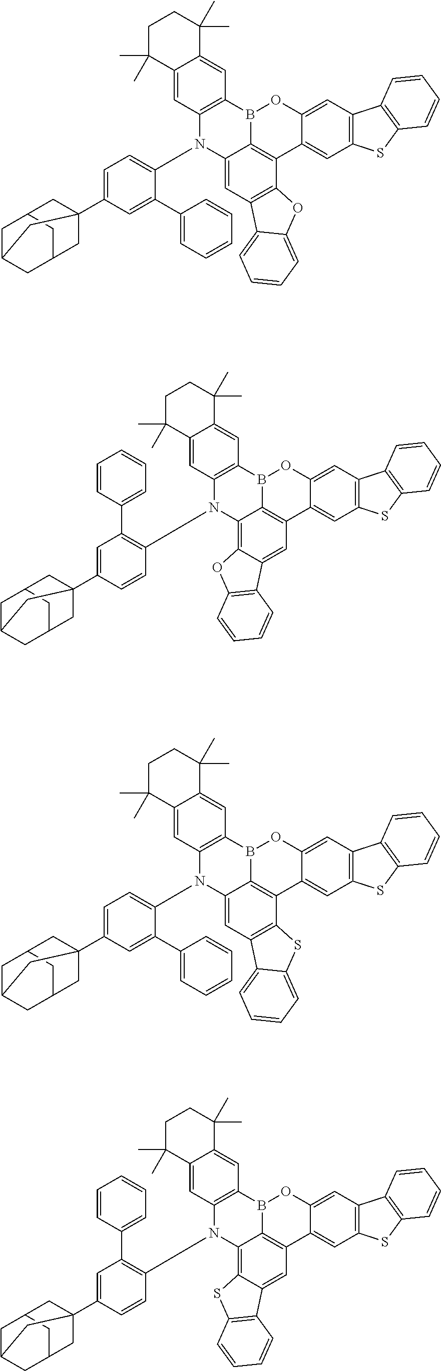 [SMILES: CC1(C)CCC(C)(C)c2cc3c(cc21)B1Oc2cc4c(cc2-c2c1c(cc1c2oc2ccccc21)N3c1ccc(C23CC5CC(CC(C5)C2)C3)cc1-c1ccccc1)sc1ccccc14 ; CC1(C)CCC(C)(C)c2cc3c(cc21)B1Oc2cc4c(cc2-c2cc5c(oc6ccccc65)c(c21)N3c1ccc(C23CC5CC(CC(C5)C2)C3)cc1-c1ccccc1)sc1ccccc14 ; CC1(C)CCC(C)(C)c2cc3c(cc21)B1Oc2cc4c(cc2-c2c1c(cc1c2sc2ccccc21)N3c1ccc(C23CC5CC(CC(C5)C2)C3)cc1-c1ccccc1)sc1ccccc14 ; CC1(C)CCC(C)(C)c2cc3c(cc21)B1Oc2cc4c(cc2-c2cc5c(sc6ccccc65)c(c21)N3c1ccc(C23CC5CC(CC(C5)C2)C3)cc1-c1ccccc1)sc1ccccc14]

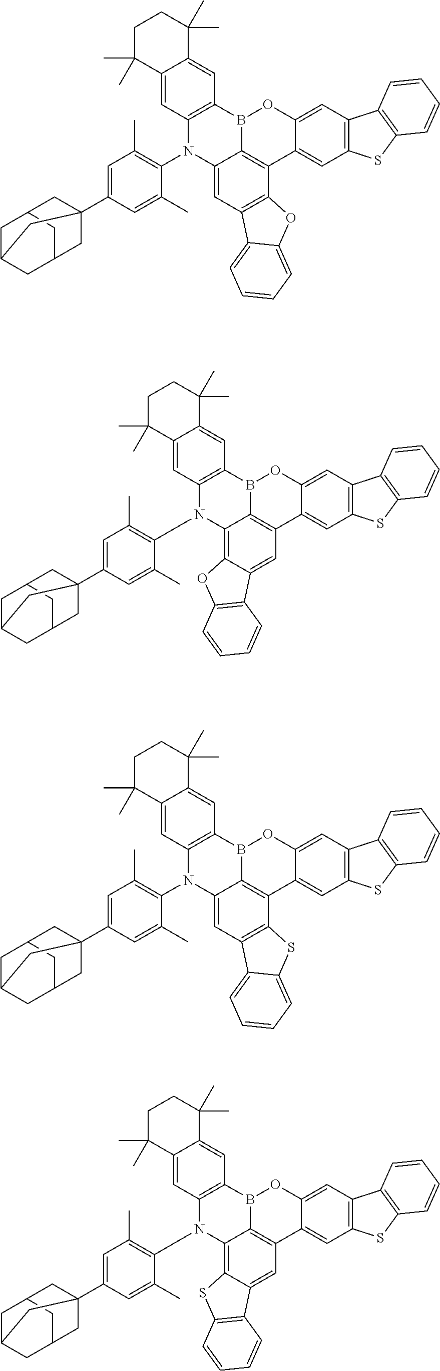 [SMILES: Cc1cc(C23CC4CC(CC(C4)C2)C3)cc(C)c1N1c2cc3c(cc2B2Oc4cc5c(cc4-c4c2c1cc1c4oc2ccccc21)sc1ccccc15)C(C)(C)CCC3(C)C ; Cc1cc(C23CC4CC(CC(C4)C2)C3)cc(C)c1N1c2cc3c(cc2B2Oc4cc5c(cc4-c4cc6c(oc7ccccc76)c1c42)sc1ccccc15)C(C)(C)CCC3(C)C ; Cc1cc(C23CC4CC(CC(C4)C2)C3)cc(C)c1N1c2cc3c(cc2B2Oc4cc5c(cc4-c4c2c1cc1c4sc2ccccc21)sc1ccccc15)C(C)(C)CCC3(C)C ; Cc1cc(C23CC4CC(CC(C4)C2)C3)cc(C)c1N1c2cc3c(cc2B2Oc4cc5c(cc4-c4cc6c(sc7ccccc76)c1c42)sc1ccccc15)C(C)(C)CCC3(C)C]

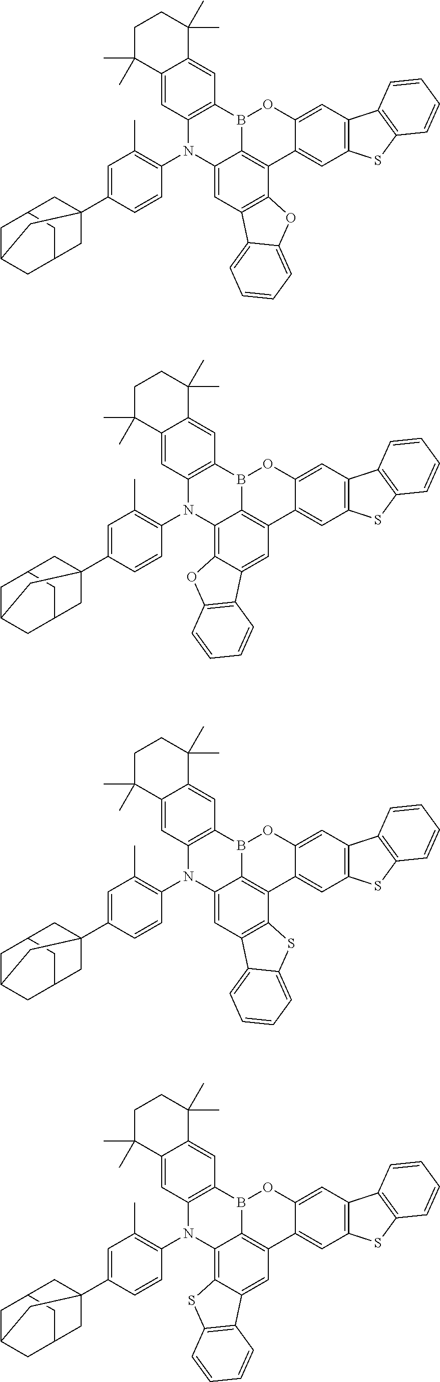 [SMILES: Cc1cc(C23CC4CC(CC(C4)C2)C3)ccc1N1c2cc3c(cc2B2Oc4cc5c(cc4-c4c2c1cc1c4oc2ccccc21)sc1ccccc15)C(C)(C)CCC3(C)C ; Cc1cc(C23CC4CC(CC(C4)C2)C3)ccc1N1c2cc3c(cc2B2Oc4cc5c(cc4-c4cc6c(oc7ccccc76)c1c42)sc1ccccc15)C(C)(C)CCC3(C)C ; Cc1cc(C23CC4CC(CC(C4)C2)C3)ccc1N1c2cc3c(cc2B2Oc4cc5c(cc4-c4c2c1cc1c4sc2ccccc21)sc1ccccc15)C(C)(C)CCC3(C)C ; Cc1cc(C23CC4CC(CC(C4)C2)C3)ccc1N1c2cc3c(cc2B2Oc4cc5c(cc4-c4cc6c(sc7ccccc76)c1c42)sc1ccccc15)C(C)(C)CCC3(C)C]

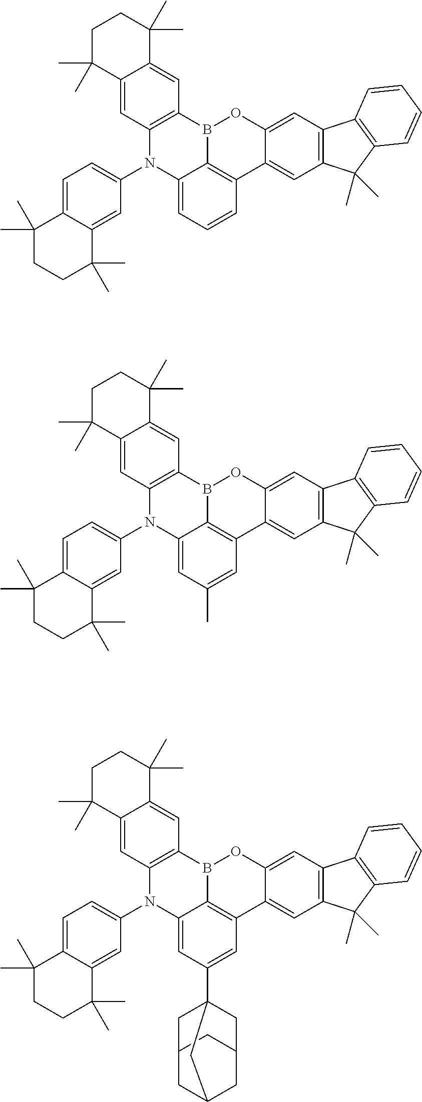 [SMILES: CC1(C)CCC(C)(C)c2cc(N3c4cc5c(cc4B4Oc6cc7c(cc6-c6cccc3c64)C(C)(C)c3ccccc3-7)C(C)(C)CCC5(C)C)ccc21 ; Cc1cc2c3c(c1)N(c1ccc4c(c1)C(C)(C)CCC4(C)C)c1cc4c(cc1B3Oc1cc3c(cc1-2)C(C)(C)c1ccccc1-3)C(C)(C)CCC4(C)C ; CC1(C)CCC(C)(C)c2cc(N3c4cc5c(cc4B4Oc6cc7c(cc6-c6cc(C89CC%10CC(CC(C%10)C8)C9)cc3c64)C(C)(C)c3ccccc3-7)C(C)(C)CCC5(C)C)ccc21]

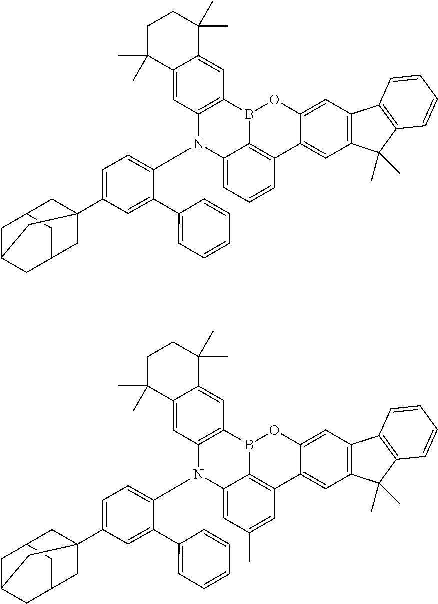 [SMILES: CC1(C)CCC(C)(C)c2cc3c(cc21)B1Oc2cc4c(cc2-c2cccc(c21)N3c1ccc(C23CC5CC(CC(C5)C2)C3)cc1-c1ccccc1)C(C)(C)c1ccccc1-4 ; Cc1cc2c3c(c1)N(c1ccc(C45CC6CC(CC(C6)C4)C5)cc1-c1ccccc1)c1cc4c(cc1B3Oc1cc3c(cc1-2)C(C)(C)c1ccccc1-3)C(C)(C)CCC4(C)C]

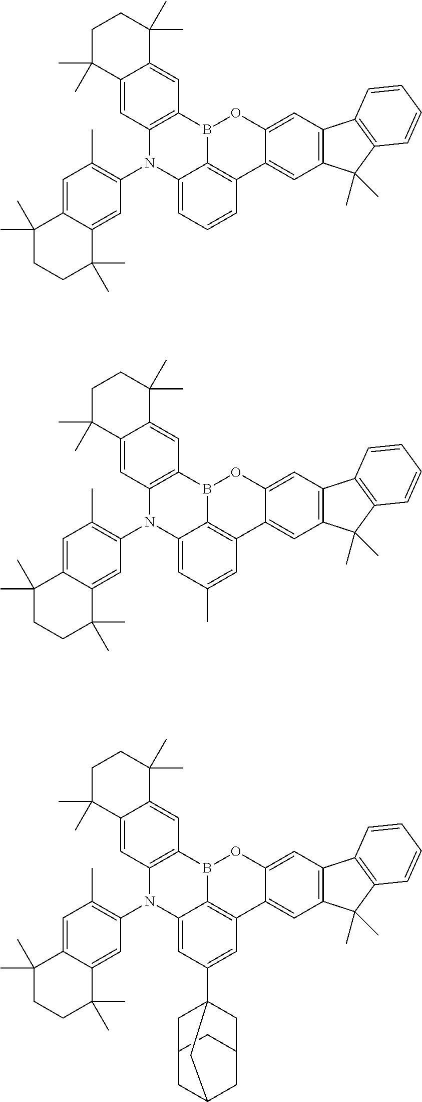 [SMILES: Cc1cc2c(cc1N1c3cc4c(cc3B3Oc5cc6c(cc5-c5cccc1c53)C(C)(C)c1ccccc1-6)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Oc1cc3c(cc1-2)C(C)(C)c1ccccc1-3)C(C)(C)CCC4(C)C ; Cc1cc2c(cc1N1c3cc4c(cc3B3Oc5cc6c(cc5-c5cc(C78CC9CC(CC(C9)C7)C8)cc1c53)C(C)(C)c1ccccc1-6)C(C)(C)CCC4(C)C)C(C)(C)CCC2(C)C]

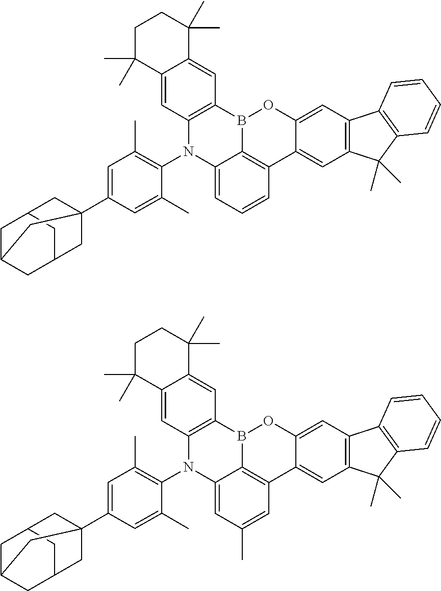 [SMILES: Cc1cc(C23CC4CC(CC(C4)C2)C3)cc(C)c1N1c2cc3c(cc2B2Oc4cc5c(cc4-c4cccc1c42)C(C)(C)c1ccccc1-5)C(C)(C)CCC3(C)C ; Cc1cc2c3c(c1)N(c1c(C)cc(C45CC6CC(CC(C6)C4)C5)cc1C)c1cc4c(cc1B3Oc1cc3c(cc1-2)C(C)(C)c1ccccc1-3)C(C)(C)CCC4(C)C]

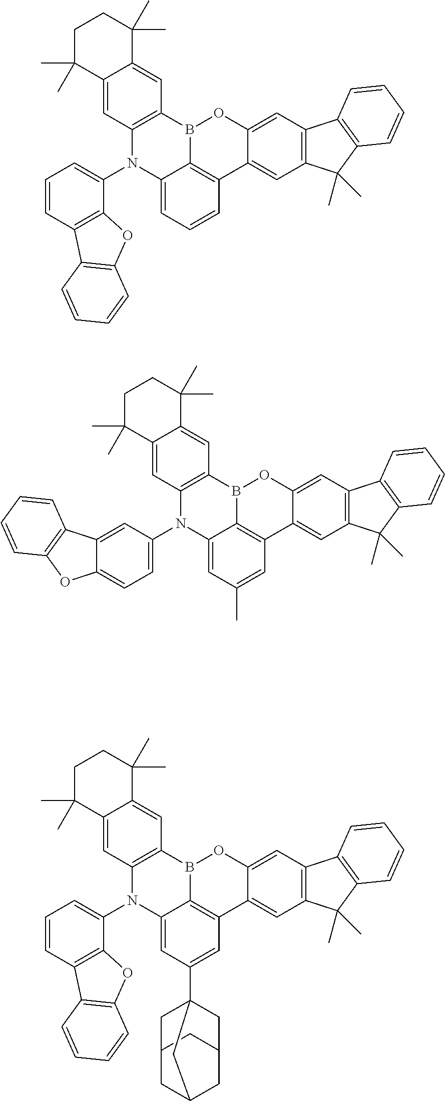 [SMILES: CC1(C)CCC(C)(C)c2cc3c(cc21)B1Oc2cc4c(cc2-c2cccc(c21)N3c1cccc2c1oc1ccccc12)C(C)(C)c1ccccc1-4 ; Cc1cc2c3c(c1)N(c1ccc4oc5ccccc5c4c1)c1cc4c(cc1B3Oc1cc3c(cc1-2)C(C)(C)c1ccccc1-3)C(C)(C)CCC4(C)C ; CC1(C)CCC(C)(C)c2cc3c(cc21)B1Oc2cc4c(cc2-c2cc(C56CC7CC(CC(C7)C5)C6)cc(c21)N3c1cccc2c1oc1ccccc12)C(C)(C)c1ccccc1-4]

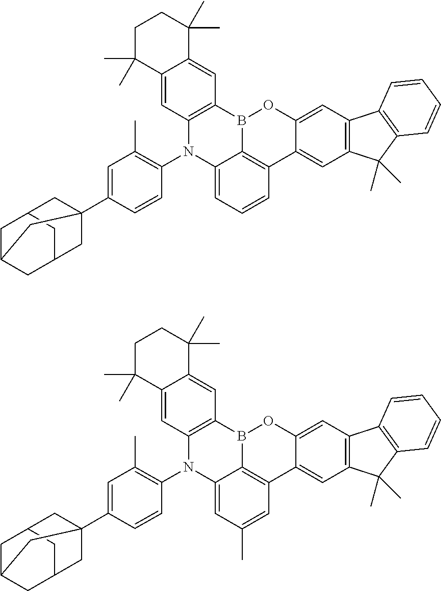 [SMILES: Cc1cc(C23CC4CC(CC(C4)C2)C3)ccc1N1c2cc3c(cc2B2Oc4cc5c(cc4-c4cccc1c42)C(C)(C)c1ccccc1-5)C(C)(C)CCC3(C)C ; Cc1cc2c3c(c1)N(c1ccc(C45CC6CC(CC(C6)C4)C5)cc1C)c1cc4c(cc1B3Oc1cc3c(cc1-2)C(C)(C)c1ccccc1-3)C(C)(C)CCC4(C)C]

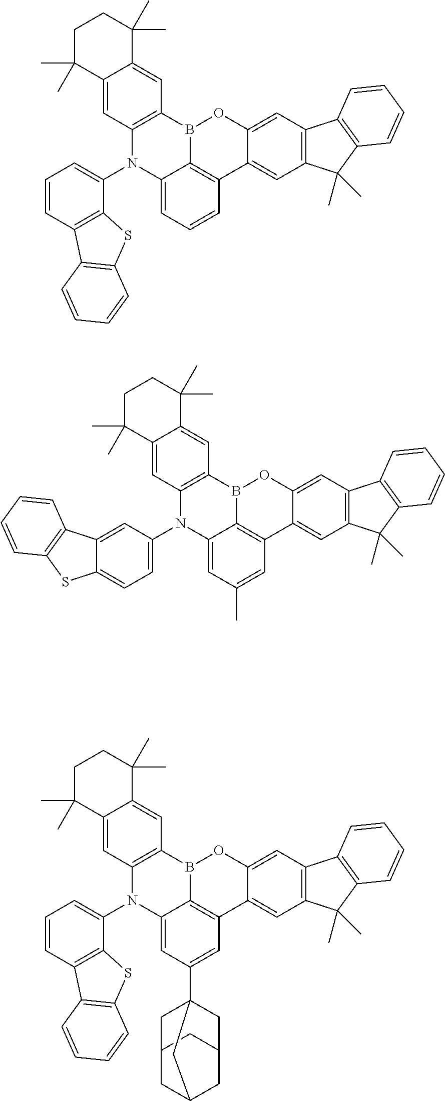 [SMILES: CC1(C)CCC(C)(C)c2cc3c(cc21)B1Oc2cc4c(cc2-c2cccc(c21)N3c1cccc2c1sc1ccccc12)C(C)(C)c1ccccc1-4 ; Cc1cc2c3c(c1)N(c1ccc4sc5ccccc5c4c1)c1cc4c(cc1B3Oc1cc3c(cc1-2)C(C)(C)c1ccccc1-3)C(C)(C)CCC4(C)C ; CC1(C)CCC(C)(C)c2cc3c(cc21)B1Oc2cc4c(cc2-c2cc(C56CC7CC(CC(C7)C5)C6)cc(c21)N3c1cccc2c1sc1ccccc12)C(C)(C)c1ccccc1-4]

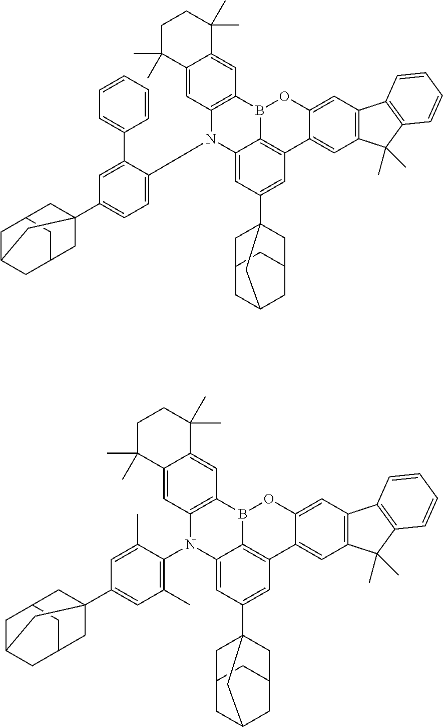 [SMILES: CC1(C)CCC(C)(C)c2cc3c(cc21)B1Oc2cc4c(cc2-c2cc(C56CC7CC(CC(C7)C5)C6)cc(c21)N3c1ccc(C23CC5CC(CC(C5)C2)C3)cc1-c1ccccc1)C(C)(C)c1ccccc1-4 ; Cc1cc(C23CC4CC(CC(C4)C2)C3)cc(C)c1N1c2cc3c(cc2B2Oc4cc5c(cc4-c4cc(C67CC8CC(CC(C8)C6)C7)cc1c42)C(C)(C)c1ccccc1-5)C(C)(C)CCC3(C)C]

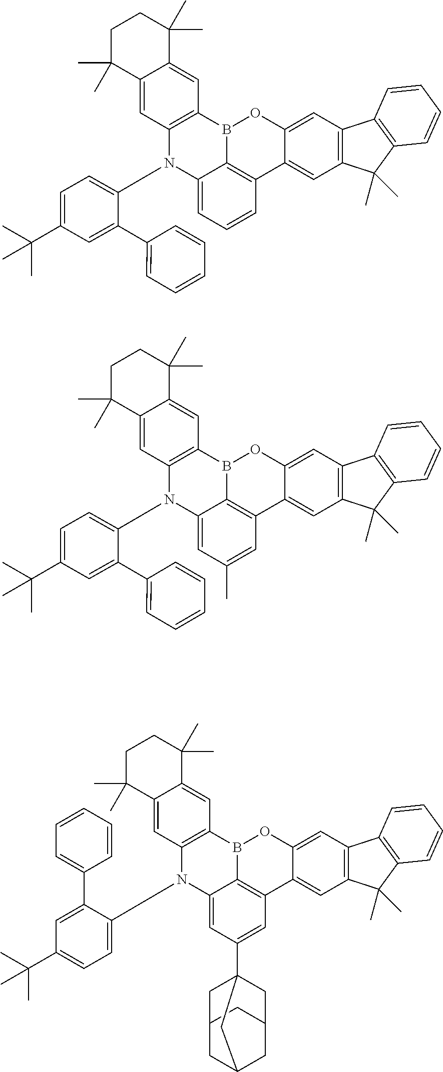

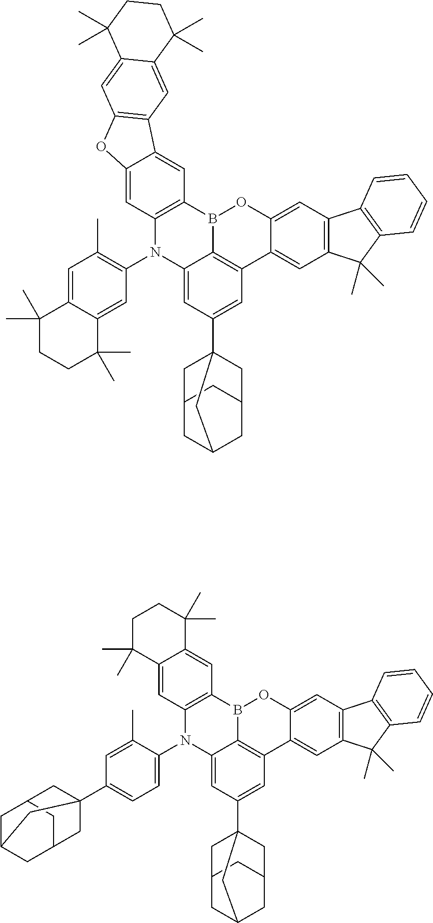 [SMILES: Cc1cc2c(cc1N1c3cc4oc5cc6c(cc5c4cc3B3Oc4cc5c(cc4-c4cc(C78CC9CC(CC(C9)C7)C8)cc1c43)C(C)(C)c1ccccc1-5)C(C)(C)CCC6(C)C)C(C)(C)CCC2(C)C ; Cc1cc(C23CC4CC(CC(C4)C2)C3)ccc1N1c2cc3c(cc2B2Oc4cc5c(cc4-c4cc(C67CC8CC(CC(C8)C6)C7)cc1c42)C(C)(C)c1ccccc1-5)C(C)(C)CCC3(C)C]

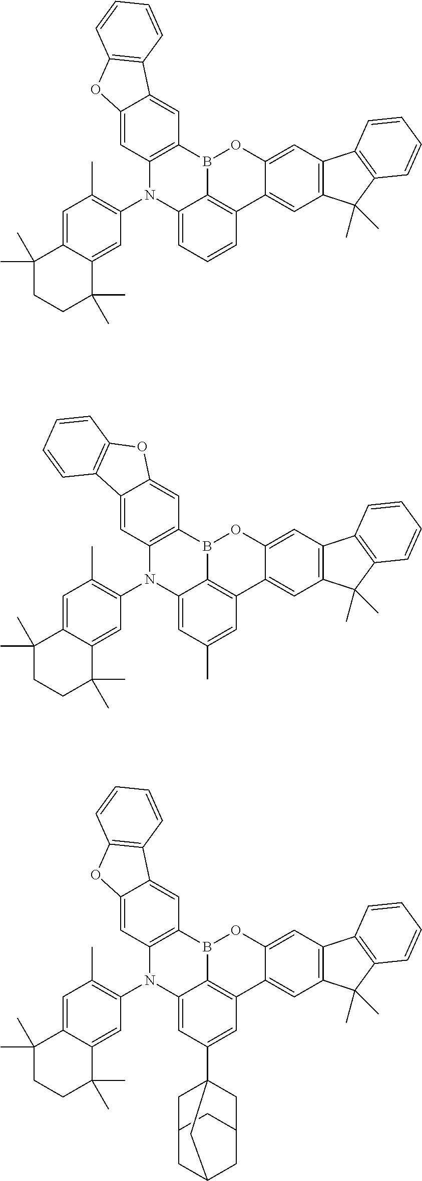 [SMILES: Cc1cc2c(cc1N1c3cc4oc5ccccc5c4cc3B3Oc4cc5c(cc4-c4cccc1c43)C(C)(C)c1ccccc1-5)C(C)(C)CCC2(C)C ; Cc1cc2c3c(c1)N(c1cc4c(cc1C)C(C)(C)CCC4(C)C)c1cc4c(cc1B3Oc1cc3c(cc1-2)C(C)(C)c1ccccc1-3)oc1ccccc14 ; Cc1cc2c(cc1N1c3cc4oc5ccccc5c4cc3B3Oc4cc5c(cc4-c4cc(C67CC8CC(CC(C8)C6)C7)cc1c43)C(C)(C)c1ccccc1-5)C(C)(C)CCC2(C)C]

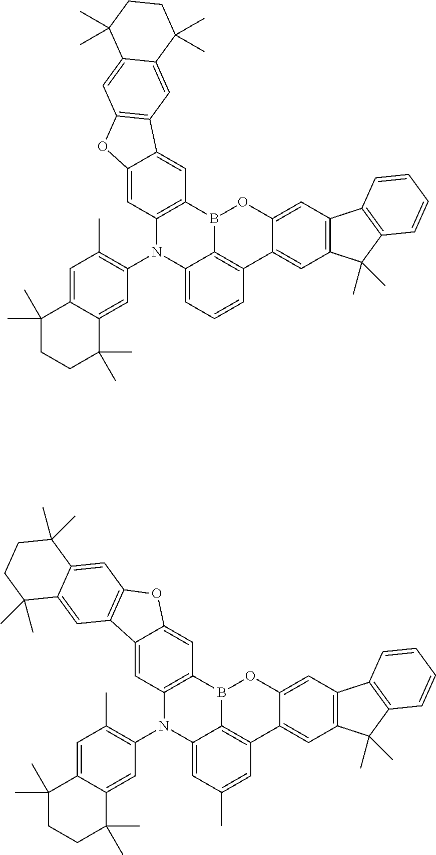 [SMILES: Cc1cc2c(cc1N1c3cc4oc5cc6c(cc5c4cc3B3Oc4cc5c(cc4-c4cccc1c43)C(C)(C)c1ccccc1-5)C(C)(C)CCC6(C)C)C(C)(C)CCC2(C)C ; Cc1cc2c3c(c1)N(c1cc4c(cc1C)C(C)(C)CCC4(C)C)c1cc4c(cc1B3Oc1cc3c(cc1-2)C(C)(C)c1ccccc1-3)oc1cc2c(cc14)C(C)(C)CCC2(C)C]

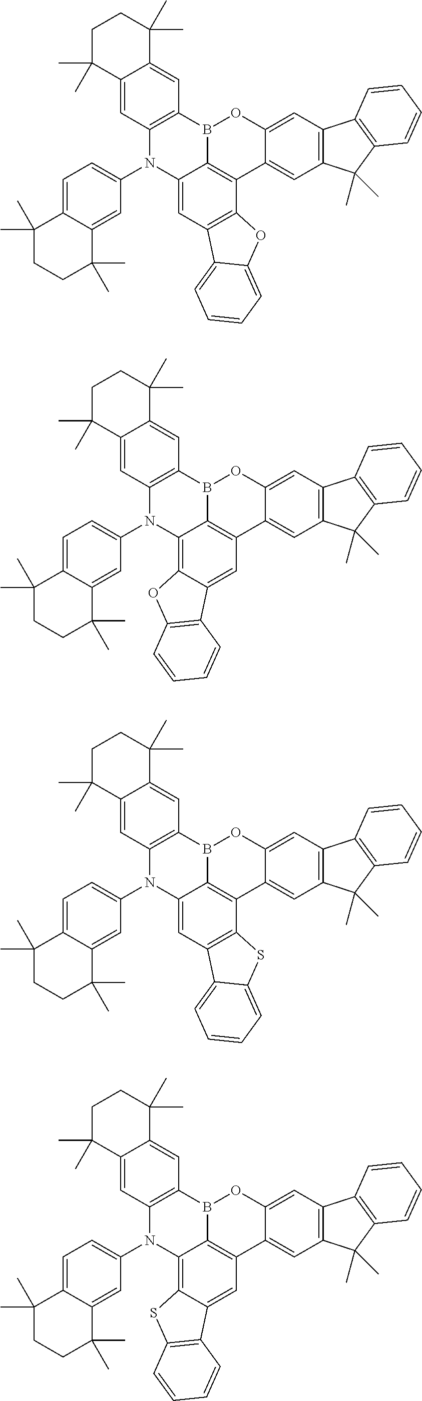

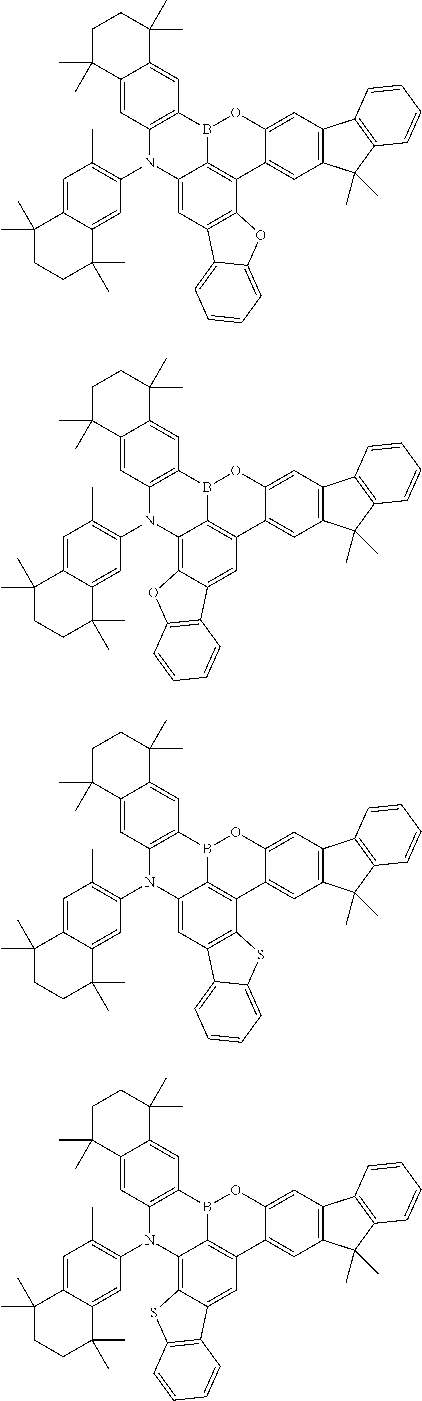

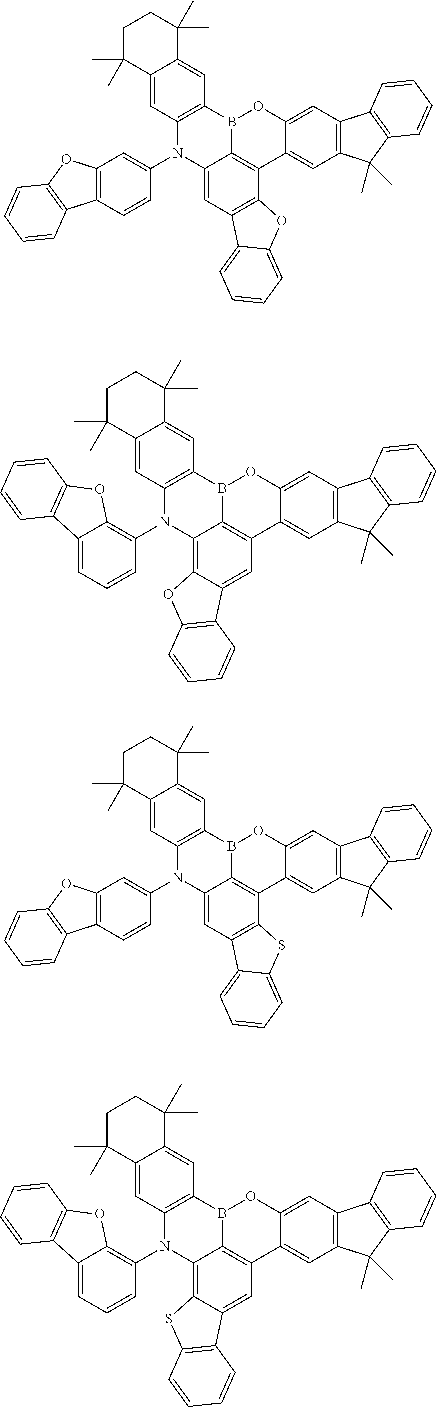

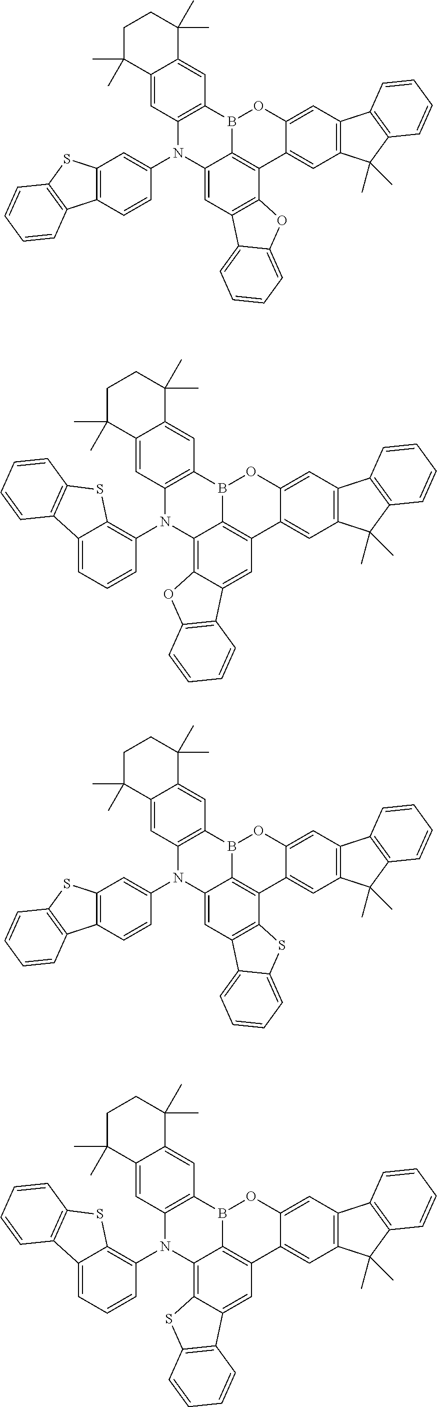

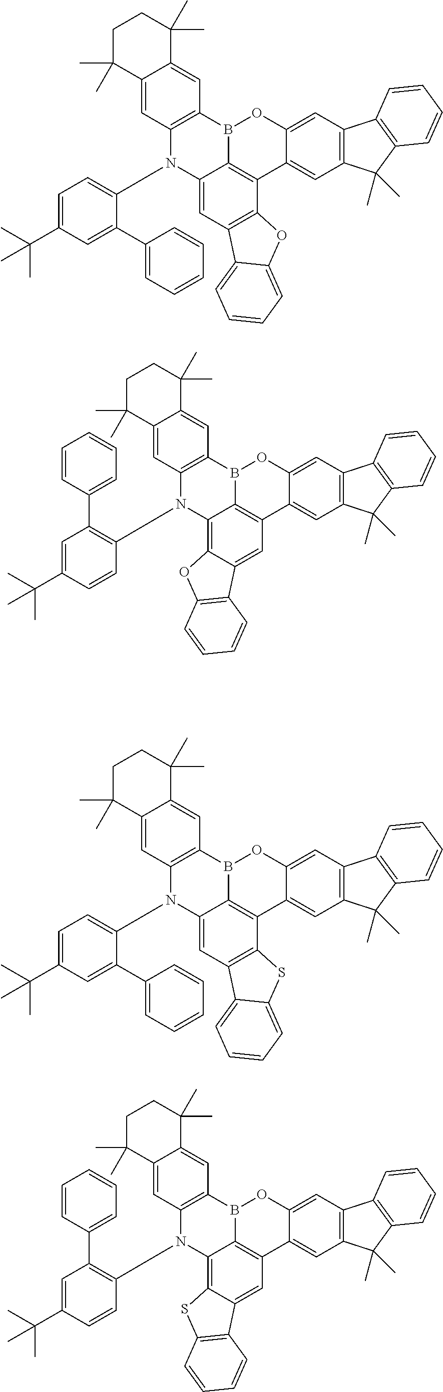

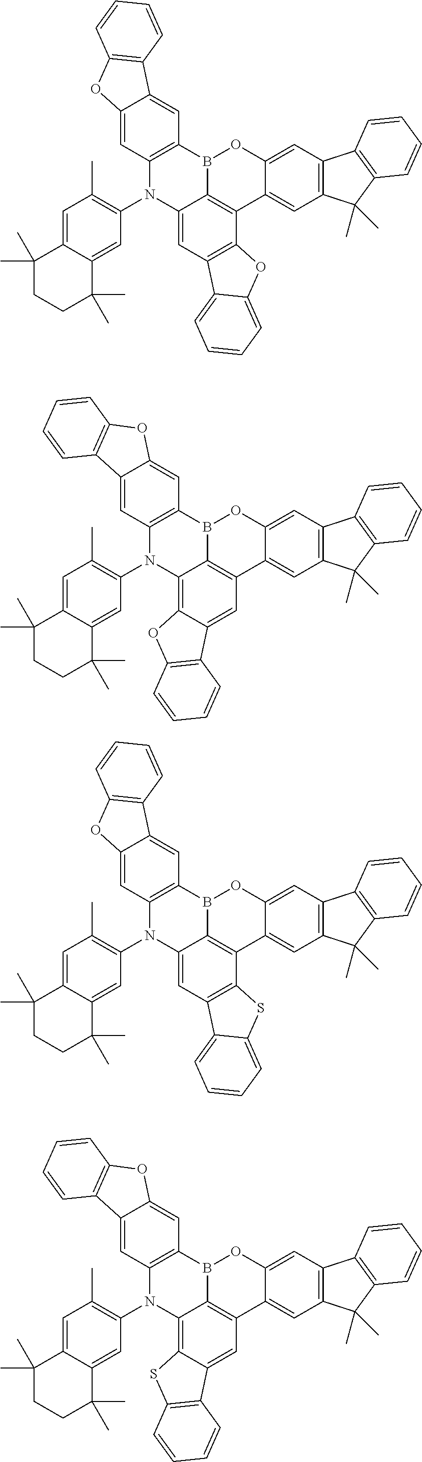

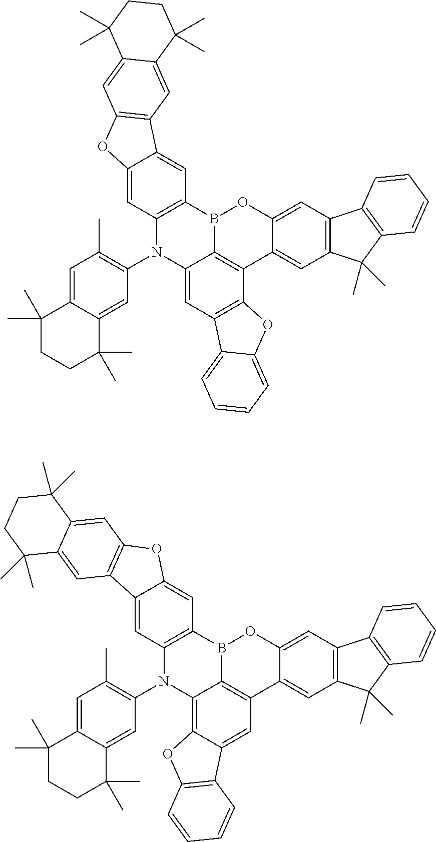 [SMILES: Cc1cc2c(cc1N1c3cc4oc5cc6c(cc5c4cc3B3Oc4cc5c(cc4-c4c3c1cc1c4oc3ccccc31)C(C)(C)c1ccccc1-5)C(C)(C)CCC6(C)C)C(C)(C)CCC2(C)C ; Cc1cc2c(cc1N1c3cc4c(cc3B3Oc5cc6c(cc5-c5cc7c(oc8ccccc87)c1c53)C(C)(C)c1ccccc1-6)oc1cc3c(cc14)C(C)(C)CCC3(C)C)C(C)(C)CCC2(C)C]

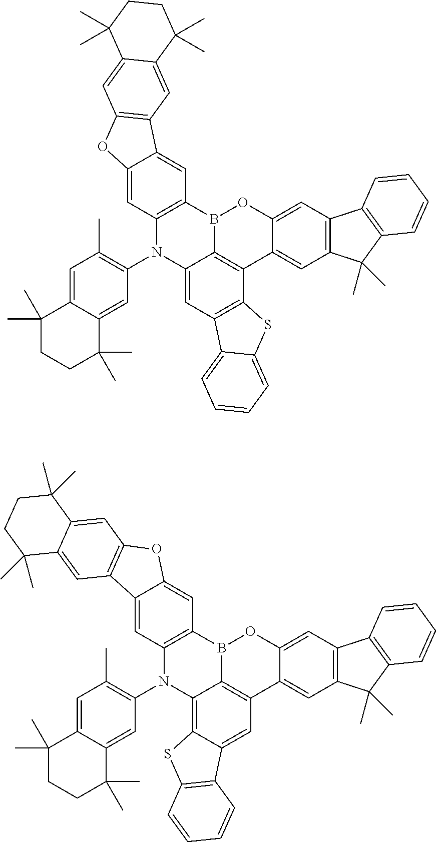 [SMILES: Cc1cc2c(cc1N1c3cc4oc5cc6c(cc5c4cc3B3Oc4cc5c(cc4-c4c3c1cc1c4sc3ccccc31)C(C)(C)c1ccccc1-5)C(C)(C)CCC6(C)C)C(C)(C)CCC2(C)C ; Cc1cc2c(cc1N1c3cc4c(cc3B3Oc5cc6c(cc5-c5cc7c(sc8ccccc87)c1c53)C(C)(C)c1ccccc1-6)oc1cc3c(cc14)C(C)(C)CCC3(C)C)C(C)(C)CCC2(C)C]

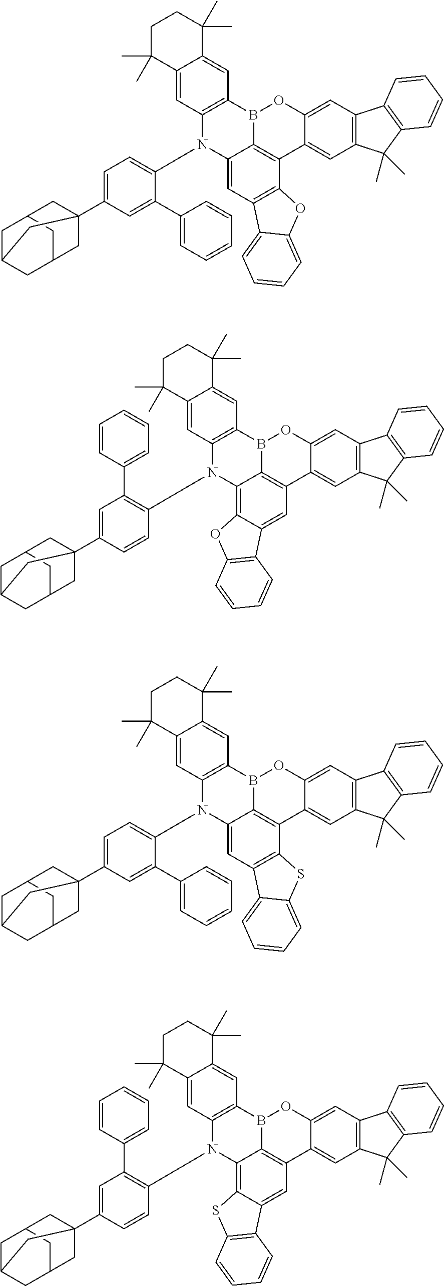

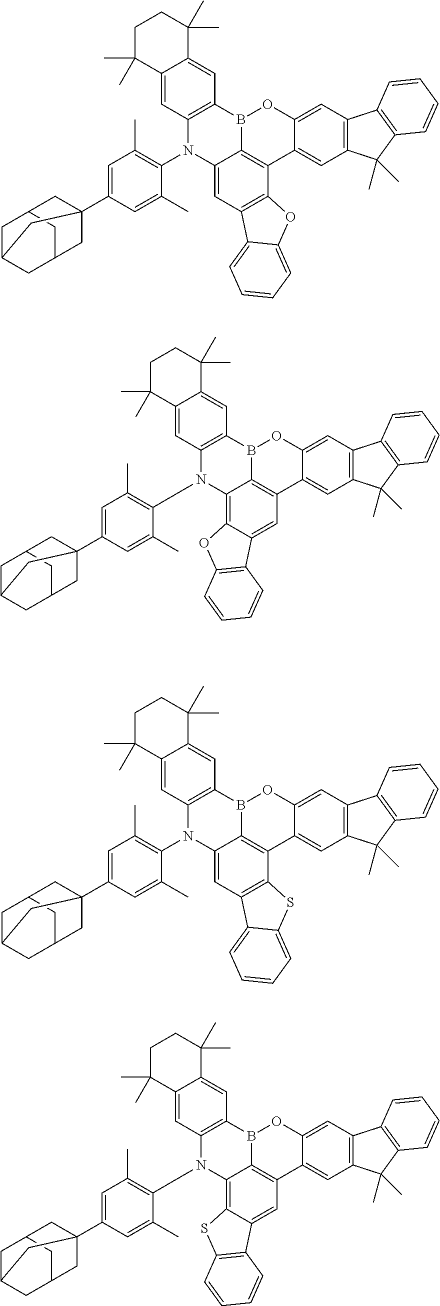 [SMILES: Cc1cc(C23CC4CC(CC(C4)C2)C3)cc(C)c1N1c2cc3c(cc2B2Oc4cc5c(cc4-c4c2c1cc1c4oc2ccccc21)C(C)(C)c1ccccc1-5)C(C)(C)CCC3(C)C ; Cc1cc(C23CC4CC(CC(C4)C2)C3)cc(C)c1N1c2cc3c(cc2B2Oc4cc5c(cc4-c4cc6c(oc7ccccc76)c1c42)C(C)(C)c1ccccc1-5)C(C)(C)CCC3(C)C ; Cc1cc(C23CC4CC(CC(C4)C2)C3)cc(C)c1N1c2cc3c(cc2B2Oc4cc5c(cc4-c4c2c1cc1c4sc2ccccc21)C(C)(C)c1ccccc1-5)C(C)(C)CCC3(C)C ; Cc1cc(C23CC4CC(CC(C4)C2)C3)cc(C)c1N1c2cc3c(cc2B2Oc4cc5c(cc4-c4cc6c(sc7ccccc76)c1c42)C(C)(C)c1ccccc1-5)C(C)(C)CCC3(C)C]

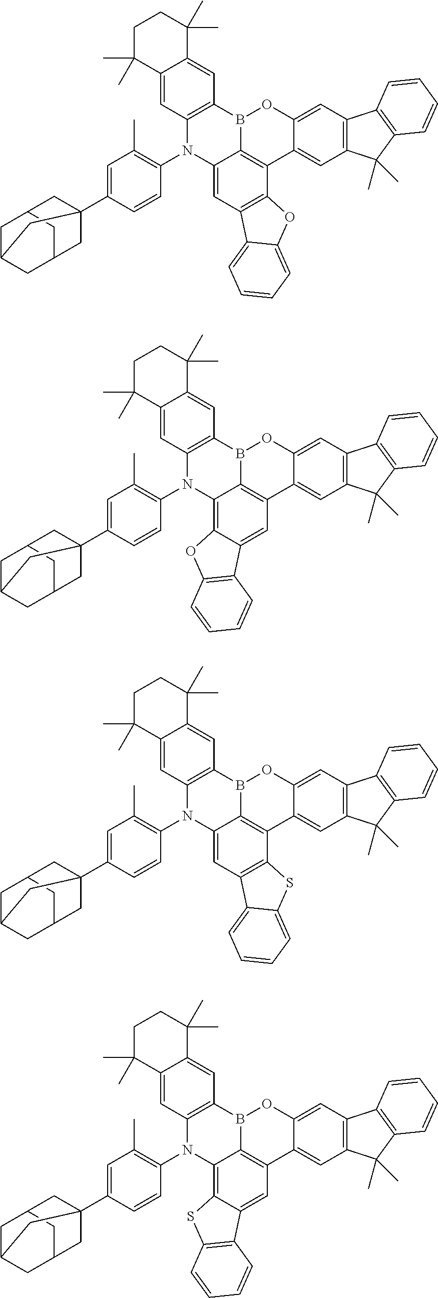

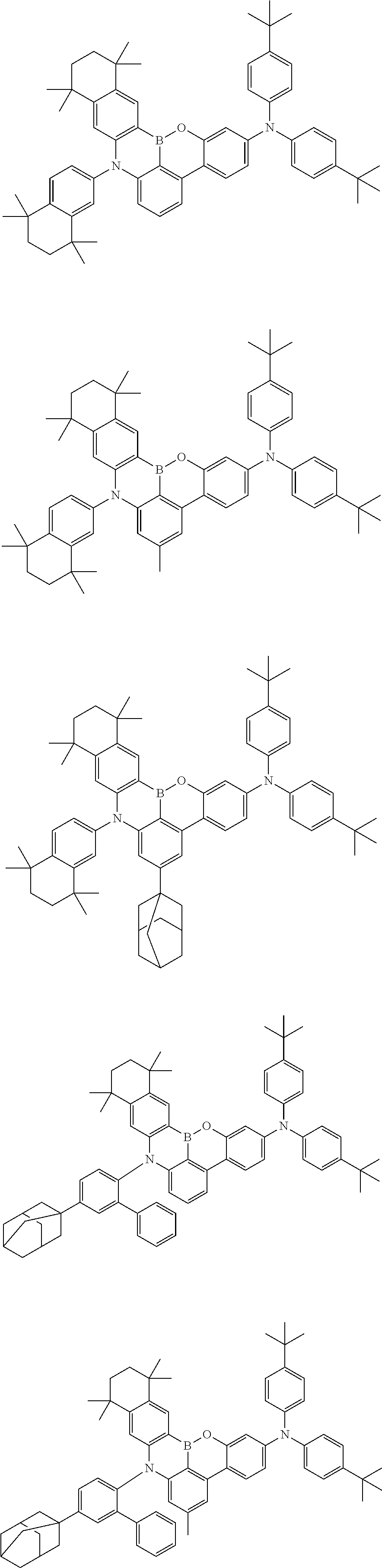

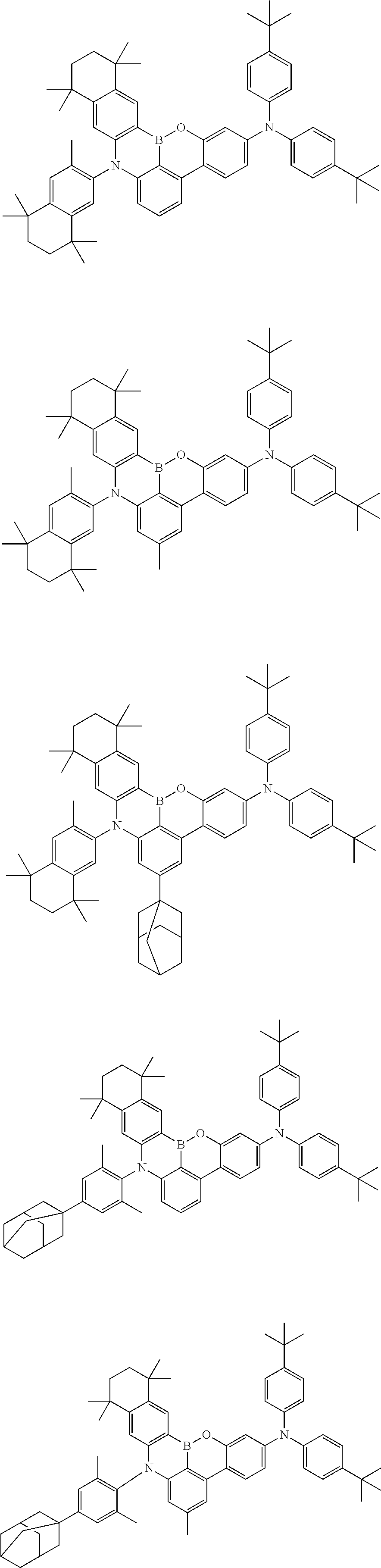

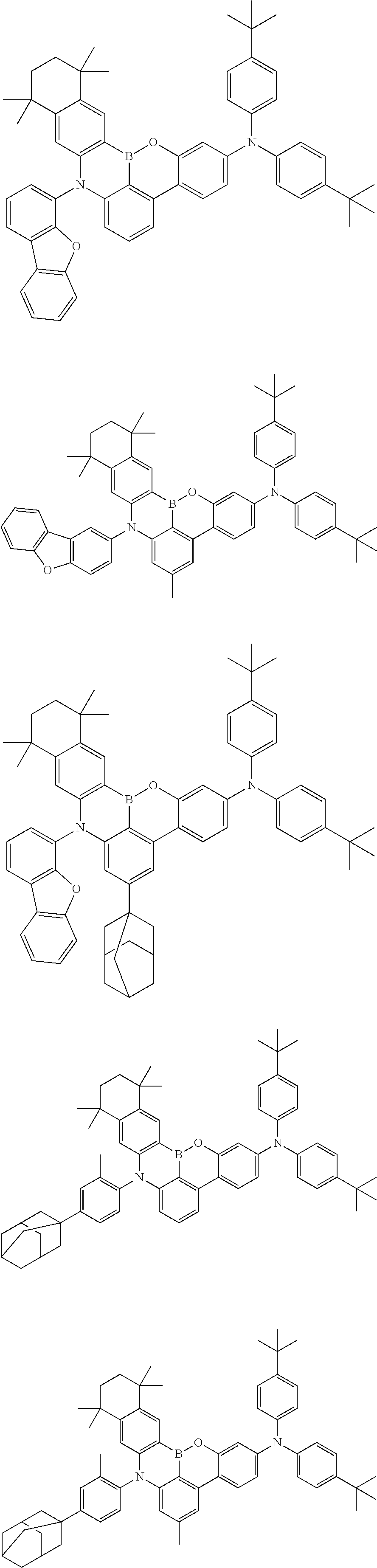

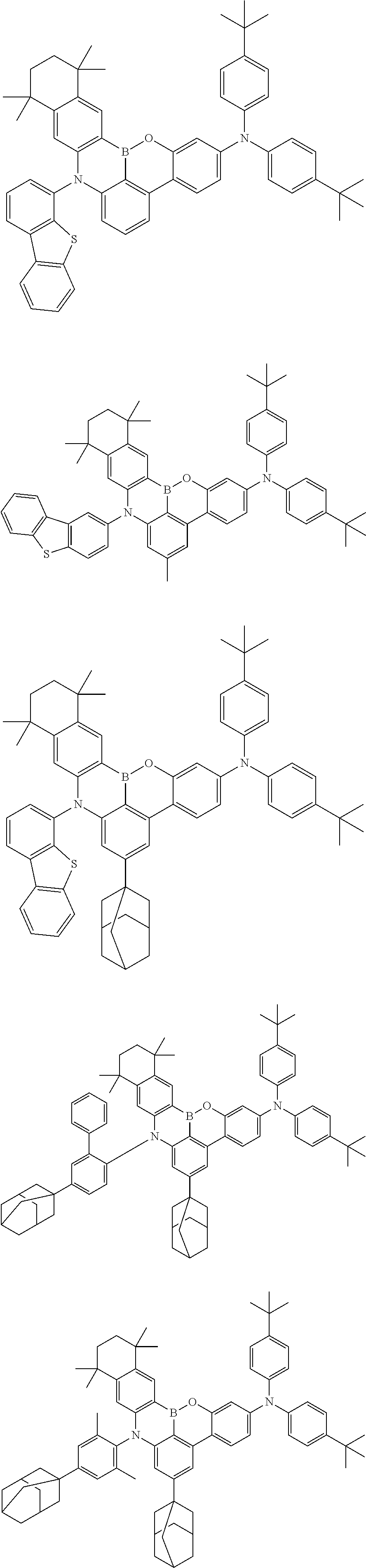

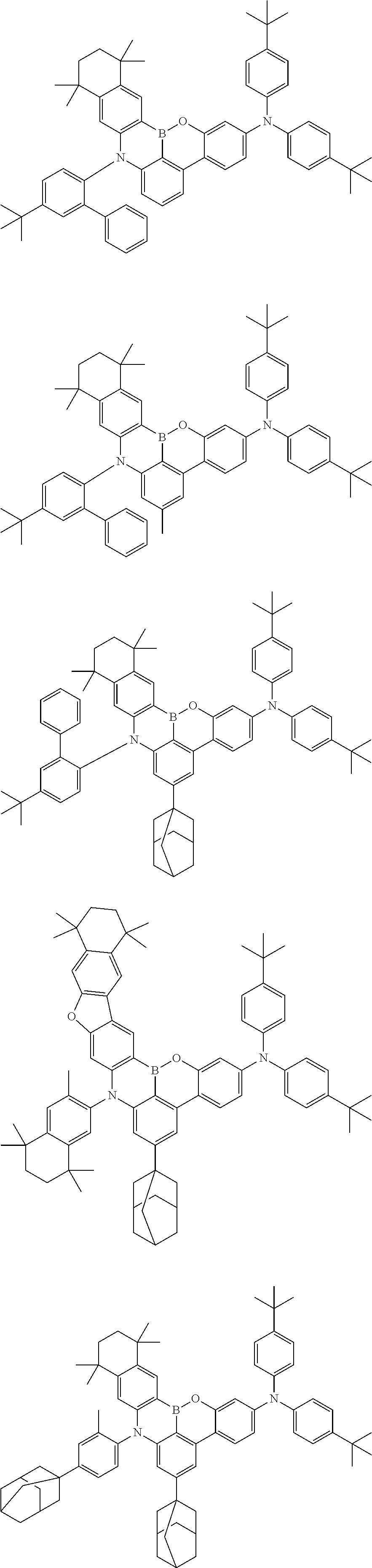

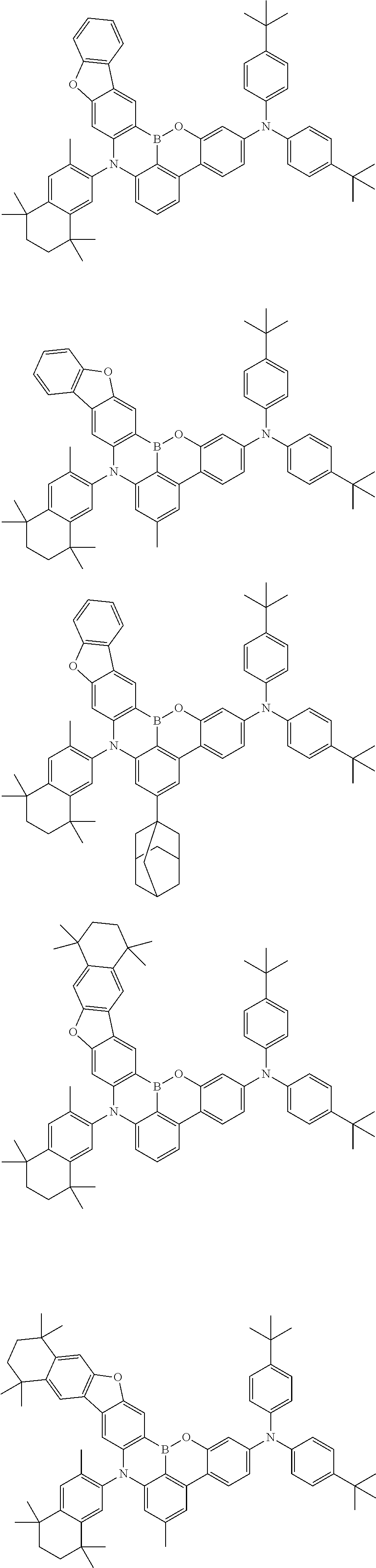

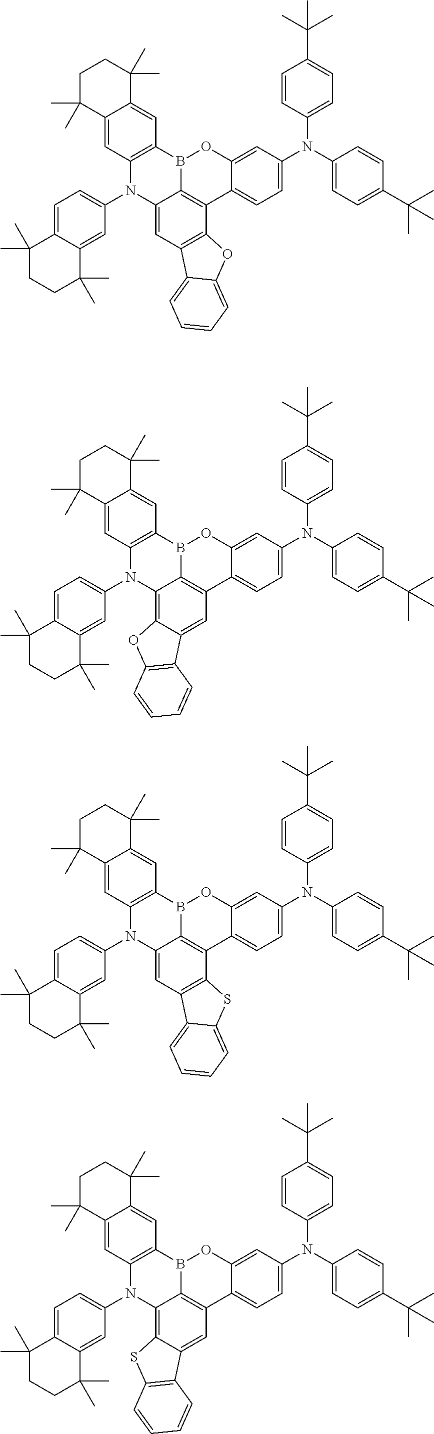

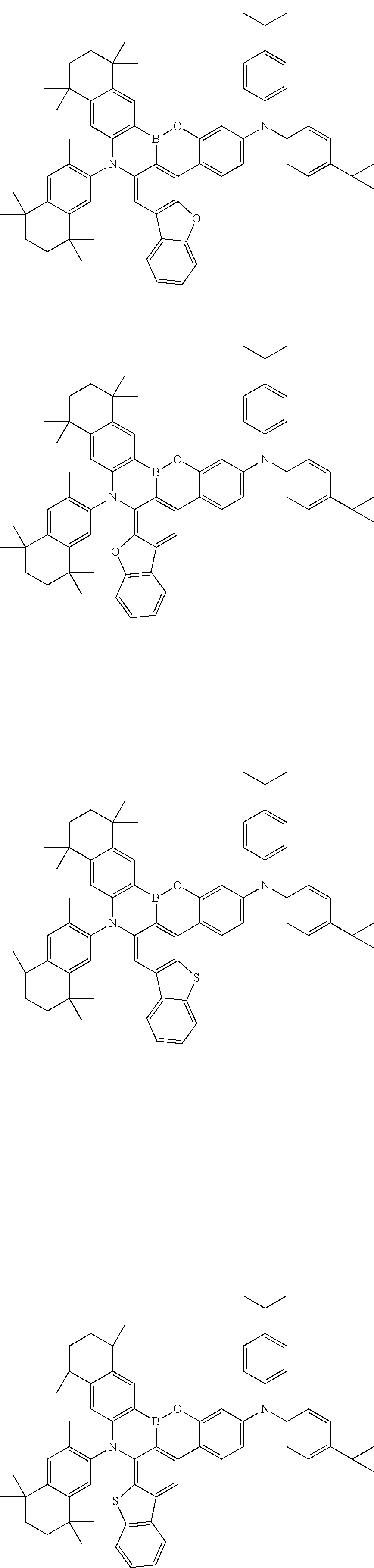

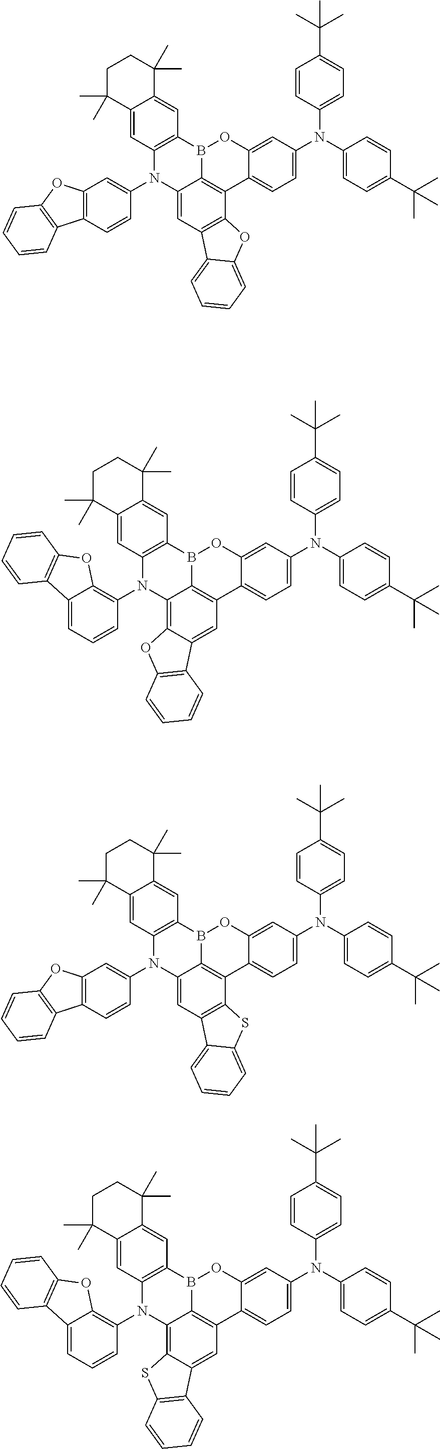

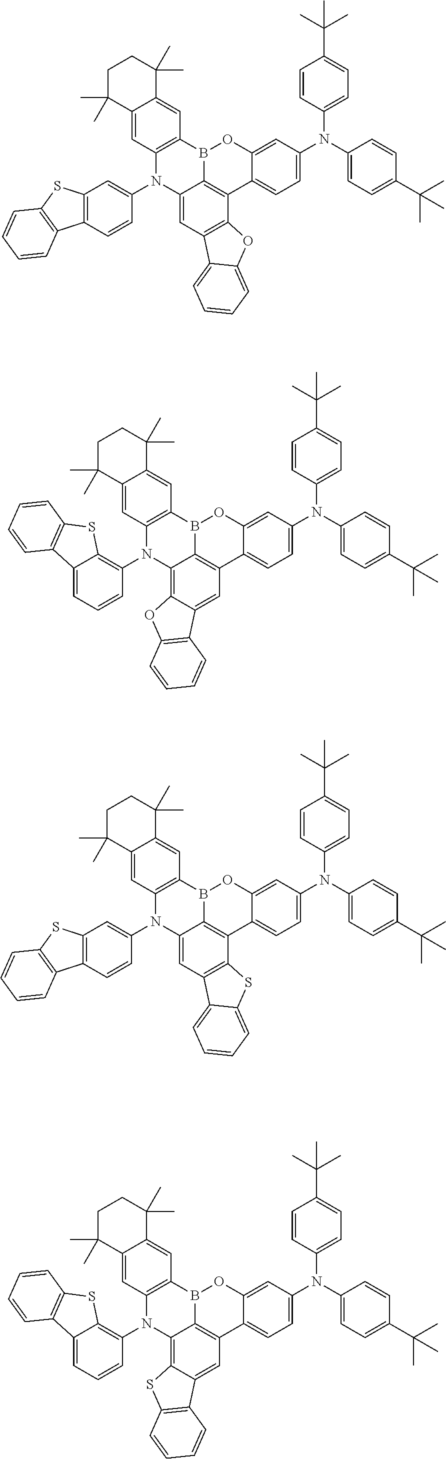

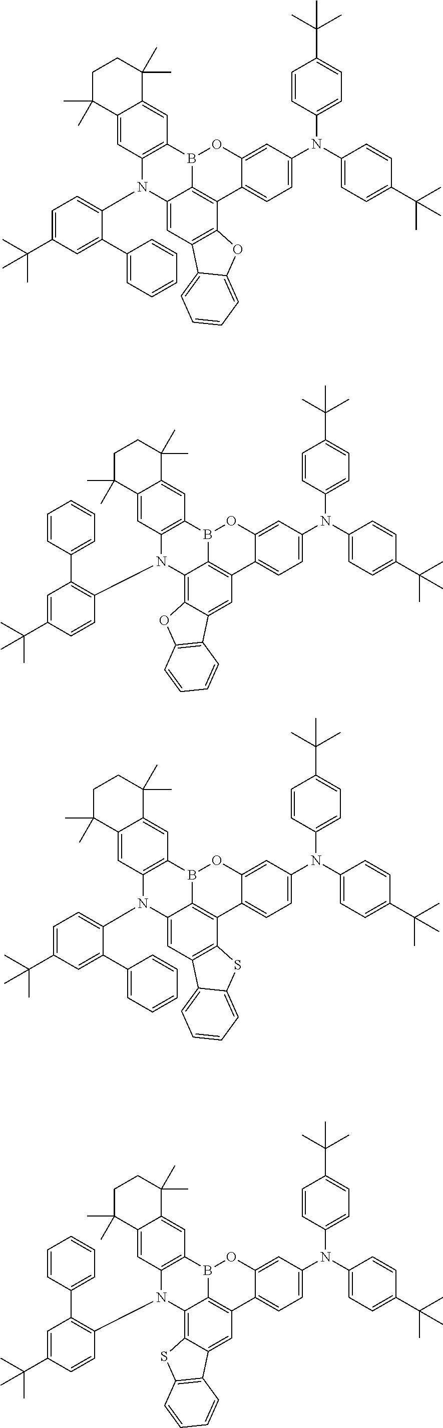

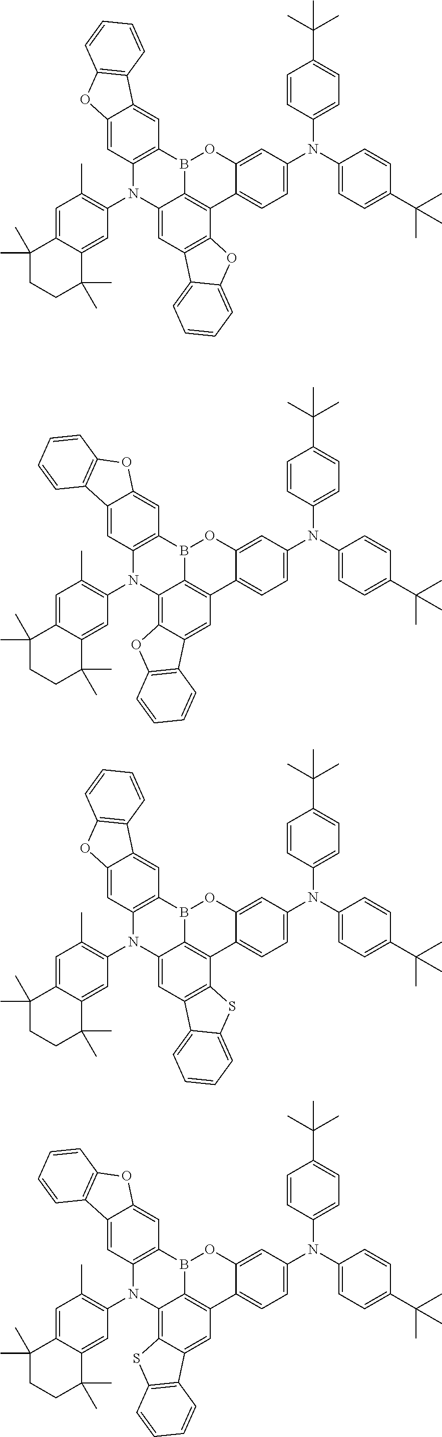

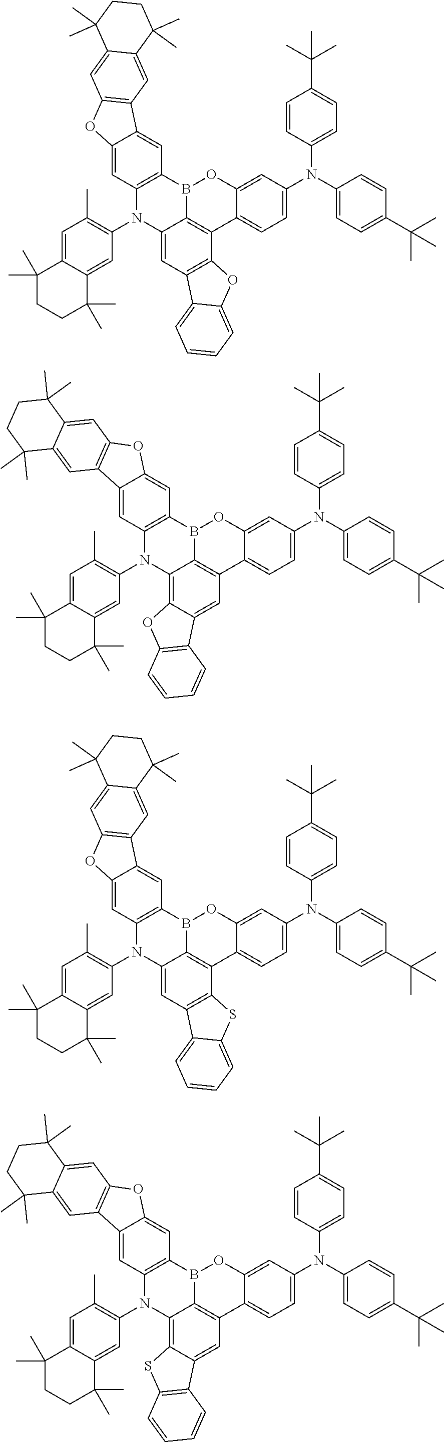

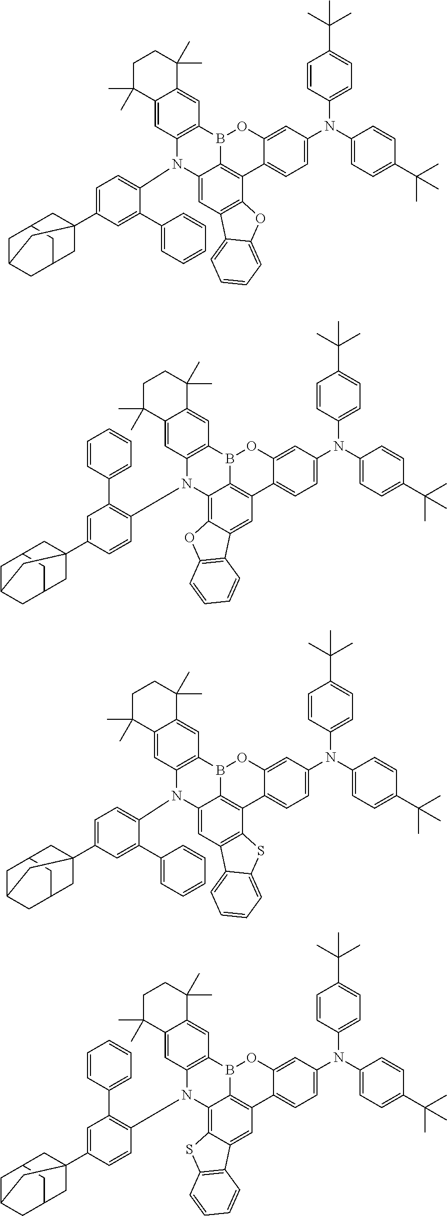

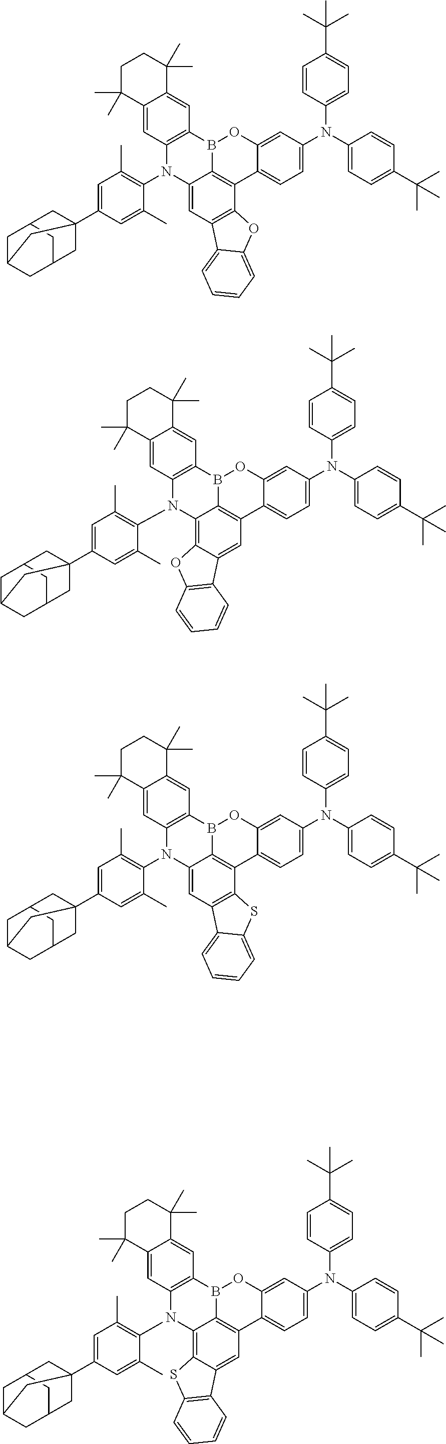

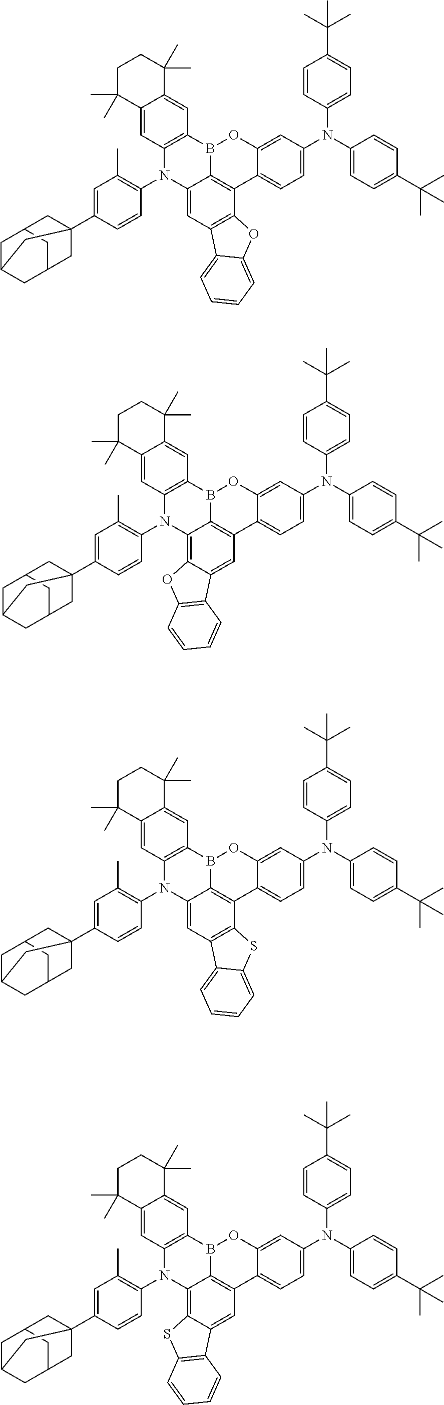

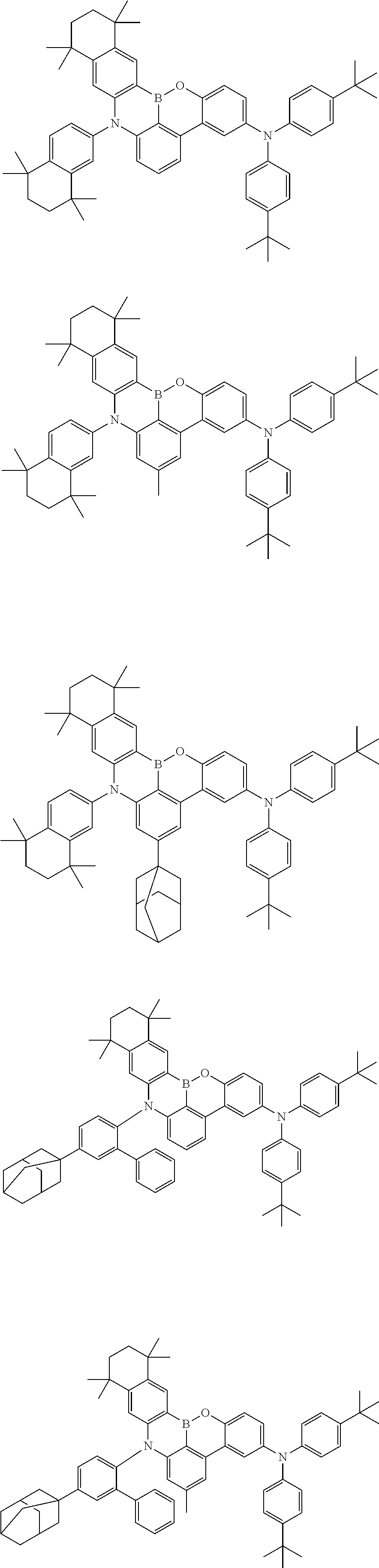

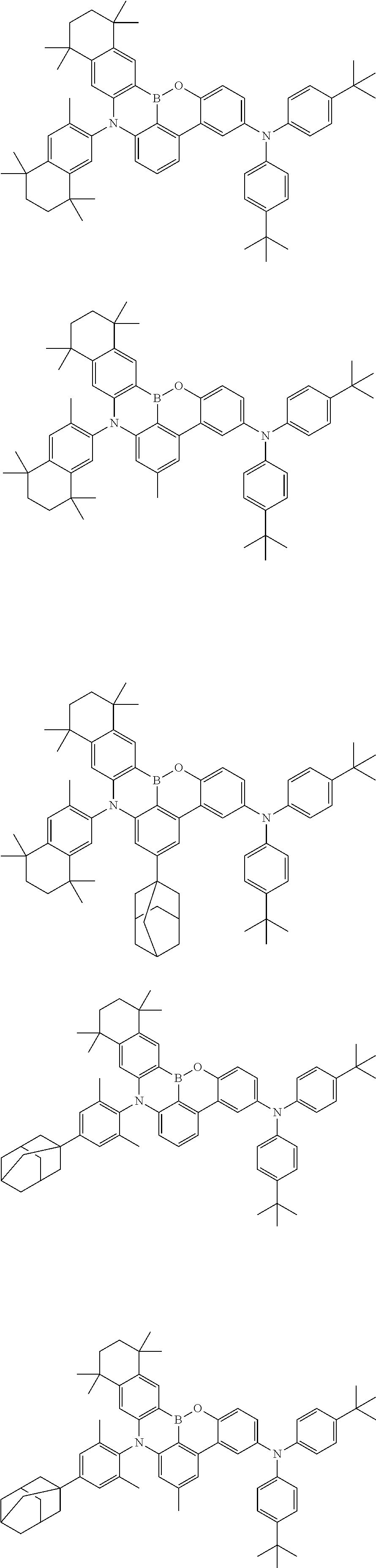

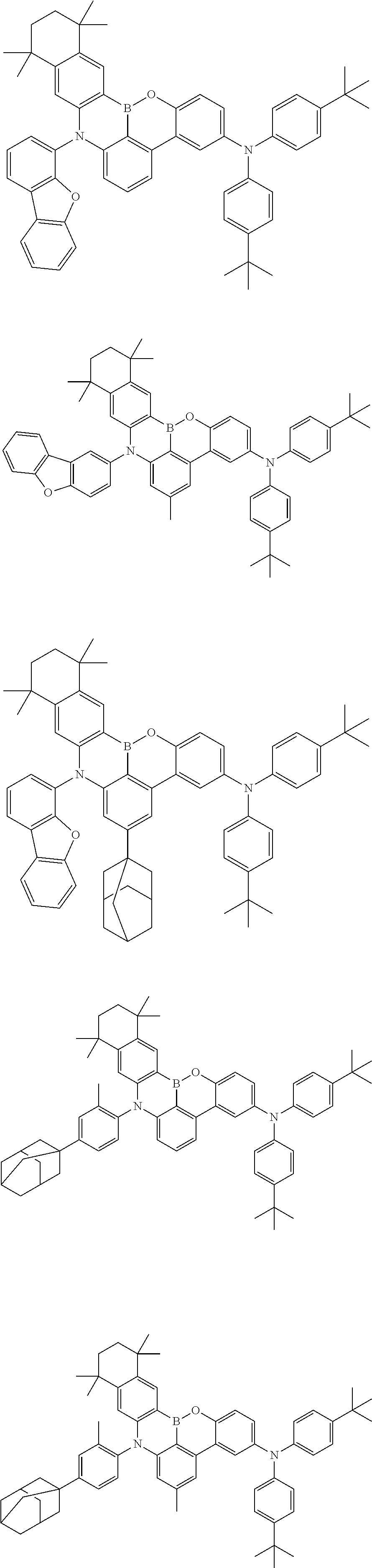

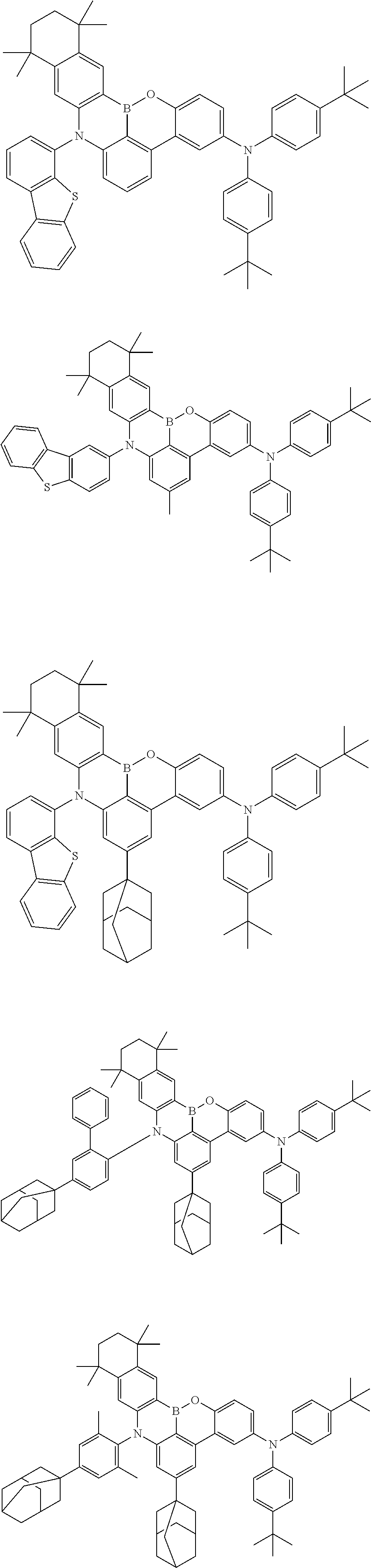

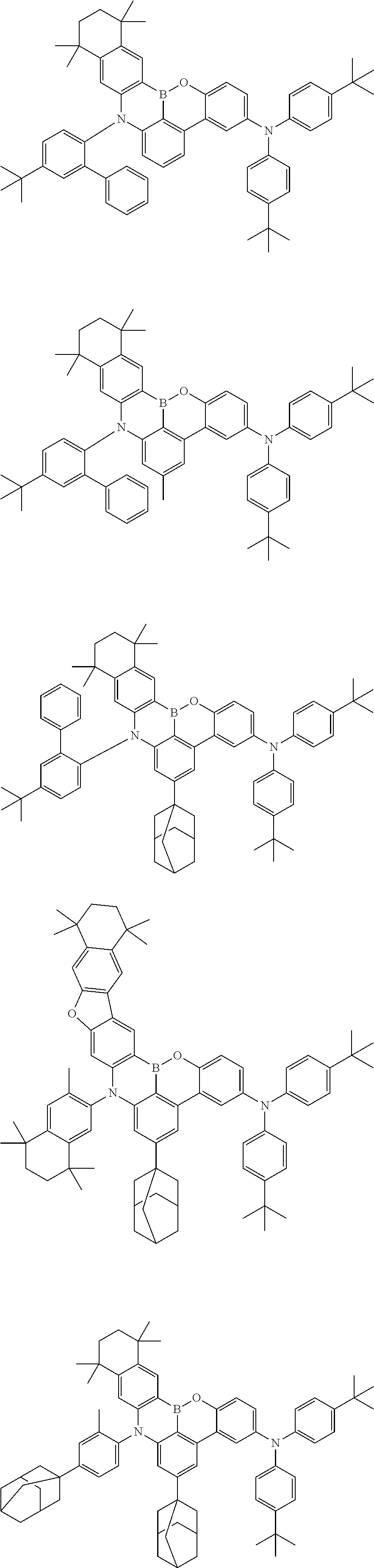

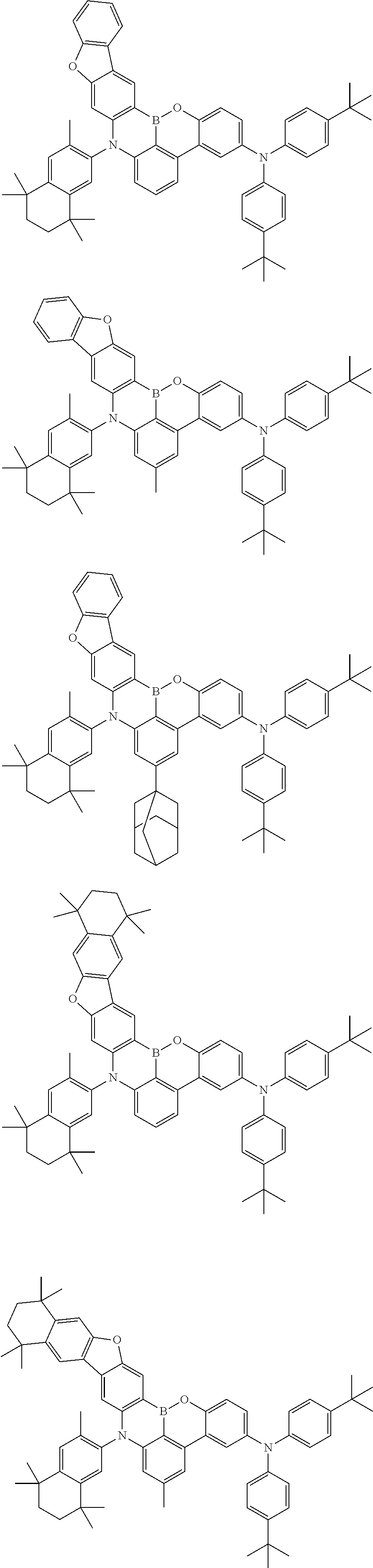

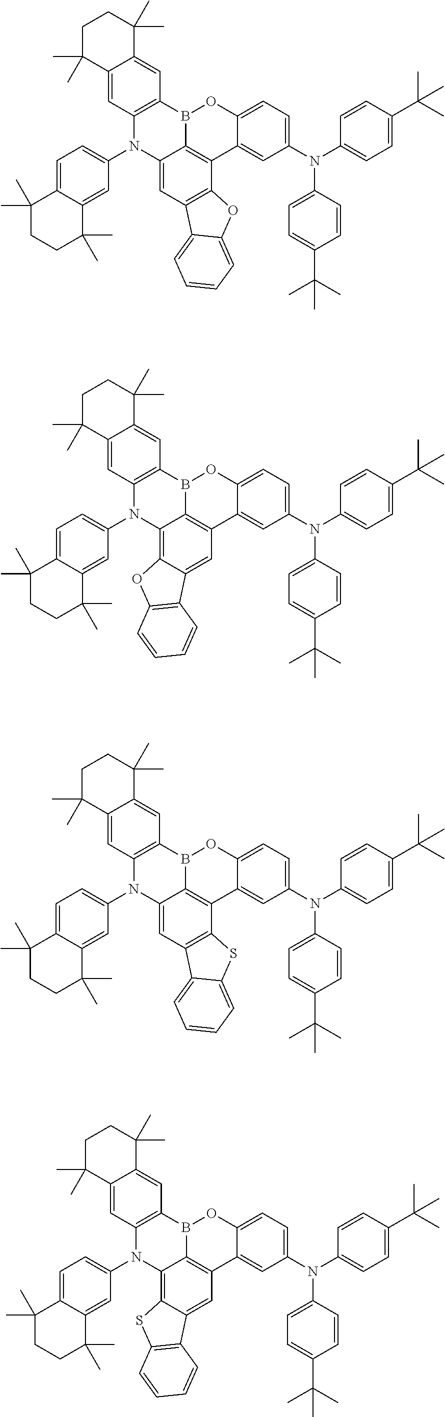

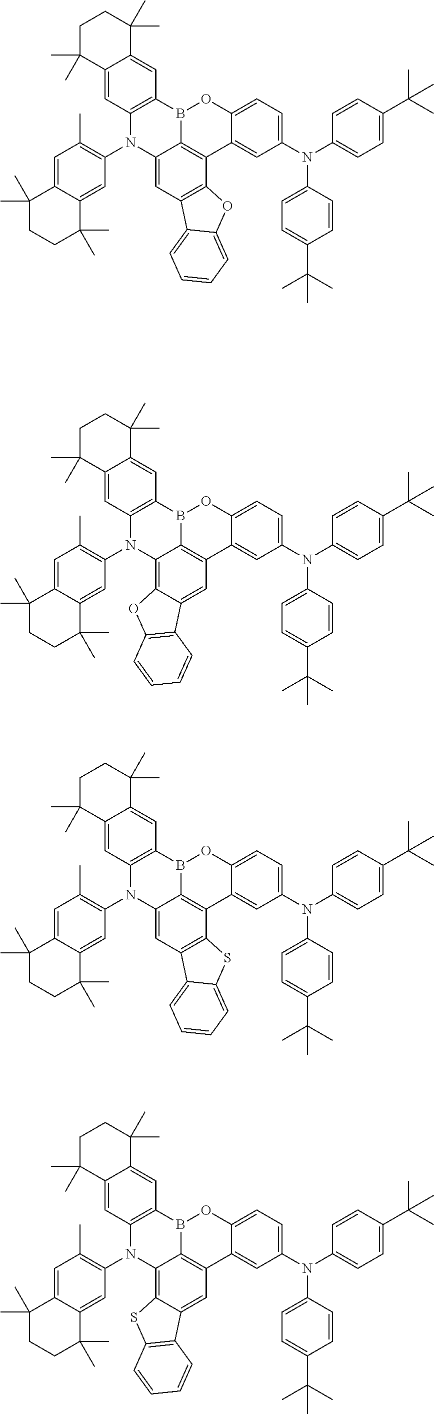

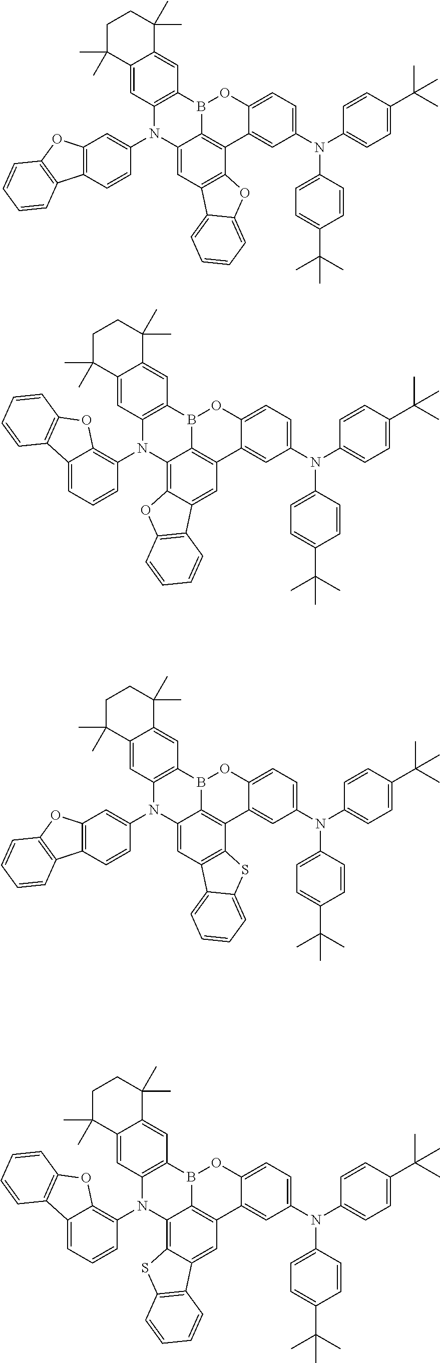

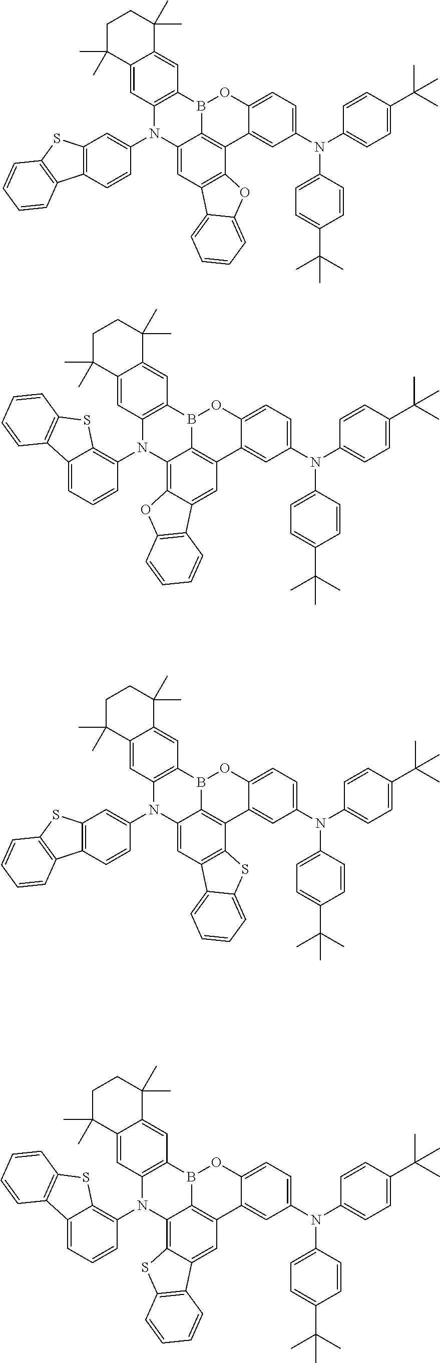

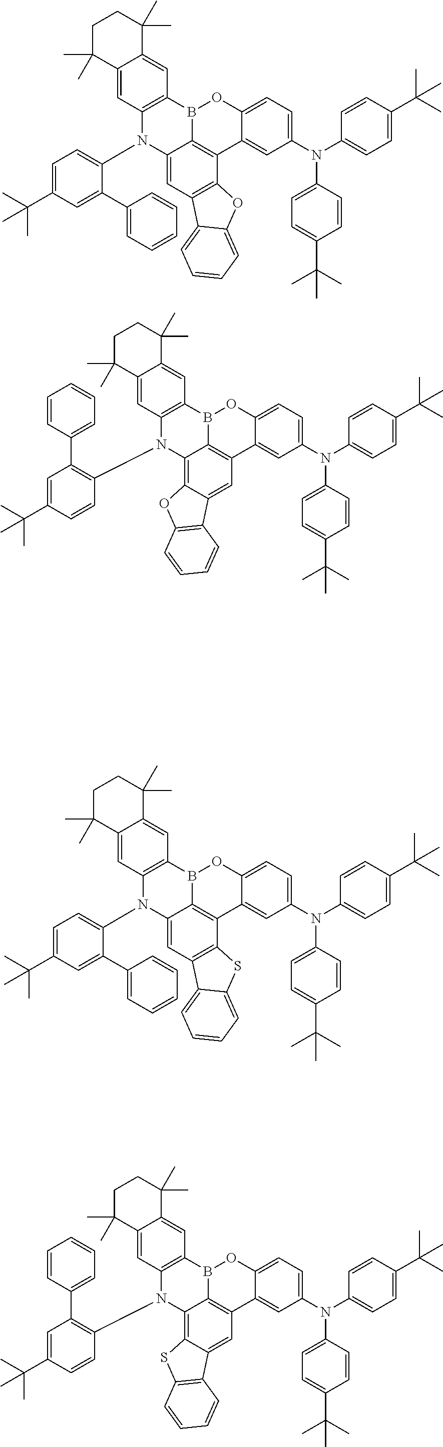

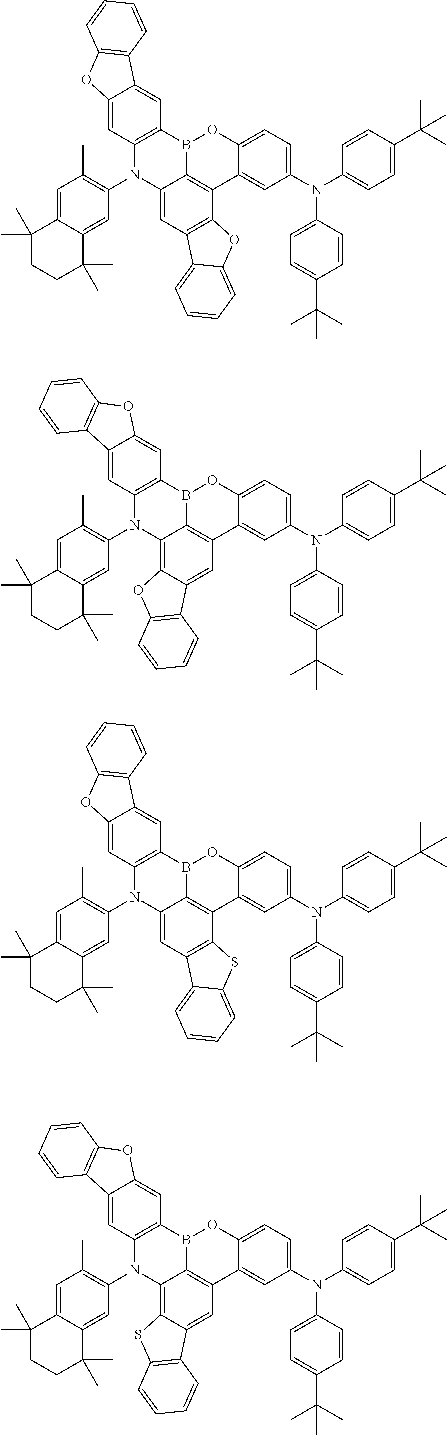

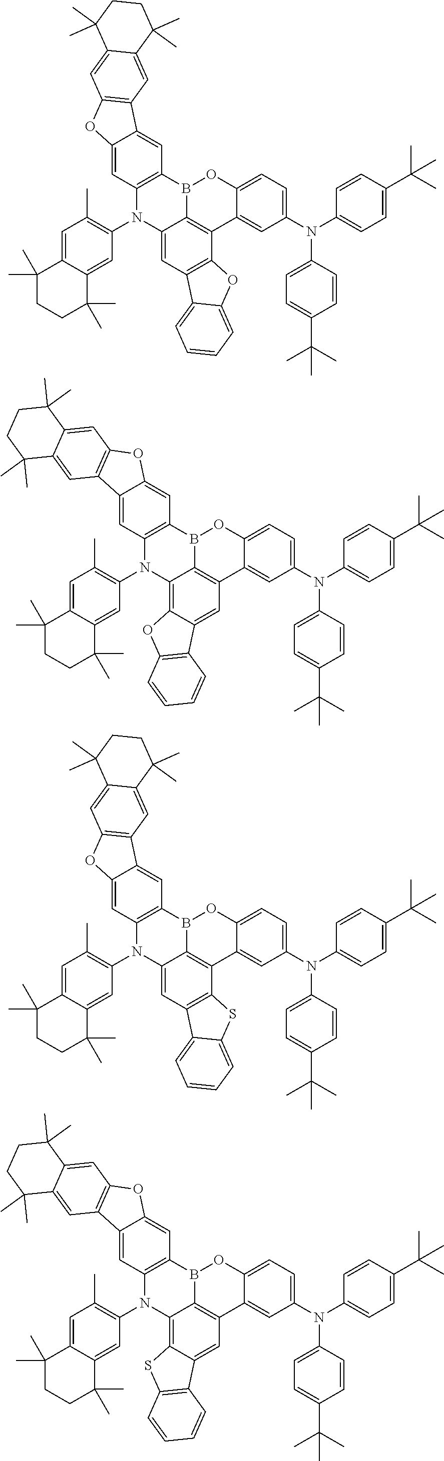

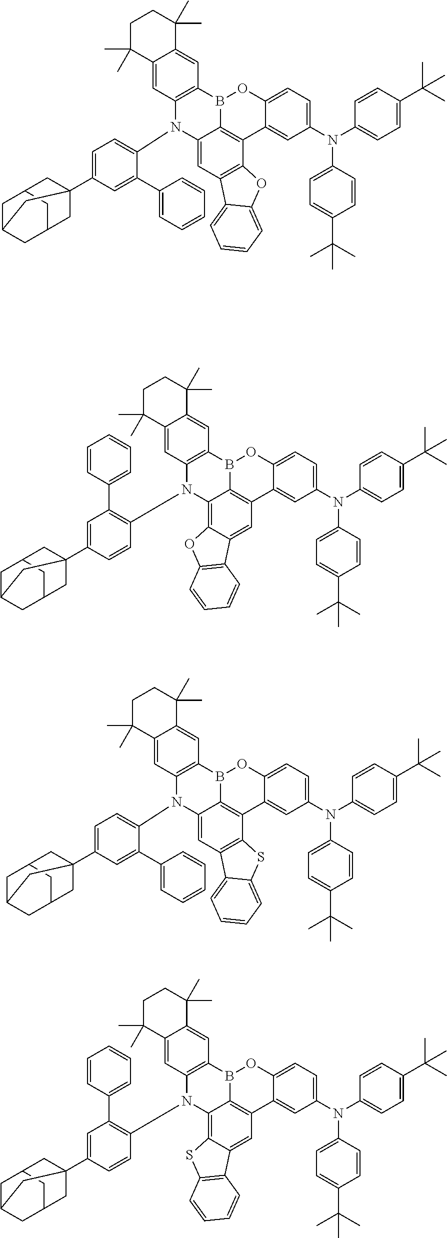

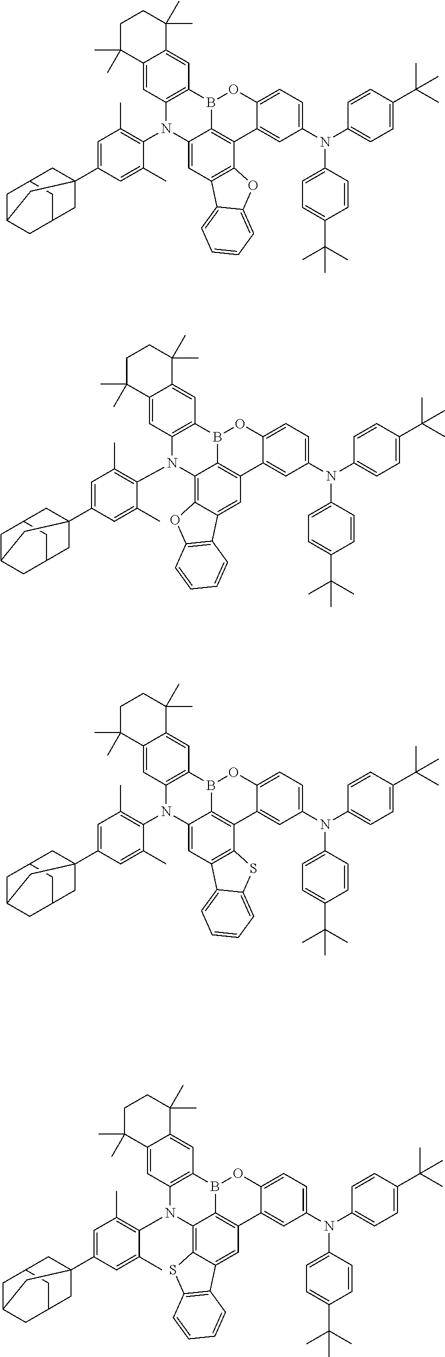

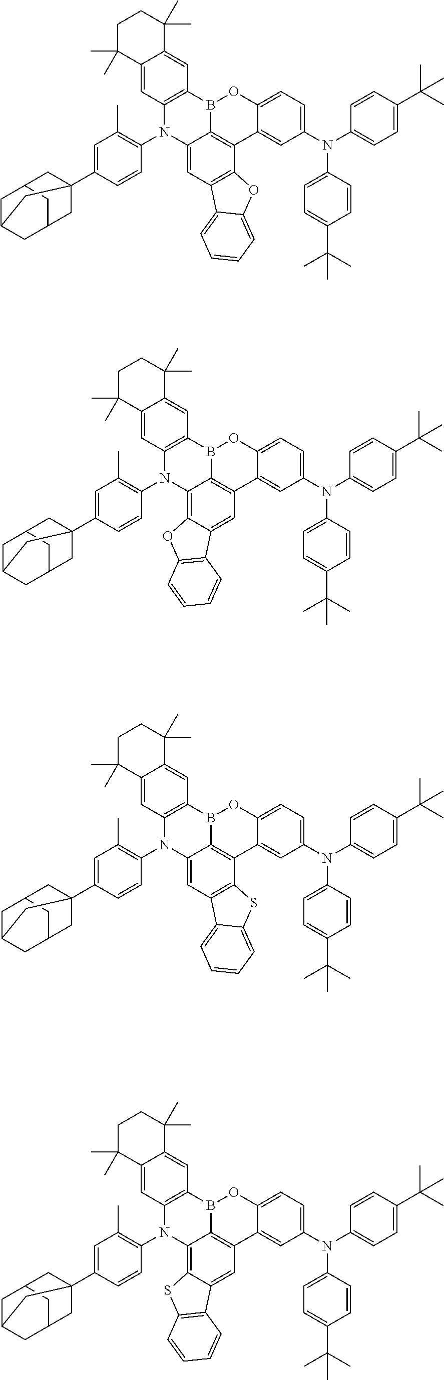

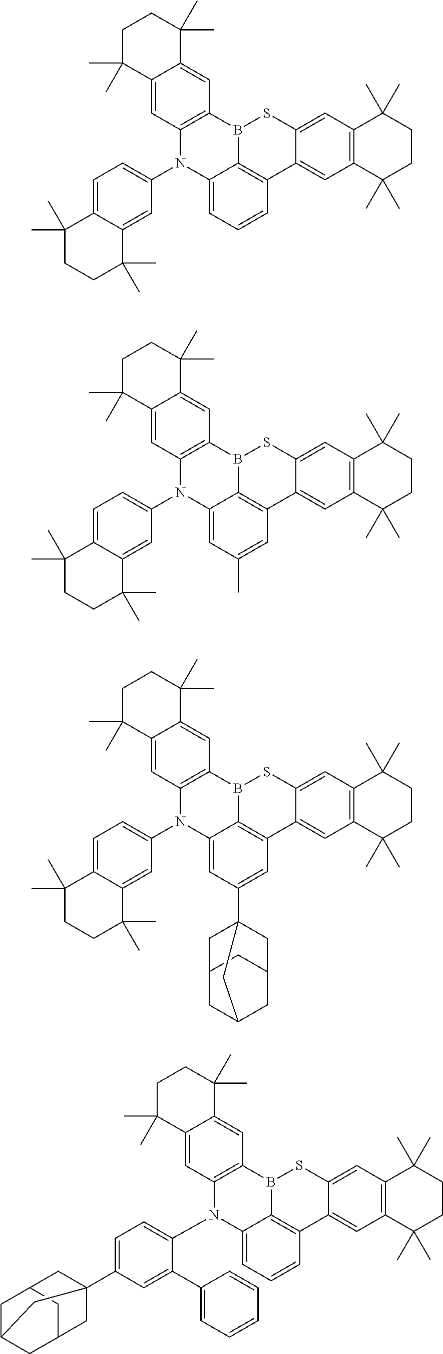

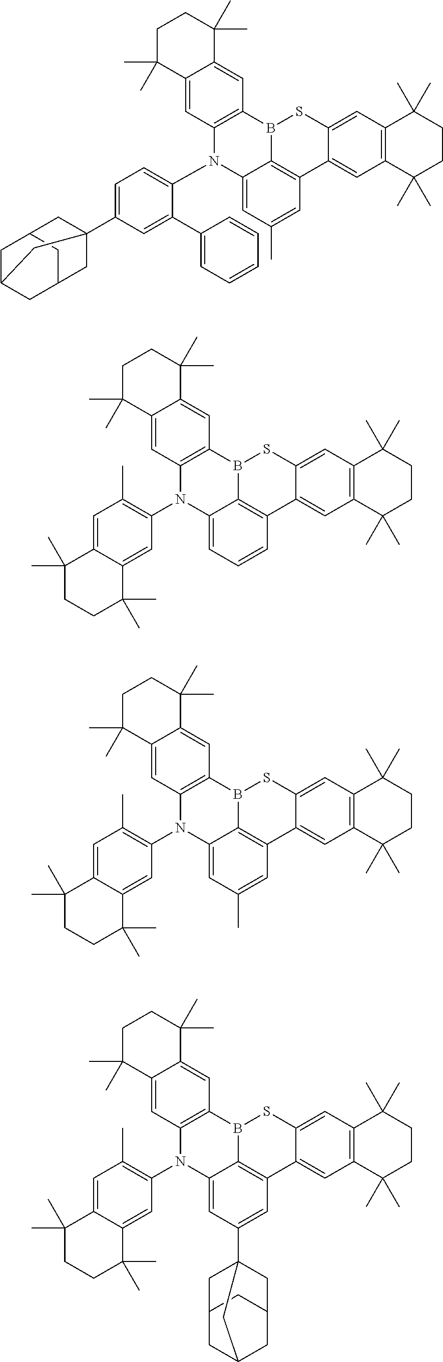 [SMILES: Cc1cc2c3c(c1)N(c1ccc(C45CC6CC(CC(C6)C4)C5)cc1-c1ccccc1)c1cc4c(cc1B3Sc1cc3c(cc1-2)C(C)(C)CCC3(C)C)C(C)(C)CCC4(C)C ; Cc1cc2c(cc1N1c3cc4c(cc3B3Sc5cc6c(cc5-c5cccc1c53)C(C)(C)CCC6(C)C)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Sc1cc3c(cc1-2)C(C)(C)CCC3(C)C)C(C)(C)CCC4(C)C ; Cc1cc2c(cc1N1c3cc4c(cc3B3Sc5cc6c(cc5-c5cc(C78CC9CC(CC(C9)C7)C8)cc1c53)C(C)(C)CCC6(C)C)C(C)(C)CCC4(C)C)C(C)(C)CCC2(C)C]

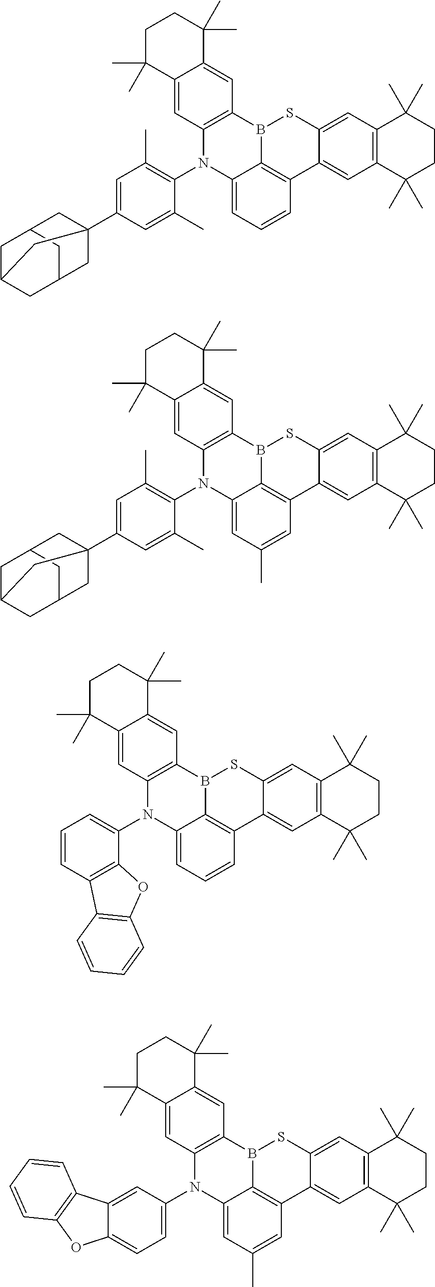 [SMILES: Cc1cc(C23CC4CC(CC(C4)C2)C3)cc(C)c1N1c2cc3c(cc2B2Sc4cc5c(cc4-c4cccc1c42)C(C)(C)CCC5(C)C)C(C)(C)CCC3(C)C ; Cc1cc2c3c(c1)N(c1c(C)cc(C45CC6CC(CC(C6)C4)C5)cc1C)c1cc4c(cc1B3Sc1cc3c(cc1-2)C(C)(C)CCC3(C)C)C(C)(C)CCC4(C)C ; CC1(C)CCC(C)(C)c2cc3c(cc21)SB1c2cc4c(cc2N(c2cccc5c2oc2ccccc25)c2cccc-3c21)C(C)(C)CCC4(C)C ; Cc1cc2c3c(c1)N(c1ccc4oc5ccccc5c4c1)c1cc4c(cc1B3Sc1cc3c(cc1-2)C(C)(C)CCC3(C)C)C(C)(C)CCC4(C)C]

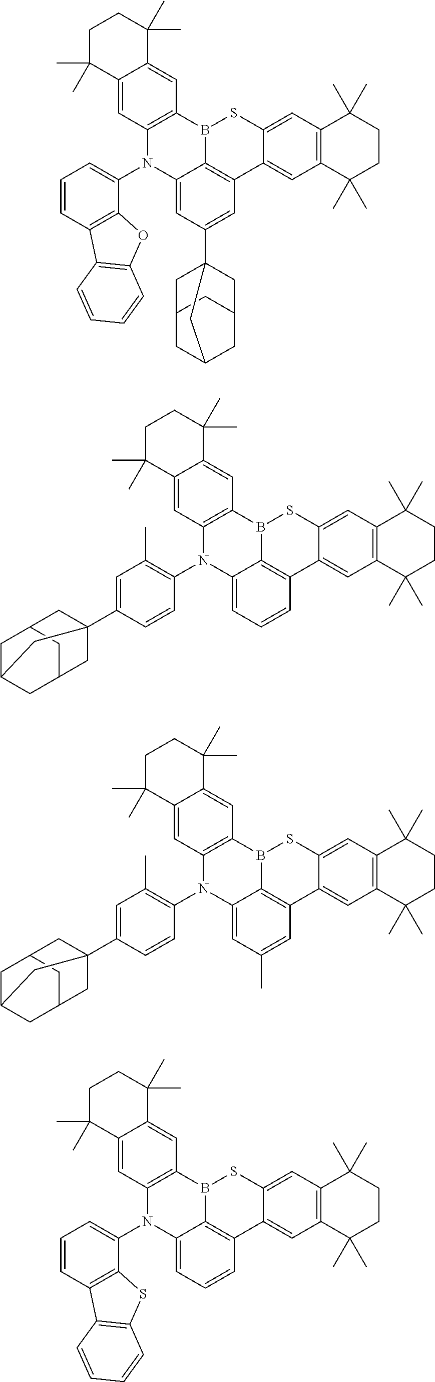

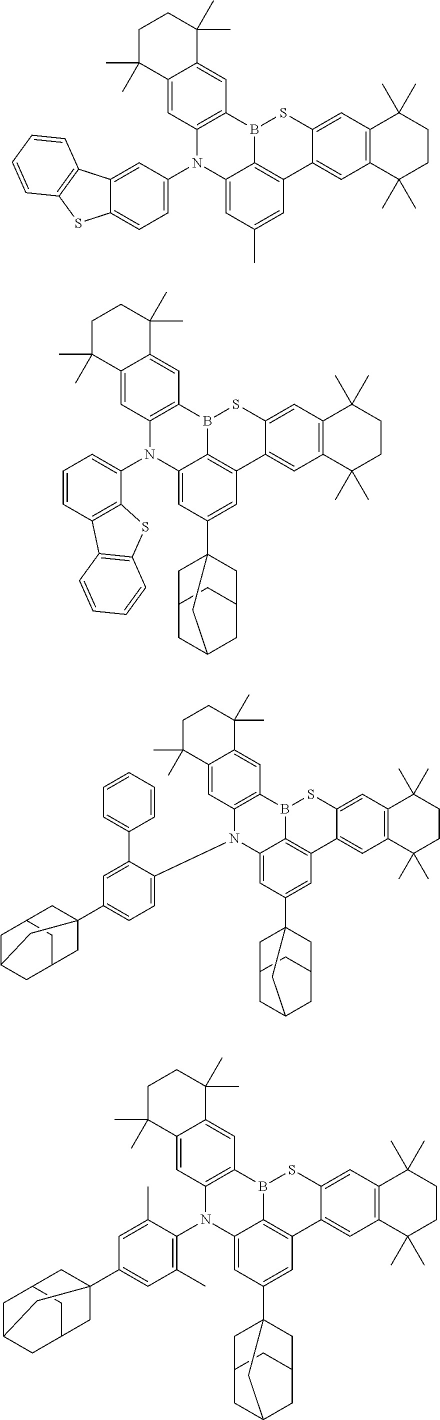 [SMILES: Cc1cc2c3c(c1)N(c1ccc4sc5ccccc5c4c1)c1cc4c(cc1B3Sc1cc3c(cc1-2)C(C)(C)CCC3(C)C)C(C)(C)CCC4(C)C ; CC1(C)CCC(C)(C)c2cc3c(cc21)SB1c2cc4c(cc2N(c2cccc5c2sc2ccccc25)c2cc(C56CC7CC(CC(C7)C5)C6)cc-3c21)C(C)(C)CCC4(C)C ; CC1(C)CCC(C)(C)c2cc3c(cc21)SB1c2cc4c(cc2N(c2ccc(C56CC7CC(CC(C7)C5)C6)cc2-c2ccccc2)c2cc(C56CC7CC(CC(C7)C5)C6)cc-3c21)C(C)(C)CCC4(C)C ; Cc1cc(C23CC4CC(CC(C4)C2)C3)cc(C)c1N1c2cc3c(cc2B2Sc4cc5c(cc4-c4cc(C67CC8CC(CC(C8)C6)C7)cc1c42)C(C)(C)CCC5(C)C)C(C)(C)CCC3(C)C]

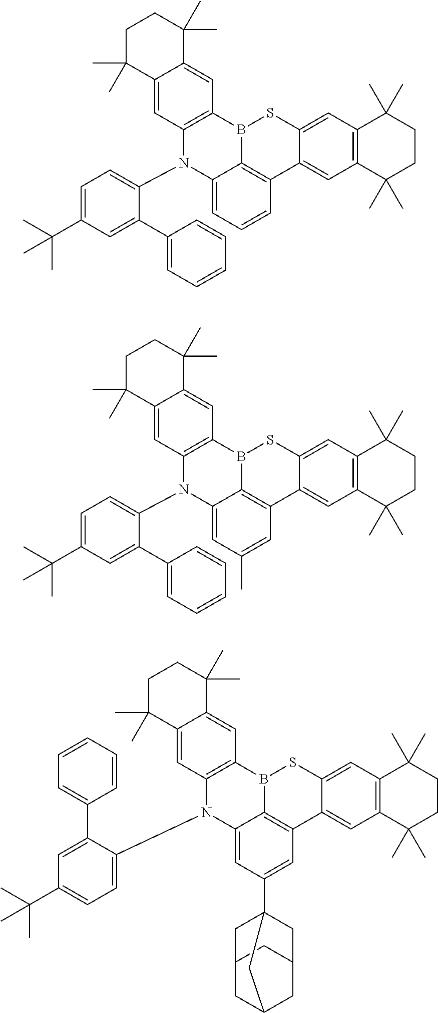

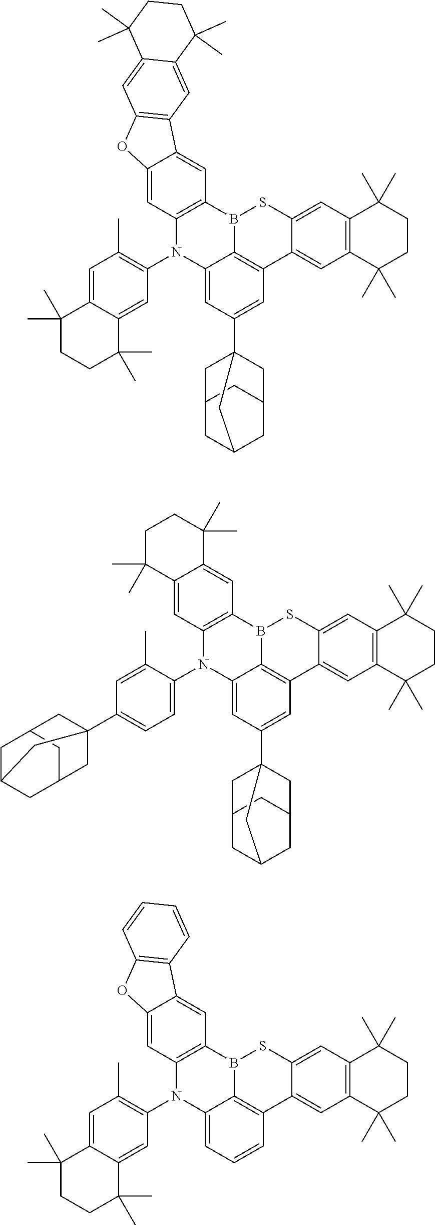 [SMILES: Cc1cc2c(cc1N1c3cc4oc5cc6c(cc5c4cc3B3Sc4cc5c(cc4-c4cc(C78CC9CC(CC(C9)C7)C8)cc1c43)C(C)(C)CCC5(C)C)C(C)(C)CCC6(C)C)C(C)(C)CCC2(C)C ; Cc1cc(C23CC4CC(CC(C4)C2)C3)ccc1N1c2cc3c(cc2B2Sc4cc5c(cc4-c4cc(C67CC8CC(CC(C8)C6)C7)cc1c42)C(C)(C)CCC5(C)C)C(C)(C)CCC3(C)C ; Cc1cc2c(cc1N1c3cc4oc5ccccc5c4cc3B3Sc4cc5c(cc4-c4cccc1c43)C(C)(C)CCC5(C)C)C(C)(C)CCC2(C)C]

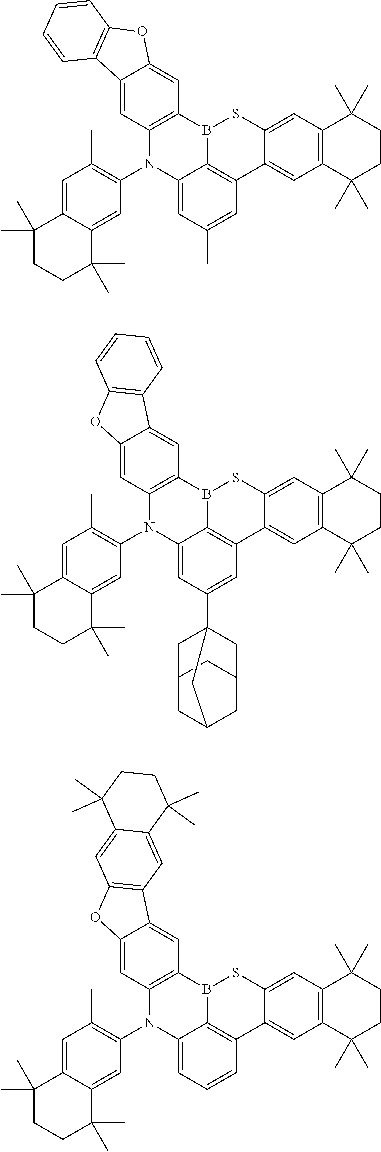

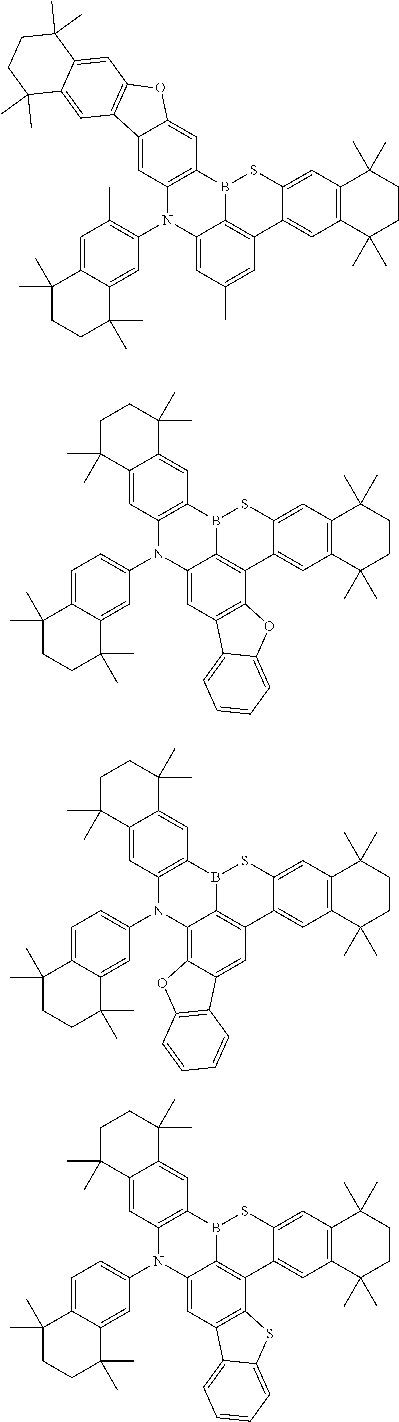

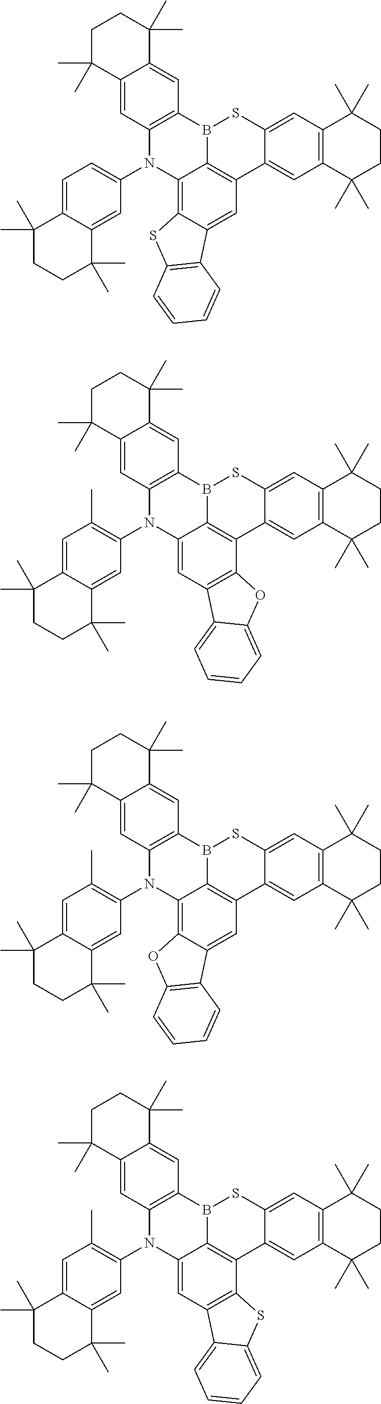

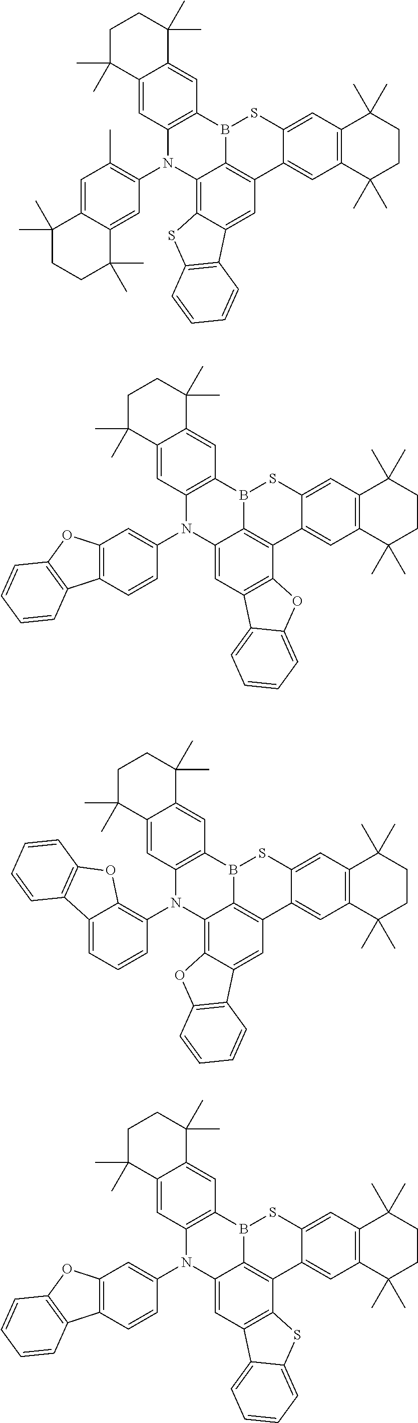

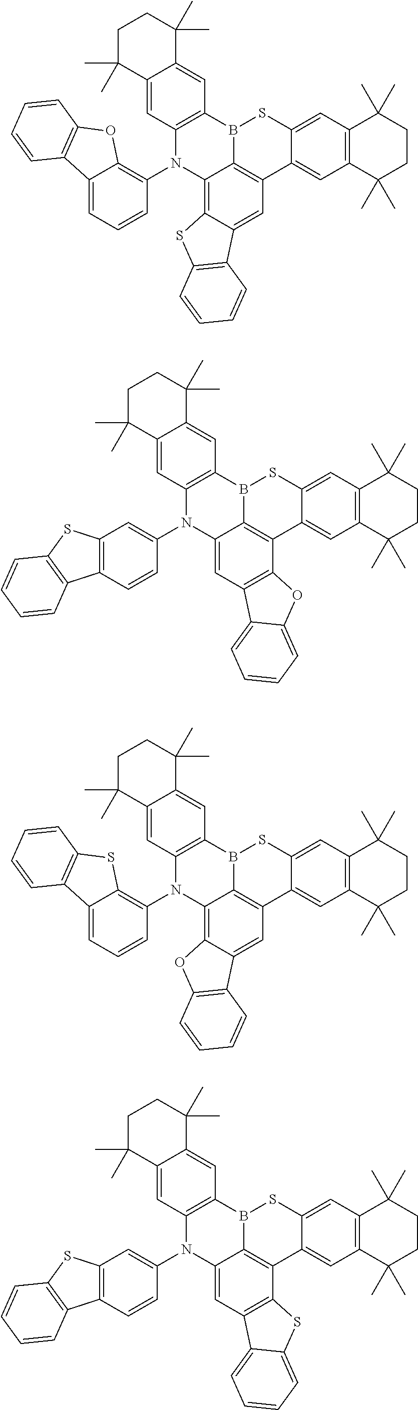

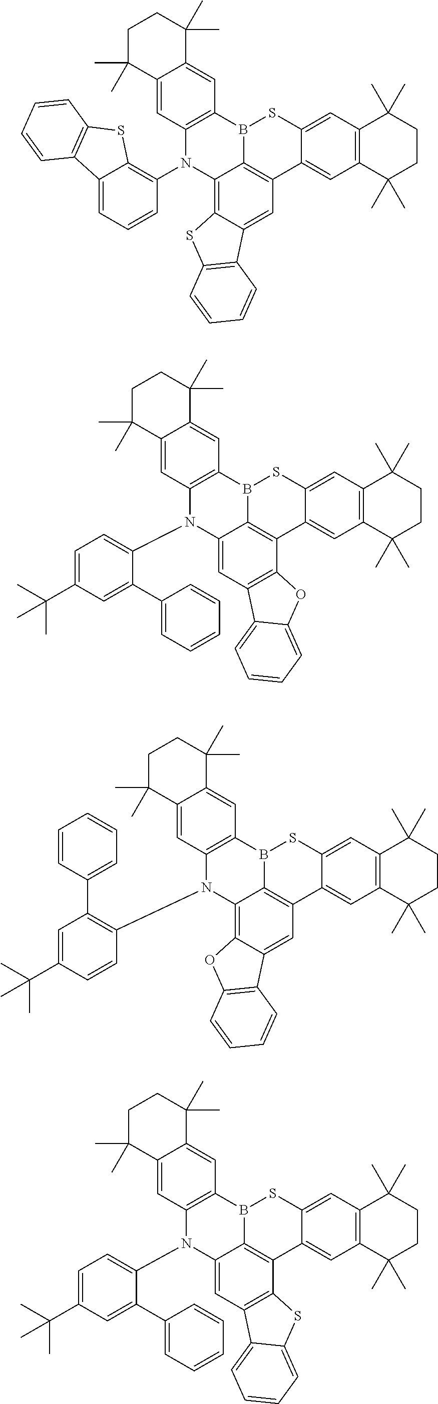

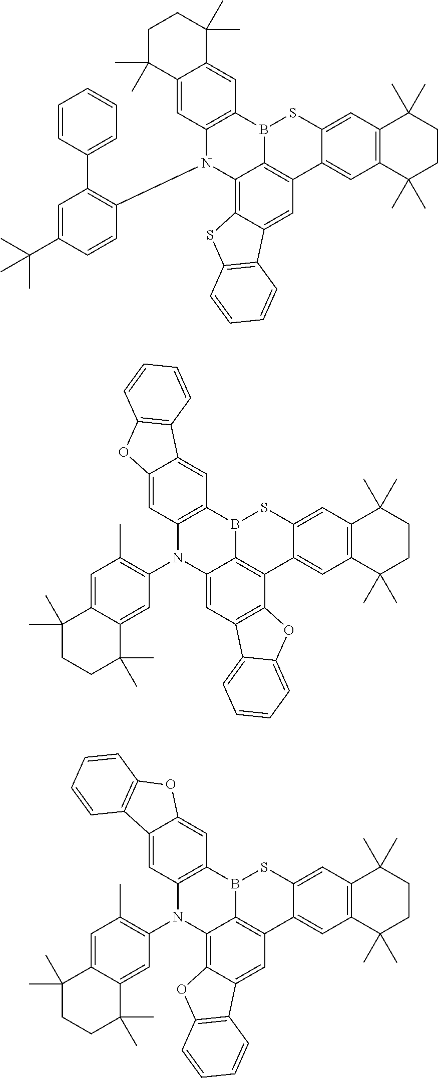 [SMILES: CC(C)(C)c1ccc(N2c3cc4c(cc3B3Sc5cc6c(cc5-c5cc7c(sc8ccccc87)c2c53)C(C)(C)CCC6(C)C)C(C)(C)CCC4(C)C)c(-c2ccccc2)c1 ; Cc1cc2c(cc1N1c3cc4oc5ccccc5c4cc3B3Sc4cc5c(cc4-c4c3c1cc1c4oc3ccccc31)C(C)(C)CCC5(C)C)C(C)(C)CCC2(C)C ; Cc1cc2c(cc1N1c3cc4c(cc3B3Sc5cc6c(cc5-c5cc7c(oc8ccccc87)c1c53)C(C)(C)CCC6(C)C)oc1ccccc14)C(C)(C)CCC2(C)C]

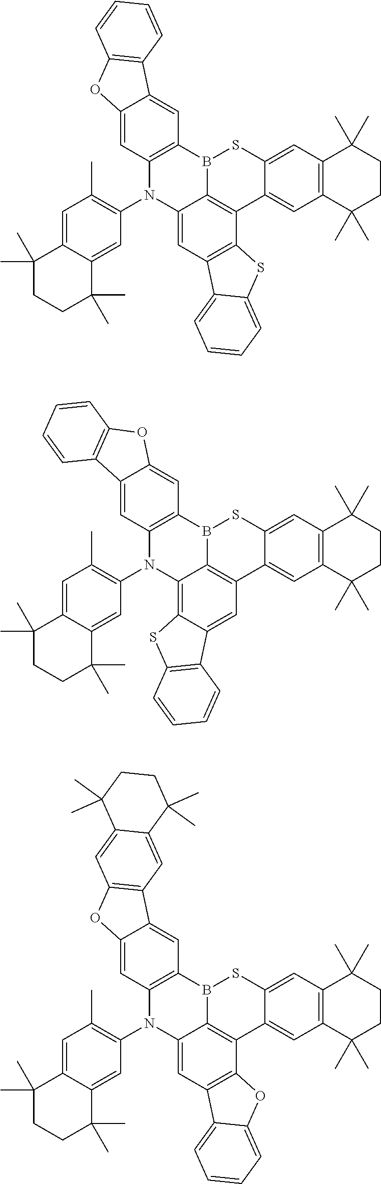 [SMILES: Cc1cc2c(cc1N1c3cc4oc5ccccc5c4cc3B3Sc4cc5c(cc4-c4c3c1cc1c4sc3ccccc31)C(C)(C)CCC5(C)C)C(C)(C)CCC2(C)C ; Cc1cc2c(cc1N1c3cc4c(cc3B3Sc5cc6c(cc5-c5cc7c(sc8ccccc87)c1c53)C(C)(C)CCC6(C)C)oc1ccccc14)C(C)(C)CCC2(C)C ; Cc1cc2c(cc1N1c3cc4oc5cc6c(cc5c4cc3B3Sc4cc5c(cc4-c4c3c1cc1c4oc3ccccc31)C(C)(C)CCC5(C)C)C(C)(C)CCC6(C)C)C(C)(C)CCC2(C)C]

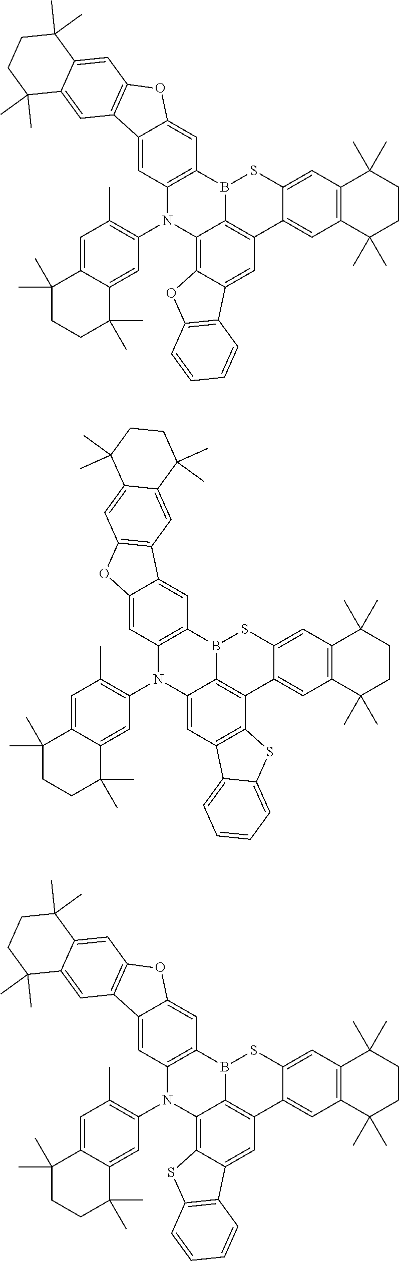 [SMILES: Cc1cc2c(cc1N1c3cc4c(cc3B3Sc5cc6c(cc5-c5cc7c(oc8ccccc87)c1c53)C(C)(C)CCC6(C)C)oc1cc3c(cc14)C(C)(C)CCC3(C)C)C(C)(C)CCC2(C)C ; Cc1cc2c(cc1N1c3cc4oc5cc6c(cc5c4cc3B3Sc4cc5c(cc4-c4c3c1cc1c4sc3ccccc31)C(C)(C)CCC5(C)C)C(C)(C)CCC6(C)C)C(C)(C)CCC2(C)C ; Cc1cc2c(cc1N1c3cc4c(cc3B3Sc5cc6c(cc5-c5cc7c(sc8ccccc87)c1c53)C(C)(C)CCC6(C)C)oc1cc3c(cc14)C(C)(C)CCC3(C)C)C(C)(C)CCC2(C)C]

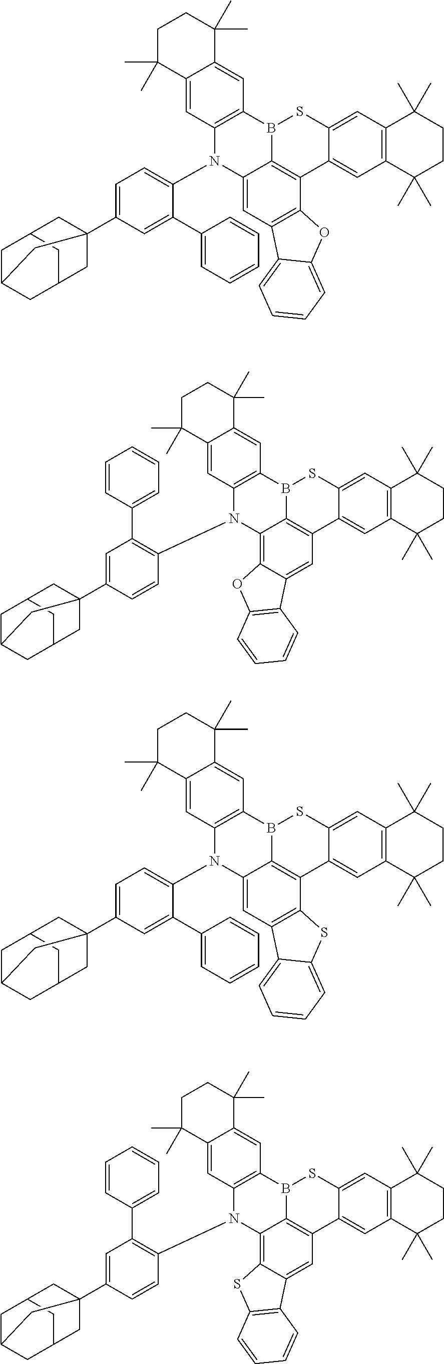

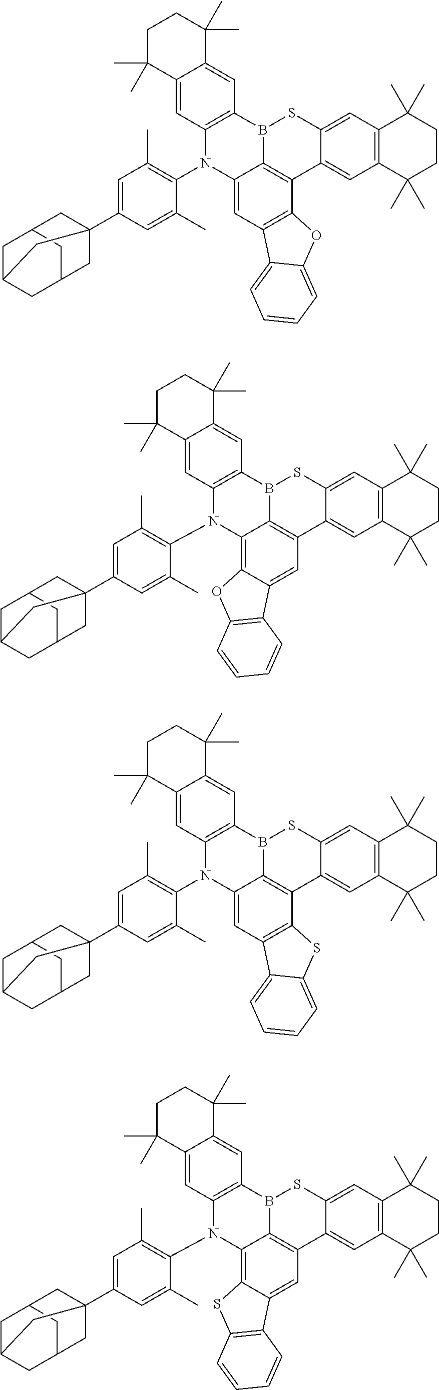

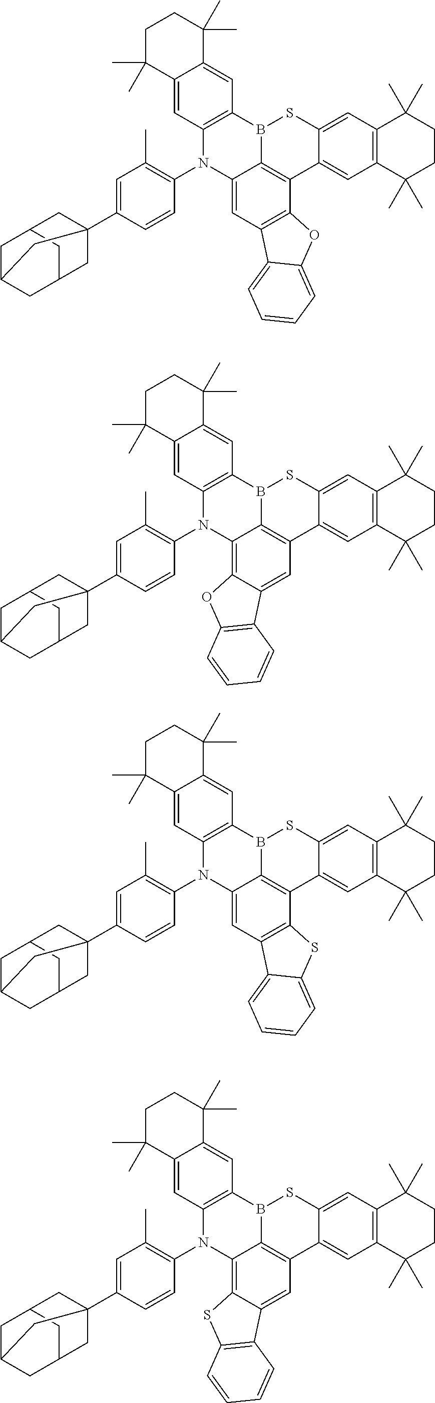

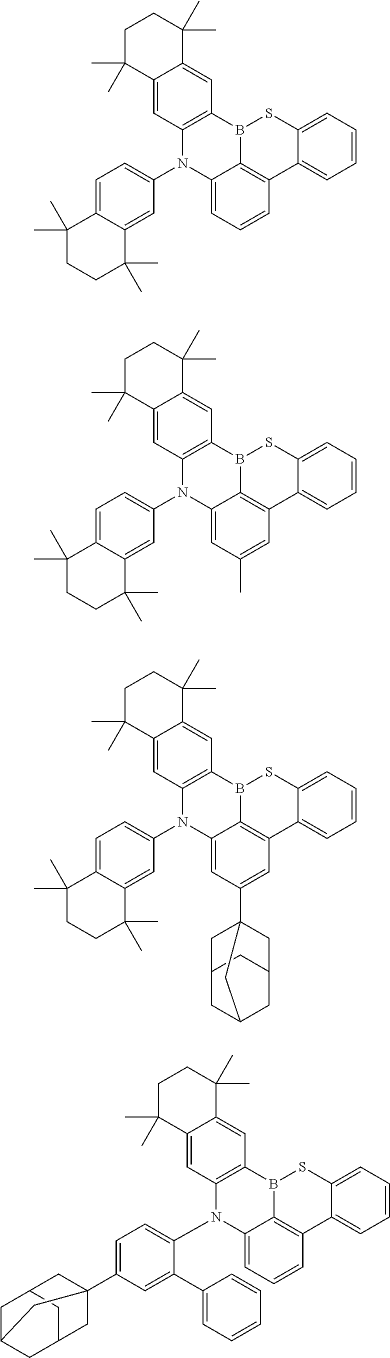

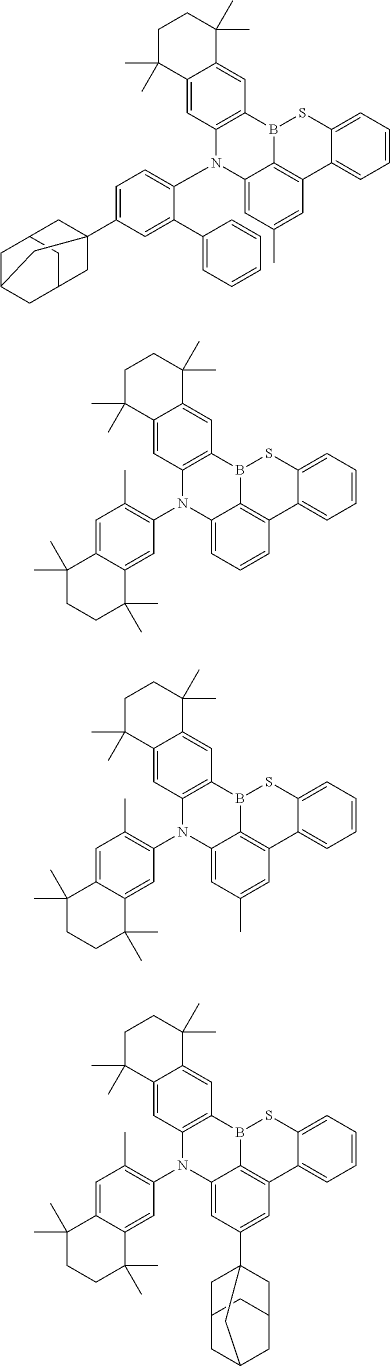 [SMILES: Cc1cc2c3c(c1)N(c1ccc(C45CC6CC(CC(C6)C4)C5)cc1-c1ccccc1)c1cc4c(cc1B3Sc1ccccc1-2)C(C)(C)CCC4(C)C ; Cc1cc2c(cc1N1c3cc4c(cc3B3Sc5ccccc5-c5cccc1c53)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Sc1ccccc1-2)C(C)(C)CCC4(C)C ; Cc1cc2c(cc1N1c3cc4c(cc3B3Sc5ccccc5-c5cc(C67CC8CC(CC(C8)C6)C7)cc1c53)C(C)(C)CCC4(C)C)C(C)(C)CCC2(C)C]

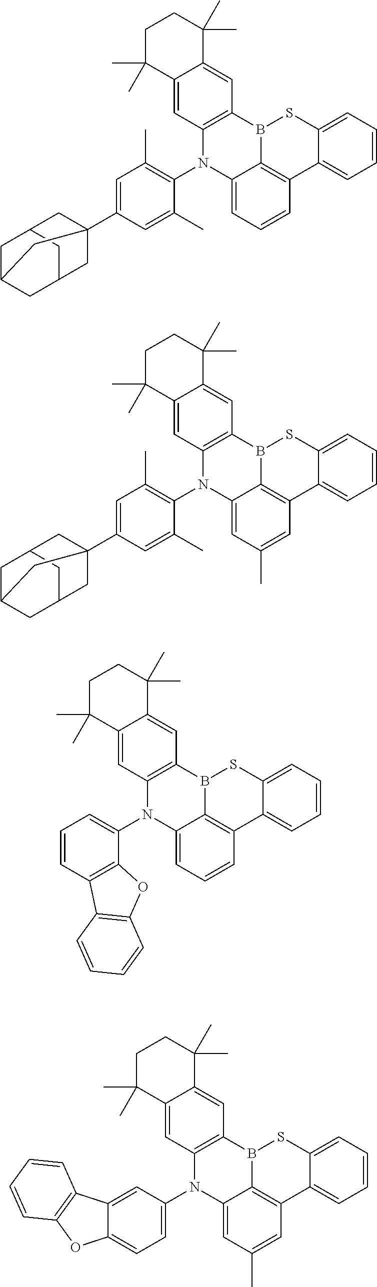 [SMILES: Cc1cc(C23CC4CC(CC(C4)C2)C3)cc(C)c1N1c2cc3c(cc2B2Sc4ccccc4-c4cccc1c42)C(C)(C)CCC3(C)C ; Cc1cc2c3c(c1)N(c1c(C)cc(C45CC6CC(CC(C6)C4)C5)cc1C)c1cc4c(cc1B3Sc1ccccc1-2)C(C)(C)CCC4(C)C ; CC1(C)CCC(C)(C)c2cc3c(cc21)B1Sc2ccccc2-c2cccc(c21)N3c1cccc2c1oc1ccccc12 ; Cc1cc2c3c(c1)N(c1ccc4oc5ccccc5c4c1)c1cc4c(cc1B3Sc1ccccc1-2)C(C)(C)CCC4(C)C]

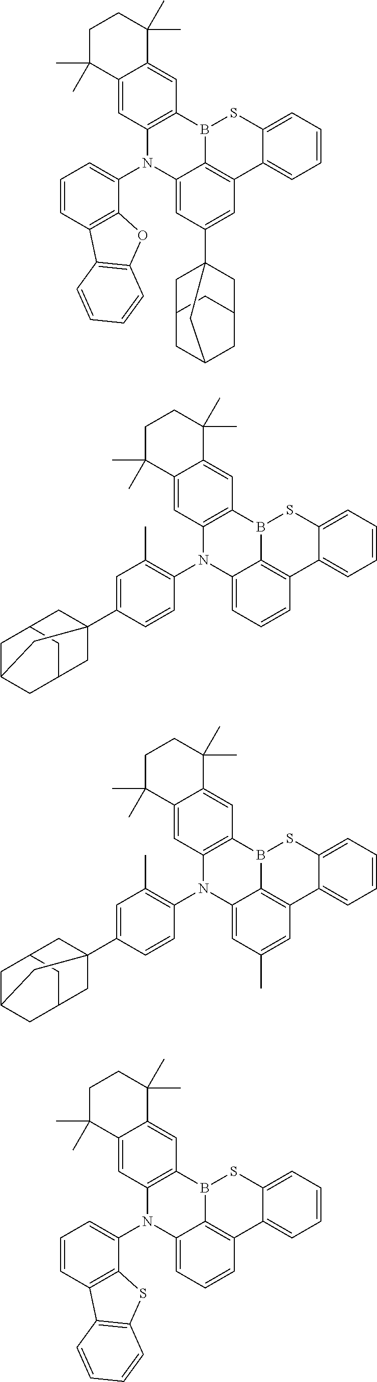

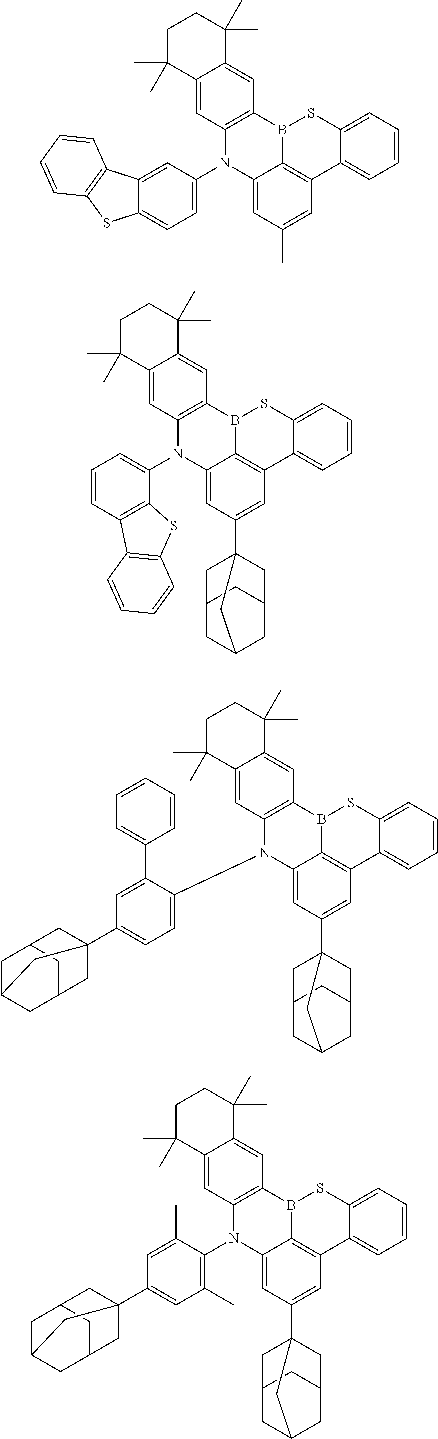 [SMILES: Cc1cc2c3c(c1)N(c1ccc4sc5ccccc5c4c1)c1cc4c(cc1B3Sc1ccccc1-2)C(C)(C)CCC4(C)C ; CC1(C)CCC(C)(C)c2cc3c(cc21)B1Sc2ccccc2-c2cc(C45CC6CC(CC(C6)C4)C5)cc(c21)N3c1cccc2c1sc1ccccc12 ; CC1(C)CCC(C)(C)c2cc3c(cc21)B1Sc2ccccc2-c2cc(C45CC6CC(CC(C6)C4)C5)cc(c21)N3c1ccc(C23CC4CC(CC(C4)C2)C3)cc1-c1ccccc1 ; Cc1cc(C23CC4CC(CC(C4)C2)C3)cc(C)c1N1c2cc3c(cc2B2Sc4ccccc4-c4cc(C56CC7CC(CC(C7)C5)C6)cc1c42)C(C)(C)CCC3(C)C]

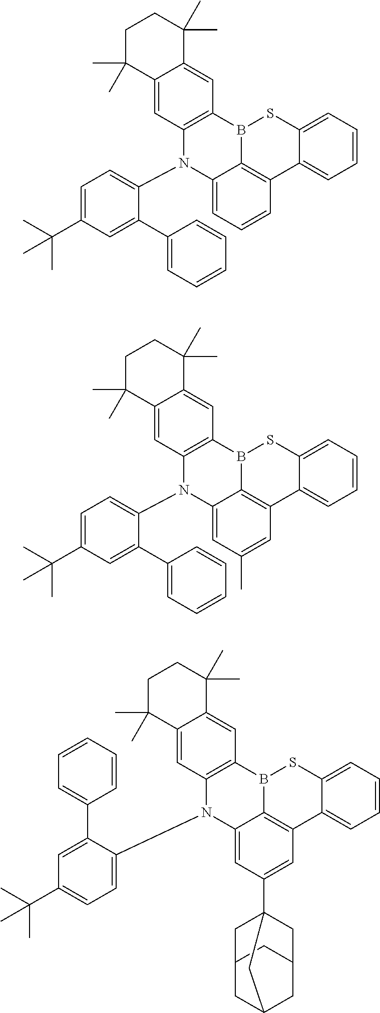

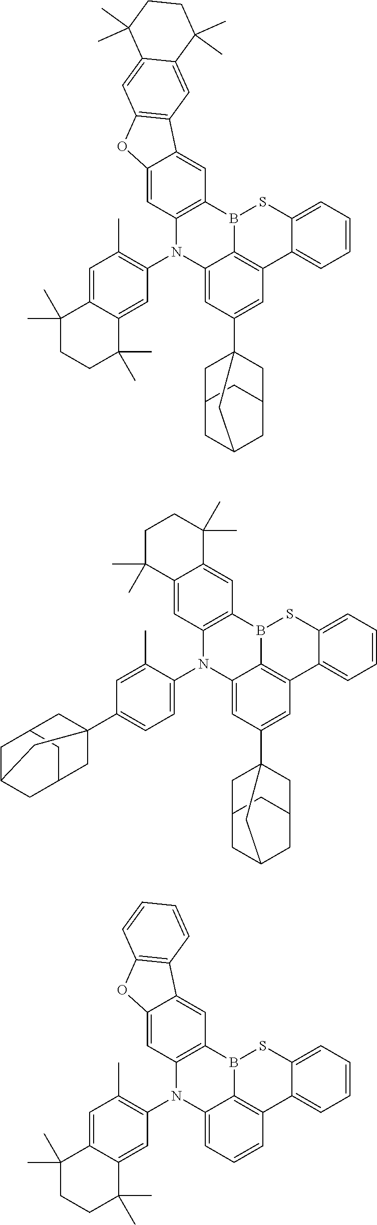 [SMILES: Cc1cc2c(cc1N1c3cc4oc5cc6c(cc5c4cc3B3Sc4ccccc4-c4cc(C57CC8CC(CC(C8)C5)C7)cc1c43)C(C)(C)CCC6(C)C)C(C)(C)CCC2(C)C ; Cc1cc(C23CC4CC(CC(C4)C2)C3)ccc1N1c2cc3c(cc2B2Sc4ccccc4-c4cc(C56CC7CC(CC(C7)C5)C6)cc1c42)C(C)(C)CCC3(C)C ; Cc1cc2c(cc1N1c3cc4oc5ccccc5c4cc3B3Sc4ccccc4-c4cccc1c43)C(C)(C)CCC2(C)C]

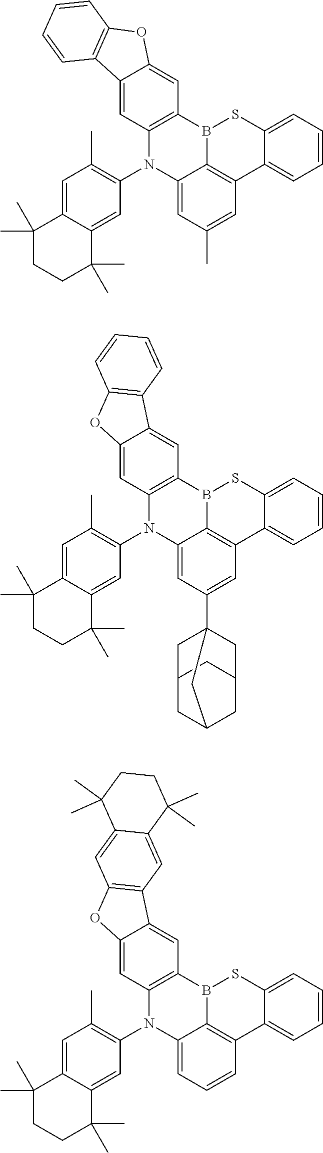

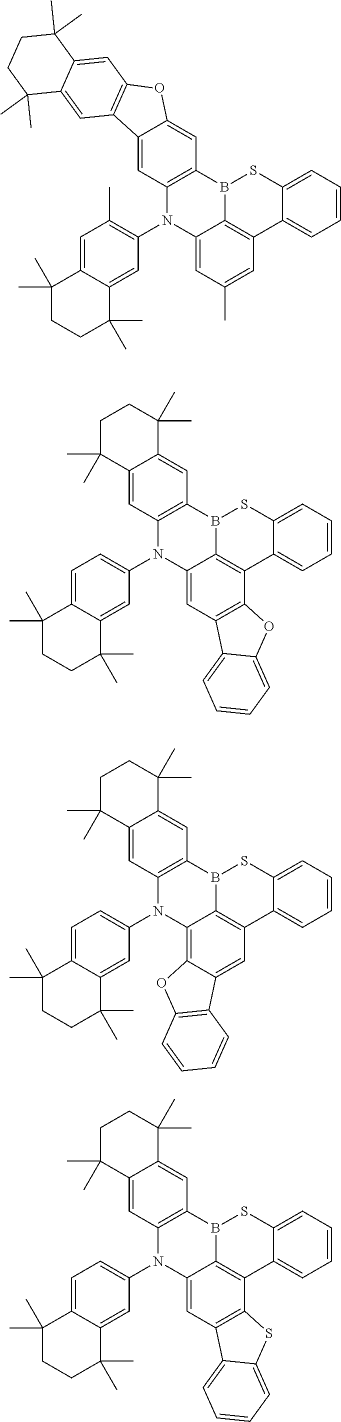

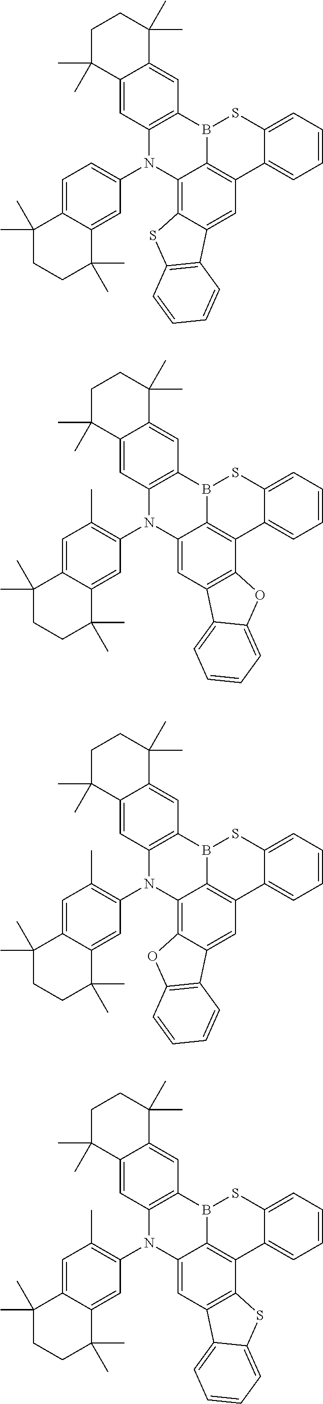

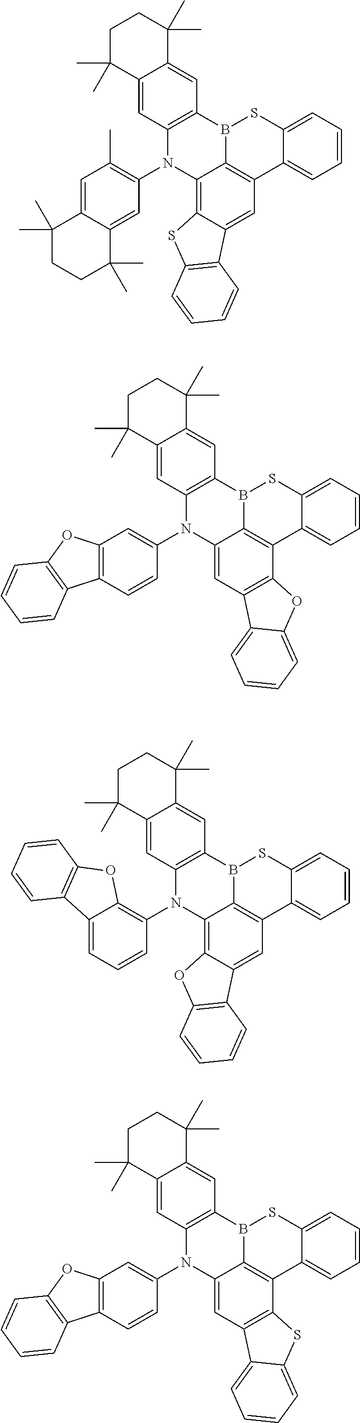

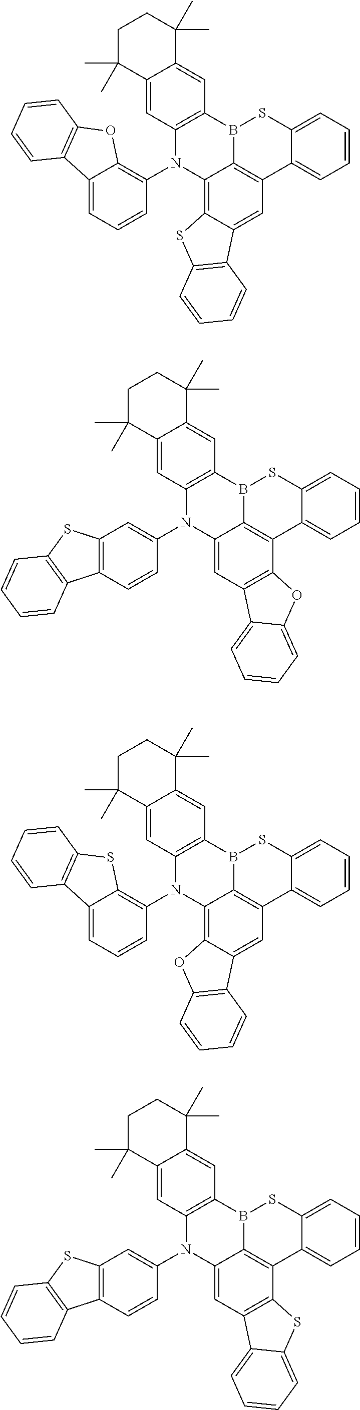

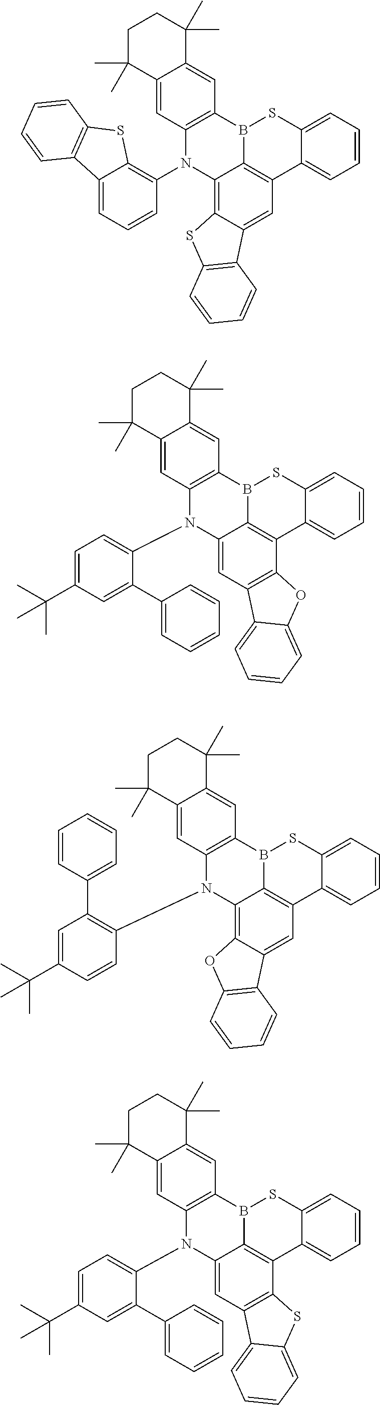

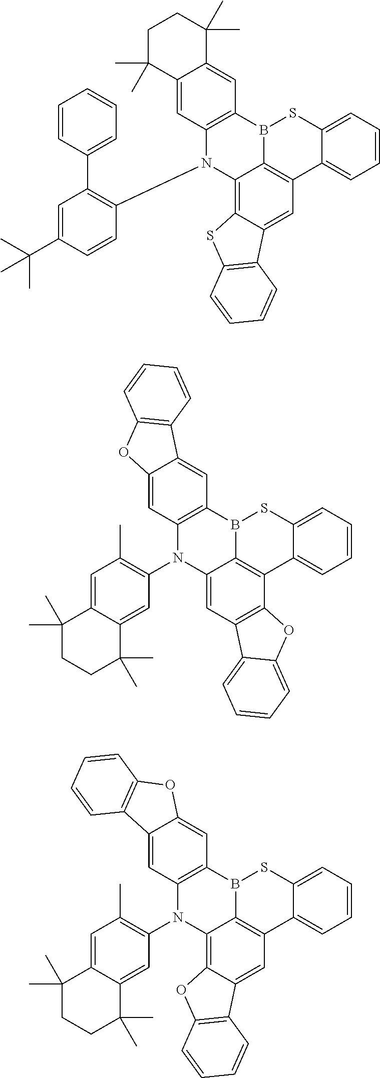 [SMILES: CC(C)(C)c1ccc(N2c3cc4c(cc3B3Sc5ccccc5-c5cc6c(sc7ccccc76)c2c53)C(C)(C)CCC4(C)C)c(-c2ccccc2)c1 ; Cc1cc2c(cc1N1c3cc4oc5ccccc5c4cc3B3Sc4ccccc4-c4c3c1cc1c4oc3ccccc31)C(C)(C)CCC2(C)C ; Cc1cc2c(cc1N1c3cc4c(cc3B3Sc5ccccc5-c5cc6c(oc7ccccc76)c1c53)oc1ccccc14)C(C)(C)CCC2(C)C]

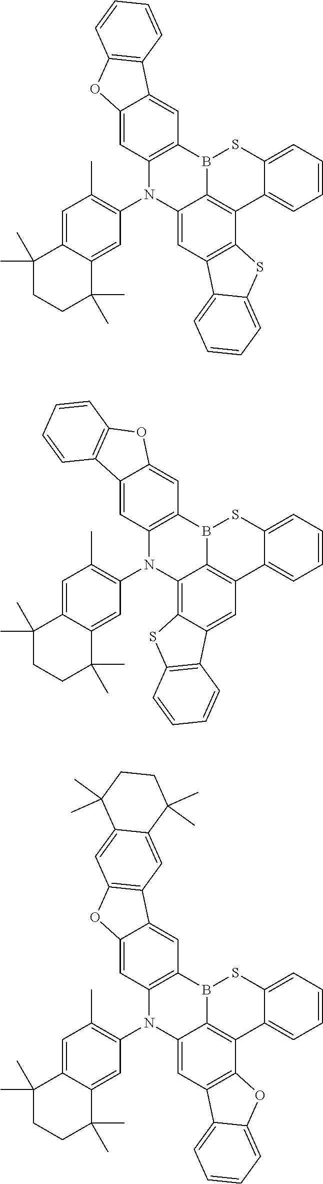 [SMILES: Cc1cc2c(cc1N1c3cc4oc5ccccc5c4cc3B3Sc4ccccc4-c4c3c1cc1c4sc3ccccc31)C(C)(C)CCC2(C)C ; Cc1cc2c(cc1N1c3cc4c(cc3B3Sc5ccccc5-c5cc6c(sc7ccccc76)c1c53)oc1ccccc14)C(C)(C)CCC2(C)C ; Cc1cc2c(cc1N1c3cc4oc5cc6c(cc5c4cc3B3Sc4ccccc4-c4c3c1cc1c4oc3ccccc31)C(C)(C)CCC6(C)C)C(C)(C)CCC2(C)C]

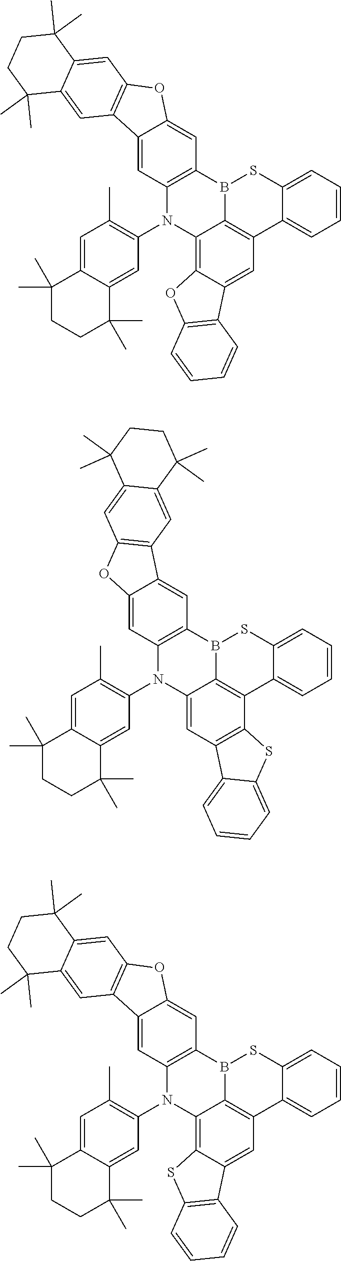 [SMILES: Cc1cc2c(cc1N1c3cc4c(cc3B3Sc5ccccc5-c5cc6c(oc7ccccc76)c1c53)oc1cc3c(cc14)C(C)(C)CCC3(C)C)C(C)(C)CCC2(C)C ; Cc1cc2c(cc1N1c3cc4oc5cc6c(cc5c4cc3B3Sc4ccccc4-c4c3c1cc1c4sc3ccccc31)C(C)(C)CCC6(C)C)C(C)(C)CCC2(C)C ; Cc1cc2c(cc1N1c3cc4c(cc3B3Sc5ccccc5-c5cc6c(sc7ccccc76)c1c53)oc1cc3c(cc14)C(C)(C)CCC3(C)C)C(C)(C)CCC2(C)C]

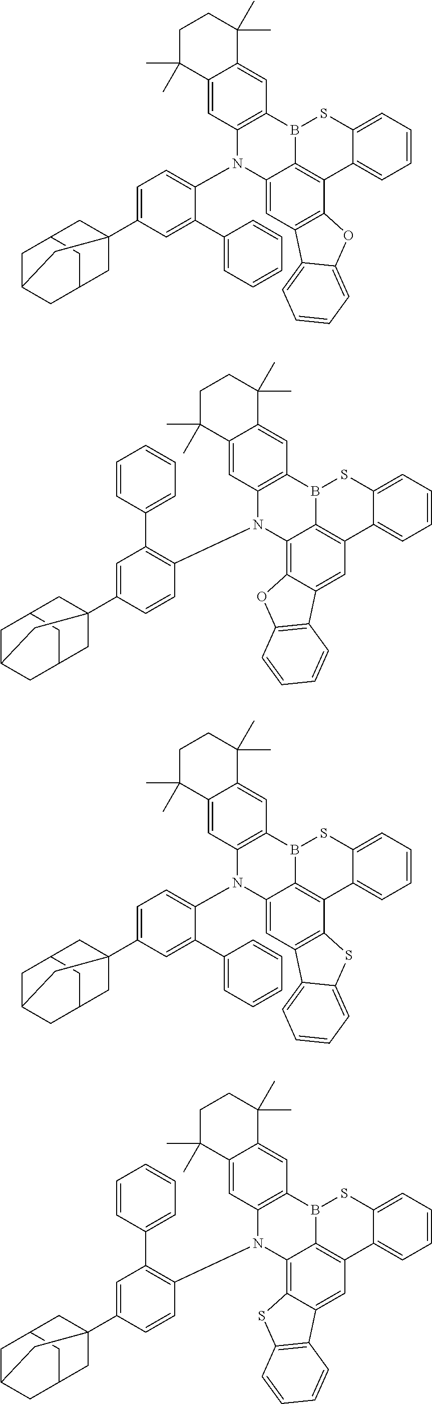

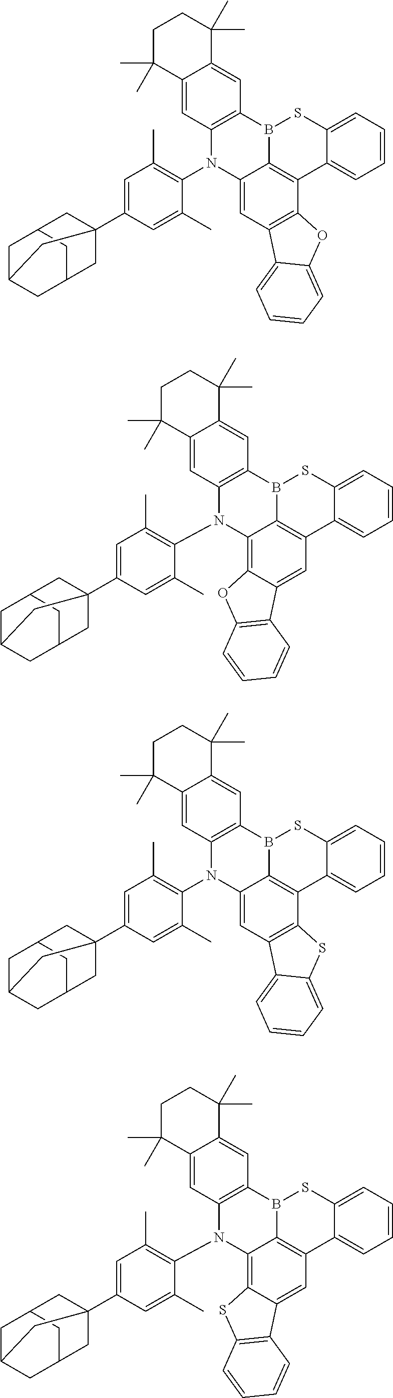

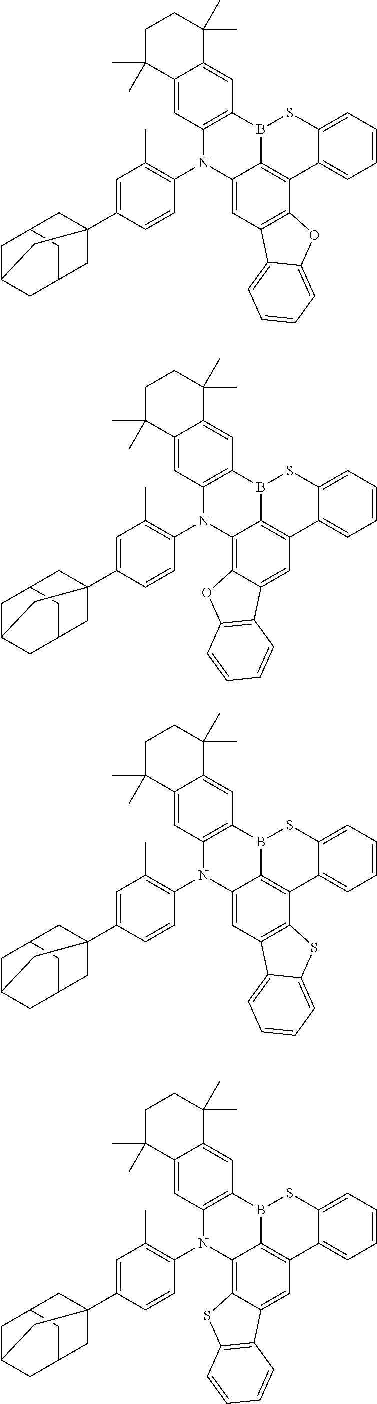

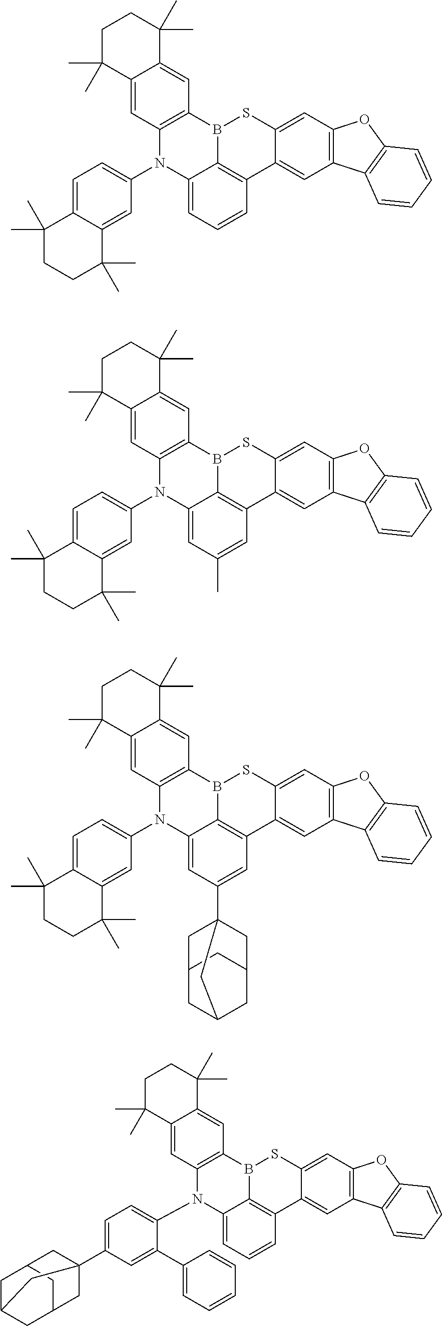

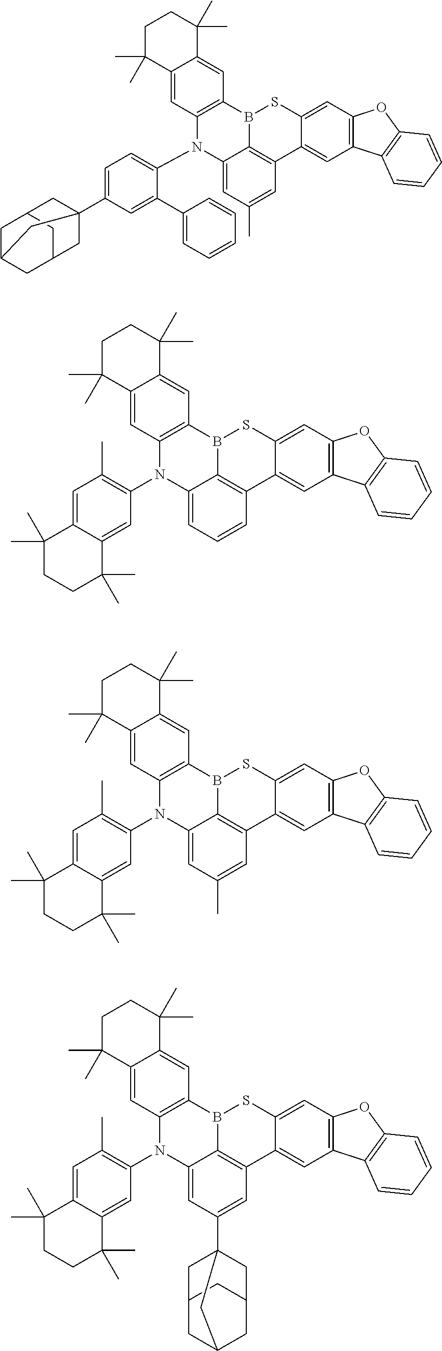 [SMILES: Cc1cc2c3c(c1)N(c1ccc(C45CC6CC(CC(C6)C4)C5)cc1-c1ccccc1)c1cc4c(cc1B3Sc1cc3oc5ccccc5c3cc1-2)C(C)(C)CCC4(C)C ; Cc1cc2c(cc1N1c3cc4c(cc3B3Sc5cc6oc7ccccc7c6cc5-c5cccc1c53)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Sc1cc3oc5ccccc5c3cc1-2)C(C)(C)CCC4(C)C ; Cc1cc2c(cc1N1c3cc4c(cc3B3Sc5cc6oc7ccccc7c6cc5-c5cc(C67CC8CC(CC(C8)C6)C7)cc1c53)C(C)(C)CCC4(C)C)C(C)(C)CCC2(C)C]

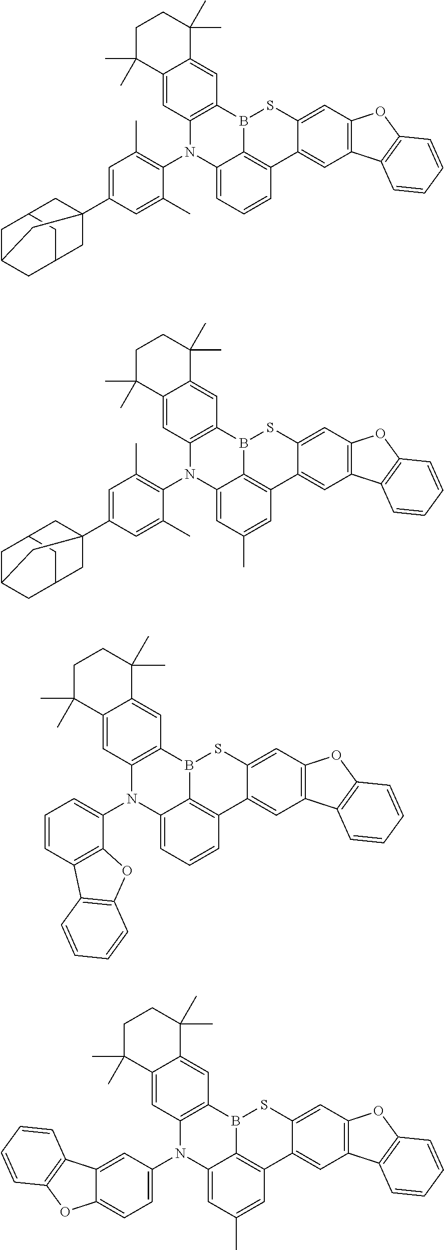 [SMILES: Cc1cc(C23CC4CC(CC(C4)C2)C3)cc(C)c1N1c2cc3c(cc2B2Sc4cc5oc6ccccc6c5cc4-c4cccc1c42)C(C)(C)CCC3(C)C ; Cc1cc2c3c(c1)N(c1c(C)cc(C45CC6CC(CC(C6)C4)C5)cc1C)c1cc4c(cc1B3Sc1cc3oc5ccccc5c3cc1-2)C(C)(C)CCC4(C)C ; CC1(C)CCC(C)(C)c2cc3c(cc21)B1Sc2cc4oc5ccccc5c4cc2-c2cccc(c21)N3c1cccc2c1oc1ccccc12 ; Cc1cc2c3c(c1)N(c1ccc4oc5ccccc5c4c1)c1cc4c(cc1B3Sc1cc3oc5ccccc5c3cc1-2)C(C)(C)CCC4(C)C]

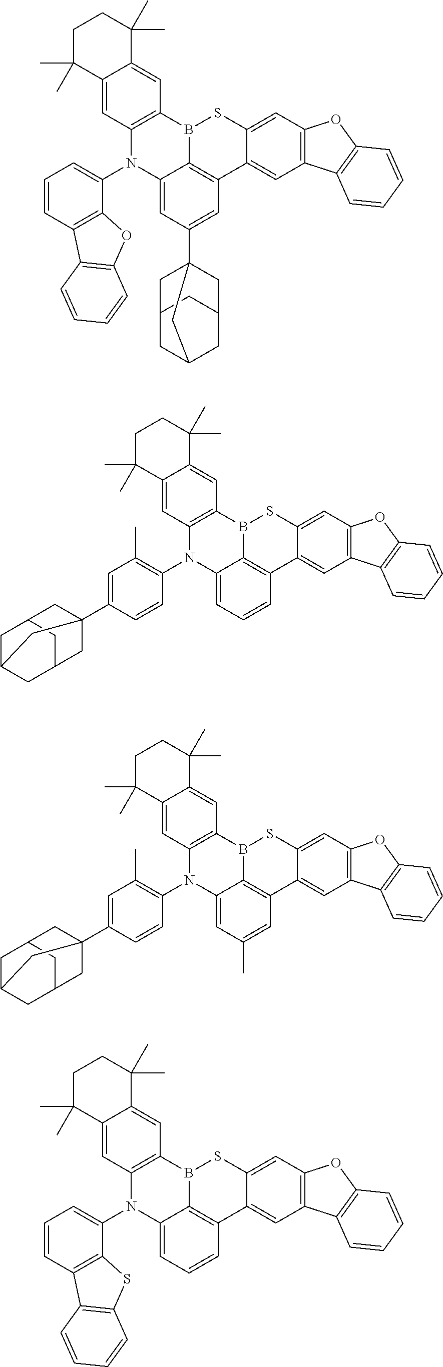

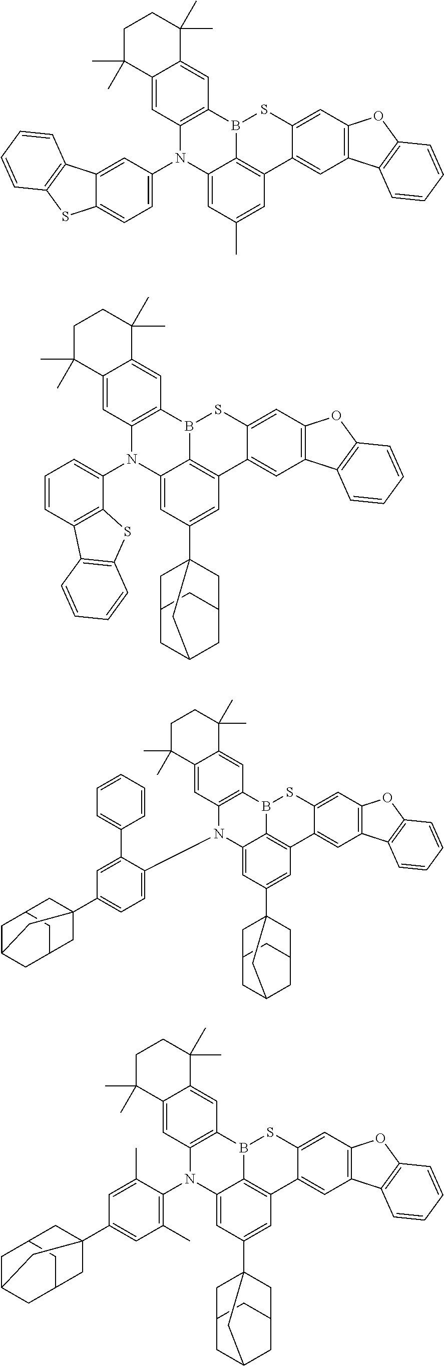 [SMILES: Cc1cc2c3c(c1)N(c1ccc4sc5ccccc5c4c1)c1cc4c(cc1B3Sc1cc3oc5ccccc5c3cc1-2)C(C)(C)CCC4(C)C ; CC1(C)CCC(C)(C)c2cc3c(cc21)B1Sc2cc4oc5ccccc5c4cc2-c2cc(C45CC6CC(CC(C6)C4)C5)cc(c21)N3c1cccc2c1sc1ccccc12 ; CC1(C)CCC(C)(C)c2cc3c(cc21)B1Sc2cc4oc5ccccc5c4cc2-c2cc(C45CC6CC(CC(C6)C4)C5)cc(c21)N3c1ccc(C23CC4CC(CC(C4)C2)C3)cc1-c1ccccc1 ; Cc1cc(C23CC4CC(CC(C4)C2)C3)cc(C)c1N1c2cc3c(cc2B2Sc4cc5oc6ccccc6c5cc4-c4cc(C56CC7CC(CC(C7)C5)C6)cc1c42)C(C)(C)CCC3(C)C]

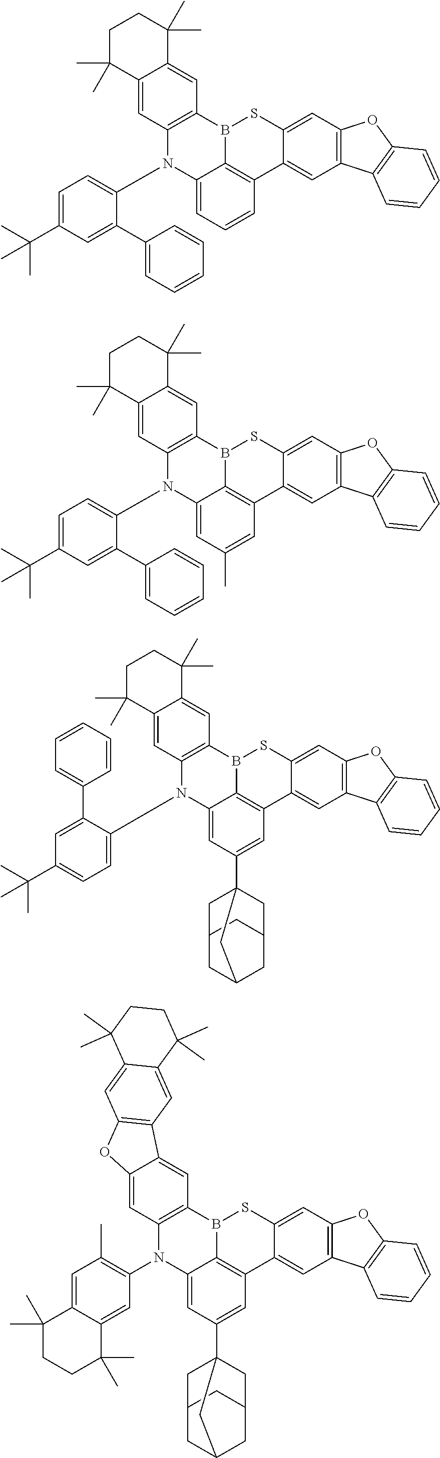

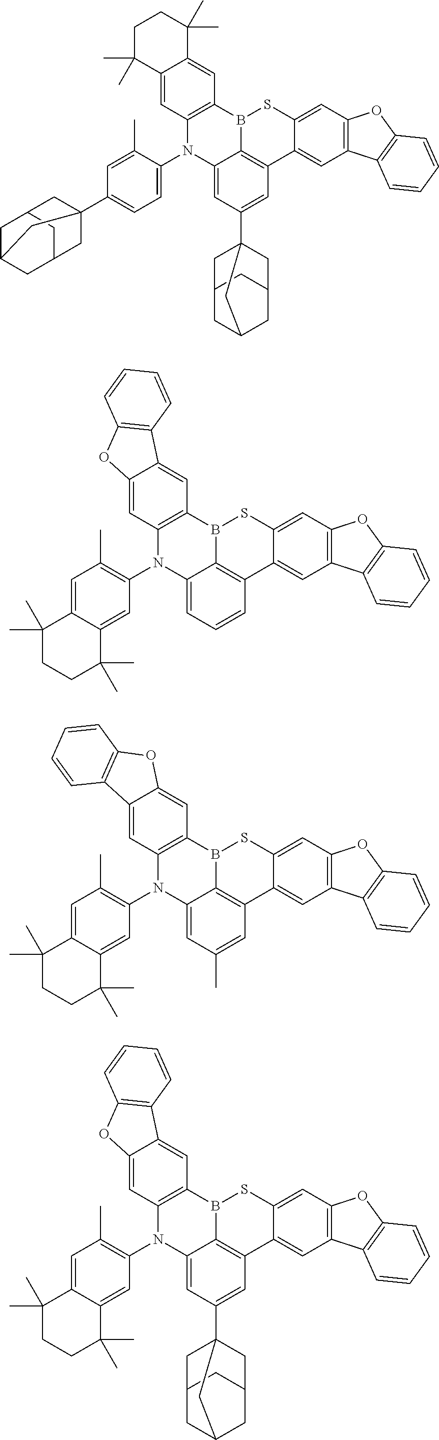

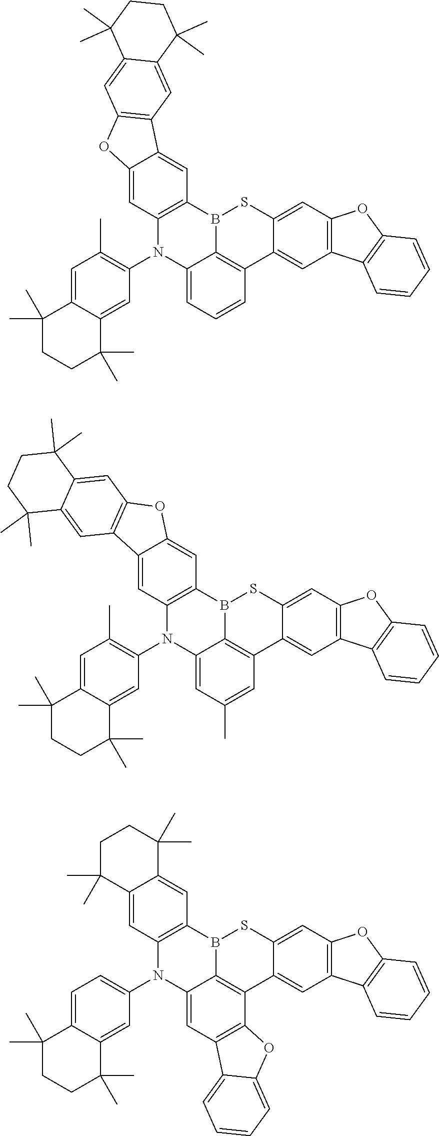 [SMILES: Cc1cc2c(cc1N1c3cc4oc5cc6c(cc5c4cc3B3Sc4cc5oc7ccccc7c5cc4-c4cccc1c43)C(C)(C)CCC6(C)C)C(C)(C)CCC2(C)C ; Cc1cc2c3c(c1)N(c1cc4c(cc1C)C(C)(C)CCC4(C)C)c1cc4c(cc1B3Sc1cc3oc5ccccc5c3cc1-2)oc1cc2c(cc14)C(C)(C)CCC2(C)C ; CC1(C)CCC(C)(C)c2cc(N3c4cc5c(cc4B4Sc6cc7oc8ccccc8c7cc6-c6c4c3cc3c6oc4ccccc43)C(C)(C)CCC5(C)C)ccc21]

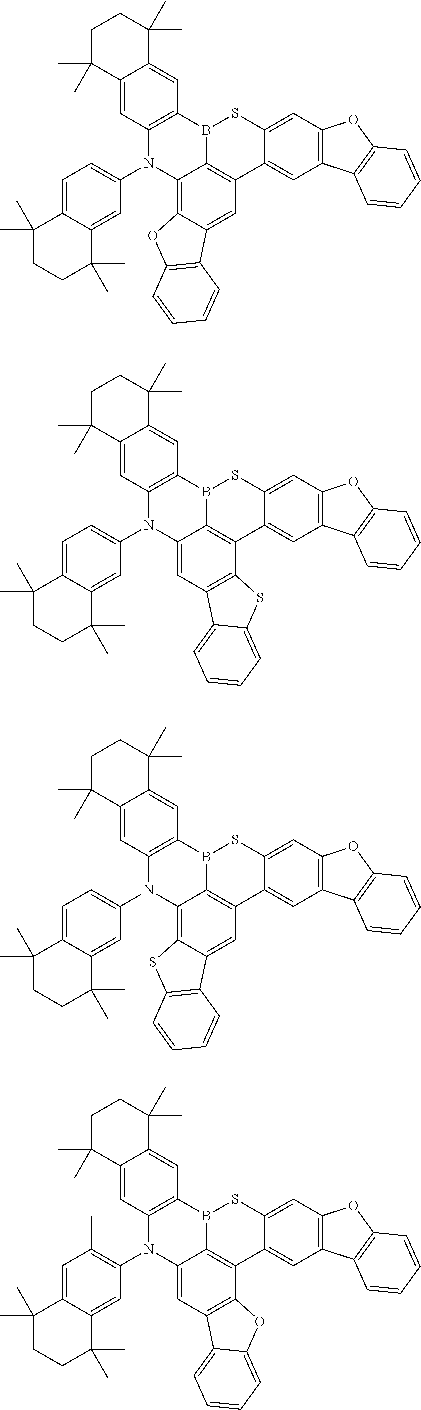

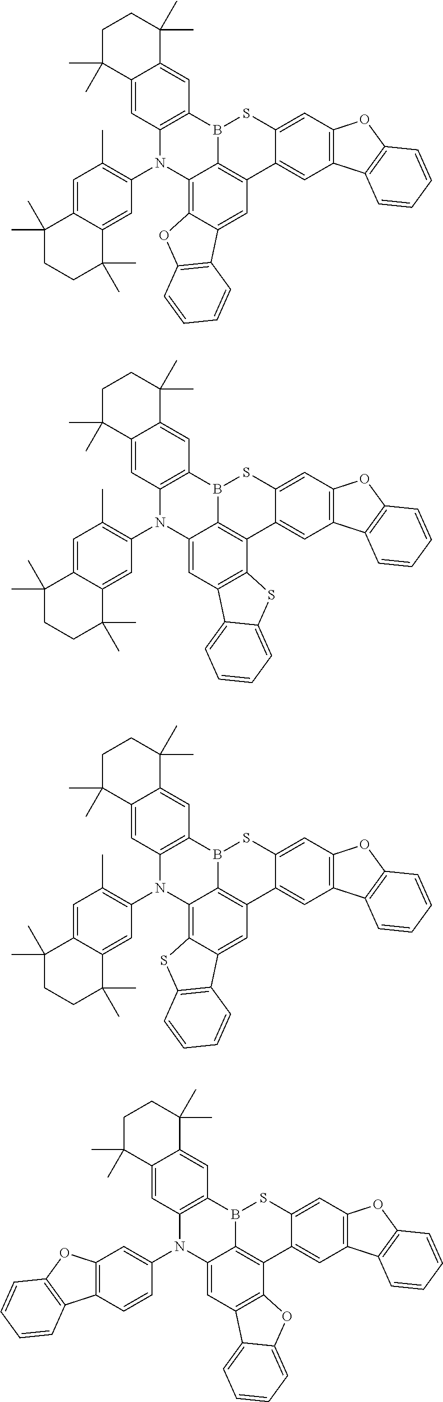

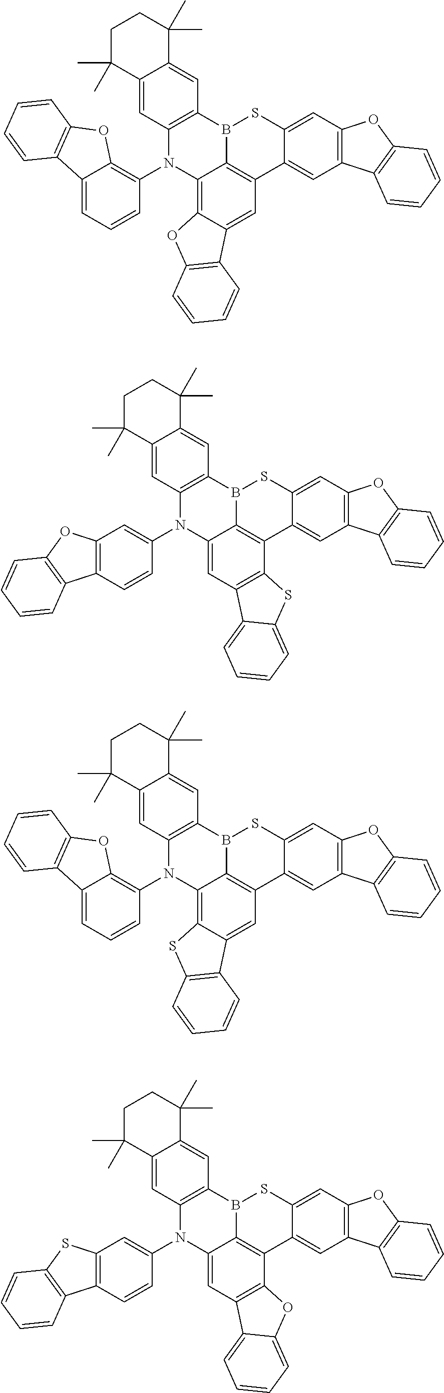

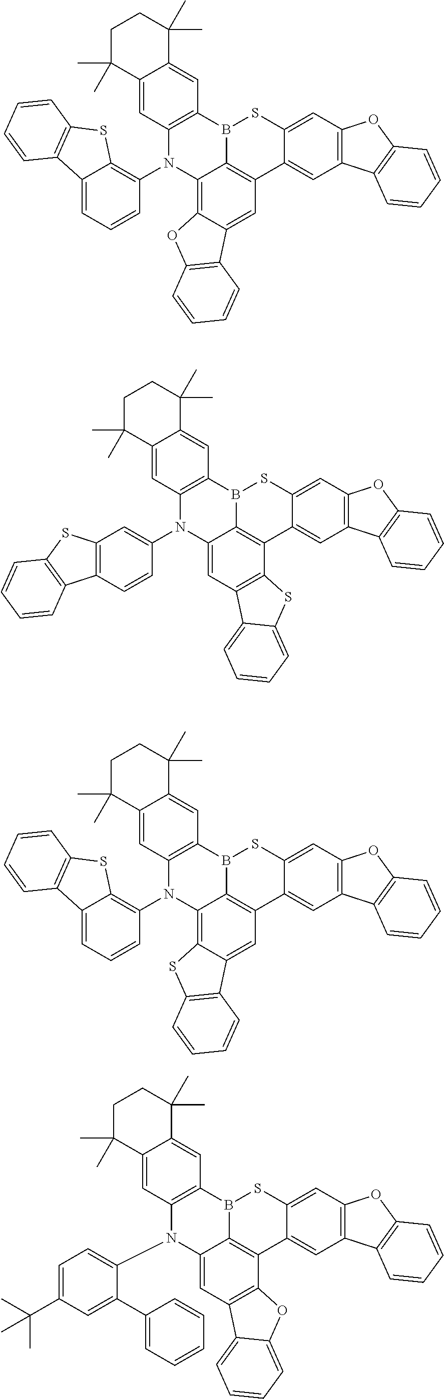

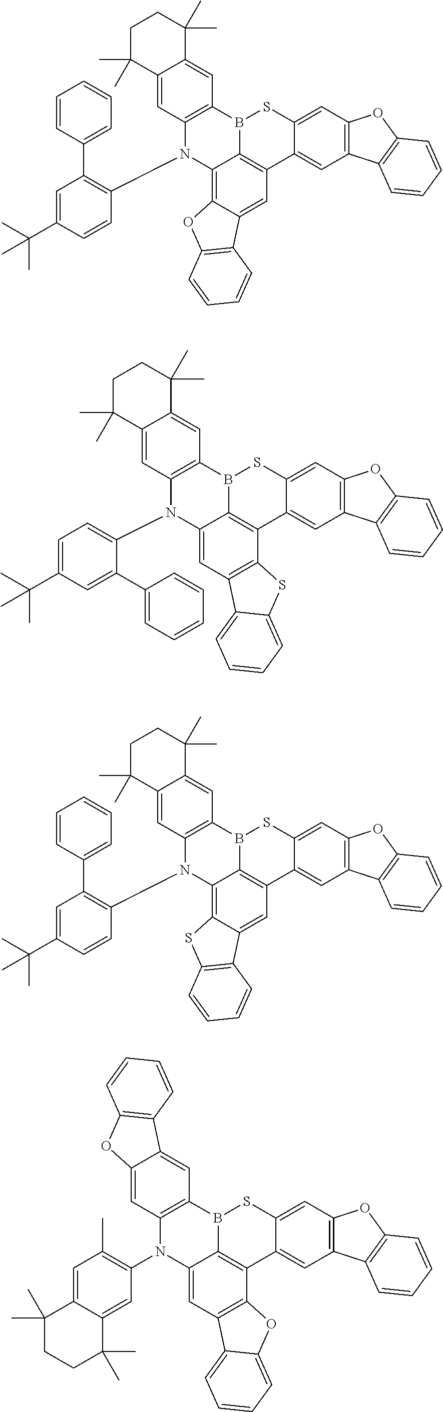 [SMILES: CC(C)(C)c1ccc(N2c3cc4c(cc3B3Sc5cc6oc7ccccc7c6cc5-c5cc6c(oc7ccccc76)c2c53)C(C)(C)CCC4(C)C)c(-c2ccccc2)c1 ; CC(C)(C)c1ccc(N2c3cc4c(cc3B3Sc5cc6oc7ccccc7c6cc5-c5c3c2cc2c5sc3ccccc32)C(C)(C)CCC4(C)C)c(-c2ccccc2)c1 ; CC(C)(C)c1ccc(N2c3cc4c(cc3B3Sc5cc6oc7ccccc7c6cc5-c5cc6c(sc7ccccc76)c2c53)C(C)(C)CCC4(C)C)c(-c2ccccc2)c1 ; Cc1cc2c(cc1N1c3cc4oc5ccccc5c4cc3B3Sc4cc5oc6ccccc6c5cc4-c4c3c1cc1c4oc3ccccc31)C(C)(C)CCC2(C)C]

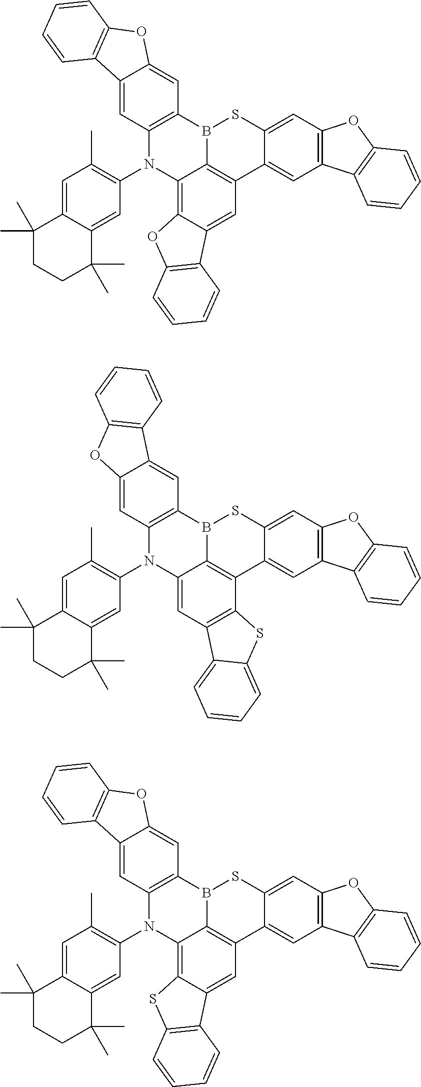 [SMILES: Cc1cc2c(cc1N1c3cc4c(cc3B3Sc5cc6oc7ccccc7c6cc5-c5cc6c(oc7ccccc76)c1c53)oc1ccccc14)C(C)(C)CCC2(C)C ; Cc1cc2c(cc1N1c3cc4oc5ccccc5c4cc3B3Sc4cc5oc6ccccc6c5cc4-c4c3c1cc1c4sc3ccccc31)C(C)(C)CCC2(C)C ; Cc1cc2c(cc1N1c3cc4c(cc3B3Sc5cc6oc7ccccc7c6cc5-c5cc6c(sc7ccccc76)c1c53)oc1ccccc14)C(C)(C)CCC2(C)C]

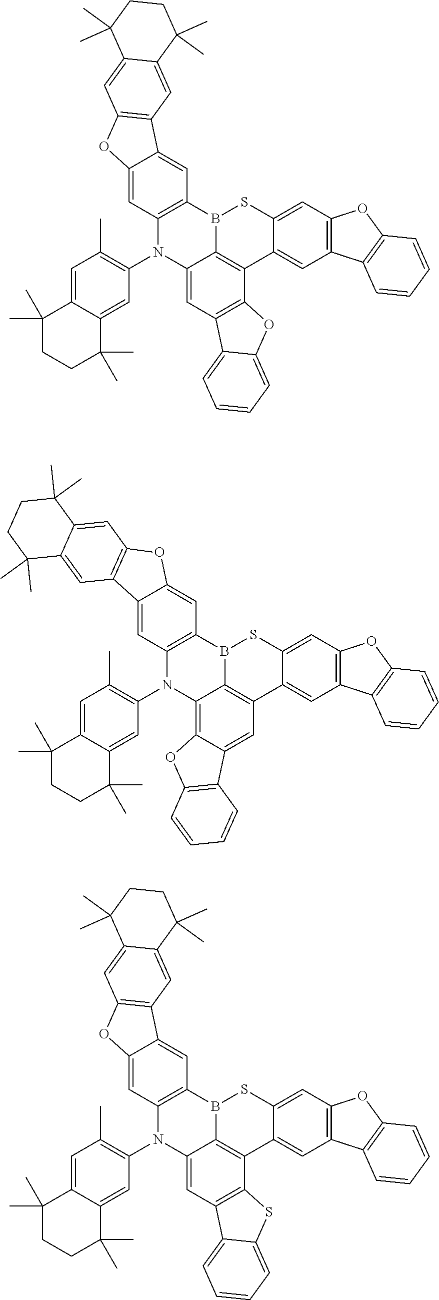 [SMILES: Cc1cc2c(cc1N1c3cc4oc5cc6c(cc5c4cc3B3Sc4cc5oc7ccccc7c5cc4-c4c3c1cc1c4oc3ccccc31)C(C)(C)CCC6(C)C)C(C)(C)CCC2(C)C ; Cc1cc2c(cc1N1c3cc4c(cc3B3Sc5cc6oc7ccccc7c6cc5-c5cc6c(oc7ccccc76)c1c53)oc1cc3c(cc14)C(C)(C)CCC3(C)C)C(C)(C)CCC2(C)C ; Cc1cc2c(cc1N1c3cc4oc5cc6c(cc5c4cc3B3Sc4cc5oc7ccccc7c5cc4-c4c3c1cc1c4sc3ccccc31)C(C)(C)CCC6(C)C)C(C)(C)CCC2(C)C]

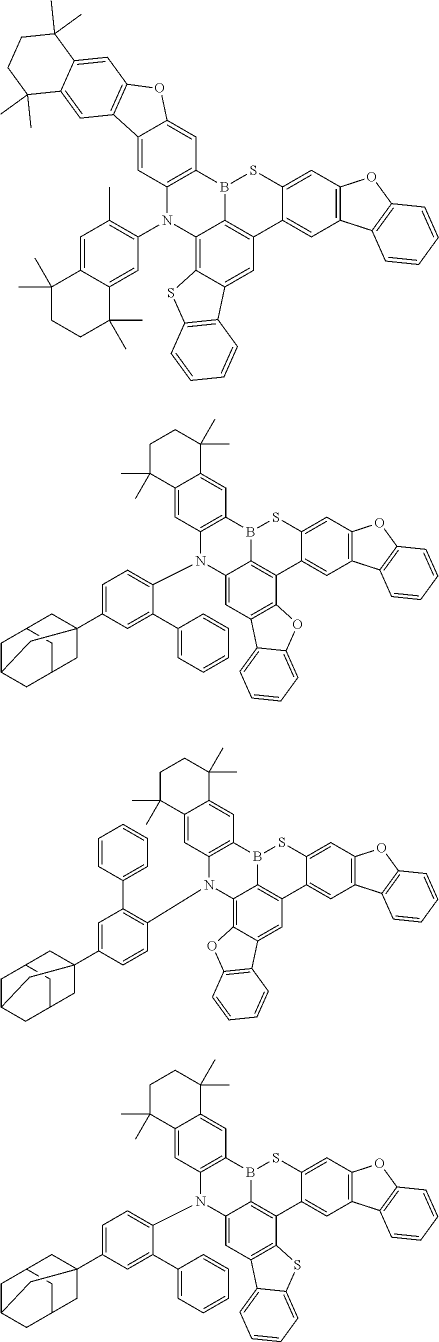 [SMILES: Cc1cc2c(cc1N1c3cc4c(cc3B3Sc5cc6oc7ccccc7c6cc5-c5cc6c(sc7ccccc76)c1c53)oc1cc3c(cc14)C(C)(C)CCC3(C)C)C(C)(C)CCC2(C)C ; CC1(C)CCC(C)(C)c2cc3c(cc21)B1Sc2cc4oc5ccccc5c4cc2-c2c1c(cc1c2oc2ccccc21)N3c1ccc(C23CC4CC(CC(C4)C2)C3)cc1-c1ccccc1 ; CC1(C)CCC(C)(C)c2cc3c(cc21)B1Sc2cc4oc5ccccc5c4cc2-c2cc4c(oc5ccccc54)c(c21)N3c1ccc(C23CC4CC(CC(C4)C2)C3)cc1-c1ccccc1 ; CC1(C)CCC(C)(C)c2cc3c(cc21)B1Sc2cc4oc5ccccc5c4cc2-c2c1c(cc1c2sc2ccccc21)N3c1ccc(C23CC4CC(CC(C4)C2)C3)cc1-c1ccccc1]

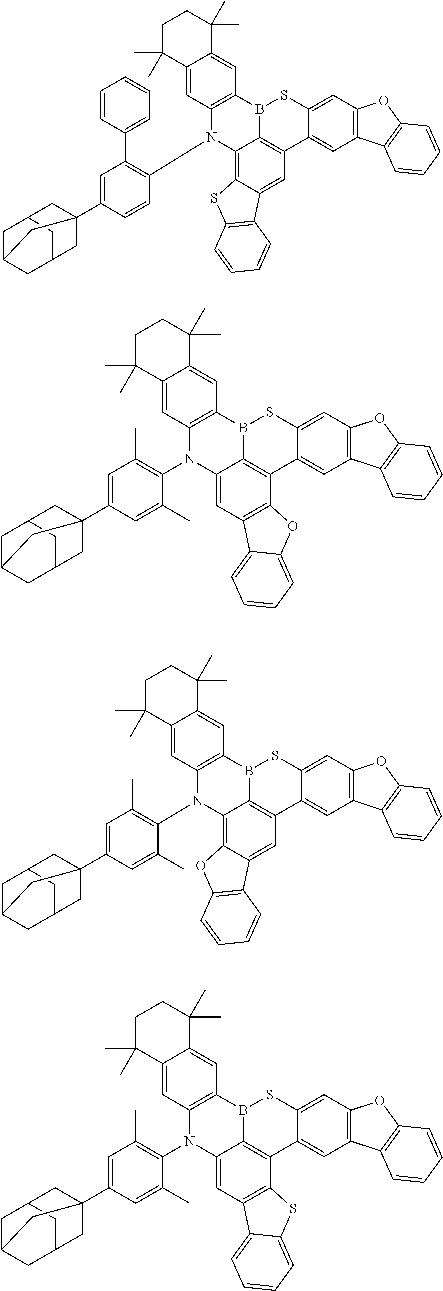 [SMILES: CC1(C)CCC(C)(C)c2cc3c(cc21)B1Sc2cc4oc5ccccc5c4cc2-c2cc4c(sc5ccccc54)c(c21)N3c1ccc(C23CC4CC(CC(C4)C2)C3)cc1-c1ccccc1 ; Cc1cc(C23CC4CC(CC(C4)C2)C3)cc(C)c1N1c2cc3c(cc2B2Sc4cc5oc6ccccc6c5cc4-c4c2c1cc1c4oc2ccccc21)C(C)(C)CCC3(C)C ; Cc1cc(C23CC4CC(CC(C4)C2)C3)cc(C)c1N1c2cc3c(cc2B2Sc4cc5oc6ccccc6c5cc4-c4cc5c(oc6ccccc65)c1c42)C(C)(C)CCC3(C)C ; Cc1cc(C23CC4CC(CC(C4)C2)C3)cc(C)c1N1c2cc3c(cc2B2Sc4cc5oc6ccccc6c5cc4-c4c2c1cc1c4sc2ccccc21)C(C)(C)CCC3(C)C]

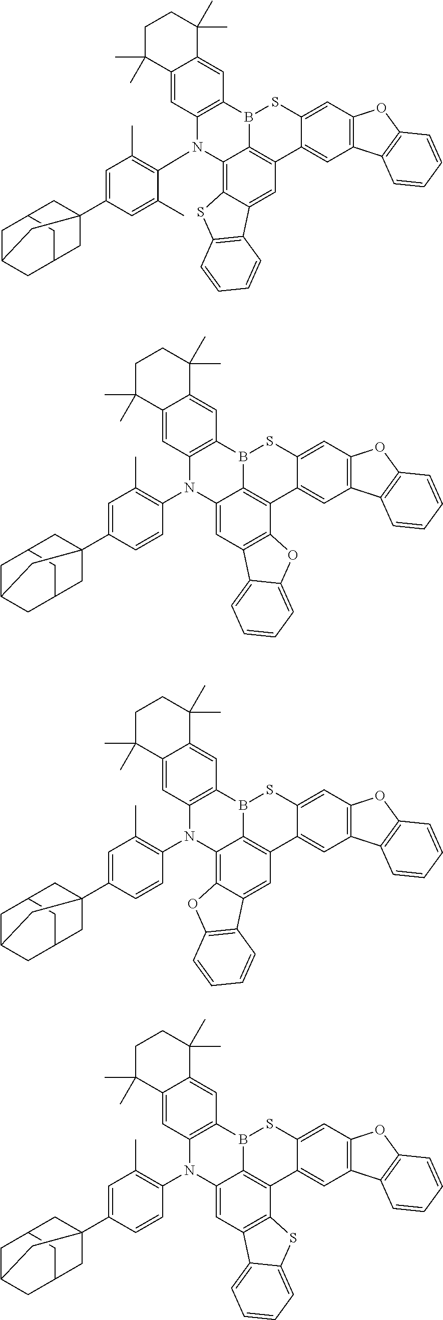

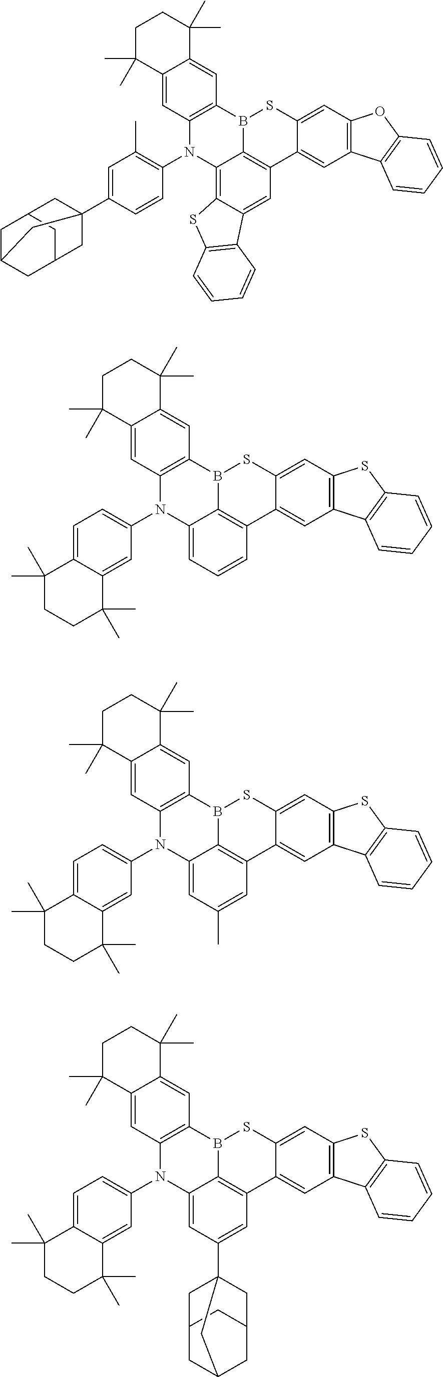 [SMILES: Cc1cc(C23CC4CC(CC(C4)C2)C3)ccc1N1c2cc3c(cc2B2Sc4cc5oc6ccccc6c5cc4-c4cc5c(sc6ccccc65)c1c42)C(C)(C)CCC3(C)C ; CC1(C)CCC(C)(C)c2cc(N3c4cc5c(cc4B4Sc6cc7sc8ccccc8c7cc6-c6cccc3c64)C(C)(C)CCC5(C)C)ccc21 ; Cc1cc2c3c(c1)N(c1ccc4c(c1)C(C)(C)CCC4(C)C)c1cc4c(cc1B3Sc1cc3sc5ccccc5c3cc1-2)C(C)(C)CCC4(C)C ; CC1(C)CCC(C)(C)c2cc(N3c4cc5c(cc4B4Sc6cc7sc8ccccc8c7cc6-c6cc(C78CC9CC(CC(C9)C7)C8)cc3c64)C(C)(C)CCC5(C)C)ccc21]

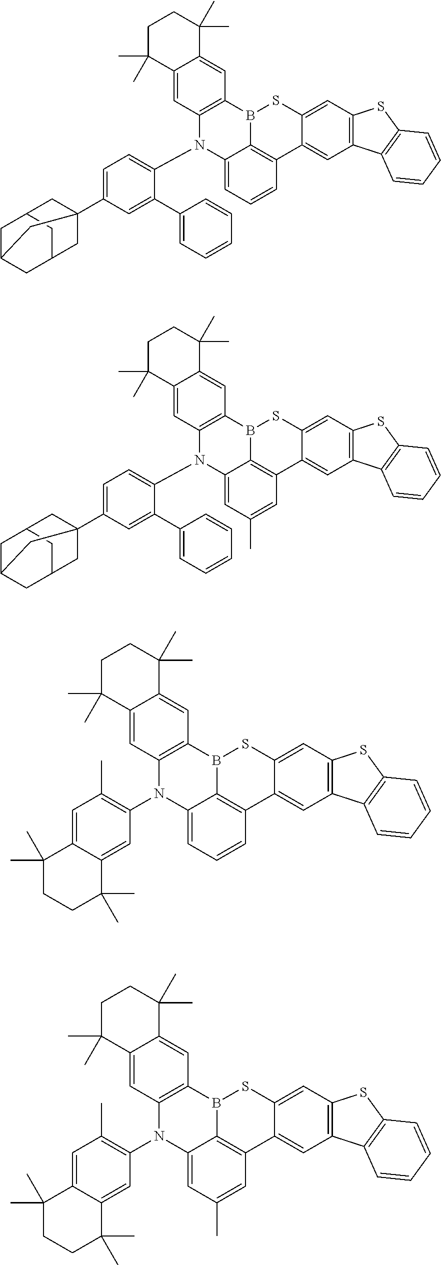 [SMILES: CC1(C)CCC(C)(C)c2cc3c(cc21)B1Sc2cc4sc5ccccc5c4cc2-c2cccc(c21)N3c1ccc(C23CC4CC(CC(C4)C2)C3)cc1-c1ccccc1 ; Cc1cc2c3c(c1)N(c1ccc(C45CC6CC(CC(C6)C4)C5)cc1-c1ccccc1)c1cc4c(cc1B3Sc1cc3sc5ccccc5c3cc1-2)C(C)(C)CCC4(C)C ; Cc1cc2c(cc1N1c3cc4c(cc3B3Sc5cc6sc7ccccc7c6cc5-c5cccc1c53)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Sc1cc3sc5ccccc5c3cc1-2)C(C)(C)CCC4(C)C]

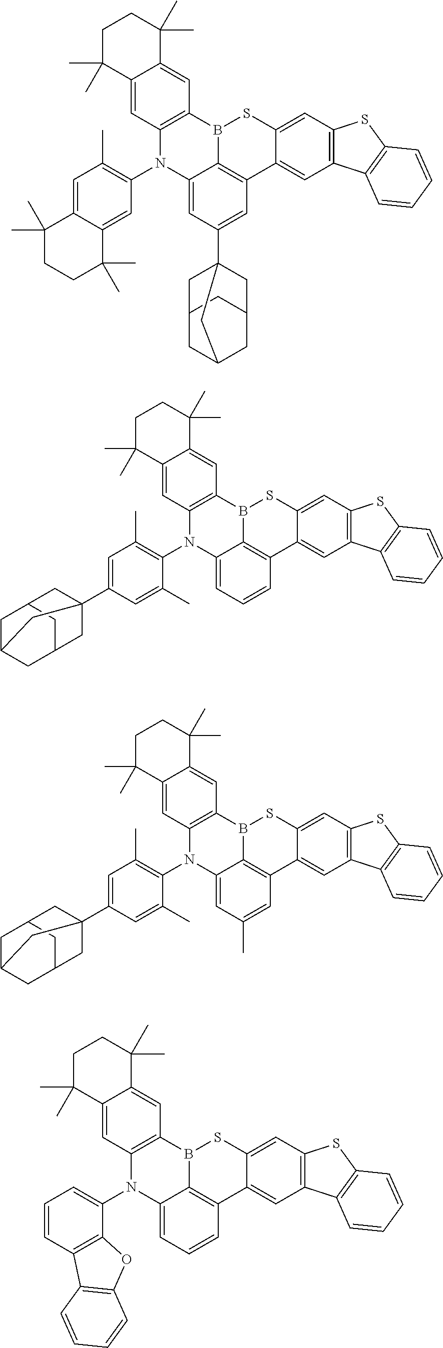

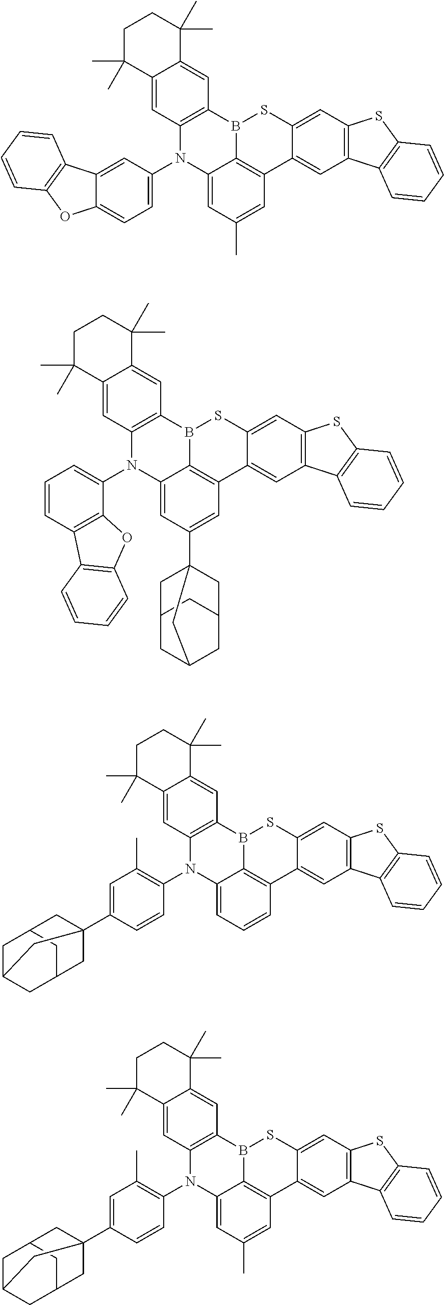 [SMILES: Cc1cc2c3c(c1)N(c1ccc4oc5ccccc5c4c1)c1cc4c(cc1B3Sc1cc3sc5ccccc5c3cc1-2)C(C)(C)CCC4(C)C ; CC1(C)CCC(C)(C)c2cc3c(cc21)B1Sc2cc4sc5ccccc5c4cc2-c2cc(C45CC6CC(CC(C6)C4)C5)cc(c21)N3c1cccc2c1oc1ccccc12 ; Cc1cc(C23CC4CC(CC(C4)C2)C3)ccc1N1c2cc3c(cc2B2Sc4cc5sc6ccccc6c5cc4-c4cccc1c42)C(C)(C)CCC3(C)C ; Cc1cc2c3c(c1)N(c1ccc(C45CC6CC(CC(C6)C4)C5)cc1C)c1cc4c(cc1B3Sc1cc3sc5ccccc5c3cc1-2)C(C)(C)CCC4(C)C]

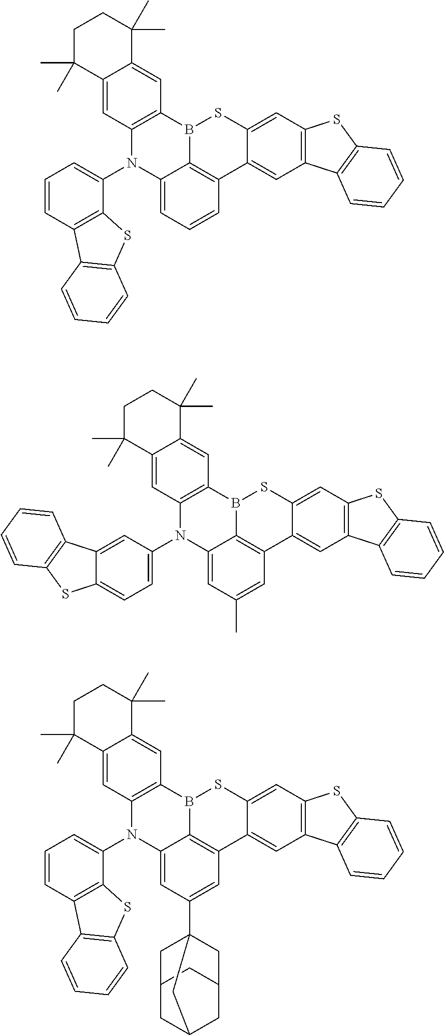 [SMILES: CC1(C)CCC(C)(C)c2cc3c(cc21)B1Sc2cc4sc5ccccc5c4cc2-c2cccc(c21)N3c1cccc2c1sc1ccccc12 ; Cc1cc2c3c(c1)N(c1ccc4sc5ccccc5c4c1)c1cc4c(cc1B3Sc1cc3sc5ccccc5c3cc1-2)C(C)(C)CCC4(C)C ; CC1(C)CCC(C)(C)c2cc3c(cc21)B1Sc2cc4sc5ccccc5c4cc2-c2cc(C45CC6CC(CC(C6)C4)C5)cc(c21)N3c1cccc2c1sc1ccccc12]

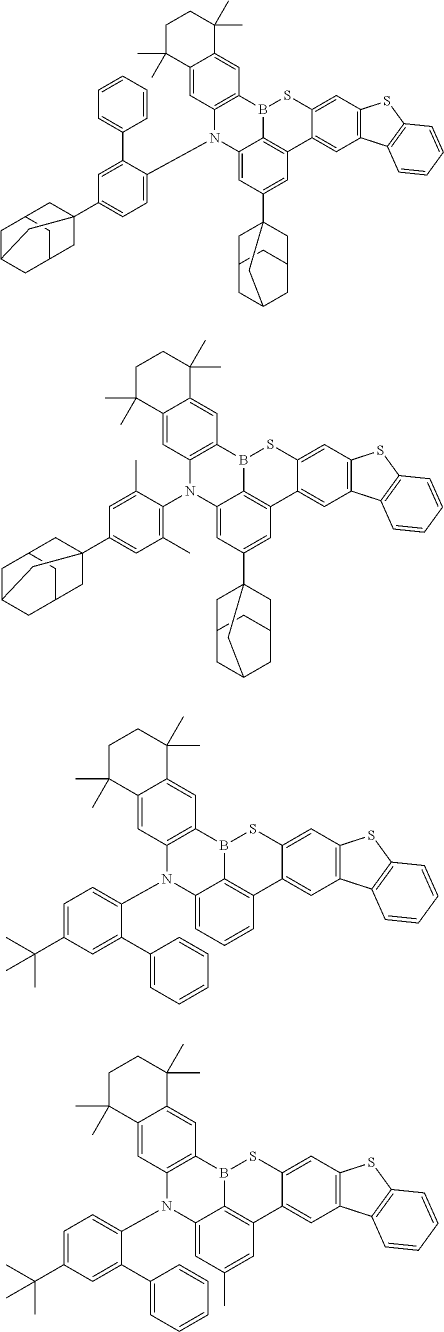

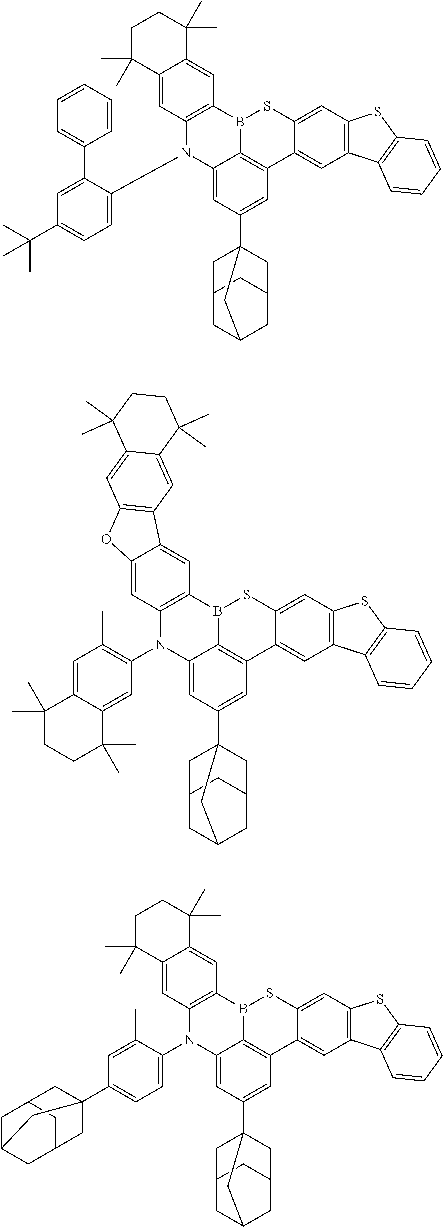 [SMILES: CC(C)(C)c1ccc(N2c3cc4c(cc3B3Sc5cc6sc7ccccc7c6cc5-c5cc(C67CC8CC(CC(C8)C6)C7)cc2c53)C(C)(C)CCC4(C)C)c(-c2ccccc2)c1 ; Cc1cc2c(cc1N1c3cc4oc5cc6c(cc5c4cc3B3Sc4cc5sc7ccccc7c5cc4-c4cc(C57CC8CC(CC(C8)C5)C7)cc1c43)C(C)(C)CCC6(C)C)C(C)(C)CCC2(C)C ; Cc1cc(C23CC4CC(CC(C4)C2)C3)ccc1N1c2cc3c(cc2B2Sc4cc5sc6ccccc6c5cc4-c4cc(C56CC7CC(CC(C7)C5)C6)cc1c42)C(C)(C)CCC3(C)C]

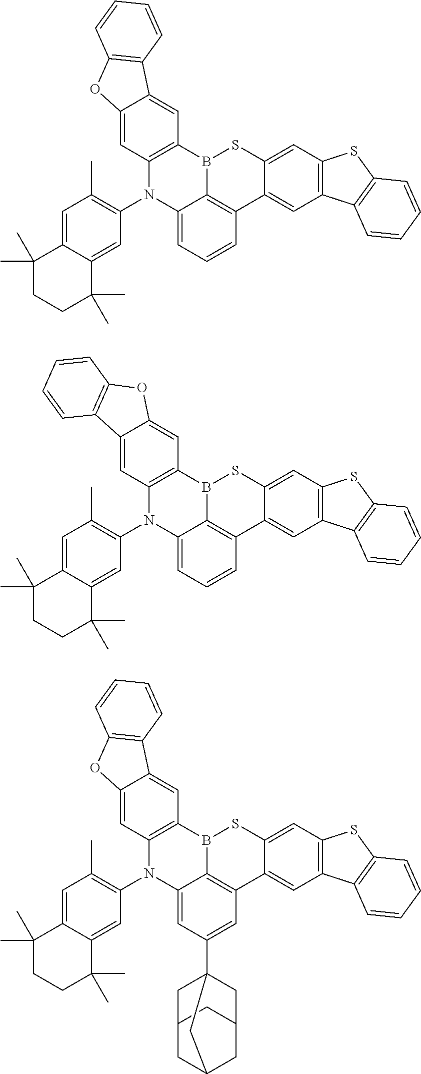

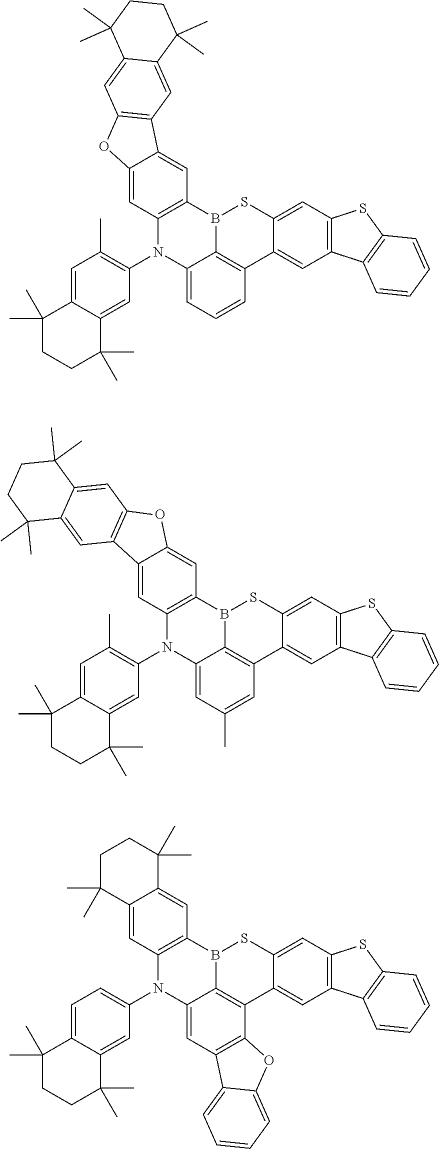 [SMILES: Cc1cc2c(cc1N1c3cc4oc5cc6c(cc5c4cc3B3Sc4cc5sc7ccccc7c5cc4-c4cccc1c43)C(C)(C)CCC6(C)C)C(C)(C)CCC2(C)C ; Cc1cc2c3c(c1)N(c1cc4c(cc1C)C(C)(C)CCC4(C)C)c1cc4c(cc1B3Sc1cc3sc5ccccc5c3cc1-2)oc1cc2c(cc14)C(C)(C)CCC2(C)C ; CC1(C)CCC(C)(C)c2cc(N3c4cc5c(cc4B4Sc6cc7sc8ccccc8c7cc6-c6c4c3cc3c6oc4ccccc43)C(C)(C)CCC5(C)C)ccc21]

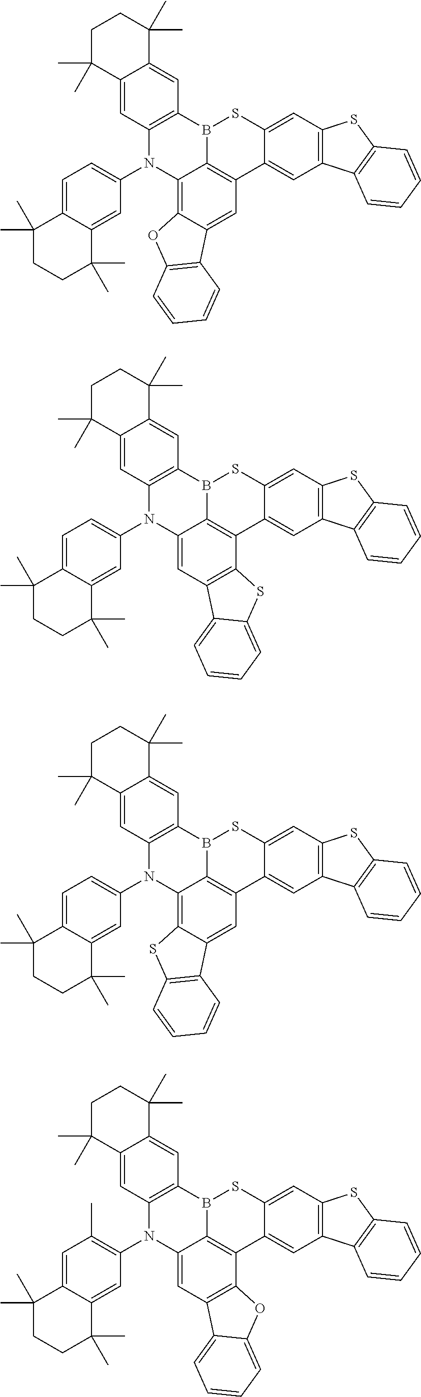

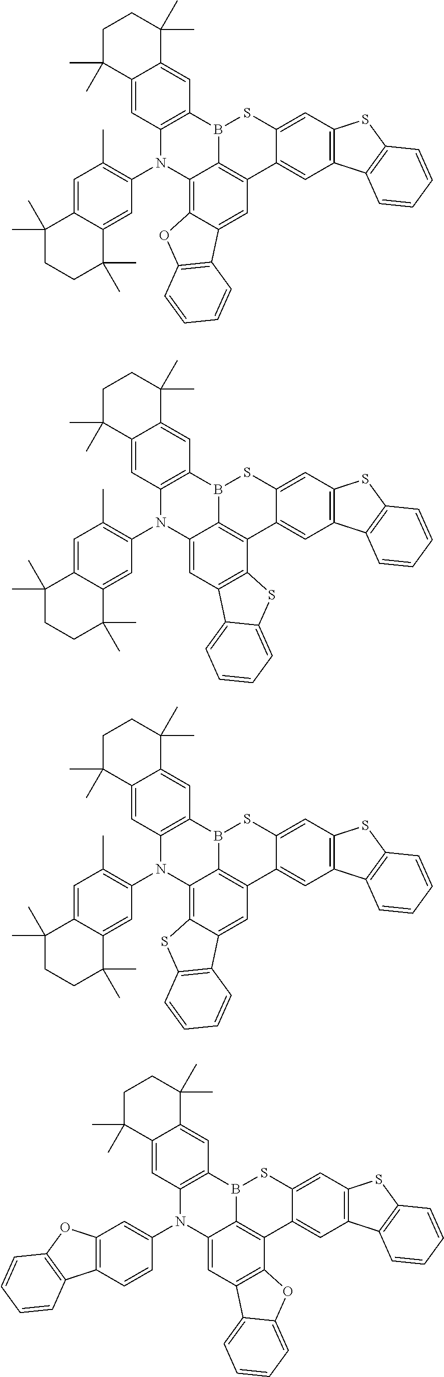

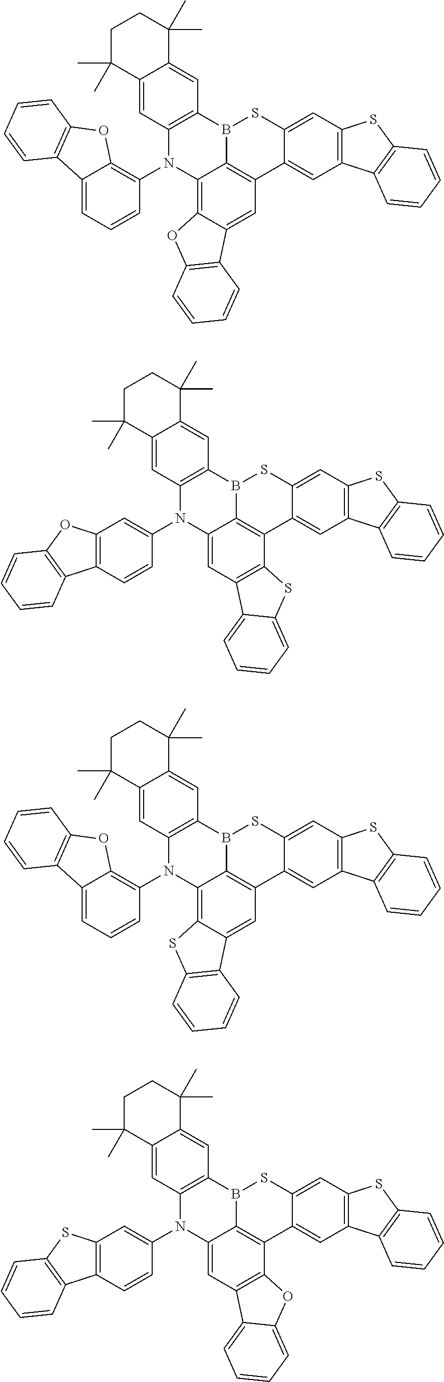

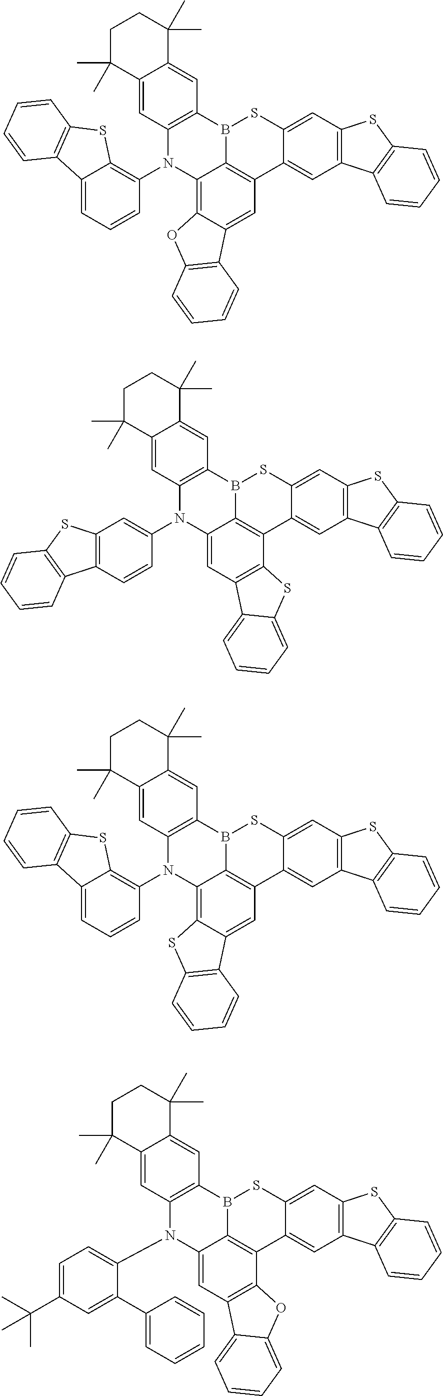

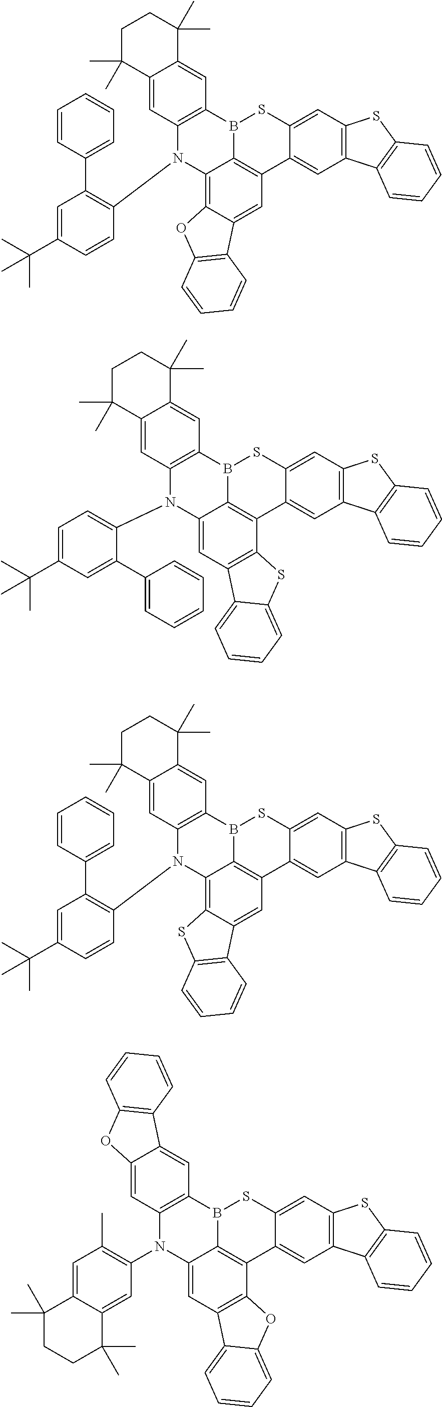

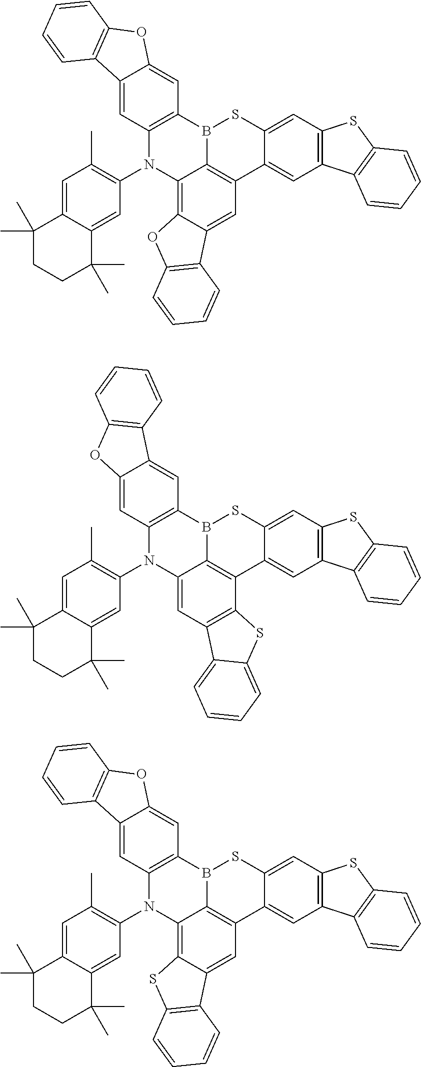 [SMILES: Cc1cc2c(cc1N1c3cc4c(cc3B3Sc5cc6sc7ccccc7c6cc5-c5cc6c(oc7ccccc76)c1c53)oc1ccccc14)C(C)(C)CCC2(C)C ; Cc1cc2c(cc1N1c3cc4oc5ccccc5c4cc3B3Sc4cc5sc6ccccc6c5cc4-c4c3c1cc1c4sc3ccccc31)C(C)(C)CCC2(C)C ; Cc1cc2c(cc1N1c3cc4c(cc3B3Sc5cc6sc7ccccc7c6cc5-c5cc6c(sc7ccccc76)c1c53)oc1ccccc14)C(C)(C)CCC2(C)C]

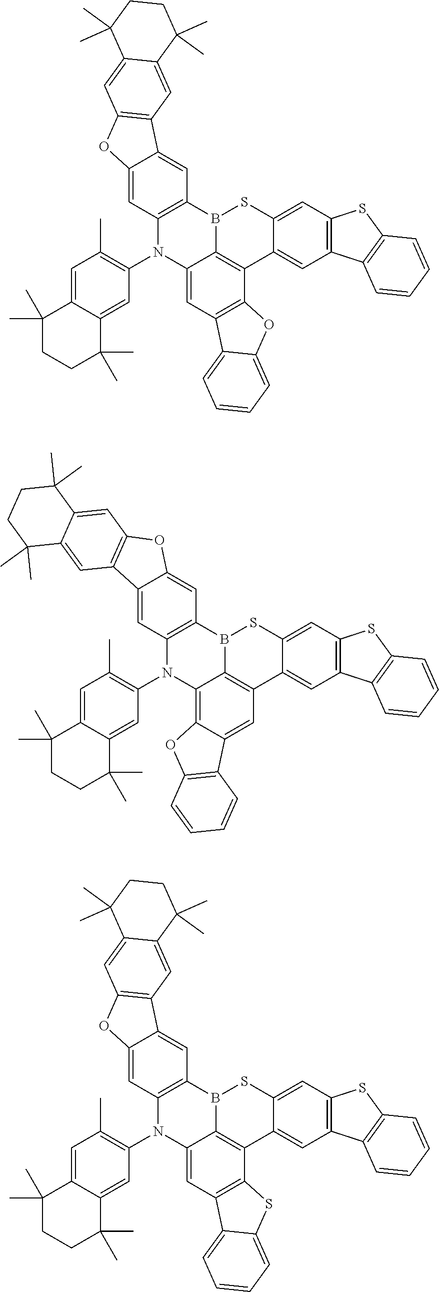 [SMILES: Cc1cc2c(cc1N1c3cc4oc5cc6c(cc5c4cc3B3Sc4cc5sc7ccccc7c5cc4-c4c3c1cc1c4oc3ccccc31)C(C)(C)CCC6(C)C)C(C)(C)CCC2(C)C ; Cc1cc2c(cc1N1c3cc4c(cc3B3Sc5cc6sc7ccccc7c6cc5-c5cc6c(oc7ccccc76)c1c53)oc1cc3c(cc14)C(C)(C)CCC3(C)C)C(C)(C)CCC2(C)C ; Cc1cc2c(cc1N1c3cc4oc5cc6c(cc5c4cc3B3Sc4cc5sc7ccccc7c5cc4-c4c3c1cc1c4sc3ccccc31)C(C)(C)CCC6(C)C)C(C)(C)CCC2(C)C]

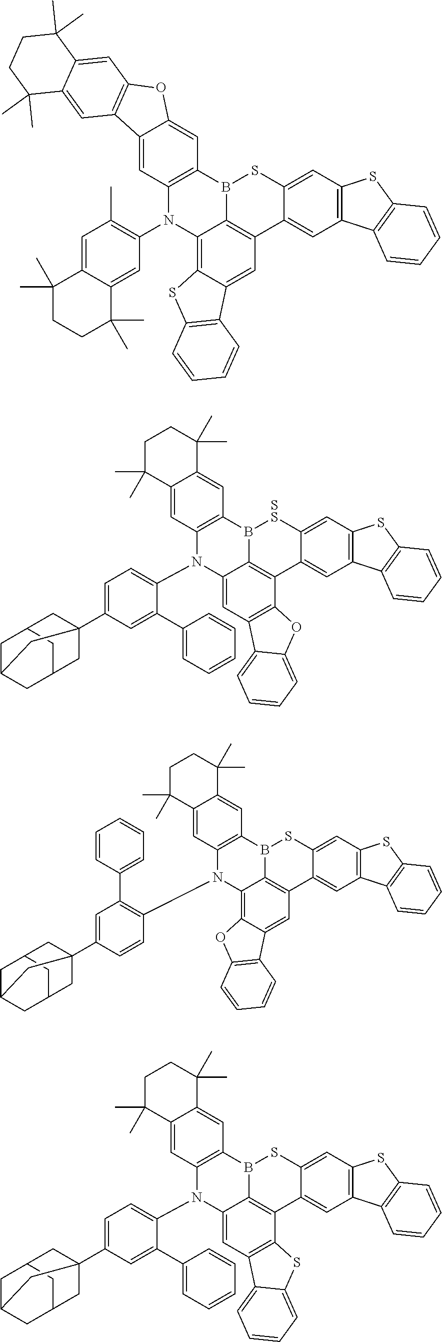

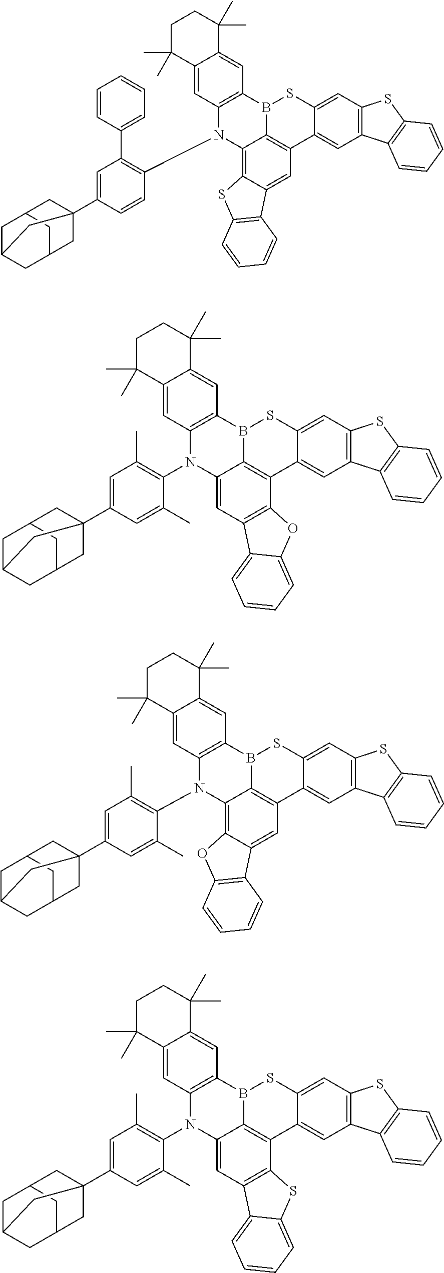 [SMILES: CC1(C)CCC(C)(C)c2cc3c(cc21)B1Sc2cc4sc5ccccc5c4cc2-c2cc4c(sc5ccccc54)c(c21)N3c1ccc(C23CC4CC(CC(C4)C2)C3)cc1-c1ccccc1 ; Cc1cc(C23CC4CC(CC(C4)C2)C3)cc(C)c1N1c2cc3c(cc2B2Sc4cc5sc6ccccc6c5cc4-c4c2c1cc1c4oc2ccccc21)C(C)(C)CCC3(C)C ; Cc1cc(C23CC4CC(CC(C4)C2)C3)cc(C)c1N1c2cc3c(cc2B2Sc4cc5sc6ccccc6c5cc4-c4cc5c(oc6ccccc65)c1c42)C(C)(C)CCC3(C)C ; Cc1cc(C23CC4CC(CC(C4)C2)C3)cc(C)c1N1c2cc3c(cc2B2Sc4cc5sc6ccccc6c5cc4-c4c2c1cc1c4sc2ccccc21)C(C)(C)CCC3(C)C]

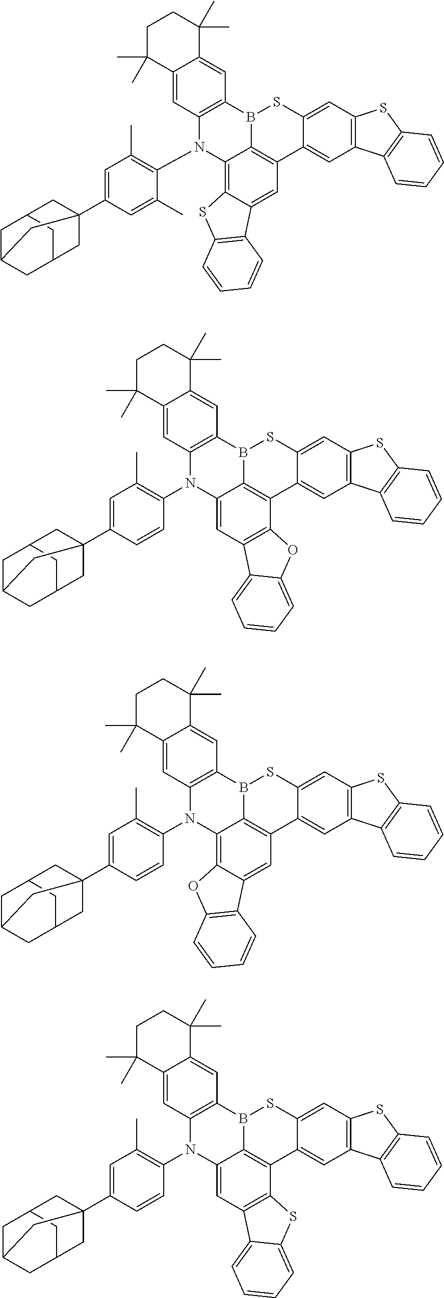

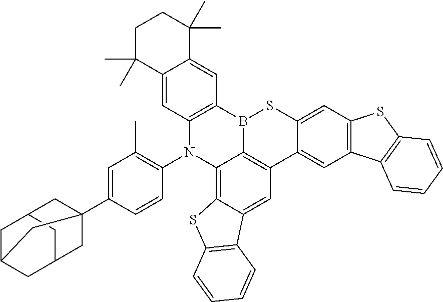 [SMILES: Cc1cc(C23CC4CC(CC(C4)C2)C3)ccc1N1c2cc3c(cc2B2Sc4cc5sc6ccccc6c5cc4-c4cc5c(sc6ccccc65)c1c42)C(C)(C)CCC3(C)C]

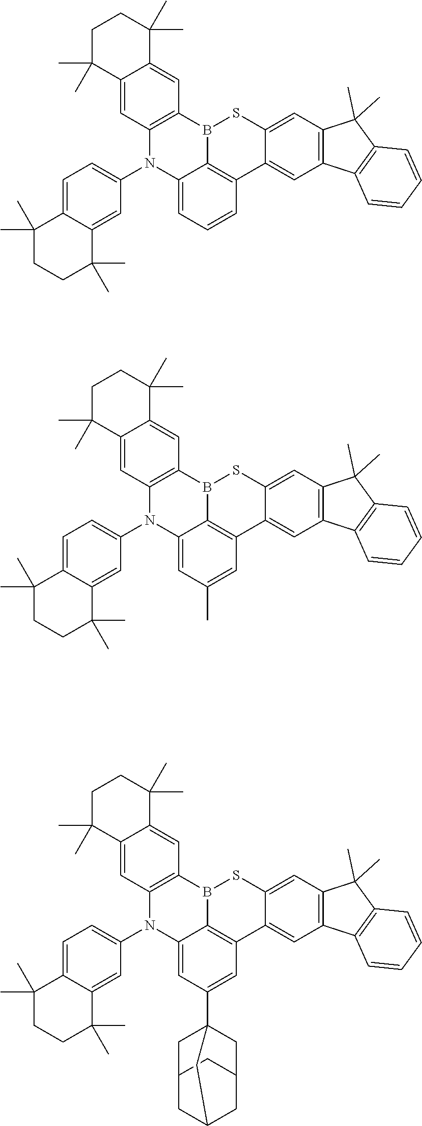 [SMILES: CC1(C)CCC(C)(C)c2cc(N3c4cc5c(cc4B4Sc6cc7c(cc6-c6cccc3c64)-c3ccccc3C7(C)C)C(C)(C)CCC5(C)C)ccc21 ; Cc1cc2c3c(c1)N(c1ccc4c(c1)C(C)(C)CCC4(C)C)c1cc4c(cc1B3Sc1cc3c(cc1-2)-c1ccccc1C3(C)C)C(C)(C)CCC4(C)C ; CC1(C)CCC(C)(C)c2cc(N3c4cc5c(cc4B4Sc6cc7c(cc6-c6cc(C89CC%10CC(CC(C%10)C8)C9)cc3c64)-c3ccccc3C7(C)C)C(C)(C)CCC5(C)C)ccc21]

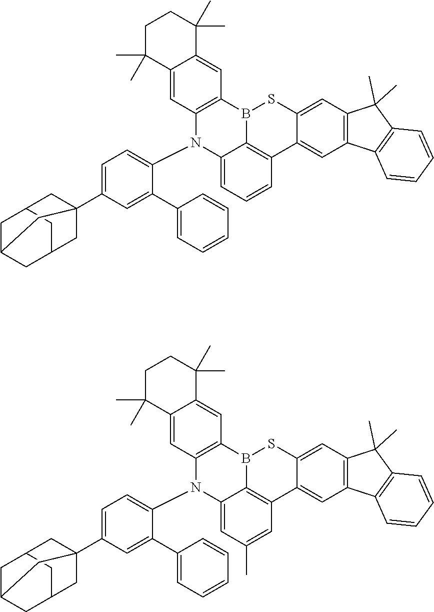 [SMILES: CC1(C)CCC(C)(C)c2cc3c(cc21)B1Sc2cc4c(cc2-c2cccc(c21)N3c1ccc(C23CC5CC(CC(C5)C2)C3)cc1-c1ccccc1)-c1ccccc1C4(C)C ; Cc1cc2c3c(c1)N(c1ccc(C45CC6CC(CC(C6)C4)C5)cc1-c1ccccc1)c1cc4c(cc1B3Sc1cc3c(cc1-2)-c1ccccc1C3(C)C)C(C)(C)CCC4(C)C]

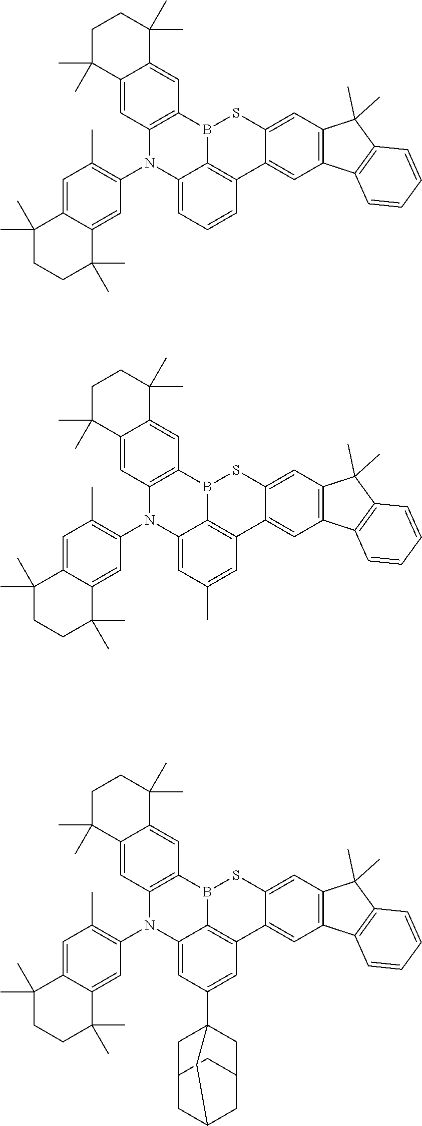 [SMILES: Cc1cc2c(cc1N1c3cc4c(cc3B3Sc5cc6c(cc5-c5cccc1c53)-c1ccccc1C6(C)C)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Sc1cc3c(cc1-2)-c1ccccc1C3(C)C)C(C)(C)CCC4(C)C ; Cc1cc2c(cc1N1c3cc4c(cc3B3Sc5cc6c(cc5-c5cc(C78CC9CC(CC(C9)C7)C8)cc1c53)-c1ccccc1C6(C)C)C(C)(C)CCC4(C)C)C(C)(C)CCC2(C)C]

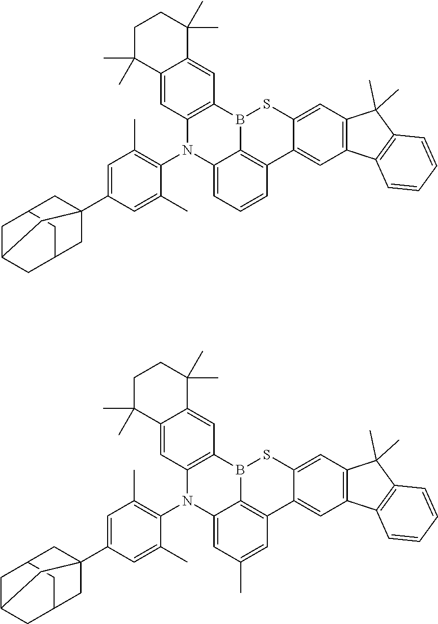 [SMILES: Cc1cc(C23CC4CC(CC(C4)C2)C3)cc(C)c1N1c2cc3c(cc2B2Sc4cc5c(cc4-c4cccc1c42)-c1ccccc1C5(C)C)C(C)(C)CCC3(C)C ; Cc1cc2c3c(c1)N(c1c(C)cc(C45CC6CC(CC(C6)C4)C5)cc1C)c1cc4c(cc1B3Sc1cc3c(cc1-2)-c1ccccc1C3(C)C)C(C)(C)CCC4(C)C]

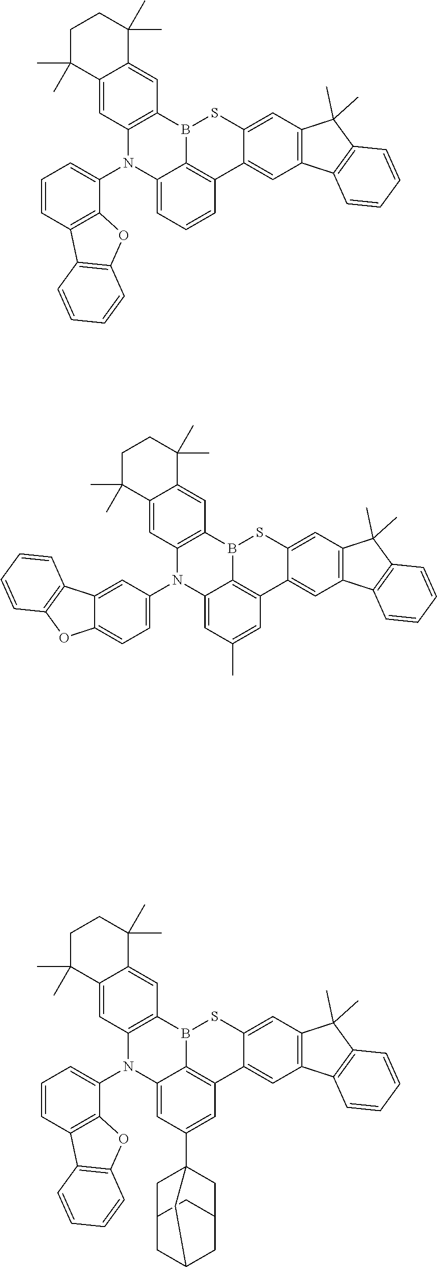 [SMILES: CC1(C)CCC(C)(C)c2cc3c(cc21)B1Sc2cc4c(cc2-c2cccc(c21)N3c1cccc2c1oc1ccccc12)-c1ccccc1C4(C)C ; Cc1cc2c3c(c1)N(c1ccc4oc5ccccc5c4c1)c1cc4c(cc1B3Sc1cc3c(cc1-2)-c1ccccc1C3(C)C)C(C)(C)CCC4(C)C ; CC1(C)CCC(C)(C)c2cc3c(cc21)B1Sc2cc4c(cc2-c2cc(C56CC7CC(CC(C7)C5)C6)cc(c21)N3c1cccc2c1oc1ccccc12)-c1ccccc1C4(C)C]

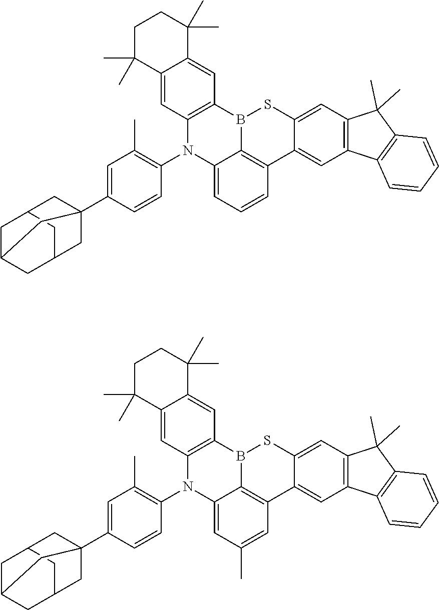 [SMILES: Cc1cc(C23CC4CC(CC(C4)C2)C3)ccc1N1c2cc3c(cc2B2Sc4cc5c(cc4-c4cccc1c42)-c1ccccc1C5(C)C)C(C)(C)CCC3(C)C ; Cc1cc2c3c(c1)N(c1ccc(C45CC6CC(CC(C6)C4)C5)cc1C)c1cc4c(cc1B3Sc1cc3c(cc1-2)-c1ccccc1C3(C)C)C(C)(C)CCC4(C)C]

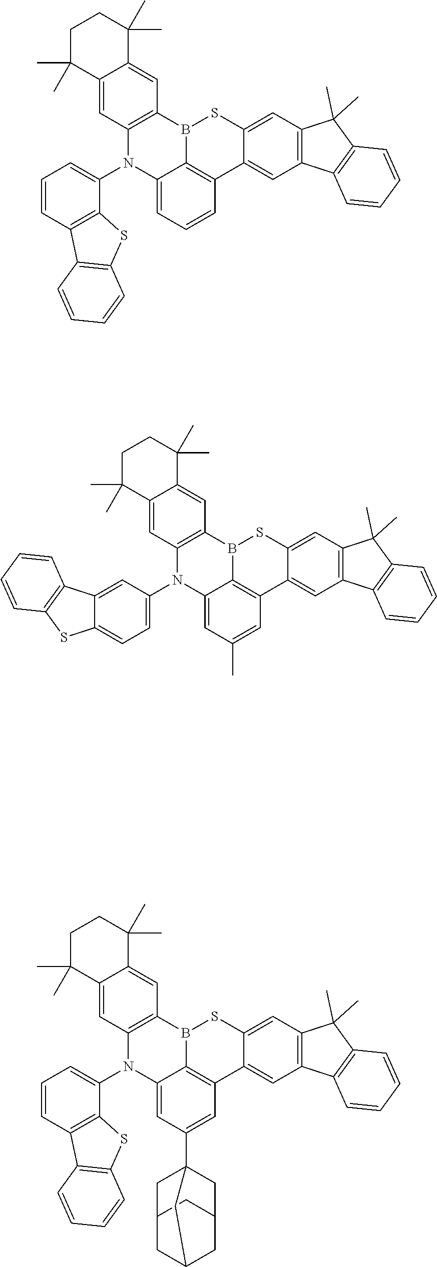 [SMILES: CC1(C)CCC(C)(C)c2cc3c(cc21)B1Sc2cc4c(cc2-c2cccc(c21)N3c1cccc2c1sc1ccccc12)-c1ccccc1C4(C)C ; Cc1cc2c3c(c1)N(c1ccc4sc5ccccc5c4c1)c1cc4c(cc1B3Sc1cc3c(cc1-2)-c1ccccc1C3(C)C)C(C)(C)CCC4(C)C ; CC1(C)CCC(C)(C)c2cc3c(cc21)B1Sc2cc4c(cc2-c2cc(C56CC7CC(CC(C7)C5)C6)cc(c21)N3c1cccc2c1sc1ccccc12)-c1ccccc1C4(C)C]

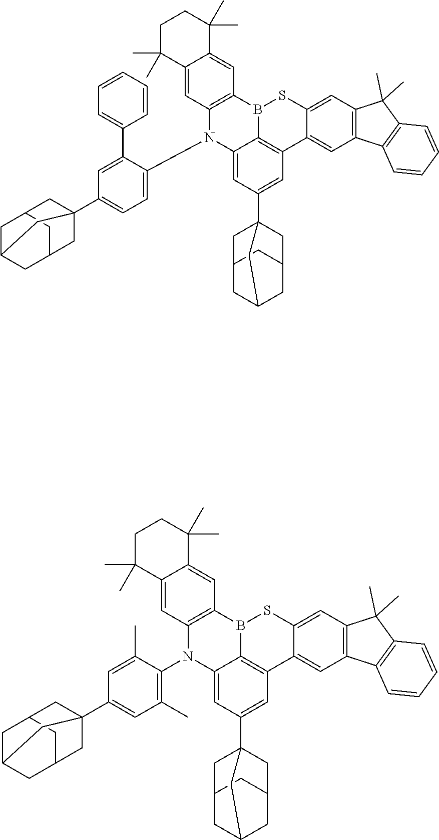 [SMILES: CC1(C)CCC(C)(C)c2cc3c(cc21)B1Sc2cc4c(cc2-c2cc(C56CC7CC(CC(C7)C5)C6)cc(c21)N3c1ccc(C23CC5CC(CC(C5)C2)C3)cc1-c1ccccc1)-c1ccccc1C4(C)C ; Cc1cc(C23CC4CC(CC(C4)C2)C3)cc(C)c1N1c2cc3c(cc2B2Sc4cc5c(cc4-c4cc(C67CC8CC(CC(C8)C6)C7)cc1c42)-c1ccccc1C5(C)C)C(C)(C)CCC3(C)C]

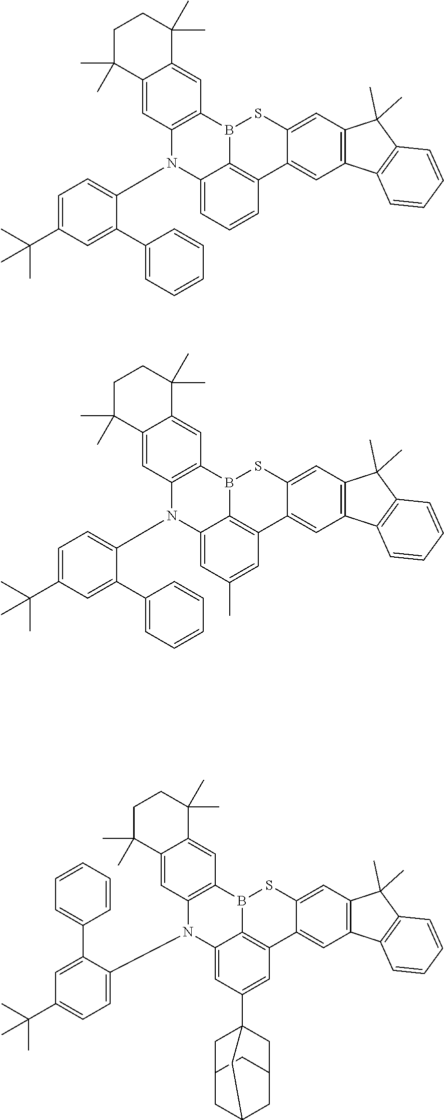 [SMILES: CC(C)(C)c1ccc(N2c3cc4c(cc3B3Sc5cc6c(cc5-c5cccc2c53)-c2ccccc2C6(C)C)C(C)(C)CCC4(C)C)c(-c2ccccc2)c1 ; Cc1cc2c3c(c1)N(c1ccc(C(C)(C)C)cc1-c1ccccc1)c1cc4c(cc1B3Sc1cc3c(cc1-2)-c1ccccc1C3(C)C)C(C)(C)CCC4(C)C ; CC(C)(C)c1ccc(N2c3cc4c(cc3B3Sc5cc6c(cc5-c5cc(C78CC9CC(CC(C9)C7)C8)cc2c53)-c2ccccc2C6(C)C)C(C)(C)CCC4(C)C)c(-c2ccccc2)c1]

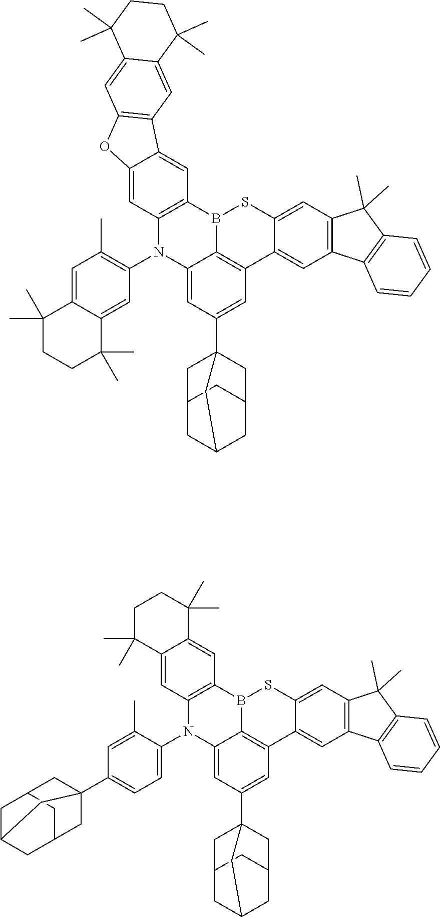 [SMILES: Cc1cc2c(cc1N1c3cc4oc5cc6c(cc5c4cc3B3Sc4cc5c(cc4-c4cc(C78CC9CC(CC(C9)C7)C8)cc1c43)-c1ccccc1C5(C)C)C(C)(C)CCC6(C)C)C(C)(C)CCC2(C)C ; Cc1cc(C23CC4CC(CC(C4)C2)C3)ccc1N1c2cc3c(cc2B2Sc4cc5c(cc4-c4cc(C67CC8CC(CC(C8)C6)C7)cc1c42)-c1ccccc1C5(C)C)C(C)(C)CCC3(C)C]

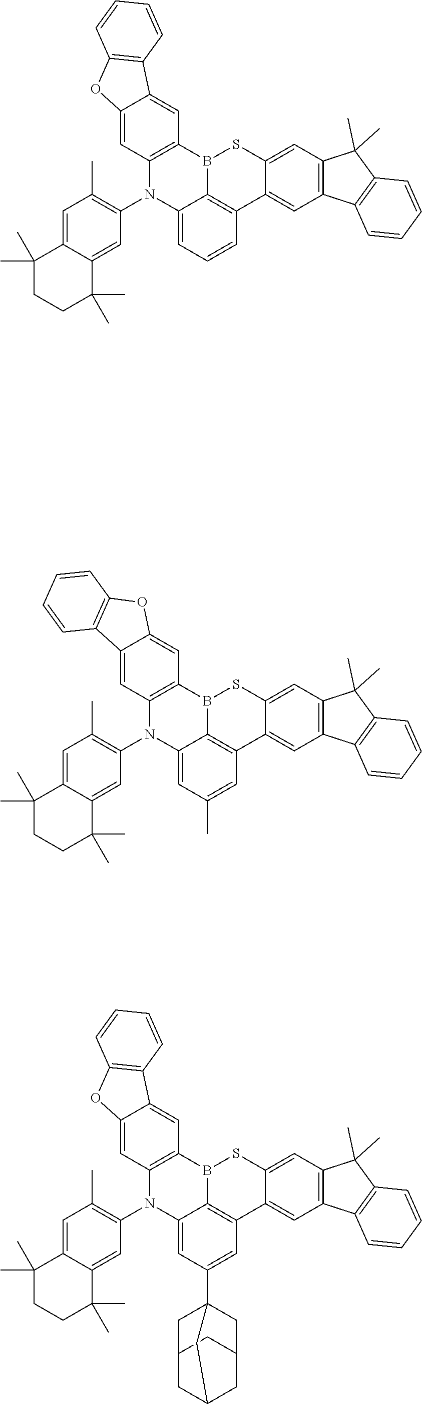 [SMILES: Cc1cc2c(cc1N1c3cc4oc5ccccc5c4cc3B3Sc4cc5c(cc4-c4cccc1c43)-c1ccccc1C5(C)C)C(C)(C)CCC2(C)C ; Cc1cc2c3c(c1)N(c1cc4c(cc1C)C(C)(C)CCC4(C)C)c1cc4c(cc1B3Sc1cc3c(cc1-2)-c1ccccc1C3(C)C)oc1ccccc14 ; Cc1cc2c(cc1N1c3cc4oc5ccccc5c4cc3B3Sc4cc5c(cc4-c4cc(C67CC8CC(CC(C8)C6)C7)cc1c43)-c1ccccc1C5(C)C)C(C)(C)CCC2(C)C]

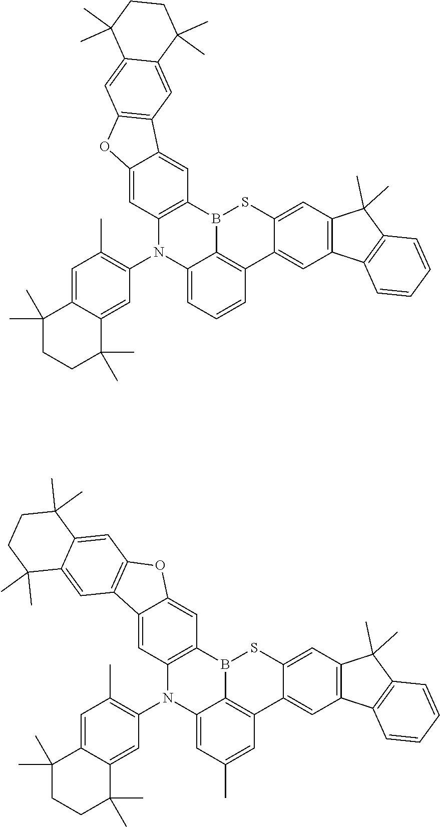 [SMILES: Cc1cc2c(cc1N1c3cc4oc5cc6c(cc5c4cc3B3Sc4cc5c(cc4-c4cccc1c43)-c1ccccc1C5(C)C)C(C)(C)CCC6(C)C)C(C)(C)CCC2(C)C ; Cc1cc2c3c(c1)N(c1cc4c(cc1C)C(C)(C)CCC4(C)C)c1cc4c(cc1B3Sc1cc3c(cc1-2)-c1ccccc1C3(C)C)oc1cc2c(cc14)C(C)(C)CCC2(C)C]

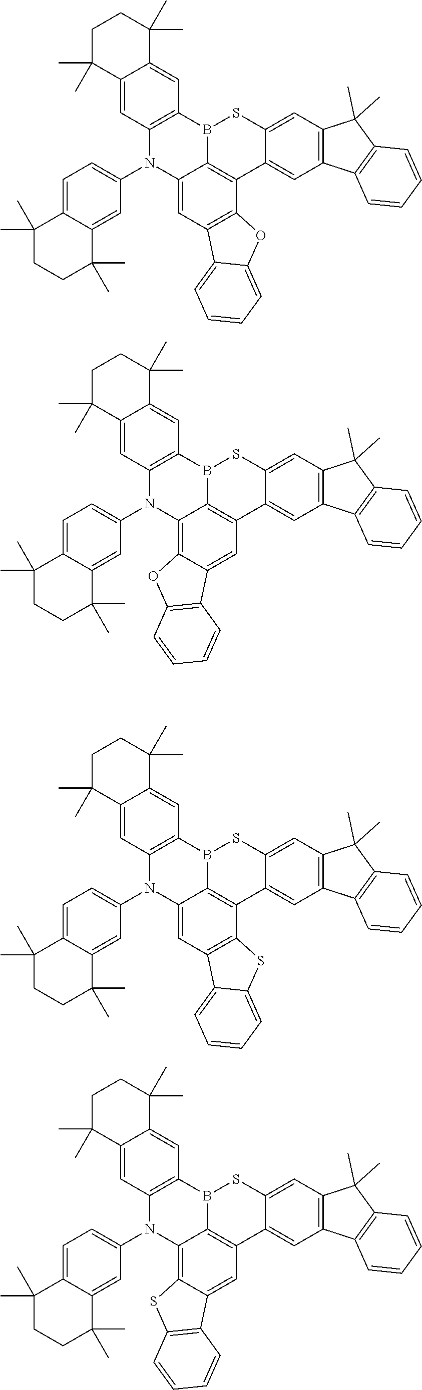 [SMILES: CC1(C)CCC(C)(C)c2cc(N3c4cc5c(cc4B4Sc6cc7c(cc6-c6c4c3cc3c6oc4ccccc43)-c3ccccc3C7(C)C)C(C)(C)CCC5(C)C)ccc21 ; CC1(C)CCC(C)(C)c2cc(N3c4cc5c(cc4B4Sc6cc7c(cc6-c6cc8c(oc9ccccc98)c3c64)-c3ccccc3C7(C)C)C(C)(C)CCC5(C)C)ccc21 ; CC1(C)CCC(C)(C)c2cc(N3c4cc5c(cc4B4Sc6cc7c(cc6-c6c4c3cc3c6sc4ccccc43)-c3ccccc3C7(C)C)C(C)(C)CCC5(C)C)ccc21 ; CC1(C)CCC(C)(C)c2cc(N3c4cc5c(cc4B4Sc6cc7c(cc6-c6cc8c(sc9ccccc98)c3c64)-c3ccccc3C7(C)C)C(C)(C)CCC5(C)C)ccc21]

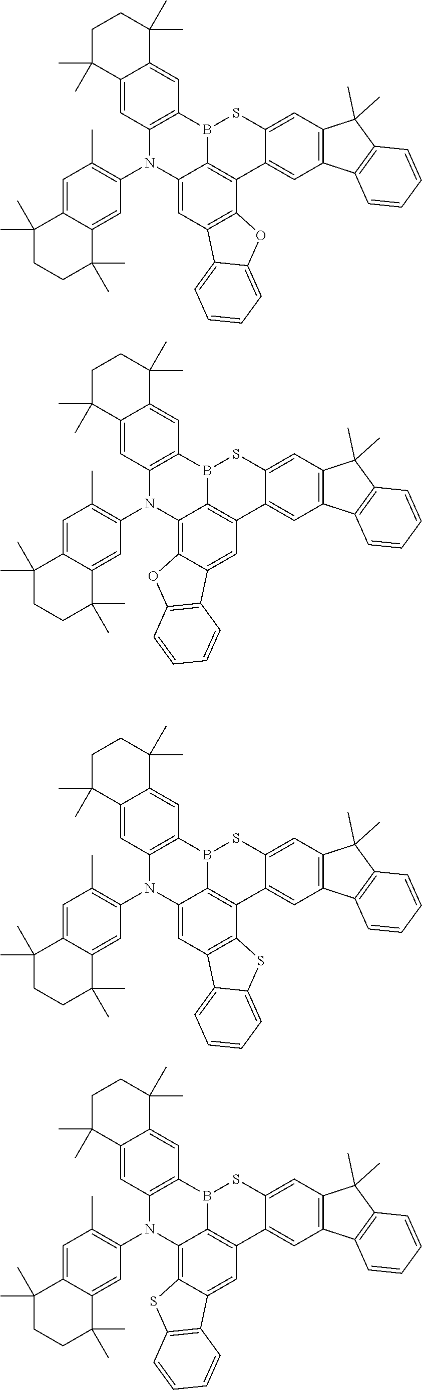 [SMILES: Cc1cc2c(cc1N1c3cc4c(cc3B3Sc5cc6c(cc5-c5c3c1cc1c5oc3ccccc31)-c1ccccc1C6(C)C)C(C)(C)CCC4(C)C)C(C)(C)CCC2(C)C ; Cc1cc2c(cc1N1c3cc4c(cc3B3Sc5cc6c(cc5-c5cc7c(oc8ccccc87)c1c53)-c1ccccc1C6(C)C)C(C)(C)CCC4(C)C)C(C)(C)CCC2(C)C ; Cc1cc2c(cc1N1c3cc4c(cc3B3Sc5cc6c(cc5-c5c3c1cc1c5sc3ccccc31)-c1ccccc1C6(C)C)C(C)(C)CCC4(C)C)C(C)(C)CCC2(C)C ; Cc1cc2c(cc1N1c3cc4c(cc3B3Sc5cc6c(cc5-c5cc7c(sc8ccccc87)c1c53)-c1ccccc1C6(C)C)C(C)(C)CCC4(C)C)C(C)(C)CCC2(C)C]

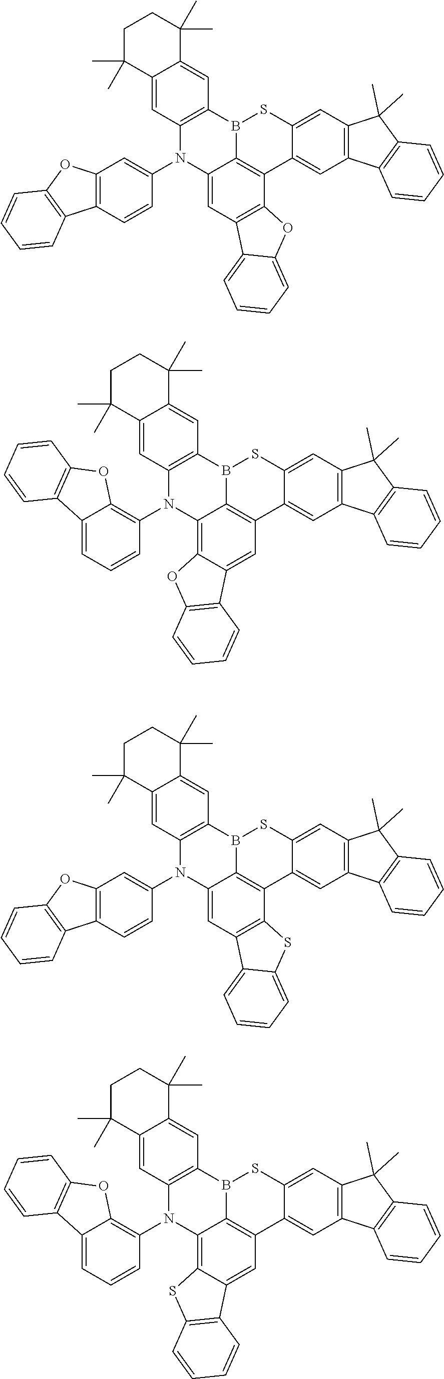 [SMILES: CC1(C)CCC(C)(C)c2cc3c(cc21)B1Sc2cc4c(cc2-c2c1c(cc1c2oc2ccccc21)N3c1ccc2c(c1)oc1ccccc12)-c1ccccc1C4(C)C ; CC1(C)CCC(C)(C)c2cc3c(cc21)B1Sc2cc4c(cc2-c2cc5c(oc6ccccc65)c(c21)N3c1cccc2c1oc1ccccc12)-c1ccccc1C4(C)C ; CC1(C)CCC(C)(C)c2cc3c(cc21)B1Sc2cc4c(cc2-c2c1c(cc1c2sc2ccccc21)N3c1ccc2c(c1)oc1ccccc12)-c1ccccc1C4(C)C ; CC1(C)CCC(C)(C)c2cc3c(cc21)B1Sc2cc4c(cc2-c2cc5c(sc6ccccc65)c(c21)N3c1cccc2c1oc1ccccc12)-c1ccccc1C4(C)C]

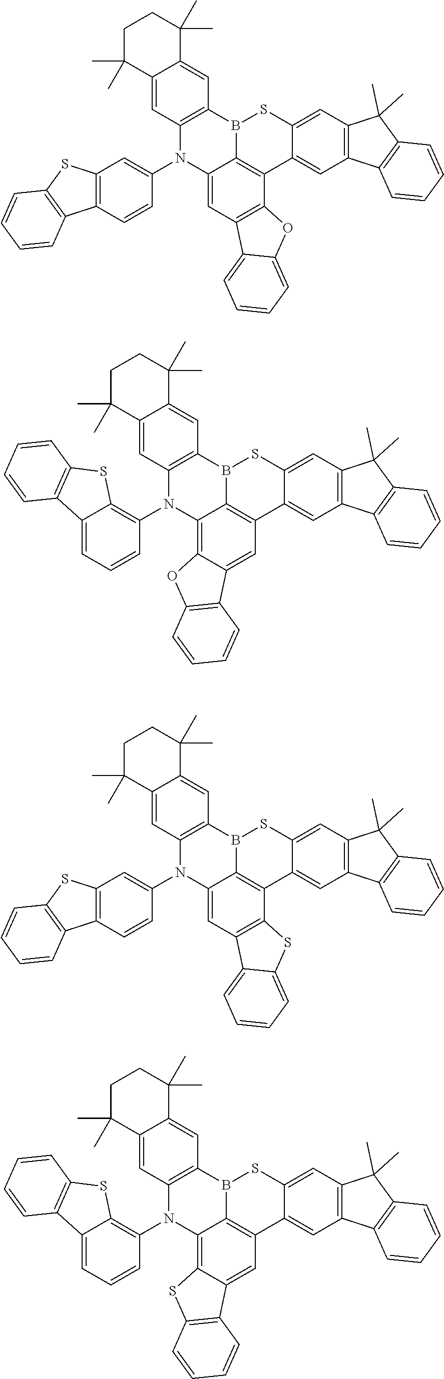 [SMILES: CC1(C)CCC(C)(C)c2cc3c(cc21)B1Sc2cc4c(cc2-c2c1c(cc1c2oc2ccccc21)N3c1ccc2c(c1)sc1ccccc12)-c1ccccc1C4(C)C ; CC1(C)CCC(C)(C)c2cc3c(cc21)B1Sc2cc4c(cc2-c2cc5c(oc6ccccc65)c(c21)N3c1cccc2c1sc1ccccc12)-c1ccccc1C4(C)C ; CC1(C)CCC(C)(C)c2cc3c(cc21)B1Sc2cc4c(cc2-c2c1c(cc1c2sc2ccccc21)N3c1ccc2c(c1)sc1ccccc12)-c1ccccc1C4(C)C ; CC1(C)CCC(C)(C)c2cc3c(cc21)B1Sc2cc4c(cc2-c2cc5c(sc6ccccc65)c(c21)N3c1cccc2c1sc1ccccc12)-c1ccccc1C4(C)C]

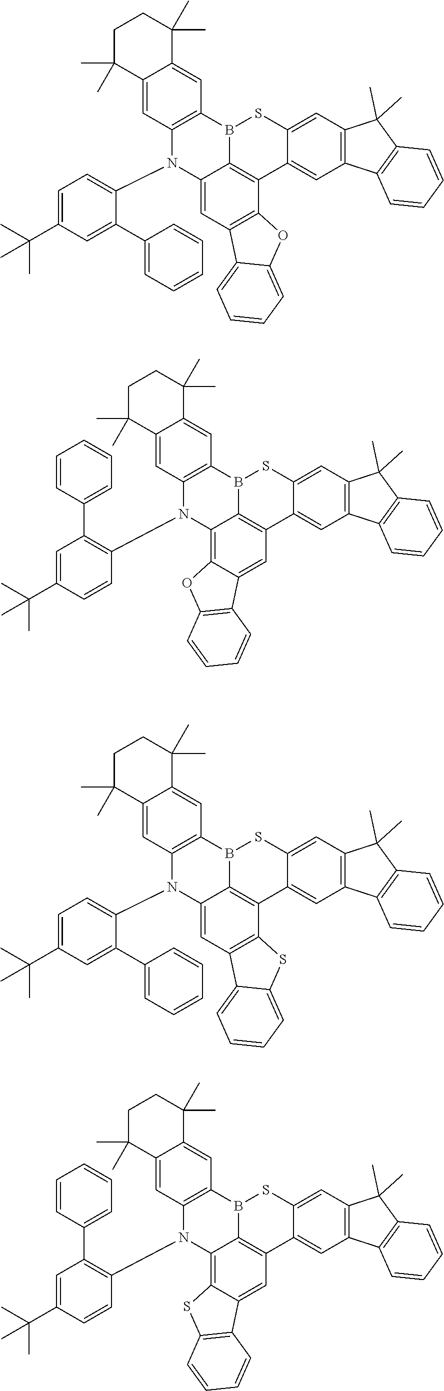 [SMILES: CC(C)(C)c1ccc(N2c3cc4c(cc3B3Sc5cc6c(cc5-c5c3c2cc2c5oc3ccccc32)-c2ccccc2C6(C)C)C(C)(C)CCC4(C)C)c(-c2ccccc2)c1 ; CC(C)(C)c1ccc(N2c3cc4c(cc3B3Sc5cc6c(cc5-c5cc7c(oc8ccccc87)c2c53)-c2ccccc2C6(C)C)C(C)(C)CCC4(C)C)c(-c2ccccc2)c1 ; CC(C)(C)c1ccc(N2c3cc4c(cc3B3Sc5cc6c(cc5-c5c3c2cc2c5sc3ccccc32)-c2ccccc2C6(C)C)C(C)(C)CCC4(C)C)c(-c2ccccc2)c1 ; CC(C)(C)c1ccc(N2c3cc4c(cc3B3Sc5cc6c(cc5-c5cc7c(sc8ccccc87)c2c53)-c2ccccc2C6(C)C)C(C)(C)CCC4(C)C)c(-c2ccccc2)c1]

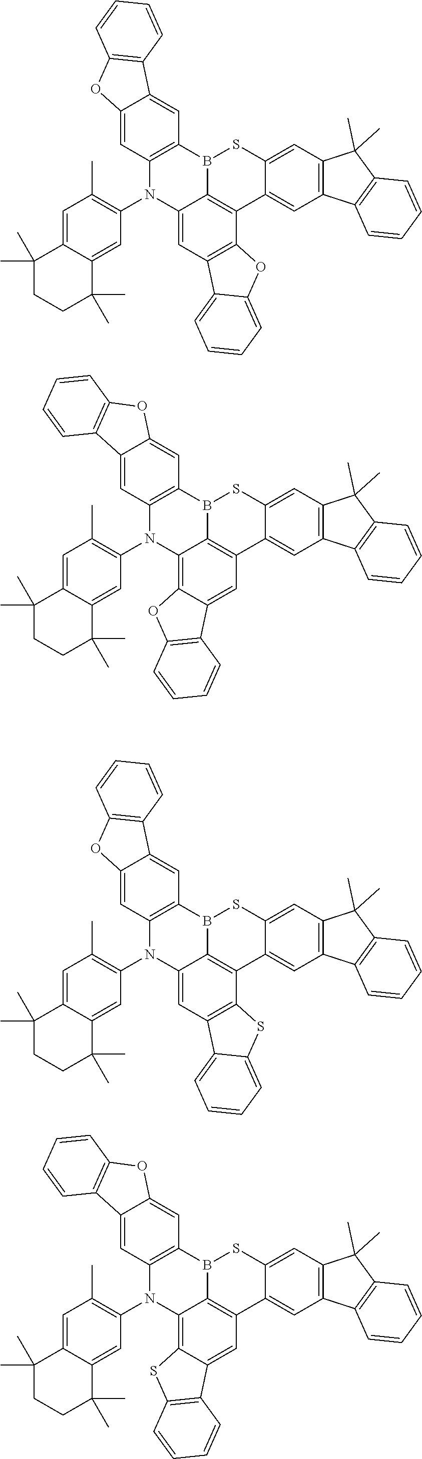 [SMILES: Cc1cc2c(cc1N1c3cc4oc5ccccc5c4cc3B3Sc4cc5c(cc4-c4c3c1cc1c4oc3ccccc31)-c1ccccc1C5(C)C)C(C)(C)CCC2(C)C ; Cc1cc2c(cc1N1c3cc4c(cc3B3Sc5cc6c(cc5-c5cc7c(oc8ccccc87)c1c53)-c1ccccc1C6(C)C)oc1ccccc14)C(C)(C)CCC2(C)C ; Cc1cc2c(cc1N1c3cc4oc5ccccc5c4cc3B3Sc4cc5c(cc4-c4c3c1cc1c4sc3ccccc31)-c1ccccc1C5(C)C)C(C)(C)CCC2(C)C ; Cc1cc2c(cc1N1c3cc4c(cc3B3Sc5cc6c(cc5-c5cc7c(sc8ccccc87)c1c53)-c1ccccc1C6(C)C)oc1ccccc14)C(C)(C)CCC2(C)C]

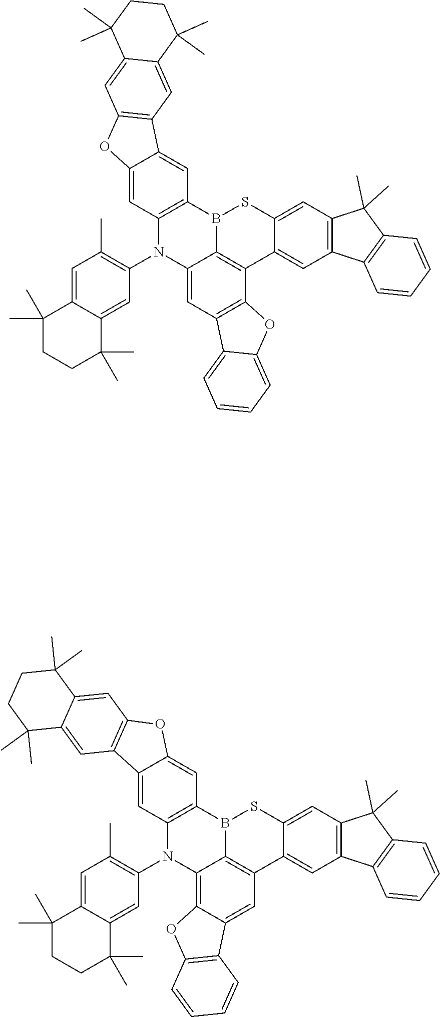 [SMILES: Cc1cc2c(cc1N1c3cc4oc5cc6c(cc5c4cc3B3Sc4cc5c(cc4-c4c3c1cc1c4oc3ccccc31)-c1ccccc1C5(C)C)C(C)(C)CCC6(C)C)C(C)(C)CCC2(C)C ; Cc1cc2c(cc1N1c3cc4c(cc3B3Sc5cc6c(cc5-c5cc7c(oc8ccccc87)c1c53)-c1ccccc1C6(C)C)oc1cc3c(cc14)C(C)(C)CCC3(C)C)C(C)(C)CCC2(C)C]

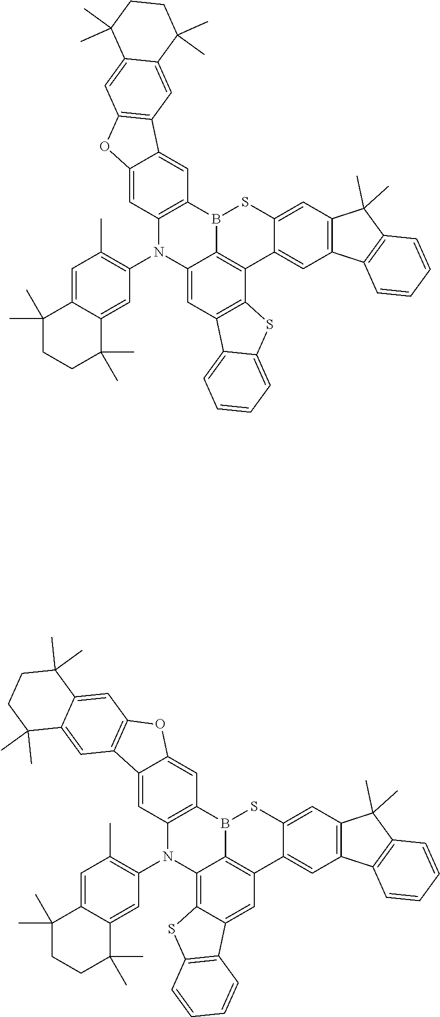 [SMILES: Cc1cc2c(cc1N1c3cc4oc5cc6c(cc5c4cc3B3Sc4cc5c(cc4-c4c3c1cc1c4sc3ccccc31)-c1ccccc1C5(C)C)C(C)(C)CCC6(C)C)C(C)(C)CCC2(C)C ; Cc1cc2c(cc1N1c3cc4c(cc3B3Sc5cc6c(cc5-c5cc7c(sc8ccccc87)c1c53)-c1ccccc1C6(C)C)oc1cc3c(cc14)C(C)(C)CCC3(C)C)C(C)(C)CCC2(C)C]

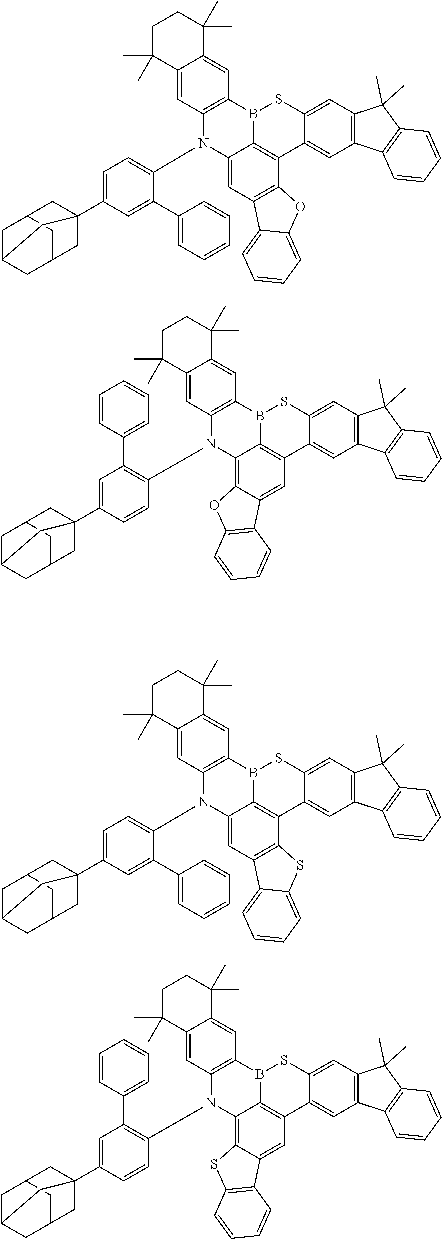

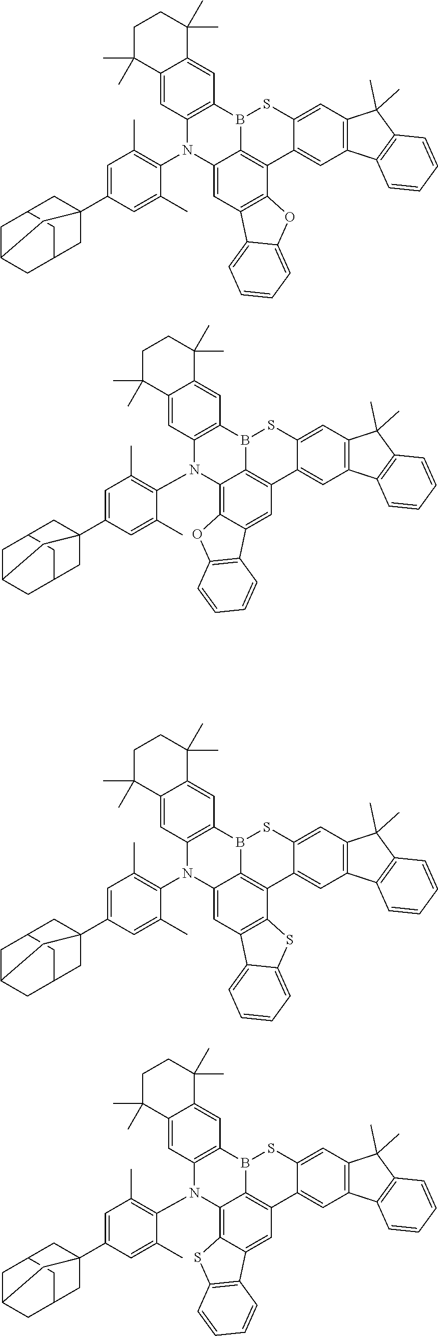 [SMILES: Cc1cc(C23CC4CC(CC(C4)C2)C3)cc(C)c1N1c2cc3c(cc2B2Sc4cc5c(cc4-c4c2c1cc1c4oc2ccccc21)-c1ccccc1C5(C)C)C(C)(C)CCC3(C)C ; Cc1cc(C23CC4CC(CC(C4)C2)C3)cc(C)c1N1c2cc3c(cc2B2Sc4cc5c(cc4-c4cc6c(oc7ccccc76)c1c42)-c1ccccc1C5(C)C)C(C)(C)CCC3(C)C ; Cc1cc(C23CC4CC(CC(C4)C2)C3)cc(C)c1N1c2cc3c(cc2B2Sc4cc5c(cc4-c4c2c1cc1c4sc2ccccc21)-c1ccccc1C5(C)C)C(C)(C)CCC3(C)C ; Cc1cc(C23CC4CC(CC(C4)C2)C3)cc(C)c1N1c2cc3c(cc2B2Sc4cc5c(cc4-c4cc6c(sc7ccccc76)c1c42)-c1ccccc1C5(C)C)C(C)(C)CCC3(C)C]

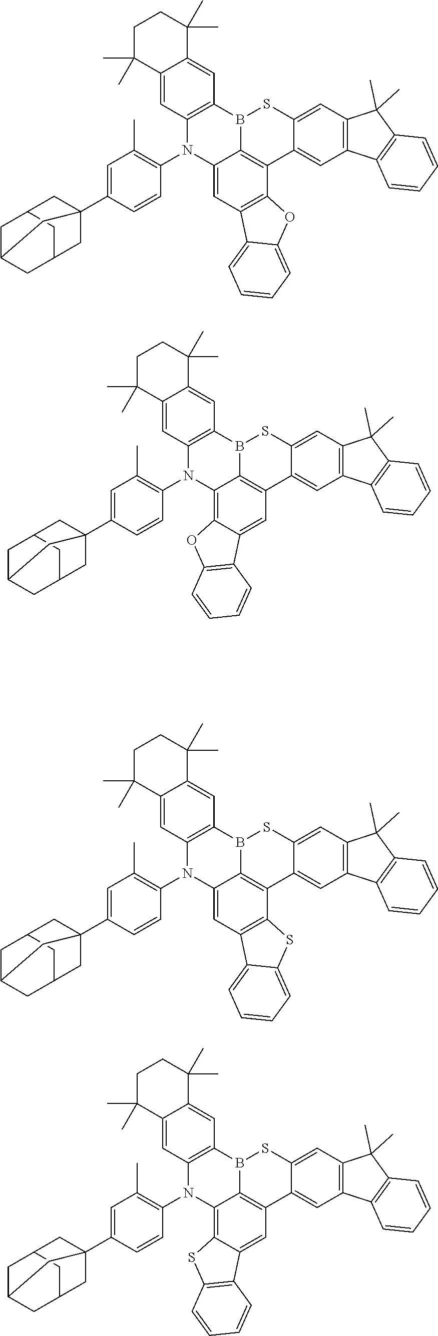 [SMILES: Cc1cc(C23CC4CC(CC(C4)C2)C3)ccc1N1c2cc3c(cc2B2Sc4cc5c(cc4-c4c2c1cc1c4oc2ccccc21)-c1ccccc1C5(C)C)C(C)(C)CCC3(C)C ; Cc1cc(C23CC4CC(CC(C4)C2)C3)ccc1N1c2cc3c(cc2B2Sc4cc5c(cc4-c4cc6c(oc7ccccc76)c1c42)-c1ccccc1C5(C)C)C(C)(C)CCC3(C)C ; Cc1cc(C23CC4CC(CC(C4)C2)C3)ccc1N1c2cc3c(cc2B2Sc4cc5c(cc4-c4c2c1cc1c4sc2ccccc21)-c1ccccc1C5(C)C)C(C)(C)CCC3(C)C ; Cc1cc(C23CC4CC(CC(C4)C2)C3)ccc1N1c2cc3c(cc2B2Sc4cc5c(cc4-c4cc6c(sc7ccccc76)c1c42)-c1ccccc1C5(C)C)C(C)(C)CCC3(C)C]

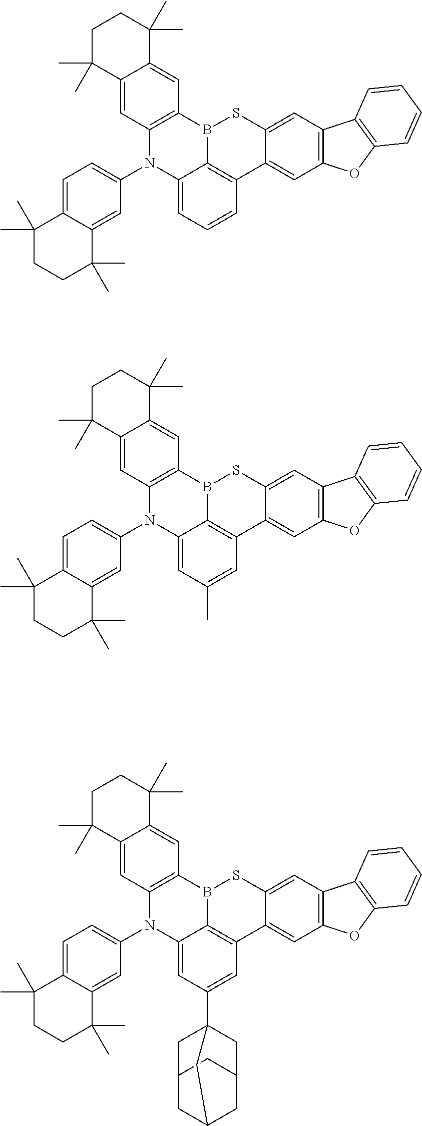 [SMILES: CC1(C)CCC(C)(C)c2cc(N3c4cc5c(cc4B4Sc6cc7c(cc6-c6cccc3c64)oc3ccccc37)C(C)(C)CCC5(C)C)ccc21 ; Cc1cc2c3c(c1)N(c1ccc4c(c1)C(C)(C)CCC4(C)C)c1cc4c(cc1B3Sc1cc3c(cc1-2)oc1ccccc13)C(C)(C)CCC4(C)C ; CC1(C)CCC(C)(C)c2cc(N3c4cc5c(cc4B4Sc6cc7c(cc6-c6cc(C89CC%10CC(CC(C%10)C8)C9)cc3c64)oc3ccccc37)C(C)(C)CCC5(C)C)ccc21]

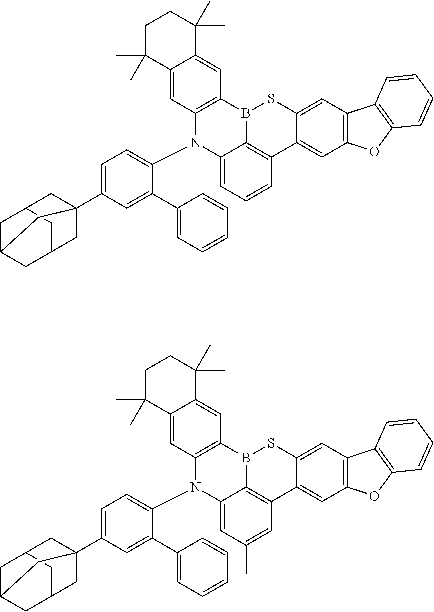 [SMILES: CC1(C)CCC(C)(C)c2cc3c(cc21)B1Sc2cc4c(cc2-c2cccc(c21)N3c1ccc(C23CC5CC(CC(C5)C2)C3)cc1-c1ccccc1)oc1ccccc14 ; Cc1cc2c3c(c1)N(c1ccc(C45CC6CC(CC(C6)C4)C5)cc1-c1ccccc1)c1cc4c(cc1B3Sc1cc3c(cc1-2)oc1ccccc13)C(C)(C)CCC4(C)C]

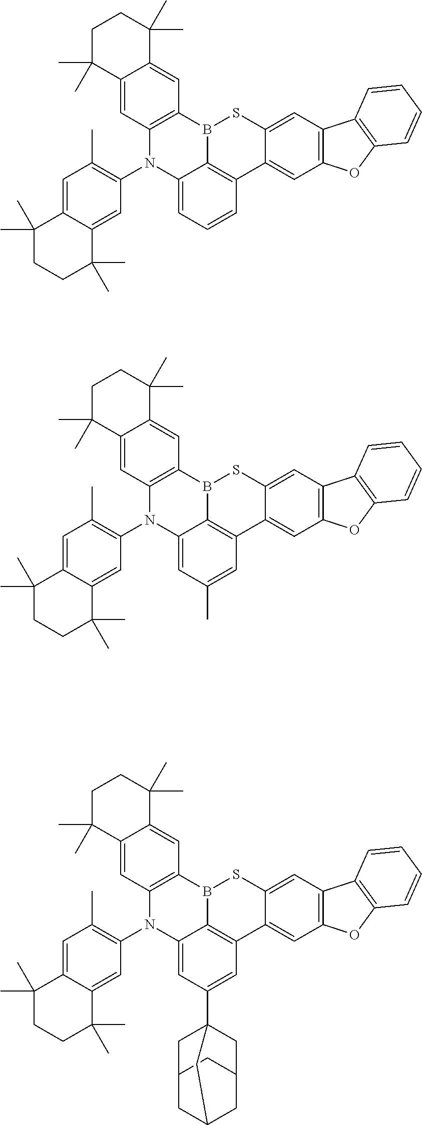 [SMILES: Cc1cc2c(cc1N1c3cc4c(cc3B3Sc5cc6c(cc5-c5cccc1c53)oc1ccccc16)C(C)(C)CCC4(C)C)C(C)(C)CCC2(C)C ; Cc1cc2c3c(c1)N(c1cc4c(cc1C)C(C)(C)CCC4(C)C)c1cc4c(cc1B3Sc1cc3c(cc1-2)oc1ccccc13)C(C)(C)CCC4(C)C ; Cc1cc2c(cc1N1c3cc4c(cc3B3Sc5cc6c(cc5-c5cc(C78CC9CC(CC(C9)C7)C8)cc1c53)oc1ccccc16)C(C)(C)CCC4(C)C)C(C)(C)CCC2(C)C]

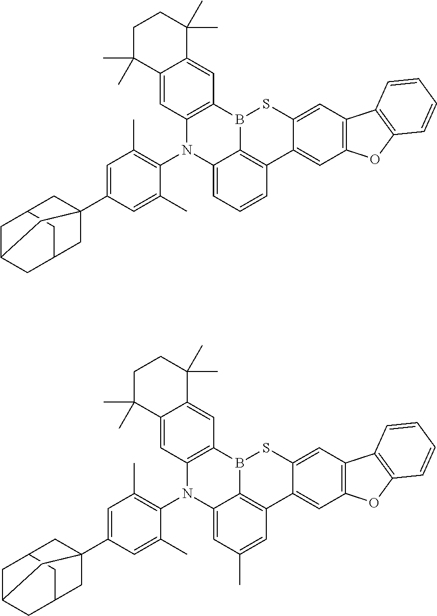 [SMILES: Cc1cc(C23CC4CC(CC(C4)C2)C3)cc(C)c1N1c2cc3c(cc2B2Sc4cc5c(cc4-c4cccc1c42)oc1ccccc15)C(C)(C)CCC3(C)C ; Cc1cc2c3c(c1)N(c1c(C)cc(C45CC6CC(CC(C6)C4)C5)cc1C)c1cc4c(cc1B3Sc1cc3c(cc1-2)oc1ccccc13)C(C)(C)CCC4(C)C]

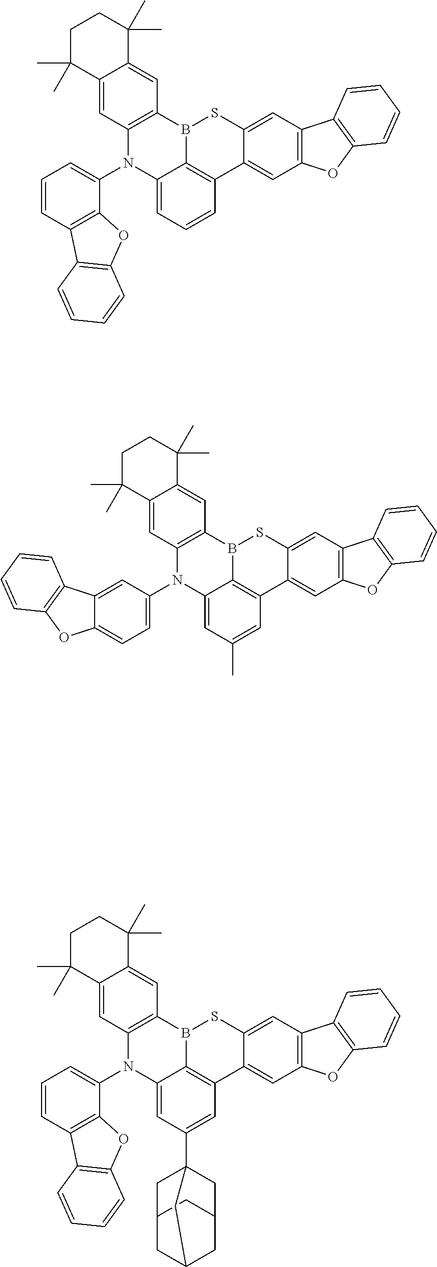 [SMILES: CC1(C)CCC(C)(C)c2cc3c(cc21)B1Sc2cc4c(cc2-c2cccc(c21)N3c1cccc2c1oc1ccccc12)oc1ccccc14 ; Cc1cc2c3c(c1)N(c1ccc4oc5ccccc5c4c1)c1cc4c(cc1B3Sc1cc3c(cc1-2)oc1ccccc13)C(C)(C)CCC4(C)C ; CC1(C)CCC(C)(C)c2cc3c(cc21)B1Sc2cc4c(cc2-c2cc(C56CC7CC(CC(C7)C5)C6)cc(c21)N3c1cccc2c1oc1ccccc12)oc1ccccc14]

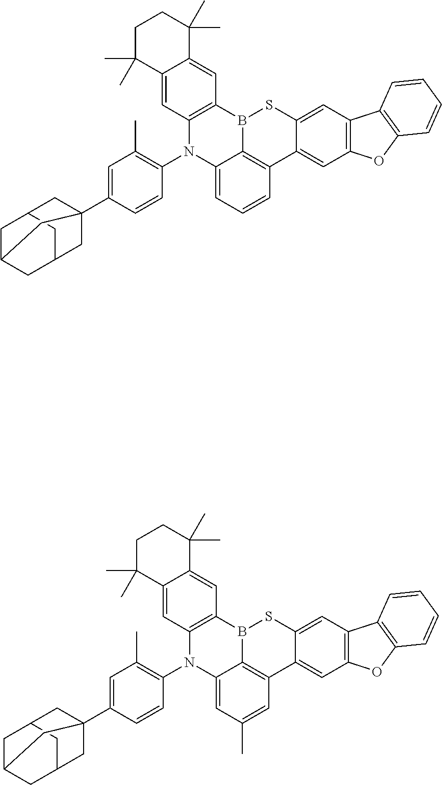 [SMILES: Cc1cc(C23CC4CC(CC(C4)C2)C3)ccc1N1c2cc3c(cc2B2Sc4cc5c(cc4-c4cccc1c42)oc1ccccc15)C(C)(C)CCC3(C)C ; Cc1cc2c3c(c1)N(c1ccc(C45CC6CC(CC(C6)C4)C5)cc1C)c1cc4c(cc1B3Sc1cc3c(cc1-2)oc1ccccc13)C(C)(C)CCC4(C)C]

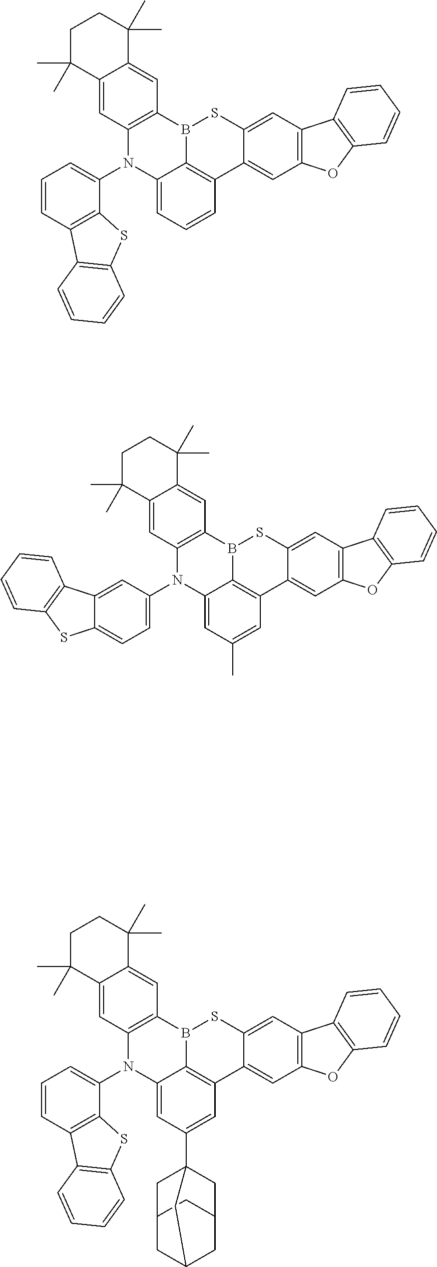 [SMILES: CC1(C)CCC(C)(C)c2cc3c(cc21)B1Sc2cc4c(cc2-c2cccc(c21)N3c1cccc2c1sc1ccccc12)oc1ccccc14 ; Cc1cc2c3c(c1)N(c1ccc4sc5ccccc5c4c1)c1cc4c(cc1B3Sc1cc3c(cc1-2)oc1ccccc13)C(C)(C)CCC4(C)C ; CC1(C)CCC(C)(C)c2cc3c(cc21)B1Sc2cc4c(cc2-c2cc(C56CC7CC(CC(C7)C5)C6)cc(c21)N3c1cccc2c1sc1ccccc12)oc1ccccc14]

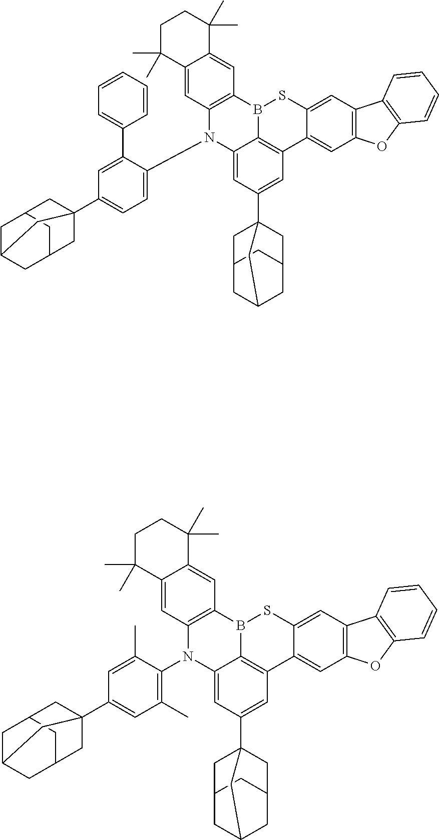 [SMILES: CC1(C)CCC(C)(C)c2cc3c(cc21)B1Sc2cc4c(cc2-c2cc(C56CC7CC(CC(C7)C5)C6)cc(c21)N3c1ccc(C23CC5CC(CC(C5)C2)C3)cc1-c1ccccc1)oc1ccccc14 ; Cc1cc(C23CC4CC(CC(C4)C2)C3)cc(C)c1N1c2cc3c(cc2B2Sc4cc5c(cc4-c4cc(C67CC8CC(CC(C8)C6)C7)cc1c42)oc1ccccc15)C(C)(C)CCC3(C)C]

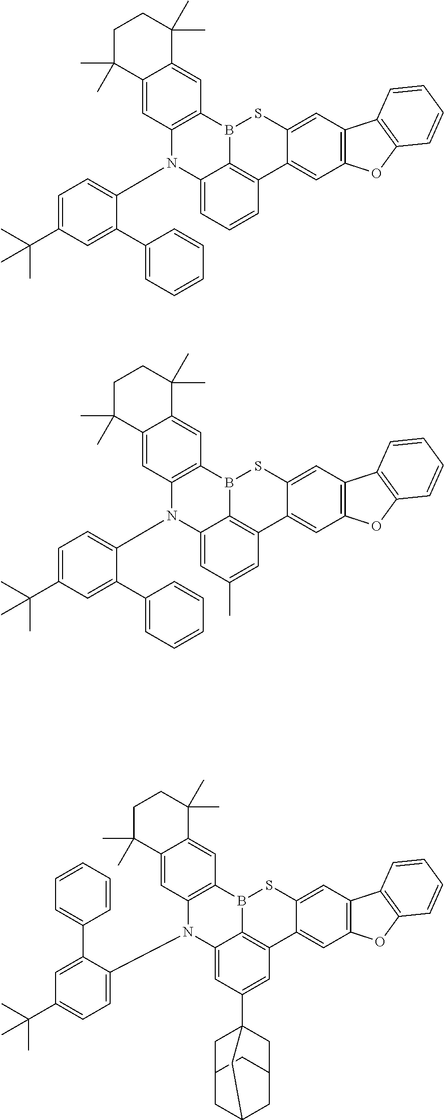 [SMILES: CC(C)(C)c1ccc(N2c3cc4c(cc3B3Sc5cc6c(cc5-c5cccc2c53)oc2ccccc26)C(C)(C)CCC4(C)C)c(-c2ccccc2)c1 ; Cc1cc2c3c(c1)N(c1ccc(C(C)(C)C)cc1-c1ccccc1)c1cc4c(cc1B3Sc1cc3c(cc1-2)oc1ccccc13)C(C)(C)CCC4(C)C ; CC(C)(C)c1ccc(N2c3cc4c(cc3B3Sc5cc6c(cc5-c5cc(C78CC9CC(CC(C9)C7)C8)cc2c53)oc2ccccc26)C(C)(C)CCC4(C)C)c(-c2ccccc2)c1]

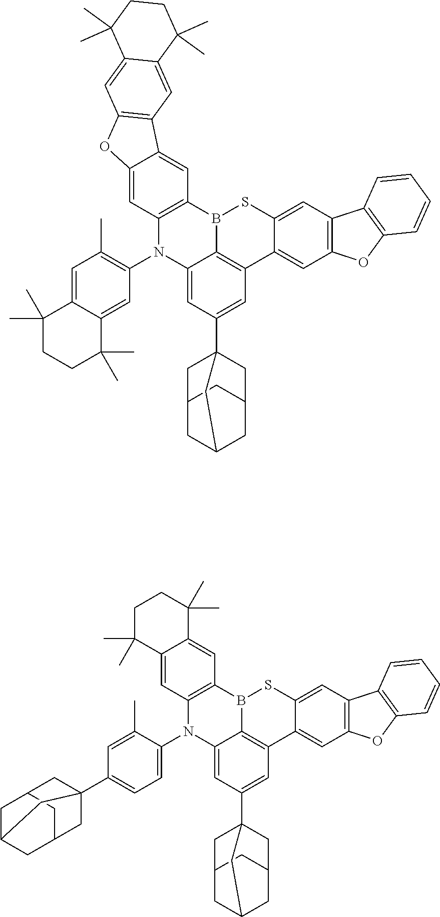 [SMILES: Cc1cc2c(cc1N1c3cc4oc5cc6c(cc5c4cc3B3Sc4cc5c(cc4-c4cc(C78CC9CC(CC(C9)C7)C8)cc1c43)oc1ccccc15)C(C)(C)CCC6(C)C)C(C)(C)CCC2(C)C ; Cc1cc(C23CC4CC(CC(C4)C2)C3)ccc1N1c2cc3c(cc2B2Sc4cc5c(cc4-c4cc(C67CC8CC(CC(C8)C6)C7)cc1c42)oc1ccccc15)C(C)(C)CCC3(C)C]

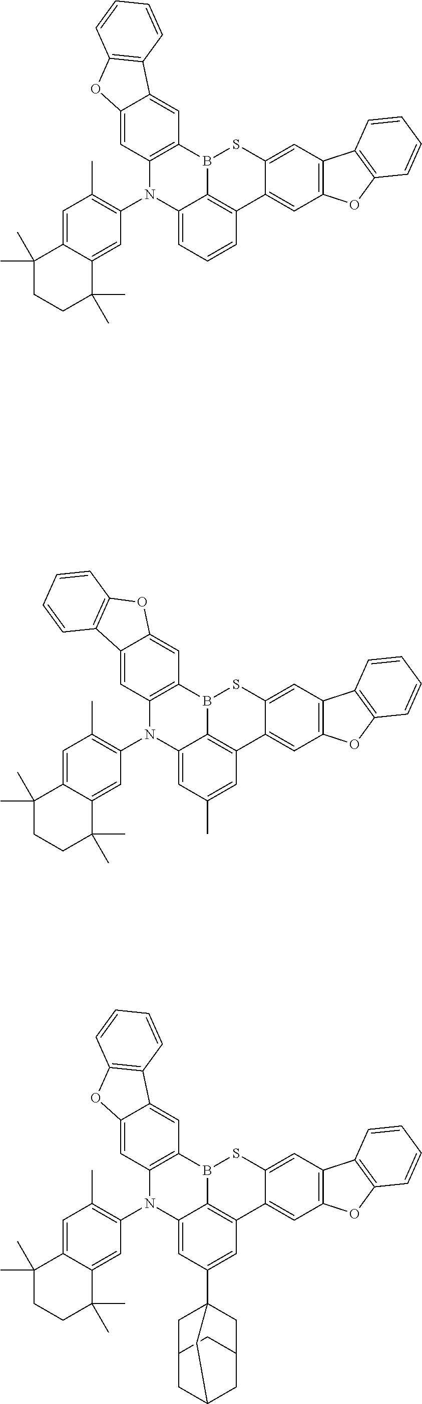 [SMILES: Cc1cc2c(cc1N1c3cc4oc5ccccc5c4cc3B3Sc4cc5c(cc4-c4cccc1c43)oc1ccccc15)C(C)(C)CCC2(C)C ; Cc1cc2c3c(c1)N(c1cc4c(cc1C)C(C)(C)CCC4(C)C)c1cc4c(cc1B3Sc1cc3c(cc1-2)oc1ccccc13)oc1ccccc14 ; Cc1cc2c(cc1N1c3cc4oc5ccccc5c4cc3B3Sc4cc5c(cc4-c4cc(C67CC8CC(CC(C8)C6)C7)cc1c43)oc1ccccc15)C(C)(C)CCC2(C)C]

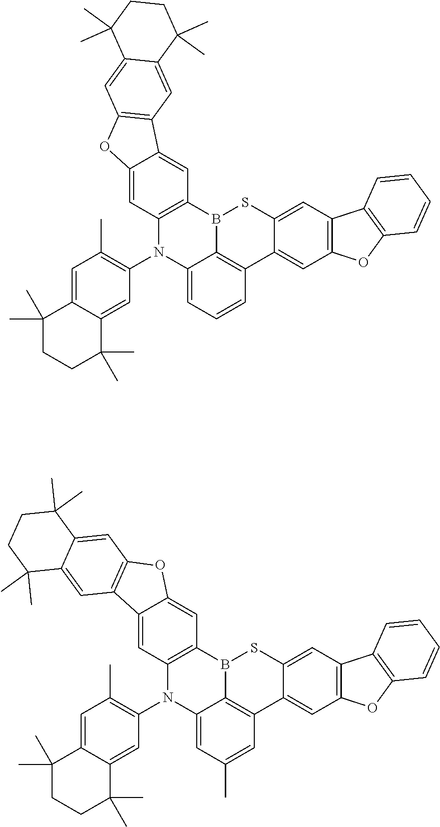 [SMILES: Cc1cc2c(cc1N1c3cc4oc5cc6c(cc5c4cc3B3Sc4cc5c(cc4-c4cccc1c43)oc1ccccc15)C(C)(C)CCC6(C)C)C(C)(C)CCC2(C)C ; Cc1cc2c3c(c1)N(c1cc4c(cc1C)C(C)(C)CCC4(C)C)c1cc4c(cc1B3Sc1cc3c(cc1-2)oc1ccccc13)oc1cc2c(cc14)C(C)(C)CCC2(C)C]

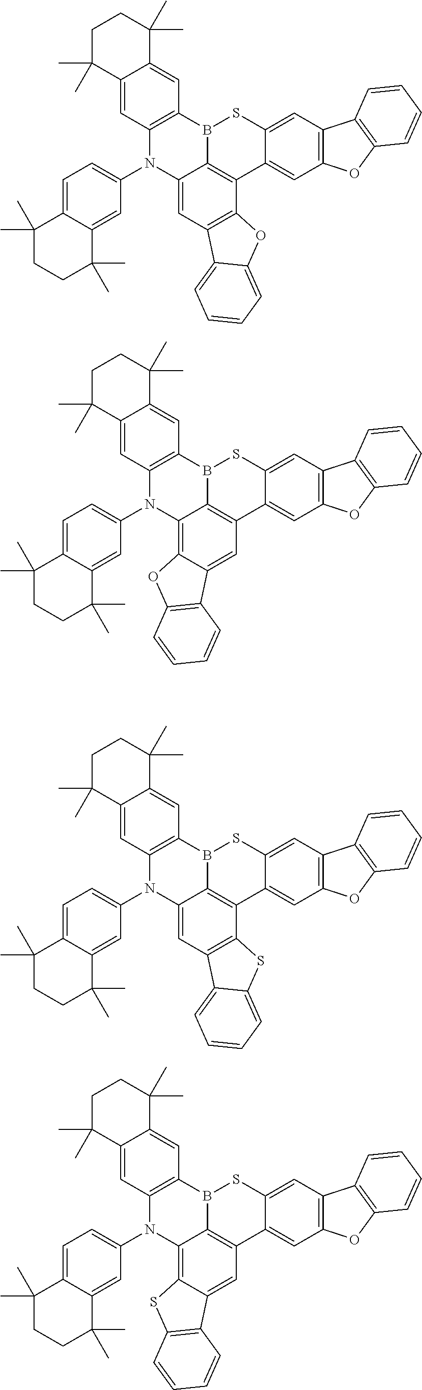 [SMILES: CC1(C)CCC(C)(C)c2cc(N3c4cc5c(cc4B4Sc6cc7c(cc6-c6c4c3cc3c6oc4ccccc43)oc3ccccc37)C(C)(C)CCC5(C)C)ccc21 ; CC1(C)CCC(C)(C)c2cc(N3c4cc5c(cc4B4Sc6cc7c(cc6-c6cc8c(oc9ccccc98)c3c64)oc3ccccc37)C(C)(C)CCC5(C)C)ccc21 ; CC1(C)CCC(C)(C)c2cc(N3c4cc5c(cc4B4Sc6cc7c(cc6-c6c4c3cc3c6sc4ccccc43)oc3ccccc37)C(C)(C)CCC5(C)C)ccc21 ; CC1(C)CCC(C)(C)c2cc(N3c4cc5c(cc4B4Sc6cc7c(cc6-c6cc8c(sc9ccccc98)c3c64)oc3ccccc37)C(C)(C)CCC5(C)C)ccc21]

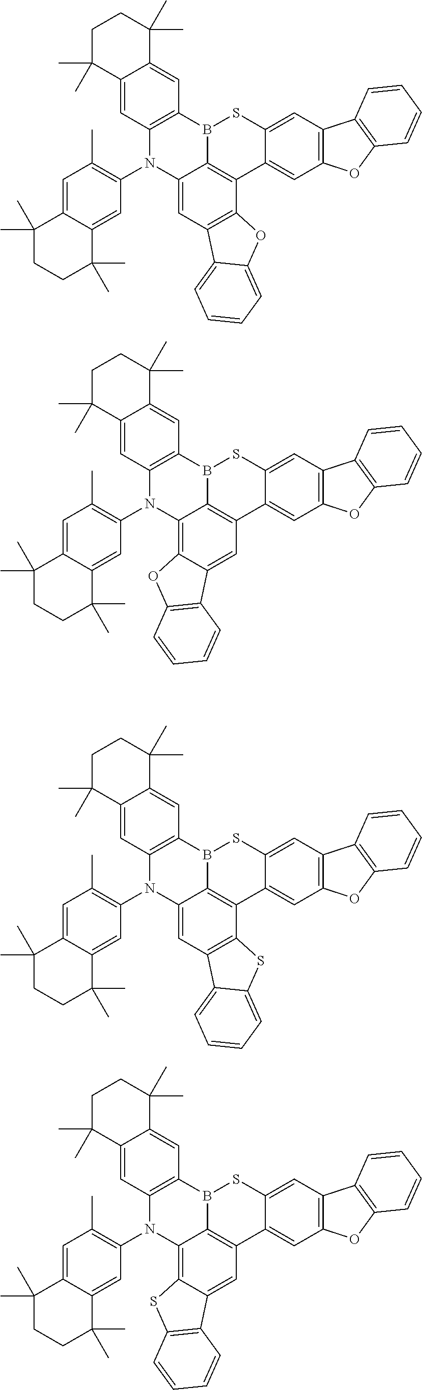 [SMILES: Cc1cc2c(cc1N1c3cc4c(cc3B3Sc5cc6c(cc5-c5c3c1cc1c5oc3ccccc31)oc1ccccc16)C(C)(C)CCC4(C)C)C(C)(C)CCC2(C)C ; Cc1cc2c(cc1N1c3cc4c(cc3B3Sc5cc6c(cc5-c5cc7c(oc8ccccc87)c1c53)oc1ccccc16)C(C)(C)CCC4(C)C)C(C)(C)CCC2(C)C ; Cc1cc2c(cc1N1c3cc4c(cc3B3Sc5cc6c(cc5-c5c3c1cc1c5sc3ccccc31)oc1ccccc16)C(C)(C)CCC4(C)C)C(C)(C)CCC2(C)C ; Cc1cc2c(cc1N1c3cc4c(cc3B3Sc5cc6c(cc5-c5cc7c(sc8ccccc87)c1c53)oc1ccccc16)C(C)(C)CCC4(C)C)C(C)(C)CCC2(C)C]

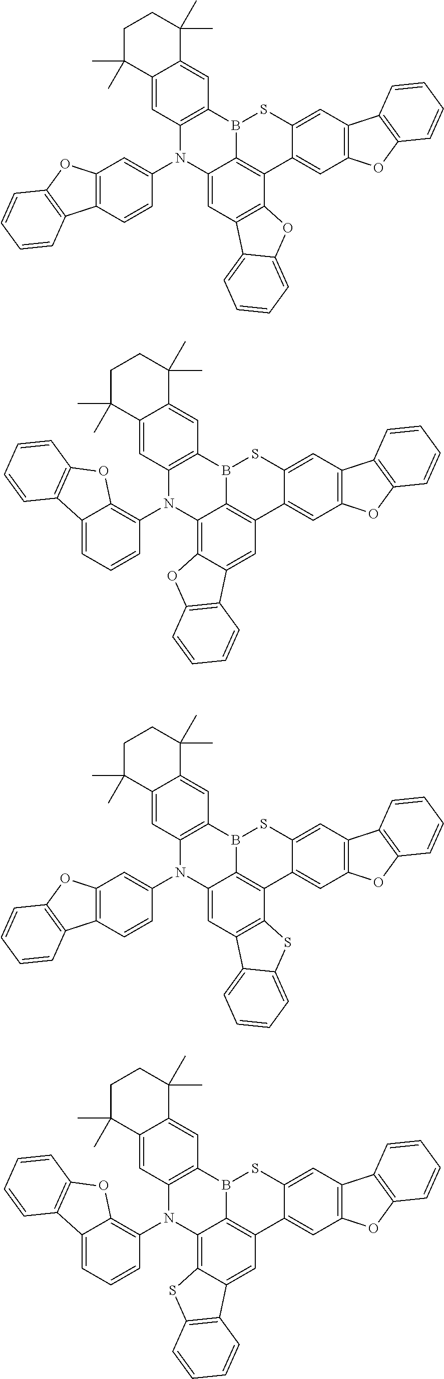 [SMILES: CC1(C)CCC(C)(C)c2cc3c(cc21)B1Sc2cc4c(cc2-c2c1c(cc1c2oc2ccccc21)N3c1ccc2c(c1)oc1ccccc12)oc1ccccc14 ; CC1(C)CCC(C)(C)c2cc3c(cc21)B1Sc2cc4c(cc2-c2cc5c(oc6ccccc65)c(c21)N3c1cccc2c1oc1ccccc12)oc1ccccc14 ; CC1(C)CCC(C)(C)c2cc3c(cc21)B1Sc2cc4c(cc2-c2c1c(cc1c2sc2ccccc21)N3c1ccc2c(c1)oc1ccccc12)oc1ccccc14 ; CC1(C)CCC(C)(C)c2cc3c(cc21)B1Sc2cc4c(cc2-c2cc5c(sc6ccccc65)c(c21)N3c1cccc2c1oc1ccccc12)oc1ccccc14]

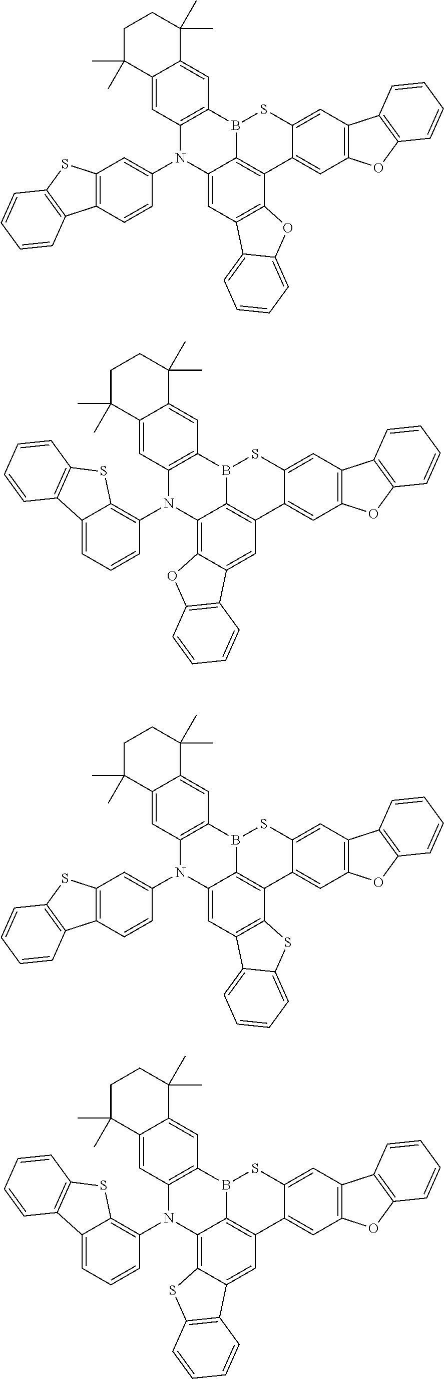 [SMILES: CC1(C)CCC(C)(C)c2cc3c(cc21)B1Sc2cc4c(cc2-c2c1c(cc1c2oc2ccccc21)N3c1ccc2c(c1)sc1ccccc12)oc1ccccc14 ; CC1(C)CCC(C)(C)c2cc3c(cc21)B1Sc2cc4c(cc2-c2cc5c(oc6ccccc65)c(c21)N3c1cccc2c1sc1ccccc12)oc1ccccc14 ; CC1(C)CCC(C)(C)c2cc3c(cc21)B1Sc2cc4c(cc2-c2c1c(cc1c2sc2ccccc21)N3c1ccc2c(c1)sc1ccccc12)oc1ccccc14 ; CC1(C)CCC(C)(C)c2cc3c(cc21)B1Sc2cc4c(cc2-c2cc5c(sc6ccccc65)c(c21)N3c1cccc2c1sc1ccccc12)oc1ccccc14]

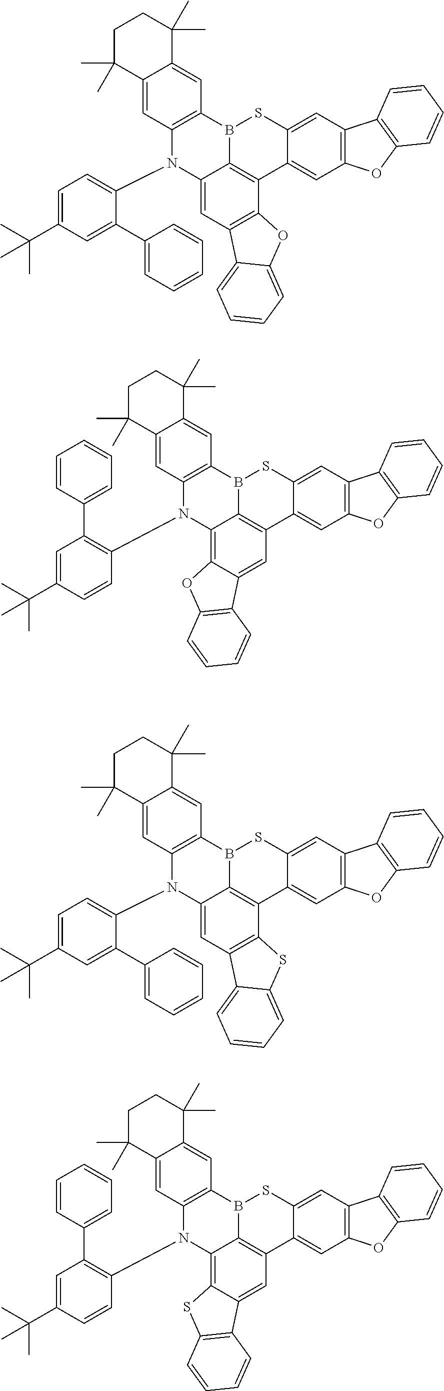 [SMILES: CC(C)(C)c1ccc(N2c3cc4c(cc3B3Sc5cc6c(cc5-c5c3c2cc2c5oc3ccccc32)oc2ccccc26)C(C)(C)CCC4(C)C)c(-c2ccccc2)c1 ; CC(C)(C)c1ccc(N2c3cc4c(cc3B3Sc5cc6c(cc5-c5cc7c(oc8ccccc87)c2c53)oc2ccccc26)C(C)(C)CCC4(C)C)c(-c2ccccc2)c1 ; CC(C)(C)c1ccc(N2c3cc4c(cc3B3Sc5cc6c(cc5-c5c3c2cc2c5sc3ccccc32)oc2ccccc26)C(C)(C)CCC4(C)C)c(-c2ccccc2)c1 ; CC(C)(C)c1ccc(N2c3cc4c(cc3B3Sc5cc6c(cc5-c5cc7c(sc8ccccc87)c2c53)oc2ccccc26)C(C)(C)CCC4(C)C)c(-c2ccccc2)c1]

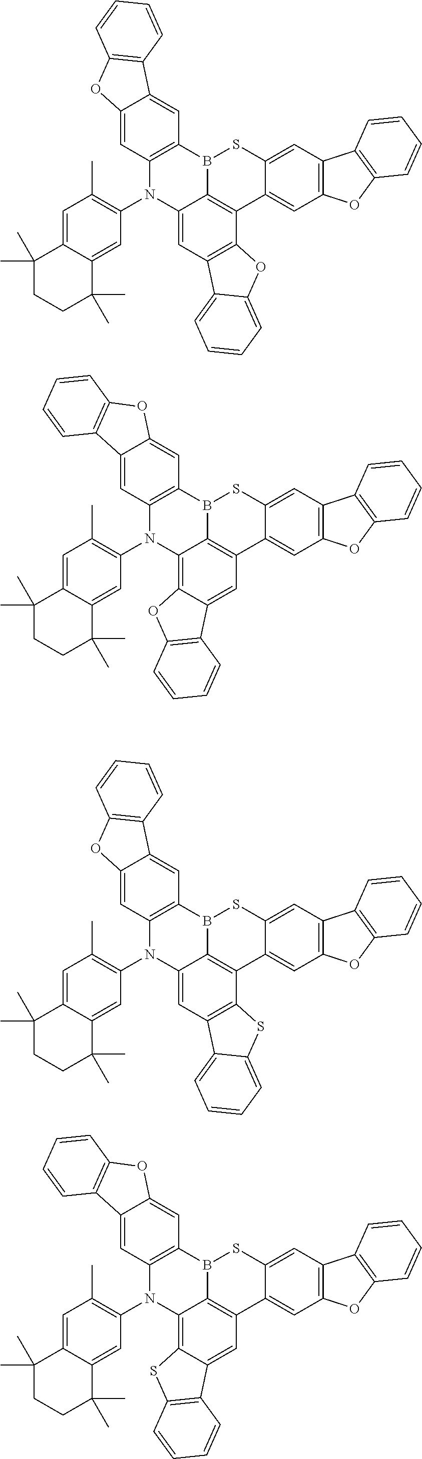 [SMILES: Cc1cc2c(cc1N1c3cc4oc5ccccc5c4cc3B3Sc4cc5c(cc4-c4c3c1cc1c4oc3ccccc31)oc1ccccc15)C(C)(C)CCC2(C)C ; Cc1cc2c(cc1N1c3cc4c(cc3B3Sc5cc6c(cc5-c5cc7c(oc8ccccc87)c1c53)oc1ccccc16)oc1ccccc14)C(C)(C)CCC2(C)C ; Cc1cc2c(cc1N1c3cc4oc5ccccc5c4cc3B3Sc4cc5c(cc4-c4c3c1cc1c4sc3ccccc31)oc1ccccc15)C(C)(C)CCC2(C)C ; Cc1cc2c(cc1N1c3cc4c(cc3B3Sc5cc6c(cc5-c5cc7c(sc8ccccc87)c1c53)oc1ccccc16)oc1ccccc14)C(C)(C)CCC2(C)C]

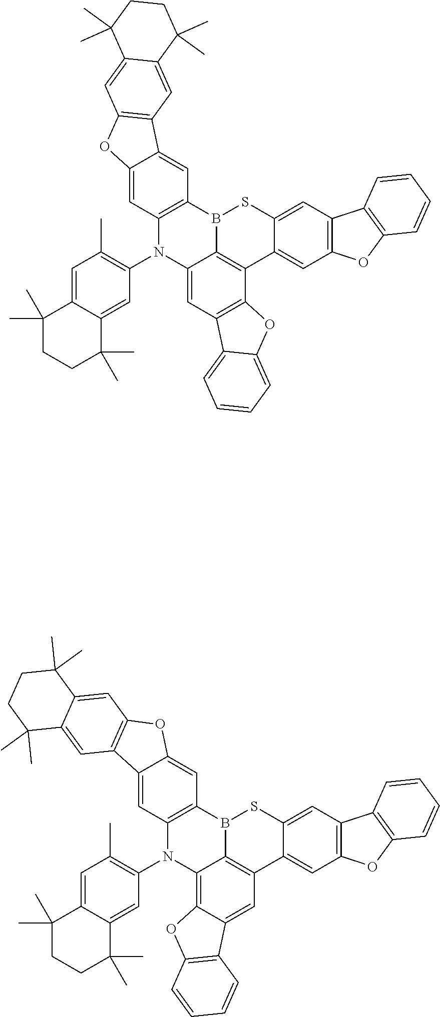 [SMILES: Cc1cc2c(cc1N1c3cc4oc5cc6c(cc5c4cc3B3Sc4cc5c(cc4-c4c3c1cc1c4oc3ccccc31)oc1ccccc15)C(C)(C)CCC6(C)C)C(C)(C)CCC2(C)C ; Cc1cc2c(cc1N1c3cc4c(cc3B3Sc5cc6c(cc5-c5cc7c(oc8ccccc87)c1c53)oc1ccccc16)oc1cc3c(cc14)C(C)(C)CCC3(C)C)C(C)(C)CCC2(C)C]

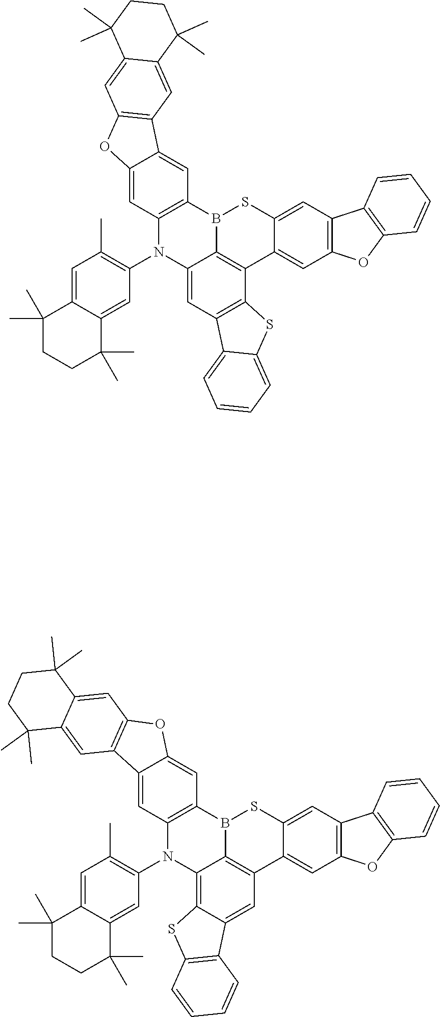 [SMILES: Cc1cc2c(cc1N1c3cc4oc5cc6c(cc5c4cc3B3Sc4cc5c(cc4-c4c3c1cc1c4sc3ccccc31)oc1ccccc15)C(C)(C)CCC6(C)C)C(C)(C)CCC2(C)C ; Cc1cc2c(cc1N1c3cc4c(cc3B3Sc5cc6c(cc5-c5cc7c(sc8ccccc87)c1c53)oc1ccccc16)oc1cc3c(cc14)C(C)(C)CCC3(C)C)C(C)(C)CCC2(C)C]

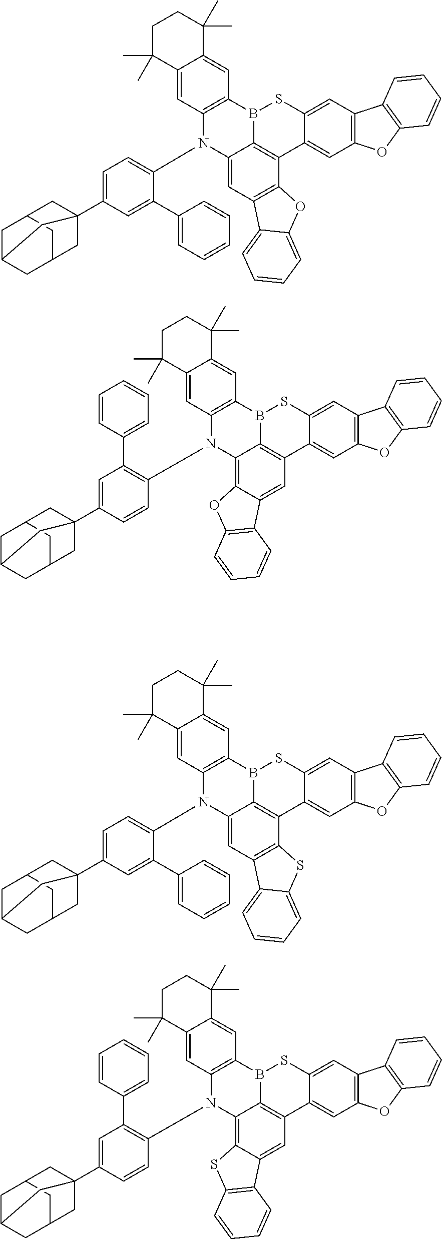

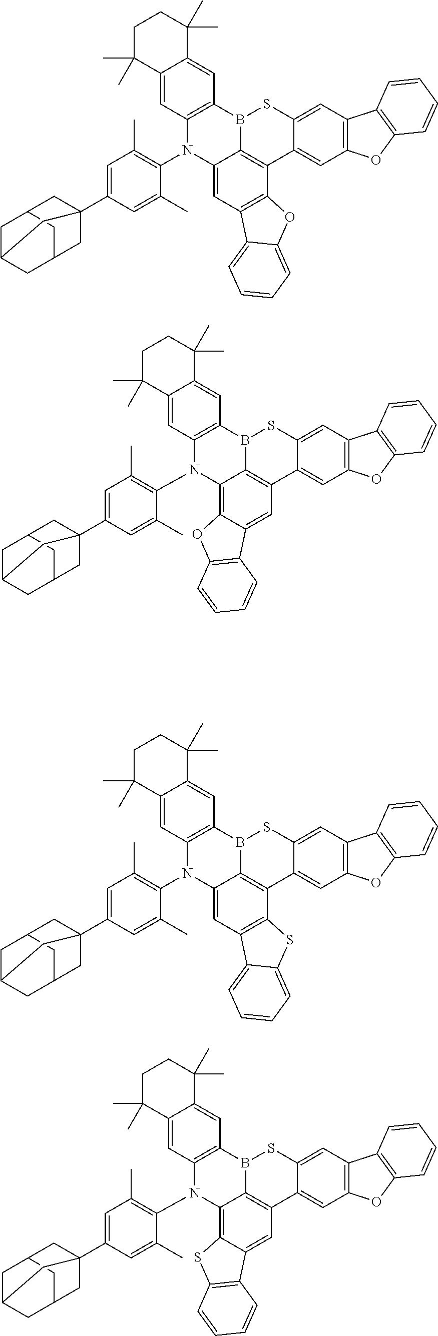 [SMILES: Cc1cc(C23CC4CC(CC(C4)C2)C3)cc(C)c1N1c2cc3c(cc2B2Sc4cc5c(cc4-c4c2c1cc1c4oc2ccccc21)oc1ccccc15)C(C)(C)CCC3(C)C ; Cc1cc(C23CC4CC(CC(C4)C2)C3)cc(C)c1N1c2cc3c(cc2B2Sc4cc5c(cc4-c4cc6c(oc7ccccc76)c1c42)oc1ccccc15)C(C)(C)CCC3(C)C ; Cc1cc(C23CC4CC(CC(C4)C2)C3)cc(C)c1N1c2cc3c(cc2B2Sc4cc5c(cc4-c4c2c1cc1c4sc2ccccc21)oc1ccccc15)C(C)(C)CCC3(C)C ; Cc1cc(C23CC4CC(CC(C4)C2)C3)cc(C)c1N1c2cc3c(cc2B2Sc4cc5c(cc4-c4cc6c(sc7ccccc76)c1c42)oc1ccccc15)C(C)(C)CCC3(C)C]

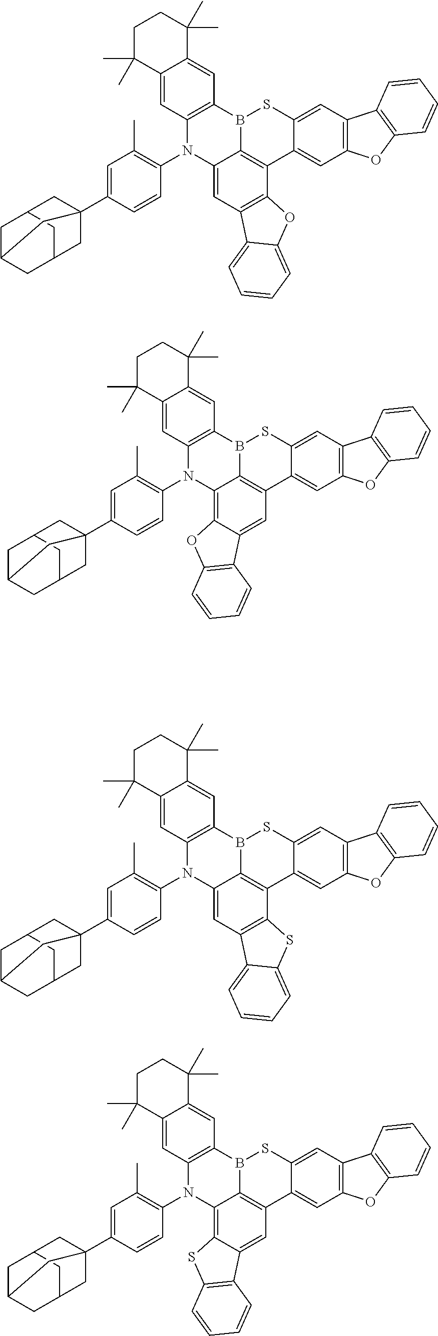 [SMILES: Cc1cc(C23CC4CC(CC(C4)C2)C3)ccc1N1c2cc3c(cc2B2Sc4cc5c(cc4-c4c2c1cc1c4oc2ccccc21)oc1ccccc15)C(C)(C)CCC3(C)C ; Cc1cc(C23CC4CC(CC(C4)C2)C3)ccc1N1c2cc3c(cc2B2Sc4cc5c(cc4-c4cc6c(oc7ccccc76)c1c42)oc1ccccc15)C(C)(C)CCC3(C)C ; Cc1cc(C23CC4CC(CC(C4)C2)C3)ccc1N1c2cc3c(cc2B2Sc4cc5c(cc4-c4c2c1cc1c4sc2ccccc21)oc1ccccc15)C(C)(C)CCC3(C)C ; Cc1cc(C23CC4CC(CC(C4)C2)C3)ccc1N1c2cc3c(cc2B2Sc4cc5c(cc4-c4cc6c(sc7ccccc76)c1c42)oc1ccccc15)C(C)(C)CCC3(C)C]

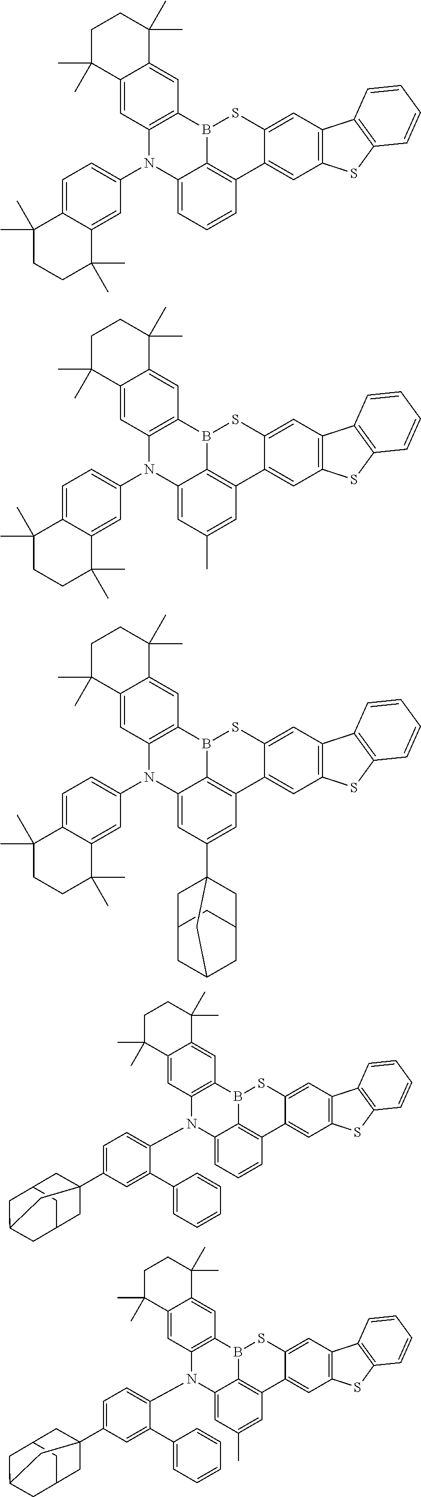

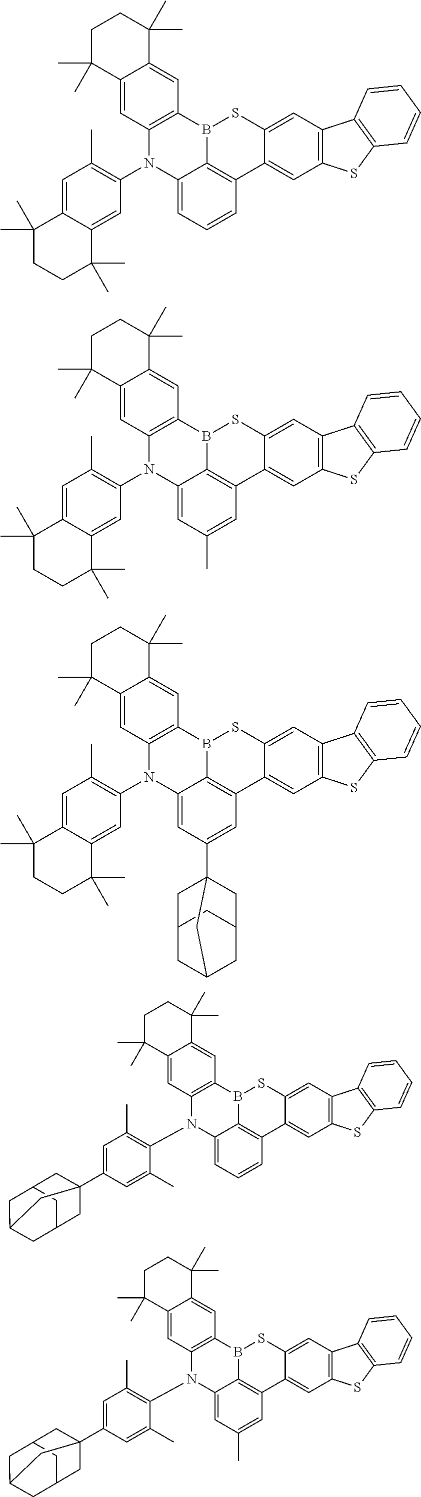

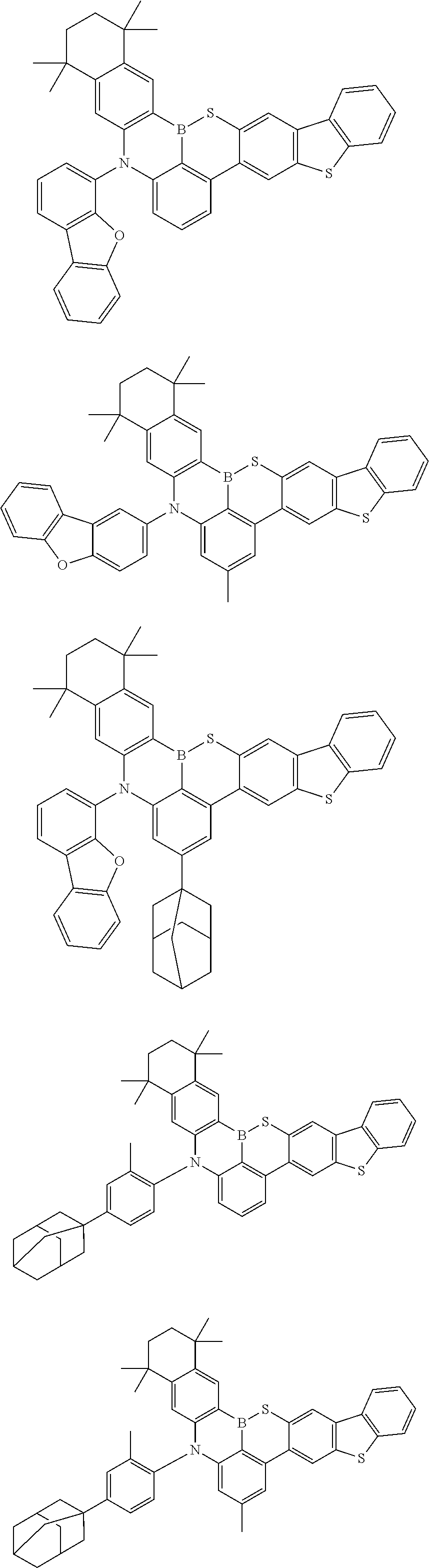 [SMILES: CC1(C)CCC(C)(C)c2cc3c(cc21)B1Sc2cc4c(cc2-c2cccc(c21)N3c1cccc2c1oc1ccccc12)sc1ccccc14 ; Cc1cc2c3c(c1)N(c1ccc4oc5ccccc5c4c1)c1cc4c(cc1B3Sc1cc3c(cc1-2)sc1ccccc13)C(C)(C)CCC4(C)C ; CC1(C)CCC(C)(C)c2cc3c(cc21)B1Sc2cc4c(cc2-c2cc(C56CC7CC(CC(C7)C5)C6)cc(c21)N3c1cccc2c1oc1ccccc12)sc1ccccc14 ; Cc1cc(C23CC4CC(CC(C4)C2)C3)ccc1N1c2cc3c(cc2B2Sc4cc5c(cc4-c4cccc1c42)sc1ccccc15)C(C)(C)CCC3(C)C ; Cc1cc2c3c(c1)N(c1ccc(C45CC6CC(CC(C6)C4)C5)cc1C)c1cc4c(cc1B3Sc1cc3c(cc1-2)sc1ccccc13)C(C)(C)CCC4(C)C]

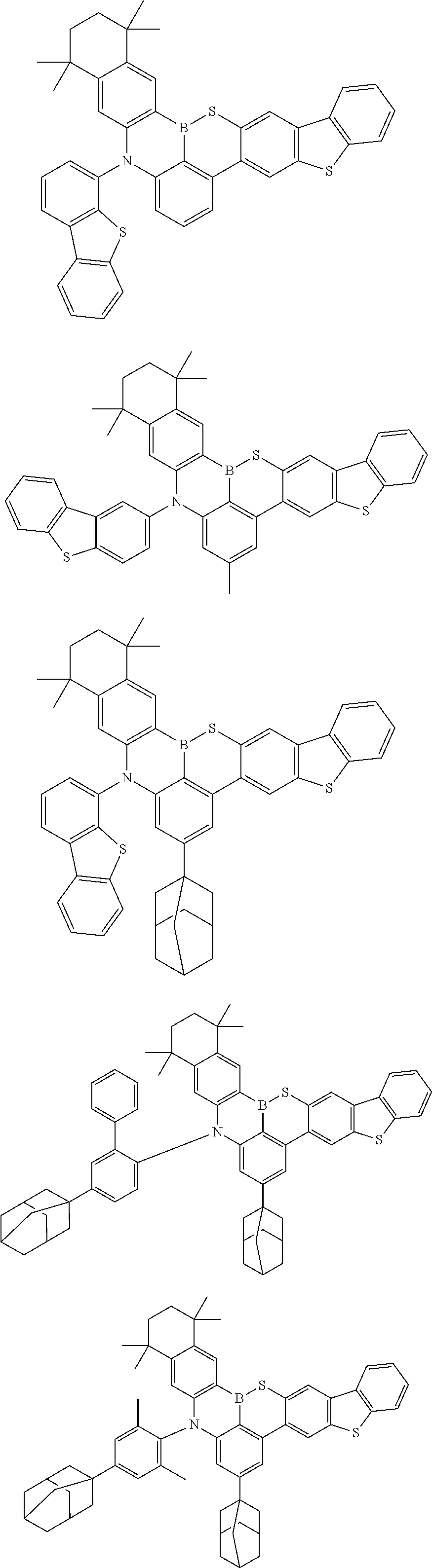

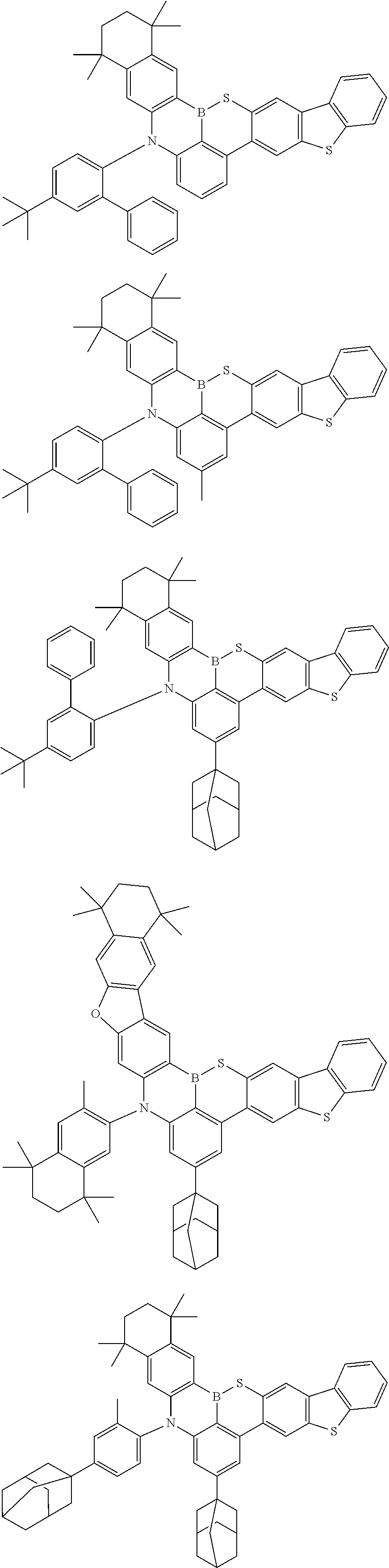

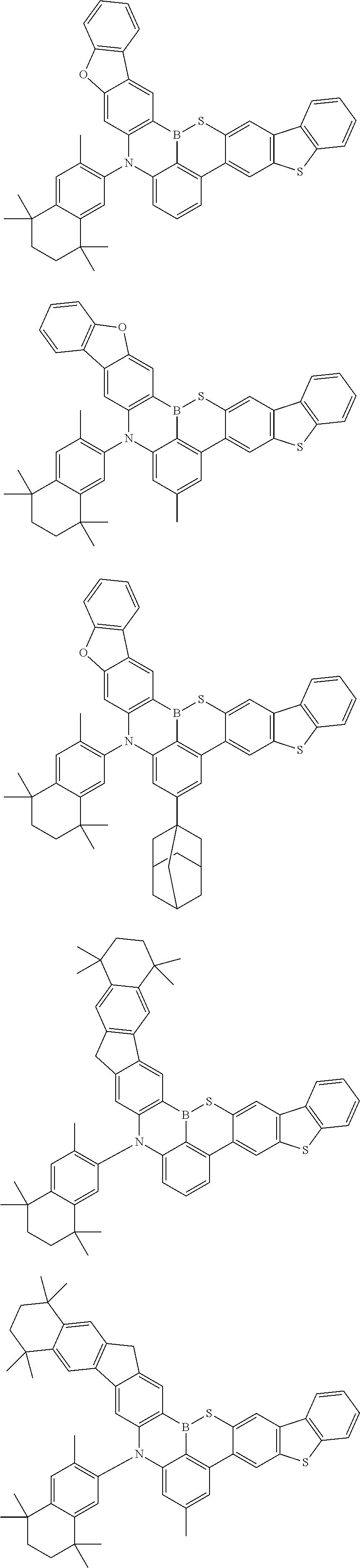

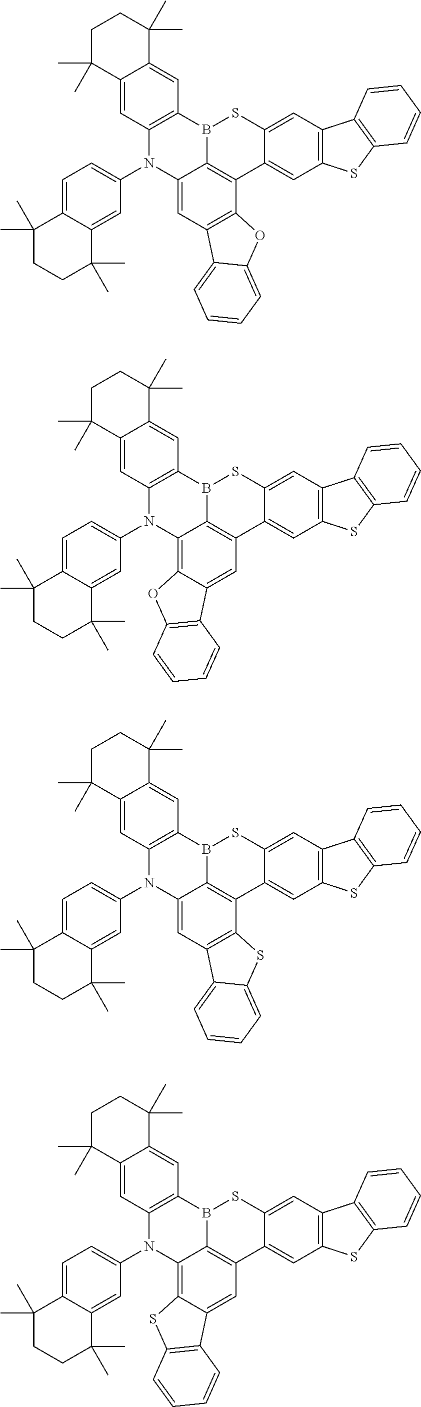

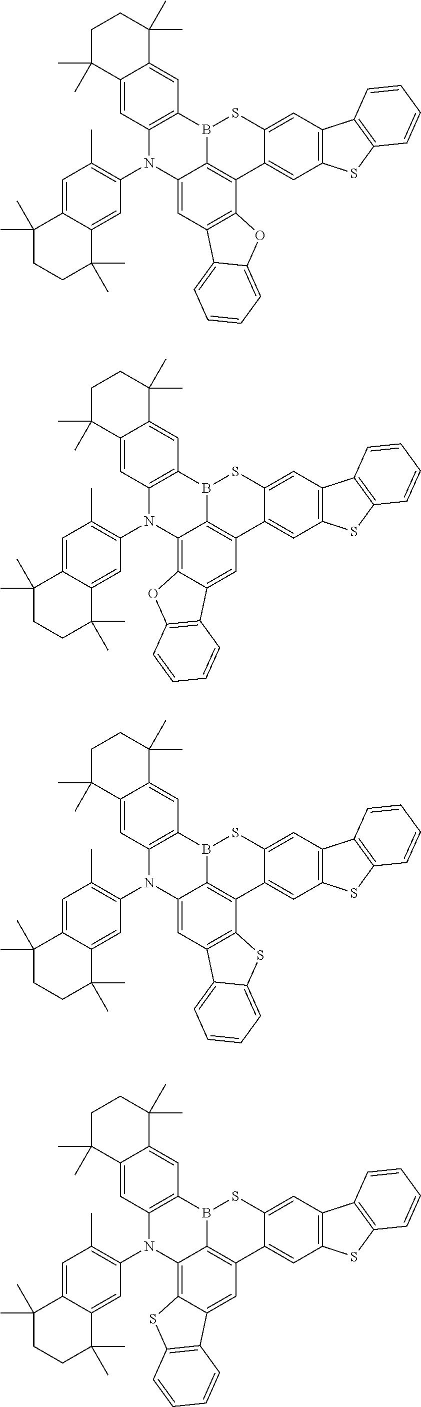

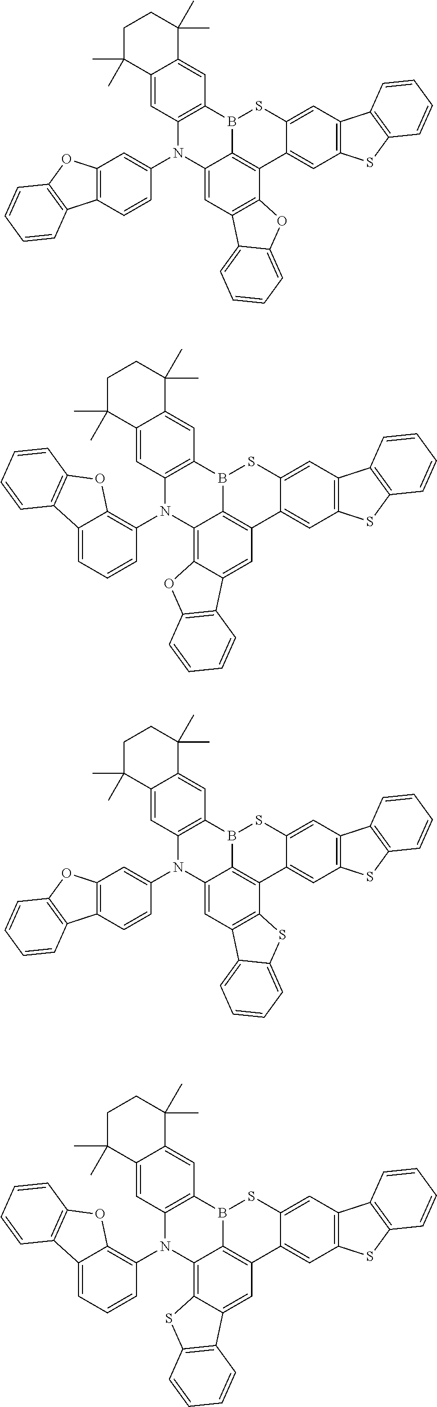

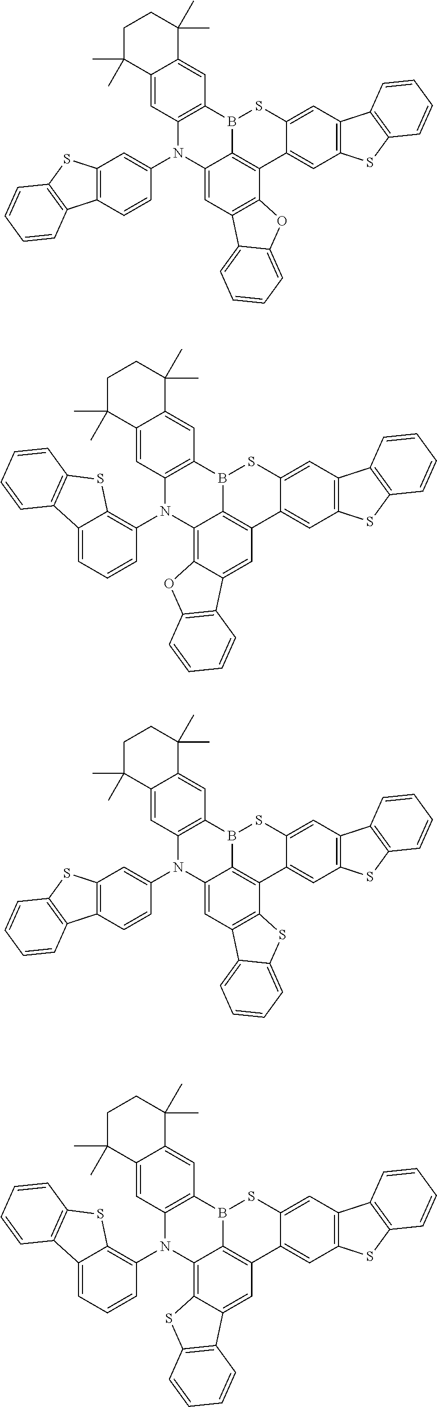

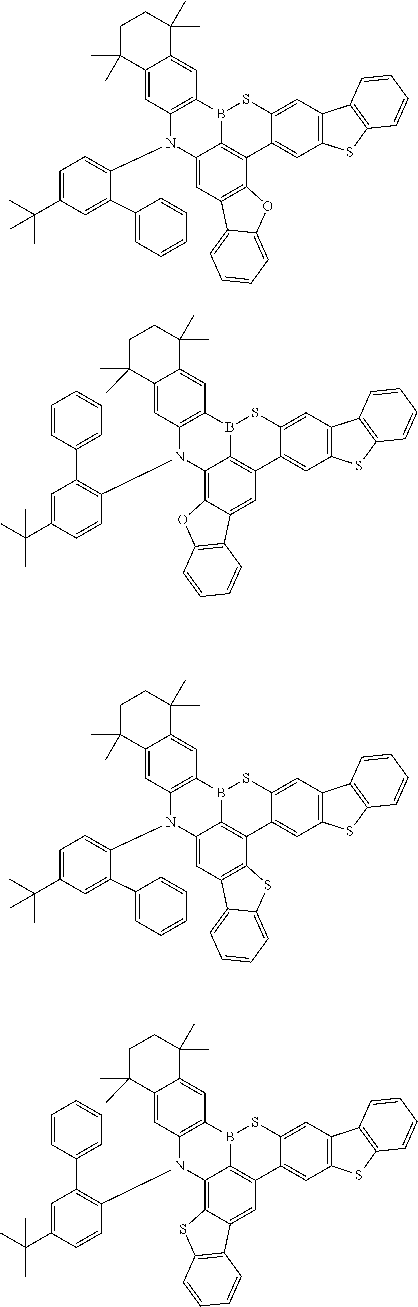 [SMILES: CC(C)(C)c1ccc(N2c3cc4c(cc3B3Sc5cc6c(cc5-c5c3c2cc2c5oc3ccccc32)sc2ccccc26)C(C)(C)CCC4(C)C)c(-c2ccccc2)c1 ; CC(C)(C)c1ccc(N2c3cc4c(cc3B3Sc5cc6c(cc5-c5cc7c(oc8ccccc87)c2c53)sc2ccccc26)C(C)(C)CCC4(C)C)c(-c2ccccc2)c1 ; CC(C)(C)c1ccc(N2c3cc4c(cc3B3Sc5cc6c(cc5-c5c3c2cc2c5sc3ccccc32)sc2ccccc26)C(C)(C)CCC4(C)C)c(-c2ccccc2)c1 ; CC(C)(C)c1ccc(N2c3cc4c(cc3B3Sc5cc6c(cc5-c5cc7c(sc8ccccc87)c2c53)sc2ccccc26)C(C)(C)CCC4(C)C)c(-c2ccccc2)c1]

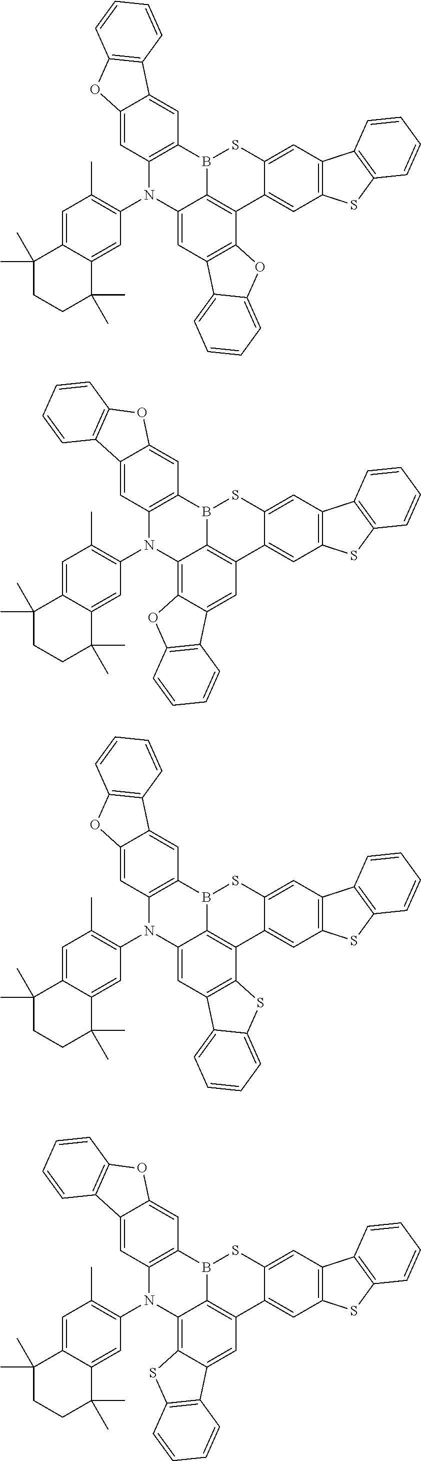

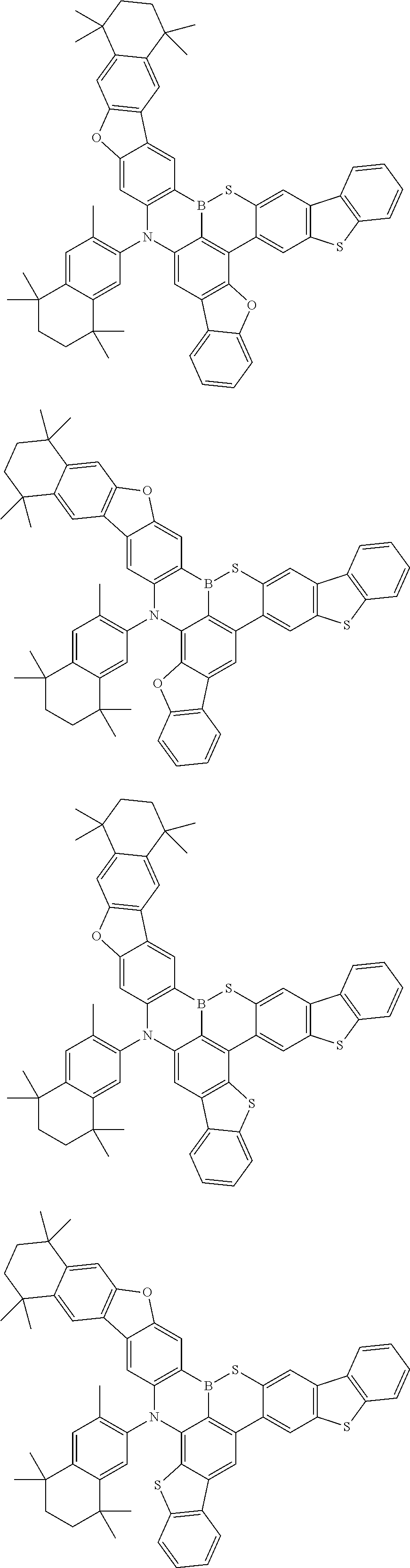

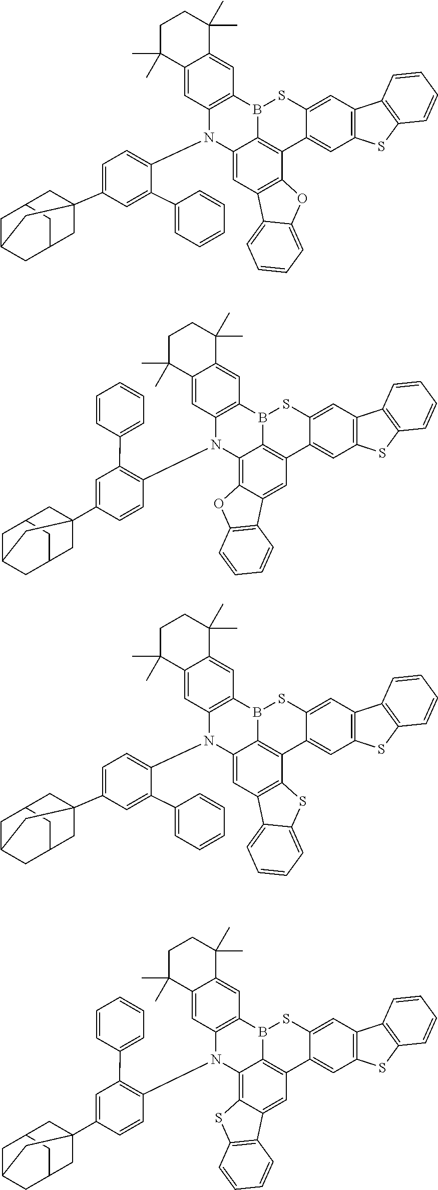

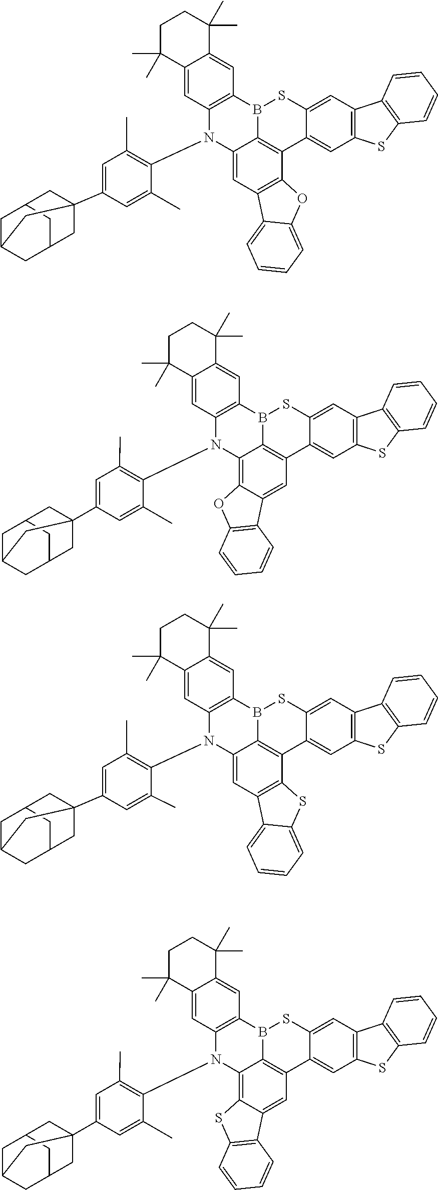

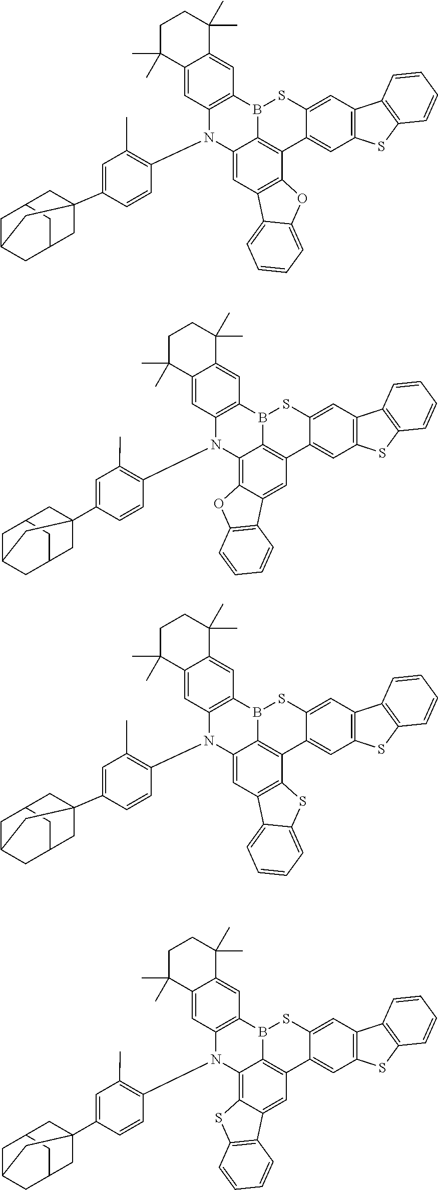

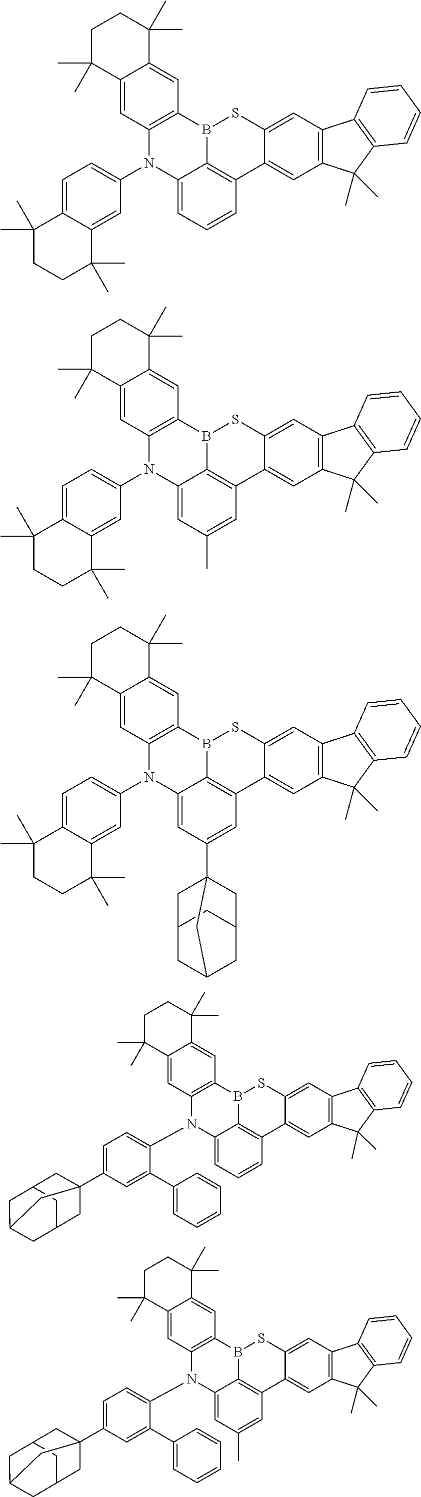

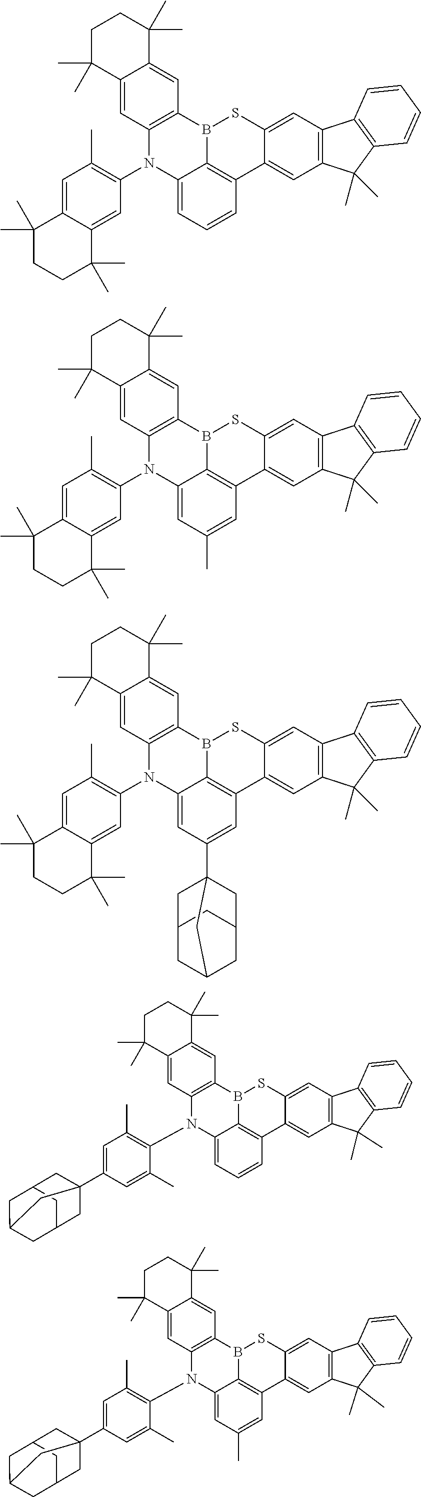

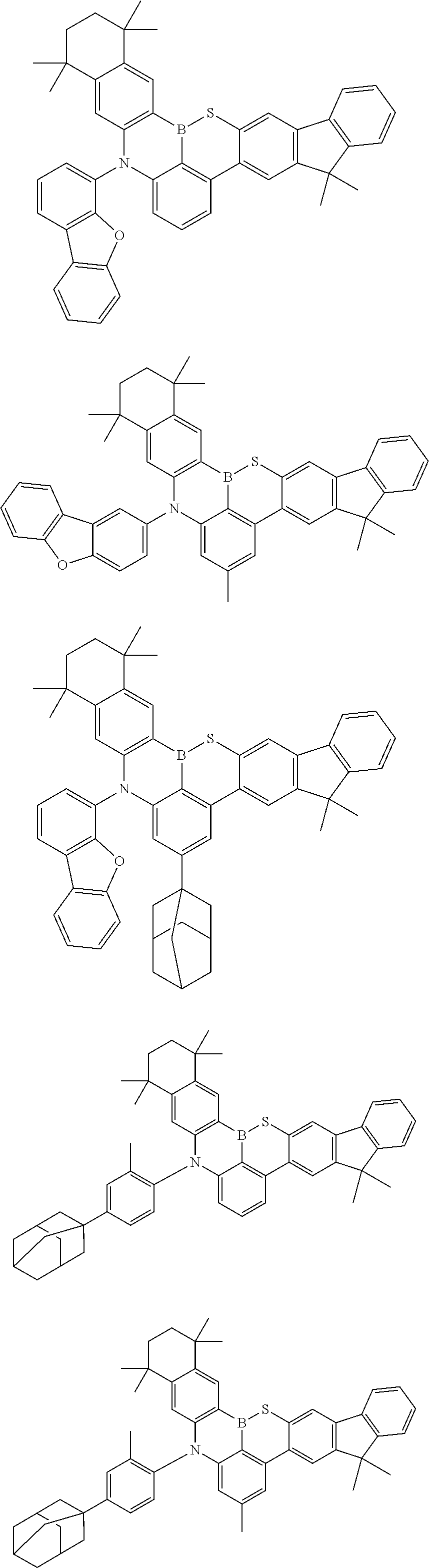

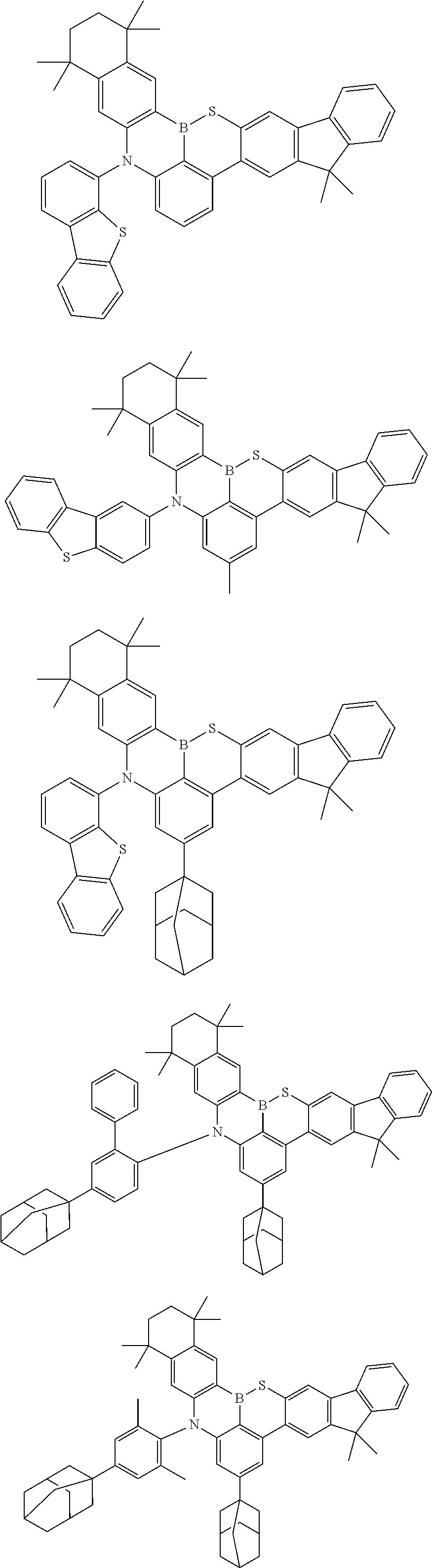

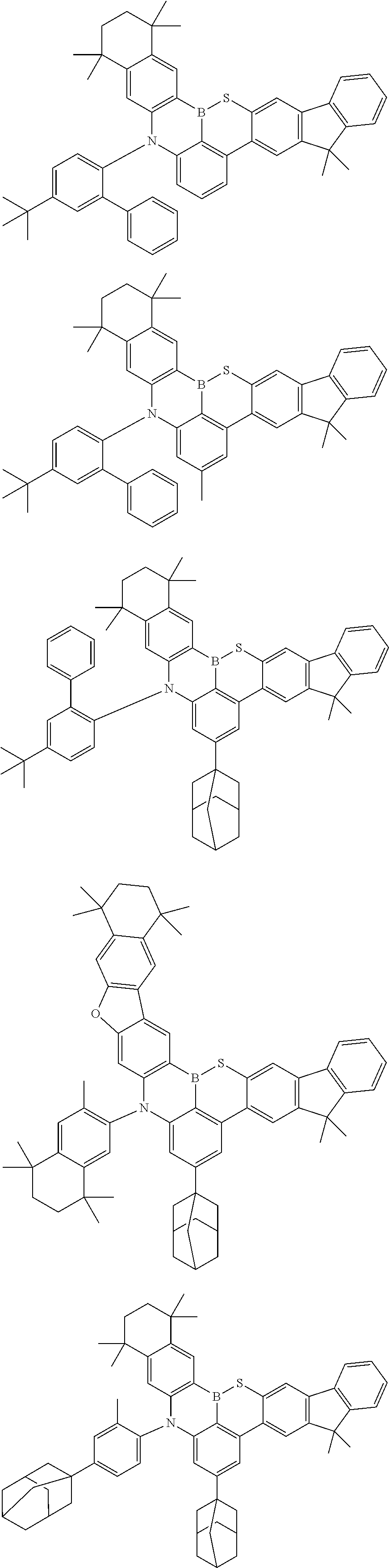

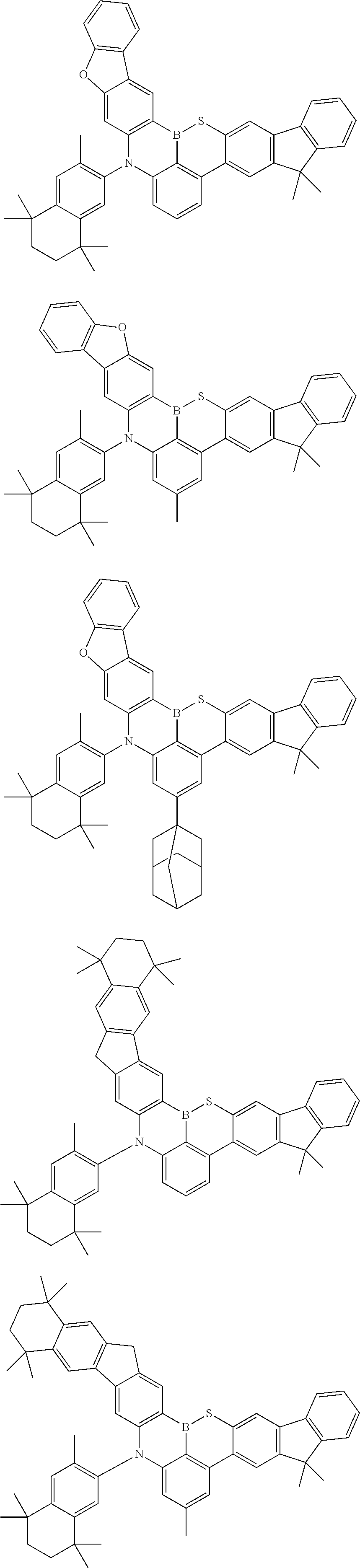

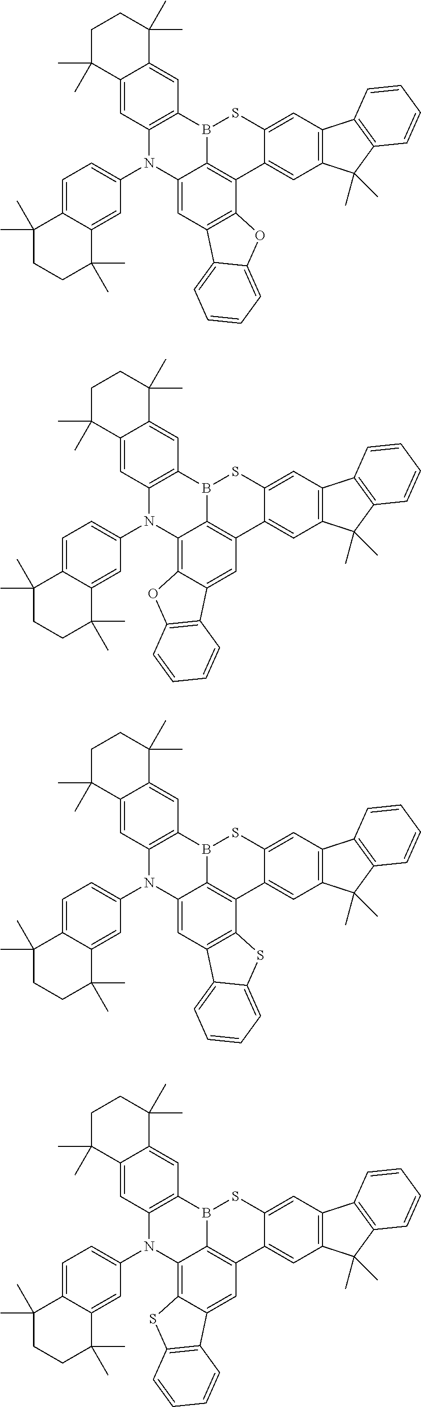

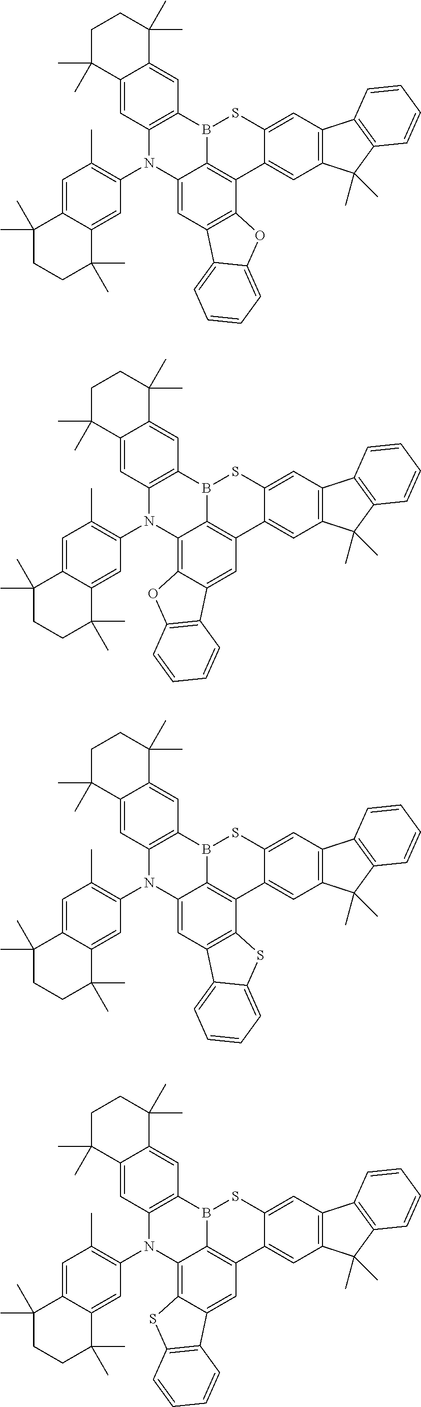

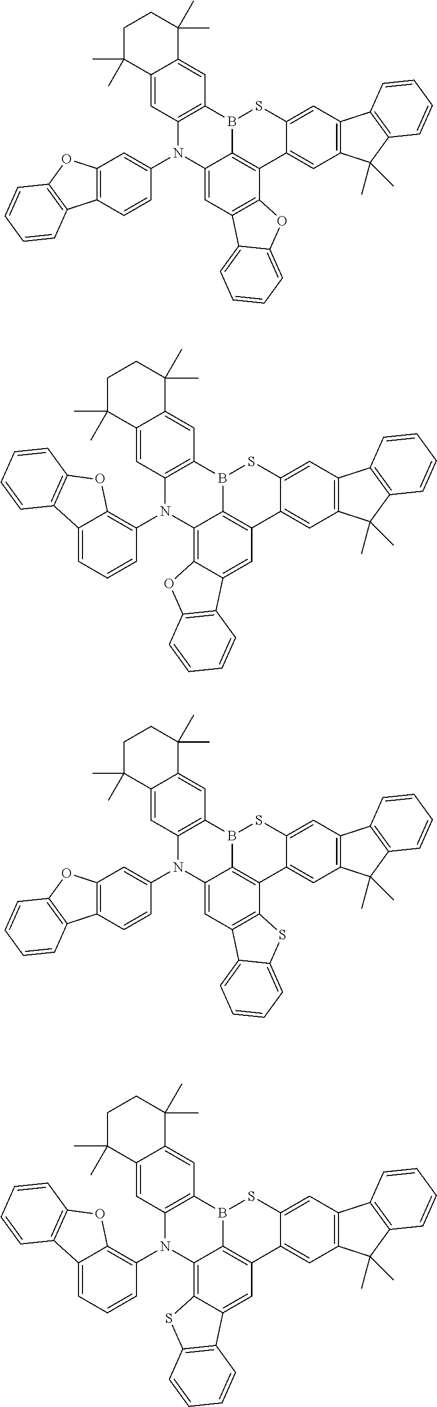

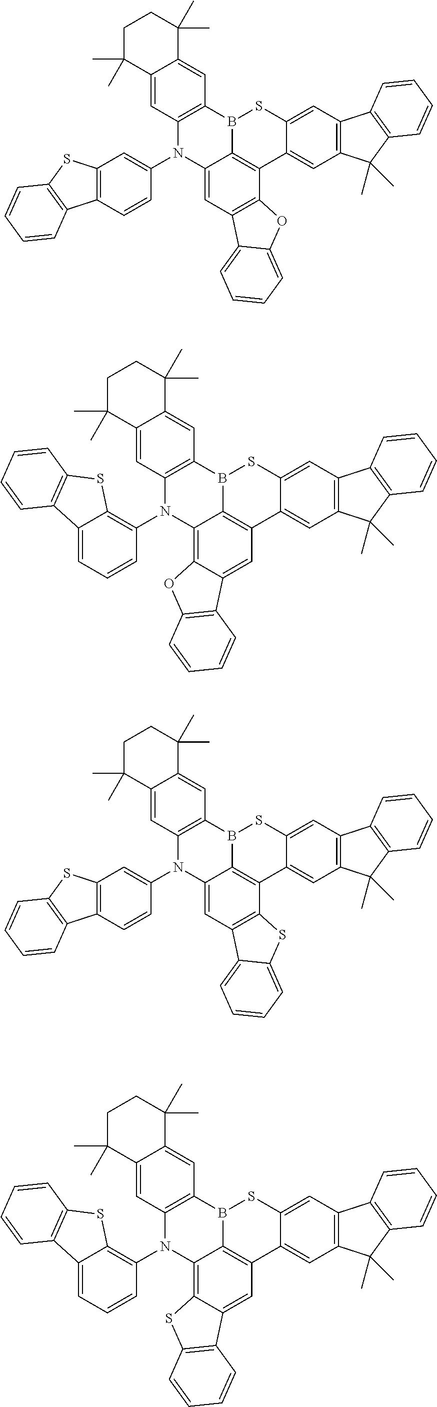

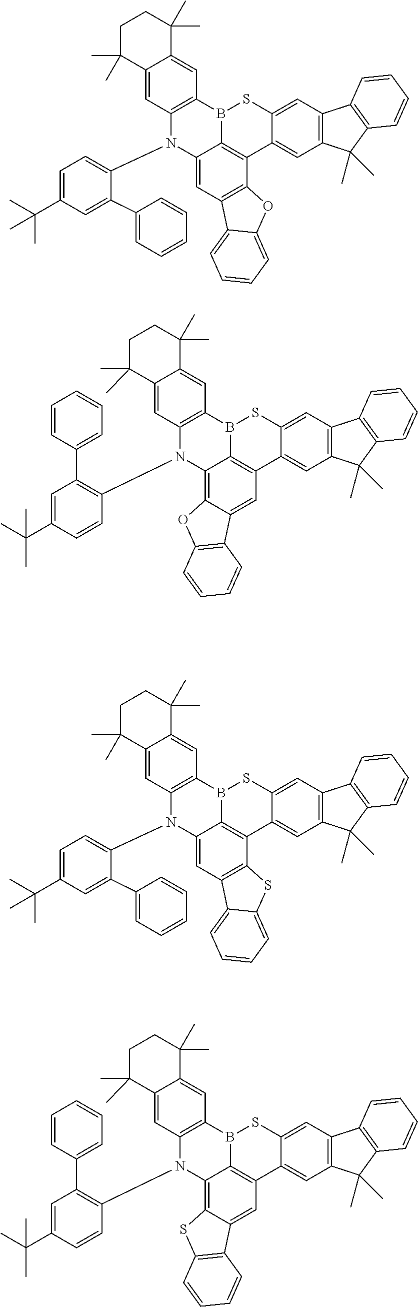 [SMILES: CC(C)(C)c1ccc(N2c3cc4c(cc3B3Sc5cc6c(cc5-c5c3c2cc2c5oc3ccccc32)C(C)(C)c2ccccc2-6)C(C)(C)CCC4(C)C)c(-c2ccccc2)c1 ; CC(C)(C)c1ccc(N2c3cc4c(cc3B3Sc5cc6c(cc5-c5cc7c(oc8ccccc87)c2c53)C(C)(C)c2ccccc2-6)C(C)(C)CCC4(C)C)c(-c2ccccc2)c1 ; CC(C)(C)c1ccc(N2c3cc4c(cc3B3Sc5cc6c(cc5-c5c3c2cc2c5sc3ccccc32)C(C)(C)c2ccccc2-6)C(C)(C)CCC4(C)C)c(-c2ccccc2)c1 ; CC(C)(C)c1ccc(N2c3cc4c(cc3B3Sc5cc6c(cc5-c5cc7c(sc8ccccc87)c2c53)C(C)(C)c2ccccc2-6)C(C)(C)CCC4(C)C)c(-c2ccccc2)c1]

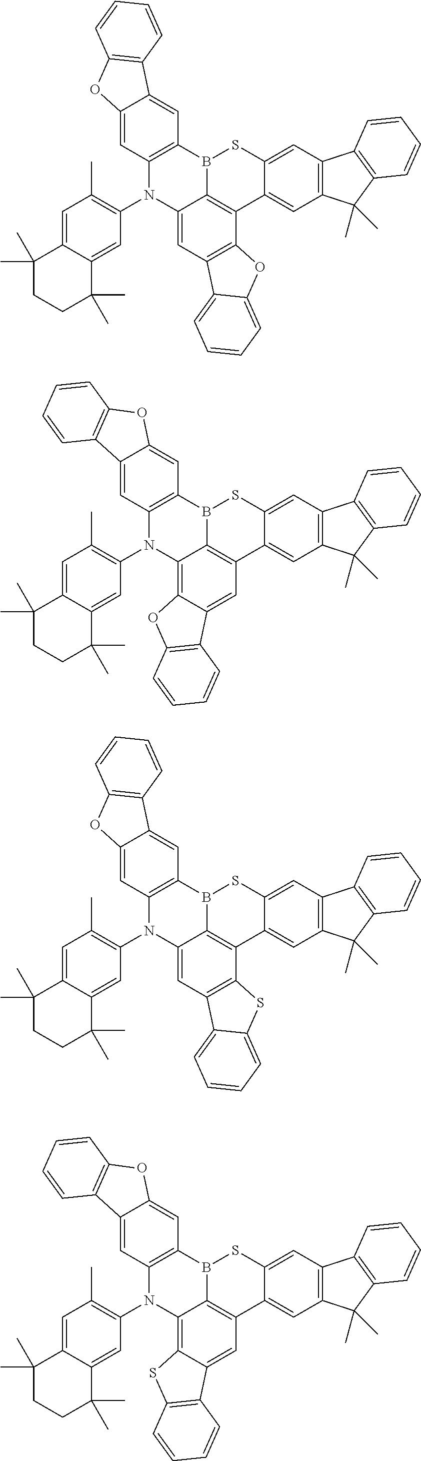

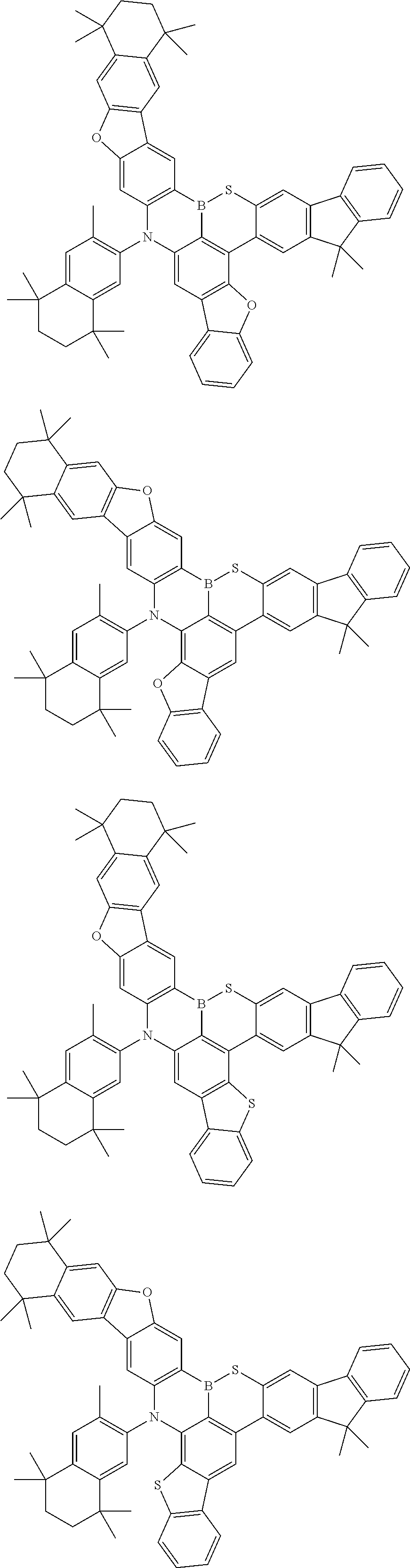

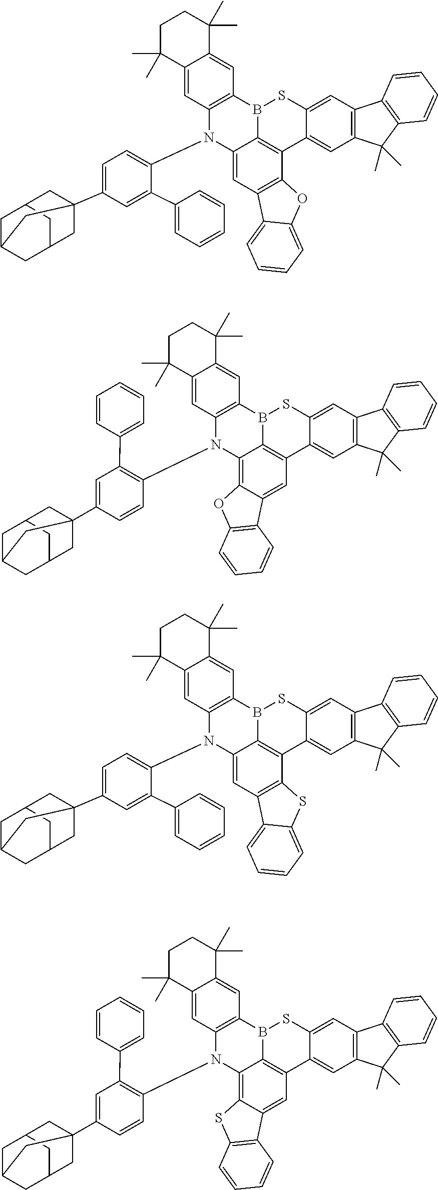

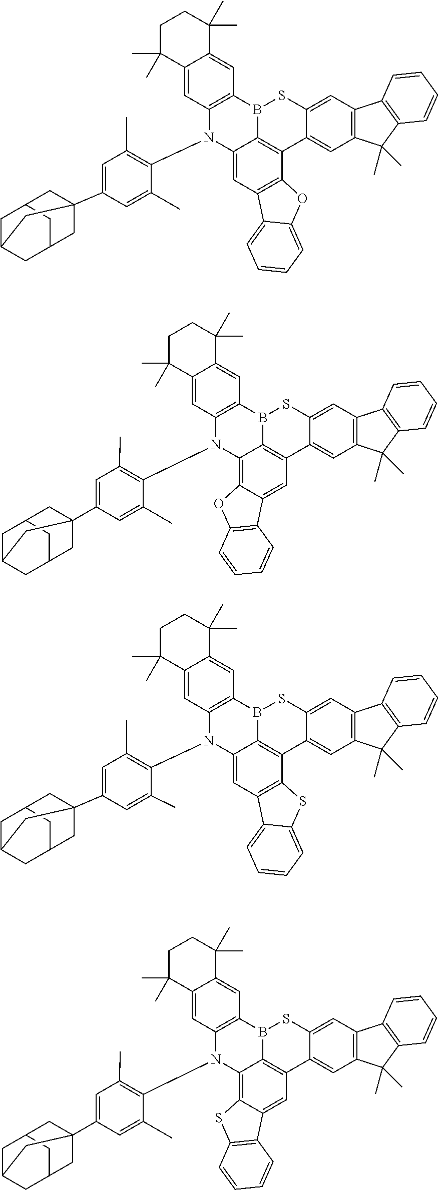

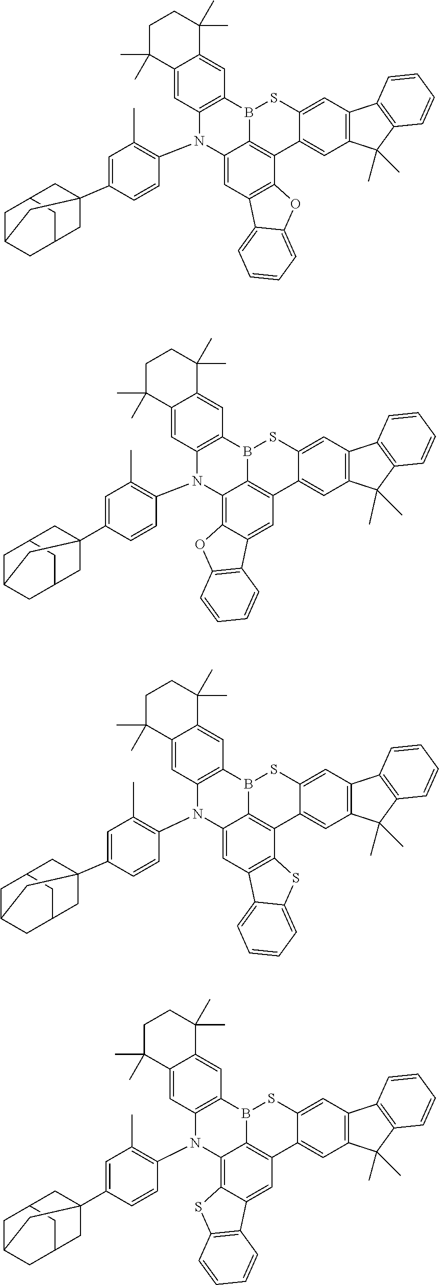 [SMILES: Cc1cc(C23CC4CC(CC(C4)C2)C3)ccc1N1c2cc3c(cc2B2Sc4cc5c(cc4-c4c2c1cc1c4oc2ccccc21)C(C)(C)c1ccccc1-5)C(C)(C)CCC3(C)C ; Cc1cc(C23CC4CC(CC(C4)C2)C3)ccc1N1c2cc3c(cc2B2Sc4cc5c(cc4-c4cc6c(oc7ccccc76)c1c42)C(C)(C)c1ccccc1-5)C(C)(C)CCC3(C)C ; Cc1cc(C23CC4CC(CC(C4)C2)C3)ccc1N1c2cc3c(cc2B2Sc4cc5c(cc4-c4c2c1cc1c4sc2ccccc21)C(C)(C)c1ccccc1-5)C(C)(C)CCC3(C)C ; Cc1cc(C23CC4CC(CC(C4)C2)C3)ccc1N1c2cc3c(cc2B2Sc4cc5c(cc4-c4cc6c(sc7ccccc76)c1c42)C(C)(C)c1ccccc1-5)C(C)(C)CCC3(C)C]

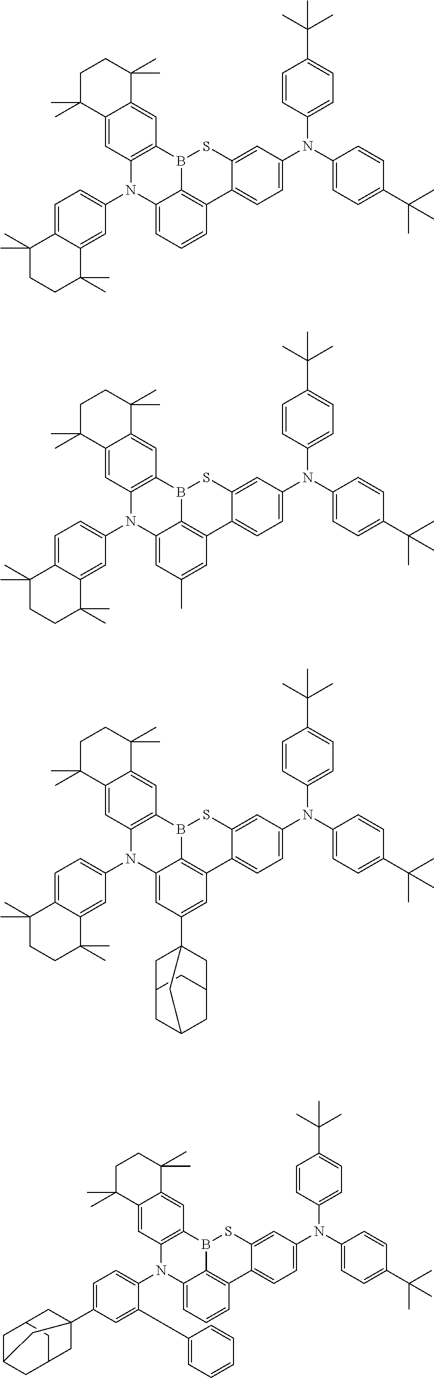

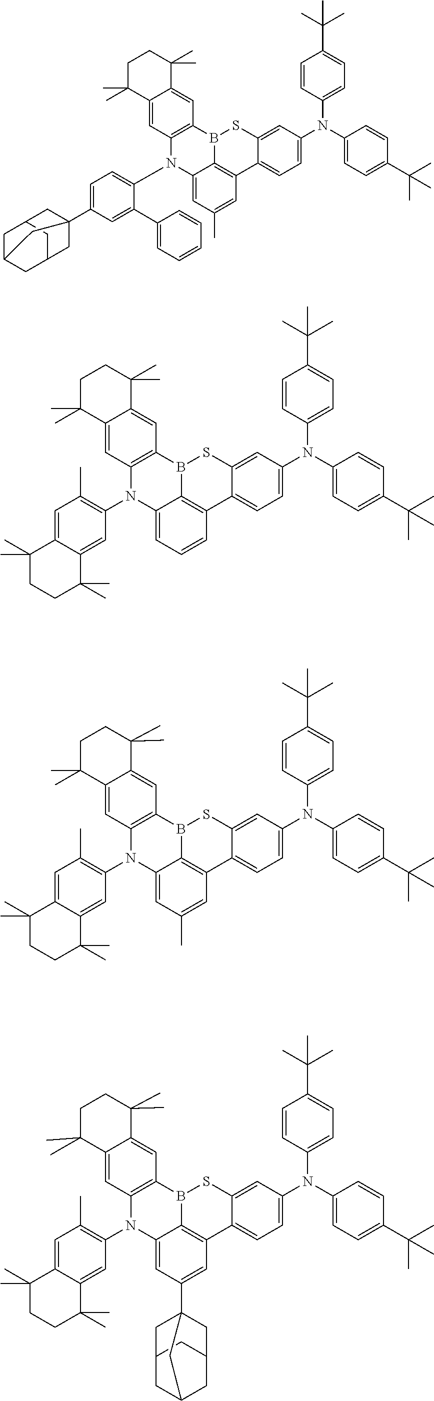

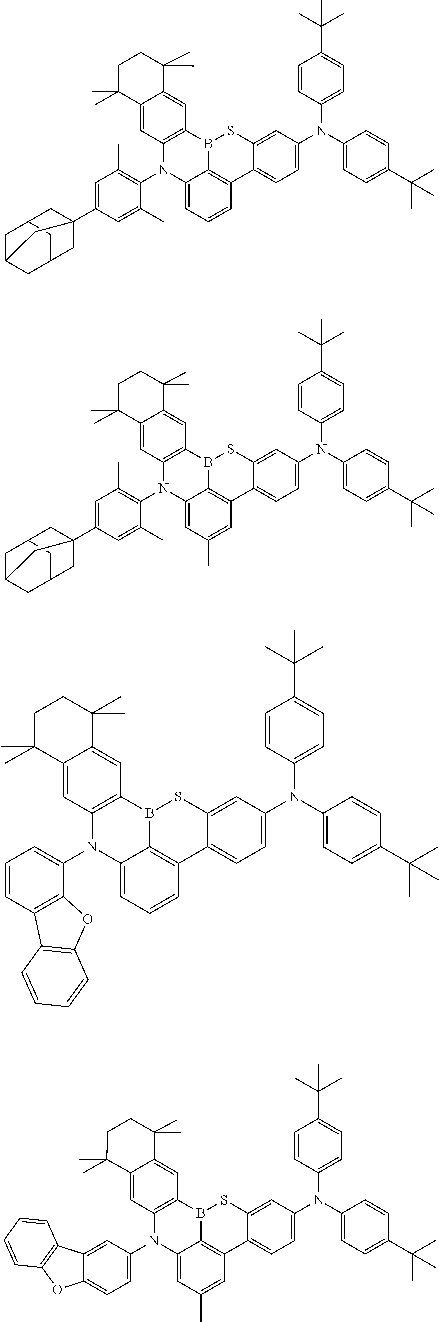

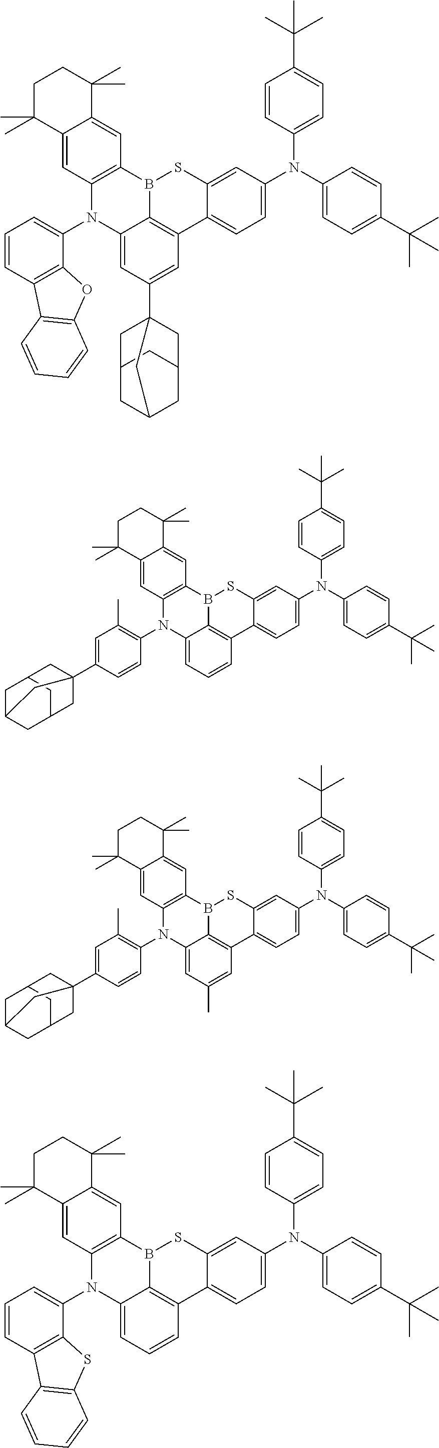

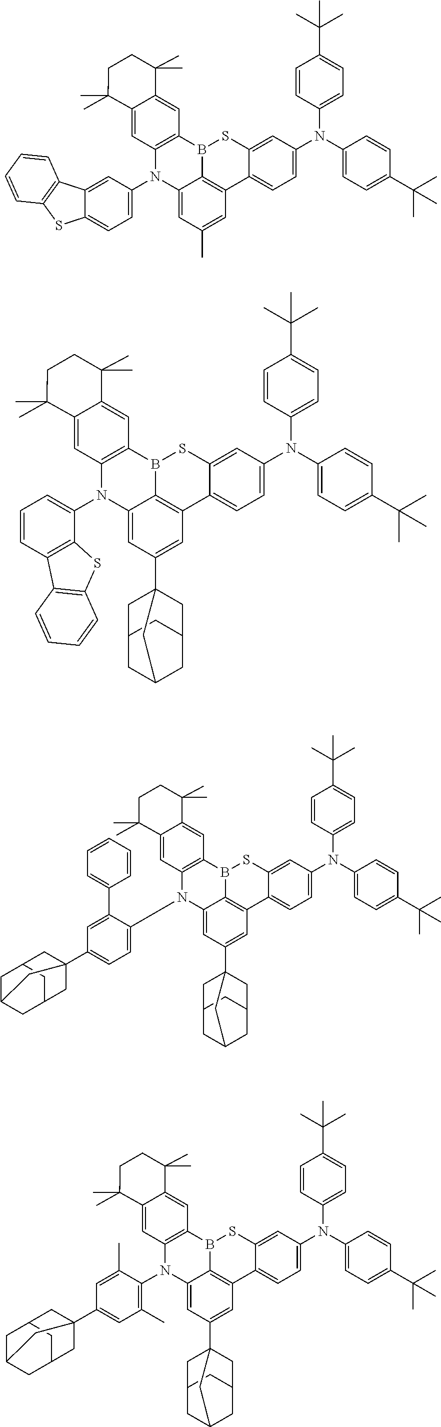

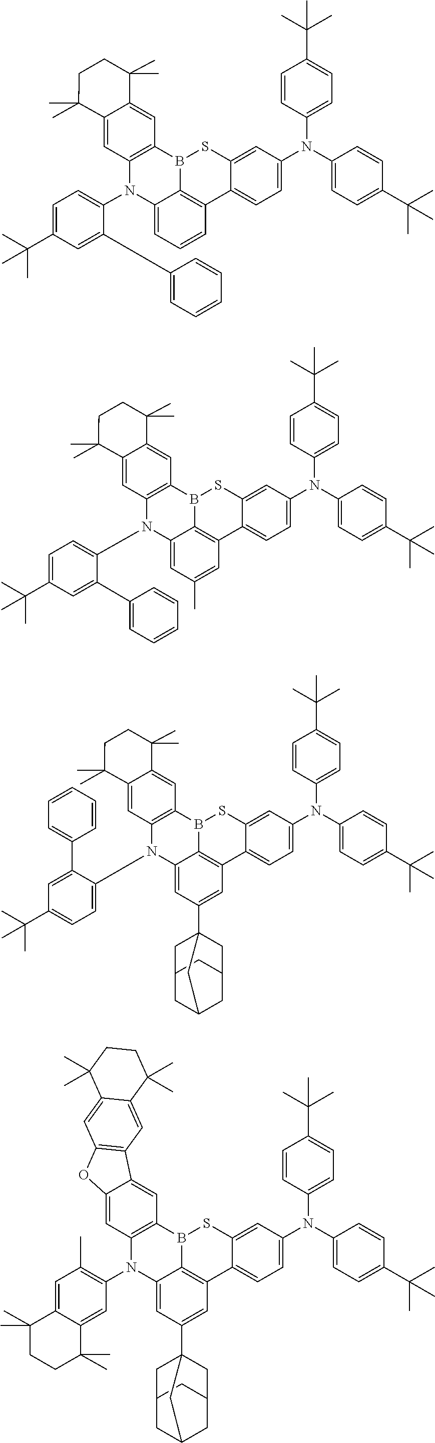

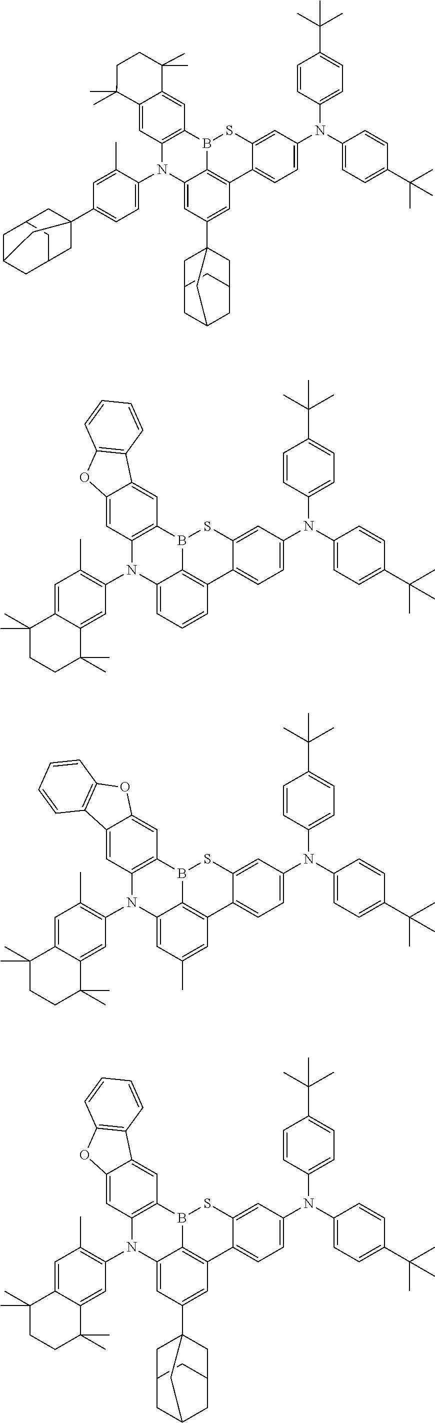

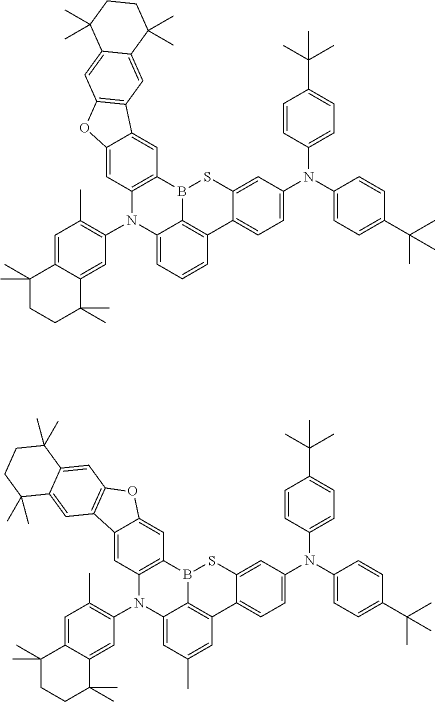 [SMILES: Cc1cc2c(cc1N1c3cc4oc5cc6c(cc5c4cc3B3Sc4cc(N(c5ccc(C(C)(C)C)cc5)c5ccc(C(C)(C)C)cc5)ccc4-c4cccc1c43)C(C)(C)CCC6(C)C)C(C)(C)CCC2(C)C ; Cc1cc2c3c(c1)N(c1cc4c(cc1C)C(C)(C)CCC4(C)C)c1cc4c(cc1B3Sc1cc(N(c3ccc(C(C)(C)C)cc3)c3ccc(C(C)(C)C)cc3)ccc1-2)oc1cc2c(cc14)C(C)(C)CCC2(C)C]

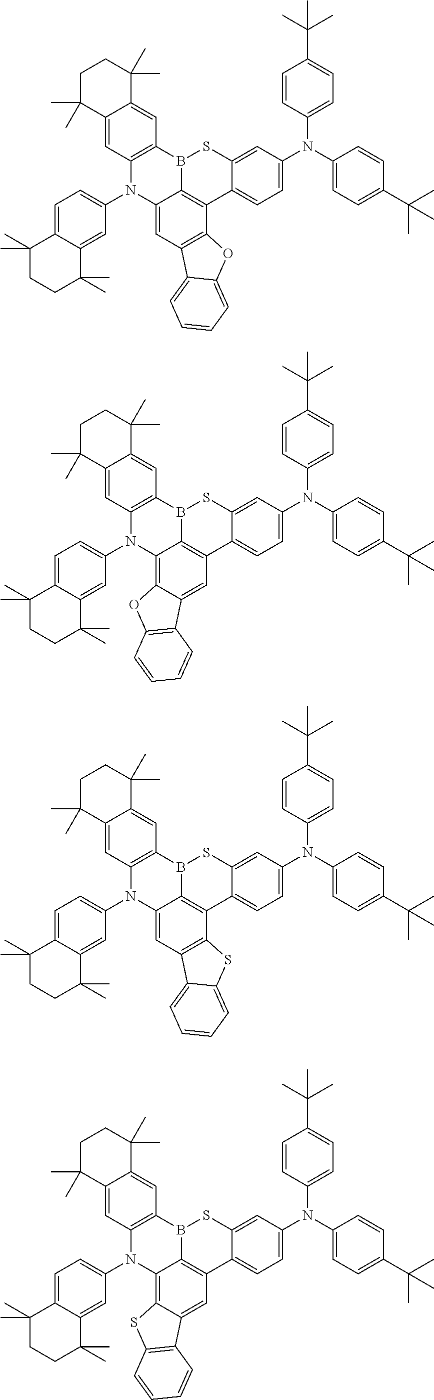

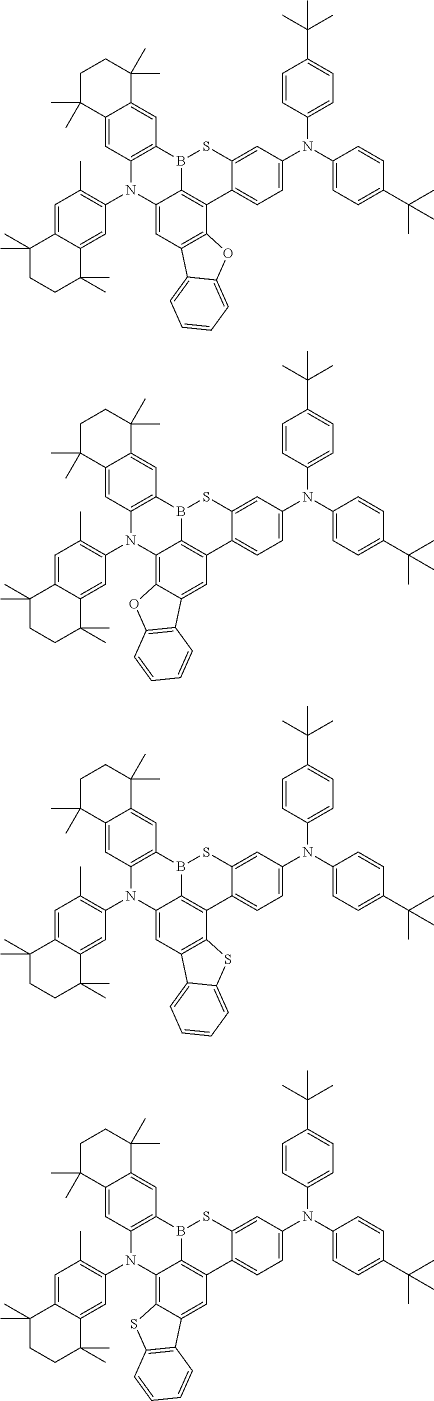

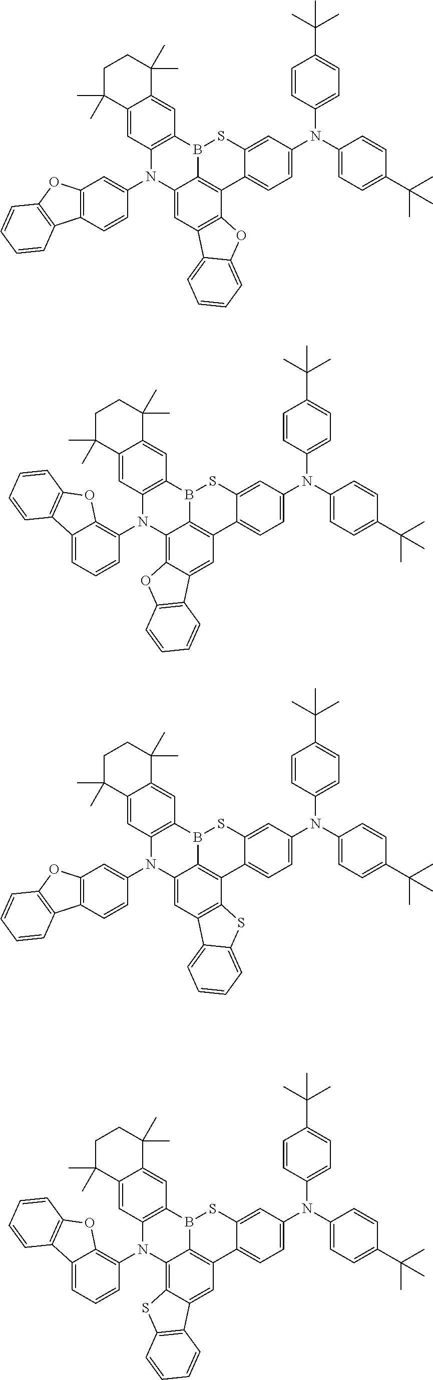

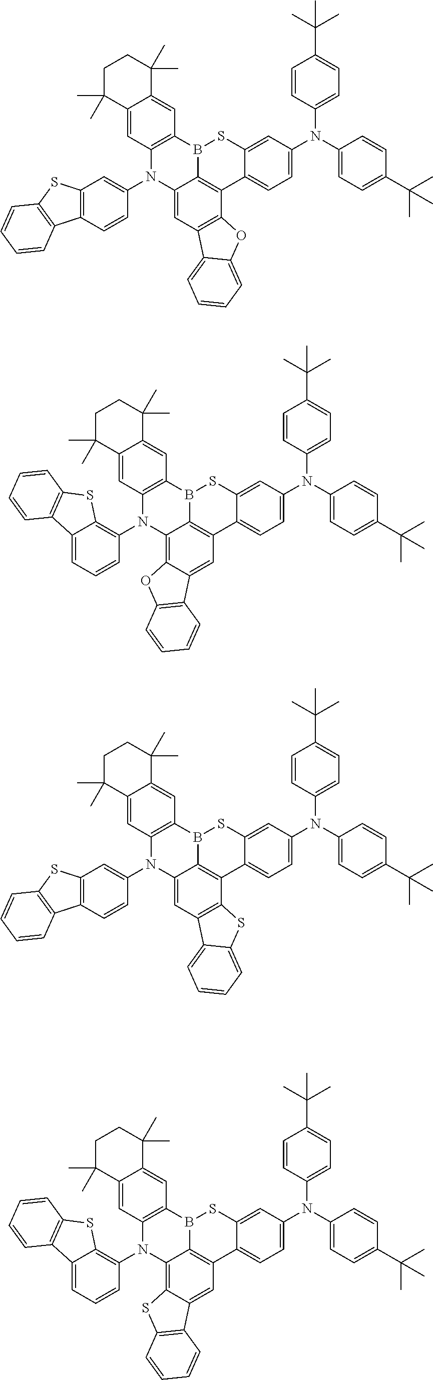

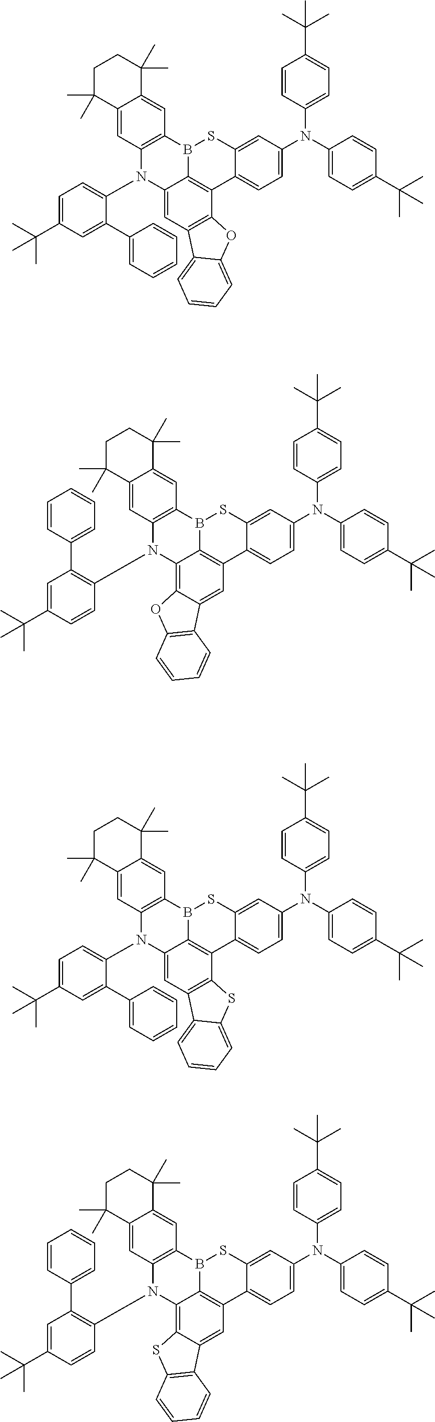

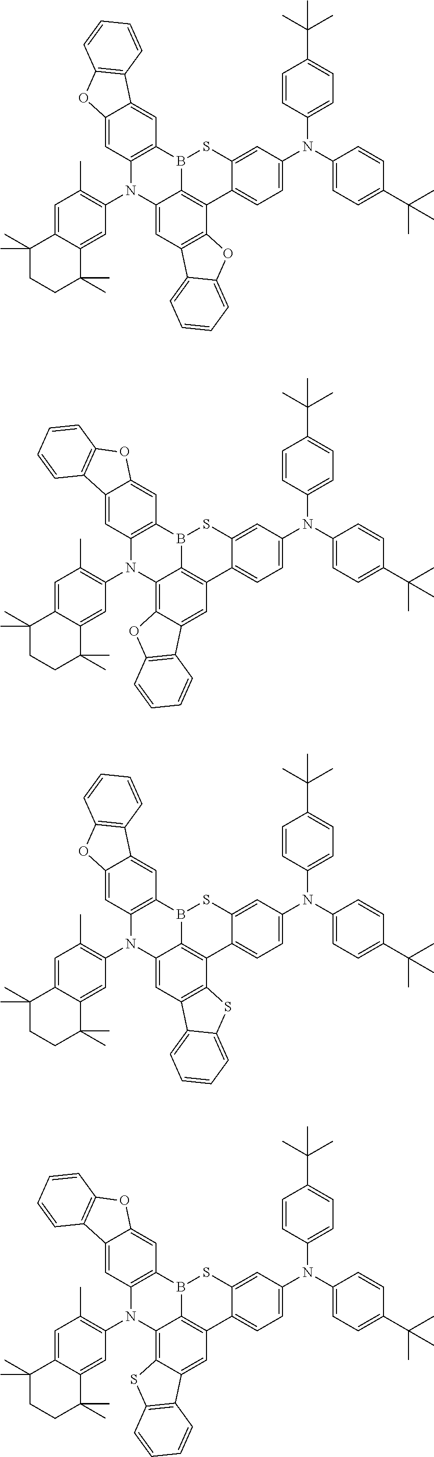

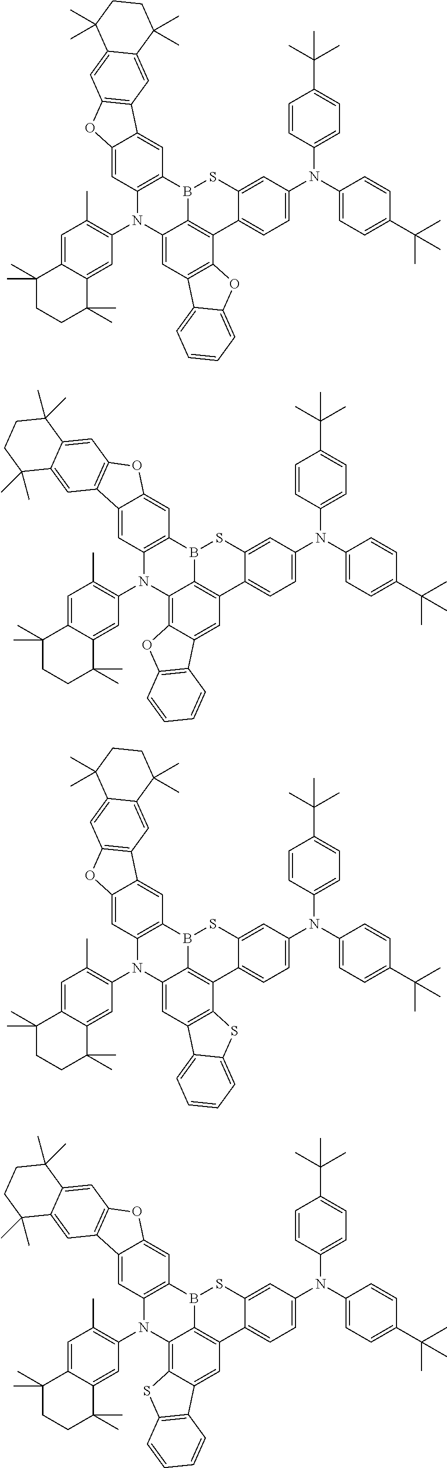

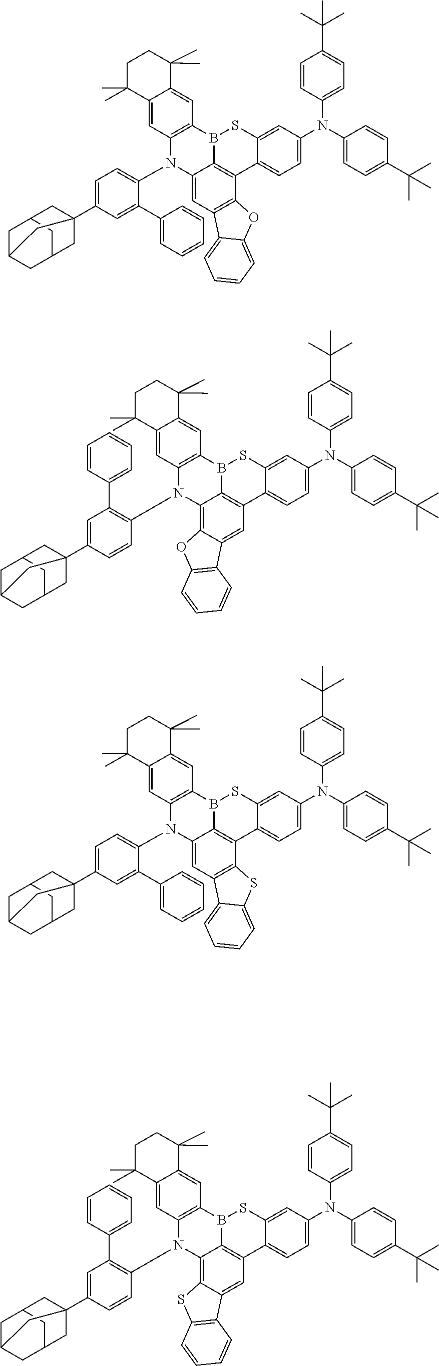

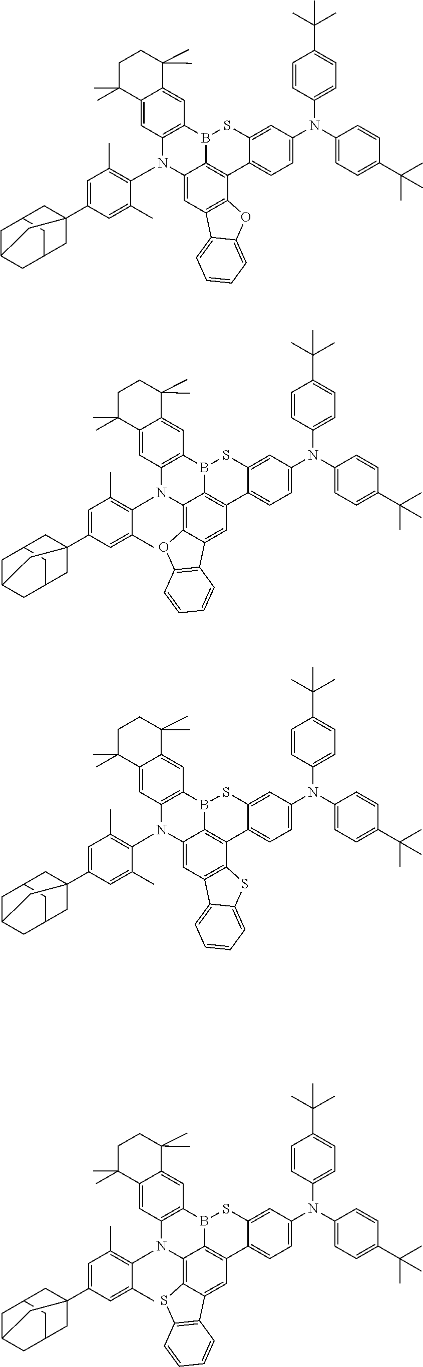

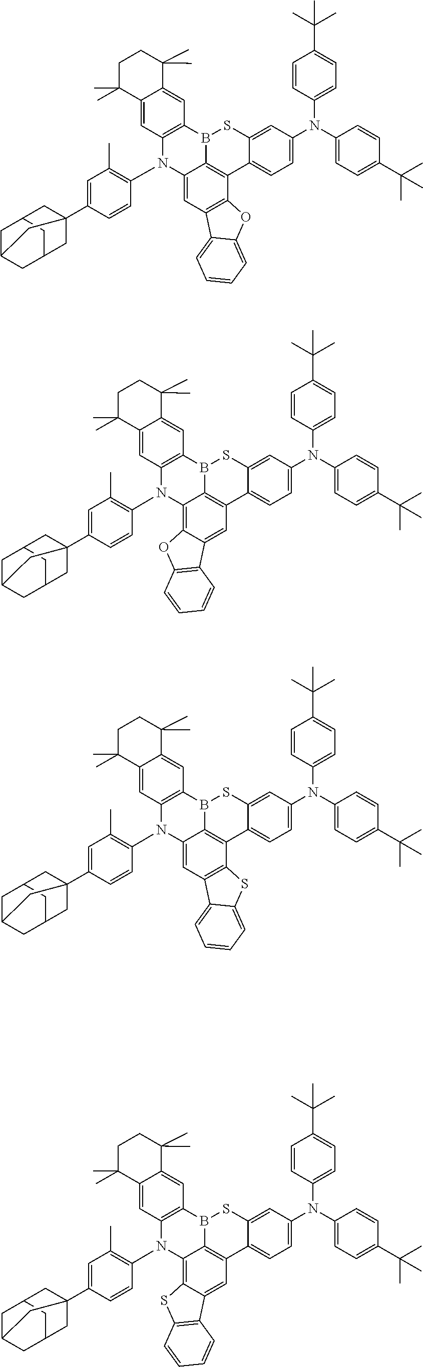

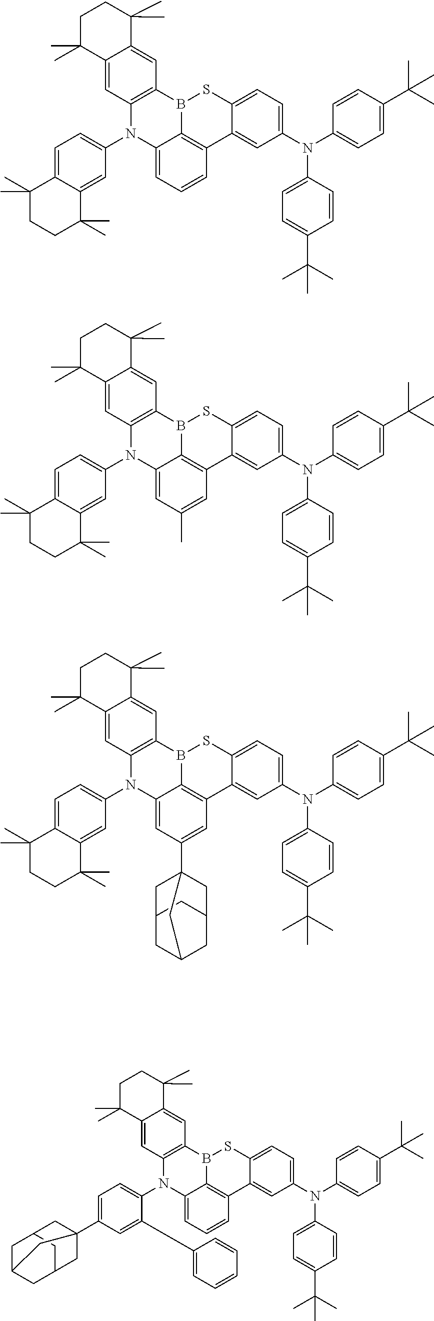

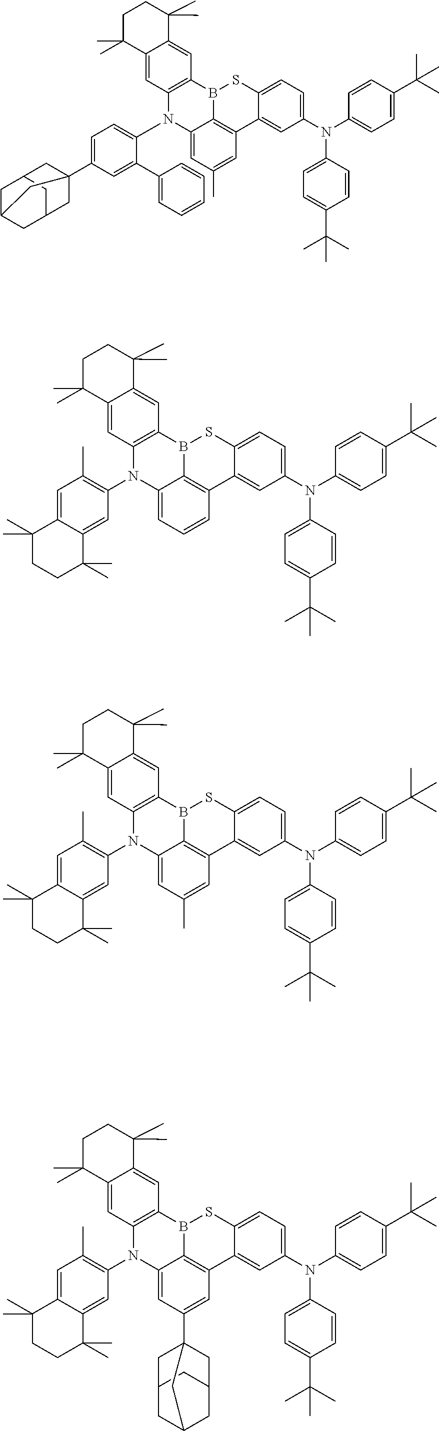

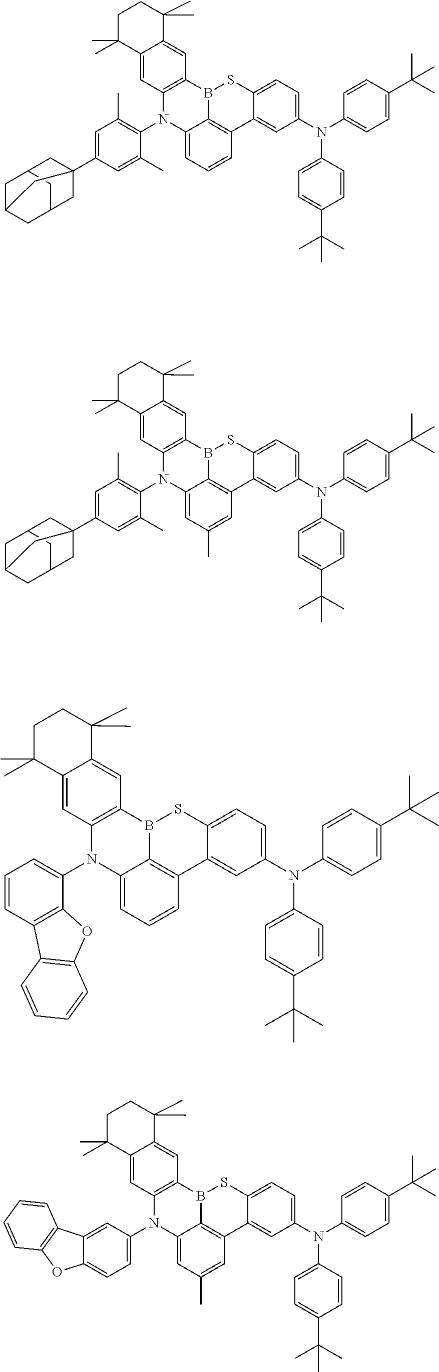

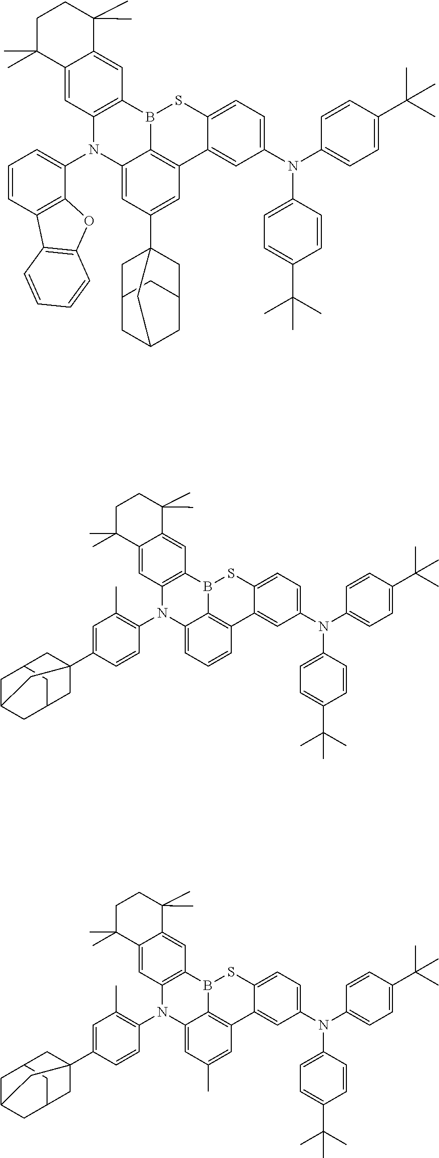 [SMILES: CC(C)(C)c1ccc(N(c2ccc(C(C)(C)C)cc2)c2ccc3c(c2)-c2cc(C45CC6CC(CC(C6)C4)C5)cc4c2B(S3)c2cc3c(cc2N4c2cccc4c2oc2ccccc24)C(C)(C)CCC3(C)C)cc1 ; Cc1cc(C23CC4CC(CC(C4)C2)C3)ccc1N1c2cc3c(cc2B2Sc4ccc(N(c5ccc(C(C)(C)C)cc5)c5ccc(C(C)(C)C)cc5)cc4-c4cccc1c42)C(C)(C)CCC3(C)C ; Cc1cc2c3c(c1)N(c1ccc(C45CC6CC(CC(C6)C4)C5)cc1C)c1cc4c(cc1B3Sc1ccc(N(c3ccc(C(C)(C)C)cc3)c3ccc(C(C)(C)C)cc3)cc1-2)C(C)(C)CCC4(C)C]

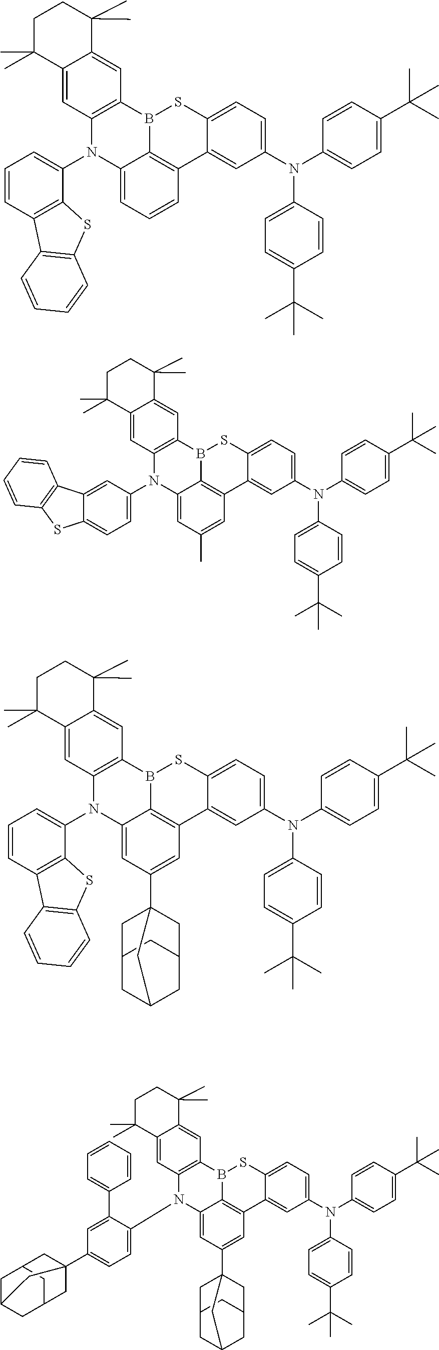

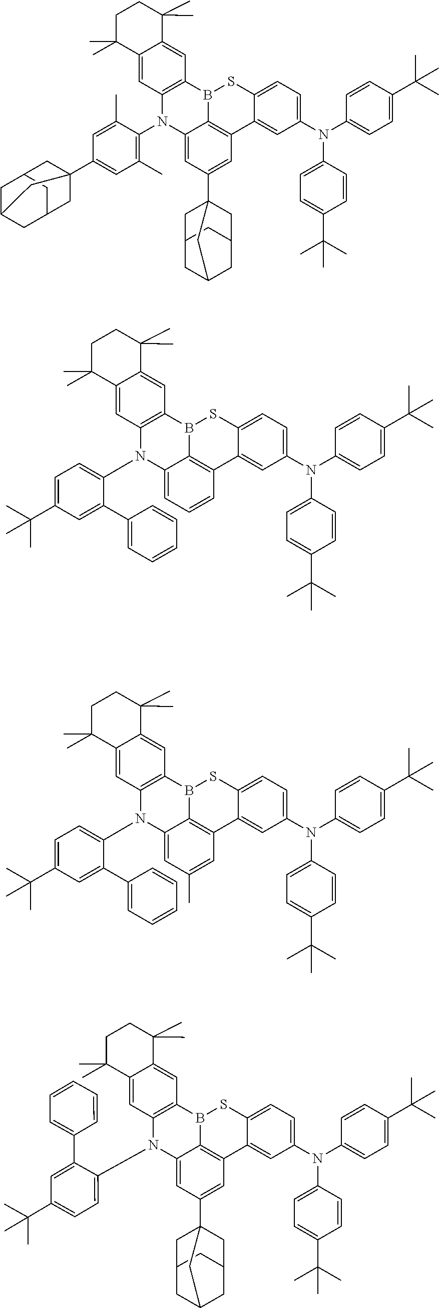

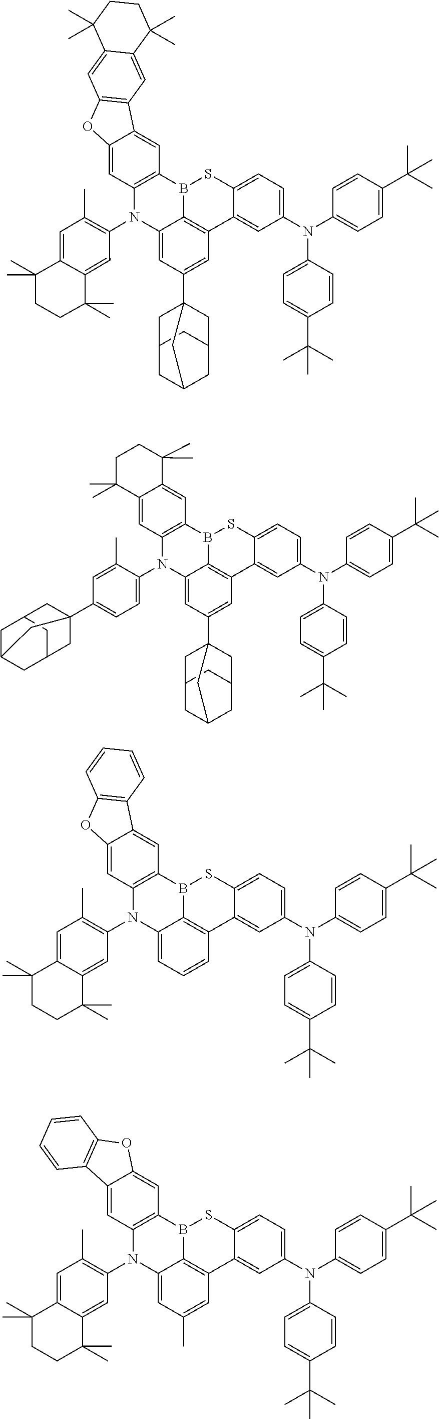

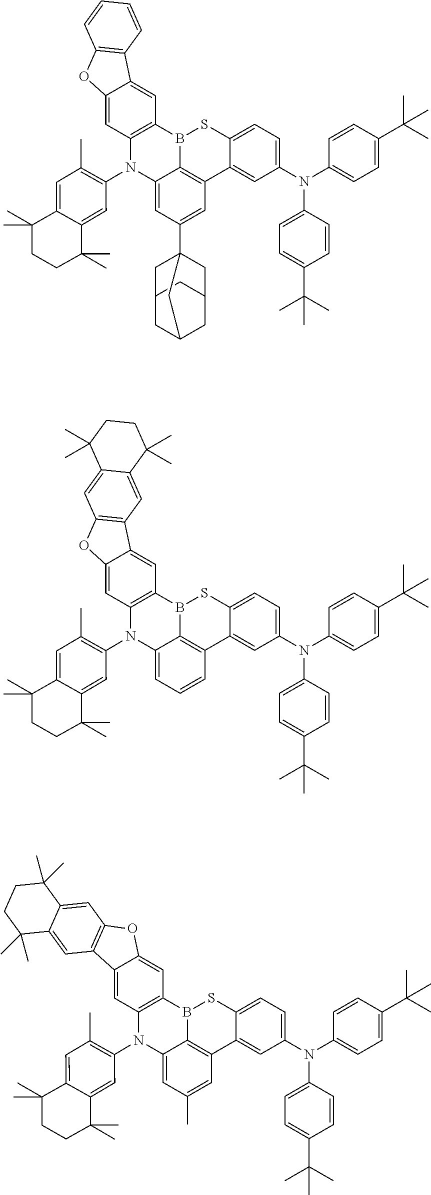

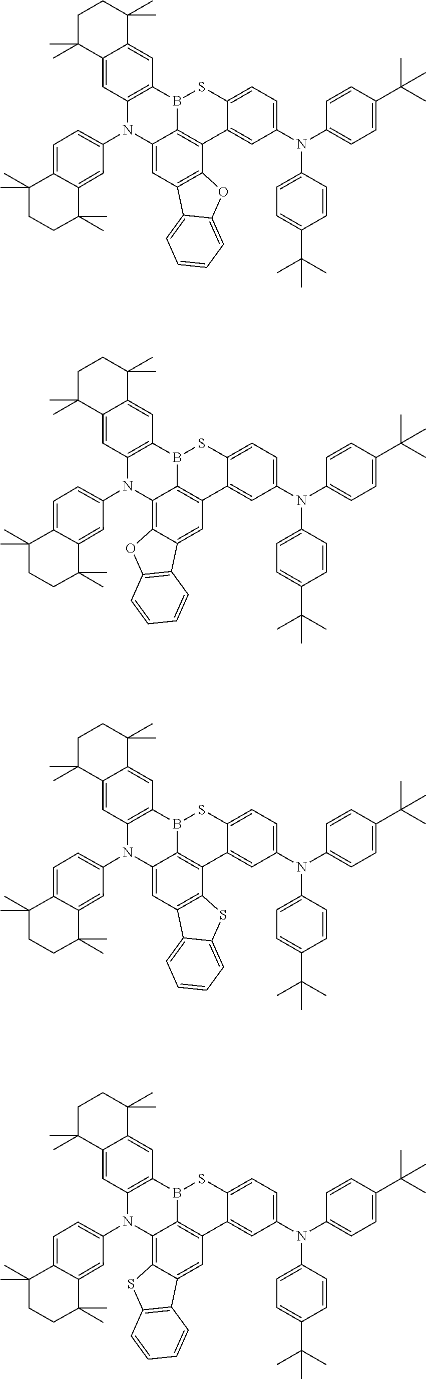

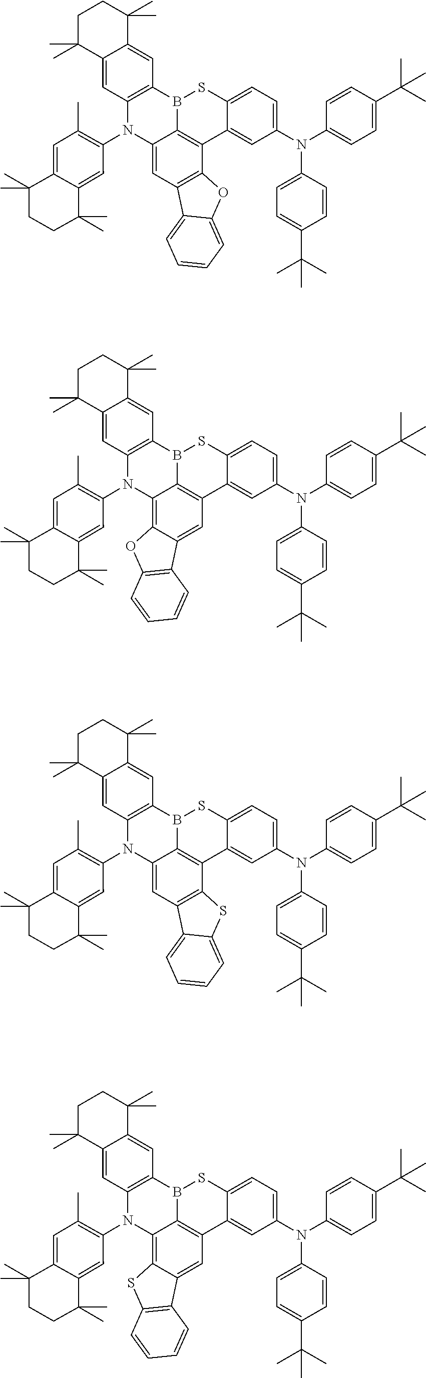

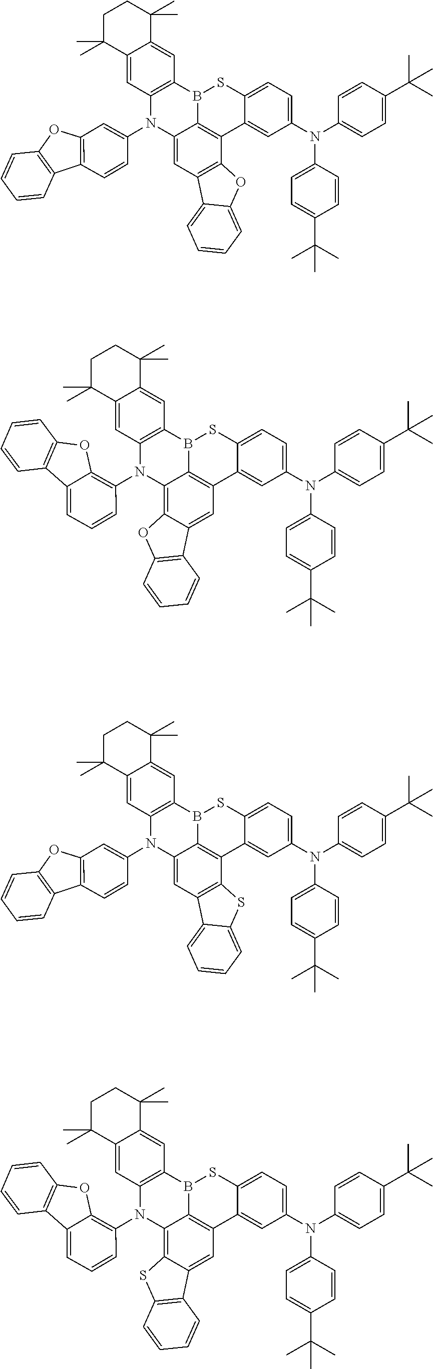

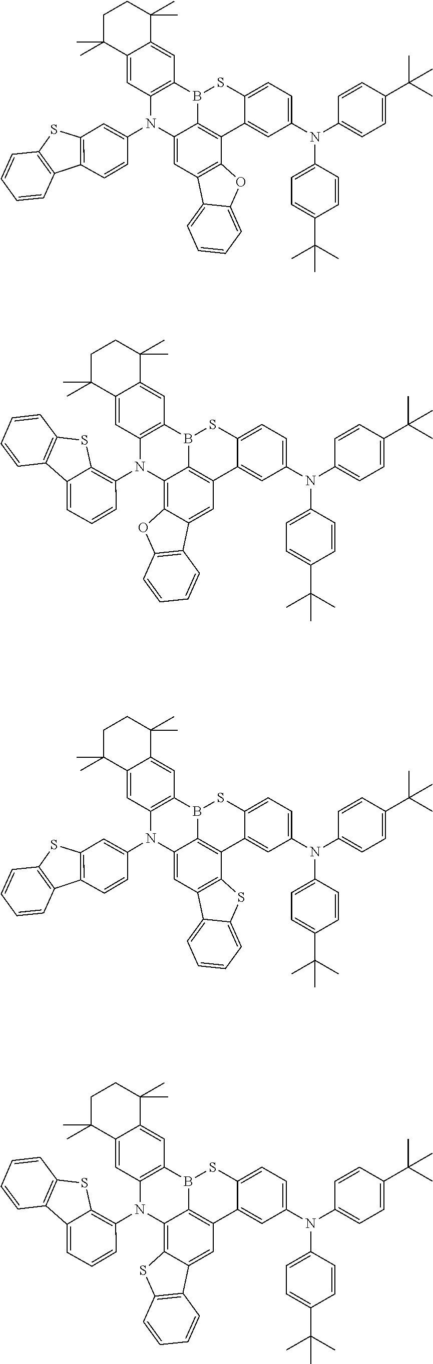

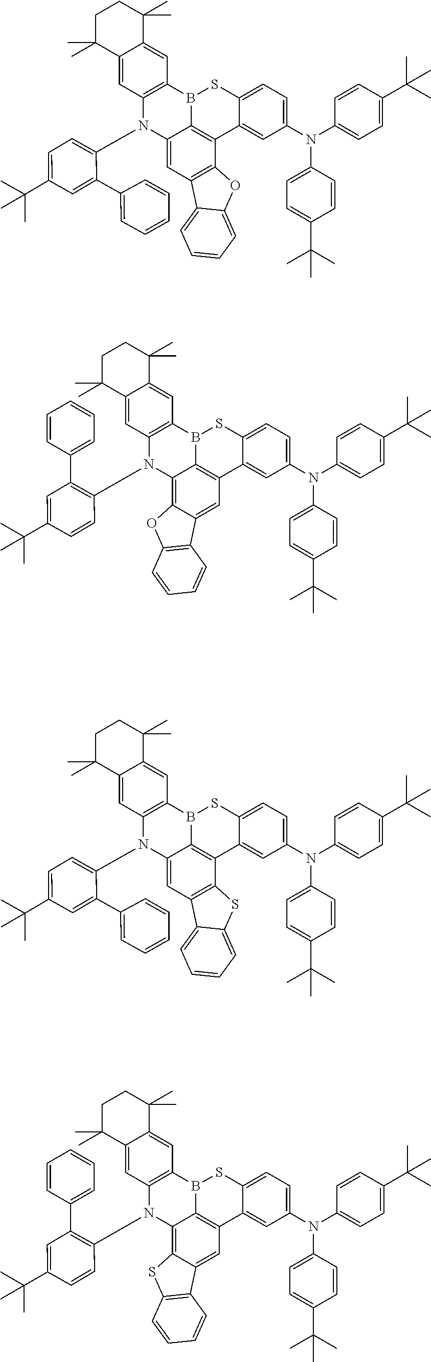

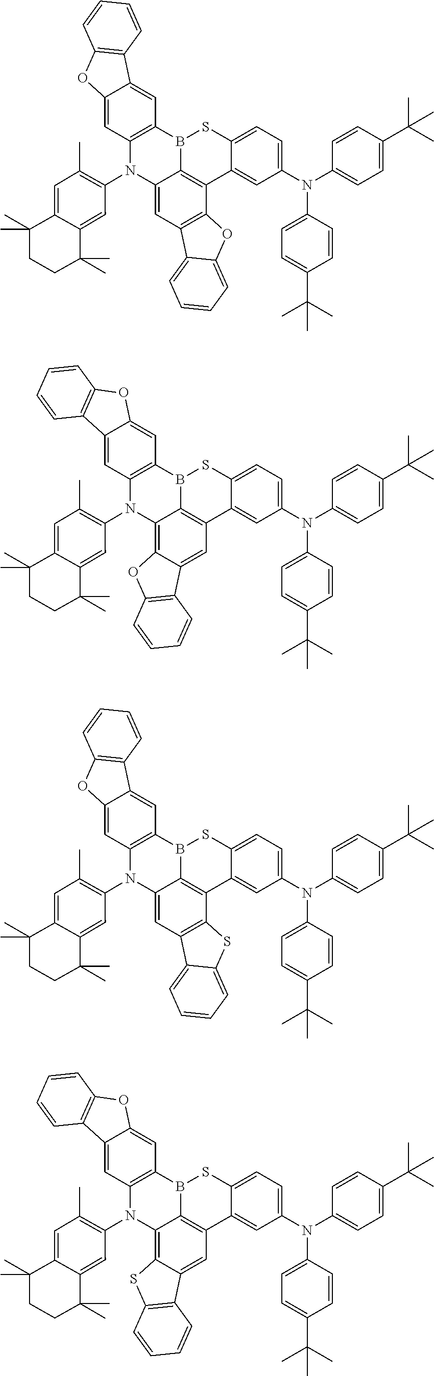

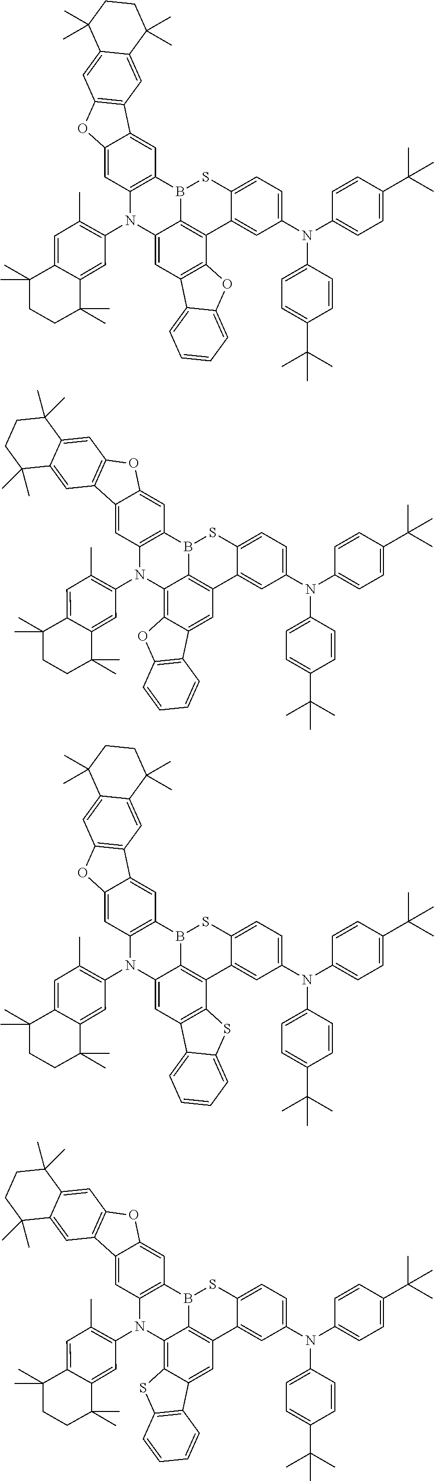

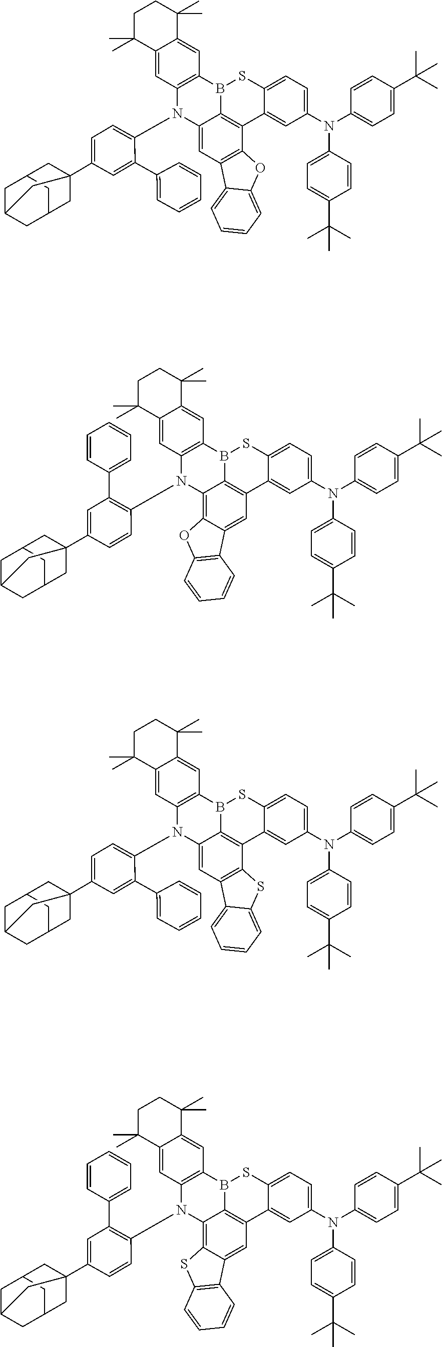

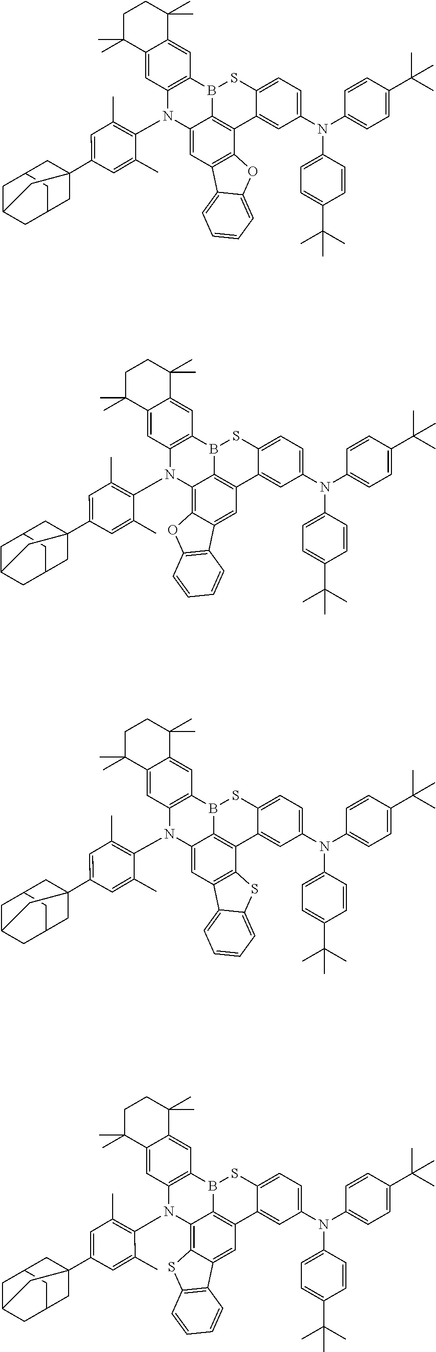

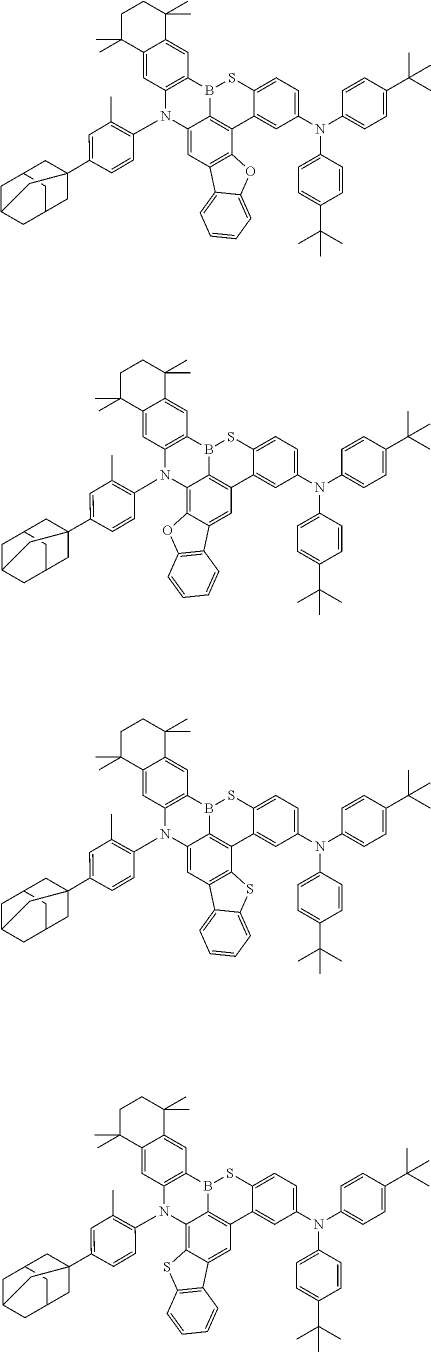

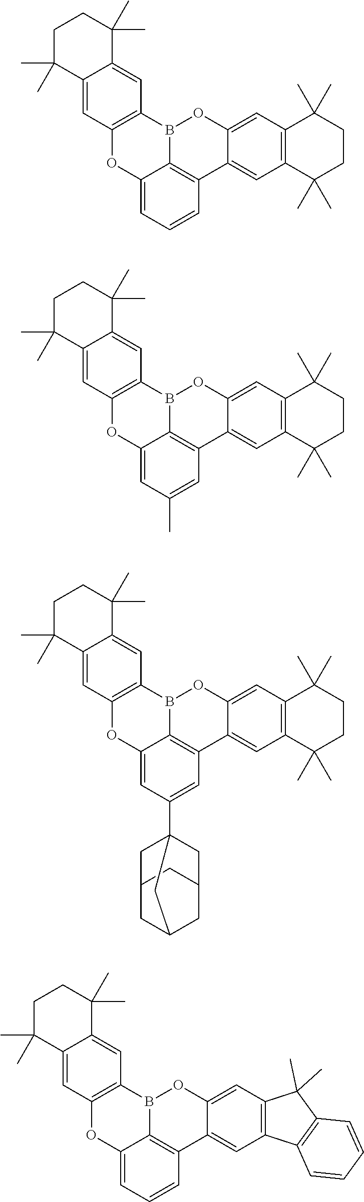 [SMILES: CC1(C)CCC(C)(C)c2cc3c(cc21)Oc1cccc2c1B3Oc1cc3c(cc1-2)C(C)(C)CCC3(C)C ; Cc1cc2c3c(c1)-c1cc4c(cc1OB3c1cc3c(cc1O2)C(C)(C)CCC3(C)C)C(C)(C)CCC4(C)C ; CC1(C)CCC(C)(C)c2cc3c(cc21)Oc1cc(C24CC5CC(CC(C5)C2)C4)cc2c1B3Oc1cc3c(cc1-2)C(C)(C)CCC3(C)C ; CC1(C)CCC(C)(C)c2cc3c(cc21)Oc1cccc2c1B3Oc1cc3c(cc1-2)-c1ccccc1C3(C)C]

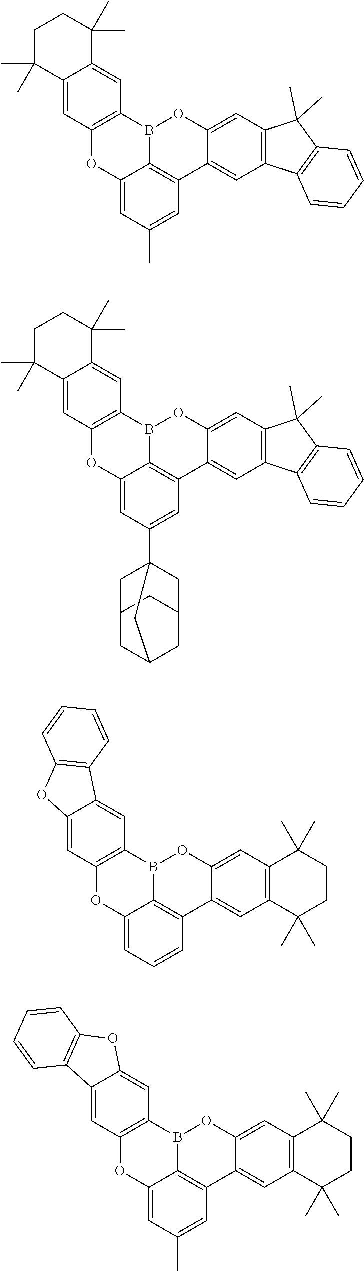 [SMILES: Cc1cc2c3c(c1)-c1cc4c(cc1OB3c1cc3c(cc1O2)C(C)(C)CCC3(C)C)C(C)(C)c1ccccc1-4 ; CC1(C)CCC(C)(C)c2cc3c(cc21)Oc1cc(C24CC5CC(CC(C5)C2)C4)cc2c1B3Oc1cc3c(cc1-2)-c1ccccc1C3(C)C ; CC1(C)CCC(C)(C)c2cc3c(cc21)OB1c2cc4c(cc2Oc2cccc-3c21)oc1ccccc14 ; Cc1cc2c3c(c1)-c1cc4c(cc1OB3c1cc3oc5ccccc5c3cc1O2)C(C)(C)CCC4(C)C]

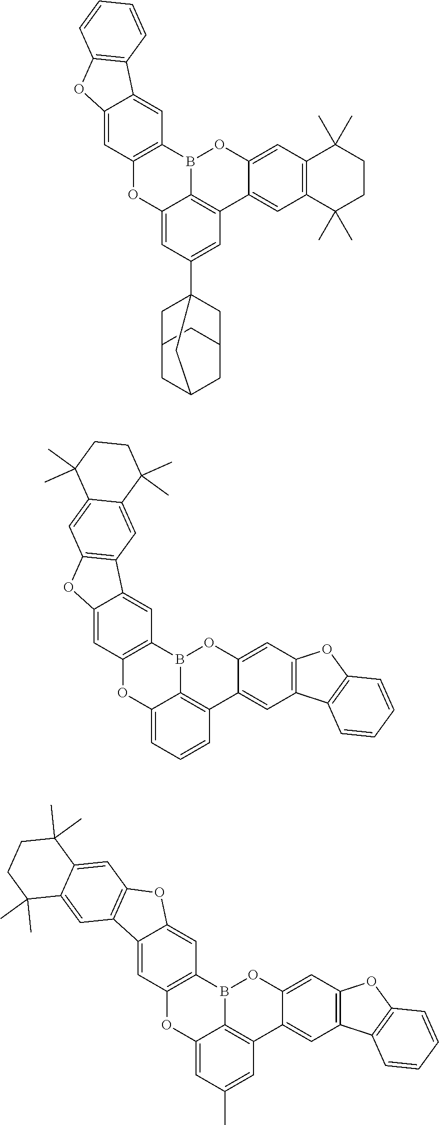 [SMILES: CC1(C)CCC(C)(C)c2cc3c(cc21)OB1c2cc4c(cc2Oc2cc(C56CC7CC(CC(C7)C5)C6)cc-3c21)oc1ccccc14 ; CC1(C)CCC(C)(C)c2cc3c(cc21)oc1cc2c(cc13)B1Oc3cc4oc5ccccc5c4cc3-c3cccc(c31)O2 ; Cc1cc2c3c(c1)-c1cc4c(cc1OB3c1cc3oc5cc6c(cc5c3cc1O2)C(C)(C)CCC6(C)C)oc1ccccc14]

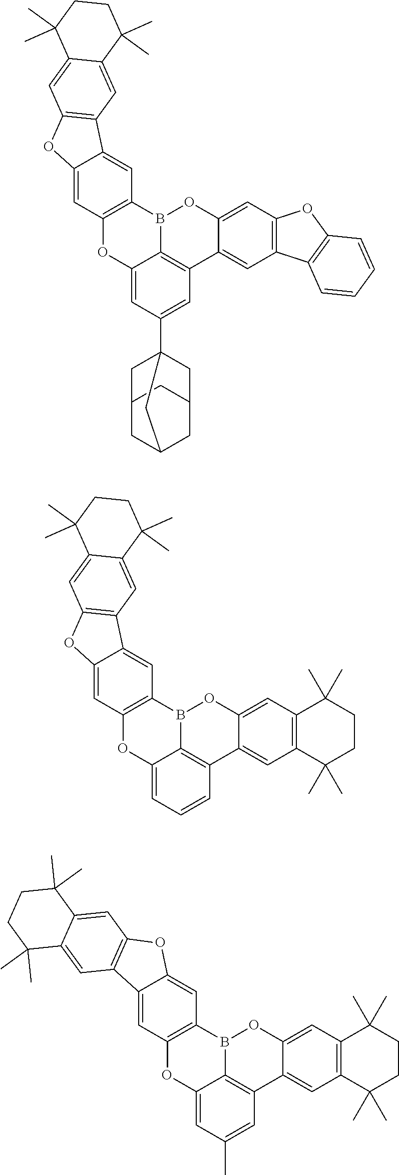 [SMILES: CC1(C)CCC(C)(C)c2cc3c(cc21)oc1cc2c(cc13)B1Oc3cc4oc5ccccc5c4cc3-c3cc(C45CC6CC(CC(C6)C4)C5)cc(c31)O2 ; CC1(C)CCC(C)(C)c2cc3c(cc21)OB1c2cc4c(cc2Oc2cccc-3c21)oc1cc2c(cc14)C(C)(C)CCC2(C)C ; Cc1cc2c3c(c1)-c1cc4c(cc1OB3c1cc3oc5cc6c(cc5c3cc1O2)C(C)(C)CCC6(C)C)C(C)(C)CCC4(C)C]

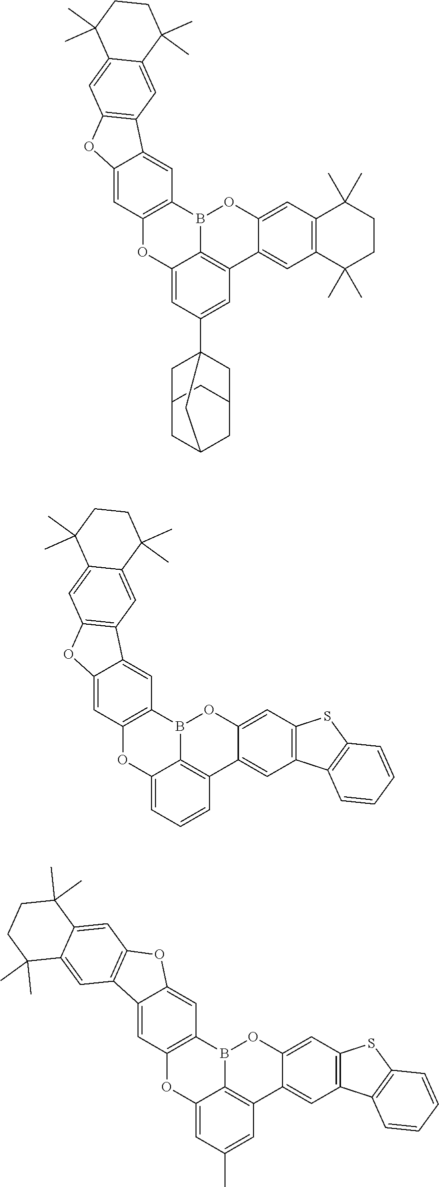 [SMILES: CC1(C)CCC(C)(C)c2cc3c(cc21)OB1c2cc4c(cc2Oc2cc(C56CC7CC(CC(C7)C5)C6)cc-3c21)oc1cc2c(cc14)C(C)(C)CCC2(C)C ; CC1(C)CCC(C)(C)c2cc3c(cc21)oc1cc2c(cc13)B1Oc3cc4sc5ccccc5c4cc3-c3cccc(c31)O2 ; Cc1cc2c3c(c1)-c1cc4c(cc1OB3c1cc3oc5cc6c(cc5c3cc1O2)C(C)(C)CCC6(C)C)sc1ccccc14]

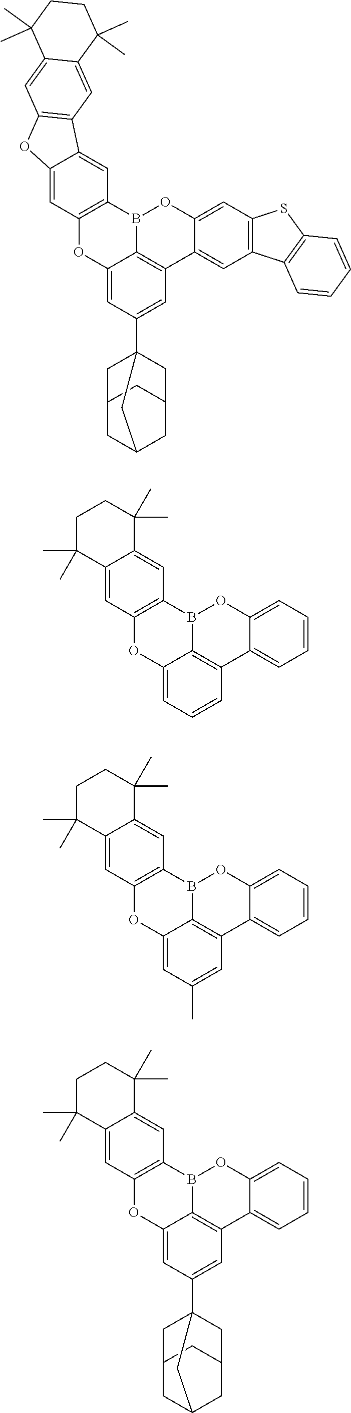

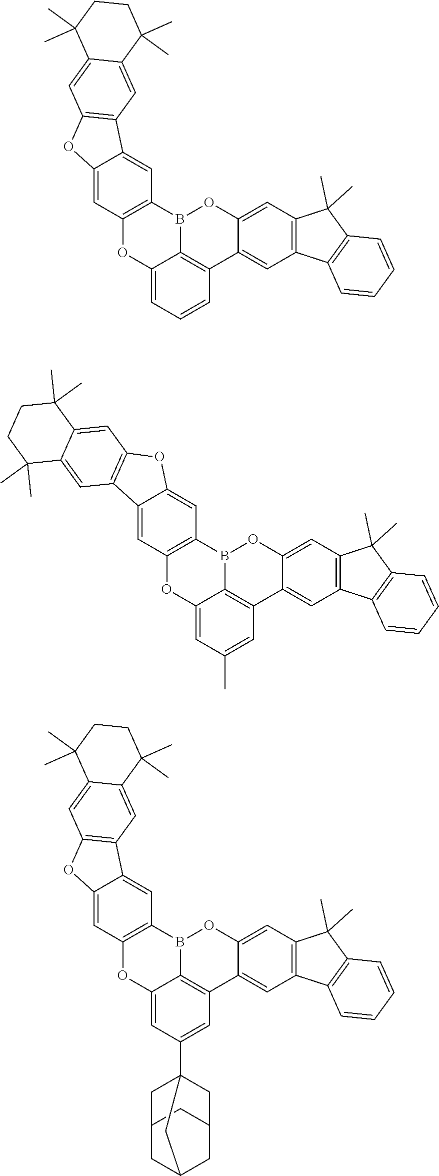 [SMILES: CC1(C)CCC(C)(C)c2cc3c(cc21)oc1cc2c(cc13)B1Oc3cc4c(cc3-c3cccc(c31)O2)-c1ccccc1C4(C)C ; Cc1cc2c3c(c1)-c1cc4c(cc1OB3c1cc3oc5cc6c(cc5c3cc1O2)C(C)(C)CCC6(C)C)C(C)(C)c1ccccc1-4 ; CC1(C)CCC(C)(C)c2cc3c(cc21)oc1cc2c(cc13)B1Oc3cc4c(cc3-c3cc(C56CC7CC(CC(C7)C5)C6)cc(c31)O2)-c1ccccc1C4(C)C]

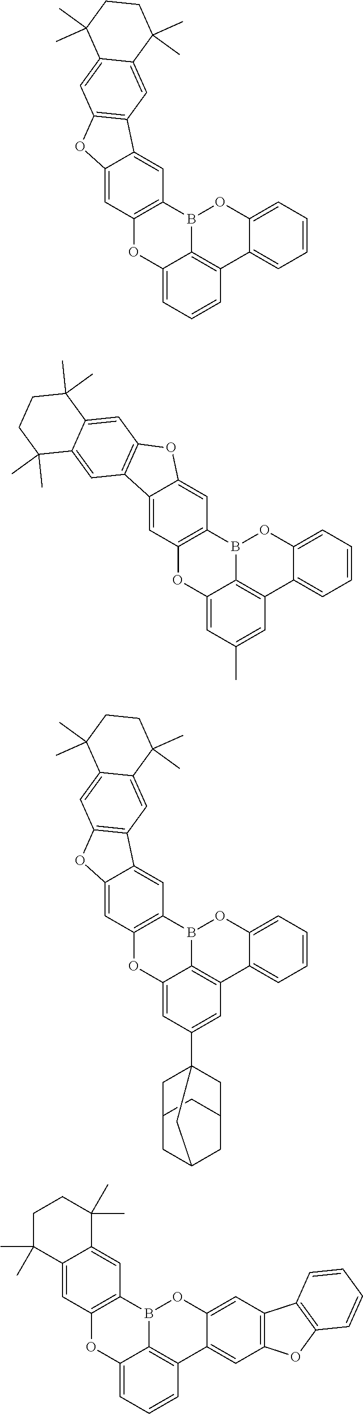 [SMILES: CC1(C)CCC(C)(C)c2cc3c(cc21)oc1cc2c(cc13)B1Oc3ccccc3-c3cccc(c31)O2 ; Cc1cc2c3c(c1)-c1ccccc1OB3c1cc3oc4cc5c(cc4c3cc1O2)C(C)(C)CCC5(C)C ; CC1(C)CCC(C)(C)c2cc3c(cc21)oc1cc2c(cc13)B1Oc3ccccc3-c3cc(C45CC6CC(CC(C6)C4)C5)cc(c31)O2 ; CC1(C)CCC(C)(C)c2cc3c(cc21)Oc1cccc2c1B3Oc1cc3c(cc1-2)oc1ccccc13]

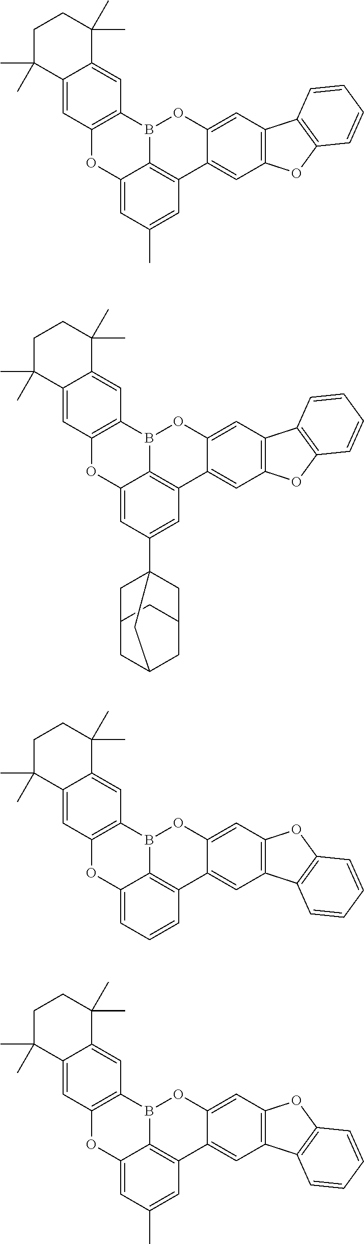 [SMILES: Cc1cc2c3c(c1)-c1cc4oc5ccccc5c4cc1OB3c1cc3c(cc1O2)C(C)(C)CCC3(C)C ; CC1(C)CCC(C)(C)c2cc3c(cc21)Oc1cc(C24CC5CC(CC(C5)C2)C4)cc2c1B3Oc1cc3c(cc1-2)oc1ccccc13 ; CC1(C)CCC(C)(C)c2cc3c(cc21)Oc1cccc2c1B3Oc1cc3oc4ccccc4c3cc1-2 ; Cc1cc2c3c(c1)-c1cc4c(cc1OB3c1cc3c(cc1O2)C(C)(C)CCC3(C)C)oc1ccccc14]

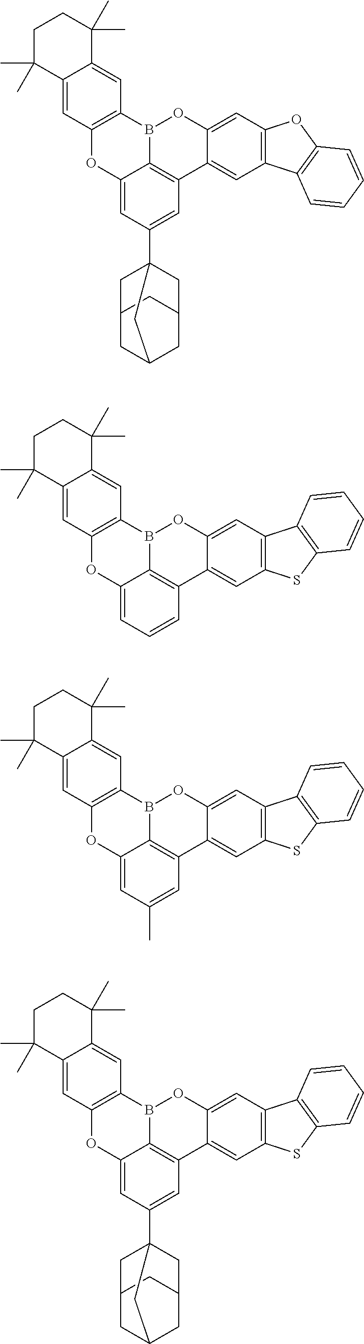 [SMILES: CC1(C)CCC(C)(C)c2cc3c(cc21)Oc1cc(C24CC5CC(CC(C5)C2)C4)cc2c1B3Oc1cc3oc4ccccc4c3cc1-2 ; CC1(C)CCC(C)(C)c2cc3c(cc21)Oc1cccc2c1B3Oc1cc3c(cc1-2)sc1ccccc13 ; Cc1cc2c3c(c1)-c1cc4sc5ccccc5c4cc1OB3c1cc3c(cc1O2)C(C)(C)CCC3(C)C ; CC1(C)CCC(C)(C)c2cc3c(cc21)Oc1cc(C24CC5CC(CC(C5)C2)C4)cc2c1B3Oc1cc3c(cc1-2)sc1ccccc13]

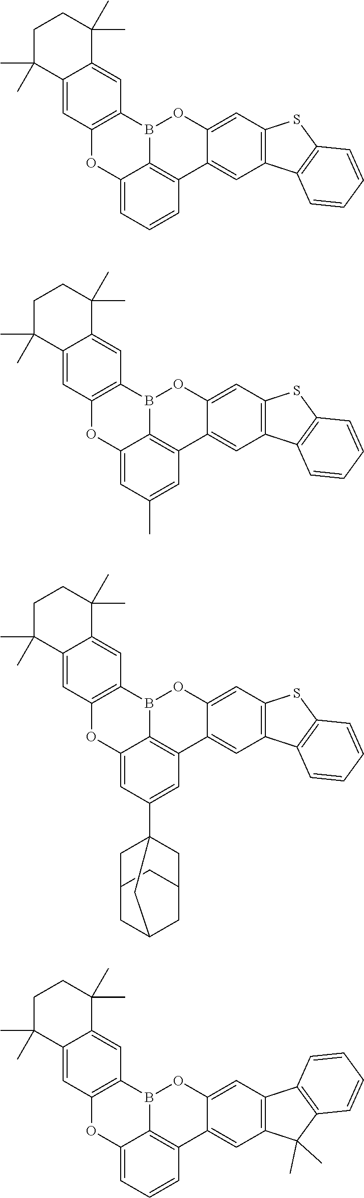 [SMILES: CC1(C)CCC(C)(C)c2cc3c(cc21)Oc1cccc2c1B3Oc1cc3sc4ccccc4c3cc1-2 ; Cc1cc2c3c(c1)-c1cc4c(cc1OB3c1cc3c(cc1O2)C(C)(C)CCC3(C)C)sc1ccccc14 ; CC1(C)CCC(C)(C)c2cc3c(cc21)Oc1cc(C24CC5CC(CC(C5)C2)C4)cc2c1B3Oc1cc3sc4ccccc4c3cc1-2 ; CC1(C)CCC(C)(C)c2cc3c(cc21)Oc1cccc2c1B3Oc1cc3c(cc1-2)C(C)(C)c1ccccc1-3]

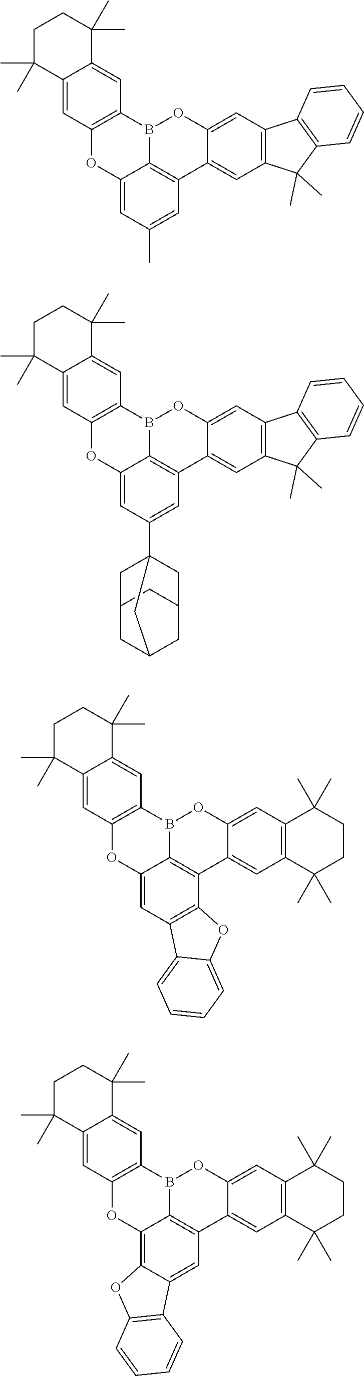

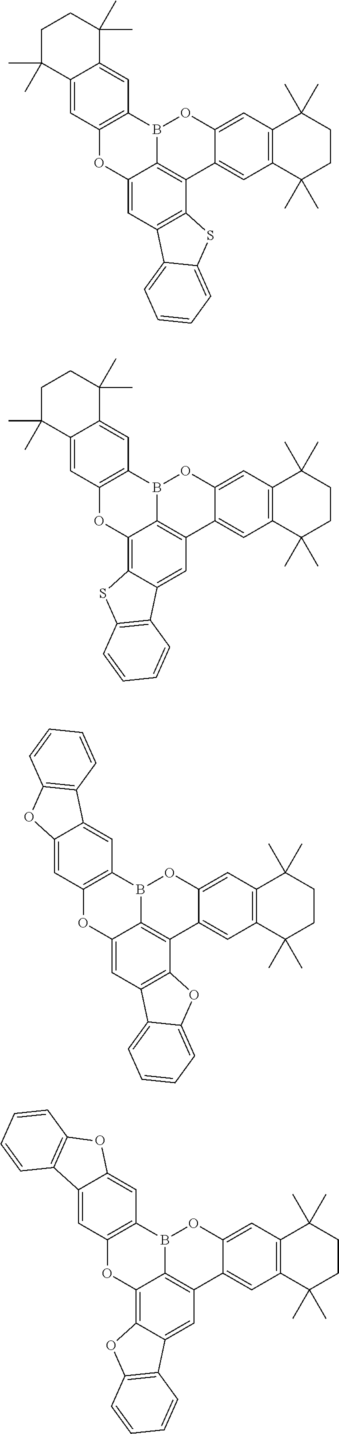 [SMILES: CC1(C)CCC(C)(C)c2cc3c(cc21)Oc1cc2c(sc4ccccc42)c2c1B3Oc1cc3c(cc1-2)C(C)(C)CCC3(C)C ; CC1(C)CCC(C)(C)c2cc3c(cc21)Oc1c2c(cc4c1sc1ccccc14)-c1cc4c(cc1OB32)C(C)(C)CCC4(C)C ; CC1(C)CCC(C)(C)c2cc3c(cc21)OB1c2cc4c(cc2Oc2cc5c(oc6ccccc65)c-3c21)oc1ccccc14 ; CC1(C)CCC(C)(C)c2cc3c(cc21)OB1c2cc4oc5ccccc5c4cc2Oc2c1c-3cc1c2oc2ccccc21]

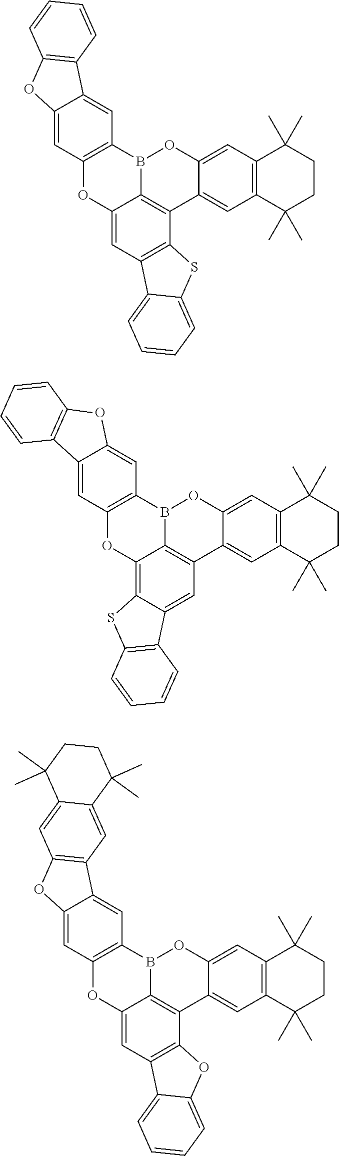 [SMILES: CC1(C)CCC(C)(C)c2cc3c(cc21)OB1c2cc4c(cc2Oc2cc5c(sc6ccccc65)c-3c21)oc1ccccc14 ; CC1(C)CCC(C)(C)c2cc3c(cc21)OB1c2cc4oc5ccccc5c4cc2Oc2c1c-3cc1c2sc2ccccc21 ; CC1(C)CCC(C)(C)c2cc3c(cc21)OB1c2cc4c(cc2Oc2cc5c(oc6ccccc65)c-3c21)oc1cc2c(cc14)C(C)(C)CCC2(C)C]

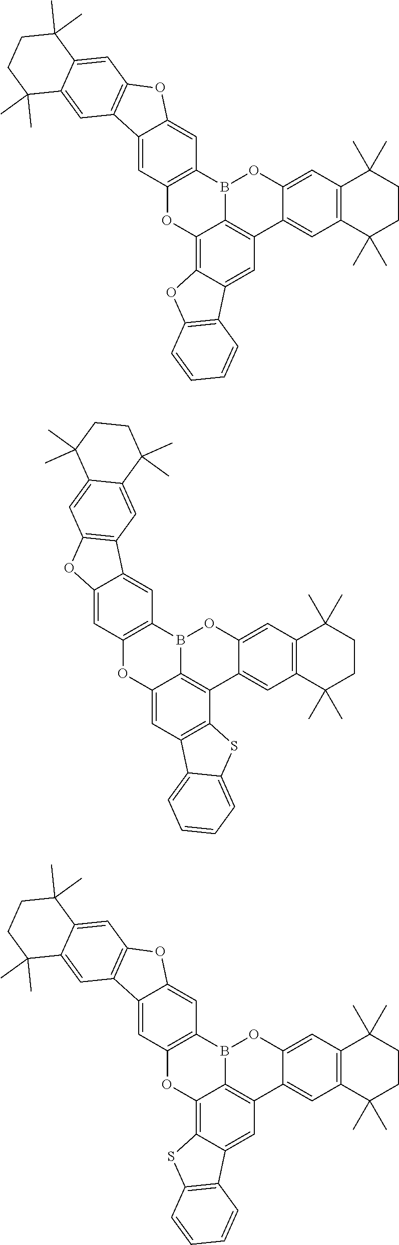 [SMILES: CC1(C)CCC(C)(C)c2cc3c(cc21)OB1c2cc4oc5cc6c(cc5c4cc2Oc2c1c-3cc1c2oc2ccccc21)C(C)(C)CCC6(C)C ; CC1(C)CCC(C)(C)c2cc3c(cc21)OB1c2cc4c(cc2Oc2cc5c(sc6ccccc65)c-3c21)oc1cc2c(cc14)C(C)(C)CCC2(C)C ; CC1(C)CCC(C)(C)c2cc3c(cc21)OB1c2cc4oc5cc6c(cc5c4cc2Oc2c1c-3cc1c2sc2ccccc21)C(C)(C)CCC6(C)C]

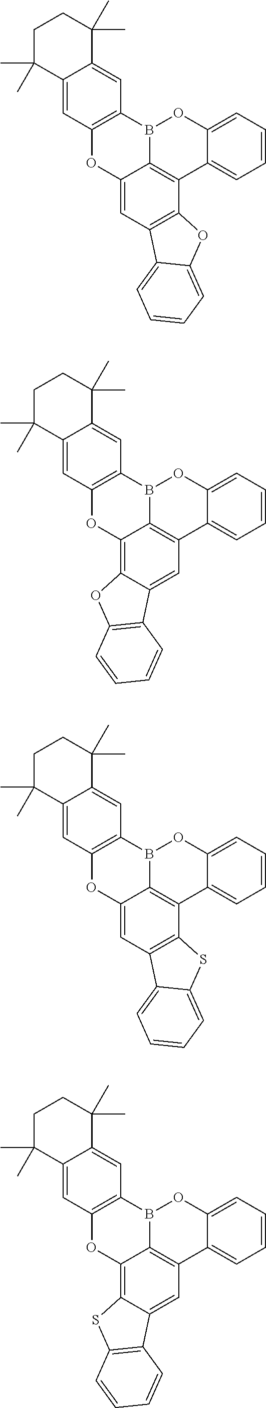

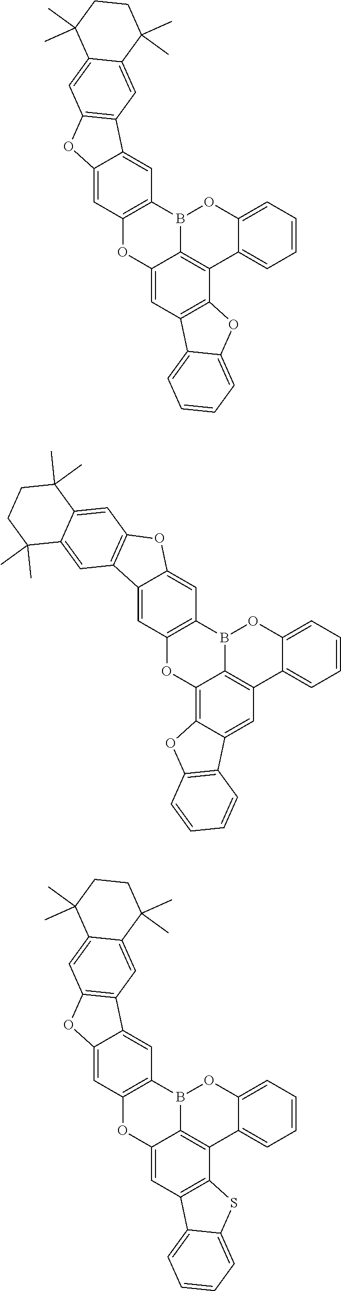 [SMILES: CC1(C)CCC(C)(C)c2cc3c(cc21)oc1cc2c(cc13)B1Oc3ccccc3-c3c1c(cc1c3oc3ccccc31)O2 ; CC1(C)CCC(C)(C)c2cc3c(cc21)oc1cc2c(cc13)Oc1c3c(cc4c1oc1ccccc14)-c1ccccc1OB23 ; CC1(C)CCC(C)(C)c2cc3c(cc21)oc1cc2c(cc13)B1Oc3ccccc3-c3c1c(cc1c3sc3ccccc31)O2]

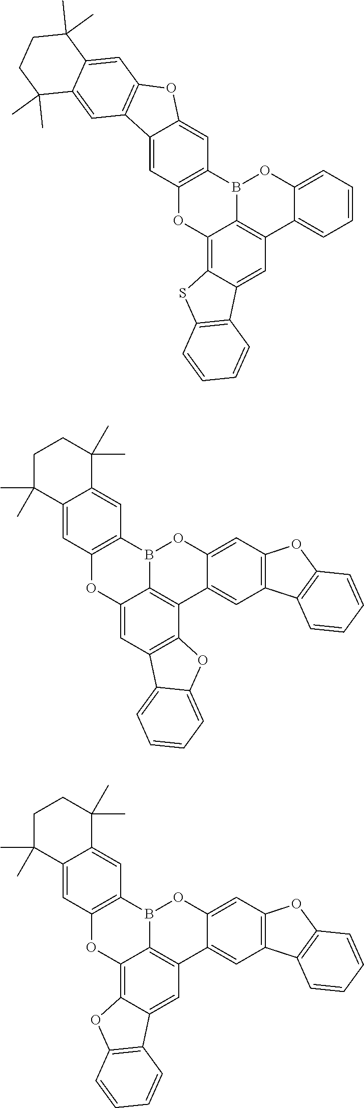 [SMILES: CC1(C)CCC(C)(C)c2cc3c(cc21)oc1cc2c(cc13)Oc1c3c(cc4c1sc1ccccc14)-c1ccccc1OB23 ; CC1(C)CCC(C)(C)c2cc3c(cc21)Oc1cc2c(oc4ccccc42)c2c1B3Oc1cc3oc4ccccc4c3cc1-2 ; CC1(C)CCC(C)(C)c2cc3c(cc21)Oc1c2c(cc4c1oc1ccccc14)-c1cc4c(cc1OB32)oc1ccccc14]

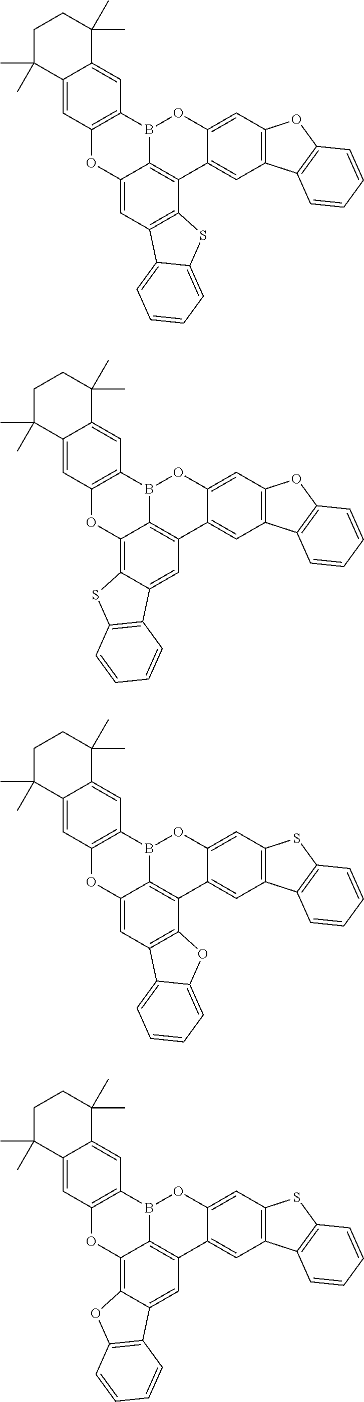

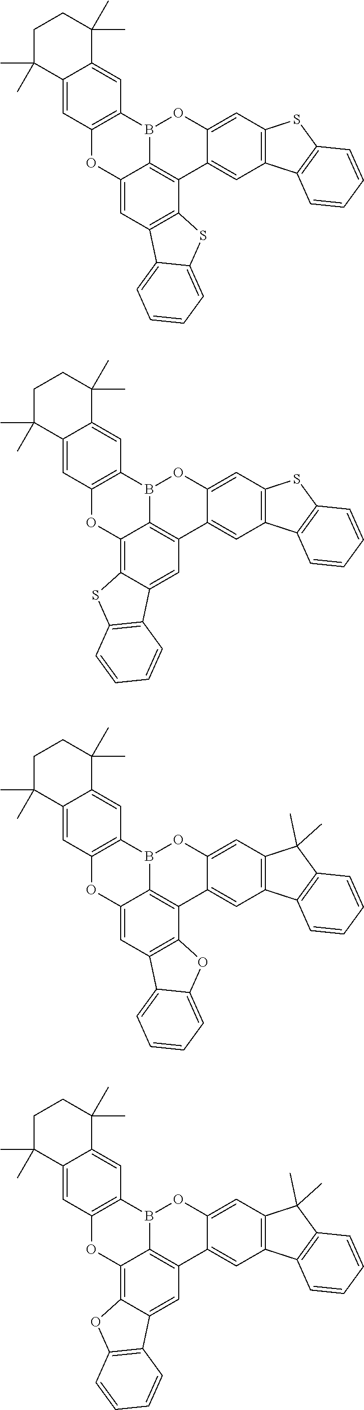

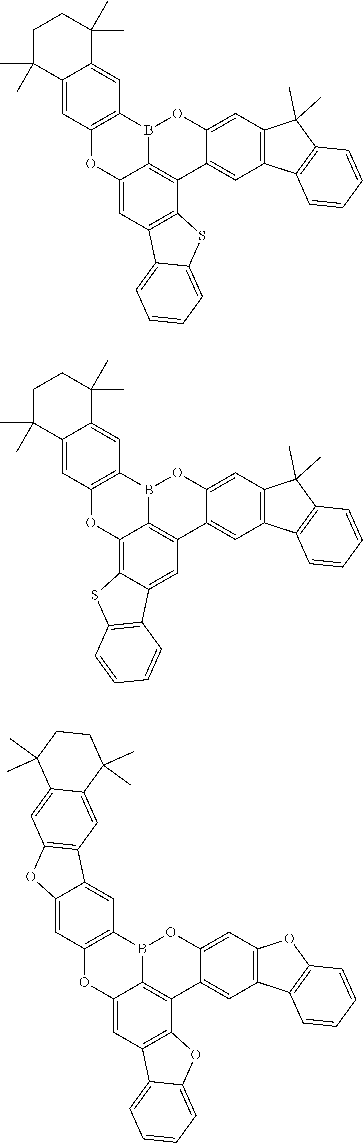 [SMILES: CC1(C)CCC(C)(C)c2cc3c(cc21)Oc1cc2c(sc4ccccc42)c2c1B3Oc1cc3c(cc1-2)-c1ccccc1C3(C)C ; CC1(C)CCC(C)(C)c2cc3c(cc21)Oc1c2c(cc4c1sc1ccccc14)-c1cc4c(cc1OB32)C(C)(C)c1ccccc1-4 ; CC1(C)CCC(C)(C)c2cc3c(cc21)oc1cc2c(cc13)B1Oc3cc4oc5ccccc5c4cc3-c3c1c(cc1c3oc3ccccc31)O2]

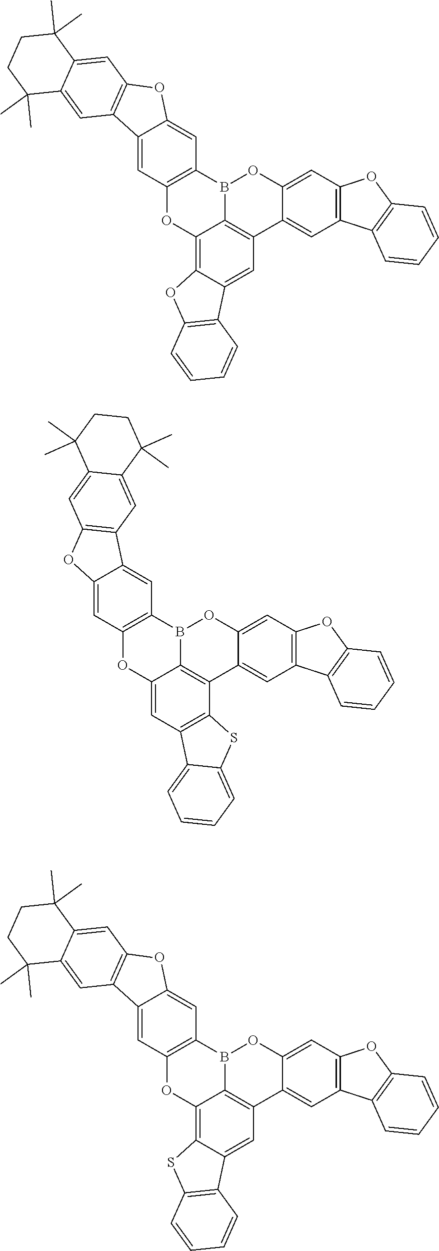 [SMILES: CC1(C)CCC(C)(C)c2cc3c(cc21)oc1cc2c(cc13)Oc1c3c(cc4c1oc1ccccc14)-c1cc4c(cc1OB23)oc1ccccc14 ; CC1(C)CCC(C)(C)c2cc3c(cc21)oc1cc2c(cc13)B1Oc3cc4oc5ccccc5c4cc3-c3c1c(cc1c3sc3ccccc31)O2 ; CC1(C)CCC(C)(C)c2cc3c(cc21)oc1cc2c(cc13)Oc1c3c(cc4c1sc1ccccc14)-c1cc4c(cc1OB23)oc1ccccc14]

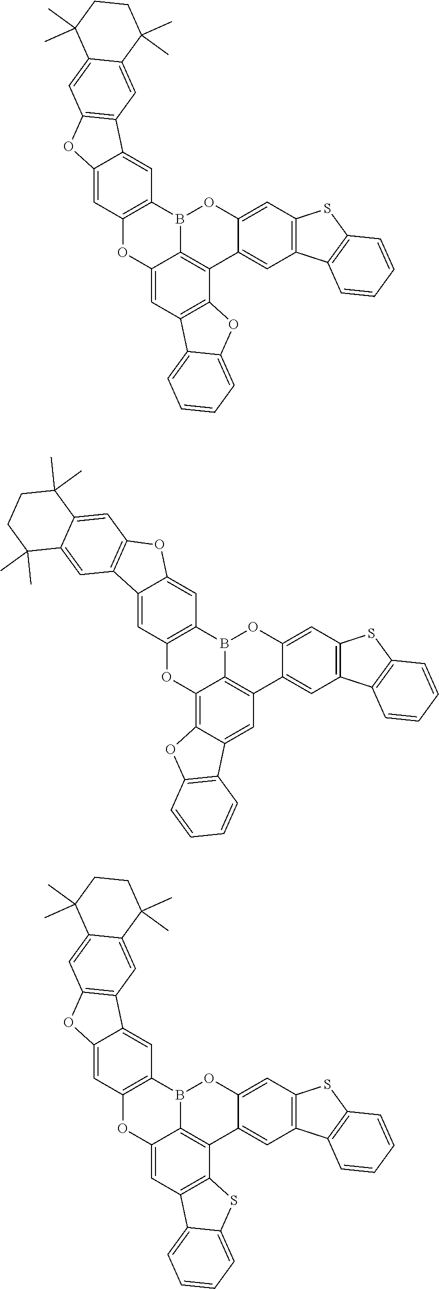 [SMILES: CC1(C)CCC(C)(C)c2cc3c(cc21)oc1cc2c(cc13)B1Oc3cc4sc5ccccc5c4cc3-c3c1c(cc1c3oc3ccccc31)O2 ; CC1(C)CCC(C)(C)c2cc3c(cc21)oc1cc2c(cc13)Oc1c3c(cc4c1oc1ccccc14)-c1cc4c(cc1OB23)sc1ccccc14 ; CC1(C)CCC(C)(C)c2cc3c(cc21)oc1cc2c(cc13)B1Oc3cc4sc5ccccc5c4cc3-c3c1c(cc1c3sc3ccccc31)O2]

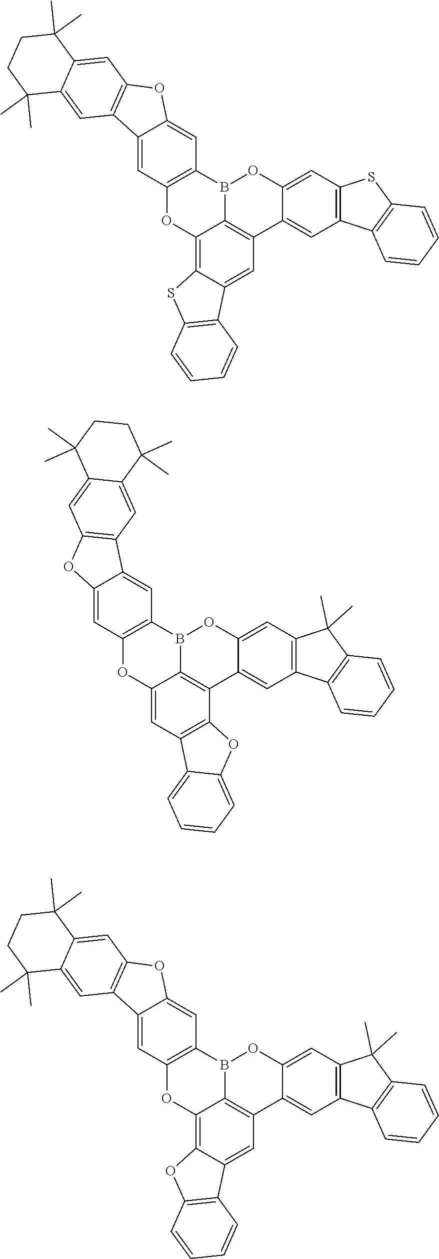 [SMILES: CC1(C)CCC(C)(C)c2cc3c(cc21)oc1cc2c(cc13)Oc1c3c(cc4c1sc1ccccc14)-c1cc4c(cc1OB23)sc1ccccc14 ; CC1(C)CCC(C)(C)c2cc3c(cc21)oc1cc2c(cc13)B1Oc3cc4c(cc3-c3c1c(cc1c3oc3ccccc31)O2)-c1ccccc1C4(C)C ; CC1(C)CCC(C)(C)c2cc3c(cc21)oc1cc2c(cc13)Oc1c3c(cc4c1oc1ccccc14)-c1cc4c(cc1OB23)C(C)(C)c1ccccc1-4]

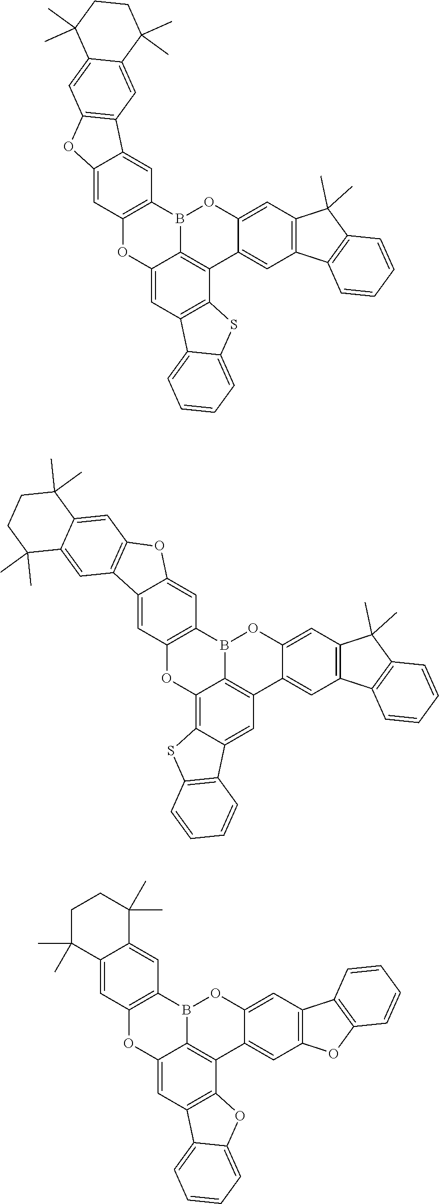 [SMILES: CC1(C)CCC(C)(C)c2cc3c(cc21)oc1cc2c(cc13)B1Oc3cc4c(cc3-c3c1c(cc1c3sc3ccccc31)O2)-c1ccccc1C4(C)C ; CC1(C)CCC(C)(C)c2cc3c(cc21)oc1cc2c(cc13)Oc1c3c(cc4c1sc1ccccc14)-c1cc4c(cc1OB23)C(C)(C)c1ccccc1-4 ; CC1(C)CCC(C)(C)c2cc3c(cc21)Oc1cc2c(oc4ccccc42)c2c1B3Oc1cc3c(cc1-2)oc1ccccc13]

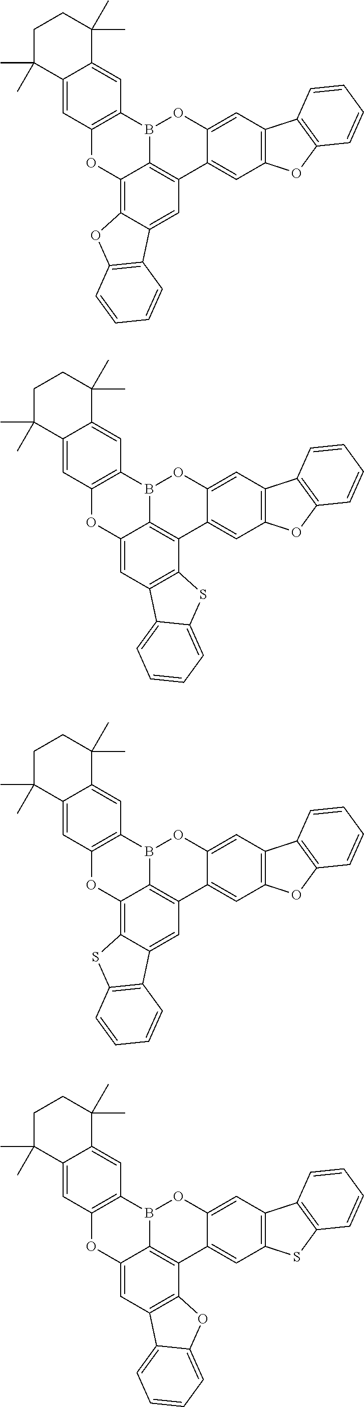

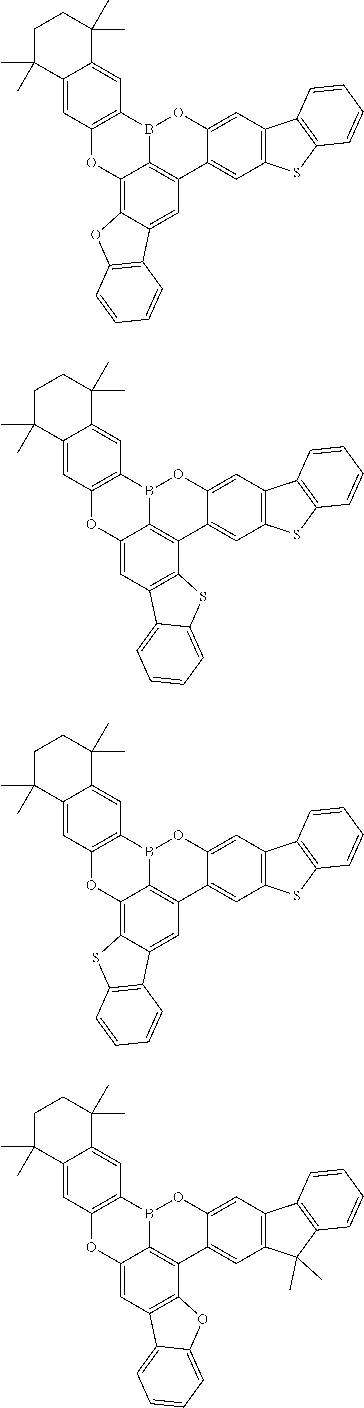

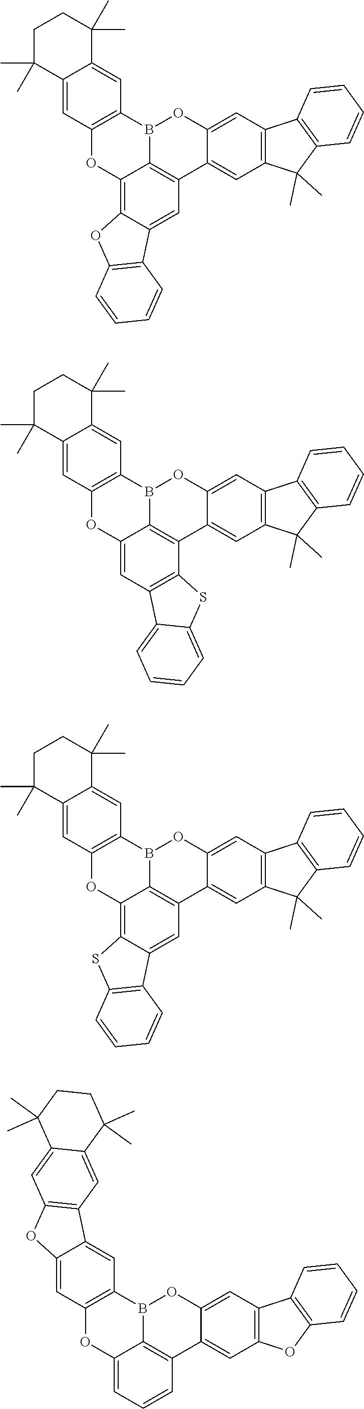

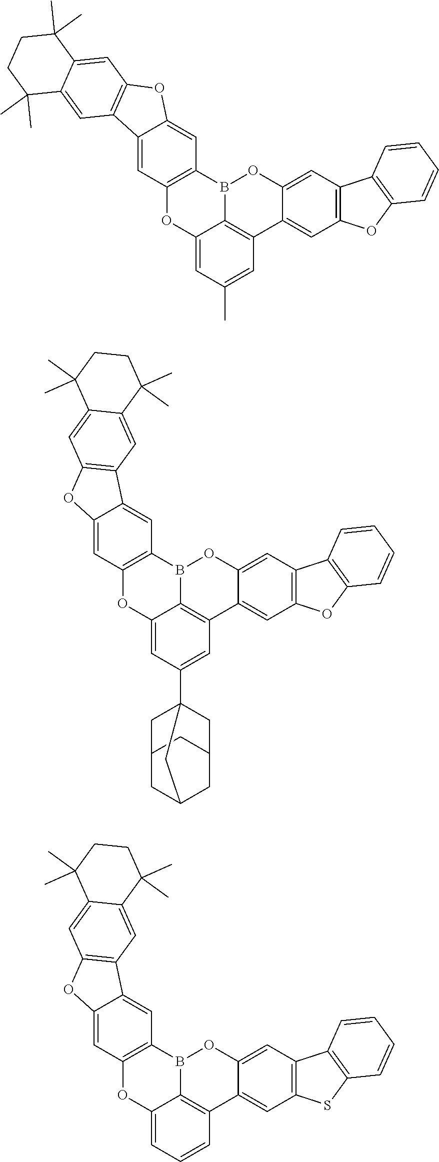 [SMILES: Cc1cc2c3c(c1)-c1cc4oc5ccccc5c4cc1OB3c1cc3oc4cc5c(cc4c3cc1O2)C(C)(C)CCC5(C)C ; CC1(C)CCC(C)(C)c2cc3c(cc21)oc1cc2c(cc13)B1Oc3cc4c(cc3-c3cc(C56CC7CC(CC(C7)C5)C6)cc(c31)O2)oc1ccccc14 ; CC1(C)CCC(C)(C)c2cc3c(cc21)oc1cc2c(cc13)B1Oc3cc4c(cc3-c3cccc(c31)O2)sc1ccccc14]

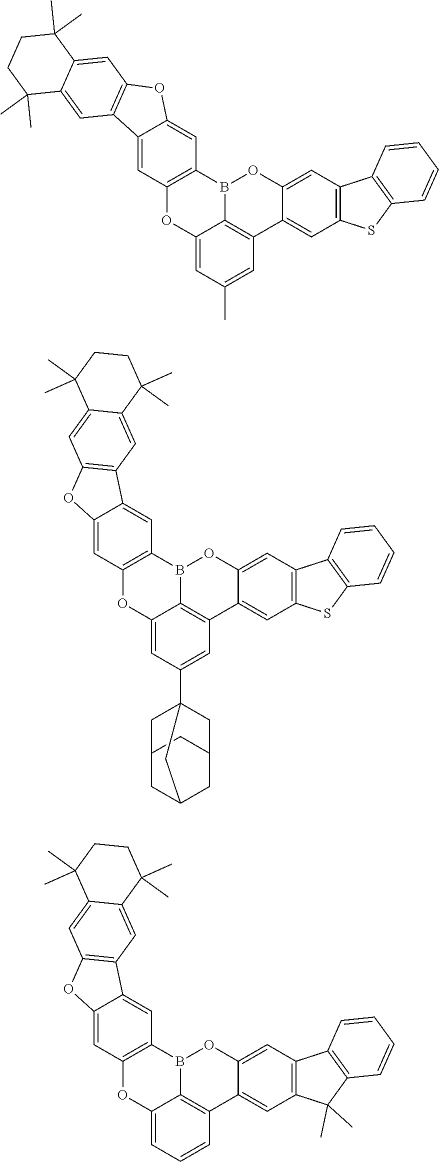 [SMILES: Cc1cc2c3c(c1)-c1cc4sc5ccccc5c4cc1OB3c1cc3oc4cc5c(cc4c3cc1O2)C(C)(C)CCC5(C)C ; CC1(C)CCC(C)(C)c2cc3c(cc21)oc1cc2c(cc13)B1Oc3cc4c(cc3-c3cc(C56CC7CC(CC(C7)C5)C6)cc(c31)O2)sc1ccccc14 ; CC1(C)CCC(C)(C)c2cc3c(cc21)oc1cc2c(cc13)B1Oc3cc4c(cc3-c3cccc(c31)O2)C(C)(C)c1ccccc1-4]

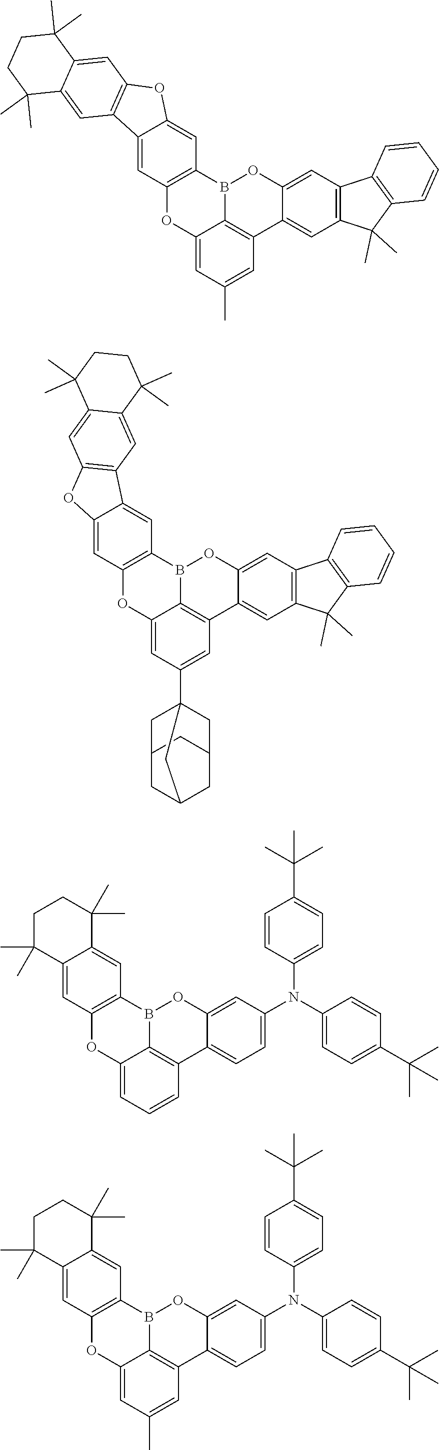

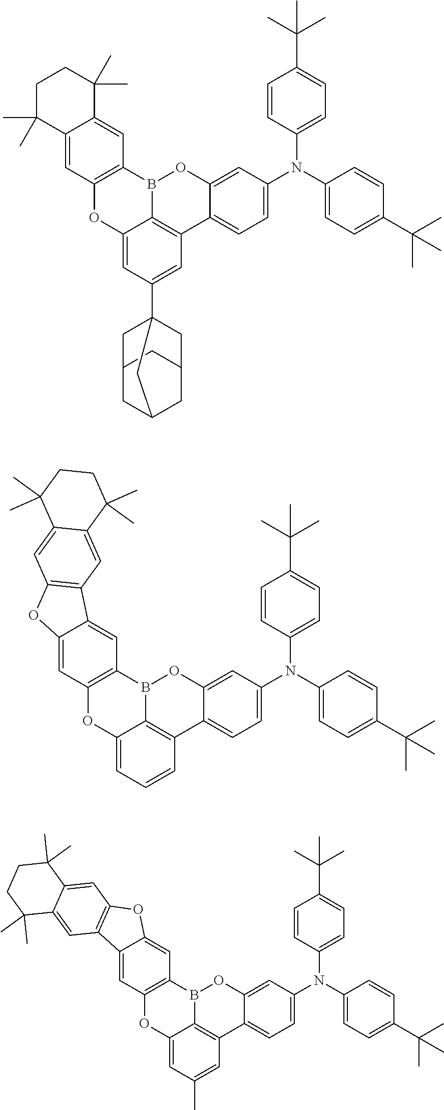

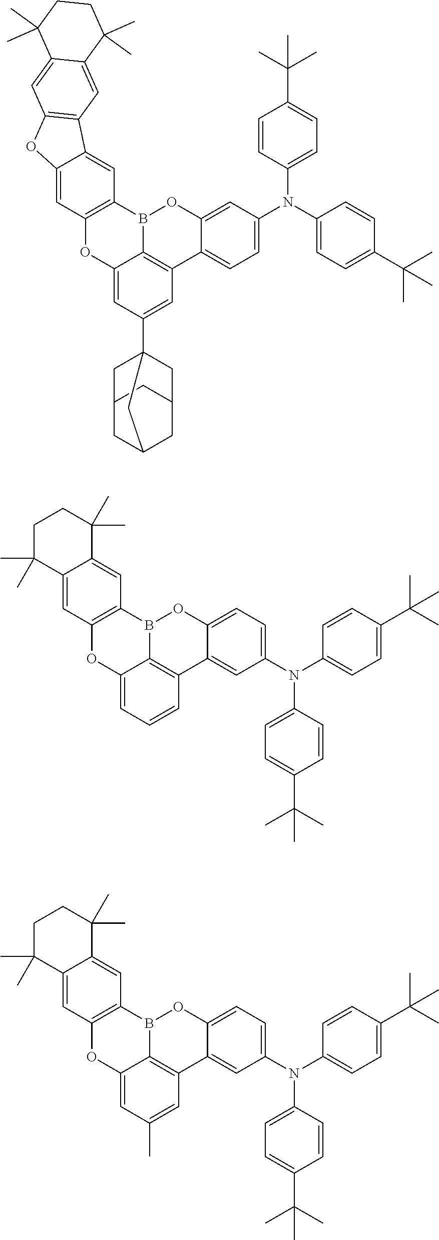

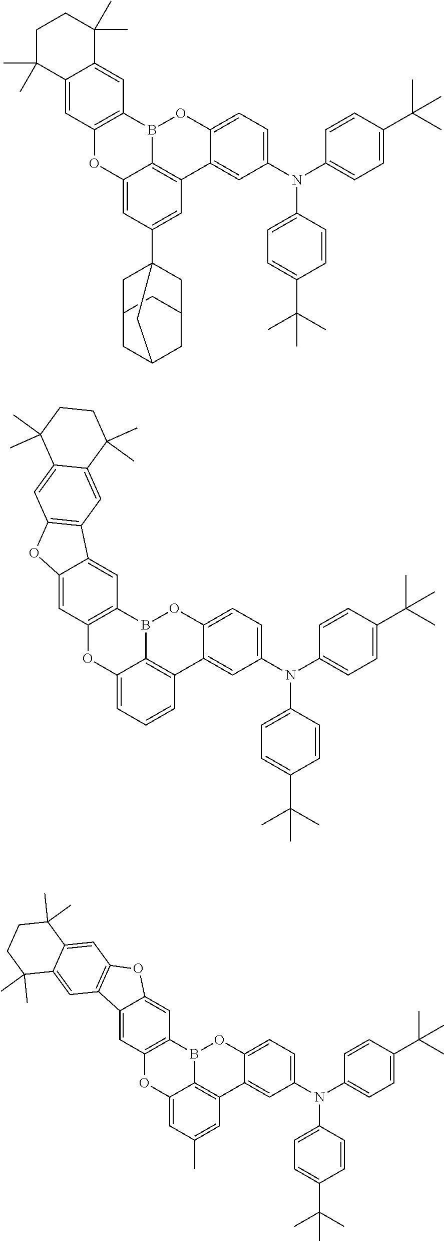

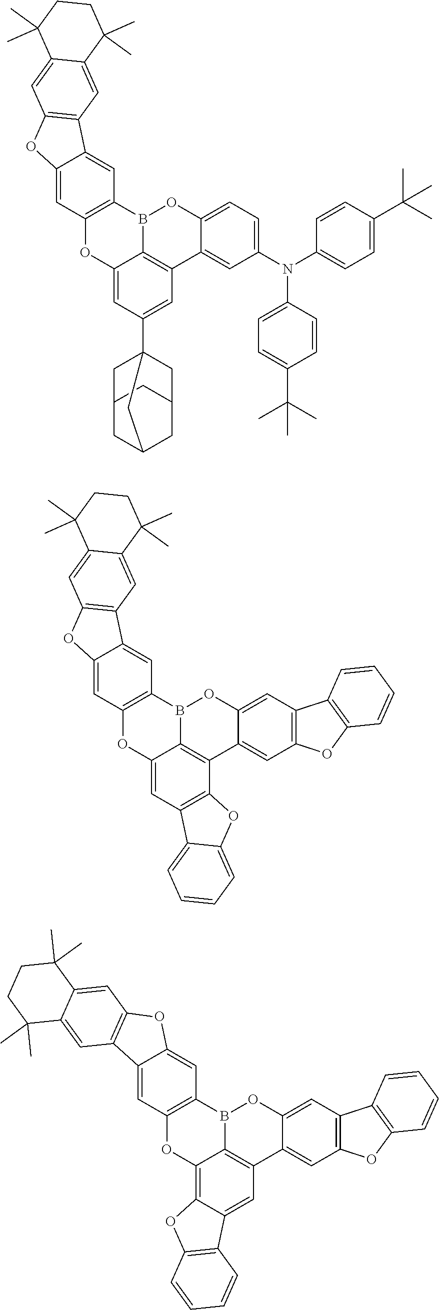

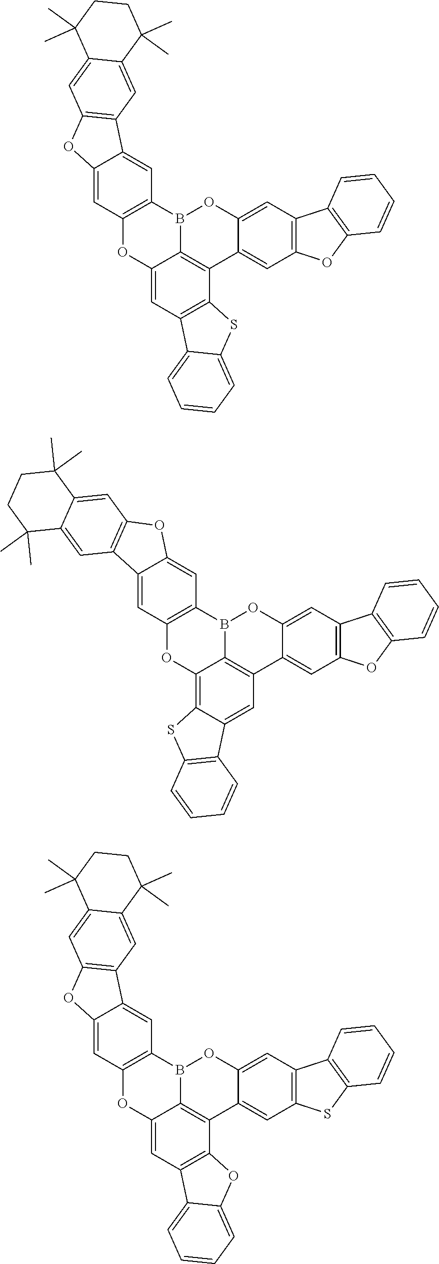 [SMILES: CC1(C)CCC(C)(C)c2cc3c(cc21)oc1cc2c(cc13)B1Oc3cc4c(cc3-c3c1c(cc1c3sc3ccccc31)O2)oc1ccccc14 ; CC1(C)CCC(C)(C)c2cc3c(cc21)oc1cc2c(cc13)Oc1c3c(cc4c1sc1ccccc14)-c1cc4oc5ccccc5c4cc1OB23 ; CC1(C)CCC(C)(C)c2cc3c(cc21)oc1cc2c(cc13)B1Oc3cc4c(cc3-c3c1c(cc1c3oc3ccccc31)O2)sc1ccccc14]

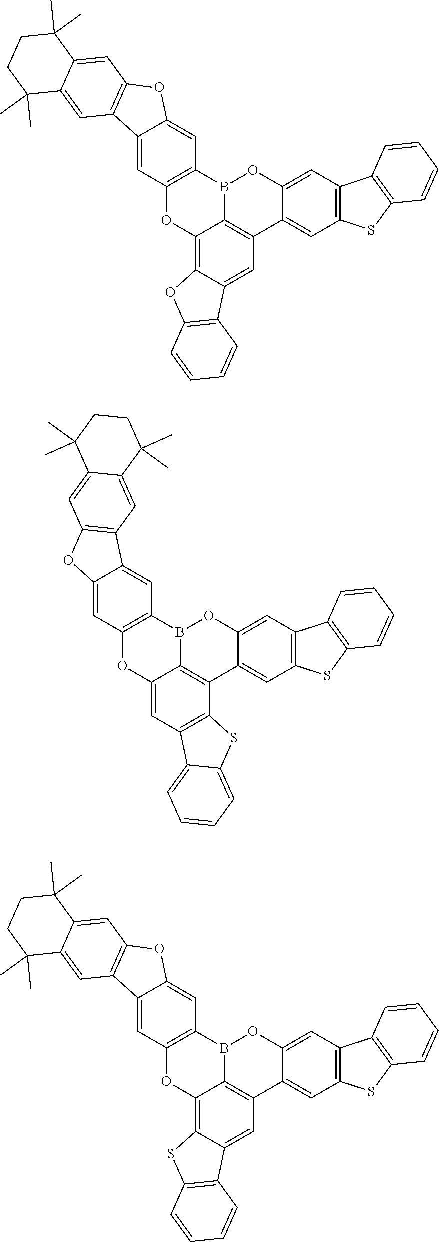 [SMILES: CC1(C)CCC(C)(C)c2cc3c(cc21)oc1cc2c(cc13)Oc1c3c(cc4c1oc1ccccc14)-c1cc4sc5ccccc5c4cc1OB23 ; CC1(C)CCC(C)(C)c2cc3c(cc21)oc1cc2c(cc13)B1Oc3cc4c(cc3-c3c1c(cc1c3sc3ccccc31)O2)sc1ccccc14 ; CC1(C)CCC(C)(C)c2cc3c(cc21)oc1cc2c(cc13)Oc1c3c(cc4c1sc1ccccc14)-c1cc4sc5ccccc5c4cc1OB23]

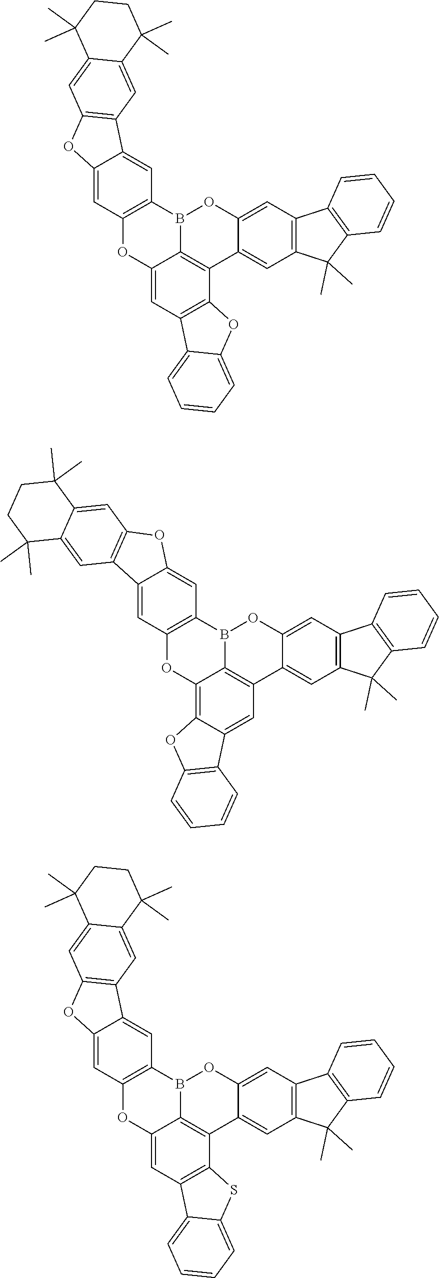 [SMILES: CC1(C)CCC(C)(C)c2cc3c(cc21)oc1cc2c(cc13)B1Oc3cc4c(cc3-c3c1c(cc1c3oc3ccccc31)O2)C(C)(C)c1ccccc1-4 ; CC1(C)CCC(C)(C)c2cc3c(cc21)oc1cc2c(cc13)Oc1c3c(cc4c1oc1ccccc14)-c1cc4c(cc1OB23)-c1ccccc1C4(C)C ; CC1(C)CCC(C)(C)c2cc3c(cc21)oc1cc2c(cc13)B1Oc3cc4c(cc3-c3c1c(cc1c3sc3ccccc31)O2)C(C)(C)c1ccccc1-4]

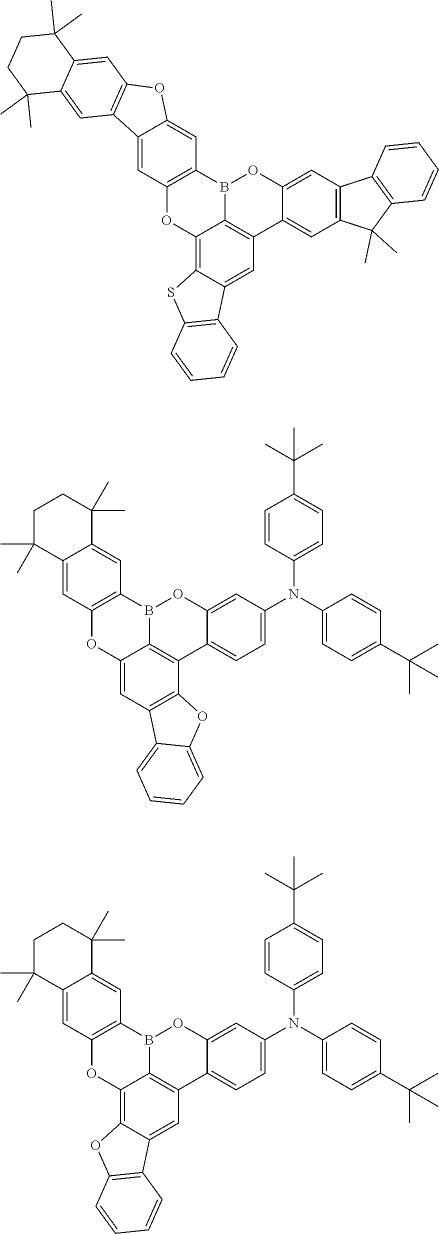

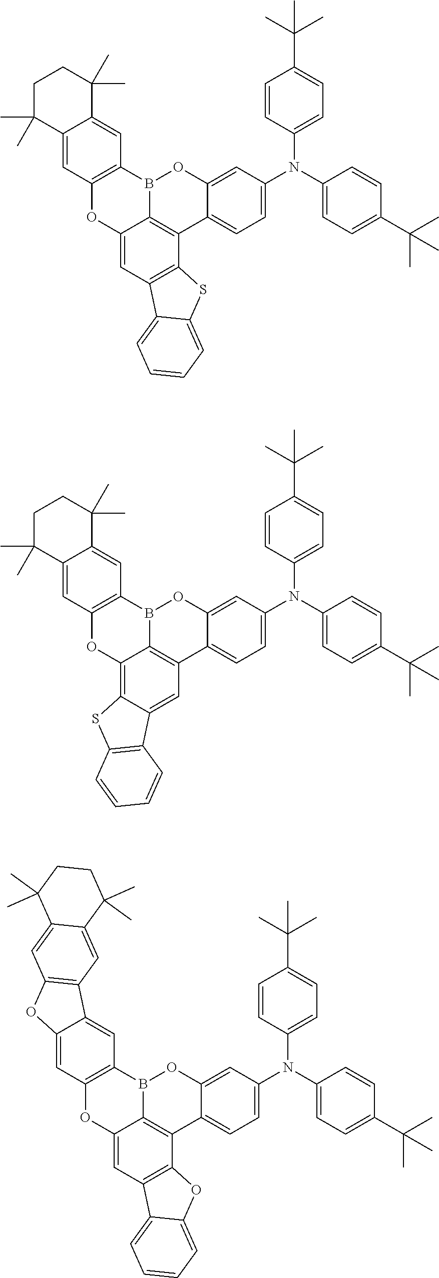

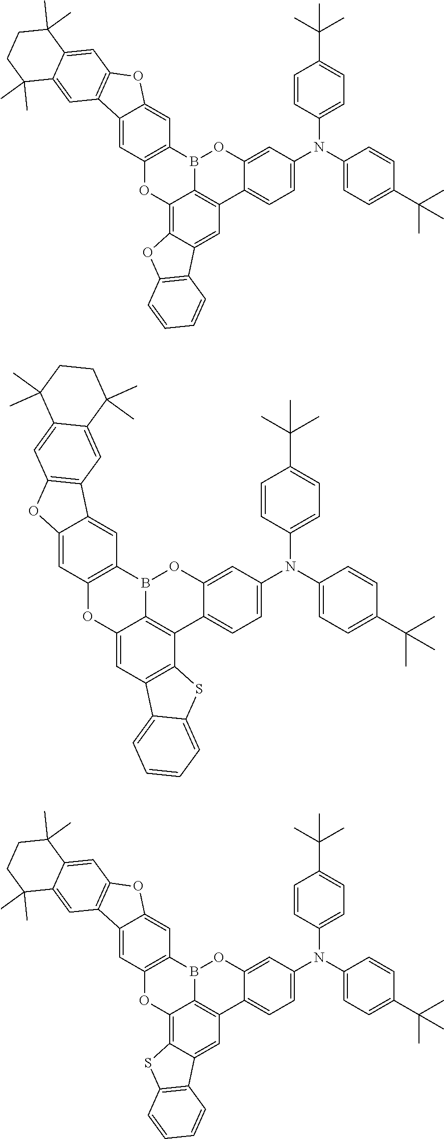

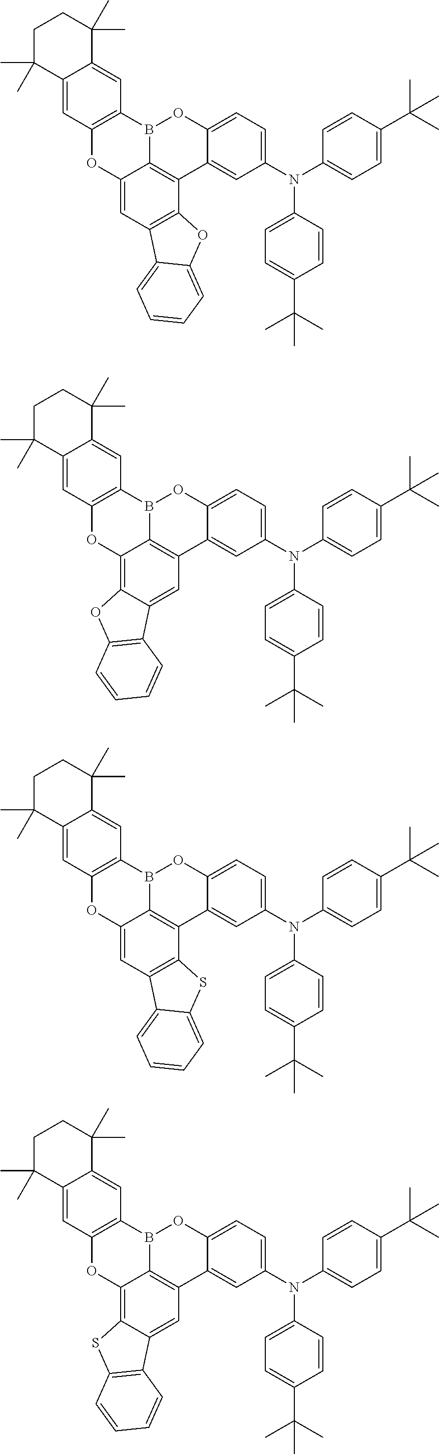

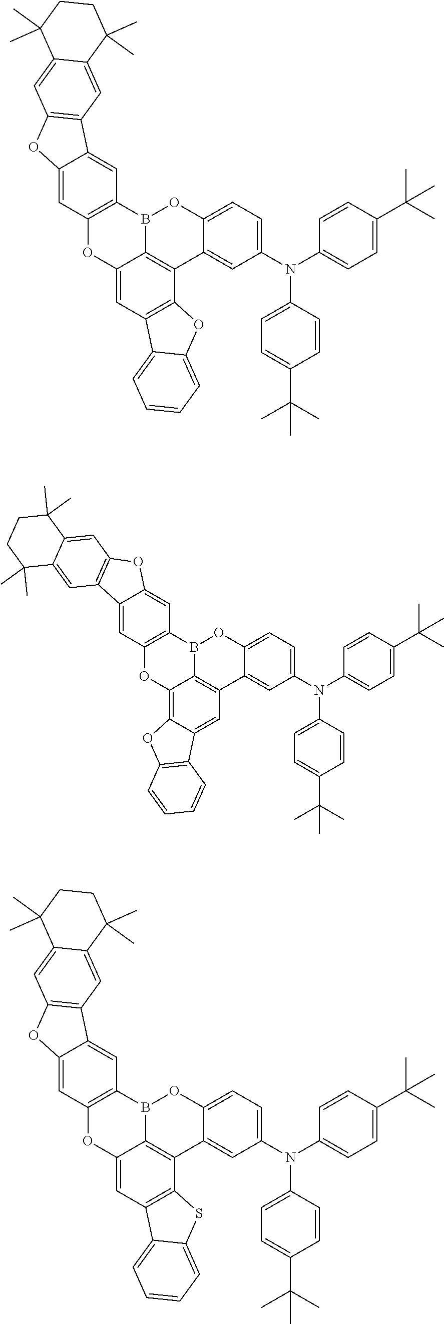

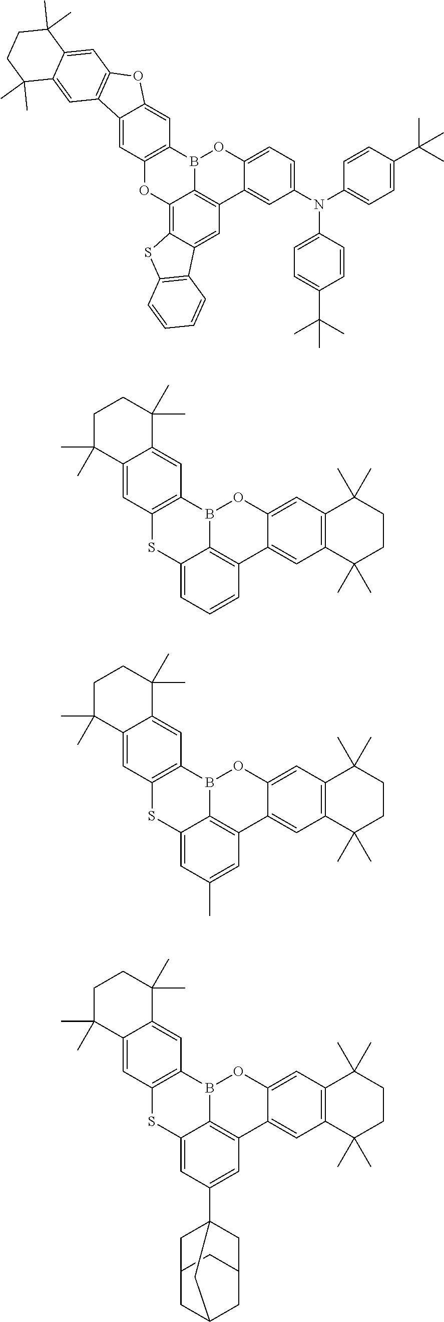

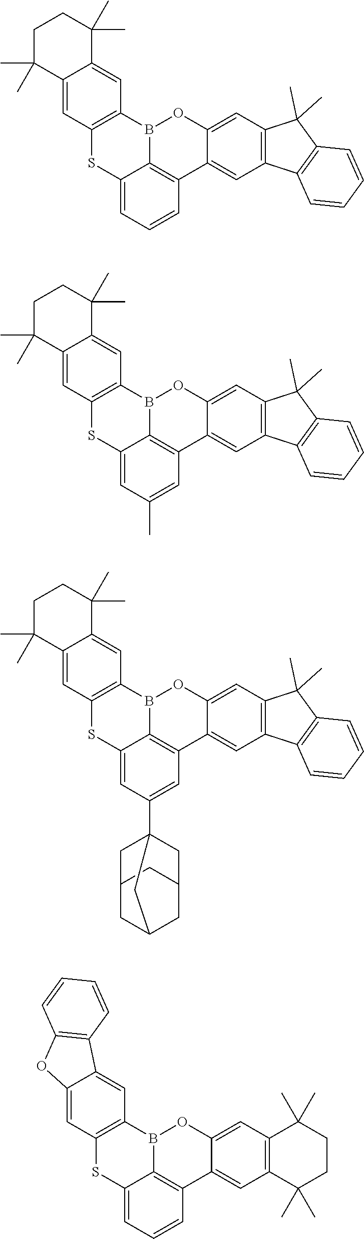 [SMILES: CC1(C)CCC(C)(C)c2cc3c(cc21)Sc1cccc2c1B3Oc1cc3c(cc1-2)-c1ccccc1C3(C)C ; Cc1cc2c3c(c1)-c1cc4c(cc1OB3c1cc3c(cc1S2)C(C)(C)CCC3(C)C)C(C)(C)c1ccccc1-4 ; CC1(C)CCC(C)(C)c2cc3c(cc21)Sc1cc(C24CC5CC(CC(C5)C2)C4)cc2c1B3Oc1cc3c(cc1-2)-c1ccccc1C3(C)C ; CC1(C)CCC(C)(C)c2cc3c(cc21)OB1c2cc4c(cc2Sc2cccc-3c21)oc1ccccc14]

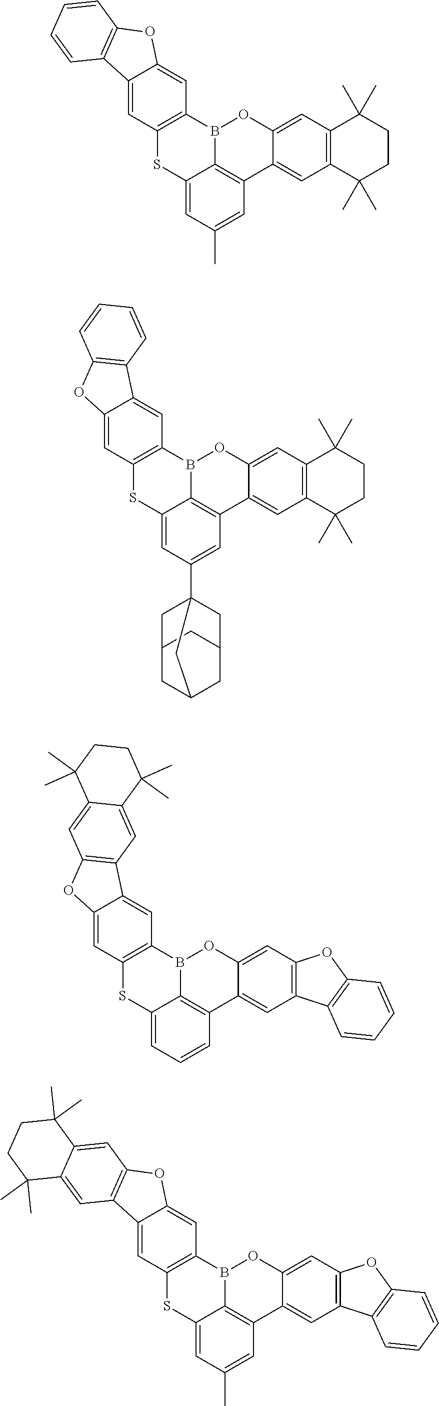 [SMILES: Cc1cc2c3c(c1)-c1cc4c(cc1OB3c1cc3oc5ccccc5c3cc1S2)C(C)(C)CCC4(C)C ; CC1(C)CCC(C)(C)c2cc3c(cc21)OB1c2cc4c(cc2Sc2cc(C56CC7CC(CC(C7)C5)C6)cc-3c21)oc1ccccc14 ; CC1(C)CCC(C)(C)c2cc3c(cc21)oc1cc2c(cc13)B1Oc3cc4oc5ccccc5c4cc3-c3cccc(c31)S2 ; Cc1cc2c3c(c1)-c1cc4c(cc1OB3c1cc3oc5cc6c(cc5c3cc1S2)C(C)(C)CCC6(C)C)oc1ccccc14]

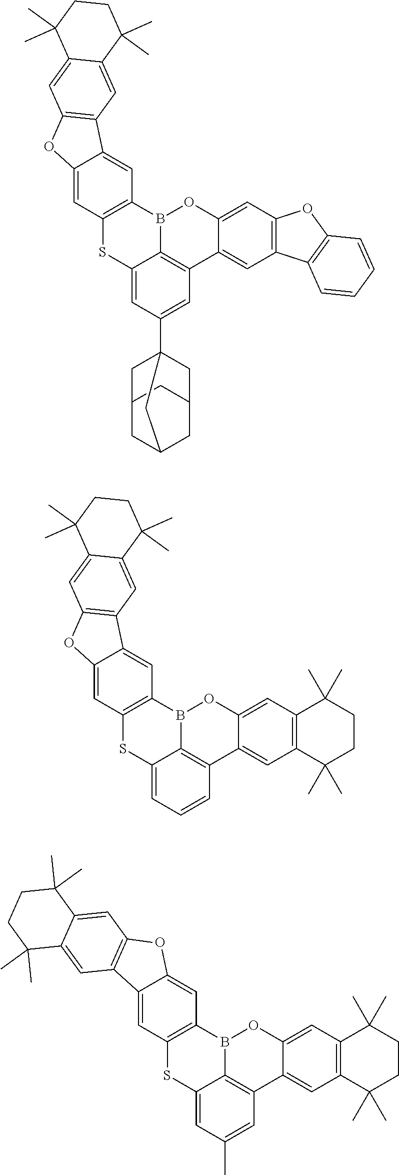 [SMILES: CC1(C)CCC(C)(C)c2cc3c(cc21)oc1cc2c(cc13)B1Oc3cc4oc5ccccc5c4cc3-c3cc(C45CC6CC(CC(C6)C4)C5)cc(c31)S2 ; CC1(C)CCC(C)(C)c2cc3c(cc21)OB1c2cc4c(cc2Sc2cccc-3c21)oc1cc2c(cc14)C(C)(C)CCC2(C)C ; Cc1cc2c3c(c1)-c1cc4c(cc1OB3c1cc3oc5cc6c(cc5c3cc1S2)C(C)(C)CCC6(C)C)C(C)(C)CCC4(C)C]

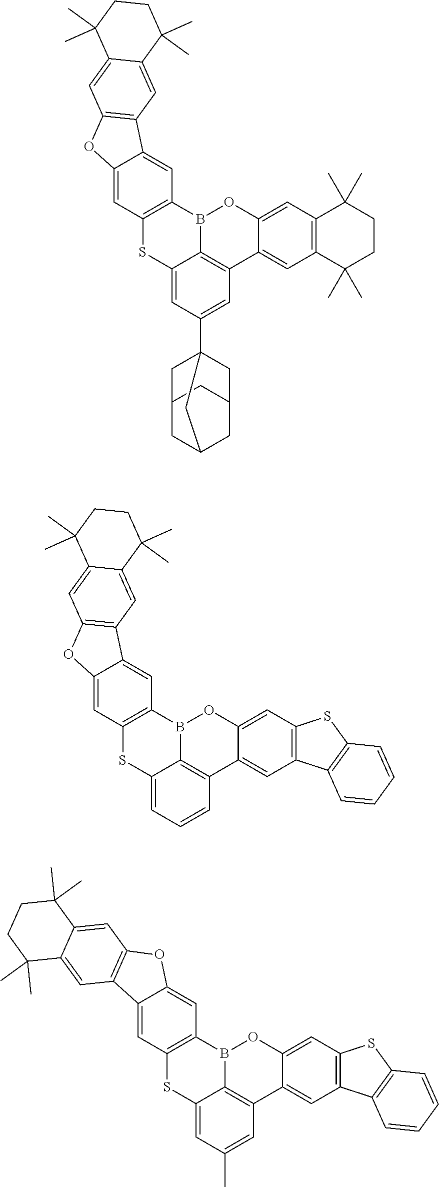 [SMILES: CC1(C)CCC(C)(C)c2cc3c(cc21)OB1c2cc4c(cc2Sc2cc(C56CC7CC(CC(C7)C5)C6)cc-3c21)oc1cc2c(cc14)C(C)(C)CCC2(C)C ; CC1(C)CCC(C)(C)c2cc3c(cc21)oc1cc2c(cc13)B1Oc3cc4sc5ccccc5c4cc3-c3cccc(c31)S2 ; Cc1cc2c3c(c1)-c1cc4c(cc1OB3c1cc3oc5cc6c(cc5c3cc1S2)C(C)(C)CCC6(C)C)sc1ccccc14]

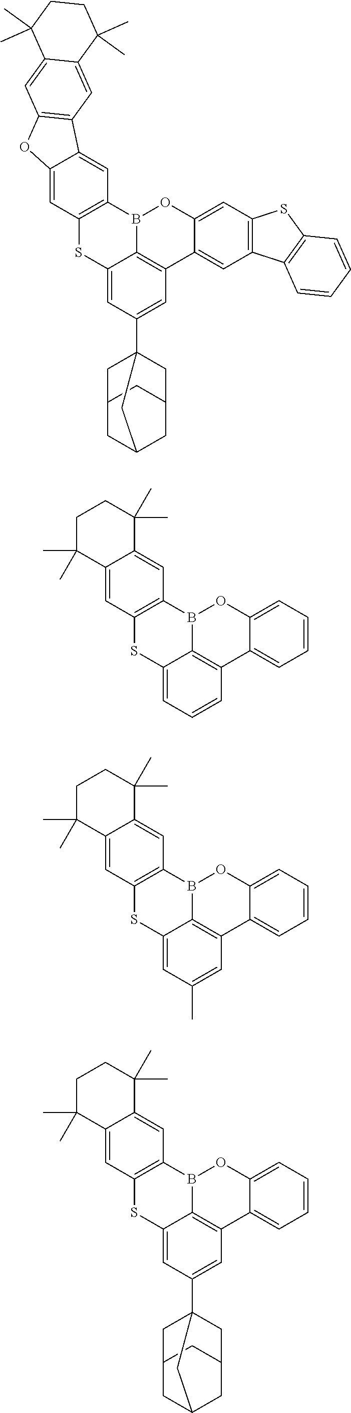

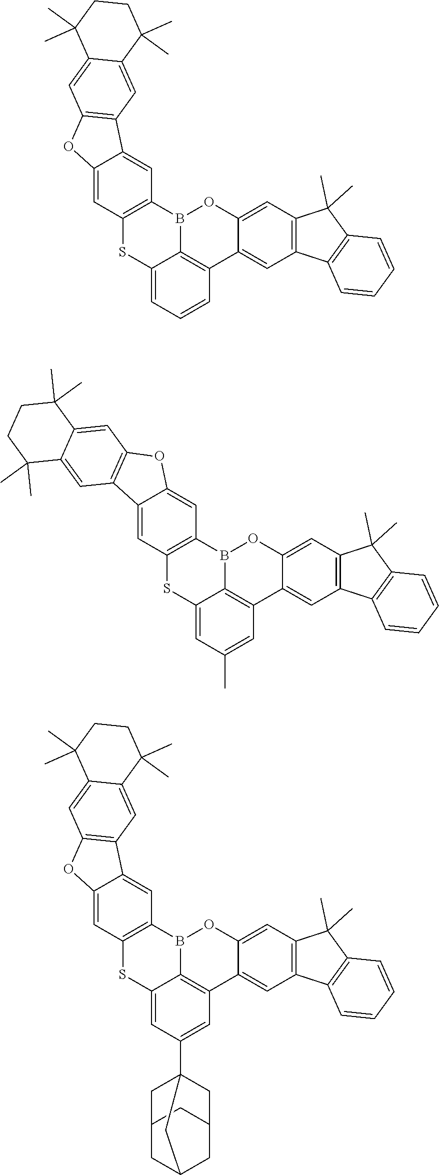 [SMILES: CC1(C)CCC(C)(C)c2cc3c(cc21)oc1cc2c(cc13)B1Oc3cc4c(cc3-c3cccc(c31)S2)-c1ccccc1C4(C)C ; Cc1cc2c3c(c1)-c1cc4c(cc1OB3c1cc3oc5cc6c(cc5c3cc1S2)C(C)(C)CCC6(C)C)C(C)(C)c1ccccc1-4 ; CC1(C)CCC(C)(C)c2cc3c(cc21)oc1cc2c(cc13)B1Oc3cc4c(cc3-c3cc(C56CC7CC(CC(C7)C5)C6)cc(c31)S2)-c1ccccc1C4(C)C]

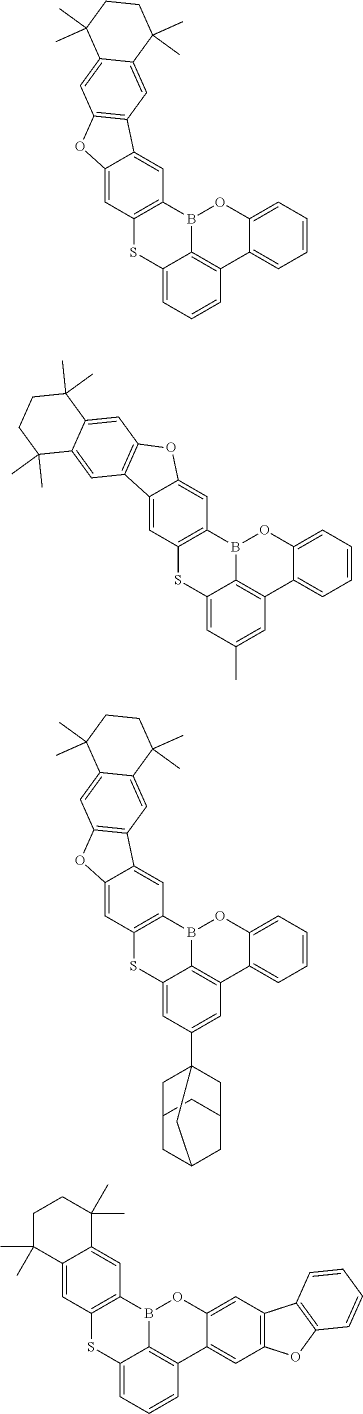 [SMILES: CC1(C)CCC(C)(C)c2cc3c(cc21)oc1cc2c(cc13)B1Oc3ccccc3-c3cccc(c31)S2 ; Cc1cc2c3c(c1)-c1ccccc1OB3c1cc3oc4cc5c(cc4c3cc1S2)C(C)(C)CCC5(C)C ; CC1(C)CCC(C)(C)c2cc3c(cc21)oc1cc2c(cc13)B1Oc3ccccc3-c3cc(C45CC6CC(CC(C6)C4)C5)cc(c31)S2 ; CC1(C)CCC(C)(C)c2cc3c(cc21)Sc1cccc2c1B3Oc1cc3c(cc1-2)oc1ccccc13]

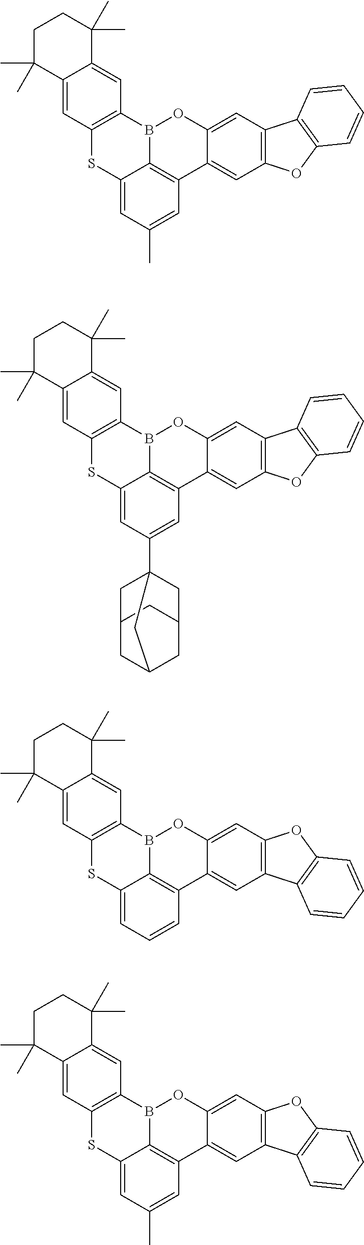 [SMILES: Cc1cc2c3c(c1)-c1cc4oc5ccccc5c4cc1OB3c1cc3c(cc1S2)C(C)(C)CCC3(C)C ; CC1(C)CCC(C)(C)c2cc3c(cc21)Sc1cc(C24CC5CC(CC(C5)C2)C4)cc2c1B3Oc1cc3c(cc1-2)oc1ccccc13 ; CC1(C)CCC(C)(C)c2cc3c(cc21)Sc1cccc2c1B3Oc1cc3oc4ccccc4c3cc1-2 ; Cc1cc2c3c(c1)-c1cc4c(cc1OB3c1cc3c(cc1S2)C(C)(C)CCC3(C)C)oc1ccccc14]

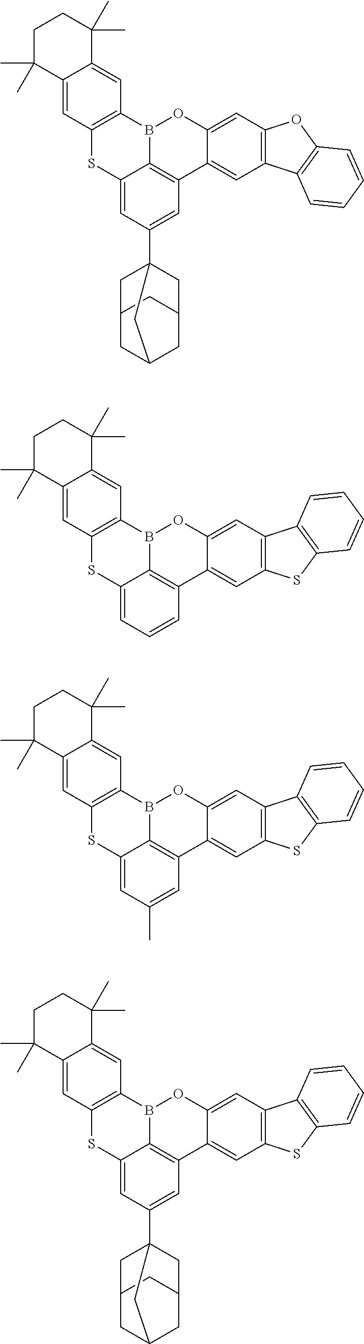 [SMILES: CC1(C)CCC(C)(C)c2cc3c(cc21)Sc1cc(C24CC5CC(CC(C5)C2)C4)cc2c1B3Oc1cc3oc4ccccc4c3cc1-2 ; CC1(C)CCC(C)(C)c2cc3c(cc21)Sc1cccc2c1B3Oc1cc3c(cc1-2)sc1ccccc13 ; Cc1cc2c3c(c1)-c1cc4sc5ccccc5c4cc1OB3c1cc3c(cc1S2)C(C)(C)CCC3(C)C ; CC1(C)CCC(C)(C)c2cc3c(cc21)Sc1cc(C24CC5CC(CC(C5)C2)C4)cc2c1B3Oc1cc3c(cc1-2)sc1ccccc13]

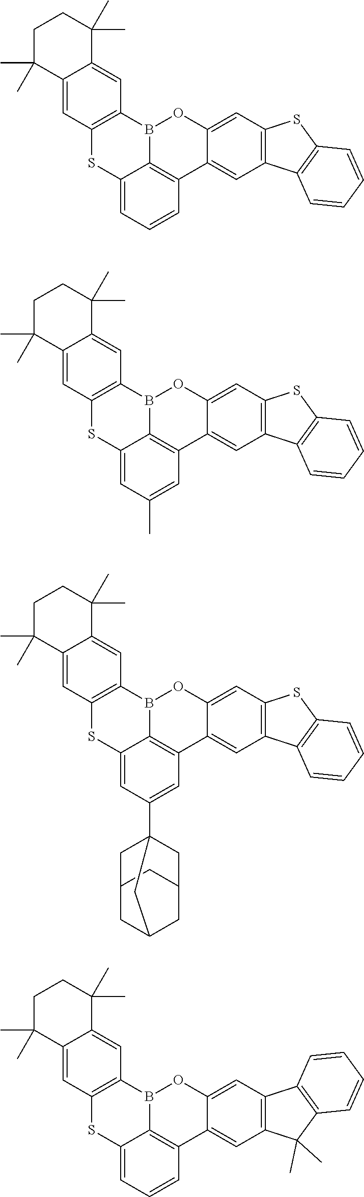 [SMILES: CC1(C)CCC(C)(C)c2cc3c(cc21)Sc1cccc2c1B3Oc1cc3sc4ccccc4c3cc1-2 ; Cc1cc2c3c(c1)-c1cc4c(cc1OB3c1cc3c(cc1S2)C(C)(C)CCC3(C)C)sc1ccccc14 ; CC1(C)CCC(C)(C)c2cc3c(cc21)Sc1cc(C24CC5CC(CC(C5)C2)C4)cc2c1B3Oc1cc3sc4ccccc4c3cc1-2 ; CC1(C)CCC(C)(C)c2cc3c(cc21)Sc1cccc2c1B3Oc1cc3c(cc1-2)C(C)(C)c1ccccc1-3]

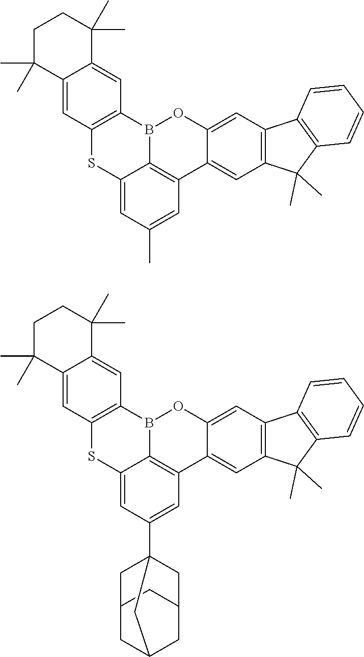 [SMILES: Cc1cc2c3c(c1)-c1cc4c(cc1OB3c1cc3c(cc1S2)C(C)(C)CCC3(C)C)-c1ccccc1C4(C)C ; CC1(C)CCC(C)(C)c2cc3c(cc21)Sc1cc(C24CC5CC(CC(C5)C2)C4)cc2c1B3Oc1cc3c(cc1-2)C(C)(C)c1ccccc1-3]

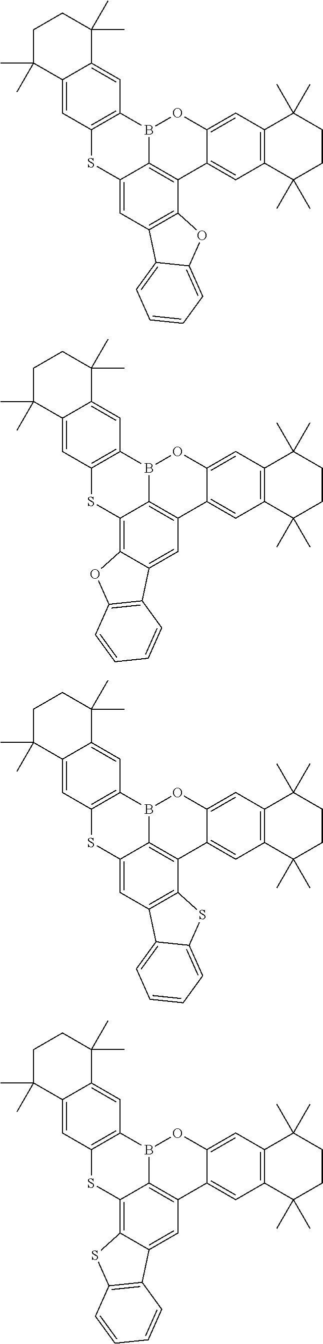

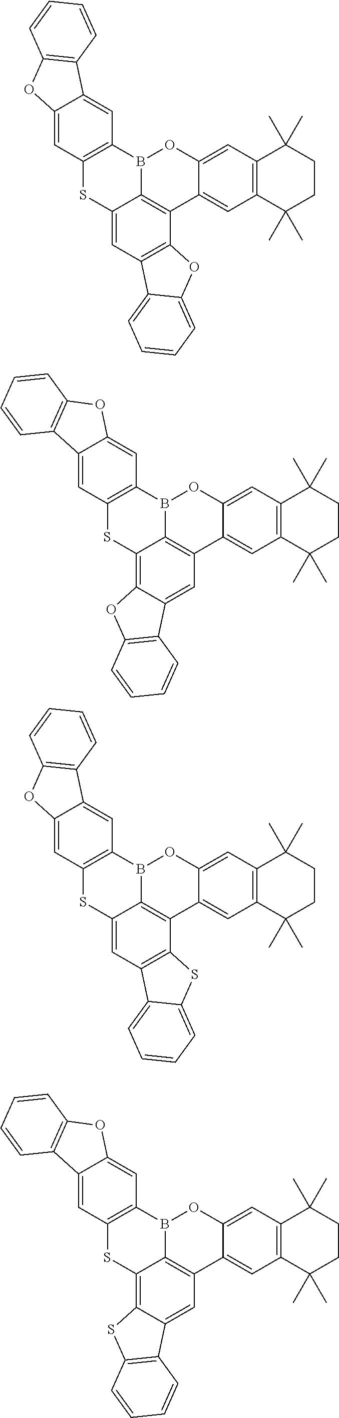 [SMILES: CC1(C)CCC(C)(C)c2cc3c(cc21)OB1c2cc4c(cc2Sc2cc5c(oc6ccccc65)c-3c21)oc1ccccc14 ; CC1(C)CCC(C)(C)c2cc3c(cc21)OB1c2cc4oc5ccccc5c4cc2Sc2c1c-3cc1c2oc2ccccc21 ; CC1(C)CCC(C)(C)c2cc3c(cc21)OB1c2cc4c(cc2Sc2cc5c(sc6ccccc65)c-3c21)oc1ccccc14 ; CC1(C)CCC(C)(C)c2cc3c(cc21)OB1c2cc4oc5ccccc5c4cc2Sc2c1c-3cc1c2sc2ccccc21]

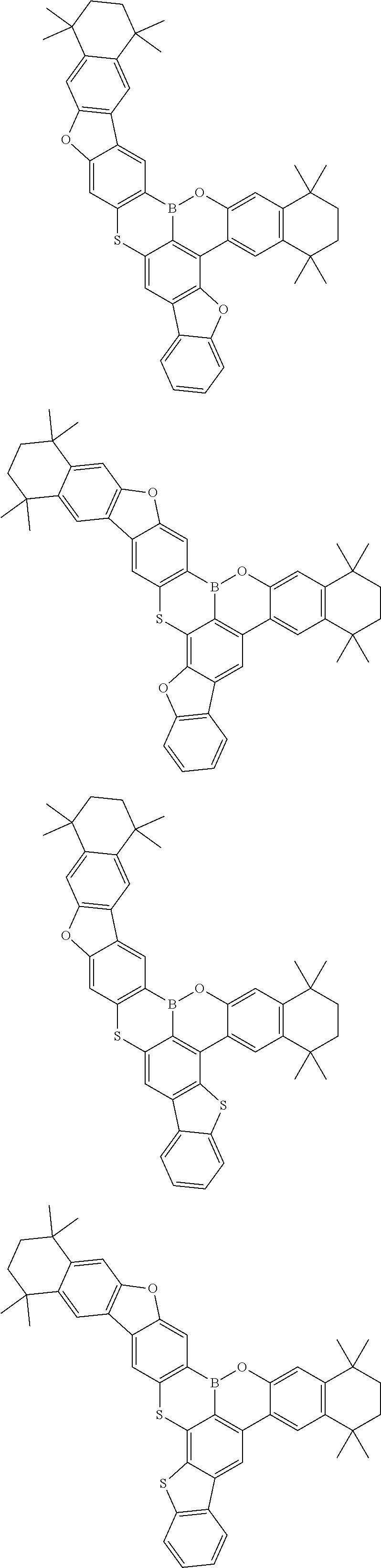 [SMILES: CC1(C)CCC(C)(C)c2cc3c(cc21)OB1c2cc4c(cc2Sc2cc5c(oc6ccccc65)c-3c21)oc1cc2c(cc14)C(C)(C)CCC2(C)C ; CC1(C)CCC(C)(C)c2cc3c(cc21)OB1c2cc4oc5cc6c(cc5c4cc2Sc2c1c-3cc1c2oc2ccccc21)C(C)(C)CCC6(C)C ; CC1(C)CCC(C)(C)c2cc3c(cc21)OB1c2cc4c(cc2Sc2cc5c(sc6ccccc65)c-3c21)oc1cc2c(cc14)C(C)(C)CCC2(C)C ; CC1(C)CCC(C)(C)c2cc3c(cc21)OB1c2cc4oc5cc6c(cc5c4cc2Sc2c1c-3cc1c2sc2ccccc21)C(C)(C)CCC6(C)C]

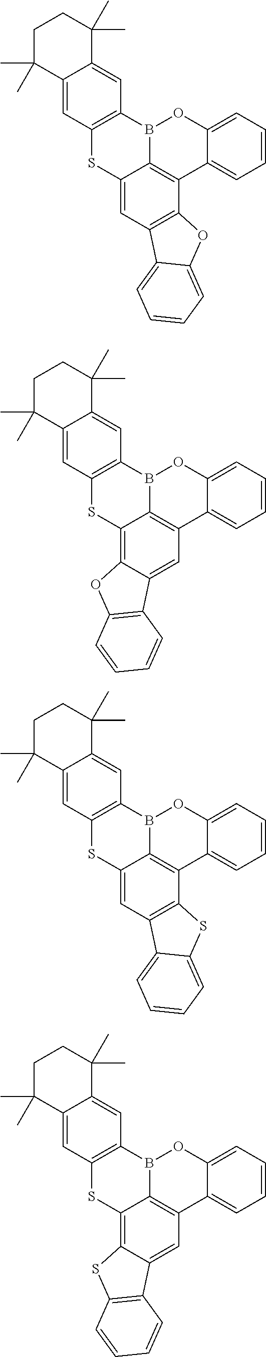

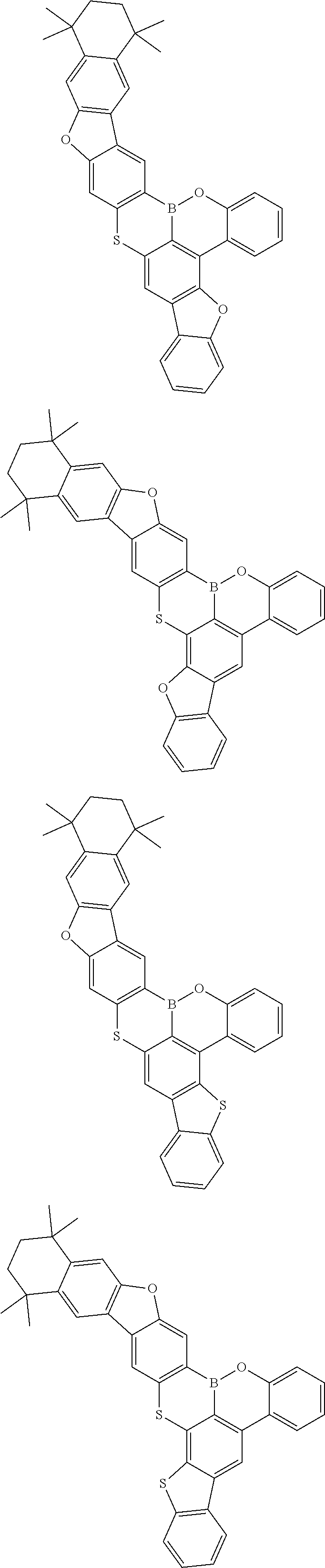 [SMILES: CC1(C)CCC(C)(C)c2cc3c(cc21)oc1cc2c(cc13)B1Oc3ccccc3-c3c1c(cc1c3oc3ccccc31)S2 ; CC1(C)CCC(C)(C)c2cc3c(cc21)oc1cc2c(cc13)Sc1c3c(cc4c1oc1ccccc14)-c1ccccc1OB23 ; CC1(C)CCC(C)(C)c2cc3c(cc21)oc1cc2c(cc13)B1Oc3ccccc3-c3c1c(cc1c3sc3ccccc31)S2 ; CC1(C)CCC(C)(C)c2cc3c(cc21)oc1cc2c(cc13)Sc1c3c(cc4c1sc1ccccc14)-c1ccccc1OB23]

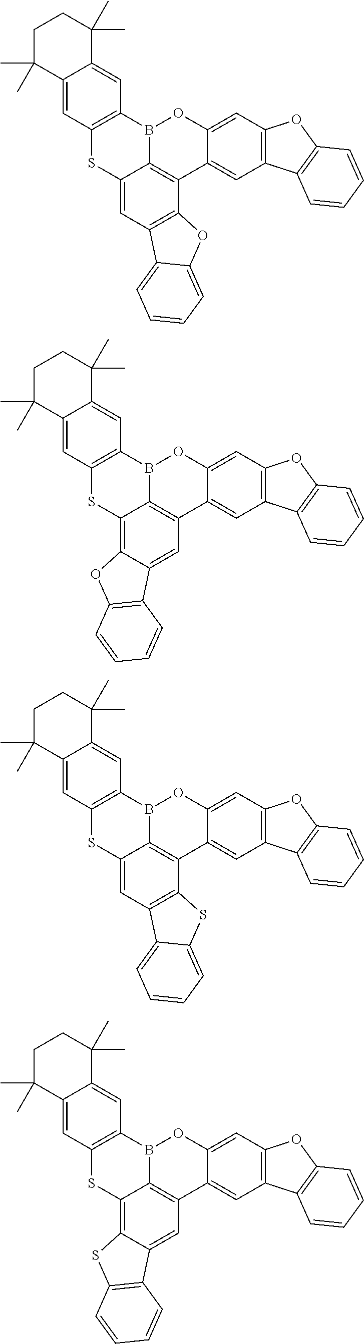

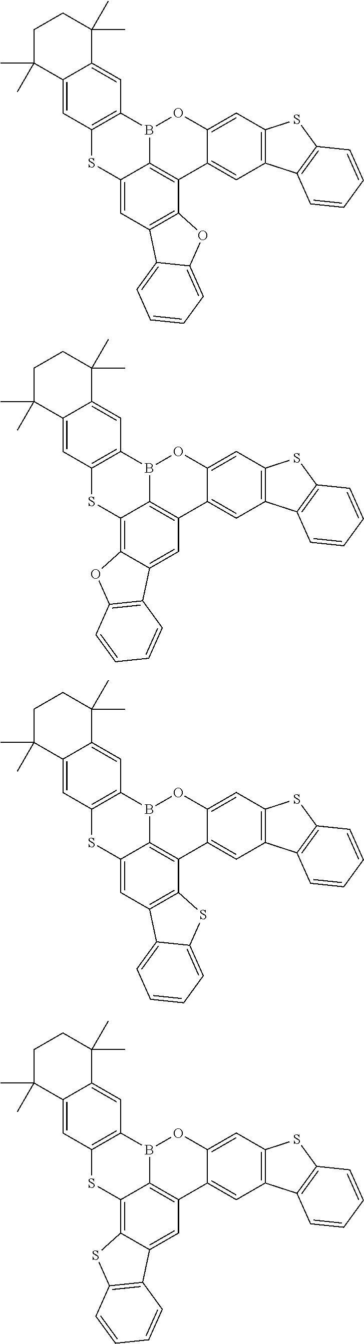

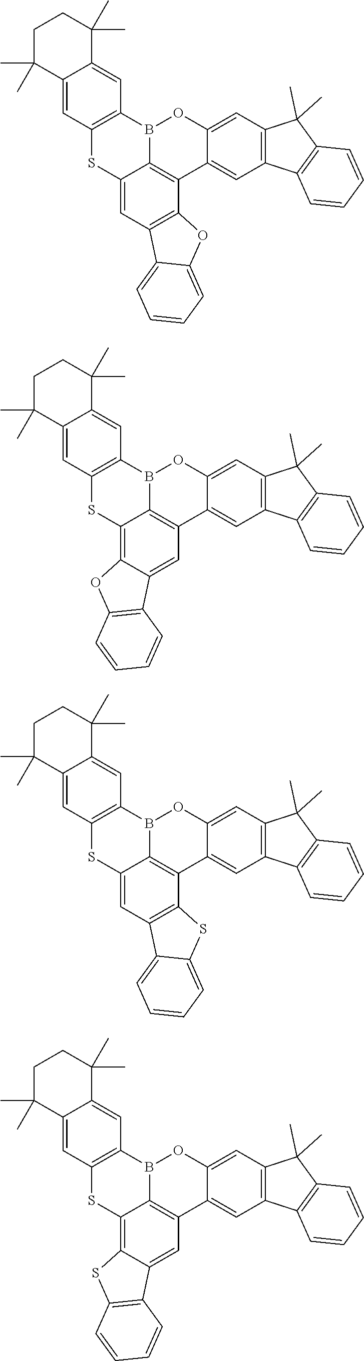

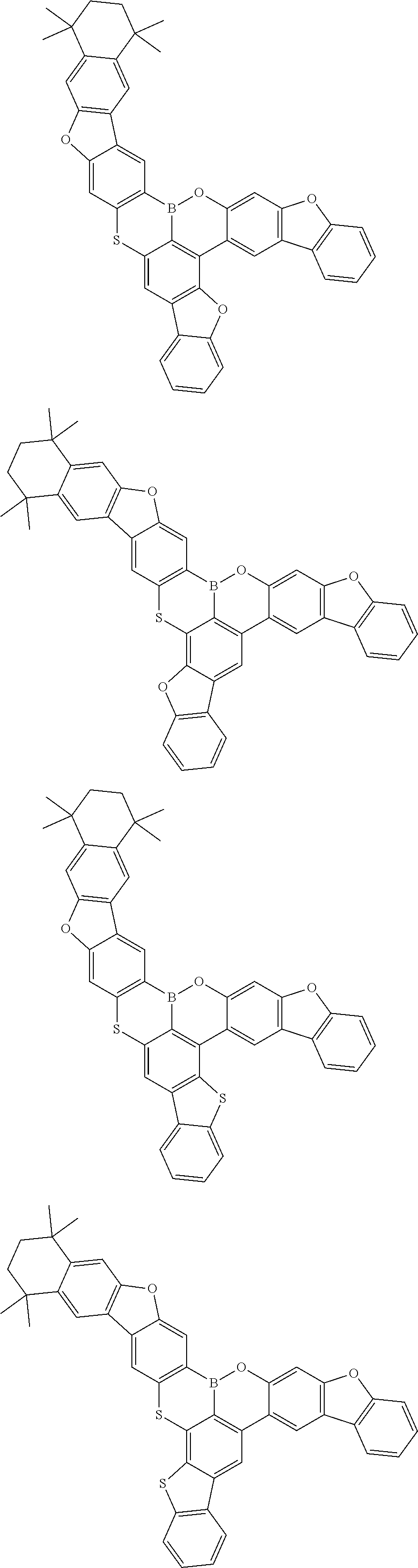

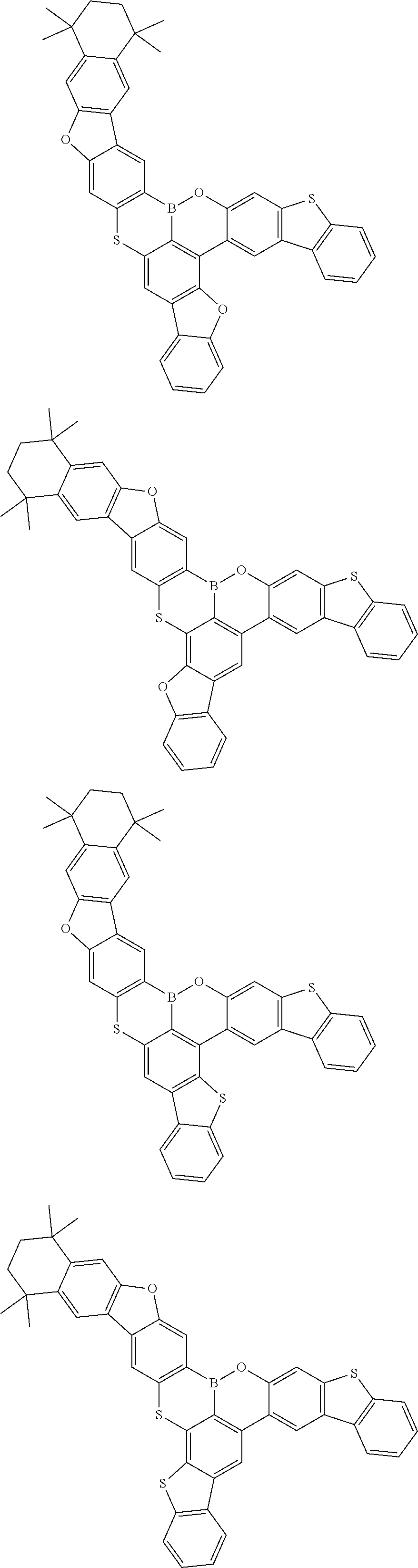

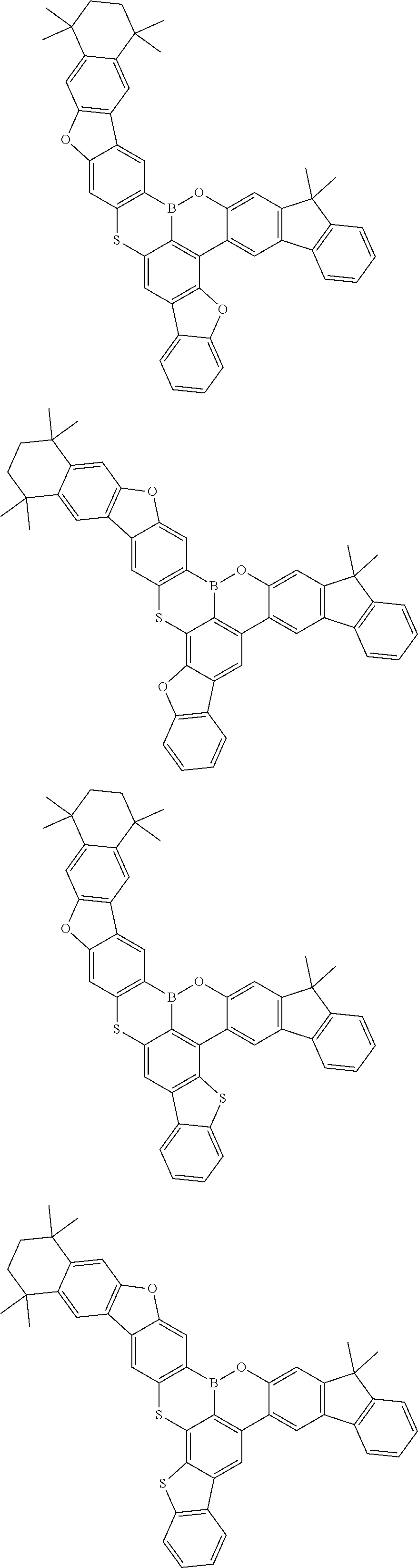

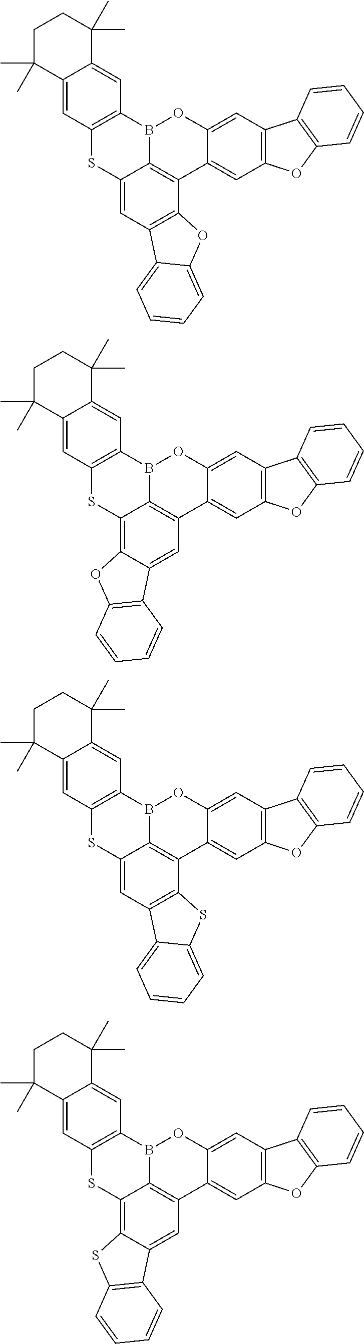

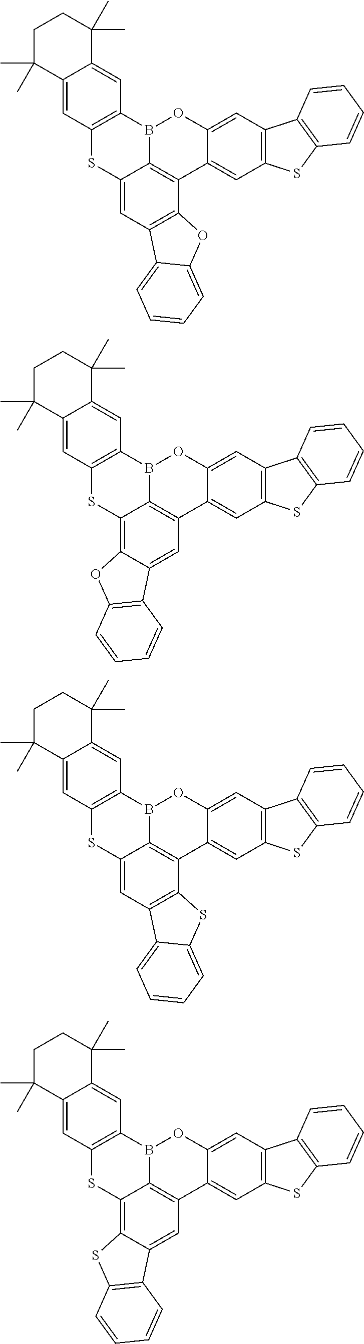

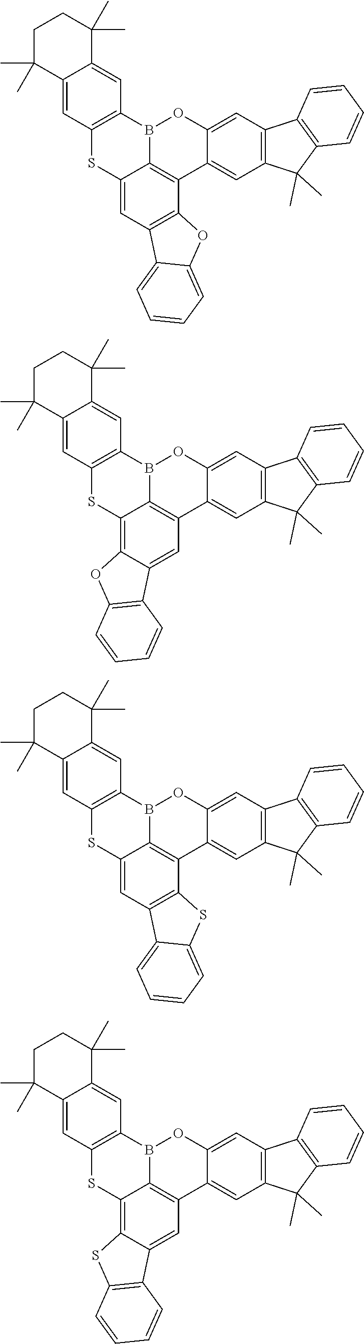

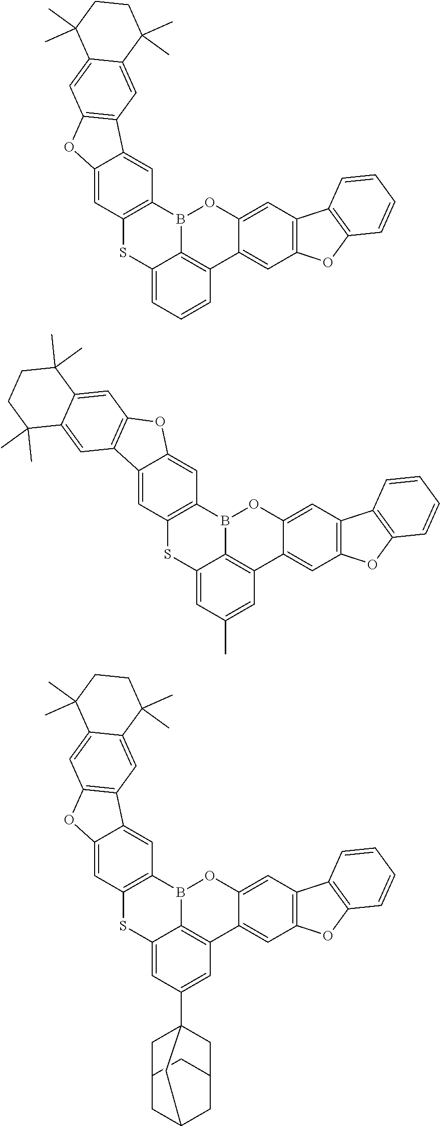 [SMILES: CC1(C)CCC(C)(C)c2cc3c(cc21)oc1cc2c(cc13)B1Oc3cc4c(cc3-c3cccc(c31)S2)oc1ccccc14 ; Cc1cc2c3c(c1)-c1cc4oc5ccccc5c4cc1OB3c1cc3oc4cc5c(cc4c3cc1S2)C(C)(C)CCC5(C)C ; CC1(C)CCC(C)(C)c2cc3c(cc21)oc1cc2c(cc13)B1Oc3cc4c(cc3-c3cc(C56CC7CC(CC(C7)C5)C6)cc(c31)S2)oc1ccccc14]

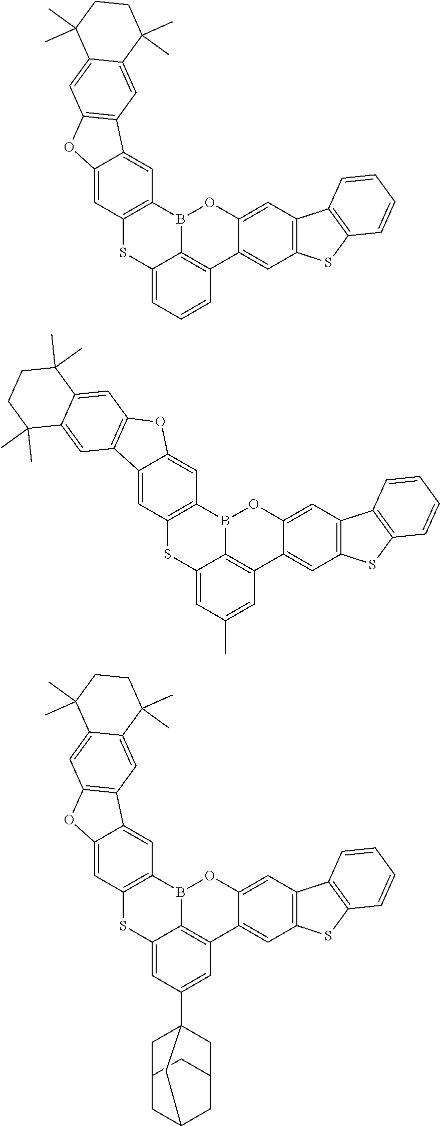 [SMILES: CC1(C)CCC(C)(C)c2cc3c(cc21)oc1cc2c(cc13)B1Oc3cc4c(cc3-c3cccc(c31)S2)sc1ccccc14 ; Cc1cc2c3c(c1)-c1cc4sc5ccccc5c4cc1OB3c1cc3oc4cc5c(cc4c3cc1S2)C(C)(C)CCC5(C)C ; CC1(C)CCC(C)(C)c2cc3c(cc21)oc1cc2c(cc13)B1Oc3cc4c(cc3-c3cc(C56CC7CC(CC(C7)C5)C6)cc(c31)S2)sc1ccccc14]

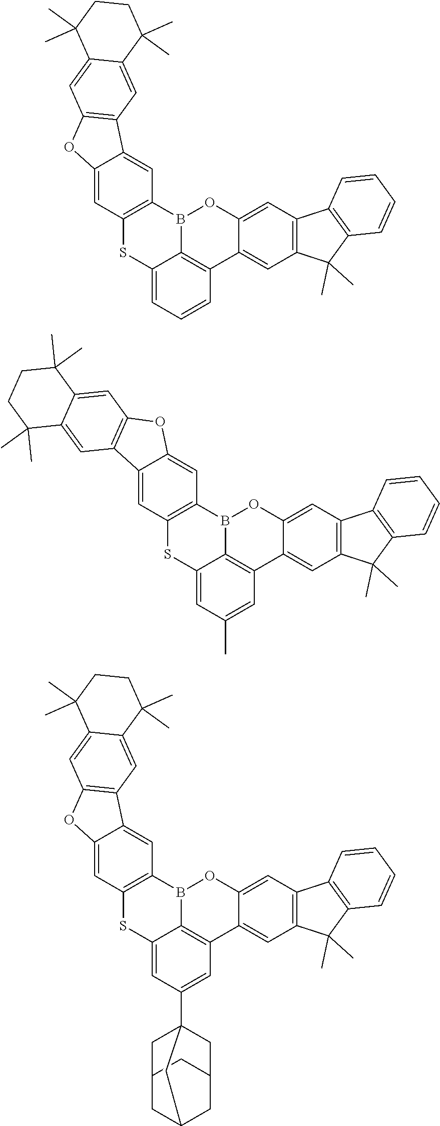 [SMILES: CC1(C)CCC(C)(C)c2cc3c(cc21)oc1cc2c(cc13)B1Oc3cc4c(cc3-c3cccc(c31)S2)C(C)(C)c1ccccc1-4 ; Cc1cc2c3c(c1)-c1cc4c(cc1OB3c1cc3oc5cc6c(cc5c3cc1S2)C(C)(C)CCC6(C)C)-c1ccccc1C4(C)C ; CC1(C)CCC(C)(C)c2cc3c(cc21)oc1cc2c(cc13)B1Oc3cc4c(cc3-c3cc(C56CC7CC(CC(C7)C5)C6)cc(c31)S2)C(C)(C)c1ccccc1-4]

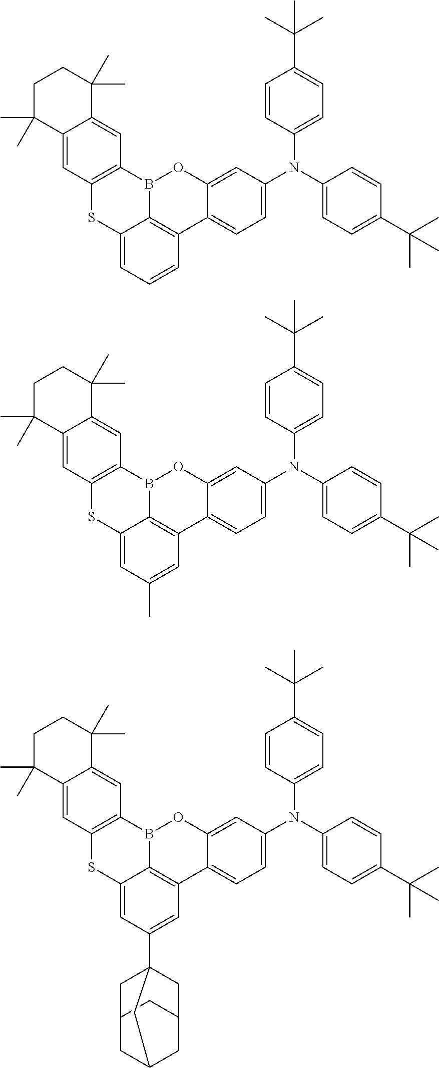

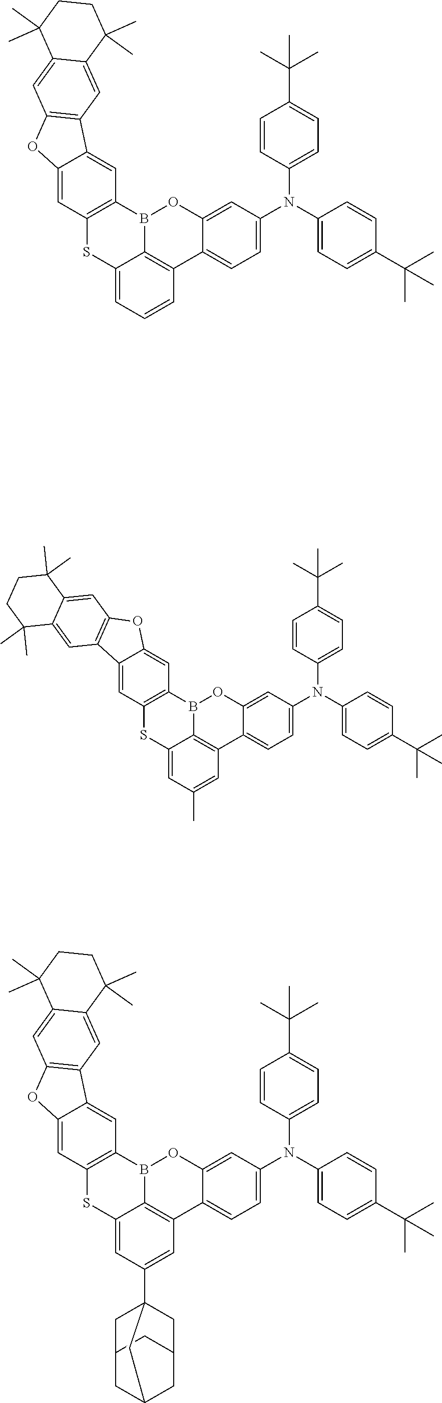

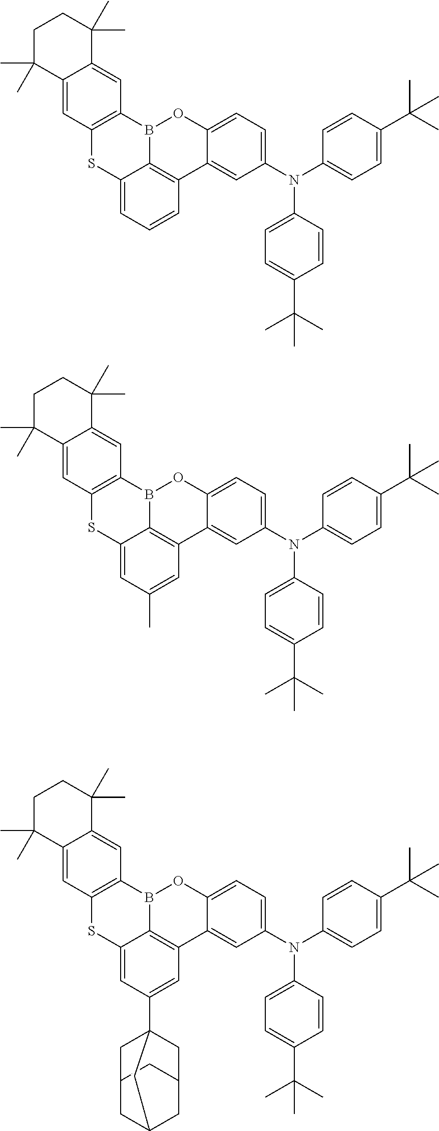

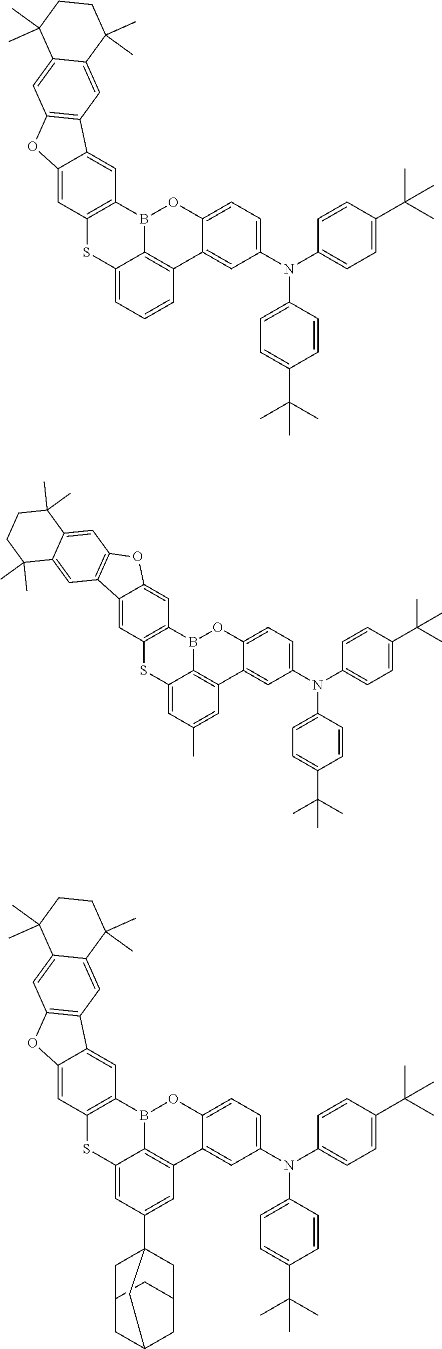

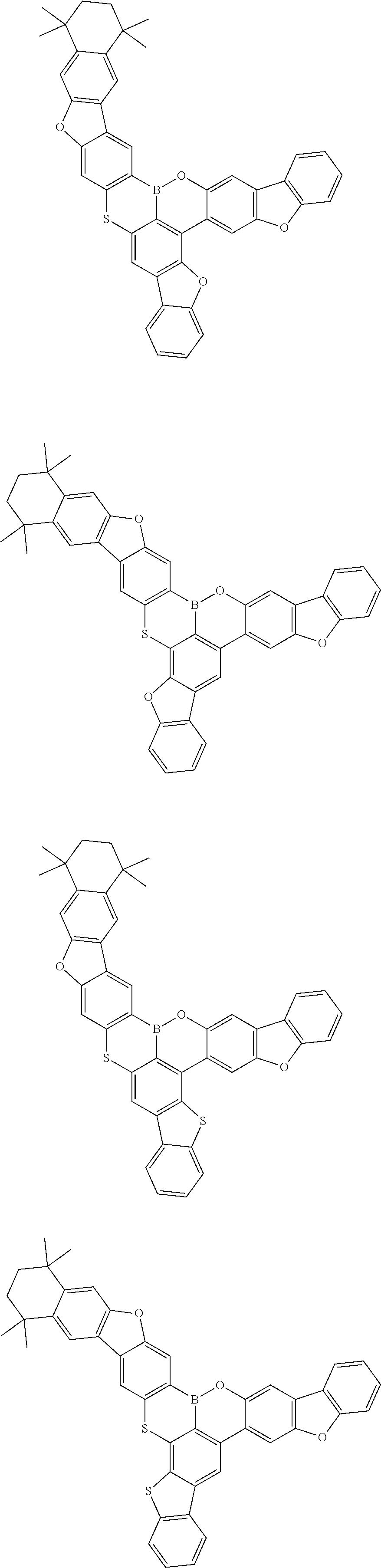 [SMILES: CC1(C)CCC(C)(C)c2cc3c(cc21)oc1cc2c(cc13)B1Oc3cc4c(cc3-c3c1c(cc1c3oc3ccccc31)S2)oc1ccccc14 ; CC1(C)CCC(C)(C)c2cc3c(cc21)oc1cc2c(cc13)Sc1c3c(cc4c1oc1ccccc14)-c1cc4oc5ccccc5c4cc1OB23 ; CC1(C)CCC(C)(C)c2cc3c(cc21)oc1cc2c(cc13)B1Oc3cc4c(cc3-c3c1c(cc1c3sc3ccccc31)S2)oc1ccccc14 ; CC1(C)CCC(C)(C)c2cc3c(cc21)oc1cc2c(cc13)Sc1c3c(cc4c1sc1ccccc14)-c1cc4oc5ccccc5c4cc1OB23]

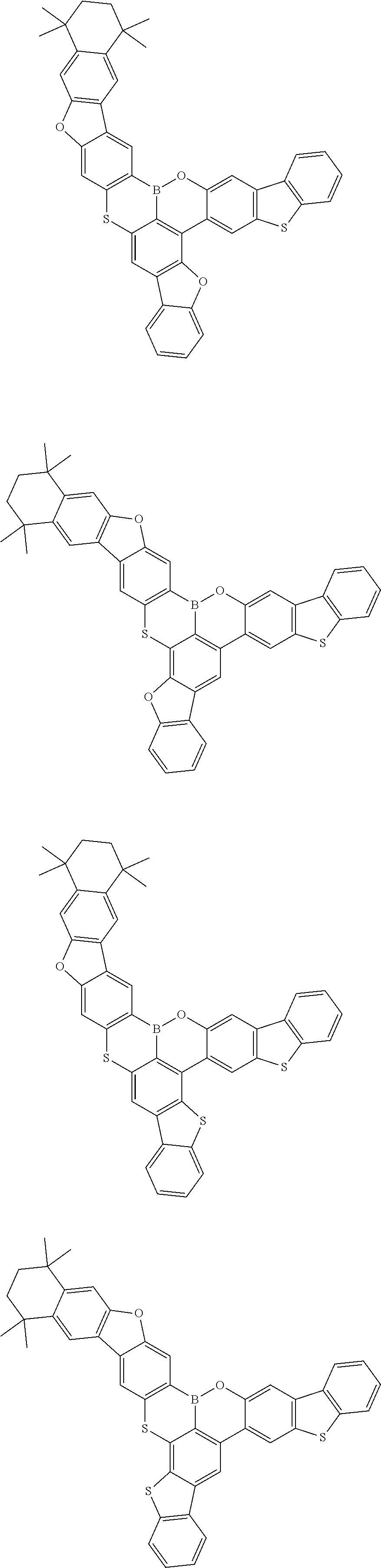 [SMILES: CC1(C)CCC(C)(C)c2cc3c(cc21)oc1cc2c(cc13)B1Oc3cc4c(cc3-c3c1c(cc1c3oc3ccccc31)S2)sc1ccccc14 ; CC1(C)CCC(C)(C)c2cc3c(cc21)oc1cc2c(cc13)Sc1c3c(cc4c1oc1ccccc14)-c1cc4sc5ccccc5c4cc1OB23 ; CC1(C)CCC(C)(C)c2cc3c(cc21)oc1cc2c(cc13)B1Oc3cc4c(cc3-c3c1c(cc1c3sc3ccccc31)S2)sc1ccccc14 ; CC1(C)CCC(C)(C)c2cc3c(cc21)oc1cc2c(cc13)Sc1c3c(cc4c1sc1ccccc14)-c1cc4sc5ccccc5c4cc1OB23]

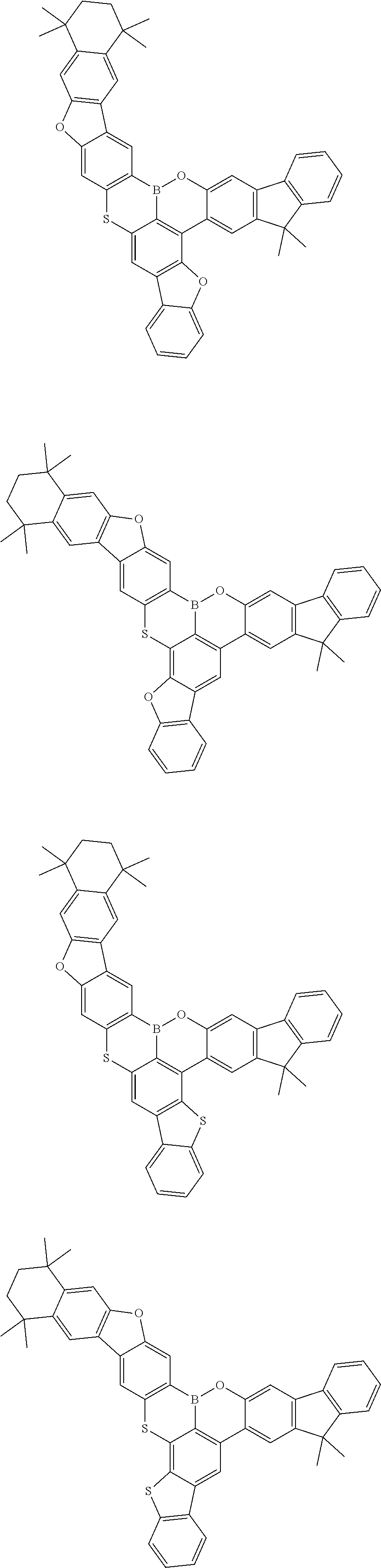 [SMILES: CC1(C)CCC(C)(C)c2cc3c(cc21)oc1cc2c(cc13)B1Oc3cc4c(cc3-c3c1c(cc1c3oc3ccccc31)S2)C(C)(C)c1ccccc1-4 ; CC1(C)CCC(C)(C)c2cc3c(cc21)oc1cc2c(cc13)Sc1c3c(cc4c1oc1ccccc14)-c1cc4c(cc1OB23)-c1ccccc1C4(C)C ; CC1(C)CCC(C)(C)c2cc3c(cc21)oc1cc2c(cc13)B1Oc3cc4c(cc3-c3c1c(cc1c3sc3ccccc31)S2)C(C)(C)c1ccccc1-4 ; CC1(C)CCC(C)(C)c2cc3c(cc21)oc1cc2c(cc13)Sc1c3c(cc4c1sc1ccccc14)-c1cc4c(cc1OB23)-c1ccccc1C4(C)C]

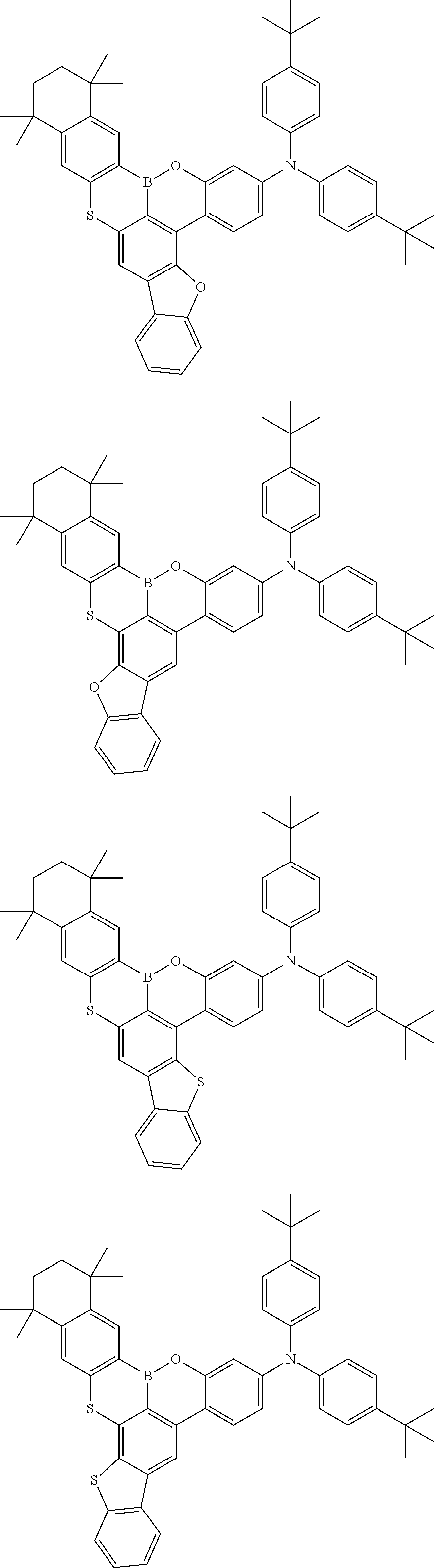

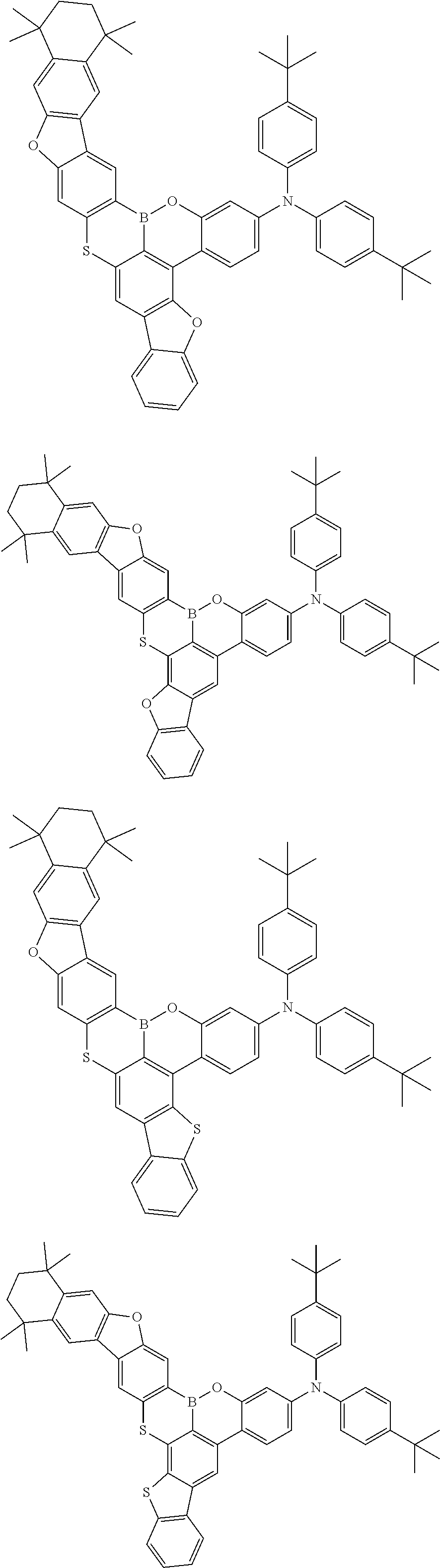

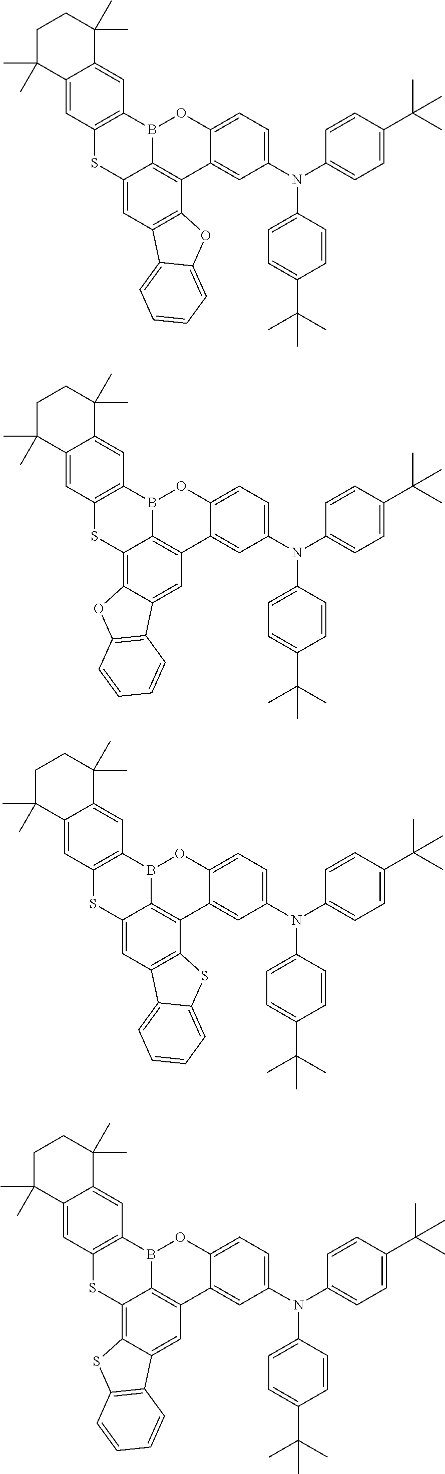

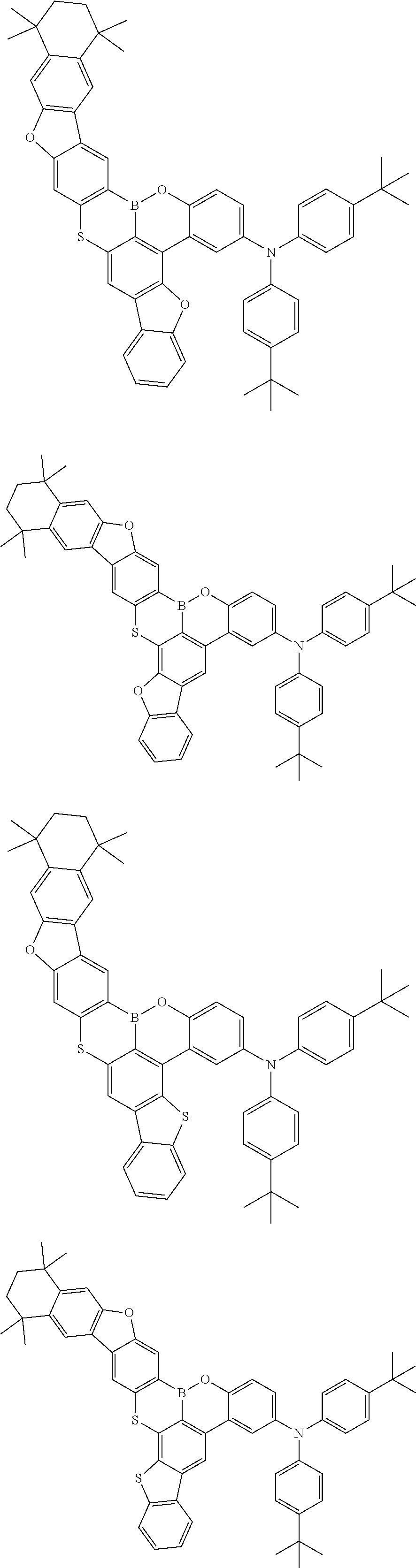

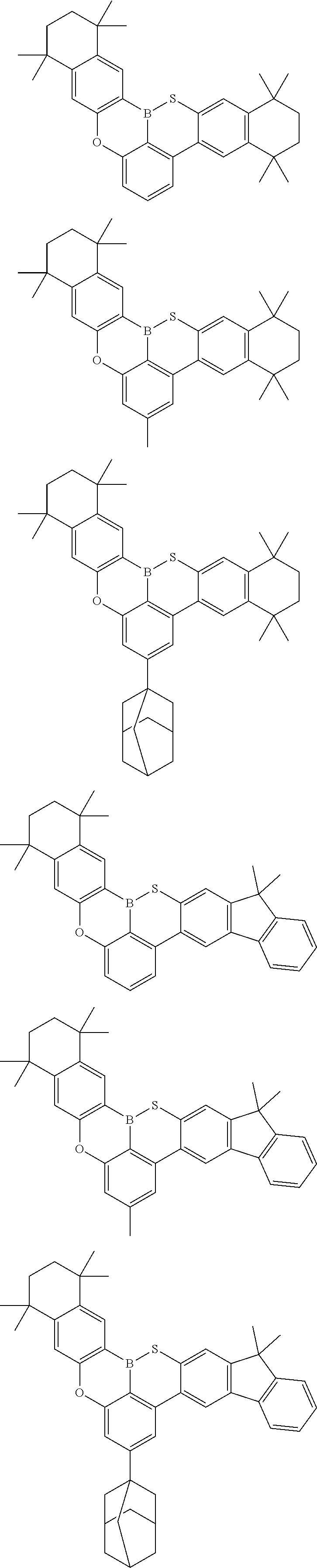

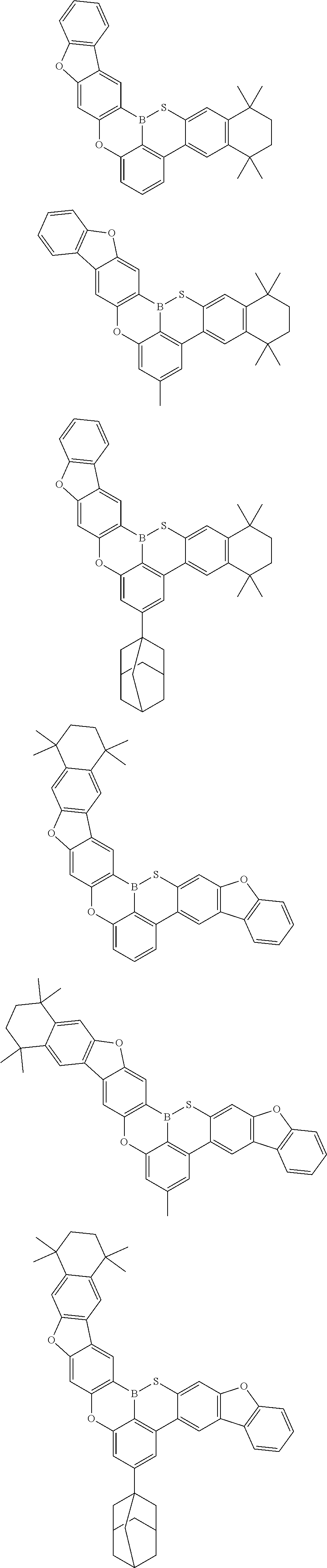

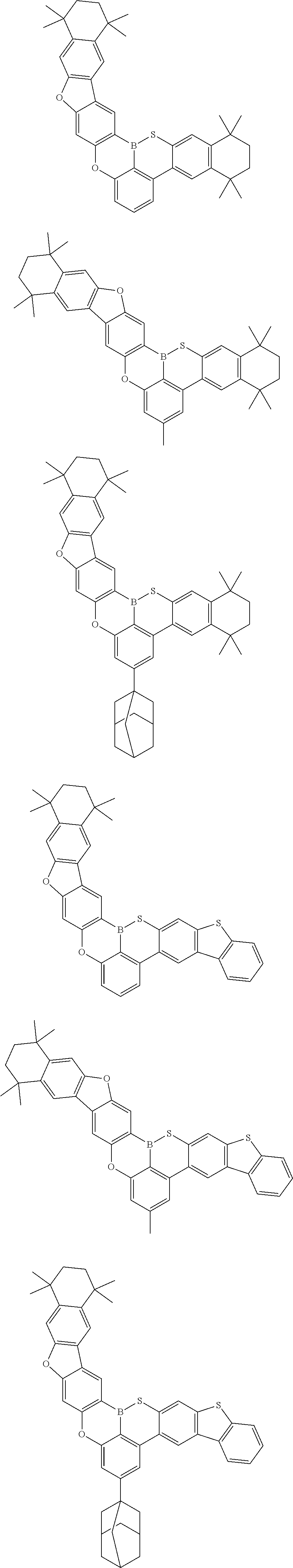

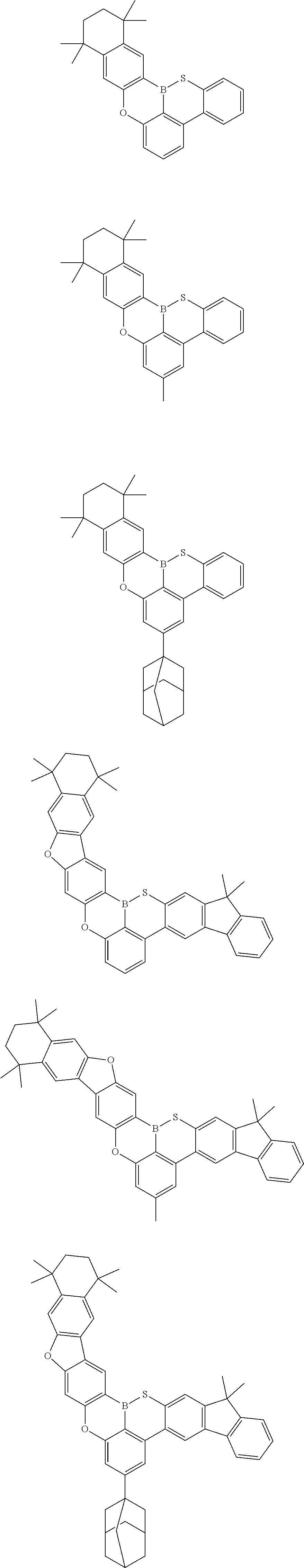 [SMILES: CC1(C)CCC(C)(C)c2cc3c(cc21)Oc1cccc2c1B3Sc1ccccc1-2 ; Cc1cc2c3c(c1)-c1ccccc1SB3c1cc3c(cc1O2)C(C)(C)CCC3(C)C ; CC1(C)CCC(C)(C)c2cc3c(cc21)Oc1cc(C24CC5CC(CC(C5)C2)C4)cc2c1B3Sc1ccccc1-2 ; CC1(C)CCC(C)(C)c2cc3c(cc21)oc1cc2c(cc13)B1Sc3cc4c(cc3-c3cccc(c31)O2)-c1ccccc1C4(C)C ; Cc1cc2c3c(c1)-c1cc4c(cc1SB3c1cc3oc5cc6c(cc5c3cc1O2)C(C)(C)CCC6(C)C)C(C)(C)c1ccccc1-4 ; CC1(C)CCC(C)(C)c2cc3c(cc21)oc1cc2c(cc13)B1Sc3cc4c(cc3-c3cc(C56CC7CC(CC(C7)C5)C6)cc(c31)O2)-c1ccccc1C4(C)C]

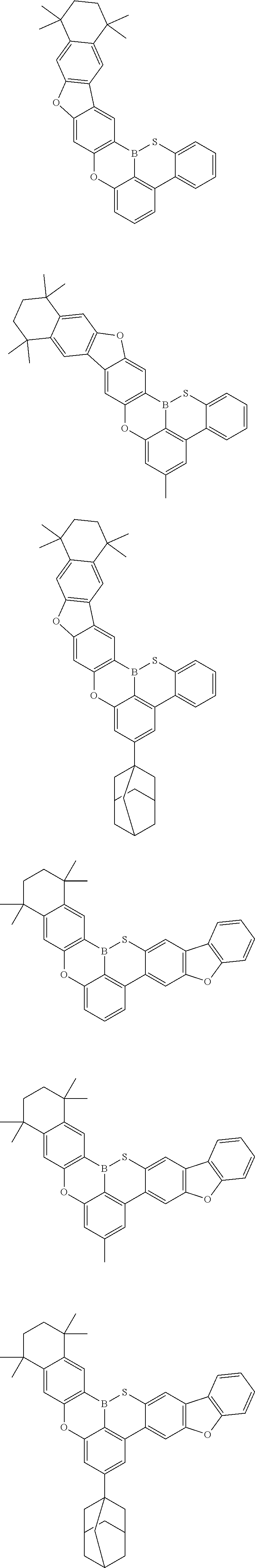 [SMILES: CC1(C)CCC(C)(C)c2cc3c(cc21)oc1cc2c(cc13)B1Sc3ccccc3-c3cccc(c31)O2 ; Cc1cc2c3c(c1)-c1ccccc1SB3c1cc3oc4cc5c(cc4c3cc1O2)C(C)(C)CCC5(C)C ; CC1(C)CCC(C)(C)c2cc3c(cc21)oc1cc2c(cc13)B1Sc3ccccc3-c3cc(C45CC6CC(CC(C6)C4)C5)cc(c31)O2 ; CC1(C)CCC(C)(C)c2cc3c(cc21)Oc1cccc2c1B3Sc1cc3c(cc1-2)oc1ccccc13 ; Cc1cc2c3c(c1)-c1cc4oc5ccccc5c4cc1SB3c1cc3c(cc1O2)C(C)(C)CCC3(C)C ; CC1(C)CCC(C)(C)c2cc3c(cc21)Oc1cc(C24CC5CC(CC(C5)C2)C4)cc2c1B3Sc1cc3c(cc1-2)oc1ccccc13]

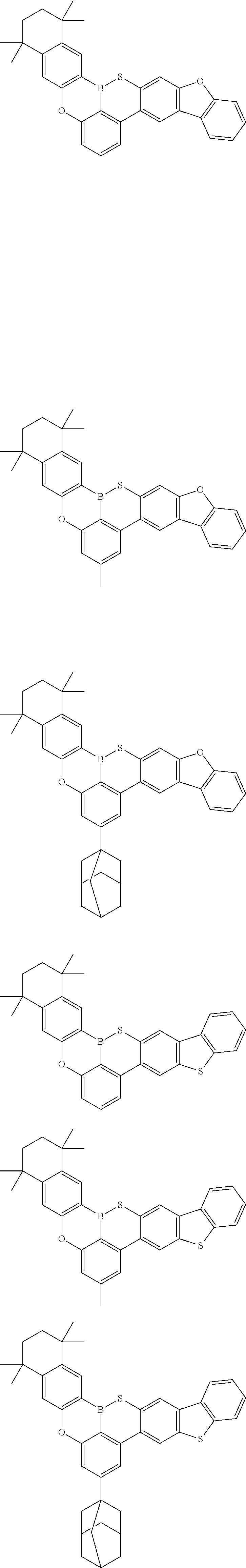 [SMILES: CC1(C)CCC(C)(C)c2cc3c(cc21)Oc1cccc2c1B3Sc1cc3oc4ccccc4c3cc1-2 ; Cc1cc2c3c(c1)-c1cc4c(cc1SB3c1cc3c(cc1O2)C(C)(C)CCC3(C)C)oc1ccccc14 ; CC1(C)CCC(C)(C)c2cc3c(cc21)Oc1cc(C24CC5CC(CC(C5)C2)C4)cc2c1B3Sc1cc3oc4ccccc4c3cc1-2 ; CC1(C)CCC(C)(C)c2cc3c(cc21)Oc1cccc2c1B3Sc1cc3c(cc1-2)sc1ccccc13 ; Cc1cc2c3c(c1)-c1cc4sc5ccccc5c4cc1SB3c1cc3c(cc1O2)C(C)(C)CCC3(C)C ; CC1(C)CCC(C)(C)c2cc3c(cc21)Oc1cc(C24CC5CC(CC(C5)C2)C4)cc2c1B3Sc1cc3c(cc1-2)sc1ccccc13]

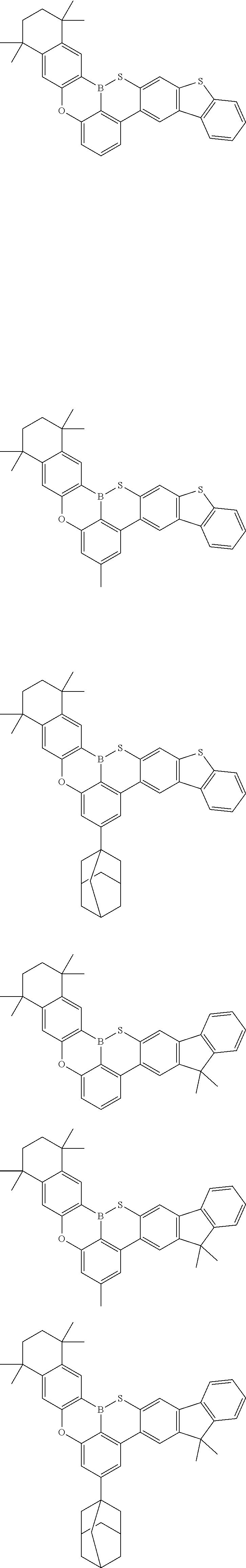 [SMILES: CC1(C)CCC(C)(C)c2cc3c(cc21)Oc1cccc2c1B3Sc1cc3sc4ccccc4c3cc1-2 ; Cc1cc2c3c(c1)-c1cc4c(cc1SB3c1cc3c(cc1O2)C(C)(C)CCC3(C)C)sc1ccccc14 ; CC1(C)CCC(C)(C)c2cc3c(cc21)Oc1cc(C24CC5CC(CC(C5)C2)C4)cc2c1B3Sc1cc3sc4ccccc4c3cc1-2 ; CC1(C)CCC(C)(C)c2cc3c(cc21)Oc1cccc2c1B3Sc1cc3c(cc1-2)C(C)(C)c1ccccc1-3 ; Cc1cc2c3c(c1)-c1cc4c(cc1SB3c1cc3c(cc1O2)C(C)(C)CCC3(C)C)-c1ccccc1C4(C)C ; CC1(C)CCC(C)(C)c2cc3c(cc21)Oc1cc(C24CC5CC(CC(C5)C2)C4)cc2c1B3Sc1cc3c(cc1-2)C(C)(C)c1ccccc1-3]

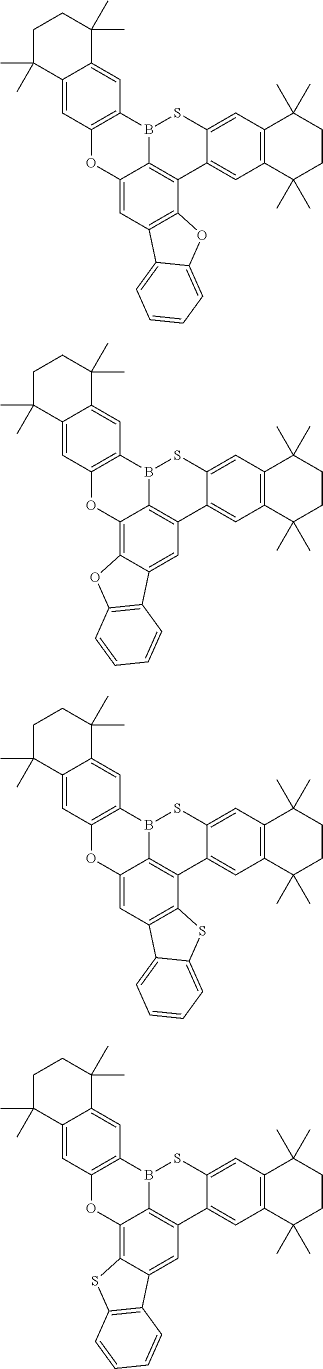

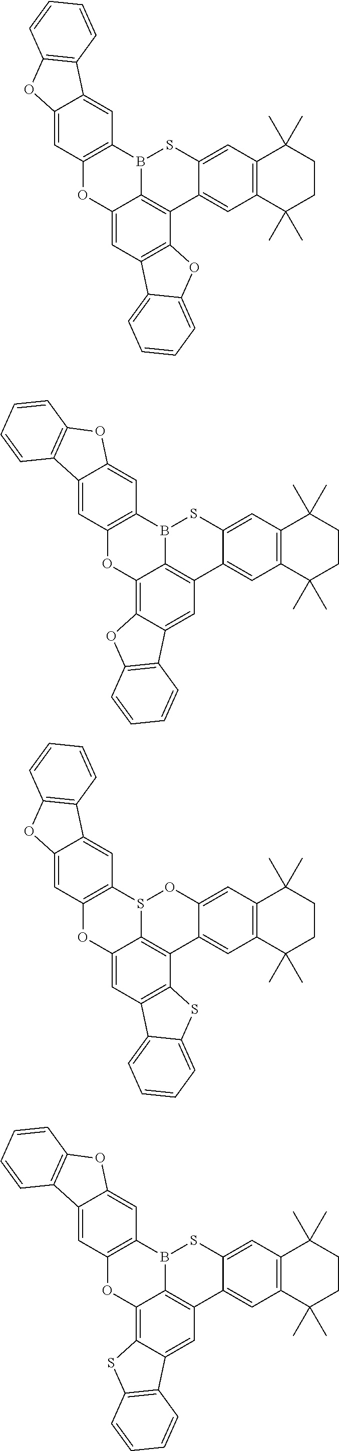

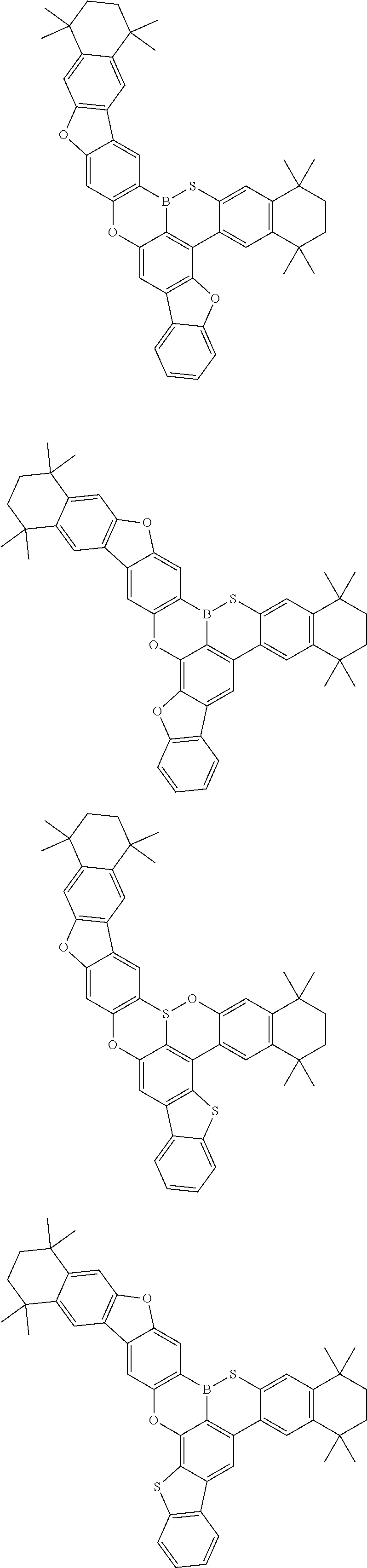

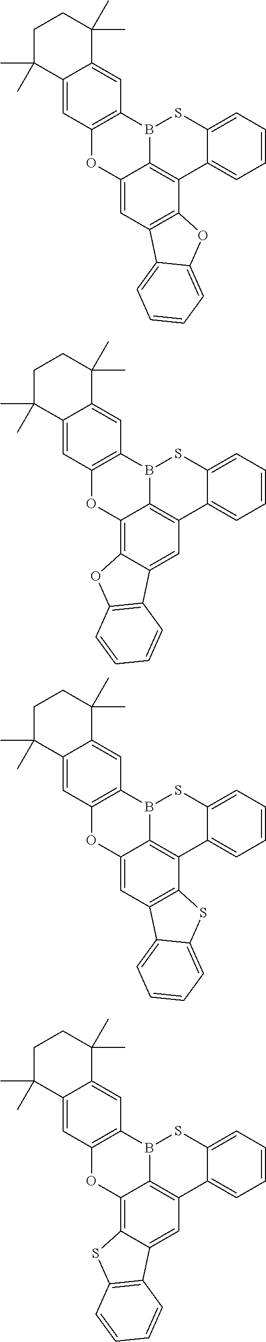

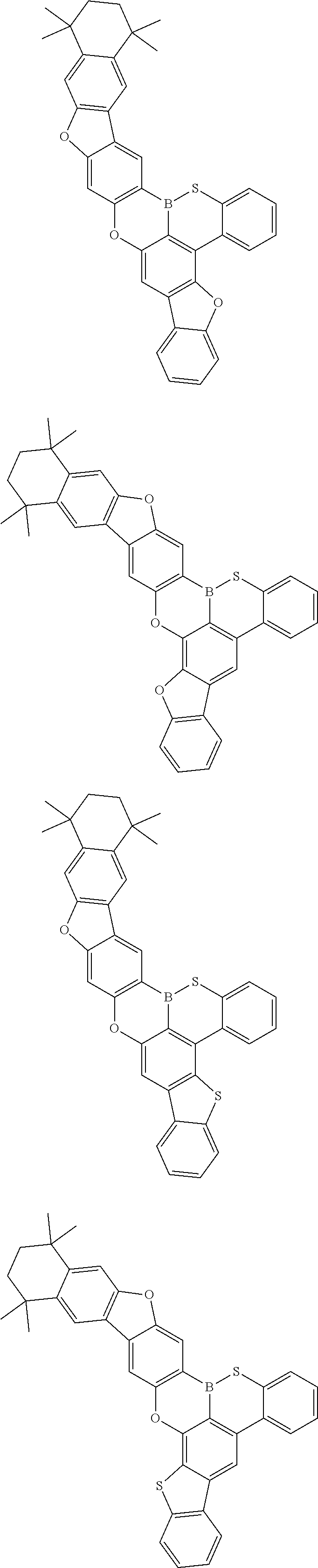 [SMILES: CC1(C)CCC(C)(C)c2cc3c(cc21)oc1cc2c(cc13)B1Sc3ccccc3-c3c1c(cc1c3oc3ccccc31)O2 ; CC1(C)CCC(C)(C)c2cc3c(cc21)oc1cc2c(cc13)Oc1c3c(cc4c1oc1ccccc14)-c1ccccc1SB23 ; CC1(C)CCC(C)(C)c2cc3c(cc21)oc1cc2c(cc13)B1Sc3ccccc3-c3c1c(cc1c3sc3ccccc31)O2 ; CC1(C)CCC(C)(C)c2cc3c(cc21)oc1cc2c(cc13)Oc1c3c(cc4c1sc1ccccc14)-c1ccccc1SB23]

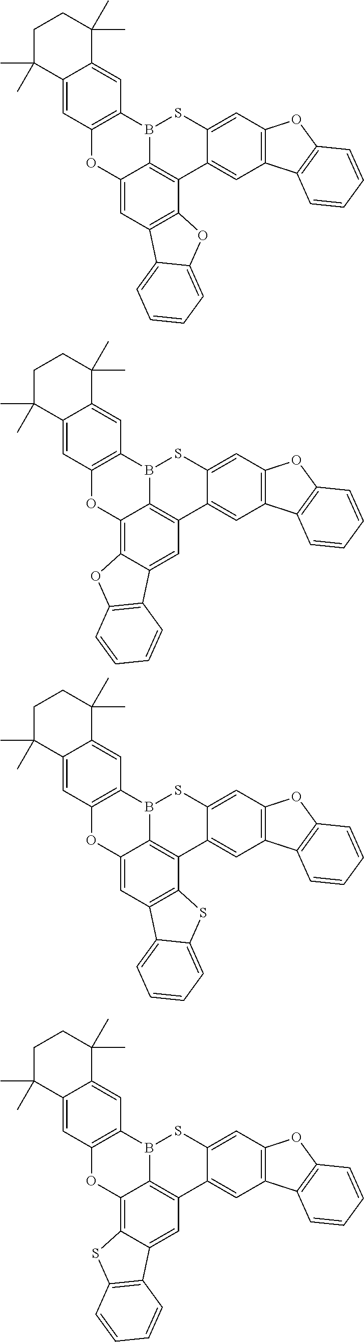

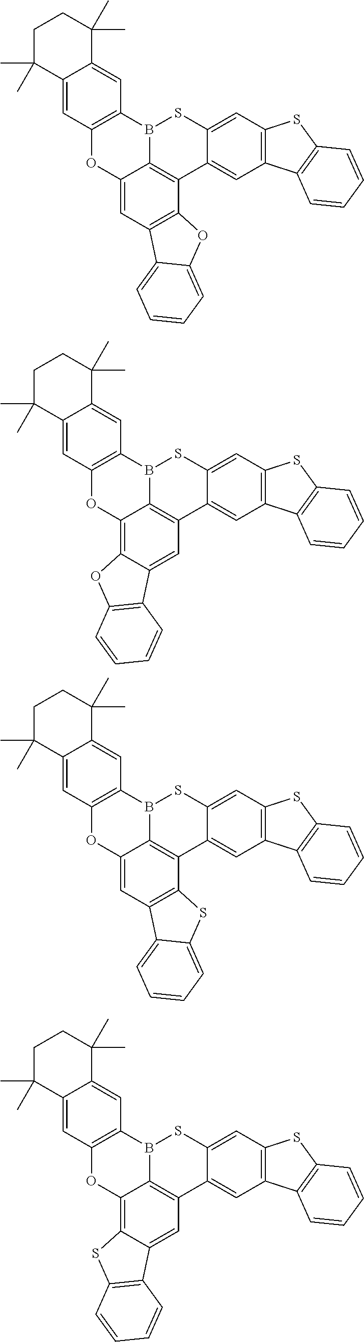

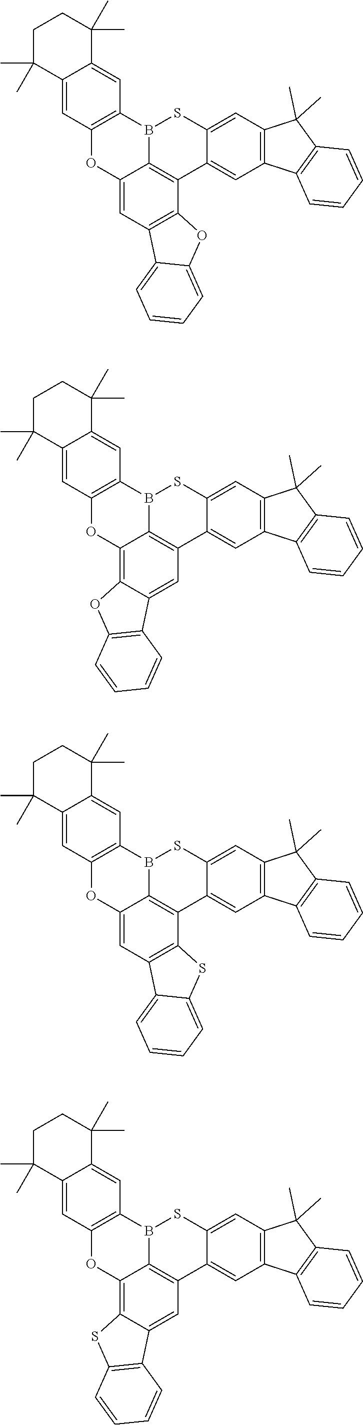

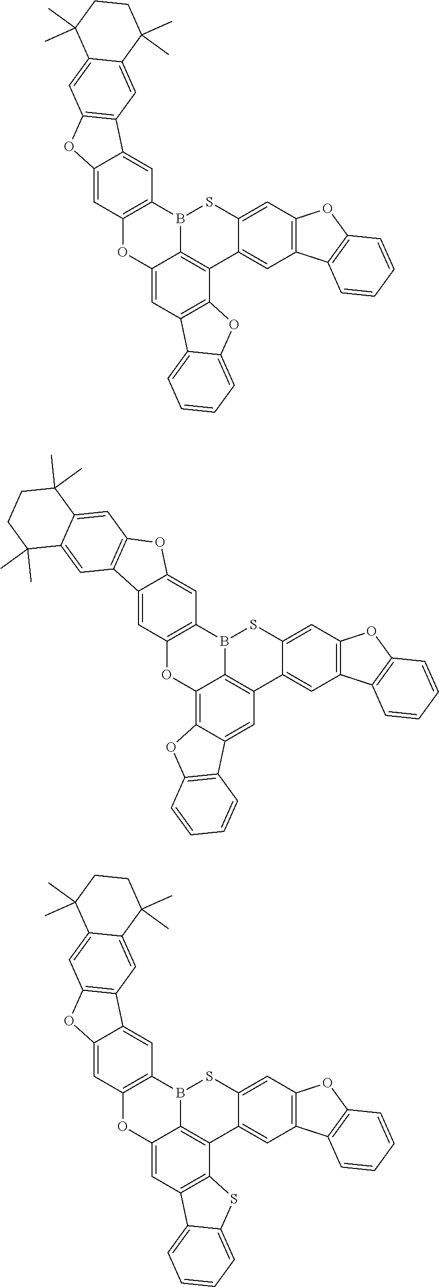 [SMILES: CC1(C)CCC(C)(C)c2cc3c(cc21)oc1cc2c(cc13)B1Sc3cc4oc5ccccc5c4cc3-c3c1c(cc1c3oc3ccccc31)O2 ; CC1(C)CCC(C)(C)c2cc3c(cc21)oc1cc2c(cc13)Oc1c3c(cc4c1oc1ccccc14)-c1cc4c(cc1SB23)oc1ccccc14 ; CC1(C)CCC(C)(C)c2cc3c(cc21)oc1cc2c(cc13)B1Sc3cc4oc5ccccc5c4cc3-c3c1c(cc1c3sc3ccccc31)O2]

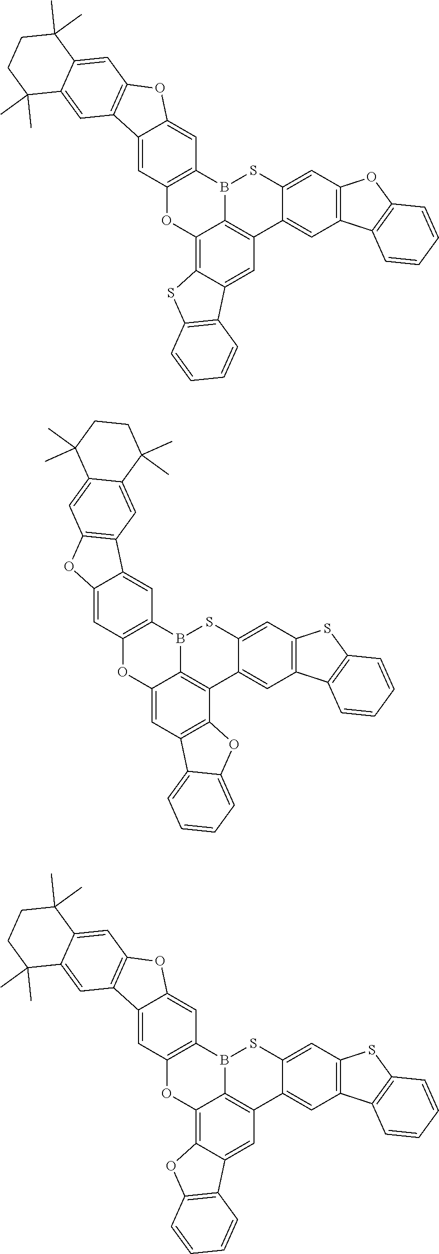 [SMILES: CC1(C)CCC(C)(C)c2cc3c(cc21)oc1cc2c(cc13)Oc1c3c(cc4c1sc1ccccc14)-c1cc4c(cc1SB23)oc1ccccc14 ; CC1(C)CCC(C)(C)c2cc3c(cc21)oc1cc2c(cc13)B1Sc3cc4sc5ccccc5c4cc3-c3c1c(cc1c3oc3ccccc31)O2 ; CC1(C)CCC(C)(C)c2cc3c(cc21)oc1cc2c(cc13)Oc1c3c(cc4c1oc1ccccc14)-c1cc4c(cc1SB23)sc1ccccc14]

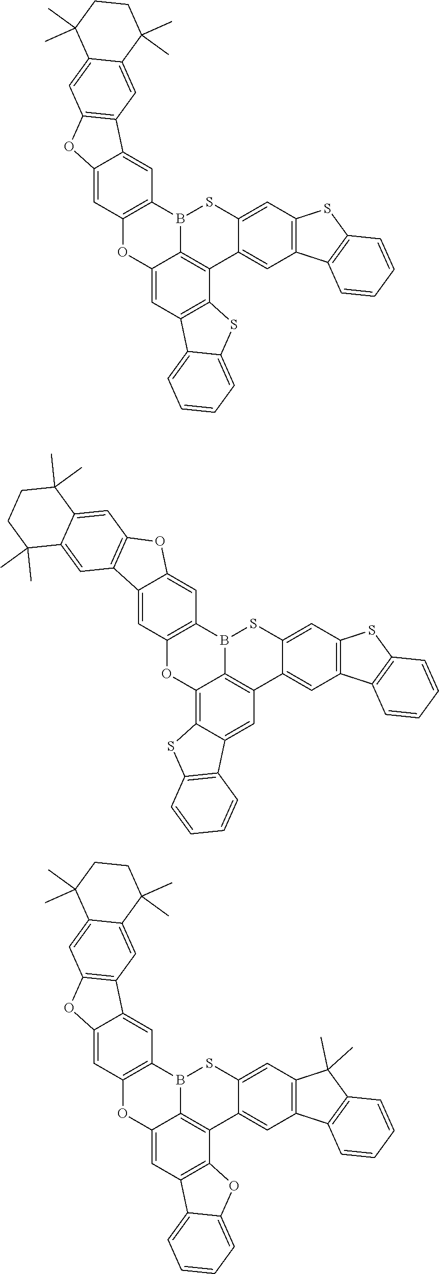 [SMILES: CC1(C)CCC(C)(C)c2cc3c(cc21)oc1cc2c(cc13)B1Sc3cc4sc5ccccc5c4cc3-c3c1c(cc1c3sc3ccccc31)O2 ; CC1(C)CCC(C)(C)c2cc3c(cc21)oc1cc2c(cc13)Oc1c3c(cc4c1sc1ccccc14)-c1cc4c(cc1SB23)sc1ccccc14 ; CC1(C)CCC(C)(C)c2cc3c(cc21)oc1cc2c(cc13)B1Sc3cc4c(cc3-c3c1c(cc1c3oc3ccccc31)O2)-c1ccccc1C4(C)C]

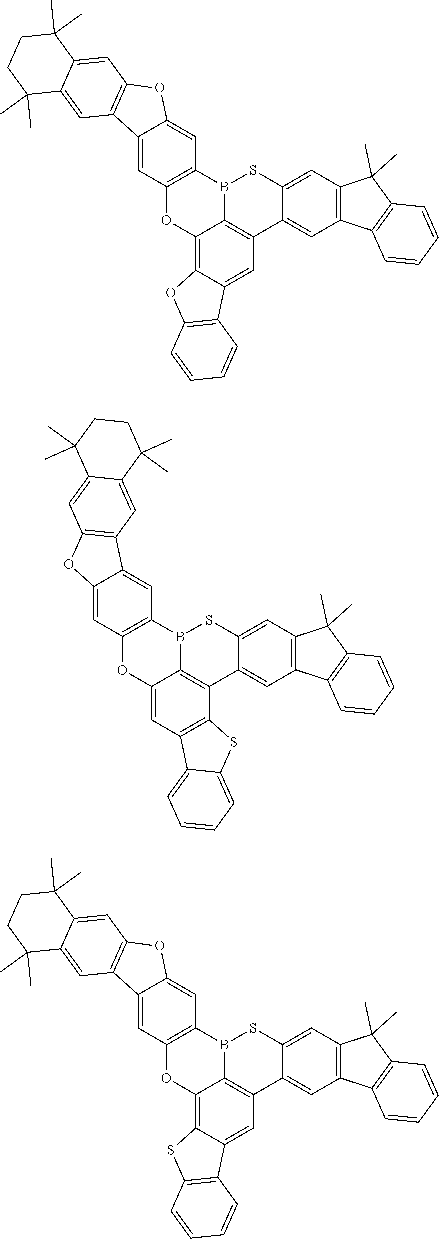 [SMILES: CC1(C)CCC(C)(C)c2cc3c(cc21)oc1cc2c(cc13)Oc1c3c(cc4c1oc1ccccc14)-c1cc4c(cc1SB23)C(C)(C)c1ccccc1-4 ; CC1(C)CCC(C)(C)c2cc3c(cc21)oc1cc2c(cc13)B1Sc3cc4c(cc3-c3c1c(cc1c3sc3ccccc31)O2)-c1ccccc1C4(C)C ; CC1(C)CCC(C)(C)c2cc3c(cc21)oc1cc2c(cc13)Oc1c3c(cc4c1sc1ccccc14)-c1cc4c(cc1SB23)C(C)(C)c1ccccc1-4]

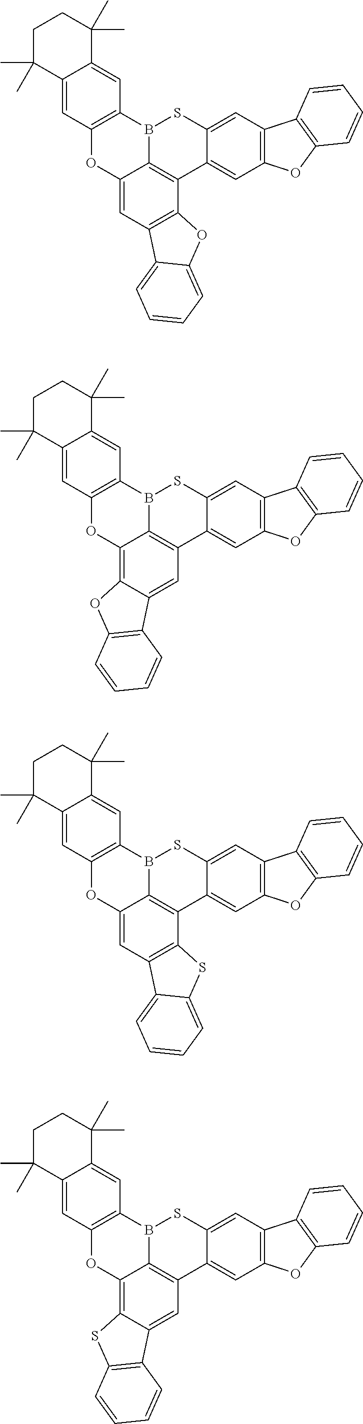

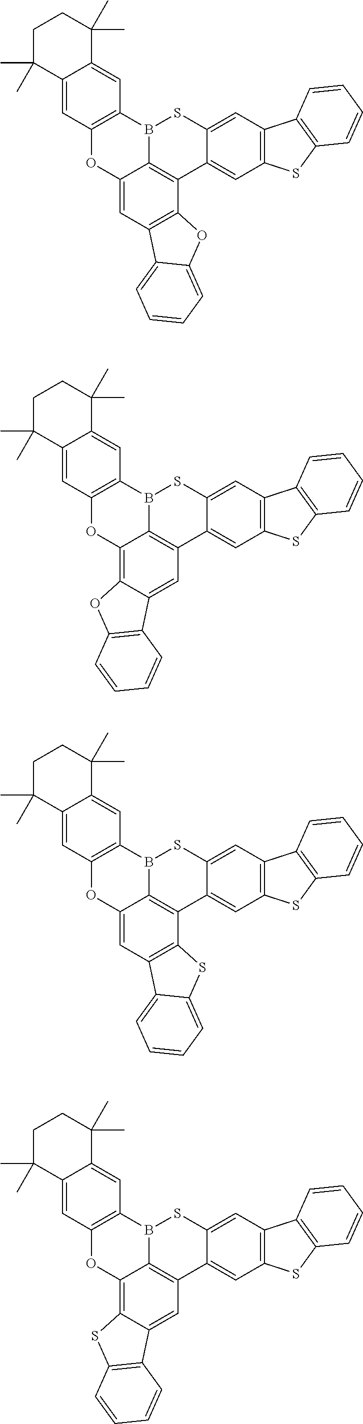

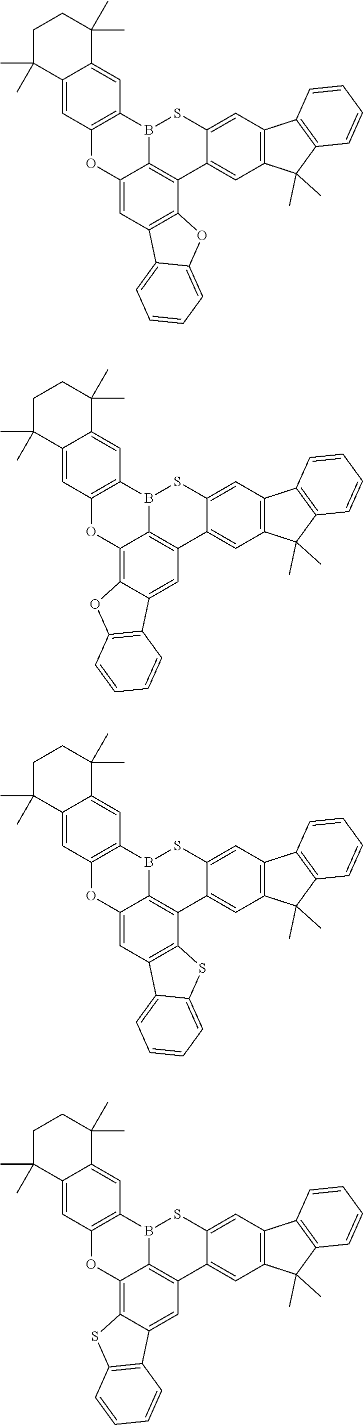

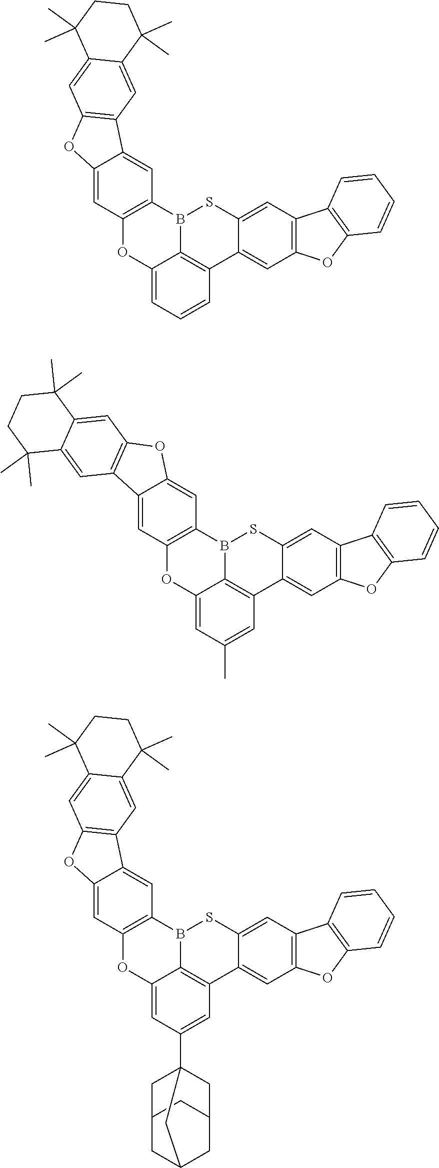 [SMILES: CC1(C)CCC(C)(C)c2cc3c(cc21)oc1cc2c(cc13)B1Sc3cc4c(cc3-c3cccc(c31)O2)oc1ccccc14 ; Cc1cc2c3c(c1)-c1cc4oc5ccccc5c4cc1SB3c1cc3oc4cc5c(cc4c3cc1O2)C(C)(C)CCC5(C)C ; CC1(C)CCC(C)(C)c2cc3c(cc21)oc1cc2c(cc13)B1Sc3cc4c(cc3-c3cc(C56CC7CC(CC(C7)C5)C6)cc(c31)O2)oc1ccccc14]

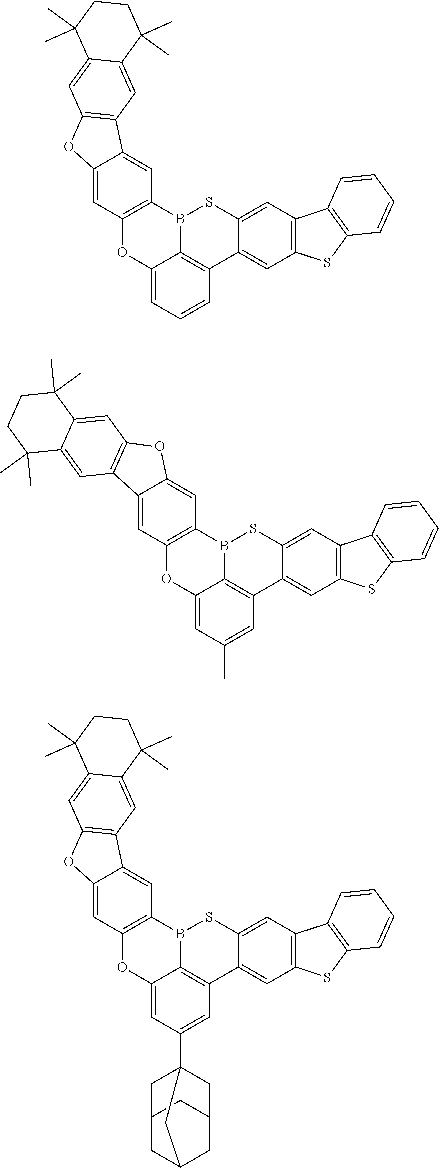 [SMILES: CC1(C)CCC(C)(C)c2cc3c(cc21)oc1cc2c(cc13)B1Sc3cc4c(cc3-c3cccc(c31)O2)sc1ccccc14 ; Cc1cc2c3c(c1)-c1cc4sc5ccccc5c4cc1SB3c1cc3oc4cc5c(cc4c3cc1O2)C(C)(C)CCC5(C)C ; CC1(C)CCC(C)(C)c2cc3c(cc21)oc1cc2c(cc13)B1Sc3cc4c(cc3-c3cc(C56CC7CC(CC(C7)C5)C6)cc(c31)O2)sc1ccccc14]

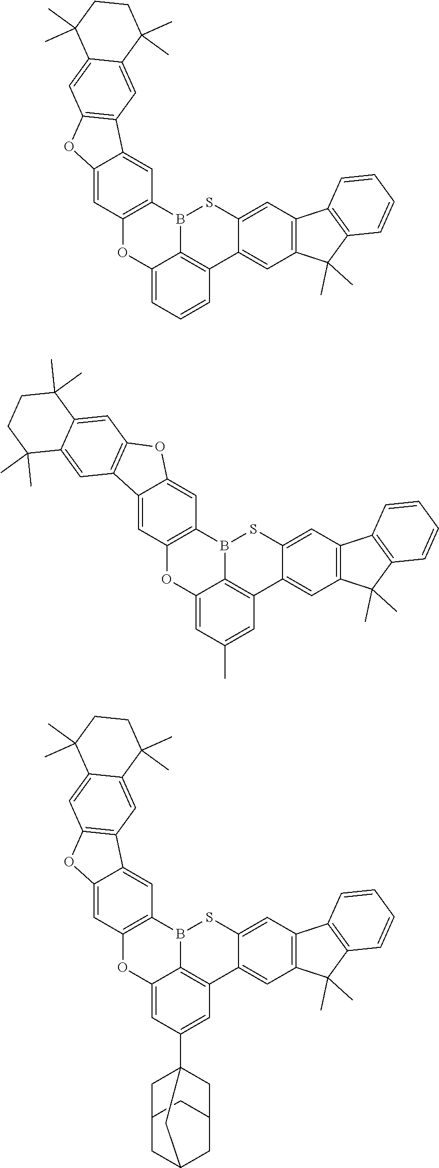 [SMILES: CC1(C)CCC(C)(C)c2cc3c(cc21)oc1cc2c(cc13)B1Sc3cc4c(cc3-c3cccc(c31)O2)C(C)(C)c1ccccc1-4 ; Cc1cc2c3c(c1)-c1cc4c(cc1SB3c1cc3oc5cc6c(cc5c3cc1O2)C(C)(C)CCC6(C)C)-c1ccccc1C4(C)C ; CC1(C)CCC(C)(C)c2cc3c(cc21)oc1cc2c(cc13)B1Sc3cc4c(cc3-c3cc(C56CC7CC(CC(C7)C5)C6)cc(c31)O2)C(C)(C)c1ccccc1-4]

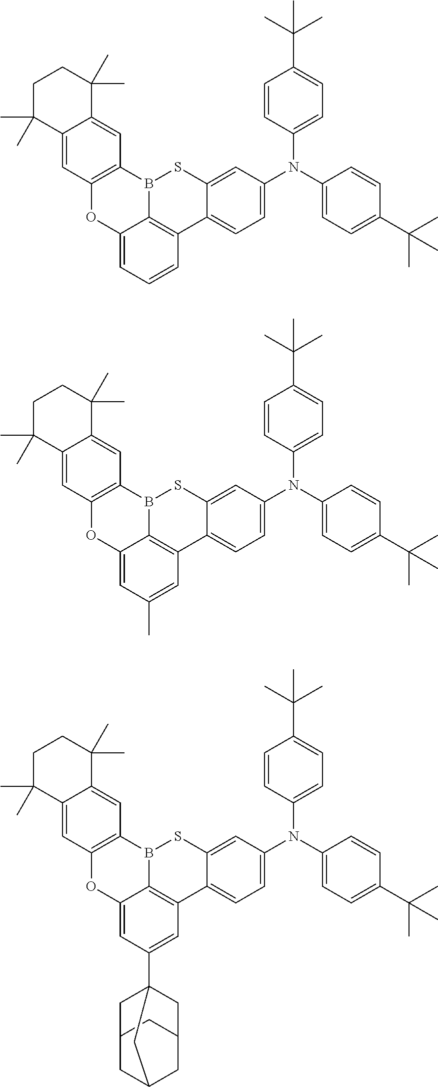

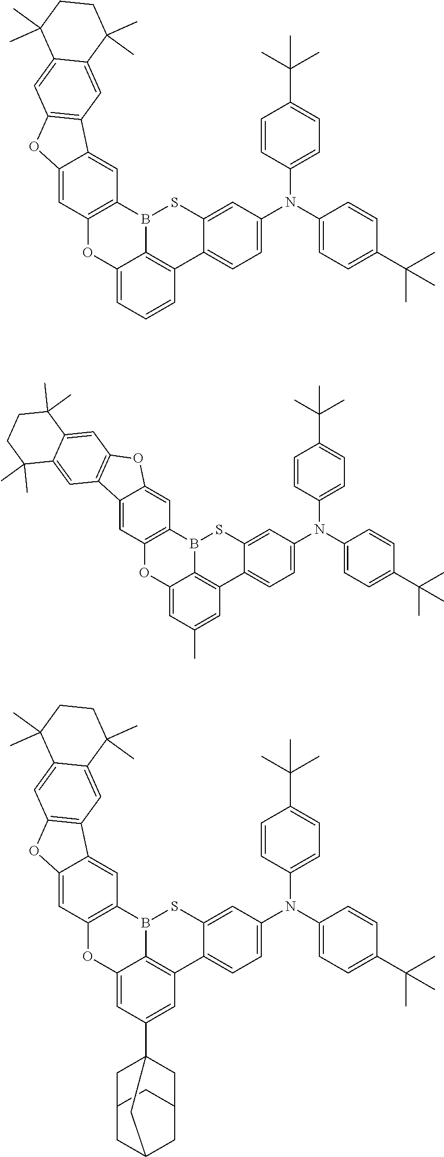

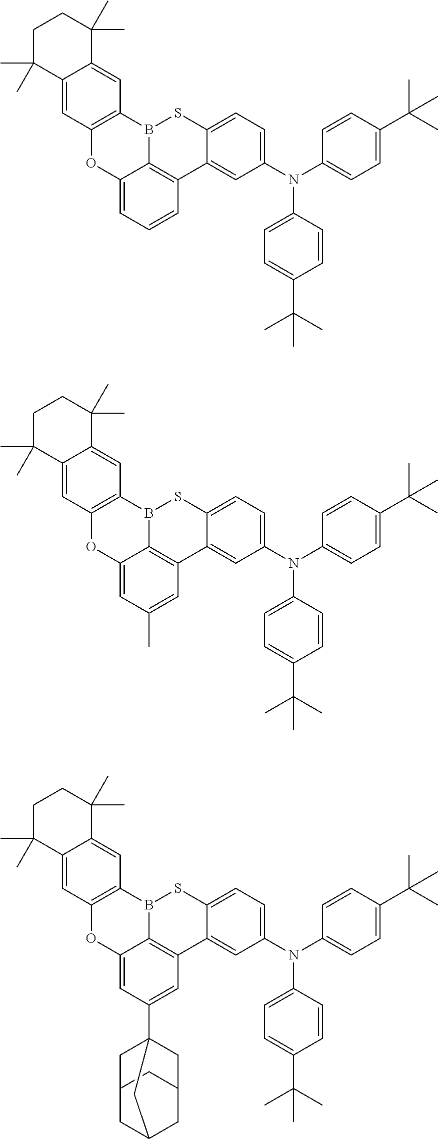

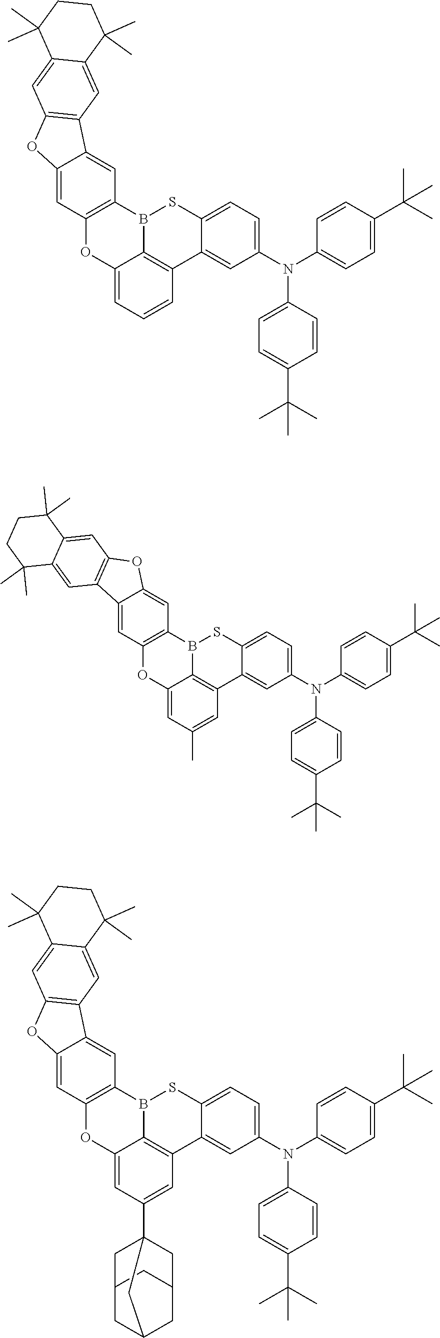

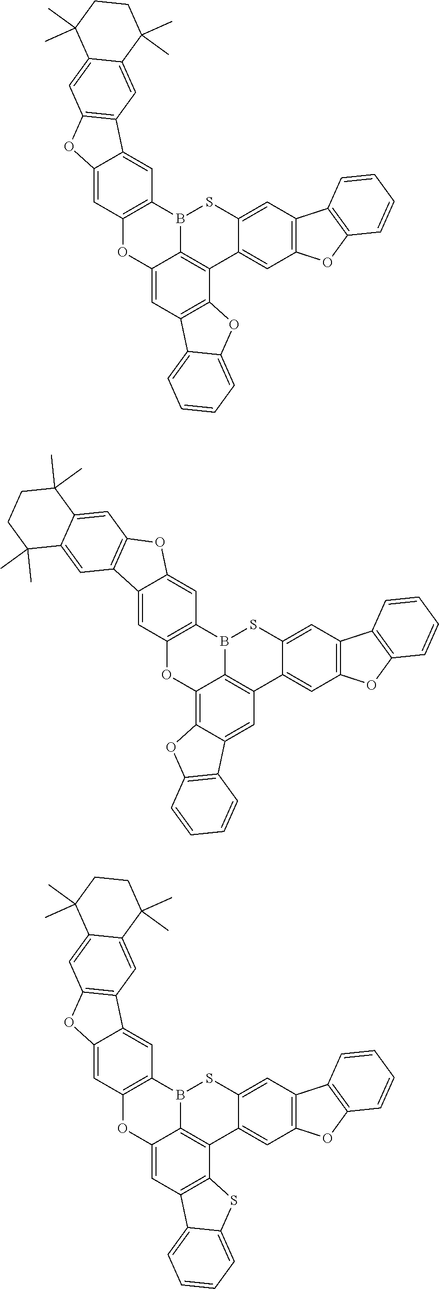 [SMILES: CC1(C)CCC(C)(C)c2cc3c(cc21)oc1cc2c(cc13)B1Sc3cc4c(cc3-c3c1c(cc1c3oc3ccccc31)O2)oc1ccccc14 ; CC1(C)CCC(C)(C)c2cc3c(cc21)oc1cc2c(cc13)Oc1c3c(cc4c1oc1ccccc14)-c1cc4oc5ccccc5c4cc1SB23 ; CC1(C)CCC(C)(C)c2cc3c(cc21)oc1cc2c(cc13)B1Sc3cc4c(cc3-c3c1c(cc1c3sc3ccccc31)O2)oc1ccccc14]

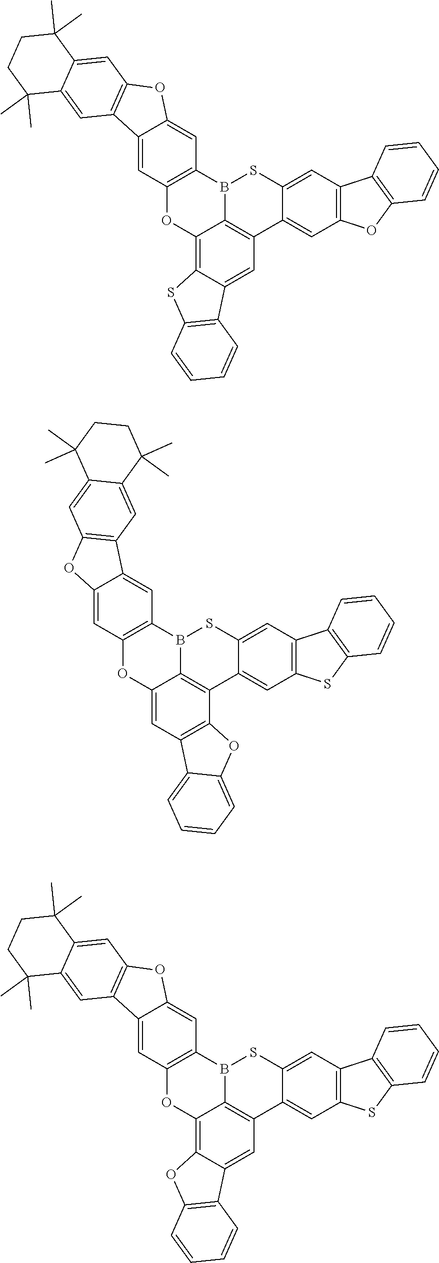 [SMILES: CC1(C)CCC(C)(C)c2cc3c(cc21)oc1cc2c(cc13)Oc1c3c(cc4c1sc1ccccc14)-c1cc4oc5ccccc5c4cc1SB23 ; CC1(C)CCC(C)(C)c2cc3c(cc21)oc1cc2c(cc13)B1Sc3cc4c(cc3-c3c1c(cc1c3oc3ccccc31)O2)sc1ccccc14 ; CC1(C)CCC(C)(C)c2cc3c(cc21)oc1cc2c(cc13)Oc1c3c(cc4c1oc1ccccc14)-c1cc4sc5ccccc5c4cc1SB23]

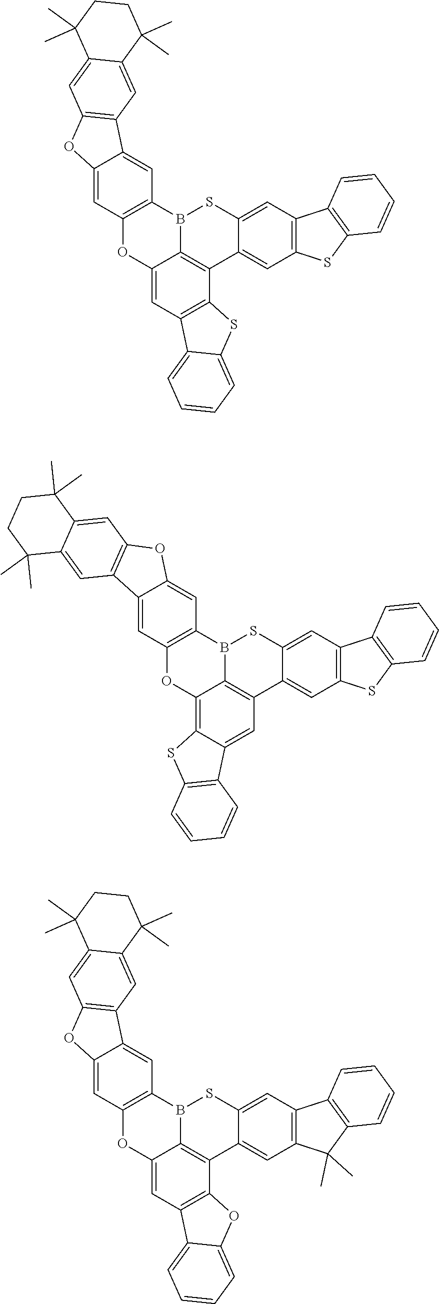 [SMILES: CC1(C)CCC(C)(C)c2cc3c(cc21)oc1cc2c(cc13)B1Sc3cc4c(cc3-c3c1c(cc1c3sc3ccccc31)O2)sc1ccccc14 ; CC1(C)CCC(C)(C)c2cc3c(cc21)oc1cc2c(cc13)Oc1c3c(cc4c1sc1ccccc14)-c1cc4sc5ccccc5c4cc1SB23 ; CC1(C)CCC(C)(C)c2cc3c(cc21)oc1cc2c(cc13)B1Sc3cc4c(cc3-c3c1c(cc1c3oc3ccccc31)O2)C(C)(C)c1ccccc1-4]

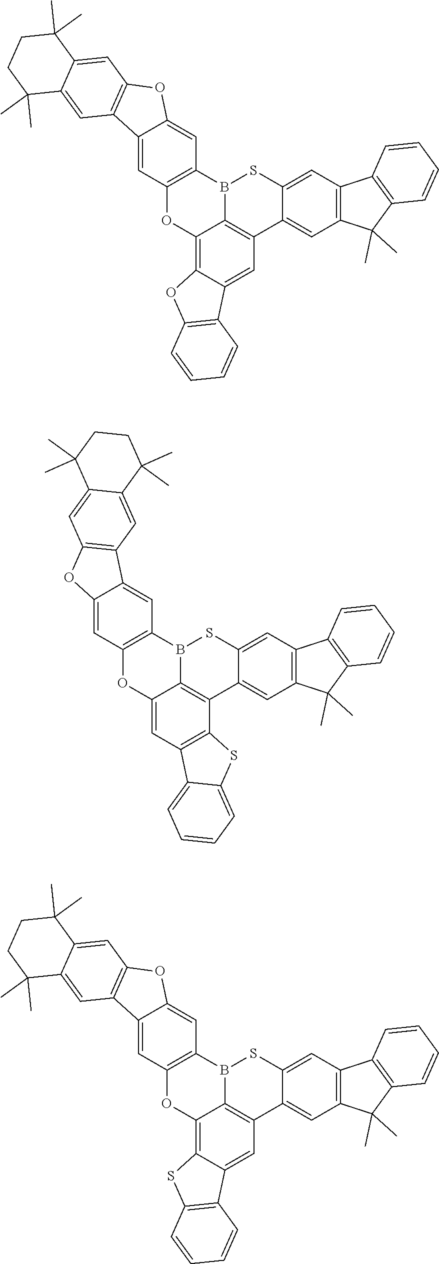 [SMILES: CC1(C)CCC(C)(C)c2cc3c(cc21)oc1cc2c(cc13)Oc1c3c(cc4c1oc1ccccc14)-c1cc4c(cc1SB23)-c1ccccc1C4(C)C ; CC1(C)CCC(C)(C)c2cc3c(cc21)oc1cc2c(cc13)B1Sc3cc4c(cc3-c3c1c(cc1c3sc3ccccc31)O2)C(C)(C)c1ccccc1-4 ; CC1(C)CCC(C)(C)c2cc3c(cc21)oc1cc2c(cc13)Oc1c3c(cc4c1sc1ccccc14)-c1cc4c(cc1SB23)-c1ccccc1C4(C)C]

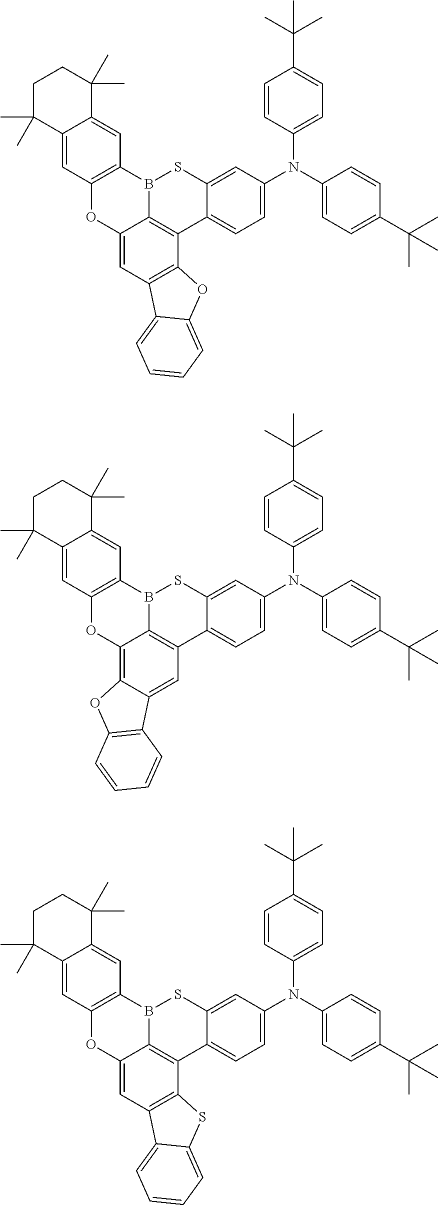

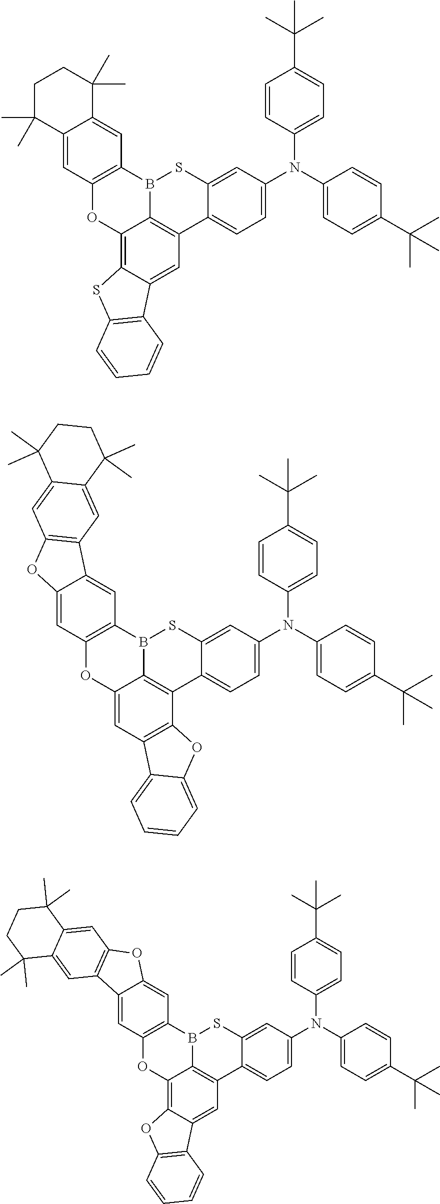

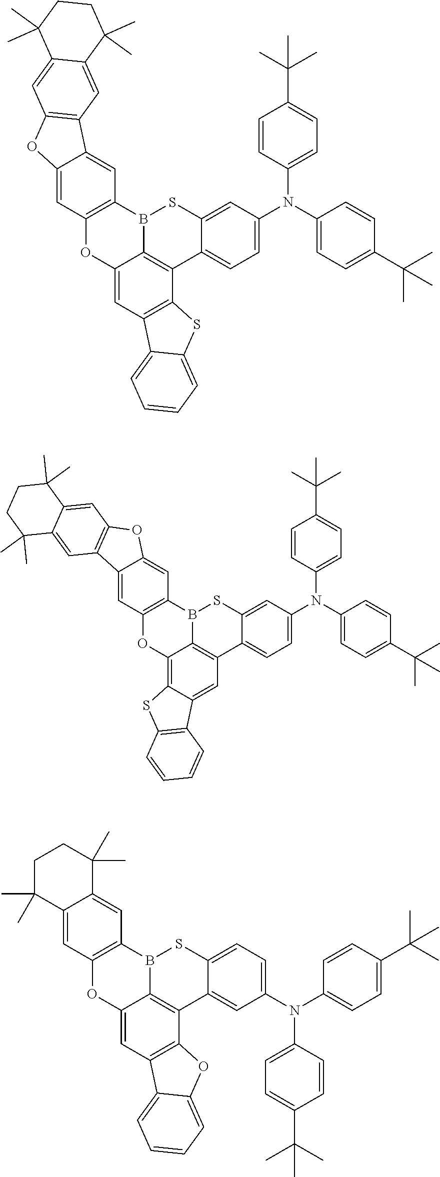

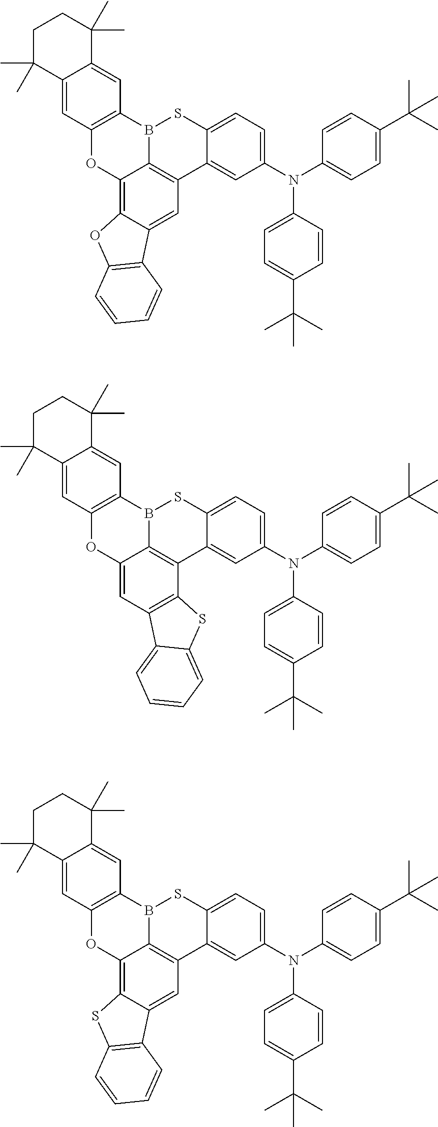

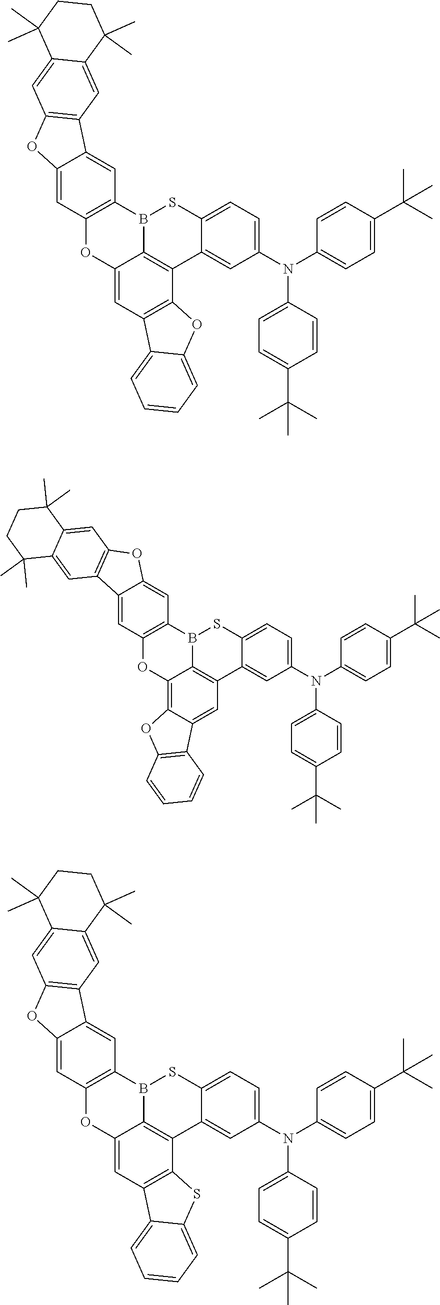

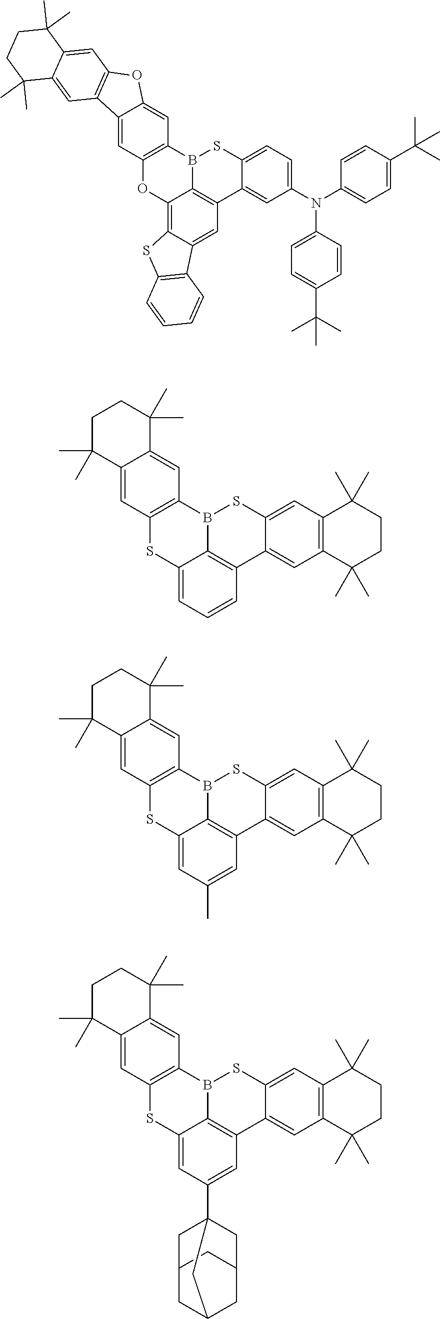

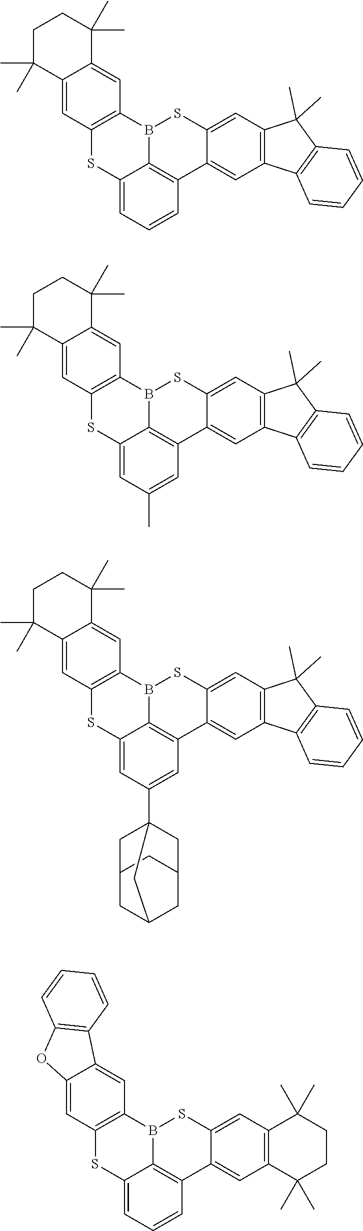 [SMILES: CC1(C)CCC(C)(C)c2cc3c(cc21)Sc1cccc2c1B3Sc1cc3c(cc1-2)-c1ccccc1C3(C)C ; Cc1cc2c3c(c1)-c1cc4c(cc1SB3c1cc3c(cc1S2)C(C)(C)CCC3(C)C)C(C)(C)c1ccccc1-4 ; CC1(C)CCC(C)(C)c2cc3c(cc21)Sc1cc(C24CC5CC(CC(C5)C2)C4)cc2c1B3Sc1cc3c(cc1-2)-c1ccccc1C3(C)C ; CC1(C)CCC(C)(C)c2cc3c(cc21)SB1c2cc4c(cc2Sc2cccc-3c21)oc1ccccc14]

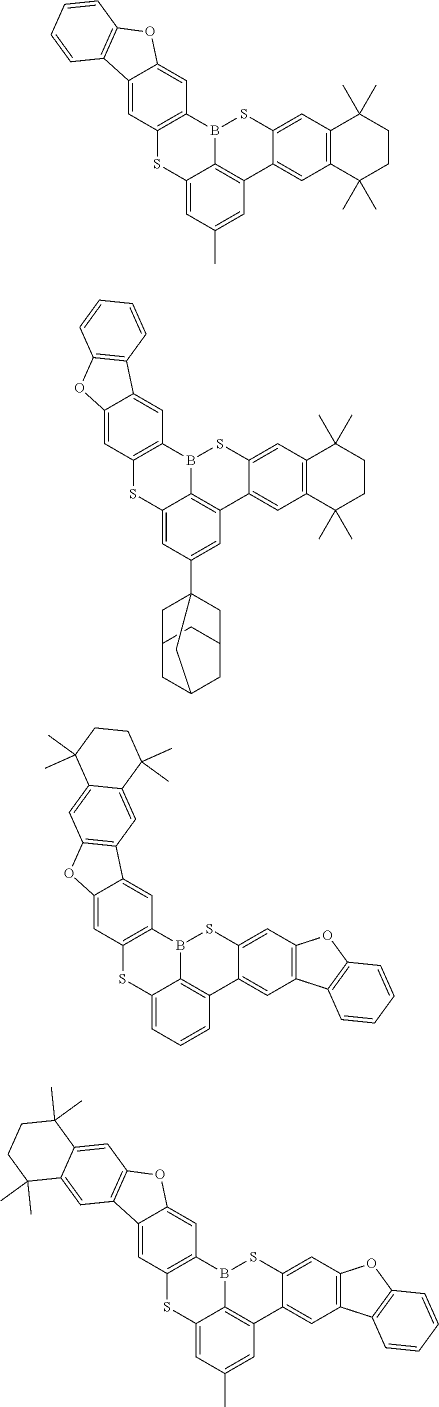 [SMILES: Cc1cc2c3c(c1)-c1cc4c(cc1SB3c1cc3oc5ccccc5c3cc1S2)C(C)(C)CCC4(C)C ; CC1(C)CCC(C)(C)c2cc3c(cc21)SB1c2cc4c(cc2Sc2cc(C56CC7CC(CC(C7)C5)C6)cc-3c21)oc1ccccc14 ; CC1(C)CCC(C)(C)c2cc3c(cc21)oc1cc2c(cc13)B1Sc3cc4oc5ccccc5c4cc3-c3cccc(c31)S2 ; Cc1cc2c3c(c1)-c1cc4c(cc1SB3c1cc3oc5cc6c(cc5c3cc1S2)C(C)(C)CCC6(C)C)oc1ccccc14]

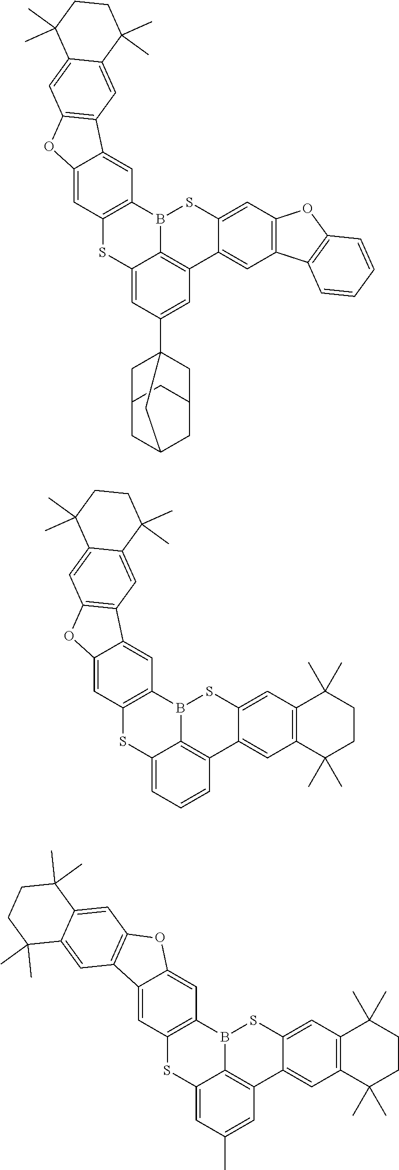 [SMILES: CC1(C)CCC(C)(C)c2cc3c(cc21)oc1cc2c(cc13)B1Sc3cc4oc5ccccc5c4cc3-c3cc(C45CC6CC(CC(C6)C4)C5)cc(c31)S2 ; CC1(C)CCC(C)(C)c2cc3c(cc21)SB1c2cc4c(cc2Sc2cccc-3c21)oc1cc2c(cc14)C(C)(C)CCC2(C)C ; Cc1cc2c3c(c1)-c1cc4c(cc1SB3c1cc3oc5cc6c(cc5c3cc1S2)C(C)(C)CCC6(C)C)C(C)(C)CCC4(C)C]

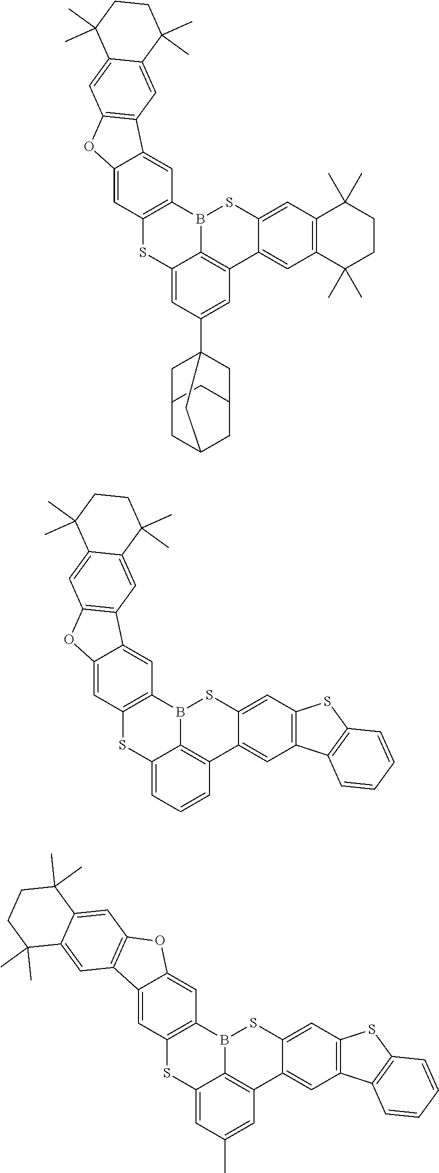 [SMILES: CC1(C)CCC(C)(C)c2cc3c(cc21)SB1c2cc4c(cc2Sc2cc(C56CC7CC(CC(C7)C5)C6)cc-3c21)oc1cc2c(cc14)C(C)(C)CCC2(C)C ; CC1(C)CCC(C)(C)c2cc3c(cc21)oc1cc2c(cc13)B1Sc3cc4sc5ccccc5c4cc3-c3cccc(c31)S2 ; Cc1cc2c3c(c1)-c1cc4c(cc1SB3c1cc3oc5cc6c(cc5c3cc1S2)C(C)(C)CCC6(C)C)sc1ccccc14]

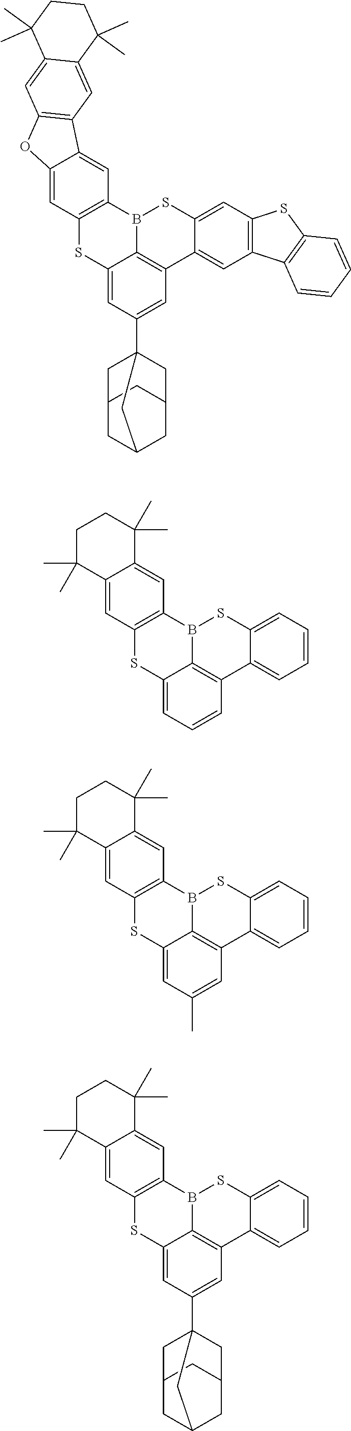 [SMILES: CC1(C)CCC(C)(C)c2cc3c(cc21)oc1cc2c(cc13)B1Sc3cc4sc5ccccc5c4cc3-c3cc(C45CC6CC(CC(C6)C4)C5)cc(c31)S2 ; CC1(C)CCC(C)(C)c2cc3c(cc21)Sc1cccc2c1B3Sc1ccccc1-2 ; Cc1cc2c3c(c1)-c1ccccc1SB3c1cc3c(cc1S2)C(C)(C)CCC3(C)C ; CC1(C)CCC(C)(C)c2cc3c(cc21)Sc1cc(C24CC5CC(CC(C5)C2)C4)cc2c1B3Sc1ccccc1-2]

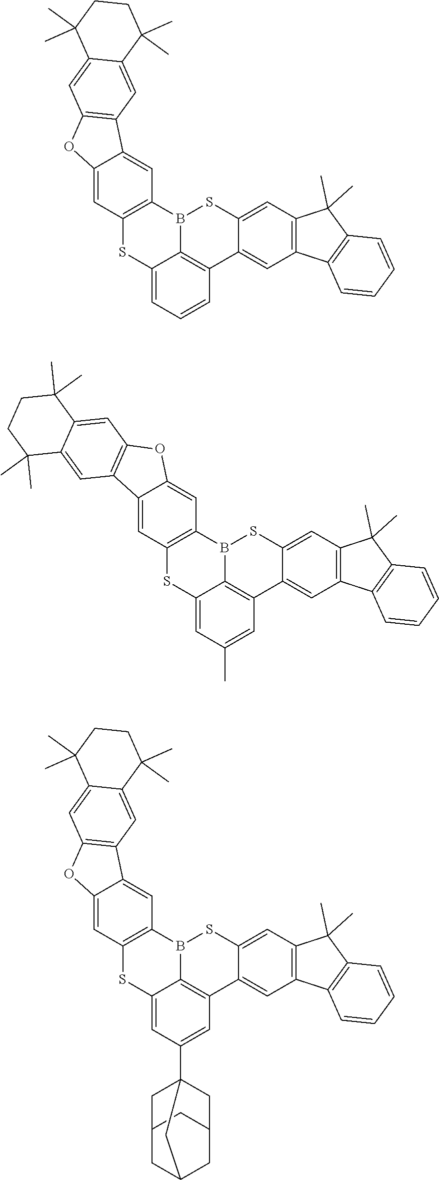 [SMILES: CC1(C)CCC(C)(C)c2cc3c(cc21)oc1cc2c(cc13)B1Sc3cc4c(cc3-c3cccc(c31)S2)-c1ccccc1C4(C)C ; Cc1cc2c3c(c1)-c1cc4c(cc1SB3c1cc3oc5cc6c(cc5c3cc1S2)C(C)(C)CCC6(C)C)C(C)(C)c1ccccc1-4 ; CC1(C)CCC(C)(C)c2cc3c(cc21)oc1cc2c(cc13)B1Sc3cc4c(cc3-c3cc(C56CC7CC(CC(C7)C5)C6)cc(c31)S2)-c1ccccc1C4(C)C]

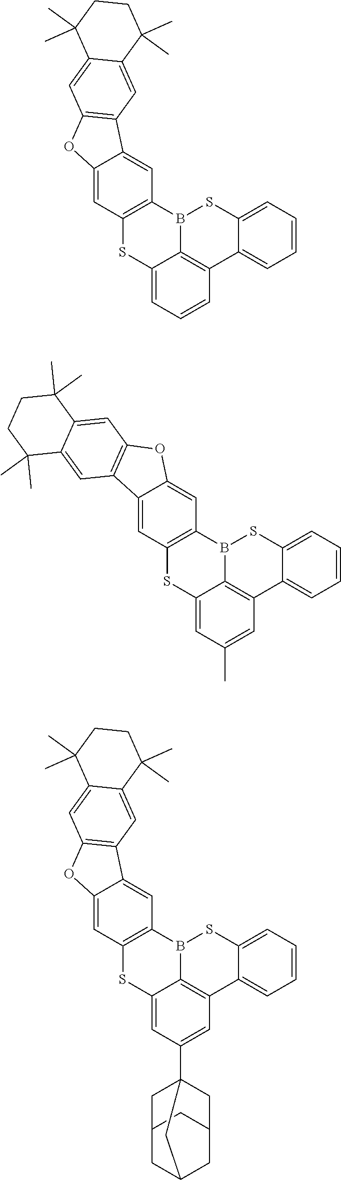 [SMILES: CC1(C)CCC(C)(C)c2cc3c(cc21)oc1cc2c(cc13)B1Sc3ccccc3-c3cccc(c31)S2 ; Cc1cc2c3c(c1)-c1ccccc1SB3c1cc3oc4cc5c(cc4c3cc1S2)C(C)(C)CCC5(C)C ; CC1(C)CCC(C)(C)c2cc3c(cc21)oc1cc2c(cc13)B1Sc3ccccc3-c3cc(C45CC6CC(CC(C6)C4)C5)cc(c31)S2]

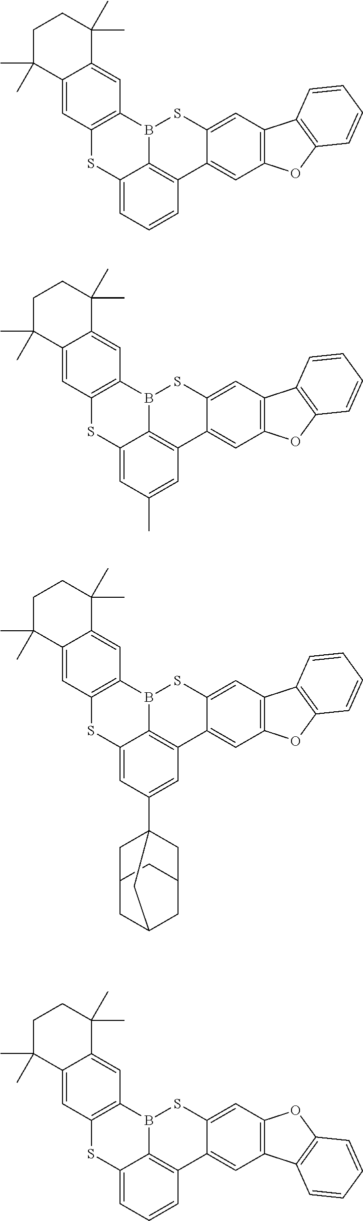 [SMILES: CC1(C)CCC(C)(C)c2cc3c(cc21)Sc1cccc2c1B3Sc1cc3c(cc1-2)oc1ccccc13 ; Cc1cc2c3c(c1)-c1cc4oc5ccccc5c4cc1SB3c1cc3c(cc1S2)C(C)(C)CCC3(C)C ; CC1(C)CCC(C)(C)c2cc3c(cc21)Sc1cc(C24CC5CC(CC(C5)C2)C4)cc2c1B3Sc1cc3c(cc1-2)oc1ccccc13 ; CC1(C)CCC(C)(C)c2cc3c(cc21)Sc1cccc2c1B3Sc1cc3oc4ccccc4c3cc1-2]

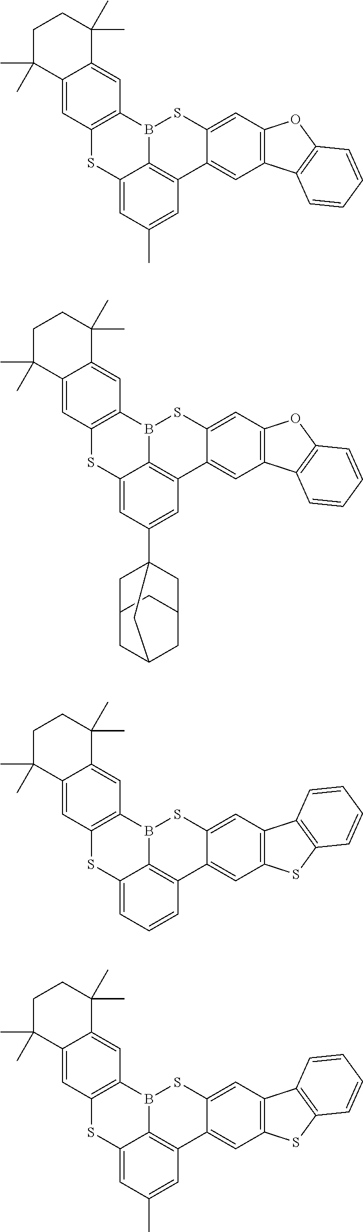 [SMILES: Cc1cc2c3c(c1)-c1cc4c(cc1SB3c1cc3c(cc1S2)C(C)(C)CCC3(C)C)oc1ccccc14 ; CC1(C)CCC(C)(C)c2cc3c(cc21)Sc1cc(C24CC5CC(CC(C5)C2)C4)cc2c1B3Sc1cc3oc4ccccc4c3cc1-2 ; CC1(C)CCC(C)(C)c2cc3c(cc21)Sc1cccc2c1B3Sc1cc3c(cc1-2)sc1ccccc13 ; Cc1cc2c3c(c1)-c1cc4sc5ccccc5c4cc1SB3c1cc3c(cc1S2)C(C)(C)CCC3(C)C]

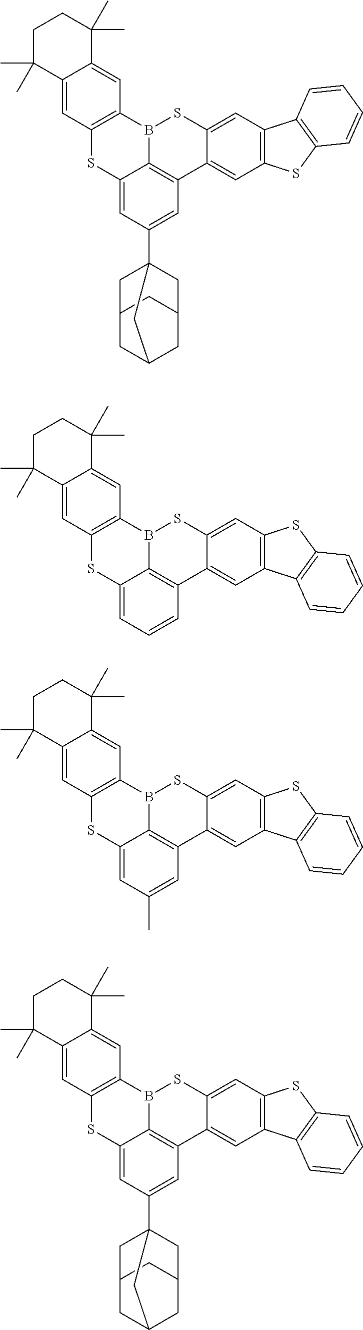 [SMILES: CC1(C)CCC(C)(C)c2cc3c(cc21)Sc1cc(C24CC5CC(CC(C5)C2)C4)cc2c1B3Sc1cc3c(cc1-2)sc1ccccc13 ; CC1(C)CCC(C)(C)c2cc3c(cc21)Sc1cccc2c1B3Sc1cc3sc4ccccc4c3cc1-2 ; Cc1cc2c3c(c1)-c1cc4c(cc1SB3c1cc3c(cc1S2)C(C)(C)CCC3(C)C)sc1ccccc14 ; CC1(C)CCC(C)(C)c2cc3c(cc21)Sc1cc(C24CC5CC(CC(C5)C2)C4)cc2c1B3Sc1cc3sc4ccccc4c3cc1-2]

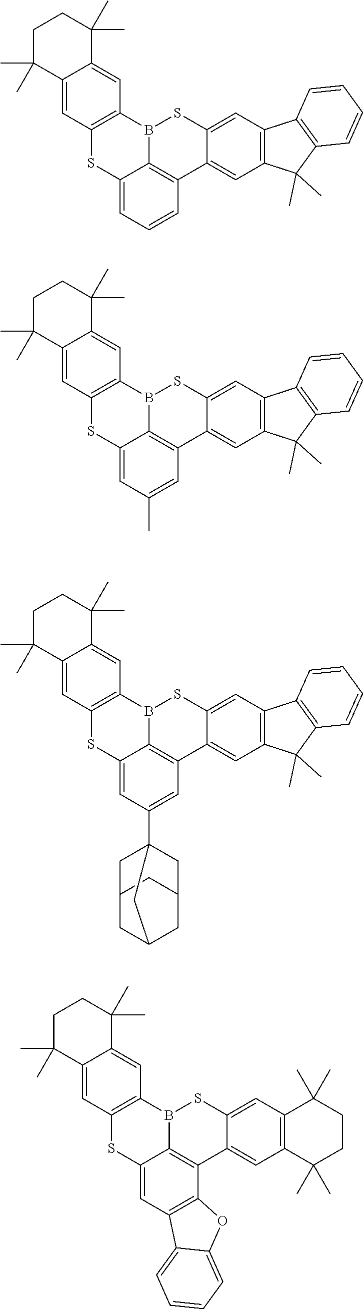 [SMILES: CC1(C)CCC(C)(C)c2cc3c(cc21)Sc1cccc2c1B3Sc1cc3c(cc1-2)C(C)(C)c1ccccc1-3 ; Cc1cc2c3c(c1)-c1cc4c(cc1SB3c1cc3c(cc1S2)C(C)(C)CCC3(C)C)-c1ccccc1C4(C)C ; CC1(C)CCC(C)(C)c2cc3c(cc21)Sc1cc(C24CC5CC(CC(C5)C2)C4)cc2c1B3Sc1cc3c(cc1-2)C(C)(C)c1ccccc1-3 ; CC1(C)CCC(C)(C)c2cc3c(cc21)Sc1cc2c(oc4ccccc42)c2c1B3Sc1cc3c(cc1-2)C(C)(C)CCC3(C)C]

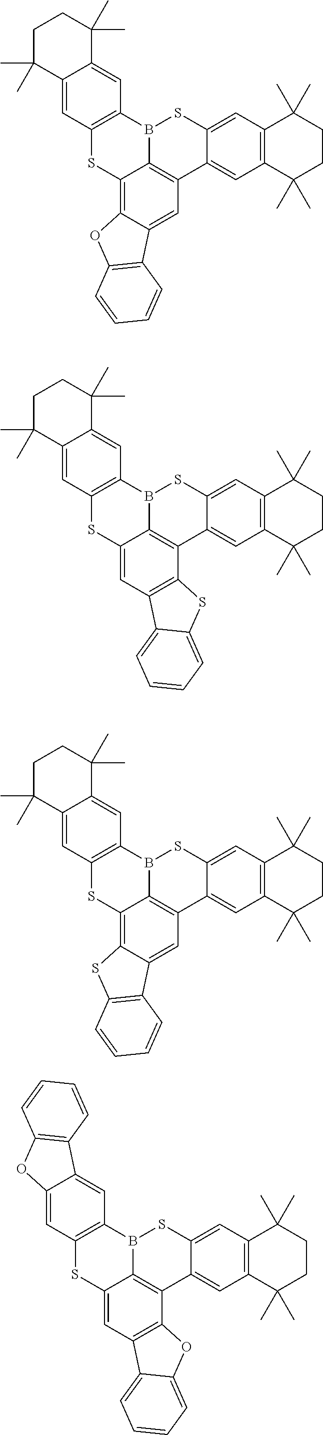

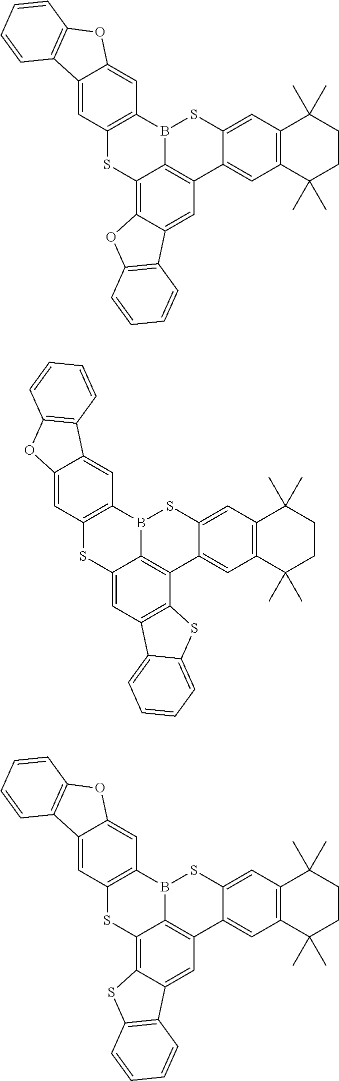 [SMILES: CC1(C)CCC(C)(C)c2cc3c(cc21)SB1c2cc4oc5ccccc5c4cc2Sc2c1c-3cc1c2oc2ccccc21 ; CC1(C)CCC(C)(C)c2cc3c(cc21)SB1c2cc4c(cc2Sc2cc5c(sc6ccccc65)c-3c21)oc1ccccc14 ; CC1(C)CCC(C)(C)c2cc3c(cc21)SB1c2cc4oc5ccccc5c4cc2Sc2c1c-3cc1c2sc2ccccc21]

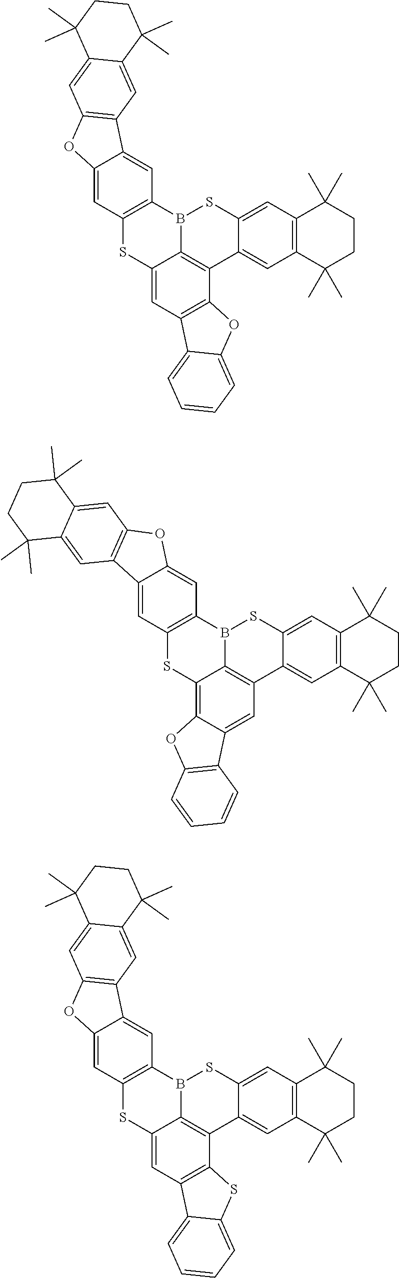 [SMILES: CC1(C)CCC(C)(C)c2cc3c(cc21)SB1c2cc4c(cc2Sc2cc5c(oc6ccccc65)c-3c21)oc1cc2c(cc14)C(C)(C)CCC2(C)C ; CC1(C)CCC(C)(C)c2cc3c(cc21)SB1c2cc4oc5cc6c(cc5c4cc2Sc2c1c-3cc1c2oc2ccccc21)C(C)(C)CCC6(C)C ; CC1(C)CCC(C)(C)c2cc3c(cc21)SB1c2cc4c(cc2Sc2cc5c(sc6ccccc65)c-3c21)oc1cc2c(cc14)C(C)(C)CCC2(C)C]

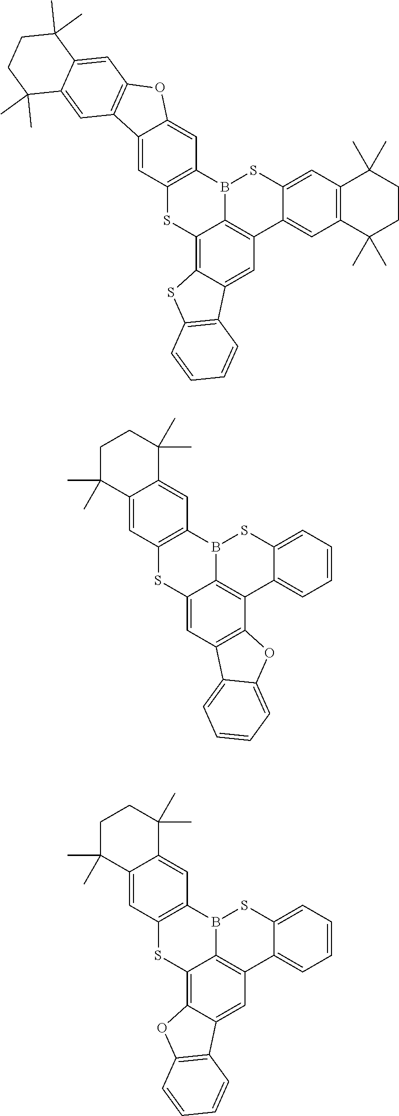

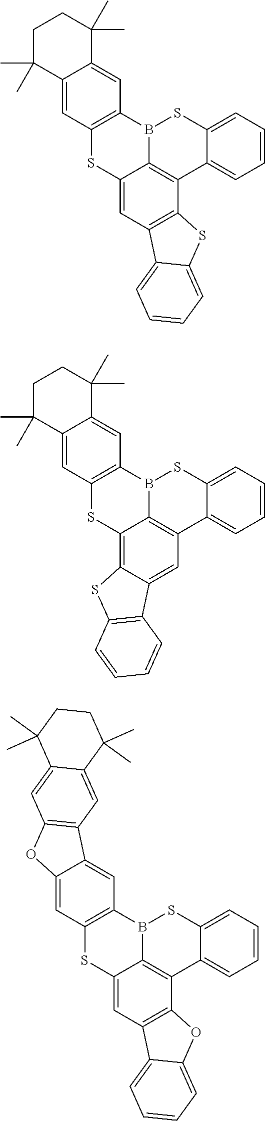

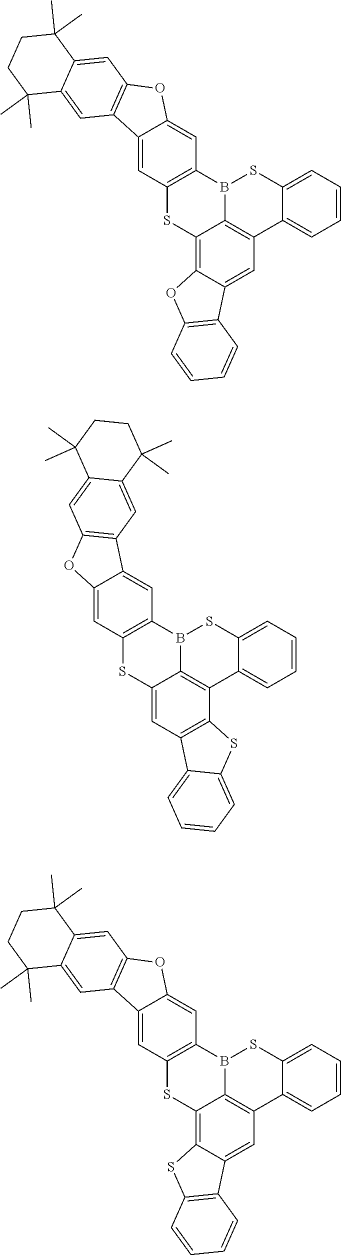 [SMILES: CC1(C)CCC(C)(C)c2cc3c(cc21)oc1cc2c(cc13)Sc1c3c(cc4c1oc1ccccc14)-c1ccccc1SB23 ; CC1(C)CCC(C)(C)c2cc3c(cc21)oc1cc2c(cc13)B1Sc3ccccc3-c3c1c(cc1c3sc3ccccc31)S2 ; CC1(C)CCC(C)(C)c2cc3c(cc21)oc1cc2c(cc13)Sc1c3c(cc4c1sc1ccccc14)-c1ccccc1SB23]

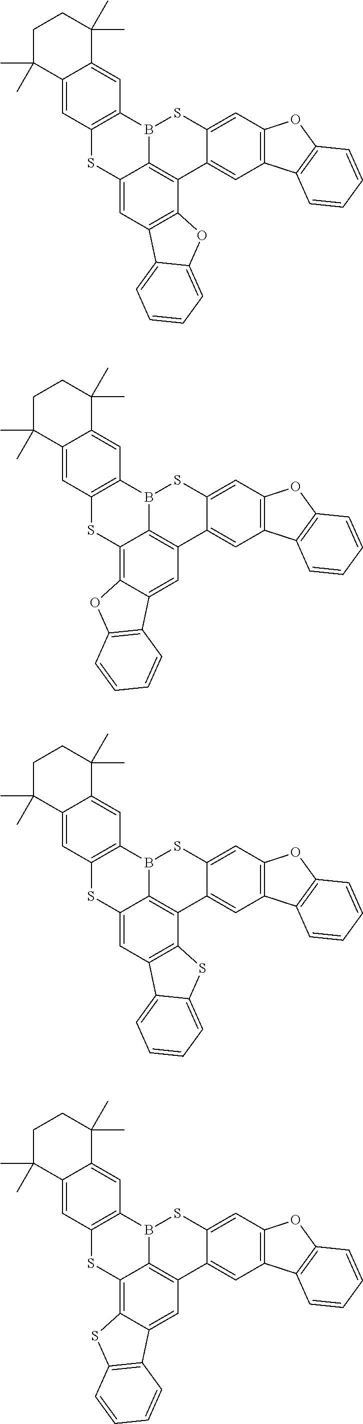

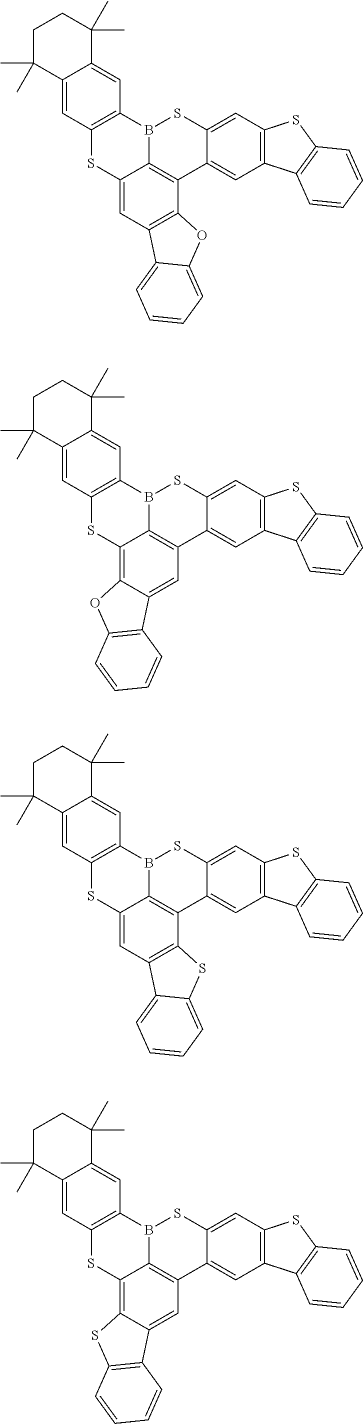

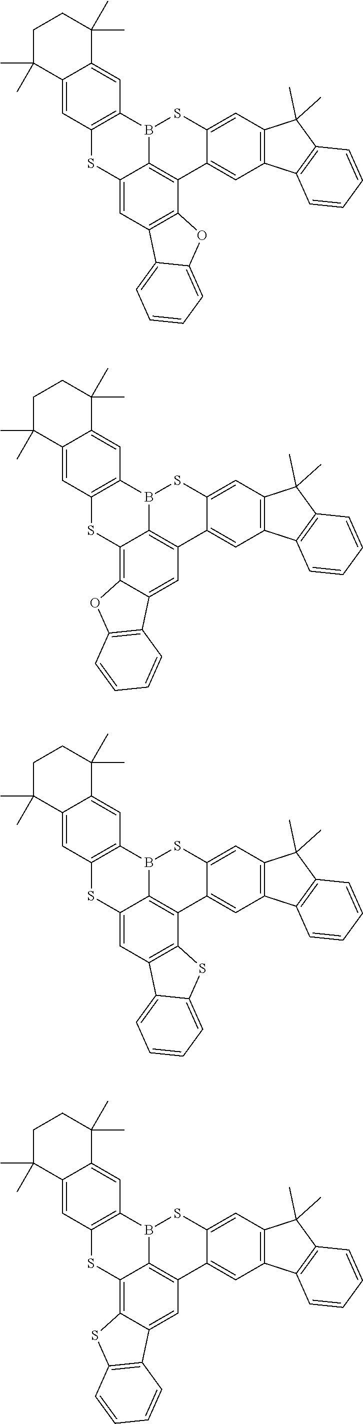

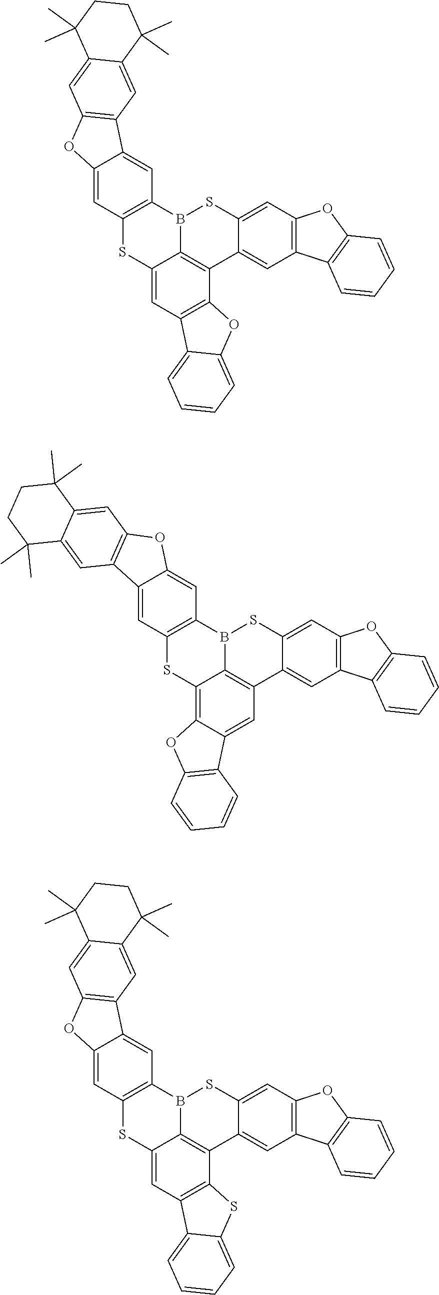 [SMILES: CC1(C)CCC(C)(C)c2cc3c(cc21)oc1cc2c(cc13)B1Sc3cc4oc5ccccc5c4cc3-c3c1c(cc1c3oc3ccccc31)S2 ; CC1(C)CCC(C)(C)c2cc3c(cc21)oc1cc2c(cc13)Sc1c3c(cc4c1oc1ccccc14)-c1cc4c(cc1SB23)oc1ccccc14 ; CC1(C)CCC(C)(C)c2cc3c(cc21)oc1cc2c(cc13)B1Sc3cc4oc5ccccc5c4cc3-c3c1c(cc1c3sc3ccccc31)S2]

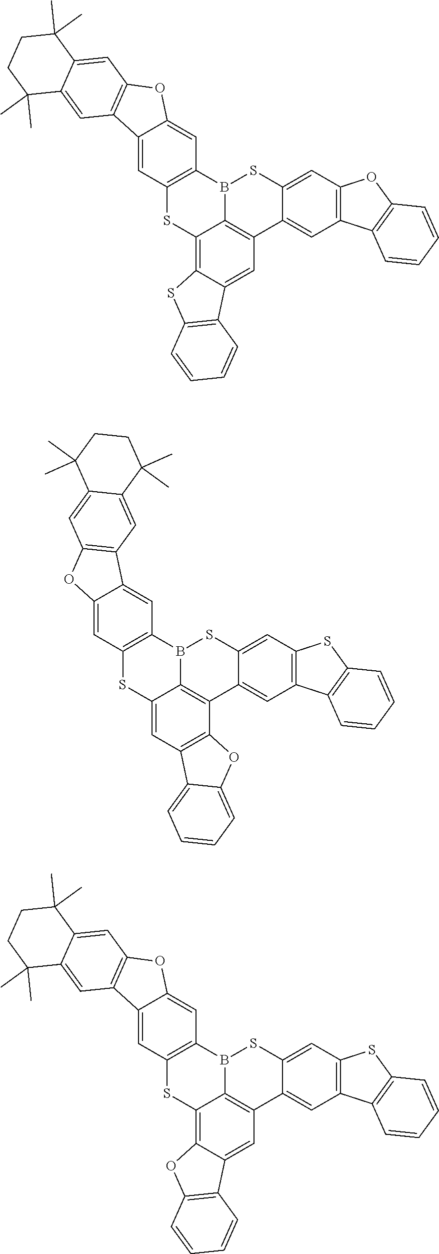 [SMILES: CC1(C)CCC(C)(C)c2cc3c(cc21)oc1cc2c(cc13)Sc1c3c(cc4c1sc1ccccc14)-c1cc4c(cc1SB23)oc1ccccc14 ; CC1(C)CCC(C)(C)c2cc3c(cc21)oc1cc2c(cc13)B1Sc3cc4sc5ccccc5c4cc3-c3c1c(cc1c3oc3ccccc31)S2 ; CC1(C)CCC(C)(C)c2cc3c(cc21)oc1cc2c(cc13)Sc1c3c(cc4c1oc1ccccc14)-c1cc4c(cc1SB23)sc1ccccc14]

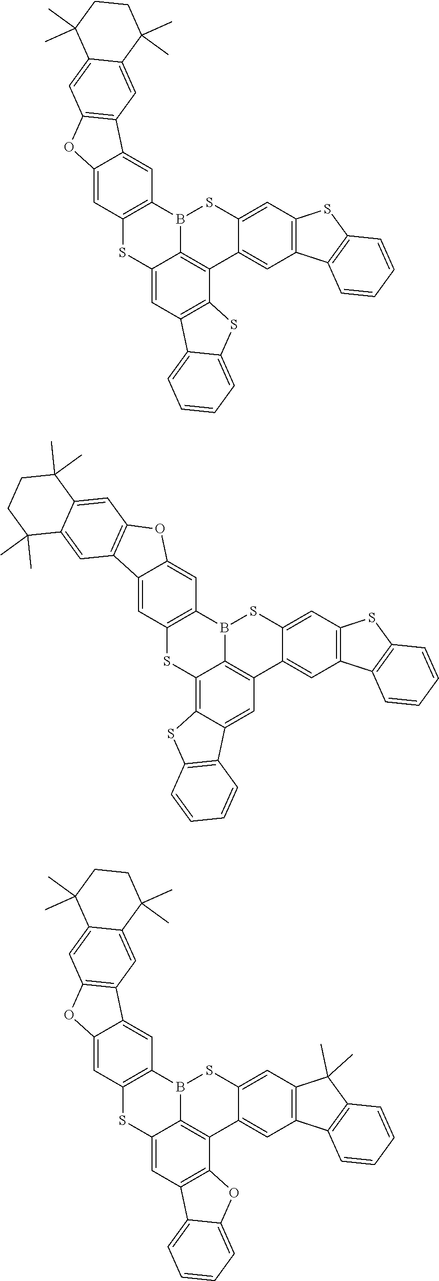 [SMILES: CC1(C)CCC(C)(C)c2cc3c(cc21)oc1cc2c(cc13)B1Sc3cc4sc5ccccc5c4cc3-c3c1c(cc1c3sc3ccccc31)S2 ; CC1(C)CCC(C)(C)c2cc3c(cc21)oc1cc2c(cc13)Sc1c3c(cc4c1sc1ccccc14)-c1cc4c(cc1SB23)sc1ccccc14 ; CC1(C)CCC(C)(C)c2cc3c(cc21)oc1cc2c(cc13)B1Sc3cc4c(cc3-c3c1c(cc1c3oc3ccccc31)S2)-c1ccccc1C4(C)C]

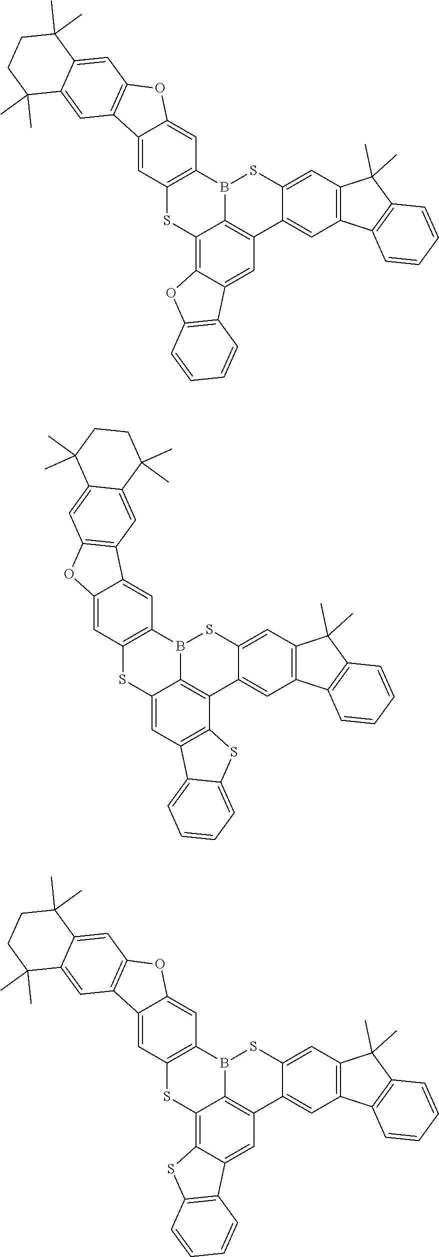 [SMILES: CC1(C)CCC(C)(C)c2cc3c(cc21)oc1cc2c(cc13)Sc1c3c(cc4c1oc1ccccc14)-c1cc4c(cc1SB23)C(C)(C)c1ccccc1-4 ; CC1(C)CCC(C)(C)c2cc3c(cc21)oc1cc2c(cc13)B1Sc3cc4c(cc3-c3c1c(cc1c3sc3ccccc31)S2)-c1ccccc1C4(C)C ; CC1(C)CCC(C)(C)c2cc3c(cc21)oc1cc2c(cc13)Sc1c3c(cc4c1sc1ccccc14)-c1cc4c(cc1SB23)C(C)(C)c1ccccc1-4]

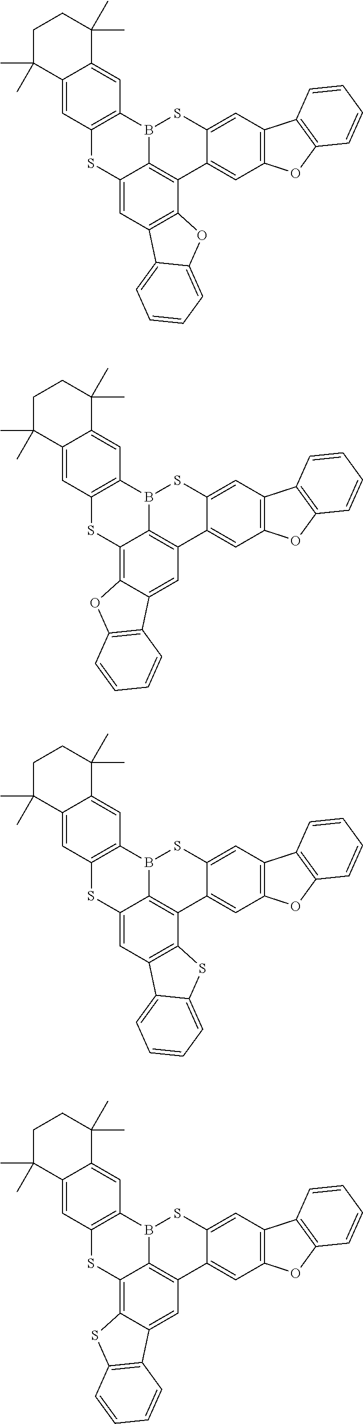

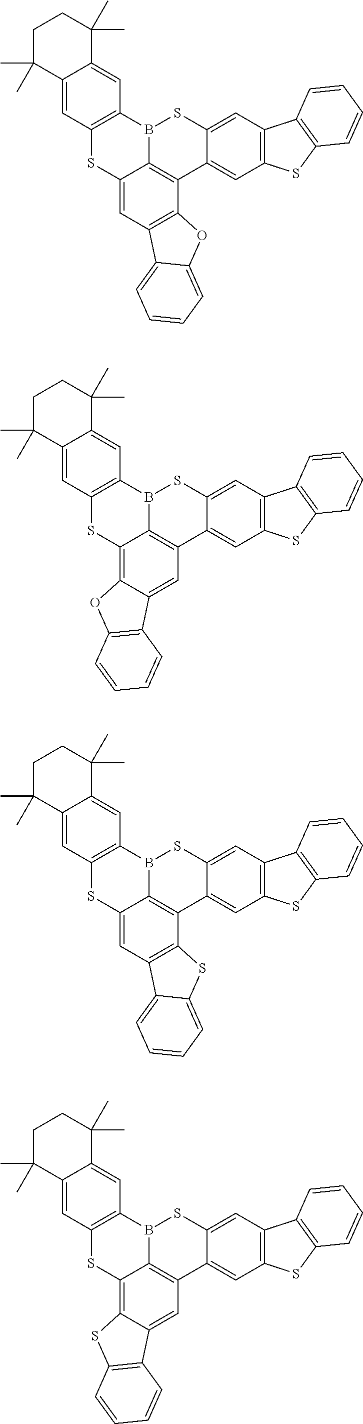

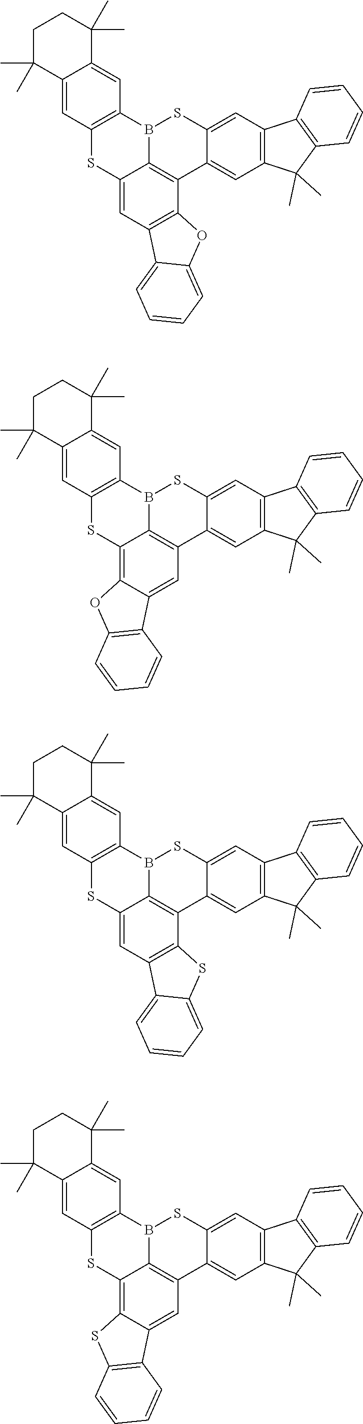

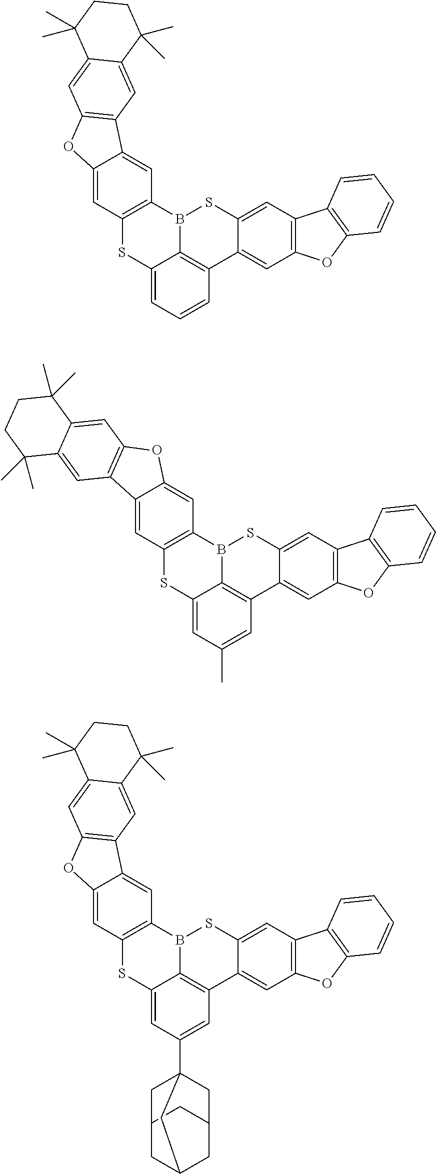 [SMILES: CC1(C)CCC(C)(C)c2cc3c(cc21)oc1cc2c(cc13)B1Sc3cc4c(cc3-c3cccc(c31)S2)oc1ccccc14 ; Cc1cc2c3c(c1)-c1cc4oc5ccccc5c4cc1SB3c1cc3oc4cc5c(cc4c3cc1S2)C(C)(C)CCC5(C)C ; CC1(C)CCC(C)(C)c2cc3c(cc21)oc1cc2c(cc13)B1Sc3cc4c(cc3-c3cc(C56CC7CC(CC(C7)C5)C6)cc(c31)S2)oc1ccccc14]

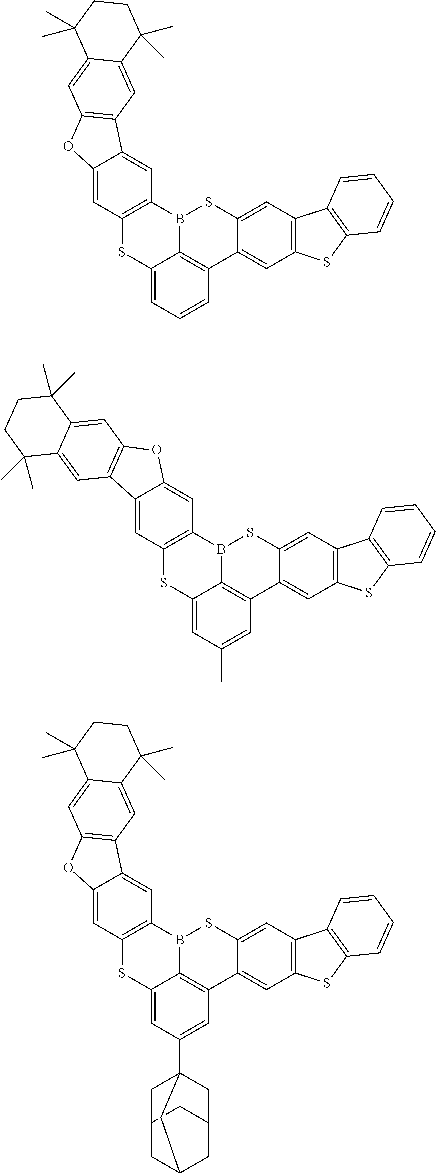 [SMILES: CC1(C)CCC(C)(C)c2cc3c(cc21)oc1cc2c(cc13)B1Sc3cc4c(cc3-c3cccc(c31)S2)sc1ccccc14 ; Cc1cc2c3c(c1)-c1cc4sc5ccccc5c4cc1SB3c1cc3oc4cc5c(cc4c3cc1S2)C(C)(C)CCC5(C)C ; CC1(C)CCC(C)(C)c2cc3c(cc21)oc1cc2c(cc13)B1Sc3cc4c(cc3-c3cc(C56CC7CC(CC(C7)C5)C6)cc(c31)S2)sc1ccccc14]

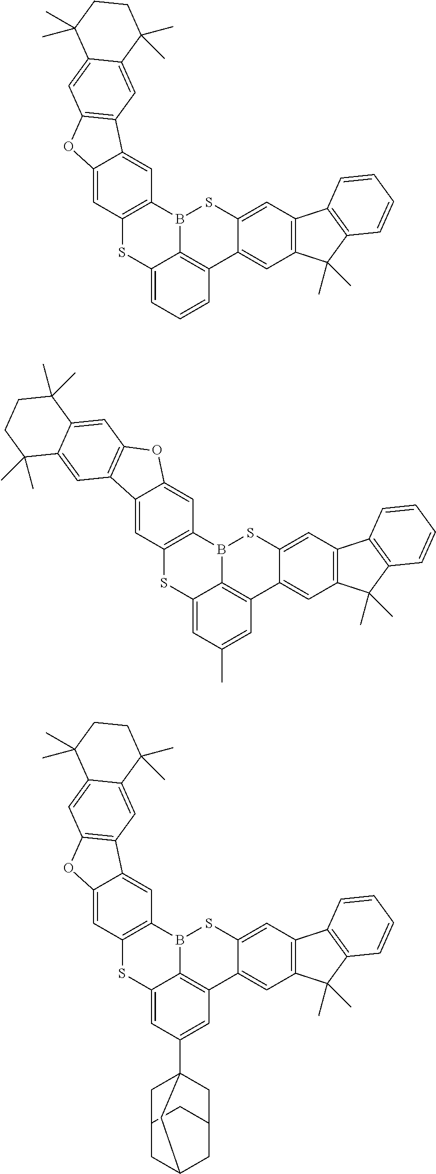 [SMILES: CC1(C)CCC(C)(C)c2cc3c(cc21)oc1cc2c(cc13)B1Sc3cc4c(cc3-c3cccc(c31)S2)C(C)(C)c1ccccc1-4 ; Cc1cc2c3c(c1)-c1cc4c(cc1SB3c1cc3oc5cc6c(cc5c3cc1S2)C(C)(C)CCC6(C)C)-c1ccccc1C4(C)C ; CC1(C)CCC(C)(C)c2cc3c(cc21)oc1cc2c(cc13)B1Sc3cc4c(cc3-c3cc(C56CC7CC(CC(C7)C5)C6)cc(c31)S2)C(C)(C)c1ccccc1-4]

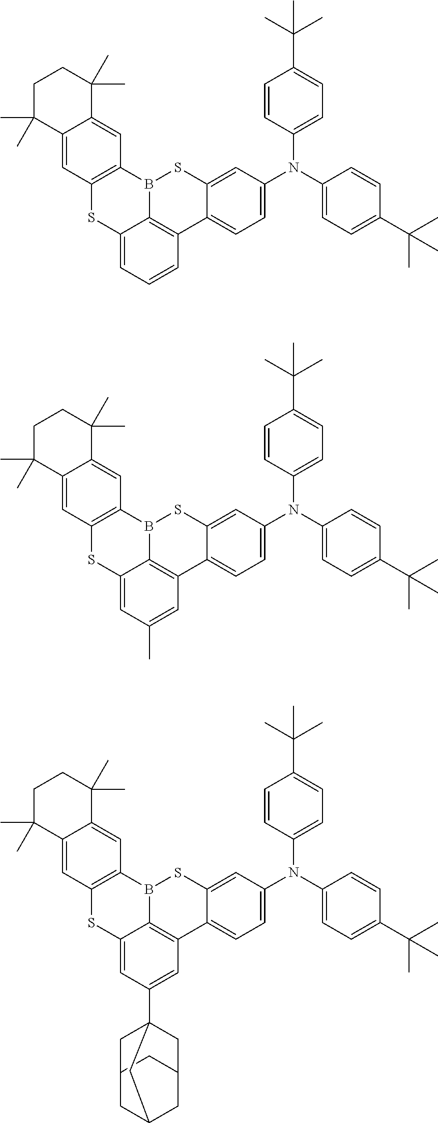

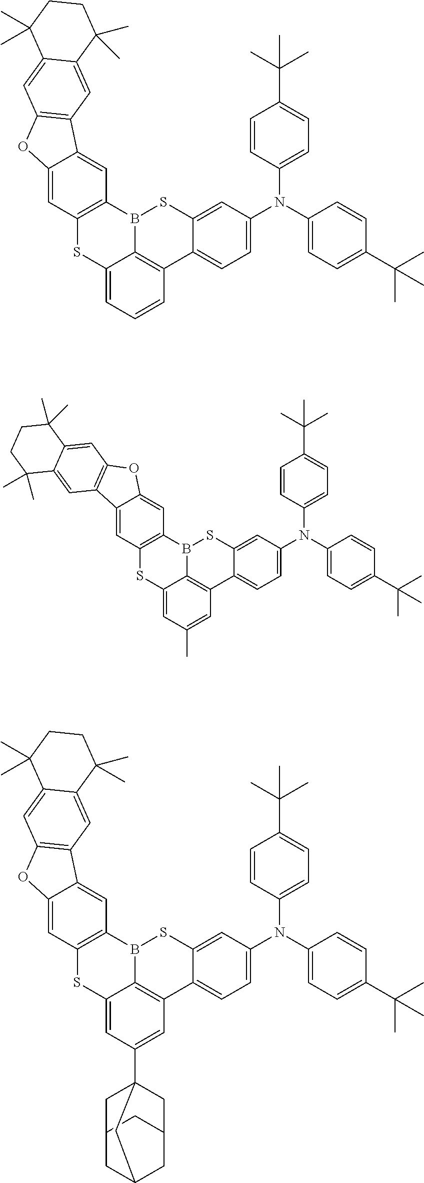

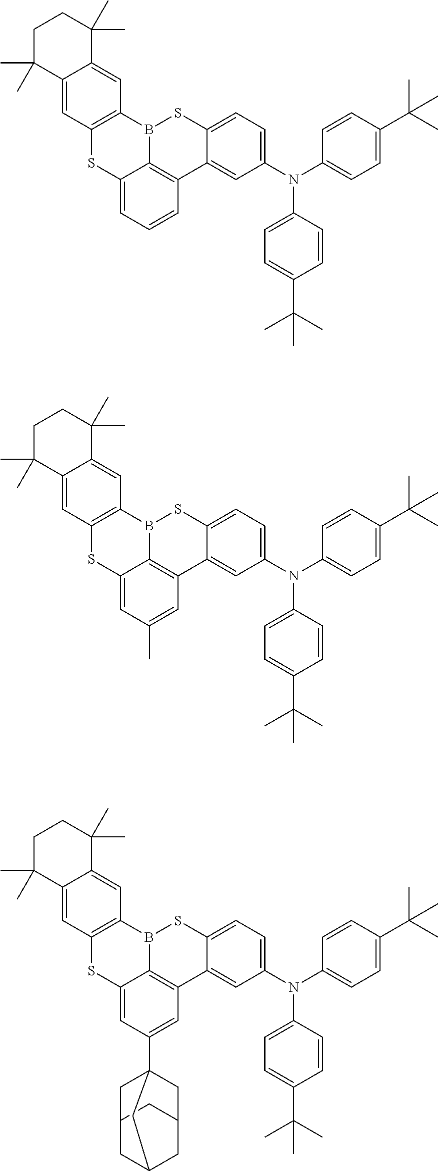

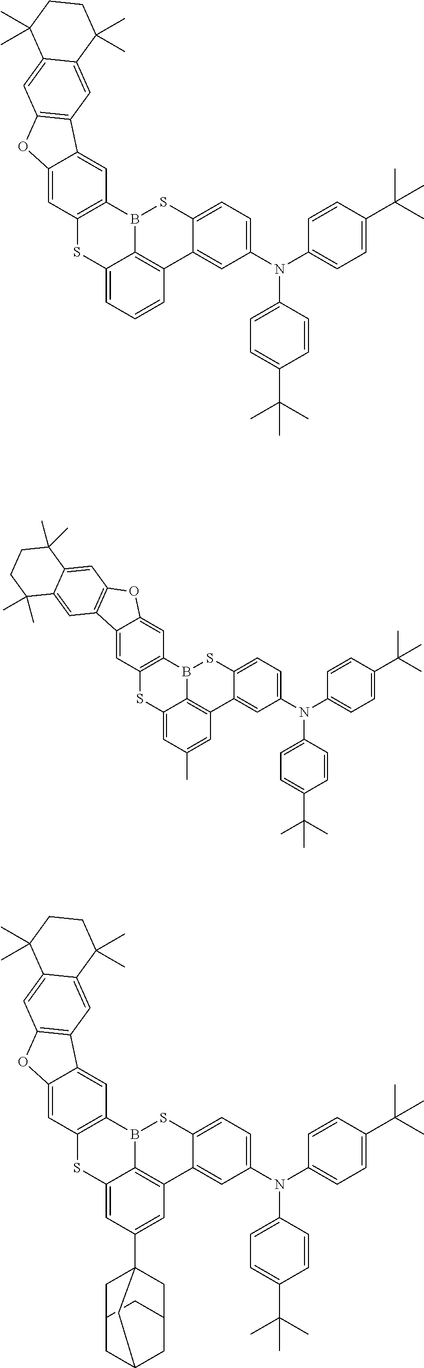

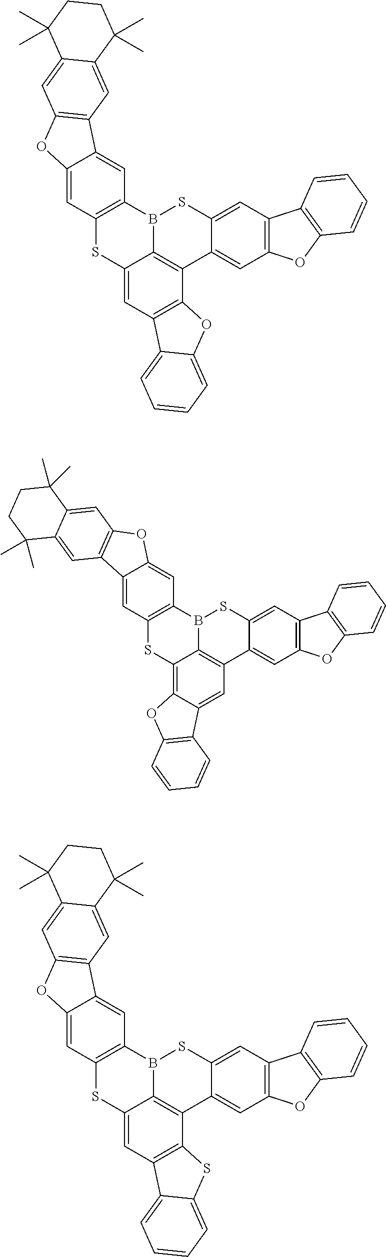 [SMILES: CC1(C)CCC(C)(C)c2cc3c(cc21)oc1cc2c(cc13)B1Sc3cc4c(cc3-c3c1c(cc1c3oc3ccccc31)S2)oc1ccccc14 ; CC1(C)CCC(C)(C)c2cc3c(cc21)oc1cc2c(cc13)Sc1c3c(cc4c1oc1ccccc14)-c1cc4oc5ccccc5c4cc1SB23 ; CC1(C)CCC(C)(C)c2cc3c(cc21)oc1cc2c(cc13)B1Sc3cc4c(cc3-c3c1c(cc1c3sc3ccccc31)S2)oc1ccccc14]

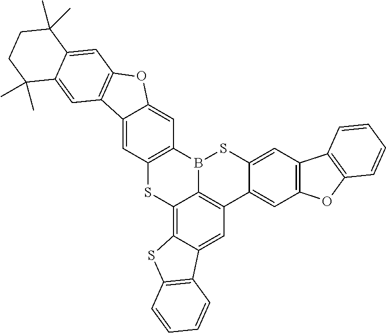 [SMILES: CC1(C)CCC(C)(C)c2cc3c(cc21)oc1cc2c(cc13)Sc1c3c(cc4c1sc1ccccc14)-c1cc4oc5ccccc5c4cc1SB23]

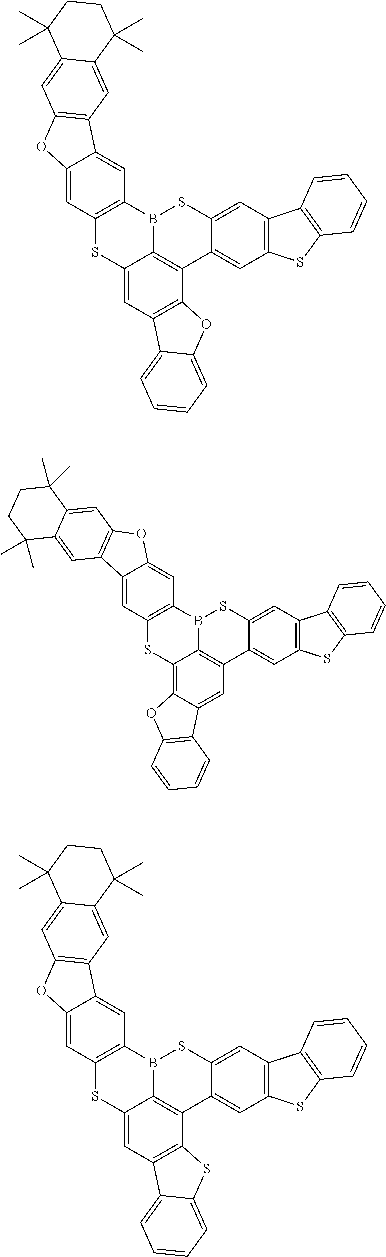 [SMILES: CC1(C)CCC(C)(C)c2cc3c(cc21)oc1cc2c(cc13)B1Sc3cc4c(cc3-c3c1c(cc1c3oc3ccccc31)S2)sc1ccccc14 ; CC1(C)CCC(C)(C)c2cc3c(cc21)oc1cc2c(cc13)Sc1c3c(cc4c1oc1ccccc14)-c1cc4sc5ccccc5c4cc1SB23 ; CC1(C)CCC(C)(C)c2cc3c(cc21)oc1cc2c(cc13)B1Sc3cc4c(cc3-c3c1c(cc1c3sc3ccccc31)S2)sc1ccccc14]

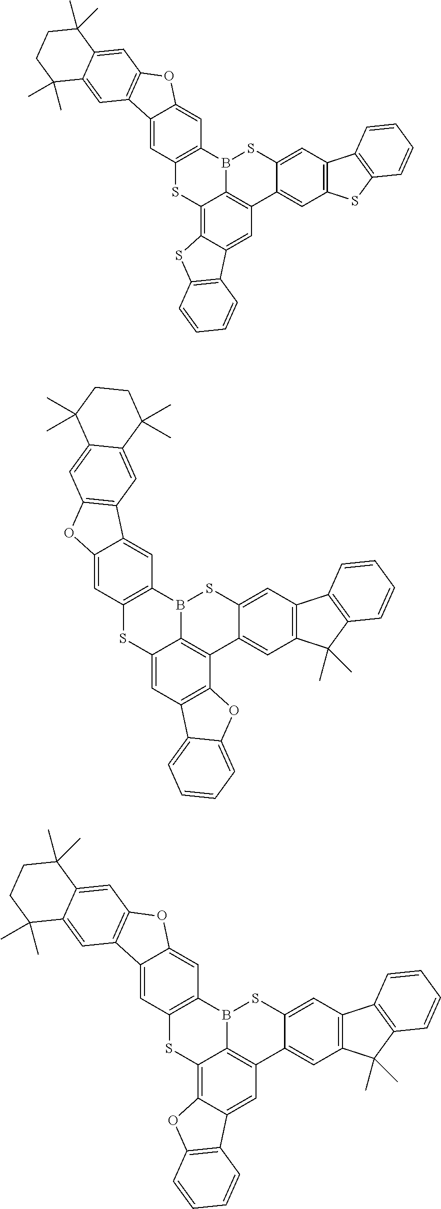 [SMILES: CC1(C)CCC(C)(C)c2cc3c(cc21)oc1cc2c(cc13)Sc1c3c(cc4c1sc1ccccc14)-c1cc4sc5ccccc5c4cc1SB23 ; CC1(C)CCC(C)(C)c2cc3c(cc21)oc1cc2c(cc13)B1Sc3cc4c(cc3-c3c1c(cc1c3oc3ccccc31)S2)C(C)(C)c1ccccc1-4 ; CC1(C)CCC(C)(C)c2cc3c(cc21)oc1cc2c(cc13)Sc1c3c(cc4c1oc1ccccc14)-c1cc4c(cc1SB23)-c1ccccc1C4(C)C]

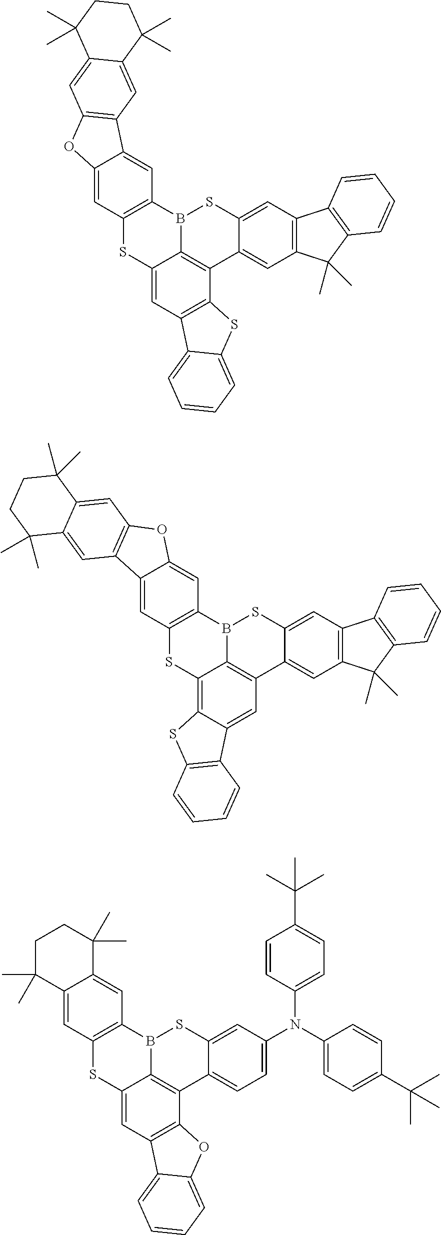 [SMILES: CC1(C)CCC(C)(C)c2cc3c(cc21)oc1cc2c(cc13)B1Sc3cc4c(cc3-c3c1c(cc1c3sc3ccccc31)S2)C(C)(C)c1ccccc1-4 ; CC1(C)CCC(C)(C)c2cc3c(cc21)oc1cc2c(cc13)Sc1c3c(cc4c1sc1ccccc14)-c1cc4c(cc1SB23)-c1ccccc1C4(C)C ; CC(C)(C)c1ccc(N(c2ccc(C(C)(C)C)cc2)c2ccc3c(c2)SB2c4cc5c(cc4Sc4cc6c(oc7ccccc76)c-3c42)C(C)(C)CCC5(C)C)cc1]

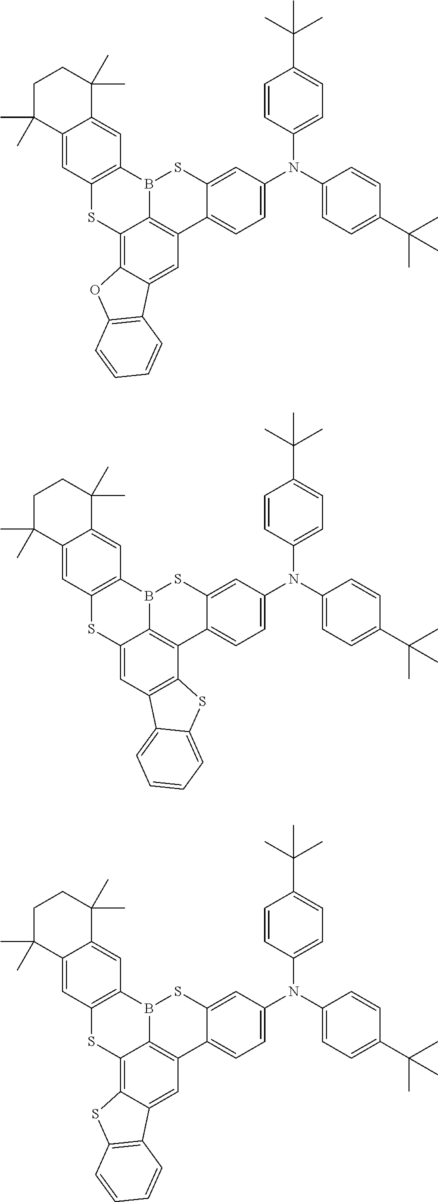

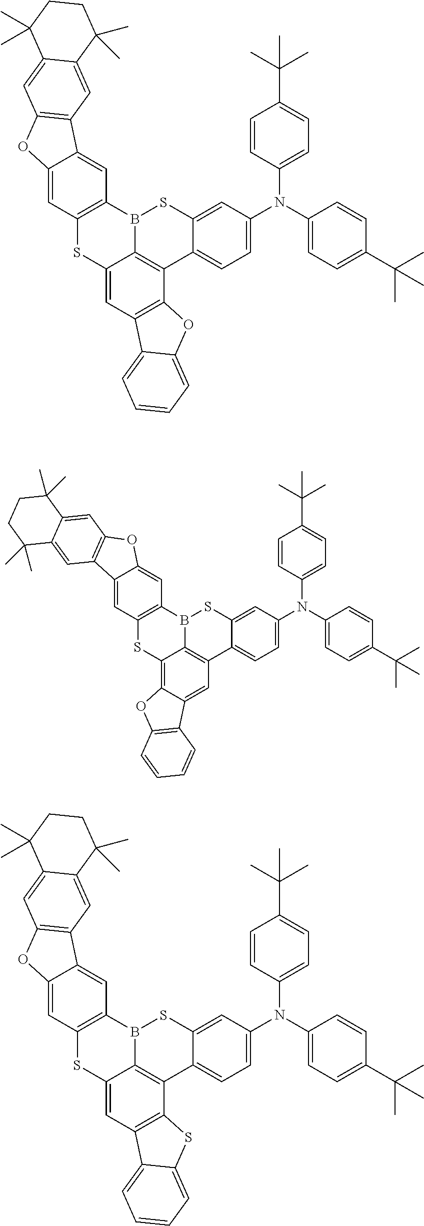

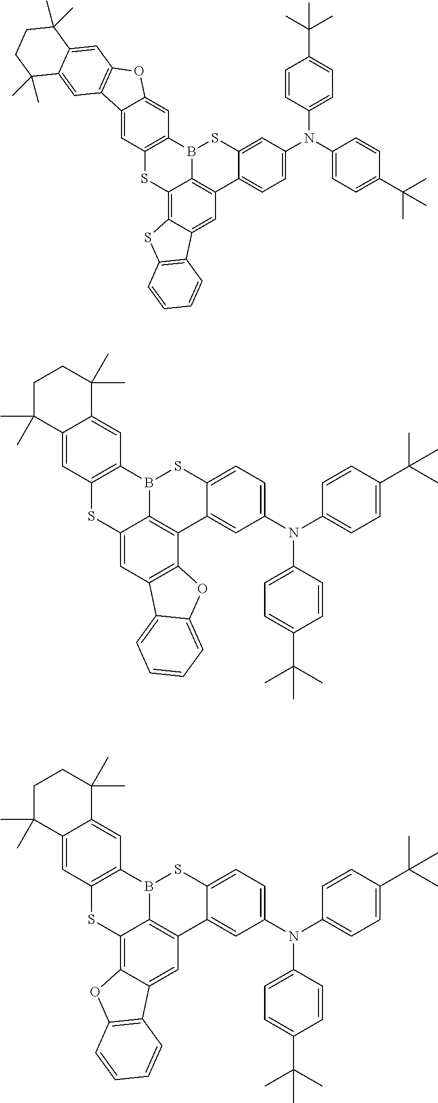

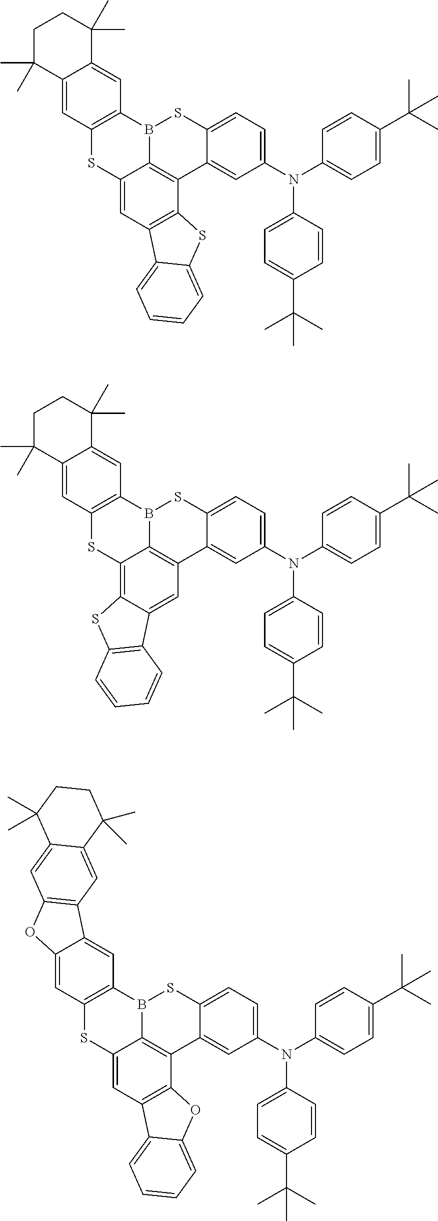

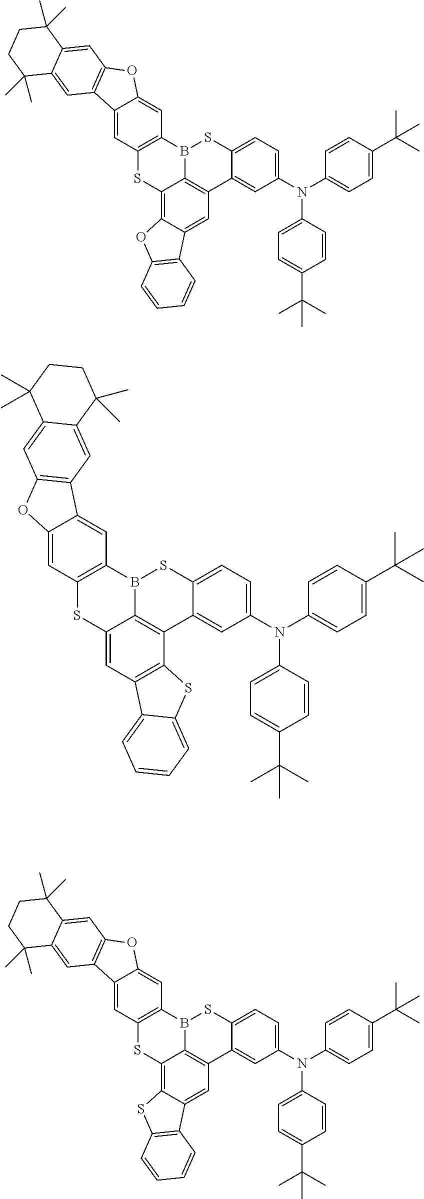

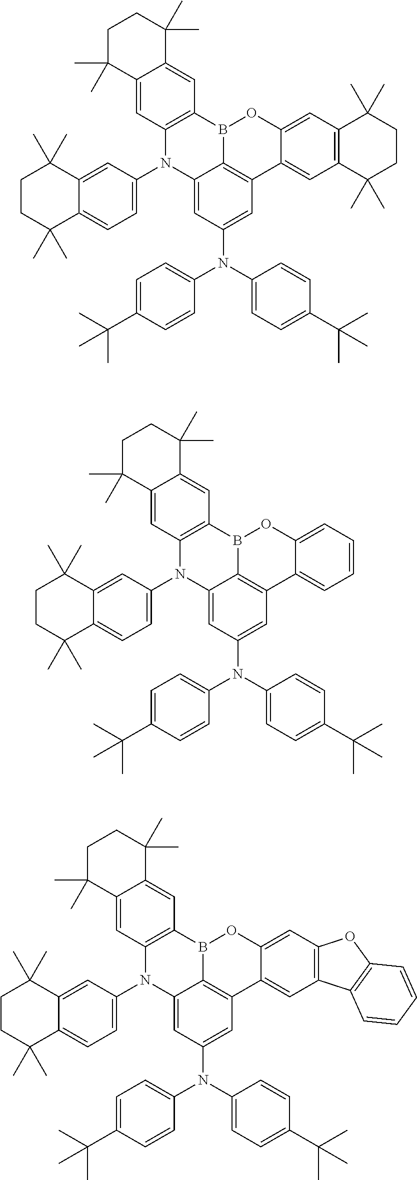 [SMILES: CC(C)(C)c1ccc(N(c2ccc(C(C)(C)C)cc2)c2cc3c4c(c2)N(c2ccc5c(c2)C(C)(C)CCC5(C)C)c2cc5c(cc2B4Oc2cc4c(cc2-3)C(C)(C)CCC4(C)C)C(C)(C)CCC5(C)C)cc1 ; CC(C)(C)c1ccc(N(c2ccc(C(C)(C)C)cc2)c2cc3c4c(c2)N(c2ccc5c(c2)C(C)(C)CCC5(C)C)c2cc5c(cc2B4Oc2ccccc2-3)C(C)(C)CCC5(C)C)cc1 ; CC(C)(C)c1ccc(N(c2ccc(C(C)(C)C)cc2)c2cc3c4c(c2)N(c2ccc5c(c2)C(C)(C)CCC5(C)C)c2cc5c(cc2B4Oc2cc4oc6ccccc6c4cc2-3)C(C)(C)CCC5(C)C)cc1]

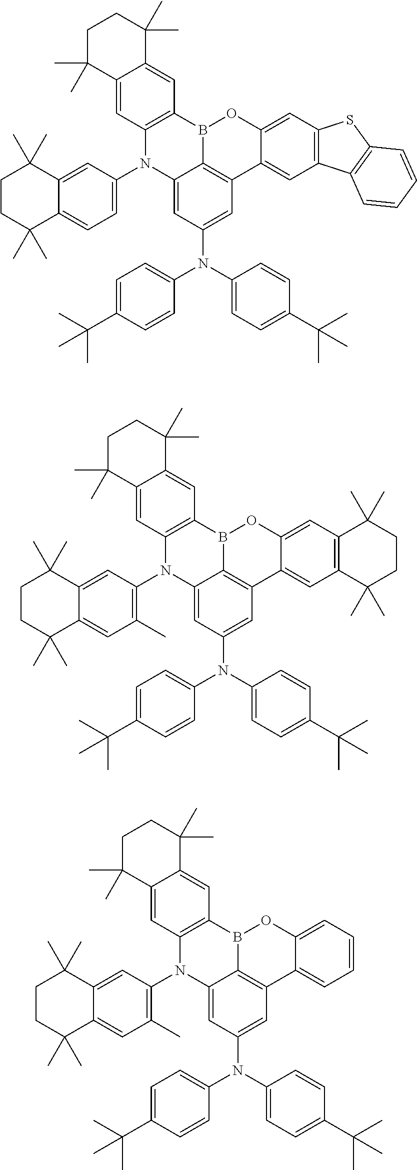 [SMILES: CC(C)(C)c1ccc(N(c2ccc(C(C)(C)C)cc2)c2cc3c4c(c2)N(c2ccc5c(c2)C(C)(C)CCC5(C)C)c2cc5c(cc2B4Oc2cc4sc6ccccc6c4cc2-3)C(C)(C)CCC5(C)C)cc1 ; Cc1cc2c(cc1N1c3cc4c(cc3B3Oc5cc6c(cc5-c5cc(N(c7ccc(C(C)(C)C)cc7)c7ccc(C(C)(C)C)cc7)cc1c53)C(C)(C)CCC6(C)C)C(C)(C)CCC4(C)C)C(C)(C)CCC2(C)C ; Cc1cc2c(cc1N1c3cc4c(cc3B3Oc5ccccc5-c5cc(N(c6ccc(C(C)(C)C)cc6)c6ccc(C(C)(C)C)cc6)cc1c53)C(C)(C)CCC4(C)C)C(C)(C)CCC2(C)C]

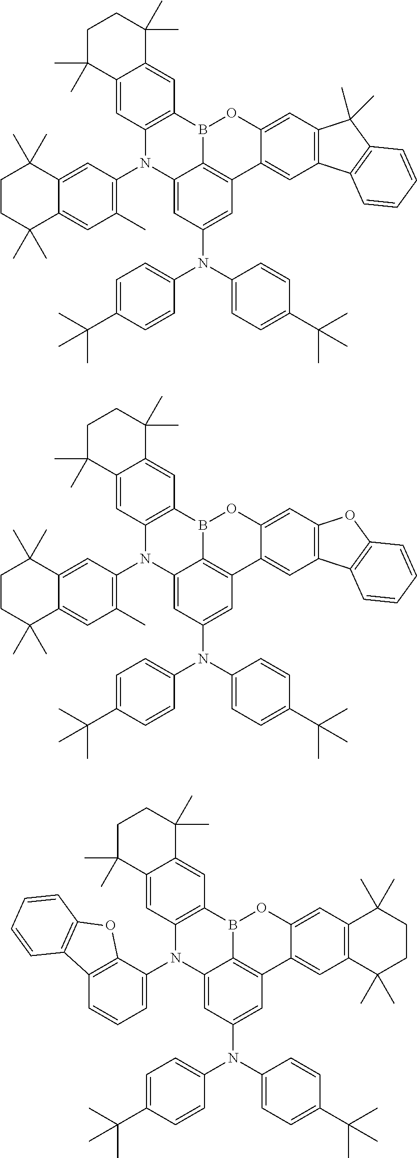 [SMILES: Cc1cc2c(cc1N1c3cc4c(cc3B3Oc5cc6c(cc5-c5cc(N(c7ccc(C(C)(C)C)cc7)c7ccc(C(C)(C)C)cc7)cc1c53)-c1ccccc1C6(C)C)C(C)(C)CCC4(C)C)C(C)(C)CCC2(C)C ; Cc1cc2c(cc1N1c3cc4c(cc3B3Oc5cc6oc7ccccc7c6cc5-c5cc(N(c6ccc(C(C)(C)C)cc6)c6ccc(C(C)(C)C)cc6)cc1c53)C(C)(C)CCC4(C)C)C(C)(C)CCC2(C)C ; CC(C)(C)c1ccc(N(c2ccc(C(C)(C)C)cc2)c2cc3c4c(c2)N(c2cccc5c2oc2ccccc25)c2cc5c(cc2B4Oc2cc4c(cc2-3)C(C)(C)CCC4(C)C)C(C)(C)CCC5(C)C)cc1]

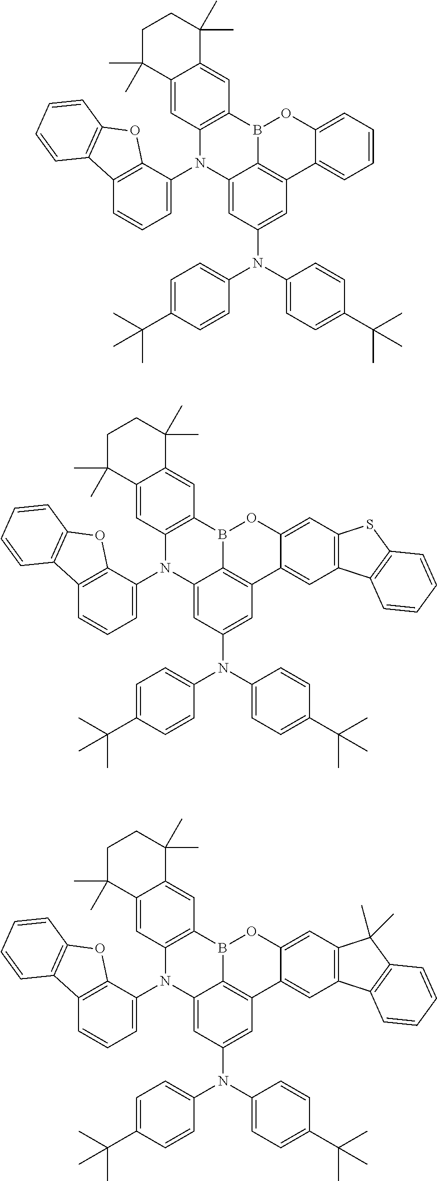 [SMILES: CC(C)(C)c1ccc(N(c2ccc(C(C)(C)C)cc2)c2cc3c4c(c2)N(c2cccc5c2oc2ccccc25)c2cc5c(cc2B4Oc2ccccc2-3)C(C)(C)CCC5(C)C)cc1 ; CC(C)(C)c1ccc(N(c2ccc(C(C)(C)C)cc2)c2cc3c4c(c2)N(c2cccc5c2oc2ccccc25)c2cc5c(cc2B4Oc2cc4sc6ccccc6c4cc2-3)C(C)(C)CCC5(C)C)cc1 ; CC(C)(C)c1ccc(N(c2ccc(C(C)(C)C)cc2)c2cc3c4c(c2)N(c2cccc5c2oc2ccccc25)c2cc5c(cc2B4Oc2cc4c(cc2-3)-c2ccccc2C4(C)C)C(C)(C)CCC5(C)C)cc1]

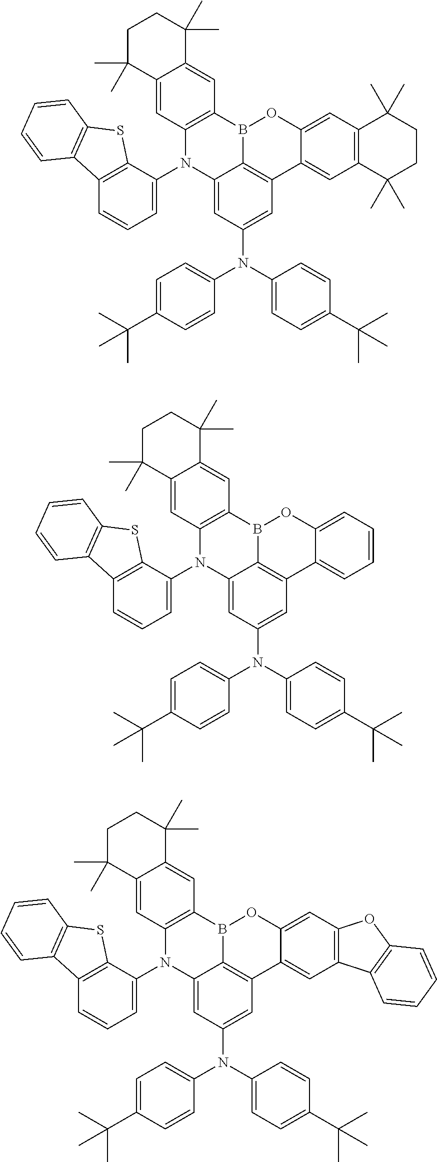 [SMILES: CC(C)(C)c1ccc(N(c2ccc(C(C)(C)C)cc2)c2cc3c4c(c2)N(c2cccc5c2sc2ccccc25)c2cc5c(cc2B4Oc2cc4c(cc2-3)C(C)(C)CCC4(C)C)C(C)(C)CCC5(C)C)cc1 ; CC(C)(C)c1ccc(N(c2ccc(C(C)(C)C)cc2)c2cc3c4c(c2)N(c2cccc5c2sc2ccccc25)c2cc5c(cc2B4Oc2ccccc2-3)C(C)(C)CCC5(C)C)cc1 ; CC(C)(C)c1ccc(N(c2ccc(C(C)(C)C)cc2)c2cc3c4c(c2)N(c2cccc5c2sc2ccccc25)c2cc5c(cc2B4Oc2cc4oc6ccccc6c4cc2-3)C(C)(C)CCC5(C)C)cc1]

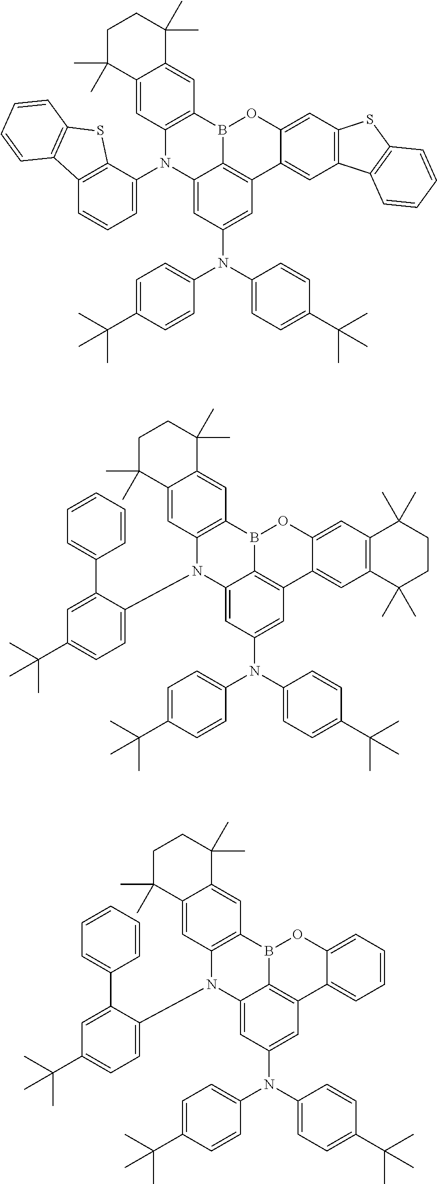 [SMILES: CC(C)(C)c1ccc(N(c2ccc(C(C)(C)C)cc2)c2cc3c4c(c2)N(c2cccc5c2sc2ccccc25)c2cc5c(cc2B4Oc2cc4sc6ccccc6c4cc2-3)C(C)(C)CCC5(C)C)cc1 ; CC(C)(C)c1ccc(N(c2ccc(C(C)(C)C)cc2)c2cc3c4c(c2)N(c2ccc(C(C)(C)C)cc2-c2ccccc2)c2cc5c(cc2B4Oc2cc4c(cc2-3)C(C)(C)CCC4(C)C)C(C)(C)CCC5(C)C)cc1 ; CC(C)(C)c1ccc(N(c2ccc(C(C)(C)C)cc2)c2cc3c4c(c2)N(c2ccc(C(C)(C)C)cc2-c2ccccc2)c2cc5c(cc2B4Oc2ccccc2-3)C(C)(C)CCC5(C)C)cc1]

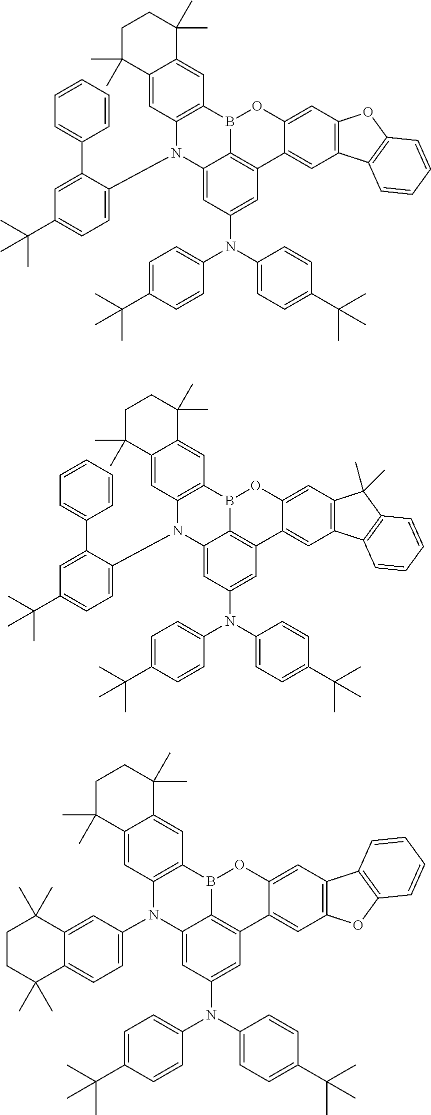 [SMILES: CC(C)(C)c1ccc(N(c2ccc(C(C)(C)C)cc2)c2cc3c4c(c2)N(c2ccc(C(C)(C)C)cc2-c2ccccc2)c2cc5c(cc2B4Oc2cc4oc6ccccc6c4cc2-3)C(C)(C)CCC5(C)C)cc1 ; CC(C)(C)c1ccc(N(c2ccc(C(C)(C)C)cc2)c2cc3c4c(c2)N(c2ccc(C(C)(C)C)cc2-c2ccccc2)c2cc5c(cc2B4Oc2cc4c(cc2-3)-c2ccccc2C4(C)C)C(C)(C)CCC5(C)C)cc1 ; CC(C)(C)c1ccc(N(c2ccc(C(C)(C)C)cc2)c2cc3c4c(c2)N(c2ccc5c(c2)C(C)(C)CCC5(C)C)c2cc5c(cc2B4Oc2cc4c(cc2-3)oc2ccccc24)C(C)(C)CCC5(C)C)cc1]

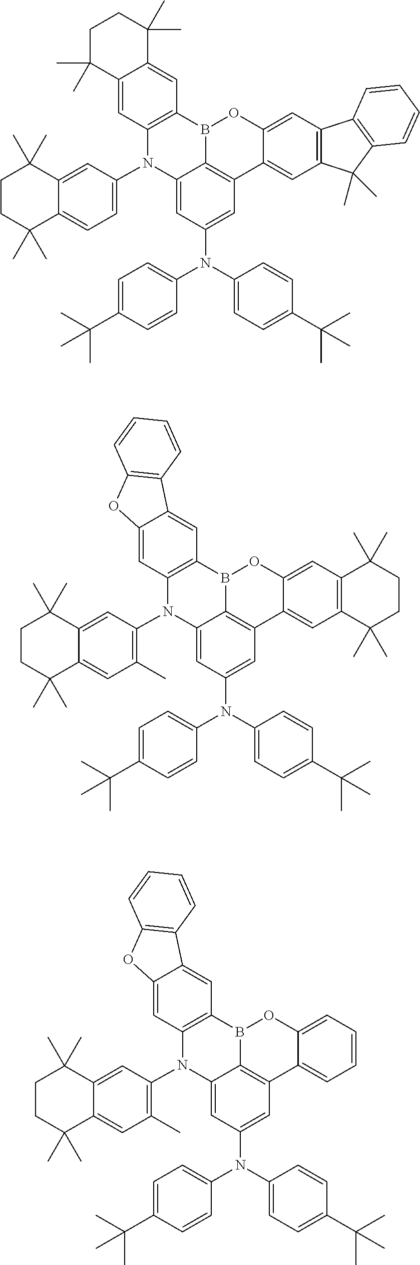 [SMILES: CC(C)(C)c1ccc(N(c2ccc(C(C)(C)C)cc2)c2cc3c4c(c2)N(c2ccc5c(c2)C(C)(C)CCC5(C)C)c2cc5c(cc2B4Oc2cc4c(cc2-3)C(C)(C)c2ccccc2-4)C(C)(C)CCC5(C)C)cc1 ; Cc1cc2c(cc1N1c3cc4oc5ccccc5c4cc3B3Oc4cc5c(cc4-c4cc(N(c6ccc(C(C)(C)C)cc6)c6ccc(C(C)(C)C)cc6)cc1c43)C(C)(C)CCC5(C)C)C(C)(C)CCC2(C)C ; Cc1cc2c(cc1N1c3cc4oc5ccccc5c4cc3B3Oc4ccccc4-c4cc(N(c5ccc(C(C)(C)C)cc5)c5ccc(C(C)(C)C)cc5)cc1c43)C(C)(C)CCC2(C)C]

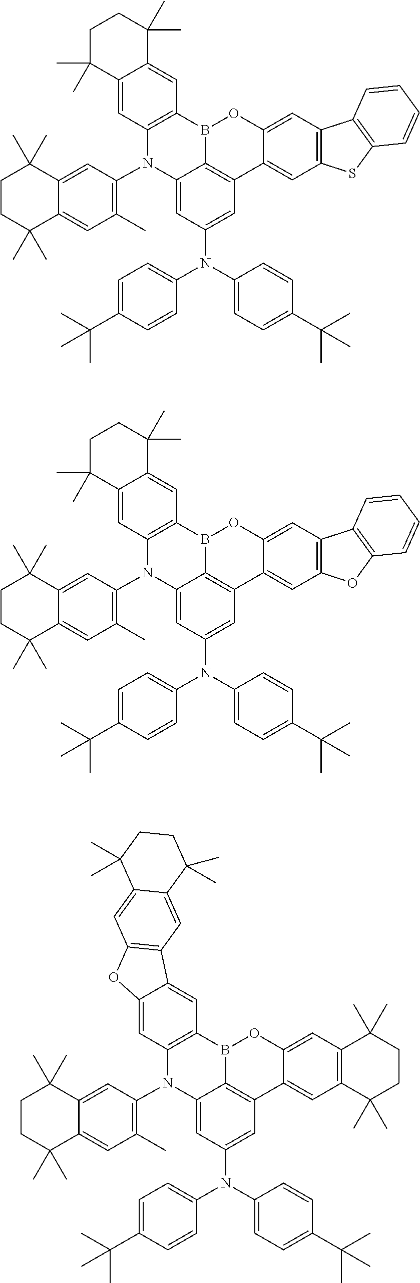 [SMILES: Cc1cc2c(cc1N1c3cc4c(cc3B3Oc5cc6c(cc5-c5cc(N(c7ccc(C(C)(C)C)cc7)c7ccc(C(C)(C)C)cc7)cc1c53)sc1ccccc16)C(C)(C)CCC4(C)C)C(C)(C)CCC2(C)C ; Cc1cc2c(cc1N1c3cc4c(cc3B3Oc5cc6c(cc5-c5cc(N(c7ccc(C(C)(C)C)cc7)c7ccc(C(C)(C)C)cc7)cc1c53)oc1ccccc16)C(C)(C)CCC4(C)C)C(C)(C)CCC2(C)C ; Cc1cc2c(cc1N1c3cc4oc5cc6c(cc5c4cc3B3Oc4cc5c(cc4-c4cc(N(c7ccc(C(C)(C)C)cc7)c7ccc(C(C)(C)C)cc7)cc1c43)C(C)(C)CCC5(C)C)C(C)(C)CCC6(C)C)C(C)(C)CCC2(C)C]

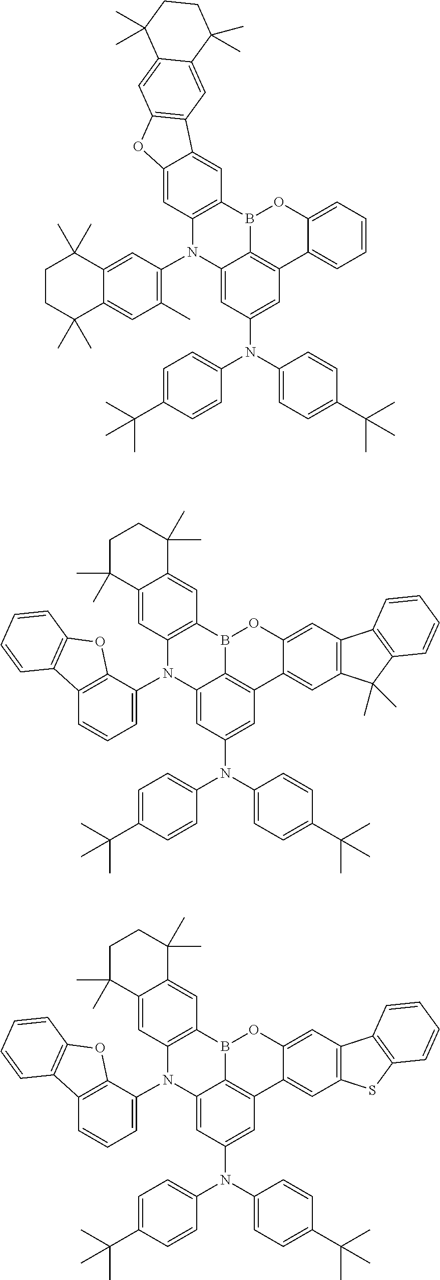 [SMILES: Cc1cc2c(cc1N1c3cc4oc5cc6c(cc5c4cc3B3Oc4ccccc4-c4cc(N(c5ccc(C(C)(C)C)cc5)c5ccc(C(C)(C)C)cc5)cc1c43)C(C)(C)CCC6(C)C)C(C)(C)CCC2(C)C ; CC(C)(C)c1ccc(N(c2ccc(C(C)(C)C)cc2)c2cc3c4c(c2)N(c2cccc5c2oc2ccccc25)c2cc5c(cc2B4Oc2cc4c(cc2-3)C(C)(C)c2ccccc2-4)C(C)(C)CCC5(C)C)cc1 ; CC(C)(C)c1ccc(N(c2ccc(C(C)(C)C)cc2)c2cc3c4c(c2)N(c2cccc5c2oc2ccccc25)c2cc5c(cc2B4Oc2cc4c(cc2-3)sc2ccccc24)C(C)(C)CCC5(C)C)cc1]

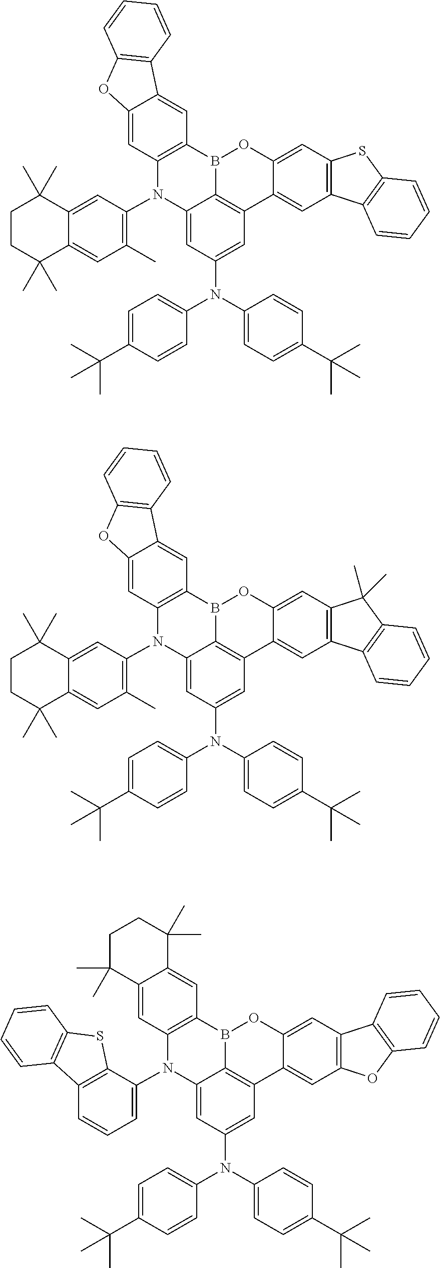 [SMILES: Cc1cc2c(cc1N1c3cc4oc5ccccc5c4cc3B3Oc4cc5sc6ccccc6c5cc4-c4cc(N(c5ccc(C(C)(C)C)cc5)c5ccc(C(C)(C)C)cc5)cc1c43)C(C)(C)CCC2(C)C ; Cc1cc2c(cc1N1c3cc4oc5ccccc5c4cc3B3Oc4cc5c(cc4-c4cc(N(c6ccc(C(C)(C)C)cc6)c6ccc(C(C)(C)C)cc6)cc1c43)-c1ccccc1C5(C)C)C(C)(C)CCC2(C)C ; CC(C)(C)c1ccc(N(c2ccc(C(C)(C)C)cc2)c2cc3c4c(c2)N(c2cccc5c2sc2ccccc25)c2cc5c(cc2B4Oc2cc4c(cc2-3)oc2ccccc24)C(C)(C)CCC5(C)C)cc1]

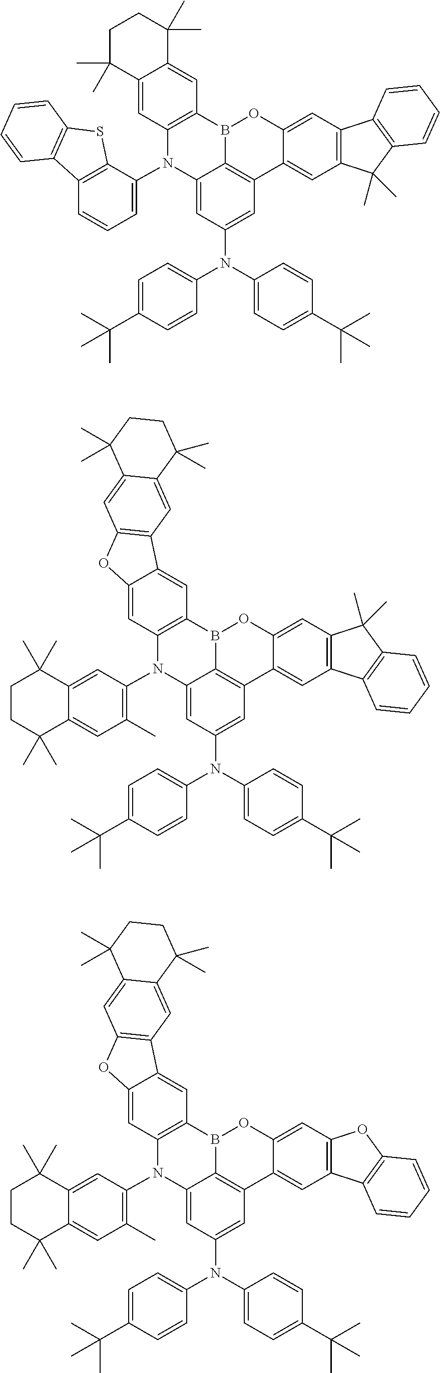 [SMILES: CC(C)(C)c1ccc(N(c2ccc(C(C)(C)C)cc2)c2cc3c4c(c2)N(c2cccc5c2sc2ccccc25)c2cc5c(cc2B4Oc2cc4c(cc2-3)C(C)(C)c2ccccc2-4)C(C)(C)CCC5(C)C)cc1 ; Cc1cc2c(cc1N1c3cc4oc5cc6c(cc5c4cc3B3Oc4cc5c(cc4-c4cc(N(c7ccc(C(C)(C)C)cc7)c7ccc(C(C)(C)C)cc7)cc1c43)-c1ccccc1C5(C)C)C(C)(C)CCC6(C)C)C(C)(C)CCC2(C)C ; Cc1cc2c(cc1N1c3cc4oc5cc6c(cc5c4cc3B3Oc4cc5oc7ccccc7c5cc4-c4cc(N(c5ccc(C(C)(C)C)cc5)c5ccc(C(C)(C)C)cc5)cc1c43)C(C)(C)CCC6(C)C)C(C)(C)CCC2(C)C]

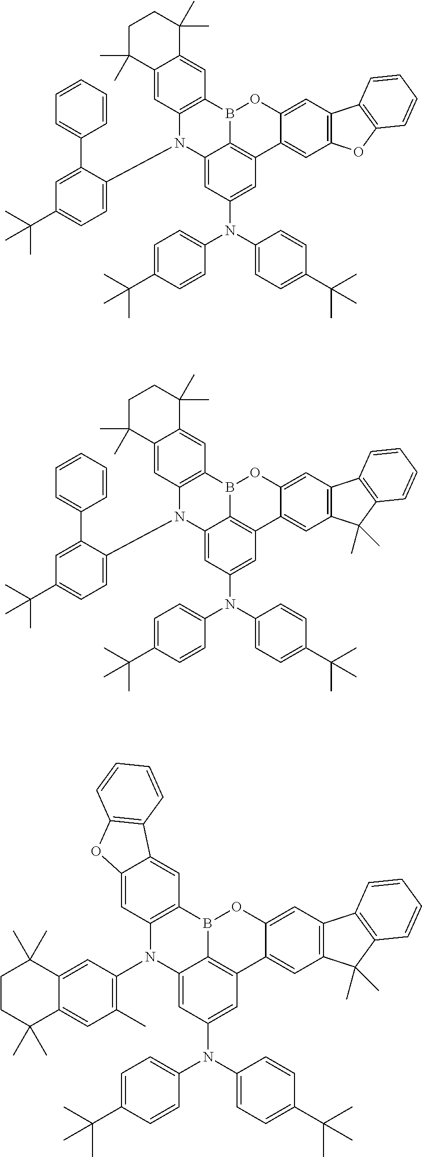 [SMILES: CC(C)(C)c1ccc(N(c2ccc(C(C)(C)C)cc2)c2cc3c4c(c2)N(c2ccc(C(C)(C)C)cc2-c2ccccc2)c2cc5c(cc2B4Oc2cc4c(cc2-3)oc2ccccc24)C(C)(C)CCC5(C)C)cc1 ; CC(C)(C)c1ccc(N(c2ccc(C(C)(C)C)cc2)c2cc3c4c(c2)N(c2ccc(C(C)(C)C)cc2-c2ccccc2)c2cc5c(cc2B4Oc2cc4c(cc2-3)C(C)(C)c2ccccc2-4)C(C)(C)CCC5(C)C)cc1 ; Cc1cc2c(cc1N1c3cc4oc5ccccc5c4cc3B3Oc4cc5c(cc4-c4cc(N(c6ccc(C(C)(C)C)cc6)c6ccc(C(C)(C)C)cc6)cc1c43)C(C)(C)c1ccccc1-5)C(C)(C)CCC2(C)C]

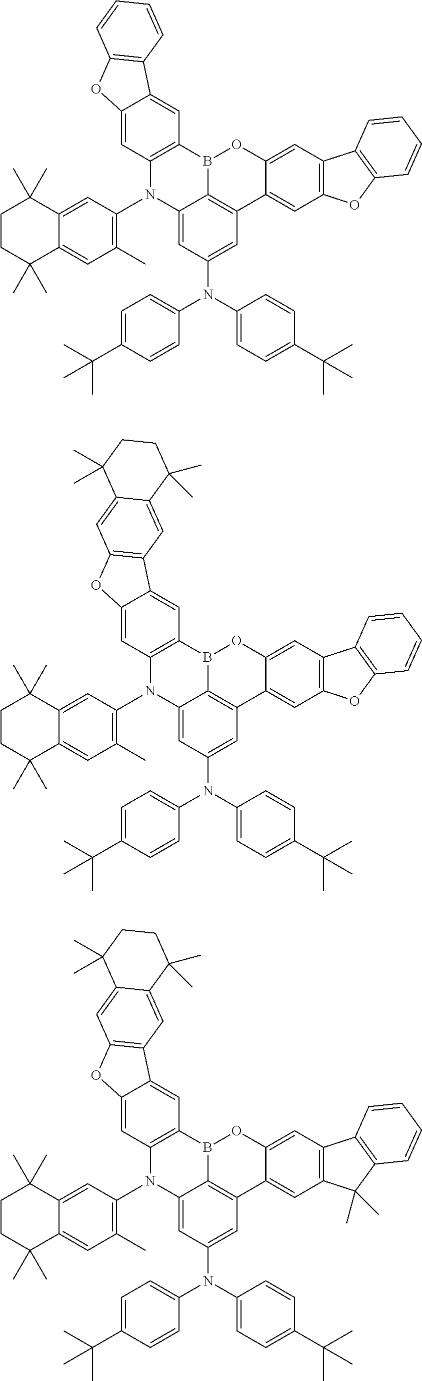 [SMILES: Cc1cc2c(cc1N1c3cc4oc5ccccc5c4cc3B3Oc4cc5c(cc4-c4cc(N(c6ccc(C(C)(C)C)cc6)c6ccc(C(C)(C)C)cc6)cc1c43)oc1ccccc15)C(C)(C)CCC2(C)C ; Cc1cc2c(cc1N1c3cc4oc5cc6c(cc5c4cc3B3Oc4cc5c(cc4-c4cc(N(c7ccc(C(C)(C)C)cc7)c7ccc(C(C)(C)C)cc7)cc1c43)oc1ccccc15)C(C)(C)CCC6(C)C)C(C)(C)CCC2(C)C ; Cc1cc2c(cc1N1c3cc4oc5cc6c(cc5c4cc3B3Oc4cc5c(cc4-c4cc(N(c7ccc(C(C)(C)C)cc7)c7ccc(C(C)(C)C)cc7)cc1c43)C(C)(C)c1ccccc1-5)C(C)(C)CCC6(C)C)C(C)(C)CCC2(C)C]

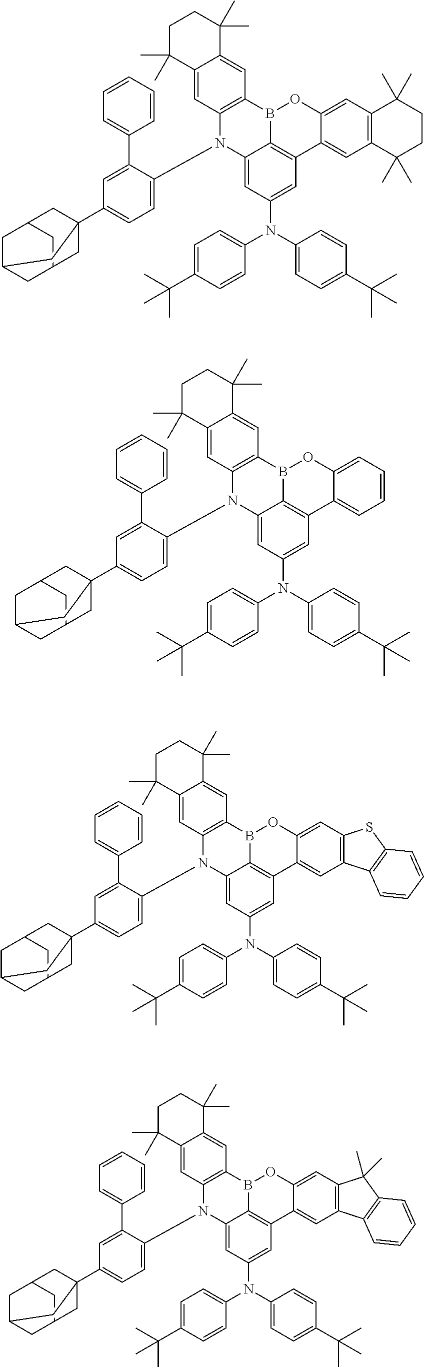

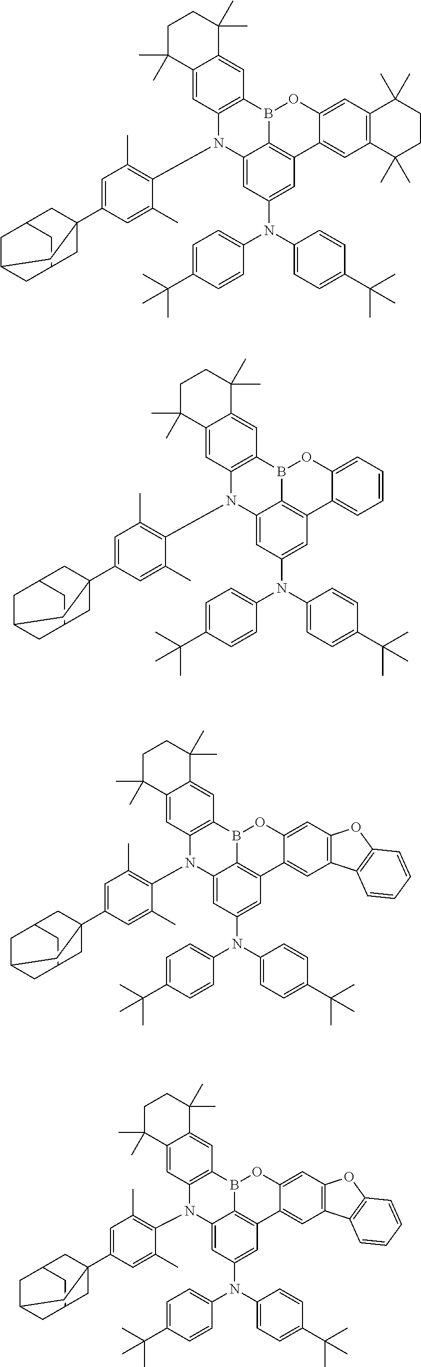

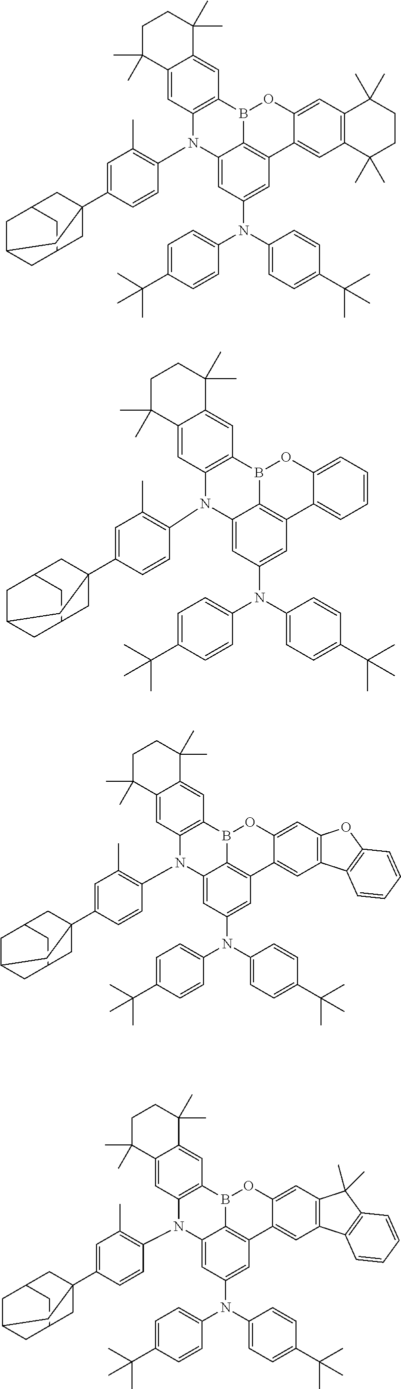

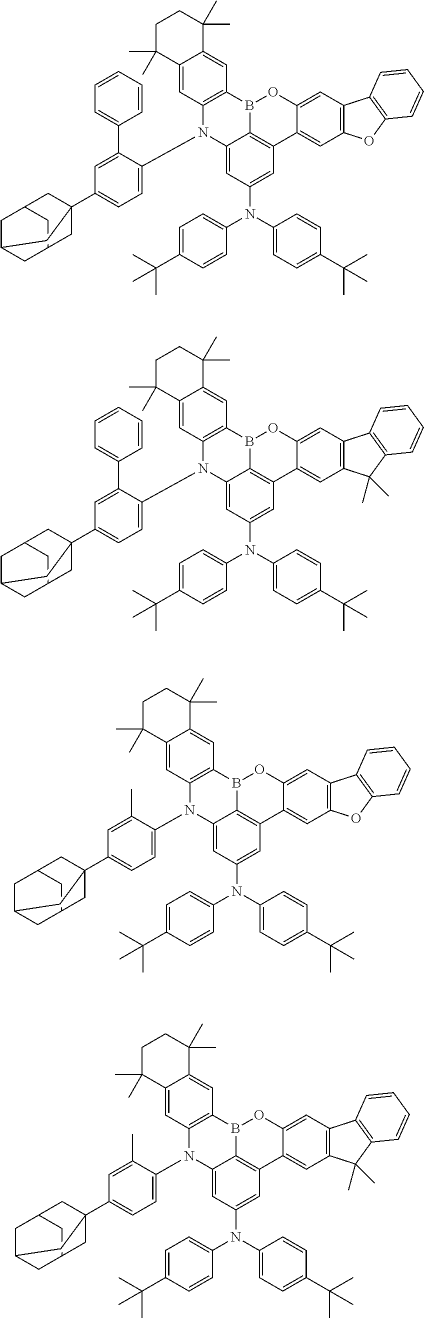

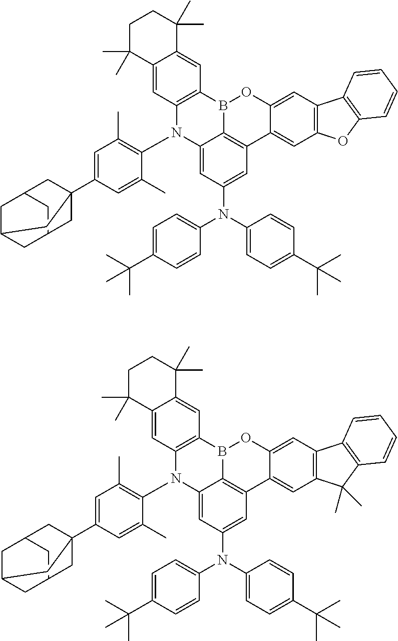 [SMILES: Cc1cc(C23CC4CC(CC(C4)C2)C3)cc(C)c1N1c2cc3c(cc2B2Oc4cc5c(cc4-c4cc(N(c6ccc(C(C)(C)C)cc6)c6ccc(C(C)(C)C)cc6)cc1c42)oc1ccccc15)C(C)(C)CCC3(C)C ; Cc1cc(C23CC4CC(CC(C4)C2)C3)cc(C)c1N1c2cc3c(cc2B2Oc4cc5c(cc4-c4cc(N(c6ccc(C(C)(C)C)cc6)c6ccc(C(C)(C)C)cc6)cc1c42)C(C)(C)c1ccccc1-5)C(C)(C)CCC3(C)C]

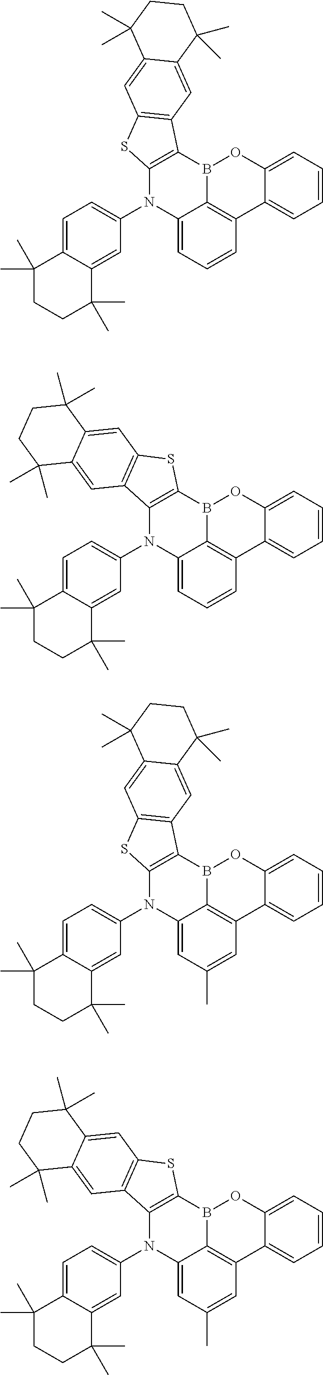

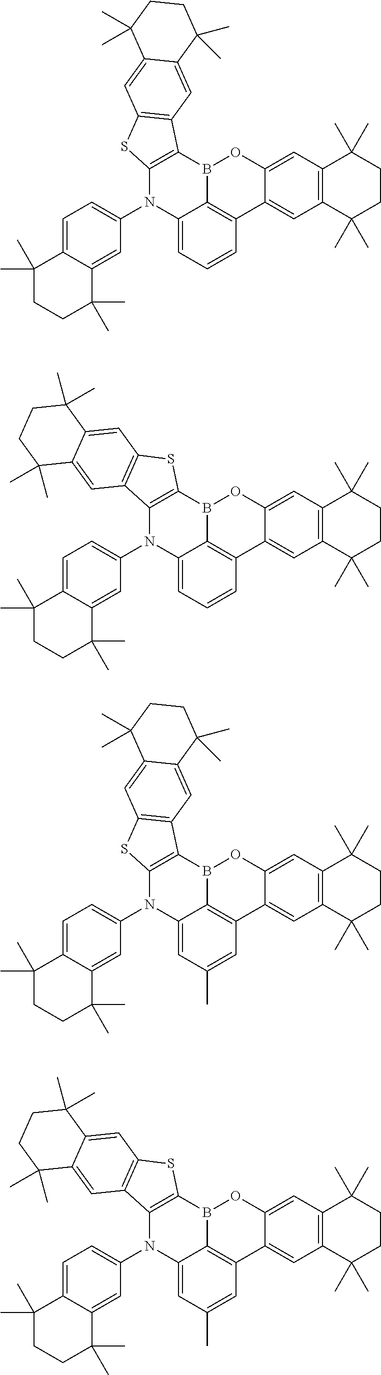

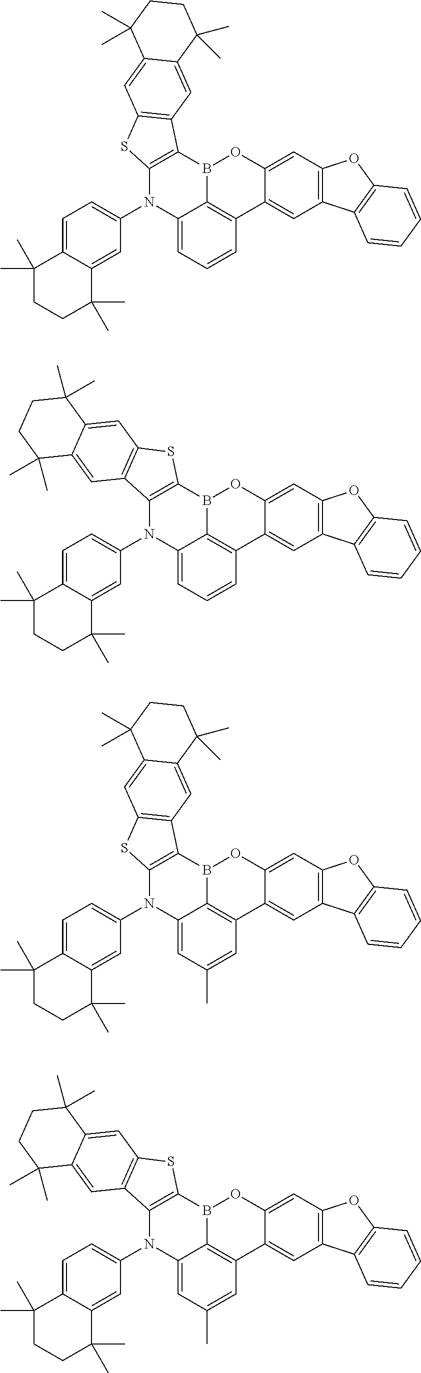 [SMILES: CC1(C)CCC(C)(C)c2cc(N3c4cccc5c4B(Oc4cc6oc7ccccc7c6cc4-5)c4c3sc3cc5c(cc43)C(C)(C)CCC5(C)C)ccc21 ; CC1(C)CCC(C)(C)c2cc(N3c4cccc5c4B(Oc4cc6oc7ccccc7c6cc4-5)c4sc5cc6c(cc5c43)C(C)(C)CCC6(C)C)ccc21 ; Cc1cc2c3c(c1)N(c1ccc4c(c1)C(C)(C)CCC4(C)C)c1sc4cc5c(cc4c1B3Oc1cc3oc4ccccc4c3cc1-2)C(C)(C)CCC5(C)C ; Cc1cc2c3c(c1)N(c1ccc4c(c1)C(C)(C)CCC4(C)C)c1c(sc4cc5c(cc14)C(C)(C)CCC5(C)C)B3Oc1cc3oc4ccccc4c3cc1-2]

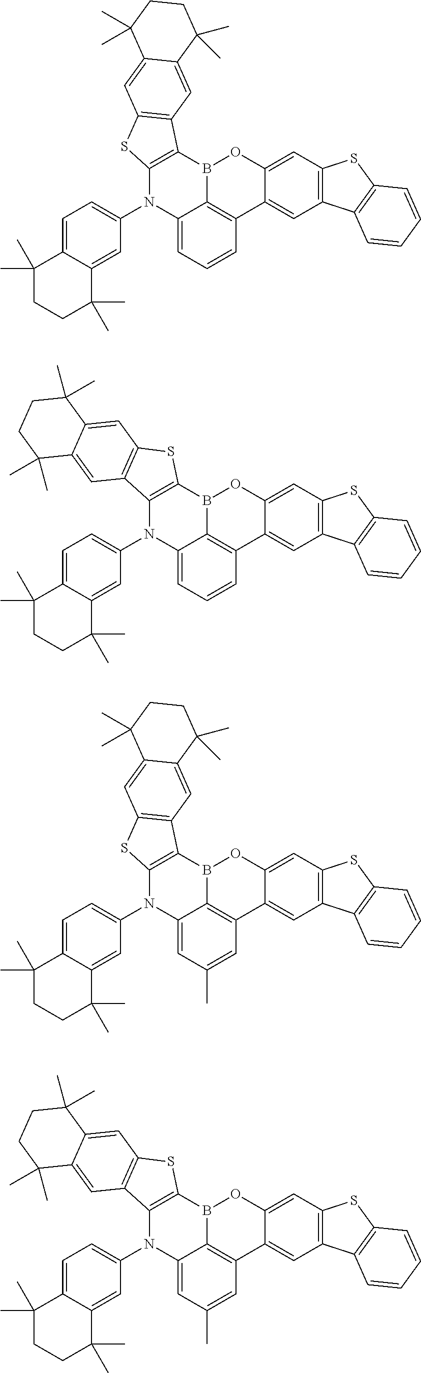 [SMILES: CC1(C)CCC(C)(C)c2cc(N3c4cccc5c4B(Oc4cc6sc7ccccc7c6cc4-5)c4c3sc3cc5c(cc43)C(C)(C)CCC5(C)C)ccc21 ; CC1(C)CCC(C)(C)c2cc(N3c4cccc5c4B(Oc4cc6sc7ccccc7c6cc4-5)c4sc5cc6c(cc5c43)C(C)(C)CCC6(C)C)ccc21 ; Cc1cc2c3c(c1)N(c1ccc4c(c1)C(C)(C)CCC4(C)C)c1sc4cc5c(cc4c1B3Oc1cc3sc4ccccc4c3cc1-2)C(C)(C)CCC5(C)C ; Cc1cc2c3c(c1)N(c1ccc4c(c1)C(C)(C)CCC4(C)C)c1c(sc4cc5c(cc14)C(C)(C)CCC5(C)C)B3Oc1cc3sc4ccccc4c3cc1-2]

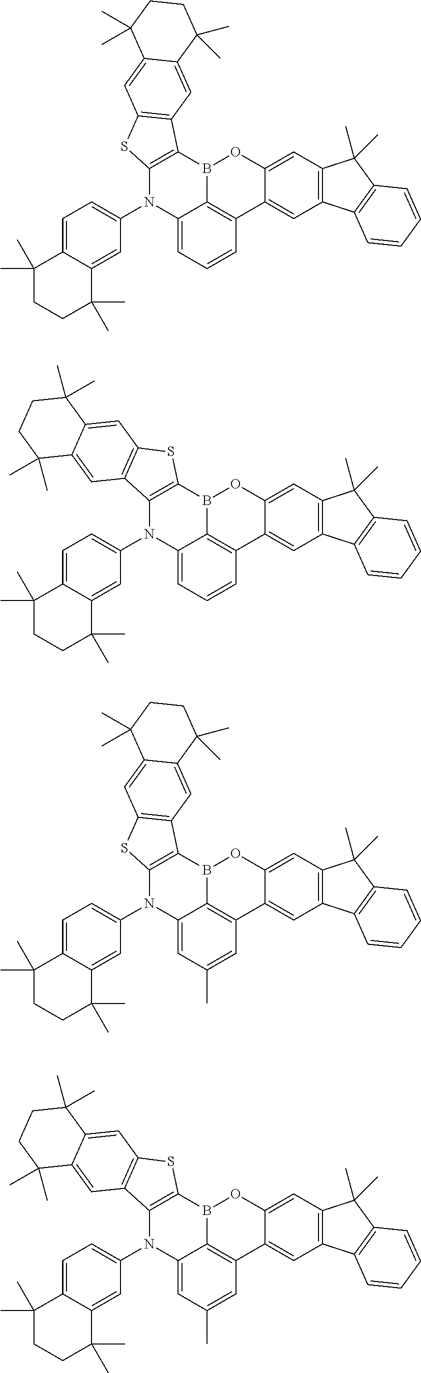 [SMILES: CC1(C)CCC(C)(C)c2cc(N3c4cccc5c4B(Oc4cc6c(cc4-5)-c4ccccc4C6(C)C)c4c3sc3cc5c(cc43)C(C)(C)CCC5(C)C)ccc21 ; CC1(C)CCC(C)(C)c2cc(N3c4cccc5c4B(Oc4cc6c(cc4-5)-c4ccccc4C6(C)C)c4sc5cc6c(cc5c43)C(C)(C)CCC6(C)C)ccc21 ; Cc1cc2c3c(c1)N(c1ccc4c(c1)C(C)(C)CCC4(C)C)c1sc4cc5c(cc4c1B3Oc1cc3c(cc1-2)-c1ccccc1C3(C)C)C(C)(C)CCC5(C)C ; Cc1cc2c3c(c1)N(c1ccc4c(c1)C(C)(C)CCC4(C)C)c1c(sc4cc5c(cc14)C(C)(C)CCC5(C)C)B3Oc1cc3c(cc1-2)-c1ccccc1C3(C)C]

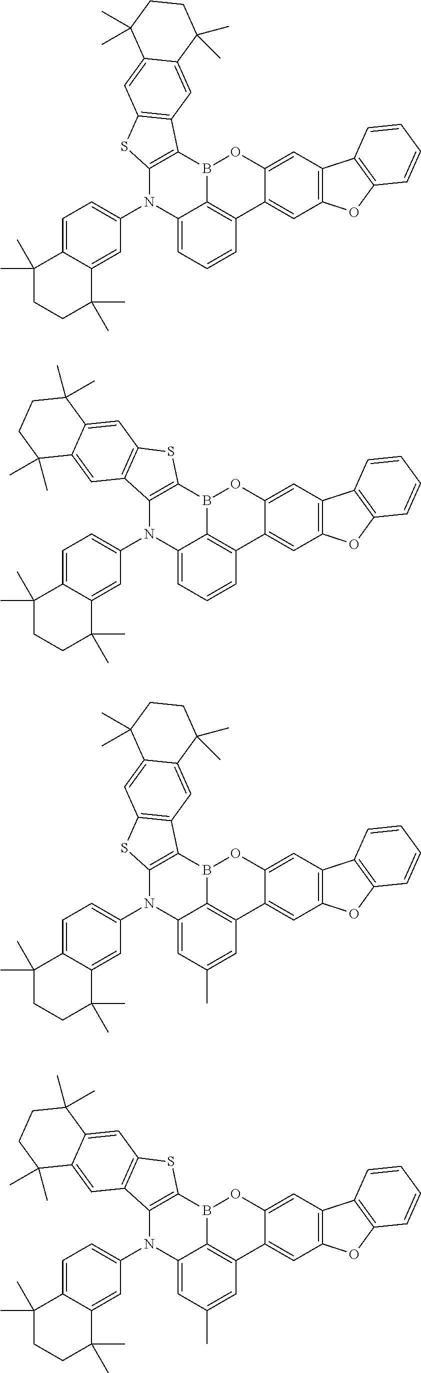 [SMILES: CC1(C)CCC(C)(C)c2cc(N3c4cccc5c4B(Oc4cc6c(cc4-5)oc4ccccc46)c4c3sc3cc5c(cc43)C(C)(C)CCC5(C)C)ccc21 ; CC1(C)CCC(C)(C)c2cc(N3c4cccc5c4B(Oc4cc6c(cc4-5)oc4ccccc46)c4sc5cc6c(cc5c43)C(C)(C)CCC6(C)C)ccc21 ; Cc1cc2c3c(c1)N(c1ccc4c(c1)C(C)(C)CCC4(C)C)c1sc4cc5c(cc4c1B3Oc1cc3c(cc1-2)oc1ccccc13)C(C)(C)CCC5(C)C ; Cc1cc2c3c(c1)N(c1ccc4c(c1)C(C)(C)CCC4(C)C)c1c(sc4cc5c(cc14)C(C)(C)CCC5(C)C)B3Oc1cc3c(cc1-2)oc1ccccc13]

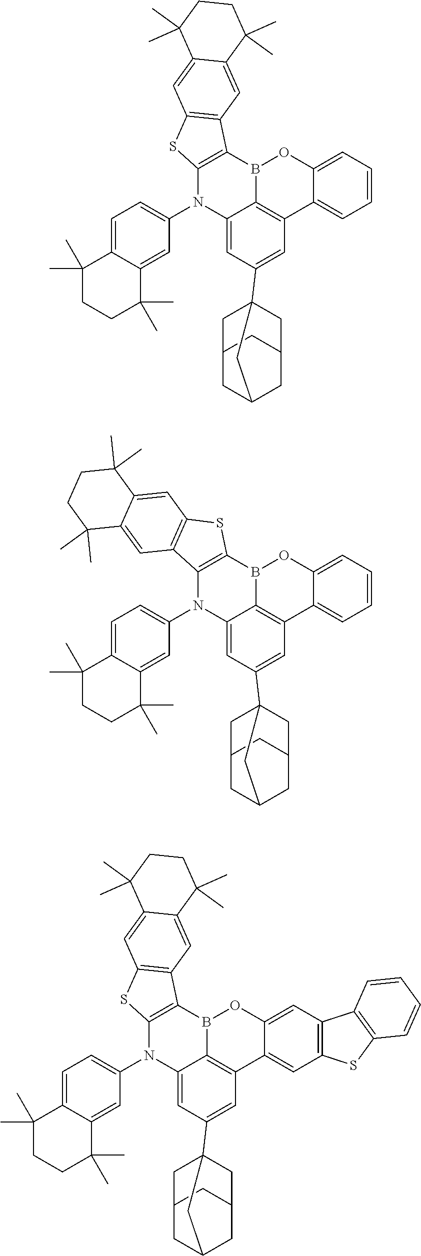 [SMILES: CC1(C)CCC(C)(C)c2cc(N3c4cc(C56CC7CC(CC(C7)C5)C6)cc5c4B(Oc4ccccc4-5)c4c3sc3cc5c(cc43)C(C)(C)CCC5(C)C)ccc21 ; CC1(C)CCC(C)(C)c2cc(N3c4cc(C56CC7CC(CC(C7)C5)C6)cc5c4B(Oc4ccccc4-5)c4sc5cc6c(cc5c43)C(C)(C)CCC6(C)C)ccc21 ; CC1(C)CCC(C)(C)c2cc(N3c4cc(C56CC7CC(CC(C7)C5)C6)cc5c4B(Oc4cc6c(cc4-5)sc4ccccc46)c4c3sc3cc5c(cc43)C(C)(C)CCC5(C)C)ccc21]

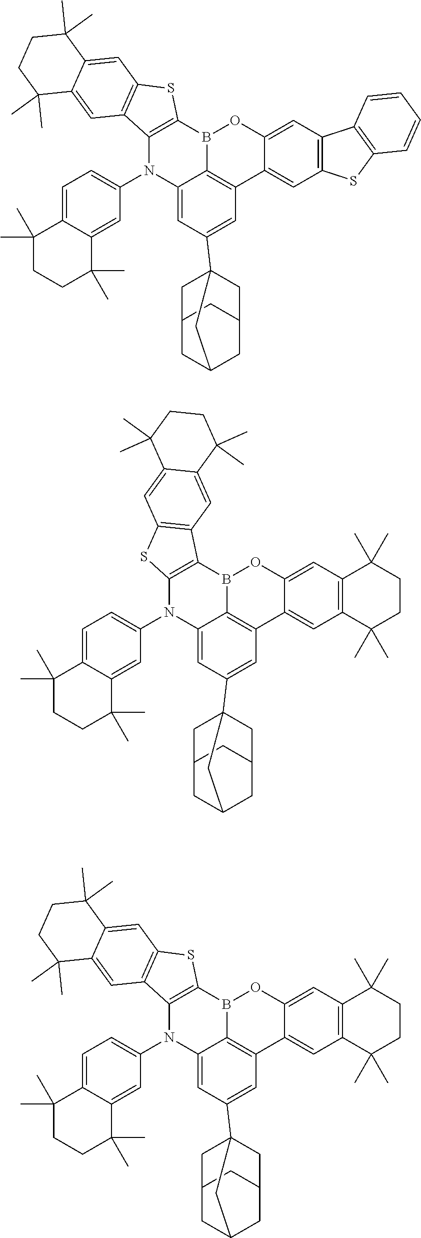

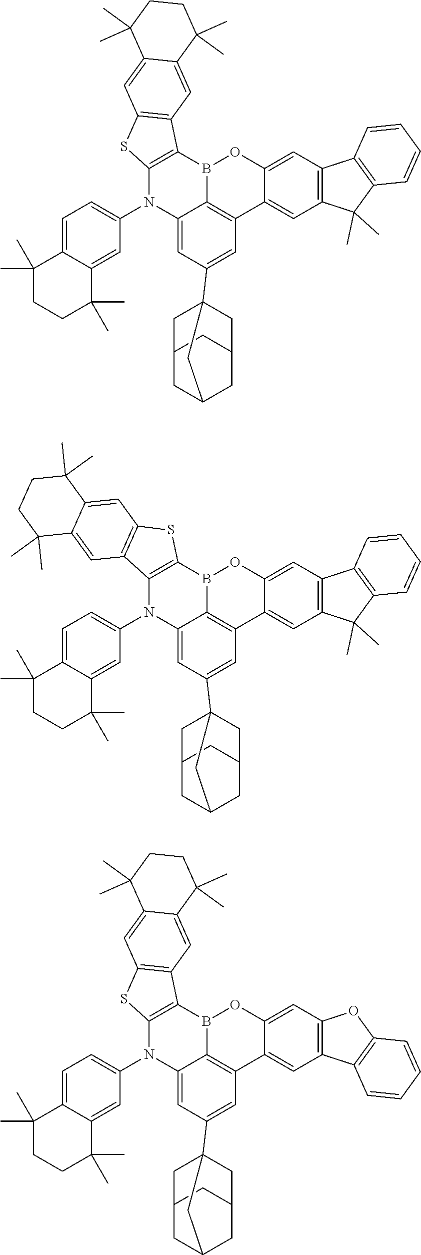 [SMILES: CC1(C)CCC(C)(C)c2cc(N3c4cc(C56CC7CC(CC(C7)C5)C6)cc5c4B(Oc4cc6c(cc4-5)C(C)(C)c4ccccc4-6)c4c3sc3cc5c(cc43)C(C)(C)CCC5(C)C)ccc21 ; CC1(C)CCC(C)(C)c2cc(N3c4cc(C56CC7CC(CC(C7)C5)C6)cc5c4B(Oc4cc6c(cc4-5)C(C)(C)c4ccccc4-6)c4sc5cc6c(cc5c43)C(C)(C)CCC6(C)C)ccc21 ; CC1(C)CCC(C)(C)c2cc(N3c4cc(C56CC7CC(CC(C7)C5)C6)cc5c4B(Oc4cc6oc7ccccc7c6cc4-5)c4c3sc3cc5c(cc43)C(C)(C)CCC5(C)C)ccc21]

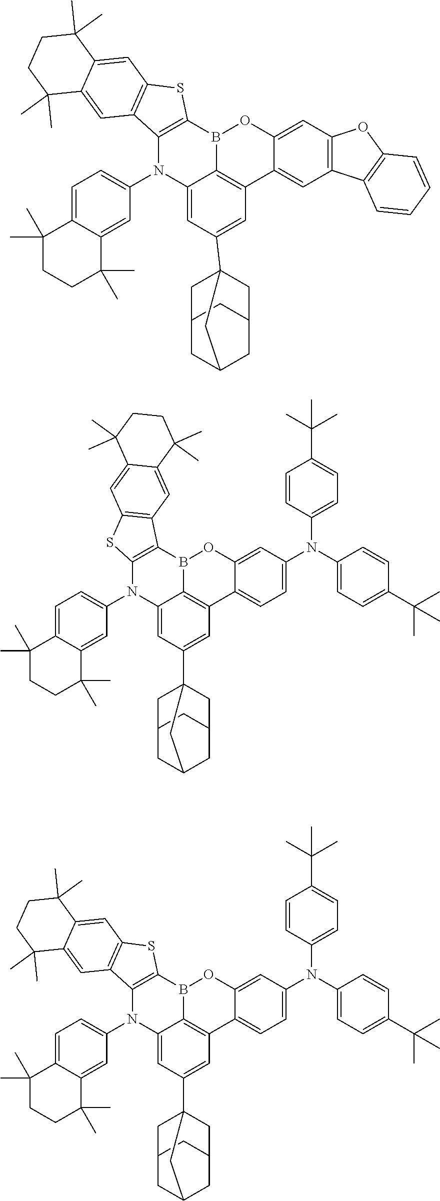

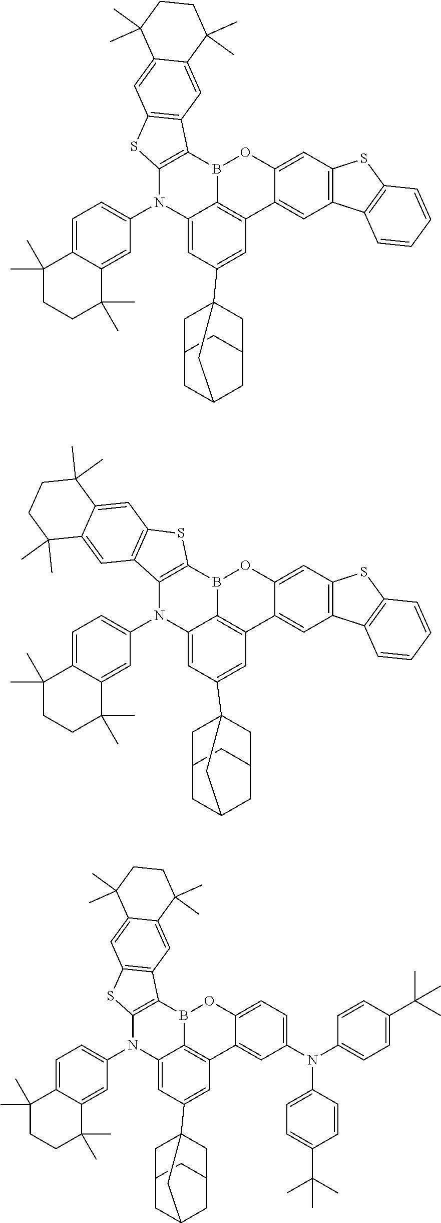 [SMILES: CC1(C)CCC(C)(C)c2cc(N3c4cc(C56CC7CC(CC(C7)C5)C6)cc5c4B(Oc4cc6sc7ccccc7c6cc4-5)c4c3sc3cc5c(cc43)C(C)(C)CCC5(C)C)ccc21 ; CC1(C)CCC(C)(C)c2cc(N3c4cc(C56CC7CC(CC(C7)C5)C6)cc5c4B(Oc4cc6sc7ccccc7c6cc4-5)c4sc5cc6c(cc5c43)C(C)(C)CCC6(C)C)ccc21 ; CC(C)(C)c1ccc(N(c2ccc(C(C)(C)C)cc2)c2ccc3c(c2)-c2cc(C45CC6CC(CC(C6)C4)C5)cc4c2B(O3)c2c(sc3cc5c(cc23)C(C)(C)CCC5(C)C)N4c2ccc3c(c2)C(C)(C)CCC3(C)C)cc1]

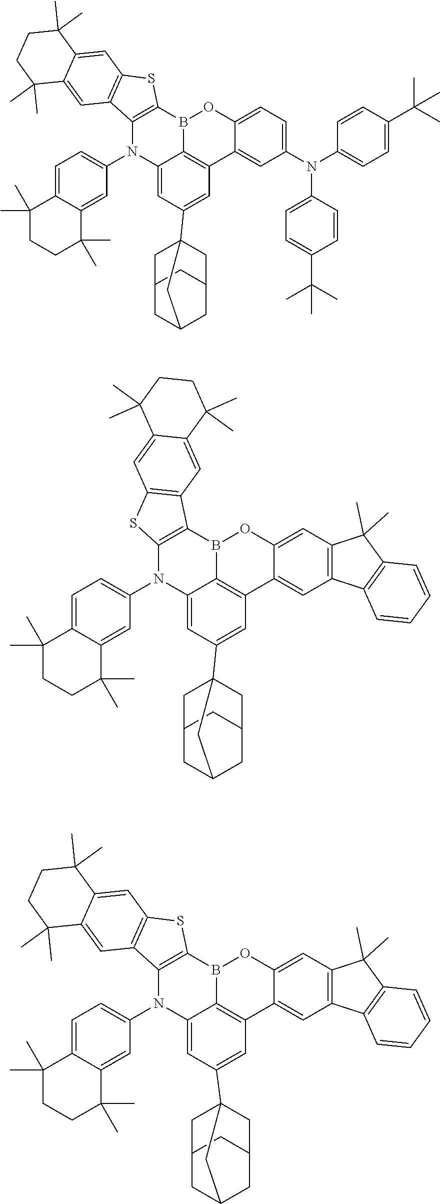

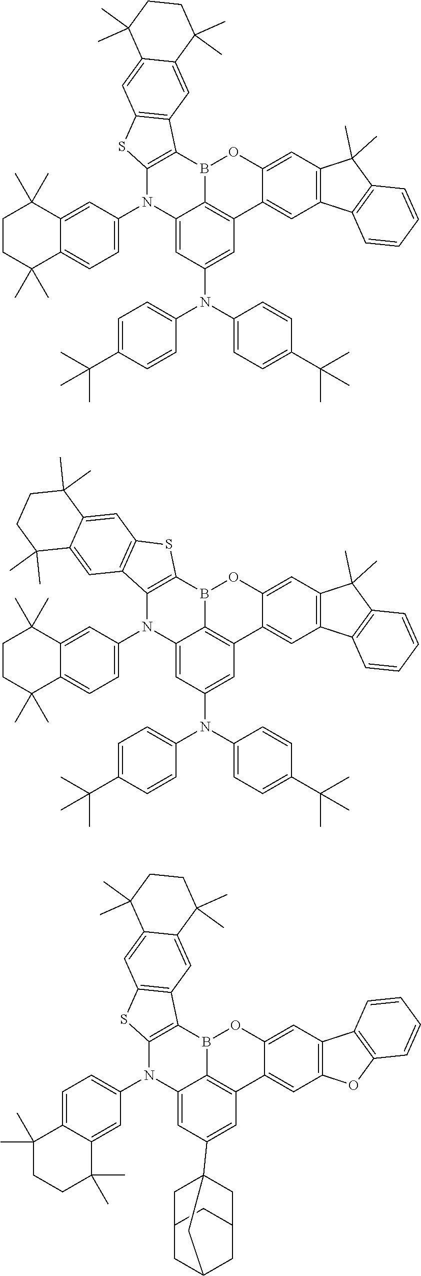 [SMILES: CC(C)(C)c1ccc(N(c2ccc(C(C)(C)C)cc2)c2cc3c4c(c2)N(c2ccc5c(c2)C(C)(C)CCC5(C)C)c2sc5cc6c(cc5c2B4Oc2cc4c(cc2-3)-c2ccccc2C4(C)C)C(C)(C)CCC6(C)C)cc1 ; CC(C)(C)c1ccc(N(c2ccc(C(C)(C)C)cc2)c2cc3c4c(c2)N(c2ccc5c(c2)C(C)(C)CCC5(C)C)c2c(sc5cc6c(cc25)C(C)(C)CCC6(C)C)B4Oc2cc4c(cc2-3)-c2ccccc2C4(C)C)cc1 ; CC1(C)CCC(C)(C)c2cc(N3c4cc(C56CC7CC(CC(C7)C5)C6)cc5c4B(Oc4cc6c(cc4-5)oc4ccccc46)c4c3sc3cc5c(cc43)C(C)(C)CCC5(C)C)ccc21]

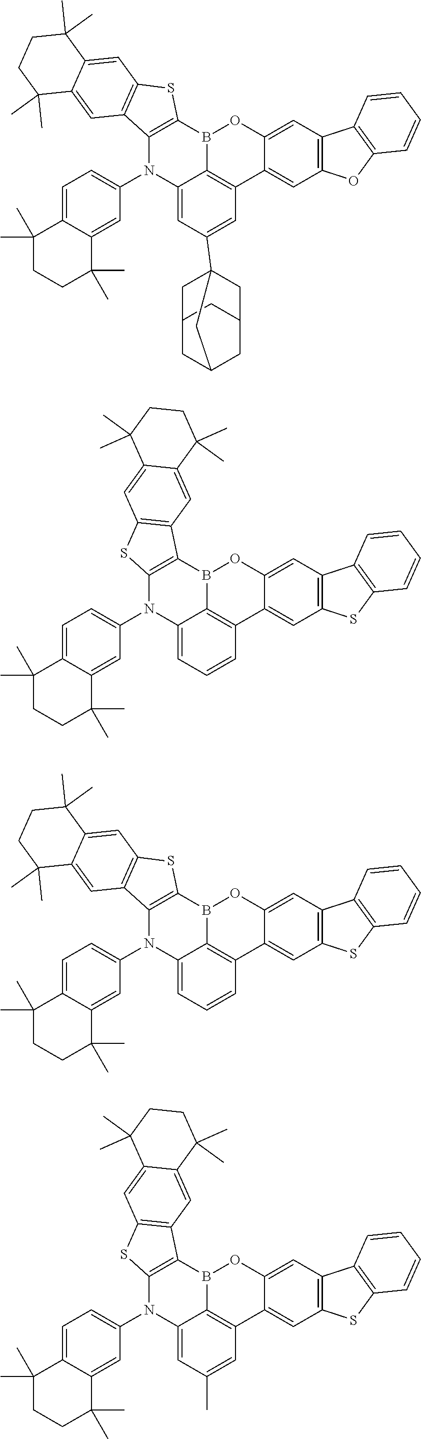

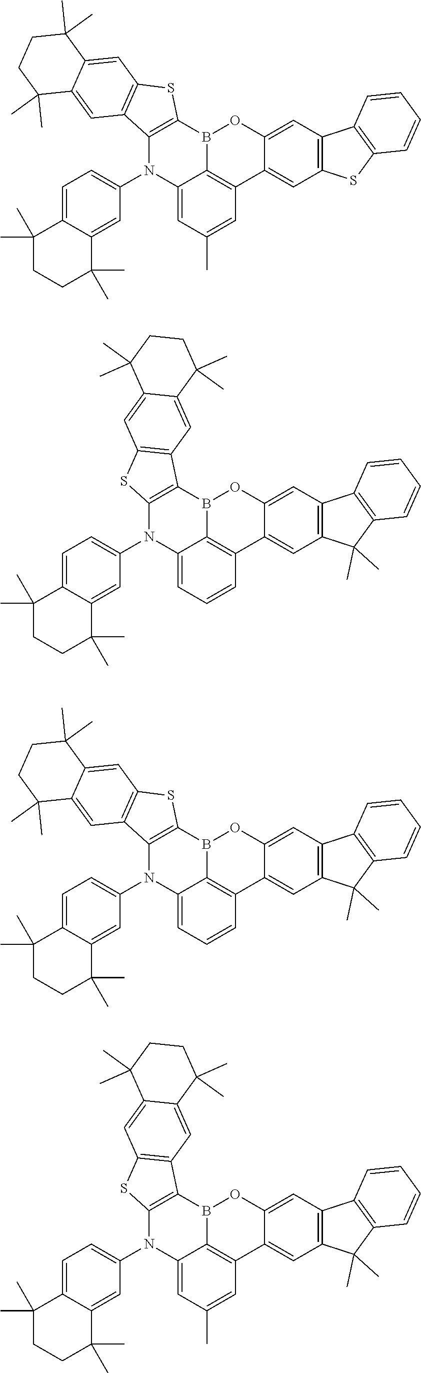

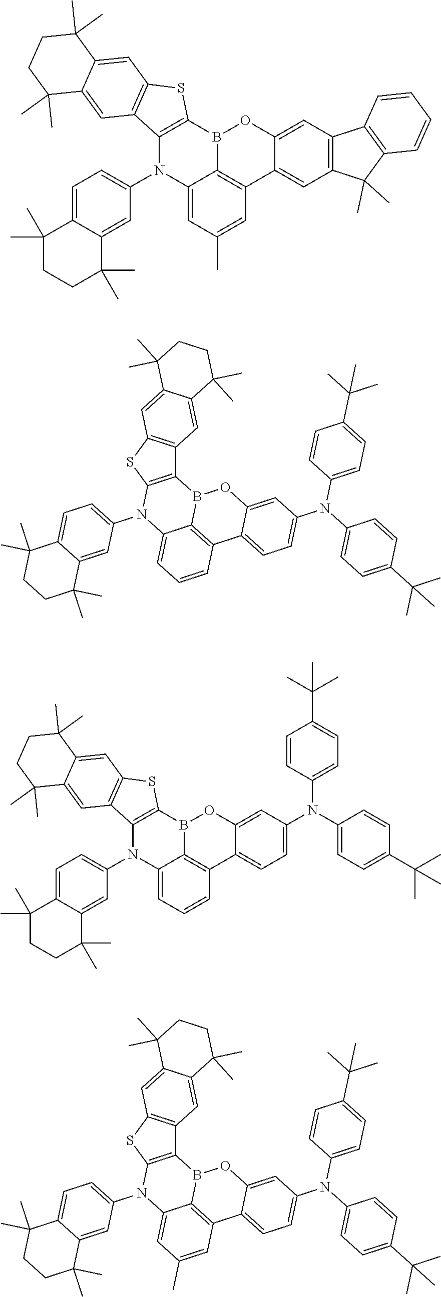

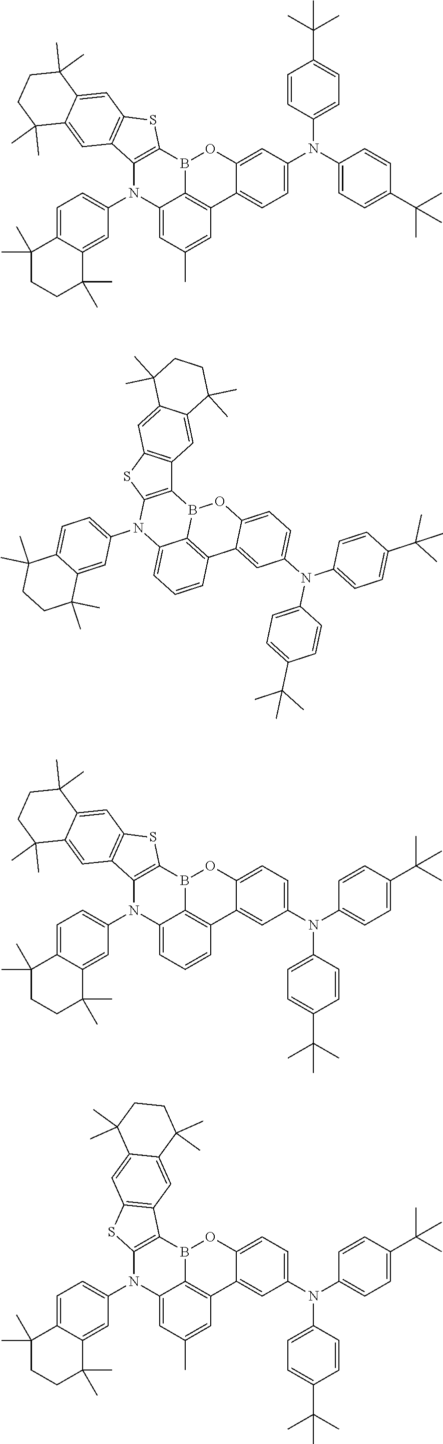

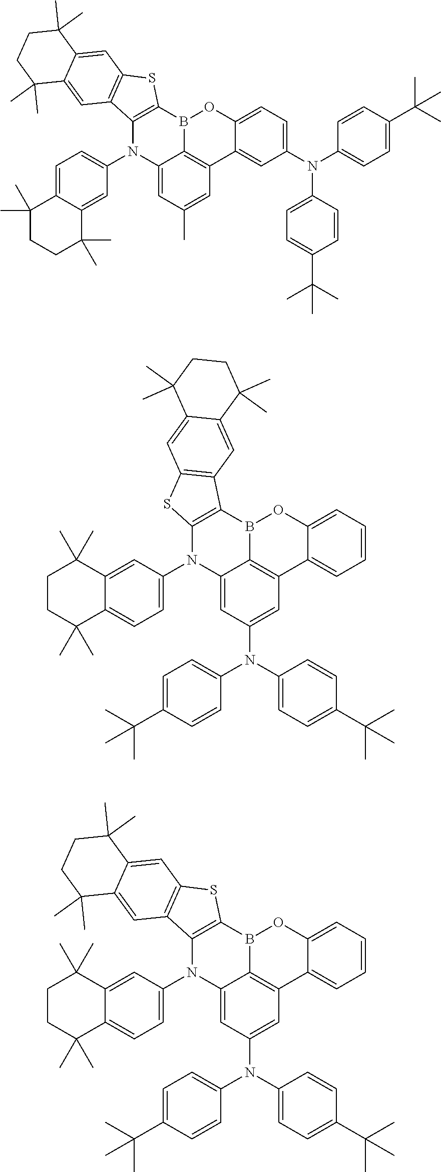 [SMILES: Cc1cc2c3c(c1)N(c1ccc4c(c1)C(C)(C)CCC4(C)C)c1c(sc4cc5c(cc14)C(C)(C)CCC5(C)C)B3Oc1ccc(N(c3ccc(C(C)(C)C)cc3)c3ccc(C(C)(C)C)cc3)cc1-2 ; CC(C)(C)c1ccc(N(c2ccc(C(C)(C)C)cc2)c2cc3c4c(c2)N(c2ccc5c(c2)C(C)(C)CCC5(C)C)c2sc5cc6c(cc5c2B4Oc2ccccc2-3)C(C)(C)CCC6(C)C)cc1 ; CC(C)(C)c1ccc(N(c2ccc(C(C)(C)C)cc2)c2cc3c4c(c2)N(c2ccc5c(c2)C(C)(C)CCC5(C)C)c2c(sc5cc6c(cc25)C(C)(C)CCC6(C)C)B4Oc2ccccc2-3)cc1]

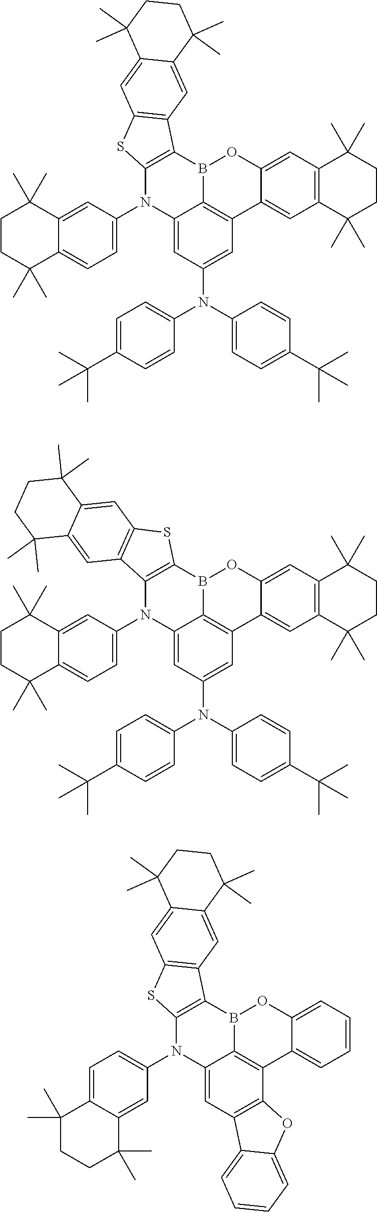 [SMILES: CC(C)(C)c1ccc(N(c2ccc(C(C)(C)C)cc2)c2cc3c4c(c2)N(c2ccc5c(c2)C(C)(C)CCC5(C)C)c2sc5cc6c(cc5c2B4Oc2cc4c(cc2-3)C(C)(C)CCC4(C)C)C(C)(C)CCC6(C)C)cc1 ; CC(C)(C)c1ccc(N(c2ccc(C(C)(C)C)cc2)c2cc3c4c(c2)N(c2ccc5c(c2)C(C)(C)CCC5(C)C)c2c(sc5cc6c(cc25)C(C)(C)CCC6(C)C)B4Oc2cc4c(cc2-3)C(C)(C)CCC4(C)C)cc1 ; CC1(C)CCC(C)(C)c2cc(N3c4cc5c(oc6ccccc65)c5c4B(Oc4ccccc4-5)c4c3sc3cc5c(cc43)C(C)(C)CCC5(C)C)ccc21]

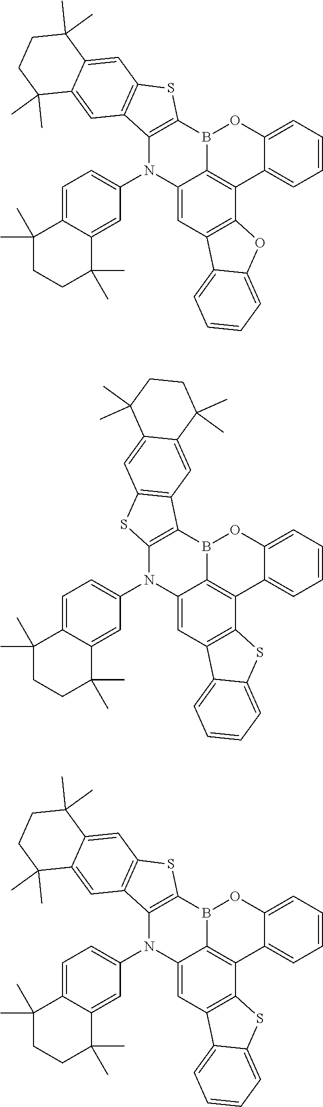 [SMILES: CC1(C)CCC(C)(C)c2cc(N3c4cc5c(oc6ccccc65)c5c4B(Oc4ccccc4-5)c4sc5cc6c(cc5c43)C(C)(C)CCC6(C)C)ccc21 ; CC1(C)CCC(C)(C)c2cc(N3c4cc5c(sc6ccccc65)c5c4B(Oc4ccccc4-5)c4c3sc3cc5c(cc43)C(C)(C)CCC5(C)C)ccc21 ; CC1(C)CCC(C)(C)c2cc(N3c4cc5c(sc6ccccc65)c5c4B(Oc4ccccc4-5)c4sc5cc6c(cc5c43)C(C)(C)CCC6(C)C)ccc21]

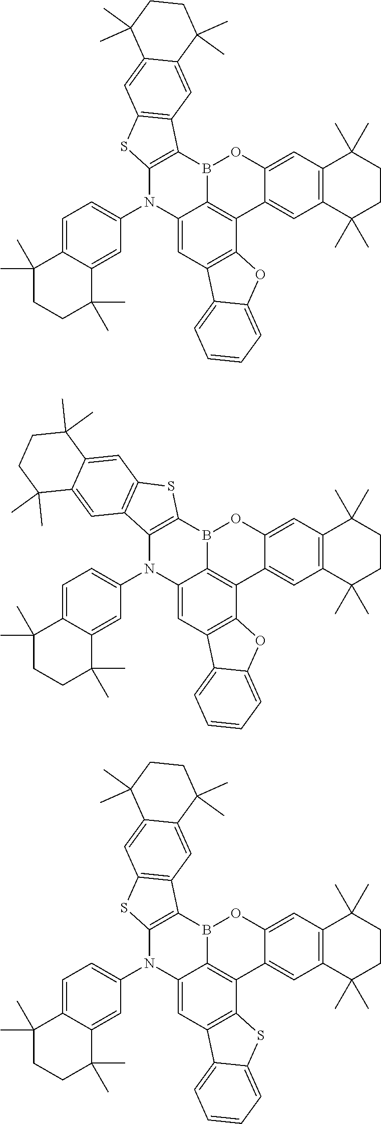 [SMILES: CC1(C)CCC(C)(C)c2cc(N3c4cc5c(oc6ccccc65)c5c4B(Oc4cc6c(cc4-5)C(C)(C)CCC6(C)C)c4c3sc3cc5c(cc43)C(C)(C)CCC5(C)C)ccc21 ; CC1(C)CCC(C)(C)c2cc(N3c4cc5c(oc6ccccc65)c5c4B(Oc4cc6c(cc4-5)C(C)(C)CCC6(C)C)c4sc5cc6c(cc5c43)C(C)(C)CCC6(C)C)ccc21 ; CC1(C)CCC(C)(C)c2cc(N3c4cc5c(sc6ccccc65)c5c4B(Oc4cc6c(cc4-5)C(C)(C)CCC6(C)C)c4c3sc3cc5c(cc43)C(C)(C)CCC5(C)C)ccc21]

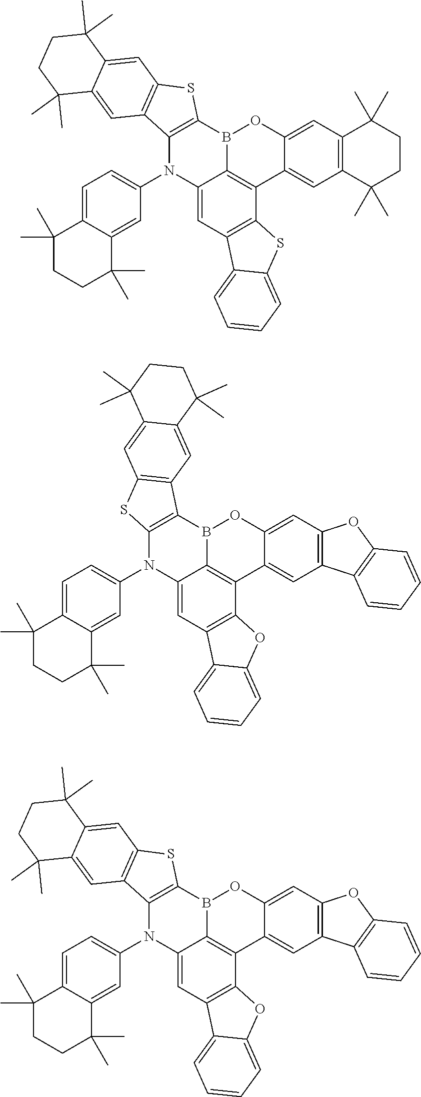 [SMILES: CC1(C)CCC(C)(C)c2cc(N3c4cc5c(sc6ccccc65)c5c4B(Oc4cc6c(cc4-5)C(C)(C)CCC6(C)C)c4sc5cc6c(cc5c43)C(C)(C)CCC6(C)C)ccc21 ; CC1(C)CCC(C)(C)c2cc(N3c4cc5c(oc6ccccc65)c5c4B(Oc4cc6oc7ccccc7c6cc4-5)c4c3sc3cc5c(cc43)C(C)(C)CCC5(C)C)ccc21 ; CC1(C)CCC(C)(C)c2cc(N3c4cc5c(oc6ccccc65)c5c4B(Oc4cc6oc7ccccc7c6cc4-5)c4sc5cc6c(cc5c43)C(C)(C)CCC6(C)C)ccc21]

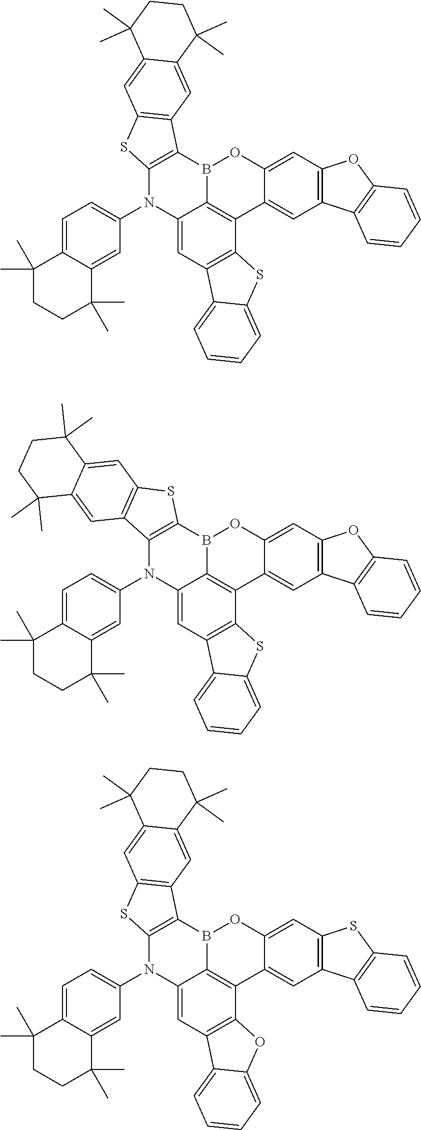 [SMILES: CC1(C)CCC(C)(C)c2cc(N3c4cc5c(sc6ccccc65)c5c4B(Oc4cc6oc7ccccc7c6cc4-5)c4c3sc3cc5c(cc43)C(C)(C)CCC5(C)C)ccc21 ; CC1(C)CCC(C)(C)c2cc(N3c4cc5c(sc6ccccc65)c5c4B(Oc4cc6oc7ccccc7c6cc4-5)c4sc5cc6c(cc5c43)C(C)(C)CCC6(C)C)ccc21 ; CC1(C)CCC(C)(C)c2cc(N3c4cc5c(oc6ccccc65)c5c4B(Oc4cc6sc7ccccc7c6cc4-5)c4c3sc3cc5c(cc43)C(C)(C)CCC5(C)C)ccc21]

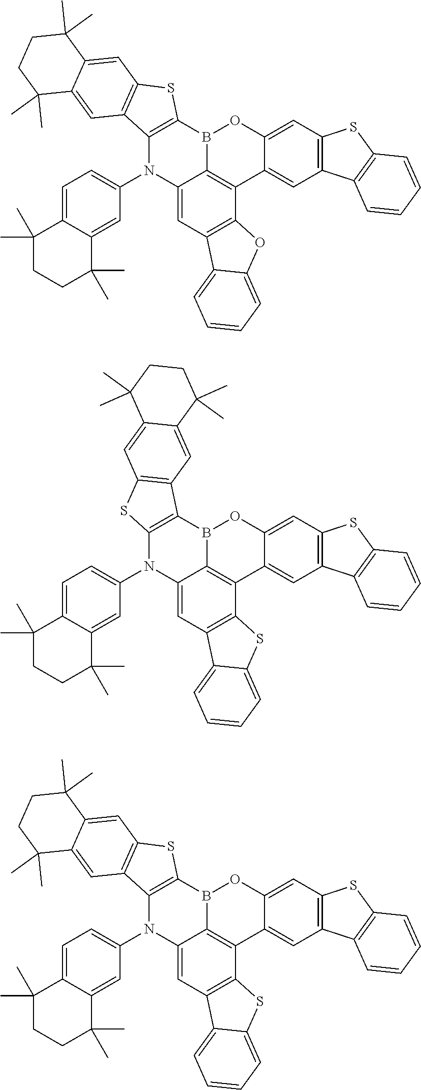 [SMILES: CC1(C)CCC(C)(C)c2cc(N3c4cc5c(oc6ccccc65)c5c4B(Oc4cc6sc7ccccc7c6cc4-5)c4sc5cc6c(cc5c43)C(C)(C)CCC6(C)C)ccc21 ; CC1(C)CCC(C)(C)c2cc(N3c4cc5c(sc6ccccc65)c5c4B(Oc4cc6sc7ccccc7c6cc4-5)c4c3sc3cc5c(cc43)C(C)(C)CCC5(C)C)ccc21 ; CC1(C)CCC(C)(C)c2cc(N3c4cc5c(sc6ccccc65)c5c4B(Oc4cc6sc7ccccc7c6cc4-5)c4sc5cc6c(cc5c43)C(C)(C)CCC6(C)C)ccc21]

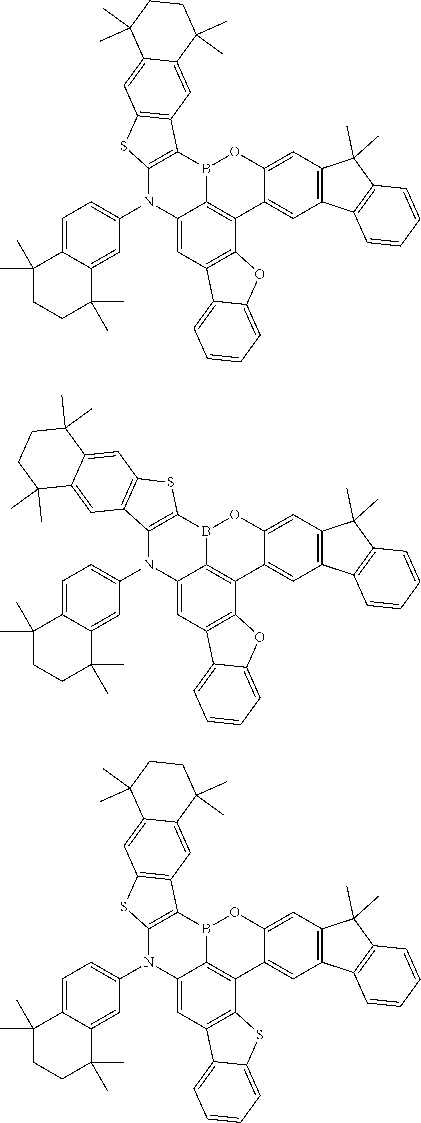 [SMILES: CC1(C)CCC(C)(C)c2cc(N3c4cc5c(oc6ccccc65)c5c4B(Oc4cc6c(cc4-5)-c4ccccc4C6(C)C)c4c3sc3cc5c(cc43)C(C)(C)CCC5(C)C)ccc21 ; CC1(C)CCC(C)(C)c2cc(N3c4cc5c(oc6ccccc65)c5c4B(Oc4cc6c(cc4-5)-c4ccccc4C6(C)C)c4sc5cc6c(cc5c43)C(C)(C)CCC6(C)C)ccc21 ; CC1(C)CCC(C)(C)c2cc(N3c4cc5c(sc6ccccc65)c5c4B(Oc4cc6c(cc4-5)-c4ccccc4C6(C)C)c4c3sc3cc5c(cc43)C(C)(C)CCC5(C)C)ccc21]

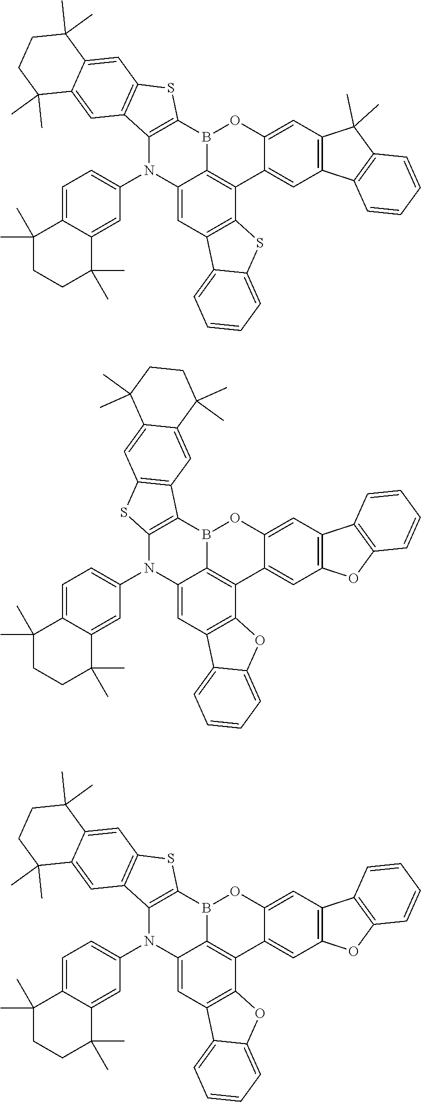 [SMILES: CC1(C)CCC(C)(C)c2cc(N3c4cc5c(sc6ccccc65)c5c4B(Oc4cc6c(cc4-5)-c4ccccc4C6(C)C)c4sc5cc6c(cc5c43)C(C)(C)CCC6(C)C)ccc21 ; CC1(C)CCC(C)(C)c2cc(N3c4cc5c(oc6ccccc65)c5c4B(Oc4cc6c(cc4-5)oc4ccccc46)c4c3sc3cc5c(cc43)C(C)(C)CCC5(C)C)ccc21 ; CC1(C)CCC(C)(C)c2cc(N3c4cc5c(oc6ccccc65)c5c4B(Oc4cc6c(cc4-5)oc4ccccc46)c4sc5cc6c(cc5c43)C(C)(C)CCC6(C)C)ccc21]

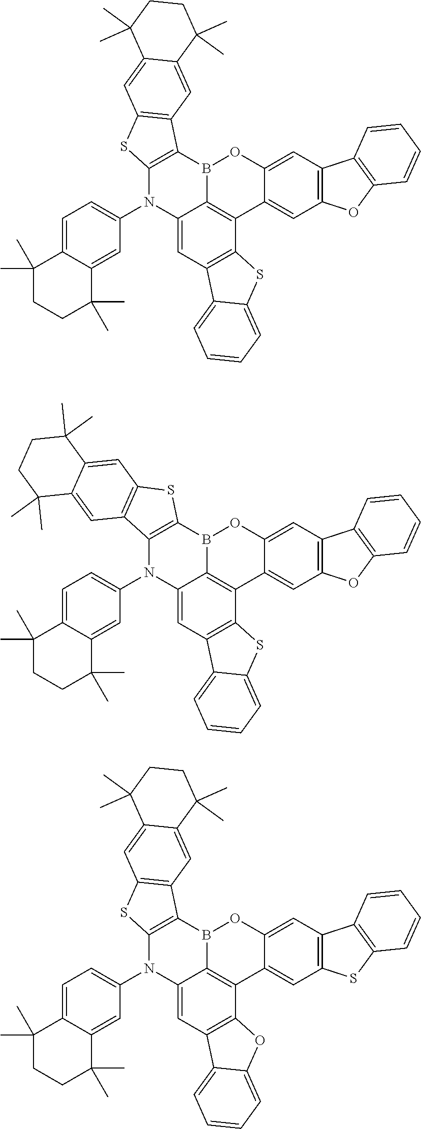 [SMILES: CC1(C)CCC(C)(C)c2cc(N3c4cc5c(sc6ccccc65)c5c4B(Oc4cc6c(cc4-5)oc4ccccc46)c4c3sc3cc5c(cc43)C(C)(C)CCC5(C)C)ccc21 ; CC1(C)CCC(C)(C)c2cc(N3c4cc5c(sc6ccccc65)c5c4B(Oc4cc6c(cc4-5)oc4ccccc46)c4sc5cc6c(cc5c43)C(C)(C)CCC6(C)C)ccc21 ; CC1(C)CCC(C)(C)c2cc(N3c4cc5c(oc6ccccc65)c5c4B(Oc4cc6c(cc4-5)sc4ccccc46)c4c3sc3cc5c(cc43)C(C)(C)CCC5(C)C)ccc21]

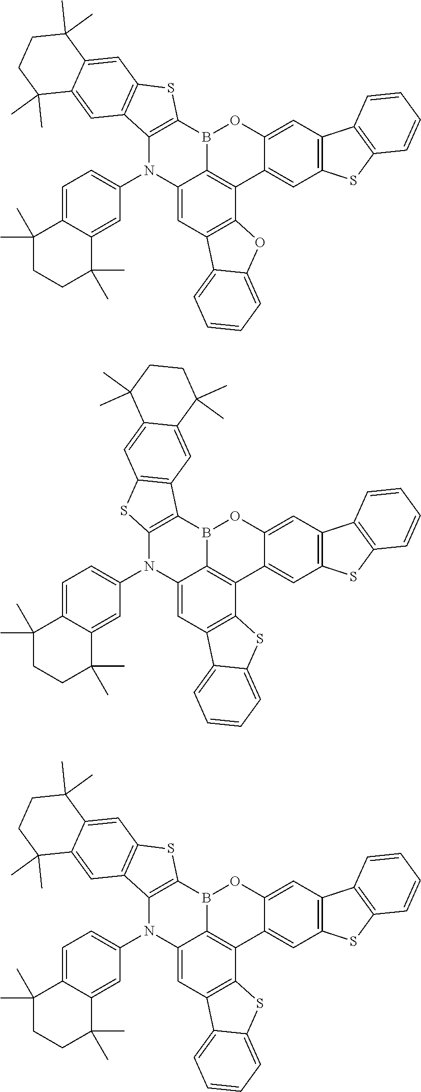 [SMILES: CC1(C)CCC(C)(C)c2cc(N3c4cc5c(oc6ccccc65)c5c4B(Oc4cc6c(cc4-5)sc4ccccc46)c4sc5cc6c(cc5c43)C(C)(C)CCC6(C)C)ccc21 ; CC1(C)CCC(C)(C)c2cc(N3c4cc5c(sc6ccccc65)c5c4B(Oc4cc6c(cc4-5)sc4ccccc46)c4c3sc3cc5c(cc43)C(C)(C)CCC5(C)C)ccc21 ; CC1(C)CCC(C)(C)c2cc(N3c4cc5c(sc6ccccc65)c5c4B(Oc4cc6c(cc4-5)sc4ccccc46)c4sc5cc6c(cc5c43)C(C)(C)CCC6(C)C)ccc21]

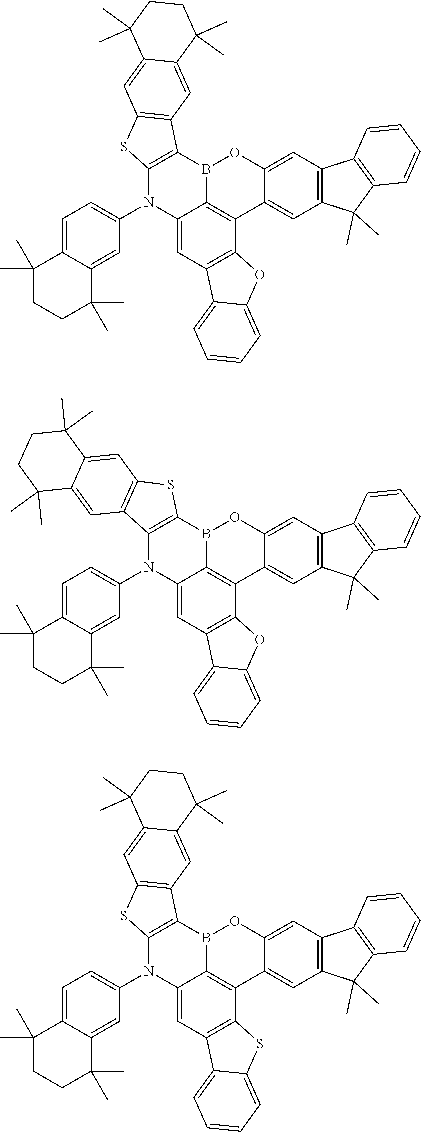 [SMILES: CC1(C)CCC(C)(C)c2cc(N3c4cc5c(oc6ccccc65)c5c4B(Oc4cc6c(cc4-5)C(C)(C)c4ccccc4-6)c4c3sc3cc5c(cc43)C(C)(C)CCC5(C)C)ccc21 ; CC1(C)CCC(C)(C)c2cc(N3c4cc5c(oc6ccccc65)c5c4B(Oc4cc6c(cc4-5)C(C)(C)c4ccccc4-6)c4sc5cc6c(cc5c43)C(C)(C)CCC6(C)C)ccc21 ; CC1(C)CCC(C)(C)c2cc(N3c4cc5c(sc6ccccc65)c5c4B(Oc4cc6c(cc4-5)C(C)(C)c4ccccc4-6)c4c3sc3cc5c(cc43)C(C)(C)CCC5(C)C)ccc21]

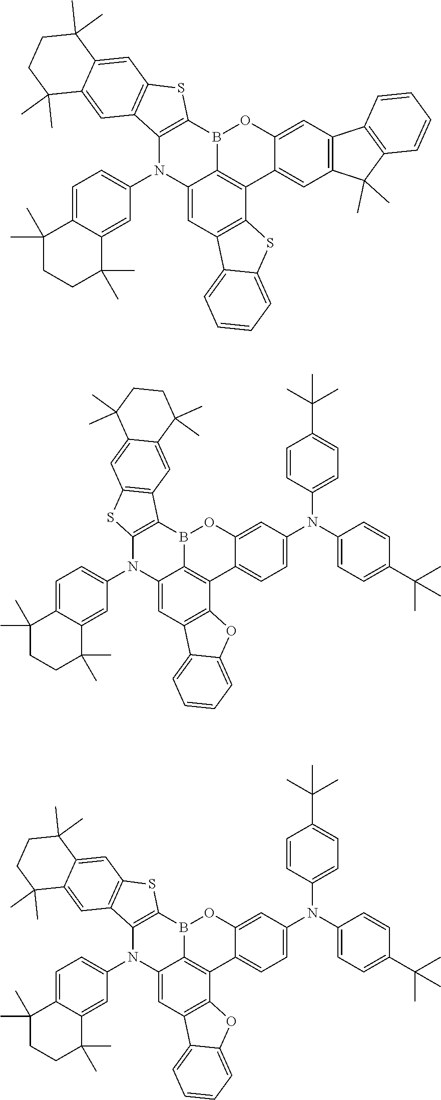

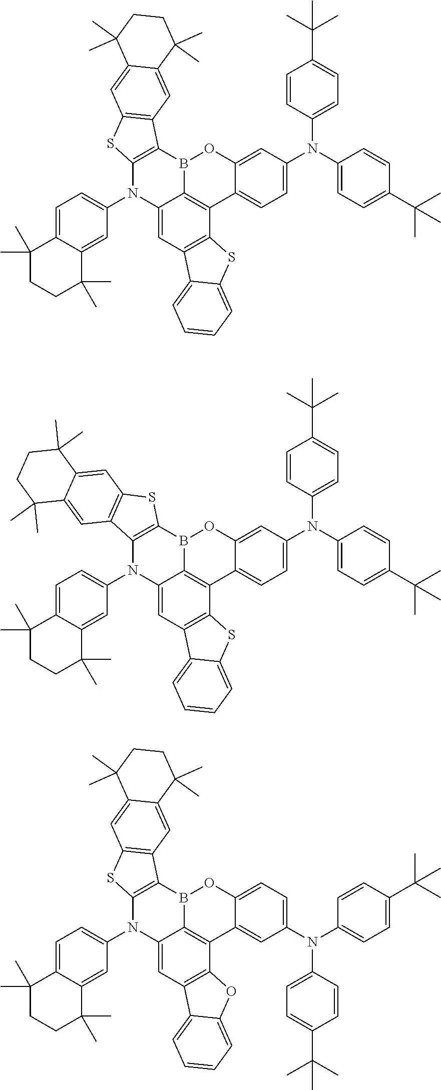

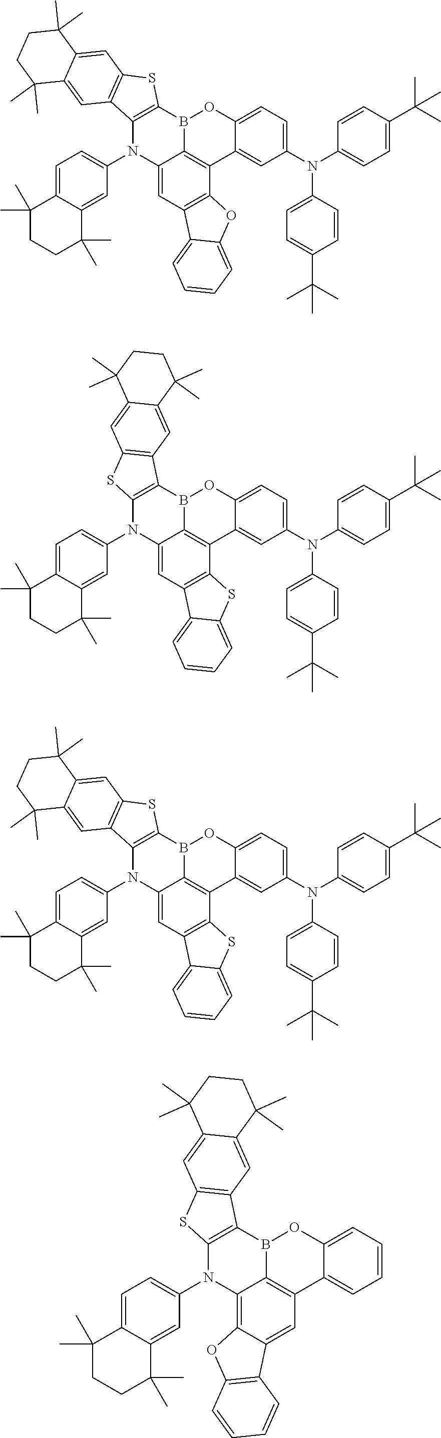

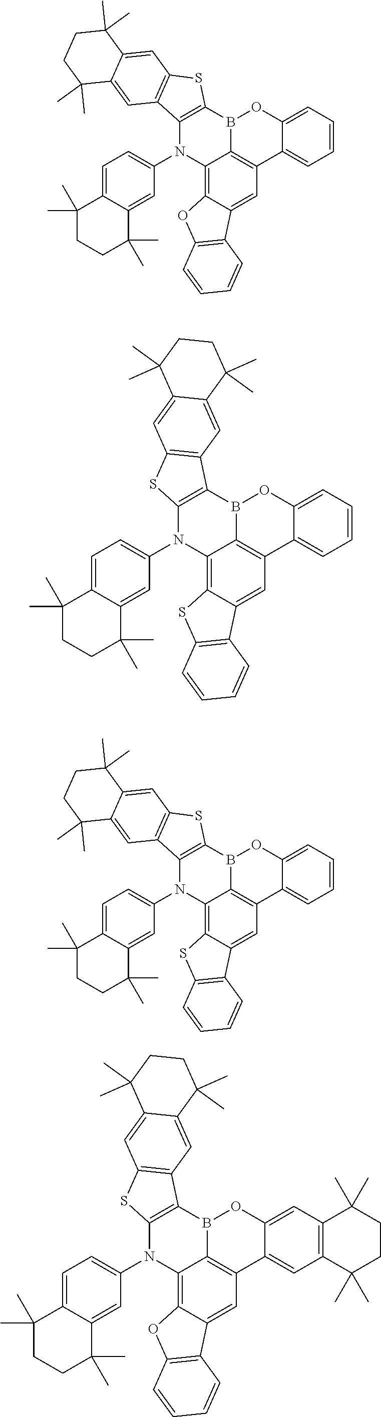

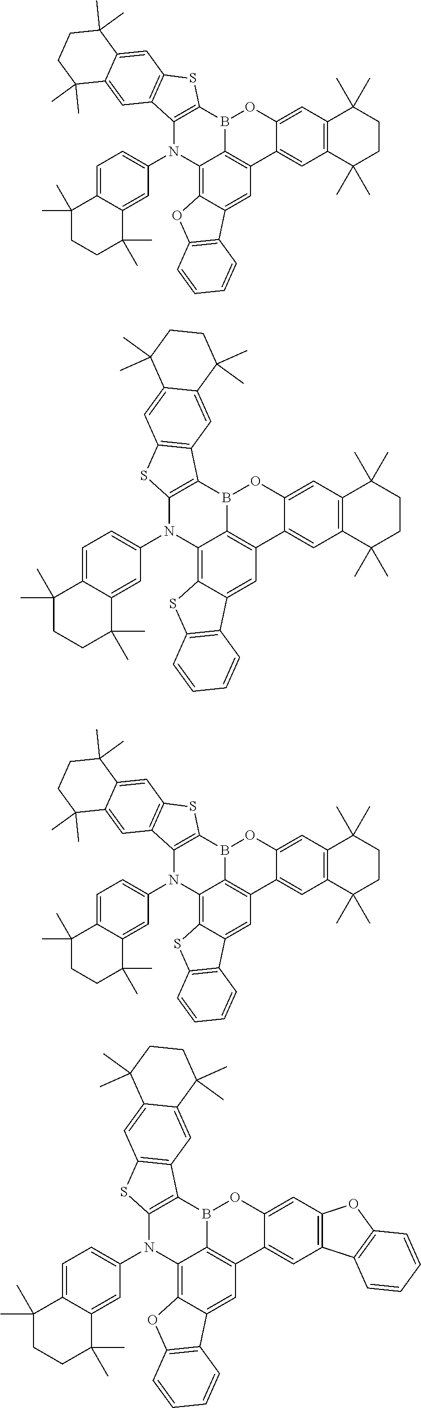

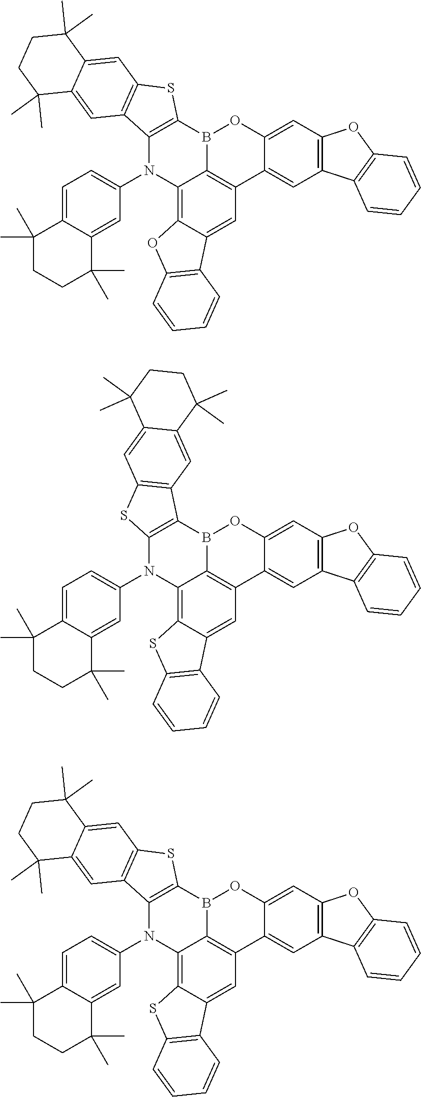

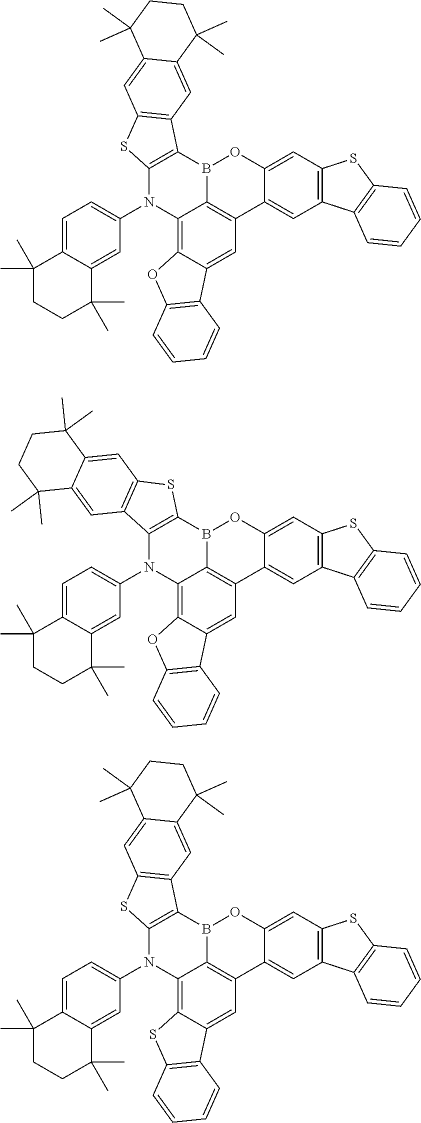

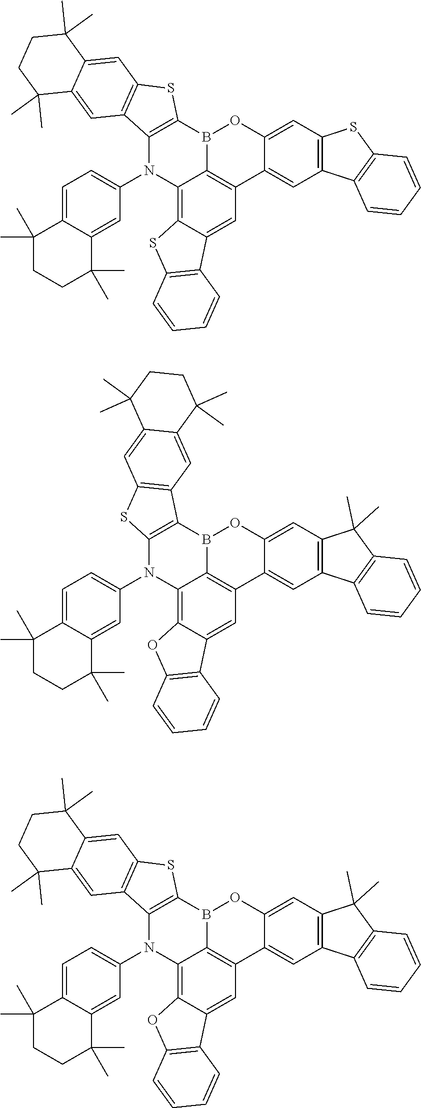

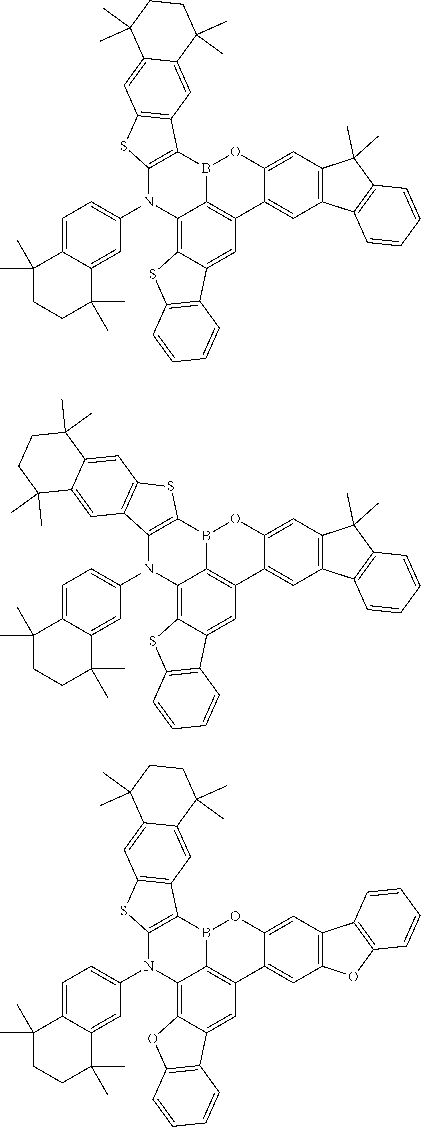

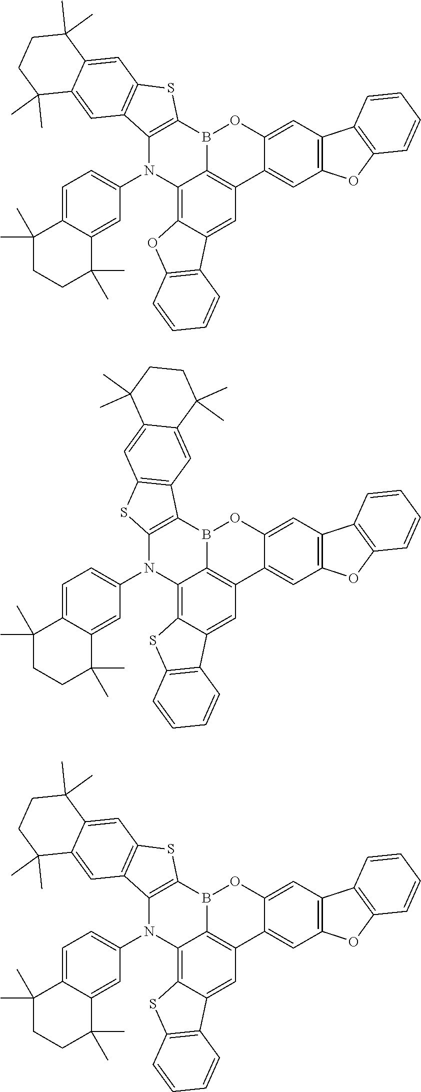

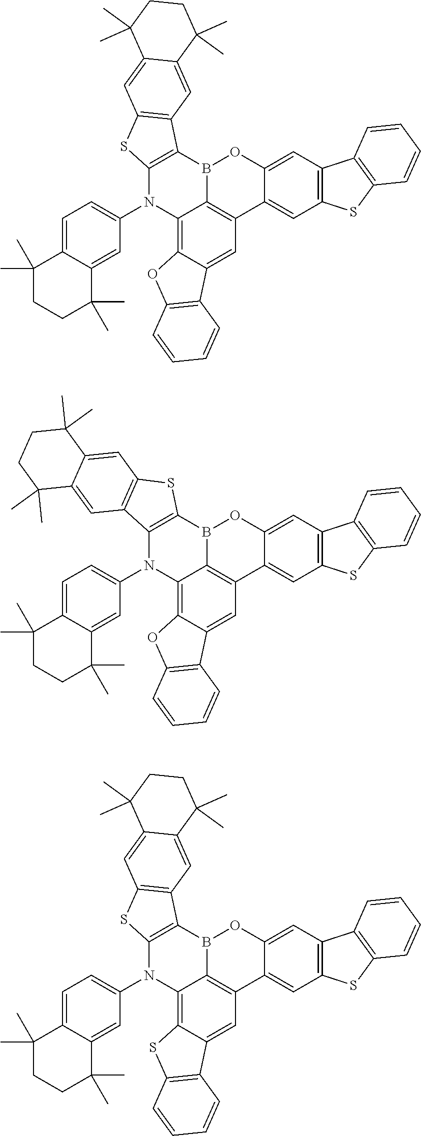 [SMILES: CC1(C)CCC(C)(C)c2cc(N3c4sc5cc6c(cc5c4B4Oc5cc7c(cc5-c5cc8c(oc9ccccc98)c3c54)sc3ccccc37)C(C)(C)CCC6(C)C)ccc21 ; CC1(C)CCC(C)(C)c2cc(N3c4c(sc5cc6c(cc45)C(C)(C)CCC6(C)C)B4Oc5cc6c(cc5-c5cc7c(oc8ccccc87)c3c54)sc3ccccc36)ccc21 ; CC1(C)CCC(C)(C)c2cc(N3c4sc5cc6c(cc5c4B4Oc5cc7c(cc5-c5cc8c(sc9ccccc98)c3c54)sc3ccccc37)C(C)(C)CCC6(C)C)ccc21]

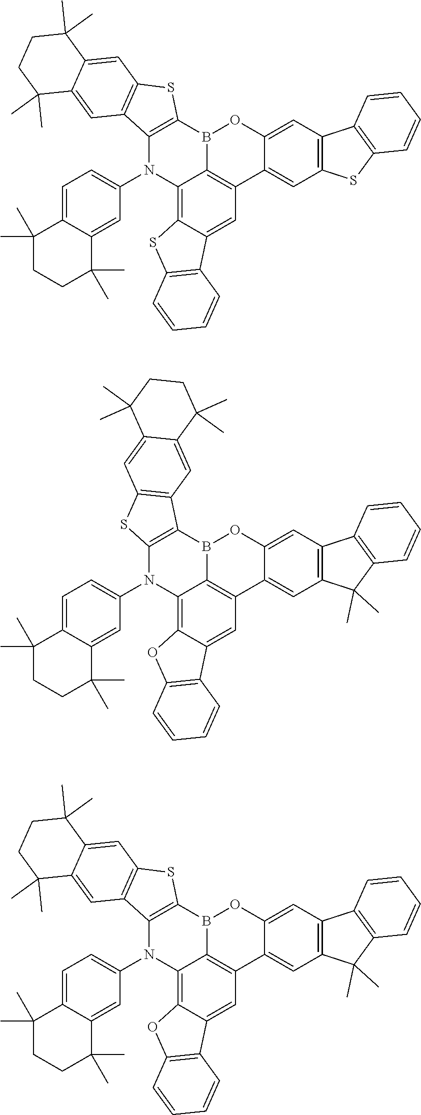 [SMILES: CC1(C)CCC(C)(C)c2cc(N3c4c(sc5cc6c(cc45)C(C)(C)CCC6(C)C)B4Oc5cc6c(cc5-c5cc7c(sc8ccccc87)c3c54)sc3ccccc36)ccc21 ; CC1(C)CCC(C)(C)c2cc(N3c4sc5cc6c(cc5c4B4Oc5cc7c(cc5-c5cc8c(oc9ccccc98)c3c54)C(C)(C)c3ccccc3-7)C(C)(C)CCC6(C)C)ccc21 ; CC1(C)CCC(C)(C)c2cc(N3c4c(sc5cc6c(cc45)C(C)(C)CCC6(C)C)B4Oc5cc6c(cc5-c5cc7c(oc8ccccc87)c3c54)C(C)(C)c3ccccc3-6)ccc21]

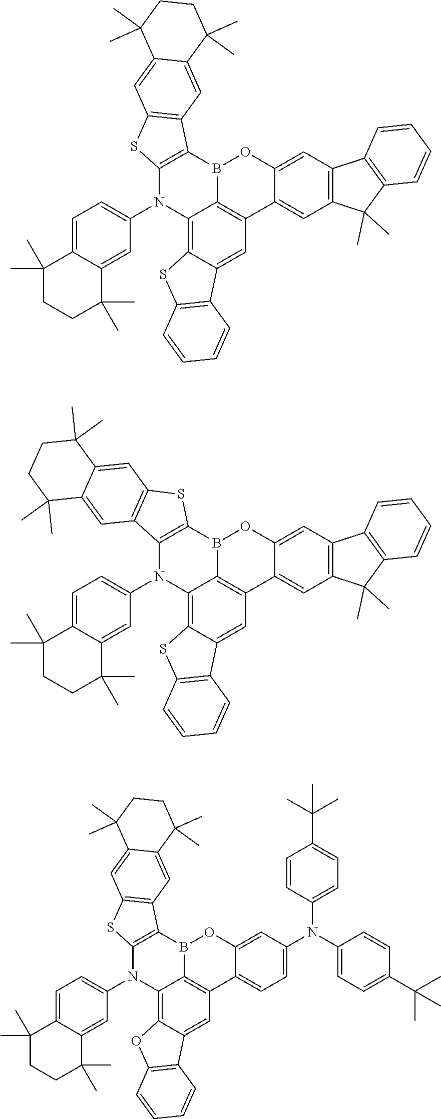 [SMILES: CC1(C)CCC(C)(C)c2cc(N3c4sc5cc6c(cc5c4B4Oc5cc7c(cc5-c5cc8c(sc9ccccc98)c3c54)C(C)(C)c3ccccc3-7)C(C)(C)CCC6(C)C)ccc21 ; CC1(C)CCC(C)(C)c2cc(N3c4c(sc5cc6c(cc45)C(C)(C)CCC6(C)C)B4Oc5cc6c(cc5-c5cc7c(sc8ccccc87)c3c54)C(C)(C)c3ccccc3-6)ccc21 ; CC(C)(C)c1ccc(N(c2ccc(C(C)(C)C)cc2)c2ccc3c(c2)OB2c4c-3cc3c(oc5ccccc53)c4N(c3ccc4c(c3)C(C)(C)CCC4(C)C)c3sc4cc5c(cc4c32)C(C)(C)CCC5(C)C)cc1]

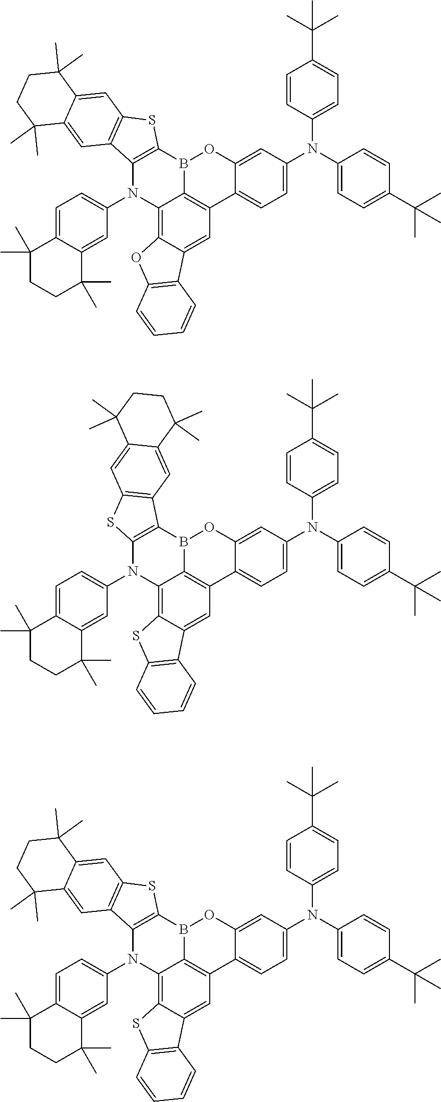

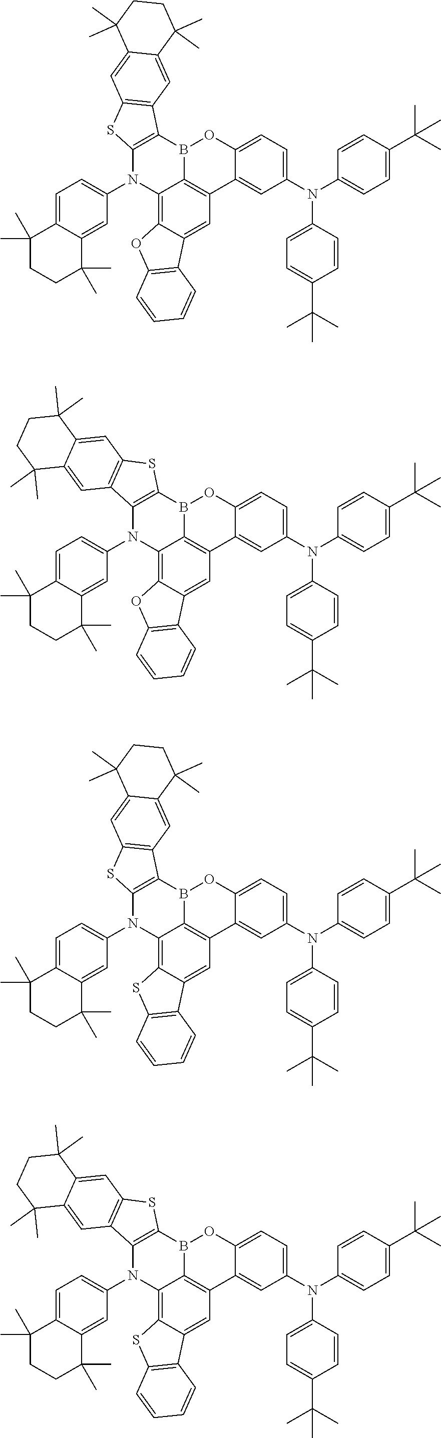

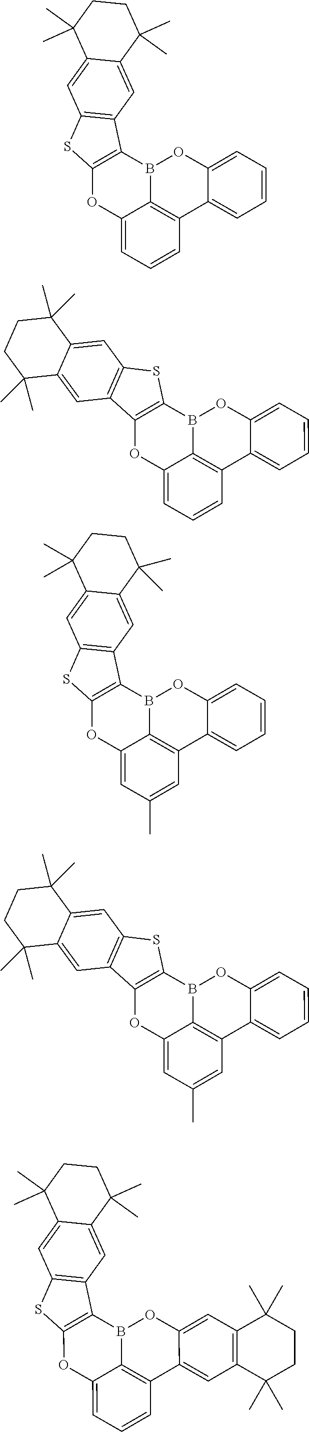

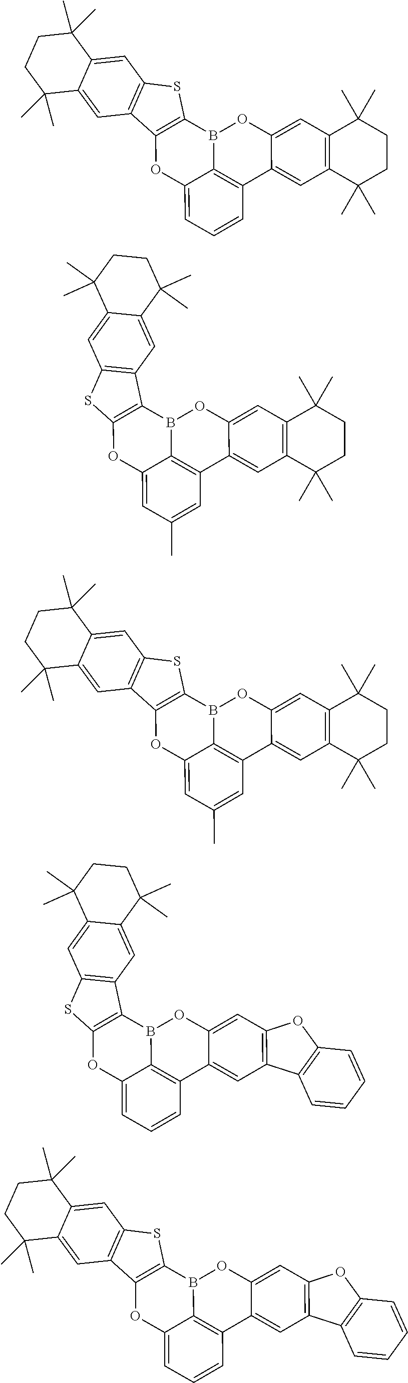

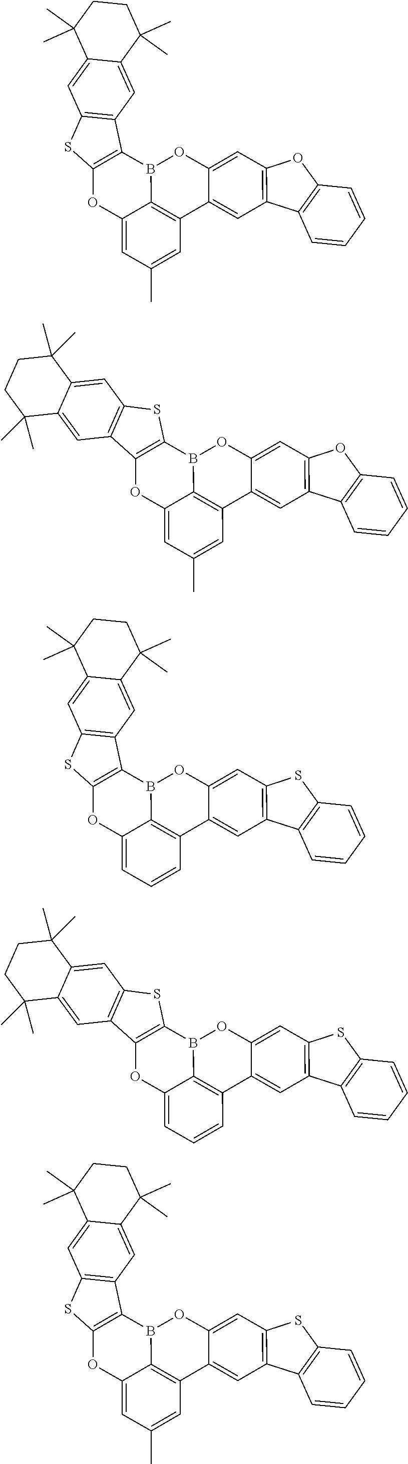

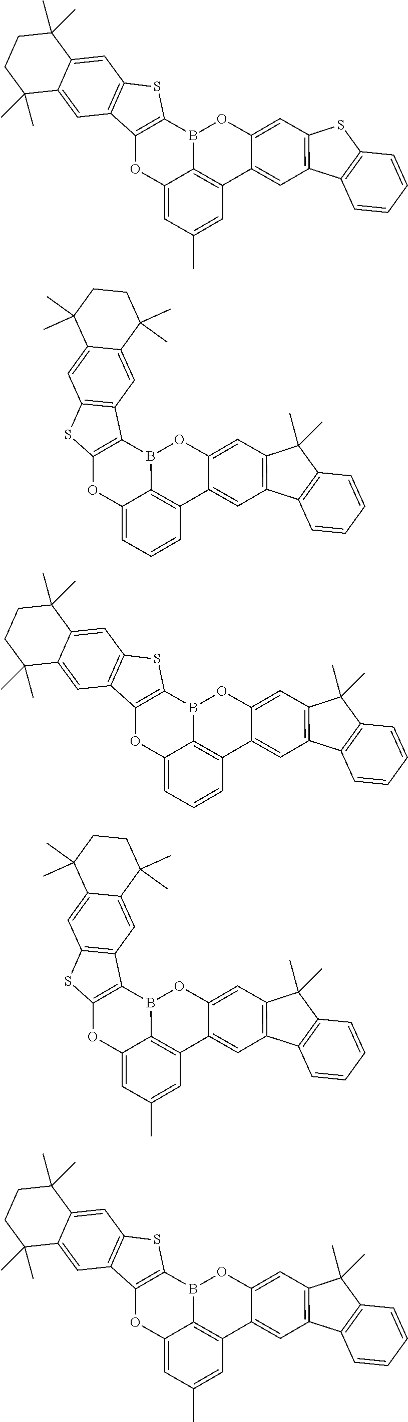

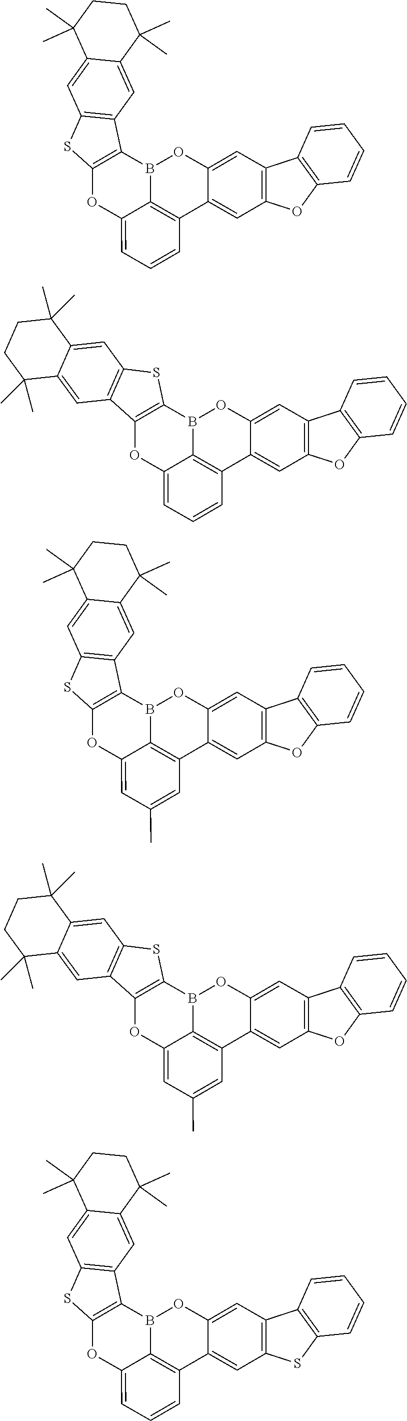

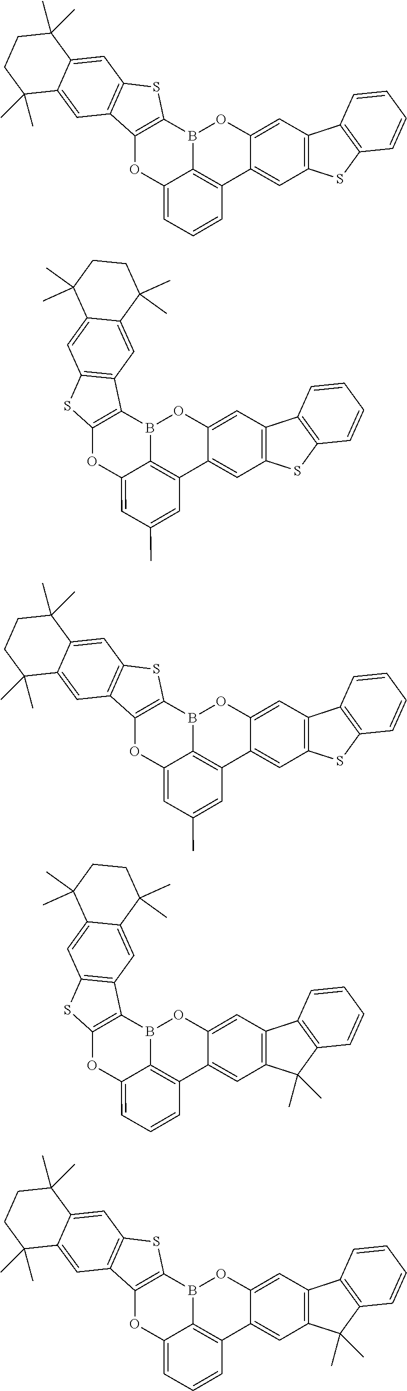

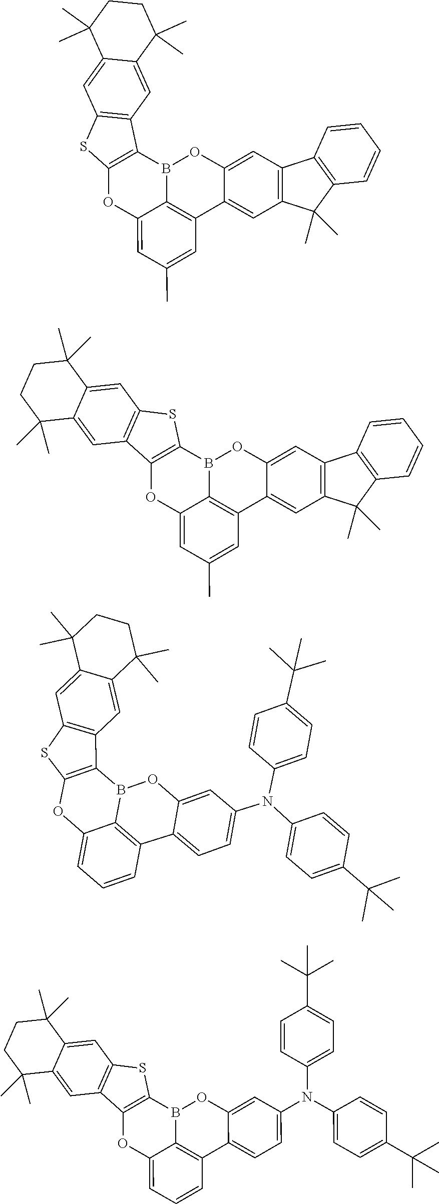

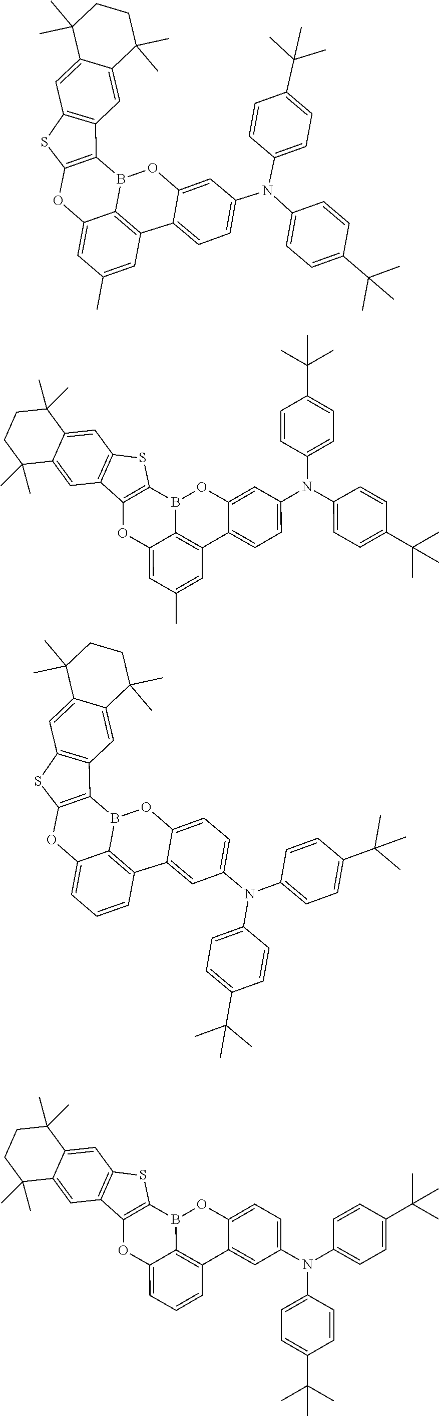

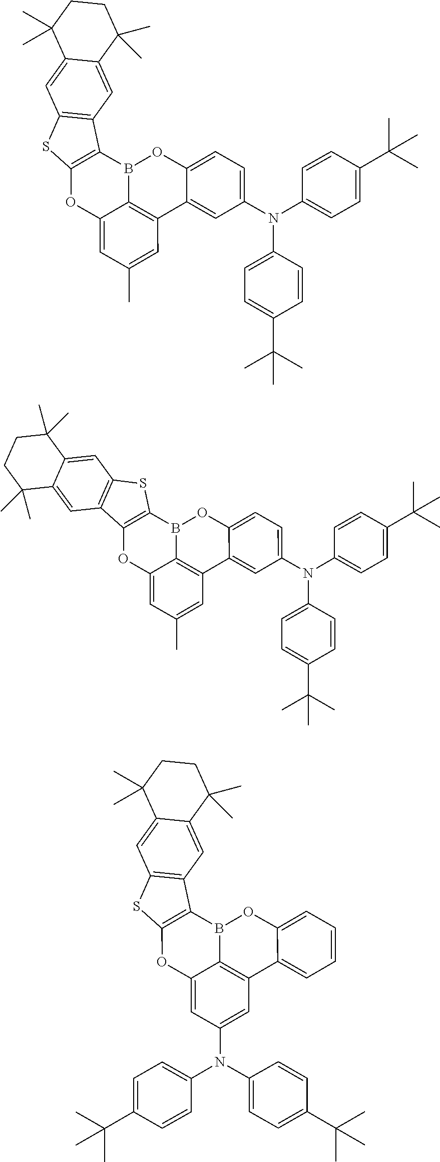

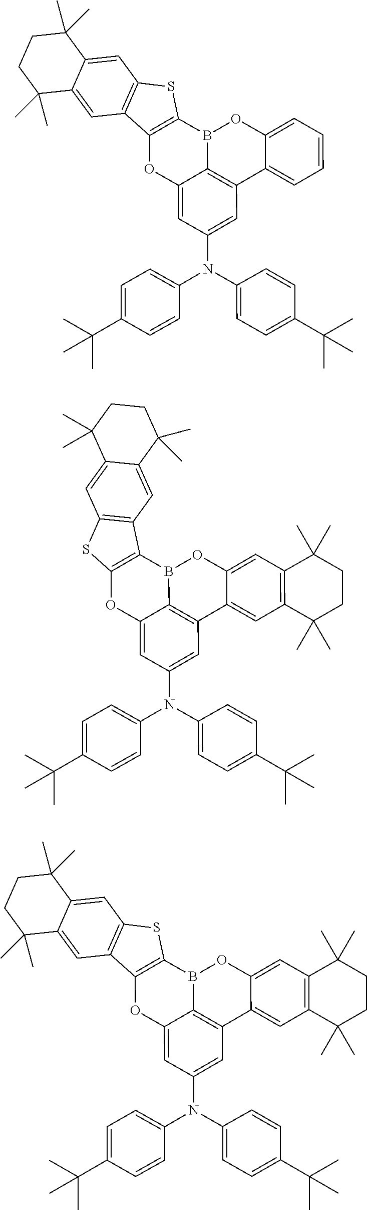

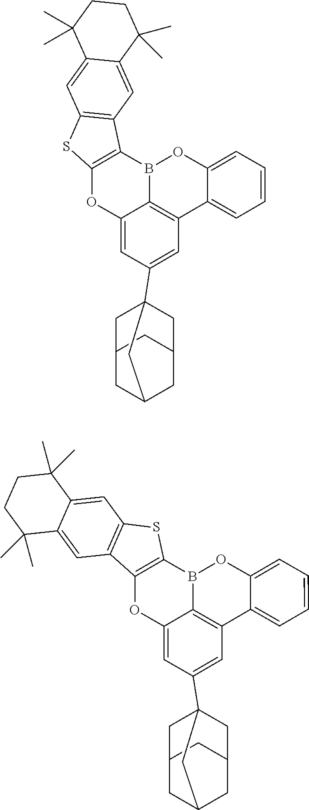

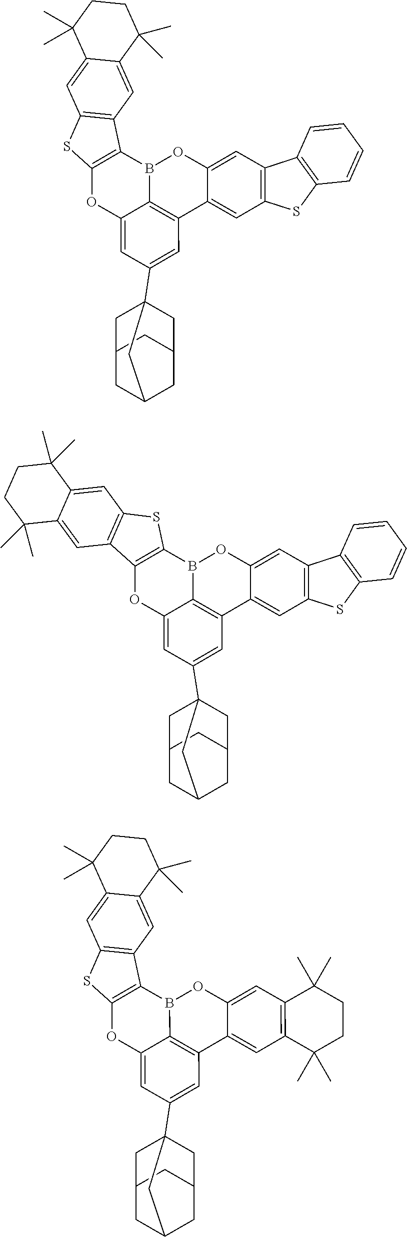

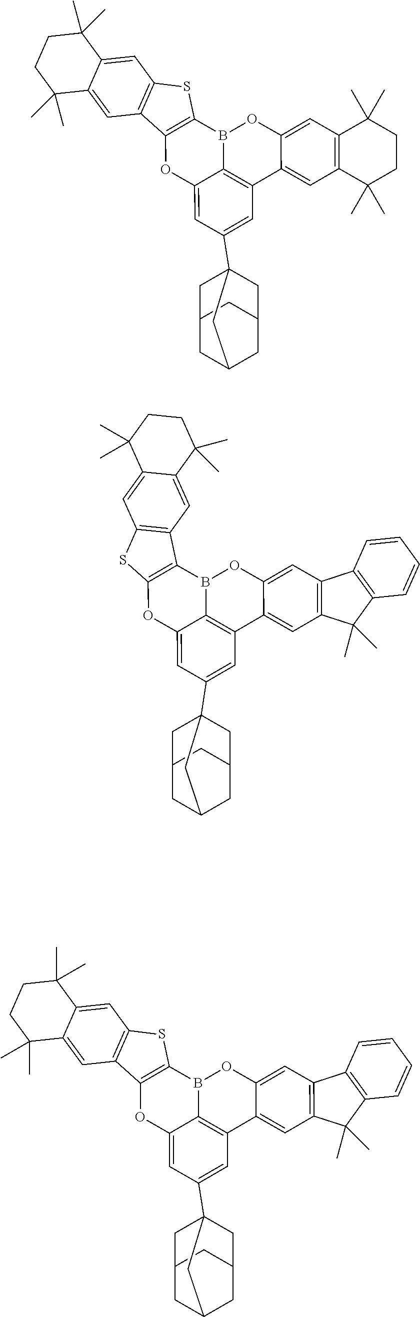

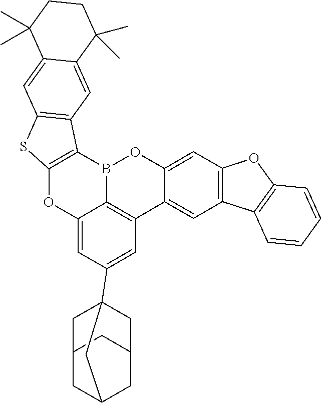

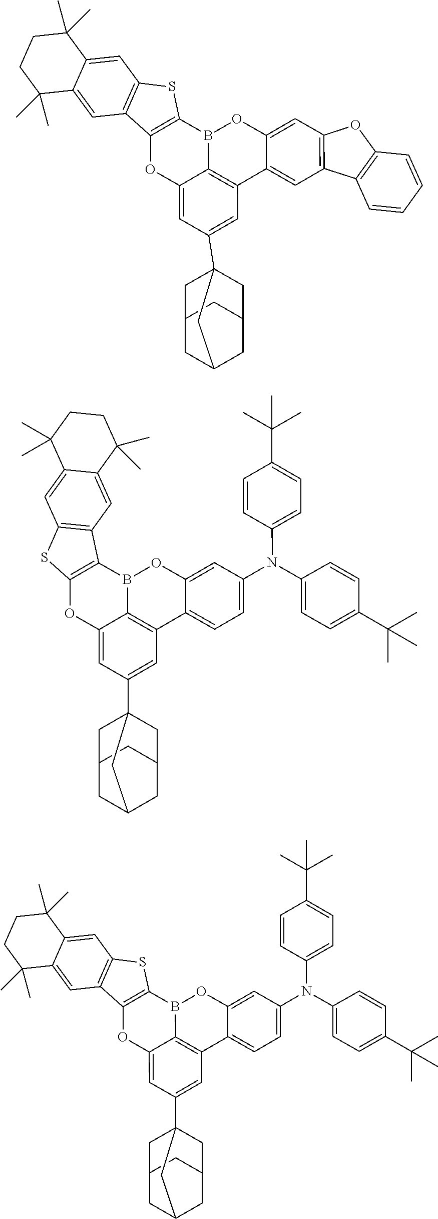

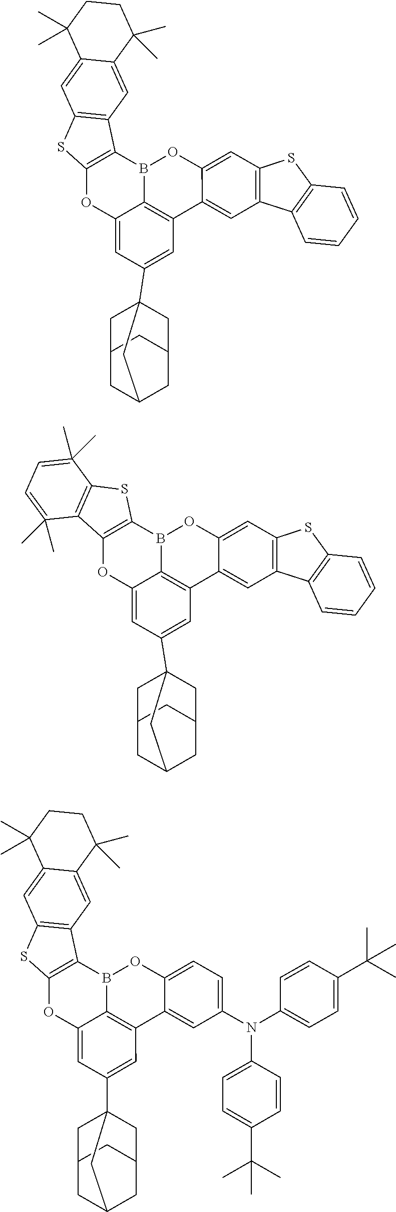

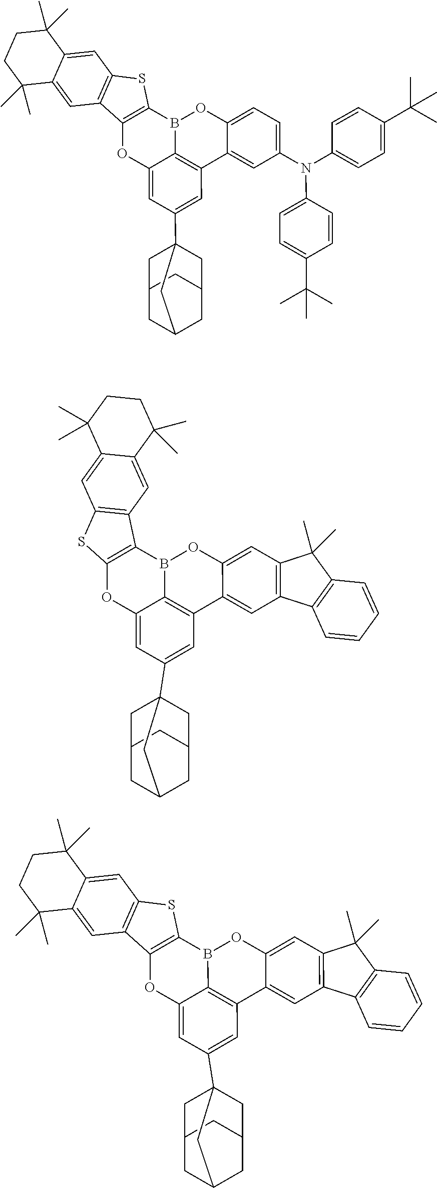

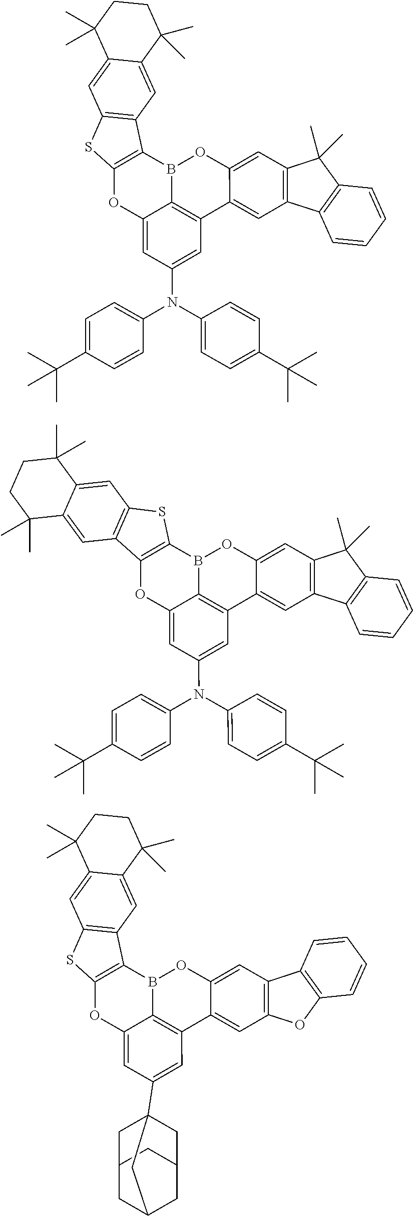

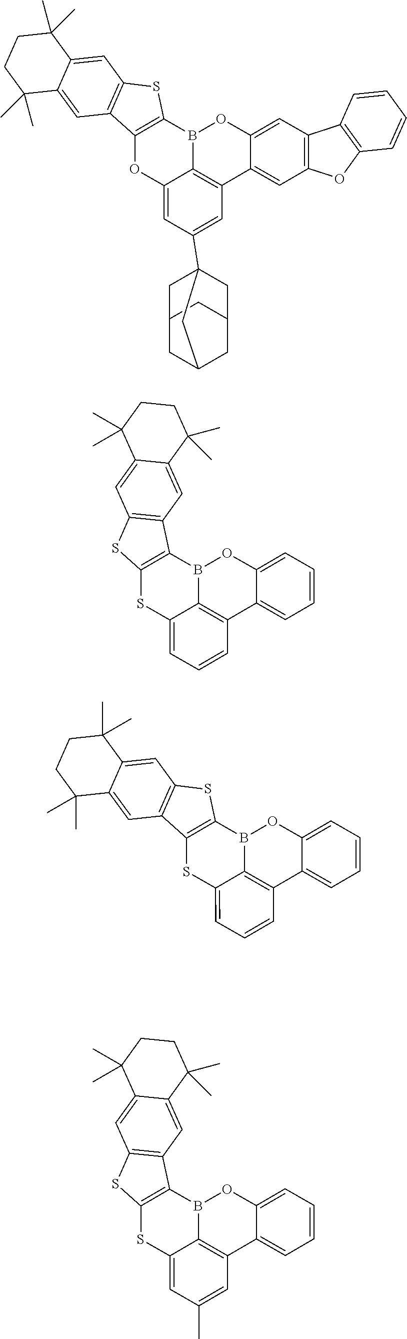

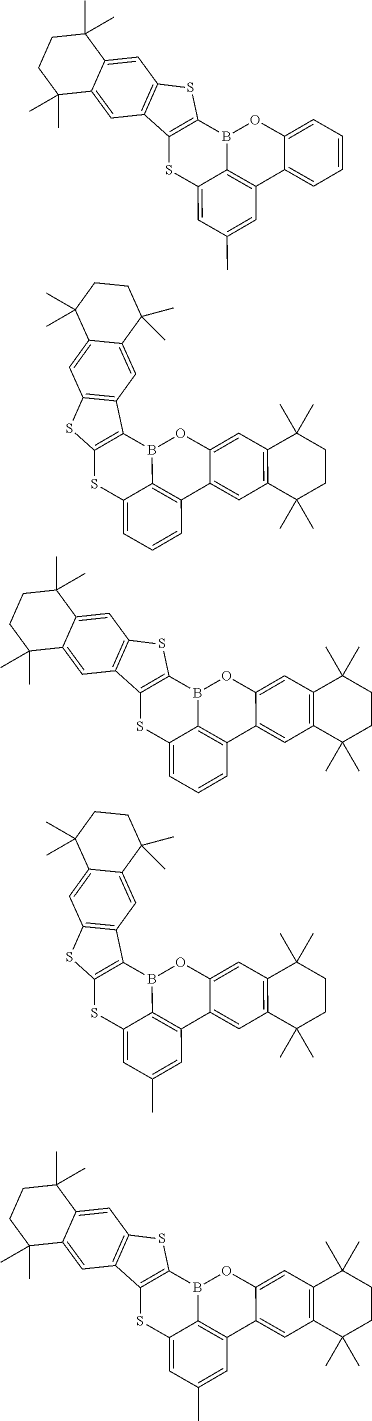

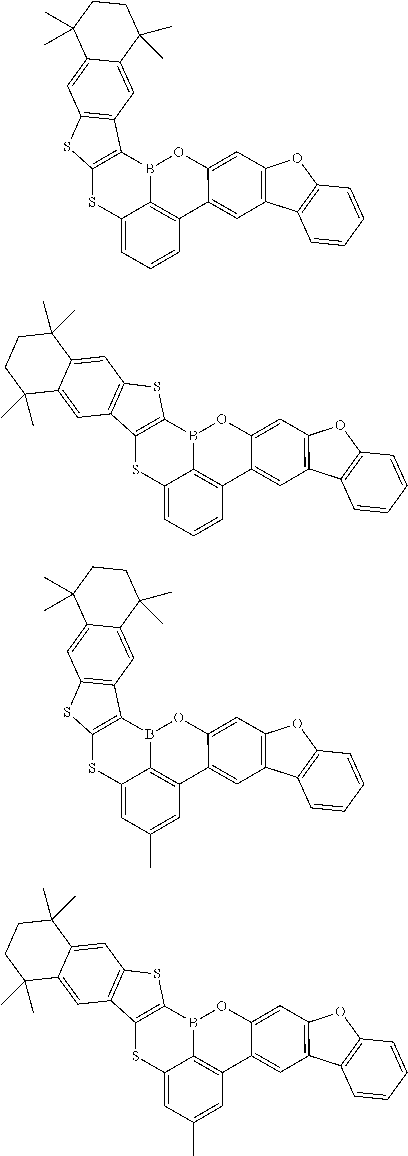

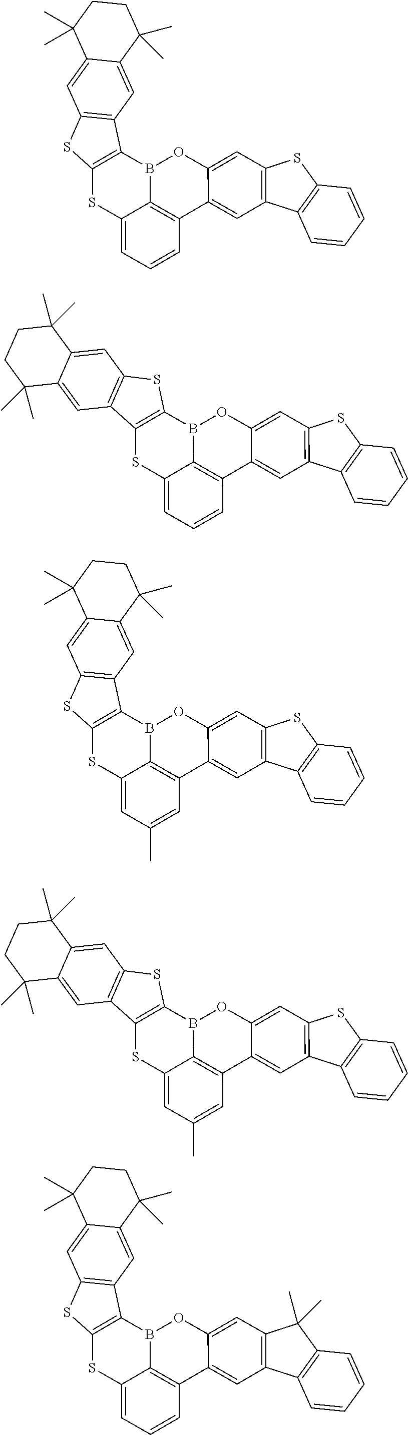

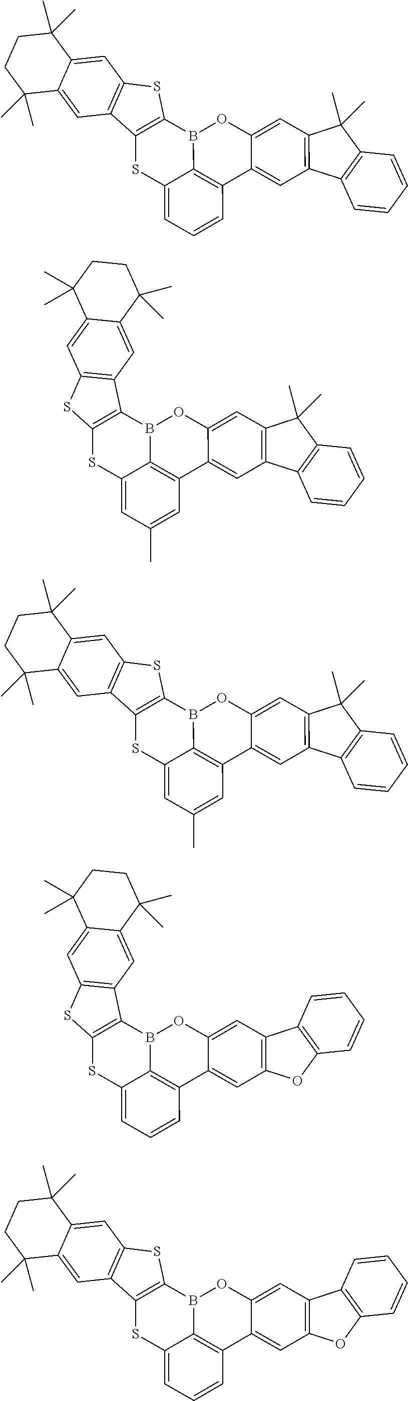

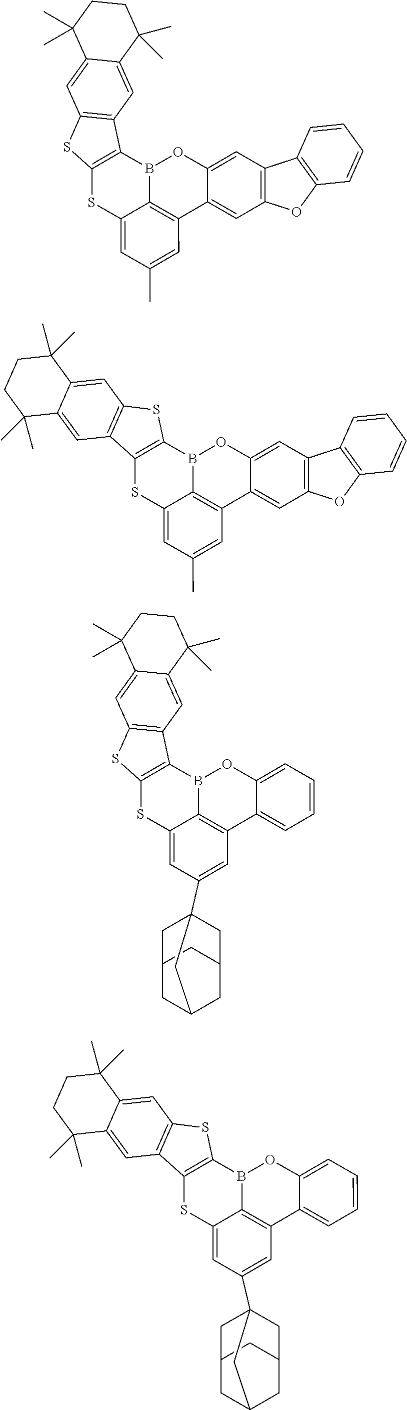

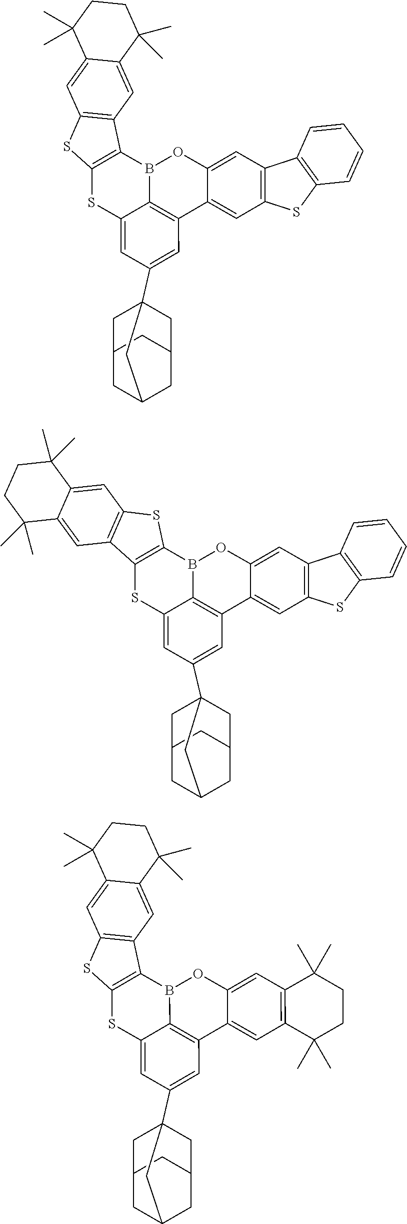

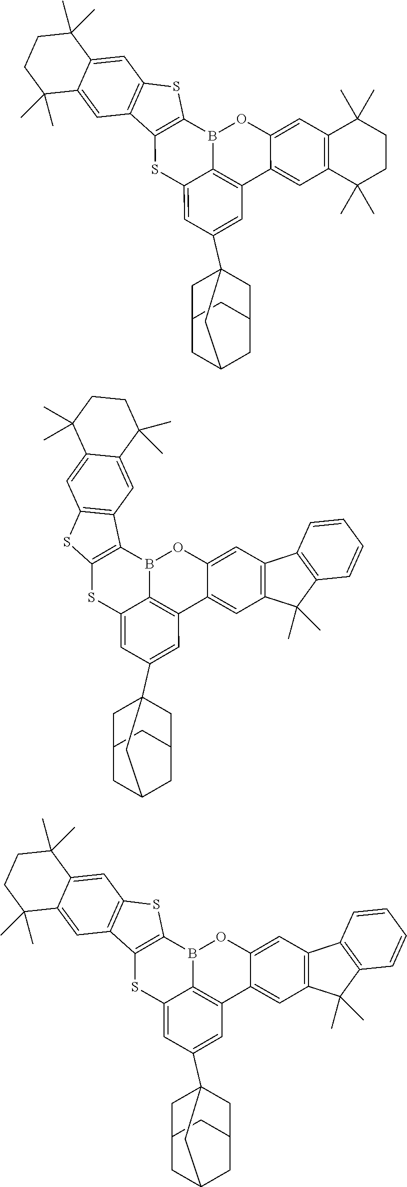

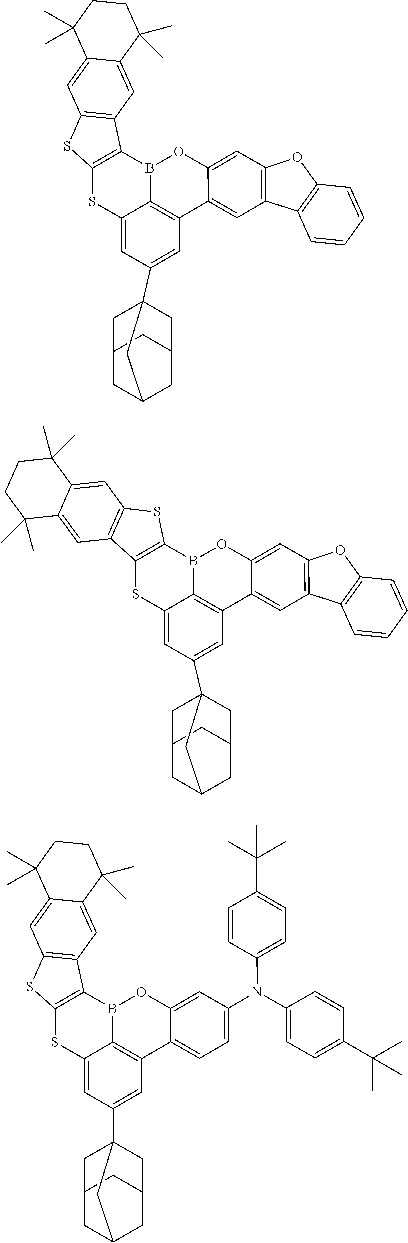

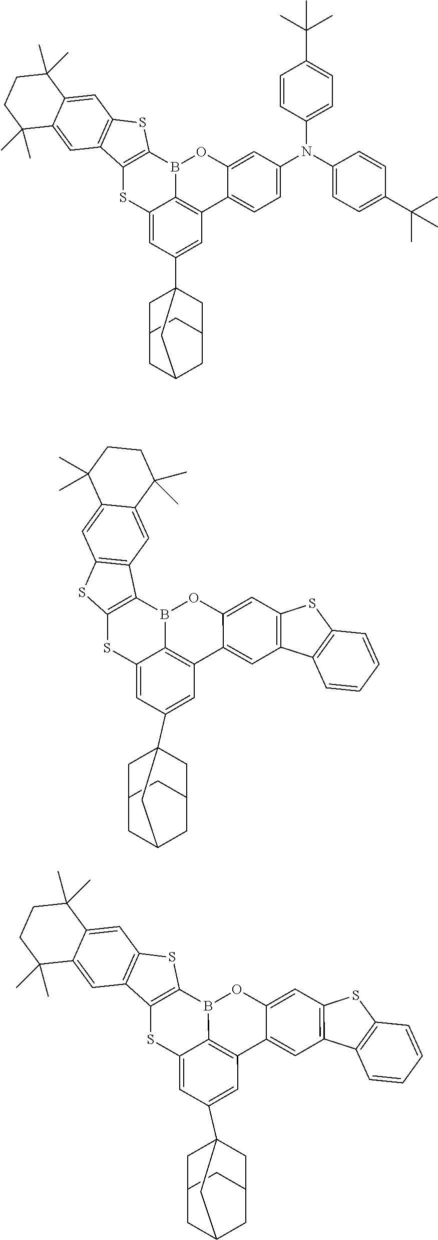

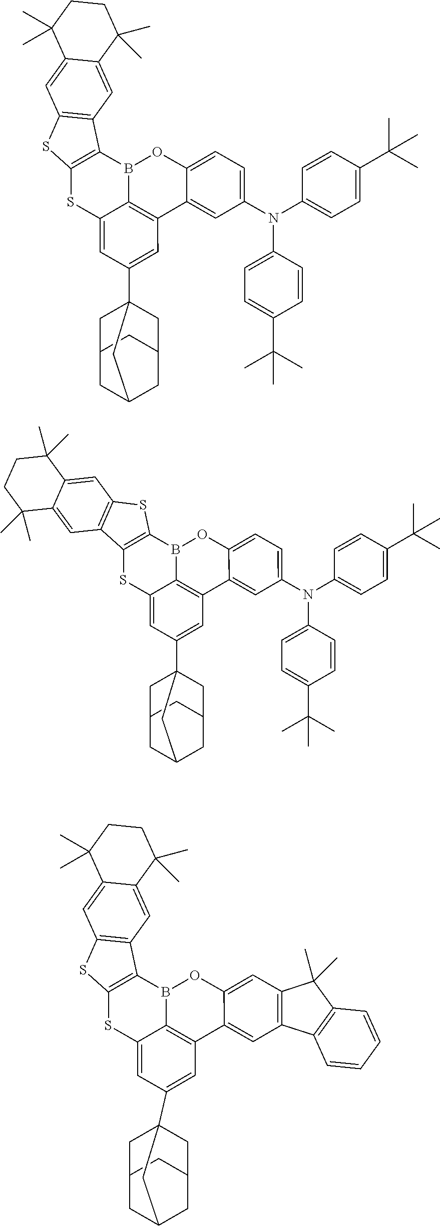

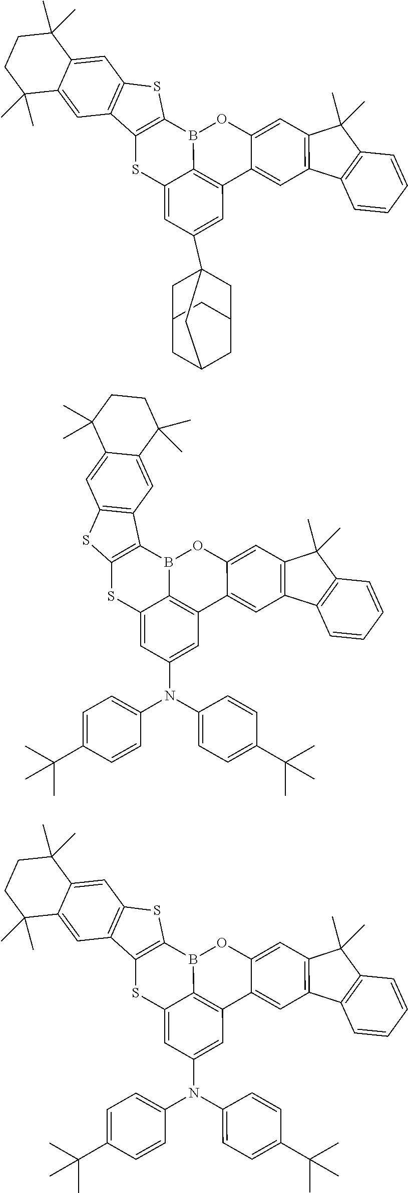

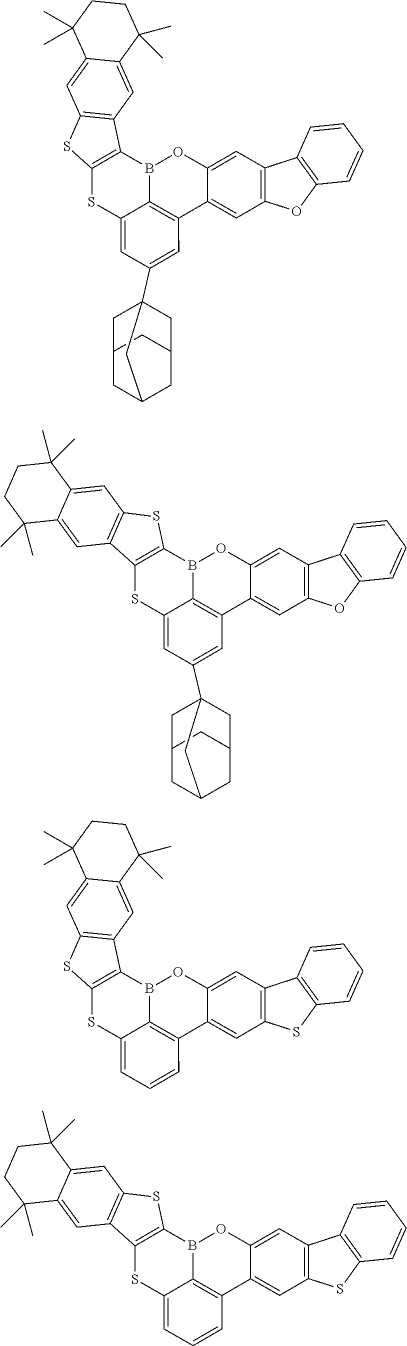

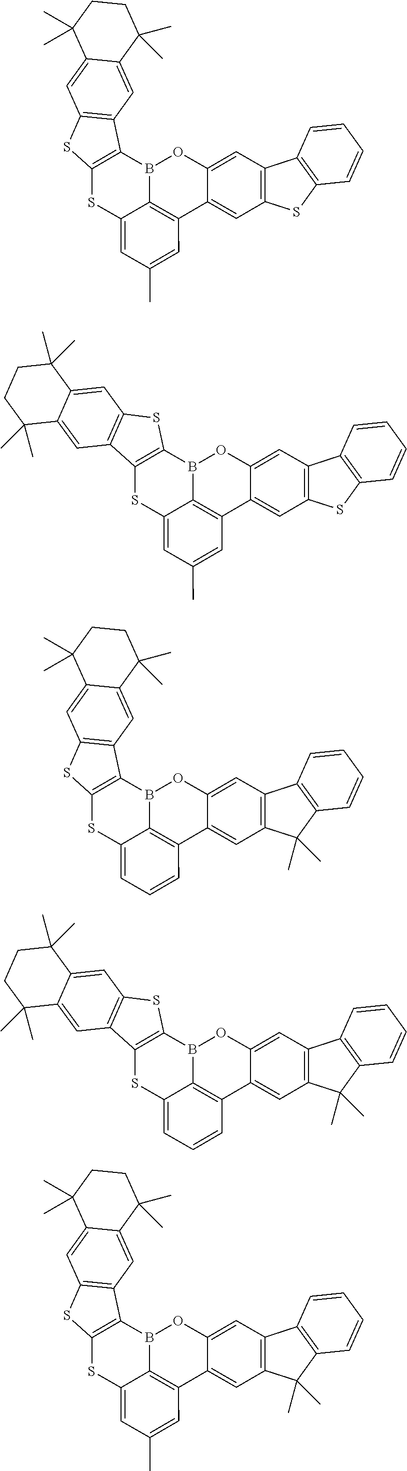

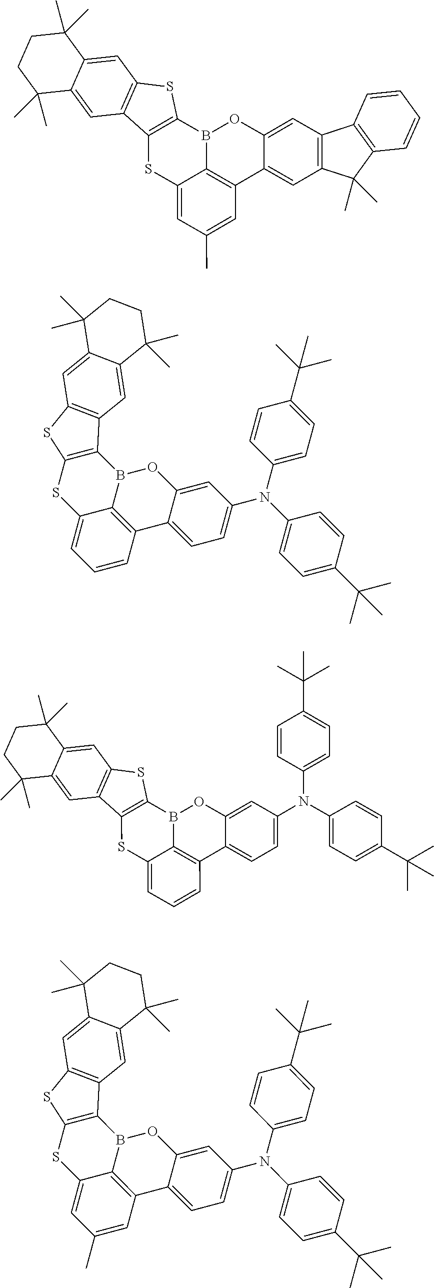

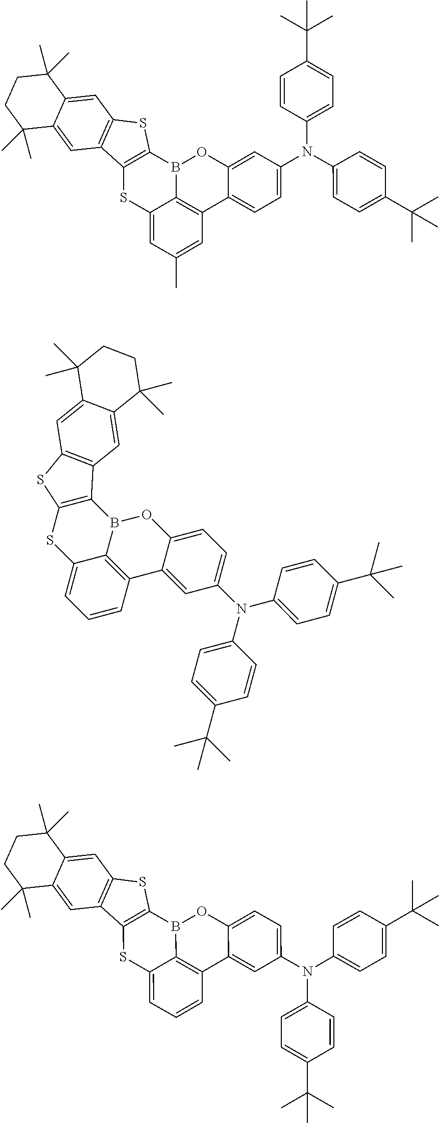

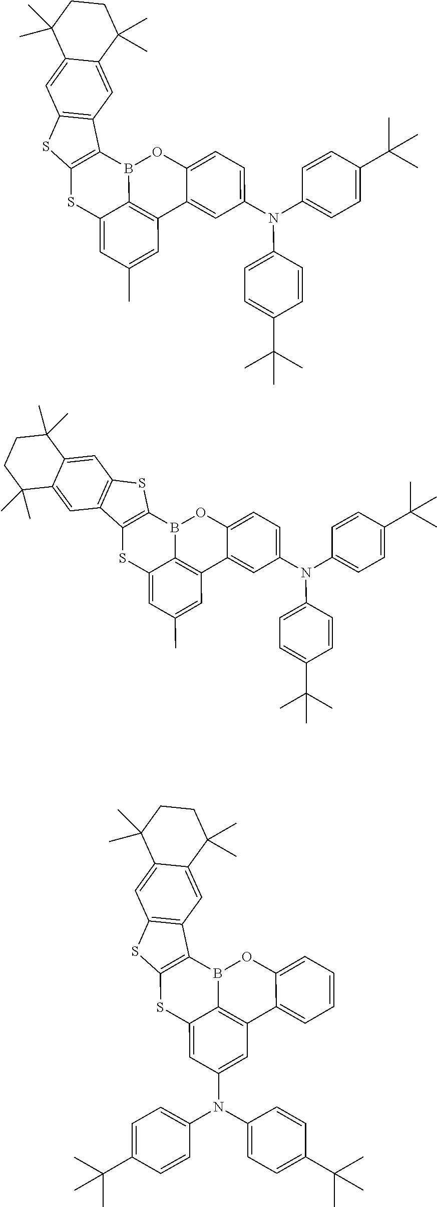

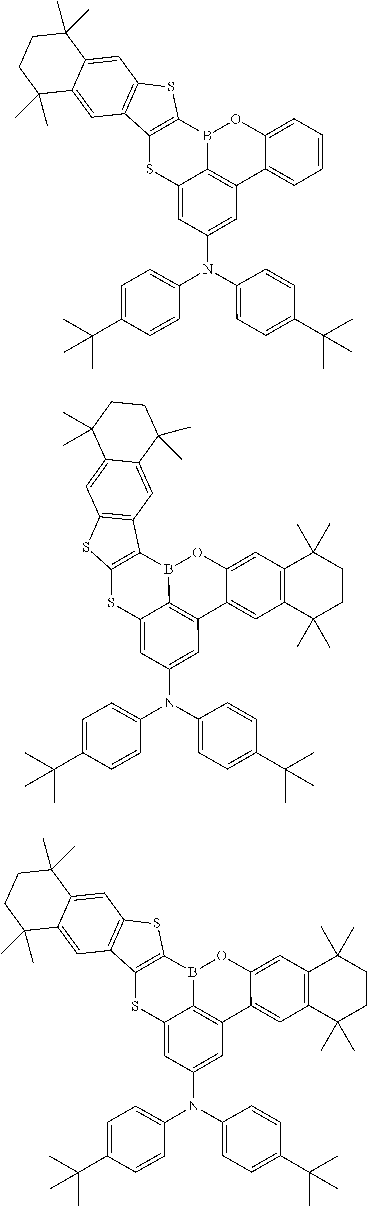

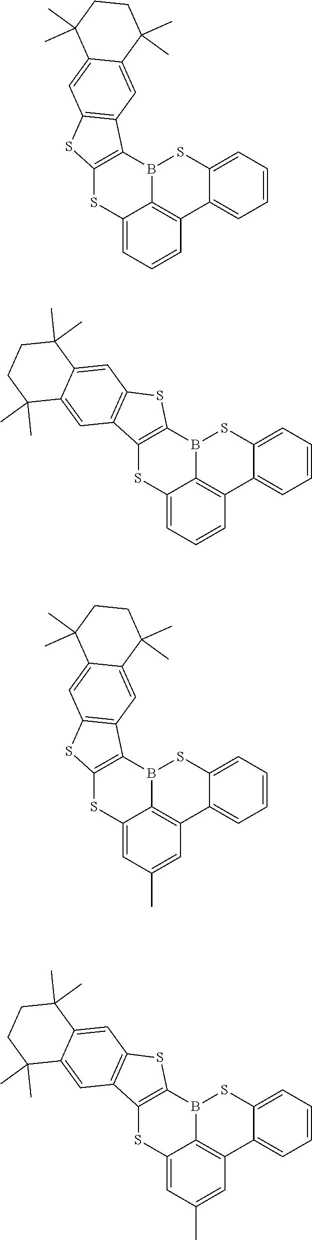 [SMILES: CC1(C)CCC(C)(C)c2cc3c4c(sc3cc21)Sc1cccc2c1B4Sc1ccccc1-2 ; CC1(C)CCC(C)(C)c2cc3c4c(sc3cc21)B1Sc2ccccc2-c2cccc(c21)S4 ; Cc1cc2c3c(c1)-c1ccccc1SB3c1c(sc3cc4c(cc13)C(C)(C)CCC4(C)C)S2 ; Cc1cc2c3c(c1)-c1ccccc1SB3c1sc3cc4c(cc3c1S2)C(C)(C)CCC4(C)C]

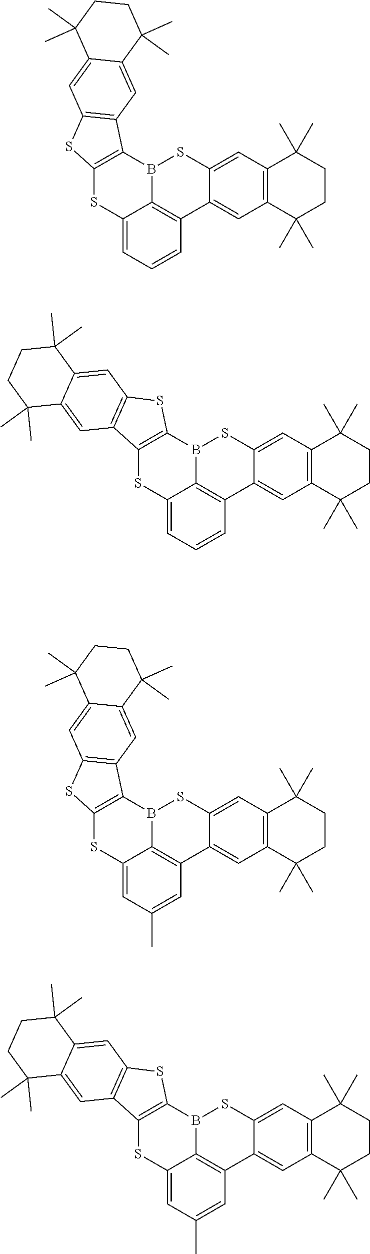 [SMILES: CC1(C)CCC(C)(C)c2cc3c(cc21)SB1c2c(cccc2-3)Sc2sc3cc4c(cc3c21)C(C)(C)CCC4(C)C ; CC1(C)CCC(C)(C)c2cc3c(cc21)SB1c2sc4cc5c(cc4c2Sc2cccc-3c21)C(C)(C)CCC5(C)C ; Cc1cc2c3c(c1)-c1cc4c(cc1SB3c1c(sc3cc5c(cc13)C(C)(C)CCC5(C)C)S2)C(C)(C)CCC4(C)C ; Cc1cc2c3c(c1)-c1cc4c(cc1SB3c1sc3cc5c(cc3c1S2)C(C)(C)CCC5(C)C)C(C)(C)CCC4(C)C]

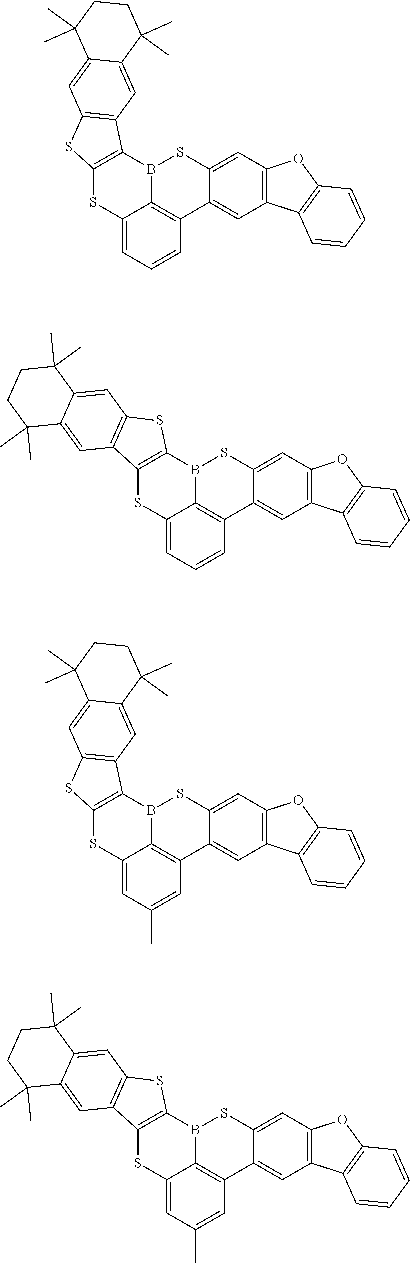 [SMILES: CC1(C)CCC(C)(C)c2cc3c4c(sc3cc21)Sc1cccc2c1B4Sc1cc3oc4ccccc4c3cc1-2 ; CC1(C)CCC(C)(C)c2cc3c4c(sc3cc21)B1Sc2cc3oc5ccccc5c3cc2-c2cccc(c21)S4 ; Cc1cc2c3c(c1)-c1cc4c(cc1SB3c1c(sc3cc5c(cc13)C(C)(C)CCC5(C)C)S2)oc1ccccc14 ; Cc1cc2c3c(c1)-c1cc4c(cc1SB3c1sc3cc5c(cc3c1S2)C(C)(C)CCC5(C)C)oc1ccccc14]

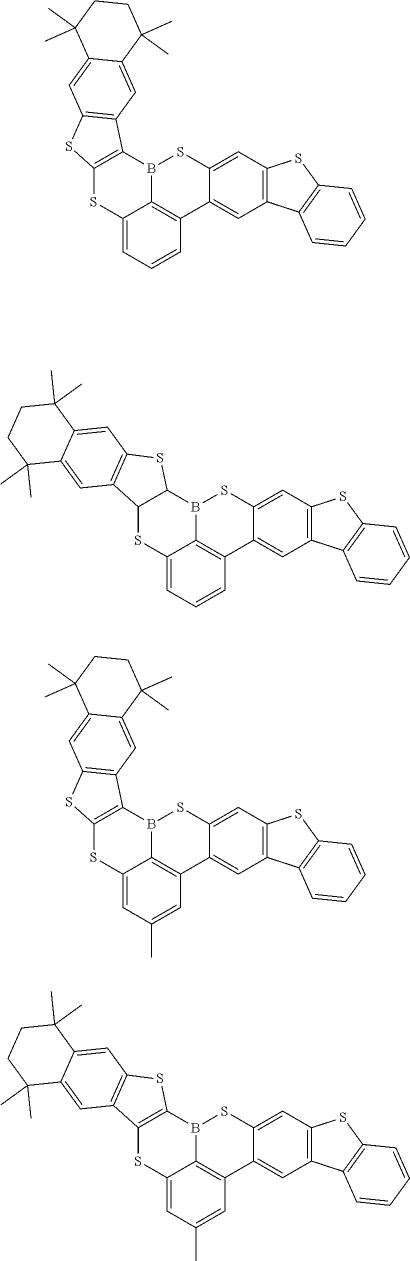

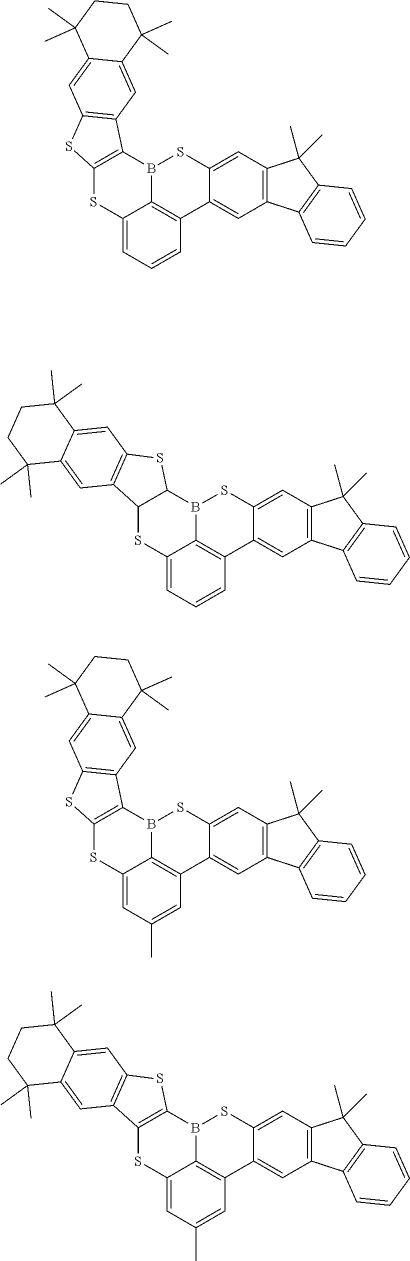

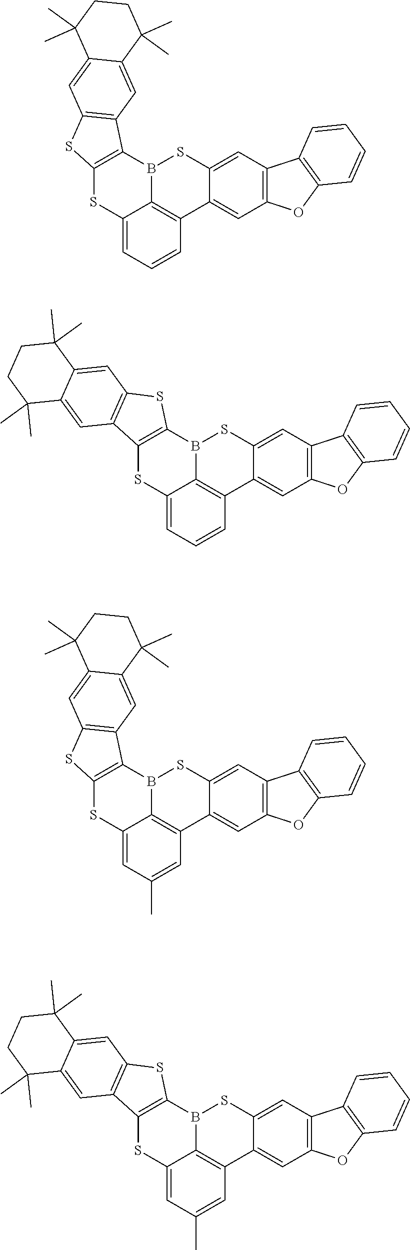

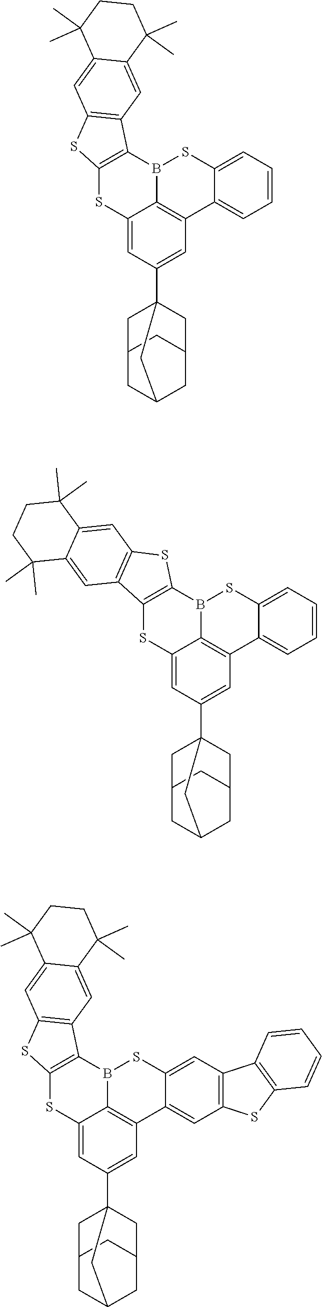

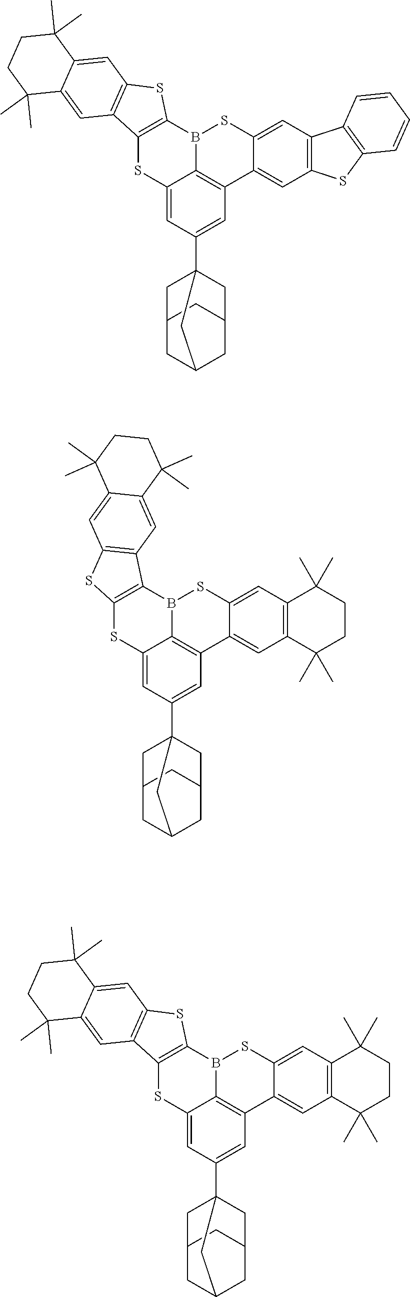 [SMILES: CC1(C)CCC(C)(C)c2cc3c4c(sc3cc21)B1Sc2cc3c(cc2-c2cc(C56CC7CC(CC(C7)C5)C6)cc(c21)S4)sc1ccccc13 ; CC1(C)CCC(C)(C)c2cc3c(cc21)SB1c2c(cc(C45CC6CC(CC(C6)C4)C5)cc2-3)Sc2sc3cc4c(cc3c21)C(C)(C)CCC4(C)C ; CC1(C)CCC(C)(C)c2cc3c(cc21)SB1c2sc4cc5c(cc4c2Sc2cc(C46CC7CC(CC(C7)C4)C6)cc-3c21)C(C)(C)CCC5(C)C]

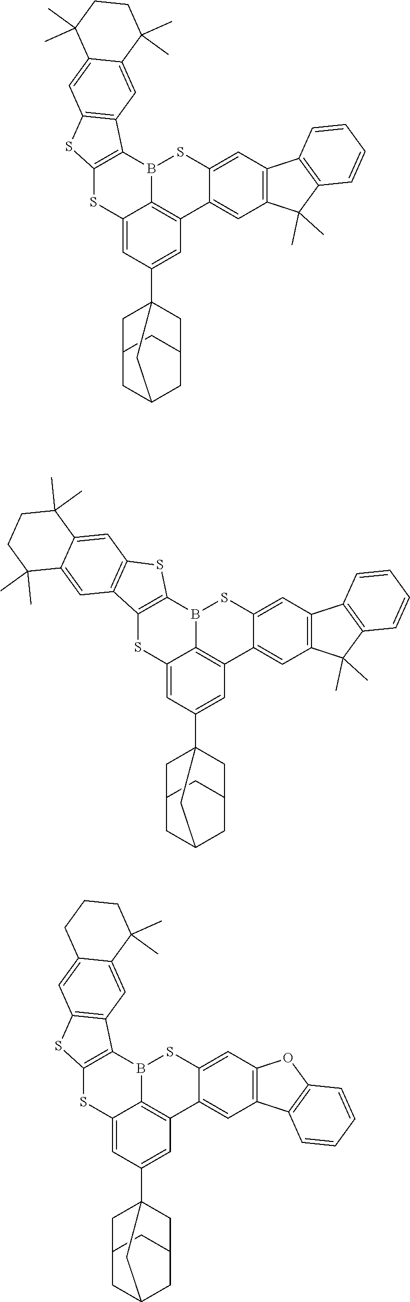

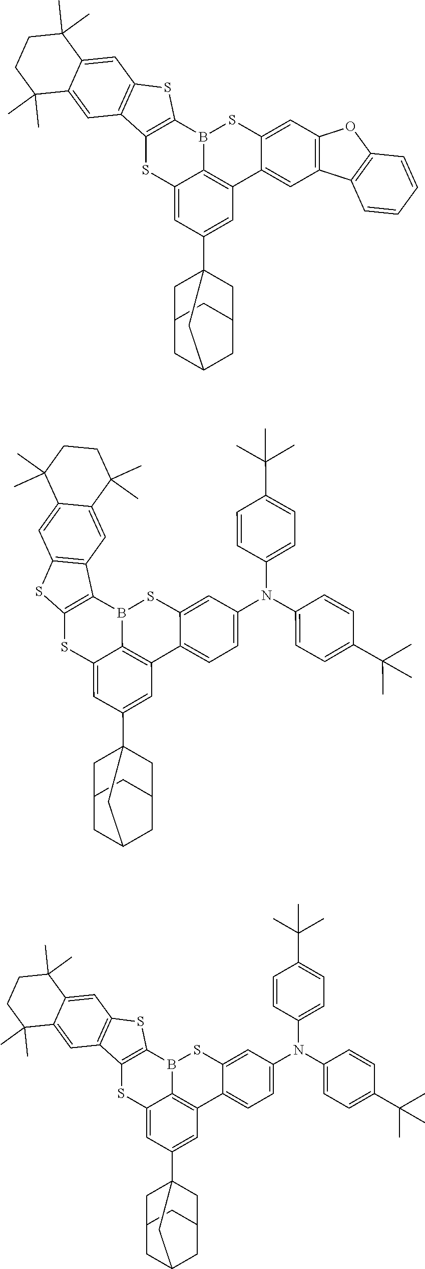

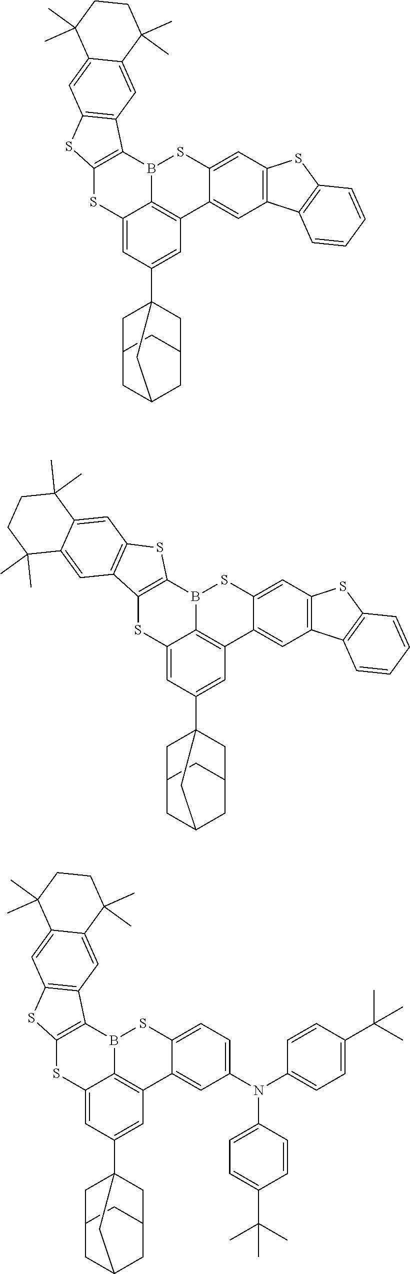

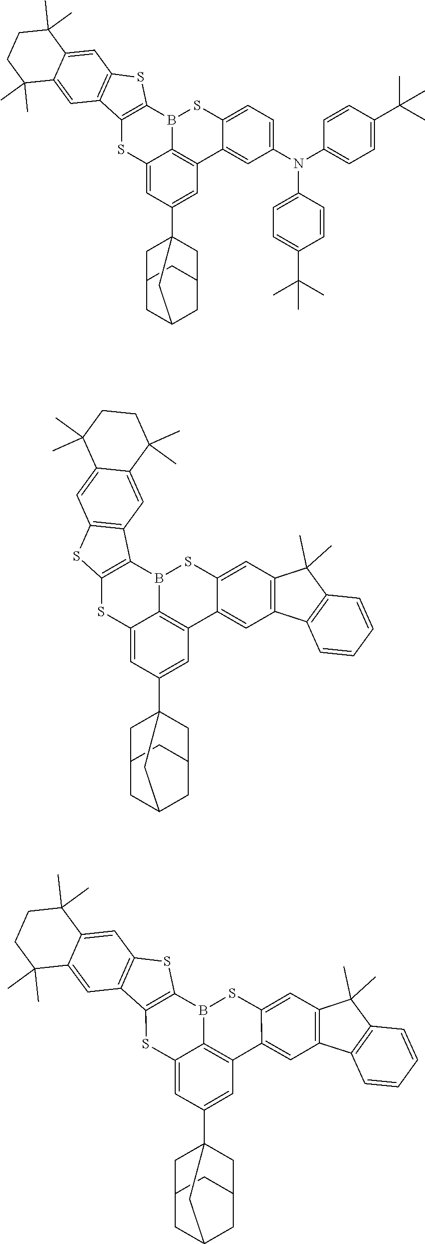

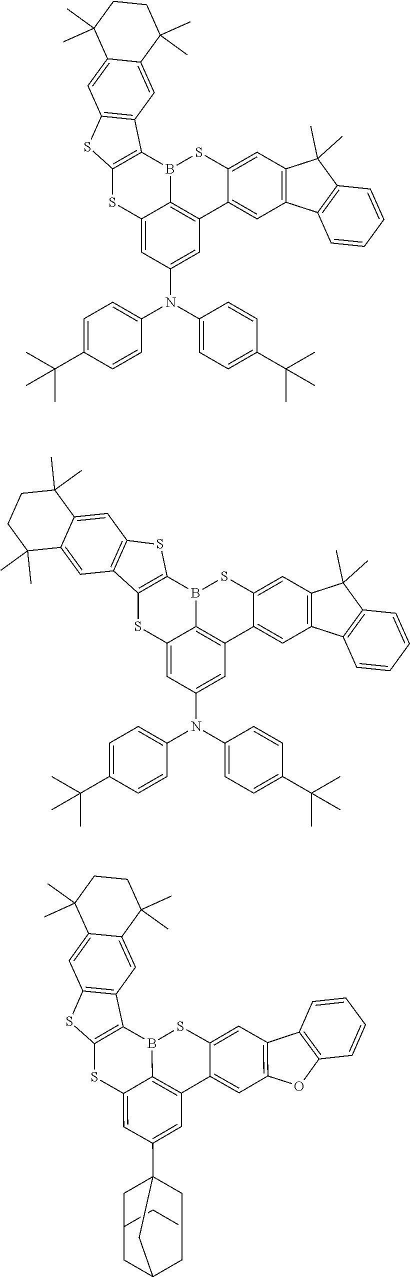

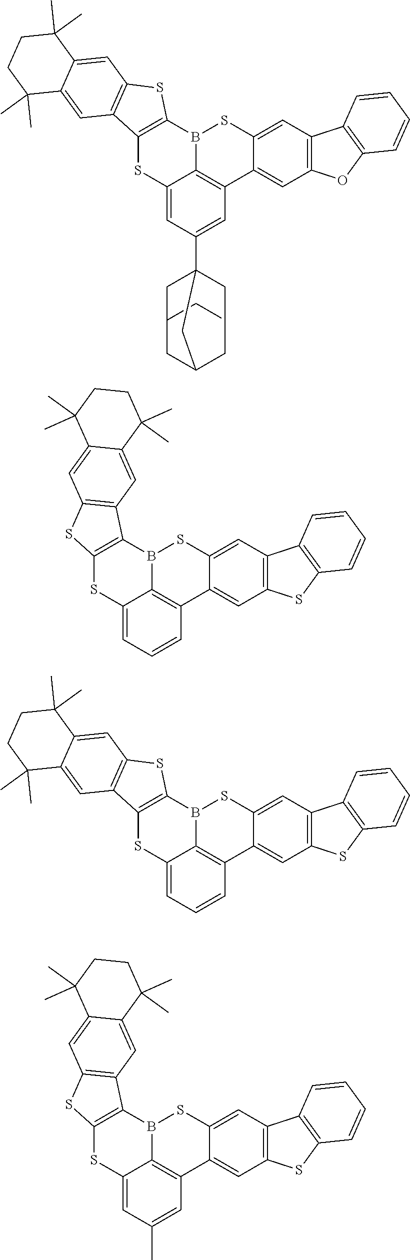

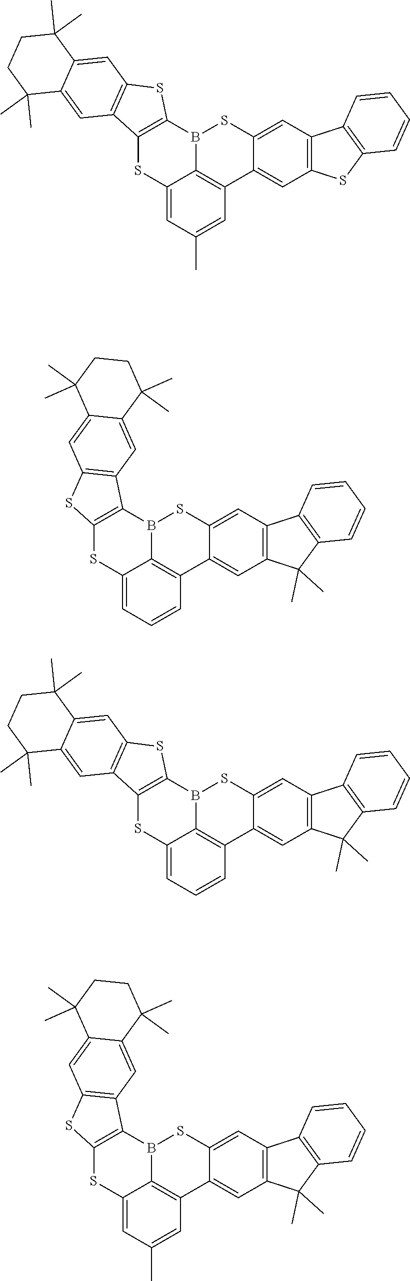

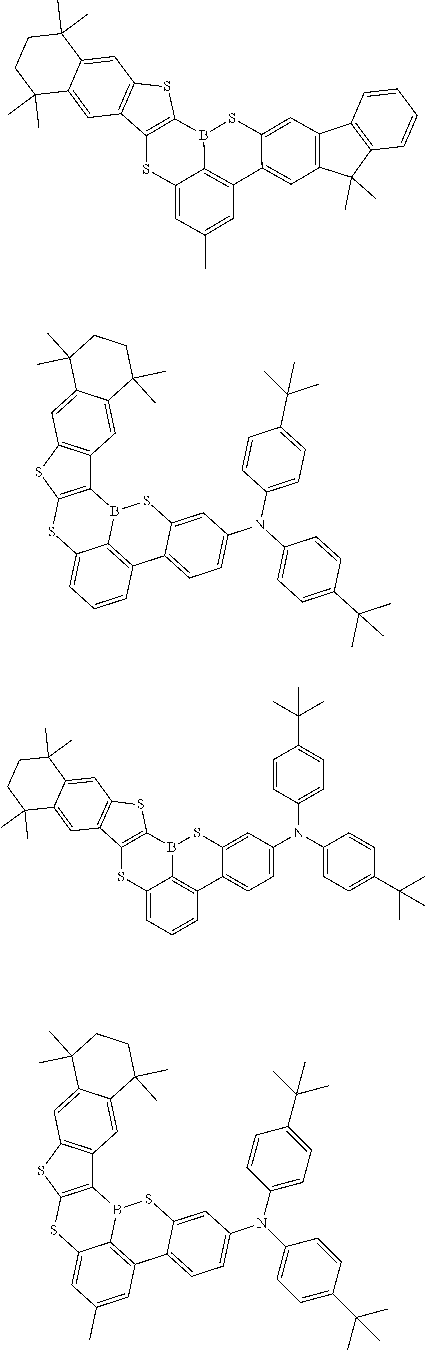

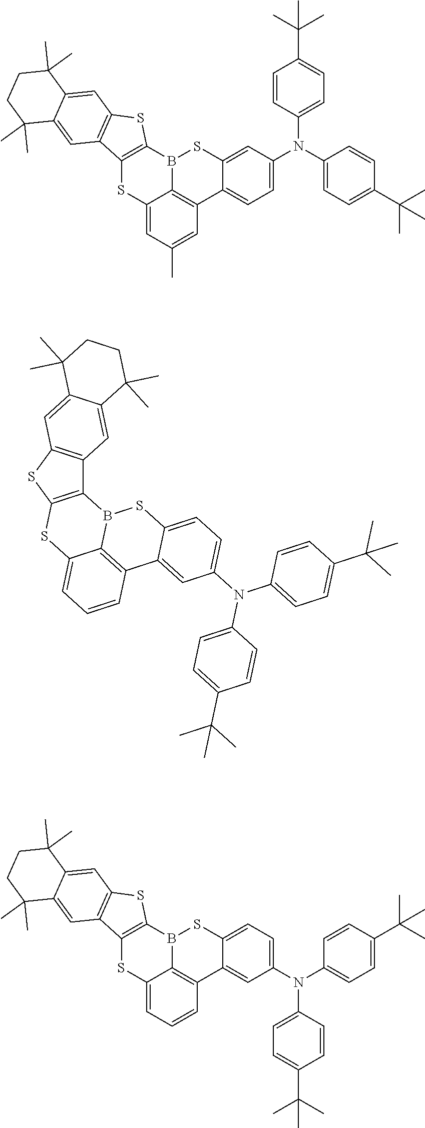

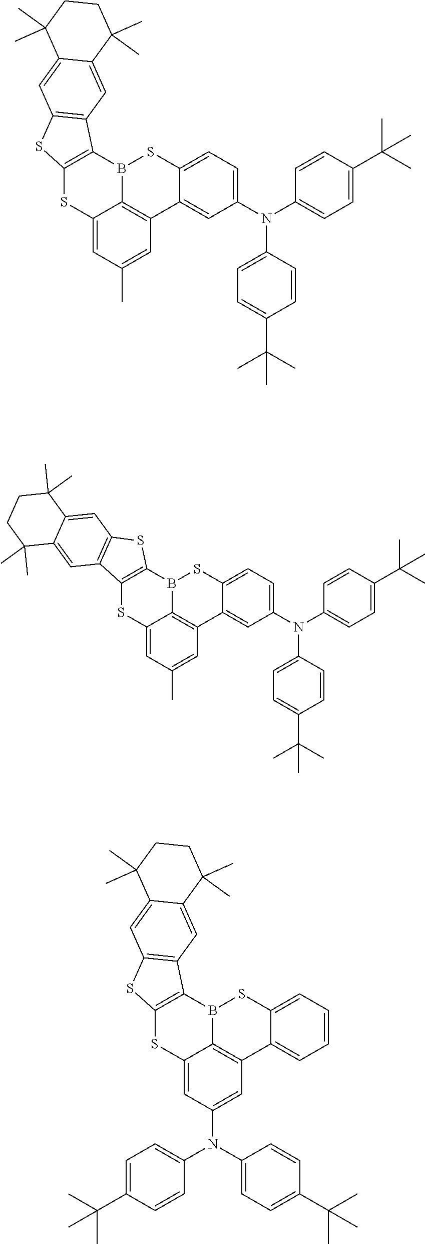

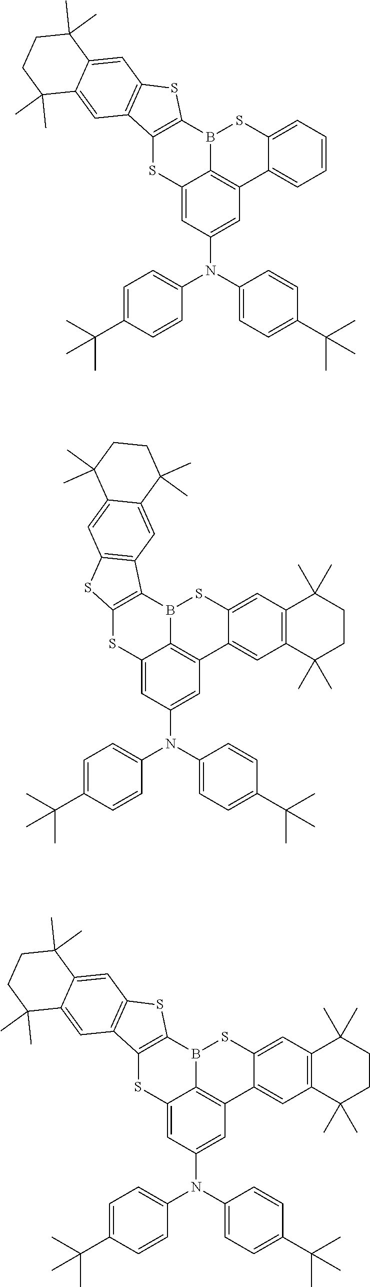

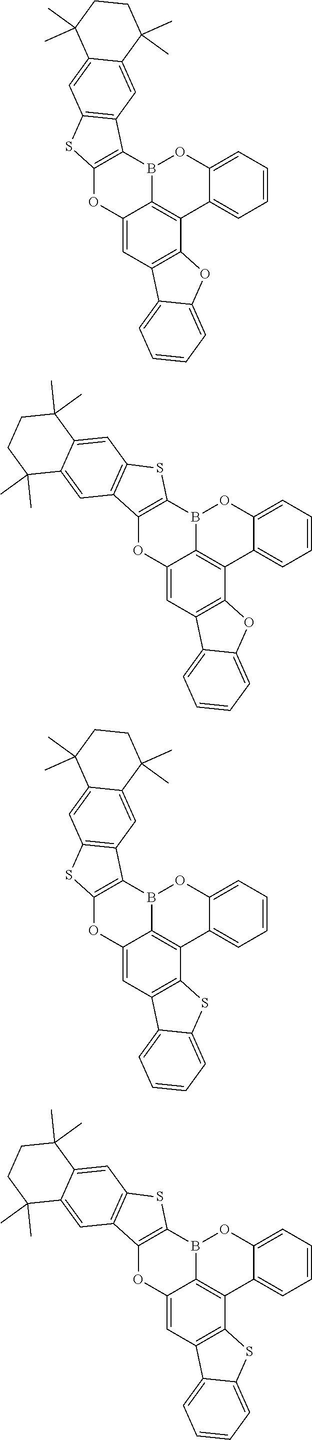 [SMILES: CC1(C)CCC(C)(C)c2cc3c4c(sc3cc21)Oc1cc2c(oc3ccccc32)c2c1B4Oc1ccccc1-2 ; CC1(C)CCC(C)(C)c2cc3c4c(sc3cc21)B1Oc2ccccc2-c2c1c(cc1c2oc2ccccc21)O4 ; CC1(C)CCC(C)(C)c2cc3c4c(sc3cc21)Oc1cc2c(sc3ccccc32)c2c1B4Oc1ccccc1-2 ; CC1(C)CCC(C)(C)c2cc3c4c(sc3cc21)B1Oc2ccccc2-c2c1c(cc1c2sc2ccccc21)O4]

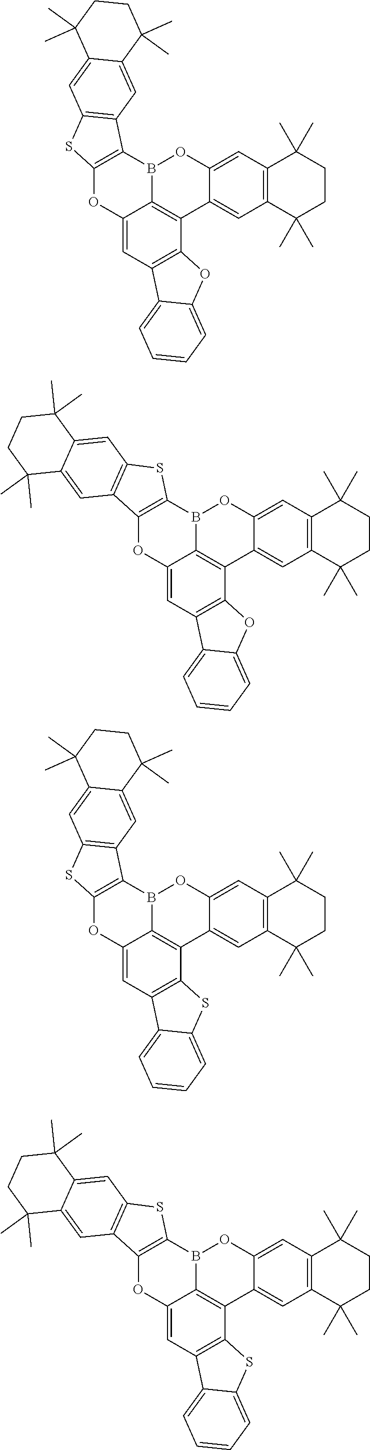 [SMILES: CC1(C)CCC(C)(C)c2cc3c(cc21)OB1c2c(cc4c(oc5ccccc54)c2-3)Oc2sc3cc4c(cc3c21)C(C)(C)CCC4(C)C ; CC1(C)CCC(C)(C)c2cc3c(cc21)OB1c2sc4cc5c(cc4c2Oc2cc4c(oc6ccccc64)c-3c21)C(C)(C)CCC5(C)C ; CC1(C)CCC(C)(C)c2cc3c(cc21)OB1c2c(cc4c(sc5ccccc54)c2-3)Oc2sc3cc4c(cc3c21)C(C)(C)CCC4(C)C ; CC1(C)CCC(C)(C)c2cc3c(cc21)OB1c2sc4cc5c(cc4c2Oc2cc4c(sc6ccccc64)c-3c21)C(C)(C)CCC5(C)C]

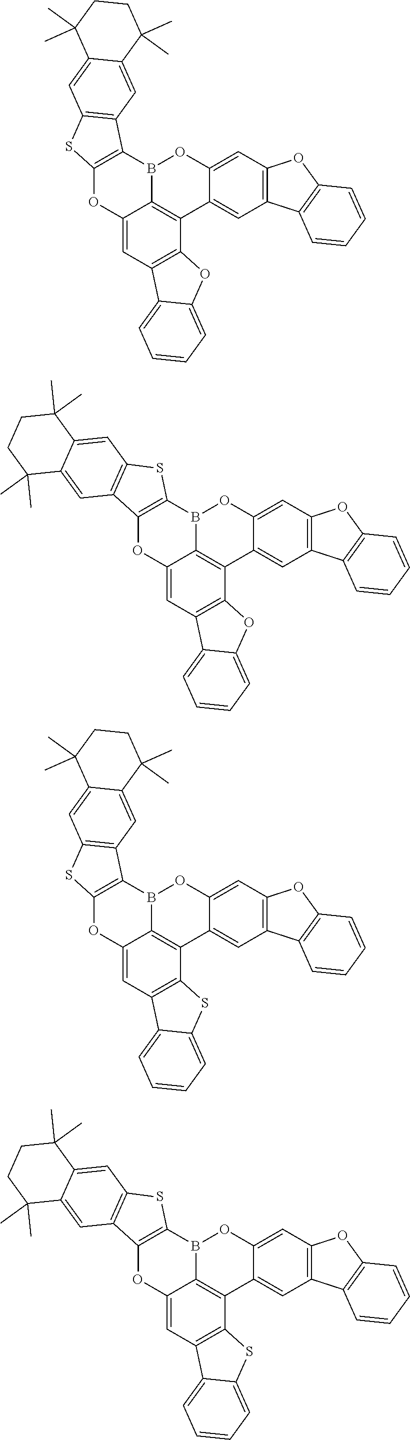 [SMILES: CC1(C)CCC(C)(C)c2cc3c4c(sc3cc21)Oc1cc2c(oc3ccccc32)c2c1B4Oc1cc3oc4ccccc4c3cc1-2 ; CC1(C)CCC(C)(C)c2cc3c4c(sc3cc21)B1Oc2cc3oc5ccccc5c3cc2-c2c1c(cc1c2oc2ccccc21)O4 ; CC1(C)CCC(C)(C)c2cc3c4c(sc3cc21)Oc1cc2c(sc3ccccc32)c2c1B4Oc1cc3oc4ccccc4c3cc1-2 ; CC1(C)CCC(C)(C)c2cc3c4c(sc3cc21)B1Oc2cc3oc5ccccc5c3cc2-c2c1c(cc1c2sc2ccccc21)O4]

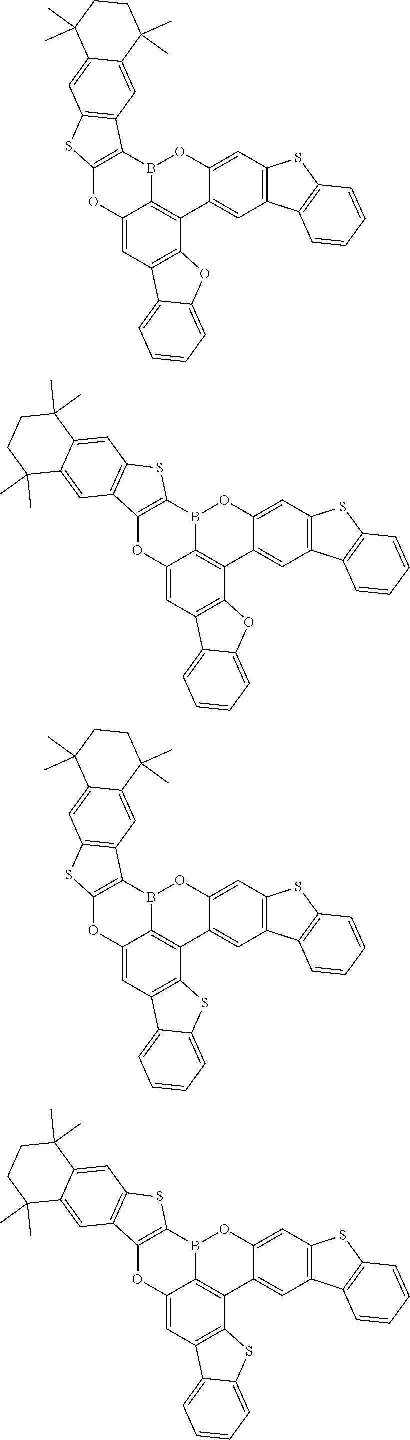 [SMILES: CC1(C)CCC(C)(C)c2cc3c4c(sc3cc21)Oc1cc2c(oc3ccccc32)c2c1B4Oc1cc3sc4ccccc4c3cc1-2 ; CC1(C)CCC(C)(C)c2cc3c4c(sc3cc21)B1Oc2cc3sc5ccccc5c3cc2-c2c1c(cc1c2oc2ccccc21)O4 ; CC1(C)CCC(C)(C)c2cc3c4c(sc3cc21)Oc1cc2c(sc3ccccc32)c2c1B4Oc1cc3sc4ccccc4c3cc1-2 ; CC1(C)CCC(C)(C)c2cc3c4c(sc3cc21)B1Oc2cc3sc5ccccc5c3cc2-c2c1c(cc1c2sc2ccccc21)O4]

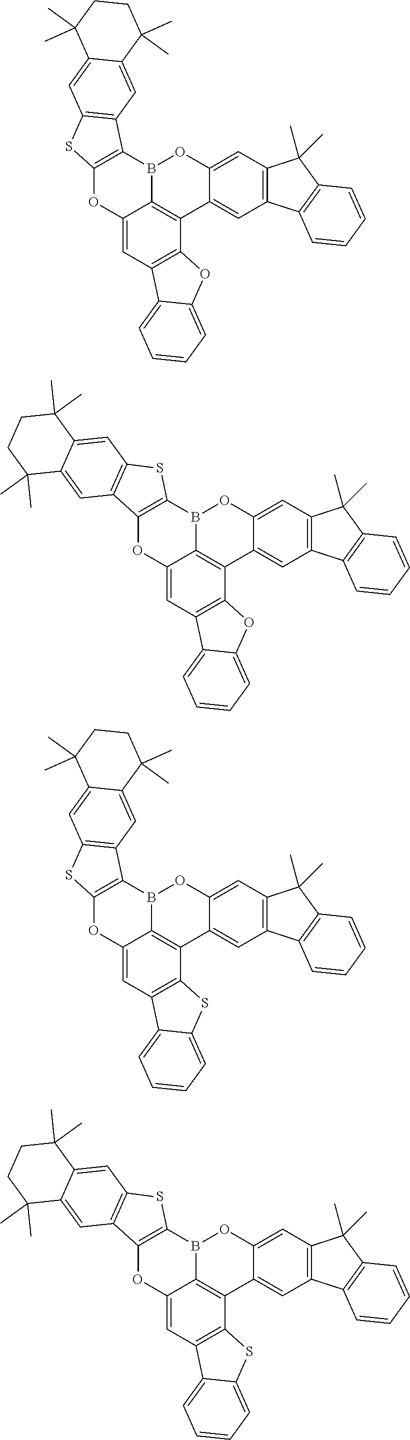 [SMILES: CC1(C)CCC(C)(C)c2cc3c4c(sc3cc21)Oc1cc2c(oc3ccccc32)c2c1B4Oc1cc3c(cc1-2)-c1ccccc1C3(C)C ; CC1(C)CCC(C)(C)c2cc3c4c(sc3cc21)B1Oc2cc3c(cc2-c2c1c(cc1c2oc2ccccc21)O4)-c1ccccc1C3(C)C ; CC1(C)CCC(C)(C)c2cc3c4c(sc3cc21)Oc1cc2c(sc3ccccc32)c2c1B4Oc1cc3c(cc1-2)-c1ccccc1C3(C)C ; CC1(C)CCC(C)(C)c2cc3c4c(sc3cc21)B1Oc2cc3c(cc2-c2c1c(cc1c2sc2ccccc21)O4)-c1ccccc1C3(C)C]

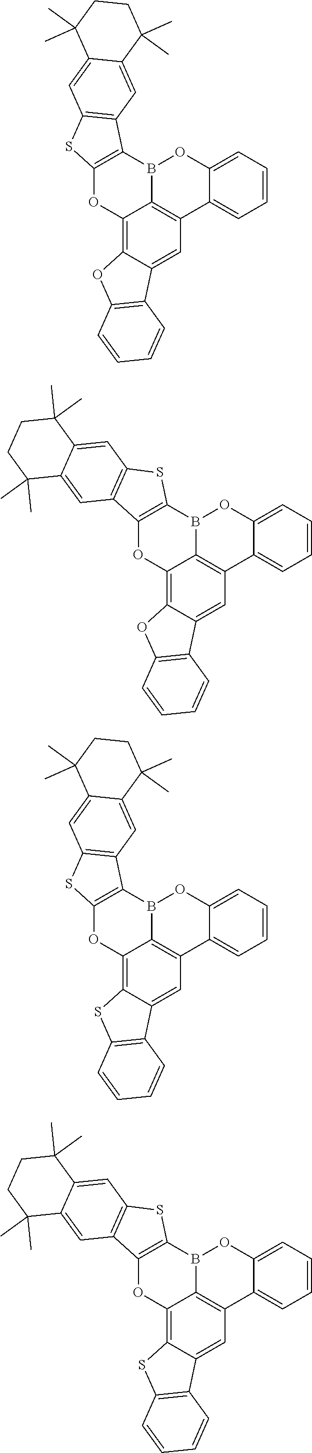

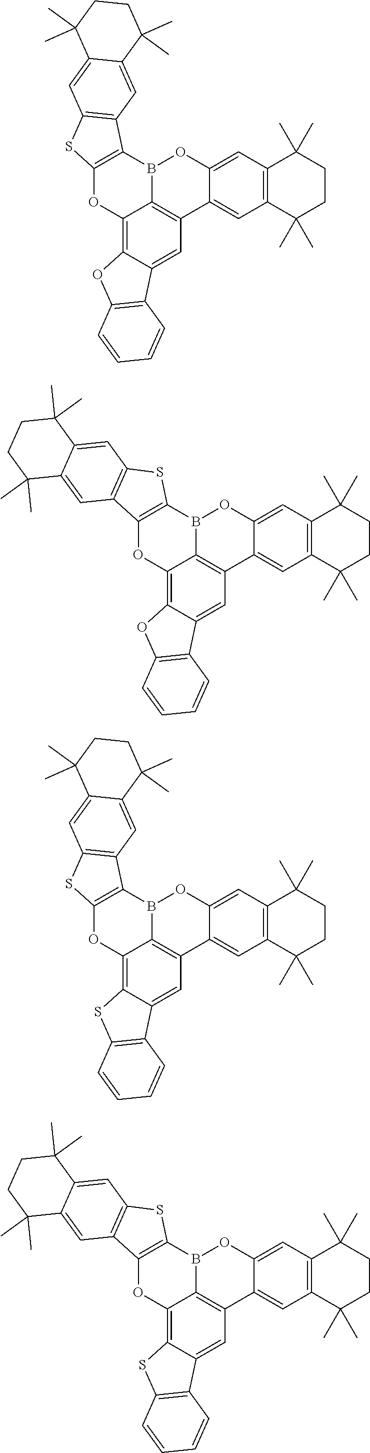

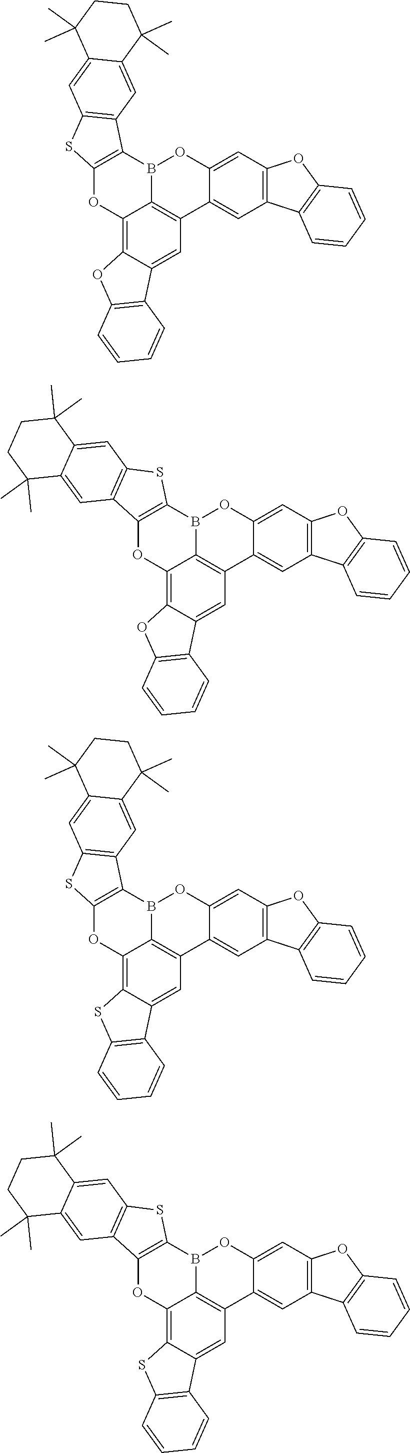

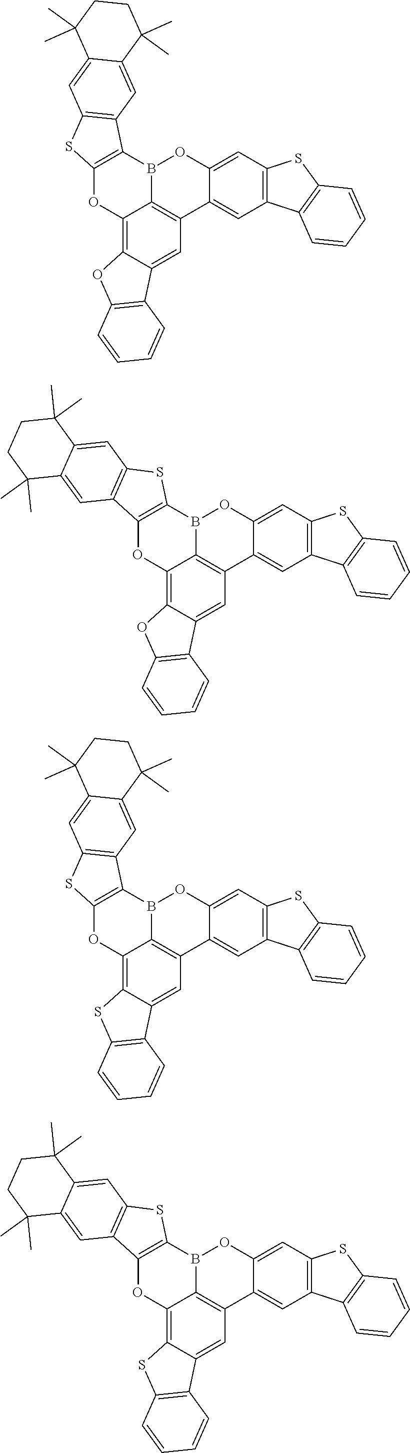

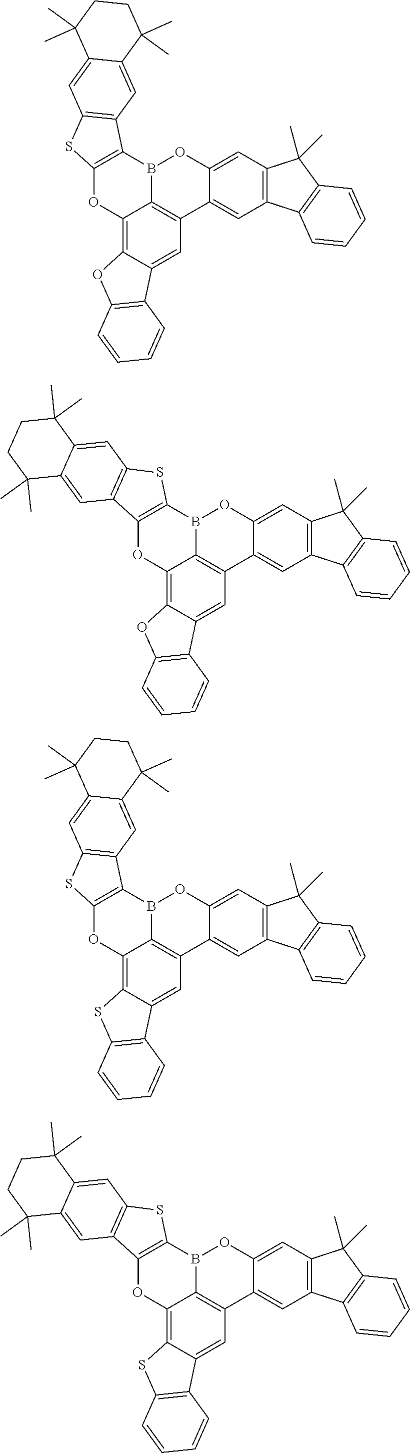

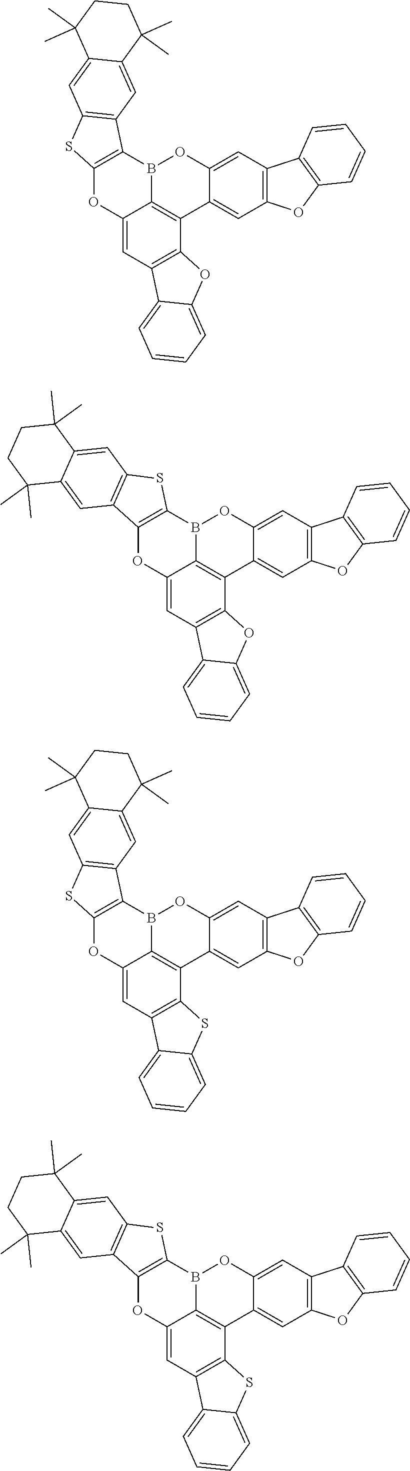

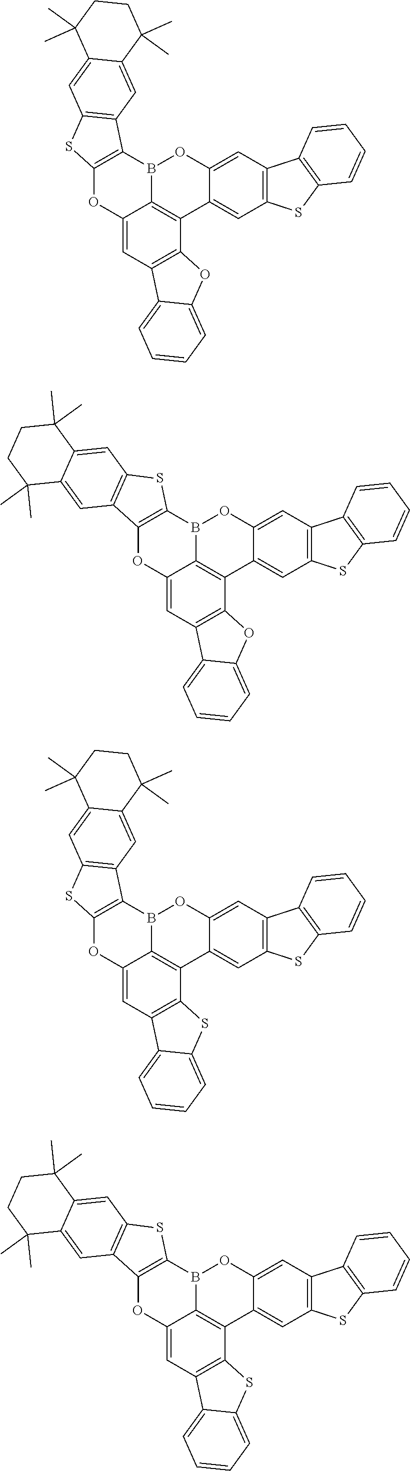

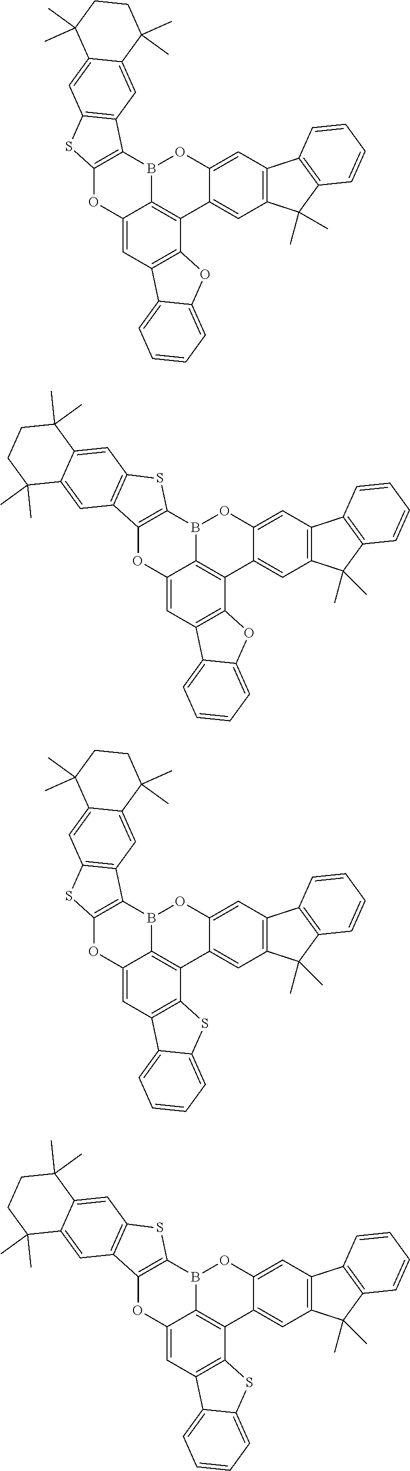

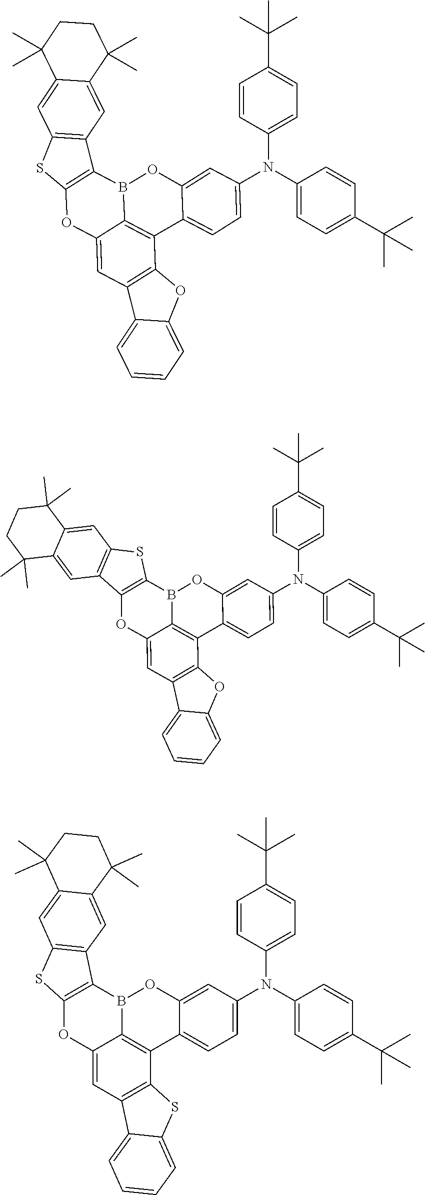

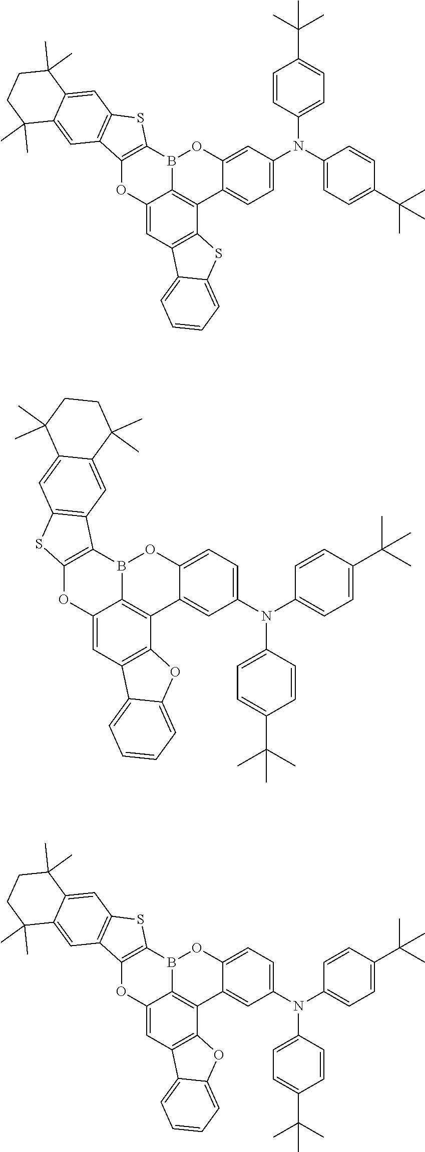

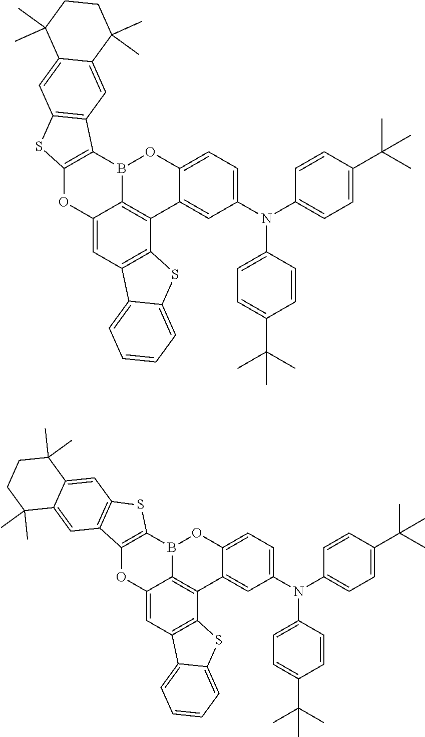

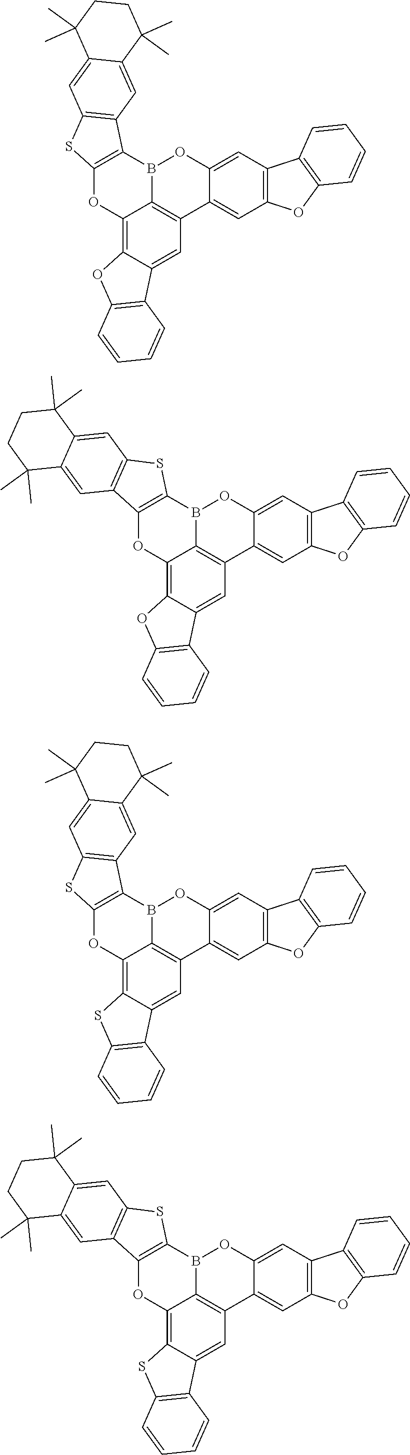

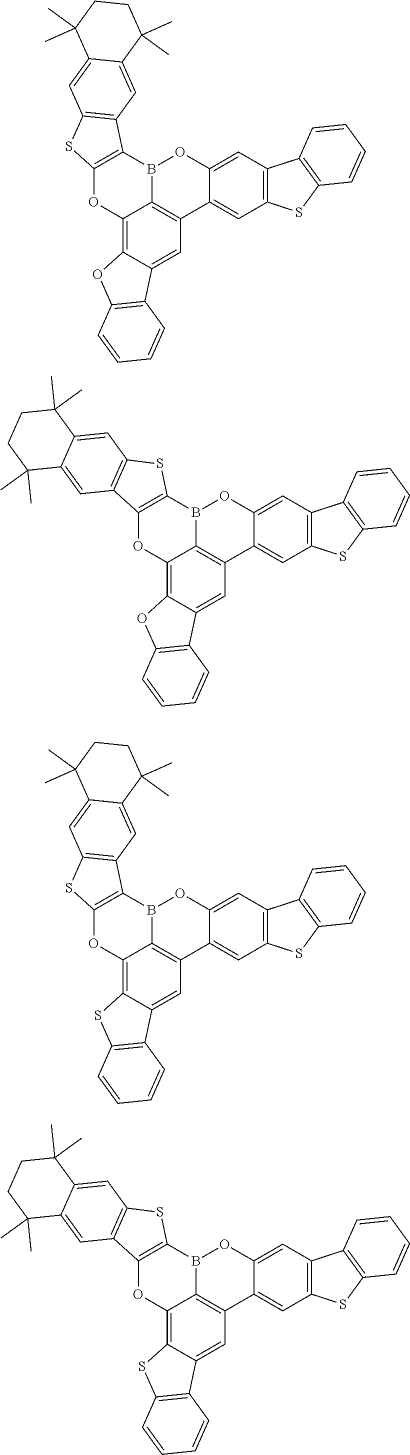

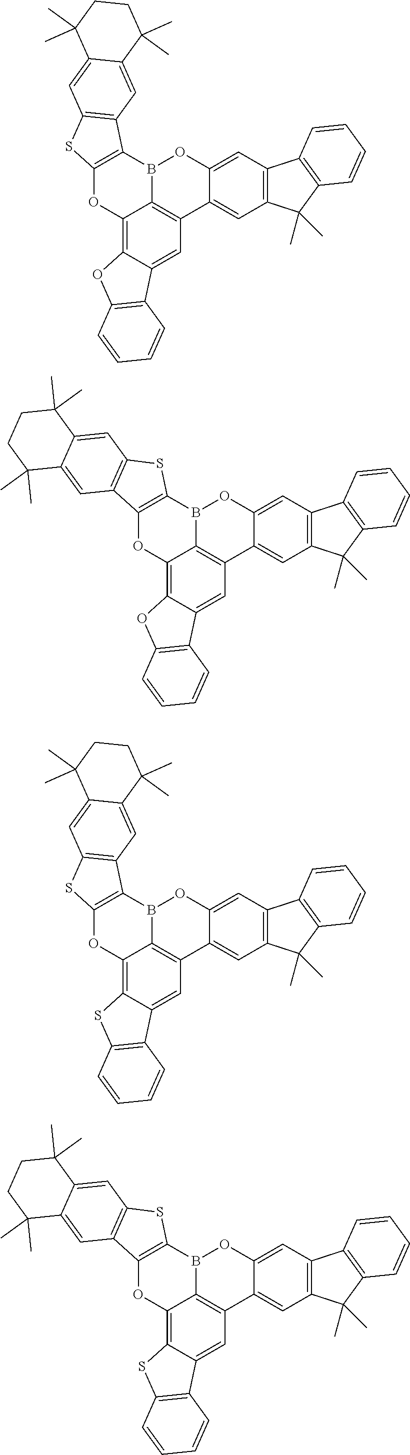

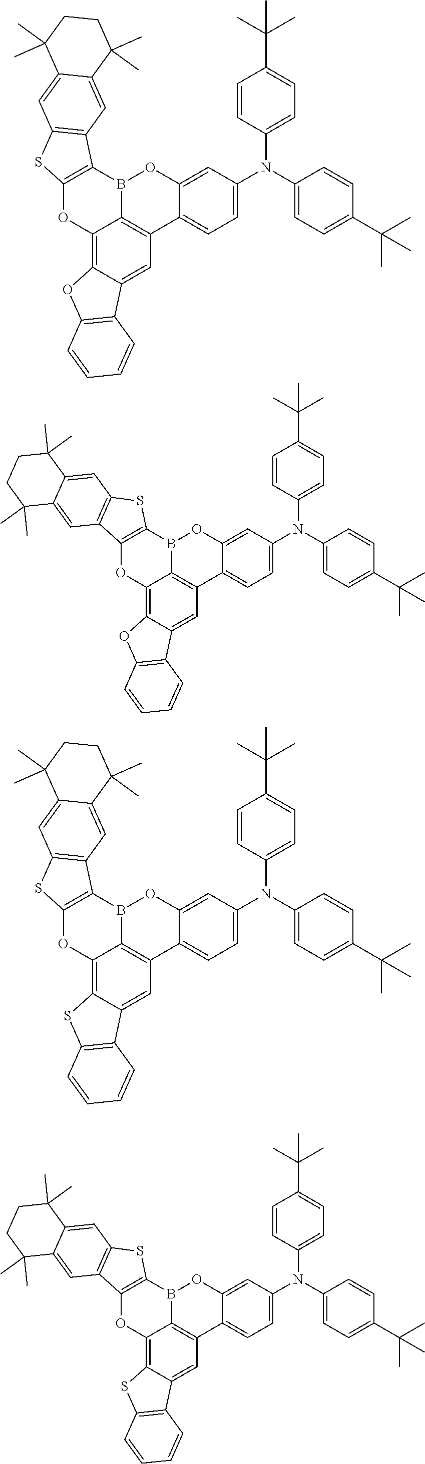

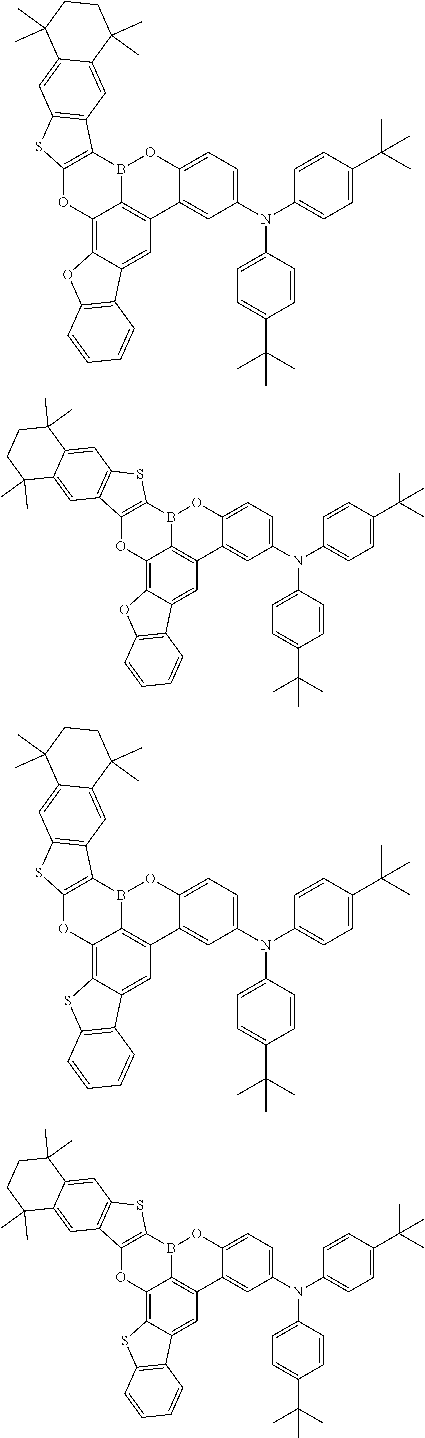

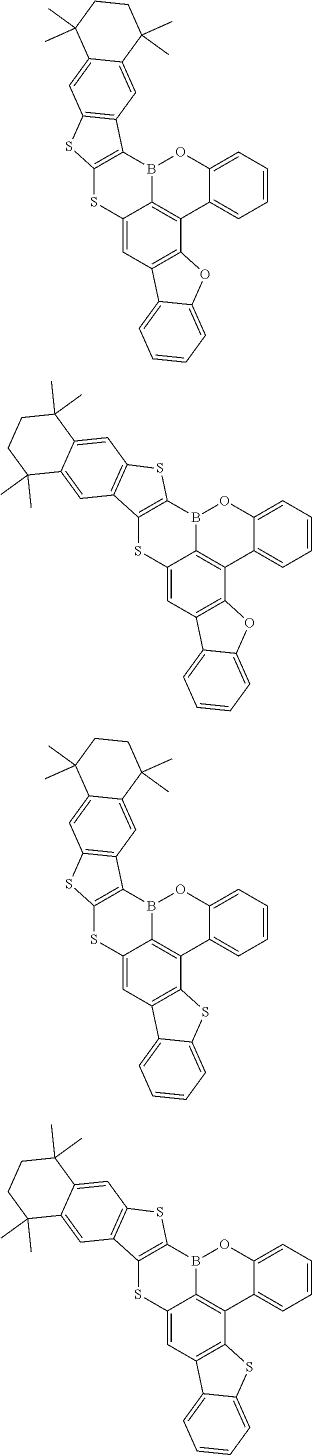

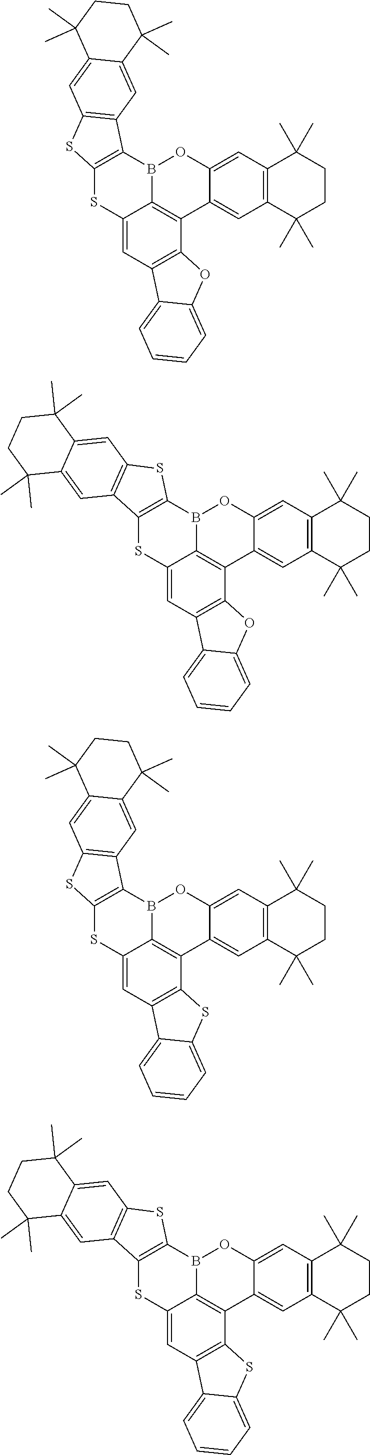

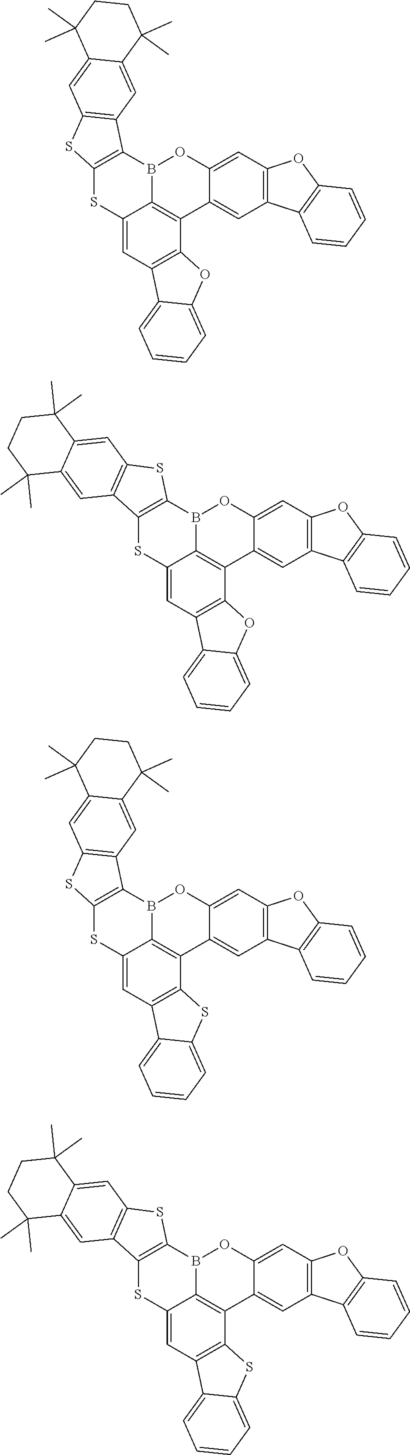

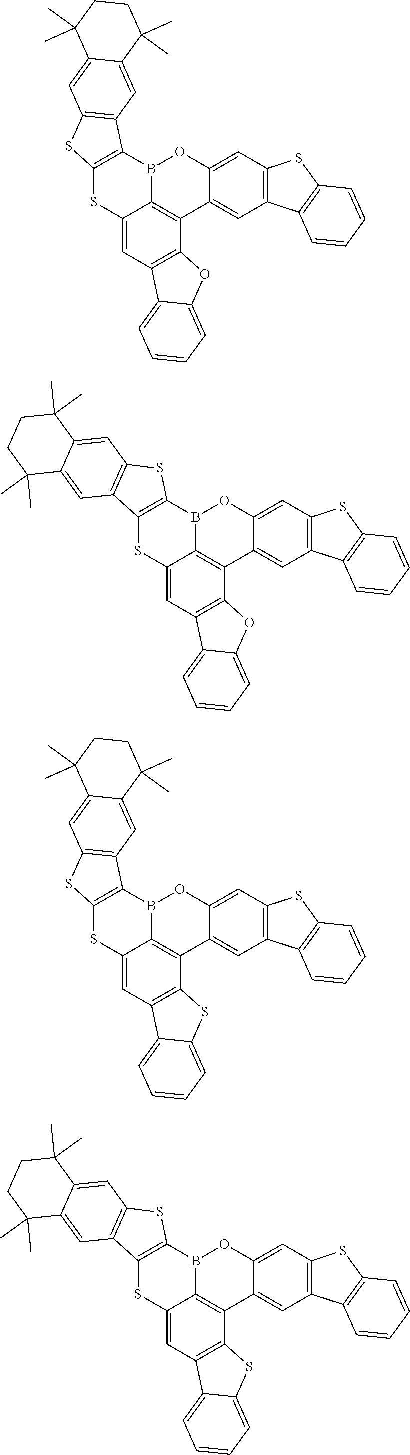

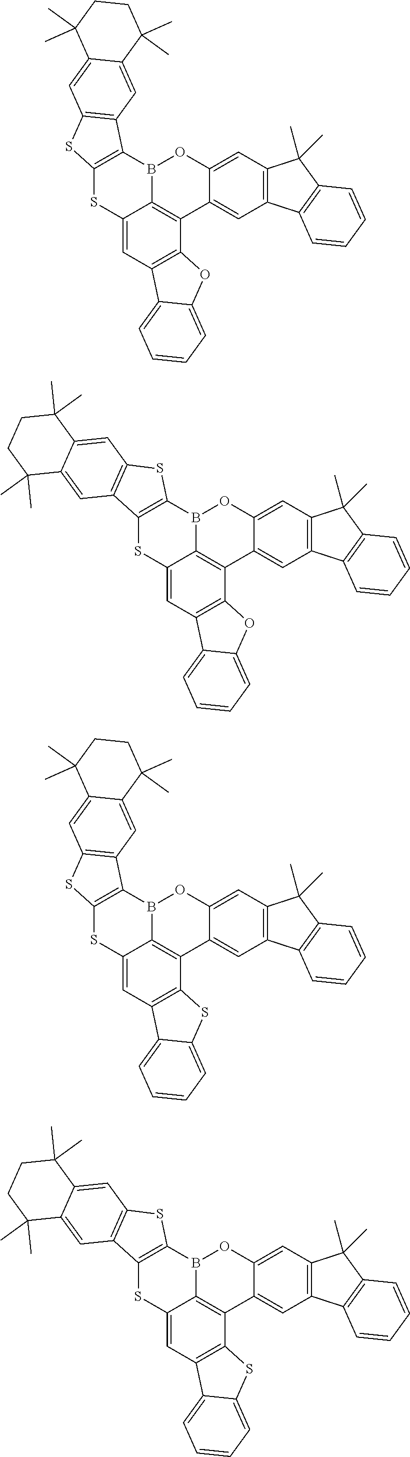

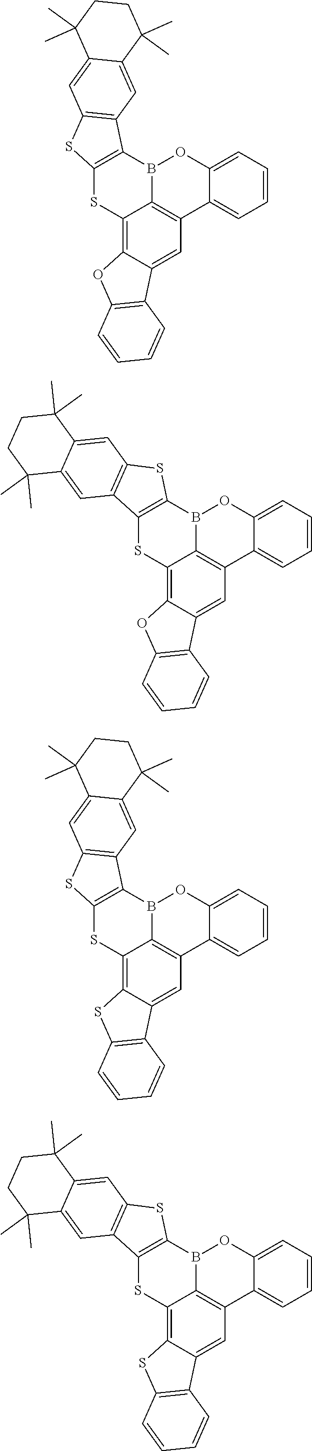

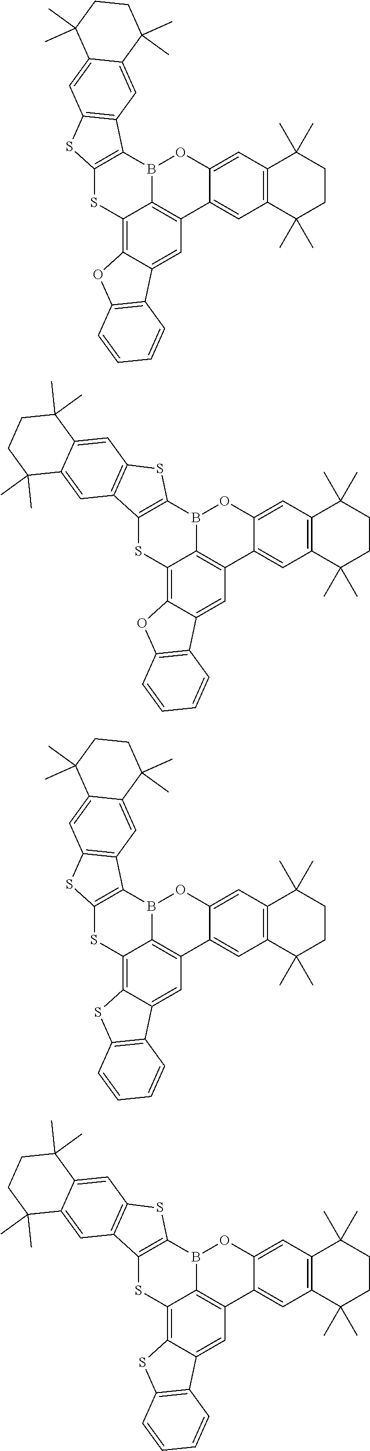

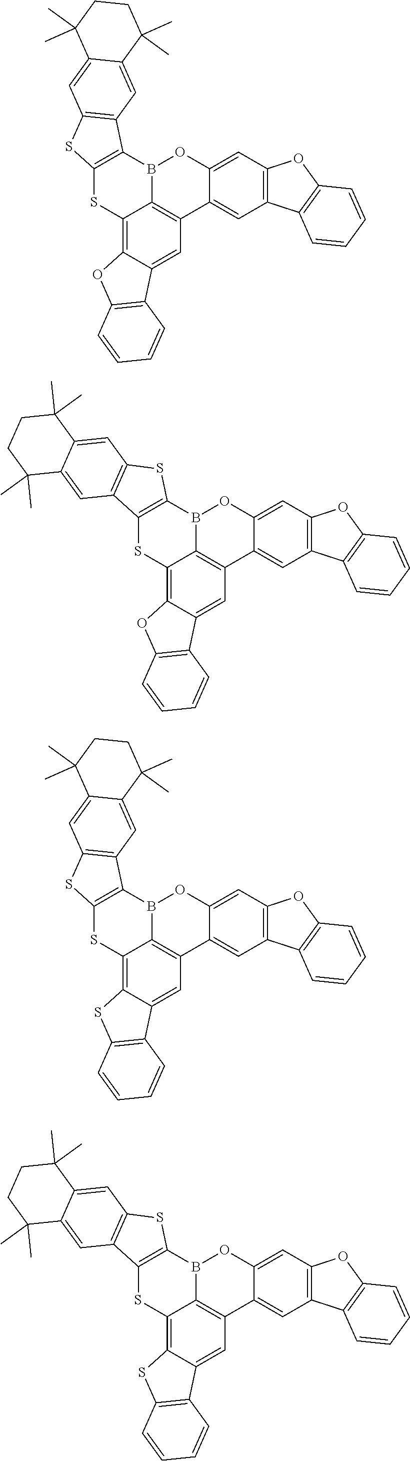

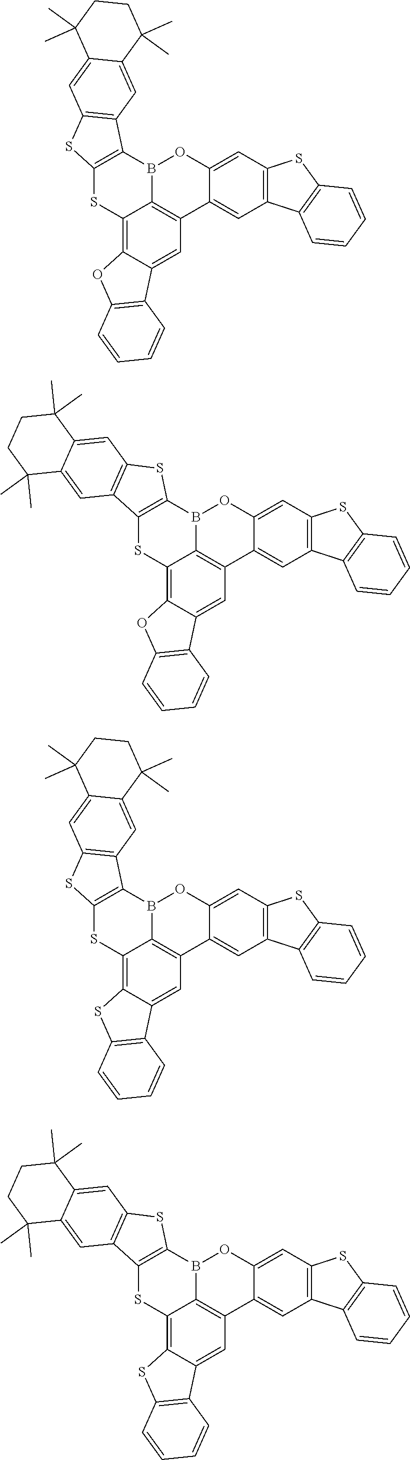

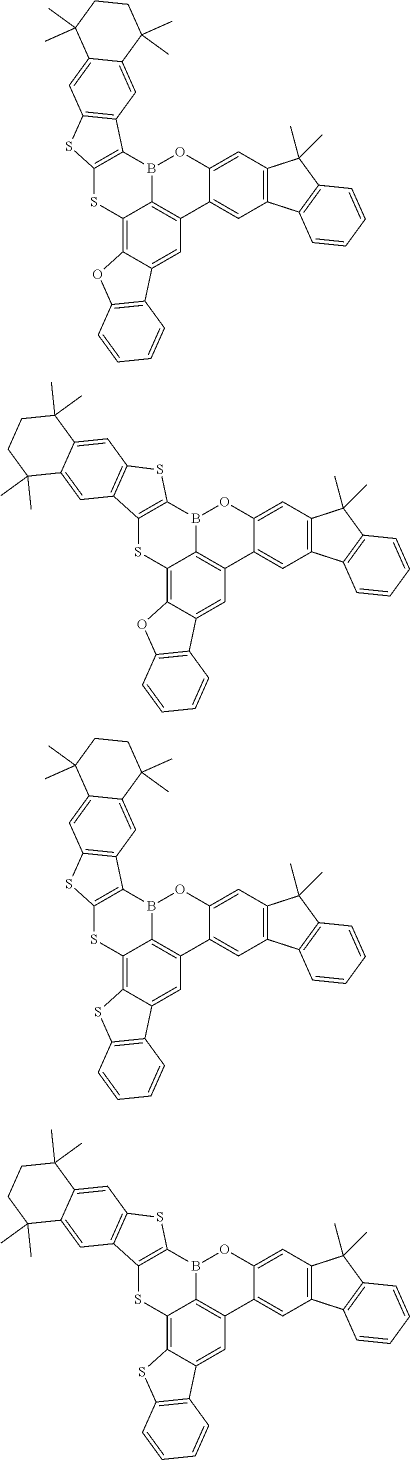

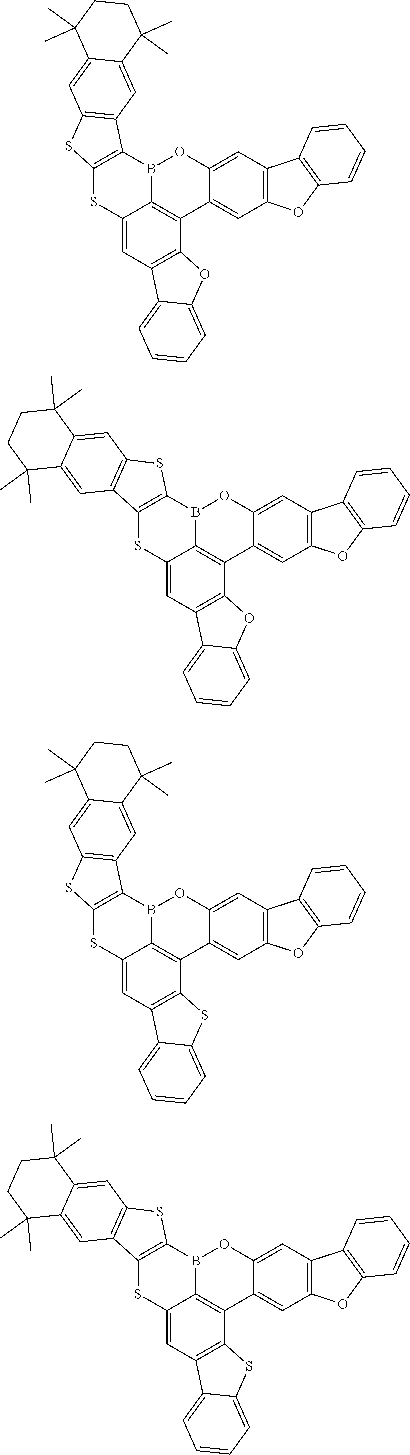

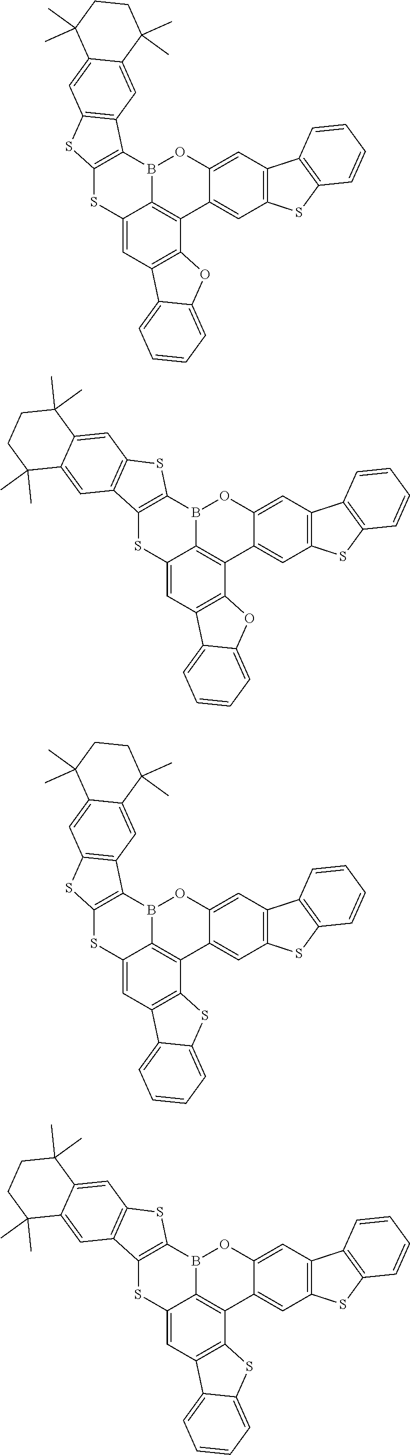

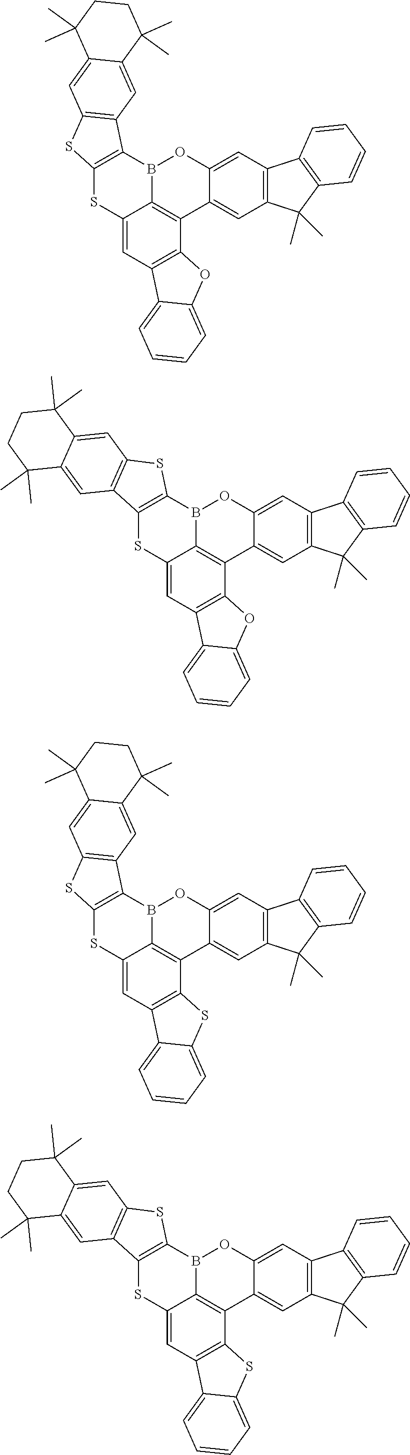

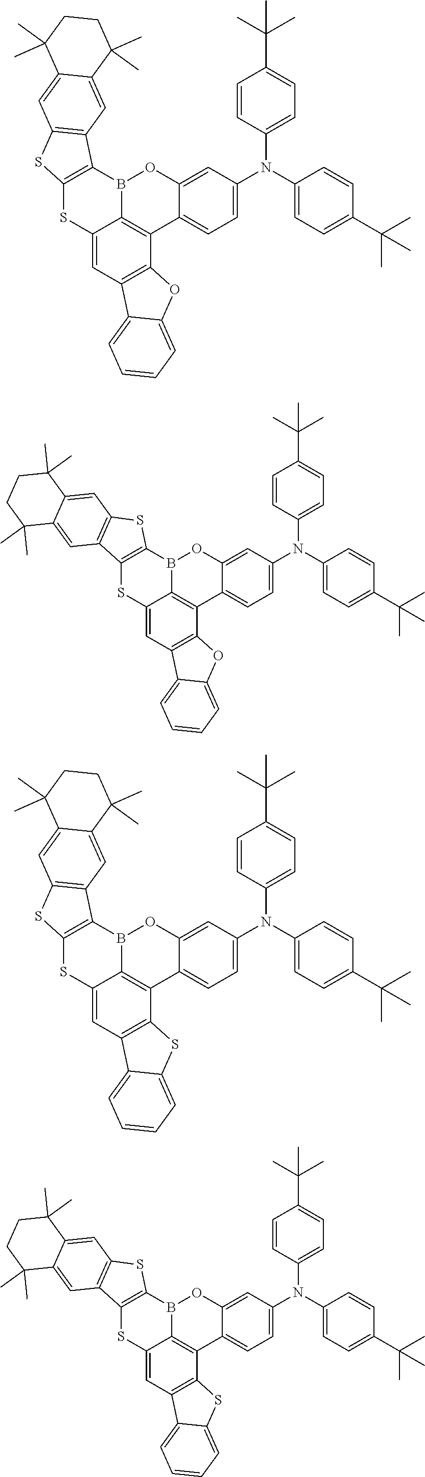

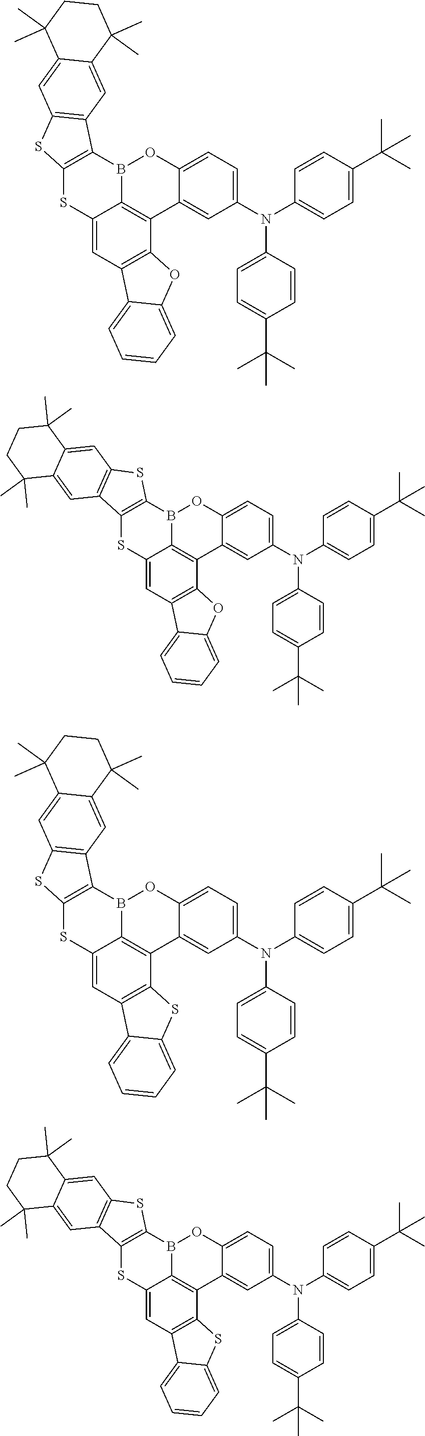

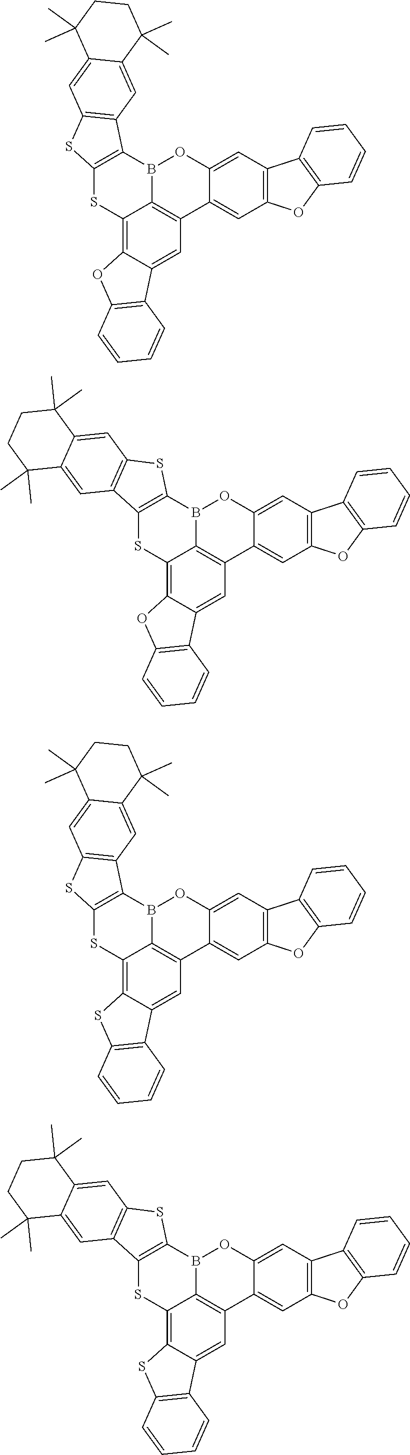

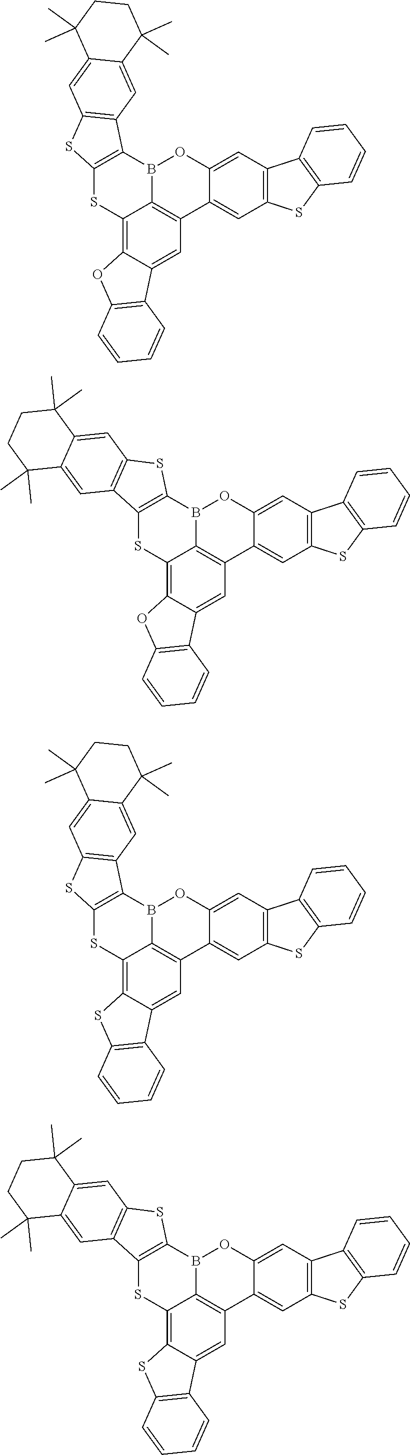

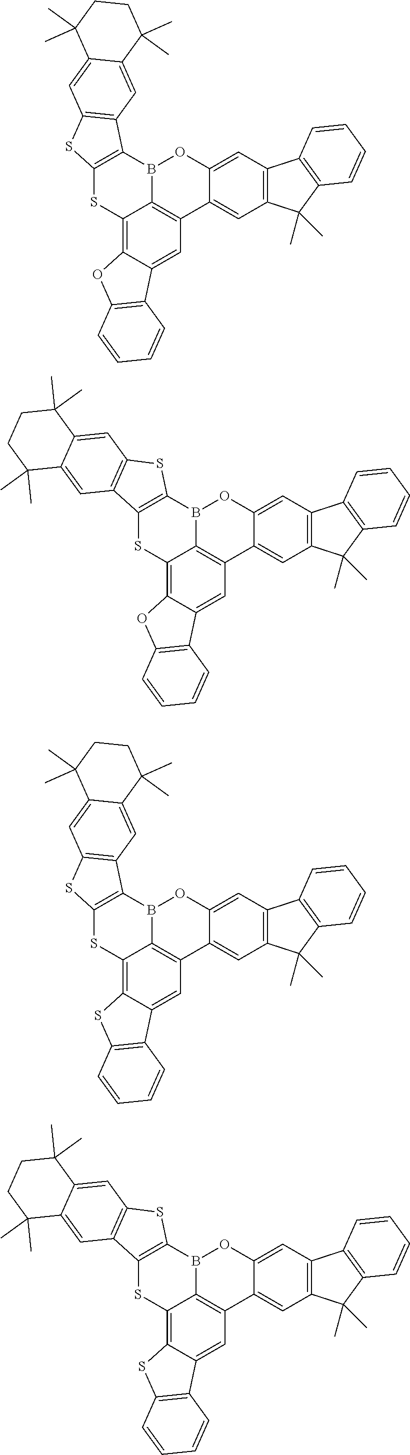

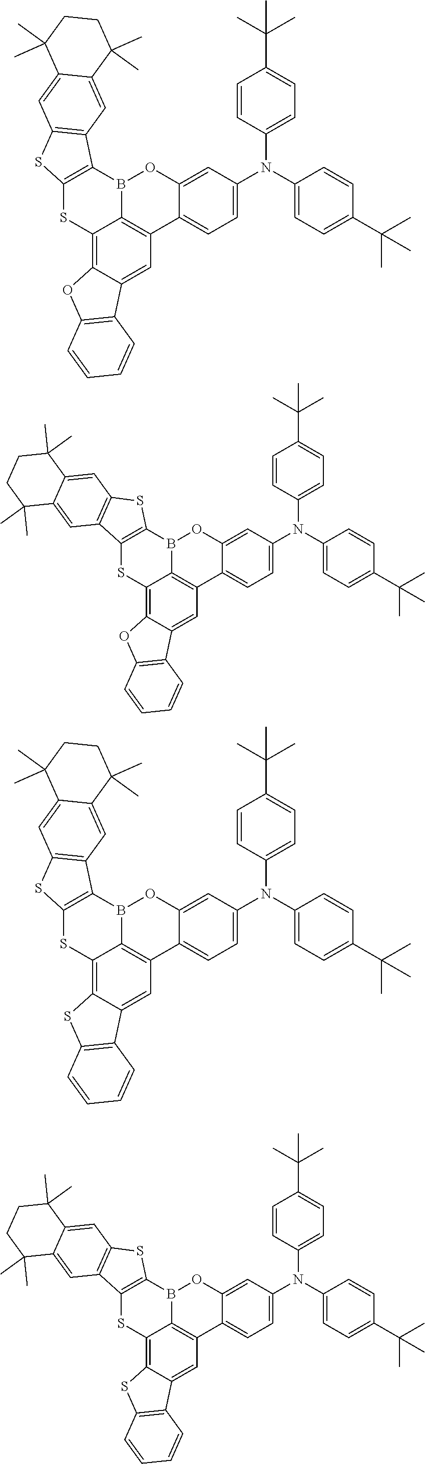

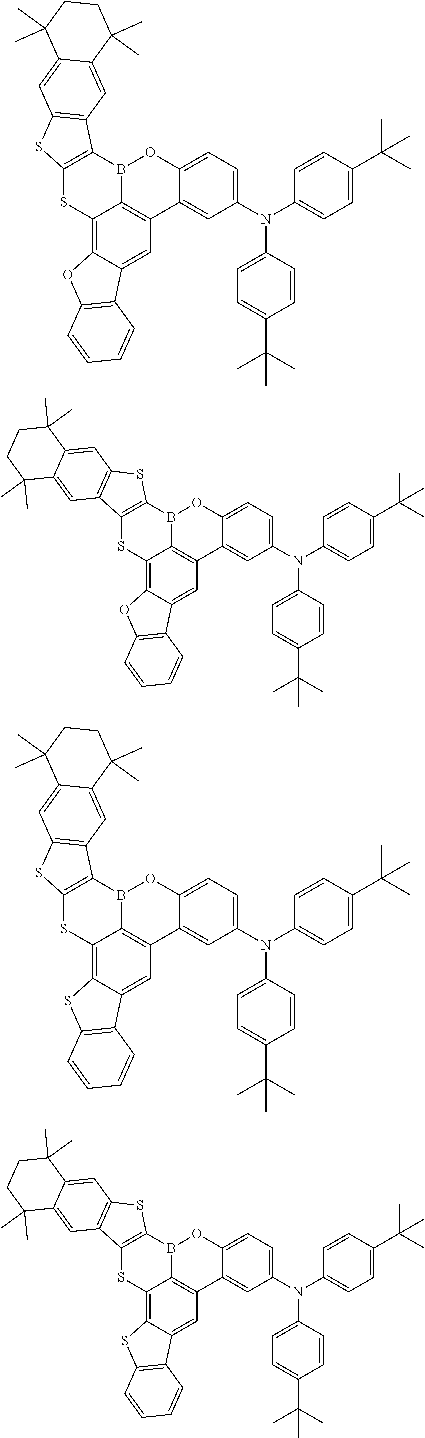

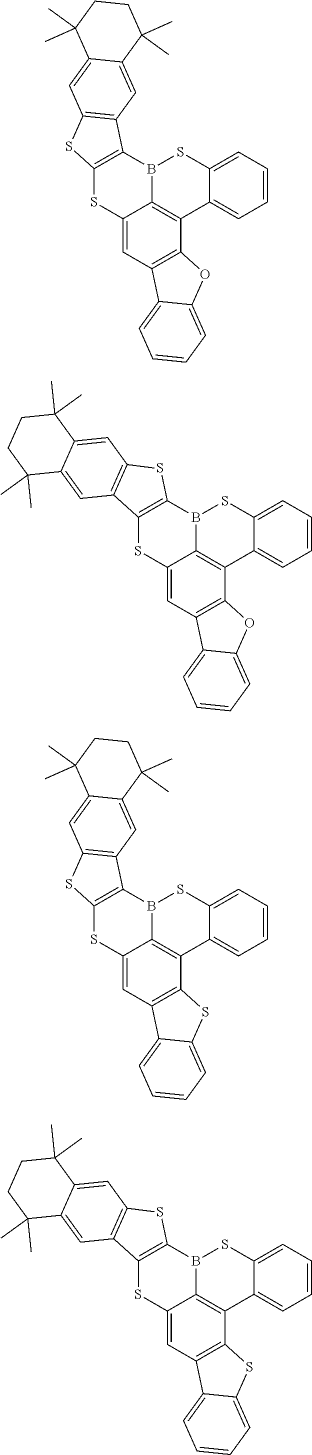

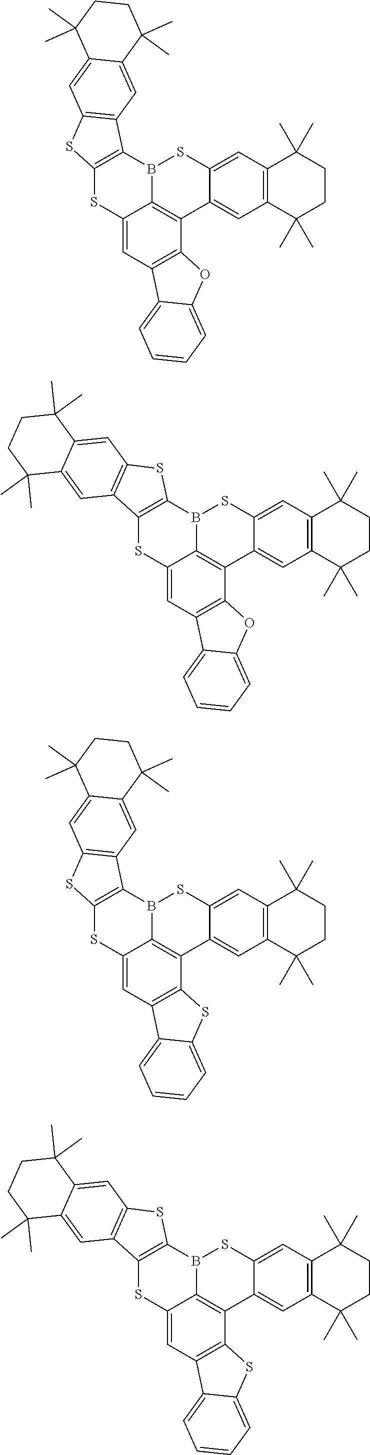

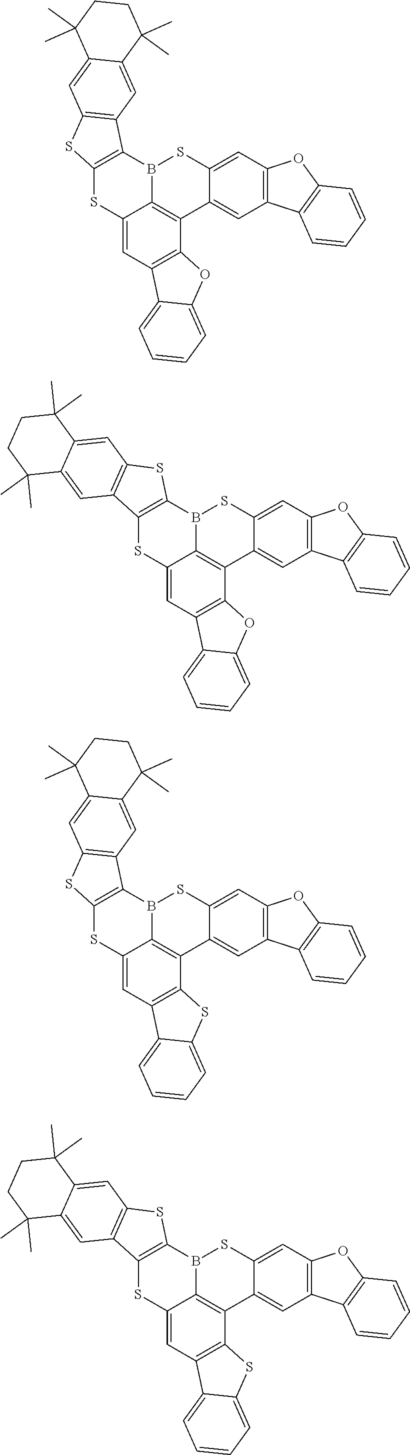

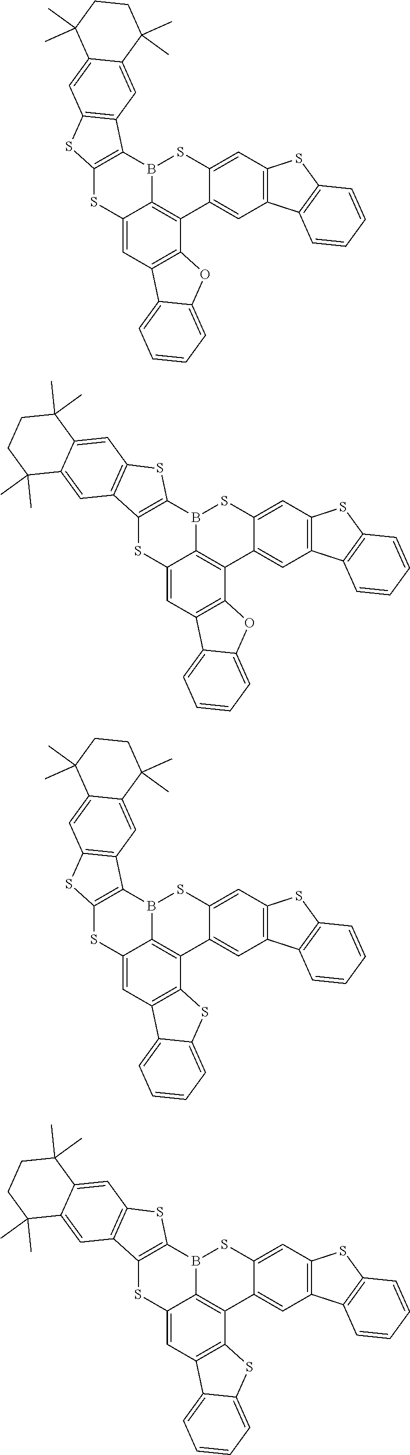

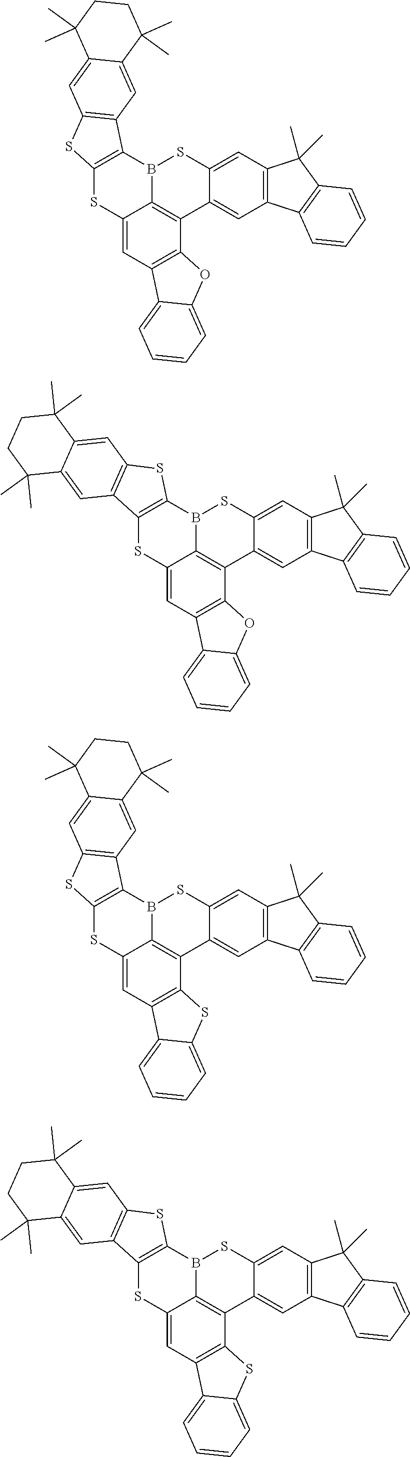

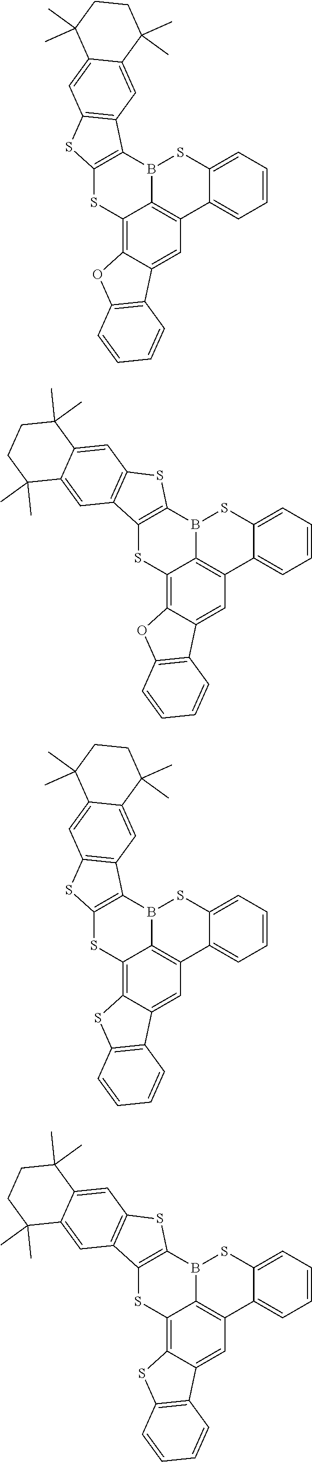

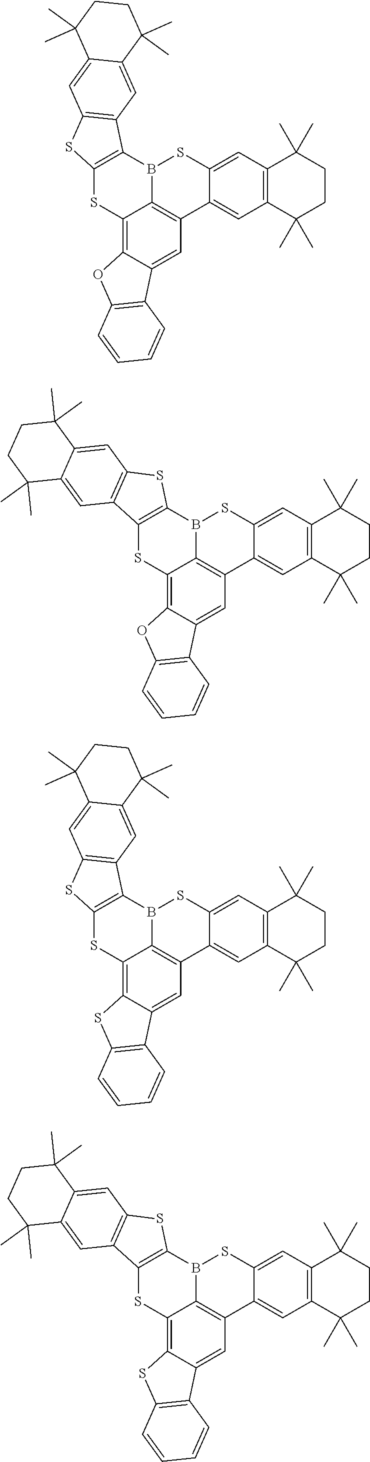

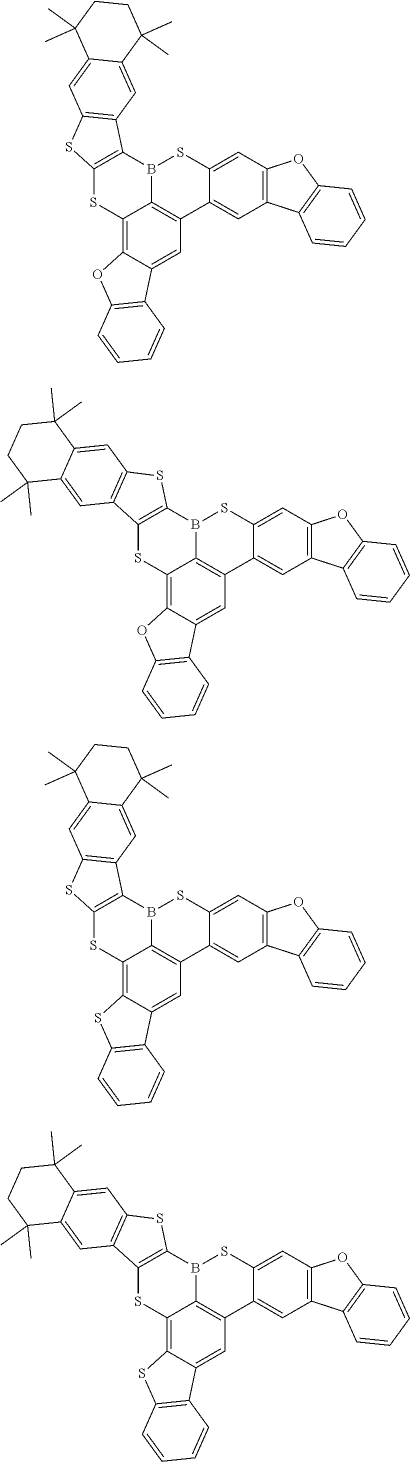

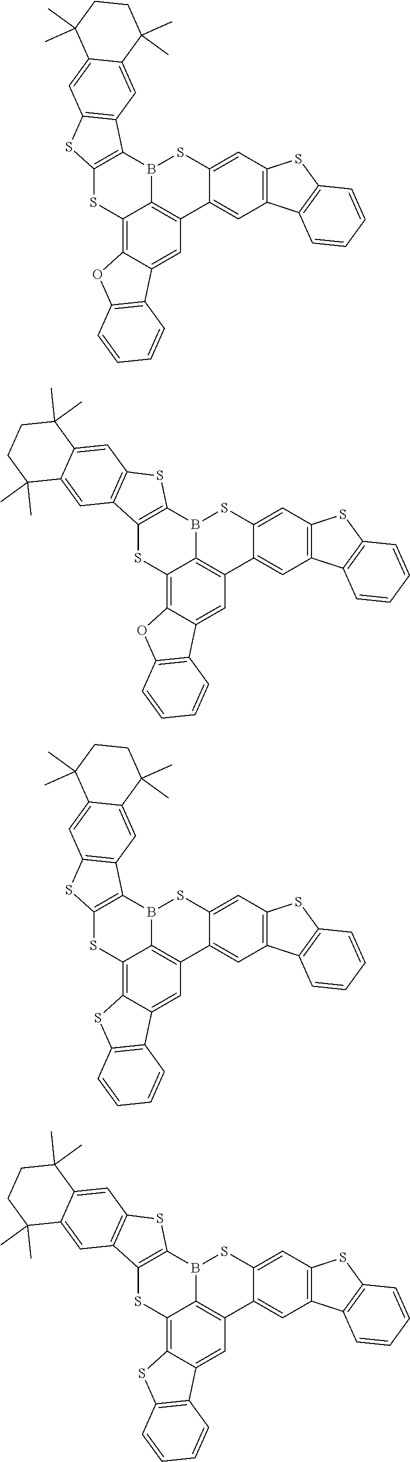

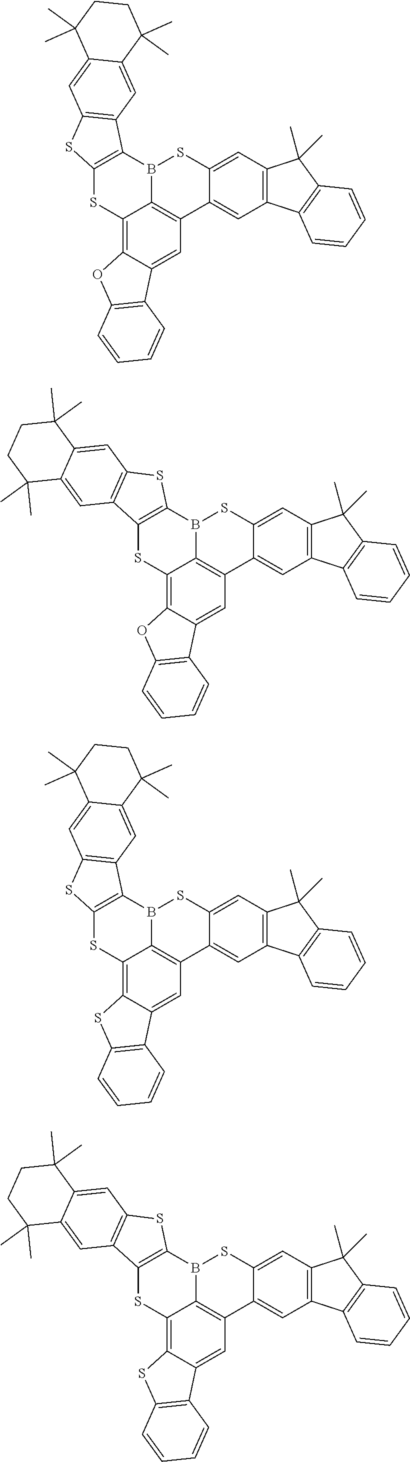

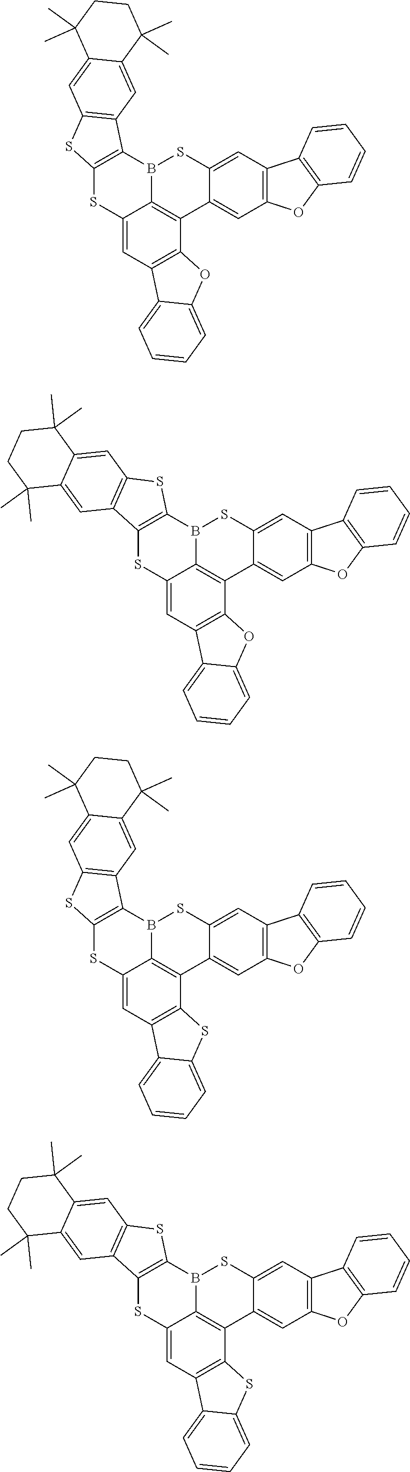

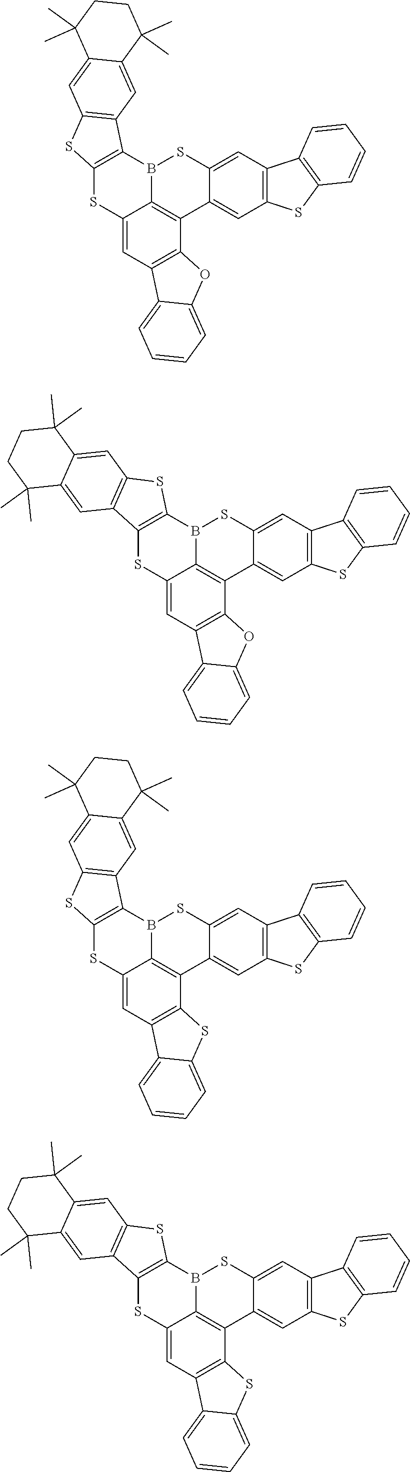

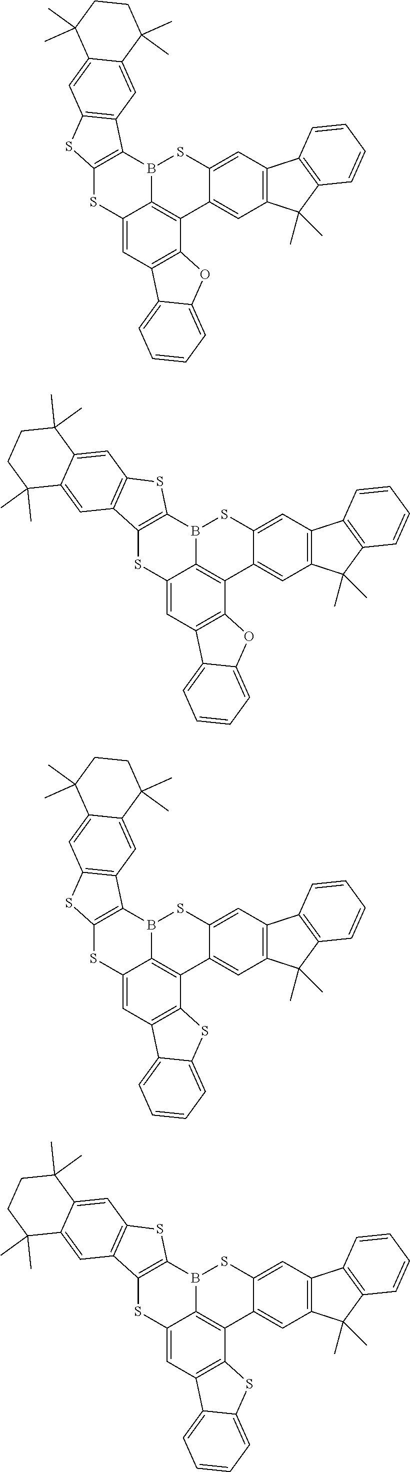

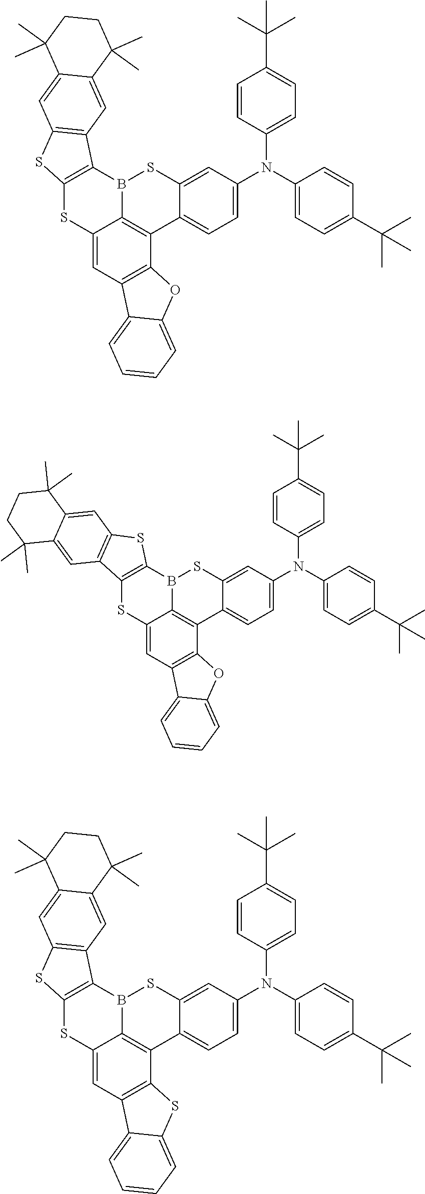

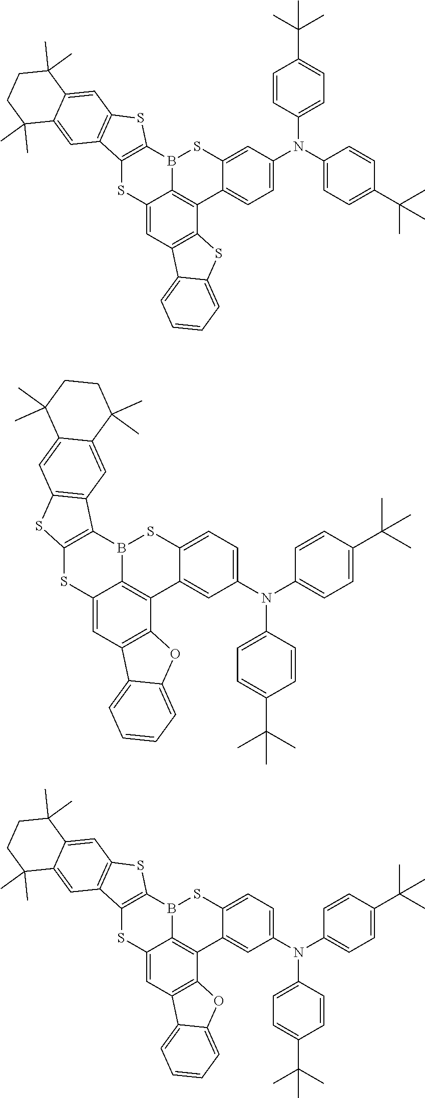

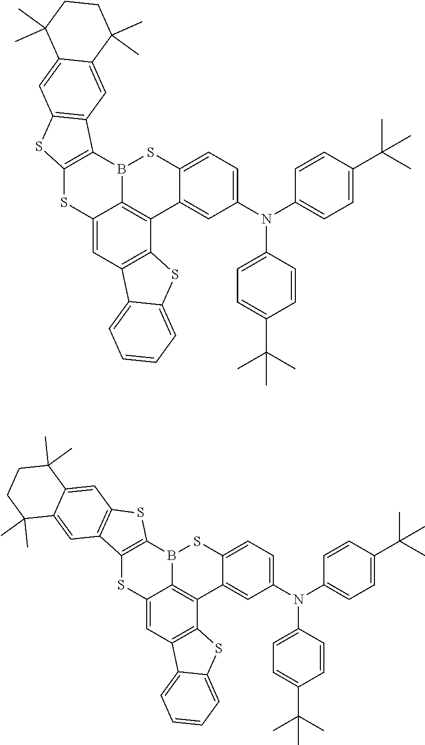

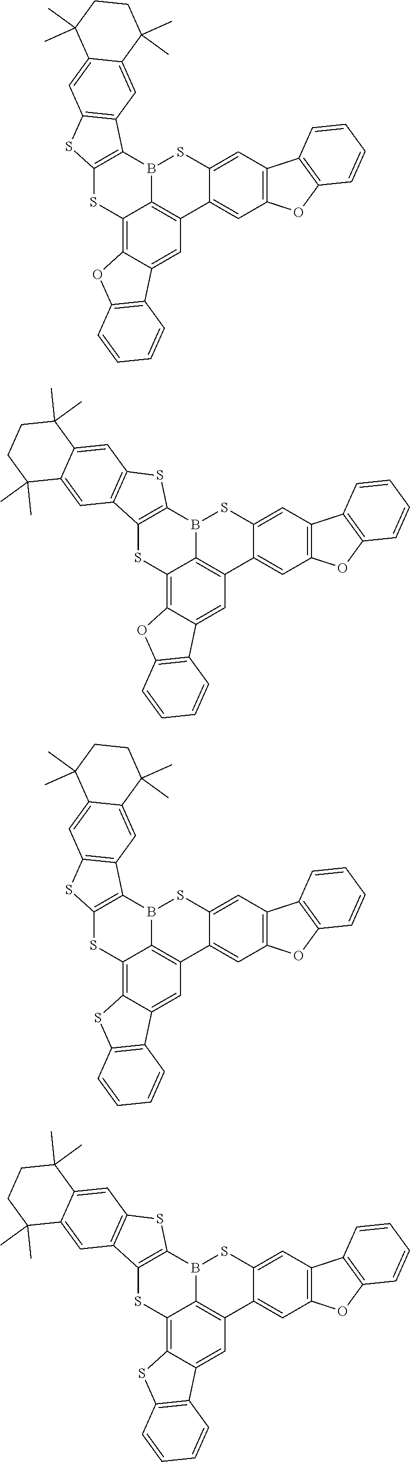

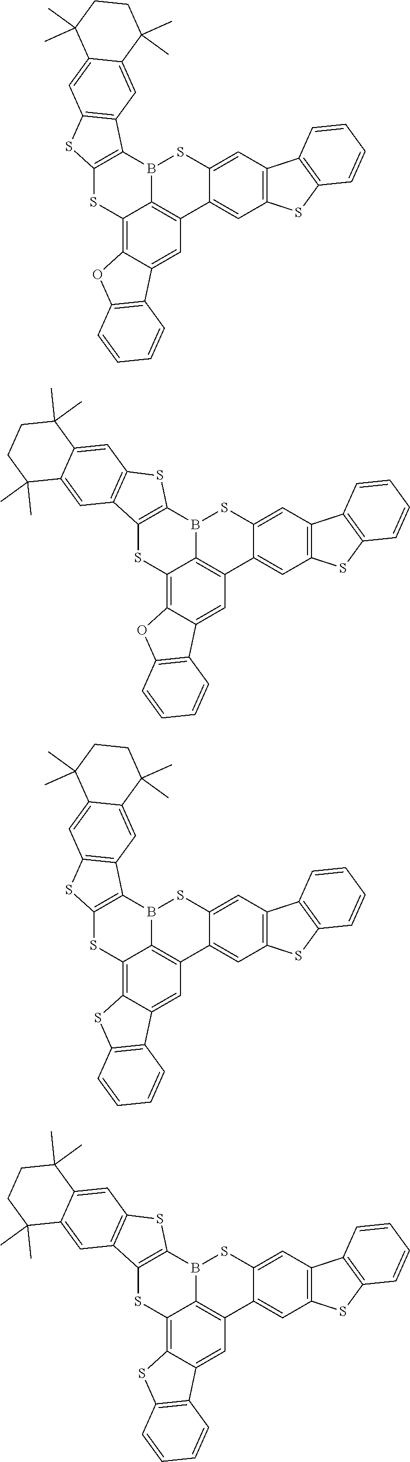

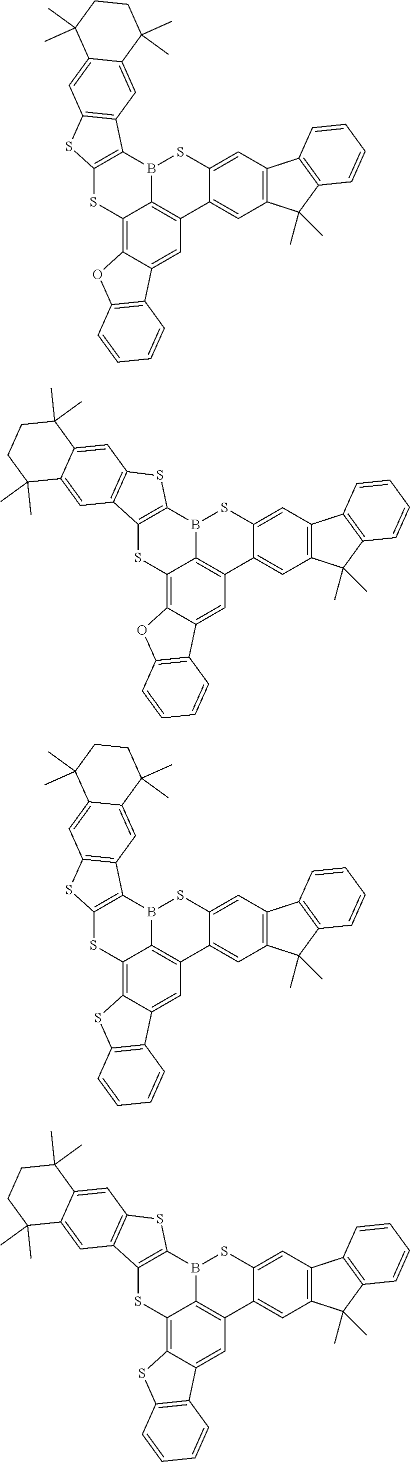

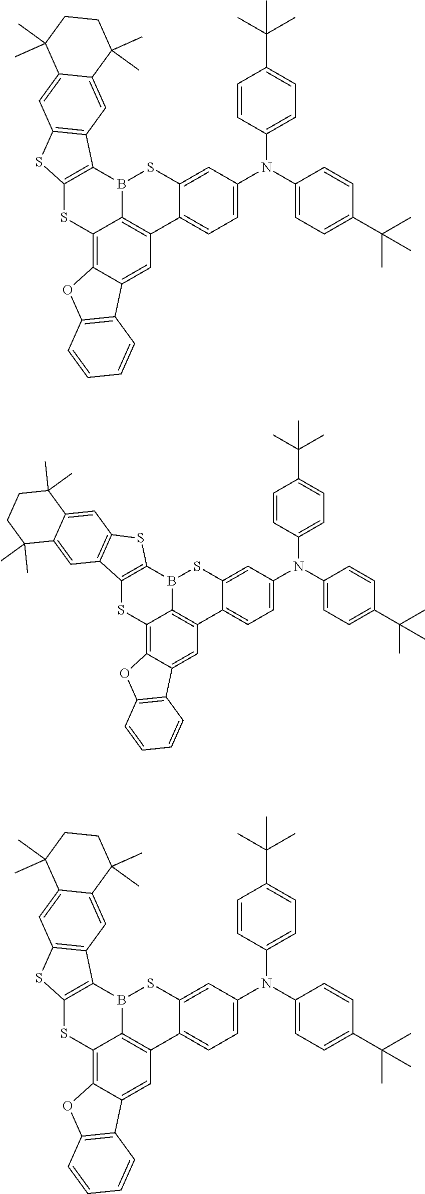

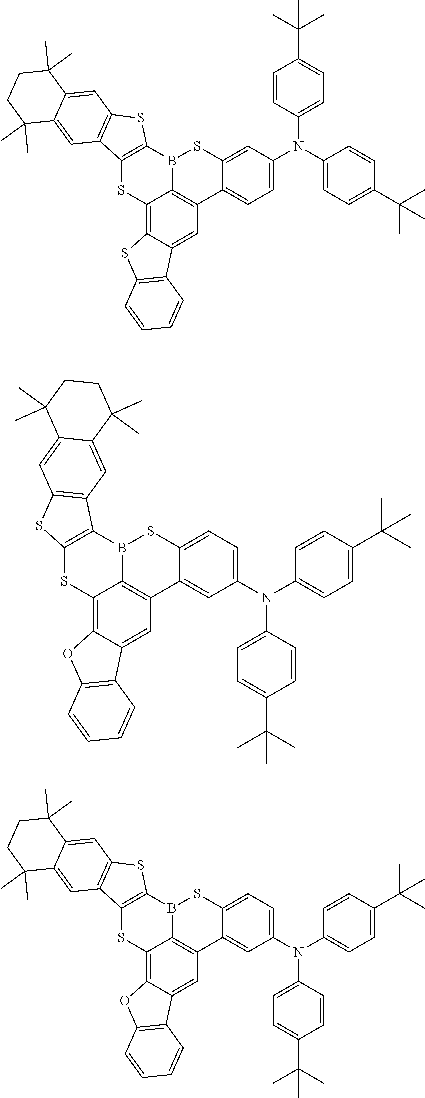

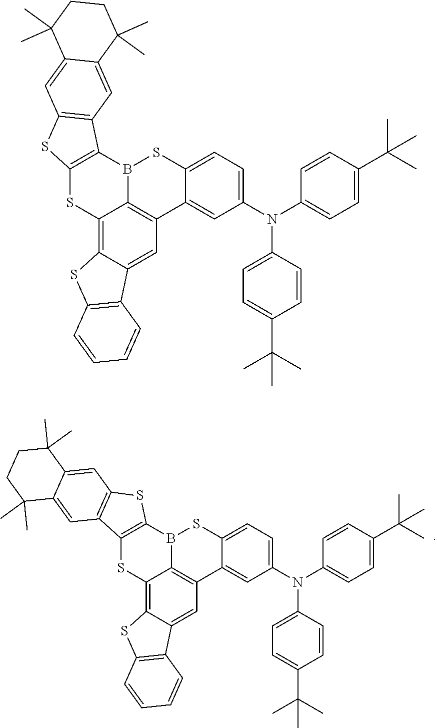

13. An organic light emitting device comprising:
a positive electrode;
a negative electrode; and
an organic material layer having one or more layers provided between the positive electrode and the negative electrode,
wherein one or more layers of the organic material layers comprises the compound of claim 1.

14. The organic light emitting device of claim 13, wherein the organic material layer comprises a light emitting layer, and the light emitting layer comprises the compound.

15. The organic light emitting device of claim 14, wherein the compound is comprised as a dopant.
